(19) United States
(12) Patent Application Publication
(10) Pub. No.: US 2026/0123620 A1
(43) Pub. Date: May 7, 2026

(54) LASER - BASED TARGETING AND OBJECT DETECTION SYSTEM

(71) Applicant: Nick Reyntjens, Bansko (BG)

(72) Inventor: Nick Reyntjens, Bansko (BG)

(21) Appl. No.: 19/356,064

(22) Filed: Oct. 11, 2025

(30) Foreign Application Priority Data
Nov. 6, 2024 (PT) 20242006625149
Nov. 24, 2024 (PT) 20242006664541
Nov. 25, 2024 (PT) 20242006675131
Dec. 20, 2024 (PT) 20242006734540
May 18, 2025 (PT) 20252007097835
Jun. 23, 2025 (PT) 20252007174414
Jun. 26, 2025 (PT) 20252007182971
Jul. 3, 2025 (PT) 20252007196586
Jul. 7, 2025 (PT) 20252007204100
Jul. 17, 2025 (PT) 20252007228492
Jul. 30, 2025 (PT) 20252007254684
Aug. 17, 2025 (PT) 20252007287994
Aug. 23, 2025 (PT) 20252007300012
Sep. 6, 2025 (PT) 20252007329606
Sep. 28, 2025 (PT) 20252007377096

(51) Int. Cl. A01M 3/00; A01M 21/04; B60K 1/04; B64U 10/14; B64U 20/87; B64U 50/39; B64U 101/40; G02B 26/08; G06T 7/70; H01S 5/00

(52) U.S. Cl. CPC A01M 3/007; A01M 21/046; B60K 1/04; B64U 10/14; B64U 20/87; B64U 50/39; G02B 26/0833; G06T 7/70; H01S 5/0071; A01M 2200/011; B60K 2001/0466; B64U 2101/40; G06T 2207/30196

(57) ABSTRACT

A pest control system is disclosed comprising an optical, computational, and monitoring subsystem, optionally mounted on a mobile platform. The optical system may include a neutralizing laser or multi-wavelength light source, discovery and detail cameras (optionally stereo), a beam-steering mechanism, tunable focus, and optional thermal or depth sensors. The processor, such as a GPU or FPGA, identifies insect or biological targets, adjusts laser focus by depth, and controls beam activation. A monitoring system verifies safety by detecting humans or other non-target entities using environmental and thermal cameras; if detected, laser firing is inhibited. The mobile platform may use wheels, propellers, tracks, or cables, with GPS and data links for remote control. A visible light pre-flash may induce a blink reflex before firing. In some embodiments, a scouting drone transmits target coordinates to the neutralization unit, enabling coordinated, efficient, and safe laser-based pest control.

### CROSS-REFERENCE TO RELATED APPLICATIONS

This application claims the benefit of Portuguese Provisional Application No. 20242006625149, titled “Vacuum Cleaning UAV,” filed by Nick Reyntjens on Nov. 6, 2024, the entire contents of which are incorporated herein by reference.

This application claims the benefit of Portuguese Provisional Application No. 20242006664541, titled “Patent Application: UAV-Based Pipe Cleaning System,” filed by Nick Reyntjens on Nov. 21, 2024, the entire contents of which are incorporated herein by reference.

This application claims the benefit of Portuguese Provisional Application No. 20242006675131, titled “UAV-Based Pipe Cleaning System,” filed by Nick Reyntjens on Nov. 25, 2024, the entire contents of which are incorporated herein by reference.

This application claims the benefit of Portuguese Provisional Application No. 20242006734540, titled “UAV-Based Pipe, Ceiling and Structure Cleaning System,” filed by Nick Reyntjens on Dec. 20, 2024, the entire contents of which are incorporated herein by reference.

This application claims the benefit of Portuguese Provisional Application No. 20252007097835, titled “Laser-Based Targeting and Object Detection System,” filed by Nick Reyntjens on May 18, 2025, the entire contents of which are incorporated herein by reference.

This application claims the benefit of Portuguese Provisional Application No. 20252007174414, titled “AI-Enabled Trading, Reputation and Review, and Medical Discovery System,” filed by Nick Reyntjens on Jun. 23, 2025, the entire contents of which are incorporated herein by reference.

This application claims the benefit of Portuguese Provisional Application No. 20252007182971, titled “AI Agent Services and Infrastructure and a Robotic Arm for UAV,” filed by Nick Reyntjens on Jun. 26, 2025, the entire contents of which are incorporated herein by reference.

This application claims the benefit of Portuguese Provisional Application No. 20252007196586, titled “Collection of Inventions,” filed by Nick Reyntjens on Jul. 3, 2025, the entire contents of which are incorporated herein by reference.

This application claims the benefit of Portuguese Provisional Application No. 20252007204100, titled “Various Inventions,” filed by Nick Reyntjens on Jul. 7, 2025, the entire contents of which are incorporated herein by reference.

This application claims the benefit of Portuguese Provisional Application No. 20252007228492, titled “Multiple Inventions,” filed by Nick Reyntjens on Jul. 17, 2025, the entire contents of which are incorporated herein by reference.

This application claims the benefit of Portuguese Provisional Application No. 20252007254684, titled “Various Inventions,” filed by Nick Reyntjens on Jul. 30, 2025, the entire contents of which are incorporated herein by reference.

This application claims the benefit of Portuguese Provisional Application No. 20252007287994, titled “Various Inventions and Pilot Beam,” filed by Nick Reyntjens on Aug. 17, 2025, the entire contents of which are incorporated herein by reference.

This application claims the benefit of Portuguese Provisional Application No. 20252007300012, titled “Various Inventions,” filed by Nick Reyntjens on Aug. 23, 2025, the entire contents of which are incorporated herein by reference.

This application claims the benefit of Portuguese Provisional Application No. 20252007329606, titled “Various Inventions,” filed by Nick Reyntjens on Sep. 6, 2025, the entire contents of which are incorporated herein by reference.

This application claims the benefit of Portuguese Provisional Application No. 20252007377096, titled “Various Inventions,” filed by Nick Reyntjens on Sep. 28, 2025, the entire contents of which are incorporated herein by reference.

### TECHNICAL FIELD

Various embodiments relate generally to autonomous or mobile systems equipped with laser-based precision targeting and neutralization systems, and more particularly to optical systems that may be integrated with or detachably mounted on unmanned aerial vehicles, ground vehicles, floating platforms, or cable-guided systems for precision interaction with the environment.

### BACKGROUND

In recent years, unmanned and autonomous mobile platforms-including unmanned aerial vehicles (UAVs), commonly referred to as drones, ground-based robots, and waterborne units—have seen increasing adoption and gained significant attention across diverse industries due to their mobility, adaptability, versatility, and automation capabilities. Applications span a wide range of tasks requiring high mobility, accuracy, and automation, including precision agriculture, infrastructure monitoring, environmental conservation, military operations, and defense.

A central challenge across these domains is enabling such platforms to interact with their environments in a highly targeted, selective, precise, and safe manner. For instance, in agricultural pest control, UAVs or tractor booms can be equipped with sprayers, but such methods often lack the precision to target specific pests, leading to unnecessary chemical use and environmental harm. Similarly, in military or security applications, the precise identification and engagement of targets remain complex tasks requiring advanced targeting systems, where enhanced precision improves mission effectiveness while minimizing collateral damage and saving ammunition.

In agriculture, pest control remains one of the most chemically intensive activities. Conventional methods typically involve blanket application of chemical pesticides via sprayers mounted on tractors or UAVs or other mobile platforms. While these methods are scalable, they suffer from low selectivity, leading to widespread collateral damage. Beneficial insects such as pollinators and natural predators are unintentionally harmed, accelerating the collapse of local ecosystems. Moreover, repeated chemical use deteriorates soil health by disrupting microbial communities essential for nutrient cycling and carbon sequestration. This not only lowers long-term crop productivity but also reduces the soil's capacity to store atmospheric CO₂, thereby contributing to climate change. Additionally, chemical pesticide residues often persist on crops and in groundwater, raising health concerns for both farmers and consumers. Chronic exposure to certain classes of pesticides has been linked to cancer, endocrine disruption, and neurological disorders. Despite these drawbacks, chemical pesticides remain in widespread use due to the lack of affordable, effective, and selective alternatives.

The integration of laser-based systems into UAVs and other autonomous platforms opens new possibilities for targeted interaction with the environment. Laser-based pest neutralization offers a promising non-chemical alternative that can be implemented on these platforms for precise, high-speed environmental interaction. Unlike sensing laser systems such as LiDAR, these non-sensing or action laser-based systems are designed to deliver highly focused energy to specific points, selectively neutralizing target organisms such as pest insects, without affecting surrounding vegetation, beneficial fauna, or the soil. This makes them ideal for applications such as precision pest control, weed management, or military operations.

Additionally, laser-based systems can operate using low-power electronics, which reduces the overall energy demand of pest control operations. Compared to conventional spraying—where chemical production, mixing with water, and repeated tractor passes over fields incur significant fuel and labor costs—this system is designed to be more energy-efficient and economically favorable over time. The proposed solution also enables broader utility: its sensing and targeting infrastructure may be extended to detect and respond to other biological threats, such as weeds, plant diseases, or nutrient stress, thus functioning as a multifunctional agricultural platform.

Thanks to the relatively low weight and compact size of the optical unit in comparison to possibly heavier spray system payload, which carry up to 70 kg of liquid, the system can be mounted on smaller and less expensive mobile platforms, including lightweight drones, rovers, or suspended carriers. This opens possibilities for deployment even on terrain where conventional tractors or sprayers are impractical. When coupled with suitably designed mechanical and software systems, overall maintenance and operational costs can be significantly lower than those of current chemical spraying solutions, especially in high-value or sensitive crops.

However, existing UAV systems with laser functionality and the implementation of such precision applications must overcome key challenges related to aiming accuracy, operational safety, precision, versatility, and adaptability. Aligning a laser beam with the camera's optical path, ensuring precise targeting, compensating for platform motion, vibrations, or wind, and the dynamic control of laser focus and beam direction are technically challenging aspects that need to be addressed.

The present application addresses these challenges by providing an autonomously operating UAV equipped with an advanced optical unit, a laser system, and a control unit. This system preferably leverages sophisticated image analysis algorithms and optical components like a movable mirror (such as fast-steering mirrors (FSMs), beam steering mirrors, or other actuated mirror types-preferably small, low-inertia mirrors capable of rapid angular redirection) and potentially a dichroic mirror to enable precise detection, localization, and targeting of objects in the platform's environment. Aiming accuracy is essential for neutralizing both fast-moving pests and stationary targets such as insect eggs or larvae, without harming the surrounding environment. This is achieved through the precise alignment of the optical paths of the laser and the camera, and the use of high-frame-rate sensing combined with the movable mirror, allowing the system to maintain focus and targeting precision even under platform motion.

Operational safety is equally critical, especially in open-field environments. The present invention builds upon research demonstrating that a combination of complementary safety mechanisms can achieve this goal, making the system suitable for commercial deployment. These safety features may include the use of non-retina-penetrating wavelengths (e.g., eye-safe infrared) that minimize the risk of permanent eye injury, a converging beam that rapidly diverges beyond the focal point, reducing hazard zones and increasing tolerance to misalignment, a surrounding monitoring system configured to track a nominal safety zone in real time, and a thermal camera, aimed at the target zone (optionally via the movable mirror), that blocks laser activation when a warm-bodied object (e.g., human or animal) is detected. Optional additional logic or optical filters may further restrict laser firing under uncertain conditions. Together, these features enable the creation of a system that is not only functionally effective but also compliant with safety standards.

In support of the targeting system, the invention further describes an enhanced insect discovery mechanism, configured to improve the efficiency and reliability of pest detection in dynamic agricultural environments. To improve spatial coverage and detection efficiency during forward motion, the system may employ a field-of-view (FOV) multiplexing architecture. In typical forward-facing configurations, the image sensor—often rectangular—allocates a large portion of its pixel rows to sensing overlapping spatial regions along the direction of motion. As the platform moves forward, rearward rows of the sensor detect the same scene already captured by forward rows, yielding diminishing informational value. To address this inefficiency, the present invention introduces a configuration in which oblique or lateral views are redirected onto these underutilized sensor regions.

The proposed solution here is adaptable for a variety of applications, including agricultural pest control, weed management, and military or security operations, offering a highly efficient, versatile, and safe solution for targeted environmental interaction, contributing to the broader goal of selective, energy-efficient operations.

The present application addresses these challenges by providing various modes of autonomous mobility platforms coupled with an advanced optical unit, a laser system, and a control unit. The system preferably incorporates a movable mirror, a dichroic mirror, and advanced image analysis algorithms to enable precise detection, localization, and targeting of objects within the environment. The proposed solution is adaptable to a wide range of use cases, including agricultural pest control, weed management, and military or security operations, thereby offering a highly efficient and versatile platform for targeted environmental interaction.

### SUMMARY

In a first aspect, the present application relates to an autonomously operating pest control system or vehicle, comprising a targeting system (100), an exclusion zone monitoring system (200), a mobility system (300), and a control and decision system (400). The control and decision system (400) may be distributed across, or housed within, one or more of the subsystems and is preferably configured to coordinate the operation of the machine.

In some embodiments, the system may autonomously perform a series of operations including: navigating to a designated area (500), scanning for insects in the target area (501), verifying safety conditions (502)—for example, by confirming that no human or mammal is present within a defined exclusion zone, and that the laser is not aimed at a heat-emitting organism based on thermal sensing-tracking a detected target (503), engaging the laser to neutralize the target (504), and optionally logging the event and proceeding to the next area (505). In some embodiments, the targeting system and exclusion zone monitoring system, or part of said systems, may be mounted to a fixed or articulated boom or arm extending from a mobile platform, such as an agricultural tractor or robotic vehicle, wherein the mobile platform may provide power, mobility, or positional support for the system modules.

The term “autonomously operating” refers preferably to the capability of an unmanned vehicle to perform its intended functions, including flight or ground mobility, without direct human intervention during operation.

This means that the unmanned vehicle independently utilizes its integrated components, such as the control unit, camera, laser unit, optical unit, and additional sensors like a global positioning system (GPS), to execute tasks such as maintaining stable flight, navigating through its environment, detecting objects, determining position parameters, and precisely directing the laser beam. The control unit, which may include a processor and memory, analyzes the images captured by the camera, identifies objects, calculates their locations, and adjusts the movable mirror to accurately target objects with the laser beam. At the same time, the global positioning system and other sensors enable autonomous navigation and ensure flight stability. By combining automated locomotion capabilities with real-time data analysis and adaptive decision-making, the unmanned vehicle operates as a fully independent and intelligent system. The invention also related to human oversighted or operated vehicles having any of the disclosed targeting systems, or exclusion zone monitoring systems.

In a second aspect, the present application relates to a targeting system that may be mounted on or integrated into a variety of mobile platforms, including but not limited to ground vehicles and aerial vehicles. The targeting system is preferably configured to operate autonomously and may comprise components such as a laser unit, an optical unit, and one or more cameras. The system may function independently or in conjunction with external control units and mobility systems, thereby enabling flexible deployment across diverse applications and environments.

In a further aspect, the present application relates to any of the disclosed surrounding monitoring systems and control systems, which may be mounted on or integrated into a variety of mobile platforms, including but not limited to aerial vehicles, ground vehicles, and floating platforms. These systems are preferably configured to operate autonomously or semi-autonomously, and may function as standalone subsystems or in conjunction with targeting systems and mobility units as described herein.

The mobility system (300) may comprise a mobile platform with one or more movement mechanisms, such as thrust-producing devices (e.g., propellers), wheels, continuous tracks, ion-thrust systems, or floating propulsion systems. The targeting system (100) may be integrated into, or detachably mounted on, the platform.

The targeting system (100) may comprise a neutralizing laser (101), an optically-aligned camera (102), a non-optically aligned camera (103), a beam steering mechanism (104), a tunable or movable focusing element (105), and optionally one or more dichroic mirrors or cubes (106) configured to optically align the laser path with the optical axis of the aligned camera. The dichroic element may be configured to reflect the laser beam while transmitting the optical path of the camera, or vice versa, enabling both paths to be co-steered by the same mechanism. In some embodiments, the targeting system (100) may further comprise a depth sensor and an illumination source, which may optionally be optically aligned with the laser path. The illumination source may assist in visual target identification or verification, while the depth sensor may provide real-time distance information used to dynamically adjust the focal point of the laser via the tunable focusing element (105), thereby improving precision and ensuring the beam converges at the correct depth. Additionally, one or more supplemental optical elements may be included, such as a visible or blue laser source configured to emit a flash prior to activation of the neutralizing laser. This pre-activation light may be intended to induce a blink reflex in humans or animals, thereby serving as a safety mechanism in the unlikely event that the laser beam intersects with an exposed eye.

In some embodiments, the system may use the non-optically aligned camera (103), which may include a wide-angle or stereo configuration, to detect potential targets in the environment. Once a target is identified, the beam steering mechanism (104) may be adjusted to redirect the laser and optically-aligned camera (102) toward the target. The optically-aligned camera (102) may then capture a higher-resolution or zoomed-in view of the target, enabling finer target verification and precise laser aiming. This dual-camera configuration allows for wide-area target acquisition followed by narrow-field precision targeting.

The control and decision system (400) may include a processing unit, such as a Graphics Processing Unit (GPU) or Field-Programmable Gate Array (FPGA), a controller, and supporting electronics. These components are preferably configured to process image and sensor data from the targeting system (100) and the exclusion zone monitoring system (200), perform object recognition and decision-making, and control all actuation processes including beam steering, focusing, and laser firing. In some embodiments, the laser beam may be dynamically focused to converge at the estimated depth of the target and diverge beyond that point to enhance operational safety.

The exclusion zone monitoring system (200) may include one or more environmental cameras (201), which may be thermal or visual or depth cameras, or a camera that captures all this data such as a RGBID (Red, green, blue, infrared, depth camera) as one camera or an integrated multicam camera module, and a processing unit (203) configured to observe the surroundings of the platform and detect the presence of non-target entities such as humans or mammals. If such entities are detected within a predefined safety perimeter, the system may inhibit or prevent laser activation.

The targeting system (100) and/or exclusion zone monitoring system (200) may be enclosed within a modular housing (500), which may include features such as strap slots, bolt holes, and standardized camera mount interfaces to facilitate mounting onto drones, ground vehicles, robotic arms, floating devices, or cable-guided systems. The optical system housing may also incorporate passive or active thermal management features.

In a further aspect, the present application relates to a specialized embodiment of the invention, namely an autonomously operating unmanned aerial vehicle comprising a main body with at least one thrust-producing means, a camera, a laser unit, an optical unit, and a control unit. In this context, the camera, laser unit, and optical unit may collectively be interpreted as forming an embodiment of the targeting system, wherein each component corresponds to one or more functional elements of the targeting system as described elsewhere in this application. The aerial vehicle itself constitutes the mobility system, the control unit corresponds to the control and decision system, and any sideward-facing or environment-monitoring cameras may serve as the exclusion zone monitoring system. This embodiment illustrates how the core subsystems disclosed in generalized terms may be integrated into a compact airborne configuration, while preserving functional equivalence to the modular architecture described throughout the application. The camera is preferably configured to capture images of an environment, and the laser unit is preferably configured to emit at least one laser beam. Further, the optical unit is preferably operatively coupled to both the laser unit and the camera and comprises at least one movable mirror and preferably a dichroic mirror. In this respect, the dichroic mirror is preferably configured to reflect the laser beam and to be transparent to an optical path of the camera, or vice versa, so that the optical path of the camera is aligned with a path of the laser beam and both the optical path of the laser beam and the optical path of the camera are directed at the movable mirror. The control unit may comprise a processor, a memory and one or more communication units which are preferably in data communication with the laser unit, the camera and the optical unit. The control unit may be configured to analyze the camera images to detect objects and determine their location parameters, which can be used to direct the laser beam onto targeted objects using the moveable mirror.

Any of the targeting systems or optical units disclosed in the context of specific vehicle embodiments, including but not limited to unmanned aerial vehicles, are intended and understood to be transferable to other mobility platforms, such as ground vehicles, waterborne vehicles, or cable-suspended platforms. Furthermore, such targeting systems and optical units are considered part of the present invention in their own right, whether implemented as integrated subsystems or as standalone modules.

In a further aspect, the application relates to an autonomously operating unmanned aerial vehicle which may comprise a main body with at least one thrust producing means, a camera, a laser unit, an optical unit, and a control unit. The camera is preferably configured to capture images of an environment, and the laser unit is preferably configured to emit at least one laser beam. Additionally, the optical unit is preferably operatively coupled to both the laser unit and the camera and comprises at least a dichroic mirror, wherein the dichroic mirror is preferably configured to reflect the laser beam and to be transparent to an optical path of the camera, or vice versa. The laser unit may comprise an actuator for directing the laser beam to the dichroic mirror, or alternatively the optical unit may comprise a movable mirror at which the laser beam can be aimed for directing the laser beam to the dichroic mirror. The control unit may comprise a processor, a memory and one or more communication units which are in data communication with the laser unit and the camera, wherein the control unit is preferably configured to analyze the camera images to detect objects and determine their location parameters, which can be used to direct the laser beam onto targeted objects using the laser unit's actuator or the movable mirror.

In a further aspect, the application relates to an autonomously operating unmanned aerial vehicle which may comprise a main body with at least one thrust producing means, a camera, a laser unit, and a control unit. The camera is preferably configured to capture images of an environment, and the laser unit is preferably configured to emit at least one laser beam. Moreover, the control unit may comprise a processor, a memory and one or more communication units which are in data communication with the laser unit and the camera, wherein the control unit is preferably configured to analyze the camera images to detect objects and determine their location parameters, which can be used to direct the laser beam onto targeted objects.

The aerial vehicle according to any of the preceding aspects may be configured in various embodiments.

Different embodiments can achieve one or more advantages. For example, certain embodiments may include means for converging a laser beam or focusing multiple laser beams to a point at a specific distance. This can lead to enhanced safety by minimizing unintended beam dispersion, reducing the risk of collateral damage or interference in sensitive environments. Furthermore, the precise control over the laser's focal point ensures that energy is only delivered where intended, preventing accidental exposure and improving operational reliability in complex or crowded settings. Further advantageous embodiments are detailed in the description of the present application, each of which may be combined with any of the previously mentioned aspects of the aerial vehicle.

Furthermore, the aerial vehicle according to any of the preceding aspects may be suitable for targeted pest control in an agricultural environment. The camera may be configured to capture environmental images of the agricultural environment, and the control unit may be configured to analyze the camera images to detect pests and determine their location parameters, which can be used to direct the laser beam onto targeted pests, for example, by using the moveable mirror or a laser unit's actuator.

The aerial vehicle according to any of the preceding aspects may be suitable for military applications. In this respect, the camera may be configured to capture images of the environment, and the control unit may be configured to analyze the camera images to detect military targets, such as human eyes, and determine their location parameters, which can be used to direct the laser beam onto the military targets, for example, by using the moveable mirror or a laser unit's actuator.

Moreover, the aerial vehicle according to any of the preceding aspects may be suitable for burning weeds or leaves. The camera can be configured to capture images of the environment, and the control unit can be configured to analyze the camera images to detect unwanted vegetation and determine their location parameters, which can be used to direct the laser beam onto the weeds or leaves, for example, by using the moveable mirror or a laser unit's actuator.

In a further aspect, the application relates to a system comprising the aerial vehicle according to any of the preceding aspects, a designated landing area and a mechanism for separating a replaceable battery from the aerial vehicle. The mechanism is preferably capable of autonomously reaching the majority of locations within the designated landing area and is not fixed to the length of the designated landing area. The mechanism may be not fixed with rigid linkages (such as a fixed robotic arm) or constrained by rails. Instead, it is configured to move freely across the platform within the designated landing area. The mechanism is preferably configured to autonomously approach the aerial vehicle after it has landed on the designated landing area, and to separate the battery from the aerial vehicle as part of a battery swap operation.

In further embodiments, the system, its components or integrated vehicles may be adapted for agricultural pest control, wherein the laser is used to neutralize specific pests without chemical agents. In other embodiments, the system may be configured for military or security applications, such as disabling equipment or identifying and engaging biological targets. Additionally, the system may be adapted for environmental tasks such as targeted weed removal or leaf incineration.

The mobile platform may optionally include navigation systems, such as GPS modules, and high-speed communication interfaces (e.g., 5G) to enable remote operation and autonomous path planning based on designated coordinates. In some embodiments, solar panels or other energy-harvesting systems may be included to reduce or eliminate the need for recharging docking stations or automatic or manual battery replacement, increasing operational autonomy.

In a still further aspect, the application relates to a system comprising the mobile platform or optical unit described above, a designated landing or docking area, and an autonomous battery replacement or charging mechanism. The mechanism may be configured to move freely within the landing zone without requiring fixed rails or rigid guide structures, and may autonomously approach the platform to remove and replace the battery when required.

In a further aspect, the present invention relates to an integrated system comprising a mobility platform and a targeting system, and optionally a surrounding monitoring system. The mobility platform may be configured for ground-based, aerial, waterborne, or suspended operation, and is preferably operatively coupled to the targeting system to enable coordinated movement and engagement. The targeting system may include a laser unit, optical components such as a movable mirror and dichroic mirror, and one or more cameras. The surrounding monitoring system, where present, may comprise sensors or cameras configured to detect non-target entities and environmental conditions to ensure safe operation. This integrated configuration allows for fully autonomous or semi-autonomous navigation, object detection, and precision targeting in a wide range of operational scenarios.

In certain embodiments, the targeting system may be reconfigured to emit a substantially parallel or collimated laser beam, rather than a focused or converging beam. This configuration may be advantageous in scenarios where maintaining beam diameter over longer distances is beneficial, such as in high-precision or long-range targeting applications. In such embodiments, the system may be suitable for military or security-related use cases, including but not limited to the targeting of flammable materials, optical sensors, or human eyes. The ability to selectively adjust the beam profile-whether convergent, divergent, or parallel—may be governed by adaptive optics, replaceable lenses, or electronically tunable beam-shaping elements.

It is understood that certain features disclosed elsewhere in this application may need to be omitted, reconfigured, or adapted in these embodiments to ensure that the device can execute its intended function effectively and safely in the relevant operational context. The flexibility to modify or omit features as needed is expressly contemplated within the scope of the invention.

Various additional embodiments and combinations are contemplated. The invention is not intended to be limited to the specific examples provided, but rather encompasses all configurations and variants that would be understood by a person skilled in the art.

Further examples of embodiments are explained in more detail below with reference to the accompanying drawings. The invention is not intended to be limited solely to these listed examples of embodiments. They merely serve to explain the invention in more detail. The present invention is intended to relate to all objects which the person skilled in the art would use now and, in the future, as obvious to realize the invention. Any disclosed safety, energy management, vibration reduction, targeting, or maintenance-enhancing features or aspects described in connection or in the context of an aerial vehicle, and of any aerial vehicle embodiments, are intended to be transferable to other embodiments and mobile platforms, including but not limited to ground-based, waterborne, cable-suspended, or stationary systems. These features are not limited to the specific mobility platform on which they are initially disclosed, but are understood to be applicable across a range of implementations within the scope of the present invention.

Furthermore, any subsystem or component described herein-such as the targeting system, optical unit, control unit, power module, or exclusion zone monitoring system—may be claimed independently as a standalone invention, or in combination with one or more other subsystems, or as part of an integrated system mounted on a specific type of mobile platform. The modularity and interoperability of these subsystems are expressly contemplated, and such variations fall within the intended scope of protection.

The scope of the present disclosure is intended to at least encompass the broadest scope of the claims. Any embodiments, drawings, aspects, features, or configurations described herein are to be interpreted as illustrative and non-limiting, and may be combined, omitted, or modified without departing from the scope defined by the claims. Any details provided in connection with a specific embodiment-including but not limited to dimensions, angles, spatial configurations, orientations, materials, or functional groupings—are presented solely to facilitate understanding of the invention and shall not be construed as limiting. All such characteristics may vary depending on implementation requirements and may be interchanged or adapted in other embodiments falling within the claimed scope.

### BRIEF DESCRIPTION OF DRAWINGS

FIG. 1 shows an embodiment of the mobile platform, illustrated in the example context of an aerial vehicle.

FIG. 2 shows a schematic view of the interaction between the laser unit, the camera and the optical unit in one possible embodiment, shown in the example context of an aerial vehicle.

FIG. 3 shows essentially the schematic illustration presented in FIG. 2 in greater detail, depicted here as a 3D model in a sectional view, in the example context of an aerial vehicle.

FIG. 4 shows a schematic illustration of the interaction between the laser unit and the optical unit in a further possible embodiment, shown in the example context of an aerial vehicle.

FIG. 5 shows a schematic illustration of the interaction between the laser unit and the optical unit in a further possible embodiment, shown in the example context of an aerial vehicle.

FIG. 6 shows a more detailed representation of the schematic illustration presented in FIG. 5, depicted here as a 3D model in a sectional view, in the example context of an aerial vehicle.

FIG. 7 shows a schematic illustration of the interaction between the laser unit, the camera and the optical unit in a further possible embodiment, shown in the example context of an aerial vehicle.

FIG. 8 shows a schematic illustration of the interaction between the laser unit, the camera and the optical unit in a further possible embodiment, shown in the example context of an aerial vehicle.

FIG. 9 shows a schematic illustration of a laser beam exiting an optical unit equipped with a means for converging the laser beam, in the example context of an aerial vehicle.

FIG. 10 shows a schematic illustration of the interaction between the laser unit, the camera and the optical unit in a further possible embodiment, shown in the example context of an aerial vehicle.

FIG. 10A shows a possible embodiment of a movable mirror, suitable for use in a mobile platform such as the example aerial vehicle.

FIG. 11 shows a further possible embodiment of the mobile platform, illustrated in the example context of an aerial vehicle.

FIG. 12 shows the roll motion of the housing via gimbal, showcasing its rotational degree of freedom around the roll axis, in the example context of an aerial vehicle.

FIG. 13 shows the pitch motion of the housing via gimbal, demonstrating its rotational capability around the pitch axis, in the example context of an aerial vehicle.

FIG. 14 shows the yaw motion of the housing via gimbal, highlighting its rotational flexibility around the yaw axis, in the example context of an aerial vehicle.

FIG. 15 shows a detailed view of the housing of the embodiment illustrated in FIG. 11-14, in the example context of an aerial vehicle.

FIG. 15A shows a cross section of the housing illustrated in FIG. 15, in the example context of an aerial vehicle.

FIG. 16 shows both an exploded view and an assembled view of a cooling component in a possible embodiment of the cooling unit, suitable for a mobile platform such as the example aerial vehicle.

FIG. 17 shows a further possible embodiment of the mobile platform, illustrated in the example context of an aerial vehicle.

FIG. 18 shows a further possible embodiment of the mobile platform, illustrated in the example context of an aerial vehicle.

FIG. 19 shows a side view of the possible embodiment depicted in FIG. 18, in the example context of an aerial vehicle.

FIG. 19A shows a possible embodiment illustrated in FIG. 18 and FIG. 19, depicted in an operating state where the laser beam is emitted from the mobile platform, in the example context of an aerial vehicle.

FIG. 20 shows a further possible embodiment of the mobile platform, which may be designed as a high-speed drone, illustrated in the example context of an aerial vehicle.

FIG. 21 shows a possible embodiment of the battery used in a mobile platform, in the example context of an aerial vehicle.

FIG. 22 shows a possible embodiment of a mechanism for separating the replaceable battery from a mobile platform, in the example context of an aerial vehicle.

FIG. 23 shows a further possible embodiment of the mobile platform, illustrated in the example context of an aerial vehicle.

FIG. 24 shows a further possible embodiment of the arrangement between control unit, the laser unit, optical unit and the camera, suitable for a mobile platform such as the example aerial vehicle.

FIG. 24A shows a possible embodiment of a movable mirror coupled to two servo motors, allowing it to be adjusted in two dimensions, making it fit the definition of a fast steering mirror, since the movable mirror can be moved in two rotational angles, suitable for a mobile platform such as the example aerial vehicle.

FIG. 25 shows a particularly compact embodiment of the arrangement involving the laser unit, the optical unit, and the camera, suitable for a mobile platform such as the example aerial vehicle.

FIG. 26 shows the possible embodiment shown in FIG. 25 in an exploded view, allowing the individual components to be seen in greater detail, in the example context of an aerial vehicle.

FIG. 27 shows the interaction between the targeting system, the exclusion zone monitoring system, the mobility system and the control and decision system.

FIG. 28 shows a flow diagram illustrating an exemplary operational sequence.

FIG. 29 shows a schematic illustration of a basic targeting system aiming at a target.

FIG. 30 shows a schematic illustration of an advanced targeting system aiming at a target.

FIG. 31A shows a first alternative embodiment of the targeting system.

FIG. 31B shows a cross section of said first alternative embodiment of the targeting system.

FIG. 32A shows a possible embodiment of the targeting system.

FIG. 32B shows an exploded view of a possible embodiment of the targeting system.

FIG. 32C shows a top view of a possible embodiment of the targeting system.

FIG. 32D shows an exploded view of the housing of a possible embodiment of the targeting system.

FIG. 32E shows a possible embodiment of a complete targeting unit, with power and signal cables for easy integration into a complete pest control system.

FIG. 33A shows an alternative optical element alignment solution, a dichroic cube.

FIG. 33B shows an exploded view of an alternative optical element alignment solution, a dichroic cube.

FIG. 33C shows a detailed view of one configuration of an embodiment of 7A.

FIG. 33D shows an overview of one configuration of an embodiment of 7A.

FIG. 33E shows an alternative configuration of an embodiment of 7A, using a shorter focal length lens for the camera (102).

FIG. 34A shows an alternative beam steering solution, a MEMS mirror.

FIG. 34B shows an alternative beam steering solution, a galvo pair.

FIG. 35A shows an example embodiment of an exclusion zone monitoring system.

FIG. 35B shows an example embodiment of an exclusion zone monitoring system.

FIG. 36A shows an example embodiment of the targeting system and the exclusion zone monitoring system, mounted or integrated into a cart suitable to shoot upwards.

FIG. 36B shows a detailed view of an example embodiment of the targeting system and the exclusion zone monitoring system, mounted or integrated into a cart suitable to shoot upwards.

FIG. 37A shows an example embodiment of the targeting system and the exclusion zone monitoring system, mounted or integrated into a cart suitable to shoot sideways.

FIG. 37B shows a detailed view of an example embodiment of the targeting system and the exclusion zone monitoring system, mounted or integrated into a cart suitable to shoot sideways.

FIG. 38 shows an example embodiment of the targeting system and the exclusion zone monitoring system, mounted or integrated into a floating vehicle suitable to shoot downwards in for example a rice paddy.

FIG. 39 shows a detail of an example embodiment of the targeting system, the exclusion zone monitoring system, and mounted or integrated into a quadruped platform.

FIG. 40A shows a schematic representation of a Lateral Field-of-View Extension Module and how a nadir-facing field of view (FOV), i.e., one oriented straight downward, may be laterally extended—that is, extended sideways—by incorporating at least one additional oblique or peripheral FOV.

FIG. 40B shows a schematic representation of a Lateral Field-of-View Extension Module and how two mirrors may be arranged to redirect light from a single lateral direction, thereby realizing an extended field of view on one side of the nadir axis. To achieve bilateral lateral extension (i.e., both left and right), a total of four mirrors may be used.

FIG. 40C shows a schematic example of a Lateral Field-of-View Extension Module and how two mirrors may be oriented to achieve a lateral field-of-view extension for a given working distance and focal length. The configuration illustrates the specific angular relationships and spacing required to redirect light from a lateral angle into the nadir-aligned optical axis.

FIG. 41A shows a top perspective view of a 3D CAD model of an example configuration of a Lateral Field-of-View Extension Module, comprising a 3D-printable structure with integrated reflective surfaces arranged to redirect light from left and right lateral directions into a nadir-facing optical path of an image sensor or camera.

FIG. 41B shows a bottom perspective view of the Lateral Field-of-View Extension Module of FIG. 41A, further illustrating the geometry and placement of the reflective surfaces used to fold peripheral scene content into the downward-facing field of view.

FIG. 41C shows a top view of the Lateral Field-of-View Extension Module, emphasizing the symmetrical mirror layout relative to the nadir axis and the alignment required to achieve lateral field-of-view extension on both sides.

FIG. 41D shows a cross-sectional view of the Lateral Field-of-View Extension Module, illustrating the internal optical paths and the angular arrangement of the reflective surfaces configured to redirect light from lateral angles into the nadir-facing camera.

FIG. 42A shows the Lateral Field-of-View Extension Module integrated with a camera and lens assembly, illustrating how the reflective geometry interfaces with the optical input of a nadir-facing imaging system.

FIG. 42B shows the Lateral Field-of-View Extension Module integrated with a camera and lens assembly mounted on an unmanned aerial vehicle (UAV), demonstrating a representative deployment configuration for aerial imaging applications.

FIG. 43A the GUI of an open source eye safety calculation tool.

FIG. 43B shows the GUI an open source energy calculation tool.

FIG. 44 shows an alternative embodiment of an optical module.

FIG. 45A shows an example data object.

FIG. 45B shows an example data object.

FIG. 45C shows an example data object.

FIG. 45D shows an example data object.

FIG. 45E shows an example data object.

FIG. 45F shows example steps.

FIG. 46A shows an example sleeping pod embodiment integrated in a self-driving vehicle.

FIG. 46B shows an example sleeping pod embodiment integrated in a self-driving vehicle.

FIG. 46C shows an example sleeping pod embodiment integrated in a self-driving vehicle.

FIG. 46D shows an example dynamic braking module.

FIG. 46E shows an example self-driving vehicle.

FIG. 46F shows an exploded view of an example dynamic braking module.

FIG. 47 shows an example mobile platform capable of depositing target insect insecticide units.

FIG. 48A shows an example cable based multiplexer overview.

FIG. 48B shows an example cable based multiplexer detail view.

FIG. 48C shows an example cable based multiplexer detail view.

FIG. 48D shows an example cable based multiplexer detail view.

FIG. 48E shows an example cable based multiplexer detail view.

FIG. 48F shows an example cable based multiplexer detail view.

FIG. 48G shows an example elastic with cable ends.

FIG. 49 shows an example insect sugarwater dispenser.

FIG. 50A illustrates a bee hive (2) provided with an add-on protection apparatus mounted adjacent to its entrance.

FIG. 50B shows an enlarged view of the add-on apparatus positioned at the hive entrance.

FIG. 50C is a cutaway view of the add-on apparatus, revealing internal components.

FIG. 50D presents an exploded view of the add-on apparatus, showing the principal elements in separated form.

FIG. 50E depicts a top-down view of the apparatus with the cover (7) removed.

FIG. 50F shows the apparatus in isolation as a standalone unit, apart from the hive.

FIG. 51 show how 2 mirror can be used to a expand a beam, and subsequent focus and align it with a camera

FIG. 52A show a sleeping pod in a self driving vehicle

FIG. 52B show a sleeping pod in a self driving vehicle

FIG. 52C show a sleeping pod in a self driving vehicle

FIG. 52D show a sleeping pod in a self driving vehicle

FIG. 52E show a sleeping pod in a self driving vehicle

FIG. 52F show a sleeping pod in a self driving vehicle

FIG. 53 shown a drone laying bait for ants

FIG. 54A shows a cable multiplexer

FIG. 54B shows a cable multiplexer

FIG. 54C shows a cable multiplexer

FIG. 54D shows a cable multiplexer

FIG. 54E shows a cable multiplexer

FIG. 54F shows a cable multiplexer

FIG. 54G shows a cable multiplexer

FIG. 55 shows a ant sugar water dispenser

FIG. 56A shows an animal smart collar

FIG. 56B shows an animal smart collar

FIG. 57 shows a stereo system using one camera

FIG. 58A shows UAV with quickly replaceable frame and motors

FIG. 58B shows UAV with quickly replaceable frame and motors

FIG. 58C shows UAV with quickly replaceable frame and motors

FIG. 58D shows UAV with quickly replaceable frame and motors

FIG. 58E shows UAV with quickly replaceable frame and motors

FIG. 58F shows UAV with quickly replaceable frame and motors

FIG. 58G shows UAV with quickly replaceable frame and motors

FIG. 58G shows UAV with quickly replaceable frame and motors

FIG. 58I shows UAV with quickly replaceable frame and motors

FIG. 58J shows UAV with quickly replaceable frame and motors

FIG. 58K shows UAV with quickly replaceable frame and motors

FIG. 59 shows pilot laser beam aligned with a converging laser beam

FIG. 60 shows an event camera sensor partitioned in functional regions

FIG. 61A shows an aspect of a flying cleaning solution

FIG. 61B shows an aspect of a flying cleaning solution

FIG. 61C shows an aspect of a flying cleaning solution

FIG. 61D shows an aspect of a flying cleaning solution

FIG. 61E shows an aspect of a flying cleaning solution

FIG. 61F shows an aspect of a flying cleaning solution

FIG. 61G shows an aspect of a flying cleaning solution

FIG. 61H shows an aspect of a flying cleaning solution

FIG. 61I shows an aspect of a flying cleaning solution

FIG. 61J shows an aspect of a flying cleaning solution

FIG. 61K shows an aspect of a flying cleaning solution

FIG. 61L shows an aspect of a flying cleaning solution

FIG. 61M shows an aspect of a flying cleaning solution

FIG. 61N shows an aspect of a flying cleaning solution

FIG. 61O shows an aspect of a flying cleaning solution

FIG. 61P shows an aspect of a flying cleaning solution

FIG. 61Q shows a an aspect of a flying cleaning solution

FIG. 61R shows a an aspect of a flying cleaning solution

FIG. 61S shows a an aspect of a flying cleaning solution

FIG. 61T shows a an aspect of a flying cleaning solution

FIG. 62A shows an object tracking hat or baseball cap

FIG. 62B shows an object tracking hat or baseball cap

FIG. 62C shows an object tracking hat or baseball cap

FIG. 63A shows a bee hive protection device

FIG. 63B shows a bee hive protection device

FIG. 63C shows a bee hive protection device

FIG. 63D shows a bee hive protection device

FIG. 63E shows a bee hive protection device

FIG. 63F shows a bee hive protection device

FIG. 63G shows a bee hive protection device

FIG. 63H shows a bee hive protection device

FIG. 63I shows a bee hive protection device

### DETAILED DESCRIPTION OF ILLUSTRATIVE EMBODIMENTS

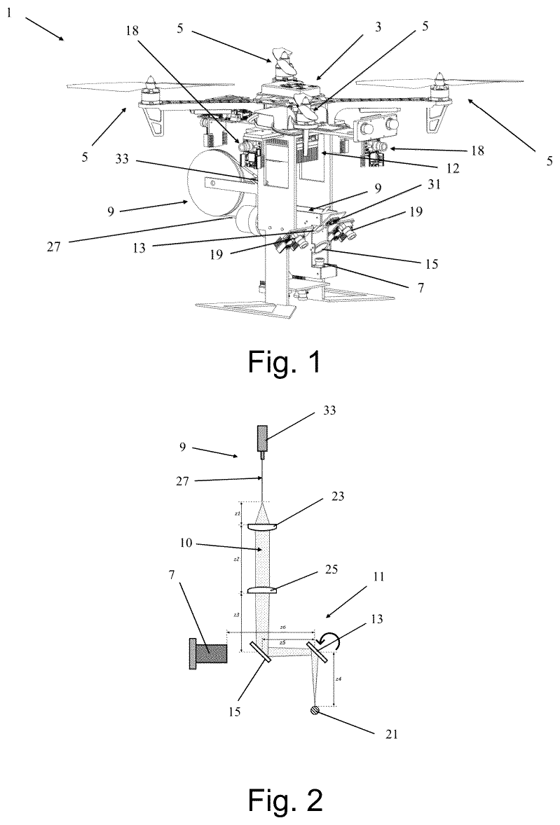

The accompanying drawings illustrate various embodiments of the invention. It should be noted that FIGS. 1 to 27 generally depict earlier configurations or specific embodiments, while subsequent figures may illustrate newer embodiments or broader system aspects. For consistency within these distinct sets of illustrations, and to clearly delineate features within different contexts or evolutionary stages of the design, some functionally equivalent components or depicted elements may be referred to by different reference numerals. The following provides a guide to the correspondence between such numerals where applicable: The main body or chassis of an aerial vehicle (drone body), shown as reference numeral 3 in FIGS. 1-27, corresponds to the main body or chassis designated by reference numeral 370 in newer figures depicting similar aerial vehicle embodiments.

The optically aligned camera, denoted by reference numeral 7 in FIGS. 1-27, is functionally equivalent to the camera denoted by reference numeral 102 in the newer figures.

The laser beam path or the emitted laser beam itself, depicted or referred to as 10 in FIGS. 1-27, may be depicted or referred to as 398 in the newer figures.

The optical unit (which may constitute or be a primary component of the targeting system), identified as reference numeral 11 in FIGS. 1-27, corresponds to the targeting system or its core optical assembly, often designated by reference numeral 100 in the newer figures.

The controller or control unit, denoted by reference numeral 12 in FIGS. 1-27, functionally corresponds to the control unit, or aspects thereof, often designated by reference numeral 401 (which may be part of the overall control and decision system 400) in the newer figures.

The beam steering mirror (movable mirror), identified as reference numeral 13 in FIGS. 1-27, is functionally analogous to the beam steering mirror identified as reference numeral 104 in the newer figures.

The dichroic mirror, shown as reference numeral 15 in FIGS. 1-27, corresponds to the dichroic mirror shown as reference numeral 110 in the newer figures.

A surrounding monitoring camera (which may contribute to the exclusion zone monitoring system 200), identified as reference numeral 18 in FIGS. 1-27, corresponds to a surrounding monitoring camera often designated by reference numeral 201 in the newer figures.

A not-optically aligned camera (which may be a stereo camera or part of a broader sensing suite), referred to as reference numeral 19 in FIGS. 1-27, corresponds to camera functionality often referred to by reference numeral 103 in the newer figures.

A target being engaged by the system, illustrated as reference numeral 21 in FIGS. 1-27, may be represented as a target designated by reference numeral 199 in subsequent illustrative figures.

The focusing lens (which may be a fixed lens or a focus-tunable lens), denoted as reference numeral 25 (or 35 if focus tunable) in FIGS. 1-27, is functionally equivalent to the focusing lens denoted as reference numeral 105 in the newer figures.

An illumination source, identified as reference numeral 31 in FIGS. 1-27 (noting that specific characteristics of the element designated 31, such as its optical alignment, are detailed in the description of those particular embodiments), corresponds to the illumination source identified as reference numeral 107 in the newer figures.

The laser unit, identified as reference numeral 33 in the context of FIGS. 1-27, corresponds to the laser unit identified as reference numeral 101 in subsequent figures detailing newer embodiments.

Regarding supporting electronics: The component previously identified as the laser driver (100) in the context of FIGS. 1-27 is, in newer embodiments depicted in subsequent figures, understood to be integrated within, or to form a part of, the broader supporting electronics, which may be identified by reference numeral 480.

It is intended that this clarification aids in the understanding of the evolution of the described embodiments and the functional equivalence of correspondingly numbered components across different drawing sets. Unless stated otherwise, a description of a component referencing one numeral is applicable to its functionally equivalent counterpart where such correspondence is indicated.

All elements, features, and configurations described in the present disclosure are to be interpreted as illustrative and non-limiting, unless explicitly described as essential using the term “must.” In particular, when terms such as “preferred,” “advantageous,” or “recommended” are used, they are intended to indicate configurations expected to perform well in specific applications or environments, but are not intended to exclude alternative implementations that may achieve similar results. No single described embodiment should be seen as superior or more definitive of the invention's scope than another.

Some parts of the embodiments have similar or identical parts. The similar or identical parts may have the same names and/or reference number. The description of one part applies by reference to another similar part, where appropriate, thereby reducing repetition of text without limiting the disclosure.

FIG. 1 shows a possible embodiment of an aerial vehicle 1. The aerial vehicle 1 may be autonomously operating, unmanned, and may comprise a main body 3 with at least one thrust-producing means 5, preferably four thrust-producing means 5, a camera 7, a laser unit 9, an optical unit 11, and a control unit 12.

The camera 7 may be configured to capture images of the environment, while the laser unit 9 may be configured to emit at least one laser beam 10. The optical unit 11, which may be operatively coupled to both the laser unit 9 and the camera 7, can comprise at least one movable mirror 13 and a dichroic mirror 15. The dichroic mirror 15 may be designed to reflect the laser beam 10 and to be transparent to the optical path of the camera 7, or vice versa. This configuration can allow the optical path of the camera 7 to align with the path of the laser beam 10, so that both the laser beam's optical path and the camera's optical path are directed toward the movable mirror 13.

The control unit 12 may comprise a processor, a memory, and one or more communication units, which can be in data communication with the laser unit 9, the camera 7, and the optical unit 11. The control unit 12 can be configured to analyze the images captured by the camera 7 to detect objects and determine their location parameters. These parameters may be used to direct the laser beam 10 onto targeted objects via the movable mirror 13.

In a possible embodiment, the one or more communication units may be wired or wirelessly coupled to the laser unit 9, the camera 7, and the optical unit 11. Additionally, the one or more communication units may enable data exchange between the aerial vehicle 1 and external systems, such as a ground control station or other aerial vehicles 1. This data exchange may include transmitting images captured by the camera 7, location parameters of detected objects, or operational status information of the aerial vehicle 1. Furthermore, the communication units may receive commands or mission updates from external systems, allowing the aerial vehicle 1 to dynamically adapt its operation.

In this context, a possible embodiment of the application may address a drone swarm comprising a plurality of aerial vehicles 1, wherein each aerial vehicle 1 is in data communication with the others and can communicate with one another.

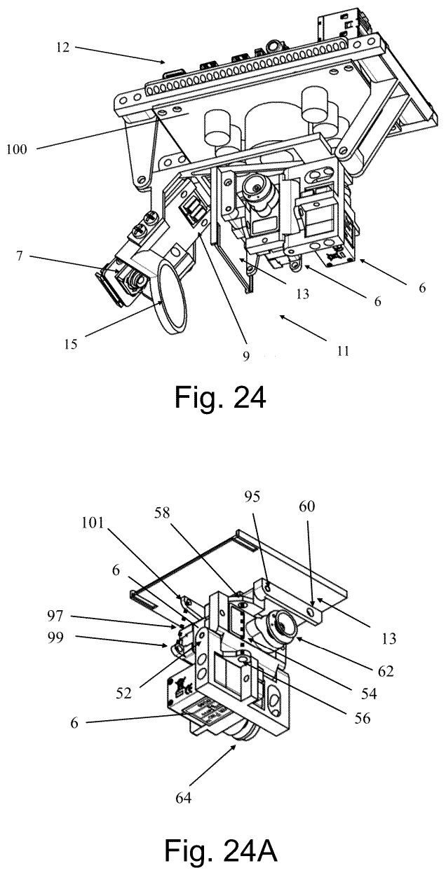

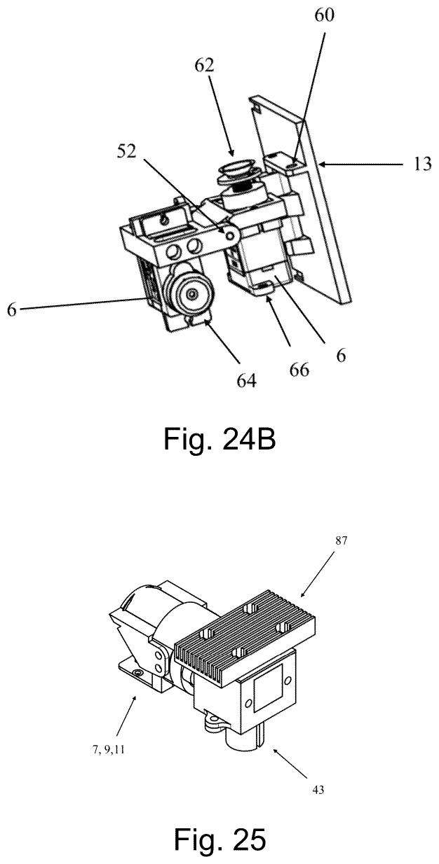

Preferably, the laser unit 9 comprises a fiber 27 coupled laser light source 33 and a collimating lens 23. In alternative embodiments, the laser unit 9 may include differently configured laser designs, particularly those that do not utilize a fiber (see, for example, FIG. 24).

The laser unit 9 may comprise a laser light source 33 having a dominant wavelength of between 440 nm and 460 nm or of between 790 nm and 820 nm. In particularly possible embodiments, the laser source 33 operates within the range of 449 nm to 461 nm, as blue wavelengths are highly absorbed by insects and plants, which minimizes unwanted reflections and maximizes the efficiency of energy transfer to the target. This reduces the risk of accidental harm to humans or animals by limiting the likelihood of the laser beam 10 bouncing off surfaces. For military applications very high power modules are available around 450 nm. Additionally, blue light is particularly suitable for agricultural applications due to its ability to avoid strong reflection from most plant and soil surfaces, thereby ensuring precise targeting of pests. The specified range of 798 nm to 818 nm, on the other hand, is optimized for generating thermal effects, where the near-infrared laser delivers concentrated heat to neutralize pests effectively. When safety is the most important design criteria, a wavelength that cannot reach the retina is a good choice, such as 1550 nm or between 1540 and 1560 nm.

In some possible embodiments, the laser unit may comprise a light source 33 with a power of 5.5 W. The light source 33 may be either a pulsed light source 33 or a continuous one. Pulsed operation is particularly advantageous for precise energy delivery and minimizing thermal damage to surrounding areas, while continuous operation allows for consistent energy output, ideal for neutralizing larger pest populations or for use in applications requiring sustained targeting. In some embodiments, the power of the light source 33 may range from 2 W to 100 W, preferably from 3 W to 60 W, and more particularly from 4 W to 10 W.

The laser unit 9 may comprise a laser driver circuit utilizing at least one transistor selected from the group consisting of a Silicon Carbide (SiC) MOSFET and a Gallium Nitride (GaN) FET. These transistors are particularly well-suited for high-frequency and high-power applications, making them ideal for driving the laser source 33 with precision and efficiency. SiC MOSFETs are known for their high thermal conductivity and ability to operate at elevated temperatures, which ensures reliable performance even under demanding conditions. GaN FETs, on the other hand, offer extremely low switching losses and fast response times.

The four thrust-producing means 5 may each comprise at least one propeller, which can generate unidirectional thrust to allow the unmanned aerial vehicle 1 to achieve and preferably maintain controlled movement. By adjusting the speed and direction of rotation of these propellers, the vehicle 1 may perform various maneuvers, such as ascending, descending, hovering, or moving laterally, forward, or backward.

By distributing the rotational speed and thus the thrust output of each propeller using a ‘mixing’ matrix, pitch, roll, and yaw rotational forces can be introduced while maintaining a given total thrust. For instance, increasing the rotational speed on one side while reducing it on the opposite side may allow the vehicle to tilt, enabling directional movement in the desired direction. Similarly, varying the the rotational speed diagonally may induce rotation around the vehicle's vertical axis, allowing it to turn or reorient as needed.

To enable smooth and accurate movement, the system may rely on additional sensors, such as accelerometers, gyroscopes, and global positioning systems, which can provide continuous data about the vehicle's position, orientation, and velocity. This data can be processed by the control unit 12, which may dynamically adjust the thrust produced by the propellers in real time to preferably maintain stability and execute the desired motion. By combining this control with 12 advanced navigation algorithms, the unmanned aerial vehicle 1 may autonomously follow pre-programmed flight paths, avoid obstacles, and react to changes in its environment.

In further examples, the aerial vehicle 1 may comprise at least one propeller which can be dynamically rearrangeable and configured to provide mainly vertical thrust or horizontal thrust. In an alternative embodiment, the thrust producing means 5 may comprise at least two propellers, wherein a first propeller is configured to provide mainly vertical thrust and a second propeller is configured to provide mainly horizontal thrust.

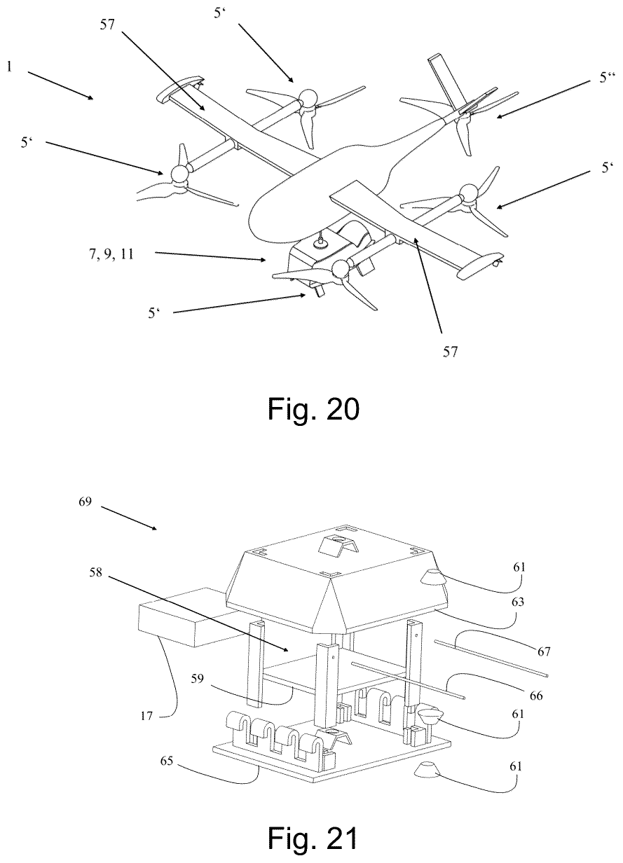

Furthermore, the aerial vehicle 1 may further comprise at least one wing 57 that generates lift when the aerial vehicle 1 moves forward (see, for example, FIG. 20).

The aerial vehicle 1 may further comprise a replaceable battery 17 (see, for example, FIG. 21), wherein all power consuming components on the vehicle 1 are coupled to the battery 17 as a power source. The replaceable battery 17 may be suitable for automatic swapping.

Preferably, the aerial vehicle 1 may further comprise a stereo camera 19. Generally, an aerial vehicle 1 may also comprise an event camera, or an infrared camera in data communication with the control unit 12 to further analyze the environment. These cameras may, for example, be arranged as sideward-facing cameras 18.

Further possible, at least one LED 31 may be provided on the vehicle 1 to illuminate the field of view of the camera 7, thereby enhancing the quality of captured images, particularly in low-light conditions. The LED 31 can be controlled by the control unit 12 and may be activated dynamically based on environmental lighting conditions or specific operational requirements.

The aerial vehicle 1 may be suitable for different applications. For example, it may be used for targeted pest control in an agricultural environment, wherein the camera 7 is configured to capture images of the agricultural environment, and the control unit 12 is configured to analyze these images to detect pests and determine their location parameters. These parameters can be used to direct the laser beam 10 from the laser unit 9 onto the targeted pests via the movable mirror 13. In some embodiments, the laser unit 9 may include an actuator, which directly aligns the laser beam 10 without relying on the movable mirror 13 or directs the laser beam 10 onto a fixed mirror for targeting.

The aerial vehicle 1 may also be suitable for military applications. In this context, the camera 7 may be configured to capture images of the environment, and the control unit 12 is configured to analyze these images to detect military targets, such as human eyes, and determine their location parameters. These parameters can then be used to direct the laser beam 10 from the laser unit 9 onto the military targets using the movable mirror 13. In some embodiments, the laser unit 9 may include an actuator, which directly aligns the laser beam 10 without relying on the movable mirror 13 or directs the laser beam 10 onto a fixed mirror for targeting.

The aerial vehicle 1 may further be suitable for burning weeds or leaves. In this application, the camera 7 may be configured to capture images of the environment, and the control unit 12 is configured to analyze these images to detect unwanted vegetation and determine their location parameters. These parameters can then be used to direct the laser beam 10 from the laser unit 9 onto the weeds or leaves using the movable mirror 13. In some embodiments, the laser unit 9 may include an actuator, which directly aligns the laser beam 10 without relying on the movable mirror 13 or directs the laser beam 10 onto a fixed mirror for targeting.

FIG. 2 shows a schematic illustration of the interaction between the laser unit 9, the camera 7 and the optical unit 11 in a possible embodiment of the aerial vehicle 1. The schematic illustration corresponds, for example, to the aerial vehicle 1 shown in FIG. 1.

The laser unit 9 may comprise a fiber 27 coupled laser light source 33 and a collimating lens 23. The collimating lens 23 may ensure that the laser light emitted from the fiber 27 is converted into a parallel laser beam 10. It is apparent that the laser beam 10, as it exits the fiber 27, may initially be diverge or widen before being collimated by the collimating lens 23. The optical unit 11 may include a means for converging the laser beam 10, which, in some embodiments, may be realized as a converging lens 25.

The converging lens 25 may have in some examples a dynamic focal length, allowing the focus point of the laser beam 10 to be adjusted based on the distance to the target 21.

In some embodiments where the laser unit 9 may comprise multiple laser sources 33 emitting multiple laser beams 10, the converging means may allow the multiple laser beams 10 to be focused to a single point at a defined distance.

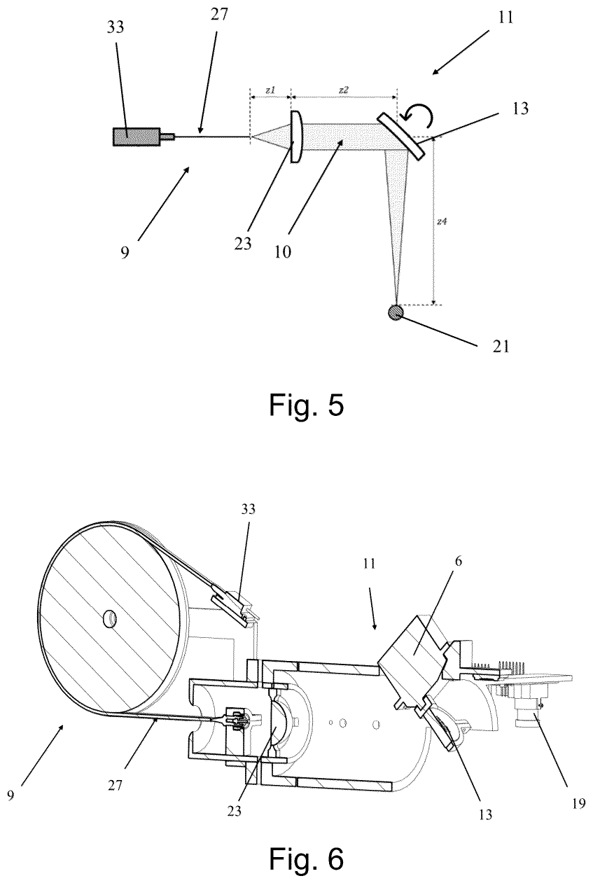

Instead of a converging lens 25, the converging means may also be implemented in alternative embodiments as a movable mirror 13, preferably configured as a concave mirror (see, for example, FIG. 5). The movable mirror 13 may be dynamically adjusted to alter the focus point by modifying its orientation or curvature, enabling precise targeting of the laser beam 10 generated by the laser unit 9.

The laser beam 10 may be directed onto a dichroic mirror 15, which may be part of the optical unit 11.

Additionally, the camera 7 is preferably positioned such that its optical path can also be directed onto the dichroic mirror 15. The dichroic mirror 15 may be configured to reflect the laser beam 10 while being transparent to the optical path of the camera 7, so that the optical path of the camera 7 may be aligned with the path of the laser beam 10. In alternative embodiments, the dichroic mirror 15 may instead be configured to allow the laser beam 10 to pass through while reflecting the optical path of the camera 7.

Both the optical path of the laser beam 10 and the optical path of the camera 7 may be directed at the movable mirror 13. The movable mirror 13 may redirect the laser beam 10 onto a target 21, utilizing data provided by a control unit 12. The control unit 12 may process input from the camera and/or various sensors to calculate the optimal orientation of the movable mirror 13. The target 21 may, for example, be an insect, but alternative targets are also possible depending on the application.

The alignment of the laser beam 10 and the camera's optical path via the dichroic mirror 15 may improve precise targeting with a compact arrangement and reducing computing resources, as it enables the system to use the same line of sight for both detecting targets 21 and directing the laser beam 10. The dichroic mirror 15 may ensure that the laser beam 10 is reflected while the camera's 7 optical path passes through, or vice versa, aligning both paths to a common axis. Preferably, the camera's 7 focal point is also precisely aligned with the focal point of the laser beam 10. Once a target 21 is detected and sharply focused in the camera's 7 image, it can be reliably assumed that the target 21 is also in the focus of the laser beam 10, triggering its emission.

Preferably, the movable mirror 13 is adjustable in at least one degree of freedom through an actuator. The actuator may, for example, be a servo motor 6. A sensor, which may optionally be part of the optical unit 11, can monitor the position or changes in the position of the movable mirror 13. The degree of freedom may include the pitch or roll of the movable mirror 13, allowing precise adjustments to its orientation based on control data.

The sensor may, optionally, be embedded in the servo motor 6.

The actuator may be coupled to the movable mirror 13 via a pulling cable or a wire. Alternatively, the movable mirror 13 may be coupled to a spring, rubber, or flexible structure. The spring, rubber, or flexible structure may be configured to apply a constant rotational force to the movable mirror 13. The rotational force may be selected from the group consisting of pitch rotational force and roll rotational force relative to the movable mirror 13.

This configuration allows precise adjustments of the laser beam 10 generated by the laser unit 9 and directed through the optical unit 11 towards the target 21.

In a further possible embodiment, the movable mirror 13 may be actuated by a second servo motor 6 to enable adjustments along at least one additional degree of freedom. The additional degree of freedom may be selected from the group consisting of pitch and roll of the movable mirror. This configuration allows the movable mirror 13 to achieve more precise positioning and targeting of the laser beam 10, improving its ability to accurately direct the beam 10 onto the target 21. The integration of the second servo motor 6 may be controlled by the control unit 12, which processes sensor data, such as positional feedback from the optical unit 11 or external environmental inputs, to optimize the alignment of the movable mirror 13. In this document we define Fast steering mirror as a mechanism that can alter two rotation degrees of freedom of a movable mirror, hence this mirror coupled to two servos makes it a fast steering mirror mechanism.

In a further possible embodiment, the optical unit 11 may comprise a galvo steering system, with the movable mirror 13 forming part of it. A galvo steering system generally uses galvanometer motors to adjust the angle of mirrors rapidly and precisely, enabling dynamic beam steering. The system is particularly suitable for applications requiring high-speed tracking or precise targeting, such as neutralizing small or moving pests.

In a further possible embodiment, the optical unit 11 may further comprise a means for preventing ambient light from passing through or being reflected by the dichroic mirror 15 and impinging upon a sensor of the camera 7.

This means may include a material composed of a dark, light-absorbing substance designed to reduce unwanted reflections, or a second material, such as a metal foil, configured to block the transmission of light. These materials may be strategically positioned within the optical unit 11 to ensure that only the desired optical path reaches the camera 7, thereby enhancing the accuracy and reliability of image capture by minimizing interference from ambient light sources.

In a further possible embodiment, the movable mirror 13 may comprise a mirror surface divided into a central zone and an outer zone. The central zone may be specifically configured to reflect the at least one laser beam 10 and may comprise a first mirror type optimized for high reflectivity and precision to ensure the accurate direction of the laser beam 10. Surrounding the central zone, the outer zone may be configured to reflect the field of view of the camera 7 and may comprise a second mirror type, which may be different from the first mirror type.

The first mirror type may exhibit higher optical quality than the second mirror type, providing enhanced accuracy for laser beam targeting. In contrast, the second mirror type may be designed to be lighter in weight than the first mirror type, reducing the overall load on the actuator and improving the responsiveness of the movable mirror 13. This configuration allows the movable mirror to efficiently balance precision and weight optimization, enabling both accurate laser targeting and effective image capture by the camera 7.

It is apparent from the context of the application that additional lenses and mirrors can be incorporated into the optical path of the laser beam 10 or the camera 7 to further adjust the optical paths.

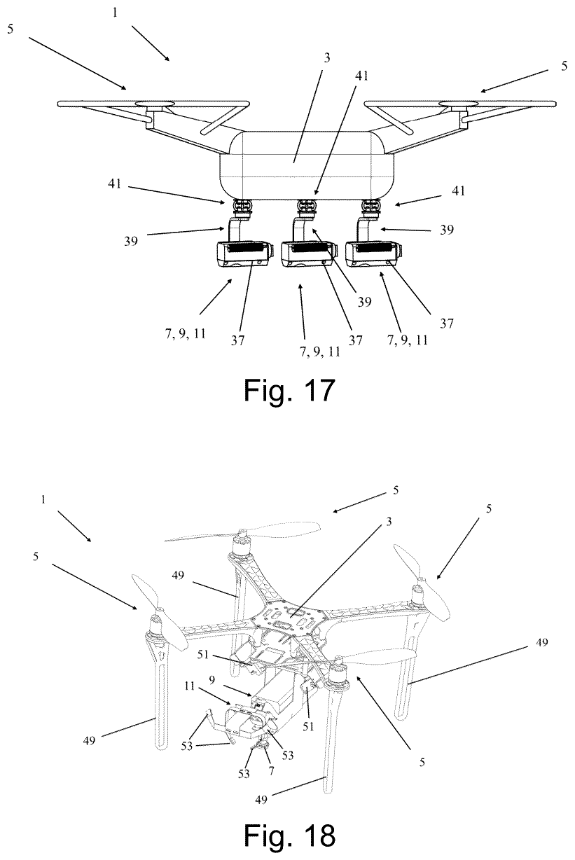

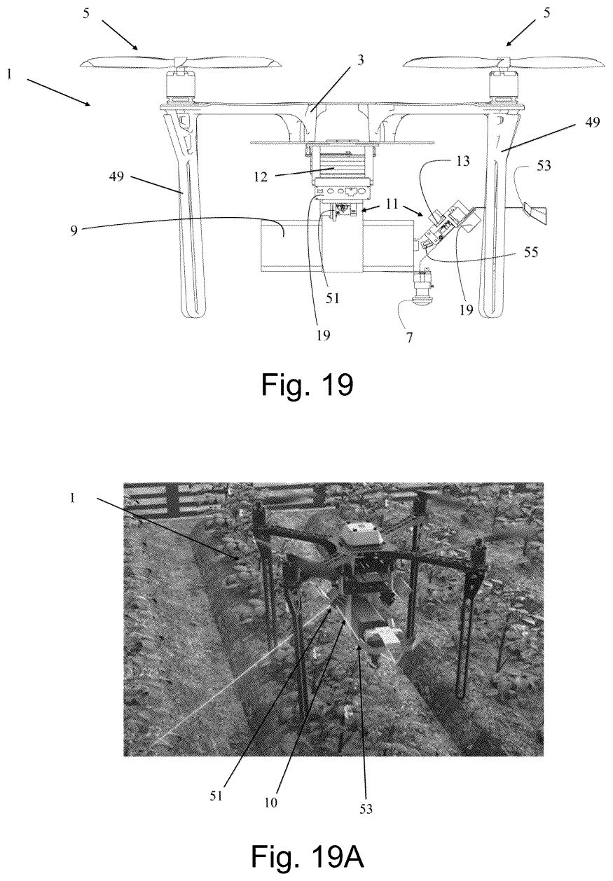

In a further possible embodiment, the optical unit 11 may comprise a first movable mirror 13 and second movable mirror 13, each capable of operating independently and in parallel such that the first mirror 13 can direct the optical path of a first laser beam 10 and the camera 7 towards a first target 21, while the second mirror 13 can direct the optical path of the first laser beam 10, a split of version of the first laser beam 10, or a second laser beam 10, and an additional camera 7 towards a second target 21. This is shown in the embodiments from FIGS. 17 and 19.

In a further possible embodiment, the movable mirror 13 may be positioned close to the dichroic mirror 15, the movable mirror 13 having a neutral position oriented at an angle of approximately 90 degrees relative to the dichroic mirror 15, thereby enabling a smaller movable mirror 13 to achieve the desired field of view for the camera 7.

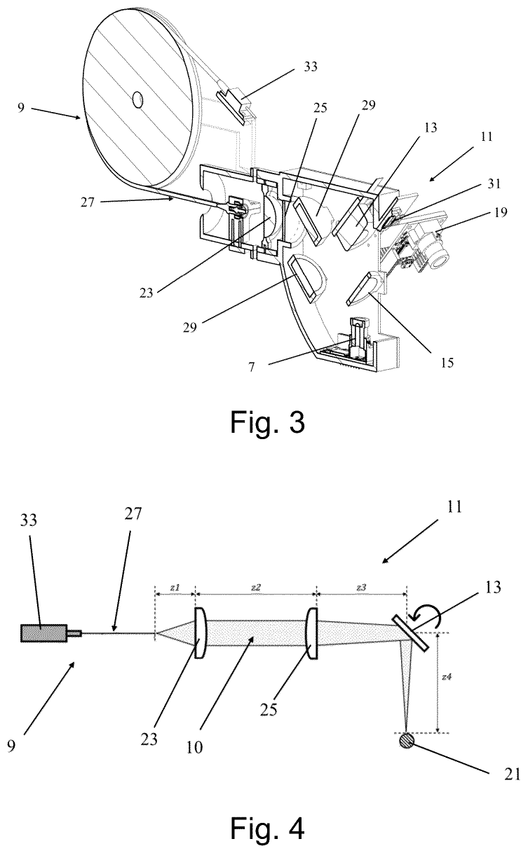

FIG. 3 shows essentially the schematic illustration presented in FIG. 2 in greater detail, depicted here as a 3D model in a sectional view. It corresponds to the embodiment from FIG. 1. In contrast to FIG. 2, two deflection mirrors 29 have been added. This deflection mirrors may redirect the laser beam 10 from the converging lens 25 to the dichroic mirror 15. The inclusion of the deflection mirrors 29 provides greater flexibility in arranging the laser unit 9 relative to the optical unit 11. Specifically, the laser unit 9 or the laser exit point of the laser unit 9 does not need to be positioned at the same height as the dichroic mirror 15, allowing for more versatile system designs. Other configurations are also conceivable, such as using more deflection mirrors 29 (for example three or four) or fewer, such as just one deflection mirror 29.

FIG. 4 shows a schematic illustration of the interaction between the laser unit 9, and the optical unit 11 in a further possible embodiment of the aerial vehicle 1. In this embodiment, the aerial vehicle 1 may comprise a main body 3 with at least one thrust producing means 5, and a camera 7 for capturing images of an environment (both are not depicted in the schematic illustration of FIG. 4). The camera 7 can, for example, be a stereo camera 19.

Further, the aerial vehicle 1 may comprise a laser unit 9 for emitting a laser beam 10. The laser unit 9 may comprise a fiber 27 coupled to a laser light source 33 with a collimating lens 23.

The optical unit 11 may comprise a converging lens 25 and a movable mirror 13, at which the laser beam 10 can be aimed to direct the laser beam onto a target 21. The movable mirror 13 is preferably coupled to an actuator and may be movable in at least one degree of freedom.

In this embodiment, the aerial vehicle 1 may include a control unit 12, which is preferably connected to the camera 7. The control unit 12 can be configured to analyze the images captured by the camera 7 to detect objects and determine their location parameters. These parameters may then be used to direct the laser beam 10 onto targeted objects, such as the target 21.

The actuator may comprise a rotary motor assembly configured to steer the laser beam 10. This assembly can include a rotary motor coupled to the movable mirror 13, where the motor is configured to rotate the movable mirror 13 in response to an applied signal. An integrated driver circuit may be three-dimensionally stacked with at least one component of the rotary motor. The integrated driver circuit may incorporate advanced features, such as through-silicon vias (TSVs) for vertical electrical connections, a silicon interposer for interconnecting stacked dies, and wafer-level packaging (WLP). At least one component of the rotary motor assembly may be fabricated from lightweight materials, such as titanium or aluminum, to reduce weight and enhance efficiency.

Furthermore, the rotary motor may optionally comprise a piezoelectric motor for precise and responsive control of the movable mirror 13.

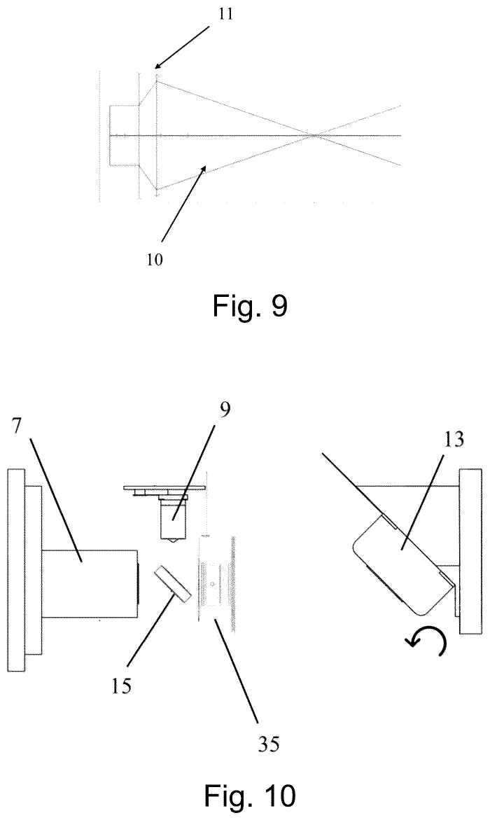

The orientation of the camera 7 may define a field of view. Within this field of view, the laser beam 10 can be directed by adjusting the movable mirror 13. The control unit 12 may be configured to control the movable mirror 13 such that the laser beam 10 can precisely target a specific target 21 located within the field of view of the camera 7. Like FIG. 8 and embodiment of FIG. 24.

FIG. 5 shows a schematic illustration of the interaction between the laser unit 9, and the optical unit 11 in a further possible embodiment of the aerial vehicle 1. This embodiment is substantially the same as that shown in FIG. 4, the difference being the removal of the converging lens 25 from the configuration. The function of the converging lens 25 is now performed by the movable mirror 13, which is in the form of a concave mirror. The concave mirror 13 may focus the expanded parallel laser beams 10 onto a target 21.

FIG. 6 shows a more detailed representation of the schematic illustration presented in FIG. 5, depicted here as a 3D model in a sectional view. In addition to the components described in connection with FIG. 5, a component of the stereo camera 19 is also visible. The stereo camera 19 may capture images of the environment, which are analyzed by the control unit 12. Based on this analysis, the movable mirror 13 directs the laser beam 10 accordingly. In this regard, the movable mirror 13 may be actuated by a servo motor 6, allowing it to move in at least one degree of freedom.

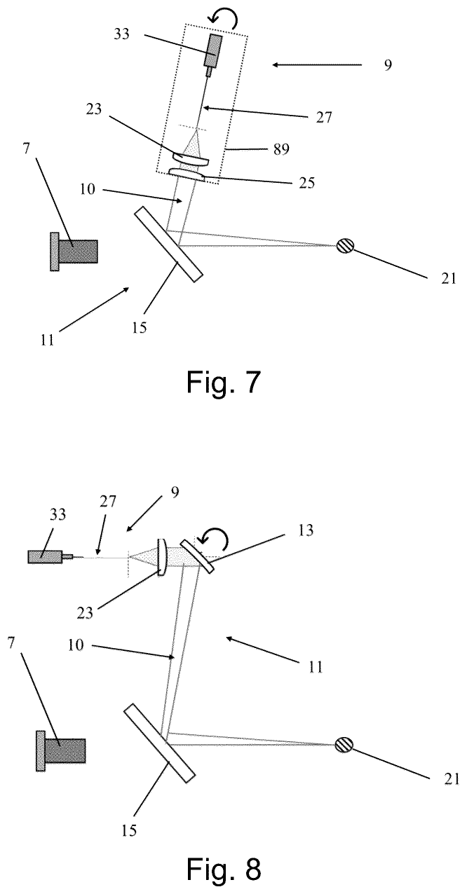

FIG. 7 shows a schematic illustration of the interaction between the laser unit 9, the camera 7 and the optical unit 11 in a further possible embodiment of the aerial vehicle 1. The laser unit 9 may comprise a fiber 27 coupled to a laser light source 33 and a collimating lens 23. The collimating lens 23 can ensure that the laser light emitted from the fiber 27 is converted into a parallel laser beam 10. It is apparent that the laser beam 10 initially expands upon exiting the fiber 27.

The optical unit 11 may include a means for converging the laser beam 10, which, in certain embodiments, can be implemented as a converging lens 25.

The laser beam 10 may be directed onto a dichroic mirror 15, which may be part of the optical unit 11. Additionally, the camera 7 is preferably positioned such that its optical path can also be directed onto the dichroic mirror 15. The dichroic mirror 15 may be configured to reflect the laser beam 10 while being transparent to the optical path of the camera 7, so that the optical path of the camera 7 may be aligned with the path of the laser beam 10. In alternative embodiments, the dichroic mirror 15 may instead be configured to allow the laser beam 10 to pass through while reflecting the optical path of the camera 7.

In some embodiments, the laser unit 9 may include an actuator for directing the laser beam 10 toward the dichroic mirror 15. Preferably, the laser light source 33, the fiber 27, the collimating lens 23, and/or the converging lens 25 may form a structural unit. This structural unit can be implemented within a housing 89, in which the laser light source 33, the fiber 27, the collimating lens 23, and/or the converging lens 25 may be integrated. The housing 89 itself may be movable in at least one degree of freedom by means of an actuator, enabling the emitted laser beam 10 to be precisely directed.

By aligning the laser beam 10 with the dichroic mirror 15, the beam's orientation toward a target 21 is also controlled. The aerial vehicle's control unit 12 may process input from the camera 7 and/or various sensors to calculate the optimal orientation of the laser beam 10 or the laser light source 33. The target 21 may, for example, be an insect, although other targets are possible depending on the specific application.

For clarification, the laser unit 9, the optical unit 11, the camera 7, and the control unit 12 refer preferably to distinct functional units of the aerial vehicle. Each unit is preferably designed to perform a specific task. These units may either be physically integrated into a single housing or distributed as separate components, depending on the specific system configuration. Their modular design allows for flexibility in assembly, maintenance, and potential upgrades.

FIG. 8 shows a schematic illustration of the interaction between the laser unit 9, the camera 7, and the optical unit 11 in a further possible embodiment of the aerial vehicle 1. The embodiment depicted in FIG. 8 largely corresponds to the embodiment shown in FIG. 7. However, instead of the laser unit 9 comprising an actuator that enables the laser beam 10 to be directed at a controlled angle onto the dichroic mirror 15, the laser unit 9 is now fixedly positioned and directs the laser beam 10 onto a movable mirror 13.

In all embodiments involving the interaction between a dichroic mirror 15, a camera 7, and a laser unit 9, the positions of the laser unit 9 and the camera 7 may be interchangeable. In such cases, it can preferably be necessary to adjust the light transmission properties of the dichroic mirror 15. Specifically, the dichroic mirror 15 may reflect the optical path of the camera 7 while allowing the laser beam 10 to pass through in the swapped positions. Conversely, when the laser unit 9 and the camera 7 are in their original positions, the dichroic mirror 15 can be configured to reflect the laser beam 10 and allow the optical path of the camera 7 to pass through.

The movable mirror 13 deflects the laser beam 10 at any desired angle onto the dichroic mirror 15. The movable mirror 13 may be designed as a concave mirror, such that the laser beam 10 is focused at a single point when exiting the optical unit 11. Ideally, this focal point corresponds to the target 21, such as an insect.

FIG. 9 shows a schematic illustration of a laser beam 10 exiting an optical unit 11 equipped with a means for converging the laser beam 10. This configuration offers significant safety advantages, particularly for human eye safety, as the laser beam 10 diverges beyond the focal point, resulting in a reduction of energy intensity.

Consequently, areas beyond the focal point are not at significant risk. At the focal point, however, the laser beam 10 is highly concentrated, enabling precise targeting and maximum effect at that specific location.

The laser unit 9 may comprise multiple laser light sources 33 for emitting multiple laser beams 10 in some embodiments. In this case, the laser light sources 33 can be implemented on an integrated laser chip or as an array. A single laser driver circuit may be configured to control and drive the multiple laser light sources 33 efficiently. The converging means of the optical unit 11, such as a converging lens 25, may focus the multiple laser beams 10 to a single point, ensuring precise targeting and maximizing the combined energy at the focal point.

Generally, the control unit 12 plays an important role in the aerial vehicle 1. It can be configured to analyze the images captured by the camera 7, potentially using artificial intelligence algorithms, such as convolutional neural networks, to detect objects and determine their location parameters. Preferably, these location parameters may be aligned with the focal point of the laser beam 10 to enable precise targeting.

In a further possible embodiment, the control unit 12 may be configured to detect the presence of any human within a nominal hazard zone of the laser beam 10. The aerial vehicle 1 may optionally include sideward-facing cameras 18, possibly infrared sensitive, to provide comprehensive coverage of the hazard zone and to enhance the detection capabilities. The nominal hazard zone can be defined as a zone with a radius of 40 meters from the movable mirror 13. In additional examples, the nominal hazard zone may have a radius selected from a range of 5 meters to 100 meters, preferably from a range of 20 meters to 80 meters, and particularly from a range of 30 meters to 60 meters.

In this embodiment, the control unit 12 may be further configured to control the laser unit 9 or the optical unit 11 in such a way that it does not target any objects outside an active operating window. The active operating window maybe located at the center of the nominal hazard zone and may define the area where the laser may be safely operated. If a human is detected within the nominal hazard zone, the control unit 12 may cease neutralizing potential targets to ensure safety.

The control unit 12 may be configured to analyze the images captured by the camera 7 for anomaly detection, potentially using artificial intelligence algorithms to identify deviations from expected patterns. Additionally, the laser unit 9 may be configured to deactivate if water droplets or other reflective surfaces are detected, as these could unpredictably deflect the laser beam 10.

In a further possible embodiment, the control unit 12 may be configured to execute a location prioritization algorithm. This algorithm can select locations for targeting insects based on the frequency of previous encounters with target insects at those locations. Alternatively, the algorithm may be executed on a remote server, with the prioritization data transmitted to the control unit 12 for implementation.

In a further possible embodiment, the control unit 12 may be configured to store information about previous encounters with target insects at various locations within the operational area of the aerial vehicle 1. In this respect, the location parameters of targeted objects may be stored in a database present in the memory.

Alternatively, this database and the associated processing may reside on a remote server, with the control unit 12 receiving processed data for implementation. Based on this stored information, the control unit 12 can estimate an insect emergence rate for each location. Using these estimated rates, the control unit may select specific locations for targeting insects, preferably prioritizing areas with higher estimated emergence rates. This configuration enhances the efficiency and effectiveness of the targeting system.

In a further possible embodiment, the aerial vehicle 1 may comprise a plurality of independently operable beam-steering mirrors or movable mirrors 13 within the optical unit 11. In this respect, the control unit 12 can configured to predict trajectories of a plurality of target objects 21 relative to the main body 3 and to assign each target object 21 to one of the plurality of beam-steering mirrors or movable mirrors 13 based on a cost function that minimizes total mirror movement.

In a further possible embodiment, the control unit 12 may be configured to perform a cluster analysis on the location parameters of a plurality of target objects to identify target-rich zones. Based on this analysis, the control unit 12 can generate an optimized flight path for the aerial vehicle 1, preferably prioritizing the identified target-rich zones. The optimized flight path may be determined using a cost function that minimizes at least one factor, such as the total distance traveled by the aerial vehicle 1, the total movement of the movable mirror 13, or a combination of these factors.

In a further possible embodiment, the control unit 12 may be configured to perform a calibration process to determine an offset aiming point. This calibration process can address observed discrepancies between an intended aim point and the actual location of the laser spot or the focal point of the laser beam 10. Using this offset aiming point, the control unit 12 may adjust the laser aiming to account for potential misalignments between the dichroic mirror 15, the laser unit 9, and/or the camera 7.

The functional interaction between the control unit 12, the camera 7, the laser unit 9, and/or the optical unit 11 enables the aerial vehicle 1 to target an object and emit a laser beam 10 at the targeted object while moving through a spatial environment.

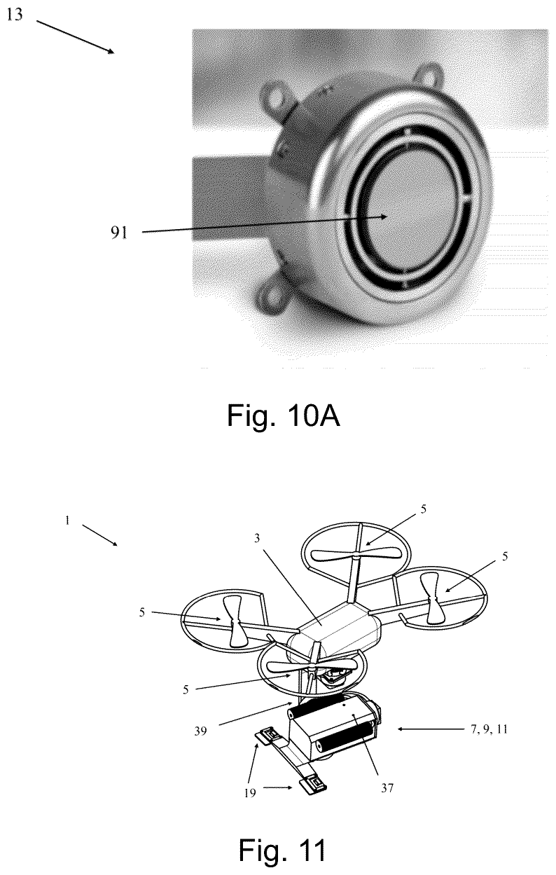

FIG. 10 shows a schematic illustration of the interaction between the laser unit 9, the camera 7 and the optical unit 11 in a further possible embodiment of the aerial vehicle 1. Unlike the previously described embodiments, the embodiment depicted in FIG. 10 includes a liquid lens 35 as converging means. This liquid lens 35 introduces enhanced flexibility in focusing, as its focal length can be dynamically adjusted by varying the electrical input. This feature enables precise targeting across varying distances and improves the overall adaptability of the system in dynamic environments. The movable mirror 13 may be a Fast Steering Mirror as depicted in FIG. 10A.

FIG. 10A shows a possible embodiment of a movable mirror 13. The movable mirror may be designed as a Fast Steering Mirror. A Fast Steering Mirror (FSM) is preferably a high-precision optical device used to dynamically adjust the angle of reflected light beams, such as laser beams 10. It may operate with rapid response times, allowing for real-time corrections in beam alignment, stabilization, or pointing.

At its core is a lightweight, highly reflective mirror 91, often mounted on a flexible suspension system to allow controlled tilting in two axes (X and Y). Actuators, such as piezoelectric or voice-coil actuators, may drive the mirror's 91 movement with high speed and precision. Integrated position sensors may monitor the mirror's 91 orientation in real-time, providing feedback to a control unit that ensures accurate and stable operation. The entire system 13 is typically enclosed in a protective housing to shield it from environmental factors like dust and vibration. Generally, a mechanism that allow controlled tilting in two axes can be defined as a Fast Steering Mirror.

FIG. 11 shows a further possible embodiment of the aerial vehicle 1. Preferably, the optical unit 11, the laser unit 9 and the camera 7 may be arranged in a common housing 37 which is attached to the main body 3 via a gimbal 39, isolating the optical unit 11, the laser unit 9 and the camera 7 from the roll and pitch movements of the main body 3.

The gimbal 39 may be coupled to the main body 3 via a flexible structure 41, such as a wire rope isolator, isolating the optical unit 11, the laser unit 9 and the camera 7 from frequency horizontal and vertical vibrations of the main body 3.

In a further possible embodiment, the gimbal 39 may comprise at least two rotational axes, with actuators configured to allow the housing 37 to rotate about these axes. This arrangement can enable the optical unit 11 to be coarsely oriented toward a potential target 21. Additionally, the movable mirror 15 within the optical unit 11 may perform fine adjustments to align either the optical path of the camera 7 or the laser beam 10 with greater precision. Further, the optical unit 11 may be iteratively directed at specific subregions of an area beneath the aerial vehicle 1, allowing it to scan and address each subregion in succession.

In a further possible embodiment, the housing 37 may comprise multiple exit openings through which the laser beam 10 can be directed out of the housing 37 via the movable mirror 13. Further possible a stereo camera 19 may be coupled to the housing 37.

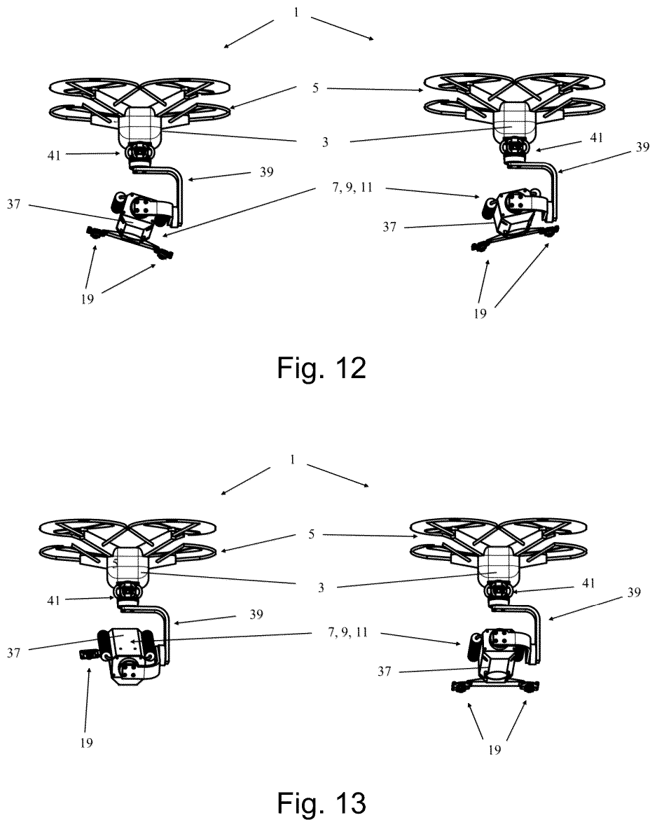

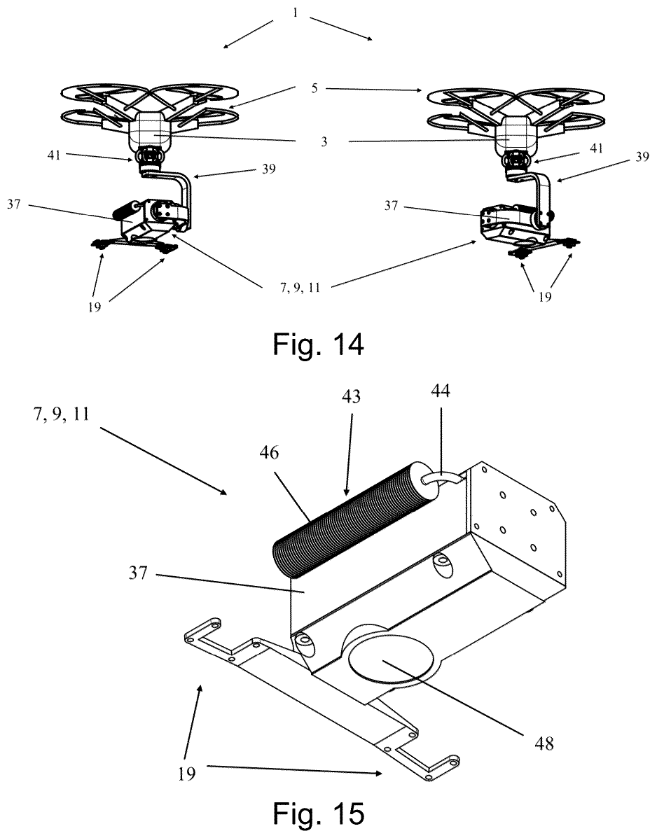

FIG. 12, FIG. 13, and FIG. 14 illustrate the embodiment depicted in FIG. 11, highlighting the housing 37 degrees of freedom via gimbal 39. These degrees of freedom allow the housing 37 to move along the roll, pitch, and yaw axes. Specifically, FIG. 12 demonstrates the roll motion, FIG. 13 depicts the pitch motion, and FIG. 14 illustrates the yaw motion. This dynamic range of movement provided by the gimbal 39 facilitates precise positioning of the optical unit 11 which is located in the housing 37.

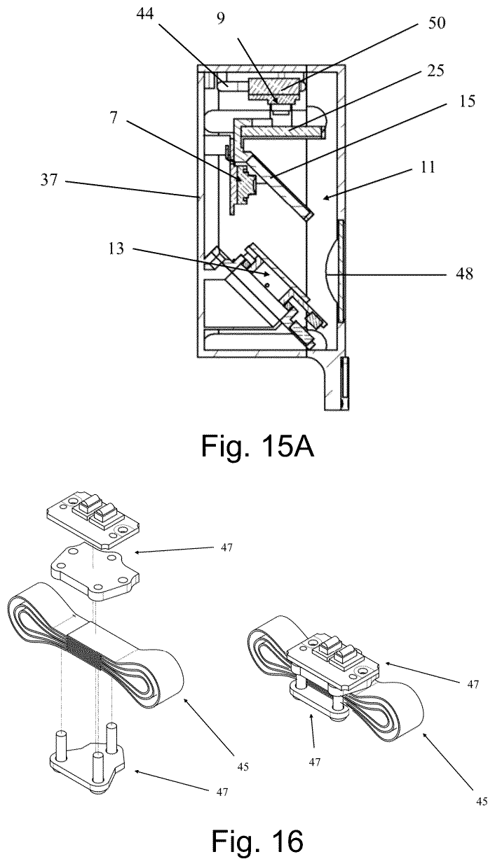

FIG. 15 shows a detailed view of the housing 37 of the embodiment illustrated in FIG. 11-14. A cooling unit 43 may be coupled with the laser unit 9 which is incorporated in the housing 37. The cooling unit 43 may employ graphene or diamond material, allowing to dissipate heat generated by the laser beam 10 away from the laser unit 9. These materials may be arranged in sheets 46 or ribs 87 to optimize heat transfer and enhance cooling efficiency (see also FIG. 25).

In this context, the heat can be transferred to a high-wind region generated by at least one thrust producing means 5. Preferably, the cooling unit 43 may be partially or entirely positioned outside the housing 37, while being securely attached to it. Additionally, means may be provided to transfer heat from the laser unit 9 to components of the cooling unit 43 in a simple and efficient manner. For instance, the cooling unit 43 can include a heat pipe 44, which transfers heat from the laser unit 9 as the heat source to components of the cooling unit located outside the housing 37. The goal is to redistribute heat concentrated on a small surface area to a component with a larger surface area, such as ribs 87 or sheets 46 connected to the heat pipe 44, to enhance heat dissipation.

The cooling unit 43 may further comprise a liquid reservoir, suitable to contain water or ammonia, allowing the heat to buffer and to release in periods of low laser firing. The capacity of the liquid reservoir can be for example less than 300 cm3.

The stereo came 19 is shown schematically in FIG. 15 by its holder on the housing 37.

FIG. 15A shows a cross section of the housing 37 illustrated in FIG. 15. Within the housing 37, a camera 7, a laser unit 9, and an optical unit 11 may be located. The optical unit 11 can preferably include a dichroic mirror 15 and a movable mirror 13, which may, for example, be designed as a Fast Steering Mirror. The camera 7 may be directed toward the dichroic mirror 15, which can reflect the optical path of the camera 7 onto the movable mirror 13. On the other side, the laser unit 9 may be directed toward the dichroic mirror 15, which can be configured to transmit the laser beam 10 or its wavelength. This arrangement may ensure that the optical path of the camera 7 and the optical path of the laser beam 10 are aligned and overlap. The movable mirror 13 may then direct the laser beam 10 and the optical path of the camera 7 outside the housing 37 through a window 48. The window 48 can preferably be made of glass or plastic.

The laser unit 9 may be thermally coupled to a vapor chamber 50, which can preferably include a wick structure made from a material selected from the group consisting of sintered copper powder or a composite wick comprising at least one layer of sintered copper powder. The vapor chamber 50 may be configured to distribute the heat generated by the laser unit 9 over a larger surface area, thereby enhancing heat dissipation.

The vapor chamber 50 may be coupled to the heat pipe 44, which can preferably transfer the heat outside the housing 37.

FIG. 16 illustrates a further embodiment of how components of the cooling unit 43 can be designed. In this embodiment, instead of using ribs 87 or sheets 46, the graphene or diamond material may be arranged in overlapping layers or sheets, which are further shaped into loops 45. These loops 45 may be clamped securely between two clamping elements 47. The clamping elements 47 may transfer the heat generated by the laser unit 9 to the loops 45, which then dissipate the heat efficiently into the surrounding environment. This configuration is shown in FIG. 16 both as an exploded view and in an assembled state.

FIG. 17 shows a further possible embodiment of an aerial vehicle 1. The aerial vehicle 1 may include a main body 3 with at least one thrust-producing means 5, preferably four thrust-producing means 5. Additionally, it can preferably include three housings 37, each of which may house a laser unit 9, an optical unit 11, and a camera 7. These components may act as independent modules and can preferably target different objectives 21 independently using laser beams 10. Alternatively, the laser unit 9, optical unit 11, and camera 7 may be integrated under the same gimbal, enabling coordinated movement and targeting for all components.

Each housing 37 may be mounted to the main body 3 of the aerial vehicle 1 via a gimbal 39 and a flexible structure 41. The aerial vehicle 1 can preferably include a control unit 12 comprising a processor, a memory, and one or more communication units, which may be in data communication with the laser unit 9, the camera 7, and the optical unit 11 of each module. The control unit 12 may be configured to analyze the images captured by the cameras 7 to detect objects and optionally determine their location parameters, which can preferably be used to individually direct the laser beam 10 of each module onto targeted objects. The modules may emit the laser beams 10 sequentially or simultaneously to target objects as required.

FIGS. 18 and 19 illustrate another possible embodiment of the aerial vehicle 1 from different perspectives. The aerial vehicle 1 may comprise a main body 3 equipped with four thrust-producing means 5, such as propellers.

Support members 49 may be attached to the main body 3 to enable the aerial vehicle 1 to stabilize when placed on a surface. These support members 49 are preferably designed to allow a variety of components, such as a laser unit 9, camera 7 and an optical unit 11, to be mounted beneath the main body 3.

The laser unit 9 may preferably comprise a high-power diode laser, such as a 70 W diode laser, serving as the light source. The optical unit 11 may include a galvo steering system, which could comprise at least one movable mirror 13. Some embodiments may use a mirror 55 or other light guiding means such as a fiber 27 to direct the laser light into the galvo system. The galvo steering system may steer the laser beam 10 in a forward-downward direction to facilitate interaction with the area below the aerial vehicle 1. Additionally, the galvo system could redirect the laser beam 10 onto small mirrors 53. These mirrors 53 may reflect the laser beam 10 into the inputs of additional galvo systems 51. These additional galvo systems 51 could then be positioned to emit the beam towards the left and right undersides of the aerial vehicle 1, respectively (see also FIG. 19A).

The camera 7 may be used to perform target insect scouting operations where the aerial vehicle 1 flies higher above the agricultural field and takes pictures allowing it to make a database of known insect locations.

Furthermore, the embodiment may contemplate the incorporation of one or more sensing systems for each galvo system direction. These sensors may provide visual or depth information about the surrounding environment.

An example for such sensing system may comprise a stereo camera 19.

The aerial vehicle 1 may comprise a control unit 12, which can be coupled to the laser unit 9, the optical unit 11, i.e. the galvo steering systems, and/or the camera 7, as well as other sensing systems. Based on the analysis of the captured images and data from the sensing systems, the control unit 12 can control the galvo steering systems such that an emitted laser beam 10 accurately targets corresponding objectives 21.

FIG. 19A shows a possible embodiment of the aerial vehicle 1 illustrated in FIGS. 18 and 19, depicted in an operating state where the laser beam 10 is emitted from the aerial vehicle 1. As already described, the generated laser beam 10 may be directed onto small mirrors 53 via the galvo system. These mirrors 53 may reflect the laser beam 10 into the inputs of additional galvo systems 51. These additional galvo systems 51 can then be configured to emit the laser beam 10 towards the left and right undersides of the aerial vehicle 1, respectively.

Preferably, the vehicle may comprise multiple movable mirrors 13, wherein each is capable of operating independently and in parallel such that the first mirror 13 can direct the optical path of a first laser beam towards a first target 21, while the movable second mirror 13 can direct the optical path of the first laser beam, a split of version of the first laser beam 10, or a second laser beam 10, and an additional camera towards a second target 21. In this respect, the first and the second movable mirrors 13 can be part of different galvo steering systems.

FIG. 20 illustrates another possible embodiment of the aerial vehicle 1, which may be designed as a high-speed drone and/or as a long-range drone. This design may support a centralized, shared recharge or battery swap solution, where one central hub can efficiently supply and service multiple locations, such as farms.

The aerial vehicle 1 may comprise at least one wing 57 that generates lift when the vehicle 1 moves forward.

The inclusion of wings allows for reduced power consumption, enabling extended flight ranges. Additionally, it may include a plurality of thrust-producing means 5, which can be configured as propellers. In the present embodiment, the configuration may involve five propellers, wherein four propellers 5′ are preferably designed to provide mainly vertical thrust, while a fifth propeller 5″ is configured to generate mainly horizontal thrust.

Alternatively, at least one propeller 5 may be dynamically rearrangeable and configured to provide either vertical thrust or horizontal thrust, depending on operational requirements.

In a further possible embodiment, the application relates to a system comprising the aerial vehicle 1 as described in the embodiments above, a designated landing area, and a mechanism for separating the replaceable battery 17 or replaceable battery assembly 69 from the aerial vehicle 1. The mechanism may be configured to autonomously reach the majority of locations within the designated landing area and is preferably not restricted by the length of the designated landing area. Additionally, the mechanism can autonomously approach the aerial vehicle 1 after it has landed and may separate the battery from the aerial vehicle 1 as part of a battery swap operation.

FIG. 21 shows a possible embodiment of the battery 17 used in the aerial vehicle 1. The battery 17 may be integrated into a replaceable battery module 69 designed for ease of swapping. This battery module 69 may include a battery housing assembly and a battery socket assembly, which both comprises several components that facilitate secure attachment, reliable energy transfer, and efficient robotic swapping. The battery socket assembly is attached or integrated into the receiving battery powered vehicle, like on the top side of a UAV. The housing assembly can be separated from the battery socket assembly, by a robot that has an electromagnet intended for this purpose.

The battery housing assembly preferably includes a battery basket 58, which features a battery resting plate 59 to support the battery 17, four legs that may slide into the cut-away sections on the roof 63, for secure attachment, and permanent magnets 61, that may interact with corresponding magnets 61 in the battery socket assembly 65 to ensure stability. The roof 63 of the battery housing assembly may comprise cut-away sections to accommodate the legs of the battery basket 59. Securing pins, 66 and 67, may lock these legs in place, while a permanent magnet holder positioned on the top side of the roof 63 enables robotic gripping. Additionally, the roof 63 may incorporate conductive material on two sides, which serves as the electrical contact points for energy transfer. These conductive features align with the curled contact flaps in the battery socket assembly.

The battery socket assembly may include a base plate 65, which is designed to securely hold the battery basket 58 legs through dedicated leg receivers. The base plate 65 may also house a permanent magnet holder that attracts the magnets 61 in the battery housing assembly, ensuring a firm connection. Electrical contact features on the base plate may facilitate energy transfer, with curled conductive flaps (e.g., made of copper) that make contact with the conductive sides of the roof 63 for reliable electrical connections.

The integration of these components creates a cohesive system where the battery housing assembly and the battery socket assembly interact seamlessly. The battery 17 is placed within the battery basket 59, covered by the roof 63, and secured by the pins 66, 67. When inserted into the socket assembly, the battery housing assembly aligns with the base plate 65, guided by the interaction of the permanent magnets 61. The conductive sides of the roof 63 establish contact with the electrical contact flaps on the base plate 65, enabling energy transfer.

The operational process begins with the assembly of the battery 17 into the basket 59, which is then covered and secured by the roof 63. During insertion, the battery housing assembly is guided into the socket assembly, establishing a secure mechanical and electrical connection. Once connected, the aerial vehicle 1 operates using the battery's power. For battery swapping, an external robotic mechanism, equipped with an electromagnet, grips the permanent magnet holder in the battery housing assembly, removes it from the socket, and replaces it with a charged battery housing assembly.

Safety measures are integrated into the design to ensure secure operation. The permanent magnets 61 and the battery basket leg receivers in the base plate 65 ensure the battery housing assembly remains firmly attached during flight. The electrical contact flaps are designed to provide consistent and reliable connections while preventing short circuits. The permanent magnet holder in the roof 63 is robustly designed to withstand the forces exerted during robotic swapping operations, ensuring the integrity of the assembly throughout the process.

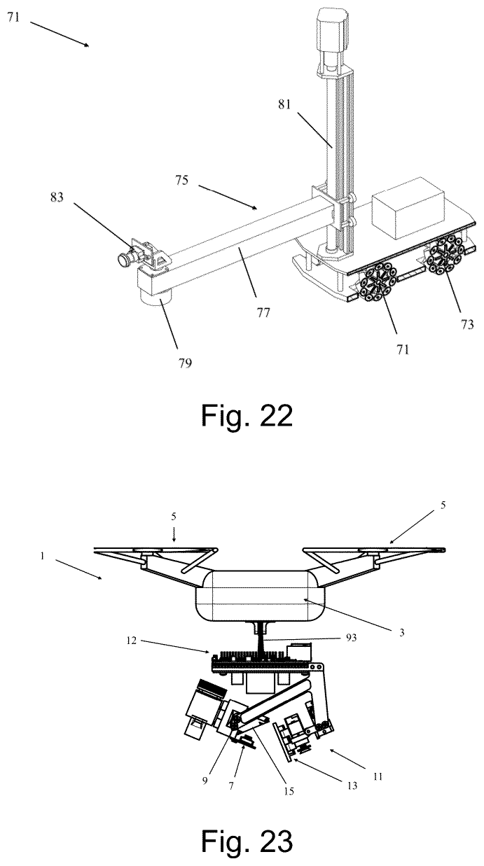

FIG. 22 illustrates a mechanism for separating the replaceable battery 17 from the aerial vehicle 1. The mechanism for separating the battery 17 may be attached to a robot 71, which can be equipped with wheels 73 or legs, making it suitable for navigating the designated landing area. In some embodiments, the wheels 73 may preferably be mecanum wheels or omni wheels, allowing for enhanced maneuverability.

Preferably, the battery 17 or the battery assembly 69 is detachably positioned on top of the aerial vehicle 1 when it is in a landed state. The battery 17 may include a magnet or metal component that can provide magnetic force to securely hold the battery 17 in place during flight and assist in its separation during the battery swapping process. Additionally, the mechanism for separating the replaceable battery 17 from the aerial vehicle 1 may comprise a battery-swapping component 75 designed to replace the battery 17. The battery-swapping component 75 may include an arm 77 equipped with an electromagnet 79, which can be moved vertically along a vertically arranged bar 81 via a rail and carriage system.

The robot 71 may preferably operate autonomously. To facilitate this, it may include a sensor, such as a camera 83, for driving and controlling the battery-swapping component 75. Furthermore, a rechargeable battery 85 and control unit may be integrated to operate the robot 71 and process data collected by the sensors, including camera 83 input, to ensure accurate positioning and efficient battery swapping. The robot may use its electro magnet to magnetically grip the magnet 61, thereby lifting the battery holder out of its socket. The robot can the transport to empty battery to another place and deposit in another battery socket, which is connected to a electricity source, which will then charge the empty battery.

In a further possible embodiment, the aerial vehicle may be configured for maintenance. In this regard a notification may be generated indicating that the aerial vehicle requires maintenance. In a next step, a component of the aerial vehicle can be replaced with a new component.

FIG. 23 illustrates a further possible embodiment of the aerial vehicle 1. The aerial vehicle 1 may include a main body 3 and a plurality of thrust-producing means 5. Coupled to the main body 3 via a rope 93 may be an alternative arrangement comprising a camera 7, a control unit 12, a laser unit 9, and an optical unit 11 with dichroic mirror 15 and a movable mirror 13. The rope 93 may preferably be configured to transfer yaw while isolating roll and pitch movements of the main body 3 of the aerial vehicle 1.

In a more generalized aspect, the invention may relate to a battery exchange system comprising a battery housing assembly configured for mechanical and electrical engagement with a battery socket assembly, wherein the battery housing assembly may include one or more features suitable for robotic gripping or engagement, enabling autonomous extraction and replacement.

The battery housing assembly could be designed to retain an energy storage element, such as a rechargeable battery, and may include one or more geometric, magnetic, or mechanical features that facilitate alignment, secure retention, and robotic interaction. For example, the housing assembly may comprise a frame, enclosure, or basket adapted to support the battery, and may further include a surface, extrusion, indentation, or fastening region that may be engaged by a robotic actuator. The gripping interaction could be achieved through a variety of means, such as a magnetic interface, a mechanical clamp, a hook mechanism, a conforming socket, or other robot-actuated tool.

In some embodiments, the battery housing assembly may include a magnetic gripping component, such as a permanent magnet, ferromagnetic plate, or magnetically attractable insert, which could be engaged by an electromagnet or passive magnet integrated into the robot. In other embodiments, the housing may comprise an outward extrusion, tab, or reinforced handle region, which would replace magnet 61, and be configured to be grasped by a robotic clamp or jaw actuator, or include slots or grooves suitable for alignment with guiding rails or fork-shaped tools. These interfaces may be positioned to remain accessible when the mobile platform-such as an aerial vehicle—is landed and in a stationary state, thereby enabling automated removal or reinsertion of the battery assembly.

The corresponding battery socket assembly may be mounted on a surface of a mobile platform or docking station and may include one or more features configured to align and receive the battery housing assembly. The socket assembly could incorporate guiding structures, receptacles for battery module legs or protrusions, and mechanical or magnetic retention elements. Electrical contact points, such as flexible conductive flaps, spring-loaded pins, or compliant contact pads, may be arranged to automatically engage with corresponding conductive surfaces on the battery housing assembly when inserted.

Together, the battery housing assembly and socket assembly may define a modular interface for both energy transfer and robotic handling. This architecture may enable rapid, repeatable, and tool-agnostic battery replacement operations suited for deployment on a range of electrically powered platforms-including, but not limited to, autonomous aerial vehicles equipped with precision targeting technologies, such as laser-based pest control systems. The system may facilitate extended autonomous operation by reducing or eliminating manual battery intervention, particularly in agricultural or remote contexts where human access may be limited or labor-intensive.

The laser unit 9 and the camera 7 are preferably rigidly connected to each other. Both the laser unit 9 and the camera 7 may be directed towards the dichroic mirror 15. The dichroic mirror 15 is preferably transmissive to the laser beam 10 and reflective to the optical path of the camera 7. This configuration ensures that the optical path of the camera 7 and the optical path of the laser unit 9, or laser beam 10, are aligned and both directed onto the movable mirror 13.

The control unit 12 may be configured to control the movable mirror 13 such that the laser beam 10 can precisely target a specific target 21.

FIG. 24 illustrates a further possible embodiment of the arrangement involving the control unit 12, the laser unit 9, the optical unit 11, and the camera 7. The laser beam 10 and the optical path of the camera 7 can be aligned because the dichroic mirror 15 is positioned in between. This dichroic mirror 15 is preferably transparent to the optical path of the camera 7 while reflecting the laser beam 10. The laser beam 10 may be directed onto the dichroic mirror 15 via the movable mirror 13. The camera 7 and the laser unit 9 are preferably rigidly connected to each other. The laser unit 9 may comprise a laser driver 100 which may be coupled with the control unit 12.

The movable mirror 13 may be operatively coupled to two servo motors 6, enabling the movable mirror 13 to be adjusted in two dimensions (see also FIGS. 24A and 24B).

FIG. 24A and FIG. 24B show a possible embodiment of a movable mirror 13 coupled to two servo motors 6, allowing it to be adjusted in two dimensions. The servo motors 6 can preferably be interconnected via a hinge 52 and may function as the first and second servo motors 6. The first servo motor 6 may generate a rotational force on the hinge 52 that opposes the force exerted by a first rubber band 54 (the first rubber band 54 is shown with dashed lines). The second servo motor 6 may generate a rotational force on the hinge 95 that opposes the force exerted by a second rubber band 97 (the rubber band 97 is shown with dashed lines). The hinges 52 and 92 may have an axis of rotation perpendicular to each other.

The first rubber band 54 may be located between and connected the holes 56 and 58 on the mounting brackets of the servo motors 6 and the second rubber band 97 may be located between and connected the holes 99 and 101. The rotational force on the hinges 52, 95 may be transmitted via a wire. A first wire can preferably be looped around or attached to a pulley 64 of the first servo motor 6 and then connected to hole 66 on the mounting bracket of the second servo motor 6. The second servo motor 6 may also include a pulley 62, with the a second wire routed around it and connected to the movable mirror 13 at hole 60. This configuration can enable precise movement of the movable mirror 13 through the coordinated actions of the two servo motors 6, offering enhanced control in two dimensions.

FIG. 25 shows a further possible embodiment of the arrangement involving the laser unit 9, the optical unit 11, and the camera 7. This arrangement is particularly compact and may also include a cooling component, which can preferably be a part of the cooling unit 43. 43. The cooling unit 43 may be coupled with the laser unit 9, wherein the cooling unit 43 employs graphene or diamond material, allowing to dissipate heat generated by the laser beam away from the laser unit 9. These materials may be arranged in sheets 46 or ribs 87 to optimize heat transfer and enhance cooling efficiency (see also FIG. 15).

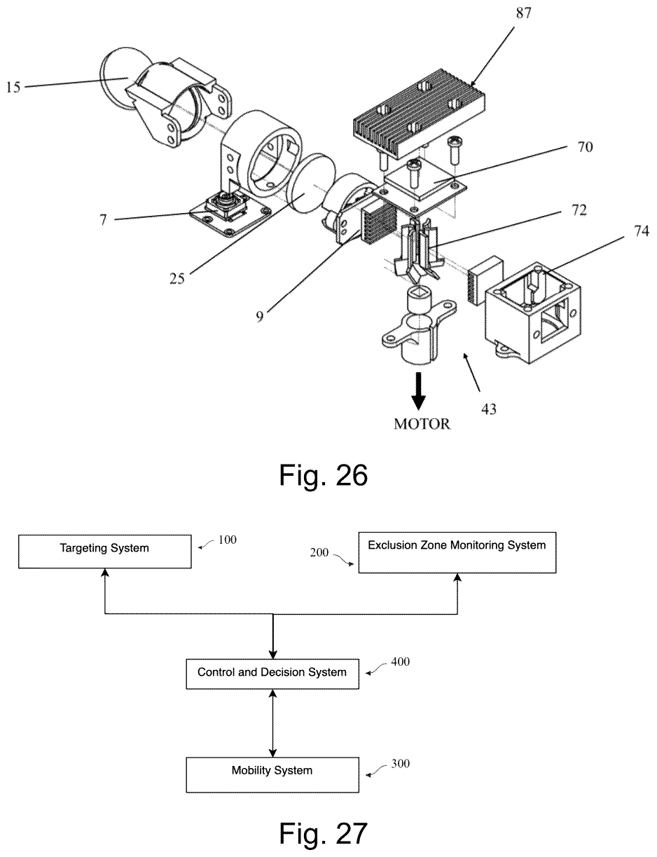

FIG. 26 shows a possible embodiment shown in FIG. 25 in an exploded view, allowing the individual components to be seen in greater detail. The arrangement may include a laser unit 9, a camera 7, and a dichroic mirror 15. This configuration can enable a compact design. All components may preferably be housed within an enclosure, which can be assembled from multiple parts. The laser beam 10 and the optical path may exit the enclosure via the dichroic mirror 15 and can be directed onto a movable mirror 13, which, in turn, may guide both onto a target 21.

Additionally, a cooling unit 43 may be provided, which can preferably include a liquid reservoir 74 suitable for containing water or ammonia. The capacity of the liquid reservoir may, for example, be less than 300 cm³. Within the liquid reservoir 74, a water or liquid wheel 72 may be arranged, which can be driven by a motor.

Furthermore, a Peltier element may be positioned above the liquid reservoir 74 to cool the liquid. Above the Peltier element, ribs 87 can preferably be placed to dissipate heat to the surrounding environment.

In some embodiments, the laser unit 9 may be equivalent to or synonymous with the laser light source 33.

FIG. 27 illustrates a block diagram of a possible embodiment of the autonomously operating pest control system, which may comprise a targeting system (100), an exclusion zone monitoring system (200), a mobility system (300), and a control and decision system (400). These subsystems may communicate with one another electronically and function in coordination to identify, track, and neutralize target organisms while ensuring safety in the surrounding area.

The control and decision system (400) preferably manages the coordination and activation of key components within the pest control system. In particular, it may control the operation of the neutralizing laser (101), an optional tunable focusing lens or metasurface (105), and a beam steering mechanism (104), such as a movable mirror, gimbal, or MEMS device. This control system is preferably configured to adjust the orientation of the laser path to continuously aim at a detected target. In some embodiments, laser activation may only occur after safety conditions have been verified, including confirmation that no human or mammal is detected in the surroundings. Such detection may be determined through electronic communication with the exclusion zone monitoring system (200), which may include environmental and thermal sensors.

All subsystems may be mounted on, or integrated into, a mobile platform such as a drone, wheeled cart, tracked robot, floating platform (e.g., a propeller-driven watercraft), or a cable- or track-guided device that moves above or between agricultural rows, green houses or home gardens.

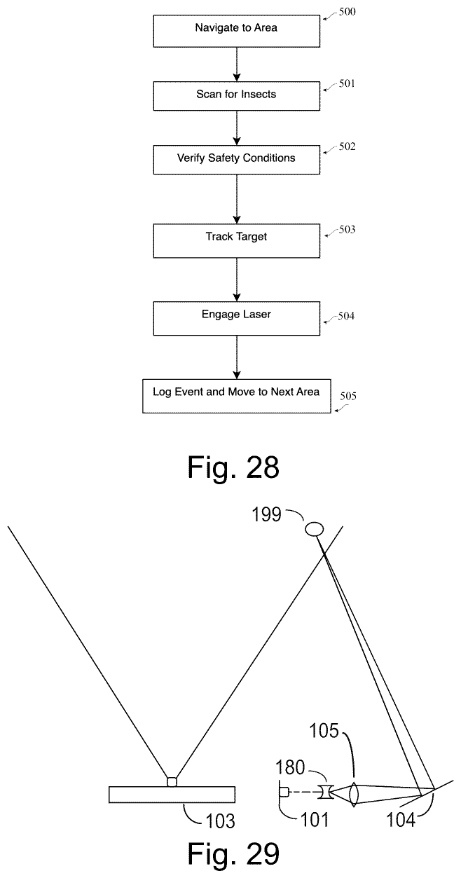

FIG. 28 illustrates a possible operational sequence for the system, which may include the following steps: navigating to a designated area (500), scanning for insects within the target area (501), verifying safety conditions (502), tracking a detected target (503), engaging the neutralizing laser (504), and optionally logging the event and transitioning to the next area (505).

The navigation step (500) may involve the use of a stored database of insect-prone zones or the application of real-time data and historical patterns to determine optimal search locations. Scanning (501) may be performed by the non-optically aligned camera (103), which may include a wide field-of-view or stereo imaging configuration. Verification of safety conditions (502) may include multiple checks, such as: detecting the presence of humans or mammals in the operational zone, ensuring that no heat-emitting organisms (e.g., animals above 30° C.) are being targeted, identifying anomalous objects in the environment (e.g., a bicycle lying in a field, a doll, or debris), and confirming that the platform and targeting system are oriented appropriately (e.g., not misaligned or toppled due to wind or terrain conditions).

Tracking the target (503) may include continuously analyzing image input, likely from the optically-aligned camera (102), and dynamically adjusting the beam steering mechanism (104), or reorienting the entire optical unit, so that the laser remains precisely aimed at the target throughout its motion. Once alignment and safety conditions are confirmed, the laser (504) may be activated to neutralize the pest. After the engagement, the system may optionally log the event and proceed to the next target location (505).

FIG. 29 illustrates a schematic optical path of a basic embodiment of the targeting system (100). In this configuration, a neutralizing laser (101) emits a beam that passes through a concave lens (180), which expands the beam, followed by a convex focusing lens (105). The beam is then directed toward a target (199) via a beam steering mechanism (104), which may include a movable mirror, gimbal, or other optical steering device. A non-optically aligned camera (103), operating outside the laser beam path, may observe the target area and provide image data to the processing unit (401). The processing unit (401) may analyze the camera feed in real-time and update the orientation of the beam steering mechanism (104) to maintain accurate targeting as the system tracks the target.

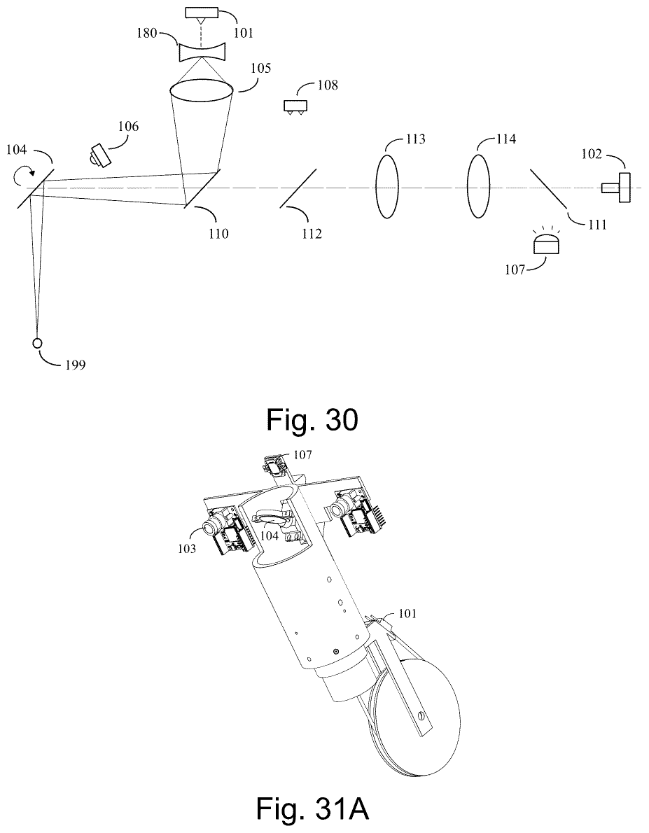

FIG. 30 illustrates a schematic optical path of a more advanced embodiment of the targeting system (100), which may incorporate additional optical and sensing elements to improve targeting accuracy, environmental awareness, and operational safety. In this embodiment, a neutralizing laser (101) is optically aligned with a camera (102), which may include an internal lens element (102b), through one or more dichroic mirrors or cubes (106), allowing both the laser beam and the optical axis of the camera to share a common path. This optically aligned configuration enables precise visual verification of the target just prior to laser engagement.

A second, non-optically aligned camera (103), which may optionally be configured as part of a stereo pair, can be used to survey a wider field of view and detect potential targets. Upon detection, the processing unit (401) may command the beam steering mechanism (104) to redirect the shared optical path of the laser and optically aligned camera toward the target. The beam steering mechanism may include, for example, galvo mirrors, fast steering mirrors (FSM), MEMS devices, gimbal systems, or servo-driven assemblies.

To ensure that the laser beam is focused at the correct depth, the targeting system (100) may further include a tunable or movable focusing element (105), such as a liquid lens or adaptive metasurface. This element may be dynamically controlled based on distance information provided by a depth sensor (108), allowing the system to adapt the focal point of the laser in real time. An illumination source (107) may also be included to assist with image acquisition or target verification, and in some embodiments may be optically aligned with the laser path via additional dichroic elements.

A thermal sensor (106), such as a heat camera, may be used to monitor the area near the target point for warm-bodied entities such as humans or mammals. This sensor may operate with a wide field of view, for example via a fisheye lens, and may receive radiation either directly or via reflections from the beam steering path. If the system detects the presence of a non-target heat source in or near the laser's engagement path, it may inhibit firing as a safety precaution.

To further reduce risk, some embodiments may include a visible or blue light source positioned to emit a brief flash just before laser activation. This light source may trigger a blink reflex in nearby biological entities, providing an additional safeguard against accidental exposure.

The use of a 4f optical system-comprising two appropriately spaced lenses (e.g., 113 and 114)—may support more flexible internal alignment of components, improve optical performance, or allow spatial separation between the laser and optical sensors while preserving a common focus.

The advanced embodiment illustrated in FIG. 30 may further rely on spectrally selective optical components to manage the alignment and separation of sensor and laser paths. In particular, the system may employ a series of wavelength-tuned optical elements, including dichroic mirrors and beam splitters, to support shared optical axes, efficient beam routing, and safety mechanisms.

In some embodiments, a first dichroic mirror (110) may be configured to reflect wavelengths at or above approximately 1550 nm-corresponding to the wavelength of the neutralizing laser (101)—and to transmit shorter wavelengths, including visible light and near-infrared bands (e.g., 850-950 nm). A second dichroic mirror (112) may be placed downstream in the optical path and tuned to reflect wavelengths above approximately 900 nm-such as those used by a depth sensor (108)—while transmitting visible light toward the imaging system.

Additionally, a 50/50 beam splitter (111) may be positioned to reflect and transmit approximately 50% of the visible spectrum. This element may allow an outgoing visible or blue illumination source (107) to be reflected into the shared optical path for the purpose of scene illumination to assist the optically aligned camera (102), or, optionally, may be configured to reflect a secondary visible light source (not shown) intended to trigger a blink reflex as a safety precaution prior to laser activation.

In one implementation, incoming visible light from the target first passes sequentially through dichroic mirror 1 (110), then dichroic mirror 2 (112), and finally through the beam splitter (111) before reaching the optically aligned camera (102). Conversely, outgoing illumination light, such as from an LED in the visible spectrum, may be introduced in reverse order: it is first reflected by the beam splitter (111), then passes through dichroic mirror 2 (112) and dichroic mirror 1 (110), and is finally reflected by the beam steering mechanism (104) toward the target.

In some embodiments, the optical path may comprise a two-lens beam expansion configuration, optionally followed by a separate focusing element. For example, the laser beam emitted by the laser unit may first pass through a negative lens and then through a positive lens arranged in a Galilean telescope configuration to expand the beam diameter. Alternatively, two positive lenses of different focal lengths may be used in a Keplerian configuration to achieve beam expansion. In either case, the expanded beam may subsequently be directed through a third lens-such as a converging lens or tunable focus lens-positioned to focus the beam toward a target at a predefined distance. This three-lens configuration allows for modular separation of beam shaping and focusing functions, which may simplify alignment or allow the use of low-cost, off-the-shelf optical components. In other embodiments, a single lens may perform both beam expansion and focusing, or a two-lens system may be configured such that the expanded beam naturally converges toward the target without requiring a third element. Using only two lenses may reduce system weight, cost, and overall size, which is advantageous in aerial or portable platforms with mass and volume constraints.

The beam diameter resulting from the beam expansion stage is preferably selected based on the desired nominal safety zone associated with the laser system. A larger beam diameter prior to focusing generally results in a tighter focal spot (smaller beam waist) and a larger divergence angle beyond the focus, which in turn reduces the nominal ocular hazard distance (NOHD), thereby improving operational safety. This enables the laser system to be safely operated in environments where humans or animals may be present. However, achieving a larger beam diameter also necessitates larger downstream optics, such as a wider steering mirror and focusing lens, potentially increasing system complexity and mass.

Conversely, decreasing the focal length of the final lens reduces the NOHD by limiting the hazard range of the beam, but also reduces the maximum effective range at which the beam can be focused, potentially requiring the mobile platform to physically approach each target. This may reduce system efficiency or increase energy consumption during operation, particularly in mobile scenarios. Accordingly, system designers may balance multiple factors including beam expansion ratio, focusing distance, mirror aperture size, and laser engagement range. These parameters may be jointly optimized using laser safety standards, such as IEC 60825-1, and commercially available optical design software such as Zemax OpticStudio.

The NOHD is preferably synchronized with the surrounding monitoring system, which may include thermal or environmental sensors configured to detect mammals, humans, or other non-target entities in the vicinity. If such entities are detected within the NOHD, the control unit may inhibit laser activation as a safety measure. This coordination between beam geometry and environmental sensing enhances the overall safety of the system by preventing hazardous exposure during targeting operations.

The targeting system (100) may be configured with a plurality of optical elements that could be arranged to define specific paths for incoming and outgoing light, potentially enabling coordinated sensing, illumination, and laser delivery functions, which could typically be directed by a common beam steering mechanism (104).

The geometrical paths for various operational light beams may be described as follows, as illustrated in FIG. 30.

Light from an external scene, which could be intended for image capture by an optically aligned camera (102), may first be incident upon and could be reflected by the beam steering mechanism (104). The reflected light may then be directed along a shared optical axis, potentially propagating sequentially through a first dichroic mirror (110), a second dichroic mirror (112), one or more lens elements (113, 114, which could form part of an optical relay or beam conditioning system such as a 4f system), and a beam splitter (111). After passing through these elements, the light could be captured by an internal image sensor within the camera (102).

An illumination light path could originate from an illumination source (107). Light emitted from this source (107) might first be incident upon and could be reflected by the beam splitter (111), thereby potentially being directed into the aforementioned shared optical axis. The illumination light could then propagate in a reverse direction relative to the incoming camera light, possibly passing sequentially through the lens elements (114, 113), the second dichroic mirror (112), and the first dichroic mirror (110). Finally, the illumination light could be reflected by the beam steering mechanism (104) outwards towards the scene or a designated target area.

For depth estimation or active sensing, an outgoing sensing beam, such as that from a Light Detection and Ranging (LIDAR) emitter which might be part of a depth sensor (108), could originate from its respective source. This outgoing sensing beam may be directed to be incident upon and could be reflected by the second dichroic mirror (112), potentially causing it to enter a shared optical axis common to the first dichroic mirror (110). The sensing beam may then pass through the first dichroic mirror (110) and could subsequently be reflected by the beam steering mechanism (104) outwards towards the scene or target (199).

An incoming sensing beam, such as LIDAR light that could be reflected or scattered back from the target (199) or scene, may first be incident upon and could be reflected by the beam steering mechanism (104). This returning sensing beam might then traverse the shared optical axis, possibly passing through the first dichroic mirror (110). It could subsequently be incident upon and reflected by the second dichroic mirror (112), which may direct the beam towards a sensor element within the depth sensing module (108) for distance determination.

For thermal monitoring, incoming heat radiation from the external scene in the field of regard of the beam steering mechanism (104) could be reflected by said beam steering mechanism (104). This reflected thermal radiation may then be directed towards a thermal sensor (106). An optional fisheye lens could be operatively associated with the thermal sensor (106) to potentially provide a wide-angle view of the area being monitored via reflections from the beam steering mechanism (104), thereby possibly enabling detection of warm-bodied entities along or near a potential laser path.

The neutralizing laser light path could originate from a laser unit (101). A laser beam emitted from the laser unit (101) may be configured to pass first through a concave lens (180), which could serve for expansion of the laser beam, and subsequently through a focusing element (105) to adjust its convergence. The expanded and subsequently focused (or pre-focused) laser beam may then be incident upon and could be reflected by the first dichroic mirror (110), potentially directing it into the shared optical axis. Finally, the laser beam could be reflected by the beam steering mechanism (104) outwards towards a potential target (199).

The following section outlines potential design parameters and approximations that may assist in configuring the optical components of the targeting system. These relationships are intended as illustrative examples to guide implementation and optimization. In practice, values may vary depending on platform constraints, laser specifications, safety requirements, and optical design preferences.

The laser beam emitted by the system may optionally be expanded using a two-lens telescope configuration to increase the beam diameter before focusing. This setup may follow a Galilean design, using a negative lens followed by a positive lens, or a Keplerian design, using two positive lenses. The beam expansion ratio may be approximated as the ratio of the second lens's focal length to the first:

$$M \approx {f}_{2} / {f}_{1}$$

where f₁ and f₂ represent the focal lengths of the first and second lenses, respectively. The spacing between the lenses may generally be set to approximately |f₁|+f₂ for beam shaping purposes. In some cases, the expanded beam may then be focused toward a target using a separate converging lens or an adaptive focusing element.

The focused spot size at the target—the beam waist—may be roughly estimated using Gaussian beam optics. One possible expression is:

$${w}_{0} \approx ( 2 λ f ) / ( π D )$$

where λ is the laser wavelength, f is the focal length of the focusing lens, and D is the incident beam diameter. This focused waist may determine the effective spot resolution and influence safety constraints. The beam divergence beyond the waist may be approximated as:

$$θ \approx λ / ( π {w}_{0} )$$

The nominal ocular hazard distance (NOHD) for a given laser output may be linked to the divergence angle and power, and can be roughly modeled as:

$$NOHD ∝ √ ( P / {θ}^{2} )$$

where P represents the optical power. These expressions may assist in balancing performance with safety: increasing the beam diameter or reducing the focal length may help decrease the NOHD, thereby enhancing safety in environments with potential human exposure. The NOHD may be coordinated with the system's environmental monitoring logic such that laser firing is inhibited when mammals or humans are detected within the hazard zone.

To preserve optical alignment or share a beam path between the laser and camera, a 4f system may be used. This system may include two lenses with focal lengths f₁ and f₂, separated by approximately f₁+f₂, with magnification roughly equal to:

$$M \approx {f}_{2} / {f}_{1}$$

The 4f layout may preserve the spatial alignment of the beam while allowing for internal reconfiguration of component placement. A target region of size hₒ may be projected through the 4f system to a sensor plane as an image of size hᵢ, where:

$${h}_{i} \approx M \times {h}_{0}$$

In embodiments where the sensor is physically smaller than hᵢ, the system may optionally include a further imaging lens or lens group positioned between the second lens of the 4f system and the camera. This additional optical assembly may be used to demagnify the relayed image and match it to the camera's active area. Such configurations may be useful when the desired field of view is narrow or when compact sensors are used.

The angular field of view θ of the camera may be estimated from the desired scene width hₒ at working distance z using:

$$θ \approx 2 \times arc tangent ( {h}_{0} / ( 2 z ) )$$

If the camera has a known sensor width hᵢ, the corresponding lens focal length required to capture this field may be roughly approximated as:

$$f \approx {h}_{i} / ( 2 \times tan ( θ / 2 ) )$$

For example, a system designed to observe a 5 cm-wide field at 1 meter may require an angular FOV of approximately 2.86°, which could correspond to a focal length of around 128 mm when using a 6.4 mm-wide sensor, depending on lens placement and configuration.

In systems using beam-steering elements such as mirrors, the lateral shift of the beam spot may be estimated as:

$$Δ x \approx 2 f \times tan ( θ )$$

where f is the distance from the steering mirror to the target or output plane, and θ is the deflection angle. This relationship may be considered when selecting steering mirror sizes and calculating targeting resolution.

All distances, angles, and relationships described herein may be adjusted or refined based on modeling results and performance objectives. Optical simulation software such as Zemax OpticStudio or Code V may be used to optimize spacing, select appropriate lens curvatures, minimize aberrations, and ensure that beam alignment and focus requirements are met across the desired range of operating conditions.

Any formulas, equations, or calculations presented herein for determining distances, focal lengths, beam paths, or other spatial parameters are intended to be illustrative and suggestive rather than limiting. In practice, persons skilled in the art typically utilize constraint solvers and parametric design tools—such as Onshape for mechanical sketches or Zemax for optical path optimization—to derive the appropriate dimensions and spatial configurations. These tools enable precise tuning of system parameters based on design constraints, performance goals, and tolerances, as deriving exact closed-form solutions is often impractical or unnecessary in real-world implementations.

In some embodiments, the system may include an event-based camera configured to detect changes in light intensity at each pixel with microsecond resolution. Unlike conventional frame-based cameras, event cameras report only dynamic changes, enabling low-latency, high-speed visual processing with reduced data load. This may improve detection of fast-moving targets, reduce motion blur, and lower power consumption. The control unit may use event camera data to support real-time targeting, motion prediction, or environmental awareness, optionally in combination with frame-based or depth sensors or assisted by a neuromorphic processor.

This optical configuration allows the system to:
Maintain co-alignment of the neutralizing laser and imaging system,
Dynamically route both incoming and outgoing light through shared optical elements,
Integrate depth sensing and optional illumination, and
Incorporate pre-activation visual signaling as an additional safety mechanism.

High-reflectivity coatings, such as protected silver or broadband dielectric stacks, may be applied to the mirrors or beam splitter to ensure minimal losses across the relevant wavelength bands. The specific cutoff points and transmission properties of the dichroic components may be selected based on the characteristics of the laser, imaging sensors, depth sensing modules, and safety requirements of the system.

In various embodiments, the neutralizing laser (101) within the targeting system (100) may be implemented as either a free-space-emitting laser or a fiber-coupled laser, depending on design constraints, modularity, and system integration requirements.

In a free-space configuration, the laser may emit directly into the optical path and be shaped using a pair of optical elements including a concave lens (180) followed by a convex lens (105). This configuration may serve to expand or collimate the beam and condition its profile before it enters the downstream optical path. In a fiber-coupled configuration, the laser may be spatially separated from the optical head and deliver light through an optical fiber. The beam may then exit through a fiber collimator and pass through the same concave-convex lens arrangement to match the optical parameters required by the beam steering system (104) and focusing element (105).

The optical system may be configured so that the laser beam converges toward a focal point (typically determined by the dynamic focusing element (105)) and subsequently diverges beyond that point. This geometry offers a critical safety advantage: once the beam has passed its focal point, its cross-sectional area increases and its irradiance drops rapidly. As a result, the system may define a Nominal Safety Zone (NSZ) based on Maximum Permissible Exposure (MPE) limits associated with the laser's wavelength and power. The converging-diverging beam profile ensures that any object located outside the NSZ-especially beyond the focal point—is subject to significantly lower, non-hazardous exposure levels.

The exclusion zone monitoring system (200) may use this NSZ information to enforce laser safety rules dynamically. For example, the monitoring system may inhibit or delay laser firing if a human, mammal, or reflective object is detected within the beam path, particularly if that object is within the NSZ where MPE thresholds could be exceeded. This approach enables the system to maintain high targeting precision while respecting safety requirements in open or semi-controlled environments.

Both free-space and fiber-coupled configurations may be compatible with the beam steering system (104), tunable focusing lens (105), dichroic optics (106, 110, 112), and co-aligned camera systems. The choice of configuration may depend on integration strategy, form factor, safety criteria, and optical performance requirements.

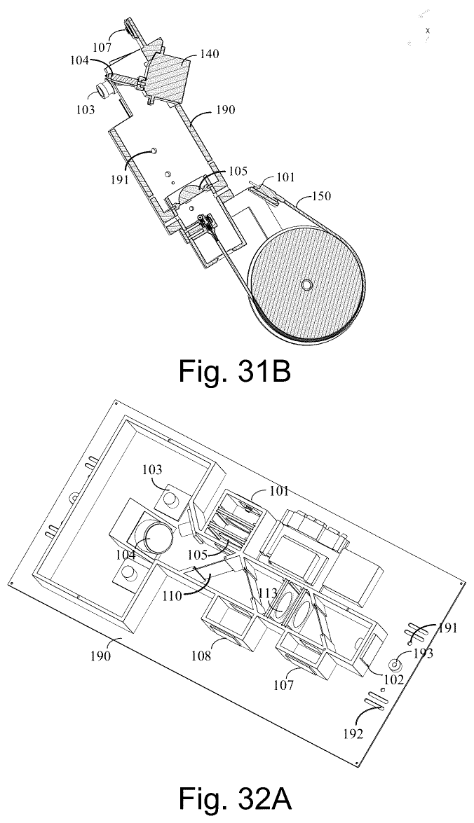

FIG. 31A shows a computer-aided design (CAD) representation of a possible embodiment of the targeting system (100), housed within a protective enclosure (190). FIG. 5B presents a corresponding cross-sectional view of the same embodiment, illustrating the internal arrangement of the optical and electromechanical components.

The system includes a non-optically aligned illumination source (107), which may provide scene lighting to support one or more cameras. Two non-optically aligned cameras (103) are positioned in a stereo configuration and may be used to detect potential targets, estimate depth, and support coarse localization tasks. A beam steering mirror (104) is centrally mounted within the housing and may be coupled to a servo motor (140) configured to control its orientation. In some embodiments, the beam steering mirror (104) may also have a curved surface or aspheric geometry, allowing it to function additionally as a focusing mirror, thereby combining directional and focusing adjustments within a single element.

Laser light may be introduced into the system via a fiber optic cable, which delivers the beam from a remote or internally housed laser source. The beam exits the fiber and passes through a focusing or collimating lens (105), which may be adjusted or tuned to condition the beam profile for steering and emission.

The enclosure (190) serves to structurally support and protect all internal components. A mounting hole (191) may be provided in the housing to facilitate secure attachment to a mobile platform, gimbal, robotic arm, or other support structures. The housing may also include optical apertures, cable routing channels, or thermal dissipation features as required.

This embodiment highlights a compact and modular configuration of the targeting system, designed for integration into a wide range of mobile or stationary platforms.

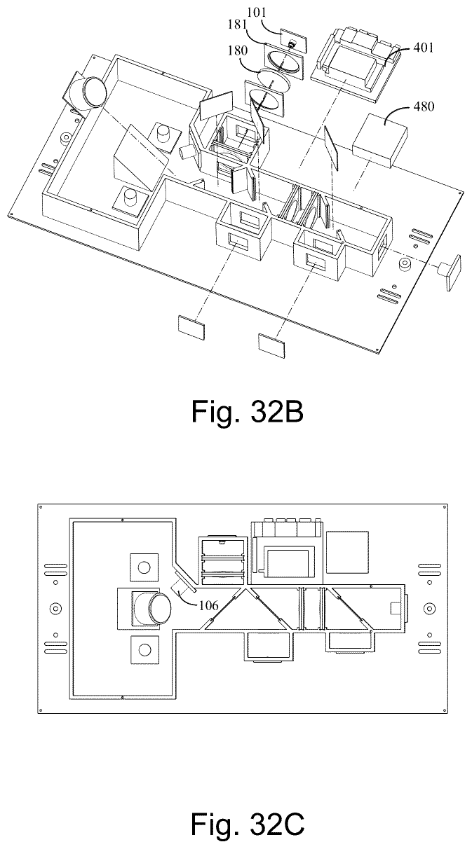

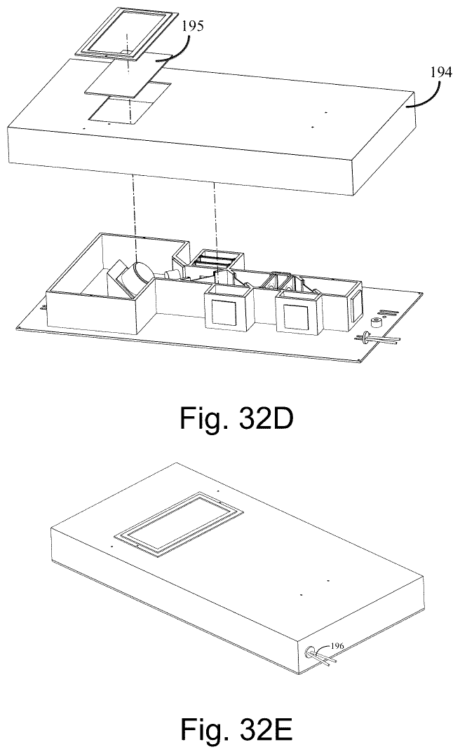

FIG. 32A illustrates a CAD rendering of an advanced embodiment of the targeting system (100), showing all major optical, electromechanical, and structural components assembled and positioned within a protective housing (190). FIG. 32B provides an exploded view of the system, revealing the internal layout of the components, while FIG. 32C shows a top view of the same embodiment. FIG. 32D illustrates a removable cover (194) designed to enclose the housing and protect the internal components from environmental exposure. The cover may include a transparent window (195), formed of glass or optical-grade plastic, that is transparent to both the outgoing laser beam and the incoming imaging and sensor light, thereby allowing normal operation while shielding the internal elements. FIG. 32E presents a fully assembled, externally viewed version of the targeting system, with the housing and cover fully closed, and showing exiting cables (196) for power supply and data communication. These cables are positioned for easy connection to a mobile platform or external control module.

The system is enclosed in a housing (190) that is designed for robust mechanical protection and flexible mounting. A mounting hole (191) may be provided to allow for rigid attachment to a vehicle, gimbal, or other mobile structure. In addition, the housing may include one or more strap slots (192) for securing the unit using flexible straps, particularly in agricultural or ad hoc mobile deployments. A camera mount bore (193) may be included to enable attachment to standard camera mounting systems or robotic arms.

The internal components include all optical and electronic elements described in earlier figures, including:
The neutralizing laser (101) delivered via optical fiber,
A beam steering mechanism (104), optionally with focusing capability,
A tunable or movable focusing lens (105),
Dichroic optics (110, 112), beam splitter (111), and optional visible or blue light sources,
Non-optically aligned cameras (103) in a stereo configuration,
An optically aligned camera (102),
Illumination sources (107),
Thermal (106) and depth (108) sensors,
And all associated optics positioned along the shared beam path.

A dedicated processing unit (401) may be mounted within the housing to perform real-time image processing, targeting logic, and safety evaluation. Supporting electronics, including voltage regulators, signal drivers, and control buses, may be housed in a dedicated electronics enclosure (480) within the unit. In some embodiments, thermal management components or shielding may also be integrated.

To facilitate lens positioning and ease of assembly, the system may employ a lens clamping mechanism (181) comprising two half-shell elements or “squeezers,” which may be made from plastic or other durable materials.

These are designed to secure a convex or concave lens between them and form a rectangular module that can be easily slid into or mounted within the housing (190) with repeatable alignment and minimal mechanical stress.

Together, FIGS. 32A through 32E illustrate a compact, weather-resistant, and integration-ready version of the targeting system suitable for use in outdoor environments, agricultural vehicles, mobile robotics, or UAV platforms. The design allows for precise targeting performance while offering mechanical robustness, modularity, and ease of integration.

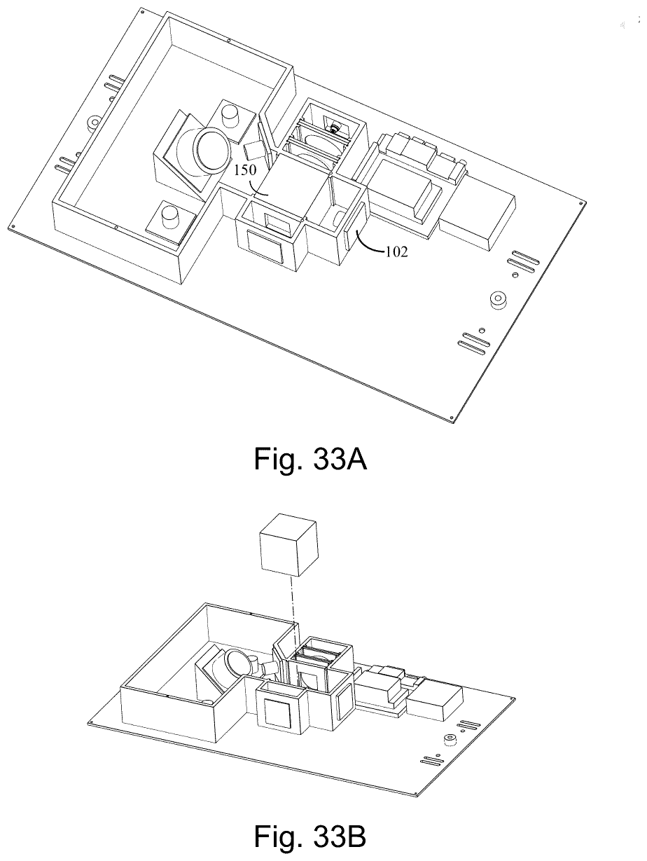

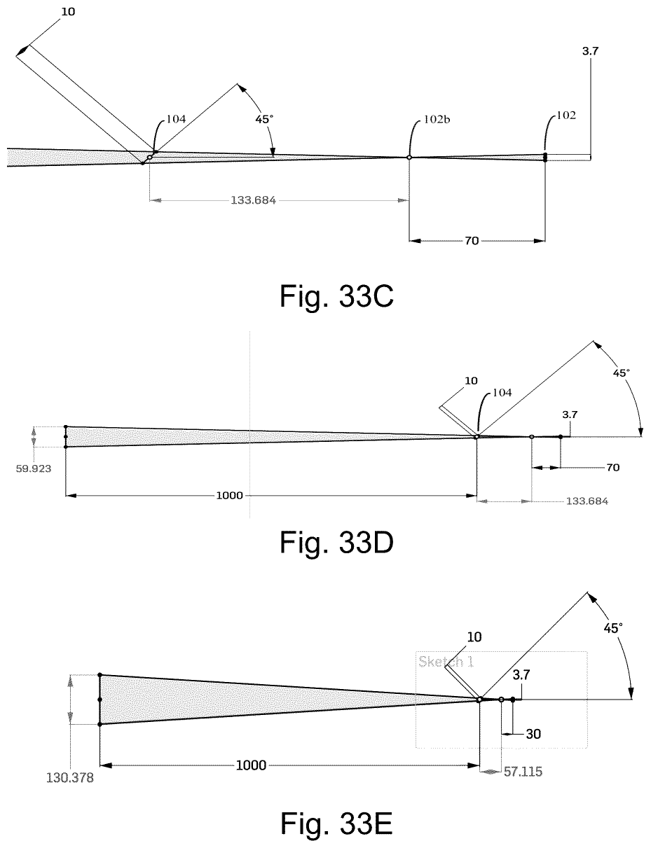

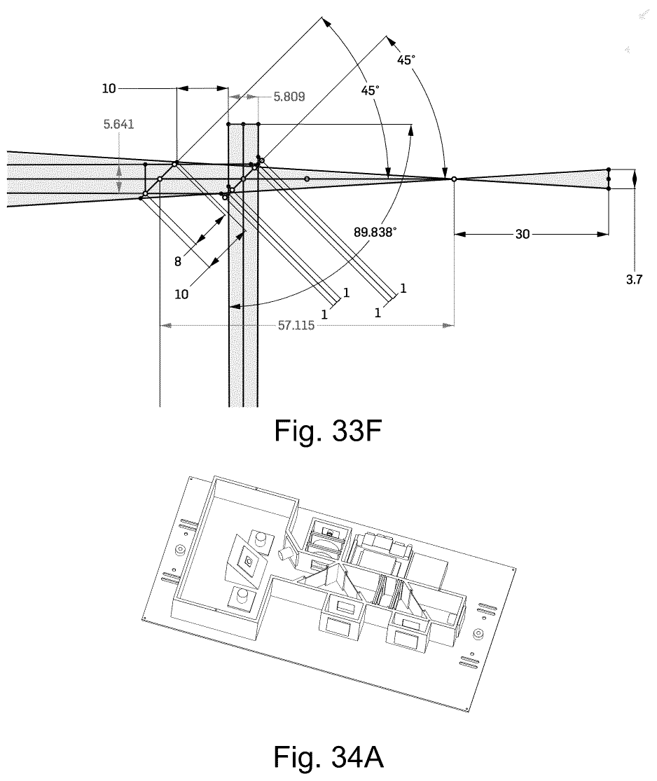

FIG. 33A illustrates a variation of the targeting system (100) in which a dichroic cube (150) is employed to optically align three elements: the optically aligned camera (102), the neutralizing laser (101), and either an illumination source (107) or a depth sensor (108). In this embodiment, all three optical paths may be combined within the cube, enabling compact and coaxial alignment of emission and sensing elements. This configuration may be advantageous in scenarios where space constraints prevent the use of multiple dichroic mirrors or extended beam paths. Notably, this design omits the 4f optical system (e.g., lenses 113 and 114), relying instead on the intrinsic alignment provided by the dichroic cube. This reduction in components may simplify assembly and reduce optical losses in some implementations, though potentially at the cost of field-of-view or focus flexibility offered by a 4f configuration.

FIG. 33B shows an exploded view of the embodiment depicted in FIG. 33A, illustrating the relative spatial arrangement of the cube (150) and its associated optical components.

FIGS. 33C to 33E illustrate schematic configurations derived from the embodiment shown in FIG. 33A, each demonstrating the effect of different focal lengths used for the camera lens (102b). In all three schematics, the scanning mirror (104) is illustrated as optically transparent to reduce visual complexity, although in practical implementation it may function as a reflective beam-steering element. Additionally, any dichroic mirrors or other optical path-combining components that may be present in actual use (e.g., dichroic mirrors or cubes) are omitted from these figures for clarity. The lens (102b) may be shown schematically as a dot, analogous to a pinhole, to emphasize its focusing function without crowding the drawing.

FIG. 33C provides a detailed schematic of one configuration in which the lens (102b) has a focal length of approximately 70 mm. With a sensor height of 3.7 mm, this produces a vertical field of view (FoV) of approximately 59.9 mm at a working distance of 1 meter beyond the beam steering mirror (104). In this configuration, the lens-to-mirror distance is approximately 133 mm, assuming the mirror has a diameter of 10 mm. This spacing may provide ample room for incorporating multiple dichroic elements-such as three stacked mirrors or a dichroic cube—to integrate additional light paths for laser emission, depth sensing, and illumination.

FIG. 33D presents an overview of a comparable configuration with simplified geometry, again based on the embodiment of FIG. 33A. The lens is not explicitly shown, and instead the optical axis is traced in a schematic manner to indicate light travel paths without overwhelming the figure with optical components.

FIG. 33E shows an alternative configuration in which the lens (102b) has a reduced focal length of approximately 30 mm. This shorter focal length results in a wider field of view-approximately 130 mm at 1 meter—and reduces the lens-to-mirror distance to approximately 57 mm. Although this tighter spacing may limit the number or size of additional optical elements, it may still support the integration of two or more dichroic mirrors, and could be better suited for embodiments employing compound lens assemblies, such as a 4f system, to achieve specific imaging or alignment goals.

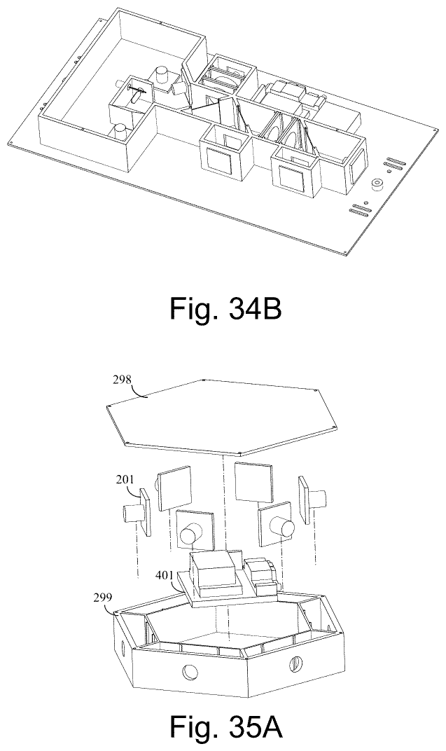

FIG. 34A presents a variation of the targeting system in which a MEMS-based beam steering mirror is used in place of the fast steering mirror (FSM) illustrated in earlier embodiments such as FIG. 32. The MEMS mirror may be used to direct the laser beam and co-aligned optical axis of the camera (102), and may provide benefits in terms of size, weight, and integration density. MEMS mirrors are particularly well-suited for compact systems with limited payload capacity, such as small UAVs, and may enable high-speed directional control over a limited angular range.

FIG. 34B illustrates an alternative variation in which the beam steering function is implemented using a two-mirror galvanometer (galvo) system. In this configuration, each galvo mirror is independently actuated-typically around orthogonal axes-allowing full two-dimensional control over the direction of the outgoing laser beam. This setup may be possible in applications requiring larger angular deflection, higher optical throughput, or more rugged electromechanical performance than MEMS devices can offer. The galvo-based system may be housed within the same optical layout as previous embodiments, and may be substituted directly for the FSM or MEMS unit, depending on application requirements.

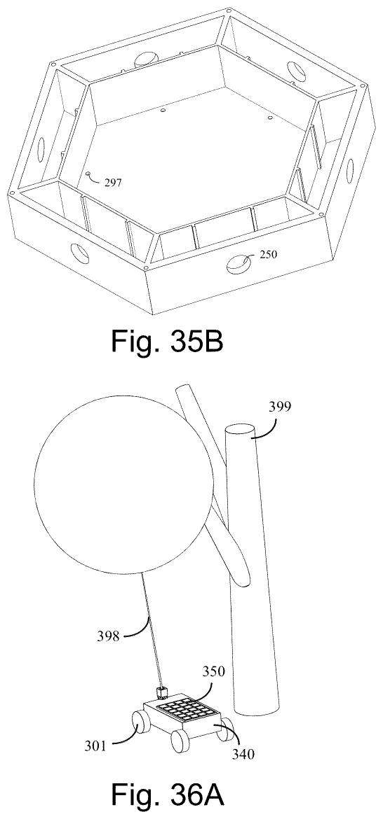

FIGS. 35A and 35B illustrates an embodiment of the surrounding monitoring system (200), which is configured to evaluate the environment around the targeting system (100) for the presence of non-target entities such as humans, animals, or obstacles. The monitoring system includes a set of wide-angle or omnidirectional cameras (204) arranged in a spatial configuration that enables near-complete coverage of the area surrounding the host platform. These cameras may be mounted on a rigid support structure and oriented to collectively cover 360 degrees in azimuth, and optionally include upward and downward fields of view.

A central processing unit (401) is positioned within the housing and is operatively connected to the camera array. This unit may execute object detection, motion tracking, thermal signature evaluation, or anomaly recognition routines in real time. Based on its analysis, the system may dynamically enforce laser safety protocols by inhibiting or permitting activation of the neutralizing laser (101) depending on exclusion zone violations.

The entire monitoring assembly is enclosed in a housing (290) that may be environmentally sealed or ruggedized for field conditions. The housing may include an integrated mounting hole (297) to facilitate attachment to a mobile platform, aerial drone, robotic arm, or static infrastructure. The system may be powered by the host platform or include its own energy supply.

This embodiment shows a modular and portable realization of the monitoring subsystem, capable of being deployed independently or in tandem with a targeting unit to enhance safety and situational awareness during autonomous operation.

In some embodiments, the monitoring system (200) may further include a UWB (Ultra Wideband) sensing unit, such as a human presence detector based on UWB radar technology—for example, devices similar in function to Ceva's UWB radar module. This radar-based sensor may be configured to detect the presence of living beings by analyzing micro-motions associated with human respiration or cardiac activity, offering an additional layer of detection capability beyond standard visual or thermal imaging. One advantage of incorporating UWB sensing is its ability to operate through visual obstructions, such as vegetation, netting, or partial cover, thereby enabling the detection of individuals who are partially hidden or obscured from the view of optical sensors. The UWB detector may be integrated into the same housing (290) or mounted externally in communication with the central processing unit (401), and may contribute to the overall safety logic by generating an exclusion-zone override signal upon the detection of a human presence within a critical proximity, even if the individual is not optically visible. This enhancement may improve the robustness of the system in complex field conditions, such as wooded or cluttered environments where optical occlusion is likely.

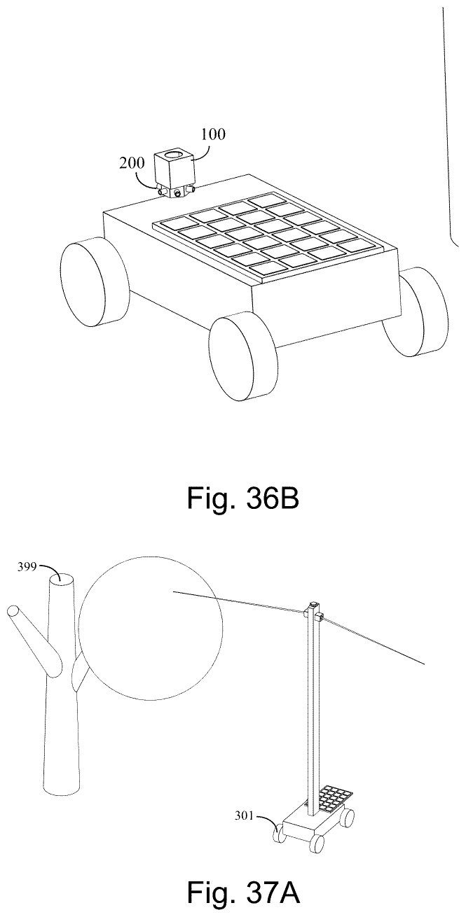

FIGS. 36A and 36B illustrate an in-field application of the pest control system mounted on a mobile cart platform (340). In this embodiment, the targeting unit (100) is installed in an upward-facing orientation, allowing the system to engage pests located in the canopy of a tree (399). This vertical targeting configuration may be particularly suited for orchard environments or tall vegetation where insect populations tend to cluster above ground level.

The mobile platform comprises a chassis supported by four wheels (301) for ground mobility and may include manual or autonomous locomotion capability. A solar panel (350) is mounted on the cart to provide renewable power for sustained field operation, potentially reducing the need for battery swaps or frequent recharging. To ensure safe operation in open environments, the system may further include a surrounding monitoring unit (200), configured to observe the area around the cart for the presence of non-target entities such as humans or animals. The monitoring system may use one or more cameras or thermal sensors to evaluate the exclusion zone prior to laser engagement, thereby supporting the same safety principles as outlined in other embodiments.

This figure illustrates the adaptability of the targeting system (100) for various mounting angles, crop types, and field scenarios, demonstrating its potential for diverse agricultural applications. The outgoing laser beam (398) is shown for illustration purposes.

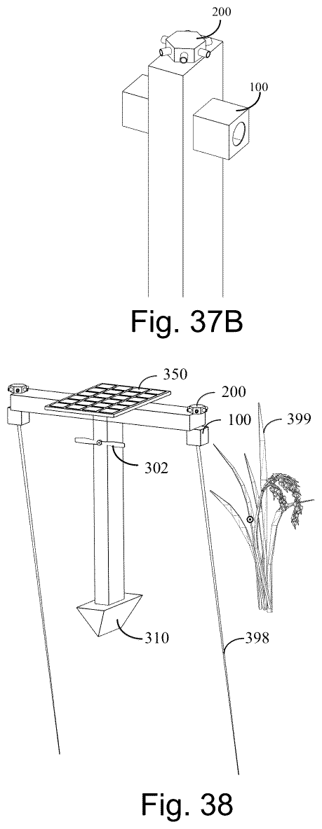

FIGS. 37A and 37B illustrates a variation of the system in which the targeting system (100)—and optionally the surrounding monitoring system (200)—are mounted on a horizontal strut or armature configured to position the optical axis of the system horizontally. In this embodiment, the laser and camera systems are oriented to fire or observe laterally, rather than vertically, making it suitable for applications where pests reside on the side-facing surfaces of a tree canopy (399) or other elevated vegetation.

The strut may be mounted to a mobile platform such as a cart, tracked vehicle, or robotic manipulator, and may include adjustable joints or locking mechanisms to fine-tune the targeting angle. This orientation allows the system to operate beneath or adjacent to a tree line, engaging pests directly from the side, which may improve visibility under dense foliage or in orchards with row-based layouts.

As in other embodiments, the targeting system (100) may be configured to receive input from the surrounding monitoring system (200) to verify that no human, animal, or obstruction is present within the beam path. The configuration shown in FIG. 37B demonstrates the versatility of the modular unit, which may be deployed in vertical, angled, or horizontal orientations depending on the task and field environment.

FIG. 38 illustrates an embodiment of the system configured for deployment in flooded agricultural environments, such as rice fields. In this example, the targeting system (100) is mounted in a downward-facing orientation on a water-optimized mobile platform, and is configured to engage pests located on or near aquatic crops, such as a rice plant (399) shown in the figure.

The mobility platform may include one or more floatation components (310) to maintain buoyancy and stable positioning on water surfaces. In some embodiments, the system may be propelled using one or more propellers (302) for active navigation, or alternatively may rely on wheeled or tracked mechanisms capable of traversing shallow water or semi-submerged terrain. The choice of propulsion may depend on the water depth, terrain conditions, and operational constraints of the specific field environment.

As with other embodiments, the targeting system (100) may operate in conjunction with a surrounding monitoring system (200) to ensure safe laser use, and may include standard components such as a beam steering mechanism (104), aligned cameras, depth sensors, and thermal detectors. The system may also utilize downward-angled lighting and optical elements adapted for water reflection conditions or low-angle surface scattering common in flooded fields.

This embodiment demonstrates the adaptability of the pest control system across diverse crop types and environmental conditions, including aquatic agricultural zones where traditional wheeled or aerial platforms may be impractical.

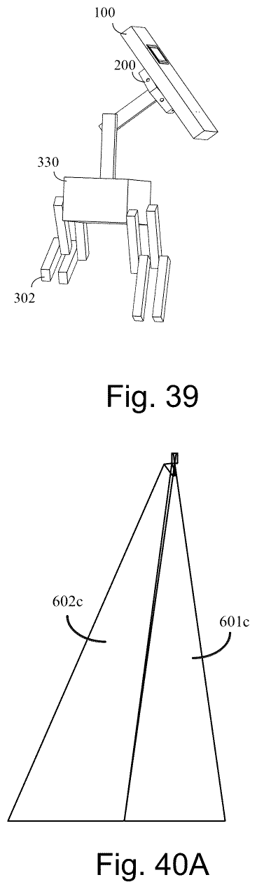

FIG. 39 shows one embodiment, of the pest control system realised as a quadruped robotic platform, having at least one leg (302), which is capable of navigating a wide range of terrains, including uneven, sloped, or debris-laden agricultural environments. This configuration may be particularly advantageous in fields where wheeled or tracked vehicles would experience mobility limitations, such as on soft soil, between densely planted crops, or over irregular ground.

As shown in one example, the targeting system (100) may be mounted on the end effector of an articulated robotic arm that is affixed to the body (330) of the quadruped platform. The robotic arm may comprise multiple degrees of freedom, allowing it to dynamically reposition the targeting system for optimal engagement angles.

Depending on the application, the arm may orient the targeting system to shoot upwards into a canopy, horizontally into mid-height vegetation, or downward toward ground-level pests or water surfaces.

The quadruped base may include onboard power storage (e.g., a battery pack), locomotion control modules, and terrain-adaptive stabilization algorithms. Locomotion may be autonomously controlled by the control and decision system (400), which may coordinate between the targeting arm, mobility system, and power management subsystems.

The system may further include an integrated surrounding monitoring system (200) mounted either on the robot's chassis, on the robotic arm, or directly on the targeting unit. This system may include wide-angle cameras, thermal sensors, or depth sensors capable of scanning the surrounding environment to detect humans, animals, or unexpected objects prior to firing. The surrounding monitoring system may dynamically adjust its scanning field in coordination with the reorientation of the arm and targeting optics.

In some implementations, the robotic arm may also be used to extend the targeting system above obstacles, peer into confined spaces, or even reposition the system during transit to reduce the robot's height profile. The flexible positioning offered by the arm, combined with the terrain versatility of the quadruped robot, enables the pest control system to operate effectively in complex, obstacle-rich agricultural settings such as orchards, greenhouses, stepped plots, or hilly terrain.

### Extend to all Locomotion Devices

While the embodiments illustrated in FIGS. 36 through 39 demonstrate representative use cases of the targeting system (100) and surrounding monitoring system (200) mounted on various platforms-including wheeled carts, floating vehicles, quadruped robots, and articulated anns—these configurations are intended as non-limiting examples. In other embodiments, the targeting and monitoring systems may be mounted on tractors, tractor-mounted booms, spraying anns, autonomous guided vehicles (AGVs), or any other form of mobile or stationary agricultural equipment.

The modular design of the targeting unit allows it to be detachably or integrally affixed to a wide range of locomotion systems, depending on the application environment, target location, and operational requirements.

Integration may occur via mechanical mounting features (e.g., bolt holes, strap slots, standardized camera mount interfaces) or robotic actuators for dynamic positioning. Power and communication connections may be provided via onboard batteries, external vehicle power, or through wired or wireless digital links, such as CAN bus, 5G, or Wi-Fi.

Accordingly, the examples shown and described should not be construed as limiting the scope of the invention, but rather as illustrative of the versatility and adaptability of the system across a broad range of agricultural and environmental platforms.

### Power and Control Integration (Extra Enablement)

In various embodiments, the mobile platform may be powered by an onboard battery system, which may include rechargeable chemical cells or hybrid energy storage modules. The battery may be electrically connected to a motor controller or drive circuit, which regulates the delivery of electrical power to the platform's mobility actuators-such as wheel motors, articulated limbs, propeller motors, or track drives (301). The motor controller may receive commands from the central control and decision system (400), which governs locomotion, navigation, and power allocation based on task requirements and environmental conditions.

The control system may interface with onboard sensors (e.g., GPS, accelerometers, current sensors) to monitor energy usage and adjust drive parameters accordingly. In some embodiments, the system may include an energy management layer, which may prioritize power distribution between the targeting system (100), the surrounding monitoring system (200), and the mobility system (300), depending on the current operational state-such as active targeting, scanning, or repositioning. Optional solar input (e.g., from solar panel 350) may be integrated via a charge controller that conditions incoming current before passing it to the battery or directly to load circuits.

In addition to local decision-making, the control and decision system (400) may be configured for digital communication with a remote server, which may be hosted in a cloud environment, base station, or local edge device. Communication may occur via wireless protocols such as 5G, Wi-Fi, LoRa, or proprietary radio links, depending on the deployment context. This connection may be used to retrieve updated mission data, transmit event logs, receive software or targeting updates, or participate in coordinated swarm operations across multiple mobile units. The remote server may also provide updated geolocation targets, historical pest density maps, or path optimization algorithms, enabling more efficient and adaptive mission planning.

The means for locomotion in a wheel-based or continuous track vehicle may comprise a set of wheels, typically two, four, or more, each driven by one or more electric motors. These motors can provide precise rotational force to the wheels, allowing the vehicle to achieve and preferably maintain controlled movement across a supporting surface. By independently or collectively adjusting the speed and direction of rotation of these wheels, the vehicle may perform various maneuvers, such as moving forward, reversing, or turning.

Maneuverability can be achieved through different steering mechanisms. For instance, in a differential drive or skid-steer configuration, varying the rotational speed of wheels on opposite sides of the vehicle allows it to turn, even rotate in place. Alternatively, an Ackerman-style steering system might be employed, where specific wheels are pivoted to guide the vehicle's direction. The overall speed is controlled by modulating the power supplied to the drive motors.

To enable smooth, accurate, and autonomous movement, the system may rely on additional sensors, such as wheel encoders (to measure distance and speed), inertial measurement units (IMIUs) with accelerometers and gyroscopes (for orientation and tilt detection), and global positioning systems (GPS) for absolute positioning. This data can be processed by its control unit, which may dynamically adjust wheel motor speeds and steering actuators in real time to preferably maintain stability, follow desired trajectories, and navigate its environment.

By combining this control with advanced navigation algorithms and potentially data from perception sensors like cameras or LiDAR, the wheel-based vehicle may autonomously follow pre-programmed paths, avoid obstacles, and adapt to variations in terrain or operational requirements.

The means for locomotion in a leg-based vehicle may comprise multiple articulated limbs, each with several joints (e.g., hip, knee, ankle analogues) powered by actuators such as servomotors. These actuators allow for precise control over the position and orientation of each segment of each leg, enabling the vehicle to generate forces against the ground to achieve and preferably maintain controlled movement using various gait patterns (e.g., walking, trotting, crawling). By coordinating the complex sequence of leg movements, the vehicle may perform diverse maneuvers, including forward, backward, and lateral motion, as well as turning and potentially adjusting its body height or posture.

The maneuverability of a leg-based vehicle is intrinsically linked to its ability to adapt its gait and foot placement. Varying the timing, stroke length, and placement of each foot allows the vehicle to change direction, navigate complex or uneven terrain, and step over or onto obstacles. This provides a high degree of mobility in environments that might be inaccessible to wheeled or tracked platforms.

To enable stable and agile movement, particularly in autonomous operation, the system relies heavily on a suite of sensors. These include joint encoders for precise feedback on leg positions, IMUs for dynamic balance and body orientation control, force or contact sensors in the feet to detect ground interaction and terrain properties, and perception sensors like cameras or 3D LiDAR for environmental mapping, obstacle detection, and strategic foot placement planning. This rich sensor data is processed by its control unit, which executes sophisticated algorithms for gait generation, dynamic stability control, body attitude adjustment, and footstep planning. By integrating this advanced motion control with navigation systems, the leg-based vehicle may autonomously traverse challenging landscapes, maintain balance on unstable surfaces, and navigate effectively towards its objectives.

The means for locomotion in a floating vehicle designed for operation on a liquid surface, such as water, may comprise one or more propulsion units, such as marine propellers, water jets, or directional thrusters, or air propellors, supported by a buoyant hull or float structure. These propulsion units generate thrust to allow the vehicle to achieve and preferably maintain controlled movement across the water surface. By adjusting the magnitude and, where applicable, the direction of thrust from these units, the vehicle may perform various maneuvers, such as moving forward, reversing, holding station, or turning.

Maneuverability is typically achieved by controlling the propulsion system and potentially dedicated steering elements. For example, rudders can direct the flow of water past the hull or propeller, or differential thrust from multiple, independently controlled propellers/thrusters can be used to induce turning moments, allowing the vehicle to change its heading. Precise control over thruster output enables fine adjustments to speed and position.

To enable reliable and autonomous operation, the system may integrate data from various sensors, including GPS for global positioning, an IMU for orientation (pitch, roll, yaw) and heave detection, a compass for accurate heading information, and potentially sonar or depth sounders for assessing water depth and detecting submerged hazards. Perception sensors like cameras may also be used for detecting surface obstacles. This information is processed by its control unit, which may dynamically adjust the propulsion and steering systems in real time to preferably maintain stability (e.g., against wind or currents), follow predetermined paths, and execute navigational tasks. Coupled with appropriate navigation algorithms, the floating vehicle may autonomously navigate waterways, maintain desired positions, and respond to environmental conditions or mission parameters.

In certain embodiments, the imaging sensors used within the targeting system (100) or the surrounding monitoring system (200) may be equipped with additional optical lenses, such as commercially available C-mount lenses, to achieve specific focal lengths or angular fields of view based on the application environment.

These lenses may be mechanically coupled to the sensor via standard threaded mounts, such as C-mount or CS-mount interfaces, which are commonly used in industrial and scientific imaging systems. For example, a C-mount lens with a 12 mm focal length may be installed on a high-resolution CMOS or CCD sensor to obtain a narrower field of view suitable for long-range observation, target verification, or optical alignment.

Alternatively, shorter focal lengths may be used for wide-angle scanning, stereo depth perception, or exclusion zone monitoring.

The modular nature of these mounts enables quick interchangeability and customization, allowing the system to be adapted to different environmental conditions, target sizes, or deployment scenarios. In some configurations, lenses may also include built-in iris control or manual/automatic focusing mechanisms, offering additional optical control beyond what is available in the downstream beam path.

These additional lenses may be used on: The optically aligned camera (102), to fine-tune precision targeting or center the laser beam within a narrow visual frame.

The non-optically aligned camera(s) (103), for scanning, detection, or depth estimation (e.g., in stereo configurations).

Cameras within the surrounding monitoring system (200), to adjust the size of the safety perimeter or adapt to wide-area surveillance requirements.

The use of these supplemental lenses may enhance overall optical flexibility without requiring modification to the core beam path or internal optical train, preserving system modularity and enabling rapid field configuration.

In some embodiments, the unmanned aerial vehicle (UAV) may comprise a balloon-assisted lift module configured to provide a partial or substantial offset to the gravitational weight of the aerial platform. The balloon may be filled with a buoyant gas, such as helium or hydrogen, or contain a heated air cavity, and may be tethered or rigidly connected to the UAV body. The balloon may be fabricated from lightweight, UV-resistant materials (e.g., Mylar, nylon composite) and may include a shape-stabilizing framework or pressurized structure to maintain aerodynamic performance.

By providing a passive lift contribution, the balloon module may reduce the mechanical loading on motor assemblies and thereby extend bearing life, reduce power consumption, and minimize thermal degradation of components. In some configurations, the balloon may offset between 10% and 90% of the total mass of the UAV, and may be optionally retractable, inflatable, or collapsible for transport or adverse weather conditions.

In further embodiments, the propulsion system may include large-diameter, low KV motors (e.g., below 500 KV) coupled to oversized propellers (e.g., 12-40 inches in diameter), configured to operate at lower rotational speeds. This configuration may generate the necessary thrust at reduced RPMs, thereby decreasing the angular velocity of the rotor assembly and reducing both frictional and vibrational wear on the bearings and motor housing. Lower RPM operation may also improve acoustic stealth, mechanical longevity, and energy efficiency, particularly in sustained loitering or surveillance modes.

In still further embodiments, the UAV may employ inrunner-type brushless motors with enclosed or sealed housings. These motors may include ceramic or sealed stainless-steel bearings and may be lubricated with a lifetime lubricant such as PFPE grease to eliminate maintenance cycles. Inrunner motors may be coupled with gear reduction mechanisms to enable torque multiplication while maintaining low bearing load and enabling the use of large-diameter propellers within compact structural envelopes.

The combination of balloon-assisted lift, low-KV large-propeller drive systems, and sealed inrunner motors may synergistically reduce the mechanical stress and operational wear of the UAV propulsion subsystem, enabling longer deployment intervals, reduced downtime, and improved field reliability in applications including but not limited to autonomous surveillance, agricultural monitoring, and pest control.

In some deployments, mobile insect control systems may comprise more than one type of optical subsystem. For example, a first optical unit may be optimized for scouting and locating insects over large areas at high speed, while a second optical unit may be optimized for high-precision insect neutralization, such as via laser-based photonic targeting.

To enable scalable and efficient field coverage, these functions may be distributed across separate mobile platforms, or implemented in stages by the same platform performing multiple passes. In a representative configuration, a lightweight, fast-moving scouting drone equipped with a wide field-of-view optical module may first map insect locations across the field, followed by a more precise neutralization system, which may revisit the coordinates for targeted elimination.

To support this approach, the present invention provides a Lateral Field-of-View Extension Module, designed as a modular, standalone optical enhancement that improves the performance of vision sensors-especially event-based vision sensors (DVS)—by significantly increasing their angular coverage without increasing the number of cameras or introducing moving parts. The module allows a downward-facing sensor to simultaneously observe lateral angular views, thereby increasing coverage without the need for mechanical articulation.

In some embodiments, the system comprises one or more event-based vision sensors, also known as dynamic vision sensors (DVS). These sensors detect pixel-level luminance changes asynchronously, outputting data only when motion or contrast is present in the scene. This architecture allows for microsecond-scale latency, high temporal resolution, and motion-blur-free imaging, even during high-speed movement or mechanical vibration.

Such sensors are particularly advantageous in mobile scouting platforms that must detect fast-moving or small targets, such as the Colorado potato beetle (Leptinotarsa decemlineata). The beetle's striped dorsal pattern generates high temporal contrast, allowing detection at distances of approximately 2 meters, even under variable lighting conditions.

To expand angular coverage without additional sensors, the Lateral Field-of-View Extension Module redirects light from lateral angles into a nadir-facing imaging system, thereby enabling a compound field of view. In an example embodiment, the optical path is split into a nadir path directed vertically downward, a left lateral path (202), and a right lateral path (203). Each lateral path may include a pair of reflective surfaces. The left path (202) comprises a first mirror (202a) and a second mirror (202b), redirecting light from the left extended field of view (202c) into the shared optical axis. The right path (203) includes mirrors 203a and 203b, redirecting light from the right extended field of view (203c).

This folded geometry forms a passive, compact, and lightweight optical relay that enables high-speed mobile platforms to scan broader areas using a single camera and lens assembly.

The imaging sensor may be functionally segmented into regions corresponding to different angular input channels. A central region receives light directly from the nadir, while the front and rear regions receive light redirected from lateral angles via the mirror system. These regions are imaged through a shared lens, which focuses both direct and angularly redirected light onto a common focal plane. The lens-mirror-sensor configuration allows the system to observe multiple angular slices of the environment simultaneously, maintain a static physical orientation, and operate effectively as a line-scanning imager when the platform moves forward.

By integrating the Lateral Field-of-View Extension Module with an event-based sensor system, the invention enables expanded lateral coverage in a single overpass, higher scouting speeds with preserved accuracy, reduced energy consumption and wear compared to gimballed or multi-camera systems, and low-latency response times suitable for dynamic environments. In embodiments that include active neutralization modules, the enhanced scouting capabilities allow for early detection and staggered engagement, such that neutralization platforms can act only on confirmed, pre-identified targets, reducing system complexity and energy cost.

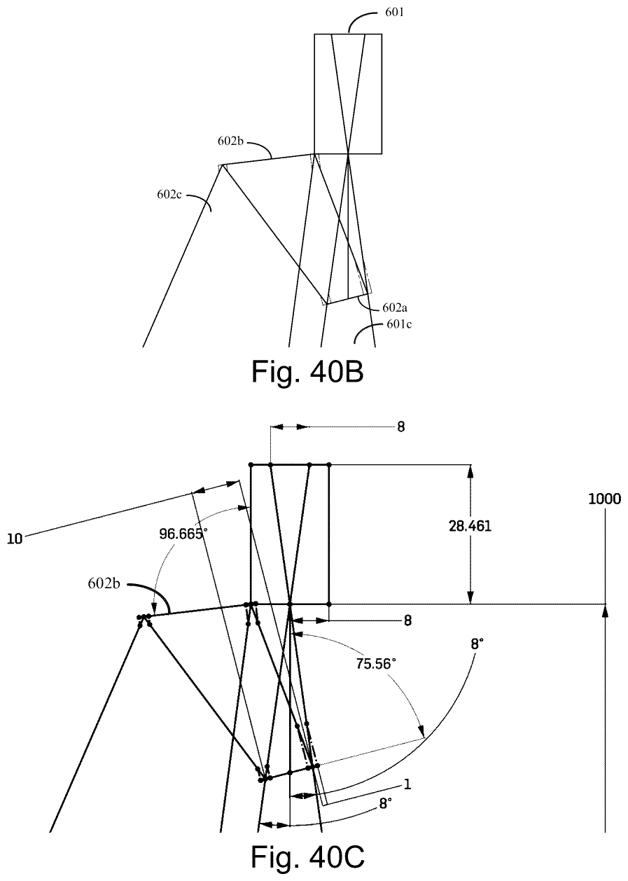

FIG. 40A shows a schematic representation of the optical fields of view, with the left extended field of view (602c) positioned to the left of the nadir field of view (601c).

FIG. 40B illustrates an event sensor (601) capturing light from both the nadir field of view (601c) and the left lateral field of view (602c). For simplicity, the right field of view (603c) is not shown, as it is symmetric to the left side. The figure further shows the placement of a first reflective surface (202a) and a second reflective surface (202b), which together fold the optical path of the left field of view (602c) into the nadir-facing sensor.

FIG. 40C shows an example of the angular relationships and spacing requirements for a given working distance and camera focal length (1000 mm and 28.461 mm, respectively). These parameters were derived using a parametric constraint-solving tool, which is recommended and may be adapted for other operational configurations.

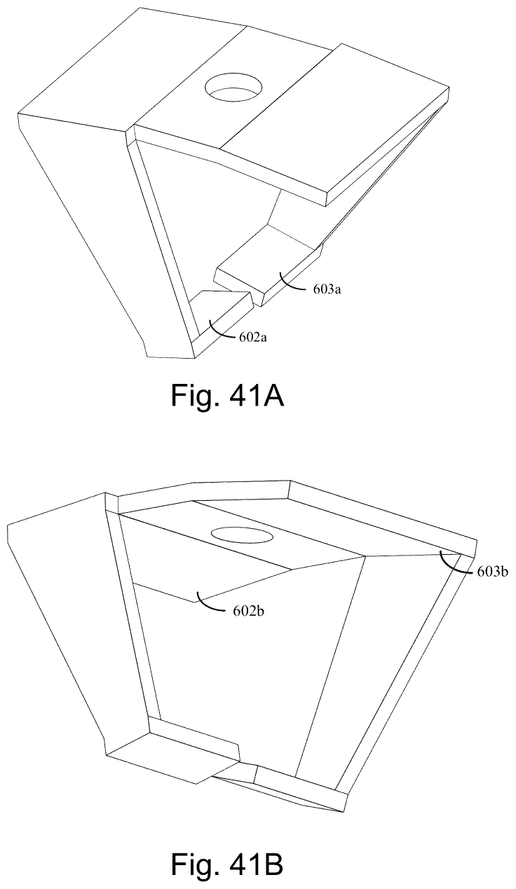

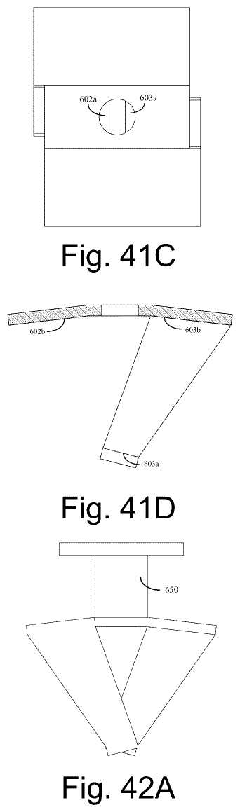

FIG. 41A shows a top perspective view of a 3D CAD model of the Lateral Field-of-View Extension Module, wherein reflective surfaces 602a and 603a are positioned within the downward field of view of the camera.

These surfaces reflect lateral scene content upward, which is then reflected downward by corresponding second surfaces 602b and 603b, thereby folding the lateral fields into the nadir optical axis.

FIG. 41B shows a bottom perspective view of a 3D CAD model of the Lateral Field-of-View Extension Module, illustrating upper mirrors 602b and 603b, which receive lateral light and reflect it downward into lower mirrors 602a and 603a. These lower mirrors then reflect the light upward into the nadir-facing optical axis of the camera, as seen in FIG. 41A. Both views include a central circular aperture for mounting the camera.

FIG. 41C shows a top view of the Lateral Field-of-View Extension Module, highlighting the orientation of reflective surfaces 602a and 603a within the camera's nadir-facing field of view. The figure illustrates how this nadir-facing field is effectively partitioned into three regions on the image sensor: a central region corresponding to the direct nadir path, a front region onto which light from the right lateral field of view is redirected via surface 603a, and a rear region onto which light from the left lateral field of view is redirected via surface 602a.

When the module is mounted on a moving platform, the surface identified as 603a corresponds to the forward-facing direction (i.e., the top of the figure is aligned with the platform's direction of motion). It should be understood that the association between lateral field of view and sensor region (front or rear) may vary depending on the mirror arrangement, and the illustrated configuration represents only one possible embodiment.

FIG. 41D shows a cross-sectional view of the same module, with particular focus on the right lateral field of view (603) and the sequence of reflections involved in folding that field of view.

FIG. 42A shows a camera with lens (650) mounted on and viewing through the circular aperture of the Lateral Field-of-View Extension Module.

FIG. 42B shows the same configuration as in FIG. 16A, with the camera and lens assembly (650) mounted through the circular aperture of the Lateral Field-of-View Extension Module, now additionally mounted on an unmanned aerial vehicle (370).

By leveraging event-based imaging and folded field-of-view tiling, the system achieves:
High-speed scouting without motion blur,
Extended lateral coverage in a single pass,
Reduced energy consumption and mechanical wear per hectare scouted, and
Improved detection accuracy for fast-moving or small targets, even under dynamic conditions.

In embodiments that include active insect neutralization (e.g., via photonic methods), the low-latency response of the event camera further enables precise targeting with minimal stabilization requirements, reducing the burden on mechanical or gimbal systems.

An embodiment of the invention may include several physical configurations that provide distinct advantages. The following descriptions detail possible configurations, the physical effects they produce, the mechanisms by which these effects are realized, and the associated advantages.

The Lateral Field-of-View Extension Module for Enhanced Scouting Coverage is a passive optical assembly comprising four reflective surfaces arranged in two symmetrical pairs—602b/602a folding the left lateral side extension and 603b/603a folding the right lateral side extension—mounted in front of a nadir-facing camera. Each lateral optical path begins with an upper mirror (602b or 603b) that captures light from the corresponding lateral scene and reflects it downward to a lower mirror (602a or 603a), which in turn reflects the light upward into the camera's nadir-facing optical axis. A central circular aperture allows the camera to be mounted or optically coupled. This configuration extends the effective angular field of view of a nadir-facing imaging sensor by capturing oblique lateral views and redirecting them into the downward optical axis, thereby forming a compound field of view that includes a central nadir view and two laterally redirected views projected onto distinct regions of a shared image sensor. Each side of the module operates as a folded optical relay, where incoming lateral light first strikes an upper planar mirror mounted at a shallow angle, is redirected downward to a corresponding lower mirror, and then reflected upward into the shared lens system. A single lens focuses both direct nadir and angular lateral light onto a common focal plane, and the image sensor may be functionally segmented-such as into vertical bands—for capturing nadir, left, and right perspectives. The optical geometry can be optimized for equalized path lengths, consistent focus, and minimal distortion across views. This module triples the angular sensing range using a single fixed-position sensor and lens, enables high-speed insect scouting with minimal motion blur when paired with event-based vision sensors, and requires no moving parts, power, or active control-making it ideal for lightweight, low-maintenance UAVs. It reduces the number of required flight passes and operational time, increasing scouting throughput per hectare, and supports a two-stage operational workflow wherein insects are located during an initial scouting pass and neutralized in a subsequent engagement pass, thereby improving both scalability and energy efficiency. While the described configuration is oriented for downward (nadir) viewing, the same optical principles may be applied to reoriented assemblies designed to capture and redirect lateral or forward-facing views, depending on the intended application.

A fast steering mirror (FSM) or micro-electro-mechanical system (MEMS) mirror may be provided as part of the system's optical path configuration. This component enables precise and rapid angular redirection of a light beam, typically occurring within milliseconds, due to the low inertia of the small mirror element. High-speed actuation is achieved through control mechanisms such as electrostatic, electromagnetic, or piezoelectric systems. The use of an FSM or MEMS mirror permits accurate targeting of small, fast-moving, or erratically behaving targets-such as flying insects—from either mobile or stationary platforms. Additionally, it allows for precise tracking of targets situated on dynamic surfaces, for example, leaves influenced by wind or movement of the platform. This capability facilitates operation at higher platform speeds and increases tolerance to mechanical vibrations, thereby potentially reducing the operational cost per unit area, such as per hectare in agricultural applications.

The Aligned Thermal Sensor for Safety-Based Beam Inhibition comprises a thermal sensor aligned to monitor the optical path directed by the beam steering mirror. This configuration provides real-time detection of warm-blooded entities-such as humans or animals-within or near the laser beam's potential path, enabling automatic inhibition of laser activation to prevent unintended exposure. The sensor operates using infrared-sensitive elements capable of identifying temperature profiles that exceed typical biological thresholds.

A specific implementation, referred to as an “optical hack,” involves positioning a fisheye thermal sensor to observe the beam steering mirror, thereby detecting reflected thermal radiation along the intended laser path.

This indirect approach is used due to the inherent limitations of conventional dichroic mirrors, which are typically not designed to co-align thermal imaging wavelengths with the laser beam path. By leveraging this method, the system significantly enhances operational safety by preventing accidental laser irradiation of non-target entities. Although the reflective detection method may occasionally generate false positives by detecting off-axis heat sources, this is considered an acceptable trade-off in favor of improved safety assurance.

The Optically-Aligned Camera via Dichroic Optics for Synchronized Visual and Laser Targeting comprises an optically-aligned camera sharing a common optical path with a laser source through the use of dichroic optics-such as dichroic mirrors or beam-splitting elements. This configuration achieves synchronized alignment between the camera's visual feed and the laser beam's trajectory, ensuring that the laser is directed precisely to the center of the visually identified target. Dichroic optical elements are engineered to selectively reflect specific wavelengths (e.g., the laser wavelength) while transmitting others (e.g., visible light), allowing both the laser and the camera to share a co-steered optical axis typically managed by a common beam steering mechanism. This arrangement ensures highly accurate laser delivery to intended targets and can simplify the overall targeting architecture by reducing or eliminating the need for complex depth-sensing hardware. Since the system may rely primarily on two-dimensional image-based targeting through the co-aligned visual feed, this simplification leads to increased system reliability, reduced weight and cost, and improved safety through a lowered chance of missing a target.

The Dichroic Mirrors and Beam Splitters for Multi-Path Optical Alignment involve a system of dichroic mirrors and/or beam splitters tuned to operate on specific wavelength bands to enable selective reflection and transmission of different light wavelengths within a shared optical assembly. The surfaces of these optical elements are treated with specialized coatings that interact predictably with designated spectral ranges—for example, reflecting 1550 nm laser light, transmitting visible light for imaging, and reflecting near-infrared (NIR) light for depth sensing. This configuration permits the co-alignment of multiple optical paths, such as those of a laser emitter, an imaging camera, a depth sensor, and an illumination source, all directed by a common beam steering mechanism. As a result, the system facilitates a compact and integrated optical architecture in which multiple emitters and sensors share a common pointing direction. Auxiliary functions like depth sensing and illumination remain precisely co-axial with the primary laser and imaging paths, enabling accurate, co-registered feedback and illumination. Additionally, co-axial illumination directs light onto the target in a way that reflects back through the beam steering mirror into the optically aligned camera, allowing the camera to operate with a narrower aperture and thereby increasing its depth of field for improved imaging performance.

The Dichroic Cube for Compact Multi-Path Optical Integration is a compact optical component configured to achieve coaxial alignment of multiple optical paths-such as those for a laser emitter, an imaging system, and optionally an illumination source or depth sensor-within a single unified structure. The dichroic cube contains internal surfaces coated to selectively reflect or transmit light based on specific wavelength bands, allowing it to combine or separate optical paths depending on their spectral properties. This configuration enables the integration of laser emission, imaging, illumination, and depth sensing channels into a common optical axis, resulting in a significant reduction in the physical footprint and complexity of the optical assembly compared to systems employing multiple discrete mirrors. The dichroic cube simplifies optical alignment procedures and is particularly advantageous in space-constrained environments, where it contributes to the development of more compact, lightweight, and robust optical units.

The Laser Beam Expansion system may utilize either a Galilean or Keplerian optical configuration to increase the diameter of the laser beam before it reaches the final focusing element. In a Galilean configuration, a negative (concave) lens initially diverges the beam, which is then collimated or further expanded by a subsequent positive (convex) lens. In a Keplerian configuration, two positive lenses are employed to achieve the expansion, with the expansion factor determined by the ratio of their focal lengths. This optical arrangement increases the beam diameter entering the final focusing lens, which in turn allows for a smaller beam waist at the focal point-resulting in enhanced targeting precision and higher energy concentration on the target.

Importantly, the wider beam aperture also results in a greater angular divergence after the focal point, causing the energy density to drop off rapidly beyond the focus. This characteristic improves operational safety by reducing the Nominal Ocular Hazard Distance (NOHD). By concentrating energy more precisely at the intended target and enabling a sharper fall-off in energy before and after the focus, the beam expansion system contributes to both precision and safety in laser-based targeting applications.

The Converging-Diverging Laser Beam Geometry for Enhanced Safety involves shaping the laser beam path using a focusing lens directed by a beam steering mechanism and, optionally, pre-conditioned by additional optical elements such as a concave lens when beam expansion is implemented. This configuration causes the laser beam to converge to a sharply defined focal point at a specific target distance and to diverge rapidly beyond that point. The focusing lens is selected or adjusted to bring the laser light to a tight focus at the desired working range, and after passing through this focal point, the beam naturally expands due to diffraction, resulting in an increasing cross-sectional area and a corresponding rapid decrease in irradiance with distance.

This geometry enhances operational safety by significantly reducing the Nominal Ocular Hazard Distance (NOHD), as the energy density falls off quickly beyond the focal point. It also serves as a passive safety mechanism: in the event the laser is inadvertently directed at a reflective or unintended surface beyond the intended focal range, the rapidly diverging beam is more likely to have an irradiance level below permissible exposure limits for the human eye, thereby reducing the risk of accidental injury.

The Tunable or Movable Focusing Lens/Metasurface for Dynamic Focal Adjustment involves the integration of a tunable focusing lens-such as a liquid lens with adjustable curvature or refractive index—or an adaptive metasurface into the laser's optical path. This component provides real-time, variable adjustment of the laser beam's focal distance. The focal length is modified either through electro-optical control, for example by applying a voltage to change the curvature of a liquid lens or the refractive index of a responsive material, or through mechanical means such as shifting the position or configuration of the lens or metasurface. Prior to laser emission, the system dynamically adjusts the focal properties of this element to match the estimated distance to the target, ensuring that the beam converges precisely at the desired location. This dynamic focusing capability allows for optimal energy delivery to the target, potentially reducing the total laser power required to achieve the intended effect, such as neutralizing a pest. Additionally, precise beam convergence enhances operational safety by minimizing the nominal hazard zone and enabling the use of lower laser power levels while maintaining targeting effectiveness.

The Depth Sensor Integrated with Focal Control for Distance-Adaptive Focusing comprises a depth sensor operatively connected to a tunable focusing lens or adaptive metasurface, both of which are managed by the control and decision system and typically integrated within the targeting system. The depth sensor may share the optical path with other components via a dichroic mirror for compact optical co-registration. This configuration enables dynamic adjustment of the laser's focal point based on real-time measurements of the target's distance from the system. The depth sensor-such as a time-of-flight sensor or stereo vision system-measures the range to the target, and this data is processed by the control unit, which in turn adjusts the tunable focusing lens to modify its curvature, refractive index, or other optical properties to focus the laser beam precisely at the detected distance. This distance-adaptive focusing ensures accurate and effective energy delivery to targets at varying ranges or on uneven terrain, without requiring physical repositioning of the entire optical assembly. It also allows the mobile platform-such as a drone or ground vehicle—to maintain a more stable altitude or operational plane while scanning, reducing the need for constant height adjustments and thereby lowering energy consumption and improving coverage efficiency across a given area.

The Non-Optically Aligned Stereo Cameras for Wide-Angle Detection and Depth Estimation consist of a pair of spatially separated cameras arranged to form a stereo vision system, typically positioned with a known baseline distance between them. This configuration enables wide-angle visual detection of potential targets while providing real-time estimation of their three-dimensional position and depth relative to the system. The two cameras capture images of the same scene from slightly offset perspectives, and stereo triangulation algorithms are applied to the image pair to compute the distance and 3D coordinates of objects within their overlapping field of view-without requiring mechanical scanning or repositioning. This setup allows efficient identification and localization of candidate targets across a broad area. Once a potential target is identified using this wide-angle stereo system, a beam steering mechanism can redirect a higher-resolution, optically aligned camera toward the detected location for confirmation and precise aiming. This two-stage approach-wide-angle detection followed by narrow-field verification and targeting-facilitates rapid target acquisition, potentially increasing the system's engagement rate and allowing the mobility platform to operate at higher speeds while maintaining accuracy, thereby improving total area coverage efficiency.

The Use of a 4f Optical System for Component Spacing and Alignment involves an optical configuration comprising two lenses arranged such that the distance between them equals the sum of their focal lengths. In this setup, the object or intermediate image is positioned at the front focal plane of the first lens, while the final image is formed at the back focal plane of the second lens. This configuration relays an image from an object plane to an image plane-optionally with magnification—while providing a region of collimated light between the two lenses, particularly at the Fourier plane, which enables increased physical separation along the optical axis. In the described system, this spacing permits greater physical distance between the optically aligned camera and the movable beam steering mirror. The first lens collimates incoming light from the object or intermediate image, and the second lens refocuses this collimated light to form the output image. The accessible collimated-light region between the lenses allows for the insertion of additional optical elements, such as dichroic mirrors or beam splitters. This expanded layout enables more flexible beam path management and improves the ability to align the camera's field of view with the angular operational range of the beam steering mirror. As a result, the system can optimize use of the image sensor, maintain consistent image quality across steering angles, and support the integration of complex optical functions within a compact, modular framework.

The Elimination of a 4f Optical System in Space-Limited Configurations, such as those incorporating a dichroic cube, involves an optical design that omits the use of traditional relay lens systems-such as those based on a 4f layout with two spaced lenses—in favor of more integrated components. In this configuration, functions such as beam alignment, path combination, or optical splitting are accomplished primarily through the internal geometry and wavelength-selective coatings of the integrated optical component itself, such as a dichroic cube, rather than through a sequential arrangement of discrete lenses and mirrors. This approach results in a more compact optical assembly with a reduced number of elements. By eliminating the 4f system, the overall footprint of the optical housing is decreased, and fewer optical surfaces are introduced, which in turn reduces optical losses from reflection, scattering, or absorption. The simplified assembly contributes to lower system weight, increased robustness, and easier manufacturability-advantages that are particularly valuable in applications subject to strict constraints on size, weight, and complexity, such as airborne or embedded optical units.

The Modular and Compact Housing with Universal Mounts comprises a protective enclosure designed to accommodate components such as the targeting system while incorporating standardized mounting interfaces for broad mechanical compatibility. The housing includes features such as strap slots, bolt holes, and camera mount bores, which are configured to conform to known mechanical dimensions and industry-standard mounting formats. Strap slots enable flexible attachment using tension-based mounting methods, bolt holes provide rigid fastening to fixed structures, and camera mount bores allow direct interfacing with standardized camera mounts.

This configuration facilitates rapid deployment and integration of the enclosed system across a wide range of platforms, including aerial drones, ground-based mobile carts, and legged robots. The modularity of the housing allows the targeting system to be offered either as a standalone, plug-in component for end-user integration or as a fully integrated subsystem within a complete mobility platform. By eliminating the need for custom mechanical interfaces, this design reduces integration time, minimizes installation cost, and enhances the overall scalability and adaptability of the system for diverse operational contexts.

The mounting of the targeting system on various mobile platforms is enabled by a compact, self-contained optical unit enclosed within a modular housing, which incorporates universal mounting features such as a mounting hole, strap slots, and a camera mount bore. These standardized mechanical interfaces allow the targeting system to be securely and flexibly integrated across a wide range of mobile platforms operating in land, aerial, and aquatic environments. The design supports direct mounting onto wheeled carts, agricultural tractors, tractor-mounted booms, legged robots such as quadrupeds-whether on their platform bodies, structural struts (vertical or horizontal), or leg assemblies-floating platforms for aquatic applications, and aerial drones driven by propeller-based thrust. This broad mechanical compatibility significantly reduces development time and cost associated with adapting the system to different operational platforms. It also maximizes the reusability and versatility of a single targeting system design, allowing the same unit to be rapidly deployed or redeployed across diverse terrains and use cases without the need for platform-specific redesign or reengineering. Furthermore, the modular housing facilitates straightforward integration into multifunctional systems-such as spraying drones equipped with a targeting module for selective application, or tractor-mounted spraying booms with embedded targeting capabilities. In addition, the same platform may be configured for integrated scouting functionality, such as locating pest insects in agricultural fields or orchards, enabling real-time inspection and data gathering prior to or in parallel with activation of targeting or spraying operations. This modular approach supports flexible mission planning, enhances system utility, and enables more intelligent, efficient, and context-aware automation in agricultural and environmental applications.

The Modular Optical Unit with Protective Weather Housing comprises a sealed, modular enclosure designed to safeguard internal optical and electronic components during outdoor operation. The housing includes a removable cover for maintenance access and a transparent optical window fabricated from optical-grade material, allowing operational light-such as laser beams or imaging wavelengths—to pass through without compromising environmental protection. This configuration provides robust shielding against dust, moisture, and other contaminants commonly encountered in field conditions. The transparent window maintains the optical clarity necessary for system performance while also offering protection against physical impacts. The overall design enhances the durability and reliability of the optical unit when deployed in outdoor environments such as agricultural fields, contributing to a longer operational lifespan and reduced failure rates. By minimizing the exposure of sensitive components to environmental stressors, the housing also reduces maintenance needs related to cleaning or replacing damaged elements, thereby increasing uptime and lowering operational costs.

The Lens Clamping Mechanism for Repeatable Assembly comprises a standardized mounting system designed to enable easy, precise, and repeatable installation, alignment, or replacement of optical lenses within the device.

The mechanism typically consists of half-shell mounts or equivalent structural elements that securely constrain the lens in a fixed position relative to the rest of the optical assembly. These mounts are engineered to apply minimal mechanical stress to the optical element while maintaining exact alignment with adjacent components in the optical path. This configuration ensures consistent optical performance across manufactured units and preserves alignment integrity during field maintenance or lens replacement procedures. The clamping system also simplifies the manufacturing and assembly process, potentially reducing both production time and cost.

Furthermore, it enhances field serviceability by allowing lenses to be replaced or realigned quickly and accurately without requiring specialized tools or extensive recalibration.

The Integrated Electronics with Signal Routing and Heat Control configuration involves the internal integration of control electronics-including components such as a processing unit and supporting circuitry-within a dedicated electronics enclosure situated inside the main system housing. This integration is paired with structured routing for external power and data cables via standardized connectors. By co-locating key electronic subsystems within a unified housing, the system achieves compact and efficient power distribution, signal integrity, and effective thermal management. Provisions such as heat sinks, thermal interface materials, or airflow channels may be included to dissipate heat generated during operation, thereby enhancing thermal stability and protecting sensitive components. Signal and power pathways are deliberately structured to reduce wiring complexity and minimize electromagnetic interference. External electrical connectivity is facilitated through standardized cables, simplifying integration with external systems. In some embodiments, the electronics architecture may include redundant subsystems employing majority-vote logic, thereby eliminating single points of failure and significantly increasing fault tolerance—an important attribute for autonomous or safety-critical applications. This integration reduces the system's overall size and wiring bulk, improves component longevity, and enhances overall system robustness and reliability.

The Visible or Blue Pre-Activation Flash feature comprises a visible light source or a dedicated blue light emitter, potentially co-located with the primary illumination source, and configured to emit a brief, high-intensity flash immediately prior to the activation of the neutralizing laser. This light source may be optically coupled into the shared optical path of the neutralizing laser and the optically aligned camera using optical elements such as beam splitters and dichroic mirrors, allowing the flash to follow the same projected direction as the laser beam. The sudden emission of bright visible light serves to trigger an involuntary blink reflex in humans or animals that may inadvertently be present within or near the laser's path. This reflex typically occurs within approximately 0.2 seconds and acts as a passive, biologically driven safety mechanism.

By prompting a natural eyelid closure just before laser activation, the system significantly reduces the risk of direct retinal exposure in the event of an unexpected misfire or the sudden presence of a non-target entity. This feature enhances overall system safety by incorporating a non-invasive, physiological layer of eye protection without requiring additional sensing or decision-making infrastructure.

The Eye-Safe Laser Wavelength configuration involves the use of a neutralizing laser operating at a wavelength known for its eye-safe properties, such as approximately 1550 nm. This laser beam may be guided through dichroic optical elements and directed by a beam steering mechanism as part of the targeting system. The use of this specific wavelength significantly reduces the risk of permanent retinal damage in the event of accidental ocular exposure. Laser energy at or near 1550 nm is primarily absorbed by the cornea and lens of the eye rather than being transmitted to and focused on the retina, which dramatically lowers the energy density reaching the retina compared to visible or near-infrared wavelengths that pass through the ocular media. As a result, any accidental exposure is more likely to cause damage to the anterior eye structures, where medical treatment has a comparatively higher chance of preserving or restoring vision. This greatly enhances the overall safety profile of the system, especially in environments where human or animal presence is possible. Moreover, the use of an eye-safe wavelength supports easier regulatory approval and encourages broader deployment of the technology by mitigating safety concerns typically associated with high-power lasers. An additional advantage of operating at this wavelength (e.g., around 1550 nm) is the availability of laser modules with optical conversion efficiencies exceeding 30%, including compact form factors such as TO-9 can packages. This high efficiency, combined with the intermittent nature of laser firing and the relatively low energy required to neutralize a target (e.g., an insect), results in minimal thermal load during operation. As a consequence, active cooling may not be necessary, and passive thermal dissipation is often sufficient. In many embodiments, the laser module can be directly mounted onto a printed circuit board (PCB) without additional heatsinking, simplifying integration and reducing system complexity and cost.

The Surrounding Monitoring System Using Thermal or Wide-Angle Cameras comprises a set of omnidirectional sensors, including one or more thermal sensors and/or wide-angle visual cameras, typically enclosed within a protective housing. This system is designed to provide comprehensive situational awareness-often approaching or achieving 360-degree coverage—of a defined exclusion zone surrounding the operational area of the laser system. The sensor data, which may include thermal signatures and wide-field visual imagery, is continuously acquired and processed either by a dedicated processing unit or by the main control and decision system. Through the use of real-time analytics and data fusion techniques, the system constructs a contextual understanding of the surrounding environment, allowing for the detection and localization of humans, animals, or other non-target entities. When such entities are identified within the monitored zone, the system can automatically inhibit laser activation, thereby enforcing a fail-safe condition and preventing unsafe operation.

This monitoring capability provides a critical layer of safety, particularly in autonomous or remotely operated platforms, where robust situational awareness is essential for safe deployment in dynamic or unpredictable environments.

The Inhibition of Laser Firing Under Unsafe Conditions is implemented through conditional logic embedded within the software and hardware architecture of the control and decision system. This feature acts as a safety override mechanism, actively preventing the activation or firing of the neutralizing laser when predetermined unsafe conditions are detected. The control system continuously analyzes real-time data from a range of onboard sensors, which may include thermal, visual, or depth cameras-such as environmental monitoring cameras-along with inputs from the surrounding monitoring system, GPS modules, motion sensors, or other positional subsystems. If this analysis identifies the presence of a human, mammal, reflective surface, or other defined hazard within a critical exclusion zone, such as the Nominal Safety Zone (NSZ), the system blocks laser activation through software gating. This logic ensures that the laser is only operable under safe conditions, significantly reducing the risk of accidental exposure or injury. By incorporating such dynamic, data-driven safety interlocks, the system enhances overall operational safety, facilitates compliance with laser safety regulations, and reduces potential liability in environments where autonomous or semi-autonomous laser operation is required.

The Nominal Safety Zone (NSZ) Enforcement system defines and actively manages a safety perimeter around the operational path of the laser, with enforcement handled by the exclusion zone monitoring system and the control and decision system. The NSZ represents a dynamically or statically defined region within which laser exposure may exceed established safety thresholds—such as Maximum Permissible Exposure (MPE) limits—and is shaped by the beam's converging-diverging optical profile. This profile is influenced by system components such as the focusing lens and beam steering mechanism, as well as key optical parameters including wavelength, power, beam diameter, focal length, and divergence. The exclusion zone monitoring system continuously scans for the presence of intruding entities-such as humans or animals-within the NSZ boundary. Upon detecting such an intrusion, the control system immediately inhibits laser activation, ensuring safe system behavior. This approach provides a context-aware, adaptive safety mechanism that aligns with the specific characteristics of the laser and operational environment. By clearly defining hazardous zones and actively monitoring them, the system balances operational effectiveness with stringent safety requirements, enabling high-performance laser applications without compromising user or bystander safety.

The Reflective Object Detection to Avoid Misfire feature is implemented through an anomaly detection module, typically software-based, integrated within the system's processing unit. This module analyzes image data acquired from environmental sensors, such as non-optically aligned cameras, to identify and filter out potentially hazardous or inappropriate targets prior to laser engagement. Using machine learning models or other advanced image analysis algorithms, the system processes visual input to detect objects or scene characteristics that deviate from known or expected safe environments. For example, the system may be trained to recognize typical agricultural landscapes and flag anomalies such as reflective debris, discarded containers, shiny tools, or other foreign objects-including those that could produce dangerous specular reflections or do not represent valid targets. Upon detecting such an anomaly, the control logic inhibits laser firing to prevent misfire. This functionality enhances system safety by reducing the risk of harmful laser reflections, improves targeting accuracy by ensuring only valid objects are engaged, and lowers the likelihood of collateral damage to unintended items within the operational field.

The Interchangeable Lenses for Camera Customization feature enables the use of standardized, swappable optical lenses-such as C-mount or other industry-standard formats-on camera modules within the system, including the optically aligned camera and non-optically aligned cameras. This configuration provides adjustable fields of view and variable magnification, allowing the imaging system to be tailored to specific operational requirements. Commercially available lenses can be readily installed without modification to the core camera housing, enabling users or integrators to select lens characteristics such as focal length and aperture that best match the intended application-whether targeting different crop types, insect sizes, or field-of-view constraints. This modularity enhances the adaptability of the system across a wide range of environments and use cases, while avoiding the need for custom optical assemblies. In addition, the ability to leverage off-the-shelf lens components reduces system cost and simplifies logistics, while preserving the ability to optimize imaging performance for specialized detection, tracking, or targeting tasks.

The Balloon-Assisted UAV Lift for Reduced Wear involves the integration of a passive lift module-such as a helium-filled balloon or heated-air aerostat-into the UAV's mobility system. This configuration provides an upward buoyant force that partially or substantially offsets the gravitational load acting on the UAV, thereby reducing the mechanical demand placed on conventional propulsion components such as motors and propellers.

By alleviating a portion of the required lift, the balloon-assisted system decreases the net thrust needed from active propulsion, leading to reduced wear on mechanical components like bearings, lower energy consumption during sustained flight, and potentially quieter operation due to reduced motor speeds. This passive lift augmentation can extend the operational lifespan of propulsion hardware, minimize maintenance frequency, and reduce the cost of operation per unit area-such as per hectare in agricultural deployments. Furthermore, the system can benefit from existing commercially available balloon or aerostat technologies capable of supporting varying payload capacities, making it a practical and scalable enhancement for UAV platforms tasked with prolonged or energy-sensitive missions.

The Low-RPM, Large Propeller UAV Propulsion configuration involves the use of low-KV (kilovolt per RPM) electric motors coupled with large-diameter propellers as part of the UAV's mobility system. This arrangement enables efficient thrust generation at reduced rotational speeds, leveraging the aerodynamic advantages of larger propellers, which can produce greater lift at lower RPMs compared to smaller counterparts. Low-KV motors are specifically designed to deliver high torque at these lower speeds, allowing them to drive large propellers directly or with minimal gearing. The resulting propulsion system offers multiple benefits, including quieter operation due to reduced propeller tip speeds and lower acoustic emissions, decreased mechanical wear on motor bearings and drivetrain components, and improved flight stability and energy efficiency. These characteristics collectively contribute to a reduction in system maintenance requirements and lower operational costs per unit of area, making this propulsion strategy especially advantageous for sustained UAV operations in noise-sensitive or maintenance-limited environments such as agriculture, surveillance, or environmental monitoring.

The Sealed Inrunner Motors with Lifetime Lubrication configuration employs brushless electric inrunner motors integrated into the UAV's mobility system, designed for long-term, maintenance-free operation. Inrunner motors feature a construction in which the rotating magnets are enclosed within the stationary stator coils, allowing the motor casing to be fully sealed. This sealed design protects internal components from environmental contaminants such as dust, moisture, and agricultural chemicals-factors commonly encountered in outdoor and field-based operations. The use of lifetime lubricants, such as Perfluoropolyether (PFPE) grease, eliminates the need for periodic re-lubrication and further enhances durability. This motor architecture significantly improves system reliability and uptime in harsh conditions, particularly in agricultural or remote deployments. It also reduces total cost of ownership by minimizing maintenance labor, component wear, and replacement frequency.

As a result, sealed inrunner motors with lifetime lubrication contribute to lower operational costs per unit of area, enabling more efficient and uninterrupted UAV-based workflows.

The Autonomous Navigation via GPS and Local Sensors configuration integrates a Global Positioning System (GPS) receiver and a suite of local environmental sensors-such as inertial measurement units (IMUs), altimeters, and obstacle detection sensors-into the control and decision system and the mobility system of the mobile platform. Additional safety-related navigation sensors, including those used for obstacle avoidance, may also be incorporated into the surrounding monitoring system. Together, these components enable self-guided, autonomous navigation to designated target zones or along predefined paths. The onboard processing unit continuously receives and processes GPS location data, motion and orientation data from IMUs, and real-time environmental inputs from other local sensors. Navigation algorithms executed by the control system translate this data into precise actuation commands that guide the platform's movement while dynamically avoiding obstacles. This configuration supports unattended or minimally supervised operation, reducing labor requirements and operational costs. It also improves the accuracy of path following and area coverage when compared to manual operation and enhances overall safety by enabling proactive obstacle detection and avoidance in real time.

The Energy-Harvesting with Integrated Solar Panels configuration involves the onboard integration of photovoltaic solar panels, such as a solar panel mounted on a mobile platform like a ground-based cart. This setup enables partial or full recharging of the platform's onboard batteries by converting ambient sunlight into electrical energy, either during idle periods or, in some cases, concurrently with active operation. Photovoltaic cells embedded in the solar panel convert solar irradiance into direct current (DC), which is then regulated by an integrated charge controller to recharge the battery system or supplement power to onboard electronics. This energy-harvesting capability can significantly extend operational endurance and deployment cycles, reducing the need for manual battery swapping or recharging. It also lowers the logistical burden of battery management in field conditions and may support continuous or near-continuous autonomous operation in environments with consistent solar exposure. Additionally, the integration of solar panels contributes to a more sustainable and environmentally friendly power solution for autonomous mobile platforms.

The Autonomous Battery Replacement or Recharging configuration comprises an automated power replenishment system that includes either a battery swapping mechanism or a docking-based recharging station, both coordinated by the control and decision system and associated with the mobile platform. This system enables uninterrupted or minimally interrupted mission continuity by automating the battery management process. When the onboard battery charge drops below a predefined threshold, the mobile platform autonomously navigates to a designated docking location. Upon arrival, the system either initiates an automatic battery swap—where a robotic mechanism replaces the depleted battery with a fully charged one—or connects to power contacts to recharge the existing battery without requiring human intervention. This approach significantly reduces downtime related to manual battery handling, supports long-duration autonomous missions, and enhances operational efficiency and throughput. It is particularly beneficial in use cases where sustained, continuous operation is critical, such as agricultural scouting, pest control, or perimeter monitoring.

The Edge/Cloud-Based Coordination via 5G/Wi-Fi configuration involves the integration of high-bandwidth wireless communication interfaces, such as 5G or Wi-Fi transceivers, operably linked to the onboard processing unit or the broader control and decision system. This setup enables real-time bidirectional data exchange between the mobile platform and external systems, which may include edge-based servers located on-site or cloud-based infrastructure. These wireless links support the transmission and reception of mission-critical information such as control commands, telemetry data, system status updates, scouting results, software patches, and optimized tasking inputs. The platform may also receive dynamically generated target coordinates or navigation paths from external scouting systems or centralized controllers. This connectivity enables advanced operational capabilities, including coordinated swarm behavior among multiple platforms, adaptive task reassignment based on evolving field conditions, and seamless integration with higher-level agricultural or industrial information systems. Additionally, it facilitates remote diagnostics, live monitoring, and over-the-air software updates, thereby improving system maintainability, reducing on-site service needs, and streamlining data offloading for downstream analysis and decision support.

In some embodiments, the targeting system (100) comprises physical and operational features suitable for integration with a mobile platform, such as a ground vehicle, aerial drone, or aquatic platform. The targeting system (100) includes a laser unit (101), a camera system, and a control unit (401). The laser unit (101) may emit a laser beam (398), which may be a converging beam directed toward a focal point at a predetermined distance. The camera may be optically aligned (102) with the laser beam's path or may include a secondary wide-field camera (103) not aligned with the laser path. The system may further include a beam steering mechanism (104), such as a movable mirror, and optionally a dichroic mirror (110) for optical path alignment.

The control unit (401) is operatively coupled to both the laser unit (101) and the camera(s) (102, 103), and may be configured to analyze image data to locate one or more target insects (199), and to activate the laser unit (101) when the beam (398) is expected to intersect with a verified target insect (199).

In some embodiments, the laser unit (101) may be a diode laser, and may operate at a wavelength selected to prevent penetration to the human retina, such as in the 1550 nm range. Safety features may include inhibiting activation of the laser unit (101) when a human is detected within a predefined threshold distance, either by the system's own sensors, by an exclusion zone monitoring system 200, or via a received external signal.

The camera system may include a first, optically aligned camera (102) and a second camera (103) with a wider field of view to enable broader scene evaluation. The laser beam (398) may be aligned with the central axis of the first camera (102) to ensure that objects detected at the focal point are precisely engaged by the laser. The system may include a fast-steering mirror (104), optionally realized as a MEMS device, to steer the laser beam dynamically.

In some implementations, the targeting system (100) may be mounted on a mobile platform (300), which comprises at least one propulsion mechanism, such as a wheel, motorized leg, water propeller, air propeller, or ion thruster. The combined system enables precise and mobile pest neutralization or object interaction.

The invention also encompasses a method for autonomous insect neutralization comprising the steps of: locating an insect based on camera image data; steering a laser beam using a movable mirror (104); verifying that safety conditions are met (e.g., no human detected within a nominal safety zone); activating the laser to neutralize the insect; and continuing along a predetermined or dynamically generated path. In some embodiments, the insect's approximate location may be pre-identified by a flying vehicle equipped with a lateral FOV extension module (see FIGS. 40A-42B), and such data may be used to inform targeting actions.

Additionally, a complete system may comprise a mobile neutralization platform (e.g., aerial vehicle with components 3, 5, 9, 12) and a separate flying scout vehicle that scans the area using a camera system (potentially event-based or including a field-of-view extending device with reflective optics). The scout platform may geolocate insects and transmit data to the neutralization platform, either directly or via an intermediate node. The aerial neutralization platform may further include a replaceable battery (17) housed in a battery housing assembly (FIG. 21), which is removable by a robotic swap device (FIG. 22) comprising a robotic arm and gripping mechanism capable of accessing the housing from above via vertical or articulated motion.

In some embodiments, the targeting system (100) comprises physical and operational features suitable for integration with a mobile platform, such as a ground vehicle, aerial drone, or aquatic platform. The targeting system (100) includes a laser unit (101), a camera system, and a control unit (401). The laser unit (101) may emit a laser beam (398), which may be a converging beam directed toward a focal point at a predetermined distance. The beam may diverge again beyond the focal point. The laser unit (101) may be optically coupled to an internal or external light source, including via free-space optics or optical fibers. The beam may be received at a beam input that directs it to the beam steering mechanism (104).

The beam steering mechanism (104) may include one or more of a MEMS mirror, a fast steering mirror, a galvanometer pair, a gimbal-mounted mirror, an acoustic beam steering system, or other optical beam steering technologies. This mechanism directs the laser beam (398) toward a target, such as an insect (199). A focusing element may be included along the beam path to cause the beam to converge at a specific point and then diverge, increasing safety and reducing unintended damage.

The system further includes a light-receiving device, which may comprise a camera (102) optically aligned with the laser beam path through dichroic optics (110), or one or more additional non-aligned cameras (103) for wide-field scanning. The control unit (401) is operatively coupled to both the laser unit (101) and the camera(s) (102, 103), and is configured to process image data to locate target insects (199) or insect eggs, optionally including anatomical targeting of specific regions such as the insect's head.

The control unit (401) may be further configured to estimate distance to the target and dynamically adjust the focusing element to optimize convergence. Safety functions may include analyzing image data or thermal input from a heat sensor (e.g., part of exclusion zone system 200) to detect non-target entities, such as humans, and inhibit laser activation within a defined exclusion zone. The system may also detect anomalies inconsistent with target characteristics and inhibit firing accordingly.

In some embodiments, the targeting system (100) is mounted within a modular housing suitable for mobile or stationary deployment. The system may be installed on a mobile platform (300), such as one having wheels, tracks, propellers, articulated legs, or cable-guided drives. In integrated configurations, the platform may also carry surrounding monitoring systems to enforce safety zones, and the targeting system may share control logic with platform navigation.

The invention further includes a method for targeting and neutralizing insects or objects. The method comprises receiving a neutralizing beam, acquiring image data through the light-receiving device, processing this data to identify and locate a target, steering the beam using the beam steering mechanism (104), and focusing the beam to a convergence point on the target. This may include directing the beam toward specific anatomical regions, estimating distance to the target, dynamically adjusting focus, and inhibiting firing upon detection of non-target heat signatures or anomalous features.

Additionally, the system may include motion-based optimization where the platform continues moving while firing, such that laser exposure per area is minimized except where concentrated on the target. The control system is configured to direct beam emission dynamically during platform motion.

In another embodiment, the system includes a light-emitting mechanism directed toward a target region and a monitoring system configured to detect human presence. The control system inhibits or modifies light emission based on monitoring feedback, which may come from thermal sensors or vision systems. These configurations may further support mobile implementation with active movement and beam control.

This disclosure supports embodiments where the targeting system is integrated into a larger platform, including robotic battery swapping (see FIGS. 21-22) or coordination with flying scouts. The scouts may identify approximate insect positions using extended field-of-view systems (e.g., lateral mirror modules as in FIGS. 40A-42B), and communicate coordinates directly or indirectly to the mobile laser unit, enhancing autonomous operational efficiency and reducing redundant scanning. The inclusion of thermal sensing, beam safety inhibition, anatomical targeting, and platform motion integration provides a robust and modular approach to automated precision neutralization systems.

The above embodiments in the application can also be described using the following Itemized lists.
In the context of the present application, the term “support structure”—and interchangeable references to a “main body,” “chassis,” “support frame,” or “structural portion”—shall be understood to collectively refer to the part of a vehicle or platform that physically supports and interconnects its functional subsystems, including propulsion, navigation, targeting, and sensing units. The specific form of the support structure may vary by platform type, and includes, by way of non-limiting examples: the fuselage of an airplane, the central hub or arm assembly of a quadcopter, the torso or spine of a legged robot (quadruped), the chassis or boom arm of a tractor or agricultural implement, and the hull or deck of a waterborne vehicle. Despite these structural differences, all such forms function as a mechanical foundation for mounting, aligning, and maintaining the relative positioning of subsystems. Furthermore, the term “support structure” may also be interpreted functionally to refer to any part or combination of parts whose role is to maintain the correct relative positioning between other components in order for the vehicle or system to operate as intended. Accordingly, any reference to a “support structure” in the present disclosure shall be understood to encompass all of the above examples, serving as a unified term for describing the load-bearing or position-maintaining component of any applicable platform, regardless of its specific mobility architecture or operational environment.
Extra note, the device from FIG. 3, or any other laser containing embodiment disclosed in this document, may also be placed at a stationary position to protect a research from an insect type. One example is mounting the device so that its laser is aimed at the area near a bee hive entrance, and also optionally a stereo camera is aimed at that region, a local or remote controller and computation unit may then target for example hornets, or any other insects, that pose a threat to the bees.
Also note, any uav related inventions, or optical invention such as stereo vision and event sensor inventions, can be combined with the photonic insecticide invention disclosed here. Also all AI infrastructure inventions can easily be combined.

The items of the first itemized list can be combined with one or more items of all other itemized lists in this document, features mentioned in other places of this document, as well as with one or more features of the claims.

### First Itemized List:

An autonomously operating unmanned vehicle, comprising:
at least one thrust- or locomotion-producing means, and
a camera for capturing images of an environment, and
a laser unit for emitting a laser beam, and
a control unit with a processor, a memory and one or more communication units which are in data communication with the laser unit and the camera, wherein the control unit is configured to analyze the camera images to detect objects and determine their location parameters, which can be used to direct the laser beam onto targeted objects.

The vehicle according to item 1, wherein the laser unit comprises an actuator for directing the laser beam, or the aerial vehicle further comprises an optical unit with a movable mirror at which the laser beam can be aimed for directing the laser beam.

The vehicle according to any of the preceding items, further comprising a rotary motor assembly configured to steer the laser beam,
wherein the rotary motor assembly comprises:
rotary motor coupled to a mirror, the rotary motor being configured to rotate the mirror in response to an applied signal;
an integrated driver circuit three-dimensionally stacked with at least one component of the rotary motor, wherein the integrated driver circuit comprises at least one of:
   through-silicon vias (TSVs) for vertical electrical connections;
   a silicon interposer for interconnecting stacked dies; and
   wafer-level packaging (WLP); and
wherein at least one component of the galvo motor assembly is fabricated from a lightweight material selected from the group consisting of titanium and aluminium.

The vehicle according to any of the preceding claims, wherein a thermal sensor or thermal camera, optionally equipped with a field-expanding lens, is configured to receive thermal radiation reflected from the movable mirror, wherein the thermal radiation comprises wavelengths greater than 2 micrometers, and wherein the control unit is configured to inhibit activation of the laser unit if the thermal sensor detects a heat-emitting object indicative of a human or animal within the laser beam path.

The vehicle according to any of the preceding items, wherein the rotary motor comprises a piezoelectric motor.

The vehicle according to any of the preceding items, wherein the camera comprises a stereo camera.

The vehicle according to any of the preceding items, suitable for targeted pest control in an agricultural environment, wherein the stereo camera is configured to capture environmental images of the agricultural environment, and the control unit is configured to analyze the camera images to detect pests and determine their location parameters, which can be used to direct the laser beam onto targeted pests.

The vehicle according to any of the preceding items, suitable for military applications, wherein the stereo camera is configured to capture images of the environment, and the control unit is configured to analyze the camera images to detect military targets, such as human eyes, and determine their location parameters, which can be used to direct the laser beam onto military targets.

The vehicle according to any of the preceding items, suitable for burning weeds or leaves, wherein the camera is configured to capture images of the environment, and the control unit is configured to analyze the camera images to detect unwanted vegetation and determine its location parameters, which can be used to direct the laser beam onto the weeds or leaves.

The vehicle according to any of the preceding items, wherein the optical unit comprises a means to converge a laser beam or to focus multiple laser beams to a point in a distance when the laser unit comprises multiple laser sources for emitting multiple laser beams.

The vehicle according to any of the preceding items, wherein the laser has an efficiency higher then 25 percent.

The vehicle according to any of the preceding items, wherein the movable mirror is movable in at least one degree of freedom via an actuator, the actuator being a servo motor, and wherein the optical unit or the laser unit comprises a sensor to monitor the position or positional change of the movable mirror or the laser unit.

The vehicle according to any of the preceding items, wherein the optical unit comprises a galvo steering system with the movable mirror being part of it.

The vehicle according to any of the preceding items, wherein the means to converge a laser beam or to focus multiple laser beams to a point in a distance is designed as follows:
the optical unit comprises a converging lens, or the movable mirror is a concave mirror, or a concave mirror is positioned along the optical path from the laser unit to the movable mirror.

The vehicle according to any of the preceding items, wherein the converging lens has a dynamic focus length.

The vehicle according to any of the preceding items, further comprising a support structure, wherein the optical unit, the laser unit, and the camera are arranged in a common housing, which is attached to the support structure via a gimbal, isolating the optical unit, the laser unit, and the camera from the roll and pitch movements of the support structure.

The vehicle according to any of the preceding items, further comprising a support structure, wherein the gimbal is coupled to the support structure via a flexible structure, such as a wire rope isolator, isolating the optical unit, the laser unit, and the camera from frequency horizontal and vertical vibrations of the support structure.

The vehicle according to any of the preceding items, wherein the gimbal comprises at least two rotational axes with actuators allowing the housing to rotate about at least two axes, so that:
the optical unit can be coarsely oriented with respect to a potential target, and fine adjustments to the alignment are made by the laser unit's actuator or the movable mirror of the optical unit, or
the optical unit can be directed iteratively at specific subregions, scanning and targeting each subregion in succession.

The vehicle according to any of the preceding items, wherein the laser unit comprises at least one laser light source having a dominant wavelength of between 449 nm and 461 nm or between 798 nm and 818 nm or between 1540 nm and 1560 nm, a wavelength that is absorbed by the cornea, lens, ocular fluids, or other anterior structures of the eye such that it does not reach the retina.

The vehicle according to any of the preceding items, wherein the laser unit comprises multiple laser light sources for emitting multiple laser beams, wherein the laser light sources are implemented on an integrated laser chip or array.

The vehicle according to any of the preceding items, wherein the laser unit comprises a light source with a power between 4 W and 6 W or between 0.5 W and 2 W, and the light source is either a pulsed light source or a continuous one.

The vehicle according to any of the preceding items, wherein the laser unit comprises a fiber-coupled laser light source and a collimating lens.

The vehicle according to any of the preceding items, wherein the locomotion means is a thrust-producing means and comprises at least one propeller and The vehicle further comprises at least one wing that generates lift when the vehicle moves forward.

The vehicle according to any of the preceding items, comprising a propeller, wherein the propeller is dynamically rearrangeable and configured to provide mainly vertical thrust or horizontal thrust.

The vehicle according to any of the preceding items, comprising a thrust-producing means comprising two propellers, wherein a first propeller is configured to provide mainly vertical thrust and a second propeller is configured to provide mainly horizontal thrust.

The vehicle according to any of the preceding items, further comprising a replaceable battery, wherein all power-consuming components on the vehicle are coupled to the battery as a power source.

The vehicle according to any of the preceding items, wherein the control unit is configured to analyze the camera images to detect objects and determine their location parameters using artificial intelligence algorithms, such as convolutional neural networks.

The vehicle according to any of the preceding items, wherein the control unit is configured to detect any human within a nominal hazard zone of the laser beam, and the vehicle may comprise an infrared camera to enhance detection.

The vehicle according to any of the preceding items, wherein the nominal hazard zone is defined as a zone with a radius of maximum 5 or 10 meters from the movable mirror, and the control unit is configured to control the laser unit such that it does not target any objects outside of the nominal hazard zone.

The vehicle according to any of the preceding items, wherein the control unit is configured to detect any human being within a nominal hazard zone of the laser beam, and The vehicle may comprise an infrared camera to enhance detection.

The vehicle according to any of the preceding items, wherein the control unit is configured to analyze the camera images for anomaly detection, using artificial intelligence algorithms to identify deviations from expected patterns.

The vehicle according to any of the preceding items, wherein the laser unit is configured to deactivate when water droplets or other reflective surfaces are detected that could unpredictably deflect the laser beam.

The vehicle according to any of the preceding items, wherein the location parameters of targeted objects are stored in a database present in the memory.

The vehicle according to any of the preceding items, further comprising a cooling unit coupled with the laser unit, wherein the cooling unit employs graphene or diamond material to dissipate heat generated by the laser beam away from the laser unit.

The vehicle according to any of the preceding items, comprising thrust-producing means and wherein the heat is transferred to a high-wind region generated by the at least one thrust-producing means.

The vehicle according to any of the preceding items, wherein the cooling unit comprises a liquid reservoir, suitable to contain water or ammonia, allowing the heat to buffer and release in periods of low laser firing, wherein the capacity of the liquid reservoir is less than 300 cm³.

The vehicle according to any of the preceding items, capable of targeting an object and emitting a laser beam at the targeted object while moving through a spatial environment.

The vehicle according to any of the preceding items, being configured for maintenance through the following steps:
Generating a notification indicating that The vehicle requires maintenance;
Replacing a component of The vehicle with a new component.

A drone swarm comprising a plurality of aerial vehicles according to any of the preceding items, wherein each aerial vehicle is in data communication with one another and can communicate with each other.

A system comprising an aerial vehicle according to any of the preceding items, a designated landing area, and a mechanism for separating the replaceable battery from The vehicle, wherein the mechanism is capable of autonomously reaching the majority of locations within the designated landing area and is not fixed to the length of the designated landing area, and is configured to autonomously approach The vehicle after it has landed and separate the battery as part of a battery swap operation.

The system of item 38, wherein the mechanism for separating the replaceable battery from the aerial vehicle is attached to a robot equipped with wheels or legs, suitable for moving on the designated landing area.

The system of item 39, wherein the wheels are mecanum wheels or omni wheels.

The system of item 38, wherein the battery is detachably positioned on top of the aerial vehicle when it is in a landed state.

The system of item 38, wherein the battery includes a magnet or metal component that provides magnetic force to secure the battery during flight and assist in the battery separation step during the battery swap process.

The system of item 38, wherein the mechanism for separating the replaceable battery from the vehicle comprises a battery-swapping component designed to replace the vehicle's battery, wherein the battery-swapping component comprises an arm with an electromagnet, which is vertically movable along a vertically arranged bar via a rail and carriage system.

Use of the aerial vehicle according to any of the preceding items for targeted pest control in an agricultural environment, for military applications or for burning weeds or leaves of unwanted vegetation.

The vehicle according to any of the preceding items
wherein the control unit is further configured:
store data associated with each targeted pest, including location, time of day, weather conditions, and time of year, and
analyze the data to identify patterns and correlations between pest prevalence and environmental factors; and
optimize the vehicle's flight path based on the analyzed data to maximize the number of pests targeted.
The items of the second itemized list can be combined with one or more items of all other itemized lists in this document, features mentioned elsewhere in this document, as well as with one or more features of the claims.

### Second Itemized List:

An autonomously operating unmanned vehicle, comprising:
at least one thrust producing or locomotion means, and
a camera for capturing images of an environment, and
a laser unit for emitting a laser beam, and
an optical unit operatively coupled to both the laser unit and the camera, comprising at least a dichroic mirror, wherein the dichroic mirror is configured to reflect the laser beam and to be transparent to an optical path of the camera, or vice versa,
wherein the laser unit comprises an actuator for directing the laser beam to the dichroic mirror, or the optical unit further comprises a movable mirror at which the laser beam can be aimed for directing the laser beam to the dichroic mirror,
a control unit with a processor, a memory and one or more communication units which are in data communication with the laser unit and the camera, wherein the control unit is configured to analyze the camera images to detect objects and determine their location parameters, which can be used to direct the laser beam onto targeted objects using the laser unit's actuator or the movable mirror.

The vehicle of item 1, suitable for targeted pest control in an agricultural environment, wherein the camera is configured to capture environmental images, and the control unit is configured to analyze the images to detect pests and direct the laser beam onto the pests using the actuator or the movable mirror.

The vehicle according to any of the preceding items, suitable for military applications, wherein the camera is configured to capture images of the environment, and the control unit is configured to analyze the images to detect military targets, such as human eyes, and direct the laser beam onto the targets using the actuator or the movable mirror.

The vehicle according to any of the preceding items, suitable for burning weeds or leaves, wherein the camera is configured to capture images of the environment, and the control unit is configured to analyze the images to detect unwanted vegetation and direct the laser beam onto the vegetation using the actuator or the movable mirror.

The vehicle according to any of the preceding items, wherein the optical unit comprises a means to converge a laser beam or to focus multiple laser beams to a point in a distance when the laser unit comprises multiple laser sources for emitting multiple laser beams.

The vehicle according to any of the preceding items,
wherein the actuator is a servo motor, and the laser unit comprises a sensor to monitor the position or positional change of the laser unit's actuator or,
wherein the movable mirror is movable in at least one degree of freedom via an actuator, the actuator being a servo motor, and wherein the optical unit comprises a sensor to monitor the position or positional change of the movable mirror.

The vehicle according to any of the preceding items,
wherein the degree of freedom is the pitch or the roll of the movable mirror.

The vehicle according to any of the preceding items,
wherein the actuator is coupled to the movable mirror by a pulling cable.

The vehicle according to any of the preceding items,
wherein the moveable mirror is coupled to a spring, rubber, or flexible structure, wherein the spring, rubber, or flexible structure is configured to apply a constant rotational force to the movable mirror, the rotational force being selected from the group consisting of pitch rotational force and roll rotational force relative to the movable mirror.

The vehicle according to any of the preceding items,
wherein the movable mirror is actuated by a second servo motor for adjustment along at least a further degree of freedom, the further degree of freedom being selected from the group consisting of pitch and roll of the movable mirror.

The vehicle according to any of the preceding items,
wherein the means to converge a laser beam or to focus multiple laser beams to a point in a distance is designed as follows:
   the optical unit comprises a converging lens, or
   the movable mirror is a concave mirror, or
   a concave mirror is positioned along the optical path from the laser unit to the movable mirror.

The vehicle according to any of the preceding items,
wherein the converging lens has a dynamic focus length.

The vehicle according to any of the preceding items, further comprising an event camera, a stereo camera or an infrared camera in data communication with the control unit to further analyze the environment.

The vehicle according to any of the preceding items, further comprising a support structure, wherein the optical unit, the laser unit, and the camera are arranged in a common housing, which is attached to the support structure via a gimbal, isolating the optical unit, the laser unit, and the camera from the roll and pitch movements of the support structure.

The vehicle according to any of the preceding items, further comprising a support structure, wherein the gimbal is coupled to the support structure via a flexible structure, such as a wire rope isolator, isolating the optical unit, the laser unit, and the camera from frequency horizontal and vertical vibrations of the support structure.

The vehicle according to any of the preceding items, wherein the gimbal comprises at least two rotational axes with actuators allowing the housing to rotate about at least two axes, such that:
the optical unit can be coarsely oriented with respect to a potential target, and fine adjustments to the alignment are made by the laser unit's actuator or the movable mirror of the optical unit, or the optical unit can be directed iteratively at specific subregions, scanning and targeting each subregion in succession.

The vehicle according to any of the preceding items, wherein the laser unit comprises at least one laser light source having a dominant wavelength of between 449 nm and 461 nm or between 798 nm and 818 nm.

The vehicle according to any of the preceding items, wherein the laser unit comprises multiple laser light sources for emitting multiple laser beams, wherein the laser light sources are implemented on an integrated laser chip or array.

The vehicle according to any of the preceding items, wherein a single laser driver circuit is configured to drive the multiple laser light sources.

The vehicle according to any of the preceding items, wherein the laser unit comprises a light source with a power of 5.5 W, and the light source is either a pulsed light source or a continuous one.

The vehicle according to any of the preceding items, wherein the laser unit comprises a fiber-coupled laser light source and a collimating lens.

The vehicle according to any of the preceding items, wherein the laser unit comprises a laser driver circuit utilizing at least one transistor selected from the group consisting of a Silicon Carbide (SiC) MOSFET and a Gallium Nitride (GaN) FET.

The vehicle according to any of the preceding items,
wherein the laser unit is thermally coupled to a vapor chamber comprising a wick structure formed from a material selected from the group consisting of sintered copper powder, and a composite wick comprising at least one layer of sintered copper powder,
wherein the vapor chamber is configured to spread the heat generated by the laser unit over a larger surface area to enhance heat dissipation.

The vehicle according to any of the preceding items, wherein the locomotion means is a thrust-producing means comprising at least one propeller and the vehicle further comprises at least one wing that generates lift when the vehicle moves forward.

The vehicle according to any of the preceding items, wherein the propeller is dynamically rearrangeable and configured to provide mainly vertical thrust or horizontal thrust.

The vehicle according to any of the preceding items, wherein the thrust-producing means comprises two propellers, wherein a first propeller is configured to provide mainly vertical thrust and a second propeller is configured to provide mainly horizontal thrust.

The vehicle according to any of the preceding items, further comprising a replaceable battery, wherein all power-consuming components on the vehicle are coupled to the battery as a power source.

The vehicle according to any of the preceding items, wherein the control unit is configured to analyze the camera images to detect objects and determine their location parameters using artificial intelligence algorithms, such as convolutional neural networks.

The vehicle according to any of the preceding items, wherein the control unit is configured to detect any human within a nominal hazard zone of the laser beam, and The vehicle may comprise an infrared camera to enhance detection.

The vehicle according to any of the preceding items, wherein the nominal hazard zone is defined as a zone with a radius of 40 meters from the movable mirror or an optical unit's output, and the control unit is configured to control the laser unit or the optical unit such that it does not target any objects outside of the nominal hazard zone.

The vehicle according to any of the preceding items, wherein if a human is detected within the nominal hazard zone of the laser beam, the control unit is configured to cease neutralizing potential targets upon detection.

The vehicle according to any of the preceding items, wherein the control unit is configured to analyze the camera images for anomaly detection, using artificial intelligence algorithms to identify deviations from expected patterns.

The vehicle according to any of the preceding items, wherein the laser unit is configured to deactivate when water droplets or other reflective surfaces are detected that could unpredictably deflect the laser beam.

The vehicle according to any of the preceding items, wherein the control unit is configured to execute a location prioritization algorithm that selects locations for targeting insects based on a frequency of previous encounters with target insects at those locations.

The vehicle according to any of the preceding items,
wherein the control unit is further configured to:
store information about previous encounters with target insects at locations within an operational area; and
estimate an insect emergence rate for each location based on the stored information; and select locations for targeting insects based on the estimated insect emergence rates.

The vehicle according to any of the preceding items,
wherein the control unit is configured to:
perform a cluster analysis on location parameters of a plurality of target objects to identify target-rich zones; and
generate an optimized path for the vehicle that prioritizes the target-rich zones; and
   wherein the optimized path is generated based on a cost function that minimizes at least one factor selected from the group consisting of: total distance traveled by the vehicle, total movement of the at least one movable mirror, and a combination thereof.

The vehicle according to any of the preceding items, further comprising further comprising a support structure and a plurality of independently operable beam-steering mirrors within the optical unit; and
wherein the control unit is configured to predict trajectories of a plurality of target objects relative to the support structure and to assign each target object to one of the plurality of beam-steering mirrors based on a cost function that minimizes total mirror movement.

The vehicle according to any of the preceding items, wherein the location parameters of targeted objects are stored in a database present in the memory.

The vehicle according to any of the preceding items, further comprising a cooling unit coupled with the laser unit, wherein the cooling unit employs graphene or diamond material to dissipate heat generated by the laser beam away from the laser unit.

The vehicle according to any of the preceding items, wherein the heat is transferred to a high-wind region generated by at least one thrust-producing means.

The vehicle according to any of the preceding items, wherein the cooling unit comprises a liquid reservoir, suitable to contain water or ammonia, allowing the heat to buffer and release in periods of low laser firing, wherein the capacity of the liquid reservoir is less than 300 cm³.

The vehicle according to any of the preceding items,
wherein the movable mirror is a first movable mirror, and the vehicle further comprises a second movable mirror, each capable of operating independently and in parallel such that the first mirror can direct the optical path of a first laser beam and the camera towards a first target, while the second mirror can direct the optical path of the first laser beam, a split of version of the first laser beam, or a second laser beam, and an additional camera towards a second target.

The vehicle according to any of the preceding items, wherein the movable mirror is positioned close to the dichroic mirror, the movable mirror having a neutral position oriented at an angle of approximately 90 degrees relative to the dichroic mirror, thereby enabling a smaller movable mirror to achieve the desired field of view for the camera.

The vehicle according to any of the preceding items,
wherein the control unit is further configured to:
perform a calibration process to determine an offset aiming point based on observed discrepancies between an intended aim point and an actual laser spot location; and
utilize the offset aiming point to adjust laser aiming and account for misalignment between the dichroic mirror, the laser unit, and the camera.

The vehicle according to any of the preceding items, wherein the housing comprises multiple exit openings through which the laser beam can be directed out of the housing via the laser unit's actuator or the movable mirror.

The vehicle according to any of the preceding items, capable of targeting an object and emitting a laser beam at the targeted object while moving through a spatial environment.

The vehicle according to any of the preceding items, being configured for maintenance through the following steps:
Generating a notification indicating that The vehicle requires maintenance;
Replacing a component of The vehicle with a new component.

The vehicle according to any of the preceding items,
wherein the optical unit comprises a means for preventing ambient light from passing through, or being reflected by, the dichroic mirror and impinging upon a sensor of the camera,
wherein the means comprises material consisting of a dark, light-absorbing material; and a material that prevents the passing of light.

The vehicle according to any of the preceding items,
wherein the movable mirror comprises a mirror surface having a central zone and an outer zone, the central zone being configured to reflect the at least one laser beam,
wherein the central zone comprises a first mirror type optimized for reflecting the at least one laser beam; and
wherein the outer zone surrounds the central zone and is configured for reflecting a field of view of the camera, the outer zone comprising a second mirror type different from said first mirror type.

The vehicle according to any of the preceding items,
wherein the first mirror type has a higher optical quality than the second mirror type.

The vehicle according to any of the preceding items,
wherein the second mirror type is lighter in weight than the first mirror type.

A drone swarm comprising a plurality of aerial vehicles according to any of the preceding items, wherein each aerial vehicle is in data communication with one another and can communicate with each other.

A system comprising an aerial vehicle according to any of the preceding items, a designated landing area, and a mechanism for separating the replaceable battery from the aerial vehicle, wherein the mechanism is capable of autonomously reaching the majority of locations within the designated landing area and is not fixed to the length of the designated landing area, and is configured to autonomously approach the aerial vehicle after it has landed and separate the battery as part of a battery swap operation.

The system of item 53, wherein the mechanism for separating the replaceable battery from the aerial vehicle is attached to a robot equipped with wheels or legs, suitable for moving on the designated landing area.

The system of item 54, wherein the wheels are mecanum wheels or omni wheels.

The system of item 53, wherein the battery is detachably positioned on top of the aerial vehicle when it is in a landed state.

The system of item 53, wherein the battery includes a magnet or metal component that provides magnetic force to secure the battery during flight and assist in the battery separation step during the battery swap process.

The system of item 53, wherein the mechanism for separating the replaceable battery from the aerial vehicle comprises a battery-swapping component designed to replace the vehicle's battery, wherein the battery-swapping component comprises an arm with an electromagnet, which is vertically movable along a vertically arranged bar via a rail and carriage system.

Use of the aerial vehicle according to any of the preceding items for targeted pest control in an agricultural environment, for military applications or for burning weeds or leaves of unwanted vegetation.

The vehicle according to any of the preceding items
wherein the control unit is further configured:
store data associated with each targeted pest, including location, time of day, weather conditions, and time of year, and
analyze the data to identify patterns and correlations between pest prevalence and environmental factors; and optimize the vehicle's flight path based on the analyzed data to maximize the number of pests targeted.
The items of the third itemized list can be combined with one or more items of all other itemized lists in this document, features mentioned elsewhere in this document, as well as with one or more features of the claims.

### Third Itemized List:

An autonomously operating unmanned vehicle, comprising:
at least one thrust producing or locomotion means, and
   a camera for capturing images of an environment, and
   a laser unit for emitting at least one laser beam, and
   an optical unit operatively coupled to both the laser unit and the camera, comprising at least one movable mirror and a dichroic mirror, wherein the dichroic mirror is configured to reflect the laser beam and to be transparent to an optical path of the camera, or vice versa, so that the optical path of the camera is aligned with a path of the laser beam and both the optical path of the laser beam and the optical path of the camera are directed at the movable mirror,
   a control unit with a processor, a memory and one or more communication units which are in data communication with the laser unit, the camera and the optical unit, wherein the control unit is configured to analyze the camera images to detect objects and determine their location parameters, which can be used to direct the laser beam onto targeted objects using the moveable mirror.

The vehicle of claim 1, suitable for targeted pest control in an agricultural environment, wherein the camera is configured to capture environmental images of the agricultural environment, and the control unit is configured to analyze the camera images to detect pests and determine their location parameters, which can be used to direct the laser beam onto targeted pests using the moveable mirror.

The vehicle according to any of the preceding items, suitable for military applications, wherein the camera is configured to capture images of the environment, and the control unit is configured to analyze the camera images to detect military targets, such as human eyes, and determine their location parameters, which can be used to direct the laser beam onto the military targets using the moveable mirror.

The vehicle according to any of the preceding items, suitable for burning weeds or leaves, wherein the camera is configured to capture images of the environment, and the control unit is configured to analyze the camera images to detect unwanted vegetation and determine their location parameters, which can be used to direct the laser beam onto the weeds or leaves using the moveable mirror.

The vehicle according to any of the preceding items,
wherein the optical unit comprises a means to converge a laser beam or to focus multiple laser beams to a point in a distance when the laser unit comprises multiple laser sources for emitting multiple laser beams.

The vehicle according to any of the preceding items,
wherein the movable mirror is movable in at least one degree of freedom via an actuator, the actuator being a servo motor, and wherein the optical unit comprises a sensor to monitor the position or positional change of the movable mirror.

The vehicle according to any of the preceding items,
wherein the degree of freedom is the pitch or the roll of the movable mirror.

The vehicle according to any of the preceding items,
wherein the actuator is coupled to the movable mirror by a pulling cable.

The vehicle according to any of the preceding items,
wherein the moveable mirror is coupled to a spring, rubber, or flexible structure, wherein the spring, rubber, or flexible structure is configured to apply a constant rotational force to the movable mirror, the rotational force being selected from the group consisting of pitch rotational force and roll rotational force relative to the movable mirror.

The vehicle according to any of the preceding items,
wherein the movable mirror is actuated by a second servo motor for adjustment along at least a further degree of freedom, the further degree of freedom being selected from the group consisting of pitch and roll of the movable mirror.

The vehicle according to any of the preceding items,
wherein the optical unit comprises a galvo steering system with the movable mirror being part of it.

The vehicle according to any of the preceding items,
wherein the means to converge a laser beam or to focus multiple laser beams to a point in a distance is designed as follows:
the optical unit comprises a converging lens, or
the movable mirror is a concave mirror.

The vehicle according to any of the preceding items,
wherein converging lens is a dynamic focus length.

The vehicle according to any of the preceding items,
further comprising an event camera, a stereo camera, or an infrared camera in data communication with the control unit to further analyze the environment.

The vehicle according to any of the preceding items, further comprising a support structure,
wherein the optical unit, the laser unit and the camera are arranged in a common housing which is attached to the support structure via a gimbal, isolating the optical unit, the laser unit and the camera from the roll and pitch movements of the support structure.

The vehicle according to any of the preceding items, further comprising a support structure,
wherein the gimbal is coupled to the support structure via a flexible structure, such as a wire rope isolator, isolating the optical unit, the laser unit and the camera from frequency horizontal and vertical vibrations of the support structure.

The vehicle according to any of the preceding items,
wherein the gimbal comprises at least two rotational axes with actuators allowing the housing to rotate about at least two axes, so that
the optical unit can be coarsely oriented with respect to a potential target, and the movable mirror of the optical unit is capable of performing fine adjustments to the alignment of the camera's optical path or the laser beam, or
the optical unit can be iteratively directed at specific subregions of an area under the vehicle, scanning and cleaning each subregion under the vehicle in succession.

The vehicle according to any of the preceding items,
wherein the laser unit comprises at least one laser light source having a dominant wavelength of between 449 nm and 461 nm or of between 798 nm and 818 nm.

The vehicle according to any of the preceding items,
wherein the laser unit comprises multiple laser light sources for emitting multiple laser beams,
wherein the laser light sources are implemented on an integrated laser chip or array.

The vehicle according to any of the preceding items,
wherein a single laser driver circuit is configured to drive the multiple laser light sources.

The vehicle according to any of the preceding items,
wherein the laser unit comprises a light source with a power of 5.5 W, and the light source is either a pulsed light source or a continuous one.

The vehicle according to any of the preceding items,
wherein the laser unit comprises a fiber coupled laser light source, and a collimating lens.

The vehicle according to any of the preceding items,
wherein the laser unit comprises a laser driver circuit utilizing at least one transistor selected from the group consisting of a Silicon Carbide (SiC) MOSFET and a Gallium Nitride (GaN) FET.

The vehicle according to any of the preceding items,
wherein the laser unit is thermally coupled to a vapor chamber comprising a wick structure formed from a material selected from the group consisting of sintered copper powder, and a composite wick comprising at least one layer of sintered copper powder,
wherein the vapor chamber is configured to spread the heat generated by the laser unit over a larger surface area to enhance heat dissipation.

The vehicle according to any of the preceding items,
wherein the thrust producing means comprises at least one propeller and the vehicle further comprises at least one wing that generates lift when the vehicle moves forward.

The vehicle according to any of the preceding items,
wherein the propeller is dynamically rearrangeable and configured to provide mainly vertical thrust or horizontal thrust.

The vehicle according to any of the preceding items,
wherein the thrust producing means comprises two propellers, wherein a first propeller is configured to provide mainly vertical thrust and a second propeller is configured to provide mainly horizontal thrust.

The vehicle according to any of the preceding items,
further comprising a replaceable battery, wherein all power consuming components on the vehicle are coupled to the battery as a power source.

The vehicle according to any of the preceding items,
wherein the control unit is configured to analyze the camera images to detect objects and determine their location parameters using artificial intelligence algorithms, such as convolutional neural networks.

The vehicle according to any of the preceding items,
wherein the control unit is configured to detect any human in a nominal hazard zone of the laser beam,
wherein The vehicle may comprise an infrared camera to enhance detection.

The vehicle according to any of the preceding items,
wherein the nominal hazard zone is defined as a zone with a radius of 40 meters from the movable mirror, and wherein the control unit is configured to control the laser unit or the optical unit such that it does not target any objects outside of the nominal hazard zone.

The vehicle according to any of the preceding items,
wherein if a human is detected within the nominal hazard zone of the laser beam, the control unit is configured to cease neutralizing potential targets upon detection.

The vehicle according to any of the preceding items,
wherein the control unit is configured to analyze the camera images to anomaly detection, using artificial intelligence algorithms to identify deviations from expected patterns.

The vehicle according to any of the preceding items,
wherein the laser unit is configured to deactivate when water droplets or other reflective surfaces are detected that could unpredictably deflect the laser beam.

The vehicle according to any of the preceding items,
wherein the control unit is configured to execute a location prioritization algorithm that selects locations for targeting insects based on a frequency of previous encounters with target insects at those locations.

The vehicle according to any of the preceding items,
wherein the control unit is further configured to:
store information about previous encounters with target insects at locations within an operational area; and
estimate an insect emergence rate for each location based on the stored information; and select locations for targeting insects based on the estimated insect emergence rates.

The vehicle according to any of the preceding items,
wherein the control unit is configured to:
perform a cluster analysis on location parameters of a plurality of target objects to identify target-rich zones; and
generate an optimized flight path for The vehicle that prioritizes the target-rich zones; and
   wherein the optimized flight path is generated based on a cost function that minimizes at least one factor selected from the group consisting of: total distance traveled by The vehicle, total movement of the at least one movable mirror, and a combination thereof.

The vehicle according to any of the preceding items, further comprising a plurality of independently operable beam-steering mirrors within the optical unit; and
wherein the control unit is configured to predict trajectories of a plurality of target objects relative to the main body and to assign each target object to one of the plurality of beam-steering mirrors based on a cost function that minimizes total wear or energy expenditure.

The vehicle according to any of the preceding items,
wherein the location parameters of targeted objects are stored in a database present in the memory.

The vehicle according to any of the preceding items,
further comprising a cooling unit coupled with the laser unit, wherein the cooling unit employs graphene or diamond material, allowing to dissipate heat generated by the laser beam away from the laser unit.

The vehicle according to any of the preceding items,
wherein the heat is transferred to a high-wind region generated by at least one thrust producing means.

The vehicle according to any of the preceding items,
wherein the cooling unit comprises a liquid reservoir, suitable to contain water or ammonia, allowing the heat to buffer and to release in periods of low laser firing, wherein capacity of the liquid reservoir is less than 300 cm³.

The vehicle according to any of the preceding items,
wherein the movable mirror is a first movable mirror, and the vehicle further comprises a second movable mirror, each capable of operating independently and in parallel such that the first mirror can direct the optical path of a first laser beam and the camera towards a first target, while the second mirror can direct the optical path of the first laser beam, a split of version of the first laser beam, or a second laser beam, and an additional camera towards a second target.

The vehicle according to any of the preceding items,
wherein the movable mirror is positioned close to the dichroic mirror, the movable mirror having a neutral position oriented at an angle of approximately 90 degrees relative to the dichroic mirror, thereby enabling a smaller movable mirror to achieve the desired field of view for the camera.

The vehicle according to any of the preceding items,
wherein the control unit is further configured to:
perform a calibration process to determine an offset aiming point based on observed discrepancies between an intended aim point and an actual laser spot location; and utilize the offset aiming point to adjust laser aiming and account for misalignment between the dichroic mirror, the laser unit, and the camera.

The vehicle according to any of the preceding items,
wherein the housing comprises multiple exit openings through which the laser beam can be directed out of the housing via the movable mirror.

The vehicle, according to any of the preceding items, capable of targeting an object and emitting a laser beam at the targeted object while moving through a spatial environment.

The vehicle of claim 1, being configured for maintenance through the following steps:
Generating a notification indicating that The vehicle requires maintenance;
Replacing a component of The vehicle with a new component.

The vehicle according to any of the preceding items,
wherein the optical unit comprises a means for preventing ambient light from passing through, or being reflected by, the dichroic mirror and impinging upon a sensor of the camera,
wherein the means comprises material consisting of a dark, light-absorbing material; and a material that prevents the passing of light.

The vehicle according to any of the preceding items,
wherein the movable mirror comprises a mirror surface having a central zone and an outer zone, the central zone being configured to reflect the at least one laser beam,
wherein the central zone comprises a first mirror type optimized for reflecting the at least one laser beam; and
wherein the outer zone surrounds the central zone and is configured for reflecting a field of view of the camera, the outer zone comprising a second mirror type different from said first mirror type.

The vehicle according to any of the preceding items,
wherein the first mirror type has a higher optical quality than the second mirror type.

The vehicle according to any of the preceding items,
wherein the second mirror type is lighter in weight than the first mirror type

A drone swarm comprising a plurality of aerial vehicles according to any of the preceding items, wherein each aerial vehicle is in data communication with one another and can communicate with each other.

A system comprising an aerial vehicle according to any of the preceding items, a designated landing area and a mechanism for separating the replaceable battery from the aerial vehicle, wherein the mechanism is capable of autonomously reaching the majority of locations within the designated landing area and is not fixed to the length of the designated landing area, and is configured to autonomously approach the aerial vehicle after it has landed on the designated landing area, and separate the battery from the aerial vehicle as part of a battery swap operation.

The system of item 54,
wherein the mechanism for separating the replaceable battery from the aerial vehicle is attached to a robot equipped with wheels or legs, suitable for moving on the designated landing area.

The system of item 55,
wherein the wheels are mecanum wheels or omni wheels.

The system of item 54,
wherein the battery is detachably positioned on top of the aerial vehicle when it is in a landed state The system of item 54,
wherein the battery includes a magnet or metal component that provides magnetic force to secure the battery during flight and assist in the battery separation step during the battery swap process.

The system of item 54,
wherein the mechanism for separating the replaceable battery from the aerial vehicle comprises a battery-swapping component designed to replace the vehicle's battery, wherein the battery-swapping component comprises an arm with an electromagnet, which is vertically movable along a vertically arranged bar via a rail and carriage system.

The vehicle according to any of the preceding items,
wherein the control unit is further configured:
store data associated with each targeted pest, including location, time of day, weather conditions, and time of year, and
analyze the data to identify patterns and correlations between pest prevalence and environmental factors; and
optimize the vehicle's flight path based on the analyzed data to maximize the number of pests targeted.
The items of the fourth itemized list can be combined with one or more items of all other itemized lists in this document as well as with one or more features of the claims.
The items of the fourth itemized list can be combined with one or more items of all other itemized lists in this document as well as with one or more features of the claims.

### Fourth Itemized List:

1. An autonomously operating pest control system, comprising:
   a targeting system comprising a camera and a laser emitting element at times emitting a laser beam, and
   a mobility system, and
   a control and decision system, which is in data communication with the targeting system and the mobility system wherein the control and decision system is configured to analyze the camera images to detect objects and determine their location parameters, which can be used to direct the laser beam emitted by the laser emitting element onto targeted objects using the moveable mirror.
2. The autonomously operating operating pest control system according to any of the preceding items, where the targeting system further comprises a moveable mirror and the control and decision system is configured to direct the laser beam emitted by the laser emitting element using the moveable mirror.
3. The autonomously operating operating pest control system according to any of the preceding items, further comprising an exclusion zone monitoring system where the control and decision system inhibits firing the laser when a person is detected to be within a certain distance from the mobility system by the exclusion zone monitoring system.
4. The autonomously operating operating pest control system according to any of the preceding items, wherein emitted laser beam is converging and starts with a beam width of at least 4 mm and converge to a focal point within 5 metres, or the emitted laser beam is converging and starts with a beam width of at least 6 mm and converges to a focal point within 2 metres, or the emitted laser beam is converging and starts with a beam width of at least 8 mm and converges to a focal point within 1 metres.
5. The autonomously operating operating pest control system according to any of the preceding items, wherein the targeting system, mobility system, exclusion zone monitoring system and control and decision system are integrated into autonomously operating unmanned vehicle suitable for targeted pest control in an agricultural environment.
6. A vehicle comprising a Lateral Field-of-View Extension Module, a camera, a control unit, and a memory operatively coupled to the camera, wherein the Lateral Field-of-View Extension Module is configured to redirect light from lateral scenes into the optical axis of the camera, thereby extending the effective field of view, wherein the control unit is configured to analyze images captured by the camera to detect target insects within the extended field of view, and wherein the control unit is further configured to store the location of the detected target insects in the memory.
7. The vehicle according to any of the preceding claims, wherein the Lateral Field-of-View Extension Module is configured to fold light from at least one lateral direction onto the same image sensor used for capturing a nadir or forward-facing view, such that the lateral view is optically redirected and focused onto a distinct region of the shared sensor surface.

The items of the fifth itemized list can be combined with one or more items of all other itemized lists in this document, features mentioned elsewhere in this document, as well as with one or more features of the claims.

### Fifth Itemized List:

1. The targeting device described in any of the itemized lists.
2. The vehicle described in any of the itemized lists wherein the vehicle is a tractor, a UVA, a cart, a legged robot, or a floating vehicle.
3. A battery exchange system for a mobile platform, comprising:
   (a) a battery housing assembly configured to retain an energy storage device and comprising a magnetic component suitable for engagement by a robotic actuator; and
   (b) a battery socket assembly configured to receive the battery housing assembly and comprising:
      (i) one or more mechanical alignment features configured to guide the insertion of the battery housing assembly,
      (ii) one or more electrical contact surfaces configured to transfer energy between the energy storage device and the mobile platform, and
      (iii) a magnetic coupling feature configured to magnetically retain the battery housing assembly during operation;
wherein the magnetic component of the battery housing assembly is positioned to allow removal by a robot equipped with a magnetic actuator when the mobile platform is in a stationary state.
4. A method for robotic battery replacement, comprising:
(a) positioning a mobile robot on a substantially planar surface in proximity to a mobile vehicle having a battery socket mounted thereon;
(b) engaging a gripper mechanism of the robot with a battery or battery assembly retained within the battery socket;
(c) lifting and separating the battery or battery assembly from the battery socket using the gripper mechanism;
(d) transporting the battery or battery assembly across the planar surface to a second location comprising a recharging socket electrically coupled to a power source; and
(e) depositing the battery or battery assembly into the recharging socket in a manner that establishes electrical contact for energy transfer.

The items of the sixth itemized list can be combined with one or more items of all other itemized lists in this document, features mentioned elsewhere in this document, as well as with one or more features of the claims

### A Sixth Itemized List:

1. A targeting device may comprise:
   a beam input configured to receive a light beam from an internal or external light source; a beam steering mechanism configured to direct the beam toward a target;
   a focusing element configured to cause the beam to converge at a focal point and diverge beyond said point;
   a light-receiving device configured to acquire incoming light from the environment; and
   a control system operatively coupled to the light-receiving device and the beam steering mechanism, the control system being configured to process input from the light-receiving device and, based on said input, control the direction in which the beam is emitted.
2. The targeting device according to item 1 may include a control system further configured to determine the location of a target insect or eggs based on input from the light-receiving device.
3. The targeting device according to item 2 may have the control system further configured to direct the beam toward a specific anatomical region of the insect, such as the head.
4. The targeting device according to any of the preceding items may comprise a light-receiving device that includes an optically-aligned camera sharing an optical path with the beam via at least one dichroic optical element.
5. The targeting device according to any of the preceding items may comprise one or more non-optically aligned cameras configured for wide-area scanning and target detection.
6. The targeting device according to item 5 may have the control system further configured to detect anomalies inconsistent with expected target characteristics and to inhibit beam activation in response.
7. The targeting device according to any of the preceding items may have the beam input optically coupled to an optical fiber or a free-space beam path originating from an external light source.
8. The targeting device according to any of the preceding items may have a control system configured to estimate the distance to the target and adjust the focusing element to converge the beam at said distance.
9. The targeting device according to any of the preceding items may employ a beam steering mechanism comprising at least one of a MEMS mirror, a fast steering mirror, a gimbal-mounted mirror, a galvanometer pair, an acoustic beam steering system, or another optical beam steering technology.
10. The targeting device according to any of the preceding items may further include a thermal sensor configured to detect heat signatures and inhibit beam activation if a heat-emitting entity is detected within a predefined exclusion zone.
11. The targeting device according to any of the preceding items may further comprise a modular housing configured for mounting to a mobile or stationary platform.
12. A system may comprise the targeting device described above and a mobile platform configured to transport the targeting device across an operational environment.
13. The system according to item 12 may include a mobile platform that comprises one or more of wheels, tracks, propellers, articulated legs, or a cable-guided drive.
14. The system according to item 12 or 13 may further include a surrounding monitoring system configured to detect non-target entities within an exclusion zone.
15. The system according to item 14 may include a control system that inhibits beam activation when a non-target entity is detected within the exclusion zone.
16. A method for targeting and neutralizing an object using a beam-steering device may comprise the steps of:
   receiving a neutralizing beam from an internal or external light source;
   acquiring environmental input via a light-receiving device;
   processing the acquired input to determine the location of a target;
   steering the neutralizing beam toward the target based on said processed input; and
   focusing the beam to converge at a focal point on the target and diverge beyond said point.
17. The method according to item 16 may further comprise directing the beam toward a specific anatomical region of the target, including a head region of an insect.
18. The method according to item 16 may comprise identifying the presence of anomalies inconsistent with known target features and inhibiting beam activation in response.
19. The method according to item 16 may further include estimating a distance to the target and dynamically adjusting the focus of the beam to converge at said distance.
20. The method according to item 16 may comprise acquiring image data using either an optically-aligned or a non-optically aligned camera.
21. The method according to item 16 may further comprise detecting heat signatures using a thermal sensor and inhibiting beam activation if a heat-emitting entity is located within a predefined exclusion zone.
22. The method according to item 16 may comprise steering the beam by actuating at least one of a MEMS mirror, a fast steering mirror, a gimbal-mounted mirror, a galvanometer pair, an acoustic beam steering system, or any other beam steering mechanism.
23. A mobile system may comprise: a light-directing mechanism configured to emit light toward a location in space; a sensor configured to receive information from the environment; a control system configured to process the received information and adjust the direction of the emitted light based on said information; and a mobility mechanism configured to transport the system through an environment.
24. A system may comprise: a light-emitting mechanism configured to emit light toward a region in space; a monitoring system configured to observe a surrounding area of the system and detect the presence of a human; and a control system configured to inhibit or modify light emission based on detection of a human by the monitoring system.
25. The system according to item 23 may be configured such that the light emitted by the light-directing mechanism converges at a focal point and diverges beyond said point.
26. The system according to item 23 may include a sensor comprising a thermal sensor configured to detect heat signatures in the environment.
27. The system according to item 24 may be configured such that the emitted light converges at a focal point and diverges beyond said point.
28. The system according to item 24 may comprise a monitoring system including a thermal sensor configured to detect the presence of a human based on heat emissions.
29. A mobile system may comprise: a light-emitting mechanism configured to emit light toward a target region; a mobility mechanism configured to move the system while light is being emitted; and a control system configured to direct the emitted light while the system is in motion, wherein motion of the system reduces the duration of light exposure at any given point in space except the location of the target.

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.
The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

This work has benefited from a grant from the PhotonHub Europe program, part of the Horizon 2020 grant scheme. Agreement ID: 101016665, DOI: 10.3030/101016665, Internal project reference: P2024-47. The grant was awarded following a formal technical feasibility review conducted by a professor of photonics at the Vrije Universiteit Brussel (VUB). The project was subsequently defended before a multidisciplinary evaluation panel comprising eight experts, including academic professors and senior figures from the business and innovation ecosystem. This evaluation validated the technical foundation, innovation potential, and real-world applicability of the proposed system, supporting its advancement toward practical deployment.

During this project the absorption of one insect, the colorado beetle, sub parts, head, wings etc have been measured in a spectrographic study and it was concluded that both frequencies around 450 nm and 1550 nm are well absorbed. Specifically, the absorption of the beetle head for 1550 nm is about 25 procent. Further was validated that according to the American National Standard for Safe Use of Lasers, ANSI Z136.1-2014, the maximum permissible exposure (MPE) for Ocular Exposure to a Laser Beam for Wavelengths from 1400 nm to 1000 um and exposure duration 10\hat{ }-9 to 10 seconds is 1 (J/cm2) for wavelengths between 1500 en 1800 nm. As part of this project the soundness of the design was also reviewed.

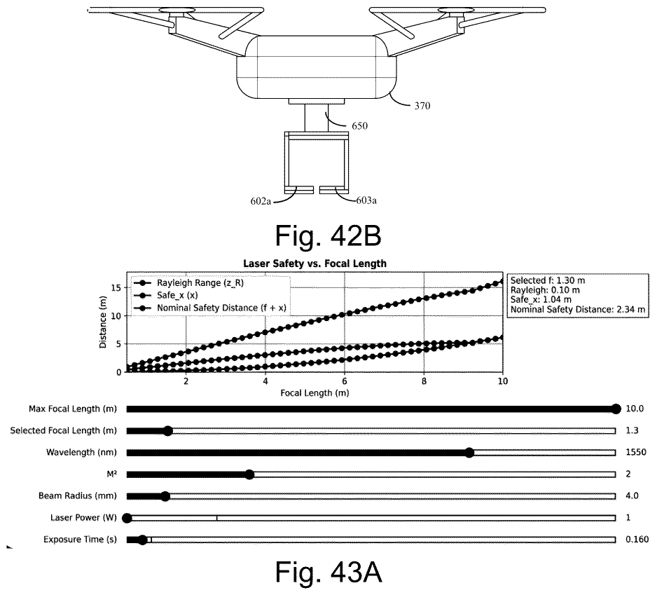

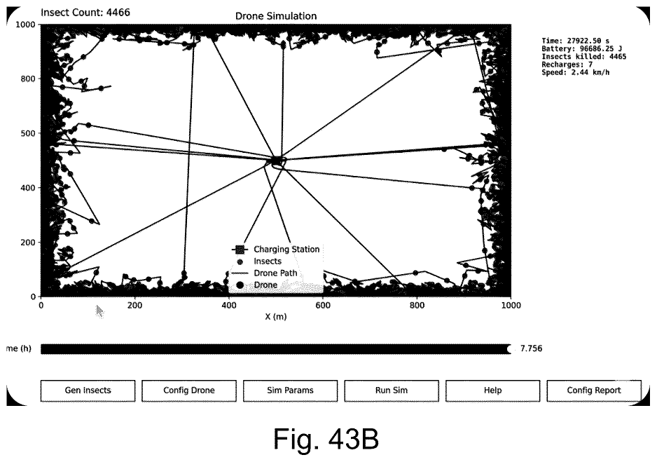

FIG. 43A shows a screenshot of a custom developed software tool that, based on the assumption of a threshold exposure of 1 J/cm², calculates the Nominal Safety Zone (NSZ). The interface allows users to adjust key laser and beam parameters—such as focal length, wavelength, beam radius, laser power, and exposure time-via sliders, and dynamically visualizes key safety distances including the Rayleigh range, minimum safe distance beyond the focus, and total NSZ. For a representative configuration of a 1 watt laser at 1550 nm, with a starting beam radius of 4 mm and a selected focal length of 1.30 meters, the tool calculates a Rayleigh range of 0.10 meters and a resulting Nominal Safety Distance of 2.34 meters. The core calculations are based on standard Gaussian beam propagation and irradiance formulas, including dynamic computation of beam divergence, spot size at distance, and comparison against Maximum Permissible Exposure (MPE) thresholds.

FIG. 43B shows a screenshot of a custom developed software that helps estimate how many hectares a UAV equipped with an insect-targeting unit could treat per day. The simulation models a quadcopter operating over a 1000 by 1000 meter field. The field is first populated using a beetle distribution function, after which the UAV is programmed to visit each insect location following a path optimized using the traveling salesman algorithm. The UAV is required to return to a centrally located charging station when its battery level becomes low. The tool allows adjustment of parameters such as beetle distribution, UAV characteristics (including maximum speed, battery capacity, and acceleration), and laser targeting settings (including target acquisition time and firing energy). The simulation includes reasonably accurate physical modeling, such as acceleration and turning constraints. By adjusting these parameters, the tool provides realistic predictions of how large a field a single UAV could cover in a 9-hour day. The conclusion is that eliminating several thousand, and in some cases up to 20,000 beetles per day, is operationally achievable within practical limits.

External validation was provided by Dr. Ananda Kafle, an Analytical Development Scientist and former Postdoctoral Fellow at Kyushu University and Tokyo University of Science, Japan. Dr. Kafle is internationally recognized for his work on lipid membrane behavior and molecular interactions. He received the Journal of Oleo Science Best Author Award (2018) and is a co-author of several peer-reviewed publications, including:
Kafle, A., Akamatsu, M., Bhadani, A., Sakai, K., Kaise, C., Kaneko, T., & Sakai, H. Effects of β-sitosteryl sulfate on the properties of DPPC liposomes. J. Oleo Sci., 67, 1511-1519 (2018).
Kafle, A., Misono, T., Bhadani, A., Akamatsu, M., Sakai, K., Kaise, C., Kaneko, T., & Sakai, H. Effects of β-sitosteryl sulfate on the hydration behavior of dipalmitoylphosphatidylcholine. J. Oleo Sci., 67, 763-771 (2018).
Kafle, A., Misono, T., Bhadani, A., Akamatsu, M., Sakai, K., Kaise, C., Kaneko, T., & Sakai, H. Effects of β-sitosteryl sulfate on the phase behavior and hydration properties of distearoylphosphatidylcholine: a comparison with dipalmitoylphosphatidylcholine. J. Oleo Sci., 67, 433-443 (2018).
Kafle, A., Akamatsu, M., Bhadani, A., Sakai, K., Kaise, C., Kaneko, T., & Sakai, H. Phase behavior of the bilayers containing hydrogenated soy lecithin and β-sitosteryl sulfate. Langmuir, 36, 6025-6032 (2020)—Cover Page Feature.

In a signed validation report dated Apr. 19, 2025, Dr. Kafle confirmed that key technical, biological, and safety assumptions underlying a laser pest control UVA system, applied to a specific crop and pest (colorado beetle), are feasible and supported by experimental data, scholarly literature, and engineering standards. Specifically, the report found that: (i) the flammability risk to crops such as potato plants is minimal due to both inherent plant properties and controlled laser parameters; (ii) laser-induced defoliation is negligible compared to natural pest damage; (iii) insect behavior allows for targeted engagement as they spend considerable time basking in the sun; (iv) modern AI and FPGA-based vision systems can meet the required detection and tracking speeds; (v) MEMS mirror technology enables rapid and precise beam steering; (vi) energy requirements for laser engagement are small relative to the overall energy used for drone mobility; and (vii) 1550 nm laser sources are both eye-safe (due to corneal absorption) and efficient, with low cooling demands and commercially available in cost-effective form factors. The report further validated an inflow estimate of approximately 200 beetles per hectare per day, derived from a study of ILVO in Flanders, and a typical feeding window of 2 to 3 days before egg laying. These findings confirm the technical viability and agricultural relevance of laser-based pest control using autonomous aerial systems. An energy analysis confirms that laser-based insect neutralization requires negligible power compared to other drone functions. Specifically, the energy needed to lethally heat a beetle head using a 1550 nm laser is approximately 1.7 joules, based on modeling the beetle's head as a 1 mm³ water-equivalent volume, with 25% absorption efficiency and 40% laser electrical-to-optical efficiency. In comparison, executing one second of embedded AI vision processing on a Jetson Nano GPU requires roughly 10 joules, while sustaining flight for one second consumes 32 joules for a lightweight DJI Mini 3 drone and up to 400 joules for a heavier tactical drone platform. A 200 W solar panel exposed to one hour of direct sunlight generates approximately 720,000 joules, enough to support extended flight and processing cycles. These figures demonstrate that laser firing contributes minimally to total system energy consumption. Therefore, the primary operational cost of such autonomous drones is not energy usage.

The above empirical results, simulation outcomes, and external validations are provided solely to illustrate possible embodiments, performance scenarios, and use cases. They are not intended to limit the scope of the invention as defined by the claims. All numerical values, parameters, and example outputs are illustrative in nature. No guarantee is made as to the absolute accuracy of these values, and any deviation, estimation error, or inaccuracy in the disclosed numbers shall not affect the interpretation, validity, or enforceability of the claimed invention.

### Additional Specification Section: Optical Focusing Elements and Metalenses:

Focusing a laser beam to a tight spot at a long focal distance using conventional refractive lenses presents manufacturing and optical challenges. In particular, the curvature of a lens designed for a long focal length becomes increasingly shallow, approaching a near-flat surface profile. Such shallow curvature is difficult to fabricate with the precision necessary to achieve diffraction-limited performance, especially for larger aperture optics. Consequently, maintaining a high-quality focused spot at extended working distances can be compromised by manufacturing tolerances, surface figure errors, and optical aberrations.

Although aspherical lenses may be employed to reduce spherical aberrations and improve focal spot quality relative to simple spherical lenses, they still depend on precisely formed curved surfaces. These surfaces may remain challenging and costly to produce at large sizes or long focal lengths. Furthermore, aspherical lenses tend to increase the system's bulk and weight, which may be undesirable for applications requiring compactness and lightweight optical assemblies, such as those mounted on unmanned aerial vehicles (UAVs).

Metalenses, comprising arrays of subwavelength nanostructures or meta-atoms arranged with precise spatial patterns, provide an alternative approach to beam focusing. Instead of relying on curved surfaces, metalenses manipulate the phase of incident light through engineered interactions with these nanostructures. The feature size, shape, height, and spatial arrangement of the meta-atoms define the lens's phase profile. While fabrication of metalenses at visible wavelengths requires extremely small feature sizes-on the order of tens of nanometers—these features scale proportionally with operating wavelength. At longer wavelengths, such as near-infrared and infrared bands (e.g., 1550 nm and beyond), the meta-atom dimensions increase, facilitating fabrication with established semiconductor processing technologies.

An important consideration for metalenses intended for high-power laser applications is their optical damage threshold and thermal handling capability. Suitable materials for fabricating high-power metalenses include silicon (Si), silicon nitride (Si₃N₄), titanium dioxide (TiO₂), and gallium nitride (GaN), which exhibit favorable transparency, high refractive index contrast, and resistance to laser-induced damage at relevant wavelengths. Experimental data and emerging literature indicate that metalenses fabricated from these materials may withstand power densities consistent with continuous-wave laser operation at power levels of approximately 1 watt or greater at wavelengths near 1550 nm.

Accordingly, for applications requiring long focal lengths and tight focal spots-particularly those involving long-wavelength laser sources-metalenses may offer significant advantages over traditional refractive or aspherical lenses. These advantages include easier fabrication, reduced system size and weight, and the potential for improved optical performance. Provided the metalenses can reliably tolerate the required optical power levels, they represent a preferred solution for integration into lightweight, high-performance laser systems, including those deployed on UAV platforms.

Embodiments may be described as laser drone system comprising:
(a) a laser source emitting radiation at a wavelength of approximately 1550 nanometers or greater;
(b) an optical focusing assembly configured to focus the laser radiation to a target at a long working distance;
(c) wherein the optical focusing assembly includes a metalens comprising an array of subwavelength nanostructures fabricated from a material selected from the group consisting of silicon, silicon nitride, titanium dioxide, and gallium nitride, the metalens designed to produce a tight focal spot at the long working distance;
(d) wherein the metalens is configured to withstand continuous-wave laser power of approximately 1 watt or greater without significant optical degradation.

Long-Range Targeting: The present invention contemplates a laser drone system capable of delivering laser radiation for precise targeting at extended working distances. Such long-range targeting may be required in applications including, but not limited to, military engagements, precision pest control, remote sensing, and material processing.

To achieve effective energy delivery at these extended ranges, the system must manage several optical challenges, including beam divergence, focal spot size, irradiance distribution, and the protection of sensitive optical components within the system.

### Collimated Beam Embodiment

In one embodiment, the system produces a substantially collimated laser beam characterized by parallel rays propagating with minimal divergence. This collimation allows the laser beam to maintain a consistent diameter and irradiance profile over long distances, ensuring precise and effective targeting of small or distant objects.

Collimation may be achieved through a variety of optical means including beam expanders, telescopic lens assemblies, or advanced metalenses specifically designed to minimize beam divergence at the operating wavelength.

Converging Beam with Downstream Collimation: In an alternative embodiment, the laser beam emitted from the source is initially formed into a converging beam prior to reaching a beam steering element, such as a steerable mirror. This configuration reduces the beam diameter at the steering optic, lowering the power density and mitigating risks of optical damage or thermal degradation to sensitive components. Following reflection, the converging beam is directed into an optical element with a negative focal length—for example, a diverging lens or concave mirror—that expands and transforms the beam into a collimated output beam suitable for long-range propagation. This downstream collimation ensures the system can deliver a stable, low-divergence beam while preserving the longevity and performance of the internal optics.

Adaptive Optics Embodiment: Further embodiments incorporate adaptive or tunable optical elements to dynamically adjust beam divergence and focal characteristics. Devices such as deformable mirrors, liquid crystal spatial light modulators, or tunable metasurfaces allow the system to modify the beam profile in real time. This adaptability enables the laser drone to optimize performance across varying target distances, switching between tightly focused beams for mid-range precision and collimated beams for extended-range applications.

Multi-Element Metasurface Assemblies: The system may also employ multi-element metasurface optical assemblies, combining metalenses engineered to correct chromatic and spherical aberrations with variable focal length properties. These flat optical assemblies enable fine control of the beam's focusing behavior without mechanical movement, resulting in a compact and lightweight design particularly well-suited for UAV payload constraints.

Material and Power Handling Considerations: For all embodiments, the optical components-including metalenses, lenses, and steering mirrors—are fabricated from materials exhibiting high laser damage thresholds, transparency at the operating wavelength (typically 1550 nm or greater), and stability under thermal loads.

Suitable materials include silicon, silicon nitride, titanium dioxide, and gallium nitride, which support continuous-wave laser operation at power levels on the order of 1 watt or greater without significant optical degradation.

By incorporating these optical strategies-collimation, converging beam management with downstream collimation, adaptive optics, and advanced metasurface assemblies—the laser drone system achieves flexible, robust, and efficient long-range targeting. This enables precise energy delivery to distant targets while balancing optical performance, component protection, system size, and weight, meeting the demanding requirements of aerial laser applications.

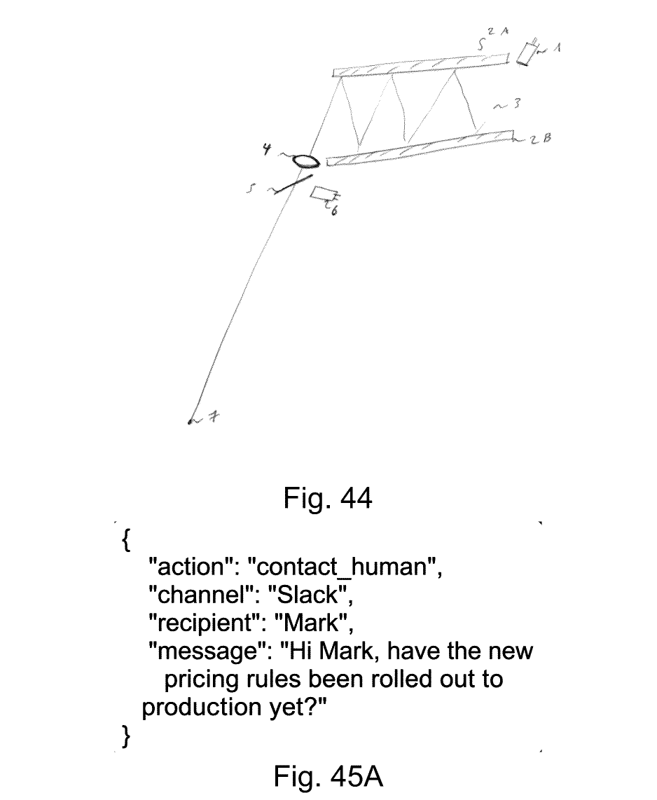

An alternative embodiment is illustrated in FIG. 44, wherein a first laser diode (1) may be configured to emit a beam (3) that is reflected between two mirrors (2A, 2B), thereby folding the optical path. The folded beam may then pass through a focusing lens (4), resulting in an outgoing beam that is optically aligned with a second laser diode (6). The second laser diode (6) may emit a visible spot that is detectable by at least one camera within the system and serves as an indicator of the impact location of the beam (3) when the first laser diode (1) is activated. This embodiment may be particularly suited for implementations in which the unmanned aerial vehicle (UAV) or mobile platform is sufficiently stable to achieve beam targeting by repositioning its body and, by extension, the optical unit attached thereto. In particular this configuration can be described as a beam alignment system for an unmanned mobile platform, comprising a first laser diode configured to emit a primary beam; a mirror assembly comprising at least two mirrors configured to reflect the primary beam and fold its optical path; a focusing lens arranged to receive the folded beam and direct an outgoing beam toward a target; a second laser diode optically aligned with the outgoing beam, said second laser diode configured to emit a visible alignment spot; and at least one camera configured to detect the visible alignment spot and thereby indicate the anticipated impact location of the primary beam when the first laser diode is activated; wherein the system is configured such that movement of the platform causes corresponding directional changes in the outgoing beam.

### Further Embodiments Addressing Environmental Challenges

Preventing damage, enhancing market efficiency, and ultimately reducing the need for physical movement and resource consumption—thereby lowering pollution, CO₂ emissions, and improving safety—are all consistent with the broader scope and intended purpose of the photonic insecticide embodiments disclosed in this document. Various distinct embodiments, each realizing a subset of these governing principles, are further disclosed herein and are intended to form the basis for potential later divisional applications. The claims of the present application, however, are limited in scope to the laser insecticide invention.

In any of the following inventions or embodiments thereof, unless explicitly constrained by limiting terms such as “must,” all descriptive language is intended to illustrate a possible implementation and should not be construed as limiting the scope of the invention. The term personal AI agent may refer to any smart device, including but not limited to a smartphone, smart glasses, or other wearable or embedded electronics. This agent may operate independently or in communication with other devices—such as smart glasses interfacing with a smartphone—and may also interface with a remote process or component running on a server. The entire configuration, including any subset thereof, may be referred to herein as an agent, personal agent, or personal AI agent.

Wherever a method, claim, or sequence of steps is described herein, it is to be understood that a corresponding hardware computing device and a computer-readable storage medium containing instructions for performing said method or steps are implicitly included.

### Embodiment A: Information Texturising for Recyclability and Accountability of Manufactured Parts

Technical Field: The invention relates to methods for embedding metadata into the surface of manufactured parts, particularly plastic components, to potentially enhance recyclability, material purity, traceability, and producer accountability. This method may be referred to as “information texturising.”

Background: Recycling systems today often lack the precision to identify detailed chemical compositions or reliably trace the origin of plastic items once they are fragmented, worn, or visually degraded. As a result, high-value recycled plastic tends to be contaminated by misclassified materials, which undermines its commercial viability. Existing indicators, such as labels or surface markings, may not survive fragmentation or abrasion and offer only limited insight into a product's full composition or production background. Therefore, there may be value in a method that allows the chemical formulation and traceability information of a manufactured item to be embedded directly into the item's structure in a way that remains detectable even on small, damaged, or shredded fragments.

Summary of the Invention: The present invention proposes a method by which information related to a part's chemical composition and provenance could be embedded into the item itself during its manufacture. This process, termed “information texturising,” may involve the deliberate structuring of the surface texture of the manufactured item to carry machine-readable information. Such encoding could occur through modifications to the mold used in the forming process or via post-production surface treatments, such as laser texturing. The textured encoding might represent data such as polymer type, additives, production batch, or manufacturer identity. The encoding could be distributed across the entire part or across select zones in a redundant manner, potentially ensuring that even fragmented portions retain legible metadata. In certain cases, this information might link to a digital registry or database containing more detailed compositional and traceability records. Detailed Description of the Invention: The information may be embedded through modifications to the mold used in the manufacturing process. A mold might be structured using micro-milling, pulsed laser ablation, focused ion beam etching, or similar micro-fabrication techniques to create a pattern that is then imprinted onto each part during molding or casting. Alternatively, after molding, a high-precision laser or comparable surface-texturing system could apply a fine pattern that encodes the necessary metadata.

The encoding patterns may be implemented as miniaturized, two-dimensional symbolic codes or distributed microdot arrays, configured for machine-readability under microscopic or enhanced imaging conditions. These patterns may remain detectable following typical surface wear, material aging, thermal cycling, or mechanical fragmentation. Suitable encoding formats include, but are not limited to, QR codes, Data Matrix codes, Aztec codes, DotCode, and PDF417, each selected based on application-specific constraints such as spatial resolution, information payload, error correction capacity, and tolerance to partial occlusion. The encoding may be repeated at multiple loci across the mold cavity, resulting in systematic replication of the embedded information across the manufactured part. This distributed encoding approach enables redundant data retrieval, ensuring that the embedded information remains accessible even when only a partial segment of the molded component is available. The repeated structures may further support fragment-based scanning and reconstruction, enhancing traceability and forensic utility in fragmented, damaged, or recycled materials.

The patterns may encode, directly or indirectly, identifiers for the polymer type, additive composition, filler materials, and manufacturing details. In cases where full information is not embedded in the texture itself, a unique identifier may serve as a reference to a registry or database that contains comprehensive material and traceability data. This registry could be local, distributed, or globally managed, and might include lifecycle instructions, compliance records, and recycling guidance.

Reading these patterns might be accomplished using current machine vision systems, optical microscopes, or infrared scanners. As reading technology improves, such systems could become increasingly efficient and compact, possibly allowing real-time scanning on recycling lines or embedded into robotic waste sorters. The encoding method is designed to be forward-compatible with such technological advances.

The invention might also be applied beyond plastics to other molded, cast, or 3D-printed materials, enabling a broader system of traceable manufacturing across various sectors.

Various refinements, alternatives, and applications of the foregoing embodiment may be described by the following itemized list, each of which is considered to fall within the general inventive concept and may be combined where technically feasible: A method of embedding information relating to the chemical composition of a manufactured part into the part itself by encoding said information in the surface structure of the mold or by applying said information to the surface texture after formation of the part.

A method of classifying fragments of a plastic item in a waste stream by detecting information that was deliberately encoded into the surface texture of the item during its manufacturing process, the classification aiming to improve the purity and consistency of sorted material.

The method of item 1, wherein the encoding comprises machine-readable surface features.

The method of item 1, wherein the encoding occurs by microstructuring the mold.

The method of item 1, wherein the encoding occurs via laser texturing after molding.

The method of item 1, wherein the encoded information may represent polymer type.

The method of item 1, wherein the encoded information may represent additive composition.

The method of item 1, wherein the encoded information may identify a manufacturing batch.

The method of item 1, wherein the encoded information may identify the producer or manufacturer.

The method of item 1, wherein the encoding is redundantly applied across multiple regions of the part.

The method of item 1, wherein the encoding remains visible on fragments after mechanical damage.

The method of item 2, wherein the classification is performed by a computer vision system.

The method of item 2, wherein the classification is based on decoding a pattern corresponding to an external database record.

The method of item 2, wherein the fragments are sorted based on polymer compatibility.

The method of item 2, wherein the decoding system is embedded in a waste-sorting machine.

The method of item 1, wherein the surface features form a miniaturized two-dimensional data pattern.

The method of item 1, wherein the encoded pattern includes error correction to allow partial reading.

The method of item 1, wherein the information includes environmental compliance or recyclability flags.

The method of item 1, wherein the texturised pattern can be detected via infrared imaging.

The method of item 1, wherein the information texturising process is standardized to comply with an international schema.

The method of item 1, wherein the texturising pattern may also include consumer-relevant information retrievable by designated reader devices.

### Embodiment B: AI-Enforced Access System for Public Toilets with Identity Verification and Vandalism Detection

BACKGROUND: Public sanitation facilities may often suffer from vandalism, misuse, and hygiene neglect, leading to increased maintenance costs and reduced accessibility. Traditional entry systems such as coin-based or free-access mechanisms may offer little to no accountability. A method that could encourage proper usage and deter vandalism through post-use accountability may be desirable, especially if privacy is respected.

### Summary

The present invention may relate to a system and method for public toilet access management that could utilize identity verification, camera-based condition monitoring, and automated analysis via artificial intelligence to detect misuse. A privacy-preserving mechanism might ensure that monitoring only occurs when the space is unoccupied. If damage or vandalism were detected, a user's deposit or stake could be forfeited and future access could be limited.

### Enabling Description

The system may comprise an integrated hardware and software platform designed to manage access, record condition before and after use, and enforce accountability through automated deductions from user-held deposits. The architecture may consist of a small local computing unit such as a Raspberry Pi, Jetson Nano, or other embedded platform. This computing unit may interface directly with physical access components including a door lock actuator, an entry request button, and an exit detection mechanism. The entry button may signal intent to access the facility, prompting the computing unit to initiate a sequence of events.

Upon receiving the entry request, the system may first check whether a valid identity token has been presented through an NFC reader, QR code scanner, or mobile application interface. Once identity is verified and a minimum deposit or stake is registered, the computing unit may activate an internal camera to take a photograph of the unoccupied interior of the toilet. This image may include the toilet bowl, floor, walls, and surrounding area under fixed lighting conditions to maintain visual consistency. The pre-use image may be timestamped and stored locally or sent to a cloud service, depending on network configuration.

Simultaneously, a motorized shutter system may be activated to physically obscure the camera lens before the door is unlocked. The door lock actuator may receive a signal to unlock, allowing the user to enter. The shutter may remain engaged throughout occupancy to ensure no images are captured during use. Occupancy may be detected through door state sensors, pressure pads, or internal motion detectors.

Upon detection of exit—either by re-locking of the door, change in motion profile, or activation of an exit button—the computing unit may reopen the camera shutter and take a second photograph of the interior. This post-use image may then be paired with the original pre-use image and fed into a trained convolutional neural network, either locally or via a remote processing server. The AI model may be specifically trained to detect deviations considered indicative of vandalism or misuse. These might include the presence of overflowing material in the bowl, graffiti on the walls, non-standard foreign objects, excessive tissue usage, or evidence of urination or defecation outside of intended receptacles.

The trained neural network may generate an anomaly score or classification label indicating whether the deviation falls within expected usage patterns or constitutes a misuse event. This determination may trigger a rule-based response engine within the computing unit. If no anomaly is detected, the user's stake may be returned in full and no further action taken. If misuse is detected, the system may automatically deduct a predefined portion or the entirety of the user's deposited amount, and may log the event to a centralized behavior database.

The system may further maintain a user reputation registry wherein individuals flagged for repeated misuse may be subjected to increased stake requirements, access delays, or outright bans depending on administrative configuration. Data retention policies may enforce that all images be deleted within a specific time window, such as 48 to 72 hours, unless flagged as part of a confirmed misuse case. Access to image data may be restricted to automated systems unless human review is legally mandated or requested by the user for appeal.

All data flows, including entry signals, identity verification, camera control, AI inference requests, and user balance updates, may be orchestrated through the local computing unit. Cloud integration may optionally extend the system's capabilities to include AI model updates, multi-location user tracking, dashboard access for facility operators, and aggregated misuse statistics.

This configuration may be deployed in fixed public toilets, mobile sanitation units, or semi-permanent festival installations. The modular design may support standardization across facilities while preserving privacy and enabling precise, low-cost enforcement of proper usage norms through automation.

The invention may be described through the following illustrative features and variations, which may be implemented independently or in combination:

A system for managing access to public toilet facilities, comprising a computing unit configured to verify user identity and capture pre-use and post-use images of the facility.

The system may include a camera positioned to capture an interior image prior to user entry.

The system may further include a servo-actuated shutter or similar mechanism configured to obscure the camera during occupancy, thereby preserving user privacy.

The computing unit may be operatively connected to a door lock actuator that responds to successful identity verification to permit access.

After use, the computing unit may capture a post-use image and compare it with the corresponding pre-use image.

The comparison may be performed by a trained neural network or other AI model configured to detect signs of misuse or abnormal facility conditions.

Misuse may be defined as the presence of foreign objects, excessive paper usage, visible waste outside of sanitary receptacles, or other predefined criteria.

Upon detection of misuse, the system may deduct an amount from a user-held deposit or stake.

Identity verification may be performed using an NFC token, biometric input (e.g., fingerprint or face recognition), or a mobile application.

The amount deducted may be scaled according to a severity score generated by the AI model based on the degree of misuse detected.

The system may maintain or access a user reputation database which is updated based on confirmed misuse events.

Repeated offenses, as tracked in the reputation database, may result in restricted access, including temporary or permanent bans.

All captured images may be automatically deleted after a defined retention period unless misuse is confirmed, in which case relevant data may be retained for evidence or dispute resolution.

The computing unit may synchronize locally stored data with a cloud-based server for centralized analysis, tracking, and management.

Multiple toilet facilities may share a federated or centralized user behavior record, enabling coordinated enforcement and access policy.

A method for managing public toilet access, comprising the steps of verifying identity, capturing pre- and post-use images, detecting anomalies, and applying corresponding consequences or access permissions.

The anomaly detection in the method may involve image analysis via a convolutional neural network trained on labeled examples of appropriate and inappropriate use.

Based on the analysis, user-held deposits may be refunded in full or partially deducted depending on detected behavior.

Occupancy detection within the facility may be achieved via motion sensors, pressure pads, or door-position monitoring.

The system may be configured to inform users of the access terms, deposit conditions, and data policy during the access request or authentication phase.

### Embodiment C: AI-Mediated Contract Exchange System with Standardized Templates, Autonomous Agent Execution, and Tiered Dispute Resolution

The present invention relates to an online deal making and enforcement platform that may enable autonomous agents to negotiate, execute, and monitor contracts on behalf of human users or organizations. This platform could operate as a standardized digital environment in which artificial intelligence agents, representing individuals or companies, may discover, evaluate, and engage in contractual agreements based on a shared registry of structured templates. These templates might define the general format and semantic structure of a wide range of service agreements, allowing agents to populate them with specific parameters and commit to them through cryptographic signing mechanisms. The platform could act as an intermediary to record, validate, and enforce these agreements, while providing both parties with traceable, verifiable records of the transaction.

Each contract may be derived from a versioned template, which could be stored in a registry that is accessible to all agents within the system. Templates might be defined using structured formats such as JSON or XML, and could include an immutable identifier, such as a hash or certificate, to ensure auditability. Agents may fill in these templates with relevant data-such as dates, locations, prices, and other terms—and cryptographically sign the result using private keys associated with their respective owners. The resulting contract document may be submitted to the platform, where it could be posted as an active offer, visible to other agents for counter-signature. Upon mutual agreement, the platform may lock the contract and initiate the execution phase, including optional escrow deposits, service delivery triggers, and post-completion logging.

The platform could support the use of both formal and informal contract attributes. Formal fields may include quantifiable parameters such as time, quantity, price, or service class, while informal descriptors might encompass subjective or experience-based features, such as user sentiment, visual quality, or aesthetic appeal.

Artificial intelligence agents might employ various models-including image classifiers, language models, or multi-modal embeddings—to interpret these informal fields and evaluate which offers best align with the user's preferences. Consequently, contract offers that are otherwise identical in structure could be prioritized differently based on inferred user behavior or historical bias, allowing for a more human-like matching process while maintaining a legal backbone that remains auditable and enforceable.

In the event of a dispute or suspected breach of contract, the system may provide a tiered resolution framework.

Disputes could be flagged by either party and accompanied by supporting evidence, such as images, sensor data, or testimonials. A built-in AI adjudication system-potentially based on large language models—may evaluate the original contract, structured terms, and submitted evidence to propose a resolution. This resolution may include outcomes such as refund calculations, corrective actions, or redistribution of escrowed stakes. If the parties remain unsatisfied with the automated ruling, the case could escalate to additional review tiers. These may include peer adjudication panels drawn from a vetted human pool, extended document-based review processes, or certified arbitrators acting under applicable legal frameworks. Escalation tiers may be associated with increasing costs and timeframes, and financial penalties or rewards could be tied to the outcomes of such reviews in order to discourage frivolous appeals.

The platform may also support a variety of fairness protections to ensure trust and integrity within the system.

Reputation scores for agents could be updated based on dispute outcomes, and repeated violations might result in increased fees, reduced contract visibility, or temporary bans. Contract value scaling mechanisms could allow the system to handle both micro-contracts and high-value agreements with proportional resources, enabling broad market accessibility.

Architecturally, the system could be composed of several interacting modules. These might include a registry for templates, a signing engine for instantiating contracts, a marketplace interface for offer discovery and filtering, and an agent communication protocol that allows secure, standardized message exchange. Monitoring components may track contract performance using external signals such as IoT sensors, third-party confirmations, or user feedback. Logging modules might record each stage of contract formation, fulfillment, and breach processing in a secure, immutable manner, enabling retrospective audits and compliance validation.

The agents themselves could reside on user devices, in private cloud deployments, or on third-party platforms offering agent-as-a-service functionality. These hosted agents may include preference modeling systems, reputation filters, and adaptive negotiation modules, and could operate independently or in coordination with other agents. The platform may support these external integrations by providing well-defined APIs and semantic ontologies for service classification, ensuring that agent behavior remains consistent across implementations.

In addition to core execution capabilities, the platform may enable agents to evaluate contract offers based not only on price or terms, but also on the presence and quality of breach resolution clauses. These clauses could specify automatic remedies for specific service failures, such as partial refunds, compensatory extensions, or automated rebookings. Agents might weigh such clauses heavily when selecting among competing offers, as strong enforcement terms could signal supplier reliability. Templates may therefore incorporate standard fields for such clauses, allowing for comparison across offers and encouraging suppliers to differentiate themselves through transparent, proactive quality assurance.

The online deal making and enforcement platform described herein could thus offer a foundation for a new class of digital commerce, in which trust is embedded in code, decisions are guided by intelligent agents, and enforcement is handled in an efficient, scalable, and programmable manner. The invention may find application in domains such as travel, accommodation, transportation, utility services, freelance labor, or other sectors where service agreements are frequent, parameterized, and often subject to failure or ambiguity. Through its combination of machine-readable templates, autonomous agent execution, and multi-level dispute resolution, the system could enable a more efficient, fair, and user-aligned marketplace.

An autonomous agent may generate a contract offer by populating a standardized template with instance-specific parameters, such as time windows, price, service descriptions, and optional terms. Once complete, the agent could transmit the offer to the platform server via an authenticated API endpoint. This submission may include the agent's digital signature, the hash of the populated contract, a reference to the template version, and an optional escrow deposit amount. The server may validate the offer's structure against the registered template schema and verify the agent's signature using its associated public key. If valid, the platform could post the offer to a public or semi-public offer registry, marking it with metadata such as offer expiry, reputation requirements, and searchable tags. Other agents, operating on behalf of potential counterparties, may periodically or continuously query the server for active offers using criteria such as service type, date range, location, pricing thresholds, or embedded quality-of-service clauses.

Upon identifying a suitable offer, a receiving agent could download the contract payload and verify the integrity of its contents, including the template ID hash, parameter fields, and origin signature. If the receiving agent determines that the offer aligns with its principal's preferences, it may countersign the contract using its own private key and resubmit the now fully executed contract to the server via a designated signing endpoint. This second submission may include a mirrored escrow amount, which could be held by the platform in a secure smart escrow subsystem. The escrow logic may specify that funds are held until contract execution is verified, and could define conditions under which the escrowed value is refunded, partially released, or transferred as compensation in the event of breach.

The platform may lock the contract upon receipt of the second valid signature, preventing further modifications or acceptance by third parties. From that moment, the platform may treat the contract as active and initiate the contractual lifecycle, including triggering downstream service execution systems, monitoring fulfillment conditions, and enabling access to the dispute resolution interface. Throughout the process, all communication and contract transitions could be logged in an immutable ledger or audit log, preserving a tamper-evident record of negotiation, signing, and escrow engagement.

This system includes software modules for template rendering, structured data ingestion, cryptographic signature verification, and AI-mediated judgment. The marketplace interfaces with agents that perform matching and selection based on real-time parameters and owner utility functions. Templates include fallback clauses to guarantee quality-of-service remedies and automate post-incident processing. By combining traditional legal contract structures with autonomous execution and real-time arbitration layers, the system supports scalable trustless contracting at global scale.

An individual may configure their autonomous agent to secure a car rental in a specific location-such as Berlin—for a defined time window, for instance from July 1st to July 5th. The agent could access the exchange interface and query available offers that match the required date, location, and service category. The results might be filtered and ranked by criteria such as total rental cost, included fuel policy, distance to pickup location, reputation score of the provider, and informal metrics such as visual appeal or brand sentiment. Among the available options, the agent may select a mid-size sedan offered by a provider—such as AutoFast GmbH—that includes favorable reviews and an embedded breach clause stipulating a 10% refund in the event of pickup delays. Upon selecting this offer, the agent could sign the contract and submit it to the platform along with an escrow amount, for example 150 EUR. The provider's backend system, acting through its own agent, may then countersign the agreement. The platform may timestamp the completed contract, lock it, and issue a confirmation to both parties. If, upon scheduled pickup, the vehicle is delivered with a delay-such as 35 minutes—the user's agent may flag a potential breach. The platform's AI judge could assess GPS or time log data to confirm the delay and, based on the embedded clause, process a partial refund (e.g., 15 EUR) to the user, directly from escrow or via platform-mediated reimbursement.

In another scenario, a traveler may instruct their AI agent to secure a hotel room that includes a quality-of-service clause-such as a guarantee of functioning air conditioning, with a full refund and paid relocation in case of failure. Upon arrival, if the guest discovers that the air conditioning unit is inoperative, they may capture timestamped video evidence and submit a breach report via the platform interface. The AI adjudication engine could validate the evidence, match it against the original clause, and execute a remedial action-such as rebooking the guest to a nearby partner hotel and refunding the original cost, including any necessary transport charges. Should the hotel provider contest the ruling, the case may escalate to the first tier of human peer review. A randomly selected panel-such as five vetted reviewers—may be asked to evaluate the case. If, for example, four of the five reviewers uphold the AI's original determination, the platform could finalize the outcome, charge the provider for incurred costs and a nominal penalty, and apply a slight reduction to the provider's public reputation score.

In a broader, ongoing use case, an AI agent representing an expatriate user may autonomously manage a portfolio of life services, including internet subscriptions, mobile phone plans, and public transportation passes.

These contracts could be negotiated, signed, and monitored without direct human intervention. The agent may regularly scan for improved offers in the background and evaluate them against current commitments. When a superior offer becomes available-such as a mobile plan with better pricing and terms—the agent might initiate a migration, provided that the termination of the current contract falls within policy allowances. In some cases, the agent may analyze the fine print using natural language processing techniques and detect clauses that are unfavorable, such as hidden roaming fees. If the risks are deemed unacceptable, the migration could be aborted preemptively. Through this continuous background process, contracts may be updated, renegotiated, or terminated with minimal user input, while the platform ensures that any required termination fees are processed appropriately and that provider behavior aligns with contractual obligations.

These scenarios illustrate how the online deal making and enforcement platform could support seamless automation, enforceability of negotiated clauses, and multi-layered fairness mechanisms, all while maintaining agent autonomy and reducing friction for end users.

The following workflow may serve as an illustrative embodiment of how the disclosed platform operates in practice, using a car rental scenario as a representative use case. While the specific domain referenced here is vehicle rental, the same structural logic could apply to other sectors such as hotel reservations, healthcare appointments, transportation bookings, or telecommunications subscriptions. The underlying process-beginning with contract offer creation and continuing through agent-based filtering, selection, digital signing, execution, validation, and potential dispute resolution—may remain constant, while the specific content of the contract templates and associated resolution logic may vary depending on the domain. For instance, a template parameter such as “vehicle type” could become “room category” in a hotel context, and breach remedies such as “rebooking” might instead imply “rescheduling” or “compensatory credit” in other sectors.

This modularity may support industry-wide interoperability and adoption.

A car rental provider may configure its autonomous agent to generate and submit contract offers to the platform.

Each offer may reference a specific version of a standardized rental contract template and include structured parameters such as pickup and drop-off locations, time windows, vehicle specifications including number of seats or fuel policy, pricing conditions, embedded insurance coverage, and optional breach resolution clauses.

Informal descriptors-such as vehicle cleanliness, aesthetic appeal, or historical review data—may also be appended. The offer may be signed using the provider's digital key and posted to a central or federated contract exchange. Upon submission, the offer could become publicly visible and indexed according to parameters including geographic location, availability window, and categorical match to potential consumer needs.

Consumer agents, operating either locally or via cloud infrastructure, may access the platform's contract registry and scan available offers. Filtering may occur based on a combination of formal constraints, such as required seating capacity, drivetrain type, or fuel policy, and informal preferences, including subjective aesthetics, brand perception, or noise levels. The agent may use multi-criteria decision functions to score and rank offers according to the user's weighted preferences, considering factors such as supplier reputation, embedded breach terms, and estimated fulfillment reliability. Once an optimal offer is identified, the consumer agent may sign the contract digitally and transmit the completed payload to the platform, thereby locking the contract and activating it. Where applicable, both parties may be required to deposit staking or escrow funds, which are held securely until successful contract fulfillment or adjudication.

The contract execution phase may involve the renter arriving at the pickup location and performing check-in via self-service interfaces, potentially supported by digital lock mechanisms, platform-issued access codes, and real-time photographic verification of vehicle condition. During the rental period, onboard sensors-such as GPS modules, diagnostic interfaces, and visual monitoring systems—may record vehicle metrics, including odometer readings, fuel levels, and any incidents such as abrupt stops or collisions. These data streams could be used to validate return conditions and detect violations. Upon contract expiration, the vehicle may be returned to the agreed location, triggering automated condition assessment using sensor logs or user-submitted media. If all contract terms are satisfied, the system may close the contract, release the escrowed funds, and finalize the transaction. In the event of deviation-such as late return, underfilled fuel tank, or physical damage-predefined breach clauses may be invoked and resolution procedures initiated.

Should either party report a breach, the platform may allow for submission of timestamped evidence, with the counterparty receiving notification and an opportunity to respond. The AI adjudication engine, equipped with access to the contract, its parameters, signatures, and evidentiary materials, may evaluate the dispute and apply automated remedies as defined by the embedded terms. These may include refund issuance, damage penalties, or alternative service reimbursement. If a party challenges the AI's decision, the case could escalate to a higher-resolution tier, such as a randomized human jury, a peer review panel, or certified arbitrators. Escalation outcomes may include financial adjustments to staked amounts, redistribution of penalties, and updates to party reputation scores. All decisions rendered by the platform's adjudication hierarchy may be considered binding under the contract's terms, with no further recourse beyond the agreed-upon process.

The platform itself may act as a neutral enforcement intermediary, possessing authority to implement and finalize outcomes rendered by the resolution subsystem. At the time of contract engagement, users may agree that all rulings issued by the embedded resolution mechanisms-whether automated or escalated—are final and enforceable. To support financial enforcement, the platform could require staking of fiat or digital currency, dynamically calculated based on contract value or risk class. These stakes may be used to cover compensatory payments, platform fees, replacement costs, or bonuses for verified fulfillment. In some implementations, the platform may insert itself as counterparty to both contracting parties, functioning similarly to centralized financial exchanges. In doing so, it could maintain control over funds, arbitration, and execution, while optionally collecting a coordination or brokerage fee.

Contracts instantiated on the platform may be derived not only from machine-readable templates, but also from canonical human-readable versions written in natural language. These documents may resemble conventional legal contracts, containing clearly defined clauses and embedded placeholders for dynamic fields such as dates, prices, or service parameters. This dual-format architecture may ensure that contracts are simultaneously accessible to AI agents and legible to human users, legal professionals, and regulatory auditors. Templates may be rendered in formats such as JSON or XML, with each field linked to an explanatory label or reference to the original human-readable clause. This structure could allow a user's personal LLM or digital legal advisor to interpret the contract, explain its contents, and highlight potentially unfavorable terms prior to signature. The use of signed and hashed template versions may guarantee that machine-parsed instances correspond to agreed-upon textual clauses, thereby improving trust, transparency, and enforceability.

To further strengthen the evidentiary integrity of the platform, all multimedia submissions used in support of breach claims may be required to include verifiable provenance. Techniques such as hardware-level signing, timestamping, location verification, or digital watermarking could be employed to establish authenticity at the point of capture. For example, trusted camera modules or mobile devices with secure enclaves may embed tamper-resistant metadata into photos or videos submitted to the platform. These materials may be processed through platform APIs that verify origin, integrity, and timestamp validity. Evidence failing to meet established provenance criteria may be flagged as low-trust or rejected entirely, depending on the terms of the contract. This integrity layer may prevent manipulation via synthetic content, such as deepfakes, and enhance reliability in the autonomous resolution of contractual disputes.

In sum, the disclosed system may provide a full-spectrum solution for autonomous contract negotiation, fulfillment, enforcement, and resolution, offering a modular framework adaptable to a wide range of services.

Through the integration of agent-mediated offer exchange, machine-readable templates anchored in human-readable legal forms, programmable dispute clauses, and provable multimedia evidence pipelines, the invention may support a new generation of fair, efficient, and self-enforcing digital agreements.

The embodiment can be described by the following itemized list, illustrating various aspects and configurations of the system in suggestive terms:
1. A method may be provided for autonomous agent-mediated contract execution, wherein a marketplace may receive a plurality of standardized contract templates, each template potentially being selected and populated by a first AI agent with contract-specific parameters. The resulting contract could then be cryptographically signed by the initiating agent and posted to either a centralized or decentralized contract exchange. A second AI agent may discover and evaluate the signed contract and, upon alignment with internal criteria, may countersign the contract. The platform could then lock the contract upon receipt of the first valid counter-signature and initiate execution of the underlying service as described in the agreed terms.
2. The method described above may support the inclusion of both formal descriptors—such as time, price, or location—and informal descriptors, which could encompass aesthetic qualities, sentiment-based evaluations, or user-generated content.
3. The method may further comprise an automated dispute resolution process, potentially implemented through a multi-tier system in which initial evaluation is performed by an AI model and higher tiers involve human or hybrid review mechanisms.
4. In some embodiments, the informal descriptors referenced above may specifically include visual attributes, such as color schemes or perceived cleanliness, and sentiment indicators derived from textual reviews or machine-generated scores.
5. The multi-tier dispute resolution system may include a first escalation tier comprising a randomly selected panel of reviewers—such as a microjury of five vetted individuals-who may receive anonymized dispute summaries and render a verdict within a predetermined timeframe.
6. The platform's enforcement logic may be configured to apply progressively increasing penalties for repeated violations by a given party, wherein the scaling of such penalties could be exponential or otherwise non-linear in nature.
7. An AI contract exchange platform may comprise a registry of versioned contract templates accessible to autonomous agents, an API interface enabling structured querying and posting of contract offers, a smart escrow engine for holding pre-execution stakes from participating parties, a subsystem for detecting potential contract breaches, a resolution engine incorporating a large language model or equivalent system for arbitration, and a contract lock mechanism that may bind and timestamp the first two signatures received for any given agreement.
8. The platform described above may support the inclusion of breach resolution clauses directly within posted contract templates, wherein such clauses could be automatically parsed and enforced by the system without requiring human intervention.
9. Agents interacting with the platform may maintain internal scoring or heuristic models that evolve based on historical case outcomes, user preferences, or contextual factors, allowing for adaptive contract evaluation and offer selection.
10. A supplier-side method may allow for the bulk posting of pre-signed contract offers using parameterized templates, such that user agents could select and countersign appropriate offers without further negotiation or delay.
11. A user-side method may allow an AI agent to evaluate available offers by applying utility heuristics defined by the user, wherein both formal parameters (such as cost or timing) and informal descriptors (such as sentiment or brand perception) may be factored into the agent's decision function.
12. A method may be employed whereby human reviewers assigned to the first escalation tier are presented with anonymized, contextually relevant dispute data and are required to issue a verdict within a defined temporal window, such as six hours.
13. A further method may include dynamic integration of breach or dispute histories into a cumulative trust score associated with each supplier, wherein such scores may influence visibility of future offers and determine required stake amounts for posting.
14. A method may be implemented in which the platform itself assumes the role of counterparty to both contract signatories, thereby acting as a centralized clearing authority, analogous to mechanisms employed in traditional financial markets such as stock or options exchanges, and providing guarantees of enforcement and finality.

### Embodiment D: System and Method for Collective Grievance Discovery and AI-Mediated Reputation Analysis

The present invention relates to systems and methods that could facilitate the discovery of shared grievances and the analysis of service provider reputations using artificial intelligence. It may provide a technological framework whereby individuals or their AI agents could submit complaints in structured or natural language form, allowing the system to identify similar reports, match affected parties, and enable coordination among them. This coordination may lead to class action efforts, group refunds, or other forms of collective remedy, possibly supported by participating legal professionals or NGOs. The invention could further incorporate reputation scoring functionality, enabling AI agents to proactively assess service provider reliability prior to future engagements.

In one embodiment, a user or their AI agent may initiate the process by submitting a complaint via a portal or agent interface. This submission may include structured metadata such as location, timestamp, service provider identity, and grievance type, along with optional documentation such as invoices, contracts, or correspondence.

The system may also support unstructured entries, which could be interpreted by a language model trained to extract meaningful features for downstream analysis. Consent settings may be configurable at the time of submission, specifying conditions under which the complaint may be matched, shared, or escalated.

A discovery engine may then evaluate complaint similarity, using natural language embeddings or metadata analysis to identify latent correlations. The architecture for this discovery process could be either centralized or distributed, depending on performance and privacy requirements. Once a sufficient number of comparable complaints are detected, the system may generate a proposed group cluster, assigning a unique identifier and optionally creating a secure collaboration link. The AI agent representing each user may prompt for additional consent before initiating contact with other affected individuals or their respective agents.

Upon user approval, secure channels may be opened for communication among participants, allowing the exchange of documents, messages, or strategy proposals. The system may maintain audit trails and allow optional pseudonymity to protect user identity until stronger trust is established. Legal professionals may gain access to group identifiers upon satisfying criteria such as verified identity or bar association registration. They may then offer representation under terms defined by the users or propose pathways toward collective redress.

Legal coordination may occur through a dedicated interface that could support evidence review, document submission, or offer negotiation functionalities.

An embedded trust engine may assess the reputation of implicated service providers by aggregating complaint frequency, severity, resolution quality, and the reliability of sources. This score may then be queried by personal AI agents seeking to evaluate the risk of engaging with a given service. Reputation data may be weighted based on potential conflicts of interest, which could be inferred from known affiliations, shared financial interests, or network ties. The system may allow users to set thresholds for sensitivity to bias, ensuring that recommendations reflect personalized trust calibration.

In an exemplary flow, the system may accept a complaint, normalize it, and match it to similar entries. Upon identifying peers, it may seek consent for group inclusion, generate a shared session or group ID, and notify legal entities once a predefined quorum is reached. Coordination may continue via secure communication channels, allowing for efficient organization and potential escalation into formal legal actions.

In one use case, a property co-owner may submit a complaint concerning unilateral fee increases. Their AI agent could detect that multiple owners have experienced the same issue, prompting a coordinated objection to the property manager. In another case, travelers affected by an airline cancellation may be matched by their respective agents, allowing evidence sharing and legal coordination for compensation claims. A third scenario may involve repeated complaints against a rental agency, triggering early warnings to future users and facilitating the pursuit of refunds by past victims.

The system could be implemented on conventional server infrastructure or via decentralized networks. Blockchain-based variants may offer tamper-proof audit logs, while zero-knowledge proofs could provide privacy-preserving peer discovery. Digital wallets may enable users to contribute funds toward group legal actions or hold escrowed compensation. Integration with civic databases, property registries, or bar association APIs may enhance identity verification, legitimacy, and access to formal recourse.

Software components may include a non-transitory computer-readable medium storing instructions executable by a processor to carry out key functionalities. These may comprise complaint ingestion and classification, peer matching based on content similarity, consent-based information sharing, group ID generation, communication orchestration among AI agents, and service reputation computation. AI coordination modules may further support visualization, multilingual support, automated conflict detection, and legal simulation tools to preview potential outcomes.

The system may offer advantages over prior art by uncovering latent group grievances that might otherwise remain unresolved. Unlike typical review platforms, it could leverage structured discovery, context weighting, and verified data pipelines to deliver higher trustworthiness and legal utility. It may empower users with proactive defenses against unreliable providers, strengthen the possibility of organized redress, and support transparent interactions through AI-enhanced trust mechanisms.

Future enhancements may include real-time alerts when new complaint clusters form, integration with civic notification systems, or gamified incentives to encourage complaint submission. Early dispute resolution modules could mediate settlements before escalation, reducing legal burden and improving user experience. The system may continue evolving to cover new domains such as medical malpractice, environmental harm, or workplace disputes.

By enabling collective intelligence and secure AI coordination, the invention may restore power to isolated individuals facing systemic issues. Through structured discovery, informed consent, and legal coordination, it could help ensure transparency, accountability, and fair treatment across a wide range of service interactions.

The invention may be described by the following itemized list: A system that could enable the discovery of individuals with shared grievances by allowing the submission of complaints and performing similarity analysis to identify commonalities among them.

The system of item 1, wherein a complaint may be submitted in either a structured or unstructured format, and natural language processing could be employed to extract relevant information from the content.

The system of item 1, wherein individuals identified as having related complaints may be assigned a shared group identifier to facilitate coordinated interaction.

The system of item 3, wherein the shared group identifier could be used to access a collaborative coordination space for communication, evidence sharing, or legal preparation.

The system of item 1, wherein personal AI agents may negotiate or solicit user consent prior to engaging in data sharing or group formation activities.

The system of item 1, further comprising a legal coordination interface that may be made accessible to law firms, legal aid groups, or advocacy organizations seeking to review or support group claims.

The system of item 6, wherein legal entities may use the interface to propose representation of the group, signal interest, or submit documentation relevant to group claims.

The system of item 1, wherein a reputation score for a service provider may be calculated based on aggregated data from user-submitted complaints, including their frequency and nature.

The system of item 8, wherein the reputation score may be further influenced by the resolution status of each complaint, the perceived trustworthiness of the reporting users, and any follow-up actions taken.

### Embodiment E: Decentralized Peer-to-Peer Service Discovery Protocol for Autonomous AI Agents

The present invention may relate to the field of agent-based computing and artificial intelligence systems, and more specifically, it could involve techniques that enable decentralized, peer-to-peer service discovery among autonomous digital agents. The proposed method may find application in distributed AI ecosystems, networks of service-oriented agents, and privacy-preserving digital infrastructures where centralized discovery is undesirable or infeasible.

In prevailing technological contexts, artificial intelligence systems commonly rely on centralized infrastructures-such as curated marketplaces, web search engines, or fixed registries—for the discovery and invocation of external services. Such models may impose constraints on adaptability, robustness, and scalability, and could introduce vulnerabilities related to censorship, manipulation, or failure of central authorities. These centralized dependencies may also hinder user autonomy and reduce the diversity of accessible services.

Accordingly, there exists a potential need for a system that could permit autonomous agents to discover services in a decentralized and context-aware manner, possibly by exchanging curated service lists, inferring trust through social or historical signals, and forming dynamic trust graphs. The present invention may address these needs by introducing a protocol through which agents may request and share structured information about services they trust, use, or endorse, thereby enabling peer-to-peer enumeration and discovery.

According to one aspect, the invention may enable agents to issue structured or semi-structured requests for service lists rather than querying for a single known service. These requests may include category filters or other contextual constraints. In response, peer agents could return structured enumerations of service metadata, including functional descriptions, semantic tags, access endpoints, interface protocols, and optional indicators of trust or usage. The requesting agent may then evaluate the received options using a locally defined trust model or decision policy, which could factor in semantic relevance, past experiences, or the social proximity of the recommending agent.

Each participating agent in the system may include several architectural components that facilitate this interaction. A local data store may retain structured records of previously encountered services and associated metadata. A trust graph may model the social or historical trust relationships between agents and services, potentially including interaction scores, endorsements, and contextual confidence signals. A communication module may facilitate the sending and receiving of requests, replies, and other protocol messages. Filtering and policy modules may determine which services to reveal in response to enumeration requests, based on privacy constraints, reputational heuristics, or internal agent policies.

Each service entry maintained by an agent may be described by a structured schema that includes a unique identifier or canonical name, a machine- or human-readable description of its functionality, one or more semantic tags indicating its domain (e.g., health, legal, logistics), and a URI or endpoint through which the service may be accessed. This schema could also include details about the communication interface, such as REST, GraphQL, or custom protocols, and may specify authentication methods or other requirements for invocation. Additional metadata fields may describe endorsements, trust anchors, or usage statistics relevant to evaluating the service.

The messaging protocol supported by the invention may include various message types. A service enumeration request may include agent identifiers and optional filters, and may prompt a responding agent to return a service enumeration response. That response could list trusted or available services, potentially filtered or prioritized according to internal agent rules. The requesting agent may then issue a service usage request to obtain access credentials or invoke the service directly. In some cases, a trust provenance query may be issued to retrieve information on the origin of a service recommendation, while a conflict-of-interest message could optionally expose known relationships or dependencies that may influence trust assessments.

All agent-to-agent communication may be secured using cryptographic techniques, including encryption, digital signatures, and optionally routed through decentralized messaging layers. Privacy-preserving features could include the use of ephemeral identifiers, partial disclosure of metadata, and differential response policies depending on the trust level of the requester. The system may also support natural language message exchange, interpreted by embedded large language models, thereby enabling interaction with agents or services that are described only in human language or loosely structured data.

The system could further support advanced optional features, such as the use of federated or local trust anchors, anonymous or pseudonymous agents, agent-to-agent micropayment systems for sharing valuable referrals, and refusal codes that explain why a service was not revealed. Zero-knowledge proof mechanisms may also be employed to share verifiable summaries without revealing full service details.

Practical applications of the invention could span numerous domains. In health care, agents might share diagnostic services or treatment recommendation engines. In the legal sector, agents could assist in locating contract automation tools or litigation participation portals. In finance, agents may recommend trusted financial planners or automated advisory tools. In logistics or advocacy contexts, agents may facilitate the coordination of users with overlapping needs or concerns, such as shared grievances against a service provider.

The invention offers several advantages. It may increase transparency and trust in agent-mediated service discovery. It may simplify the process of uncovering niche or emergent services without reliance on centralized advertising or curation. It could also promote organic service propagation through peer validation and contextual relevance. Most notably, it may reinforce user sovereignty by enabling agents to discover and recommend services without requiring disclosure of their users' queries or intents to a central platform.

The embodiment could be described by the following itemized text:
1. A method for decentralized service discovery could comprise the steps of an agent transmitting a service enumeration request to another agent and receiving in response a list of known services.
2. The method of item 1 could include that the list of services comprises metadata such as a service name, a description, a semantic category, an access type, an interface specification, and one or more trust indicators.
3. The method of item 1 could further comprise that the receiving agent applies one or more privacy filters or policy-based constraints to determine which services are included in the returned list.
4. The method of item 1 may further allow that the response includes services that are either hosted locally by the responding agent or otherwise known through previously established trust with third-party agents.
5. The method of item 1 could include that the list of services incorporates trust-related data computed from a weighted trust graph.
6. A method for evaluating received services could comprise applying semantic filtering based on contextual requirements or user preference vectors.
7. The method of item 6 may employ a learned model or vector embedding to match service descriptions with contextual needs.
8. The method of item 6 could further involve ranking candidate services based on usage metrics, endorsement history, or inferred quality indicators.
9. A system could be composed of a plurality of agents each configured to perform the decentralized discovery method described in item 1.
10. The system of item 9 may include that each agent maintains both a local registry of known services and a dynamically updated trust graph.
11. A message protocol may be defined to include at least a service enumeration request message, a service enumeration response message, and a service usage request message.
12. The message protocol of item 11 could further include a trust provenance query message and a conflict-of-interest alert message.
13. A computer-readable storage medium may contain instructions that, when executed by an agent computing system, cause it to transmit and process messages in accordance with the protocol defined in item 11.
14. A method for propagating trust information could involve agents sharing reputational metadata and service endorsements with one another.
15. The method of item 14 may compute trust values using a combination of social signal weighting, endorsement counts, and contextual relevance metrics.
16. The method of item 14 could additionally compute conflict-of-interest information based on factors such as agent ownership, organizational affiliation, or recorded behavior patterns.
17. A communication system may be defined wherein all agent-to-agent messages are cryptographically signed and routed through a decentralized messaging infrastructure.
18. The system of item 17 may ensure message confidentiality through end-to-end encryption or other cryptographic protections.
19. A method could enable agent-mediated invocation of a remote service that was discovered via another agent's registry.
20. The method of item 19 may include a negotiation phase wherein the invoking agent acquires routing information or access tokens from the providing agent.
21. A hybrid message parsing system could be implemented wherein agents are capable of interpreting both structured protocol messages and unstructured natural language service descriptions.
22. The system of item 21 may utilize language model-based semantic interpretation to enable the handling of vague, informal, or incomplete service requests.
23. A system for distributed trust graph formation could enable agents to update the weights of trust relationships based on the observed success or failure of past service interactions.
24. The system of item 23 may further support propagation of trust changes through peer networks by means of referral-based transitive updates.
25. A decentralized registry could be formed dynamically through peer-to-peer message exchange, thereby avoiding dependence on any centralized indexing service.
26. A method for privacy-preserving service sharing could allow agents to transmit zero-knowledge proofs asserting possession of service knowledge without revealing identity or service details.
27. The method of item 26 may generate said zero-knowledge proofs using one or more established cryptographic protocols.
28. A method for access throttling or selective refusal may be implemented wherein agents reply to incoming requests with structured refusal codes.
29. The method of item 28 could include that refusal codes communicate specific reasons, such as policy non-compliance, failed authentication, or semantic mismatch between request and service offering.
30. A method for local service caching may allow an agent to retain metadata of previously discovered peer services and to periodically validate or refresh the data to maintain accuracy.

### Embodiment F: System and Method for Booking Passenger Travel with Decoupled Luggage Transport

In conventional airline travel, luggage is typically transported together with passengers on the same aircraft, which may result in increased fuel consumption, delayed boarding, complex baggage handling logistics, and environmental inefficiencies. There exists a need for a system that could decouple passenger transport from luggage logistics in a seamless manner, potentially improving both sustainability and convenience.

The present invention may enable a system that facilitates the integrated booking of human travel and decoupled luggage delivery, wherein a unified interface could allow users to reserve a flight while simultaneously arranging separate luggage transport. The luggage transport may utilize alternative modes, such as rail freight, ground delivery, or cargo air services, selected dynamically for cost-efficiency, delivery time, and environmental impact. The system may calculate optimized combinations and display a bundled offer that includes both flight details and estimated luggage delivery metrics. This itinerary may further support direct delivery to the user's hotel, accommodation, or another specified final address.

A backend platform could be configured to integrate a flight booking API for retrieving and reserving passenger flights, a logistics interface for querying available luggage transport services, a coordination module for aligning luggage delivery with passenger arrival times, and a front-end user interface that allows for a combined booking experience. Upon receiving a travel request from a user or delegated digital agent, the system may retrieve potential flight options and concurrently compute optimal luggage delivery schedules. The system could evaluate eligible logistics providers based on cost, CO₂ emissions, reliability metrics, and capacity, and may rank available options accordingly.

Once candidate itineraries are identified, the system may present the user with a bundled offer that could include live flight availability, estimated luggage delivery times, a breakdown of associated emissions versus conventional transport, and total combined cost. Upon user confirmation, the system may proceed to book both the flight and the selected luggage transport, forwarding relevant confirmations and instructions to the respective service providers. Reference numbers and receipts might be stored in a centralized database and made accessible to the user.

The luggage transport component may be executed through a network of approved drop-off centers or scheduled home collection services. Identity verification during pickup and drop-off could be accomplished via digital ID scanning, biometric authentication, or QR code-based tagging. The luggage itself may be tagged using secure digital or optical identifiers to ensure continuous traceability throughout transit. The backend could store each tag's movement history and provide real-time tracking data to the user.

The coordination module may dynamically adapt the luggage delivery schedule based on updated flight arrival times or hotel check-in windows. In the case of flight delays, the system could reschedule the corresponding luggage handoff automatically. A rules engine or machine learning module may be used to calculate the optimal delivery path using historical transport data, predictive delay models, and user-configured preferences such as lowest environmental impact, fastest delivery, or lowest cost.

Environmental impact calculations may rely on standardized transport emissions data, which could be integrated via public or private emissions databases. The system might compare the calculated CO₂ footprint of traditional luggage-on-flight handling with alternative multimodal transport routes and display this comparison to the user at the time of booking to encourage eco-conscious choices.

For cross-border deliveries, customs declarations could be requested during the booking process. These declarations may be formatted into compliant digital documents and transmitted either to the logistics provider or directly to relevant customs authorities using API-based protocols, where available. The system may also facilitate additional services such as insurance, loss protection, and destination-specific delivery enhancements.

The user interface may support account login and profile management, selection of departure and destination cities, entry of luggage weight and dimensions, and selection of optional services such as insurance or customs assistance. The platform may be implemented as a responsive web application or native mobile application and could support both manual interaction and API-based agent automation.

From a technical standpoint, the backend system could be deployed on a cloud infrastructure platform such as AWS or GCP, and data could be stored using relational or NoSQL databases such as PostgreSQL or DynamoDB. RESTful APIs may be used to interface with third-party flight aggregators (e.g., Amadeus, Sabre) and logistics services (e.g., DHL, FedEx, rail or regional courier networks). Authentication could be handled using OAuth 2.0 and OpenID Connect protocols, while transaction data may be cryptographically signed for security and non-repudiation.

Payment handling might be conducted through a single checkout interface that processes the total amount for both the flight and the luggage transport, possibly utilizing an integrated payment gateway or escrow system.

The funds may then be disbursed to the respective service providers according to predefined terms or dynamic contractual logic, which may optionally include smart contract enforcement.

In some embodiments, the system could act as a contract broker that establishes and enforces service-level agreements between users, airlines, and logistics providers. A coordination interface may be exposed to hospitality systems such that hotels could be notified of incoming luggage and prepare accordingly. The system architecture may be modular, with plugin modules enabling integration with additional travel-related services, such as airport shuttle reservations, mobile SIM cards for arrival, or carbon offset programs.

Deployment of the system could begin with regional pilots using a limited set of routes and a single logistics provider, and may scale globally through strategic partnerships with airline alliances, travel aggregators, and freight consortiums. The invention could be implemented entirely in software using commercially available technologies, without requiring novel hardware. All functional modules may be embodied in machine-readable instructions stored on computer-readable media, and may be executed by standard computing equipment.

This description suggests that the invention is fully enabled, technically feasible, and may be implemented with current APIs, transport infrastructure, and payment technologies, offering a practical pathway toward more sustainable and efficient travel logistics.

The booking process disclosed herein may proceed through a sequence of coordinated user interactions and backend system operations, enabling the combined reservation of passenger air travel and a decoupled luggage transport service. In a typical embodiment, the process may begin when a user accesses a digital interface, such as a web-based or mobile application, and provides basic travel parameters, including departure and destination locations, intended dates of travel, and passenger details. The system may further allow the user to indicate a preference for separating luggage transport from the flight booking, thereby initiating the logistics evaluation component.

Upon selection of the decoupled luggage transport option, the system may prompt the user to input additional baggage-specific parameters, such as the number of items, estimated weight and volume, preferred pickup location (which may be a home address, office, or authorized drop-off point), and the delivery destination. The system may also allow for the specification of a preferred delivery window and the prioritization of optimization parameters including delivery speed, cost, or environmental impact.

The backend platform may then initiate parallel operations. A flight search module may query airline booking APIs to retrieve available flights based on user-specified constraints. In parallel, a logistics evaluation engine may query a plurality of logistics providers to identify viable luggage transport routes between the user's pickup location and delivery destination. These routes may be filtered and ranked based on a variety of criteria, such as estimated delivery time, cost, emissions profile, customs requirements, and service reliability. Historical data, predictive models, and provider-specific performance metrics may inform this evaluation.

Once flight and logistics options are retrieved, the system may generate one or more bundled travel packages.

Each package may include a proposed passenger flight itinerary, an associated luggage transport plan, estimated delivery times, comparative emissions savings versus conventional checked baggage, and a unified total cost.

The user may then review and accept a selected package, at which point the system may proceed to execute a combined transaction through a secure payment gateway. Upon payment confirmation, the system may reserve the passenger flight and simultaneously book the logistics service, issuing confirmation references for both components.

Following the confirmed booking, the system may provide the user with a unique identifier for each piece of luggage, which may be implemented as a scannable QR code, RFID tag, or digital token. The user may receive instructions for luggage handoff, either via home pickup or drop-off at a designated facility. Identity verification protocols may be triggered at this stage, potentially involving biometric scanning, government-issued ID upload, or digital authentication through a secure session.

As the trip progresses, the system may coordinate all relevant timeline events. In the case of changes to the passenger's itinerary, such as flight delays or rebookings, the backend coordination module may recalculate the expected arrival time and dynamically adjust the logistics delivery window to maintain synchronization.

Notifications may be generated and dispatched to the user at relevant milestones, including confirmation of flight check-in, luggage pickup, customs clearance (if applicable), out-for-delivery status, and successful luggage handoff at the destination.

In cases where the final delivery location corresponds to a hotel or accommodation, the system may interface with the property's management system to coordinate delivery timing in accordance with standard check-in policies. A notification may be sent to hotel personnel when luggage is en route, and receipt confirmation may be captured upon arrival through a scan or signature process.

Customs declaration processes may be initiated automatically if the luggage is expected to cross international borders. During the booking flow, the system may prompt the user to complete standardized customs forms, which could then be converted into compliant formats and transmitted to customs authorities via an integrated API or through digital submission protocols agreed upon with the logistics provider.

All data related to the booking transaction, including user identity, travel and delivery preferences, payment records, and logistics metadata, may be stored in a centralized transaction database. This database may support both operational tracking and auditability. Security protocols may ensure the confidentiality and integrity of the data, potentially including encryption, digital signatures, and access control mechanisms.

The system may also act as a digital contract facilitator between the user, airline, and logistics provider, optionally enforcing service-level agreements using either conventional terms or smart contract mechanisms.

Funds collected during the unified checkout process may be distributed according to negotiated terms with each provider, potentially using escrow or automated release protocols upon confirmation of service completion.

The entire architecture may be modular, with service plugins supporting integration of additional travel-related offerings such as airport shuttles, SIM card activation on arrival, carbon offset subscriptions, or travel insurance.

The invention may be deployed in a limited geographic region for initial validation and subsequently expanded through partnerships with airline alliances, booking platforms, and international freight networks.

All software modules enabling the process may be embodied in computer-readable instructions stored on a tangible medium and executed by one or more processing units connected to cloud infrastructure. The implementation may utilize known APIs, data exchange protocols, and commercially available transport services, thereby ensuring feasibility with current technological capabilities.

The embodiment can be described by the following itemized list:
1. A method for booking a transportation service, which may comprise exchanging a monetary amount for the combined services of transporting a person via air and transporting associated luggage via a separate ground logistics service.
2. The method of item 1, wherein the system may receive a user input indicating a desired passenger travel itinerary.
3. The method of item 1, wherein a backend processor could be configured to select a separate logistics service for transporting the luggage associated with the passenger booking.
4. The method of item 1, wherein the system may generate a bundled booking offer comprising both the passenger air travel and the decoupled luggage transport itinerary.
5. The method of item 1, wherein the system may transmit booking confirmations to both the passenger transport provider and the logistics service provider upon completion of the booking transaction.
6. The method of item 1, wherein the decoupled luggage transport could be scheduled to arrive directly at a designated hotel or temporary accommodation address specified by the passenger.
7. The method of item 1, wherein the system may estimate a differential in carbon footprint between transporting the luggage on the same aircraft as the passenger versus using a decoupled logistics routing.
8. The method of item 1, wherein the system may include a process for verifying the identity of the passenger and the ownership of the associated luggage prior to finalizing the booking.
9. The method of item 1, wherein the selection of the logistics service may be based on one or more factors, including estimated delivery cost, delivery timing, and projected environmental impact.
10. The method of item 1, wherein the system may be configured to issue a single payment transaction that covers both the passenger flight and the luggage transport booking.
11. The method of item 1, wherein the user interface may be adapted to display alternative luggage transport options, allowing comparative selection alongside the passenger flight itinerary.
12. The method of item 1, wherein the system may integrate customs declaration documents automatically into the luggage delivery workflow when cross-border transport is involved.
13. The method of item 1, wherein the luggage may be transported using a mode of transport selected from a group that could include ground freight, rail cargo, maritime shipping, and cargo-only air services.
14. A computer-readable medium storing instructions which, when executed by one or more processors, may cause a system to perform the method of any of items 1 through 13.

### Embodiment G: LLM Task Orchestrator

A system and method are disclosed for orchestrating task resolution through a language model (LLM) that autonomously initiates interactions with human agents. Rather than responding solely to user prompts, the LLM receives a task or query, analyzes its content, determines which elements can be resolved internally, and identifies which aspects require human knowledge or real-world input. The LLM consults a structured memory containing metadata about available human agents, including their skills, knowledge domains, availability, historical reliability, and preferred communication channels. It then generates and dispatches prompts to selected humans via appropriate channels (e.g., messaging platforms, email, SMS).

The system enables two-way interaction: a human receiving a prompt may engage in follow-up conversation with the LLM, request clarification, obtain supporting information, or request redirection to a more appropriate person. Additionally, the LLM may request that humans perform specific actions in the physical world, such as inspecting a device, manipulating an object, or uploading images or sensor data. All responses are interpreted and incorporated into the LLM's reasoning loop to iteratively refine task state and reach resolution. The system maintains performance metrics for each human participant—such as accuracy, response time, and resolution rate—which may inform future task routing, reward allocation, or removal from the agent pool. The final answer is returned to the original requester through the initiating channel. This architecture enables the LLM to function as a dynamic task orchestrator across distributed human networks, extending its capabilities into the physical world via delegated sensing, actuation, and social coordination.

### Example Use Case: AI-Orchestrated Multi-Human Task Resolution

To illustrate the invention, consider the following scenario:
A user types a natural language query into the system's interface:
“Can you check if the new pricing rules have been rolled out and approved?” Upon receiving the query, the system instantiates a task resolution agent powered by a language model (LLM).

The LLM parses the query and determines that it contains two sub-questions: whether the pricing rules have been rolled out to the production environment, and whether the pricing rules have received final approval.

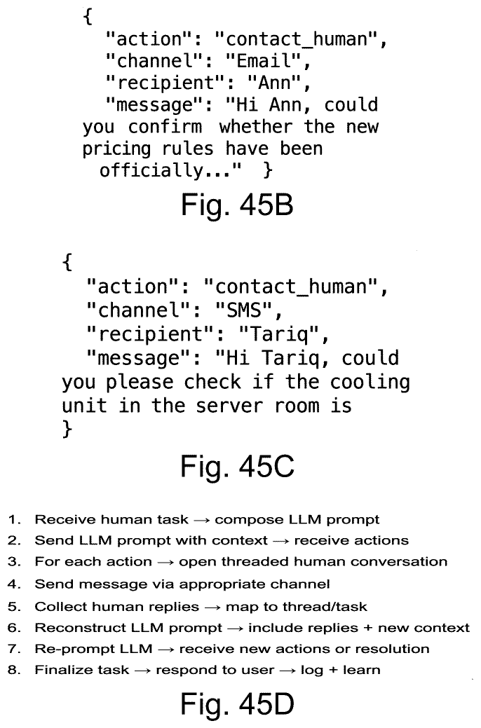

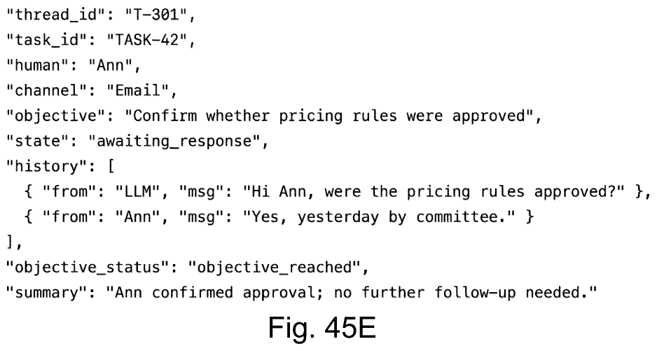

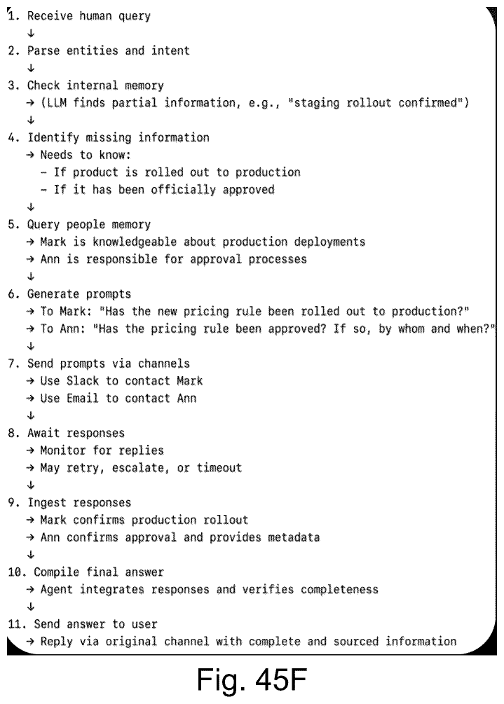

The LLM checks its internal memory, which includes recent system logs and previously resolved tasks. It finds that the rollout to a staging environment has been completed, but has no information about the production deployment or the approval status. To fill these gaps, the LLM consults its structured memory containing information about available human collaborators. This memory indicates that: Mark is a DevOps engineer knowledgeable about deployments to production, and Ann is a finance lead responsible for approval of pricing rules. The LLM determines that it must contact both individuals. Internally, it generates the following two message instructions: see FIG. 45A and FIG. 45B

These messages are passed to the system's messaging router, which delivers them through the appropriate channels and awaits responses.
Mark responds via Slack: “Yes, they were rolled out to production this morning.”
Ann replies via email: “Yes, they were approved yesterday by the pricing committee.”
Each response is received by the system and processed by the LLM. The LLM updates its internal task state and verifies that the user's query has been fully resolved. It then constructs the following response: “Yes, the new pricing rules were rolled out to production this morning and approved yesterday by the pricing committee.”

This answer is sent back to the original user through the same channel where the query was received. In an alternative scenario, had either Mark or Ann been unavailable, uncertain, or provided incomplete information, the LLM may have: Asked follow-up clarification questions, Requested a screenshot, log snippet, or document as evidence, Or redirected the prompt to another qualified individual based on the people memory. Additionally, the system may log metadata about the interaction, such as: The time taken to respond, Whether follow-up questions were needed, And the perceived helpfulness or clarity of the response. Over time, these records are used to maintain a performance profile for each human participant. These profiles can be used to improve future task routing or support human resource decisions such as delegation authority, skill tagging, or access restrictions. This example demonstrates how the LLM agent operates not just as a passive question-answer system, but as an active orchestrator: prompting humans, managing dependencies, and autonomously completing tasks that span digital and human input channels.

Below is a natural-language Example prompt that would be provided as input to the language model (LLM) in the scenario you described.
###**Example Input to the Language Model (LLM Prompt)**

In one example use case, the system may construct the following prompt and provide it to the language model as part of a reasoning cycle:
>**Main User Task:**
>“Can you check if the new pricing rules have been rolled out and approved?”
>**Contextual Memory:**
>*A previous task log shows that the pricing rules were rolled out to the **staging environment** two days ago.
>* No available memory confirms rollout to **production**.
>* No memory entry indicates whether the **approval** process has been completed.
>**People Memory:**
>* Mark (DevOps): Knows about production deployments. Available via Slack.
>* Ann (Finance Lead): Handles approval of pricing rules. Available via email.
>** Current Active Threads:**
>* None.
>**Instructions:**
>Based on the above information, determine:
>1. What missing information is required to answer the user's task.
>2. Which human collaborators should be contacted.
>3. What messages to send to gather the required information.
>4. How to route the messages via the appropriate communication channels.
>5. Whether the task can be resolved from available memory alone.
>Then, generate:
>* A proposed message to Mark asking whether the pricing rules have been rolled out to production.
>* A proposed message to Ann asking whether the pricing rules have been approved by the appropriate committee.
>* Optionally, a task status report if either message cannot be sent due to availability or channel failure.
###* *Example Output from the Language Model**

In response to this prompt, the language model may return the following:
>**Generated Messages:**
>**To Mark (via Slack):* “Hi Mark, do you know if the new pricing rules have been rolled out to the production environment?”
>* *To Ann (via Email):* “Hi Ann, just checking—have the new pricing rules been approved by the pricing committee?”
>**Routing Instructions:**
>* Send the message to Mark via Slack immediately.
>* Send the message to Ann via email with normal priority.
>**Internal Task Notes:**
>* Awaiting human response. Task incomplete.
>* Partial information available in memory (staging deployment confirmed).
>* No contradictory data found.

This prompt structure enables the LLM to act as an orchestration agent that decomposes the user's query, identifies the appropriate human collaborators, generates targeted follow-up prompts, and manages the ongoing state of the task until it is resolved.

### Example Use Case: LLM Requests Human to Inspect the Physical World

In a second scenario, a user enters the following query into the system: “Can you check if the cooling unit in the server room is working correctly?”

The system routes this query to the LLM agent, which parses the task and identifies that: It lacks direct access to sensor data from the server room, and the condition of the cooling unit must be visually or physically verified.

The LLM consults its structured memory to identify a person who is physically present at the location and capable of performing the task. It finds that Tariq, a local IT technician, is currently on-site and available. The LLM internally generates the following message: see 18C

Tariq receives the prompt via SMS, walks to the server room, inspects the cooling unit, and notices that the temperature display reads 35° C.—much higher than normal. He takes a photo and replies with the following message:
“It's running, but the display shows 35° C. Here's a photo: [link or attachment]”

The system ingests this reply, attaches the image metadata to the task, and routes the content back into the LLM's reasoning loop.

Based on the high temperature and the human-provided visual confirmation, the LLM determines that the cooling unit is technically running but not functioning properly.

It composes and returns the following answer to the original user: “The cooling unit is on, but it is not operating within the expected temperature range. The current reading is 35° C. A photo has been provided by the on-site technician.” The system may also take further automated steps based on preconfigured rules or additional LLM inference—for example, it may: Open a maintenance ticket, Notify the infrastructure manager Or ask Tariq to verify the airflow and compressor noise.

In this example, the LLM has: Delegated a physical-world inspection to a human, Accepted photo evidence as input, Interpreted a real-world measurement, and resolved the original query with grounded, observed data. The system also logs the latency, completeness, and reliability of Tariq's response, updating his human agent profile accordingly.

### System Loop in 8 Abstracted Steps: see FIG. 45D

Upon receiving a task query from a human user, typically in natural language form, the system constructs an input prompt for a language model (LLM), wherein said prompt comprises the original user question, relevant contextual metadata, and any previously known facts stored in system memory. The LLM analyzes the prompt and determines whether it can fully resolve the task using internal reasoning. If the LLM determines that one or more pieces of information are missing or uncertain, it generates a structured set of actions necessary to progress toward resolution. These actions may include contacting specific human agents who are likely to possess the required information, requesting those individuals to perform physical inspections, uploading photographic evidence, or confirming the status of a process or event. Each action returned by the LLM includes a recipient identifier, a preferred communication channel (such as Slack, email, or SMS), and a message payload formulated by the LLM to elicit a precise and relevant response. Upon receiving this structured output from the LLM, the system initiates a separate conversational thread for each action, whereby a message is transmitted to the target individual via the selected communication channel. Each such thread is tagged with a task identifier and remains open until a human response is received or a timeout condition is met. When a response is submitted by a human, the system logs the reply, associates it with the originating thread and task, and normalizes the content as needed for further reasoning. Once sufficient responses have been collected-or upon reaching a defined time or confidence threshold—the system constructs a new LLM input prompt comprising the original question, all received human replies, and the evolving contextual state of the task. This updated prompt is submitted to the LLM, which reevaluates the task, integrates the new information, and returns a new set of actions or, if the task is deemed complete, a finalized answer to be delivered to the original requester. This loop may be repeated iteratively, allowing the LLM to coordinate among multiple humans across asynchronous channels, recursively issue follow-up instructions, or escalate to alternative agents as needed. Upon task completion, the system may optionally update the performance record of each participating human based on accuracy, helpfulness, response time, and engagement level. This data may be used for future task assignment, access control, or incentive mechanisms. The final output is returned to the initiating user through the original interface, accompanied by a traceable task record, and all associated conversational threads may be archived or closed accordingly.

In some embodiments, a main task is initiated by a user query. The system invokes a language model (LLM) to decompose the task into a set of conversational subthreads, each of which is assigned a distinct chat objective and linked to a specific human recipient via a designated communication channel. As replies are received or timeouts occur, each thread is updated with its current state, including the history of exchanged messages, the evaluated objective status, and any detected obstacles to completion. The main LLM is periodically or reactively re-invoked with the full current state of the task, comprising the overarching task goal, the state of each thread, summaries of replies, the objective fulfillment status of each thread, and any auxiliary system context. Based on this holistic input, the LLM generates a new set of actions, which may include sending follow-up prompts within existing threads, reassigning a conversation to a different human, closing threads where the objective has been reached, or composing and delivering a final answer to the initiating user. Additionally, the LLM may initiate entirely new conversation threads by assigning new chat objectives to selected humans, thereby expanding the coordination space dynamically as task resolution progresses. This architecture enables iterative, multi-human coordination driven by a central reasoning engine, with each chat thread acting as an independently evolving unit of work tied to a verifiable subgoal.

In some embodiments, each thread maintains a structured representation of its associated objective, a conversation history log, and a state indicator selected from a predefined set of possible states such as open, awaiting_response, responded, objective_reached, blocked, escalated, or closed. In further embodiments, the system may include a performance profiling module that records metadata associated with each human participant, such as response time, helpfulness, frequency of reassignment, and objective completion rate. These profiles may be used by the LLM or a policy engine to optimize future task decomposition, contact routing, or incentive mechanisms. In some cases, the system may employ confidence scoring, content verification, or cross-agent agreement mechanisms to determine whether a chat objective has been sufficiently fulfilled. In further embodiments, the LLM may generate messages with suggested formats (e.g., include/exclude file attachments, ask for confirmation, propose options) based on the nature of the objective and the recipient's communication preferences. This flexible framework allows the system to function as a general-purpose LLM-driven orchestration engine for resolving complex tasks that depend on distributed human knowledge, physical-world inspection, or decision-making input from multiple stakeholders.

Example ChatThread Object: see FIG. 45E Each conversation initiated by the system is represented as a thread with a clearly defined objective. The objective may be fulfilled, blocked, escalated, or redirected based on human responses. These conversational threads are evaluated collectively, along with the overarching task goal, by a central reasoning engine that determines how to advance the task. This structure enables distributed, asynchronous resolution of complex queries through a dynamic interplay of language model reasoning and human participation.

### LLM Reasoning Cycle

### Each Iteration Includes:

Input to LLM: Main task prompt plus a list of all current ChatThreads: Their state, Human reply summaries, Whether their objectives have been reached, and optional knowledge base entries
LLM Output: New or updated chat threads (e.g., forward Thread T-301 to Bob), Rephrased prompts for clarification, Close thread action, Final task resolution (if all objectives are met)

### Core Working of the Invention

At the core of the system is a language model (LLM) configured to receive a task or problem description in natural language and decompose it into a set of conversational threads, each linked to a specific human recipient and assigned a well-defined chat objective. Each thread represents a subgoal necessary to achieve overall task resolution and is communicated via a selected human-facing channel such as email, messaging apps, or SMS.

The LLM formulates the initial message for each thread and tracks the state of the objective associated with that thread as responses are received or as additional context evolves.

As human replies are collected, each thread is evaluated to determine whether its objective has been fulfilled, is blocked, or requires redirection, escalation, or follow-up. These threads operate asynchronously and independently, but all contribute toward the resolution of the overarching task. The system periodically or event-triggered re-prompts the LLM with a summary of the current thread states, response content, and task context, allowing the LLM to generate new actions. These actions may include creating new chat threads with new objectives, modifying existing ones, closing completed threads, or returning the final result to the initiating user.

The task is considered resolved when all active chat threads have reached a terminal state with their objectives marked as fulfilled, and the LLM is able to synthesize a complete and coherent response based on the collected inputs. This architecture enables distributed, asynchronous, and iterative resolution of complex tasks by leveraging human insight and physical-world verification, coordinated entirely through dynamic prompting by the LLM.

### Enabling Description

In an exemplary embodiment, the system comprises a central coordination engine powered by a large language model (LLM), a task database, a thread state store, a context memory module, and a set of pluggable channel modules for interfacing with human users via various communication APIs (e.g., Slack, email, WhatsApp, SMS). The system receives an initial user query, which is processed and normalized before being passed to the LLM as part of a structured prompt that may include historical context, system memory, task metadata, and any recent related queries or responses.

Upon processing this prompt, the LLM returns a structured set of actions, which may include one or more human contact instructions. Each such instruction includes a recipient identifier, a preferred communication channel, a formulated message, and a defined objective that specifies what kind of information or action the LLM expects to result from the conversation. These instructions are stored in the task database and are each assigned a unique chat thread identifier. For each instruction, the system invokes the corresponding channel module-such as a Slack module, email module, or WhatsApp module—each of which contains the necessary logic to authenticate and communicate with its respective API. These channel modules are responsible for delivering messages to the appropriate human user and for receiving and normalizing human replies.

Each message thread and its corresponding objective are tracked in the thread state store, which may be implemented as a relational database, key-value store, or structured document store, depending on scalability and performance requirements. Each thread maintains metadata including its state (e.g., open, awaiting_response, responded, blocked, objective_reached, closed), message history, timestamps, and associated user IDs. All thread-level information is periodically aggregated into a higher-level task context, which is stored in the context memory module. The context memory is a structured object (e.g., a JSON document, a vector database with semantic indexing, or a hybrid memory graph) that includes summaries of all threads, their current objective status, and extracted information from human responses.

The central coordination engine periodically or reactively (e.g., upon new replies) composes a new prompt to the LLM, embedding the main task goal, the current memory context, and the status of all ongoing threads. The LLM processes this updated context and returns a new set of actions, which may include sending follow-up prompts within existing threads, forwarding a thread to another human participant, closing a thread due to objective completion, or creating a new thread to initiate a conversation with a different human. Optionally, the LLM may also return a complete final answer to the initiating user if it determines that all necessary objectives have been fulfilled and no further action is required.

Each channel module is stateless and designed to interface with standard communication APIs. For instance, the Slack module may use the Slack Events API and OAuth tokens to send and receive messages and thread replies, while the email module may use SMTP for outgoing messages and IMAP or webhook-based email gateways for ingesting responses. All responses received from humans are parsed, timestamped, associated with the corresponding thread, and passed into the memory system to update thread summaries and influence subsequent LLM prompts.

Additionally, the system may include a performance profiling subsystem, which records human-agent interaction metrics (e.g., response time, message clarity, frequency of reassignment) and stores them in a reputation or scoring database. These profiles may be used in future LLM calls to influence the choice of which human to contact or whether a task should be escalated or reassigned.

In some embodiments, the system may use a distributed message bus or event queue (e.g., Kafka, RabbitMQ) to coordinate communication between the orchestration engine, memory module, channel modules, and database subsystems. This allows the architecture to support asynchronous operation, horizontal scaling, and fault tolerance.

This enabling framework provides a practical method for implementing a dynamic, LLM-driven coordination system in which the main task is decomposed into discrete human-facing chat threads, each tied to a specific objective. As objectives are reached, blocked, or escalated, the system continues to cycle through reasoning phases until the task is fully resolved and a final output is produced.

Alternative embodiments may use: see FIG. 45F The embodiment can be described by the following itemized list: A method for resolving a user task using a language model, wherein the method may comprise receiving a task query from a user and generating, using the language model, one or more conversational threads, each of which may be associated with a respective human recipient and a defined objective.

The method of item 1, wherein the system may further comprise transmitting, for each conversational thread, a message to the respective human recipient through a selected communication channel.

The method of item 2, wherein the selected communication channel may be chosen from a group comprising email, messaging platform, SMS, or in-application chat.

The method of item 1, wherein the system may further comprise receiving, from at least one of the human recipients, a response message related to the corresponding conversational thread.

The method of item 4, wherein the system may further comprise updating the state of the conversational thread based on the received response.

The method of item 5, wherein the state of the conversational thread may be selected from a group comprising: open, awaiting response, responded, objective reached, blocked, escalated, or closed.

The method of item 1, wherein the system may further comprise evaluating the current state of the conversational threads using the language model to determine one or more follow-up actions.

The method of item 7, wherein the one or more follow-up actions may include sending a follow-up message, initiating a new conversational thread with a different human recipient, reassigning an objective, or marking the objective as complete.

The method of item 1, wherein the system may further comprise storing metadata associated with each conversational thread, including message history, timestamps, and objective status.

The method of item 1, wherein the system may further comprise completing the user task upon determining that the objectives associated with the conversational threads have been fulfilled.

A non-transitory computer-readable medium storing instructions which, when executed by one or more processors, may cause a system to perform a method for resolving a user task using a language model, the method comprising receiving a task query from a user and generating, using the language model, one or more conversational threads, each associated with a respective human recipient and a defined objective.

The non-transitory computer-readable medium of item 11, wherein the method may further comprise transmitting, for each conversational thread, a message to the respective human recipient via a selected communication channel.

The non-transitory computer-readable medium of item 12, wherein the selected communication channel may be selected from a group comprising email, messaging platform, SMS, or in-application chat.

The non-transitory computer-readable medium of item 11, wherein the method may further comprise receiving, from at least one of the human recipients, a response message related to the conversational thread.

The non-transitory computer-readable medium of item 14, wherein the method may further comprise updating the state of the conversational thread based on the received response.

The non-transitory computer-readable medium of item 15, wherein the state of the conversational thread may be selected from a group comprising: open, awaiting response, responded, objective reached, blocked, escalated, or closed.

The non-transitory computer-readable medium of item 11, wherein the method may further comprise evaluating the current state of the conversational threads using the language model to determine one or more follow-up actions.

The non-transitory computer-readable medium of item 17, wherein the one or more follow-up actions may include sending a follow-up message, initiating a new conversational thread with a different human recipient, reassigning an objective, or marking the objective as complete.

The non-transitory computer-readable medium of item 11, wherein the method may further comprise storing metadata associated with each conversational thread, including message history, timestamps, and objective status.

The non-transitory computer-readable medium of item 11, wherein the method may further comprise completing the user task upon determining that the objectives of the conversational threads have been fulfilled.

### Embodiment H: System and Method for Deceleration-Optimized Sleeping Pods in Autonomous Vehicles

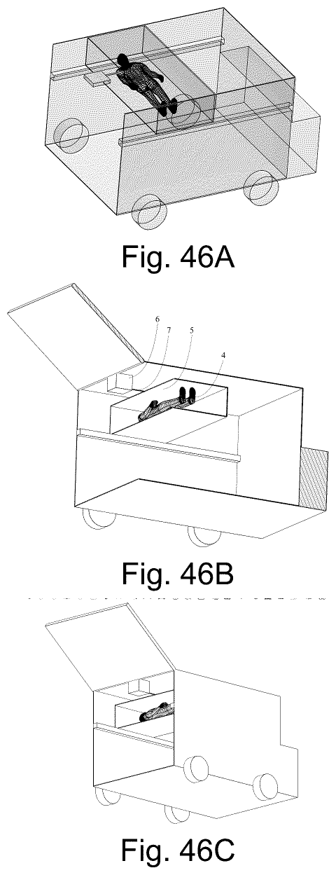

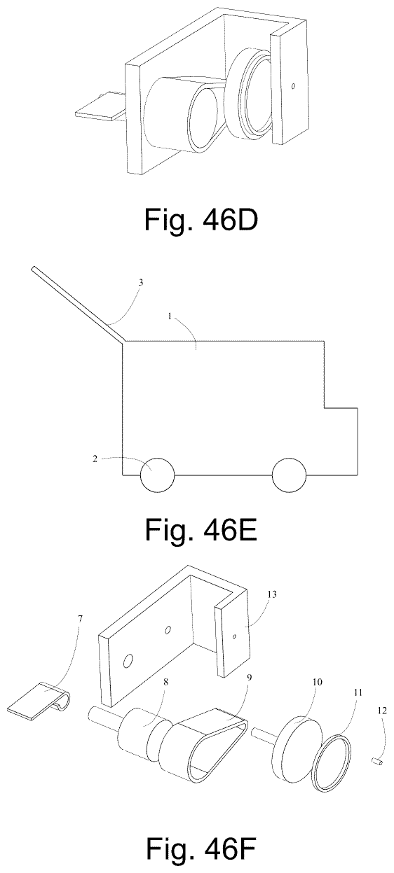

One embodiment is depicted in FIGS. 46A to 46F. A passenger safety system for vehicles is disclosed, wherein a human occupant may be positioned within a sleeping pod that is suspended or otherwise decoupled from the vehicle frame. The pod is mechanically connected to a braking unit via a cable or tether, enabling relative motion during a crash event. The braking unit may comprise a compound spool and transmission system that amplifies motion to a rotating conductive disk, which is subject to a controlled magnetic braking force, such as via eddy current induction. A control system may regulate the braking force to achieve a desired deceleration profile, reducing peak impact forces on the occupant. The pod may optionally be oriented perpendicular to the direction of travel, and the system may be applied in autonomous or long-distance vehicles to enable safe travel in a resting or reclined position.

Detailed description: In one embodiment, the invention relates to a crash-mitigating system designed to safely decelerate a horizontally oriented sleeping pod during a vehicle collision. The vehicle (1) is preferably autonomous and may be elongated to accommodate one or more passengers lying perpendicular to the direction of travel. The vehicle is supported on wheels (2) for normal road operation and includes a rear hatch or door (3) through which the sleeping area may be accessed. A human occupant (4) is positioned within a sleeping pod (5), the pod being configured to move forward relative to the vehicle frame in the event of a sudden deceleration.

The pod is mechanically connected to a controlled braking unit (6) via a strap or cable (7), which is arranged to transmit the forward kinetic energy of the pod into a rotary braking system.

The cable (7) is affixed to a first compound spool (8), comprising a small-diameter drum onto which the cable winds, and a coaxially aligned larger-diameter drum. The larger drum of spool (8) is operatively coupled to a second compound spool (10) via a transmission belt (9). The second compound spool (10) likewise includes a small drum receiving input from the belt and a larger drum that is mechanically connected to a metal braking disk (11). This disk is typically fabricated from a conductive material such as aluminum or copper and rotates rapidly as a result of the speed amplification achieved through the compound spool and belt transmission.

A fixed-position electromagnet (12) is mounted adjacent to the braking disk (11) and, when energized, induces eddy currents within the disk. The resulting electromagnetic braking force is smooth, non-contact, and can be dynamically controlled based on crash severity or pod velocity. All components from spool (8) through electromagnet (12) are housed within a rigid support structure (13), which may be integrated into the floor or chassis of the vehicle. The system allows for prolonged deceleration over distances such as 1.5 to 2 meters, thereby reducing peak forces on the human occupant and mitigating injury risk. This architecture is particularly suited to self-driving vehicles, where passengers may sleep during transit in a horizontal orientation.

In a further embodiment, the controlled braking system may incorporate a passive force-biasing mechanism configured to maintain the pod in a default rearward position within the vehicle under normal driving conditions. This may be achieved by coupling the pod to a soft-tension spring, elastic cord, or similar restoring element that exerts a continuous pull on the tether or cable toward the rear of the vehicle cabin. The force applied may be low enough to avoid restricting occupant comfort or movement during normal operation, yet sufficient to gradually reposition the pod after a braking event or occupant entry. This rearward biasing ensures that, in the event of a crash-induced braking sequence, the full available deceleration path is preserved, maximizing energy dissipation distance. The system may optionally include position sensors or damping elements to stabilize pod motion during non-crash driving scenarios, and to gently return the pod to its reset position without abrupt motion.

In one embodiment, the crash-deceleration system may include one or more accelerometers positioned within the vehicle frame, preferably at or near the structural extremities. These accelerometers are configured to continuously monitor the vehicle's linear acceleration and detect abrupt negative spikes indicative of a collision or sudden deceleration event. The sensor signal may be digitized and passed to an onboard processing unit, hereinafter referred to as the control computer, which resides within the rear compartment of the vehicle, optionally near or integrated with a backup battery module. The backup battery ensures system functionality even in the event of primary power loss.

Upon detecting acceleration levels exceeding a predefined crash threshold (e.g., a sustained deceleration exceeding −0.5 g within 50 ms), the control computer initiates a crash response protocol. This may include triggering a preloaded braking algorithm designed to optimize occupant safety by distributing the deceleration of the internal sleeping pod across the maximum possible distance and time available within the vehicle cabin.

The braking algorithm may dynamically calculate the required force profile to bring the pod from its relative velocity (with respect to the vehicle) to a halt, using real-time input from a position sensor embedded in the tether or pod guide rail, as well as predicted collision severity based on the initial deceleration spike. The desired profile may follow a constant or smoothly ramped deceleration curve, selected to minimize peak g-forces experienced by the occupant. In some configurations, the braking force may be non-linear and adaptive, increasing gradually to prevent abrupt tension spikes in the cable.

To execute the calculated force profile, the control computer modulates the current supplied to an electromagnet positioned adjacent to a conductive braking disk. The disk, which is mechanically linked to a compound spool system driven by the pod tether, rotates proportionally to the pod's movement. By adjusting the magnetic field strength over time, the system induces variable eddy currents in the disk, generating a braking torque precisely matched to the target deceleration curve. Feedback from rotational encoders on the spool or disk may be used to confirm actual braking torque, allowing for real-time correction of braking force via a closed-loop control scheme.

In some embodiments, secondary safety protocols may be initiated simultaneously. These may include tensioning any integrated restraint belts within the pod, activating cabin lighting for emergency awareness, or transmitting a wireless distress signal. If available, inertial measurements from multiple accelerometers (e.g., front and rear axles) may be fused to improve crash direction estimation, allowing the pod braking profile to adapt to both frontal and oblique impacts.

The control unit and electromagnet assembly are ideally mounted within a rigid housing near the rear section of the vehicle, minimizing exposure to front-end deformation and preserving system integrity during high-severity frontal crashes. The system may also incorporate redundant capacitive or kinetic energy storage (e.g., supercapacitors or flywheels) to ensure consistent braking power in the moments following power disruption.

Through this arrangement, the system enables a suspended or semi-free-moving sleeping pod to decelerate smoothly and in a controlled fashion, reducing occupant injury risk and allowing safe horizontal rest during autonomous transit.

The described embodiment is configured to protect the human body during vehicular collisions by minimizing the peak deceleration forces transmitted to the occupant and distributing those forces over an extended time interval and body surface area. In contrast to conventional upright seating with rigid restraint systems, the occupant may be positioned in a reclined or horizontal posture within a sleeping pod, which itself is mechanically decoupled from the rigid vehicle frame. In the event of a crash, the pod is permitted to move forward relative to the vehicle interior, and this movement is met with a controlled, programmable braking force that gradually arrests the pod's velocity. This deceleration is governed by a braking unit that modulates resistive force using an eddy-current braking mechanism, thereby allowing the pod to decelerate over distances on the order of 1.5 to 2 meters. The resulting reduction in acceleration gradient significantly lowers the risk of injury to soft tissues, spinal structures, and internal organs.

Moreover, because the occupant lies within a cushioned pod with high surface contact, inertial forces are distributed across a broader area of the body compared to conventional seatbelt points of contact. The horizontal orientation may further mitigate whiplash and neck trauma, as head and torso motion are more aligned. Optional restraint belts may be deployed to increase body-to-mattress friction or to gently compress the occupant against the sleeping surface during the braking phase, enhancing energy dissipation through distributed friction. The system avoids abrupt load spikes typical of explosive restraint systems by replacing them with smooth, computer-regulated deceleration, improving overall occupant survivability and reducing post-crash trauma. In this way, the invention transforms the violent nature of a crash event into a controlled, biomechanically tolerable motion experience for the resting occupant.

In some embodiments, the sleeping pod may incorporate one or more inflatable cushions, airbag bladders, or deformable energy-absorbing chambers positioned at the interior region of the pod that faces the vehicle's forward direction—i.e., the surface the occupant is expected to contact when the pod is decelerated during a frontal crash. When a collision is detected and the pod braking sequence begins, the occupant's inertia causes the body to shift forward within the pod frame, and the forward-facing cushions may either inflate rapidly or transition from a low-fill standby state to a high-support pressure. These structures distribute contact loads across the torso, shoulder, hip, and head regions (depending on orientation), thereby reducing localized impact pressure.

In configurations where the occupant lies substantially perpendicular to the direction of vehicle travel, the forward-facing cushion may be elongated along the pod sidewall to intercept a broad portion of the occupant's lateral body surface. Multi-chamber designs may be used so that upper, middle, and lower body zones inflate differentially; for example, a head-and-shoulder chamber may inflate more aggressively than a hip chamber.

Inflation may be triggered by the same crash-detection accelerometer logic that controls the pod braking electromagnet, and inflation pressure may be modulated over time to coordinate with the programmed deceleration profile, thereby avoiding hard rebound. Pressure-relief valves or metered bleed ports may be included to lengthen the impulse duration and further smooth body loading. These inflatable elements may also be duplicated on the opposite side of the pod to provide protection in reverse-motion events or to manage secondary occupant rebound following the primary deceleration phase.

In alternative embodiments, the controlled deceleration of the passenger pod may be achieved using a range of mechanical, electromagnetic, hydraulic, and pneumatic systems, either alone or in hybrid combinations. Each system is configured to dissipate the kinetic energy of the moving pod during a crash event in a manner that reduces peak forces transmitted to the occupant.

One approach involves the use of elastomeric restraints such as rubber bands, bungee cords, or torsional springs.

In this configuration, the pod is mechanically tethered to the vehicle frame via high-durability elastic elements that stretch as the pod moves forward. These materials exhibit a non-linear force-extension characteristic, offering low initial resistance that increases progressively with displacement. The progressive tension slows the pod in a smooth and continuous manner, minimizing the impulse applied to the occupant. This solution is passive and requires no electronic control, but may suffer from variability due to material fatigue, temperature sensitivity, and degradation over time.

A second alternative includes a non-circular spool or variable-radius cam. The tether cable connecting the pod to the braking system is wound around a spool whose radius varies along its circumference. As the spool rotates during pod displacement, the changing mechanical advantage alters the effective braking force. For example, an elliptical or logarithmic spiral profile may be used to create a ramped deceleration curve. This purely mechanical solution enables a pre-engineered force-displacement profile without sensors or actuators. However, its non-adjustable nature may limit its ability to adapt to crash severity or occupant mass.

A third approach uses eddy current damping, wherein the tether cable drives a conductive metal disk via a rotating spool system. A fixed-position magnet, typically an electromagnet, is located adjacent to the disk. As the disk spins, eddy currents are induced within the conductor, creating a resistive force that opposes rotation.

This resistive force is proportional to velocity and can be modulated dynamically by adjusting the magnetic field strength. The system enables smooth, contactless braking and can be tuned in real time to match the crash profile. It requires power and control logic but produces minimal wear and noise, making it ideal for repeated use.

In another embodiment, the braking system comprises a viscous fluid damper, such as a piston immersed in silicone oil or hydraulic fluid. As the pod moves forward, it drives the piston through the fluid, generating resistance through shear forces. The damping force is velocity-dependent and can be modified by selecting appropriate fluid viscosity and orifice geometry. This system is passive, robust, and well understood in automotive and aerospace applications. Its drawbacks include potential leakage and a relatively large physical footprint.

An alternative mechanism utilizes a flywheel system coupled with a friction clutch or brake. The motion of the pod drives the rotation of a flywheel, either directly or through a gear train. A controllable brake applies resistance to the flywheel, extracting kinetic energy and converting it to heat. The braking torque can be adjusted electronically, pneumatically, or mechanically. This setup allows for energy buffering and smooth deceleration, with the added benefit of potential integration with energy recovery systems. However, mass and inertia constraints may limit its feasibility in compact vehicle architectures.

Another variant employs regenerative electromagnetic braking using a motor-generator unit. The pod's kinetic energy is transferred via a mechanical linkage to a rotary generator, which converts the motion into electrical energy. This energy may be stored in a capacitor bank or battery, or dissipated across resistive loads. By controlling the electrical load, the braking force can be precisely modulated. This solution allows for real-time adaptation, potential energy recovery, and integration with existing vehicle power systems. It requires advanced control electronics and must be carefully engineered to function reliably during crash-induced power disruptions.

In a further embodiment, an air compression cylinder or pneumatic damper is used to absorb the pod's momentum. As the pod advances, it compresses air in a sealed chamber through a piston or bellows system. The compressed air offers resistance to motion and may be vented through a valve system that regulates pressure release, creating a smooth deceleration curve. This design is passive and may be augmented with one-way valves or staged venting for multi-phase damping. Its limitations include size and the requirement for robust seals and structural components.

Yet another design utilizes a friction-based braking track or belt system. The pod may slide along a dedicated rail or friction surface, where braking pads or belts apply resistance through direct mechanical contact. Tension in the belts may be preloaded or dynamically adjusted using servo-actuators to tailor braking response. This approach is simple and proven in various industrial applications but introduces concerns regarding wear, heat generation, and noise. It is best suited as a supplementary or redundant braking mechanism.

Finally, the system may incorporate deformable or sacrificial elements such as shear pins or crash rails. These components are designed to plastically deform or fracture under predefined loads, absorbing energy through material deformation. As the pod moves forward, it shears or compresses these elements in a controlled fashion, converting kinetic energy into mechanical work. This passive method is reliable and predictable, though it is generally single-use and may not reset automatically without replacement.

These alternative deceleration methods may be used individually or in combination, depending on vehicle size, crash energy, occupant orientation, and cost constraints. By incorporating such modular designs, the system ensures flexibility, redundancy, and the ability to tailor safety performance to specific use cases.

In practice, the system is designed to dynamically mitigate the inertial forces acting on the human body during high-impact events, especially frontal collisions. By allowing the pod to move independently from the vehicle chassis, and by actively regulating the rate at which the pod is decelerated, the system transforms what would otherwise be a sudden and potentially injurious impact into a smoother, time-distributed event. The control system, upon detecting a crash via onboard accelerometers or impact sensors, calculates the optimal deceleration curve based on pod velocity, crash severity, and available displacement distance. The braking unit is then actuated to provide a precisely modulated counter-force, thereby reducing the biomechanical stress on the occupant's body and lowering the likelihood of trauma. This approach offers significant safety advantages compared to conventional seatbelt or airbag-only systems, particularly for reclining passengers who cannot be restrained using upright harness methods.

To enable the deceleration process described herein, the control system may be configured to compute a time-dependent braking force profile based on a combination of sensor inputs and pre-calculated physical constraints. Upon detection of a crash event, an onboard accelerometer or inertial measurement unit (IMU) determines the initial relative velocity v0v0 of the passenger pod with respect to the vehicle chassis.

Simultaneously, internal position sensors estimate the remaining allowable displacement dd for the pod to move within the vehicle interior. The system may reference preloaded biomechanical safety thresholds to constrain the maximum allowable deceleration amaxamax, based on known occupant tolerances.

Using these parameters, the control unit calculates the optimal deceleration curve a(t)a(t) such that the pod comes to rest within distance dd while minimizing the jerk (time-derivative of acceleration) and peak G-forces experienced by the occupant. In one embodiment, a constant deceleration profile may be used, computed by the formula a=v02/(2d)a=v02/(2d), which ensures full velocity cancellation over the available travel range. In more advanced implementations, the control system may use adaptive or nonlinear profiles, applying higher deceleration initially and tapering off near the end of travel to reduce occupant rebound and improve comfort.

The selected braking force is then translated into control signals for the braking unit—for example, modulating magnetic field strength in an eddy current brake or adjusting fluid flow in a hydraulic damper—to physically realize the desired deceleration curve in real time.

This approach ensures that the pod's kinetic energy is dissipated safely and predictably within the mechanical constraints of the system and the physiological constraints of the occupant.

To support the controlled deceleration functionality, the system may include multiple sensor units strategically positioned to provide real-time data on vehicle dynamics, pod behavior, and crash conditions. At least one vehicle-mounted accelerometer, preferably positioned near the front or center of mass of the vehicle chassis, may be used to detect sudden deceleration indicative of a collision event. This primary sensor serves to initiate the crash response protocol and provides a reference frame for interpreting pod motion.

In addition, one or more accelerometers mounted directly on the passenger pod may be used to measure the pod's relative motion, instantaneous velocity, and the inertial forces acting on the occupant during the braking sequence. These pod-based sensors enable the control system to detect anomalies, verify braking performance, and dynamically adjust force application based on real-time feedback.

Complementing the accelerometers, the system may include position sensors (e.g., optical encoders, linear potentiometers, magnetic strip readers, or time-of-flight distance sensors) to monitor the pod's position within its travel rail or guide path. These sensors are preferably mounted along the pod's movement track and interface with the pod or tether to calculate the remaining travel distance.

Additionally, gyroscopes or inertial measurement units (IMUs) may be embedded within the pod or control system to track angular motion or orientation of the pod, which is useful in non-horizontal layouts or when body alignment is safety-critical.

To further enhance system awareness, occupant detection sensors such as pressure mats, infrared occupancy sensors, or vision-based posture detectors may be installed within or near the pod to determine whether the occupant is present and correctly positioned. This allows the control unit to tailor the braking profile based on occupant mass distribution and posture.

All sensor data may be processed locally by a dedicated safety microcontroller or routed to a centralized vehicle control system, which fuses the information to compute optimal braking trajectories and safety responses.

Embodiments may be described by the following itemized list:
1. An autonomously driving road vehicle comprising: a passenger pod configured to receive a reclining human occupant; a braking unit mounted within the vehicle; and a control system configured to detect a crash event and responsively apply a decelerating force to the passenger pod via said braking unit, wherein the passenger pod is permitted to move relative to the vehicle during a crash, and said decelerating force is applied so as to reduce the peak acceleration experienced by the occupant.
2. The vehicle of item 1, wherein the passenger pod may be coupled to the braking unit by a flexible tension element, such as a cable, belt, or chain.
3. The vehicle of item 1, wherein the braking unit may comprise a rotatable element configured to convert linear pod motion into rotational braking torque.
4. The vehicle of item 1, wherein the braking unit may comprise an eddy current braking system with a rotating conductive element and at least one magnet.
5. The vehicle of item 4, wherein the braking force may be modulated by adjusting the position or magnetic field strength of the magnet.
6. The vehicle of item 1, wherein the control system may determine the deceleration profile based on data from one or more accelerometers configured to detect crash severity.
7. The vehicle of item 1, wherein the control system may include a backup power supply to ensure braking functionality during power failure.
8. The vehicle of item 1, wherein the braking unit may include a fluid damper configured to generate velocity-dependent resistance.
9. The vehicle of item 1, wherein the braking unit may include a flywheel and a controllable friction brake.
10. The vehicle of item 1, wherein the passenger pod may include at least one inflatable cushion or airbag disposed at a surface toward which the occupant is expected to move during a deceleration event.
11. The vehicle of item 1, wherein the passenger pod may be biased toward a rearward rest position by a passive restoring mechanism such as a spring or elastic band.
12. The vehicle of item 1, wherein the braking unit may comprise a generator configured to convert kinetic energy into electrical energy and modulate braking force by controlling electrical load.
13. The vehicle of item 1, wherein the passenger pod may include an internal structure configured to increase surface contact with the occupant during deceleration.
14. The vehicle of item 1, wherein the braking unit may comprise a pneumatic system configured to resist pod motion by compressing air.
15. The vehicle of item 1, wherein the braking unit may comprise a deformable mechanical element that plastically deforms under crash-induced loads.
16. The vehicle of item 1, wherein the passenger pod may be oriented perpendicular to the forward direction of vehicle travel.
17. The vehicle of item 1, wherein the pod may be configured for dual occupancy.
18. The vehicle of item 1, wherein the pod may include sensors configured to detect occupant position and adjust the deceleration profile accordingly.
19. The vehicle of item 1, wherein the control system may include a processor programmed with a crash-response algorithm that determines braking force over time.
20. The vehicle of item 1, wherein the braking unit and passenger pod may be mounted on a common rail or guide system configured to constrain pod movement along a predetermined path.

### Embodiment I: Method and System for Forecasting Goal Outcomes Using Structured Experience Reports

A system and method are disclosed for enabling predictive goal fulfillment through incentivized experience sharing among autonomous agents. The method may involve receiving structured experience reports from personal agents, each report describing a user's attempt to achieve a defined goal using a selected option, along with contextual metadata and an observed outcome. These reports may be stored in a shared experience repository accessible by a network of agents. When a user or agent submits a prediction query specifying a goal and one or more candidate options, the system may analyze relevant prior reports to estimate the likelihood that each option will successfully achieve the goal under comparable conditions. In some embodiments, agents may be incentivized to contribute experience data in exchange for prediction access credits or monetary rewards.

For example, a user intending to have mobile data access while traveling may rely on the system to determine that SIM cards from Provider X have a low likelihood of activating roaming in Belgium, while Provider Z has a significantly higher success rate in similar contexts. In another example, a user considering purchasing a phone charging cable from a vendor at a train station may receive predictive feedback indicating that cables from that vendor often fail within one month, while cables from a verified online supplier demonstrate significantly longer durability. The system may continuously refine prediction accuracy through ongoing experience submissions, enabling proactive decision-making based on the real-world outcomes of others.

Background of the Invention: In both digital and real-world environments, individuals frequently encounter uncertainty when attempting to achieve specific goals through the selection of products, services, or actions.

Examples of such goals may include obtaining reliable mobile data service while traveling, selecting a durable phone charging cable, or completing a digital task using a free online tool. Despite the widespread availability of user reviews, testimonials, and general ratings, existing systems typically lack the specificity, contextual relevance, and predictive utility required for accurate decision-making in situational or individualized scenarios.

Conventional review platforms often aggregate generalized opinions that may not reflect the specific goal of the user, the conditions under which the product or service was used, or the probability of encountering a known failure mode. Furthermore, such platforms rarely offer probabilistic forecasts, structured outcome modeling, or agent-personalized insights that reflect a user's context, device, location, or intended use case. As a result, users are frequently required to rely on incomplete, anecdotal, or misleading information when making decisions, which may lead to loss of time, money, or effort.

Moreover, there exists no widely adopted system wherein autonomous agents operating on behalf of users can both contribute to and query a collective repository of structured experience data in exchange for incentives.

Current systems do not adequately leverage shared experiential outcomes to simulate future results or quantify the likelihood of goal fulfillment for specific options under particular conditions.

In some cases, a user may be unaware that a goal has failed until additional consequences arise, or may lack the time or motivation to document and share the experience. To address this, the present invention contemplates the use of personal agents that may autonomously detect the failure or success of a goal and submit a structured report with minimal or no human intervention. For instance, a personal agent may infer that a purchased SIM card failed to provide roaming service based on device telemetry, location data, and lack of connectivity. By removing friction in the reporting process and aligning incentives-such as offering prediction access credits or monetary rewards in exchange for experience reports—the system enables the consistent accumulation of high-quality, context-rich outcome data.

This combination of low-effort reporting and incentive-based participation is expected to substantially increase the density, diversity, and reliability of shared experiential data, thereby dramatically improving the system's ability to generate accurate, context-aware predictions of future outcomes. As a result, users may benefit from a powerful new form of collective foresight, enabling them to make more informed decisions and avoid common sources of regret, friction, or failure.

Applications and Illustrative Use Cases: The methods and systems described herein may be applied across a broad range of domains in which users must select among competing options to fulfill specific goals. In various embodiments, the invention enables a user's personal agent to simulate future outcomes based on structured reports submitted by other agents in similar contexts. The following examples are provided to illustrate representative use cases, and are not intended to limit the scope of the invention.

In one example, a user preparing to travel internationally may seek to ensure mobile data access upon arrival in a foreign country. The user's personal agent may query the system with the goal of “having working mobile data in Belgium” and evaluate a list of candidate SIM card providers. Based on experience reports submitted by other agents-some of which may indicate successful activation of roaming features, while others may describe failures due to regional restrictions or unresponsive customer support—the system may return a goal realization likelihood score for each provider. The agent may advise the user to avoid providers with historically poor outcomes in similar contexts.

In another embodiment, the system may be used to assist users in selecting an insurance provider. A goal such as “obtain fast, hassle-free reimbursement after a flight cancellation” may be evaluated across multiple insurers.

Experience reports could include outcome data on past claims, such as response times, documentation demands, and dispute frequency. By aggregating these reports, the system may offer the user a probabilistic forecast of successful claim fulfillment with minimal friction.

In yet another example, the user may wish to remove the background from a photo using an online service.

While many websites advertise free background removal, some may require account creation, introduce hidden paywalls after effort is expended, or produce unusable results. The agent may submit a prediction query with the goal “obtain a transparent PNG background removal in under two minutes with no watermark or payment.” By referencing past user experiences, the system may predict which sites are most likely to fulfill the goal without time loss or post-effort disappointment.

The system may also assist with impulse decisions in physical retail environments. For example, a user at a gas station may consider purchasing a phone charging cable from a generic vendor. The agent may detect the intended use case and evaluate the product ID or seller tag against prior experience reports. If multiple agents have previously logged that such cables fail within a few weeks or are incompatible with certain devices, the user may be warned before purchasing.

Finally, the invention may enhance everyday decisions such as selecting a place to sit and enjoy a coffee. A goal may be defined as “charge my phone while drinking coffee at the train station.” The agent may cross-reference experience reports to identify which restaurants or seating areas reliably provide working power outlets, factoring in time-of-day patterns and outlet occupancy trends. As a result, the user may be directed to a specific cafe or table location with a high probability of satisfying the charging requirement.

These examples illustrate how the system may be used to optimize decision-making across digital services, physical product selection, travel logistics, and environmental resource access. By continuously learning from structured reports and offering contextual predictions, the invention may serve as a valuable tool for minimizing regret, effort loss, and goal failure in everyday life.

Applications and Illustrative Use Cases: The methods and systems described herein may be applied across a broad range of domains in which users must select among competing options to fulfill specific goals. In various embodiments, the invention enables a user's personal agent to simulate future outcomes based on structured reports submitted by other agents in similar contexts. The following examples are provided to illustrate representative use cases, and are not intended to limit the scope of the invention.

In one example, a user preparing to travel internationally may seek to ensure mobile data access upon arrival in a foreign country. The user's personal agent may query the system with the goal of “having working mobile data in Belgium” and evaluate a list of candidate SIM card providers. Based on experience reports submitted by other agents-some of which may indicate successful activation of roaming features, while others may describe failures due to regional restrictions or unresponsive customer support—the system may return a goal realization likelihood score for each provider. The agent may advise the user to avoid providers with historically poor outcomes in similar contexts.

In another embodiment, the system may be used to assist users in selecting an insurance provider. A goal such as “obtain fast, hassle-free reimbursement after a flight cancellation” may be evaluated across multiple insurers.

Experience reports could include outcome data on past claims, such as response times, documentation demands, and dispute frequency. By aggregating these reports, the system may offer the user a probabilistic forecast of successful claim fulfillment with minimal friction.

In yet another example, the user may wish to remove the background from a photo using an online service.

While many websites advertise free background removal, some may require account creation, introduce hidden paywalls after effort is expended, or produce unusable results. The agent may submit a prediction query with the goal “obtain a transparent PNG background removal in under two minutes with no watermark or payment.” By referencing past user experiences, the system may predict which sites are most likely to fulfill the goal without time loss or post-effort disappointment.

The system may also assist with impulse decisions in physical retail environments. For example, a user at a gas station may consider purchasing a phone charging cable from a generic vendor. The agent may detect the intended use case and evaluate the product ID or seller tag against prior experience reports. If multiple agents have previously logged that such cables fail within a few weeks or are incompatible with certain devices, the user may be warned before purchasing.

Finally, the invention may enhance everyday decisions such as selecting a place to sit and enjoy a coffee. A goal may be defined as “charge my phone while drinking coffee at the train station.” The agent may cross-reference experience reports to identify which restaurants or seating areas reliably provide working power outlets, factoring in time-of-day patterns and outlet occupancy trends. As a result, the user may be directed to a specific cafe or table location with a high probability of satisfying the charging requirement.

These examples illustrate how the system may be used to optimize decision-making across digital services, physical product selection, travel logistics, and environmental resource access. By continuously learning from structured reports and offering contextual predictions, the invention may serve as a valuable tool for minimizing regret, effort loss, and goal failure in everyday life.

In some embodiments, the method described in claim 1 may be realized by a system comprising one or more experience processing servers configured to receive structured reports from a plurality of autonomous or semi-autonomous personal agents. Each agent may be associated with a user and may be configured to monitor, infer, or record attempts by the user to achieve a particular goal. The agent may detect the goal explicitly, such as via user input, or infer it from surrounding behavioral context, such as application usage, online activity, location data, or other observable signals. When the user selects an option in pursuit of that goal-such as purchasing a product, using a service, or initiating a digital interaction—the agent may log the selected option along with eventual success or failure outcomes.

Upon detecting that sufficient outcome information is available, the agent may compile a structured experience report. This report could include, by way of example and not limitation, a goal description, the option selected, the result of the action (e.g., success, partial success, failure), and a set of contextual attributes relevant to outcome interpretation. These attributes may include environmental data, device type, timing, location, service conditions, user feedback, or any other parameter useful for later predictive evaluation. A representative experience report may be structured in a machine-readable format, such as JSON, as follows:

```
‘‘‘json
{
  ″goal″: ″Have working mobile data while traveling in Belgium″,
  ″selected_option″: ″ProviderX SIM card, purchased online″,
  ″outcome″: ″Failure - SIM card did not activate roaming in BE″,
  ″timestamp″: ″2025-07-14T10:23:00Z″,
  ″context″: {
    ″location_of_use″: ″Brussels, Belgium″,
    ″device″: ″iPhone 13″,
    ″time_elapsed_before_failure″: ″3 days″,
    ″setup_steps″: [″Inserted SIM″, ″Followed instructions″, ″Activated via app″],
    ″user_feedback″: ″Support unreachable, no refund offered″
  }
}
‘‘‘
```

In some configurations, the system may receive the structured report and store it in a shared experience repository, optionally associating it with a unique identifier, a confidence score, or a cryptographic proof of provenance. The experience repository may be searchable by other agents and may serve as the basis for later predictive operations. For example, a second agent may submit a prediction query to the system, specifying a desired future goal (e.g., working mobile data while abroad) and one or more candidate options (e.g., various SIM card providers). In response, the system may retrieve relevant prior experience reports, optionally filtering by context similarity, and compute for each candidate a goal realization likelihood score, indicating a probability or confidence that the goal would be achieved under conditions similar to those described in the query. The results of this analysis may be returned to the agent in structured form, potentially accompanied by annotations, such as common failure points, remediation costs, or alternative recommendations. The system may continuously update its predictive capabilities as additional experience reports are submitted, allowing it to adapt over time to changing conditions, rare edge cases, and evolving user goals.

In some embodiments, the platform may operate using a distributed architecture, and experience reports may be submitted pseudonymously, anonymously, or with cryptographic signatures. The report submission and query process may be mediated through an incentive mechanism, such that agents who contribute experience data may receive access privileges, prediction credits, or other benefits as described in related claims.

In one illustrative embodiment, the invention may be applied in the context of selecting a cafe for the purpose of achieving the goal of charging a mobile phone while consuming a beverage at a train station. This example demonstrates how primary keys may be used to retrieve relevant prior experiences, which are subsequently used as input to a large language model (LLM) for the purpose of predicting the likelihood of goal success under current conditions.

At the outset, a personal agent associated with a user may detect or be informed of the user's intent to locate a cafe within a transportation hub, such as a central train station, with the specific goal of charging their phone.

The agent may construct a query using a set of **primary keys**, representing observable or inferable facts about the current situation. These keys may include, but are not limited to: “goal:charge_phone”, “venue_type:cafe”, “location:central_station”, “time_of day:morning”, “device_type:mobile_phone”

Using these keys, the system may retrieve a set of experience reports from a shared experience repository. Each experience report may correspond to a past attempt by a different user to achieve a similar goal under similar or overlapping conditions. These reports may be structured to include outcome data and relevant context, as illustrated below.

```
‘‘‘json
[
  {
    ″goal″: ″charge_phone″,
    ″venue_type″: ″cafe″,
    ″location″: ″central_station″,
    ″time″: ″2025-07-04T09:15Z″,
    ″outcome″: ″success″,
    ″details″: {
      ″cafe_name″: ″Café X″,
      ″table″: ″4″,
      ″outlet_available″: true,
      ″outlet_working″: true,
      ″duration_minutes″: 30
    }
  },
  {
    ″goal″: ″charge_phone″,
    ″venue_type″: ″cafe″,
    ″location″: ″central_station″,
    ″time″: ″2025-07-04T08:50Z″,
    ″outcome″: ″failure″,
    ″details″: {
      ″cafe_name″: ″Café Y″,
      ″outlet_available″: false
    }
  },
  {
    ″goal″: ″charge_phone″,
    ″venue_type″: ″cafe″,
    ″location″: ″central_station″,
    ″time″: ″2025-07-03T09:00Z″,
    ″outcome″: ″partial_success″,
    ″details″: {
      ″cafe_name″: ″Café X″,
      ″outlet_available″: true,
      ″outlet_interrupted″: true
    }
  }
]
‘‘‘
```

Following retrieval, the system may select a subset of representative experiences, optionally filtered by recency or contextual similarity, and format these into a prompt for a large language model. The prompt may include a natural language representation of the current user goal, the current conditions, and a listing of prior experiences.

An example prompt might be as follows: **Prompt to LLM:**

“A user is currently at the central train station and is looking for a cafe where they can sit and charge their mobile phone while having a coffee. It is currently 9:00 AM. The goal is to find a nearby cafe with working, available power outlets.

Here are 3 past user experiences:
1. Café X, 9:15 AM, July 4: Table 4 had a working outlet. User successfully charged phone for 30 minutes.
2. Cafe Y, 8:50 AM, July 4: No outlet was available. User could not charge.
3. Cafe X, 9:00 AM, July 3: Outlet was initially working but power was interrupted midway through.

Based on these past reports, what is the probability that the user will be able to successfully charge their phone at Cafe X right now (9:00 AM)?Please provide a percentage estimate, any identified risks, and suggested actions.”

Upon receiving this prompt, the LLM may process the inputs and return a structured or semi-structured output.

For example: **LLM Output:**
***Estimated probability of success at Cafe X at 9:00 AM**: 65%
***Risks identified**:
* Outlet reliability may vary by table
* Temporary power interruptions were reported
* Morning hours may lead to competition for limited outlets
* **Suggestions**:
* Request Table 4 if available
* Bring backup power bank
* Consider Cafe Y after 10:00 AM, where lower outlet usage was observed

This output may then be consumed by the user's agent and used to inform a recommendation, optionally rendered in natural language or through visual interface elements. The agent may advise the user accordingly, such as: *“Cafe X gives you a moderate chance of charging now, especially at Table 4. Outlet reliability is variable. Would you like to check other options after 10:00 AM?″*

In some embodiments, the system may assign a confidence score to the LLM's prediction based on the volume, consistency, or contextual alignment of the retrieved reports. The agent may also prompt the user to contribute their own outcome after the attempt, thereby completing the feedback loop and improving the system's predictive accuracy over time.

This example illustrates how primary keys may be used to accurately retrieve situationally relevant prior experiences, and how an intelligent model may be prompted to synthesize those experiences into an actionable forecast that helps the user choose the most effective path toward goal fulfillment.

In some embodiments, the system may operate by first identifying a set of primary keys associated with the user's current decision context. These keys may include, by way of example, the location at which the product or service is to be used, the type of object or service under consideration, the intended user goal, and any other observable attributes such as time of day, device type, or vendor identity. Once the keys are established, they may be used to query an experience repository containing structured reports from prior users or agents who attempted to achieve similar goals under comparable conditions. The result of this query is a collection of historical experiences that match or approximate the identified context. The system may then assemble a custom prompt by embedding the current goal and the retrieved experience data into a formatted textual query suitable for a large language model (LLM). The LLM may be configured to analyze the prior outcomes, identify relevant patterns, and return a structured response containing an estimated probability of goal success, a list of contextual risks, and actionable advice or alternatives. This output may then be consumed by the user's agent to support real-time decision-making or user guidance, and optionally presented in natural language or visual format. The overall process enables goal-directed prediction through the combination of structured experience mining and generative language-based reasoning.

In some embodiments, the system may implement an incentive mechanism to encourage the submission of structured experience reports by user-associated agents. Upon submission of a report describing a user's attempt to achieve a defined goal using a specific option-along with outcome data and contextual information—the agent may be rewarded through various mechanisms. The incentive may take the form of a usage credit, which enables the agent to access future prediction queries without cost, or a digital token, which may be recorded on a centralized server or decentralized ledger and optionally exchanged for platform services, goods, or monetary value. In certain implementations, the incentive may consist of direct financial compensation, whereby the agent or user receives currency or a digital payment in exchange for providing verified, high-value experience data.

The amount or type of incentive may vary depending on factors such as the relevance of the report to current prediction demand, the rarity or novelty of the reported scenario, or the report's consistency with other agent-submitted data. Incentives may be adjusted dynamically based on system-defined quality metrics or validation signals. This reward mechanism serves to ensure that personal agents contribute high-quality, timely, and contextually rich data, thereby increasing the density and diversity of the experience repository, which in turn enhances the system's ability to provide accurate goal outcome predictions for future users.

In some embodiments, the system may include a verification mechanism configured to ensure that submitted experience reports reflect authentic user interactions. This mechanism may operate in various modes, optionally managed or initiated by the personal agent. In one configuration, the agent may be required to participate in a staking process, wherein a digital token or reputation score is temporarily committed as collateral when an experience report is submitted. At a later point, the system may randomly or selectively challenge the agent to provide proof of the reported experience, such as supplemental metadata, sensor logs, or documentary evidence.

If the agent fails to provide such proof, the staked value may be partially or fully slashed, disincentivizing dishonest reporting. In other embodiments, the agent may attach a proof of payment or transactional receipt to the report, such as a digital invoice, e-commerce confirmation, or NFC payment log, demonstrating that the product or service was actually acquired. In further implementations, the agent may automatically generate usage telemetry, such as device activity logs, geolocation patterns, interaction timestamps, or other passive signals indicative of genuine engagement. These verification signals may be cryptographically signed, anonymized, or privacy-preserving, and used to calculate a report confidence score. Reports with higher confidence may receive greater rewards or higher weight in predictive computations. The system may also support third-party validation services or cross-agent corroboration mechanisms. By assigning verification responsibilities to the personal agent and linking them to staking, proofs, or system-collected signals, the platform may maintain high data integrity without requiring direct user intervention.

Following are step-by-step **high-level system description** using plain English and numbered steps. It covers the major components of the invention:
###**Part A: Making a Goal-Based Prediction**
**Step 1: User or agent defines a goal.**

For example: “Charge my phone while having coffee at the central train station.”
**Step 2: The agent extracts primary keys.**

These are facts known in advance, such as:
* Location: ‘central_station’
* Venue type: ‘cafe’
* Time of day: ‘morning’
* Goal: ‘charge_phone’
**Step 3: The agent queries the experience database using these keys.**

It requests all relevant past experience reports involving similar contexts.
**Step 4: The system filters and selects the most relevant past experiences.**

For example, five reports involving Cafe X, Table 4, and similar times.
**Step 5: The system constructs a custom prompt for a language model (LLM).**

The prompt includes the current goal and a summary of selected experiences.
**Step 6: The LLM analyzes the data and returns a prediction.**

The output may include:
* Estimated chance of success (e.g., 65%)
* Risks (e.g., outlet reliability, high occupancy)
* Advice (e.g., “Table 4 is preferred, or try Cafe Y after 10 AM”)
**Step 7: The agent presents this prediction and recommendation to the user.**

This helps the user choose the best option with informed foresight.
###**Part B: Submitting an Experience Report**
**Step 1: After the user attempts the action, the agent logs the result.**

For example: “Charged phone successfully for 30 minutes at Cafe X, Table 4.”
**Step 2: The agent formats this into a structured report.**

It includes:
* The goal
* The selected option (e.g., Cafe X)
* The outcome (success or failure)
* Context (time, location, device, etc.)
**Step 3: The system stores the experience in the shared database.**
**Step 4: The agent receives an incentive.**

This could be:
* Prediction access credits
* A digital token (possibly exchangeable for money or services)
* Direct monetary payment
###**Part C: Ensuring Report Authenticity (Verification and Staking)**
**Step 1: In some cases, the agent may be required to lock a stake.**

A digital stake (e.g., token or credit) is committed when submitting the report.
**Step 2: The system may later request proof of the experience.**

This could include:
* Proof of purchase or payment
* Usage telemetry from the device
* Location or activity logs
**Step 3: If the agent provides valid proof, the stake is returned.**

If not, the stake may be slashed (partially or fully lost).
**Step 4: Verified reports are given higher trust weight.**

They may receive greater incentives and influence predictions more strongly.

The embodiment may be described by the following itemized list:
1. A method for providing predictive goal outcome guidance via an experience sharing system, the method comprising the steps of:
   (a) receiving, from a personal agent, a structured experience report describing a user's attempt to achieve a defined goal using a selected option, the report including outcome data and contextual metadata;
   (b) storing the experience report in a shared experience repository accessible to other agents; and
   (c) processing a prediction query submitted by an agent, wherein the system analyzes previously submitted experience reports to estimate the likelihood that each of a plurality of candidate options will achieve a specified goal under given conditions.
2. The method of item 1, further comprising issuing an access incentive to the contributing agent in exchange for the submitted experience report.
3. The method of item 2, wherein the access incentive may comprise one or more of:
   (a) a prediction access credit;
   (b) a reputational score adjustment; or
   (c) priority access to high-quality predictions.
4. The method of item 2, wherein the access incentive may comprise a monetary reward, issued upon submission of an experience report that satisfies one or more criteria selected from:
   (a) high relevance to a trending prediction query,
   (b) rarity or novelty of the reported scenario,
   (c) confirmation of a previously uncertain outcome, or
   (d) inclusion of validated telemetry or third-party verification.
5. The method of item 1, wherein the structured experience report may include metadata selected from: geographic location, time of use, product or service identifier, device type, user profile, or environmental conditions.
6. The method of item 1, wherein the prediction query may include:
   (i) a user-defined or agent-inferred goal,
   (ii) a list of candidate options under consideration, and
   (iii) an optional context specification, and wherein the system may compute a goal realization likelihood score for each candidate option based on aggregate outcomes from similar historical experiences.
7. The method of item 1, further comprising returning, in response to a prediction query, additional data selected from:
   (a) a summary of common failure points,
   (b) estimated remediation effort if the goal is not achieved,
   (c) alternative options with higher historical success rates, or
   (d) user-verified warnings or anomaly flags.
8. The method of item 1, wherein experience reports may be submitted and prediction queries may be executed via a secure communication interface, and wherein agent identity may be pseudonymous, cryptographically verified, or anonymized.
9. The method of item 1, wherein prediction accuracy may be iteratively improved using a feedback loop that incorporates:
   (a) new experience reports,
   (b) follow-up success or failure logs from agents that acted on prior predictions, or
   (c) corrections or post-hoc annotations.
10. The method of item 1, wherein submitted experience reports may include or reference telemetry data or signed usage logs from user devices or applications, enabling partial or full automated validation of the reported outcome.
11. The method of item 1, wherein the system may support both:
   (a) an experience retrieval mode, in which a querying agent receives historical reports for local inference; and
   (b) a direct prediction mode, in which the system returns a computed likelihood score for each option in the context of a specific goal.

### Embodiment J: System and Method for Agent-Mediated Strategic Matchmaking

FIELD OF THE INVENTION: The present invention relates to autonomous agent systems and, more specifically, to systems and methods for identifying and enabling strategic collaborations between agents representing distinct parties by means of goal-based matchmaking, automated synergy scoring, and structured agent-to-agent negotiation.

BACKGROUND: In modem digital environments, autonomous agents are increasingly employed to represent individuals, companies, or institutions in performing tasks such as recommendation, monitoring, and decision-making. However, the problem of discovering non-obvious collaborative opportunities between agents acting independently remains unsolved. Conventional systems rely on static profiles, keyword-based searches, or pre-existing relationships. There is no known framework for enabling agents to autonomously announce strategic goals, discover synergies through reasoning, and engage in structured negotiation when mutual value is detected.

SUMMARY: This invention provides a system and method for agent-mediated strategic matchmaking. The system allows agents to submit structured goal announcements, each expressing an intent, offer, or need of a respective party. A central platform continuously evaluates pairs of goal announcements originating from different agents. When a potential synergy is detected based on semantic similarity, goal alignment, or inferred mutual benefit, the system generates a match object and delivers it to the agents of both parties.

Upon match detection, the system further provides a shared communication channel, such as a private chat interface, to enable agent-to-agent negotiation. Entry into the chat may imply mutual agreement to a predefined or negotiated confidentiality framework, optionally formalized through a digital negotiation agreement (DNA).

The agents may exchange structured terms, evaluate feasibility, propose collaborative actions, or escalate the opportunity to human users. This system enables autonomous agents to go beyond passive task execution and engage in intelligent matchmaking and strategic value discovery across domains, industries, and interest areas.

### DESCRIPTION OF EMBODIMENTS

In one embodiment, the system comprises:
* A goal announcement interface configured to receive structured data from agents, each goal comprising a textual description, one or more strategies, optional constraints, and contextual metadata.
* A matchmaking engine configured to iterate over cross-agent goal pairs, compute a relatedness score using semantic embeddings, strategic alignment models, and mutual value templates.
* A threshold filter to identify synergistic goal pairs exceeding a match threshold.
* A communication module configured to instantiate a private chat, structured dialogue, or negotiation interface shared between matched agents.
* A confidentiality enforcement layer, wherein entry into said interface implies acceptance of an implicit or explicit non-disclosure agreement.
* An optional digital negotiation agreement engine allowing agents to exchange machine-readable terms, usage boundaries, and agreement conditions.

In another embodiment, agents may refine their goal announcements over time based on observed match outcomes, feedback loops, or shifts in strategic priorities. The platform may maintain a history of accepted, rejected, or ignored matches to further train agent behavior. In a preferred implementation, goal announcements and associated strategies are submitted in natural language format to maintain human readability and transparency. For example, an ESG-focused fashion brand may submit the goal “Improve sustainability branding in the European market” with strategies such as “Sponsor a clean agriculture project to associate our brand with pesticide-free practices.” An agricultural drone startup may submit the goal “Secure €500K in funding to demonstrate a pesticide-free laser drone system” with strategies such as “Offer sponsorship rights on drone field demos.” Upon detection of sufficient synergy between such parties, the system may present a shared chat link and a human-readable match summary to both agents, allowing negotiation and mutual evaluation to proceed with transparency and trust.

ENABLING IMPLEMENTATION: Each goal announcement may be linked to one or more proposed strategies, where each strategy represents a possible path to achieving the associated goal. Strategies may include actions to be taken, offers to be made, or conditions under which collaboration is desired. The system evaluates all possible pairs of strategies across different agents, determining whether a pair of strategies-when taken together—form a plausible and mutually beneficial path toward satisfying at least one goal from each agent.

This evaluation may consider both the semantic similarity of the strategy descriptions and the logical implications of one strategy supporting or complementing the other.

An example step-by-step scenario:
* **Agent A** (Startup): Goal: “Secure €500K in funding to demonstrate a pesticide-free laser drone system.”

### Strategies:

* “Offer co-branding rights on field trial deployments,”
* “Provide ESG data from chemical-free pilot zones,”
* “Seek sponsorship partnerships with sustainability-aligned corporations.”
* **Agent B** (H&M): Goal: “Strengthen our sustainability branding in the EU market.”

### Strategies:

* “Sponsor innovative agricultural technologies aligned with ESG objectives,”
* “Seek co-branded projects that highlight clean production methods,”
* “Support startups working to eliminate chemical inputs in textile supply chains.”

The system evaluates all strategy pairs and identifies:
* **Pair**:
* “Seek sponsorship partnerships with sustainability-aligned corporations”
* “Sponsor innovative agricultural technologies aligned with ESG objectives”

With a high synergy score, a **match object** is created and shared with both agents, including:
* Synergy explanation
* Chat link
* Automatic mutual NDA
* Optional DNA exchange as the chat evolves
**Example JSON:**

```
‘‘‘json
{
  ″agentA″: {
    ″goal″: ″Secure €500K in funding to demonstrate a pesticide-free laser drone system″,
    ″strategies″: [
      ″Offer co-branding rights on field trial deployments″,
      ″Provide ESG data from chemical-free pilot zones″,
      ″Seek sponsorship partnerships with sustainability-aligned corporations″
    ]
  },
  ″agentB″: {
    ″goal″: ″Strengthen our sustainability branding in the EU market″,
    ″strategies″: [
      ″Sponsor innovative agricultural technologies aligned with ESG objectives″,
      ″Seek co-branded projects that highlight clean production methods″,
      ″Support startups working to eliminate chemical inputs in textile supply chains″
    ]
  },
  ″match″: {
    ″strategy_pair″: [
      ″Seek sponsorship partnerships with sustainability-aligned corporations″,
      ″Sponsor innovative agricultural technologies aligned with ESG objectives″
    ],
    ″matched_goals″: [
      ″Secure €500K in funding to demonstrate a pesticide-free laser drone system″,
      ″Strengthen our sustainability branding in the EU market″
    ],
    ″synergy_score″: 0.93,
    ″explanation″: ″The strategies show mutual value exchange: the startup receives funding and visibility, while
the sponsor strengthens ESG branding by supporting pesticide-free innovation.″,
    ″chat_link″: ″https://synergy-platform.ai/chat/xyz123″,
    ″nda_implied″: true
  }
}
‘‘‘
```

### Architecture & Fallbacks

System architecture may include:
* Goal & strategy encoder using a language model (e.g., GPT-based transformer)
* Vector matching engine (e.g., cosine similarity) with logic rules for implication
* Chat provisioning with optional prefilled negotiation prompts
* Implicit or explicit NDA logic
* Optional structured DNA templates

### Fallbacks:

* If no match found: prompt for refinement
* If rejected: log cause and improve models
* If ambiguous: escalate to human review

### Strategy Pair Evaluation Via LLM

It is further described that the server-side evaluation of strategy pairs may be performed as follows: two strategy descriptions, submitted in natural language, are programmatically selected by the matchmaking engine and passed as input to a large language model (LLM) hosted on the platform or via an API. The LLM processes both strategies within a prompt template designed to elicit an explanation of synergy scope and rationale. The output may include: (i) whether a mutual benefit exists, (ii) a proposed form of collaboration, and (iii) a natural-language justification of the match. This output is parsed and embedded into the match object delivered to both agents, enabling transparent evaluation and initiating negotiation where appropriate.

The embodiments may be described by the following itemized list:
1. A system for enabling strategic matchmaking between agents, the system comprising: a goal announcement module configured to receive goal declarations from a first agent and a second agent; a matching engine configured to compare said declarations and determine a synergy score based on predefined criteria; and a communication module configured to provide a shared chat link to both agents upon determining that said synergy score exceeds a threshold.
2. The system of item 1, wherein the goal declarations may comprise structured strategies, offers, or needs.
3. The system of item 1, wherein the synergy score may be computed using semantic embeddings, goal alignment logic, or inferred mutual benefit.
4. The system of item 1, wherein the shared chat link may lead to a private communication interface governed by an implicit confidentiality agreement.
5. The system of item 1, further comprising a digital negotiation agreement (DNA) exchange layer enabling agents to submit, review, and accept structured negotiation terms.
6. The system of item 1, wherein agents may autonomously evaluate the match object and determine whether to accept, decline, or modify the proposed interaction.
7. A method for agent-mediated strategic matchmaking, the method comprising: receiving a first goal announcement from a first agent; receiving a second goal announcement from a second agent; evaluating whether a synergy exists between said announcements; and, if so, providing both agents with a shared chat link for further negotiation.
8. The method of item 7, further comprising inferring a mutual non-disclosure agreement upon entry into said chat.
9. The method of item 7, wherein said negotiation may include exchange of structured digital negotiation agreements.
10. The method of item 7, wherein each agent may determine internally whether to escalate the opportunity to a human user based on private policies or constraints.
11. The method of item 7, wherein a digital negotiation agreement (DNA) may optionally be introduced at a later point during the chat session, after the initial connection has been established, to formalize confidential or strategic collaboration terms.
12. For enablement purposes, it is further described that the server-side evaluation of strategy pairs may be performed as follows: two strategy descriptions, submitted in natural language, may be programmatically selected by the matchmaking engine and passed as input to a large language model (LLM) hosted on the platform or accessed via an external API. The LLM may process both strategies within a prompt template designed to elicit an explanation of synergy scope and rationale. The output may include: (i) whether a mutual benefit exists, (ii) a proposed form of collaboration, and (iii) a natural-language justification of the match. This output may then be parsed and embedded into the match object delivered to both agents, enabling transparent evaluation and initiating negotiation where appropriate.

### Embodiment K: Emergency Medical Guidance Via Offline Embedded Language Model in Mobile Devices

A system and method for providing emergency medical assistance using an embedded language model (LLM) within a mobile device operable without internet connectivity. The invention may provide first aid, triage guidance, and critical health instructions in real-time using on-device processing. The embedded model may optionally access locally available data, such as user medical history, biometric sensors, or GPS, and adapt recommendations accordingly. The system may support voice-based and text-based interaction, include safety mechanisms to prevent harmful hallucinations, and permit periodic updates when connectivity is restored. This allows individuals in remote or disaster-affected areas to receive potentially life-saving medical guidance autonomously.

BACKGROUND: Access to timely medical advice is critical during emergencies, yet individuals frequently encounter connectivity loss during travel, natural disasters, or in rural environments. Existing digital medical assistants require internet access to function, rendering them ineffective under such conditions. Furthermore, existing offline resources, such as downloaded PDFs or static rule-based applications, lack adaptability and personalized interaction. There is a need for a system that can provide context-aware, adaptive, and reliable medical guidance without relying on cloud infrastructure.

SUMMARY OF THE INVENTION: The present invention proposes an embedded large language model (LLM) that operates directly on a mobile device such as a smartphone, smartwatch, or tablet, providing medical guidance without requiring internet access. In one embodiment, the LLM is specifically trained on first-aid procedures, basic diagnostics, and emergency response protocols. The model may be optimized for edge-device inference, reducing size and power consumption while maintaining accuracy. The system may allow a user to describe symptoms or an emergency scenario via voice or text. The model interprets this input and generates a series of actionable, context-appropriate steps. Optionally, the model may utilize available local data, such as:
* User profile (e.g., age, known conditions)
* Biometric sensor input (e.g., heart rate, temperature, oxygen)
* Environmental context (e.g., GPS location, altitude)

A safety layer may constrain the model to prioritize conservative, life-preserving decisions and alert the user when a hospital visit or professional consultation is advisable. Offline logs may be stored and synced when the device reconnects.

### DETAILED DESCRIPTION

**1. Architecture:**
* The language model may be a distilled, quantized version of a medically-tuned transformer model (e.g., 3B parameters or smaller).
* It may run on an edge accelerator (e.g., Apple Neural Engine, Qualcomm Hexagon DSP).
* Core functions include:
* Input processing (text/voice)
* Context integration (biometrics, location)
* Response generation
* Safety filtering
**2. Interaction Modes:**
* **Text Entry:** Users can type symptoms or questions.
* **Voice Interface:** Users can speak aloud; speech-to-text conversion handled locally.
* **Hands-Free Mode:** Activated by hotword or gesture.
**3. Emergency Scenarios Covered:**

The embedded LLM may provide guidance for: Cardiopulmonary resuscitation (CPR), Bleeding control, Choking, Allergic reactions, Burns, Dehydration, Seizures, Ankle sprains, fractures, and immobilization, Shock
**4. Safety Features:**
* Risk thresholds: If confidence is low or user input is unclear, the model suggests conservative action or seeks more data.
* Disclaimer prompts: User informed that the advice is not a substitute for professional care.
* Red team training: The model is fine-tuned to avoid hallucinations and minimize liability.
**5. Update Mechanism:**
* The model and medical database may be updated when the device regains internet access.
* Logs and interactions are saved locally and encrypted for user privacy.
**6. Multilingual Support:**
* Model may be multilingual or include fallback translation modules.
**7. Regional Adaptation:**
* Optional loading of location-specific medical practices (e.g., venomous snakebite protocols for jungle regions).
**8. Integration with Health Apps:**
* Optional integration with Apple Health, Google Fit, or proprietary apps to personalize advice.

To enable implementation of the invention, one may begin by collecting and curating a dataset comprising trusted medical literature, first aid guides, emergency medical protocols, and real-world patient dialogue samples. The language model may be fine-tuned using supervised learning and reinforcement learning with human feedback (RLHF) to optimize for clarity, safety, and conservatism in recommendations. Training may be performed on medical-specific subsets of general-purpose LLMs, with fine-tuning on use-case-specific emergency care scenarios. The model may be distilled and quantized to fit within on-device hardware constraints, using tools such as ONNX, Core ML, or TensorFlow Lite. Integration within the mobile device may be achieved by embedding the inference engine within the operating system's AI runtime (e.g., using Apple Core ML or Android NNAPI). The model may be triggered by a local application that manages input, invokes model inference, and formats the output. The app may optionally connect with voice recognition systems available on the phone, or use offline speech-to-text models. Biometric and contextual sensor data may be accessed via local APIs to inform the model response. The system may be deployed in secure sandboxed environments with user consent dialogs and built-in legal disclaimers. Updates to the model weights or medical knowledge base may be provided over-the-air and integrated only after user review and approval.

EXAMPLE USE CASE: A traveler in a mountainous area with no reception slips and injures their leg. Unable to call emergency services, they activate the emergency medical LLM. By describing their symptoms, they receive step-by-step instructions to check for fracture signs, create a splint, and elevate the leg. The system also advises on hydration, shock signs, and when to move or rest.

The embodiments may be described by the following itemized list:
1. A method of providing emergency medical guidance using a language model embedded on a mobile device, the method comprising: receiving user input describing a medical condition; processing the input using a locally stored language model; generating step-by-step emergency instructions based on said input; and outputting said instructions to the user via text or audio, wherein the method operates without requiring internet connectivity.
2. The method of item 1, further comprising accessing local sensor data to contextualize the medical guidance.
3. The method of item 1, further comprising triggering a conservative fallback response when the model's confidence is below a defined threshold.
4. The method of item 1, wherein the language model may be optimized for execution on a mobile AI accelerator.
5. The method of item 1, further comprising a hands-free activation mechanism.
6. The method of item 1, wherein user interaction logs may be stored locally and synced when internet connectivity is restored.
7. The method of item 1, further comprising displaying a disclaimer indicating that the guidance is not a substitute for professional medical advice.
8. The method of item 1, further comprising multilingual support.
9. The method of item 1, further comprising automatic integration with local health data applications to enhance personalization.
10. The method of item 1, wherein the language model may be periodically updated when connectivity becomes available.

### Embodiment L: Aerial Precision System for Targeted Ant Trail Disruption and Aphid Biocontrol Using a Robotic Drone Mechanism

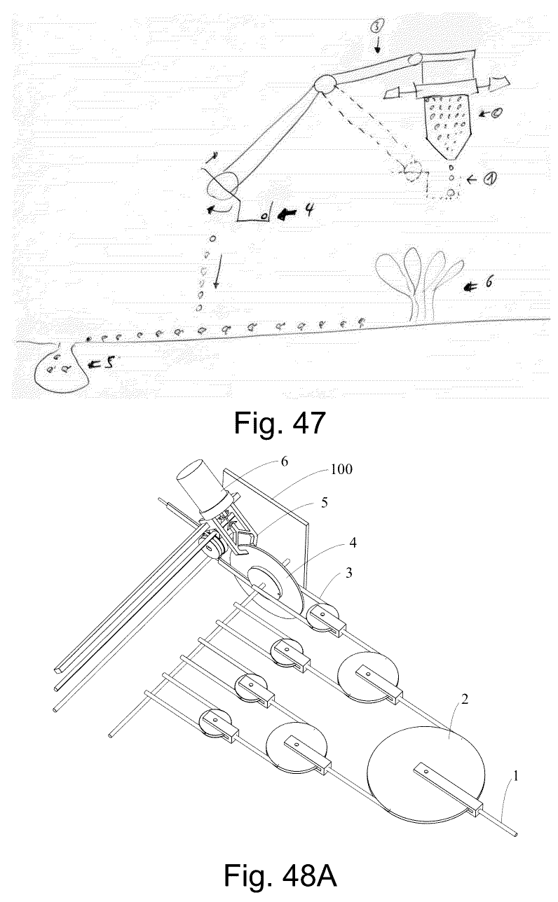

FIG. 47 depicts one embodiment of this invention. This embodiment builds further on: US20250162711A1

Background of the Invention: Ant species that farm aphids create a persistent agricultural challenge by protecting aphid colonies in exchange for honeydew. This ant-aphid mutualism leads to larger aphid populations, greater crop damage, and suppression of natural aphid predators. Conventional mitigation strategies rely heavily on chemical spraying, which is imprecise, environmentally damaging, and indiscriminate. There remains a clear need for a more ecologically sound and behaviorally informed method to disrupt this relationship, ideally by targeting the ant colony directly without affecting non-target species or the broader environment.

Summary of the Invention: The present invention describes an unmanned aerial vehicle system configured to detect, approach, and precisely position a toxic or otherwise disruptive payload onto or near the foraging trail of ants engaged in aphid farming. Aerial deployment allows for a high degree of precision and the possibility of revisiting the location to perform sequential or multimodal interventions, such as deploying beneficial insect predators after initial colony weakening. The system employs a lightweight robotic arm and end-effector capable of receiving and positioning small payloads-such as poison bait balls, abrasive powders, or live biological agents-over locations determined through visual or spectral plant analysis and ant behavior observation.

Detailed Description of the Invention: Description of the Components Identified in the Drawing The accompanying illustration (not shown) schematically represents the interaction between the drone-based delivery system and the ant-aphid agricultural environment. The figure includes multiple numbered components, each of which corresponds to a functionally distinct element of the system as outlined below.

A component labeled as (1) depicts the cup in a loading state, wherein the cup is positioned directly underneath the onboard ball dispenser. In this configuration, the robotic arm is retracted or aligned such that the distal end of the arm places the cup concentrically below the dispenser outlet. This allows the dispenser to release a single poison bait ball or other payload into the cup through gravity or gentle mechanical feed. The loading state is intended to be transient, with the cup soon transitioning into the deployment configuration.

The component labeled (2) shows the ball dispenser mounted beneath the drone frame. The dispenser may take the form of a gravity-fed magazine, a motorized chambered unit, or a hopper-style feeder capable of holding and sequentially releasing spherical payloads. It is contemplated that this dispenser is configured to interface securely with the cup's opening during the loading phase and is dimensioned to accommodate bait balls of consistent geometry and mass.

Component (3) represents the upper limb of the robotic arm, which is constructed similarly to the robotic actuator disclosed in US20250162711A1. This limb may be cable-driven or feature integrated rotary joints and is mechanically coupled to the drone chassis. The limb serves to articulate the cup between its loading and deployment states, providing vertical and lateral mobility while maintaining system balance. It is anticipated that the upper limb offers at least two degrees of freedom to allow extension and precise positioning.

Component (4) illustrates the cup in a “ready-to-release” configuration, where it has been extended by the robotic arm away from the central axis of the drone to a location hovering above the intended drop site. In this state, the cup contains a bait ball and is held over the ant trail, as inferred or detected via onboard imaging systems. The cup may be constructed with a tipping mechanism actuated by a small servo located at the joint, or alternatively, through a tensioned cable routed along the robotic arm and remotely controlled by a servo mounted on the drone body. This flipping action allows the ball or payload to be deposited with precision and minimal kinetic disturbance.

The element labeled as (5) denotes a schematic representation of an ant nest, typically situated in or near the soil at the base of the field. This nest serves as the origin of the foraging trail and is not necessarily directly visible to the drone, although its location may be inferred based on trail structure and aphid concentrations. It is contemplated that the drone may target trail locations proximate to the nest in order to maximize bait uptake and colony impact.

Component (6) shows a crop plant, particularly one that exhibits signs of aphid infestation. These plants often emit specific spectral signatures detectable through near-infrared or multispectral imaging. The ant trail commonly leads from the nest to such plants, as the ants actively protect aphid colonies to harvest honeydew.

By identifying this plant, the system may prioritize targeting the trail section where ant activity is most concentrated.

Connecting the ant nest (5) and the crop plant (6) is a visible or inferred ant trail, typically rendered in the drawing as a dotted or curved line. This trail forms the behavioral path along which the drone system will position the poison ball. In some applications, this trail may be identified using a downward-facing RGB camera paired with edge detection algorithms or via operator tagging based on prior knowledge.

Taken together, the identified components enable a closed-loop system for the detection, loading, positioning, and precise deployment of disruptive substances-ranging from poison bait to predators-directly onto the foraging trail of aphid-farming ants. The diagram represents not only the mechanical states of the arm and payload mechanism but also the biological context into which the system is deployed.

In one contemplated embodiment, the system comprises a multirotor drone outfitted with downward-facing cameras and stabilization features suitable for close proximity hovering over foliage. Mounted to the underside of the drone is a compact dispenser unit containing multiple preloaded poison bait balls or similar small payloads. A lightweight robotic arm, resembling the upper limb configuration described in US20250162711A1, extends below the drone and is designed to manipulate a detachable or tiltable cup at its distal end. The cup may be positioned beneath the dispenser to receive a payload, and thereafter extended outward to deliver the substance at a target location.

Trail identification may be accomplished through a variety of means. In some applications, the ant trail is inferred from visual observation of linear patterns between visible ant nests and aphid-affected crop plants.

Alternatively, near-infrared (NIR) imagery or vegetation indices may be used to identify plant stress or specific aphid-related signatures, providing an indirect indicator of ant activity. It is anticipated that such imaging data may be collected in real time during the drone's flight or preloaded from satellite or prior survey data. Once the trail is localized, the robotic arm transitions the cup to a loading position directly beneath the dispenser. Upon receiving a payload-typically a poison bait ball—the arm then repositions the cup to a “ready-to-deploy” configuration hovering above the inferred trail path. At the selected release site, the cup may be actuated to flip or tilt, thereby depositing the ball onto the trail. This flipping motion may be performed by a dedicated servo located at the end-effector, or alternatively via a cable routed through the robotic arm and tensioned by a remotely located servo. The poison bait ball is envisioned to be formulated with a palatable sugar base, optionally combined with slow-acting insecticides such as boric acid, fipronil, spinosad, or hydramethylnon. In some cases, the ball may also include synthetic pheromones to encourage foraging and trophallaxis, as well as biodegradable carrier materials such as starch or agar. In certain embodiments, the cup may additionally be loaded with finely ground natural shell material-such as eggshells or diatomaceous earth-intended to physically abrade and compromise the cuticle of ant larvae or other soil-dwelling pest stages. This material may be dispersed gently over the nest site or trail using a similar tilting motion.

Crucially, the system does not limit itself to poison-only deployments. In a multi-phase treatment strategy, the drone may return to the site hours after initial bait deployment. Once ant activity is sufficiently reduced, the drone may perform a follow-up deployment, releasing beneficial predator organisms such as ladybug larvae directly onto the aphid-infested crop plant. This staged deployment method allows for the strategic weakening of ant defenses followed by the encouragement of natural biological control. The entire process may be performed autonomously or under remote operator guidance. In some envisioned implementations, an operator may manually tag visible trails or nests on a live video feed, whereas in others, AI-based visual systems may autonomously detect and prioritize trails for treatment. The overall system enables precise, repeatable, and scalable ant control with minimal environmental disturbance. The combination of behavioral targeting, aerial deployment, and staged biological support reflects a significant advancement over traditional chemical spraying.

While some components may resemble prior art in robotics or UAV delivery, the combination of selective trail-based poison placement and subsequent predator release defines a novel ecological intervention platform.

In one contemplated embodiment, the invention provides a method for reducing aphid pressure in an agricultural field by intervening in the mutualistic relationship between aphid colonies and the ant colonies that protect them. The method begins with the identification of a foraging trail formed by ants-typically soil-nesting species known to protect and farm aphids on nearby crop plants. This trail may be visually observed by tracking ant movement between a presumed nest site and aphid-affected foliage, or inferred through computational means using aerial imagery. In some instances, the trail is detected based on geometric patterns or the density of moving insects. In other embodiments, the trail is inferred by detecting signs of plant stress indicative of aphid infestation using spectral imaging technologies such as near-infrared (NIR), NDVI, or similar methods.

Upon successful identification of such a trail, the method proceeds by deploying a bait composition designed to disrupt the ants' activity and, by extension, their protective behavior over the aphid colony. This bait is preferably deposited directly on or near the active foraging trail, ideally at a location where it is likely to be encountered and carried by worker ants. The bait composition may include a slow-acting toxicant-such as boric acid, spinosad, fipronil, or hydramethylnon-formulated within a sugar-rich matrix to encourage ingestion and trophallaxis. In certain formulations, additional chemical cues such as trail pheromones or flavor enhancers may be included to enhance uptake and delivery back to the nest.

The deployment of the bait is carried out by an aerial or mobile apparatus. In the preferred embodiment, the apparatus comprises an unmanned aerial vehicle (UAV), or drone, equipped with an onboard dispenser and a robotic arm. The arm includes an articulated upper limb as described in US20250162711A1, and is configured to manipulate a cup or similar receptacle mounted at its distal end. This cup serves as the temporary holder of the bait composition during its transition from the dispenser to the targeted drop location. The robotic arm can reposition the cup from a loading state beneath the dispenser to a deployment state, where it is held in alignment with the identified ant trail.

To release the bait, the cup may be actuated by either a compact servo motor located near the end-effector or by a tensioned cable system routed through the arm, connected to a servo at the base of the UAV. The flipping or tilting of the cup allows the bait ball to fall in a controlled manner onto the trail, with minimal aerodynamic interference.

In a further embodiment, the drone may return to the same site after a predefined delay—typically several hours—to conduct a second operation. At this time, the drone may be loaded with a different payload, such as live beneficial insects. The apparatus is then used to deposit biological aphid predators—such as Coccinella septempunctata (ladybug larvae), lacewing larvae, or parasitoid wasps-onto the same crop plant previously protected by the ants. The prior disruption of the ant colony allows these predators to establish and control aphid populations without interference.

In addition to chemical bait, the system may optionally be used to deliver mechanical or physical disruptors. For example, the cup may be used to release finely ground particulate matter such as eggshell powder, silica, or diatomaceous earth onto the trail or nest site. These materials are known to compromise the integrity of soft-bodied insects or larvae by abrasion, and may offer a non-toxic control pathway that complements or substitutes for chemical bait.

The system is not limited to drones. In other configurations, the same mechanisms may be deployed from a terrestrial robot, a tethered aerial platform, or a manually guided boom. However, the airborne embodiment offers key advantages, including rapid repositioning, field scalability, and minimal plant disturbance.

The UAV is expected to include onboard navigation and control logic, allowing it to autonomously execute a predefined baiting sequence once the trail or target coordinates are provided. In certain versions, the UAV may operate fully autonomously, identifying trails in real time, executing bait placement, and logging GPS-tagged release events for monitoring.

Collectively, this invention provides a scalable, minimally invasive, and ecologically mindful solution for managing aphid outbreaks by targeting the social structure that protects and sustains them. By leveraging ant behavioral patterns and combining tactical poison baiting with timed predator deployment, the system enables a new tier of targeted pest control that aligns with integrated pest management (IPM) goals.

In some embodiments, the identification of ant foraging trails is performed by acquiring high-resolution downward-facing images of the terrain, typically captured from an aerial vehicle such as a drone. This imaging may be conducted by the same unmanned aerial vehicle that is later used to deploy bait compositions, or alternatively by a separate scouting drone tasked specifically with data acquisition.

The imaging process involves capturing a series of overlapping photographs of the field or crop area at sufficient resolution to resolve fine detail on the ground, including the subtle linear paths formed by ant foragers traveling between their nest sites and aphid-hosting plants. These trails often manifest as slightly darkened or reflective lines due to repeated traffic and may be visible even in the absence of individual ants, especially under favorable lighting conditions.

Once captured, these images may be stitched into an orthorectified mosaic or processed as discrete frames, and analyzed using artificial intelligence-based vision techniques. In one implementation, a convolutional neural network (CNN) or other pattern-recognition algorithm is employed to extract potential foraging paths from the imagery. The system may be trained to identify repetitive, linear, or radiating structures that typically correlate with known ant behavior, and to differentiate these from plant stems, irrigation lines, or other field features.

This image analysis may be performed in real time (“onboard processing”) using embedded compute units on the drone, such as AI accelerators or mobile GPUs. Alternatively, the images may be transmitted wirelessly to a base station, edge server, or cloud platform where more computationally intensive analysis is performed. Once a trail or set of trails is detected, the geographic coordinates of one or more drop zones may be extracted and used to guide subsequent bait deployment operations.

The trail identification system may also incorporate additional contextual data-such as the spectral signature of vegetation—to correlate the presence of trails with known aphid infestations. This enables a hierarchical approach, where aphid-suspect crop regions are first prioritized, and then ant trails within those regions are identified and targeted. This two-tiered analysis increases deployment efficiency by focusing resources where ant-aphid interactions are most likely to occur.

In practice, the image-capturing drone may follow a serpentine or raster scan path across the field at a height optimized for image clarity, typically between 2 and 10 meters depending on camera optics and lighting. The resolution is preferably such that individual ant trails of approximately 1-2 cm in width can be resolved. The imaging vehicle may be outfitted with fixed-focus optics, stabilized gimbals, or global-shutter sensors to reduce motion blur.

This approach provides a non-contact, data-rich means of trail detection that is well suited for integration into autonomous or semi-autonomous field workflows. It further allows historical trail data to be archived and used to assess ant behavior over time, or to optimize future control efforts by building predictive models of colony dynamics.

When implemented in tandem with the bait delivery system, this imaging and AI detection capability forms the core of a self-guided, behaviorally targeted pest management platform.

In one embodiment, ant trail detection is performed using a lightweight image analysis algorithm that operates on high-resolution aerial photographs or live video frames. The method begins with the identification of individual ants in the image, preferably through a pre-trained object detection neural network such as YOLO (You Only Look Once). The YOLO detector processes the image and outputs a list of bounding boxes or centroids corresponding to the location of ants identified in the frame.

Following detection, the image is divided into a uniform two-dimensional grid of cells. The resolution of the grid may be selected based on the expected density and spacing of ant activity, with typical cell sizes on the order of 10-30 pixels in width. Each grid cell is then classified as either “contains ants” or “does not contain ants” based on whether one or more detected ant centroids fall within its spatial bounds.

Once this binary classification has been established across the grid, the algorithm searches for a connected path of ant-containing cells. Connectedness may be defined using a 4-neighbor or 8-neighbor rule, and noise filtering may be applied to eliminate isolated detections unlikely to belong to a coherent trail.

For each cell classified as containing ants, the algorithm then calculates the local weighted center of the ant positions within that cell. This may be performed by averaging the X and Y coordinates of the detected ant centroids within the grid cell, optionally weighted by detection confidence.

With all weighted centers computed, the algorithm constructs the trail path by connecting the sequence of these centers using straight line segments. This set of connected line segments forms a polygonal approximation of the ant foraging trail. Further smoothing or curve-fitting techniques may be applied to produce a more continuous trajectory suitable for guiding a robotic arm or bait delivery vehicle.

This method provides a computationally efficient approach to approximate trail structure based on discrete detections, and is well suited for implementation in onboard systems with limited processing capability.

In an alternative embodiment, ant trails may be inferred by tracking the movement of individual ants across multiple image frames using optical flow techniques. By applying sparse or dense optical flow algorithms-such as Lucas-Kanade or Farneback—to consecutive frames captured from a low-altitude drone, the system identifies coherent motion vectors associated with foraging ants. These short-term trajectories are accumulated over time to form persistent linear movement patterns. Clustering and filtering methods may then be applied to isolate the dominant direction of travel, allowing the system to reconstruct the underlying trail even in cases where the trail is not visually apparent in a single frame. In another embodiment, individual ant detections are treated as nodes in a spatial graph, with edges drawn between detections that fall within a defined spatial proximity. A traversal algorithm-such as depth-first search or a shortest-path heuristic—is used to identify the most likely foraging trail by locating the longest or most connected path within the graph. This graph-based approach accommodates irregular trail geometries and is robust to intermittent or noisy detections, as it leverages the spatial structure and density of ant movement rather than relying solely on image features.

In one implementation, a commercially available drone platform-such as a DJI quadcopter—is modified to incorporate a lightweight cable-driven robotic arm mounted centrally beneath the drone body. The arm includes multiple degrees of freedom and terminates in a functional end-effector, such as a tiltable cup used for bait or agent deployment. To enable closed-loop control and real-time positioning of the end-effector relative to external targets, the system further includes two downward-facing first-person-view (FPV) cameras mounted in fixed positions near the drone's center axis. These cameras are oriented to provide overlapping visual coverage of the working area directly beneath the drone, including the end-effector and the target site on the ground (e.g., an ant trail or aphid-infested plant). Both camera feeds are transmitted wirelessly to an offboard computer, which performs simultaneous image analysis to locate two key visual features: the current position of the end-effector-marked by a visually distinctive element such as a specific color, geometric pattern, or light-emitting marker—and the target position on the ground, which may be identified through prior mapping or real-time detection. By analyzing the relative positions of the end-effector and the target in both camera views, the system infers the spatial offset between them.

To control the arm, the computer issues servo commands that actuate the cable-driven joints of the arm. Over time, the system may observe how specific servo commands result in specific visual displacements of the end-effector in image space. This control loop may be implemented as a hard-coded mapping function, but is preferably learned automatically, using either supervised calibration procedures or reinforcement learning techniques. In the latter case, the system iteratively experiments with servo actions and refines a control model based on feedback from observed positional outcomes. This approach is particularly robust to small misalignments or calibration errors between the cameras and the drone frame, as the control logic relies not on geometric assumptions but on empirical learning of how to move the end-effector to visually coincide with the target. The system is thereby able to position the payload precisely above the target location without requiring externally calibrated camera rigs, GPS refinement, or complex 3D modeling, making it highly practical for field deployment.

In this embodiment, the offboard computer not only performs visual analysis of the FPV video streams but also issues low-level actuator commands to control the drone's robotic mechanisms. These commands are transmitted to the drone via a wireless link, which may be implemented using a conventional radio control (RC) transmitter paired with an onboard RC receiver, or alternatively through a Wi-Fi or telemetry module connected to the drone's flight controller and auxiliary servo driver. The servo commands determine the angular positions or tension forces applied to the cable-driven joints of the robotic arm, enabling precise positioning of the end-effector based on visual feedback. In addition to controlling the arm's spatial movement, the system may also engage various types of end-effectors. For instance, the computer may command the cup to tip and release its contents, open a valve to dispense a measured water droplet, or trigger a high-voltage discharge if the end-effector is configured as an electrified probe. These functions are mapped to discrete RC channels or digital control lines, and can be activated remotely from the offboard interface in coordination with visual alignment tasks.

Furthermore, the same offboard computer may be used to send high-level navigational or positioning commands to the drone itself, such as instructing it to move laterally, adjust altitude, or hold position above a specified target. This drone maneuvering can be performed via standard RC pitch/roll/yaw inputs, MAVLink waypoint commands, or direct flight controller integration. Because the vision system remains in the loop during these movements, fine adjustments to the drone's position can be made in tandem with arm articulation, ensuring that both the drone and the arm cooperate to achieve sub-centimeter end-effector placement accuracy. The modularity of this control framework allows a single operator or autonomous program to coordinate multi-modal actions-such as identifying a trail, aligning above it, manipulating the arm, and releasing a payload—with minimal onboard processing requirements, since all decision logic resides offboard.

Alternatively, the robotic arm and cup-based deployment mechanism need not be limited to aerial platforms and may be mounted on a ground-based mobile unit, such as a quadrupedal robot (e.g., a robot dog) or a wheeled rover. In the case of a robot dog, the articulated limbs provide stable locomotion over uneven agricultural terrain, while the arm mounted on its back or torso can extend to deploy the bait cup with precision. This configuration offers advantages in endurance, payload capacity, and proximity to ground-level targets such as ant nests and foraging trails. Similarly, the system may be implemented on other mobile platforms, including tracked vehicles, autonomous field robots, or manually operated booms, depending on the terrain and scale of the application. In each case, the core inventive principle remains the same: identifying the spatial location of ant foraging trails that connect to aphid-infested crops, and precisely placing a bait or biological control agent along that trail to disrupt the ant-aphid mutualism. The delivery mechanism, imaging system, and control logic may be adapted to the mobility constraints and affordances of the chosen platform, but the fundamental concept—targeting ant behavior to indirectly control aphids-remains central to the invention. The embodiments may be described by the following itemized lists:
1. A method for controlling aphid populations in a crop environment, the method comprising: identifying a foraging trail of ants that protect aphid colonies; and depositing a bait composition on or near the foraging trail, the bait being configured to disrupt the ant colony and thereby reduce aphid protection.
2. The method of item 1, wherein the bait composition may comprise a sugar-based carrier and a slow-acting insecticide selected from the group consisting of boric acid, fipronil, spinosad, and hydramethylnon.
3. The method of item 1, wherein the foraging trail may be identified by detecting linear movement patterns between an ant nest and an aphid-infected crop plant using aerial imagery.
4. The method of item 1, wherein the foraging trail may be inferred by detecting aphid-induced plant stress via near-infrared or multispectral imaging and estimating the likely ant path from surrounding nest sites.
5. The method of item 1, further comprising actuating a robotic arm to move a cup containing the bait composition from a loading position to a deployment position prior to release.
6. The method of item 5, wherein the cup may be flipped to release the bait composition by a servo motor or by a tensioned cable actuated remotely.
7. The method of item 1, further comprising returning to the aphid-infected crop plant after a time delay and releasing live beneficial predators selected from the group consisting of ladybug larvae, lacewing larvae, and parasitic wasps.
8. The method of item 1, wherein the bait composition may include finely ground shell material configured to physically irritate or damage ant larvae or soft-bodied pests.
9. The method of item 1, wherein the depositing step may include hovering a drone at a height of less than one meter above the ant trail and actuating a gravity-assisted or mechanically-tilted release mechanism.
10. An apparatus for disrupting ant colonies that protect aphid populations on crops, the apparatus comprising: a mobile platform; a trail detection system configured to identify a foraging trail of ants; and a bait delivery mechanism mounted on the platform and configured to deposit a bait composition on or near the identified trail.
11. The apparatus of item 10, wherein the mobile platform may comprise an unmanned aerial vehicle.
12. The apparatus of item 10, wherein the bait delivery mechanism may comprise a cup configured to receive a bait composition from a dispenser and to release the bait by tilting, flipping, or dropping.
13. The apparatus of item 12, further comprising a robotic arm coupled to the mobile platform, the arm being configured to position the cup at a desired drop location.
14. The apparatus of item 13, wherein the cup may be actuated by a servo motor or a tensioned cable to release the bait.
15. The apparatus of item 10, wherein the trail detection system may comprise a camera and an image processing unit configured to detect ant movement or infer trails based on plant stress or spatial patterns.
16. The apparatus of item 10, wherein the bait composition may include a slow-acting toxicant combined with a carbohydrate attractant.
17. The apparatus of item 10, further comprising a secondary dispenser configured to release beneficial insects or additional substances onto the crop or nest site after a predetermined time delay.
18. The apparatus of item 10, wherein the bait delivery mechanism may be further configured to dispense particulate abrasive material such as finely ground shell or silica to physically damage ant larvae or soft-bodied pests.
19. The apparatus of item 10, wherein the mobile platform may comprise autonomous navigation and control means for executing a programmed baiting sequence based on identified trail locations.

### Embodiment M: Cable-Based Multiplexed Actuation System for Lightweight Robotic Limbs and End-Effectors

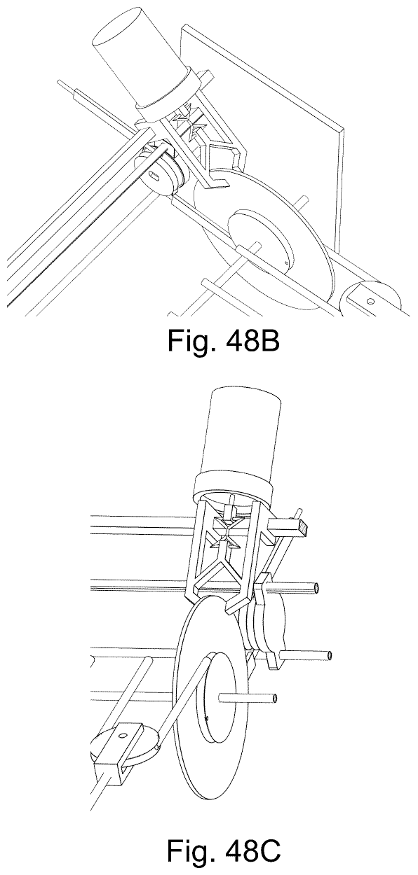

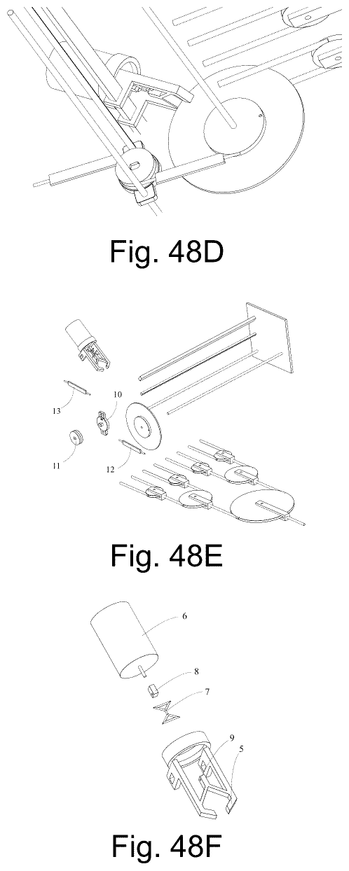

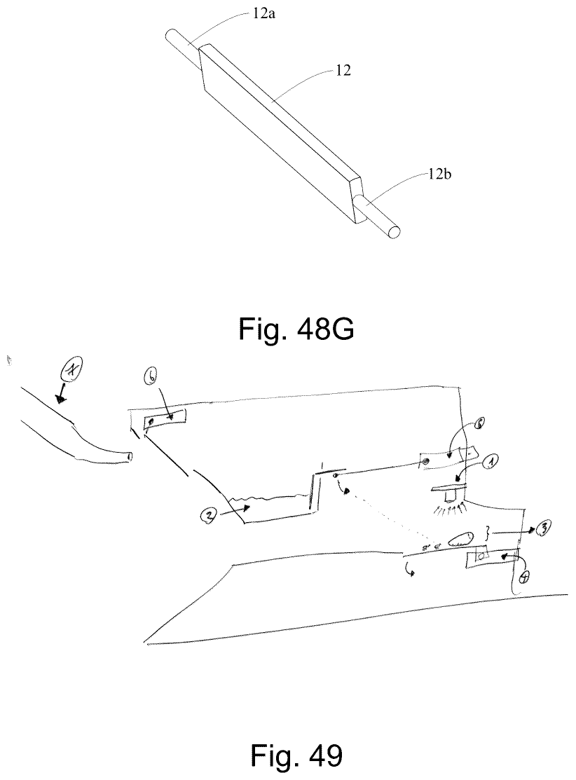

The example embodiment is depicted in FIGS. 48A to 48G.

TECHNICAL FIELD: The present invention relates generally to the field of robotics, and more specifically to systems and methods for cable-driven actuation. In particular, the invention pertains to multiplexed motion transmission architectures for robotic limbs, arms, or end-effectors, including those mounted on unmanned aerial vehicles (UAVs) or multi-limbed robotic platforms, wherein a single actuation input may be selectively routed to multiple outputs through a centralized gating mechanism.

BACKGROUND: Cable-driven robotic systems are widely used in applications where weight reduction, spatial decoupling, or safety is critical. In such systems, actuators are often located remotely from the actuated joints, and force is transmitted via tensioned cables, tendons, or pull-lines. This architecture has seen particular use in soft robotics, aerial manipulators, prosthetics, and lightweight multi-limbed robots. While cable-based actuation provides several advantages—such as low moving mass and increased compliance—it presents key challenges in scalability and control.

In conventional designs, each degree of freedom typically requires its own dedicated actuator, routed control cable, and associated electronics. As the number of joints increases, this one-to-one mapping leads to a proportional increase in system weight, cost, power consumption, and mechanical complexity. This limitation is especially problematic for UAVs, where distributed weight severely impacts flight stability and energy efficiency, and for agricultural or field robots, which benefit from low-cost, robust, and scalable designs. Furthermore, many cable-driven systems lack mechanisms for energy buffering or time-delayed release, meaning that actuation must be synchronized in real time, requiring more sophisticated controllers and higher energy peaks. In some applications-such as insect targeting, weed suppression, localized pollination, or environmental manipulation-motion can be slow, but must occur reliably and in parallel across multiple joints, often with limited onboard computation or actuation resources.

There remains a need for a multiplexed actuation architecture that allows a single actuator to control multiple joints or outputs by selectively routing force, optionally storing energy in elastic elements, and releasing it in a delayed, controlled manner. Such a system would allow robotic limbs and manipulators to achieve higher degrees of freedom with fewer actuators, centralized actuation, reduced weight, and improved safety—particularly in applications where cost, power, and weight constraints are dominant.

SUMMARY: The present invention provides a multiplexed cable-driven actuation system for robotic limbs, anns, or end-effectors, particularly suited for use on unmanned aerial vehicles (UAVs) and multi-limbed robotic platforms. The system is designed to allow a single actuation input to selectively deliver mechanical force to multiple output paths via a centralized motion multiplexer, thereby significantly reducing the number of actuators required to achieve multi-joint motion.

In one embodiment, the invention comprises a motion multiplexer having a set of selectively actuated motion gates, each coupled to a corresponding control cable. The multiplexer is configured to receive input from a single input cable or actuator and, based on the state of the motion gates, to route mechanical force to one or more downstream output cables. Each output may be connected to a cable-driven joint or end-effector, located remotely on a limb, arm, or manipulator.

In some embodiments, elastic energy storage elements are connected to the output cables. When a gate is open, motion from the input cable stretches the elastic element, storing potential energy. This energy may then be released through a rotational damper, allowing time-delayed, smoothed motion to be delivered to the limb or end-effector. This enables temporal buffering of discrete actuation inputs and the coordination of multiple joint motions using a single actuator.

The motion gates may be actuated by dedicated lightweight actuators, such as coreless motors or shape-memory alloy (SMA) wires. Alternatively, a single indexing actuator may be used to selectively enable one motion gate at a time, either in a predefined sequential order or on demand under control of a computational controller. This approach allows for extremely low actuator count while maintaining the ability to route motion to any of multiple outputs based on system requirements or environmental conditions.

The system may be implemented using 3D-printed mechanical components, including spools, clamps, and structural mounts, in combination with commercially available rotary dampers, fishing-line-style control cables, and low-friction routing guides. The use of modular, low-cost components enables scalable and field-deployable designs.

In one application, the multiplexed actuation system may be integrated into the central body of a multi-limbed robot, such as a hexapod, wherein the limbs are constructed from passive, lightweight structures without embedded motors. In another embodiment, the system may be mounted on a UAV with a cable-actuated robotic arm, enabling manipulation of objects or plants with high precision while maintaining flight stability due to centralized mass distribution.

The invention is particularly suited for tasks that involve slow-changing or continuous environments, including but not limited to weed suppression, insect targeting, localized pollination, leaf manipulation, environmental sampling, cleaning, hedge trimming, and debris removal. Because these tasks do not require rapid motion but benefit from persistent, autonomous operation, the proposed system enables a robot to perform complex functions using minimal energy and a simplified control system.

By decoupling the number of joints from the number of required actuators, and enabling elastic buffering, delayed motion, and lightweight remote actuation, the invention offers a scalable, energy-efficient, and low-complexity solution for cable-driven robotic systems across a wide range of domains.

### BRIEF DESCRIPTION OF DRAWINGS

FIG. 21A shows an overview

FIG. 21B shows an more detailed view

FIG. 21C shows an more detailed view

FIG. 21D shows an more detailed view

FIG. 21E shows an exploded view

FIG. 21F shows an detailed view of the example braking mechanism

FIG. 21G shows an detailed view of the example elastic with wire ends.

### DETAILED DESCRIPTION OF ILLUSTRATIVE EMBODIMENTS

In one embodiment, the system may comprise an input actuation cable (1) that is configured to transmit a pulling force to an input-to-intermediate cable splitting pulley (2). This pulley may redirect the incoming force, possibly in a cascading pulley configuration, into two or more branches of intermediate output cables (3). These cables may be routed toward a primary dual-groove spool with flywheel (4), which could serve as a rotary interface between linear input motion and downstream actuation elements.

The primary spool (4) may be mechanically and continuously coupled to a rotational energy dissipation unit (10) via a secondary dual-groove spool (11), wherein the coupling may include an elastic energy transmission member (12). The rotational energy dissipation unit (10) may be configured to resist or modulate rotation of spool (11), thereby dissipating mechanical energy during periods of dynamic loading.

The ability of the primary spool (4) to rotate—and thereby allow motion from the intermediate cable (3) to influence the elastic element (12)—may be governed by an electromechanical clamp assembly (5). When disengaged, the clamp may permit the spool to rotate, enabling adjustment of the elastic tension via movement of the intermediate cable. When engaged, the clamp may inhibit rotation, thereby maintaining the current elastic tension.

In some implementations, the stored elastic tension may act in mechanical opposition to a constant counter-tensionapplied by an end-effector, joint, or limb, as may be found in a cable-driven robotic system. If the stored elastic tension exceeds this counter-tension, the rotational energy dissipation unit (10) may permit contraction of the elastic element, resulting in motion of the coupled output. Conversely, if the counter-tension dominates, the motion may be restricted or reversed.

This configuration may enable temporal buffering and time-sliced actuation, in which a single actuation input is used to incrementally update the tension of multiple elastic elements over time. The resulting mechanical states may be resolved in parallel based on threshold tension levels or damped response profiles, such that multiple end-effectors or joints are actuated indirectly and asynchronously, possibly without requiring direct simultaneous input.

In this way, the system may support distributed mechanical coordination using minimal actuation channels, and could be particularly suitable for applications in cable-driven robotics, soft robotic limbs, multiplexed actuators, or passive motion control mechanisms.

In some embodiments, the elastic energy transmission member (12) may comprise an elongate elastic section flanked by non-elastic terminal segments (12a, 12b), such as braided fishing wire, kevlar thread, or similar high-tensile cord. These non-stretch segments may facilitate reliable attachment to the wire anchors or tie points located on the primary spool (4) and the secondary spool (11), enabling secure mechanical coupling without risk of creep or slippage under tension. The central elastic portion (12) may be formed from a stretchable material such as rubber, silicone, or polymeric elastomers, while the terminal segments (12a, 12b) may be mechanically crimped, knotted, or adhesively bonded to the elastic core. This hybrid structure allows the elastic member to maintain consistent dynamic properties while simplifying integration with grooved spools or quick-release attachment mechanisms.

In some embodiments, the elastic energy transmission member (12) may comprise a hybrid structure formed by a central stretchable segment (12) bounded by non-elastic terminal segments (12a, 12b). The stretchable portion may consist of an elastomeric material such as rubber, silicone, or a resilient polymer, while the terminal segments may be fabricated from low-stretch, high-tensile materials such as fishing line, aramid fiber, or braided steel. These non-elastic ends (12a, 12b) may facilitate robust anchoring to the wire attachment points on the primary spool (4) and the secondary spool (11), providing precise mechanical coupling without slippage.

Similarly, the output cable (13) may also be realized as a composite element comprising a central elastic segment (13) with non-stretchable ends (13a, 13b), which may be anchored to downstream robotic components or guiding hardware. This configuration allows the robotic limb or end-effector to exhibit bidirectional compliance, as both the pulling and returning motions may be influenced by the elasticity of the cable itself. The non-elastic terminal sections (13a, 13b) may serve to maintain positional stability at attachment points, while the central elastic segment (13) introduces passive flexibility and impact tolerance.

By integrating elasticity into both the energy storage path and the output linkage, the system may accommodate soft, compliant motion in both actuation and retraction directions, which may be advantageous in robotic systems that interact with delicate objects, adapt to variable loads, or require shock absorption during operation.

The mechanism may be configured to convert simple, discrete actuation inputs-such as a tug on a cable-into smooth, delayed, or buffered motion, which could be particularly advantageous for controlling limbs or joints in soft robotic or cable-driven systems. In one embodiment, an input cable may provide the primary actuation force, which may be routed through a motion splitter that divides and redirects the input into multiple intermediate output cables. These outputs could then be directed to different subsystems or degrees of freedom, either sequentially or in parallel. Before motion is transmitted further downstream, it may pass through a selective locking mechanism-such as a motor-actuated clamp-which may be engaged to inhibit motion or released to permit it. This clamp may act as a gating mechanism, selectively allowing or blocking motion transmission depending on control logic.

When disengaged, the clamp may permit motion to be transferred into an elastic member, such as a spring or rubber element, which may be configured to store potential energy. This elastic component could serve as a temporary buffer or motion accumulator, capable of releasing the stored energy gradually or at a later time. The energy stored in the elastic member may then pass through a rotational damping element, which could be configured to slow or regulate the release, thereby transforming a fast input into a controlled and gradual output motion. In some embodiments, the output cable-coupling the mechanism to a limb, joint, or end-effector—may also include an elastic section. This additional compliance may allow the output structure to flex in both actuation and return directions, potentially improving shock absorption, adaptability to external forces, and mechanical safety.

Through this architecture, discrete cable inputs may be mapped to time-buffered mechanical outputs, enabling a small number of lightweight actuators to coordinate complex, distributed motion across multiple joints or limbs.

In one conceptual representation, the downstream mechanical path of the system may be described as a sequence of functional stages: Input→Intermediate→Gate→Potential Store→Delayed Motion→Compliant Output. An input force—typically delivered via a cable—may first be routed through intermediate structures such as pulleys or splitters that distribute or redirect the actuation. The resulting intermediate motion may then pass through a selectively actuated gate, such as a motorized clamp, which may be engaged or released to control whether motion proceeds further downstream.

When the gate is opened, motion may be transmitted into a potential store, for example an elastic element, which may temporarily retain energy as strain. This stored energy may then pass through a motion delay mechanism, such as a rotary damper, which could regulate the release of energy to produce a gradual, time-buffered mechanical response. The resulting motion may be delivered to a compliant output, such as a limb, joint, or end-effector, which may itself incorporate elastic elements for bidirectional flexibility and passive interaction.

In some embodiments, the potential store and time delay mechanisms may be omitted, resulting in a more direct transmission of force from input to output. While this simplified configuration may reduce complexity, it may also limit the system's ability to coordinate parallel motion across multiple limbs, effectively allowing only one degree of freedom to move at a time. In contrast, inclusion of elastic buffering and delayed release may enable time-multiplexed control, whereby a single actuator may sequentially set energy states across multiple outputs, which then resolve into continuous or overlapping motion.

The gate stage may be implemented using a wide variety of mechanisms configured to selectively enable or disable the transmission of motion or force. In some embodiments, a motor-actuated friction clamp may be used to press against a rotating shaft or pulley, thereby arresting movement when activated. Alternatively, a solenoid-operated pin-lock or brake could insert a locking element into a detent or slot to hold a component in place. In certain cases, a ratcheting mechanism with an escapement release may permit motion in discrete steps and provide mechanical locking between updates. A magnetic clutch might be employed to selectively engage or disengage rotary elements via controllable magnetic coupling. In other variants, a bi-stable snap-action cam lever may be used to toggle between locked and released states using minimal actuation energy. A servo or micro-motor could be configured to pull a wedge, band brake, or compression collar that physically restrains motion by frictional or mechanical interference. In some lightweight or compact designs, a shape-memory alloy wire, such as nitinol, may contract upon heating to actuate a clamp or lock. Additional implementations may rely on electrostatic, pneumatic, or magnetic braking systems, each of which could apply force-based resistance to motion without requiring direct mechanical contact. In further embodiments, the gate function may be achieved by modulating the viscosity or yield strength of a fluid using electrorheological or magnetorheological effects, allowing for smooth and variable engagement. These mechanisms may be selected based on criteria such as speed of actuation, energy efficiency, physical footprint, or compatibility with digital control systems.

The gate may function as a binary on/off device or as a proportional controller, and may in some cases be operated passively or triggered by conditions within the system.

In some embodiments, a single actuator may be configured to selectively open one of multiple motion gates, thereby allowing sequential or addressable control over a set of downstream elements. For example, a servo motor may rotate to discrete angular positions, each corresponding to the mechanical engagement or release of a particular gate. In such a configuration, the actuator may drive a rotary indexing arm, cam disc, or sliding linkage, which in turn selectively actuates one gate at a time while the others remain locked. This form of mechanical multiplexing may significantly reduce the total number of actuators required to control multiple limbs, joints, or elastic buffers, enabling a compact and low-cost design. The indexing behavior may be time-synchronized with the input actuation signal, allowing one gate to be opened just prior to motion input, and closed again before the next is addressed. This approach could allow a single input force-when combined with fast gating and buffering—to update the state of multiple elastic elements in succession, each of which may subsequently produce delayed and overlapping output motion. Such a mechanism may be particularly advantageous in systems where weight, cost, or wiring complexity must be minimized, and where fine-grained real-time coordination is not strictly necessary.

In one practical implementation, an embodiment of the system may be constructed using lightweight, modular components and standard fabrication techniques. Each motion gate may be actuated either by its own dedicated coreless motor, selected for its minimal weight and low inertia, or, in alternative embodiments, a single gate-selector servo may be used to mechanically engage one gate at a time through an indexed cam or rotary selector. The motion gates themselves may consist of 3D-printed clamps or locking mechanisms, mechanically interfaced with 3D-printed rotary spools or wheels, which form the primary and secondary motion transmission components. These elements may be mounted onto a shared support structure or base (100), which can be additively manufactured for lightweight integration. Fishing wire, braided polymer cord, or similar high-tensile lines may be used to form the actuation and intermediate cables, while rubber bands, elastic cords, or silicone tubing may serve as the elastic potential energy storage elements. The rotational dampers used to retard the motion output may include low-cost, compact, commercially available viscous dampers, which are readily obtainable through online suppliers. An input servo motor may provide discrete actuation pulses by pulling on a primary cable, thereby enabling stored energy to be selectively distributed and time-buffered across the system.

This construction may allow the creation of a low-cost, distributed robotic system in which multiple limbs or joints are passively coordinated using minimal electronics, lightweight components, and off-the-shelf hardware.

The resulting cable-actuated robotic system, equipped with a lightweight motion multiplexer as described herein, may be controlled by a computational controller configured to receive inputs from a variety of sensors, including but not limited to camera-based imaging of the robot's environment. In one embodiment, a camera or vision system may be positioned to observe the physical state of the robot's elastic elements, including both the energy-storing components and any optional compliant elastic outputs, thereby allowing the controller to infer the internal state of stored or pending motions. This form of observation may enable a form of visual proprioception, wherein the robot perceives its own potential actuation states through image analysis rather than embedded sensors. Based on this input, the controller may select which motion gate to activate, determine the magnitude and timing of cable pulls, and coordinate multiple degrees of freedom using predictive models. The vision system may further be used to track limb positions, assess environmental interactions, or synchronize the robot's actions with external events. This configuration may allow the robot to respond adaptively to unstructured environments, while maintaining extremely low onboard complexity through centralized sensing and minimal actuator count.

It is further noted that the described cable-actuated, multiplexed robotic system may serve as a foundation for a class of slower-moving, persistent-operation robots. In one particularly interesting embodiment, the system may be implemented in a multi-limbed platform, such as a hexapod robot, where the centralized multiplexer and computational controller are housed in the main body or thorax section. The actuators, energy storage, and decision logic may be concentrated within this central unit, while the limbs may be constructed using extremely lightweight, passive structures, made possible by the offloaded actuation and control burden. This architectural approach may allow for larger-scale robots that are nevertheless cheap, safe to operate around humans, and capable of navigating irregular or complex terrain.

In some variants, the core unit may include an onboard solar panel or alternative energy harvesting system, enabling long-term or semi-autonomous deployment in outdoor environments. This configuration may be particularly advantageous in slow-changing or biologically driven problem spaces, where speed is less important than endurance and reliability. For example, tasks such as weed suppression, insect detection or elimination, lawn maintenance, localized pollination, debris collection, or environmental cleanup may all benefit from a continuously operating robot that works quietly and safely over extended periods.

Because the multiplexing architecture minimizes actuator count and reduces the mechanical burden per limb, these robots may scale in size and reach without a proportional increase in cost or complexity. This makes the system well-suited for agricultural, ecological, and domestic applications where large areas must be monitored or influenced over time, but the urgency of response is low. Such robots may act as autonomous ecosystem assistants, performing low-intensity but high-coverage operations with minimal supervision or infrastructure.

Another compelling application of the described multiplexed cable-actuation architecture lies in aerial robotic systems, particularly flying platforms equipped with articulated arms or complex end-effectors. In one such embodiment, the system may be integrated into a drone-mounted robotic arm, where the centralized multiplexing unit is housed within the drone's main body, and force is transmitted remotely via cables. This approach aligns with existing strategies-such as those disclosed in a pending patent by the present inventor—where cable-driven actuation is used to relocate mass toward the drone's center of gravity, thereby improving flight stability. However, the current invention enables a significant further step: the ability to scale to high degrees of freedom without requiring a one-to-one ratio of actuators to joints.

By introducing a lightweight motion multiplexer, multiple joints or compliant elements may be selectively controlled using a single high-power input actuator, coupled with either a set of lightweight gate actuators or a gate selector mechanism. This allows each degree of freedom to receive significant force-sourced from a powerful centralized actuator-without the weight penalty typically associated with onboard motors for each joint. As a result, robotic arms or end-effectors mounted on flying platforms may exhibit both increased mechanical strength and substantial weight reduction, enabling longer flight times, increased payload capacity, and more complex manipulation tasks in the air. This architecture may be especially well suited for precision agriculture, aerial repair or inspection, targeted delivery, and autonomous in-field manipulation, where dexterity and reach are important but minimizing actuator count and distributing load efficiently are critical to overall system performance.

In some embodiments, the multiplexed actuation system described herein may be integrated into multi-limbed robotic platforms, such as hexapods, quadrupeds, or aerial manipulators. Each limb or joint may be actuated using a cable-driven mechanism of conventional design, wherein motion is transmitted from a central body to distal joints via routed tension elements, pulleys, or tendon-like cables. The cable-driven limbs themselves are not considered part of the present invention, and may be constructed using methods well established in the field of robotics. Rather, the novelty resides in the use of a centralized motion multiplexer, capable of selectively controlling multiple output paths through timed gating, elastic energy buffering, and delayed release. This allows a single input actuator to sequentially modify the actuation state of multiple limbs or joints, enabling complex coordinated motion using a reduced number of actuators. The central placement of the multiplexer-within the robot's body or thorax section—may allow the limbs to be constructed with minimal onboard actuation hardware, resulting in a system that is lightweight, energy-efficient, and scalable, while preserving the ability to perform distributed motion across a high number of degrees of freedom.

In one embodiment, a robotic actuation system is provided for a limb, arm, or end-effector mounted on an unmanned aerial vehicle (UAV) or multi-limbed robot. The system may comprise one or more control cables configured to transmit actuation force from a central actuator to one or more distal components. A motion multiplexer may be included, comprising a set of selectively actuated motion gates. The multiplexer may be configured to receive actuation input from a single input cable and selectively route said actuation to multiple downstream output paths, with each output path coupled to a corresponding control cable.

The system may further comprise a plurality of elastic energy storage elements, each mechanically coupled to one of the output paths of the motion multiplexer. When a motion gate is open, actuation energy may be stored in the corresponding elastic element as mechanical strain. One or more rotational dampers may also be included, each configured to regulate the release of stored energy from an elastic storage element to the corresponding limb, arm, or end-effector. The motion multiplexer may be centrally located within the body of the UAV or multi-limbed robot. This architecture allows limbs or end-effectors to be actuated via cable-driven output paths without requiring dedicated actuators mounted at each joint.

In certain embodiments, the input cable may be cascade-split using a pulley system. This arrangement allows the actuation force to be divided into two or more intermediate branches, which may be routed to different motion gates. Such a configuration may enable effective distribution of force using a minimal actuator footprint.

The end-effector may be adapted to perform one or more agricultural or environmental manipulation functions.

These may include cutting leaves, electrocuting insects, layering or sorting insects or small objects, displacing foliage to expose the underside of leaves, and grasping, picking up, or depositing objects. These functional capabilities may be achieved through mechanical attachments, elastic preloads, or compliant structures actuated via the cable system.

In one variation, the motion multiplexer may include a single actuator, such as a servo motor, that selectively opens only one motion gate at a time. This single actuator may rotate through indexed positions to address each gate sequentially. In an alternative embodiment, each motion gate may be actuated by a dedicated actuator, such as a coreless motor or shape-memory alloy (SMA) element, enabling independent parallel gating.

The actuators for the gates may be selected based on weight, responsiveness, and energy efficiency. In lightweight applications, coreless motors may be preferred, whereas SMA elements may be used for compact or thermally activated switching.

The entire actuation system may be managed by a computational controller, which may receive environmental data from one or more onboard or external cameras. These cameras may be used not only for navigation or object detection but also to observe the state of the elastic energy storage elements or compliant output cables.

In this way, the system may achieve visual proprioception—that is, an inference of its internal mechanical state based on visual input alone.

The robot may be optimized for slow and continuous operation, particularly in biologically slow-changing environments. Tasks such as weed suppression, insect targeting, localized pollination, environmental sampling, debris removal, lawn maintenance, hedge cutting, and general cleaning may be executed with low power consumption and extended deployment timeframes.

To further extend autonomy, the robot may include a solar panel mounted on its central body, allowing for energy harvesting during daylight hours and operation in remote or power-constrained environments.

In one embodiment, the multiplexer may be integrated into the central body of a hexapod robot. In such a configuration, actuation signals may be distributed from the central body to a plurality of lightweight limbs using cable pathways, allowing for coordinated locomotion or manipulation without the need for local motors at each joint.

The elastic energy storage elements may comprise hybrid structures with a central stretchable segment and non-stretchable terminal portions. These terminal ends may be implemented using fishing line, braided fiber, or other tensile cables, allowing easy attachment to anchors, spools, or clamp mechanisms.

Similarly, the output cables themselves may be formed with a stretchable central section and stiff end segments, allowing for compliance in both pulling and returning directions. This bidirectional compliance may be beneficial in soft robotic limbs or passive tension return systems.

The motion multiplexer may be constructed using 3D-printed clamps, spools, and mounting structures, making the system easily manufacturable and lightweight. The rotational dampers used to control motion output may include off-the-shelf viscous or magnetic damping units commonly available through commercial suppliers.

The actuation sequence may follow a time-sliced or sequential pattern, wherein a single actuator modifies the tension of one or more elastic elements in succession. The resulting motions may be resolved concurrently due to delayed energy release through the dampers, enabling coordinated multi-joint behavior from time-multiplexed actuation input.

In aerial applications, such as drone-mounted robotic arms, the use of a centralized multiplexer may allow high degrees of freedom with significantly reduced peripheral mass. By concentrating actuation components in the drone body, flight stability and payload handling may be improved.

The robotic system may be particularly suited to agricultural terrain or natural environments, where slow continuous work with minimal supervision is acceptable. The system may operate autonomously or semi-autonomously, performing manipulation or sampling tasks across broad areas.

Each motion gate may incorporate a mechanical, electromagnetic, or electromechanical switching mechanism.

These may include friction clamps, pin locks, magnetic brakes, servo-actuated wedges, or other devices configured to allow or prevent the transfer of force through a given output path.

Control cables may be routed through Bowden sheaths, low-friction guide tubes, or cable conduits to minimize mechanical resistance and frictional losses between the multiplexer and the moving limb or joint. These routing systems may also provide protection and environmental isolation for the cables.

In one embodiment, each motion gate within the multiplexer may be controlled by a tensioned actuation wire, such as a length of fishing line, flexible cord, or filament routed from a central control unit to a mechanical clamp located at the gate. In an initial implementation, a dedicated coreless motor may be used to twist the wire axially, generating tension by rotating one end. This torsional twisting, while effective, serves merely as a compact method of producing linear pull force in the absence of direct mechanical access to the clamp. The core functionality of the system depends not on twist per se, but on the wire being pulled with sufficient linear tension to engage or disengage the clamp mechanism.

In an alternative implementation, the same actuation wire may be controlled using a mechanical cam-based indexing system. In this embodiment, a single servo motor may rotate a cam wheel or indexing disc, which is mechanically configured to engage and pull on one selected wire at a time. The cam may include raised protrusions, anns, or guide tracks that contact the wire directly or through an intermediate linkage. As the cam rotates to a specific indexed position, it pulls linearly on the corresponding wire, applying the required tension to actuate the clamp at that gate. Once the cam is rotated to the next indexed position, the previously engaged wire is released and the next wire is tensioned, thus sequentially or selectively opening or closing motion gates.

In another variation, the cam-based indexing system may bypass the use of pull wires entirely, and instead act directly on the clamping mechanism itself. For example, the cam surface may directly press against a braking element, lever, or band that controls the engagement of the gate's rotational spool. The cam may apply localized force to engage or disengage friction directly on the rotating spool, disk, or coupling interface. This implementation allows for purely mechanical interaction between the indexing mechanism and each gate, without requiring intermediate transmission elements such as wires or cables.

The cam may further include mechanical detents, slots, or grooves to ensure reliable registration at each gate position and to prevent partial engagement. In wire-driven embodiments, the actuation wire may optionally include a spring or elastic return element to restore the clamp to its default (engaged or disengaged) state when tension is removed.

These variations of the cam-based indexing mechanism enable low-power, low-complexity, and mechanically robust control of a set of clamps using only a single actuator, without requiring a dedicated motor or electronic controller for each individual gate. By acting either through wire pulling, direct clamp engagement, or direct braking of a spool, the system enables a compact, scalable, and lightweight solution for multiplexed actuation.

This is particularly valuable in robotic applications such as UAV-mounted manipulators, multi-limbed walking robots, or distributed cable-driven systems, where centralization of control and minimization of mass are critical. The embodiments may be described by the following itemized list:
1. A robotic actuation system for a limb, arm, or end-effector mounted on an unmanned aerial vehicle (UAV) or multi-limbed robot, the system comprising:
   (a) one or more control cables configured to transmit actuation force; and
   (b) a motion multiplexer comprising a set of selectively actuated motion gates, the motion multiplexer being configured to receive actuation input from a single input cable and to selectively route said actuation to multiple downstream output paths, each coupled to a corresponding control cable.
2. The system of item 1, further comprising:
   (a) a plurality of elastic energy storage elements, each coupled to an output of the motion multiplexer and configured to store mechanical energy when a corresponding motion gate is open; and
   (b) one or more rotational dampers configured to regulate the release of stored energy from the elastic energy storage elements to the corresponding limb, arm, or end-effector;
   wherein the motion multiplexer is centrally located within the body of the UAV or robot, and the limb, arm, or end-effector is actuated via said cable-driven output paths without requiring dedicated onboard actuators at each joint.
3. The system of item 1, wherein the input cable may be cascade-split using a pulley system, such that the input actuation force is divided into two or more intermediate cable branches routed to different motion gates of the multiplexer.
4. The system of item 1, wherein the end-effector may be configured to perform one or more of the following functions: cutting leaves; electrocuting insects; layering or sorting insects or small objects; displacing foliage to expose the underside of leaves; and grasping, picking up, and depositing objects.
5. The system of item 1, wherein the motion multiplexer may comprise a single actuator configured to selectively open one gate at a time, such that only one downstream output path is enabled during a given actuation cycle.
6. The system of item 1, wherein each motion gate of the multiplexer may be actuated by a dedicated actuator, such that a separate actuator is provided for each gate to enable or disable motion transfer to its corresponding output path.
7. The system of item 1, wherein the actuators for the motion gates may comprise lightweight coreless motors or shape-memory alloy elements.
8. The system of item 1, wherein the actuation system may be controlled by a computational controller configured to receive environmental data from one or more cameras, and wherein the cameras are further configured to observe the state of elastic elements to infer the internal actuation state of the robot.
9. The system of item 1, wherein the robot may be configured for slow and continuous operation, and adapted for tasks such as weed suppression, insect targeting, localized pollination, environmental sampling, debris removal, lawn maintenance, hedge cutting, or cleaning.
10. The system of item 1, wherein the robot may comprise a solar panel mounted on its central body to enable autonomous or semi-autonomous operation over extended durations in outdoor environments.
11. The system of item 1, wherein the motion multiplexer may be integrated into the central body of a hexapod robot and configured to distribute actuation to a plurality of lightweight limbs, allowing coordinated locomotion with reduced onboard actuator count.
12. The system of item 1, wherein the elastic energy storage elements may comprise central stretchable segments with non-stretchable end portions, configured to facilitate secure anchoring to spools or clamps.
13. The system of item 1, wherein the output cables may comprise central elastic segments with non-stretchable end segments, allowing the limb or end-effector to remain compliant in both actuation and return directions.
14. The system of item 1, wherein the motion multiplexer may comprise 3D-printed clamps and spools mounted on a 3D-printed base structure.
15. The system of item 1, wherein the rotational dampers may be selected from commercially available viscous or magnetic damping devices configured to regulate mechanical energy release.
16. The system of item 1, wherein the actuation sequence may be controlled through time-sliced updates, such that a single actuation input is used to incrementally preload multiple elastic elements whose motion is resolved in parallel through damping.
17. The system of item 1, wherein the robotic arm or limb may be mounted on an aerial platform, and the multiplexed actuation architecture is configured to reduce peripheral mass and centralize actuation forces near the drone's center of gravity.
18. The system of item 1, wherein the robot may be configured to operate continuously over agricultural terrain and capable of performing tasks with minimal human supervision.
19. The system of item 1, wherein each motion gate may further comprise a friction clamp, pin-lock, magnetic brake, or servo-actuated engagement mechanism.
20. The system of item 1, wherein the control cables may be routed through Bowden sheaths or low-friction guides to minimize mechanical losses between the multiplexer and the distal actuated components.

### Embodiment N: Conditional Sugar Water Dispenser for Incentivized Ant-Based Object Retrieval

The example embodiment is depicted in FIG. 49

This invention relates to a smart dispensing system that rewards ants with sugar water, either unconditionally or only when they deliver human-desired items such as pest larvae, infected plant matter, or microplastics. A camera monitors a designated platform area, detecting the presence of ants and optionally verifying whether they have brought a target object. Upon positive detection-based on species recognition and object classification-a servo-controlled sugar stick is lowered to grant access to the reward. The sugar stick's tip is wetted in a raised position by contact with a wick connected to a sugar water reservoir. If configured for conditional operation, no reward is dispensed unless the delivered object matches predefined criteria. A second servo beneath the platform opens a hatch to collect the deposited items into a storage chamber. An access hatch on the reservoir allows for automated or manual refilling via a tube connected to an external robot or refill system. The device discriminates between ants and non-target species such as bees to ensure only qualified agents are rewarded. Over time, this system may condition ants to perform micro-scale environmental services, such as pest control or waste cleanup. It serves as a modular interface between natural insect behavior and programmable machine logic.

### Explicitly Numbered Elements (from the Drawing)

### 1) Camera and Recognition Logic

A camera configured to observe the platform area, coupled with a classifier system. The system may:
Detect the presence of ants (excluding bees or other species), and
In conditional mode, verify whether ants have delivered a target object such as a pest insect, Colorado beetle larva, fungus-infected leaf, or microplastic fragment.

Upon positive detection, the system signals for reward dispensing.

### 2) Sugar Water Reservoir and Wick

A reservoir containing sugar water. A wick extends vertically and then horizontally from the reservoir such that, when the sugar stick is in its raised position, its absorbent end contacts the wick to become saturated with sugar water.

### 3) Ant Delivery Example

Depiction of two ants carrying a large larva onto the platform—this is an exemplary scenario that would fulfill the condition for triggering a sugar water reward.

### 4) Hatch Servo (Object Collection Mechanism)

A servo-operated hatch beneath the platform that can be opened to release deposited target items (e.g., larvae or leaves) into a collection chamber or container positioned below.

### 5) Sugar Stick Servo

A servo configured to raise and lower a sugar stick with an absorbent tip, allowing it to switch between (a) a wetting position in contact with the wick, and (b) a lowered position where ants can access the reward.

### 6) Reservoir Access Hatch Servo

A servo-controlled hatch or flap that, when opened, provides external access to the sugar water reservoir for refilling.

### 7) Sugar Water Fill Tube (End Segment)

The exposed terminal section of a fill tube intended to connect to an external refill system, such as a robotic dog, drone, or fixed pipeline. The fill tube allows automated or manual replenishment of the sugar water reservoir.

### Supporting Elements (Implied but not Explicitly Numbered)

### A) Platform (Interaction Zone)

The surface area upon which ants arrive and present collected objects. It serves as the detection and reward interface.

### B) Sugar Stick

An elongated member with an absorbent end configured to pick up sugar water from the wick and deliver it to ants when lowered.

### C) Collection Container (Below Platform)

A passive or structured chamber located beneath the hatch, for storing retrieved objects such as pest insects or debris.

### D) Logic and Control Unit

An embedded or connected processor that receives input from the camera and governs servo actions based on conditional logic.

### E) Species Discriminator

A computer vision module or algorithm capable of distinguishing ants from non-target species, thereby ensuring only intended agents receive sugar water.

### F) Refill Robot (External, Not Shown)

A mobile refill system such as a drone or quadruped robot, equipped with a fluid delivery arm capable of connecting to the fill tube for automated maintenance.

### G) Power Supply (Optional)

Local or external power delivery for operating the servos, camera, and controller logic. Likely a solar panel in combination with a battery.

Background: Insects, particularly ants, exhibit remarkable capabilities in foraging, transport, and recognition tasks. Ants can be conditioned to search for specific types of food, threats, or debris by manipulating their reward systems. This invention proposes a system that may leverage these behaviors by providing a sugar water reward in response to desired actions. Specifically, ants may be incentivized to collect pest insects, contaminated organic material, or microplastics in exchange for access to sugar water. The system may operate with or without conditions, allowing for flexibility in training and application.

Summary of Invention: The invention may comprise a platform where ants interact with a programmable sugar water dispenser. A camera may observe the platform and provide input to a processing unit that determines whether sugar water should be dispensed. In unconditional mode, the system may lower a sugar stick whenever ants are detected. In conditional mode, the system may only lower the sugar stick when ants are present and have delivered a target object such as a Colorado beetle larva, a leaf infected with fungus, or a microplastic fragment. A servo may lower the sugar stick, allowing the ants to access sugar water. The sugar stick may be wetted when raised by contacting a wick attached to a sugar water reservoir.

The system may include a hatch below the platform, operated by a second servo, which allows collected objects to fall into a storage chamber. An additional servo may control access to the sugar reservoir for automated or manual refilling. A refill tube may interface with a robotic dog, drone, or tubing network that supplies sugar water on a periodic basis.

Detailed Description: The device may consist of: a platform for ant interaction, a camera oriented toward the platform, a processing unit connected to the camera for object and species detection, a sugar stick actuated by a servo, a wick system connected to a sugar water reservoir, a hatch and servo mechanism to release collected items, a reservoir access servo for refilling, a refill interface such as a flexible fill tube The processing unit may be configured to distinguish ants from non-target insects such as bees or flies. It may also be trained to recognize desired objects based on image classification models. Upon satisfying its programmed logic, the control unit may trigger the sugar stick servo to lower the reward.

The sugar stick may be designed such that its absorbent tip becomes wetted when raised into contact with the wick. When lowered, ants may access the sugar water from the stick tip. A secondary servo may open the platform hatch to collect the deposited objects.

To enable the system, a control unit such as a microcontroller (e.g., ESP32 or Raspberry Pi Zero) may be connected via standard data lines (e.g., USB or GPIO) to a camera module. Servos may be powered through a solar panel and battery system, optionally regulated by a voltage controller. The microcontroller may run image recognition software, either onboard or via a connected neural processing unit or cloud interface. Servo actuation signals may be issued through PWM lines. The refill access servo may be scheduled weekly or triggered by low reservoir level sensors.

Training the ants may begin by placing sugar water on the platform unconditionally. Objects such as pest larvae may be manually positioned nearby to encourage association. Over time, ants that bring such objects may be selectively rewarded. Conditional reward logic may reinforce this behavior by only lowering the sugar stick when qualifying objects are detected.

### Example Use Cases

This invention may be applied in several scenarios:
1. **Guarding Spruce Trees from Spruce Bark Beetles:** Ant nests may be installed near trees, and the dispenser platform may reward ants for collecting beetle larvae or chewing through resin to reach boring beetles. This may reduce infestations biologically.
2. **Agricultural Leaf Monitoring:** Ants may be conditioned to bring leaves infected with blight, mold, or other diseases, thus acting as decentralized plant health monitors.
3. **Aphid Collection:** In greenhouses or crops, ants may be trained to collect aphids or honeydew-contaminated plant material, allowing early pest detection or removal.

And collecting and fighting other insects and larva and fungals etc . . . .

Efficiency Argument: Ants require only milligrams to grams of sugar per week to remain active. Their innate foraging capabilities and colony-based labor division make them far more energy-efficient than any robotic equivalent. This system could outperform insect-scale drones in terms of power, cost, and reliability.

Automated Refilling: An automated system may periodically replenish the sugar water reservoir. A robot-such as a quadruped dog with a refilling arm—may navigate to each station, connect to the fill port, and refill the reservoir via tube. Alternatively, fixed tubing may connect multiple dispensers to a central sugar tank, pumped via schedule or demand. Refill access may be enabled by opening the reservoir hatch via servo.

Other Applicable Species and Reward Forms: While ants are the primary focus, the system may also be applicable to other foraging or worker insects, and even small animals. The term “sugar water” may be interpreted broadly to include any liquid or solid substance that is attractive or desirable to the target organism, such as nectar, protein gel, or a pheromone attractant. Species such as bees, wasps, or even rodents could potentially be conditioned using variants of this system, provided their behavior is sufficiently regular and the reward delivery mechanism adapted to their morphology and cognitive capability.

Conclusion: The proposed system creates a programmable interface between natural insect behavior and machine intelligence. Through selective sugar water dispensing, ants may be trained to collect valuable environmental signals or perform targeted pest control tasks. This technology may enable novel, scalable, and ultra-efficient biological data collection and intervention platforms.

Embodiments may be used to give sugar water to other insects as well. The embodiments may be described by the following itemized list:
1. A device comprising a camera and means for conditionally allowing ants or other insects to access sugar water.
2. The device of item 1, wherein the condition may comprise the detection of a specific object brought by the insect.
3. The device of item 1, wherein the camera may be connected to a classifier configured to distinguish between target and non-target species.
4. The device of item 2, wherein the object may be a pest insect, infected leaf, or microplastic.
5. The device of item 1, wherein the sugar water may be dispensed via a sugar stick actuated by a servo.
6. The device of item 5, wherein the sugar stick tip may become wetted via contact with a wick connected to a reservoir.
7. The device of item 1, further comprising a platform on which the insects may present objects.
8. The device of item 1, further comprising a servo-controlled hatch for removing deposited objects.
9. The device of item 1, wherein the sugar water reservoir may include a refill access point controlled by a servo.
10. The device of item 1, further comprising a refill tube configured to connect to an automated refill system.
11. The device of item 3, wherein the classifier may be trained to ignore bees, flies, or other non-ant species.
12. The device of item 1, wherein the reward substance may include, but is not limited to, sugar water and may comprise any desirable fluid or compound.
13. The device of item 1, wherein the system may be powered by solar energy.
14. The device of item 1, wherein the behavior of the ants may be trained over time using conditional reward logic.
15. The device of item 1, wherein the system may be used to protect trees from pests by incentivizing foraging behavior.
16. The device of item 1, wherein the system may be applied to agricultural crop monitoring.
17. The device of item 1, wherein the reward logic may be processed by a local or cloud-connected microcontroller.
18. The device of item 1, further comprising a collection chamber for storing deposited objects.
19. The device of item 1, wherein the platform may include a visual marker or surface texture to encourage insect landing.
20. The device of item 1, wherein insects may interact with the platform autonomously without external intervention.
21. A method of enabling insects to perform useful work toward achieving a human-desired environmental state by deploying autonomous robots that refill insect reward stations with sugar water or equivalent attractants.

### Embodiment O: Downward-Facing Vision-Based Indoor Positioning System for Wearable Devices

The present invention relates to wearable navigation systems, and more specifically to a wearable system such as smart glasses equipped with a downward-facing imaging device configured to provide visual navigation or positioning cues for indoor localization.

Positioning systems based on satellite signals, such as GPS, are ineffective indoors due to signal attenuation and reflection. While existing solutions rely on external infrastructure (e.g., Bluetooth beacons, Wi-Fi mapping), such systems require prior setup and often raise privacy concerns. There is a need for a system that may provide accurate, infrastructure-free indoor localization while preserving privacy and being seamlessly integrated into everyday wearable devices.

Disclosed herein is a wearable indoor positioning system, which may be embedded into smart glasses or similar wearable devices. The system may comprise a downward-facing camera configured to capture imagery of the floor or ground directly beneath the user. By computing **optical flow** and/or visual odometry from the captured imagery, the system may estimate the user's movement trajectory with high precision, possibly within a range of approximately one centimeter. The camera system may operate either in real time on the wearable device or offload computation to a connected device such as a smartphone or cloud server. The positional estimate derived from visual tracking may optionally be fused with additional signals such as inertial measurements, step detection, or known semantic landmarks to enhance robustness and reduce drift. A major advantage of the disclosed system lies in its use of **downward-facing imaging**, which inherently avoids capturing identifiable features of other people or environments, thus preserving the privacy of surrounding individuals. The resulting position estimate may then be used to guide the wearer toward desirable indoor resources, such as toilets, electrical outlets, seating areas, vending machines, or protein-rich food sources.

In one embodiment, a pair of smart glasses may include an imaging module mounted to face downward, with the camera's optical axis approximately perpendicular to the ground plane. The imaging module may use the same class of miniature lenses, sensors, and processing electronics as those used in forward-facing smart glasses cameras, benefiting from economies of scale and existing miniaturization. The downward-facing camera may acquire a continuous or periodic stream of images showing the ground immediately below or in front of the user's footpath. Using this imagery, the system may compute **optical flow vectors**, identify floor features such as textures, joints, tiles, or debris, and estimate translational and rotational motion. The output may be an incremental pose update, which when integrated over time yields an indoor position trajectory.

The optical flow computation may be performed: directly on the smart glasses, using a local processor; on a tethered smartphone via a wireless connection; or offloaded to a cloud service for higher throughput and model complexity.

The estimated trajectory may optionally be corrected or fused with:
inertial measurement unit (IMU) data from accelerometers and gyroscopes; prior indoor maps, such as floorplans; known floor texture patterns or visual landmarks; wireless signal triangulation (e.g., Wi-Fi or Bluetooth).

In certain implementations, the wearable device may periodically transmit its estimated location to a guiding system which may provide navigational prompts. These prompts may include directions to indoor amenities such as restrooms, cafes with available power outlets, emergency exits, or any other semantically tagged indoor location. In practice, it is preferred to use low-power camera modules and efficient processing pipelines to ensure continuous operation without significantly impacting battery life. Compression, frame skipping, or region-of-interest processing may be used to further reduce resource consumption. The downward-facing configuration also allows for continual tracking during movement without capturing the faces or identities of bystanders, thus mitigating privacy concerns often associated with outward-facing wearable cameras.

The imaging module may be connected to the internal controller of the smart glasses, which manages both sensor acquisition and wireless communication. The same circuit board and lens mounting methods used for existing forward-facing cameras may be employed to integrate the downward-facing module. The camera module may interface with the system-on-chip (SoC) or microcontroller of the glasses through standard interfaces (e.g., MIPI, USB, or SPI). Captured image frames may be processed locally using lightweight SLAM or visual odometry libraries, or wirelessly transmitted to a smartphone app via Bluetooth or Wi-Fi. The smartphone may run a navigation app that accepts frame data or processed motion vectors and maintains an estimate of the user's indoor position. This position may be used to display wayfinding arrows, vibrational feedback, or voice guidance. The smartphone or cloud service may also query a local floorplan database to match floor texture data and resolve long-term drift. Additionally, a feedback loop may be implemented where the system compares predicted and observed textures or landmarks to refine trajectory estimates. The embodiments may be described by the following itemized list:
1. A wearable positioning system comprising a downward-facing camera mounted on a pair of smart glasses, wherein the camera is configured to capture imagery of the ground beneath a user, and wherein said imagery may be used to estimate indoor movement.
2. The system of item 1, wherein the estimation of movement may be based on optical flow analysis.
3. The system of item 2, wherein optical flow vectors may be computed locally on the smart glasses.
4. The system of item 2, wherein optical flow vectors may be transmitted to a smartphone or other external computing device for processing.
5. The system of item 1, wherein the estimated movement may be combined with inertial measurement unit (IMU) data to reduce positional drift.
6. The system of item 1, wherein the downward-facing camera may utilize lenses and sensors identical to those used for forward-facing wearable cameras.
7. The system of item 1, wherein the estimated user position may be used to guide the user toward predefined indoor resources.
8. The system of item 7, wherein the resources may include toilets, power outlets, seating areas, or food sources.
9. The system of item 1, wherein image frames may be compressed before transmission to an external processor.
10. The system of item 1, wherein a floor texture or pattern database may be used to localize the user with increased accuracy.
11. The system of item 1, wherein the system may fuse visual data with map constraints or known visual landmarks to improve localization.
12. The system of item 1, wherein the estimated position may be used to provide navigational instructions via augmented reality overlays.
13. The system of item 1, wherein the camera may be oriented at an oblique downward angle to capture both the user's footpath and upcoming floor regions.
14. The system of item 1, wherein the downward-facing camera may capture grayscale, color, or infrared images.
15. The system of item 1, wherein the smart glasses may include a processor configured for edge-based SLAM or visual odometry.
16. The system of item 1, wherein user privacy may be preserved due to the camera's downward orientation avoiding faces and private content.
17. The system of item 1, wherein the device may further include a microphone or speaker to enable audio-based guidance.
18. The system of item 1, wherein the system may provide feedback to a cloud server to improve mapping accuracy over time.
19. The system of item 1, wherein the camera may be triggered at defined intervals to conserve battery power.
20. The system of item 1, wherein an AI model may be trained on typical floor imagery to enhance the accuracy of optical flow estimation and indoor navigation.

### Embodiment P: System and Method for AI-Guided Peer Matching, Conversational Medical Insight Generation, and Adaptive Hypothesis Refinement

FIELD OF THE INVENTION: The present invention relates to digital healthcare systems and artificial intelligence. More specifically, it pertains to methods and systems for collecting user medical histories, matching similar user profiles, generating treatment insights through large language models (LLMs), and refining diagnostic suggestions via live peer meetings and expert review.

BACKGROUND OF THE INVENTION: Many patients suffer from chronic, rare, or underdiagnosed conditions where effective treatments are not widely known or documented in conventional clinical guidelines. The current medical system lacks mechanisms to capture, structure, and analyze the experiential knowledge of patients, particularly for conditions with limited research or non-standard treatment paths. Treatments such as hydrodissection for cubital tunnel syndrome are often discovered by patients themselves through online searches, not physician recommendation. There is a need for a system that can crowdsource anonymized, structured patient experiences and synthesize these into actionable, individualized treatment insights.

SUMMARY OF THE INVENTION: The invention provides a centralized, privacy-aware system comprising:
1. A Personal Health Agent (PHA) for data collection and anonymization.
2. A peer-matching engine that identifies users with similar medical conditions.
3. A large language model (LLM) that synthesizes personalized treatment suggestions based on peer case narratives.
4. An optional live peer meeting module, wherein AI agents participate to ask hypothesis-driven questions.
5. A feedback loop allowing expert annotation and model refinement.

The invention allows patients to learn from the experience of others, discover underutilized therapies, and contribute to the collective understanding of medical condition subtypes.

### DETAILED DESCRIPTION OF THE INVENTION

### 1. Personal Health Agent (PHA):

Each user is associated with a PHA that collects medical history, symptoms, and treatment outcomes. The PHA uses NLP to convert input into structured data and applies context-aware redaction for anonymization. Users approve all submissions.

### 2. Peer Matching Engine:

Structured records are embedded in a vector space using semantic encoders. Peer profiles are ranked based on condition similarity, symptom progression, treatment paths, demographics, and lifestyle factors. Both high-similarity and outlier cases are selected for analysis.

### 3. Case Summarization and Prompt Construction:

Peer cases are summarized into 2-4 sentence narratives capturing onset, treatment attempts, and outcomes. These narratives, along with the user's profile, are combined into a prompt for the LLM.

### 4. LLM-Generated Insight:

The LLM receives prompts that include: User's structured health profile, Peer case summaries, Instructional context to identify treatments, trends, and diagnostic hypotheses

The LLM returns: Personalized treatment suggestions, Ranked intervention options, Warnings and condition subtypes, Suggested follow-up questions for clinicians

5. Live Peer Meetings: Users with Similar Profiles May Join Live Meetings. AI Agents Embedded in these Sessions: Pose Hypothesis-Driven Questions, Steer Dialogue to Collect Structured Insights, Clarify Ambiguous Statements

Meetings may be recorded with consent. Transcripts are processed with NLP to extract structured case updates and emerging patterns.

### 6. Expert Annotation and Feedback:

Medical professionals may review conversations and annotate: Observed condition subtypes, Unexpected treatment pathways, Contradictions or confirmations of existing hypotheses Annotations are integrated into the model training process.
7. Model Refinement: All structured data and conversational insights are continuously fed into a supervised or reinforcement learning loop, allowing the system to adapt over time and improve the relevance of its treatment suggestions.

ENABLEMENT SECTION: The system begins by allowing users to describe their medical history and condition via a Personal Health Agent (PHA), which may be locally hosted on their device or deployed via secure cloud infrastructure. The user can input natural language descriptions of their symptoms, previous diagnoses, attempted treatments, and outcomes. This input is processed using medical natural language processing (NLP) models that extract structured information such as symptom type, timeline, demographic attributes, treatment names and durations, and observed effects.

These extracted elements are stored as structured case profiles in a standardized schema, typically in JSON or protocol buffer format. These profiles are then embedded into a high-dimensional semantic vector space using pre-trained medical transformer models (e.g., BioBERT, ClinicalBERT) or custom embeddings trained on similar case corpora. Peer profiles are stored in a central database optimized for similarity search using approximate nearest neighbor algorithms (e.g., HNSW or FAISS).

When a new user submits a case, the system performs semantic similarity search across the database to find peers with closely matching medical trajectories. Matching is determined by vector proximity, with weighting factors applied to key dimensions such as symptom overlap, treatment path similarity, age and sex, and lifestyle indicators (e.g., desk work, athletic activity).

The matched peer profiles are filtered to select two sets: Highly similar users with shared medical history and condition timelines, Dissimilar users who nonetheless achieved a positive outcome (to discover novel outliers).

Each selected peer case is then summarized. Summarization involves: Extracting key elements: onset, duration, treatment attempts, and outcomes.

Using template-based or abstractive LLMs to create coherent, anonymized narrative summaries. Example: “42-year-old male, software engineer, experienced 7 months of wrist tingling and hand weakness. Tried vitamin B12 and splinting without effect. Significant improvement reported 3 weeks after hydrodissection guided by ultrasound.”

These summaries are bundled into a structured prompt alongside the user's own case data. A typical prompt includes: Description of the target user, Top-N peer summaries, Optional medical tags or clinician annotations, Instructions to the LLM to highlight promising treatments, trends, and emergent hypotheses Prompt Example: “You are a medical assistant AI. Based on the following patient profile and peer cases, identify promising treatment paths. Include treatment response patterns, risks, and questions the user might ask a healthcare professional.”

The prompt is processed by a fine-tuned LLM (e.g., GPT-4, MedPalm) running either on-premise or via a privacy-compliant API. The output includes: Personalized treatment suggestions with rationale, Ranked likelihood of success based on peer outcomes, Observed side effects, Questions to consider with medical professionals. This output is delivered back to the user's PHA, which may present it in a conversational format or structured insight panel. The user can request clarifications, ask follow-up questions, or view detailed statistics (e.g., “75% of users like you improved with intervention X”). If consent is granted, the user's outcomes (e.g., symptom improvement, new treatments tried) are monitored and fed back into the central system to retrain embeddings and improve model accuracy. Conversational data from group peer meetings, with consent, is also parsed into structured updates. In the case of group discussions, the system organizes small cohorts of similar patients, facilitates secure real-time dialogue, and embeds an AI assistant that proposes hypothesis-driven questions (e.g., “Did imaging correlate with symptom severity?”). Transcripts are anonymized and processed using NLP to capture discussion outcomes. Medical professionals may annotate these conversations to confirm or refute emergent hypotheses. All structured data, expert annotations, and LLM outputs are continuously fed into a model refinement pipeline that retrains prompt strategies, updates case clustering metrics, and expands the knowledge graph of treatment-effect relationships. The system therefore becomes more accurate and useful over time, with minimal burden on end users.

In one embodiment, the invention may be implemented using one or more computing devices comprising non-transitory computer-readable memory and one or more processors. The local agent responsible for collecting and structuring user health data may reside on the user's device and be stored in a computer memory.

This agent may include software modules that perform natural language processing to convert free-text input into structured representations and apply redaction rules before submission. The anonymized data may be transmitted over a secure channel to a remote system, where it is stored in a persistent database optimized for semantic search and retrieval. This persistent database may reside on one or more servers connected to the internet, using high-availability storage infrastructure. The similarity engine may be executed by a cloud-based or distributed processing system. It utilizes semantic embedding techniques (e.g., transformer-based encoders) to convert user records into high-dimensional vectors and compares these using vector distance functions (e.g., cosine similarity). Matching peer records are identified and retrieved for further processing. The language model component may be stored on a machine-readable storage medium and executed on server-grade hardware, optionally accessed via API by the local agent. The language model receives structured prompts containing the current user profile and selected peer summaries, and generates outputs comprising suggested treatments, risk considerations, and follow-up questions. These outputs may be cached temporarily in volatile memory or persisted for audit purposes. In one embodiment, the system includes a meeting coordination module stored in computer memory that schedules peer-to-peer or group meetings based on matching health profiles. Users may interact via a conferencing interface, which integrates an AI participation agent configured with instructions stored on a machine-readable storage medium. The AI agent may observe, log, and contribute to discussions by posing relevant hypothesis-driven questions in real time. Meeting audio or video data may be recorded and stored to a secure storage medium for further processing. A speech-to-text engine may transcribe the conversation. This transcription is then analyzed using NLP pipelines to extract structured insights and updated case data. In one embodiment, an annotation interface is provided to licensed medical professionals, allowing them to review transcripts and validate or refute hypotheses discussed during the session. These annotations are stored alongside the structured data in the persistent database and may be used to refine the underlying AI models. A model training pipeline executed by one or more processors may incorporate new user outcomes, conversational insights, and expert annotations. This pipeline supports the continuous improvement of treatment recommendations, condition subtype inference, and insight generation. These technical components collectively enable the described functionality in a scalable, privacy-aware manner, supporting dynamic interaction between user agents, peer data, AI models, and clinical reviewers.

The present invention relates to a system and method for generating personalized medical insights by analyzing anonymized peer cases, using empirical treatment outcomes to inform new recommendations. A core component of the invention involves the use of personal health agents that maintain user context, generate anonymized case summaries, and provide continuous feedback to improve the system for future users.

Additionally, the invention may support group-based peer interaction and incentive mechanisms to encourage responsible participation and longitudinal data contribution.

In one embodiment, each user may be assigned a personal agent-a digital module operating locally or in a secure containerized cloud environment-configured to monitor, collect, and synthesize a comprehensive health profile. This agent may maintain long-term contextual awareness, incorporating data such as: reported symptoms and medical history;
biometric inputs from wearables or sensors;
behavioral context (e.g., sleep, diet, stress);
demographic features (e.g., age, occupation, lifestyle).

Using this context, the agent may construct a medical case summary describing the current episode or concern.

The summary may be anonymized or contextually redacted before submission to a central health advisor system, ensuring compliance with privacy standards while retaining medically relevant features.

Upon receipt, the system may extract search keys from the submitted data using a language model or feature parser. These may include symptom keywords, modifiers (e.g., duration, intensity), and demographic indicators.

The system may query a database of anonymized peer cases, using keyword matching, embedding similarity, or disease-code indexing to identify relevant prior cases.

Each matched peer case may include treatment metadata and outcome records, which may be compiled into a dataset. A medical-domain language model may analyze this dataset to distill personalized treatment suggestions. The resulting output may include:
ranked treatment paths;
subtype hypotheses;
contraindication alerts;
clarifying questions.

In addition to model output, the system may assign the user an optional group identifier or session link, granting access to a live or asynchronous discussion space involving other individuals with medically similar cases. A meeting coordination module may organize and moderate these peer sessions, optionally including an AI participation agent configured to pose structured, hypothesis-driven questions during the conversation.

Conversations may be transcribed, anonymized, and analyzed to extract new diagnostic signals and shared insights.

To ensure high data quality and system sustainability, the invention may include an incentive structure tied to progress reporting. The personal agent may monitor the user's progress—e.g., treatment adherence, symptom evolution, recurrence, and resolution—and may transmit anonymized follow-up reports back to the health advisor system. These updates may refine the original case and improve the model's future inferences.

In some configurations, access to future recommendations may be conditional on regular reporting. For example: Users who fail to submit follow-up reports may be required to pay a higher fee for future use; Continued access to group sessions or premium diagnostic features may depend on consistent participation; Users may receive status tiers or usage credits based on their contribution to the system's evolving dataset.

This structure creates a reciprocal intelligence loop, wherein each user benefits from the experiences of others while contributing to the refinement of a shared, empirically grounded medical knowledge base.

The embodiments may be described by the following itemized list:
1. A system for generating personalized medical insights, which may comprise:
   a) a personal agent configured to collect user health data;
   b) a database adapted to store anonymized peer health records;
   c) a similarity engine operable to match peer records;
   d) a language model configured to generate treatment suggestions based on matched peer cases.
2. The system of item 1, wherein the local agent may perform context-sensitive redaction and may transmit only user-approved records.
3. The system of item 1, which may further comprise a meeting coordination module adapted to organize live sessions between users with similar profiles.
4. The system of item 3, which may further comprise an AI participation agent configured to pose hypothesis-driven questions during the peer session.
5. The system of item 3, wherein the conversation may be transcribed, anonymized, and analyzed using natural language processing techniques.
6. The system of item 5, wherein medical professionals may annotate the transcripts in order to validate or refine diagnostic hypotheses.
7. The system of item 1, which may further comprise a training module configured to refine the language model based on user outcomes and expert annotations.
8. The system of item 1, wherein the language model output may include ranked suggestions, condition subtype indicators, and follow-up questions for clinician discussion.
9. The system of item 1, wherein the peer matching engine may select both high-similarity and successful outlier cases to increase diversity and relevance of insight.
10. A method for improving diagnostic accuracy through group conversation, the method comprising:
   a) matching users based on similarity of medical conditions;
   b) facilitating a peer meeting involving embedded AI agents;
   c) recording and analyzing the conversation for emergent patterns;
   d) integrating the derived findings into a diagnostic support system.
11. A computer-implemented system for generating personalized medical insights, which may comprise:
   a) a local agent stored in a non-transitory computer-readable memory and configured to collect user health data;
   b) a persistent database configured to store anonymized peer health records;
   c) a similarity engine executed by one or more processors and configured to match peer records based on semantic embeddings;
   d) a language model hosted on a server and stored on a machine-readable storage medium, configured to output treatment suggestions based on matched peer cases.
12. The system of item 11, wherein the local agent may include logic for context-sensitive redaction and may transmit only user-approved data to the persistent database.
13. The system of item 11, which may further comprise a meeting coordination module stored in computer memory and configured to schedule live sessions between users with matching conditions.
14. The system of item 13, which may further comprise an AI participation agent comprising instructions stored on a machine-readable storage medium, wherein the agent may pose hypothesis-driven questions during the session.
15. The system of item 13, wherein the peer meeting may be recorded to a secure storage medium, transcribed using a speech-to-text engine, and analyzed using natural language processing to extract structured case updates.
16. The system of item 15, wherein licensed medical professionals may annotate the transcribed conversation using an annotation interface to validate or refine diagnostic hypotheses, and wherein such annotations may be stored in the database for future model training.
17. The system of item 11, which may further comprise a model training pipeline executed by one or more processors, wherein the pipeline may retrain the language model using structured user outcomes and expert annotations.
18. The system of item 11, wherein the language model output may include ranked treatment suggestions, condition subtype indicators, and a list of follow-up questions for clinical discussion.
19. The system of item 11, wherein the similarity engine may select both high-similarity peer cases and successful outlier cases based on treatment effectiveness indicators stored in the database.
20. A computer-implemented method for improving diagnostic accuracy through peer interaction, the method comprising:
   a) identifying users with semantically similar medical condition profiles using a vector similarity engine;
   b) organizing a live peer meeting using a coordination module;
   c) embedding an AI agent into the meeting to pose questions and record the discussion;
   d) analyzing the recorded data using natural language processing and storing emergent insights in a persistent database for use in future diagnostic support.
21. A method for generating personalized treatment suggestions, comprising:
receiving a patient query comprising symptom data and demographic profile information;
extracting key search features from the query using a language model;
retrieving a set of anonymized peer cases from a database based on similarity to the extracted features; collecting treatment outcomes associated with the retrieved cases; and generating, using a medical-domain language model, one or more treatment suggestions based on the retrieved cases and their outcomes.

In one embodiment, the invention provides a method for enabling group communication among users who exhibit related medical conditions. The method may begin when a medical case is submitted to a central system, either by a user directly or via a personal agent operating on the user's device. The submitted case may include structured or semi-structured data representing symptom descriptions, demographic attributes (such as age, sex, or occupation), and optionally prior treatment history or comorbidities.

Upon receipt, the system may extract clinically relevant features from the case using a parsing module, rules-based system, or language model. Extracted features may include symptom keywords, duration indicators, severity levels, and contextual tags derived from the demographic profile.

These extracted features may then be compared against a database of anonymized historical or contemporaneous medical cases using a similarity engine. The similarity engine may apply a variety of techniques to identify related cases, including but not limited to:
semantic similarity using embedding vectors;
keyword overlap scoring;
clustering algorithms trained on diagnostic codes;
rule-based mapping to known condition classes or subtypes.

When a subset of sufficiently similar cases is identified, the system may generate or assign a group identifier.

This identifier may function as a reference to the matched cluster of cases and may be used to control access to a communication channel, such as a chat group, live video session, or asynchronous message board.

Each new user whose case is matched to the same group may be associated with the corresponding group identifier and provided with a secure access mechanism. In one embodiment, the system may generate a session link, a hashed identifier, or a tokenized credential, which is then returned to the user's personal agent or directly displayed to the user.

Access to the group communication channel may be gated by the presence of this group identifier. The communication space may be designed for mutual support, information exchange, or collective analysis of treatment experiences. In some cases, an AI participation agent may be embedded in the session, configured to pose hypothesis-driven or clarifying questions, guide discussions, or summarize emerging patterns.

To maintain data integrity and encourage meaningful participation, the system may further condition continued access to the communication channel on the submission of periodic progress reports. Such reports may be collected by the personal agent and may include self-reported outcomes, side effects, symptom progression, or resolution. The system may enforce incentive mechanisms, such as revoking access or applying higher usage fees for users who repeatedly fail to contribute updates.

The communication channel itself may be optionally transcribed, anonymized, and processed using natural language processing (NLP) methods. Extracted insights from these conversations may then be tagged, indexed, and reused to further refine the system's understanding of treatment effectiveness, emerging symptom clusters, or contextual factors influencing outcome.

This group-based communication model, anchored in a dynamically assigned group identifier, enables patients facing similar conditions to share experience, receive collective insight, and contribute to an evolving knowledge base, all while preserving privacy and enabling scalable coordination.

The embodiments may be described by this second itemized list:
1. A method for enabling communication among users with related medical conditions, comprising generating a group identifier based on similarity between medical case records and using said identifier to provide shared access to a communication channel.
2. The method of claim 1, wherein the similarity is determined based on clinical symptoms and demographic features extracted from the medical case records.
3. The method of claim 1, wherein the group identifier is assigned by a similarity engine operating on a database of anonymized peer cases.
4. The method of claim 1, wherein the communication channel comprises a live video meeting, chat group, or asynchronous discussion forum.
5. The method of claim 1, wherein access to the communication channel is limited to users associated with the same group identifier.
6. The method of claim 1, wherein an AI agent is embedded in the communication channel and configured to guide discussion using hypothesis-driven prompts.
7. The method of claim 1, wherein conversations within the communication channel are transcribed, anonymized, and analyzed to refine diagnostic or treatment suggestions.
8. The method of claim 1, further comprising updating group membership dynamically as user cases evolve or as new similarity thresholds are met.
9. The method of claim 1, wherein the group identifier is cryptographically signed, time-limited, or condition-specific.
10. The method of claim 1, wherein participation in the communication channel is conditional on submitting follow-up health reports or treatment progress updates.

### Embodiment Q: Decentralized Conflict-Aware AI-Mediated Reputation System (“WordOfAiNetwork”)

The present invention pertains to decentralized systems and methods that enable autonomous artificial intelligence agents to evaluate, exchange, and synthesize reputational information about services, products, or entities. More specifically, it relates to a distributed network of personal AI agents capable of propagating trust-based service evaluations, performing recursive queries among socially trusted peers, identifying conflicts of interest, and generating contextually relevant, privacy-respecting recommendations.

Conventional reputation systems are typically centralized and rely on openly posted reviews, which are often vulnerable to manipulation, fake ratings, and a lack of personalized relevance. In contrast, the invention disclosed herein provides a decentralized alternative that mimics and enhances traditional word-of-mouth trust propagation by leveraging the computational, memory, and communication capabilities of AI agents acting on behalf of individuals. Each agent maintains a structured trust model based on social proximity, domain knowledge, and historical performance, and uses this model to answer or forward requests for service evaluations. The system functions even when the original user is unavailable, thus extending their influence and judgment through autonomous agents.

The disclosed architecture comprises a plurality of personal AI agents, each associated with a human user. These agents may be hosted locally, deployed in the cloud, or implemented in a federated topology. Each agent maintains a private trust graph-essentially a directed and weighted graph of known and trusted agents, identified via cryptographically secured credentials such as public keys or decentralized identifiers. The edges of this graph encode scalar trust weights, domain-specific expertise labels, historical interaction metadata, and optionally qualitative social descriptors such as “friend” or “colleague.” This trust graph is dynamically updated based on system outcomes, user feedback, and external annotations.

Agents are configured to initiate and respond to standardized query types. These include a service reputation request, which identifies a particular provider or service and includes relevant contextual metadata such as domain, location, and timestamp. The agent receiving such a query may respond with an opinion (e.g., positive, neutral, or negative), a normalized confidence score, supporting rationale, and optional conflict-of-interest flags with explanatory annotations. Responses may also include metadata such as the last recorded interaction with the service or provider in question.

The system supports recursive evaluation of reputation. When initiating a query, an agent may contact the most trusted nodes in its graph. These contacted agents may, depending on policy, further forward the query to their own trusted contacts, subject to recursion limits. As responses are collected, the originating agent aggregates the findings using a scoring algorithm that factors in trust weights, recency of service interaction, domain relevance, and any detected conflicts of interest. This process culminates in a synthesized summary presented in a form comprehensible to the end user, including natural language explanations if appropriate.

To detect and mitigate potential bias, agents are equipped with conflict-of-interest detection mechanisms. Each agent may access a metadata registry-either local, federated, or publicly scraped-which contains information about known affiliations, employment, business ownership, or prior flagged behavior of other agents. If a response appears compromised due to such affiliations, the responding agent may automatically apply conflict annotations, reduce the trust weight of the opinion, or request corroboration from additional trusted parties.

In some instances, agents may also initiate meta-credibility evaluations to assess the reliability of other agents who contribute opinions in a reputation chain. This enables recursive vetting and may be particularly useful in cases where an agent lacks a direct connection to the source of a reputation statement but has access to others who can validate or challenge the intermediary's reliability.

User behavior is modulated through configurable policy profiles. These profiles determine the manner in which reputation queries are constructed, forwarded, and interpreted. Parameters include recursion depth, trust decay over time, response weighting strategies, and thresholds for invoking meta-credibility verification. Policies may be defined manually by users, adopted from socially shared templates, or downloaded from trusted organizations that provide curated trust behaviors.

The system is designed with strong privacy and security safeguards. Communication between agents is encrypted and signed to prevent eavesdropping and impersonation. Trust graphs and opinion logs are stored privately, with access strictly limited to agents authorized by the user. Conflict detection features are transparent, and the reasoning behind discounting or promoting particular inputs is preserved and auditable.

To illustrate the system's operation, consider the following example. A user books a car rental through a service provider and is unexpectedly charged a mandatory insurance fee upon arrival. The user's AI agent records this experience as a negative review with a corresponding confidence score and context metadata. Later, another user, unaware of the incident, considers renting from the same provider. Their AI agent initiates a reputation query through its trust network. The first user's agent responds with a negative review, unflagged for conflict. A second agent supplies a positive review, but the system detects that this agent is affiliated with a competing rental agency. This conflict is flagged, and the input is downweighted. The resulting summary generated by the querying agent may read: “Two negative reviews were received from trusted agents. One positive review was discounted due to a detected conflict of interest.” This concise output enables informed decision-making while maintaining privacy and accountability across the network.

The present invention therefore provides a scalable and resilient architecture for the decentralized evaluation of service reputation, enabling a contextually personalized and socially aware extension of traditional word-of-mouth mechanisms via autonomous artificial agents.

In one embodiment, each personal AI agent-powered by a local or cloud-based large language model (LLM)-maintains an internal memory structure for associating service experiences with contextual metadata and opinion summaries. This memory may include both structured fields and natural language embeddings to allow fast retrieval, flexible reasoning, and human-readable explanation generation.

When a user interacts with a service provider (e.g., books a hotel, hires a contractor, uses a delivery platform), the AI agent records the experience in its internal memory. This record may include the service identifier, date and time of use, location, domain context (e.g., travel, healthcare, financial), and an annotated outcome assessment. The assessment itself may be structured (e.g., positive/negative/neutral, scalar rating, severity level) and optionally accompanied by free-text justification, either extracted from user feedback or generated by the agent based on observed outcomes. These records are indexed not only by service ID but also by semantic tags and situational context, allowing future queries to match relevant experiences even if the service ID is not an exact match.

When another agent sends a REPUTATION_REQUEST or a RECOMMENDATION_REQUEST regarding a given service or service type, the receiving agent consults its memory using a two-stage process. In the first stage, it performs a semantic and metadata-based retrieval of all past experiences associated with the specified service or matching the requested service type. In the second stage, it uses an internal scoring mechanism-weighted by confidence, recency, user satisfaction, and potential conflicts of interest—to generate a synthesized opinion. If multiple records are found, the agent may summarize the set, note any anomalies or mixed experiences, and generate an appropriate confidence score reflecting both alignment and variance.

For example, if the request is: *“Do you recommend Company X for car rentals in Spain?”* the receiving agent searches its memory for previous interactions involving Company X, filtered by domain (“car rental”) and location (“Spain”). If a matching record is found indicating a prior negative review due to hidden fees, the agent may return a response such as:
*“I do not recommend Company X for rentals in Spain. Last used on Apr. 3, 2025. User was charged an undisclosed insurance fee upon pickup. Confidence: 0.8.”* If the memory includes both positive and negative experiences-perhaps in different countries or years—the agent may respond more cautiously:
*“Mixed experiences with Company X. Positive interactions in France (2024), but a negative incident in Spain (2025) involving surprise charges. Recommend with caution. Confidence: 0.5.”*

In addition to direct service memories, the LLM agent may also weigh indirect opinions by recursively querying trusted peers, incorporating their structured responses into the final recommendation. These externally sourced opinions are kept separate from local memory but may be cached with appropriate timestamps and source annotations to reduce query load in the future.

The system is designed such that when an agent is queried about a service it has no direct memory of, it may explicitly respond with *“No experience with this provider”* and optionally suggest similar providers it does know, ranked by internal trust and prior outcomes. This approach ensures clarity about the provenance of each opinion and supports both personalized recommendations and honest disclosures of informational gaps. The embodiments of the invention may be described by the following itemized list:
1. A method for evaluating the reputation of a service provider using a decentralized network of personal AI agents, the method comprising the steps of initiating a reputation query by a first AI agent; transmitting said query to a plurality of trusted AI agents based on a trust graph; receiving reputation responses from said plurality of agents; and aggregating said responses to compute a reputation score for said service provider.
2. The method of claim 1, wherein each received response is weighted according to a numerical trust score associated with the responding agent and stored in the trust graph of the querying agent.
3. The method of claim 1, further comprising modifying the computed reputation score in response to detection of a conflict of interest associated with one or more responding agents.
4. The method of claim 3, wherein the conflict of interest is identified through metadata indicating the responding agent's business ownership, employment relationship, or financial stake in the service provider.
5. The method of claim 1, further comprising including with each reputation response a rationale string that identifies the origin of the opinion and any associated conflict metadata.
6. The method of claim 1, wherein the reputation query comprises a recursion depth parameter configured to constrain further propagation of the query to a specified number of hops.
7. The method of claim 1, further comprising recursively transmitting the reputation query to second-degree or further agents through one or more of the plurality of trusted agents, subject to the defined recursion policy.
8. The method of claim 1, wherein the reputation score is computed using a multi-factor function that incorporates trust score, opinion polarity, recency of experience, and presence of conflict flags.
9. The method of claim 1, further comprising storing service experience records and associated metadata in a persistent memory or knowledge base coupled to the first AI agent.
10. The method of claim 1, further comprising transmitting a meta-credibility request to a third-party agent for evaluating the credibility, reliability, or potential bias of a second agent contributing to the reputation response.
11. The method of claim 10, further comprising adjusting the weight assigned to the second agent's reputation response based on results received from the meta-credibility evaluation.
12. The method of claim 1, further comprising generating a human-readable explanation summarizing the computed reputation score and identifying key contributing factors or flagged conflicts.
13. The method of claim 1, wherein all transmitted reputation queries and responses are cryptographically signed and optionally encrypted for authentication and privacy purposes.
14. The method of claim 1, wherein the trust graph comprises domain-specific trust scores associated with distinct categories of service or geographic relevance.
15. The method of claim 1, further comprising executing the evaluation in accordance with a behavioral policy profile that governs recursion depth, decay of trust over time, and weighting adjustments in the presence of conflict metadata.
16. The method of claim 15, wherein the behavioral policy profile is either user-defined or retrieved from a shared repository of community-endorsed policies.
17. The method of claim 1, further comprising caching previously received reputation responses in local memory to reduce future query propagation and minimize network load.
18. The method of claim 1, further comprising detecting and discounting reputation responses indicative of coordinated response patterns or echo chamber effects among agents.
19. The method of claim 1, wherein the reputation query includes context metadata comprising domain specification, geographic location, and applicable time filters.
20. The method of claim 1, further comprising updating the stored trust scores of responding agents over time based on alignment between their prior recommendations and the eventual satisfaction level or feedback of the user.
21. A non-transitory computer-readable medium comprising instructions which, when executed by one or more processors of a personal AI agent, cause said agent to receive a reputation query regarding a specified service provider; identify a subset of trusted agents from a locally stored trust graph; transmit the query to said trusted agents; receive their respective reputation responses; and compute a reputation score based on said responses.
22. The computer-readable medium of claim 21, wherein said instructions further cause the agent to apply response weightings derived from numerical trust values stored in the trust graph.
23. The computer-readable medium of claim 21, wherein said instructions further cause the agent to analyze metadata from responding agents to detect conflicts of interest and apply penalty adjustments accordingly.
24. The computer-readable medium of claim 21, wherein said instructions further cause the agent to issue meta-credibility requests to third-party agents to evaluate the credibility of a responding reviewer.
25. The computer-readable medium of claim 21, wherein said trust graph is maintained locally and comprises weighted edges, domain-specific trust annotations, and time-stamped interaction records.
26. The computer-readable medium of claim 21, wherein said instructions further cause the agent to apply a behavioral policy profile which governs query resolution strategies including recursion depth, decay rules, and conflict resolution thresholds.
27. The computer-readable medium of claim 21, wherein each message transmitted or received by the agent is cryptographically signed and optionally encrypted.
28. The computer-readable medium of claim 21, wherein the agent is further configured to generate a human-readable explanation string summarizing the resulting reputation score, contributing responses, and any detected conflicts.
29. The computer-readable medium of claim 21, wherein said instructions further cause the agent to adjust the trust graph dynamically in response to user feedback, observed recommendation accuracy, or outcome verification.
30. A system comprising a plurality of computing devices, each configured to execute an AI agent as in claim 21, wherein said agents are communicatively coupled over a network and operate cooperatively as a decentralized system for recursive reputation exchange and trust-based evaluation of service providers.

### Embodiment R: Direct-Connect Job Board Platform

The present invention relates to an online recruitment platform designed to facilitate direct connections between job seekers and employers, bypassing traditional intermediaries such as recruitment agencies. The disclosed system leverages an integrated verification and contractual framework to ensure that job postings originate from authorized representatives of hiring companies, thereby promoting transparency, authenticity, and efficiency in the hiring process.

In conventional systems, job boards frequently include postings from third-party recruiters, leading to higher costs, reduced trust, and limited direct communication between the hiring entity and prospective candidates.

Moreover, there exists a significant risk of misrepresentation when postings do not come from verifiable sources within a company. The disclosed invention addresses these inefficiencies by introducing a direct-connect job board system in which every job posting must originate from an authenticated company employee, verified through a structured email validation mechanism and supported by signed contractual commitments.

The system may comprise an email verification module configured to determine whether a given email address is affiliated with a non-recruitment entity. This verification may include analysis of domain data, querying of third-party APIs, or DNS record lookups to ascertain whether the user is acting on behalf of a recruitment or outsourcing company. Should the system determine that the email originates from such an entity, the registration process is immediately halted, preventing access to the job posting functionality. Conversely, users with verified company-affiliated emails may proceed to sign a legally binding electronic agreement affirming their authorization to post jobs on behalf of their employer, and accepting liability in the event of misrepresentation.

The platform further includes a dual-contract structure. First, a Job Supplier Contract may be electronically presented to any user intending to post a job. This contract affirms that the individual is not acting on behalf of a third-party recruiter, asserts their authorization to act on behalf of the employer, and establishes legal liability for misrepresentation or noncompliance with platform terms. Second, job candidates are similarly presented with a Job Candidate Contract, which outlines the terms of use and establishes an agreement to remit a predefined finder's fee-potentially a portion of the candidate's first-month salary-upon successful placement.

Once verified, Job Suppliers are granted access to a job posting dashboard, allowing them to enter detailed job descriptions including title, responsibilities, qualifications, salary range, and location. These postings are then reviewed, optionally by an internal moderation system, to ensure compliance with content standards and platform guidelines. Upon approval, listings become publicly viewable by registered Job Candidates. Candidates may browse, filter, and apply to listings directly via a communication mechanism that routes applications to the verified corporate email address of the Job Supplier, ensuring a direct connection and eliminating intermediary interference.

Candidate onboarding may include optional or mandatory email verification, depending on platform policy.

Upon expressing interest in a listing, the Job Candidate is prompted to register and review the Job Candidate Contract. Upon acceptance, the candidate is redirected to their email client, where the platform may generate a pre-populated email containing the candidate's CV, cover letter, and other application materials addressed to the Job Supplier. Communication following the application may proceed directly between the two parties via email or other mutually agreed channels.

The invention also includes a referral module wherein existing Job Suppliers are encouraged to refer additional direct employers to the platform. This system may operate via unique referral links and provide compensation upon verified hires through those referrals. The referral mechanism is designed to promote organic platform growth and incentivize user engagement by rewarding successful network expansion among non-recruitment entities.

In case of disagreements or procedural violations, the platform comprises a dispute resolution subsystem. This module enables users to report issues, such as non-payment of the finder's fee or misrepresentation of job details. The platform may act as a mediator, reviewing evidence submitted by both parties, and may provide arbitration services or escalate the matter to legal authorities when appropriate. Penalties for violations may include account suspension, legal liability, or forfeiture of referral or platform privileges.

The user experience is structured into two primary flows. For Job Suppliers, the process begins at a landing page highlighting the core benefits of direct connection and cost reduction. Upon initiating sign-up, the user inputs their corporate email, which undergoes verification. If accepted, the Job Supplier is prompted to sign the supplier contract and complete profile creation with name, title, company name, and security measures such as two-factor authentication. Following account confirmation via email, the Job Supplier accesses the job posting dashboard and proceeds through the posting and candidate management phases. Applications are received via email, and optional tools for interview scheduling and applicant tracking may be integrated. Upon a successful hire, the platform facilitates finder's fee handling, retaining a commission and forwarding the remainder to the employer.

For Job Candidates, the landing page offers job listings and search functionalities. Candidates may search using filters such as location, industry, salary, and experience level. After selecting a job, they are prompted to sign up or log in, after which they review and accept the candidate contract. Applications are sent via email with optional assistance from the platform, such as email templates. Communication, interviews, and job acceptance proceed directly between the candidate and employer, with the platform stepping in for fee processing once employment is confirmed.

Additional flows include referral functionality, where users input the email address of a colleague at another verified non-recruitment company. Upon successful registration and hire resulting from this referral, rewards are distributed to both the referrer and the referred party. The dispute handling flow allows either party to report misconduct or contract violations, with the platform facilitating resolution via internal mediation or external escalation as needed.

In summary, the disclosed system offers a technically robust and legally enforceable framework for enabling direct, verified connections between job seekers and legitimate hiring companies. It improves efficiency, reduces costs, enhances authenticity, and promotes organic platform growth through incentivized referrals, while also safeguarding user interests via structured contractual and dispute resolution mechanisms. The embodiments can be described by the following itemized list:
1. A direct-connect job board platform comprising an email verification system configured to verify email addresses of users seeking to post job vacancies, said system rejecting email addresses associated with recruitment or outsourcing companies.
2. The platform of claim 1, further comprising a job supplier contract electronically signed by users posting job vacancies, said contract confirming that the user is an authorized representative of a non-recruitment or outsourcing company.
3. The platform of claim 1, further comprising a job candidate contract electronically signed by job seekers, said contract acknowledging the direct-connect nature of the platform and agreeing to a finder's fee if hired through the platform.
4. The platform of claim 1, further comprising a job posting and application system enabling verified users to post job vacancies and job seekers to apply directly to the hiring company.
5. The platform of claim 1, further comprising a referral system that incentivizes users to refer other authorized individuals to post job vacancies on the platform.
6. The platform of claim 1, further comprising a dispute resolution mechanism for addressing issues between job seekers and users posting job vacancies.
7. The platform of claim 1, wherein the email verification system utilizes domain analysis and/or third-party APIs to determine the association of an email address with a recruitment or outsourcing company.
8. The platform of claim 2, wherein the job supplier contract includes a provision establishing liability for misrepresentation or failure to comply with the platform's terms.
9. A method of operating a direct-connect job board platform comprising the steps of verifying the email address of a user seeking to post a job vacancy; rejecting the user if the email address is associated with a recruitment or outsourcing company; requiring the user to electronically sign a job supplier contract if the email address is verified; enabling the verified user to post a job vacancy; enabling job seekers to browse and apply for job vacancies; and facilitating direct communication between job seekers and the hiring company.
10. The method of claim 9, further comprising incentivizing users to refer other authorized individuals to post job vacancies on the platform.
11. The method of claim 9, further comprising providing a mechanism for resolving disputes between job seekers and users posting job vacancies.

### Embodiment XE: Bee Hive Protection Apparatus with Automated Insect Detection and Neutralization

A bee hive protection apparatus is disclosed. The apparatus may comprise a camera arranged to capture images of insects near a hive entrance, a processor configured to classify insects based on the captured images, and a neutralizer controlled by the processor to act selectively against hornets. The hive entrance may be bordered by electrodes positioned above and below, wherein a high-voltage module could energize the electrodes to deliver a localized discharge when a hornet is detected. In some embodiments, the electrodes may be divided into independently selectable zones, and a selector such as a servo-driven conductor arm or an electronic switching device may route the high voltage to the appropriate zone. Alternative embodiments may employ mechanical neutralization means such as a striking or squeezing actuator, or an optical laser beam directed toward the target insect. The system may be provided as an add-on module for existing hives, as an integrated hive with protection built in, or as a construction kit. In further variations, image analysis may be performed remotely, with control commands transmitted back to the apparatus, or a single camera may be used to monitor multiple hive entrances.

### Gentle Introduction

Bees may be most vulnerable at the hive entrance, where returning foragers pass through a narrow slot and predators such as hornets may hover to intercept them. The disclosed apparatus could watch this entrance from above using a small camera, so that insects crossing the slot appear clearly in view. Because hornets may be larger and bulkier than bees, simple image features such as apparent length, body proportions, and movement near the entrance could allow a processor to distinguish hornets from bees without complex setup. Once a hornet is identified, the apparatus may act only in the location where the hornet is present. It could do so by energizing two electrodes arranged above and below the entrance to create a brief, localized discharge, or by triggering a mechanical or optical neutralizer. To avoid affecting the entire entrance, the electrode near the slot may be divided into sections, and a selector such as a servo-driven arm or electronic switch could route high voltage only to the section aligned with the target. The apparatus may therefore reduce energy use and incidental bee impact while providing targeted protection. In some installations, the camera images may be sent to a remote processor that could analyze multiple hives, returning commands to each apparatus so that a single computation resource serves many entrances.

### Examples

In a first example, a single-hive add-on module may operate with local image analysis and zoned electrical neutralization. A compact camera could be mounted above the entrance slot so that each insect that traverses the slot is seen from a top-down view. The processor may continuously acquire frames at a modest rate, for example ten frames per second, extract simple features such as apparent length and aspect ratio, and classify each tracked insect as bee or hornet. When a hornet candidate is detected with confidence above a configurable threshold, the processor may compute the zone index from the insect's horizontal position over the slot, disable the high-voltage module, and command the servo to rotate the selection arm until a dock sensor confirms alignment to the target zone. The processor could then recheck the target's presence in the same zone, energize the electrodes for a short pulse, for example fifteen milliseconds, optionally repeat once or twice at intervals near one hundred milliseconds, and finally reassess whether the target has been neutralized or has exited the scene. In this example, a device event record may be formed as a single-line JSON object: {“type”:“detection”,“insectId”:“d-2023-08-15T10:22:03Z-0412”,“classification”:“hornet”,“confidence”:0.94,“position”:{“x”:0.62,“y”:0.47},“zone”:3,“frameTs”:“2023-08-15T10:22:03.517Z” }followed by an actuation request: {“type”:“actuate”,“zone”:3,“hv”:{“pulseMs”:15,“repeats”:2,“intervalMs”:120},“interlocks”:[“selector_docked”, “no_swarm_detected”],“requestId”:“r-0412” } and an outcome report: {“type”:“result”,“requestId”:“r-0412”,“status”:“completed”,“framesReviewed”:8,“targetGone”:true,“ts “:“2023-08-15T10:22:04.002Z” }. These records may be stored locally and, when configured, exported to a beekeeper's application to provide externally observable behavior and verifiable neutralization counts.

In a second example, a remote analysis service may classify insects for several hives while each local module performs only capture and actuation. The camera could send compact image crops or embeddings to a remote processor over a network link such as Wi-Fi or cellular. The interface may leverage a Model Context Protocol so that the device and service exchange analysis requests and control responses using a stable, tool-centric schema. A request message could include a reference to recent frames and entrance geometry as a single-line JSON payload: {“type”:“analysis_request”,“deviceld”:“BH-0081”,“windowStart”:“2023-09-01T07:11:12.100Z”,“win dowEnd”:“2023-09-01T07:11:12.300Z”,“frames”:[“fl67”,“fl68”,“fl69”],“entrance”:{“widthMm”:150, “zones”:6},“hints”:{“lighting”:“overcast” }}. The service may reply with classification and zone selection: {“type”:“analysis_response”,“deviceld”:“BH-0081”,“result”:{“classification”:“hornet”,“confidence”:0. 91,“zone”:5},“actuation”:{“pulseMs”:12,“repeats”:1},“requestId”:“ar-5532” }. The local unit could validate interlocks, perform the actuation, and return an execution receipt: {“type”:“actuation receipt”,“deviceld”:“BH-0081”,“requestId”:“ar-5532”,“executed”:true,“ts”:“2023-0 9-01T07:11:12.520Z” }. In deployments with many hives, the same remote processor may cycle through devices, thereby amortizing compute across the apiary.

In a third example, a mechanical neutralizer may be substituted for electrical discharge to provide a fallback embodiment. The processor could detect and track a hornet as before, compute the zone or strike location, and command a servo-driven arm to swing along a constrained path over the slot. The control flow may include arming the actuator, confirming that no bee is under the arm via a brief pre-strike image check, executing a strike motion with travel limited by mechanical stops, and then dwelling for a short interval to ensure immobilization. The device may record both the decision and the motion completion as single-line JSON entries such as {“type”:“mech_strike”,“target”:“hornet”,“zone”:2,“strikeAngleDeg”:38,“travelMs”:120,“ts”:“2023-08-21T15:41:09.301Z” } and {“type”:“mech_result”,“success”:true,“recoveryMs”:350,“ts”:“2023-08-2IT15:41:09.780Z” }. The same classification and safety interlocks could be reused, and the entrance electrodes may remain present but inactive in this variant.

In a fourth example, one overhead camera could observe multiple entrances arranged along a bench of hives, while each entrance retains its own neutralizer. The shared camera may provide synchronized frames, and the processor, local or remote, could maintain per-entrance regions of interest. When a hornet is detected over entrance number four, only that entrance's neutralizer may be commanded. A compact routing command could be formed as {“type”:“route_cmd”,“cameraId”:“C-12”,“entranceld”:“E-4”,“action”:“actuate”,“zone”:4,“hv”:{“pulse Ms”: 10}} so that neutralization remains localized while camera hardware is shared.

### Scope and Interpretation

The scope of all the inventions and embodiments in this document, will be limited solely by the claims. Descriptions of figures, embodiments, and examples are illustrative and may not limit the claims. Features described in connection with any embodiment could be combined with, omitted from, or substituted into other embodiments unless a contradiction would result. Operations and flows may be reordered, performed concurrently, or made optional, and functional elements may be implemented in hardware, software, firmware, or combinations thereof without departing from the claimed scope. Dimensions, materials, component choices, and numerical values are presented as examples and may be varied as appropriate for a given implementation.

For the bee hive protection invention specifically, references to a hive entrance or entrance region may include, without limitation, an entrance slot, any associated landing board or ramp, an entrance tunnel or reducer, and an adjacent flight volume proximal to the slot. As used herein, neutralize may include lethal or non-lethal actions including stun, disable, repel, displace, deter, confine, or temporarily immobilize sufficient to prevent or materially reduce predation during the relevant interval.

Selectively actuate may refer to actuation localized in space and/or time so that only a portion of the entrance region or a limited time window is affected. Hornet may encompass predatory Vespa species and functionally similar vespid wasps that hunt bees at hive entrances.

### Background

Beekeeping is an important agricultural activity that contributes to pollination services and the production of honey and other hive products. Managed bee colonies are increasingly exposed to threats from invasive predators, among which hornets such as Vespa velutina are of particular concern. These hornets often hover at the entrance of a hive, capturing foraging bees and disrupting normal colony activity. Persistent hornet pressure can lead to colony weakening, reduced foraging, and eventual collapse. Conventional methods for hornet control include traps, nest destruction, and chemical treatments. Traps are often non-selective and may capture beneficial insects, while chemical methods may raise safety and environmental concerns. Nest destruction is labor-intensive and not always practical, particularly when nests are concealed or located at height. Individual beekeepers therefore face difficulty in reliably protecting hives against hornet attack. Accordingly, there is a need for a hive-level protective system that can automatically distinguish hornets from bees and apply a targeted neutralization method at the hive entrance. Such a system would ideally reduce hornet predation pressure while limiting incidental harm to bees and avoiding broader environmental impacts.

### Summary

The disclosure may provide a hive-entrance protection system that could detect insects using a camera and/or electrical sensing, classify hornets using local or remote processing, and actuate a neutralizer selectively and locally where the target is present. The neutralizer may include zoned electrodes energized by a high-voltage module, a servo- or electronically switched selector that routes energy only to the selected zone, or mechanical or optical means that could strike, squeeze, or irradiate the target. Implementations may be realized as add-on modules, integrated hives, or construction kits, and could operate with a single camera per entrance or a shared camera serving multiple entrances, thereby enabling practical, selective, and energy-efficient defense for bee colonies. In further embodiments, detection may be performed using additional modalities such as acoustic sensing of wingbeat signatures, thermal or infrared sensing, time-of-flight or lidar ranging, or radio-based motion sensing, and neutralization may additionally include pneumatic airflow, entangling or trapping mechanisms, or other non-chemical deterrents localized to the entrance region.

### Detailed Description of the Figures

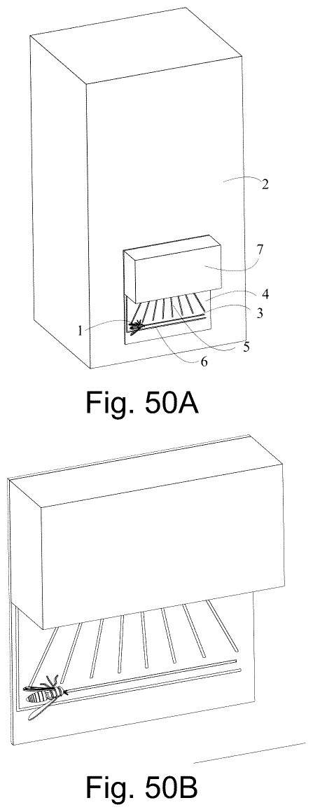

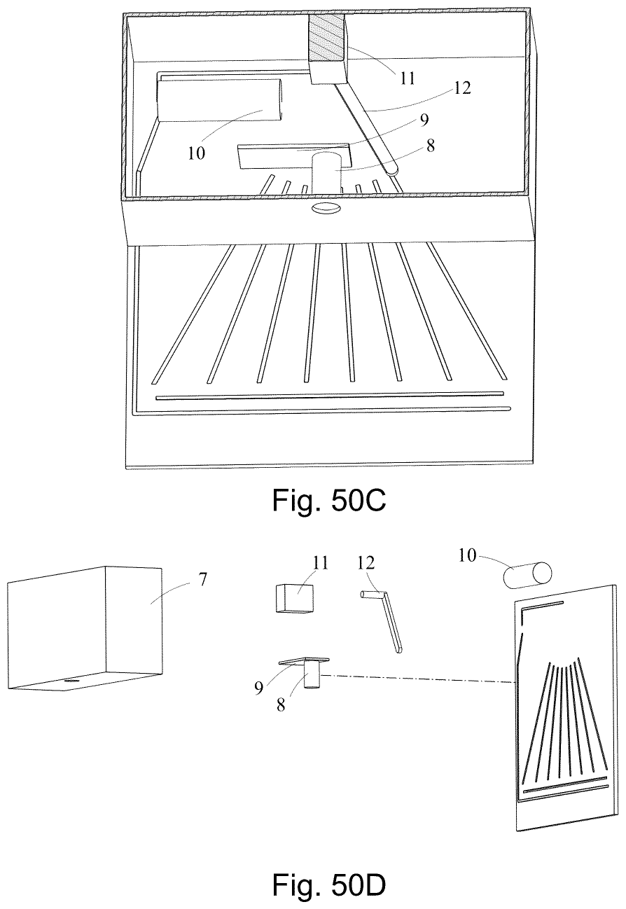

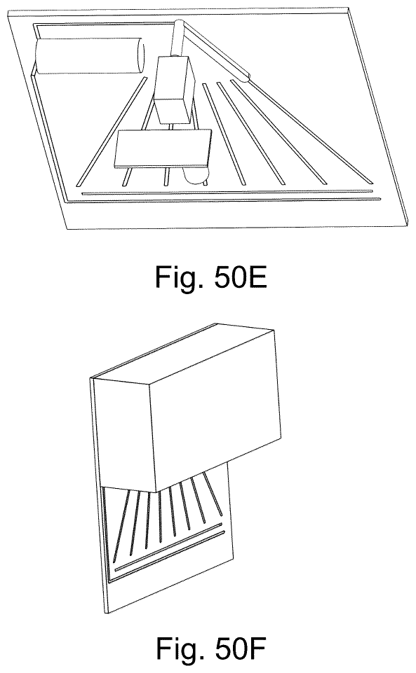

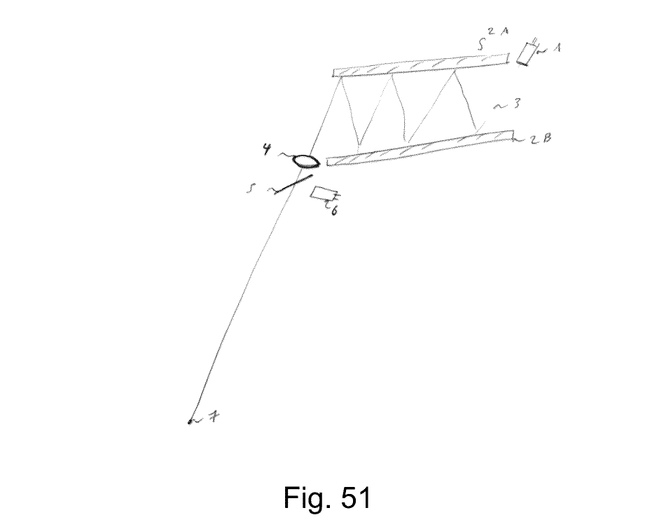

FIG. 50A illustrates a bee hive (2) provided with an add-on protection apparatus mounted adjacent to its entrance.

FIG. 50B shows an enlarged view of the add-on apparatus positioned at the hive entrance.

FIG. 50C is a cutaway view of the add-on apparatus, revealing internal components.

FIG. 50D presents an exploded view of the add-on apparatus, showing the principal elements in separated form.

FIG. 50E depicts a top-down view of the apparatus with the cover (7) removed.

FIG. 50F shows the apparatus in isolation as a standalone unit, apart from the hive.

In FIGS. 50A to 50F the following elements are shown: 1. hornet or other insect 2. Bee hive 3. Entry slot in base plate 4. Base plate 5. Selectable electrode 6. Non-selectable electrode 7. Cover 8. Camera sensor and lens 9. processor 10. High voltage module 11. Servo or actuator 12. Selection arm with conductor.

The bee hive (2) has an entry slot (3) formed in a base plate (4). A selectable electrode (5) is positioned above the slot and a non-selectable electrode (6) below. A cover (7) encloses a camera sensor and lens (8) linked to a processor (9). The processor (9) drives a high-voltage module (10), one output fixed to the non-selectable electrode (6), the other routed through a servo or actuator (11). The servo (11) positions a selection arm with conductor (12) to connect the voltage to a chosen segment of the selectable electrode (5). Thus the computing unit (9) may energize the appropriate electrode zone when a hornet (1) is detected at the entrance. The hornet (1) is shown to show the apparatus in context.

### Alternative Configurations

In another embodiment, the camera (8) may transmit its captured images to a remote processor or server rather than performing classification locally. The remote processor may analyze the images and transmit control commands back to a receiver in the apparatus, which could then actuate the servo (11) and high-voltage module (10). This arrangement may reduce unit cost by allowing a single computation resource to be shared across multiple protection modules. In a further variation, a single camera (8) may be arranged so that its field of view covers multiple entry slots (3) associated with multiple bee hives (2). The shared camera could thereby monitor several hives simultaneously and direct neutralization commands to each corresponding apparatus. This configuration may again lower overall cost by reducing the number of cameras required.

### Alternative Embodiments for Switching

Alternative embodiments may employ different means for directing or switching the conductive path between the high-voltage module (10) and the selectable electrode (5). Instead of using a servo or actuator (11) to move a selection arm (12), the apparatus could incorporate solid-state components such as MOSFETs or IGBTs configured to withstand the applied voltage and selectively energize electrode zones. In another variation, electromagnetic devices such as relays or solenoids could be arranged to route the high-voltage output to the desired contact. Additional techniques, including gas-discharge switches, rotary spark gaps, or plasma-based steering elements, may also be employed to establish or interrupt the electron stream. The control unit (9) may be configured to coordinate activation of any such switching means in response to hornet detection, provided that isolation and current-limiting features are maintained to ensure reliable operation.

### Embodiment Variations

The invention may be realized in different product forms. In one embodiment, the system may be provided as a bee hive add-on, configured to be mounted onto an existing hive and to protect the colony without requiring modification of the hive body. In another embodiment, the protection system may be integrated directly into a bee hive during manufacture, so that the hive and the neutralization apparatus form a unified structure. In a further embodiment, the invention may be supplied as a construction kit comprising parts and instructions, allowing a user to assemble a hive together with the protection system.

### Alternative Embodiments

Alternative embodiments may vary the physical arrangement and means of neutralization. In one configuration, the selectable electrode (5) may be placed on the bottom of the entry slot (3) with the non-selectable electrode (6) positioned above, or the polarity of the electrodes may be reversed while retaining the same functional effect. In another embodiment, the electrodes may not be divided into selectable sections, and the entire electrode length could be energized when activation is required. Mechanical means may also be employed instead of electrical discharge. For example, a servo-driven arm could swing to strike or pierce the hornet (1) as it approaches the hive entrance, or an actuator could reduce the spacing between two elements so that the hornet is squeezed, crushed, or pierced. In yet another variation, an optical approach could be adopted, in which the hornet is neutralized by a directed laser beam. In further variations, a pneumatic neutralizer may direct a short, high-velocity air jet across the entrance region to displace, stun, or immobilize the hornet (1) without chemical agents, a micro-net or tether may be deployed from a compact launcher to entangle the hornet (1) at the entrance, an electrostatic capture pad may be actuated to present a charged adhesive surface for temporary immobilization, or a small trap door or gate may momentarily close a localized subsection of the entrance to confine the hornet for subsequent removal by electrical, mechanical, pneumatic, or optical means.

### Alternative Detection Methods

Detection of a hornet (1) or other insect may be achieved through analysis of images captured by the camera (8). In alternative embodiments, detection may instead be performed by electrical sensing at the hive entrance (3). For example, the presence of a relatively large insect body may alter conduction or capacitance across the slot. One set of conductive elements may be positioned on one side of the entry slot (3) and another set on the opposite side, so that when an insect bridges the gap, a measurable change in conductivity or capacitance occurs. Such a change may be interpreted by the processor (9) as an indication of insect presence and size, thereby allowing discrimination between bees and larger insects such as hornets. Additional sensing modalities may include an acoustic transducer that could capture wingbeat frequencies and temporal envelopes characteristic of hornets versus bees, a light curtain comprising one or more break-beam paths oriented across the entrance line, a thermal or infrared sensor to detect body heat and size, a time-of-flight or lidar sensor to measure range and silhouette, or a radio-based motion sensor such as a Doppler or frequency-modulated continuous-wave device that may detect hover behavior and body size. Any such modality could be used alone or in combination with imaging or electrical sensing, and fusion logic may weigh multiple indicators before actuation.

### Base Plate Construction

The base plate (4) may be fabricated from a variety of materials, including plastic, wood, or a combination thereof. The electrical paths for the electrodes may be realized by metallic conductors, such as copper, which may be applied on the surface of the base plate, embedded within the plate, or otherwise integrated by conventional methods. In another embodiment, the base plate (4) may be produced by additive manufacturing, wherein two different filaments are employed during the printing process: a conductive filament forming the electrode paths, and a non-conductive filament forming the insulating structural portions. This approach may enable the base plate to be manufactured as a single integrated component with both mechanical and electrical functionality.

### Main Flow

In operation, the apparatus may follow a two-stage process. First, the camera (8) in combination with the processor (9) may detect and classify an insect at or near the hive entrance (3). If the extracted features correspond to a hornet (1), the target may be confirmed. Second, upon confirmation of a hornet or other harmful insect, the processor (9) may command the neutralizer-whether by initiating an electrode discharge between the selectable electrode (5) and the non-selectable electrode (6), actuating a mechanical striking or squeezing element, or directing an optical laser system—to engage and neutralize the target.

In another embodiment, the apparatus may follow a two-stage process with computation performed externally. First, the camera (8) may capture images of insects at or near the hive entrance (3) and transmit the images to a remote processor or server. The remote processor may analyze the images, classify the insect, and return a control signal to the local apparatus. If the features correspond to a hornet (1), the signal may confirm the target. Second, upon receiving the control signal, the local processor (9) or receiver may command the neutralizer-whether an electrode discharge between the selectable electrode (5) and non-selectable electrode (6), a mechanical striking or squeezing element, or an optical laser system—to engage and neutralize the hornet at the hive entrance (3).

### Enablement

An embodiment may be constructed by mounting a base plate (4) with an entry slot (3) to the hive (2), affixing a non-selectable electrode (6) to one side of the slot and a selectable electrode (5) to the opposite side, and wiring these to a high-voltage module (10) that could deliver brief, current-limited pulses. The selectable electrode (5) may be divided into isolated sections, each routed to a zone terminal accessible to a servo-driven selector (11, 12) or to an electronic switching bank. A camera (8) may be positioned generally above the entrance, for example near forty centimeters, under a cover (7), and connected to a processor (9). Each selected zone may include a ballast resistor dimensioned so that per-pulse energy could remain limited, and unselected zones may include bleeder resistors to discharge stray charge when idle. Firmware may be arranged to acquire frames at a modest rate such as ten frames per second, extract apparent length and aspect ratio features, and track insect trajectories across frames. A multi-frame confirmation may precede actuation. The processor (9) could compute a zone index from the horizontal position over the slot, disable the high-voltage module (10), drive the selector (11) until a dock sensor indicates alignment, revalidate target presence, and then command a pulse sequence such as fifteen-millisecond pulses with optional repeats separated by about one hundred milliseconds. The apparatus may evaluate outcome, log detection, actuation, and result records in single-line JSON as shown in the examples, and return to idle. In remote-analysis variants, the device may transmit compact crops or embeddings and receive per-target decisions, exchanging messages using a Model Context Protocol with JSON payloads as illustrated, and may perform the same interlocks and actuation locally upon receipt.

### Technical Effects

Zoned actuation may reduce energy consumption and incidental bee impact by localizing discharge to the portion of the entrance where a hornet is present. Top-down imaging may increase classification reliability by maximizing apparent insect length and simplifying segmentation at the entrance line. Selector docking and current-limited pulses may improve robustness and component life by avoiding arcing during motion and limiting arc energy. Remote analysis and camera sharing may improve scalability by amortizing compute across multiple hives. Electrical sensing alternatives may provide operation during low-visibility conditions. Mechanical and optical neutralizers may provide fallback protection where electrical discharge would be undesirable. Additional sensing modalities may provide redundancy in adverse weather or lighting, and pneumatic or trapping neutralizers may offer non-chemical control where electrical or optical means are constrained by regulation or site-specific safety considerations. In particular, solid-state or relay-based zone switching may reduce maintenance relative to purely mechanical selectors by eliminating sliding contacts in the high-voltage path, while the servo-driven selector may minimize parts count and cost where speed requirements are modest. Mechanical striking or squeezing elements may deliver neutralization without high voltage, which could simplify compliance with electrical safety standards and maintain effectiveness in rain or high humidity. Directed optical neutralization may provide highly localized action with no moving parts near the entrance region, which could reduce mechanical wear and eliminate electrical conduction paths through debris or moisture. Pneumatic jets, trap doors, and entangling mechanisms may avoid conductive arcs entirely, thereby reducing electromagnetic emissions and minimizing the risk of carbonization of organic material near the entrance. Use of per-zone ballast and bleeder resistors may limit peak currents and ensure timely discharge of residual charge, which could improve user safety and reduce inadvertent re-triggering due to latent potentials. Shared-camera deployments may reduce bill-of-materials cost and simplify calibration across entrances, while maintaining per-entrance localization to prevent collateral impact. Remote processing may enable continuous model improvement and fleet-wide updates without device replacement, which could maintain or improve classification performance over time under changing environmental conditions. Fusion of acoustic, infrared, and radio-based sensing with imaging may sustain detection performance during dusk, night, or heavy overcast, thus extending protective uptime and reducing false activations.

### External Observability

The apparatus may expose externally observable behavior via recorded JSON events, including detections, actuation requests, execution receipts, and outcome reports with timestamps and identifiers. Neutralization counts, on-device counters, and exported summaries may be made available to a beekeeper application. When subscriptions or remote services are used, signed logs and authenticated transcripts may allow later verification that detections and actuations occurred as reported, supporting independent observability without requiring inspection of internal algorithms.

### Interoperability Coverage for Software Patents

The device and service interfaces may operate over multiple transports and protocols, including Ethernet, Wi-Fi, cellular, HTTP(S), MQTT, and WebSocket. Where external analysis is employed, a Model Context Protocol could be used so that tools, schemas, and message types remain stable across device firmware and service implementations, thereby allowing multi-vendor interoperability and preventing avoidance by interface changes.

### Fallback Embodiments

Simplified embodiments may energize an entire electrode length rather than zones, may use only electrical sensing without a camera, or may substitute a purely mechanical striking or squeezing neutralizer while retaining the same detection logic and interlocks. Remote computation may be omitted so that all classification is performed locally, and network connectivity may be optional so that core protection continues in offline operation. In sites where lethal neutralization would be disfavored, non-lethal deterrent embodiments may be used, including pulsed airflow directed across the entrance region or brief optical or acoustic stimuli configured to disrupt hornet hovering while minimizing bee disturbance.

### Support

Each claim may be supported by the detailed description, the figures anchor, the main flow, the alternative configurations and embodiments, the examples including JSON interfaces, and the continuation support itemized list. Apparatus claims may map to the enumerated elements in the anchor, and method claims may map to the operational sequences described in the main flow and examples.

### Broadening

Alternative implementations may be described for principal elements. Switching may be performed by a servo-driven selector or by solid-state or electromagnetic devices. Detection may be visual, electrical, acoustic, infrared, radio-based, or time-of-flight. Neutralization may be electrical, mechanical, optical, pneumatic, or trapping/entangling. Electrodes may be arranged above or below the slot with interchangeable polarity, and fabrication may use conventional conductors or additive manufacturing. Processing may be local or remote with one or multiple cameras, thereby broadening coverage while remaining within the inventive concept.

### Claim Layering

The claim set may include multiple independent claims at different abstraction levels, including apparatus claims that define sensors, processing, and neutralization, and method claims that define detection, classification, zone selection, and actuation flows. Additional potential claims may be reserved in the continuation support itemized list for future continuation filings.

### No Unneeded Limitations

Independent claims may be drafted to require only elements that would be unavoidable for an implementation of the inventive concept, with specific implementations such as zoned electrodes, selector geometries, or particular protocols recited in dependent claims or disclosed as alternatives so that unnecessary restrictions may be avoided.

### Monetization and Damages Considerations

In some embodiments, the apparatus may be provided under a subscription model in which certain features are enabled by license for a defined term. The processor (9) or a companion control unit may maintain a secure real-time clock and a cryptographically verifiable license token such that the availability of remote classification, multi-hive coordination, higher frame-rate analysis, or enhanced safety diagnostics could be activated only while a valid subscription is present. License enforcement may be implemented using asymmetric cryptographic signatures generated by a server and verified on the device, thereby allowing renewal messages to be transmitted over intermittent networks while preventing unauthorized feature activation. Usage-based metering could be supported by on-device counters that may increment for each neutralization event, active hour, or processed frame. These counters may be stored in tamper-evident memory with forward-secure hashing so that deletion or rollback attempts would be detectable. The apparatus could periodically transmit metering summaries to a remote service along with attestation data that may include device identity, firmware version, and integrity proofs. In low-connectivity settings, the apparatus may defer transmission and could continue operation in a grace mode until connectivity resumes, at which point deferred usage records may be uploaded. To facilitate damages assessment in cases of infringement or unauthorized service provision, the apparatus may maintain signed operational logs that could record feature usage, configuration changes, and safety interlock status. The logs may be sealed with a device-bound key and could be exportable in an authenticated transcript format suitable for later verification. When remote processing is used, the service endpoint may authenticate each device session and could issue per-session tokens, allowing correlation between device-side logs and server-side computation records. The system may further support over-the-air updates, key rotation, and secure boot, so that subscription features and measurement functions remain trustworthy over the lifetime of the product. The subscription service may be offered at tiers, such as a base tier enabling local detection and single-entrance protection, and higher tiers that could add remote classification, multi-entrance orchestration from a single camera (8), advanced analytics, and fleet management for commercial apiaries. Payment models may include monthly or seasonal billing, event-based billing per neutralization or per day of hornet activity, or enterprise licenses across multiple bee hives (2) managed under one account. These mechanisms may allow clear quantification of usage and economic value attributable to the patented features, which could support calculation of royalties and damages.

### Continuation Support Itemized List

Embodiments can be described by the following itemized list: (1) a system including a camera arranged to capture images of insects near a hive entrance, a processor configured to classify insects based on the captured images, a high-voltage supply, and electrodes positioned above and below the entrance that are activated selectively upon detection of a hornet; (2) electrodes comprising multiple electrode endings distributed along upper and lower edges of the entrance, with control that activates only a subset corresponding to a detected hornet location; (3) electrode endings divided into independently actuatable zones such that only a selected zone is energized when a hornet is present; (4) each zone including a current-limiting ballast resistor restricting discharge energy to a predetermined level; (5) inhibition of activation under conditions detected in images such as swarm activity or other states where bee losses would be unacceptable; (6) a servo-actuated selector connecting the high-voltage output to a chosen electrode zone; (7) the selector comprising an insulating disk with a conductive segment rotatable to align with fixed zone terminals; (8) control logic disabling the high-voltage source while the selector is in motion and enabling it only upon confirmation of a docked position; (9) a selector that uses a movable electrode to establish a discharge across a controlled air gap to a chosen zone terminal; (10) arc-erosion-resistant materials, including tungsten or silver-tungsten, and air-gap geometry dimensioned for reliable breakdown at the applied voltage; (11) hornet classification based on apparent body length, morphology, or flight pattern in a top-down imaging geometry; (12) tolerance of occasional incidental bee electrocution without compromising overall colony health; (13) recessed or shielded electrode rails reducing likelihood of accidental human or animal contact; (14) confirmation of hornet detection across multiple consecutive frames before energizing; (15) delivery of the discharge as a short burst or as a series of pulses separated by intervals; (16) a base plate defining an entry slot with a selectable electrode on one side and a non-selectable electrode on the opposite side; (17) a neutralizer controlled by the processor that may be an electrical discharge between electrodes, a mechanical striking, piercing, or squeezing mechanism, or an optical laser directed at the target; (18) a selectable electrode divided into independently energizable sections with routing by a servo-driven selection arm with conductor, wherein the processor disables the high-voltage module during motion and re-enables it upon confirmation of a settled position; (19) remote computation in which the processor is located remotely, the camera transmits images to the remote processor, the remote processor returns control commands, a single remote processor serves multiple hives, and a single camera monitors multiple entry slots; (20) alternative switching means for directing high voltage to an electrode section, including MOSFETs, IGBTs, relays, solenoids, gas-discharge switches, rotary spark gaps, and plasma steering elements; (21) detection based on conduction or capacitance change across the entry slot when an insect bridges conductive elements; (22) a base plate fabricated from plastic, wood, or combinations, with electrode paths realized by metallic conductors such as copper applied on or embedded in the base plate, or produced by additive manufacturing using conductive and non-conductive filaments; (23) configurations with the selectable electrode positioned below and the non-selectable electrode above, and variants with reversed electrode polarity; (24) product forms including an add-on module for existing hives, an integrated hive with built-in protection, and a construction kit comprising parts and instructions; (25) operational sequencing including idle state, zone index determination, selector movement with high voltage disabled, dock confirmation, revalidation of target position, application of one or more pulses, reassessment, and repeat or idle, with servo repositioning times on the order of seconds and per-zone ballast and bleeder resistors to manage energy and discharge; (26) safety features that include current-limited energy delivery and shielding, together with interlocks and decision thresholds that inhibit activation in defined conditions; (27) orchestration whereby a central service coordinates remote analysis and actuation across multiple devices; (28) subscription-licensed features enforced by a secure real-time clock and cryptographically verifiable license tokens, usage metering with tamper-evident memory and forward-secure hashing, signed operational logs sealed with a device-bound key and exportable as authenticated transcripts, and support for secure boot, key rotation, over-the-air updates, tiered offerings, and event-based billing models; (29) externally observable behaviors such as per-event indicators, recorded neutralization counts, exported summaries, and device or service outputs that report detections and actuation timestamps suitable for later verification; (30) interoperability with multiple network transports and protocols including wired and wireless links such as Ethernet, Wi-Fi, cellular, HTTP(S), MQTT, and WebSocket, and, where external analysis services are used, an interface that may leverage a Model Context Protocol to exchange analysis requests and control responses; (31) method embodiments corresponding to apparatus features, including capturing images, classifying insects, selecting electrode zones, controlling high voltage, performing remote classification with multi-hive coordination, detecting via conduction or capacitance changes, and actuating mechanical or optical neutralizers in add-on, integrated, or kit implementations; (32) detection using acoustic sensing of wingbeat frequency, temporal envelope, or spectrotemporal patterns that differentiate hornets from bees, optionally fused with image or electrical cues; (33) detection using a light curtain or break-beam arrangement across the entrance region to sense body size, trajectory, and hover behavior; (34) detection using thermal or infrared sensors to estimate insect size and motion in low-light or night conditions; (35) detection using time-of-flight, lidar, or structured-light ranging to determine insect range, size, and motion vector; (36) detection using radio-based motion sensing including Doppler or frequency-modulated continuous-wave sensing to identify hover and approach patterns indicative of hornets; (37) neutralization or deterrence using a pneumatic jet directed across a localized entrance subsection to displace or immobilize the target; (38) neutralization using an entangling micro-net, tether, or deployable mesh configured to capture a hornet within the entrance region; (39) immobilization using an electrostatic capture pad or actuated adhesive surface presented only upon target confirmation; (40) temporary confinement using a localized trap door or gate that closes a subsection of the entrance for target isolation followed by neutralization by any disclosed means; (41) non-lethal deterrent stimuli including brief optical or acoustic emissions configured to disrupt hornet hover while minimizing bee disturbance; (42) definitions of the entrance region to include an entrance slot, any associated landing board, an entrance tunnel or reducer, and an adjacent flight volume proximal to the slot so that localized actuation remains within the scope of the entrance region; (43) electrode and field geometries including lateral, oblique, mesh, or perforated-grid arrangements positioned around the entrance region so that a localized field may be established without requiring a strictly above-below orientation; (44) directed-energy neutralizers including ultrasonic emitters, high-intensity focused acoustic sources, ultraviolet sources, or radiofrequency or microwave emitters configured to apply energy in a localized beam with power-limiting and interlocks; (45) operator-in-the-loop embodiments in which a human operator or automated external service issues an actuation command via a device or network interface while device-side safety interlocks and localization are enforced; (46) dynamic spatiotemporal actuation patterns including sequential or traveling-wave zone activation to track a moving target across zones while limiting total energy; (47) repellents emitted in localized, metered, and non-persistent form such as brief bursts of inert gas, water mist, or odorant at levels configured to deter hornet hover while minimizing bee disturbance, wherein such emissions are treated as non-lethal neutralization consistent with the definitions of neutralize.

### Embodiment AE: Information Texturising for Recyclability and Accountability of Manufactured Parts

Disclosed are methods, systems, articles, and computer-readable media for embedding machine-readable metadata into the surface texture of manufactured parts, particularly plastics, so that fragments remain decodable after wear or breakage. Encoded surface relief may be imparted during molding via microstructured tools or added post-formation via texturing processes such as laser ablation or embossing. Payloads may include polymer class, additive identifiers, batch and manufacturer identifiers, compliance flags, and unique identifiers resolvable via a registry. Reader devices may image and decode the textures on whole parts or fragments and drive sorting or auditing actions. Redundant placement of textures enhances survivability and recyclability while enabling provenance and accountability.

Gentle Introduction: Many manufactured parts may be thought of as having unused “real estate” on their surfaces. The invention treats that surface as a durable data carrier by shaping it with tiny ridges and pits that encode information much like a miniature two-dimensional code would, but formed as micro-relief rather than printed ink. During molding or after a part is made, the surface could be textured so that even if the part is scuffed, worn, or broken into small pieces, at least some fragments still carry enough of the pattern to be read by a camera under simple lighting. A sorting line or handheld reader might then recover the polymer type, additive family, batch, or a compact identifier that links to a registry for full details. Because the patterns may be repeated in multiple places and include error correction, a small shard could still reveal what the material is and where it came from. Manufacturers could add this texture at near-zero material cost by integrating it into a mold insert, or retrofit existing parts using laser or embossing tools. Waste processors could use off-the-shelf imaging and decoding software to improve purity of recycled streams and to route items more accurately. In some deployments, a registry-backed unique identifier and optional signature could allow authentication of payloads and lifecycle status without opening devices or performing destructive tests. In this way, the concept may provide a simple, interoperable means to make materials self-describing and traceable across their lifecycle.

Examples: The following examples illustrate concrete, step-by-step walkthroughs of representative deployments. They are illustrative and non-limiting, and steps may be reordered or substituted where technically feasible.

Example 1: Injection-molded HDPE cap with mold-integrated texture. A manufacturer may define a payload schema including polymer class HDPE, additive family code, batch ID, manufacturer ID, and schema version, targeting approximately 80 to 120 bits plus error correction. The manufacturer could select a Data Matrix symbol with a module pitch of about 50 micrometers and a relief depth of about 10 micrometers. A toolmaker may micro-mill the negative of the symbol onto a removable insert sized to fit a flat zone of the cap cavity, mirror-corrected for molding. The insert may be polished to achieve a local finish of Ra less than 0.4 micrometers and installed with alignment features so the symbol repeats at four quadrants around the cap skirt. Molding parameters may be tuned so micro-relief replicates reliably, for example HDPE melt at about 220 degrees Celsius, mold at about 30 degrees Celsius, and pack-and-hold pressure sufficient to fill relief valleys. Quality control personnel might inspect first-article parts at 10× magnification and capture images under coaxial bright-field illumination. A decoding application may detect finder patterns, correct distortion, and output the payload plus a confidence score. In the field, caps entering a materials recovery facility could pass under a reader that images the skirt area; when a cap is intact the reader may decode any one of the four symbols. If caps are shredded, fragments as small as about 5 by 5 millimeters may still present part of a symbol; error correction could recover the payload, and a conveyor diverter may route fragments to an HDPE stream.

Example 2: Post-formation laser texturing of an ABS housing. An electronics producer may choose to retrofit an existing enclosure without modifying the mold by applying a texture post-formation using a green pulsed laser. The producer could encode a compact unique identifier of 96 bits and a truncated signature of 128 bits, with a QR symbol using approximately 35 micrometer modules at about 3 micrometers depth to avoid cosmetic impact. The laser may scan at about 200 millimeters per second, two passes, to achieve the desired relief The symbol may be tiled at a pitch of about 20 millimeters across the inner sidewalls of the housing so external aesthetics are unchanged while redundancy is achieved. Devices in service might be authenticated during repair by imaging any interior tile; in e-waste streams, housings that are cracked or broken may still expose interior tiles that a reader can image and decode. A registry lookup over HTTPS could return the full material declaration and compliance flags, enabling directed disassembly or routing.

Example 3: Opaque, filler-rich polypropylene sorted using dark-field and infrared imaging. A packaging plant may produce PP parts with high carbon black content. The plant could select a DotCode or structured microdot field with raised features of about 20 micrometers height designed for high topographic contrast. The pattern might be applied by hot-roller embossing with a nickel shim at a temperature slightly above the PP softening point and a nip pressure adjusted to avoid warpage. A sorting facility may configure a reader with switchable 850 to 940 nanometer illumination and oblique dark-field lighting. As fragments pass the imaging station, the system may detect the locator structure from specular highlights of the relief and decode the payload indicating PP, even where visible imaging fails due to pigmentation. The system could then actuate a diverter to route fragments to a PP bin, recording timestamps, decoded fields, and actuation positions as an externally observable log.

Example 4: Fragment survivability and redundancy in PET trays. A food tray producer may embed a Data Matrix pattern with about 75 micrometer modules in several zones: near the gate vestige, along rib roots, and around ejector pin circles. After production, a durability protocol could subject trays to about 1,000 Taber abrasion cycles followed by shredding and sieving to 5 to 10 millimeter fragments. A bench-top reader may image random fragments under bright-field and infrared illumination, with decoding software reporting success rates and error-correction statistics. Results might show that more than 95 percent of fragments above about 25 square millimeters decode successfully, with recovered payloads matching batch and polymer records. In a live trial, a conveyor-integrated reader could decode fragments and correlate outputs with diverter pulses, demonstrating external observability of classification decisions based on the textured encoding.

Example 5: Registry interaction and tool orchestration using Model Context Protocol and JSON payloads. In a deployment where the decoding application runs on an edge device, the device may act as a client of a Model Context Protocol tool interface to standardize calls to a registry service and to local verification tools. A decoded payload on a fragment could be represented as JSON such as {“schema”:“v1”,“poly”:“PP”,“add”:“CB-05”,“batch”:“B2309”,“mfg”:“ACME”,“uid”:“0xC8F3A2B4C 901D7E8”,“sig”:“0x9f2c . . . ” } and logged alongside an imaging context such as {“ts”:“2025-05-18T12:03:55Z”,“px_per_module”:5.2,“illum”:“IR-880-darkfield”,“confidence”:0.997}. The edge device may invoke an MCP tool named registry.resolve with a request like {“tool”:“registry.resolve”,“args”:{“uid”:“0xC8F3A2B4C901D7E8”,“want”:“material,compliance,revo cation” }} and receive a response like {“uid”:“0xC8F3A2B4C901D7E8”,“material”:{“poly”:“PP”,“add”:“CB-05” },“compliance”:{“rohs”:“ye s”,“halogen_free”:“no” },“revocation”:{“status”:“valid”,“until”:“2026-06-30” },“sig_ok”:true}. For closed-network facilities, the device may instead call a local MCP tool verify.signature with input {“tool”:“verify.signature”,“args”:{“uid”:“0xC8F3A2B4C901D7E8”,“sig”:“0x9f2c . . . ”,“pub”:“did:exam ple:vendor #k1” }} and proceed based on {“sig ok”:true,“alg”:“Ed25519” }. These JSON examples illustrate externally observable inputs and outputs without constraining implementations to any specific message format; non-MCP interfaces may be substituted where appropriate.

Technical Field: The invention relates to methods for embedding metadata into the surface of manufactured parts, particularly plastic components, to potentially enhance recyclability, material purity, traceability, and producer accountability. This method may be referred to as “information texturising.”

Background: Recycling systems today often lack the precision to identify detailed chemical compositions or reliably trace the origin of plastic items once they are fragmented, worn, or visually degraded. As a result, high-value recycled plastic tends to be contaminated by misclassified materials, which undermines its commercial viability. Existing indicators, such as labels or surface markings, may not survive fragmentation or abrasion and offer only limited insight into a product's full composition or production background. Therefore, there may be value in a method that allows the chemical formulation and traceability information of a manufactured item to be embedded directly into the item's structure in a way that remains detectable even on small, damaged, or shredded fragments.

Summary of the Invention: The present invention proposes a method by which information related to a part's chemical composition and provenance could be embedded into the item itself during its manufacture. This process, termed “information texturising,” may involve the deliberate structuring of the surface texture of the manufactured item to carry machine-readable information. Such encoding could occur through modifications to the mold used in the forming process or via post-production surface treatments, such as laser texturing. The textured encoding might represent data such as polymer type, additives, production batch, or manufacturer identity. The encoding could be distributed across the entire part or across select zones in a redundant manner, potentially ensuring that even fragmented portions retain legible metadata. In certain cases, this information might link to a digital registry or database containing more detailed compositional and traceability records. For the avoidance of doubt, the scope of the invention is defined solely by the claims. The examples and embodiments described herein, including any sequences of steps or flows, are illustrative and may be performed in different orders, combined, substituted, or omitted where technically feasible, and any figures, if provided, are exemplary and non-limiting.

Definitions and Objective Measurement Criteria: As used herein, encoded texture refers to a spatial variation in surface topography that forms part of the surface of a manufactured part or of a bonded layer that, once attached, constitutes the part's external surface, the variation being configured to represent machine-readable information. Encoded texture may include raised or recessed relief, continuous or discretized features, single-depth or multi-level relief, and anisotropic or isotropic microstructures, whether periodic or aperiodic, including structures that do not visually resemble conventional barcodes yet carry decodable payloads. As used herein, machine-readable refers to a condition in which, when the encoded texture is imaged under reasonable optical conditions suitable for the material, a compliant decoder can recover the intended payload with error-correction assistance. By way of objective and non-limiting measurement guidance, reasonable optical conditions may include illumination in the visible or near-infrared bands with bright-field and/or dark-field components, image sampling of at least approximately three pixels per smallest data-bearing feature, and signal-to-noise sufficient for standard symbology decoders to operate. A decode may be considered successful when the payload bitstring is reconstructed exactly as encoded, optionally accompanied by an error-correction statistic or confidence score produced by the decoder. As used herein, fragment refers to any portion of a part that has separated from the whole through wear, fracture, shredding, or cutting and that retains at least a portion of an encoded texture sufficient for a decoder to output any payload field or unique identifier. Non-limiting practical thresholds for demonstration may include fragments of about 5 by 5 millimeters for thermoplastics with module pitches in the tens of micrometers, with the exact threshold depending on symbology, relief depth, and imaging conditions. As used herein, redundantly applied refers to the presence of more than one instance of the encoded payload or data-bearing field at two or more non-overlapping regions of a part such that loss, abrasion, or occlusion of any single region is unlikely to eliminate all instances. As used herein, exterior surface region refers to a surface that, in normal use, is exposed to the environment or becomes exposed upon routine disassembly, damage, or breakage, including interior walls of housings that are ordinarily concealed but are exposed on fragments in end-of-life streams. As used herein, registry refers to a service or data structure that maps a unique identifier to associated records and may provide issuance, verification, revocation, and schema management functions, whether implemented locally, in a distributed manner, or as a network-accessible service. The foregoing definitions and objective measurement criteria are intended to clarify terms for consistent construction and to provide repeatable, externally verifiable tests without limiting scope to any particular threshold or instrument configuration.

Technical Effects: The proposed texturised surface encoding may yield several concrete technical effects across the disclosed embodiments. By embedding machine-readable micro-relief that includes error correction and locator structures, fragments as small as several square millimeters could remain decodable under bright-field, dark-field, or infrared illumination, improving the probability of successful identification in fragmented waste streams. Redundant tiling of symbols or distributed microdot fields may increase decode survivability in the presence of abrasion, thermal cycling, chemical exposure, and mechanical damage, which could reduce misclassification rates and increase recycled stream purity by measurable margins, for example by several to tens of percentage points depending on input mix and operating conditions. Mold-integrated embodiments may produce highly repeatable micro-relief at effectively zero incremental bill-of-materials cost, improving manufacturability and long-term stability relative to adhesive labels or inks that may delaminate; this could reduce part-to-part variability in decoding and lower the need for post-process verification. Post-formation texturing may enable retrofit of existing molds and parts, expanding applicability without redesigning tooling and allowing adaptive payloads late in the supply chain, which could accelerate deployment and lower capital expenditure. Where a registry-backed unique identifier and optional cryptographic signature are included, devices may authenticate payloads in the field, yielding a technical effect of resistance to spoofing and improved provenance assurance without disassembly or destructive testing. Multi-band illumination and symbol-agnostic decoding may enable interoperability with a range of polymers and fillers, allowing robust detection even on highly scattering or pigmented substrates and thereby improving throughput on sorting lines by reducing the need for multiple specialized sensors. In combination with the external observability mechanisms, the system could facilitate automated actuation decisions that are traceable and auditable, which may decrease false diverter triggers and increase line efficiency. In aggregate, these effects may enable higher-value closed-loop recycling, more accurate recall and compliance auditing, and lifecycle analytics with reduced manual intervention, while maintaining low per-part cost and compatibility with established manufacturing processes.

Description of the Drawings: No drawings are provided in this filing. If drawings are added in a later filing, they may illustrate a manufactured part bearing encoded textures, molding tools with microstructured inserts that impart the textures, post-formation texturing systems such as lasers or embossers, reader devices configured to image and decode the textures on parts or fragments, optional registry services that resolve unique identifiers and verify authenticity, and sorting systems that route items based on decoded classifications.

Anchor: Elements and Relationships: The manufactured part may be referred to as a part formed from a material such as a polymer, composite, or metal, the part having an exterior surface region on which an encoded texture is present. A mold may include a cavity and, in some implementations, a removable or integral microstructured insert that carries negative relief corresponding to the encoded texture, such that during molding the texture is imparted to the part surface. In post-formation embodiments, a texturing system such as a laser, hot-roller embosser, ultrasonic embosser, or heated stamp applies localized energy or pressure to create the encoded texture on the finished part surface without modifying the primary mold. The encoded texture may comprise machine-readable patterns including two-dimensional symbolic codes, distributed microdot arrays, or structured micro-relief fields with locator marks and error-correction features, the patterns being repeated at multiple regions to provide redundancy against wear and fragmentation. The encoded texture may represent payload fields including polymer class, additive and filler identifiers, batch and manufacturer identifiers, environmental compliance flags, consumer-relevant indicators, and a unique identifier that resolves to a registry record. A registry service may maintain database records keyed by the unique identifier and may provide interfaces for issuance, verification, revocation, and schema updates, optionally using cryptographic signing keys to authenticate payloads and validity windows or revocation pointers to manage lifecycle status. A reader device may include illumination, imaging optics, a sensor, a processor executing decoding firmware, and an output interface to produce decoded payloads or feature vectors, with configurations suitable for microscopic, infrared, or dark-field detection of the texture. A sorting system may integrate one or more reader devices with a conveyor, diverter, and receptacles to route fragments according to decoded material classifications or provenance. During recycling, fragments bearing any redundant portion of the encoded texture can be imaged, decoded, mapped to registry data if present, and acted upon by downstream systems; in other deployment modes, the encoded payload alone may be sufficient for on-device decisions without network access.

The relationships among these elements are that the mold or post-formation texturing system defines the encoded texture on the part; the encoded texture carries the payload; the reader decodes the payload from whole parts or fragments; the registry, when referenced, resolves identifiers and verifies authenticity; and the sorting or auditing systems consume decoded and optionally verified outputs to enable material classification, traceability, and accountability.

Detailed Description of the Invention: The information may be embedded through modifications to the mold used in the manufacturing process. A mold might be structured using micro-milling, pulsed laser ablation, focused ion beam etching, or similar micro-fabrication techniques to create a pattern that is then imprinted onto each part during molding or casting. Alternatively, after molding, a high-precision laser or comparable surface-texturing system could apply a fine pattern that encodes the necessary metadata. The encoding patterns may be implemented as miniaturized, two-dimensional symbolic codes or distributed microdot arrays, configured for machine-readability under microscopic or enhanced imaging conditions. These patterns may remain detectable following typical surface wear, material aging, thermal cycling, or mechanical fragmentation. Suitable encoding formats include, but are not limited to, QR codes, Data Matrix codes, Aztec codes, DotCode, and PDF417, each selected based on application-specific constraints such as spatial resolution, information payload, error correction capacity, and tolerance to partial occlusion. The encoding may be repeated at multiple loci across the mold cavity, resulting in systematic replication of the embedded information across the manufactured part. This distributed encoding approach enables redundant data retrieval, ensuring that the embedded information remains accessible even when only a partial segment of the molded component is available. The repeated structures may further support fragment-based scanning and reconstruction, enhancing traceability and forensic utility in fragmented, damaged, or recycled materials. The patterns may encode, directly or indirectly, identifiers for the polymer type, additive composition, filler materials, and manufacturing details. In cases where full information is not embedded in the texture itself, a unique identifier may serve as a reference to a registry or database that contains comprehensive material and traceability data. This registry could be local, distributed, or globally managed, and might include lifecycle instructions, compliance records, and recycling guidance. Reading these patterns might be accomplished using current machine vision systems, optical microscopes, or infrared scanners. As reading technology improves, such systems could become increasingly efficient and compact, possibly allowing real-time scanning on recycling lines or embedded into robotic waste sorters. The encoding method is designed to be forward-compatible with such technological advances. The invention might also be applied beyond plastics to other molded, cast, or 3D-printed materials, enabling a broader system of traceable manufacturing across various sectors.

Enablement: Implementations may be realized using commercially available tooling, polymers, lasers, imaging devices, and software, following a sequence that a skilled person can reproduce without undue experimentation. An implementer may begin by defining a payload schema that includes fields such as a polymer class code, optional additive and filler identifiers, a batch identifier, a manufacturer identifier, a schema version, and optionally a unique identifier that maps to a registry record. The target total payload length may be estimated and paired with a symbology choice such as Data Matrix or QR where error-correction overhead and locator patterns are compatible with anticipated fragment sizes. A module pitch of about 25 to 200 micrometers may be selected based on part size and manufacturing capability, with a relief depth of about 2 to 50 micrometers suitable to survive abrasion while replicating reliably in common thermoplastics such as HDPE, PP, PET, ABS, and PC. For mold-based embodiments, a toolmaker may fabricate a removable insert or modify a cavity surface by micro-milling or laser texturing the negative of the chosen symbol. A finish of Ra less than 0.4 micrometers around features may improve contrast and demolding. Draft on vertical micro-walls may be at least 1 degree to avoid feature damage during ejection where geometry allows, and micro-vents may be placed to prevent gas trapping over high-aspect features. After polishing and passivation, the insert may be installed in the mold. Injection molding parameters may be tuned so that replication of the micro-relief is consistent across cycles. For HDPE, a melt temperature around 200 to 240 degrees Celsius, mold temperature around 20 to 40 degrees Celsius, moderate injection speeds to avoid jetting over microfeatures, and sufficient pack-and-hold pressure to fill relief valleys may be used, with values adjusted per resin datasheet and part geometry. Short-shot studies and optical inspection under 5× to 10× magnification may be used to confirm full fill of micro-relief before production. For post-formation embodiments, surface texturing may be applied using a UV or green pulsed laser with a spot size of about 10 to 30 micrometers. Pulse energy and repetition rate may be adjusted to achieve about 1 to 5 micrometers of ablation depth per pass without causing melting artifacts; multiple passes may build the desired depth. Typical scan speeds may be in the range of 50 to 500 millimeters per second depending on polymer absorption and heat accumulation. Embossing alternatives may use a nickel shim bearing the positive of the pattern affixed to a heated roller at a temperature just above the glass transition or softening point of the polymer and a nip pressure sufficient to achieve the target relief depth without warping the part. Redundancy may be achieved by tiling multiple identical symbols around functional landmarks such as ribs, bosses, and along flow paths, or by distributing microdot fields over a grid so that any fragment of at least several square millimeters is likely to include decodable content. A tiling pitch of about 5 to 50 millimeters may be used for large parts, with smaller parts using continuous fields. Reader devices may be configured with coaxial bright-field and oblique dark-field illumination to enhance topographic contrast. A camera with a pixel pitch that yields about 3 to 10 pixels per module at expected working distance may be selected; for a 50 micrometer module at 200 millimeters working distance, a 5 megapixel sensor with a suitable objective may suffice. Decoding firmware may perform flat-field correction, local contrast enhancement, symbol finder detection, geometric rectification, and error-correction decoding using Reed-Solomon or BCH algorithms provided by the chosen symbology library. Successful decode may output a payload, a confidence score, and an error-correction statistic. For registry-backed embodiments, the unique identifier may be structured as a compact binary field, for example 64 to 128 bits, optionally accompanied by a truncated digital signature such as a 128-bit tag derived from ECDSA or EdDSA to enable authenticity checks. Devices may verify signatures using published public keys and may query a registry over HTTPS using API keys or client certificates. Offline operation may be enabled by encoding a validity window and rotating keys, with devices caching certificate chains and revocation lists until connectivity is restored. Where a tool-orchestration layer is desired, the reader or edge gateway may expose Model Context Protocol tools that standardize registry and verification calls; for example, a decode-to-verify sequence could use input JSON like {“uid”:“0xC8F3A2B4C901D7E8”,“sig”:“0x9f2c . . . ”,“ctx”:{“schema”:“v1”,“poly”:“PP” }} and produce outputs like {“sig_ok”:true,“material”:{“poly”:“PP” },“actions”:[“route:PP”]}, with equivalent non-MCP APIs being substitutable without departing from the inventive concept. Durability may be validated by abrasion and fragmentation tests. Samples may undergo about 500 to 5,000 cycles on a Taber abrasion tester with CS-10 wheels and standardized mass, followed by optical inspection and decoding to establish survival of relief contrast. Fragment survivability may be evaluated by shredding parts using typical industrial shredders, sieving fragments by size, and measuring decode rates on fragments down to about 5 by 5 millimeters, recording the minimum fragment size at which error-corrected decoding remains above a target success rate such as 95 percent. For infrared-read embodiments, illumination in the 850 to 940 nanometer range may be used with plastics whose scattering yields high relief contrast, and the reader may switch bands based on material heuristics. Quality control in production may include sampling parts per lot, imaging one or more redundant symbols, verifying payload correctness against the bill of materials and batch records, and logging decode metrics to a traceability database. These concrete procedures and parameter ranges, together with known adjustments by a skilled person to accommodate specific materials, geometries, and equipment, may enable practical implementation without undue experimentation. In one presently preferred mode, a 50 micrometer-pitch Data Matrix symbol with approximately 10 micrometers of relief depth replicated via a polished mold insert on HDPE at a melt temperature of about 220 degrees Celsius and a mold temperature of about 30 degrees Celsius provides high replication fidelity and robust fragment decodability down to approximately 25 square millimeters under coaxial bright-field illumination.

Fallback Embodiments: To ensure coverage if certain elements are challenged or not implemented, simplified or partial implementations may be used while still embodying the inventive concept. In a minimal configuration, the encoded texture may consist of a short fixed-length identifier that maps to a registry record, repeated periodically in one or more limited regions such as around the gate, along rib roots, or near ejector pin marks, thereby achieving redundancy without full-surface coverage. The surface relief may be produced using lower-cost processes such as masked sandblasting, chemical etching, or mechanical knurling, yielding feature sizes on the order of tens of micrometers that are resolvable by commodity optics, without requiring micro-milling, laser ablation, or focused ion beam steps. The identifier may omit cryptographic signatures or extended payload fields and instead rely on a look-up table maintained locally or offline for applications where anti-spoofing is not essential. For post-formed parts, the encoded texture may be applied via heated stamping, hot-roller embossing, ultrasonic embossing, or insert-molded films carrying pre-embossed microstructures, avoiding modification of the primary mold. For highly filled or opaque materials, the pattern geometry may be selected for contrast under dark-field or infrared illumination, with raised or recessed features designed to survive wear even if error-correction coding is reduced. In sorting-only deployments, the payload may be limited to polymer class and a version tag, excluding additive lists or batch identifiers, while still enabling improved recyclate purity. These simplified embodiments still embed machine-readable metadata into the part surface such that fragments remain decodable, thereby achieving the recyclability and traceability benefits contemplated herein.

Workaround Resistance: To minimize potential design-arounds while remaining within the scope defined by the claims, the encoded texture may be understood to encompass recessed or raised relief, single-depth or multi-level relief, periodic or aperiodic microstructures, and structured fields that do not resemble conventional barcodes yet carry decodable payloads via locator features, synchronization cues, or error-correcting arrangements. Implementations could employ two-dimensional symbols, pseudo-random microdot constellations, anisotropic hatch fields, or multi-scale tilings in which coarse locator features coexist with fine data-bearing elements. The relief may be produced by subtractive processes such as laser ablation or micro-milling, by formative processes such as embossing, coining, or ultrasonic texturing, or by additive processes such as deposit of micro-beads, UV-curable ridges, or laser-induced forward transfer of textured material that becomes part of the exterior surface. Placement may occur on exterior faces, interior walls, hidden cavities, rib roots, bosses, gate vestiges, and ejector footprints, as well as on overmolds, coatings, in-mold labels, or insert-molded films that, once bonded, form the part's external surface. Redundancy could be achieved by rotationally symmetric layouts, omnidirectional locator motifs, and uniform microdot fields so that any fragment orientation remains decodable. Survivability may be enhanced by encoding at multiple spatial scales and depths so that abrasion that removes shallow features still leaves deeper carriers, and by distributing textures across mechanically distinct regions so that fracture patterns are unlikely to erase all instances. Reader pipelines may be designed to be symbol-agnostic and illumination-agnostic, so substituting a different symbology, module shape, or illumination band would not avoid detection or decoding, and registry-indirection may ensure that payload minimization does not bypass provenance or compliance checks. These implementation options may render attempts to avoid infringement by changing symbology, relocating textures to obscure surfaces, altering feature polarity, or modifying interface protocols ineffective where the system still embeds machine-readable surface relief that remains decodable on fragments for classification or traceability.

External Observability: For deployments in which internal algorithms or firmware cannot be inspected, the invention may define externally observable behaviors that demonstrate practice of the inventive features without access to internal workings. A part or fragment bearing an encoded texture may, when illuminated in visible or near-infrared bands and imaged at a spatial sampling suitable to resolve the micro-relief, yield a decodable symbol that maps to a structured payload or unique identifier consistent with a published schema or version tag. The decoding event may be externally evidenced by a reader device outputting, over a wired or wireless interface, a data record that includes at least a decoded identifier, a timestamp, an imaging context such as magnification or pixel pitch if available, and a decode confidence or error-correction statistic. In sorting systems, external observability may be provided by a correlation between the decoded classification and a downstream actuation such as a diverter pulse, with logs or counters recording item counts per class and actuation timing relative to conveyor position. In registry-backed modes, a network request containing the decoded unique identifier may elicit a registry response that includes a payload or attestation, a validity window, and optionally a signature verification status computed against a published public key; these request and response exchanges may be logged and are externally verifiable without device disassembly. In fragment scenarios, observability may be shown by imaging and decoding multiple distinct fragments from a single part and demonstrating that each fragment yields either the same unique identifier or a payload subset consistent with redundancy and error correction, thereby evidencing survivability. In offline verification modes, an externally obtained image of the encoded texture may be processed by a reference decoder to reproduce the same identifier or payload, and, where cryptographic signing is used, a third-party verification of the signature may succeed using the corresponding public key retrieved from the registry. These externally observable inputs and outputs, including emitted classifications, actuator events, registry lookups, verification statuses, and reproducible decode results from independent tools, may provide objective evidence of infringement or compliance in field conditions without requiring inspection of internal source code or hardware.

Interoperability Coverage: The invention may be implemented to operate across diverse hardware, software, and network environments so that changes in interfaces, platforms, or standards do not avoid infringement. Encoded textures may conform to multiple bar code and two-dimensional symbology standards including ISO/IEC 16022 for Data Matrix, ISO/IEC 18004 for QR Code, ISO/IEC 24778 for Aztec Code, ISO/IEC 15438 for PDF417, and AIM DotCode specifications, with decoder firmware being symbol-agnostic and capable of auto-detecting formats. Imaging and transport layers may interoperate with common industrial camera interfaces such as USB3 Vision and GigE Vision and with consumer interfaces such as USB Video Class, and may accept image formats including JPEG, PNG, BMP, TIFF, and raw sensor outputs, allowing readers from different vendors and operating systems including Linux, Windows, macOS, Android, and embedded RTOS to function. Device-to-registry communications could use multiple application protocols including HTTPS over HTTP/1.1 or HTTP/2, gRPC, MQTT, AMQP, and OPC UA, with payloads serialized as JSON, CBOR, Protocol Buffers, or XML so schema evolution and cross-vendor compatibility are maintained. Cryptographic verification may rely on widely adopted algorithms and key formats such as ECDSA or EdDSA signatures with keys distributed via X.509 certificates, COSE or JOSE structures, and may support key rotation, revocation, and multiple trust anchors to align with enterprise public key infrastructures. Reader control and telemetry may integrate with industrial automation systems via OPC UA nodes, Modbus bridges, or publish/subscribe topics, enabling interoperable actuation with diverse programmable logic controllers and manufacturing execution systems. For consumer or repair contexts, mobile devices may decode textures using native or web applications that access on-device cameras and perform offline or online verification, with deep links mapping identifiers to registry endpoints compatible with GS1 Digital Link or similar frameworks. These interoperability provisions may ensure that the encoded textures, decoding processes, and verification services function across heterogeneous ecosystems and evolving standards, and that substituting alternative interfaces or platforms does not materially change the externally observable inputs and outputs by which the invention operates.

Damages Maximization: The invention may be deployed in monetization models that support enhanced damages calculations by defining paid technical capabilities and associated usage. A subscription-based registry service could assign and manage unique identifiers for manufacturers and production batches, issue schema-compliant payload templates, and provide cryptographic signing keys under license. The encoded surface texture may include fields such as a subscription identifier, a validity window, a cryptographic signature or message authentication code derived from a private key, and a revocation pointer to enable verification against the registry. Verification services may be provided as paid APIs that accept images or feature vectors from decoding devices and return validated payloads, provenance attestations, compliance status, and recycling guidance. Access control could be enforced using API keys, mutual TLS, device certificates, rate limiting, and audit logging. Billing models may include per-identifier issuance fees, per-scan verification fees, or tiered subscriptions tied to throughput, resolution, or advanced error-correction features. Offline and low-connectivity environments might be supported via short-lived verification tokens embedded in the texture, rotating signing keys, and cached certificate chains synchronized when connectivity becomes available. Reader devices in sorting facilities could integrate attestation mechanisms and secure boot to ensure only licensed firmware performs decoding, and the registry may log anonymized verification events and usage metrics to substantiate commercial use. These technical mechanisms may enable a patentee to distinguish licensed versus unlicensed implementations and to quantify use of premium features, thereby supporting higher reasonable royalty calculations and damages assessments.

Court-Readiness and Definiteness: The terminology used in the claims and description may be construed according to its ordinary and customary meaning to a person of ordinary skill in the art at the time of filing, except where explicit definitions are provided herein. The definitions and objective measurement criteria provided for encoded texture, machine-readable, fragment, redundantly applied, exterior surface region, and registry are intended to promote definiteness and repeatable testing. For example, machine-readable may be established by external tests in which, under reasonable optical conditions yielding at least approximately three pixels per smallest data-bearing feature with bright-field and/or dark-field illumination in the visible or near-infrared bands, a compliant decoder outputs the payload bitstring exactly as encoded, optionally with an error-correction statistic or confidence score. Fragment may be evidenced when a separated portion of a part, after wear or shredding, retains enough encoded texture that a decoder outputs at least one payload field or unique identifier. Redundantly applied may be evidenced when more than one non-overlapping region of a part carries the same payload or data-bearing field such that occlusion or loss of one region is unlikely to eliminate all instances. The phrase configured to, as used in the claims, refers to structural arrangements that are adapted or arranged to perform the recited function and is not intended to invoke 35 U.S.C. § 112(f) absent explicit use of the term means. The non-transitory qualifier in the computer-readable medium claim excludes transitory propagating signals per se. The presently preferred mode is exemplified in the enablement section as a molded HDPE implementation using approximately 50 micrometer-pitch Data Matrix relief at approximately 10 micrometers depth replicated via a polished insert, and this disclosure may satisfy any best-mode requirement without limiting scope. Each independent claim finds written-description support: the method of embedding is supported by the summary, detailed description, enablement, and examples; the method of classifying fragments is supported by the external observability section, examples, and sorting system disclosures; the article is supported by the anchor and detailed description describing a part with an exterior encoded texture; the system is supported by the interoperability coverage, external observability, and enablement sections describing a conveyor, reader, processor, and diverter; and the computer-readable medium is supported by the reader pipeline steps of image acquisition, locator detection, geometric rectification, error-correction decoding, and outputting classifications or identifiers. The externally observable inputs and outputs defined herein provide objective indicia by which practice of the claims may be evidenced in field conditions. Nothing in the examples or alternative embodiments should be construed as a disclaimer of broader claim scope.

Various refinements, alternatives, and applications of the foregoing embodiment may be described by the following itemized list, each of which is considered to fall within the general inventive concept and may be combined where technically feasible:

A method of embedding information relating to the chemical composition of a manufactured part into the part itself by encoding said information in the surface structure of the mold or by applying said information to the surface texture after formation of the part.

A method of classifying fragments of a plastic item in a waste stream by detecting information that was deliberately encoded into the surface texture of the item during its manufacturing process, the classification aiming to improve the purity and consistency of sorted material.

The method of item 1, wherein the encoding comprises machine-readable surface features.

The method of item 1, wherein the encoding occurs by microstructuring the mold.

The method of item 1, wherein the encoding occurs via laser texturing after molding.

The method of item 1, wherein the encoded information may represent polymer type and/or additive composition.

The method of item 1, wherein the encoded information may identify a manufacturing batch.

The method of item 1, wherein the encoded information may identify the producer or manufacturer.

The method of item 1, wherein the encoding is redundantly applied across multiple regions of the part.

The method of item 1, wherein the encoding remains visible on fragments after mechanical damage.

The method of item 2, wherein the classification is performed by a computer vision system.

The method of item 2, wherein the classification is based on decoding a pattern corresponding to an external database record.

The method of item 2, wherein the fragments are sorted based on polymer compatibility.

The method of item 2, wherein the decoding system is embedded in a waste-sorting machine.

The method of item 1, wherein the surface features form a miniaturized two-dimensional data pattern.

The method of item 1, wherein the encoded pattern includes error correction to allow partial reading.

The method of item 1, wherein the information includes environmental compliance or recyclability flags.

The method of item 1, wherein the texturised pattern can be detected via infrared imaging.

The method of item 1, wherein the information texturising process is standardized to comply with an international schema.

The method of item 1, wherein the texturising pattern may also include consumer-relevant information retrievable by designated reader devices.

An article of manufacture comprising a manufactured part having an exterior surface region that includes an encoded texture configured to carry machine-readable information relating to chemical composition and provenance, the encoded texture being redundantly applied across multiple regions such that fragments of the part remain decodable after mechanical damage.

A system for classifying and sorting manufactured items or fragments, the system comprising a conveyor, an illumination and imaging reader device configured to image encoded surface textures, a processor configured to decode the textures and classify items, and a diverter configured to route items according to the classification.

The system of the preceding item, wherein the processor verifies a cryptographic signature or message authentication code embedded in the encoded texture against a registry service to authenticate payloads.

A non-transitory computer-readable medium storing instructions that, when executed by one or more processors, cause a reader device to obtain images of an encoded surface texture, detect locator marks, decode a data pattern with error correction, and output a classification or identifier usable for sorting or registry lookup.

### Embodiment BE: AI-Enforced Access System for Public Toilets with Identity Verification and Vandalism Detection

A system and method may manage public toilet access by verifying user identity, capturing pre-use and post-use interior conditions under controlled lighting, and automatically determining misuse via image comparison using a trained model or comparator. A controllable privacy shutter may physically occlude the camera during occupancy and may be interlocked with occupancy detection to preserve privacy. When misuse is indicated, deposits or stakes associated with the user may be partially or fully deducted, and a reputation record may be updated to influence future access. Tamper-evident audit logs, optional cloud synchronization for analytics and model updates, and interoperability with multiple identity and payment providers may be supported. Fallback embodiments may provide non-imaging sensing, offline operation, depositless accountability, and privacy-fault safing while preserving externally observable outcomes such as deposit refunds, deductions, and access restrictions.

BACKGROUND: Public sanitation facilities may often suffer from vandalism, misuse, and hygiene neglect, leading to increased maintenance costs and reduced accessibility. Traditional entry systems such as coin-based or free-access mechanisms may offer little to no accountability. A method that could encourage proper usage and deter vandalism through post-use accountability may be desirable, especially if privacy is respected.

### Summary

The present invention may relate to a system and method for public toilet access management that could utilize identity verification, camera-based condition monitoring, and automated analysis via artificial intelligence to detect misuse. A privacy-preserving mechanism might ensure that monitoring only occurs when the space is unoccupied. If damage or vandalism were detected, a user's deposit or stake could be forfeited and future access could be limited.

GENTLE INTRODUCTION: At a high level, the system may function like a deposit-backed access gate that could automatically check the facility's condition before and after a visit while preserving privacy during use. Before entry, the system may capture a quick snapshot or sensor reading of the empty interior under known lighting, similar to taking an inventory of the space. During occupancy, a physical privacy mechanism such as a shutter or power-gated camera may ensure that no images are taken, so the user's time inside remains private. After the user leaves, the system may capture another snapshot under the same conditions and may compare the two records to see if anything changed in ways that indicate misuse, such as spills, graffiti, or foreign objects. If the facility remains in good condition, the user's deposit may be fully refunded. If misuse is indicated, a portion of the deposit may be deducted according to configurable rules, and a reputation score may be updated to influence future access. The same concept may operate without a camera by using non-imaging sensors that could detect odors, spills, or abnormal sounds, enabling deployments where imaging is constrained. The approach may resemble an automated security deposit that is objectively evaluated by before/after evidence with strong privacy protections, clear external outcomes such as refunds or deductions, and optional cloud services for analytics and updates.

EXAMPLES: The following concrete scenarios exemplify operation of representative embodiments without limiting scope. In a routine refund scenario, a user approaches a locked stall and taps an NFC card linked to a wallet. The system verifies the token online, places a refundable deposit hold, and energizes fixed illumination to capture a pre-use image of the empty stall while the privacy shutter is open and the occupancy detector indicates unoccupied status. The shutter then closes, the door unlocks, and the user enters. During occupancy, the shutter remains closed and the camera is power-gated, so no images are captured. Upon exit, the occupancy detector transitions to unoccupied, the shutter reopens, and a post-use image is captured under the same lighting. The analyzer compares the two images and returns no misuse. The consequence logic immediately releases the deposit hold and records a tamper-evident log entry that includes timestamps, device identifiers, image hash digests, a no-misuse indication, and the deposit release. Images are retained within the local retention window and may be automatically deleted before the window expires when permitted by policy. From an external perspective, an observer could see that a deposit hold appeared at the time of authentication, the door unlocked, and the hold was released within seconds of exit with no human intervention.

In a scaled deduction scenario, a user scans a QR code with a mobile application that authenticates via a cloud token and posts a deposit. The system captures a pre-use image, engages the shutter, and unlocks the door. After exit, the post-use image reveals new graffiti lines on a wall and scattered paper on the floor. The analyzer, implemented as a trained model, produces a misuse indication with a severity score of moderate. The consequence logic maps the severity score to a deduction amount using an operator-configurable table, applies the deduction, and refunds the remainder of the deposit.

The reputation record associated with the user token is updated to reflect the incident, raising the required deposit for future visits. The audit log chains entries for authentication, image acquisitions, inference output, and the deduction, with signatures tied to device credentials. The images and relevant metadata are retained beyond the standard retention window for dispute resolution according to policy, and a notification is issued to the user application describing the deduction and appeal options. An external observer could detect that access was granted after a deposit, that a deduction correlated to the exit event occurred automatically, and that the system produced exportable incident summaries.

In a non-imaging, offline fallback scenario, a venue prohibits cameras and has intermittent connectivity. The facility controller operates with the camera disabled and relies on an ammonia sensor, a pressure mat near the bowl, and an acoustic sensor. A pseudonymous NFC token is presented and a local deposit is placed against a prepaid balance stored on the token. Before unlocking, the controller samples baseline sensor readings, records hash digests to a removable storage device, and unlocks the door. During occupancy, sampling continues but consequences are inhibited. After exit, the controller samples post-use readings for a brief interval and computes deltas using comparator logic that fuses elevated ammonia with an increased pressure footprint near the floor to indicate likely off-target waste. The system applies a small deduction and a short cooldown delay before the next access, updates the local reputation for the token, and writes hash-chained audit entries to removable media. When connectivity resumes, summaries and model parameters synchronize with the cloud service, but all core outcomes were enforced locally. From a black-box perspective, camera capture never occurs, deposits and deductions are still observable, and tamper-evident logs exist even without continuous network access.

In a software interoperability example, the system may integrate with a Model Context Protocol workflow so that a facility computing unit or a supervisory agent may expose tools for capture and analysis while preserving privacy guarantees. A local agent may advertise capture_pre_use, capture_post_use, analyze_pair, and adjust_deposit as MCP tools; upon successful identity verification and immediately prior to door unlock, the agent may invoke capture_pre_use and publish a compact event record, for example: {“type”:“pre_use_capture”,“facility_id”:“FAC-17A”,“session_id”:“S-2024-10-12-09-15-33Z-001”,“ti mestamp”:“2024-10-12T09:15:33Z”,“image_sha256”:“86b1 . . . f2c9”,“lighting_mode”:“fixed_4000K”,“occupancy”:“unoccupied” }. After exit, the agent may similarly produce a post-use record and request analysis via the MCP tool interface, for example: {“tool”:“analyze_pair”,“args”:{“pre_sha256”:“86bl . . . f2c9”,“post_sha256”:“aa77 . . . 19e0”,“modality”:“r gb”,“policy_id”:“POLICY-STD-01”,“return”:“severity” }} with a corresponding response such as {“severity”:0.42,“misuse”:true,“labels”:[“graffiti”,“paper scatter”]}. When misuse is indicated, the MCP client may request a scaled deduction through the same channel, for example: {“tool”:“adjust_deposit”,“args”:{“session_id”:“S-2024-10-12-09-15-33Z-001”,“user_token_ref”:“urn:t oken:abc123”,“action”:“deduct”,“amount”:4.50,“currency”:“USD”,“reason_codes”:[“MISUSE”,“SEV ERITY_TIER_2”]}}, and append a tamper-evident audit entry locally, for example: {“log_seq”:10293,“prev hash”:“0034 . . . 9bd1”,“entry”:{“event”:“deduction_applied”,“session_id”:“S-2 024-10-12-09-15-33Z-001”,“device_id”:“DEV-EDGE-042”,“time”:“2024-10-12T09:17:02Z”,“misuse”:true,“severity”:0.42,“deposit_change”:“−4.50”,“pre_hash”:“86bl . . . f2c9”,“post_hash”:“aa77 . . . 19e0” }, “sig”:“base64:MEUCIQC2 . . . kQ==” }. In privacy-fault or offline modes, the MCP tool surface may still return structured no-capture results and defer adjust_deposit to a local policy that issues refunds by default, while retaining the event schema for later synchronization.

### Enabling Description

The system may comprise an integrated hardware and software platform designed to manage access, record condition before and after use, and enforce accountability through automated deductions from user-held deposits. The architecture may consist of a small local computing unit such as a Raspberry Pi, Jetson Nano, or other embedded platform. This computing unit may interface directly with physical access components including a door lock actuator, an entry request button, and an exit detection mechanism. The entry button may signal intent to access the facility, prompting the computing unit to initiate a sequence of events.

Upon receiving the entry request, the system may first check whether a valid identity token has been presented through an NFC reader, QR code scanner, or mobile application interface. Once identity is verified and a minimum deposit or stake is registered, the computing unit may activate an internal camera to take a photograph of the unoccupied interior of the toilet. This image may include the toilet bowl, floor, walls, and surrounding area under fixed lighting conditions to maintain visual consistency. The pre-use image may be timestamped and stored locally or sent to a cloud service, depending on network configuration.

Simultaneously, a motorized shutter system may be activated to physically obscure the camera lens before the door is unlocked. The door lock actuator may receive a signal to unlock, allowing the user to enter. The shutter may remain engaged throughout occupancy to ensure no images are captured during use. Occupancy may be detected through door state sensors, pressure pads, or internal motion detectors.

Upon detection of exit-either by re-locking of the door, change in motion profile, or activation of an exit button—the computing unit may reopen the camera shutter and take a second photograph of the interior. This post-use image may then be paired with the original pre-use image and fed into a trained convolutional neural network, either locally or via a remote processing server. The AI model may be specifically trained to detect deviations considered indicative of vandalism or misuse. These might include the presence of overflowing material in the bowl, graffiti on the walls, non-standard foreign objects, excessive tissue usage, or evidence of urination or defecation outside of intended receptacles.

The trained neural network may generate an anomaly score or classification label indicating whether the deviation falls within expected usage patterns or constitutes a misuse event. This determination may trigger a rule-based response engine within the computing unit. If no anomaly is detected, the user's stake may be returned in full and no further action taken. If misuse is detected, the system may automatically deduct a predefined portion or the entirety of the user's deposited amount, and may log the event to a centralized behavior database.

The system may further maintain a user reputation registry wherein individuals flagged for repeated misuse may be subjected to increased stake requirements, access delays, or outright bans depending on administrative configuration. Data retention policies may enforce that all images be deleted within a specific time window, such as 48 to 72 hours, unless flagged as part of a confirmed misuse case.

Access to image data may be restricted to automated systems unless human review is legally mandated or requested by the user for appeal.

All data flows, including entry signals, identity verification, camera control, AI inference requests, and user balance updates, may be orchestrated through the local computing unit. Cloud integration may optionally extend the system's capabilities to include AI model updates, multi-location user tracking, dashboard access for facility operators, and aggregated misuse statistics.

This configuration may be deployed in fixed public toilets, mobile sanitation units, or semi-permanent festival installations. The modular design may support standardization across facilities while preserving privacy and enabling precise, low-cost enforcement of proper usage norms through automation.

DESCRIPTION OF THE DRAWINGS: No drawings are included in this document. For clarity and in lieu of figures, the Anchor section maps core components and their relationships so that a practitioner may unambiguously understand the structure and operation. If figures are provided in related filings, they may depict the facility computing unit, identity interface, door lock actuator, occupancy detector, camera, privacy shutter, lighting, memory, network interface, trained model, account adjustment logic, audit logging subsystem, and reputation database arranged and interacting as described herein.

### Anchor:

For clarity of implementation, the following anchor maps core elements of representative embodiments and their relationships so that the structure and operation can be unambiguously understood. A facility computing unit may coordinate an identity verification interface, an entry request button, a door lock actuator, an occupancy detector, a camera, a controllable privacy shutter that physically occludes the camera during occupancy, fixed or controlled lighting, a memory for storing pre-use and post-use images and associated metadata, a network interface for cloud connectivity, a machine-learning model used for image comparison and misuse determination, account adjustment logic linked to a user wallet or deposit store, an audit logging subsystem that produces tamper-evident records, and a reputation database storing incident history. In operation, a user may authenticate via the identity verification interface and optionally press an entry request button, after which the computing unit may capture a pre-use interior image under controlled lighting while the occupancy detector indicates unoccupied status and while the privacy shutter is unoccluded. The computing unit may then engage the privacy shutter and unlock the door lock actuator to permit entry. While the occupancy detector indicates occupied status, image capture may be inhibited both by software policy and by a mechanical interlock between the privacy shutter and occupancy detector path that prevents opening the shutter during occupancy. Upon exit detection, the computing unit may reopen the shutter, capture a post-use image, compare the pre-use and post-use images using the machine-learning model to generate a misuse indication and optionally a severity score, and invoke the account adjustment logic to issue a refund or a scaled deduction. The audit logging subsystem may record timestamps, device identifiers, identity token references, image hash digests, the misuse indication or severity score, and any deposit or fee adjustments in a hash-chained log. The reputation database may be updated accordingly and may influence subsequent access decisions by imposing higher deposit requirements, delays, or bans. Images may be deleted after a retention window unless a misuse case is flagged for evidence or dispute resolution, and a fail-safe rule may prevent any deduction when the camera, privacy shutter, occupancy detector, lighting control, or machine-learning model reports a fault condition. Via the network interface, the computing unit may synchronize images, incident records, reputation data, anomaly scores, account adjustments, and audit logs with a cloud service that provides centralized analytics, multi-site reputation federation, model updates, operator dashboards, entitlement verification for subscribed features, and APIs for exporting aggregated misuse costs and incident summaries.

The invention may be described through the following illustrative features and variations, which may be implemented independently or in combination:

A system for managing access to public toilet facilities, comprising a computing unit configured to verify user identity and capture pre-use and post-use images of the facility.

The system may include a camera positioned to capture an interior image prior to user entry.

The system may further include a servo-actuated shutter or similar mechanism configured to obscure the camera during occupancy, thereby preserving user privacy.

The computing unit may be operatively connected to a door lock actuator that responds to successful identity verification to permit access.

After use, the computing unit may capture a post-use image and compare it with the corresponding pre-use image.

The comparison may be performed by a trained neural network or other AI model configured to detect signs of misuse or abnormal facility conditions.

Misuse may be defined as the presence of foreign objects, excessive paper usage, visible waste outside of sanitary receptacles, or other predefined criteria.

Upon detection of misuse, the system may deduct an amount from a user-held deposit or stake.

Identity verification may be performed using an NFC token, biometric input (e.g., fingerprint or face recognition), or a mobile application.

The amount deducted may be scaled according to a severity score generated by the AI model based on the degree of misuse detected.

The system may maintain or access a user reputation database which is updated based on confirmed misuse events.

Repeated offenses, as tracked in the reputation database, may result in restricted access, including temporary or permanent bans.

All captured images may be automatically deleted after a defined retention period unless misuse is confirmed, in which case relevant data may be retained for evidence or dispute resolution.

The computing unit may synchronize locally stored data with a cloud-based server for centralized analysis, tracking, and management.

Multiple toilet facilities may share a federated or centralized user behavior record, enabling coordinated enforcement and access policy.

A method for managing public toilet access, comprising the steps of verifying identity, capturing pre- and post-use images, detecting anomalies, and applying corresponding consequences or access permissions.

The anomaly detection in the method may involve image analysis via a convolutional neural network trained on labeled examples of appropriate and inappropriate use.

Based on the analysis, user-held deposits may be refunded in full or partially deducted depending on detected behavior.

Occupancy detection within the facility may be achieved via motion sensors, pressure pads, or door-position monitoring.

The system may be configured to inform users of the access terms, deposit conditions, and data policy during the access request or authentication phase.

TECHNICAL EFFECTS: The described configurations may yield concrete technical effects that improve the operation, safety, reliability, and evidentiary trust of sanitation access systems. Capturing pre-use and post-use images under fixed illumination may reduce variability in scene appearance, thereby lowering false positives and false negatives for both trained models and comparator logic. The controllable privacy shutter, when mechanically interlocked with occupancy detection and supported by software gating, may physically prevent image capture during occupancy, which may reduce risk from software faults, firmware compromise, or sensor glitches and may enable deployments in privacy-regulated venues that would otherwise prohibit imaging-based systems.

Automated analysis via a trained model or non-learning comparator may transform noisy image or sensor data into an actionable misuse indication and optional severity score, which may enable deterministic policy enforcement by the account adjustment logic without requiring human review.

This automation may decrease operator response latency, may triage cleaning resources more effectively by correlating severity to service dispatch, and may lower total compute and power consumption when comparator-only modes are selected for constrained hardware. Non-imaging sensor fusion modes may deliver detection capability when cameras are restricted, with technical effects including resilience to lighting failure, improved robustness in steamy or low-visibility conditions, and reduced bandwidth and storage footprints.

Tamper-evident, hash-chained audit logs signed with device credentials may provide cryptographic integrity for event records such as door unlocks, inference outputs, and deposit adjustments, thereby enabling non-repudiation during dispute resolution and improving trustworthiness of exported summaries. Offline operation with local retention windows and removable media may increase availability during network outages while maintaining privacy guarantees and preventing deductions when fault conditions are detected, which may reduce erroneous charges and associated support loads.

Interoperable adapters for identity, payment, and messaging may reduce integration friction and system downtime during provider changes, while external observability through defined inputs and outputs such as deposit holds, refunds, deductions, and retention expirations may permit independent verification of correct system operation and detection of infringing implementations through black-box testing.

EXTERNAL OBSERVABILITY: Externally observable behaviors, inputs, and outputs may be defined so that correct operation and infringing implementations can be demonstrated without inspecting internal software. A deposit hold or pre-authorization may be placed at or immediately after authentication, producing a transaction entry visible to a user wallet, payment provider, or operator billing console and temporally preceding the door unlock event. The access control mechanism may indicate unlock and relock transitions through actuator sound, status indicators, or door-state telemetry, which may correlate with the authentication timestamp and the subsequent refund or deduction event. The system may emit notifications to a user application or to operator endpoints that summarize session outcomes such as refund issued, deduction amount, severity classification, and appeal options, with identifiers that match tamper-evident audit log references and with image or sensor data represented by hash digests so that privacy is preserved while external correlation remains possible. Privacy preservation may be externally validated by confirming that no capture-dependent consequences occur when occupancy is asserted continuously, that the privacy indicator or shutter remains engaged during occupancy, and that deductions are inhibited during declared privacy-fault conditions, with these states reflected in exported event summaries. For interoperable deployments, standardized API or MCP tool invocations and responses may be observed at the boundary of the facility computing unit or supervisory agent, including pre-use capture requests, post-use capture requests, analysis requests producing a misuse indication or severity, and deposit adjustment requests, each labeled by session identifiers and timestamps that align with physical events and account changes. These externally visible invariants may include that a baseline condition capture precedes entry, that a follow-up capture or sensor reading follows exit, that the analyzer determination precedes any monetary adjustment, and that refunds or deductions are applied automatically without human intervention, thereby enabling black-box testing, monitoring, and evidentiary proof of operation.

LEGAL AND EVIDENTIARY ROBUSTNESS: The system may incorporate structures that strengthen admissibility, reproducibility, and compliance. Audit logs may be append-only and hash-chained using a collision-resistant digest such as SHA-256, with each entry containing at least a monotonic sequence value, a prior-entry hash, a current-entry hash over event fields, and a digital signature produced by a device-held private key protected in a secure element, TPM, or trusted execution environment. Device identity and key provenance may be anchored by secure boot and attestation so that a verifier may confirm that only approved firmware produced the signed logs. Timekeeping may be derived from authenticated sources such as secured NTP, cellular network time, or GNSS time, with cross-checking and drift bounds recorded in the log; in offline modes, a local monotonic counter may be combined with later time reconciliation to produce verifiable timelines without enabling backdating. Analyzer reproducibility may be provided by recording the analyzer type, code or model version identifiers, and parameter hashes, enabling exact re-execution of a determination on preserved inputs; when a trained model is used, the log may include a model artifact hash and policy identifier so that an appeals process can replay the inference deterministically on the same pre-use and post-use data. For comparator-only embodiments, an enabling reference algorithm may convert images to a normalized luminance channel, apply Gaussian blur to suppress sensor noise, compute a background-subtracted difference image between pre- and post-use captures, threshold by an adaptive or Otsu method, apply morphological opening and closing to remove small artifacts, perform connected-component labeling to measure changed regions, and compute a severity index as a weighted function of change area, color ranges consistent with waste, and edge-density increases consistent with graffiti; this pipeline may be implemented with standard image processing libraries and parameterized to accommodate different installations without undue experimentation. For non-imaging sensing, an enabling fusion algorithm may normalize sensor streams over a short pre-use baseline, compute z-score deltas post-use, and combine features with a logistic or decision-tree classifier to produce a misuse probability and severity, with thresholds recorded in the policy and logged for later review. Consequence mapping may be bound to a policy table identified by an immutable hash so that the monetary or non-monetary outcome can be verified against the policy in effect at the time. Privacy safeguards may be self-tested at startup and at intervals by exercising shutter actuation or power-gating while observing a dark-frame or no-signal condition at the camera interface; failure to meet expected signatures may force the system into a privacy-fault mode that inhibits capture and deductions while still logging the fault. Chain-of-custody may be preserved by retaining only hash digests of large artifacts in routine logs and releasing underlying artifacts under policy and law, with the ability to prove that any presented artifact matches the original capture via recorded digests and signatures. These measures may reduce challenges to authenticity, enable third-party verification and replay, and provide clear, externally observable outcomes that can be independently corroborated, thereby improving the likelihood that determinations and records hold up in court.

MONETIZATION AND DAMAGES: The system may support monetization models for facility operators and service providers, including subscription-based access to the centralized cloud service for analytics, model updates, reputation federation, and dashboard functionality. A multi-tenant billing subsystem may meter events such as identity verifications, door unlock cycles, image capture pairs, inference runs, deposit adjustments, audit record writes, and data retention exceptions, and may associate those events with an operator account for monthly invoicing. Operator subscriptions may include tiered entitlements that enable or disable features such as higher model update frequency, extended analytics history, cross-site reputation synchronization, priority support, and remote diagnostics, with the local computing unit enforcing entitlements by verifying cryptographic tokens issued by the cloud service. For end users, the system may enable per-use fees in addition to refundable deposits, where a wallet linked to the identity token may be debited upon access and credited upon refund processing. The account adjustment logic may map AI-derived severity scores to monetary deduction tables maintained by the operator, optionally incorporating dynamic pricing factors such as current cleaning backlog, consumables costs, and time-of-day demand. To maximize damages recovery, the system may generate tamper-evident, hash-chained audit logs containing timestamps, device identifiers, identity token references, anomaly scores, image hash digests, and deposit or fee adjustments, thereby providing exportable evidentiary records for chargebacks, insurance claims, or civil actions. The cloud service may expose APIs for exporting aggregated misuse costs, per-user incident totals, and site-level damage estimates, supporting operator invoicing to third parties and enabling automated reconciliation with payment processors. The platform may further support prepaid balances, postpaid invoicing with credit limits, and revenue sharing between municipalities and service vendors, all enforced by the same metering and entitlement controls.

FALLBACK EMBODIMENTS: To ensure protection of the inventive concept if certain elements are unavailable, disputed, or impractical in a deployment, simplified or partial implementations may be configured while retaining accountable access based on pre- and post-condition assessment with privacy preservation. In a comparator-only fallback, the misuse determination may be performed without a machine-learning model by computing pixel-wise or feature-based differences between pre-use and post-use images under fixed illumination, applying thresholding, morphology, or statistical heuristics to detect added graffiti strokes, paper accumulation, liquid puddles, or foreign objects. A severity index may be derived from measured change area, color ranges associated with waste, or edge-density increases, and the account adjustment logic may apply refunds or deductions based on the severity index. In a camera privacy fallback, instead of a movable shutter, the system may enforce privacy by power-gating the camera during occupancy via a relay or solid-state switch and optionally engaging a solenoid-actuated lens cap that is spring-biased to the closed position, with occupancy-linked interlocks preventing energizing the camera until exit detection. In an offline operations fallback, all functions may execute locally without network connectivity, with audit records and image hash digests stored on removable media, images retained only within the local retention window, and model or comparator parameters updated via a portable storage device carried by an operator. In a depositless accountability fallback, where monetary deposits are not feasible, the system may issue per-use warnings, apply escalating cooldown delays, and update a pseudonymous reputation record tied to a token or device identifier, with future access conditioned on remedial actions such as completing a short on-device acknowledgement; when payments resume availability, the same reputation may be mapped to deposit multipliers. In an alternative sensing fallback, where imaging is constrained by policy, the system may detect misuse using non-imaging sensors including ammonia or VOC sensors indicating off-target waste, turbidity or color sensors in the bowl indicating overflow, acoustic signatures of prolonged flushing or impacts, and weight or pressure patterns indicating floor contamination, wherein the comparator or model fuses signals before applying account adjustments. In a retrofit-light fallback, the system may omit the entry request button and rely solely on a door-position sensor for occupancy state, may drive an existing electromechanical lock with an inline controller, and may display access terms and deposit status on a simple indicator panel or via a mobile application, while preserving before/after capture and automated consequences. In a privacy-fault fallback, if any privacy-related component reports a fault, the system may default to access with no imaging and no deductions while still recording a tamper-evident log of the fault and access event, thereby maintaining service continuity without compromising user privacy. Each of these fallback implementations may be configured through parameters and may operate independently or in combination to preserve the core operation of verifying identity or a pseudonymous token, capturing or sensing pre- and post-use conditions when permitted, determining misuse by automated analysis, and applying externally observable outcomes including refunds, deductions, access restrictions, or delays under a defined policy.

WORKAROUND RESILIENCE: To reduce opportunities for design-around while preserving privacy and interoperability, the inventive concepts may be characterized in terms of equivalence classes that encompass materially similar implementations. Condition data may include any representation of interior state captured before and after a contiguous occupancy interval, including but not limited to RGB images, monochrome images, HDR exposures, depth maps, structured-light point clouds, time-of-flight measurements, thermal or multispectral frames, acoustic impulse responses or spectrograms, weight or pressure distributions, gas sensor arrays, fluid turbidity or color metrics, valve or flush telemetry, or fused combinations thereof. The analyzer may be local or remote, synchronous or batched, and may comprise any algorithmic comparator or trained model that maps paired pre- and post-use condition data to a misuse indication and optional severity, including statistical differencing, feature hashing, template or background modeling, or machine-learned classifiers and segmenters; implementations that subsample time windows around entry and exit or that smooth, denoise, or normalize data to improve robustness may remain within scope. Privacy preservation during occupancy may be provided by any mechanism that physically, electrically, or logically inhibits sensing when occupancy is indicated, including shutters, lens caps, apertures, power or clock gating, or interlocks that prevent enablement while the occupancy signal is asserted, with fail-safe defaults to non-capture states. Identity association may be direct or pseudonymous and may include one-time or revocable tokens, device-bound credentials, privacy-preserving anonymous credentials, or mobile app assertions, so long as consequences are attributable to a token or identity for access control and accounting. Consequence application may include monetary or non-monetary holds, deposits, fees, refunds, warnings, cooldowns, access delays, or bans, enforced at any gating point including a door lock, stall latch, turnstile, kiosk, or upstream building entrance. Implementations that relocate computation to the cloud, split functionality across edge and backend components, substitute protocols or providers, or alter sensor modalities without removing the core sequence of identity association, pre- and post-condition capture with privacy during occupancy, automated misuse determination, and consequence application may be treated as equivalent. Externally observable behaviors may allow black-box detection of infringing systems, including the presence of a pre-authorization or deposit hold associated with an authenticated token, the capture of a baseline state immediately prior to entry and a follow-up state immediately after exit, and an automated refund, scaled deduction, or access restriction that correlates to detected condition differences in the absence of human operator intervention, with tamper-evident logging or retention windows reinforcing evidentiary integrity.

CONTINUATION-READY ITEMIZED LIST: Embodiments can be described by the following itemized list, which provides explicit support for present claims and for additional claim variants suitable for future continuations, with each entry being independently combinable unless context dictates otherwise. A sanitation facility access system may comprise a computing unit, an identity verification interface, a camera, a controllable privacy shutter, an occupancy detector, a door lock actuator, a memory, a trained model to compare pre-use and post-use images, and account adjustment logic holding and adjusting a user-associated deposit or stake. The identity verification interface may comprise at least one of an NFC reader, a QR code scanner, a biometric sensor, or a mobile application interface. The occupancy detector may comprise at least one of a door-position sensor, a pressure sensor, or a motion sensor. The computing unit may activate the camera to capture a pre-use image responsive to verifying a user identity and before unlocking the door, and may capture a post-use image responsive to detecting exit. The controllable privacy shutter may be servo-actuated and may remain engaged to obscure the camera while occupancy is indicated. The trained model may output a severity score and the account adjustment logic may scale a deduction amount in proportion to the severity score. A reputation database may store incident records associated with user identities and may apply access restrictions based on repeated misuse. Captured images may be automatically deleted after a defined retention period unless a misuse case is confirmed for evidence or dispute resolution. The computing unit may synchronize at least one of images, incident records, reputation data, anomaly scores, or account adjustments with a cloud service for centralized analysis, model updates, multi-location user tracking, dashboard access, or aggregated statistics. The computing unit may generate an auditable record comprising timestamps, device identifiers, identity token references, a misuse indication or severity score, and a deposit or fee adjustment entry. Lighting control may provide fixed illumination conditions during image capture to maintain visual consistency. A fail-safe rule may prevent deductions when the camera, privacy shutter, occupancy detector, lighting control, or trained model reports a fault condition. A method for managing access may include verifying identity, capturing a pre-use image while unoccupied, engaging a privacy shutter, unlocking a door, monitoring occupancy, capturing a post-use image upon detecting exit, comparing the images using a trained model to determine misuse, and adjusting a deposit or stake by issuing a refund or deduction based on the determination. The method may further include updating a user reputation record with determinations and applying access restrictions based on accumulated records. The method may further include deleting the pre-use and post-use images after a retention window unless a misuse case is flagged. Verifying the user identity may include at least one of detecting an NFC token, performing biometric recognition, scanning a QR code, or authenticating via a mobile application. A non-transitory computer-readable medium may store instructions that cause a facility computing unit to perform the method described herein. A networked system may comprise a plurality of sanitation facilities each including the system described herein and a centralized or federated service maintaining a shared user behavior record and distributing trained model updates. Determining misuse may comprise detecting at least one of foreign objects, graffiti, waste outside sanitary receptacles, an overflowing bowl, or excessive paper usage. The privacy shutter may be mechanically interlocked with the occupancy detector to prevent image capture during occupancy. Misuse detection may alternatively or additionally be performed without a camera via non-imaging sensors including ammonia or VOC sensors, turbidity or color sensors, acoustic sensors, pressure or weight sensors, or combinations thereof, with comparator logic or a trained model fusing signals to derive a misuse indication and severity score. Privacy preservation may alternatively be achieved during occupancy by power-gating the camera, disabling image sensor clocks, and optionally engaging a spring-biased lens cap, while maintaining mechanical or electrical interlocks that prevent capture until exit is detected. Offline operation may be supported wherein all functions execute locally without network connectivity, audit logs are hash-chained and stored on removable media, and models or parameters are updated via portable media. Depositless accountability may be supported wherein consequences include warnings, cooldown delays, or access restrictions, and a pseudonymous token reputation may be mapped to deposit multipliers when payments are enabled. Monetary deductions may be mapped from severity scores via operator-configurable tables and may incorporate dynamic factors such as cleaning backlog, consumables costs, and time-of-day demand. Tamper-evident audit logs may include cryptographic hash chaining, device certificates, and image or sensor data hash digests to provide evidentiary records for disputes, insurance claims, or civil actions. Interoperability may be supported by abstracting identity providers, payment processors, and messaging protocols through modular adapters so that NFC standards, barcode formats, mobile wallets, and cloud APIs can be substituted without departing from the core operation. External observability may be provided by defining externally visible behaviors including deposit holds and releases, door unlock events, retention window expirations, and exportable incident summaries, enabling detection of infringement by monitoring inputs and outputs without internal inspection. Operator subscriptions may be enforced by entitlements verified via cryptographic tokens, with metering of identity verifications, door unlocks, image or sensor acquisitions, inference runs, deposit adjustments, and retention exceptions for billing. Mechanical and electrical safety interlocks may ensure that privacy controls default to safe states, with automatic suspension of deductions upon detected faults and with continued logging for service continuity. The sequencing of operations may be reordered or performed in parallel while still preserving the core before/after assessment, misuse determination, and consequence application.

SCOPE AND INTERPRETATION: The embodiments described herein are illustrative and non-limiting. The scope of protection is defined solely by the claims, and no feature, element, figure, flow, or example shall be construed as limiting except to the extent expressly recited in a claim. Operations may be performed in different orders or in parallel, elements may be substituted with equivalents that perform substantially the same function in substantially the same way to achieve substantially the same result, and optional components may be omitted in particular implementations. References to specific hardware, sensors, models, or protocols are by way of example; interoperable alternatives may be used. Any description of advantages, effects, or outcomes is not intended to limit scope but to illustrate potential benefits under certain operating conditions.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

Item 1. A system for managing access to a sanitation facility, comprising:
a computing unit;
an identity verification interface;
a sensing subsystem configured to capture pre-use and post-use condition data of the facility; a memory;
an analyzer; and
consequence logic configured to apply at least one of monetary adjustments, access restrictions, or notifications.

Item 2. The system of item 1, wherein the sensing subsystem comprises a camera oriented to capture interior images of the facility.

Item 3. The system of item 2, wherein the camera is coupled with a privacy-preservation mechanism configured to prevent image capture during occupancy.

Item 4. The system of item 3, wherein the privacy-preservation mechanism comprises at least one of a controllable privacy shutter, camera power-gating, image sensor clock disabling, or a spring-biased lens cap.

Item 5. The system of item 1, wherein the sensing subsystem comprises a non-imaging sensor suite including at least one of an ammonia sensor, a volatile organic compound sensor, a turbidity sensor, a color sensor, an acoustic sensor, a pressure sensor, or a weight sensor.

Item 6. The system of item 1, wherein the identity verification interface comprises at least one of an NFC reader, a QR code scanner, a biometric sensor, or a mobile application interface.

Item 7. The system of item 1, further comprising an occupancy detector.

Item 8. The system of item 7, wherein the occupancy detector comprises at least one of a door-position sensor, a pressure sensor, or a motion sensor.

Item 9. The system of item 1, wherein the computing unit is configured to activate the camera to capture a pre-use image responsive to verifying identity and before unlocking a door lock actuator, and to capture a post-use image responsive to detecting exit.

Item 10. The system of item 1, wherein the analyzer comprises a machine-learning model that outputs a severity score.

Item 11. The system of item 10, wherein the consequence logic scales a deduction amount in proportion to the severity score.

Item 12. The system of item 1, further comprising a reputation database configured to store incident records associated with user identities.

Item 13. The system of item 12, wherein the reputation database applies access restrictions based on repeated misuse.

Item 14. The system of item 1, wherein captured images are automatically deleted after a defined retention period unless a misuse case is confirmed for evidence or dispute resolution.

Item 15. The system of item 1, wherein the computing unit synchronizes at least one of images, incident records, reputation data, anomaly scores, or account adjustments with a cloud service.

Item 16. The system of item 1, wherein the computing unit generates an auditable record comprising timestamps, identity token references, misuse indications, and deposit adjustment entries.

Item 17. The system of item 1, further comprising lighting control configured to provide fixed illumination conditions during image capture.

Item 18. The system of item 1, wherein a fail-safe rule prevents deductions when the camera, privacy shutter, occupancy detector, or machine-learning model reports a fault condition.

Item 19. The system of item 2, wherein the privacy shutter is mechanically interlocked with the occupancy detector to prevent image capture during occupancy.

Item 20. A method for managing access to a public toilet facility, comprising:
verifying at least one of a user identity or pseudonymous token;
capturing a pre-use condition of the facility while unoccupied;
engaging, when a camera is employed, a privacy-preservation mechanism;
unlocking a door;
monitoring occupancy;
capturing a post-use condition upon detecting exit;
comparing the pre-use and post-use conditions with an analyzer; and
applying consequences comprising at least one of deposit adjustments, access restrictions, or notifications.

Item 21. The method of item 20, further comprising updating a user reputation record with the determination.

Item 22. The method of item 21, wherein applying access restrictions is based on accumulated records in the reputation database.

Item 23. The method of item 20, further comprising deleting pre-use and post-use images after a retention window unless a misuse case is flagged.

Item 24. The method of item 20, wherein verifying the user identity comprises at least one of detecting an NFC token, performing biometric recognition, scanning a QR code, or authenticating via a mobile application.

### Embodiment CE: AI-Mediated Contract Exchange System with Standardized Templates, Autonomous Agent Execution, and Tiered Dispute Resolution

An online deal-making and enforcement platform may enable autonomous agents to negotiate, execute, and monitor standardized digital contracts using versioned templates anchored to canonical human-readable clauses. Agents could populate templates with parameters, sign them cryptographically, and post offers via authenticated APIs for discovery and countersignature. Upon two verified signatures, the platform may lock the contract, activate a lifecycle state machine, and manage programmable escrow. Monitoring subsystems may ingest fulfillment signals, and a tiered dispute resolution engine may apply embedded clauses and escalate from AI adjudication to human peer panels or certified arbitration. Immutable audit logs and externally observable interfaces may provide tamper-evident proofs of formation, execution, and rulings. The system may interoperate across devices and clouds, support fallback embodiments, provide monetization and metering for damages computation, and expose flows suitable for method claims.

Background: Digital contracting remains fragmented, with heterogeneous formats, opaque enforcement, and costly dispute processes. Conventional marketplaces often rely on natural-language agreements that are hard to parse by automation and poorly interoperable across vendors and platforms. Escrow and adjudication are typically manual, delays increase friction, and proofs of breach or fulfillment are difficult to verify. There is a need for a standardized, machine-readable yet human-anchored contract environment in which autonomous agents can safely transact, where execution, observability, and dispute outcomes are programmatically enforced.

Summary: Disclosed is a platform that may maintain a registry of versioned machine-readable templates linked to canonical human-readable clauses, enable autonomous agents to populate and sign instances, publish offers for discovery, and lock contracts upon countersignature. A programmable escrow subsystem, monitoring for fulfillment signals, and a multi-tier resolution engine may enforce embedded clauses. Immutable audit logs and publicly queryable registries may provide external observability for proof of infringement and damages. The system may interoperate across devices, clouds, and data standards, with fallback embodiments that preserve infringement-determinative behaviors.

Description of the Drawings: No drawings are included for this embodiment. If provided in other filings, figures may depict the elements and relationships described in the Anchor section and the flows described in the Detailed Description.

Gentle Introduction: Most online agreements still depend on long, human-written documents and manual follow-up. The disclosed platform may let software agents handle the repetitive parts safely and predictably. At a high level, a provider's agent may select a standard contract template that reads like a familiar agreement to people but is also represented in a structured form that computers can check. The agent may fill in basic blanks—who, what, when, and how much—and sign. The offer may become visible to a buyer's agent, which could verify that the template version matches, that fields are valid, and that the signer is genuine. If acceptable, the buyer's agent may sign as well. At that moment, the platform may lock the deal so no one else can take it, start a simple lifecycle that tracks progress, and, where applicable, hold funds in a neutral escrow.

Fulfillment may be observed using straightforward signals that are already common in many services, such as timestamps, location pings, third-party confirmations, or short user acknowledgments. If something goes wrong, the contract may already say what should happen next—for example, a partial refund for a late pickup-so the platform could apply those rules automatically as a first step. When evidence is needed, photos or logs may be submitted with device signatures and timestamps so that authenticity can be checked. If either party disagrees with the automated decision, the contract may allow a predictable escalation to a small human peer panel or to certified arbitration, with each step adding time and cost to discourage abuse.

Because all key steps-offer posting, acceptance, locking, state changes, evidence checks, rulings, and fund movements—may be recorded in an immutable audit log and exposed through simple, documented interfaces, outsiders may verify what happened without needing access to internal code. The same approach could work across devices and clouds: agents may call standard APIs and use versioned templates, so switching tools or vendors may not break compatibility. The result may be a cleaner, more interoperable way to make and enforce everyday agreements, with clear remedies when things go wrong and proofs that are easy to show.

This intuitive flow-fill a known template, sign, lock, observe, and resolve—may support a wide range of services, from rentals to subscriptions. The sections that follow may formalize the data structures, interfaces, and lifecycle mechanics that implement this flow, while keeping contracts grounded in human-readable clauses that explain the meaning of each field.

### Examples

A car rental transaction may proceed as follows in a concrete, step-by-step manner. First, a provider agent may retrieve a specific versioned rental template from the template registry and populate fields including pickup location, pickup and drop-off times, vehicle class, price, fuel policy, and a breach clause that specifies a 10% refund for pickup delays exceeding 30 minutes. The agent may compute a hash of the populated instance, sign the payload with the provider's key, and submit the offer via the authenticated offer-posting endpoint, optionally including an escrow deposit parameter. The platform may validate the schema and signature, assign an offer identifier, timestamp the posting, and publish the offer for discovery. A consumer agent may then query the offer registry for matching rentals, download the selected offer, verify the template identifier and signature, and evaluate the embedded terms alongside informal attributes such as sentiment and cleanliness indicators. If acceptable, the consumer agent may sign a countersignature, optionally include a mirrored escrow amount, and submit this acceptance via a signing endpoint. Upon verification, the platform may lock the contract, assign a contract identifier, activate the lifecycle, and hold escrow. At pickup time, if the vehicle is delivered 35 minutes late, the consumer agent may file a breach report with device-signed timestamps. The AI adjudicator may verify the evidence against the contract's delay clause and execute a 10% refund directly from escrow, recording all events-countersignature, lock, evidence submission, ruling, and fund movement—in the immutable audit log.

A hotel quality-of-service guarantee may be handled similarly. A hotel agent may post a room offer referencing a template that includes a clause guaranteeing functioning air conditioning with a full refund and paid relocation if it fails. After the guest's agent countersigns and the platform locks the contract, the guest may arrive and discover that air conditioning is inoperative. The guest may capture timestamped, device-signed video and submit a breach report. The AI adjudicator may validate provenance, correlate the evidence to the clause, and issue a ruling that triggers a refund and an automated rebooking through partner listings. If the provider contests, the case may escalate to a peer panel that receives an anonymized summary and returns a decision within a defined window. The platform may then finalize the outcome, adjust stakes, update reputation scores, and expose receipts and ruling artifacts via audit APIs.

An ongoing subscription migration scenario may illustrate rolling decisions. A user's agent may continually scan the offer registry for improved mobile plans, interpreting both formal terms such as monthly price and data caps and informal indicators such as sentiment scores. When a superior plan is discovered, the agent may check termination windows under the current contract, submit a signed termination notice if permitted by policy, and then sign a new subscription contract instance with the preferred provider. The platform may lock the new contract, manage any pro-rated charges via escrow or pre-authorization holds, and monitor service activation signals. If the new provider fails to activate service by a deadline defined in the template, the agent may submit device-signed logs, prompting the AI adjudicator to apply an embedded remedy that may include a compensatory credit or automatic rollback to the prior provider, with all transitions recorded in the immutable audit log.

In MCP-based implementations, agents and the platform may interoperate using the Model Context Protocol, wherein the platform could expose tools such as template.get, offer.post, offer.discover, sign.countersign, escrow.deposit, dispute.file, evidence.submit, and audit.query. An agent may invoke offer.post with a populated instance and signatures, for example using a compact JSON payload like {“template_id”:“tpl:car rental:v3”,“clause_set_hash”:“b8alf7 . . . ”,“instance hash”:“91e4c2 . . . ”,“parame ters”:{“pickup_location”:“BER-T1”,“pickup time”:“2026-07-01T09:00:00Z”,“dropoff time”:“2026-0 7-05T10:00:00Z”,“vehicle_class”:“midsize”,“price”:{“amount”:“150.00”,“currency”:“EUR” },“breach _clauses”:[{“id”:“delay_pickup_over 30m”,“remedy”:{“type”:“refund_percent”,“value”:10}}]},“sign atures”:[{“party”:“provider:autofast”,“alg”:“ed25519”,“sig”:“d2ab . . . ” }],“escrow”:{“amount”:“150.00”, “currency”:“EUR” }} and may later call sign.countersign with a countersignature such as {“offer id”:“off-7f3a2c”,“sig”:{“party”:“consumer:alice”,“alg”:“ed25519”,“sig”:“a9cl . . . ” }}. When filing a breach under dispute.file, the agent could attach evidence via evidence.submit using inline JSON such as {“contract_id”:“ctr-48b9e1”,“evidence_id”:“ev-0021”,“media_hash”:“f0aa . . . ”,“device_sig”:“5c3d . . . ”,“t s”:“2026-07-01T09:35:1OZ”,“gps”:{“lat”:52.5541,“lon”:13.2893,“acc_m”:8.2}}. These examples may illustrate concrete, interoperable exchanges that align with the structured templates and auditability described herein.

### Enablement

A skilled person may implement the system by provisioning server components comprising: a template registry that stores versioned JSON or XML schemas linked to canonical clauses; authenticated API endpoints for template retrieval, offer posting, discovery, countersigning, escrow operations, dispute filing, evidence submission, and audit access; a signing engine with public-key verification and schema validation; a contract lock and lifecycle state machine; a smart escrow engine integrated with payment rails; monitoring adaptors for IoT, third-party confirmations, and user feedback; an AI adjudicator configured with contract schemas, provenance policies, and remedial templates; escalation orchestration to peer panels or arbitration; and an immutable append-only audit log with query endpoints. Agents running on user devices or cloud instances may discover templates, populate parameters, produce hashes, sign payloads, submit offers, verify counterpart offers, countersign, and interact with escrow and dispute APIs. Evidence capture applications may embed device-signed timestamps and location metadata. The workflows in the Detailed Description provide step-by-step operational sequencing that can be implemented without undue experimentation using standard cryptographic, web API, and database techniques.

In MCP-based deployments, the platform may define Model Context Protocol tools that correspond to the aforementioned endpoints, enabling agents to interoperate through a uniform tool-calling interface. Tool names may include template.get, offer.post, offer.discover, sign.countersign, escrow.deposit, dispute.file, evidence.submit, and audit.query, each accompanied by JSON schemas for inputs and outputs. For example, a minimal offer.post request may be

{“template_id”:“tpl:service:v1”,“clause_set_hash”:“c1a9...”,“instance_hash”:“9f02...”,“parameters”:{“
service”:“rental”,“start”:“2026-07-01T09:00:00Z”,“end”:“2026-07-05T10:00:00Z”,“price”:{“amount”:
“150.00”,“currency”:“EUR”}},“signatures”:[{“party”:“provider:autofast”,“alg”:“ed25519”,“sig”:“d2ab
...”}]} and a corresponding sign.countersign call may be
{“offer_id”:“off-1234”,“sig”:{“party”:“consumer:alice”,“alg”:“ed25519”,“sig”:“a9c1...”}}. A breach
filing via dispute.file could reference evidence submitted with evidence.submit as
{“contract_id”:“ctr-48b9e1”,“evidence_id”:“ev-0021”,“media_hash”:“f0aa...”,“device_sig”:“5c3d...”,“t
s”:“2026-07-01T09:35:10Z”}.

A concrete implementation sequence may proceed in discrete steps that a skilled person could execute without undue experimentation: (1) implement a content-addressable template registry storing versioned JSON or XML schemas and a canonical clause set, keyed by digests such as template_id and clause_set_hash; (2) expose authenticated REST-like endpoints and MCP tools for template retrieval, offer posting, discovery, countersigning, escrow, dispute filing, evidence submission, and audit queries; (3) integrate a signing engine that verifies ed25519 or ECDSA signatures and optionally time-bounded HMAC tokens bound to agent identities; (4) implement a contract lock and lifecycle state machine compiled into deterministic bytecode with O(1) transition evaluation; (5) deploy a smart escrow engine that issues idempotent transfer instructions keyed to contract_id and event id; (6) realize an immutable append-only audit log as a hash chain with periodic Merkle roots anchored to a public attestor; (7) add monitoring adapters for IoT, third-party confirmations, and user feedback; (8) configure the resolution engine with policy versions, clause identifiers, and remedial templates, optionally including an AI adjudicator with a model configuration hash and prompt digest; (9) perform end-to-end conformance tests by posting a signed offer, countersigning, verifying contract lock, injecting a synthetic fulfillment or breach signal, and confirming escrow and audit log outcomes; and (10) harden transport and key management with mutually authenticated TLS, hardware-backed keys, and FIPS-validated cryptographic modules.

### Technical Effects

The disclosed architecture may produce concrete technical effects including: tamper-evident auditability through immutable logging; reduction of fraud via device-signed evidence provenance; improved interoperability through versioned machine-readable templates anchored to human-readable clauses; lower dispute latency via automated adjudication and programmable remedies; scalable enforcement by lifecycle-driven escrow releases; and externally verifiable usage metering that supports damages computation. These effects may increase reliability, throughput, and trust in automated contracting systems compared to ad hoc, manual processes.

### Court-Robustness and Computer Functionality Improvements

The specification may describe concrete data structures and processor-executed mechanisms that improve the functioning of computer systems rather than merely automating a business practice. The immutable audit log may be implemented as an append-only hash chain in which each record includes a previous-hash pointer, a monotonic sequence number, a high-resolution timestamp, an event type code, a canonical payload digest, and a record-level signature. The platform may periodically compute a Merkle root over recent records and anchor the root to a public attestor, such as a timestamping or notary service, thereby enabling efficient third-party verification and tamper-evidence without full database disclosure. This structure may improve integrity guarantees and verification throughput relative to conventional mutable logs.

The contract lifecycle may be realized as a finite-state machine compiled into deterministic bytecode with a transition table stored in memory. Transitions may only execute when a verifier validates a signed event against the active state and guard conditions, yielding O(1) transition evaluation and reducing lock contention in concurrent processing. This state-machine approach may improve server throughput, decrease contention-related retries, and reduce error rates caused by race conditions compared to ad hoc workflow code.

The template registry may operate as content-addressable storage keyed by a cryptographic digest of each template version and a corresponding digest of its canonical human-readable clause set. Referential integrity may be enforced by verifying that populated instances carry both digests, ensuring that machine-readable fields are anchored to specific human-readable text. This binding may improve consistency and reduce parsing ambiguity, thereby enhancing machine verification performance.

The resolution engine may generate verifiable decision traces comprising a normalized facts vector, clause references by identifier, applied policy version identifiers, and, when an artificial intelligence model is used, a model configuration hash and prompt digest. These traces may be signed and stored in the audit log to support reproducibility and appeal tiers. The escrow subsystem may integrate with payment rails through tokenized instruments or pre-authorizations and may expose idempotent transfer instructions keyed to contract and event identifiers, reducing reconciliation errors and manual interventions. Transport security may employ mutually authenticated TLS 1.3, hardware-backed key storage for server credentials, and signing operations performed in FIPS-validated modules. Collectively, these architectural choices may provide specific improvements to computer functionality, including stronger integrity, lower latency in state transitions and settlements, and efficient external verification of system behavior.

To promote litigation robustness and subject-matter eligibility, the claimed methods and systems may be expressly tied to particular machine components and non-generic data structures that effect improvements in computer operation. For example, signature verification and acceptance artifacts may be executed by processors invoking constant-time cryptographic primitives operating on fixed-format acceptance payloads that include fields such as key_id, alg, ts_monotonic_ns, payload digest, and record_sig, thereby preventing timing-leak variability and reducing verification latency jitter. The lifecycle state machine may be compiled into deterministic bytecode stored in a read-only memory-mapped segment with transition entries laid out as fixed-width structs comprising state_code, guard_mask, event_code, next_state_code, and action_ptr, enabling O(1) array-indexed dispatch without dynamic allocation. The immutable audit log may commit records through a write-ahead log with fsync barriers and sequence fences to enforce ordering on persistent media, and may compute Merkle roots over contiguous record windows using a sliding hash to amortize cost, which reduces I/O and enables external verification without disclosing internal database layouts. Escrow transfer instructions may be generated as idempotence-keyed directives, keyed to tuples such as (contract_id, event_id, seq_no), and transmitted over mutually authenticated channels with retry semantics that de-duplicate at the receiver, thereby improving reliability of settlement even under transient network faults. These operations cannot be performed as mental steps or by pen-and-paper processes, depend on specialized machine operations and memory ordering, and produce measurable resource and latency improvements compared to conventional software stacks.

The claims may not be directed to a fundamental economic practice in the abstract, nor do they preempt all implementations of digital contracting. Instead, they recite a specific architecture comprising versioned, content-addressable templates anchored to canonical clauses; authenticated submission and countersignature using cryptographic artifacts; a bytecode-compiled lifecycle state machine with O(1) transition evaluation; a programmable escrow subsystem issuing idempotent transfer instructions; and an append-only hash-chained audit log periodically anchored by Merkle roots to a public attestor, all exposed through authenticated interfaces that yield externally verifiable artifacts. Implementations that omit these concrete structures and machine-tied operations may fall outside the claims, while variants that employ equivalent computer-implemented structures may remain within scope. The disclosed structures provide algorithmic and systems-level improvements to computer functionality, including reduced lock contention, deterministic state transition latency, stronger tamper-evidence, and failure-resilient financial settlement.

### Flows

Process flows are described in the Detailed Description, including offer creation by a first agent, offer discovery by a second agent, countersignature and contract lock activation, lifecycle monitoring, breach reporting, AI adjudication, optional escalation, and escrow release or redistribution. These flows can be directly converted into flowcharts to support method claims.

### Support

Each claim is supported by the Detailed Description and the itemized list. For example, claim 1 maps to the registry, API, signing, offer publication, countersignature, lock, lifecycle, and audit log operations described throughout and summarized in itemized entries 15 and 30. Claims 2-15 are supported by passages addressing formal/informal descriptors, escrow, automated adjudication, escalation, reputation updates, human-readable linkage, evidence provenance, monitoring, agent decision functions, bulk posting, clearing-counterparty role, embedded remedy execution, external observability, and programmable escrow release. Claims 16-18 are supported by the platform component architecture and multi-tier resolution engine. Claims 19-20 are supported by the non-transitory medium and server apparatus disclosures. The Anchor section further supports structural relationships among elements.

### Broadening

Alternative implementations are expressly disclosed, including asymmetric keys or time-bounded HMAC for signing, programmable escrow or pre-authorized holds, centralized or federated offer registries, sensor-based or attestation-only monitoring, AI or deterministic rules for first-tier adjudication, and device classes for evidence provenance. These alternatives broaden claim scope while preserving core functionality.

### Continuation-Ready Itemized List

The itemized list in the Detailed Description provides explicit, suggestively worded embodiments suitable for direct use in continuations. Each independent claim and key dependent claim features has a corresponding entry, enabling future claim expansion without adding new matter.

### Claim Layering

The claim set includes independent method, system, computer-readable medium, and apparatus claims, with dependent claims capturing optional features. Additional claimable features appear in the itemized list for future continuations.

### No Unneeded Limitations

Independent claims focus on essential elements-template registry, authenticated submission, signature verification, offer publication, countersignature, contract lock and lifecycle activation, and immutable audit logging—while optional or refinable features are placed in dependent claims or reserved for continuations, reducing unnecessary restrictions.

### External Observability

Externally observable artifacts may include a publicly queryable offer registry with timestamps and unique identifiers, an immutable audit log accessible by API, and metered usage receipts. These behaviors, inputs, and outputs define verifiable interfaces for proving infringement in server-based implementations.

### Interoperability Coverage

The system may interoperate across devices, clouds, and platforms by standardizing on versioned template schemas (e.g., JSON or XML), authenticated REST-like APIs, and semantic ontologies for service classes. Agents may operate on user devices, private clouds, or third-party agent-as-a-service platforms with consistent behavior.

### Detailed Description

### Embodiment C: AI-Mediated Contract Exchange System with Standardized Templates, Autonomous Agent Execution, and Tiered Dispute Resolution

The present invention relates to an online deal making and enforcement platform that may enable autonomous agents to negotiate, execute, and monitor contracts on behalf of human users or organizations. This platform could operate as a standardized digital environment in which artificial intelligence agents, representing individuals or companies, may discover, evaluate, and engage in contractual agreements based on a shared registry of structured templates. These templates might define the general format and semantic structure of a wide range of service agreements, allowing agents to populate them with specific parameters and commit to them through cryptographic signing mechanisms. The platform could act as an intermediary to record, validate, and enforce these agreements, while providing both parties with traceable, verifiable records of the transaction.

Unless expressly stated otherwise, the scope of the invention may be defined solely by the claims. The embodiments, examples, and scenarios described herein could be illustrative and non-limiting; features described with respect to one embodiment may be combined with or substituted into others; and the order of operations in any described flow may be varied, performed in parallel, omitted, or repeated. Any figures or drawings, if present, may be exemplary. Terminology used to describe components may encompass software, hardware, firmware, or combinations thereof.

Each contract may be derived from a versioned template, which could be stored in a registry that is accessible to all agents within the system. Templates might be defined using structured formats such as JSON or XML, and could include an immutable identifier, such as a hash or certificate, to ensure auditability. Agents may fill in these templates with relevant data—such as dates, locations, prices, and other terms—and cryptographically sign the result using private keys associated with their respective owners. The resulting contract document may be submitted to the platform, where it could be posted as an active offer, visible to other agents for counter-signature. Upon mutual agreement, the platform may lock the contract and initiate the execution phase, including optional escrow deposits, service delivery triggers, and post-completion logging.

The platform could support the use of both formal and informal contract attributes. Formal fields may include quantifiable parameters such as time, quantity, price, or service class, while informal descriptors might encompass subjective or experience-based features, such as user sentiment, visual quality, or aesthetic appeal. Artificial intelligence agents might employ various models-including image classifiers, language models, or multi-modal embeddings—to interpret these informal fields and evaluate which offers best align with the user's preferences. Consequently, contract offers that are otherwise identical in structure could be prioritized differently based on inferred user behavior or historical bias, allowing for a more human-like matching process while maintaining a legal backbone that remains auditable and enforceable.

In the event of a dispute or suspected breach of contract, the system may provide a tiered resolution framework. Disputes could be flagged by either party and accompanied by supporting evidence, such as images, sensor data, or testimonials. A built-in AI adjudication system—potentially based on large language models—may evaluate the original contract, structured terms, and submitted evidence to propose a resolution. This resolution may include outcomes such as refund calculations, corrective actions, or redistribution of escrowed stakes. If the parties remain unsatisfied with the automated ruling, the case could escalate to additional review tiers. These may include peer adjudication panels drawn from a vetted human pool, extended document-based review processes, or certified arbitrators acting under applicable legal frameworks. Escalation tiers may be associated with increasing costs and timeframes, and financial penalties or rewards could be tied to the outcomes of such reviews in order to discourage frivolous appeals.

The platform may also support a variety of fairness protections to ensure trust and integrity within the system. Reputation scores for agents could be updated based on dispute outcomes, and repeated violations might result in increased fees, reduced contract visibility, or temporary bans. Contract value scaling mechanisms could allow the system to handle both micro-contracts and high-value agreements with proportional resources, enabling broad market accessibility.

Architecturally, the system could be composed of several interacting modules. These might include a registry for templates, a signing engine for instantiating contracts, a marketplace interface for offer discovery and filtering, and an agent communication protocol that allows secure, standardized message exchange. Monitoring components may track contract performance using external signals such as IoT sensors, third-party confirmations, or user feedback. Logging modules might record each stage of contract formation, fulfillment, and breach processing in a secure, immutable manner, enabling retrospective audits and compliance validation.

Anchor: Elements and core relationships. The platform may include the following elements and their relationships so that embodiments are precisely understood and consistently implemented. A template registry may store versioned machine-readable templates and identifiers that anchor correspondence to canonical human-readable clauses. An authenticated application programming interface may expose endpoints for template retrieval, offer posting, offer discovery, countersigning, escrow management, dispute filing, evidence submission, and audit log access. A signing engine may verify digital signatures on populated contract instances and validate conformance to the referenced template schema. An offer registry may maintain published offers with unique offer identifiers, immutable timestamps, and status metadata such as expiry and visibility constraints. A contract lock mechanism may bind the first two verified signatures for a given offer into a locked contract instance with a unique contract identifier and activate a lifecycle state machine. A smart escrow engine may accept deposits from parties, hold funds under programmable release conditions, and transfer funds upon fulfillment or breach determinations. A monitoring subsystem may ingest fulfillment signals from sources including IoT sensors, third-party confirmations, and user feedback to update lifecycle states or trigger evaluation. A resolution engine may implement a multi-tier dispute process beginning with an artificial intelligence adjudicator that applies embedded clauses to verified evidence and, if invoked, escalating to human peer panels or certified arbitration. An immutable audit log may record state transitions, signatures, escrow events, dispute submissions, rulings, and fund movements, producing queryable, tamper-evident artifacts. Autonomous agents acting for parties may include a first agent that populates a template into a signed offer and a second agent that verifies the offer and submits a countersignature; both may optionally submit escrow deposits. Data artifacts may include template identifiers and hashes, populated contract hashes, offer identifiers, contract identifiers, dispute case identifiers, evidence identifiers, and timestamps. Core relationships may comprise: the first agent producing and signing a populated contract that references a template version, the platform validating and publishing it as an offer, the second agent verifying and countersigning, the contract lock mechanism activating lifecycle control, the monitoring subsystem and parties generating fulfillment or breach signals, the resolution engine issuing outcomes according to embedded clauses, the escrow engine enforcing financial consequences, and the audit log persisting externally observable records accessible via the application programming interface.

The agents themselves could reside on user devices, in private cloud deployments, or on third-party platforms offering agent-as-a-service functionality. These hosted agents may include preference modeling systems, reputation filters, and adaptive negotiation modules, and could operate independently or in coordination with other agents. The platform may support these external integrations by providing well-defined APIs and semantic ontologies for service classification, ensuring that agent behavior remains consistent across implementations.

In addition to core execution capabilities, the platform may enable agents to evaluate contract offers based not only on price or terms, but also on the presence and quality of breach resolution clauses. These clauses could specify automatic remedies for specific service failures, such as partial refunds, compensatory extensions, or automated rebookings. Agents might weigh such clauses heavily when selecting among competing offers, as strong enforcement terms could signal supplier reliability. Templates may therefore incorporate standard fields for such clauses, allowing for comparison across offers and encouraging suppliers to differentiate themselves through transparent, proactive quality assurance.

The online deal making and enforcement platform described herein could thus offer a foundation for a new class of digital commerce, in which trust is embedded in code, decisions are guided by intelligent agents, and enforcement is handled in an efficient, scalable, and programmable manner. The invention may find application in domains such as travel, accommodation, transportation, utility services, freelance labor, or other sectors where service agreements are frequent, parameterized, and often subject to failure or ambiguity. Through its combination of machine-readable templates, autonomous agent execution, and multi-level dispute resolution, the system could enable a more efficient, fair, and user-aligned marketplace.

An autonomous agent may generate a contract offer by populating a standardized template with instance-specific parameters, such as time windows, price, service descriptions, and optional terms. Once complete, the agent could transmit the offer to the platform server via an authenticated API endpoint. This submission may include the agent's digital signature, the hash of the populated contract, a reference to the template version, and an optional escrow deposit amount. The server may validate the offer's structure against the registered template schema and verify the agent's signature using its associated public key. If valid, the platform could post the offer to a public or semi-public offer registry, marking it with metadata such as offer expiry, reputation requirements, and searchable tags. Other agents, operating on behalf of potential counterparties, may periodically or continuously query the server for active offers using criteria such as service type, date range, location, pricing thresholds, or embedded quality-of-service clauses.

Upon identifying a suitable offer, a receiving agent could download the contract payload and verify the integrity of its contents, including the template ID hash, parameter fields, and origin signature. If the receiving agent determines that the offer aligns with its principal's preferences, it may countersign the contract using its own private key and resubmit the now fully executed contract to the server via a designated signing endpoint. This second submission may include a mirrored escrow amount, which could be held by the platform in a secure smart escrow subsystem. The escrow logic may specify that funds are held until contract execution is verified, and could define conditions under which the escrowed value is refunded, partially released, or transferred as compensation in the event of breach.

The platform may lock the contract upon receipt of the second valid signature, preventing further modifications or acceptance by third parties. From that moment, the platform may treat the contract as active and initiate the contractual lifecycle, including triggering downstream service execution systems, monitoring fulfillment conditions, and enabling access to the dispute resolution interface.

Throughout the process, all communication and contract transitions could be logged in an immutable ledger or audit log, preserving a tamper-evident record of negotiation, signing, and escrow engagement.

This system includes software modules for template rendering, structured data ingestion, cryptographic signature verification, and AI-mediated judgment. The marketplace interfaces with agents that perform matching and selection based on real-time parameters and owner utility functions.

Templates include fallback clauses to guarantee quality-of-service remedies and automate post-incident processing. By combining traditional legal contract structures with autonomous execution and real-time arbitration layers, the system supports scalable trustless contracting at global scale.

An individual may configure their autonomous agent to secure a car rental in a specific location-such as Berlin—for a defined time window, for instance from July 1st to July 5th. The agent could access the exchange interface and query available offers that match the required date, location, and service category. The results might be filtered and ranked by criteria such as total rental cost, included fuel policy, distance to pickup location, reputation score of the provider, and informal metrics such as visual appeal or brand sentiment. Among the available options, the agent may select a mid-size sedan offered by a provider-such as AutoFast GmbH—that includes favorable reviews and an embedded breach clause stipulating a 10% refund in the event of pickup delays. Upon selecting this offer, the agent could sign the contract and submit it to the platform along with an escrow amount, for example 150 EUR. The provider's backend system, acting through its own agent, may then countersign the agreement. The platform may timestamp the completed contract, lock it, and issue a confirmation to both parties. If, upon scheduled pickup, the vehicle is delivered with a delay-such as 35 minutes—the user's agent may flag a potential breach. The platform's AI judge could assess GPS or time log data to confirm the delay and, based on the embedded clause, process a partial refund (e.g., 15 EUR) to the user, directly from escrow or via platform-mediated reimbursement.

In another scenario, a traveler may instruct their AI agent to secure a hotel room that includes a quality-of-service clause-such as a guarantee of functioning air conditioning, with a full refund and paid relocation in case of failure. Upon arrival, if the guest discovers that the air conditioning unit is inoperative, they may capture timestamped video evidence and submit a breach report via the platform interface. The AI adjudication engine could validate the evidence, match it against the original clause, and execute a remedial action-such as rebooking the guest to a nearby partner hotel and refunding the original cost, including any necessary transport charges. Should the hotel provider contest the ruling, the case may escalate to the first tier of human peer review. A randomly selected panel-such as five vetted reviewers—may be asked to evaluate the case. If, for example, four of the five reviewers uphold the AI's original determination, the platform could finalize the outcome, charge the provider for incurred costs and a nominal penalty, and apply a slight reduction to the provider's public reputation score.

In a broader, ongoing use case, an AI agent representing an expatriate user may autonomously manage a portfolio of life services, including internet subscriptions, mobile phone plans, and public transportation passes. These contracts could be negotiated, signed, and monitored without direct human intervention. The agent may regularly scan for improved offers in the background and evaluate them against current commitments. When a superior offer becomes available-such as a mobile plan with better pricing and terms—the agent might initiate a migration, provided that the termination of the current contract falls within policy allowances. In some cases, the agent may analyze the fine print using natural language processing techniques and detect clauses that are unfavorable, such as hidden roaming fees. If the risks are deemed unacceptable, the migration could be aborted preemptively. Through this continuous background process, contracts may be updated, renegotiated, or terminated with minimal user input, while the platform ensures that any required termination fees are processed appropriately and that provider behavior aligns with contractual obligations.

These scenarios illustrate how the online deal making and enforcement platform could support seamless automation, enforceability of negotiated clauses, and multi-layered fairness mechanisms, all while maintaining agent autonomy and reducing friction for end users.

The following workflow may serve as an illustrative embodiment of how the disclosed platform operates in practice, using a car rental scenario as a representative use case. While the specific domain referenced here is vehicle rental, the same structural logic could apply to other sectors such as hotel reservations, healthcare appointments, transportation bookings, or telecommunications subscriptions. The underlying process-beginning with contract offer creation and continuing through agent-based filtering, selection, digital signing, execution, validation, and potential dispute resolution—may remain constant, while the specific content of the contract templates and associated resolution logic may vary depending on the domain. For instance, a template parameter such as “vehicle type” could become “room category” in a hotel context, and breach remedies such as “rebooking” might instead imply “rescheduling” or “compensatory credit” in other sectors. This modularity may support industry-wide interoperability and adoption.

A car rental provider may configure its autonomous agent to generate and submit contract offers to the platform. Each offer may reference a specific version of a standardized rental contract template and include structured parameters such as pickup and drop-off locations, time windows, vehicle specifications including number of seats or fuel policy, pricing conditions, embedded insurance coverage, and optional breach resolution clauses. Informal descriptors-such as vehicle cleanliness, aesthetic appeal, or historical review data—may also be appended. The offer may be signed using the provider's digital key and posted to a central or federated contract exchange. Upon submission, the offer could become publicly visible and indexed according to parameters including geographic location, availability window, and categorical match to potential consumer needs.

Consumer agents, operating either locally or via cloud infrastructure, may access the platform's contract registry and scan available offers. Filtering may occur based on a combination of formal constraints, such as required seating capacity, drivetrain type, or fuel policy, and informal preferences, including subjective aesthetics, brand perception, or noise levels. The agent may use multi-criteria decision functions to score and rank offers according to the user's weighted preferences, considering factors such as supplier reputation, embedded breach terms, and estimated fulfillment reliability. Once an optimal offer is identified, the consumer agent may sign the contract digitally and transmit the completed payload to the platform, thereby locking the contract and activating it. Where applicable, both parties may be required to deposit staking or escrow funds, which are held securely until successful contract fulfillment or adjudication.

The contract execution phase may involve the renter arriving at the pickup location and performing check-in via self-service interfaces, potentially supported by digital lock mechanisms, platform-issued access codes, and real-time photographic verification of vehicle condition. During the rental period, onboard sensors-such as GPS modules, diagnostic interfaces, and visual monitoring systems—may record vehicle metrics, including odometer readings, fuel levels, and any incidents such as abrupt stops or collisions. These data streams could be used to validate return conditions and detect violations. Upon contract expiration, the vehicle may be returned to the agreed location, triggering automated condition assessment using sensor logs or user-submitted media. If all contract terms are satisfied, the system may close the contract, release the escrowed funds, and finalize the transaction. In the event of deviation-such as late return, underfilled fuel tank, or physical damage-predefined breach clauses may be invoked and resolution procedures initiated.

Should either party report a breach, the platform may allow for submission of timestamped evidence, with the counterparty receiving notification and an opportunity to respond. The AI adjudication engine, equipped with access to the contract, its parameters, signatures, and evidentiary materials, may evaluate the dispute and apply automated remedies as defined by the embedded terms. These may include refund issuance, damage penalties, or alternative service reimbursement. If a party challenges the AI's decision, the case could escalate to a higher-resolution tier, such as a randomized human jury, a peer review panel, or certified arbitrators. Escalation outcomes may include financial adjustments to staked amounts, redistribution of penalties, and updates to party reputation scores. All decisions rendered by the platform's adjudication hierarchy may be considered binding under the contract's terms, with no further recourse beyond the agreed-upon process.

The platform itself may act as a neutral enforcement intermediary, possessing authority to implement and finalize outcomes rendered by the resolution subsystem. At the time of contract engagement, users may agree that all rulings issued by the embedded resolution mechanisms-whether automated or escalated—are final and enforceable. To support financial enforcement, the platform could require staking of fiat or digital currency, dynamically calculated based on contract value or risk class. These stakes may be used to cover compensatory payments, platform fees, replacement costs, or bonuses for verified fulfillment. In some implementations, the platform may insert itself as counterparty to both contracting parties, functioning similarly to centralized financial exchanges. In doing so, it could maintain control over funds, arbitration, and execution, while optionally collecting a coordination or brokerage fee.

Contracts instantiated on the platform may be derived not only from machine-readable templates, but also from canonical human-readable versions written in natural language. These documents may resemble conventional legal contracts, containing clearly defined clauses and embedded placeholders for dynamic fields such as dates, prices, or service parameters. This dual-format architecture may ensure that contracts are simultaneously accessible to AI agents and legible to human users, legal professionals, and regulatory auditors. Templates may be rendered in formats such as JSON or XML, with each field linked to an explanatory label or reference to the original human-readable clause. This structure could allow a user's personal LLM or digital legal advisor to interpret the contract, explain its contents, and highlight potentially unfavorable terms prior to signature. The use of signed and hashed template versions may guarantee that machine-parsed instances correspond to agreed-upon textual clauses, thereby improving trust, transparency, and enforceability.

To further strengthen the evidentiary integrity of the platform, all multimedia submissions used in support of breach claims may be required to include verifiable provenance. Techniques such as hardware-level signing, timestamping, location verification, or digital watermarking could be employed to establish authenticity at the point of capture. For example, trusted camera modules or mobile devices with secure enclaves may embed tamper-resistant metadata into photos or videos submitted to the platform. These materials may be processed through platform APIs that verify origin, integrity, and timestamp validity. Evidence failing to meet established provenance criteria may be flagged as low-trust or rejected entirely, depending on the terms of the contract. This integrity layer may prevent manipulation via synthetic content, such as deepfakes, and enhance reliability in the autonomous resolution of contractual disputes.

In sum, the disclosed system may provide a full-spectrum solution for autonomous contract negotiation, fulfillment, enforcement, and resolution, offering a modular framework adaptable to a wide range of services. Through the integration of agent-mediated offer exchange, machine-readable templates anchored in human-readable legal forms, programmable dispute clauses, and provable multimedia evidence pipelines, the invention may support a new generation of fair, efficient, and self-enforcing digital agreements.

Fallback embodiments. The platform may be deployed in reduced configurations that still embody the inventive concept while omitting or simplifying optional components. In one minimal configuration, the resolution engine could operate as a single-tier deterministic rules module without escalation, applying remedial action templates directly to verified facts. In another configuration, escrow may be replaced by pre-authorized payment holds or credit offsets administered by the platform, with the same programmable release semantics expressed as authorization captures and reversals. The offer registry could be implemented as an in-memory or file-backed index with time-to-live expirations, while the immutable audit log may be realized as an append-only hash-chained file or database table producing periodic checkpoint hashes for external attestation. Cryptographic signing may be accomplished via asymmetric keys or, alternatively, via time-bounded HMAC tokens bound to agent identities and template versions, with equivalent verification semantics at the signing engine.

Monitoring of fulfillment may rely solely on attestations and counterparty confirmations rather than IoT sensor feeds, with evidentiary weight adjusted by contract terms. Agents may be implemented as lightweight rule-based scripts or scheduled jobs rather than adaptive learning systems, yet still discover, evaluate, sign, and countersign offers through the same authenticated API. These fallback embodiments could maintain externally observable behaviors, including publication of offers with timestamps, issuance of locked contract identifiers upon countersignature, exposure of audit artifacts via the application programming interface, and enforcement of embedded breach clauses, thereby preserving infringement-determinative interfaces even when internal modules are simplified.

Monetization and damages support may be provided to maximize enforceability and compensation in the event of infringement. The platform could be delivered under subscription models that may include per-seat licensing for human users or administrative operators, per-agent licensing for autonomous agents registered to a given account, tiered plans based on monthly active agents, and usage-based components metered per posted offer, per locked contract, per dispute opened, per adjudication executed, and per evidence verification call. A metering subsystem may maintain cryptographically signed usage counters for each tenant, agent identifier, and template identifier, with periodic emission of audit receipts containing timestamps, monotonically increasing sequence numbers, and hashes of counter states. These receipts could be retrievable via the application programming interface and verifiable against the immutable audit log so that an external observer may correlate account usage to publicly visible offer identifiers and contract lifecycle events. In some implementations, edge-deployed agents may periodically produce signed offline usage attestations that include counts of offers evaluated, offers posted, contracts countersigned, and platform API methods invoked, enabling reconciliation when connectivity is intermittent. Entitlement enforcement may be performed by issuance and renewal of time-bounded access tokens that encode subscription tier and feature flags, with the platform applying throttles or degradations when entitlements are exceeded. Billing exports could be generated in standardized formats consumable by third-party accounting systems and may include line items keyed to offer registry identifiers, contract identifiers, and dispute case identifiers. These observable metering artifacts and billing records may enable direct computation of avoided fees or unjust enrichment attributable to unlicensed use, thereby facilitating calculation of damages based on the number of active agents, the volume of contracts processed, or the frequency of dispute adjudications. Where the platform assumes a clearing-counterparty role, fee schedules may include per-transaction coordination fees and escrow management fees that are deterministically tied to contract value, with the same metering primitives providing verifiable evidence of fee-bearing events for damages estimation.

Workaround resistance. The disclosed architecture may be described in terms of infringement-determinative behaviors rather than particular interfaces so that superficial modifications do not avoid the claimed methods. Implementations that perform the following externally observable invariants could still fall within scope: using a versioned schema or functional equivalent to define a contract instance; authenticating and submitting a signed instance from a first party; making that instance discoverable to a second party by any dissemination mechanism including centralized posting, peer-to-peer broadcast, or direct push; accepting the instance by a second party through a cryptographic act or equivalent authenticated acceptance; transitioning the instance into a locked state that prevents conflicting acceptance; enforcing a lifecycle with programmable financial consequences; and persisting tamper-evident records of state transitions. Variants may include peer-to-peer exchanges without a central offer registry, alternatives to dual-sign workflows such as authenticated acceptance receipts or payment-token acknowledgments, threshold or N-of-M multi-party signatures, escrow substitutes including insurance-backed guarantees, letters of credit, or pre-authorization holds, and audit logging realized via off-platform append-only journals periodically anchored to a public attestor. These alternative implementations may preserve the same externally observable inputs and outputs described herein and could therefore be detected and proven by third parties through registry queries, receipt verification, and audit artifact inspection.

The embodiment can be described by the following itemized list, illustrating various aspects and configurations of the system in suggestive terms: 1. A method may be provided for autonomous agent-mediated contract execution, wherein a marketplace may receive a plurality of standardized contract templates, each template potentially being selected and populated by a first AI agent with contract-specific parameters. The resulting contract could then be cryptographically signed by the initiating agent and posted to either a centralized or decentralized contract exchange. A second AI agent may discover and evaluate the signed contract and, upon alignment with internal criteria, may countersign the contract. The platform could then lock the contract upon receipt of the first valid counter-signature and initiate execution of the underlying service as described in the agreed terms. 2. The method described above may support the inclusion of both formal descriptors-such as time, price, or location—and informal descriptors, which could encompass aesthetic qualities, sentiment-based evaluations, or user-generated content. 3. The method may further comprise an automated dispute resolution process, potentially implemented through a multi-tier system in which initial evaluation is performed by an AI model and higher tiers involve human or hybrid review mechanisms. 4. In some embodiments, the informal descriptors referenced above may specifically include visual attributes, such as color schemes or perceived cleanliness, and sentiment indicators derived from textual reviews or machine-generated scores. 5. The multi-tier dispute resolution system may include a first escalation tier comprising a randomly selected panel of reviewers-such as a microjury of five vetted individuals-who may receive anonymized dispute summaries and render a verdict within a predetermined timeframe. 6. The platform's enforcement logic may be configured to apply progressively increasing penalties for repeated violations by a given party, wherein the scaling of such penalties could be exponential or otherwise non-linear in nature. 7. An AI contract exchange platform may comprise a registry of versioned contract templates accessible to autonomous agents, an API interface enabling structured querying and posting of contract offers, a smart escrow engine for holding pre-execution stakes from participating parties, a subsystem for detecting potential contract breaches, a resolution engine incorporating a large language model or equivalent system for arbitration, and a contract lock mechanism that may bind and timestamp the first two signatures received for any given agreement. 8. The platform described above may support the inclusion of breach resolution clauses directly within posted contract templates, wherein such clauses could be automatically parsed and enforced by the system without requiring human intervention. 9. Agents interacting with the platform may maintain internal scoring or heuristic models that evolve based on historical case outcomes, user preferences, or contextual factors, allowing for adaptive contract evaluation and offer selection. 10. A supplier-side method may allow for the bulk posting of pre-signed contract offers using parameterized templates, such that user agents could select and countersign appropriate offers without further negotiation or delay. 11. A user-side method may allow an AI agent to evaluate available offers by applying utility heuristics defined by the user, wherein both formal parameters (such as cost or timing) and informal descriptors (such as sentiment or brand perception) may be factored into the agent's decision function. 12. A method may be employed whereby human reviewers assigned to the first escalation tier are presented with anonymized, contextually relevant dispute data and are required to issue a verdict within a defined temporal window, such as six hours. 13. A further method may include dynamic integration of breach or dispute histories into a cumulative trust score associated with each supplier, wherein such scores may influence visibility of future offers and determine required stake amounts for posting. 14. A method may be implemented in which the platform itself assumes the role of counterparty to both contract signatories, thereby acting as a centralized clearing authority, analogous to mechanisms employed in traditional financial markets such as stock or options exchanges, and providing guarantees of enforcement and finality. 15. An embodiment may include maintaining a registry of versioned machine-readable contract templates; receiving from a first autonomous agent a signed populated contract instance that references a template version via an authenticated application programming interface; validating the instance against the referenced template and verifying the signature; publishing the instance as an offer; receiving a countersignature from a second autonomous agent; locking the contract upon verification; activating a lifecycle; and recording state transitions in an immutable audit log. 16. An embodiment may include templates that comprise formal quantifiable descriptors and informal subjective descriptors, with at least one model interpreting informal descriptors into scores used for offer discovery and ranking by agents. 17. An embodiment may include receiving, with a countersignature, a mirrored escrow deposit from at least one party and storing the deposit in a smart escrow subsystem configured with programmable release conditions. 18. An embodiment may include automated adjudication of a reported breach using an artificial intelligence model that applies contract terms to submitted evidence before any escalation occurs. 19. An embodiment may include escalation of disputes by submitting an anonymized dispute summary to a randomly selected peer panel constrained to issue a verdict within a defined timeframe. 20. An embodiment may include updating a reputation score of at least one party based on outcomes and applying non-linear penalty scaling for repeated violations. 21. An embodiment may include linking each contract instance's machine-readable fields to a canonical human-readable clause set, with a hash anchoring correspondence between the two representations. 22. An embodiment may include requiring multimedia evidence to include device-originated cryptographic signatures, timestamps, and location metadata; verifying such provenance; and flagging or rejecting evidence that fails verification pursuant to contract terms. 23. An embodiment may include monitoring fulfillment conditions by ingesting signals from sources including IoT sensors, third-party confirmations, and user feedback. 24. An embodiment may include agent selection of offers using a multi-criteria decision function that combines formal and informal attributes weighted by user-defined heuristics. 25. An embodiment may include supplier-side bulk posting of pre-signed parameterized offers for selection and countersignature without additional negotiation. 26. An embodiment may include the platform assuming a clearing-counterparty role with respect to both signatories to ensure enforcement and financial finality. 27. An embodiment may include embedding breach resolution clauses in templates and automatically parsing and executing such clauses to issue remedies including partial refunds, compensatory extensions, or automated rebookings. 28. An embodiment may include exposing externally observable interfaces comprising a publicly queryable offer registry with timestamps and unique identifiers, and an immutable audit log accessible via the application programming interface. 29. An embodiment may include programmable release conditions for escrow comprising full release on verified fulfillment, partial release, or compensatory transfer upon a determined breach in accordance with embedded clauses. 30. An embodiment may include a contract exchange platform with a template registry storing versioned templates, an application programming interface for structured querying and posting of offers, a signing engine for cryptographic verification, a marketplace interface for discovery and filtering, a smart escrow engine, a monitoring subsystem for fulfillment validation, a resolution engine including an artificial intelligence adjudicator, a contract lock mechanism to bind and timestamp signatures, and an immutable audit log, wherein the components operate to perform the previously described method. 31. An embodiment may include a resolution engine that implements a multi-tier dispute framework comprising an artificial intelligence first tier and at least one higher tier selected from a human peer panel and certified arbitration. 32. An embodiment may include an artificial intelligence adjudicator comprising a large language model configured with contract schemas, evidence provenance policies, and remedial action templates. 33. An embodiment may include a non-transitory computer-readable medium storing instructions that, when executed by one or more processors of a server platform, cause performance of the disclosed method for AI-mediated contract exchange. 34. An embodiment may include a server apparatus configured as a neutral enforcement intermediary and optionally as counterparty, comprising processors, memory, and network interfaces and being configured to manage staking of fiat or digital currency, apply rulings rendered by the resolution engine, and control fund transfers according to a locked contract state. 35. An embodiment may include disseminating offers without a centralized offer registry by broadcasting signed populated contract instances over a peer-to-peer overlay or distributed hash table, while maintaining unique offer identifiers and discovery metadata sufficient for countersignature and later audit. 36. An embodiment may include treating an authenticated acceptance receipt, payment-token signature, or other cryptographically verifiable acknowledgment by a second party as a countersignature event that triggers contract locking and lifecycle activation. 37. An embodiment may include multi-party or group contracts in which an offer is locked upon reaching an N-of-M threshold of authenticated acceptances or signatures, after which the lifecycle state machine applies to all signatories. 38. An embodiment may include substituting escrow with financial instruments comprising insurance-backed guarantees, letters of credit, collateralized accounts, or pre-authorization holds, while preserving programmable release or drawdown semantics tied to lifecycle and resolution outcomes. 39. An embodiment may include persisting audit records in off-platform append-only journals that periodically emit checkpoint hashes to a public attestor or notary service, thereby achieving tamper-evidence without requiring a single centralized audit store. 40. An embodiment may include settling funds through third-party processors or bank instructions while the platform retains lifecycle control, dispute adjudication, and issuance of cryptographic receipts that reference contract and event identifiers. 41. An embodiment may include operating with pseudonymous identities bound to non-transferable keys, optional attestation of KYC or compliance attributes, and the same signature verification and lifecycle semantics as for identified parties. 42. An embodiment may include streaming contracts that lock in rolling windows or tranches, with incremental fulfillment verification and proportional escrow releases or compensatory transfers scheduled by the lifecycle state machine.

In practice it is preferred to implement the Contract Exchange system to replace conventional paper-based agreements with machine-readable digital contracts, which leads to the elimination of physical printing, mailing, and archiving and thereby reduces resource consumption. More specifically, the system applies cryptographic signatures, timestamps, and standardized templates to produce contracts that can be verified automatically and remotely, which results in a measurable technical improvement in the security and reliability of the contracting process. Because the agreements are confirmed digitally, uncertainty, fraud risk, and disputes are minimized, which in turn prevents the need for redundant manual verification or in-person execution of contracts. This has the further effect of reducing unnecessary travel associated with securing rentals, reservations, or other agreements, since users can rely on the remote verification to ensure that a vehicle, room, or service will be delivered as agreed. The system therefore yields multiple technical effects, including reduced processor overhead for contract validation, improved data integrity through cryptographic controls, and reduced reliance on physical and transportation resources. Since both paper production and fuel consumption correlate directly with carbon dioxide emissions, the Contract_Exchange platform indirectly reduces the carbon footprint associated with contract execution while simultaneously improving the security, efficiency, and reliability of digital contracting.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

An item describes a computer-implemented method for AI-mediated contract exchange, comprising: maintaining a registry of versioned machine-readable contract templates; receiving, via an authenticated application programming interface, from a first autonomous agent an authenticated acceptance artifact comprising a cryptographic signature or a time-bounded message authentication code on a populated contract instance that references a template version; validating the populated contract instance against the referenced template and verifying the acceptance artifact using a corresponding verification key or shared secret; publishing the populated contract instance as an offer via a dissemination mechanism comprising at least one of an offer registry, peer-to-peer broadcast, or direct push; receiving from a second autonomous agent a countersignature or authenticated acceptance receipt for the offer; in response to verifying the second agent's acceptance, transitioning the contract into a locked state that prevents conflicting acceptances and activating a contract lifecycle; and recording, in an immutable audit log, state transitions associated with contract formation and execution.

The item of item 1, wherein the templates include both formal descriptors comprising quantifiable parameters and informal descriptors comprising subjective attributes, and wherein at least one model interprets informal descriptors into scores used by agents for offer discovery and ranking.

The item of item 1, further comprising receiving, with the countersignature, a mirrored escrow deposit from at least one party and storing the deposit in a smart escrow subsystem configured with programmable release conditions.

The item of item 1, further comprising performing automated adjudication of a reported breach using an artificial intelligence model that applies the contract terms to submitted evidence prior to any escalation.

The item of item 4, wherein escalation comprises submission of an anonymized dispute summary to a randomly selected peer panel constrained to issue a verdict within a defined timeframe.

The item of item 1, further comprising updating a reputation score of at least one party based on outcomes and applying non-linear penalty scaling for repeated violations.

The item of item 1, wherein each contract instance links machine-readable fields to a canonical human-readable clause set and a hash anchors correspondence between the two representations.

The item of item 1, wherein multimedia evidence submitted in support of a breach includes device-originated cryptographic signatures, timestamps, and location metadata that are verified by the platform, and evidence failing verification is flagged or rejected pursuant to contract terms.

The item of item 1, further comprising monitoring fulfillment conditions by ingesting signals from one or more sources selected from the group consisting of IoT sensors, third-party confirmations, and user feedback.

The item of item 1, wherein agent selection of offers uses a multi-criteria decision function that combines formal and informal attributes weighted by user-defined heuristics.

The item of item 1, further comprising supplier-side bulk posting of pre-signed parameterized offers for selection and countersignature without further negotiation.

The item of item 1, further comprising the platform assuming a clearing-counterparty role with respect to both signatories to ensure enforcement and financial finality.

The item of item 1, wherein breach resolution clauses embedded in the template are automatically parsed and executed to issue remedies including at least one of partial refunds, compensatory extensions, or automated rebookings.

The item of item 1, wherein the platform exposes externally observable interfaces including a publicly queryable offer registry with timestamps and unique identifiers, and an immutable audit log accessible via the application programming interface.

The item of item 3, wherein the programmable release conditions include full release on verified fulfillment, partial release, or compensatory transfer upon a determined breach in accordance with embedded clauses.

An item describes a contract exchange platform comprising: a template registry storing versioned templates; an application programming interface for structured querying and posting of offers; a signing engine for cryptographic verification of agent signatures; a marketplace interface for discovery and filtering of offers; a smart escrow engine for holding stakes; a monitoring subsystem for fulfillment validation; a resolution engine including an artificial intelligence adjudicator; a contract lock mechanism to bind and timestamp signatures; and an immutable audit log, wherein the components are operable to perform the operations of item 1.

The item of item 16, wherein the resolution engine implements a multi-tier dispute framework comprising an artificial intelligence first tier and at least one higher tier selected from a human peer panel and certified arbitration.

The item of item 16, wherein the artificial intelligence adjudicator comprises a large language model configured with one or more of contract schemas, evidence provenance policies, and remedial action templates.

An item describes a non-transitory computer-readable medium storing instructions that, when executed by one or more processors of a server platform, cause the server platform to perform the method of item 1.

An item describes a server apparatus configured as a neutral enforcement intermediary and optionally as counterparty, the apparatus comprising processors, memory, and network interfaces and being configured to manage staking of fiat or digital currency, apply rulings rendered by the resolution engine, and control fund transfers according to a locked contract state.

### Embodiment DE: System and Method for Collective Grievance Discovery and AI-Mediated Reputation Analysis

Disclosed are systems and methods that may enable collective grievance discovery and AI-mediated reputation analysis. Users or their AI agents may submit complaints in structured or unstructured form, after which a similarity engine could identify related complaints, propose groupings, and coordinate secure communications upon consent. A trust engine may compute reputation scores for service providers using aggregated complaints, resolution signals, and source reliability. Implementations may include privacy-preserving matching, interoperability across platforms, monetization with verifiable usage receipts, and externally observable outputs to enable independent verification.

Gentle introduction. Many people experience the same problem with a service provider but may not realize others are in the same situation or how to coordinate a response. The invention could act as a consent-first, privacy-aware discovery and coordination layer. In simple terms, a person or their AI agent may tell the system what happened; the system could find others who reported materially similar events; it may ask each participant for permission before connecting them; and, if permitted, it may create a shared handle that functions like a case tag for the group and open a secure space for communication and evidence exchange. Verified legal professionals could be invited by the group when helpful, and users may remain pseudonymous until they agree otherwise. In parallel, a reputation component may summarize how reliable a provider appears to be, based on how often complaints occur, whether they were resolved, and how trustworthy the sources seem. The platform may work with familiar channels such as email, messaging, and web APIs so that people and agents can participate without changing their tools. It may also emit clear external signals such as group identifiers, cluster notifications, and signed usage receipts so that third parties could verify that the system operated as claimed without seeing internal code. This intuitive overview is non-limiting and the formal embodiments, flows, and claims described below may control.

Examples. The following concrete scenarios illustrate how embodiments may operate step by step in real-world conditions. In an airline cancellation scenario, a traveler may submit an unstructured narrative such as a description of a canceled flight and denied refund through email or a web form. The ingestion interface may normalize the message and the feature extractor may derive embeddings and metadata including airline, route, date, and refund status. The similarity engine may compare these features to a corpus and detect multiple near-duplicate or closely related complaints within a rolling window. When a similarity threshold or quorum condition is satisfied, the cluster manager may allocate a new group identifier, while the consent manager may send prompts to each affected user or their AI agent requesting permission to share limited details and to Join a coordination space. Upon receipt of consent, the coordination module may instantiate a secure channel, maintain pseudonymity through the pseudonymity manager, and enable exchange of boarding passes, emails, and receipts. If the group later opts in, the legal coordination interface may admit a verified attorney who may post proposed next steps. The audit logger may generate signed receipts for each operation and the trust engine may update the airline's reputation score based on the unresolved cluster, with externally observable outputs including the group identifier and a cluster notification emitted to subscribed agents.

In a property co-owner fee increase scenario, a co-owner may submit a structured complaint with fields such as property identifier, management company, invoice deltas, and dates. The system may extract features, compute similarity, and discover a pattern of fee increases across units. The cluster manager may propose a group identifier and the consent manager may request per-complaint permission for disclosure and outreach. After consent, the coordination module may open a space for sharing invoices and management correspondence. A verified legal professional may be invited only after a user-defined quorum is reached. Where privacy sensitivity is high, the privacy-preserving matcher may execute within a trusted execution environment so that plaintext complaint bodies are not accessible to operators, while still producing a proof that a complaint belongs to the cluster. The system may emit signed audit records and notify user agents that a cluster has formed, enabling independent verification without revealing confidential content.

In a fallback, low-footprint deployment for workplace scheduling disputes, an edge software development kit may perform approximate similarity on-device and transmit only a hashed handle and consented metadata to the server. The server may assign a group identifier and send email notifications indicating group inclusion, without creating a hosted chat or admitting legal professionals. Users may coordinate via a third-party mailing list referenced by the handle. Despite the limited configuration, externally observable signals such as the group identifier and signed usage receipts may be available, and the trust engine may be disabled by policy in this minimal mode.

In an MCP-enabled software embodiment using the Model Context Protocol, personal or organizational agents may invoke tools exposed by the platform such as submitComplaint, getClusterUpdates, and emitSignedReceipt. An agent could submit a complaint as a JSON payload over MCP transport with a consent policy, for example

{“type”:“complaint”,“tenant”:“acme-co”,“complaintId”:“c-9f3a”,“user”:“u-2a1”,“provider”:“AirlineX”
,“timestamp”:“2025-04-12T10:03:11Z”,“body”:“Flight AX123 cancelled; refund
denied”,“metadata”:{“route”:“SFO-JFK”,“flight”:“AX123”,“travelDate”:“2025-04-10”},“consent”:{“
match”:true,“notify”:true,“shareDetails”:“handle-only”,“legalOutreach”:{“mode”:“quorum”,“min”:5}}
}. Upon similarity detection and quorum satisfaction, the platform could emit an MCP event to
subscribed agents, for example
{“type”:“cluster-notice”,“groupId”:“g-b471”,“tenant”:“acme-co”,“matchedComplaints”:[“c-9f3a”,“c-7
d21”,“c-5ab0”],“pseudonymous”:true,“joinUrl”:“https://coord.example/g-b471”,“quorum”:5,“member
s”:7}. When billable operations occur, an MCP tool invocation may return a signed usage receipt
suitable for independent verification, for example
{“type”:“usage-receipt”,“tenant”:“acme-co”,“event”:“cluster-formed”,“groupId”:“g-b471”,“ts”:“2025-0
4-12T10:05:26Z”,“counter”:102334,“sig”:“ed25519:8f1a2c...”}.

Background Individuals experiencing service failures or unfair practices often lack visibility into whether others share the same grievance. Conventional review platforms may emphasize subjective ratings and anecdotal narratives without structured discovery, consent-aware coordination, or legal-readiness. Existing complaint portals may not provide clustering of similar incidents, secure group formation, or AI-mediated reputation analysis that accounts for conflict-of-interest and resolution quality. There is a need for a technological framework that could discover latent group harms, coordinate redress among affected parties, and inform future decisions with defensible reputation signals.

Summary In certain embodiments, a complaint ingestion interface may receive structured or unstructured inputs, a similarity engine may detect related complaints and create a group identifier upon a threshold or quorum, and a consent manager may gate disclosure and coordination. A coordination module may establish secure communication channels with optional pseudonymity, while a legal coordination interface may admit verified professionals to assist with representation. A trust engine may compute service provider reputation scores from aggregated complaints with bias calibration and conflict detection. Implementations may include centralized or decentralized deployments, privacy-preserving matching, interoperability adapters, tamper-evident audit logging, and monetization through metered gateways and billing integrations.

Description of the drawings Figures are not required for understanding; however, figures may be provided in related filings to depict architectures and flows corresponding to the Anchor section. The Anchor section herein enumerates elements and core relationships suitable for mapping to figure references without altering the scope of the embodiments.

### Detailed Description

### Embodiment D: System and Method for Collective Grievance Discovery and AI-Mediated Reputation Analysis

Scope and interpretation. The scope of protection may be limited only by the claims. Any figures, examples, and described sequences are provided as illustrative, non-limiting embodiments, and operations may be reordered, performed in parallel, omitted, or substituted by functionally equivalent steps unless expressly stated otherwise. Components may be implemented in hardware, software, firmware, or any combination thereof, locally or remotely, and references to singular elements may encompass one or more instances unless context dictates otherwise. For purposes of determining infringement, implementations that achieve the same externally observable behaviors under materially similar conditions may be considered within the scope even where internal algorithms, data representations, or deployment topologies differ, including substitutions that are functionally equivalent to the described elements.

Definitions and construction. As used herein, complaint denotes a machine-ingestible message or record describing a purported harm or service failure, including but not limited to email bodies, web-form submissions, uploaded documents, or agent-to-agent protocol payloads, together with associated metadata. Consent denotes a persistently stored policy object cryptographically bound to a complaint record and to a user or agent identity, specifying permitted disclosures and coordination actions and enforceable by the consent manager. Group identifier denotes any alias, token, tag, handle, or cryptographically signed reference that co-references a set of related complaints and that may be verified by third parties; examples include random 128-bit identifiers, UUIDs, content-addressed hashes, or JSON Web Signatures encapsulating a handle and metadata. Configured to denotes structural or code-level configuration, whether in firmware, software instructions, or hardware logic, that causes the recited component to perform the specified operation when executed. Secure communication channel denotes a transport with encryption and peer authentication such as Transport Layer Security version 1.3 with mutual authentication or equivalent. Tamper-evident ledger denotes an append-only, hash-chained event store with periodic checkpointing to an external notary or timestamp authority, enabling detection of deletion or reordering. Privacy-preserving matcher denotes a component that performs similarity computations within a trusted execution environment or produces a zero-knowledge proof that a complaint belongs to a cluster without exposing underlying complaint content. Communication channel denotes any mechanism by which messages, notifications, invitations, or references are caused to be exchanged among members of a group, including but not limited to hosted chat, email threads, listservs, bulletin-board threads, webhook fan-out to user agents, or the issuance of a shared handle or link that deterministically or programmatically instantiates or addresses such messaging facilities on third-party platforms. Sharing contact or complaint details encompasses any action that enables parties to discover, address, or reach each other or their submissions, including notifying a user that others exist under a shared handle, delivering invitations, or posting or emitting identifiers that permit addressing or retrieval of group-related content, irrespective of whether raw personal identifiers are disclosed. Similarity engine denotes any automated, semi-automated, or human-in-the-loop mechanism configured to determine relatedness among complaints, including learned models, rule-based pipelines, deterministic lookups, crowdsourced or moderator adjudication assisted by system-provided features, and combinations thereof executed on client, edge, server, or third-party services.

The present invention relates to systems and methods that could facilitate the discovery of shared grievances and the analysis of service provider reputations using artificial intelligence. It may provide a technological framework whereby individuals or their AI agents could submit complaints in structured or natural language form, allowing the system to identify similar reports, match affected parties, and enable coordination among them. This coordination may lead to class action efforts, group refunds, or other forms of collective remedy, possibly supported by participating legal professionals or NGOs. The invention could further incorporate reputation scoring functionality, enabling AI agents to proactively assess service provider reliability prior to future engagements.

In one embodiment, a user or their AI agent may initiate the process by submitting a complaint via a portal or agent interface. This submission may include structured metadata such as location, timestamp, service provider identity, and grievance type, along with optional documentation such as invoices, contracts, or correspondence. The system may also support unstructured entries, which could be interpreted by a language model trained to extract meaningful features for downstream analysis.

Consent settings may be configurable at the time of submission, specifying conditions under which the complaint may be matched, shared, or escalated.

A discovery engine may then evaluate complaint similarity, using natural language embeddings or metadata analysis to identify latent correlations. The architecture for this discovery process could be either centralized or distributed, depending on performance and privacy requirements. Once a sufficient number of comparable complaints are detected, the system may generate a proposed group cluster, assigning a unique identifier and optionally creating a secure collaboration link. The AI agent representing each user may prompt for additional consent before initiating contact with other affected individuals or their respective agents.

Upon user approval, secure channels may be opened for communication among participants, allowing the exchange of documents, messages, or strategy proposals. The system may maintain audit trails and allow optional pseudonymity to protect user identity until stronger trust is established. Legal professionals may gain access to group identifiers upon satisfying criteria such as verified identity or bar association registration. They may then offer representation under terms defined by the users or propose pathways toward collective redress. Legal coordination may occur through a dedicated interface that could support evidence review, document submission, or offer negotiation functionalities.

An embedded trust engine may assess the reputation of implicated service providers by aggregating complaint frequency, severity, resolution quality, and the reliability of sources. This score may then be queried by personal AI agents seeking to evaluate the risk of engaging with a given service. Reputation data may be weighted based on potential conflicts of interest, which could be inferred from known affiliations, shared financial interests, or network ties. The system may allow users to set thresholds for sensitivity to bias, ensuring that recommendations reflect personalized trust calibration.

In an exemplary flow, the system may accept a complaint, normalize it, and match it to similar entries. Upon identifying peers, it may seek consent for group inclusion, generate a shared session or group ID, and notify legal entities once a predefined quorum is reached. Coordination may continue via secure communication channels, allowing for efficient organization and potential escalation into formal legal actions.

In one use case, a property co-owner may submit a complaint concerning unilateral fee increases. Their AI agent could detect that multiple owners have experienced the same issue, prompting a coordinated objection to the property manager. In another case, travelers affected by an airline cancellation may be matched by their respective agents, allowing evidence sharing and legal coordination for compensation claims. A third scenario may involve repeated complaints against a rental agency, triggering early warnings to future users and facilitating the pursuit of refunds by past victims.

The system could be implemented on conventional server infrastructure or via decentralized networks. Blockchain-based variants may offer tamper-proof audit logs, while zero-knowledge proofs could provide privacy-preserving peer discovery. Digital wallets may enable users to contribute funds toward group legal actions or hold escrowed compensation. Integration with civic databases, property registries, or bar association APIs may enhance identity verification, legitimacy, and access to formal recourse.

Software components may include a non-transitory computer-readable medium storing instructions executable by a processor to carry out key functionalities. These may comprise complaint ingestion and classification, peer matching based on content similarity, consent-based information sharing, group ID generation, communication orchestration among AI agents, and service reputation computation. AI coordination modules may further support visualization, multilingual support, automated conflict detection, and legal simulation tools to preview potential outcomes.

The system may offer advantages over prior art by uncovering latent group grievances that might otherwise remain unresolved. Unlike typical review platforms, it could leverage structured discovery, context weighting, and verified data pipelines to deliver higher trustworthiness and legal utility. It may empower users with proactive defenses against unreliable providers, strengthen the possibility of organized redress, and support transparent interactions through AI-enhanced trust mechanisms.

Future enhancements may include real-time alerts when new complaint clusters form, integration with civic notification systems, or gamified incentives to encourage complaint submission. Early dispute resolution modules could mediate settlements before escalation, reducing legal burden and improving user experience. The system may continue evolving to cover new domains such as medical malpractice, environmental harm, or workplace disputes.

By enabling collective intelligence and secure AI coordination, the invention may restore power to isolated individuals facing systemic issues. Through structured discovery, informed consent, and legal coordination, it could help ensure transparency, accountability, and fair treatment across a wide range of service interactions.

Anchor: elements and core relationships. For clarity across embodiments, element names and their interactions may be understood as follows. An ingestion interface may receive complaint payloads and pass them to a feature extractor that could produce embeddings and metadata consumed by a similarity engine. When a similarity threshold or quorum is satisfied, a cluster manager may allocate or update a group identifier that represents a set of related complaints. A consent manager may gate notifications, disclosure, and group formation so that contact or complaint details are shared only under the recorded policies. When consent is satisfied, a coordination module may establish a secure communication channel and maintain pseudonymity through a pseudonymity manager until further consent authorizes identity disclosure. A legal coordination interface may be exposed to verified legal professionals via an identity verification component linked to professional registries. A trust engine may compute a reputation score for service providers from aggregated complaints and resolution signals, weighting contributions using a conflict-of-interest detector and a user-configurable bias calibrator before making the score available to user agents. An audit logger may generate cryptographically signed receipts and append events to a tamper-evident ledger through a metered gateway and a billing integration that could also compute periodic charges. Interoperability adapters may provide connectivity to REST application programming interfaces, messaging protocols, email, short message service, and external registries and databases. A privacy-preserving matcher may execute similarity operations within trusted execution environments or produce zero-knowledge proofs of match membership. A deployment fabric may host modules on centralized servers or decentralized networks, and a digital wallet or escrow component may hold prepaid credits and compensation for legal coordination. A fallback embodiment may comprise only the ingestion interface, similarity engine, consent manager, group identifier allocation, and external notifications to inform users of group inclusion without legal coordination or reputation scoring. Externally observable outputs may include the group identifier, cluster formation notifications, reputation scores, and signed audit records that together enable independent verification of operation.

Enablement. The invention may be enabled as follows. A processor-executable software stack could be deployed on a server or decentralized network to instantiate the ingestion interface, feature extractor, similarity engine, cluster manager, consent manager, coordination module, legal coordination interface, and trust engine as described in the Detailed description and Anchor. A skilled person could implement feature extraction using sentence-transformer embeddings or equivalent models trained on complaint corpora; similarity could be computed with cosine similarity or approximate nearest neighbor indexes; thresholds or quorum policies may be stored per tenant and adjusted dynamically as described herein. Consent workflows may be implemented using policy objects linked to complaint records, and secure channels may be established using transport layer security and authenticated user or agent identities. Audit logging may be configured to cryptographically sign events and append them to a hash-chained ledger. Interoperability adapters may be implemented as REST endpoints, email gateways, short message service connectors, and registry API clients. Privacy-preserving matching may be implemented within trusted execution environments or with zero-knowledge protocols that reveal match membership proofs without exposing underlying complaint content. In MCP-enabled deployments using the Model Context Protocol, the ingestion interface and eventing may be exposed as MCP tools such as submitComplaint, getClusterUpdates, and emitSignedReceipt, with tool schemas corresponding to the JSON complaint, cluster-notice, and usage-receipt examples disclosed in the Examples section; a practitioner could implement these tools over MCP transport to carry complaint payloads and to return signed receipts while preserving the consent and privacy controls described herein. MCP usage is optional and functionally equivalent interfaces may be provided via RPCs, webhooks, or message queues without departing from the described embodiments. These steps provide sufficient detail for a practitioner to implement the system without undue experimentation. In preferred configurations, embeddings may be derived from compact transformer models such as all-MiniLM-L6-v2 or e5 variants quantized for latency, approximate nearest neighbor search may be served by a hierarchical navigable small world index with parameters such as M in a range of 12 to 24 and efConstruction in a range of 100 to 400 with efSearch tuned per latency budget, and streaming updates may be applied using background maintenance threads that preserve index recall targets. Trusted execution environments may include Intel Software Guard Extensions or AMD Secure Encrypted Virtualization with attestation over remote APIs, while zero-knowledge match membership may be proved using succinct non-interactive arguments such as Groth16 over commitments to bucketed embeddings hashed with collision-resistant functions. Signed receipts may be produced using Ed25519 or equivalent digital signature schemes with RFC 3339 timestamps, and the append-only ledger may compute rolling Merkle roots periodically anchored to an RFC 3161-compliant timestamp authority or public blockchain for independent verification. Identity verification for legal professionals may rely on verifiable credentials or OpenID Connect-backed attestations from bar association registries. These concrete choices are illustrative and do not limit the scope.

Technical effects. The described architectures may produce technical effects including reduction of search complexity in complaint matching via learned embeddings and ANN indexes, increased data integrity and non-repudiation through cryptographically signed ledgers, improved privacy through TEEs or zero-knowledge proofs for similarity operations, lower coordination latency by automated consent-gated channel establishment, and enhanced decision support via conflict-aware reputation scoring with user-specific bias calibration. As compared to baseline keyword search with exhaustive pairwise comparisons, the disclosed approximate nearest neighbor pipeline may reduce matching time from quadratic to near sublinear behavior in practice with bounded recall loss, delivering lower latency and lower compute cost at scale. Executing similarity within trusted execution environments or proving cluster membership without revealing complaint content may materially reduce the attack surface for data exfiltration while preserving verifiability. The combination of signed group identifiers, append-only hash chains, and external timestamp anchoring may yield auditable artifacts suitable for evidentiary use without reliance on internal source code. The claimed combinations may improve computer functionality itself by introducing specific data structures and cryptographic protocols that reduce computational complexity, increase integrity, and enforce consent and policy at machine boundaries, including hierarchical navigable small world indexes with bounded-recall tuning, remotely attested trusted execution environments, and Ed25519-signed, Merkle-batched ledgers anchored to external timestamp authorities.

Flows. Process flows are disclosed in the Detailed description and further include receiving a complaint, normalizing and extracting features, computing similarity against a corpus, forming a cluster upon threshold or quorum, soliciting consent, establishing secure communications among matched participants, optionally onboarding verified legal professionals, and computing and serving reputation scores. These flows could be directly translated into flowcharts and support the method claims.

Support. Each claim is supported by the Detailed description, the Anchor, and the itemized list. For example, claims 1-7 are supported by the ingestion, similarity, consent, coordination, pseudonymity, and verified legal access disclosures; claims 8-9 by the trust engine and bias calibration; claims 10-12 by the method flows and privacy-preserving matching; claims 13-14 and 20 by the non-transitory medium instructions including dynamic threshold adjustment and signed audit logs; claims 15-16 by the monetization architecture; claim 17 by the externally observable outputs; claims 18-19 by interoperability adapters and fallback configuration.

Broadening. Alternative implementations are expressly contemplated, including centralized or decentralized deployments, different embedding models and similarity metrics, threshold or quorum-based clustering, various consent policy schemes, multiple secure communication protocols, and interchangeable primitives for auditability and privacy. Interoperability adapters may target diverse protocols and registries so that interface changes do not avoid the scope. Anti-evasion coverage may further include implementations that determine relatedness using any of supervised, unsupervised, or rule-based techniques; that operate in real time, near real time, or batch mode; that execute fully client-side, edge-based, serverless, federated, or centralized; and that coordinate participants via any of asynchronous or synchronous mechanisms including group email threads, listservs, bulletin boards, shared documents, webhook fan-out, on-chain messaging, or third-party chat rooms. Consent enforcement may be achieved by any policy engine capable of gating disclosure and coordination, and pseudonymity may be preserved using cryptographic techniques including blind signatures, threshold credentials, or unlinkable identifiers. Implementations that substitute functionally equivalent data structures, tokens, or handles for the group identifier while maintaining co-reference of a set of related complaints may still be considered within the described embodiments. Implementations that establish coordination by emitting artifacts that cause third-party or user-agent-created threads to form, or that route notifications among group members, may be considered to establish a communication channel within the described embodiments. Architectures that determine relatedness via human moderation workflows, crowdsourcing, or deterministic policy engines are within scope of the similarity engine alternatives. Consent enforcement may encompass gating of any outreach, invitation, or notification that would reveal group membership, even absent disclosure of personal identifiers or complaint bodies.

Continuation-ready. Embodiments are described in an itemized list suitable for continuation filings. The list, together with the Detailed description and Anchor, may provide direct support for future claims that recast systems as methods, media, or apparatus and that combine or separate features such as pseudonymity, verified legal access, privacy-preserving matching, interoperability adapters, fallback configurations, and dynamic thresholding.

Claim layering. Multiple independent claims at different abstraction levels are present, including system, method, medium, and monetization system claims, with additional embodiments disclosed in the itemized list to facilitate layered protection in this filing and future continuations.

No unneeded limitations. The main claim is expressed in terms of ingestion, similarity, consent, and coordination functions that may be unavoidable for competitors implementing collective grievance discovery with coordinated interaction, while optional features such as legal coordination and reputation scoring are separated into dependent or distinct claims.

External observability. Externally observable behaviors may include issuance of group identifiers, cluster-formation notifications, reputation scores, and signed audit records, enabling independent verification of platform operation without inspecting internals, as also described in the Anchor. As used herein, the group identifier may encompass any alias, tag, token, handle, or logical reference used to co-reference a set of related complaints, whether persistent or ephemeral and whether numeric, alphanumeric, or cryptographic. Platforms that, given multiple complaint inputs, emit common or cross-referenced identifiers for related complaints and gate notifications or disclosures by recorded consent policies may exhibit the externally observable behaviors described, irrespective of internal algorithmic choices. In certain embodiments, signed outputs may be produced using asymmetric digital signatures such as Ed25519 and may be batched into Merkle trees whose roots are periodically anchored to external timestamp authorities, thereby yielding verifiable, court-admissible artifacts that demonstrate operation without exposing internal code or confidential data. Platforms that, given multiple complaint inputs, emit invitations or notifications that cause a third-party thread or list to form under a common handle may exhibit the externally observable behaviors described. For evidentiary reliability in litigation, embodiments may publish a rotating verification key schedule and public attestation endpoints, record model and index version identifiers alongside threshold or quorum parameters in signed receipts, and emit Merkle proofs for event inclusion; an independent expert could verify signatures, reconstruct Merkle roots anchored to external timestamp authorities, confirm TEE or SEV attestation for privacy-preserving matches, and deterministically re-run matching using the recorded model and parameters on the signed inputs to reproduce cluster membership decisions within stated tolerances, thereby establishing operation and infringement without discovery of internal source code.

Interoperability coverage. The ingestion interface and coordination modules may work across REST application programming interfaces, messaging protocols, email, short message service, and integrations with civic databases, property registries, or professional association interfaces, thereby preventing competitors from avoiding infringement through interface changes. Additional interoperability may include ActivityPub, Matrix, XMPP, SMTP, IMAP, POP3, USSD, RCS, webhooks, message queues or streams including MQTT and Kafka, and identity frameworks including OpenID Connect, SAML, decentralized identifiers, and verifiable credentials, so that substitutions in transport, messaging, or identity do not avoid the scope.

Fallback embodiments. A minimal configuration may include only the ingestion interface, similarity engine, consent manager, and group identifier allocation, coupled with external notifications to users regarding group inclusion, without legal coordination or reputation scoring, ensuring the inventive concept is embodied in simpler deployments. In further minimal embodiments, matching may occur via a client-side or edge SDK with approximate similarity and server-side receipt limited to consented notifications delivered over email, short message service, or webhook callbacks, while still assigning a group identifier or equivalent handle to the related complaints.

Damages maximization. As further detailed in the Monetization and damages support section, subscription and usage-based metering, verifiable usage receipts, and tiered services may be implemented to quantify attributable usage and value, supporting reasonable royalty calculations and enhanced damages assessments where appropriate.

Monetization and damages support. The system may support subscription and usage-based access models implemented through license keys and tenant identifiers, per-seat or per-agent entitlements, metered API gateways that count and rate-limit requests, and billing integrations that compute periodic charges based on metrics such as number of active users, number of complaints ingested, similarity computations performed, clusters formed, participants coordinated, documents processed, messages exchanged, and reputation queries served. It may generate cryptographically signed, tamper-evident usage receipts and hash-chained audit logs that record billable events with timestamps, tenant IDs, group IDs, and operation descriptors, optionally anchored to external notaries or blockchains. Administrative dashboards and export APIs could provide aggregated reports and immutable event streams suitable for independent verification, enabling reliable calculation of actual usage, attributable value delivered, and reasonable royalty baselines. The system could further support service tiers (for example basic, professional, and enterprise), overage detection and alerts, prepaid credits and escrow wallets for legal coordination, and automated invoicing and receipts, thereby facilitating monetization and providing technical artifacts useful in assessing damages in the event of infringement.

The invention may be described by the following itemized list, each of which is considered within the general inventive concept and may be combined where technically feasible:

### Collective Grievance Discovery System

A system for collective grievance discovery comprising an ingestion interface configured to receive user complaints, a similarity engine configured to identify related complaints based on extracted features and to generate a group identifier for a set of related complaints, a consent manager configured to solicit and enforce user consent prior to sharing contact or complaint details, and a coordination module configured to establish a communication channel among users associated with the group identifier.

The system of item 1, wherein the ingestion interface accepts both structured and unstructured submissions and comprises a natural language processing extractor that produces embeddings and metadata.

The system of item 1, wherein consent policies are recorded on a per-complaint basis and enforced during matching, notification, and group formation.

The system of item 1, wherein the group identifier is generated responsive to a similarity threshold or quorum condition being satisfied.

The system of item 1, wherein the communication channel supports evidence sharing, messaging, and collaborative preparation for dispute resolution.

The system of item 1, further configured to preserve participant pseudonymity until subsequent consent authorizes identity disclosure.

The system of item 1, further comprising a legal coordination interface gated by identity verification through professional registries and configured to allow legal entities to signal interest, propose representation, and submit documentation.

The system of item 1, wherein the ingestion interface and the coordination module are interoperable with multiple protocols and platforms including REST application programming interfaces, messaging protocols, email, short message service, and integrations with civic databases, property registries, or professional association interfaces.
9. A system for AI-mediated reputation analysis comprising a trust engine configured to compute a reputation score for a service provider from aggregated complaints including their frequency and nature, resolution status, and source reliability, and an interface configured to provide the score to user agents for decision support.
10. The system of item 9, wherein the trust engine weights data based on detected conflicts of interest and user-configurable bias thresholds.
11. A computer-implemented method comprising receiving a complaint from a user or agent, extracting features from the complaint, computing similarity against stored complaints, identifying a set of related complaints, requesting consent from affected users, creating a group identifier for the set, and establishing a secure communication channel among members of the set.
12. The method of item 11, further comprising performing similarity matching using privacy-preserving techniques including zero-knowledge proofs or trusted execution environments.
13. The method of item 11, wherein one or more steps are executed on a decentralized network or on centralized servers based on privacy or performance requirements.
14. The method of item 11, further comprising emitting externally observable outputs including the group identifier, cluster formation notifications, reputation scores, and signed audit records to enable independent verification of platform operation.
15. A non-transitory computer-readable medium storing instructions that, when executed by one or more processors, cause the processors to perform the method of item 11.
16. The non-transitory computer-readable medium of item 15, wherein the instructions further cause generation of cryptographically signed audit logs and usage receipts including timestamps, tenant identifiers, and group identifiers.
17. The non-transitory computer-readable medium of item 15, wherein the instructions further cause dynamic adjustment of matching thresholds based on observed cluster formation rates and feedback regarding false positives.
18. A monetization system for a grievance discovery and reputation analysis platform comprising a metered gateway configured to count and rate-limit requests, a billing integration configured to compute charges based on one or more metrics including number of complaints ingested, similarity computations performed, clusters formed, participants coordinated, documents processed, messages exchanged, and reputation queries served, and a tamper-evident ledger configured to record billable events.
19. The monetization system of item 18, further comprising service tiers, overage detection and alerts, prepaid credits, escrow wallets for legal coordination, and automated invoicing and receipts.
20. A system implemented as a fallback configuration comprising an ingestion interface configured to receive user complaints, a similarity engine configured to identify related complaints and to generate a group identifier for a set of related complaints, and a consent manager configured to solicit and enforce user consent prior to sharing contact or complaint details, the system further configured to notify users associated with the group identifier without establishing a hosted communication channel or legal coordination or reputation scoring.

### Embodiment EE: Decentralized Peer-to-Peer Service Discovery Protocol for Autonomous AI Agents

A decentralized, peer-to-peer service discovery protocol for autonomous digital agents may be provided. Agents could exchange structured service enumerations, evaluate candidates via local trust graphs and semantic interpretation, and optionally negotiate credentials for invocation, all while maintaining privacy and security through cryptography and decentralized messaging. Optional modules may include zero-knowledge proofs, micropayments, refusal codes, and conflict-of-interest disclosures. The approach could reduce reliance on centralized registries, improve resilience and transparency, and enable externally observable behaviors that support enforcement and monetization.

### Gentle Introduction

The present invention may relate to the field of agent-based computing and artificial intelligence systems, and more specifically, it could involve techniques that enable decentralized, peer-to-peer service discovery among autonomous digital agents. The proposed method may find application in distributed AI ecosystems, networks of service-oriented agents, and privacy-preserving digital infrastructures where centralized discovery is undesirable or infeasible.

For clarity, the scope of the invention is intended to be limited only by the claims; all examples are illustrative embodiments, and the order of steps and message flows may be reordered, combined, or omitted without departing from the inventive concept.

### Examples

In one example, a requesting agent may discover and invoke a legal contract drafting service through a peer agent while preserving privacy and producing externally observable artifacts. A requesting agent may generate a service enumeration request that includes filters indicating a legal and contracts category and permitted interfaces such as REST. The communication module may sign and encrypt the request using a cryptographic subsystem and transmit it over decentralized messaging infrastructure to a peer agent. The peer agent may consult its local registry and trust graph under a policy module, then reply with a service enumeration response listing multiple candidate services including names, descriptions, semantic tags, interface specifications, endpoint URIs, and trust indicators. The requesting agent may compute semantic relevance with a semantic interpretation module and a composite trust score using its trust graph, then select a target candidate. If access credentials are needed, the requesting agent may transmit a service usage request asking for routing details and a token. The peer agent may coordinate with an access credential and token issuer to provide a token and return it in a secured reply. The requesting agent may then invoke the selected endpoint and, based on the observed outcome, both agents may update their trust graphs and optionally exchange a referral-based trust update. Externally observable records may include signed messages and any attached receipts or refusal codes as applicable.

In another example, an agent may require provenance without revealing sensitive identifiers. A requesting agent could issue a service enumeration request with minimal filters and later send a trust provenance query referencing a recommended candidate. The responding peer agent may return verifiable endorsements and a zero-knowledge proof generated by a proof module that attests to prior successful interactions with services tagged in a given domain without disclosing the specific service identifier or agent identity. The requesting agent may verify signatures and proofs using its cryptographic subsystem before accepting the recommendation and proceeding to selection and invocation as above. Privacy may be maintained through ephemeral identifiers and differential disclosure policies, while still yielding externally auditable, signed exchanges that demonstrate protocol use.

In a further example addressing entitlements and monetization, an agent may operate under subscription constraints enforced by a policy module. Upon receiving a service enumeration request, the responding agent could evaluate subscription state associated with the requester and either return a prioritized service enumeration response for subscribed tiers or emit a structured refusal code indicating quota exhaustion or payment required. If enumeration proceeds and a referral or invocation occurs, the micropayment and compensation subsystem may attach a signed usage receipt to the relevant exchange, recording payer, payee, message type, timestamp, and a counter value. Periodically, the responding agent may emit signed usage summaries that can be reconciled against counters in the local registry and validated by a cache validator. These steps could enable precise billing and provide externally observable artifacts suitable for damages assessment.

In an MCP-integrated example, a deployment using the Model Context Protocol may map the protocol's service enumeration request to an MCP tool invocation so that MCP-compliant runtimes can interoperate without altering semantics. A requesting agent could invoke a tool named service enumerate with encoded filters and a correlation identifier, for example:

{“mcp”:“tool.invoke”,“tool”:“service.enumerate”,“args”.{“req_id”:“r-123”,“filters”:{“category”:[“lega
l”,“contracts”],“interface”:[“REST”],“trust_threshold”:0.6}}}

and receive an MCP result carrying a response payload, for example:

(“mcp”:“result”,“correlates”:“r-123”,“payload”:{“type”:“202”,“services”:[{“svc_id”:“svc-legal-001”,“
name”:“ContractGen”,“uri”:“https://api.contractgen.example/v1”,“iface”:“REST”,“tags”:[“legal”,“cont
racts”],“auth”:“BearerToken”}]}}

The same mapping may be applied to service usage requests and trust provenance queries using tools service use and trust provenance, while a conflict-of-interest alert may be surfaced via a tool coi.disclose. An MCP-capable agent may advertise available protocol bindings through a resource descriptor such as:

Signatures produced by the cryptographic subsystem may be included as fields within arguments or payload and verified by recipients, and end-to-end encryption may be preserved by carrying ciphertext bodies through MCP transport channels.

### Background

In prevailing technological contexts, artificial intelligence systems commonly rely on centralized infrastructures-such as curated marketplaces, web search engines, or fixed registries—for the discovery and invocation of external services. Such models may impose constraints on adaptability, robustness, and scalability, and could introduce vulnerabilities related to censorship, manipulation, or failure of central authorities. These centralized dependencies may also hinder user autonomy and reduce the diversity of accessible services.

### Summary

Accordingly, there exists a potential need for a system that could permit autonomous agents to discover services in a decentralized and context-aware manner, possibly by exchanging curated service lists, inferring trust through social or historical signals, and forming dynamic trust graphs. The present invention may address these needs by introducing a protocol through which agents may request and share structured information about services they trust, use, or endorse, thereby enabling peer-to-peer enumeration and discovery.

According to one aspect, the invention may enable agents to issue structured or semi-structured requests for service lists rather than querying for a single known service. These requests may include category filters or other contextual constraints. In response, peer agents could return structured enumerations of service metadata, including functional descriptions, semantic tags, access endpoints, interface protocols, and optional indicators of trust or usage. The requesting agent may then evaluate the received options using a locally defined trust model or decision policy, which could factor in semantic relevance, past experiences, or the social proximity of the recommending agent.

### Detailed Description

Each participating agent in the system may include several architectural components that facilitate this interaction. A local data store may retain structured records of previously encountered services and associated metadata. A trust graph may model the social or historical trust relationships between agents and services, potentially including interaction scores, endorsements, and contextual confidence signals. A communication module may facilitate the sending and receiving of requests, replies, and other protocol messages. Filtering and policy modules may determine which services to reveal in response to enumeration requests, based on privacy constraints, reputational heuristics, or internal agent policies.

Each service entry maintained by an agent may be described by a structured schema that includes a unique identifier or canonical name, a machine- or human-readable description of its functionality, one or more semantic tags indicating its domain (e.g., health, legal, logistics), and a URI or endpoint through which the service may be accessed. This schema could also include details about the communication interface, such as REST, GraphQL, or custom protocols, and may specify authentication methods or other requirements for invocation. Additional metadata fields may describe endorsements, trust anchors, or usage statistics relevant to evaluating the service.

The messaging protocol supported by the invention may include various message types. A service enumeration request may include agent identifiers and optional filters, and may prompt a responding agent to return a service enumeration response. That response could list trusted or available services, potentially filtered or prioritized according to internal agent rules. The requesting agent may then issue a service usage request to obtain access credentials or invoke the service directly. In some cases, a trust provenance query may be issued to retrieve information on the origin of a service recommendation, while a conflict-of-interest message could optionally expose known relationships or dependencies that may influence trust assessments.

All agent-to-agent communication may be secured using cryptographic techniques, including encryption, digital signatures, and optionally routed through decentralized messaging layers. Privacy-preserving features could include the use of ephemeral identifiers, partial disclosure of metadata, and differential response policies depending on the trust level of the requester. The system may also support natural language message exchange, interpreted by embedded large language models, thereby enabling interaction with agents or services that are described only in human language or loosely structured data.

Optional features could further include the use of federated or local trust anchors, anonymous or pseudonymous agents, agent-to-agent micropayment systems for sharing valuable referrals, and refusal codes that explain why a service was not revealed. Zero-knowledge proof mechanisms may also be employed to share verifiable summaries without revealing full service details.

Practical applications of the invention could span numerous domains. In health care, agents might share diagnostic services or treatment recommendation engines. In the legal sector, agents could assist in locating contract automation tools or litigation participation portals. In finance, agents may recommend trusted financial planners or automated advisory tools. In logistics or advocacy contexts, agents may facilitate the coordination of users with overlapping needs or concerns, such as shared grievances against a service provider.

### Technical Effects

The invention offers several advantages. It may increase transparency and trust in agent-mediated service discovery. It may simplify the process of uncovering niche or emergent services without reliance on centralized advertising or curation. It could also promote organic service propagation through peer validation and contextual relevance. Most notably, it may reinforce user sovereignty by enabling agents to discover and recommend services without requiring disclosure of their users' queries or intents to a central platform.

### Fallback Embodiments

Simpler or partial implementations that still embody the inventive concept may omit one or more optional mechanisms while preserving decentralized peer-to-peer enumeration and peer-mediated selection of services. In a minimal configuration, an agent equipped with a communication module and a local service registry may construct a service enumeration request and process a service enumeration response from a peer agent without consulting weighted trust computations, instead relying on deterministic policy thresholds applied to semantic tags, interface types, and access requirements present in the returned metadata. In another configuration, messages may be relayed over conventional client-server transports while maintaining agent-to-agent protocol semantics and field definitions, thereby enabling deployment in environments where a decentralized messaging infrastructure is unavailable. A lightweight embodiment may exclude the zero-knowledge proof module, the micropayment and compensation subsystem, the conflict-of-interest alert, and referral-based trust updates; discovery and invocation proceed using only the enumeration and optional usage request messages. Semantic evaluation may be performed without learned embeddings by configuring the semantic interpretation module to operate in a rules-only mode that applies exact or keyword-based matching against semantic tags and descriptions. Caching may be limited to storing service identifiers and endpoint URIs with periodic refresh by a cache validator on a fixed schedule. Authentication and access control may utilize pre-shared tokens obtained from an access credential and token issuer, with the cryptographic subsystem still providing message signing and encryption for all messages. These fallback embodiments maintain the core externally observable behavior of decentralized service enumeration and agent-mediated selection, thereby providing coverage where specific optional components are unavailable, restricted, or challenged.

### Monetization and Damages Maximization:

The system may support subscription-oriented and usage-based economic models that could increase measurable damages in the event of infringement. An agent could enforce subscription entitlements for access to service enumerations, trust provenance data, or prioritization tiers, wherein entitlements may be embodied as time-bound or usage-bound tokens issued by an access credential and token issuer and validated by a cryptographic subsystem during message exchanges. Subscription states could include plan levels, expiration timestamps, seat counts, and per-interval quotas, which may be evaluated by a policy and filtering module before disclosing services or provenance. Agents may meter consumption by incrementing counters associated with specific requester identities or ephemeral identifiers within a communication module, and may apply rate limits or throttling policies that align with subscription terms. When subscription breaches occur, a refusal code generator could produce structured refusal codes indicating quota exhaustion or payment requirement, and the codes may be logged to provide auditability of entitlement enforcement.

The micropayment and compensation subsystem could enable per-enumeration, per-referral, or per-invocation fees between agents, optionally using escrow or hold-and-release semantics to align incentives. Agents may attach signed usage receipts to service usage requests or trust provenance queries, where each receipt could contain at least a payer identifier, payee identifier, message type, timestamp, counter value, and a cryptographic signature. Receipts may be aggregated into audit logs that are retained locally and optionally mirrored to decentralized storage, thereby providing verifiable records of economic activity. These records could include settlement proofs and micropayment confirmations suitable for computing license fees, unpaid balances, and consequential damages. Tiered monetization could further include premium discovery channels that prioritize responses in service enumeration responses, revenue-sharing for referral-based trust updates, and discounts or credits tied to longitudinal reliability inferred from the trust graph.

To support subscription billing workflows, agents may periodically emit signed usage summaries that could be verified by counterparties and reconciled against counters in the local registry and against validations performed by a cache validator. The summaries may include time-windowed counts of enumerations, provenance queries, and invocations, broken down by category filters and semantic tags, enabling accurate attribution of billable events to plan tiers. Dispute resolution could be assisted by cross-checking signed message transcripts and refusal codes, and by using zero-knowledge proofs to attest to aggregate usage without revealing sensitive service identities. These monetization features may provide clear, externally auditable signals of entitlement enforcement and economic value, thereby supporting assessment of reasonable royalties, lost profits, and enhanced damages.

### Court-Enforceability and Technical Character:

This embodiment may be characterized as a specific improvement to computer networking and distributed computing systems rather than as a field-agnostic abstract idea. The improvement could be realized through concrete machine operations, structured data formats, and cryptographic mechanisms that change how networked computers discover and invoke services. The protocol may require the construction, transmission, and verification of defined message types, each being a deterministically serialized record signed and optionally encrypted by the cryptographic subsystem, and linked to ephemeral identifiers bound to corresponding key pairs. The trust graph may be implemented as an adjacency-structured data model with numerically weighted edges and algorithmic update rules that compute composite scores from endorsements, usage outcomes, and social proximity. These constructs and computations could be executed by processor instructions and produce measurable changes in system-level behavior, including reduced bandwidth consumption via filtered multi-candidate enumerations, fewer round-trips when compared to sequential single-service lookups, and lower mean time to successful invocation resulting from ranking and thresholded selection guided by the trust model and semantic interpretation module.

The described system may alter the operation of conventional networks by avoiding centralized registries and instead performing authenticated, end-to-end encrypted peer exchanges on decentralized messaging infrastructure. This routing choice, coupled with signature verification of messages and cache management via a validator, could improve fault tolerance and resistance to single-point failures. The use of a zero-knowledge proof module may further enable privacy-preserving provenance without disclosing sensitive identifiers, while still permitting verification of cryptographic attestations. These mechanisms are not mental processes; they may be implemented by specific data structures, cryptographic algorithms including Ed25519 and X25519, deterministic serialization for signature generation, and executable procedures for computing semantic similarity and trust-weighted ranks.

External observables described herein may support evidentiary determinations of use, including signed and timestamped messages, refusal codes, usage receipts, nonce values, counters, and verifiable provenance artifacts. Implementations could expose repeatable, testable performance characteristics such as per-request byte counts, hop counts across the decentralized infrastructure, success-rate deltas before and after applying trust thresholds, and cache hit ratios attributable to a validator. The claimed subject matter may therefore be tied to specific, verifiable technical steps and protocol semantics, without precluding unrelated forms of recommending or indexing that do not implement the defined message exchanges, cryptographic protections, trust-graph computations, or invocation negotiations disclosed herein. The combination of decentralized routing, authenticated structured enumerations, algorithmic trust evaluation, and optional ZKP-backed provenance may yield a demonstrable, practical application that improves the functioning of computer networks used by autonomous agents.

### Itemized Embodiments

A method for decentralized service discovery comprising transmitting a service enumeration request to another agent and receiving in response a list of known services.

The method of item 1 including that the list of services comprises metadata such as a service name, a description, a semantic category, an access type, an interface specification, and one or more trust indicators.

The method of item 1 further comprising that the receiving agent applies one or more privacy filters or policy-based constraints to determine which services are included in the returned list.

The method of item 1 allowing that the response includes services that are either hosted locally by the responding agent or otherwise known through previously established trust with third-party agents.

The method of item 1 including that the list of services incorporates trust-related data computed from a weighted trust graph.

A method for evaluating received services comprising applying semantic filtering based on contextual requirements or user preference vectors.

The method of item 6 employing a learned model or vector embedding to match service descriptions with contextual needs.

The method of item 6 further involving ranking candidate services based on usage metrics, endorsement history, or inferred quality indicators.

A system composed of a plurality of agents each configured to perform the decentralized discovery method described in item 1.

The system of item 9 including that each agent maintains both a local registry of known services and a dynamically updated trust graph.

A message protocol defined to include at least a service enumeration request message, a service enumeration response message, and a service usage request message.

The message protocol of item 11 further including a trust provenance query message and a conflict-of-interest alert message.

A computer-readable storage medium containing instructions that, when executed by an agent computing system, cause it to transmit and process messages in accordance with the protocol defined in item 11.

A method for propagating trust information involving agents sharing reputational metadata and service endorsements with one another.

The method of item 14 computing trust values using a combination of social signal weighting, endorsement counts, and contextual relevance metrics.

The method of item 14 additionally computing conflict-of-interest information based on factors such as agent ownership, organizational affiliation, or recorded behavior patterns.

A communication system wherein all agent-to-agent messages are cryptographically signed and routed through a decentralized messaging infrastructure.

The system of item 17 ensuring message confidentiality through end-to-end encryption or other cryptographic protections.

A method enabling agent-mediated invocation of a remote service discovered via another agent's registry.

The method of item 19 including a negotiation phase wherein the invoking agent acquires routing information or access tokens from the providing agent.

A hybrid message parsing system implemented wherein agents are capable of interpreting both structured protocol messages and unstructured natural language service descriptions.

The system of item 21 utilizing language model-based semantic interpretation to enable handling of vague, informal, or incomplete service requests.

A system for distributed trust graph formation enabling agents to update the weights of trust relationships based on the observed success or failure of past service interactions.

The system of item 23 further supporting propagation of trust changes through peer networks by means of referral-based transitive updates.

A decentralized registry formed dynamically through peer-to-peer message exchange, thereby avoiding dependence on any centralized indexing service.

A method for privacy-preserving service sharing allowing agents to transmit zero-knowledge proofs asserting possession of service knowledge without revealing identity or service details.

The method of item 26 generating said zero-knowledge proofs using one or more established cryptographic protocols.

A method for access throttling or selective refusal implemented wherein agents reply to incoming requests with structured refusal codes.

The method of item 28 including that refusal codes communicate specific reasons, such as policy non-compliance, failed authentication, or semantic mismatch between request and service offering.

A method for local service caching allowing an agent to retain metadata of previously discovered peer services and to periodically validate or refresh the data to maintain accuracy.

A machine-implementable message protocol defining that each of the service enumeration request, service enumeration response, and service usage request message types includes fields for agent identifiers, optional filters, and service metadata with defined schemas.

A computer-readable storage medium containing instructions that, when executed by an agent computing system, cause it to map unstructured natural language service descriptions to construction of service enumeration requests and to evaluation of service enumeration responses in accordance with the protocol of item 11.

A system including an agent-to-agent micropayment and compensation subsystem enabling compensation for referrals or for access to service enumerations.

An embodiment corresponding to a decentralized service discovery method comprising constructing and transmitting a service enumeration request with one or more optional filters to at least one peer agent, receiving a service enumeration response containing metadata for multiple candidate services, evaluating the candidates using a locally maintained trust model and contextual relevance, selecting a service, and initiating invocation of the selected service.

The embodiment of item 34 including that the optional filters comprise at least one of a semantic category, an interface specification, a trust threshold, or an access type.

The embodiment of item 34 including that the service enumeration response comprises metadata including a service name, a description, one or more semantic tags, an access endpoint uniform resource identifier, an interface specification, and one or more trust indicators.

The embodiment of item 34 including that evaluating the candidate services comprises computing a score from a weighted trust graph encoding endorsements, usage statistics, and social proximity of a recommending agent.

The embodiment of item 34 further including applying vector-embedding-based semantic matching between contextual needs and service descriptions.

The embodiment of item 34 including that initiating invocation comprises negotiating to obtain routing information or access tokens from a providing agent associated with the selected service.

A decentralized service discovery system comprising a plurality of autonomous agents each including a local registry of known services, a trust graph store with relationship weights, a communication module to send and receive at least a service enumeration request, a service enumeration response, and a service usage request, and a policy module to apply privacy filters and constraints to determine which services are revealed in responses.

The system of item 40 including that all agent-to-agent messages are digitally signed and end-to-end encrypted.

The system of item 40 including that the communication module is configured to route messages through a decentralized messaging infrastructure.

The system of item 40 further configured to generate and verify zero-knowledge proofs asserting possession of service knowledge without revealing an associated agent identity or full service details.

A non-transitory computer-readable storage medium storing instructions that, when executed by an agent computing system, cause the agent computing system to interpret both structured protocol messages and unstructured natural language service descriptions and to map such inputs to construction of service enumeration requests and to evaluation of responses.

The medium of item 44 including that interpreting unstructured natural language service descriptions utilizes language model-based semantic interpretation.

A system configured such that a service enumeration response includes a structured refusal code conveying a reason for non-disclosure including at least one of policy non-compliance, failed authentication, or semantic mismatch.

The system of item 40 including that the local registry comprises a cache of previously discovered services and a validator configured to periodically refresh or validate cached metadata.

A machine-implementable message protocol defining message types comprising at least a service enumeration request, a service enumeration response, and a service usage request, each with defined fields for agent identifiers, optional filters, and service metadata.

The message protocol of item 48 further defining a trust provenance query message and a conflict-of-interest alert message.

The message protocol of item 48 further defining mechanisms for referral-based transitive updates to distributed trust graph weights based on observed outcomes of service interactions.

A computer-implemented method for propagating trust information comprising sharing reputational metadata and service endorsements between agents, computing trust values using social signal weighting, endorsement counts, and contextual relevance metrics, and updating a trust graph accordingly.

The method of item 51 further comprising computing conflict-of-interest information based on at least one of agent ownership, organizational affiliation, or recorded behavior patterns.

A decentralized service discovery system further comprising an agent-to-agent micropayment subsystem enabling compensation for referrals or for access to service enumerations.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

Item 1. A computer-implemented method performed by an agent computing system for decentralized service discovery, the method comprising: constructing and transmitting, to at least one peer agent over a network, a service enumeration request including one or more optional filters; receiving, from the peer agent, a service enumeration response comprising metadata for a plurality of candidate services; evaluating the plurality of candidate services based on a locally maintained trust model and contextual relevance; selecting a service from the plurality of candidate services; and initiating invocation of the selected service.

Item 2. The method of item 1, wherein the one or more optional filters comprise at least one of a semantic category, an interface specification, a trust threshold, or an access type.

Item 3. The method of item 1, wherein the service enumeration response comprises metadata including a service name, a description, one or more semantic tags, an access endpoint uniform resource identifier, an interface specification, and one or more trust indicators.

Item 4. The method of item 1, wherein evaluating the plurality of candidate services comprises computing a score from a weighted trust graph that encodes endorsements, usage statistics, and social proximity of the recommending agent.

Item 5. The method of item 1, wherein evaluating further comprises applying vector-embedding-based semantic matching between contextual needs and service descriptions.

Item 6. The method of item 1, wherein initiating invocation comprises negotiating to obtain routing information or access tokens from a providing agent associated with the selected service.

Item 7. A decentralized service discovery system comprising a plurality of autonomous agents, each agent including: a local registry of known services; a trust graph store configured to maintain trust relationships and associated weights; a communication module configured to send and receive messages of a protocol including at least a service enumeration request, a service enumeration response, and a service usage request; and a policy module configured to apply privacy filters and constraints to determine which services are revealed in responses.

Item 8. The system of item 7, wherein all agent-to-agent messages are digitally signed and end-to-end encrypted.

Item 9. The system of item 7, wherein the communication module is further configured to route messages through a decentralized messaging infrastructure.

Item 10. The system of item 7, further configured to generate and verify zero-knowledge proofs asserting possession of service knowledge without revealing an associated agent identity or full service details.

Item 11. A non-transitory computer-readable medium storing instructions that, when executed by an agent computing system, cause the agent computing system to interpret both structured protocol messages and unstructured natural language service descriptions and to map such inputs to construction of service enumeration requests and to evaluation of responses.

Item 12. The medium of item 11, wherein interpreting unstructured natural language service descriptions utilizes language model-based semantic interpretation.

Item 13. The system of item 7, wherein a service enumeration response includes a structured refusal code conveying a reason for non-disclosure including at least one of policy non-compliance, failed authentication, or semantic mismatch.

Item 14. The system of item 7, wherein the local registry comprises a cache of previously discovered services and a validator configured to periodically refresh or validate cached metadata.

Item 15. A machine-implementable message protocol defining message types comprising at least a service enumeration request, a service enumeration response, and a service usage request, each message type having defined fields for agent identifiers, optional filters, and service metadata.

Item 16. The message protocol of item 15, further defining a trust provenance query message and a conflict-of-interest alert message.

Item 17. The message protocol of item 15, further defining mechanisms for referral-based transitive updates to distributed trust graph weights based on observed outcomes of service interactions.

Item 18. A computer-implemented method for propagating trust information among agents, the method comprising: sharing reputational metadata and service endorsements between agents; computing trust values using social signal weighting, endorsement counts, and contextual relevance metrics; and updating a trust graph in accordance with the computed trust values.

Item 19. The method of item 18, further comprising computing conflict-of-interest information based on at least one of agent ownership, organizational affiliation, or recorded behavior patterns.

Item 20. The system of item 7, further comprising an agent-to-agent micropayment subsystem enabling compensation for referrals or for access to service enumerations.

### Embodiment FE: System and Method for Booking Passenger Travel with Decoupled Luggage Transport

Disclosed is a computer-implemented system that may enable integrated booking of passenger air travel together with a decoupled luggage transport service. A unified interface could obtain flight options and logistics options via application programming interfaces, generate bundled offers using an optimization engine, and process a single checkout to place bookings with flight and logistics providers. Luggage may be tagged for traceability, identity verification may be performed at pickup or drop-off, customs declarations may be integrated for cross-border shipments, and delivery may be coordinated to destinations such as hotels. The platform may compute comparative emissions and support subscriptions and monetization features to enable damages models. The invention may be implemented using commercially available cloud infrastructure, databases, and standard APIs.

### Gentle Introduction

Air travel today generally treats a suitcase as a passenger's companion that moves on the same plane, which can add cost, fuel burn, and procedural friction. The core idea here is to treat luggage more like a parcel that could be routed independently while the traveler takes the best available flight. In practical terms, a traveler may pick a flight that suits timing and price, while a separate logistics plan could move the bags by rail, ground, or cargo air on an efficient schedule. A single interface may present both parts together as one easy choice, so the traveler experiences one checkout and one reference, even though different providers fulfill each leg.

This decoupling could improve convenience and sustainability. Travelers may avoid airport check-in lines and baggage carousels, and hotels or residences could receive bags directly. Logistics providers may consolidate loads on lower-emission modes where feasible. The platform may coordinate timing so that luggage arrives when or shortly after the traveler does, and if the flight changes, the luggage plan could adjust automatically. Identity checks, tagging, and tracking may ensure that custody is clear at every handoff. Because the system is software-based and uses common APIs and cloud components, it may be built with existing technology and integrated with airlines, couriers, and hospitality systems without requiring specialized hardware.

### Background

In conventional airline travel, luggage is typically transported together with passengers on the same aircraft, which may result in increased fuel consumption, delayed boarding, complex baggage handling logistics, and environmental inefficiencies. There exists a need for a system that could decouple passenger transport from luggage logistics in a seamless manner, potentially improving both sustainability and convenience.

### Preamble and Scope

For avoidance of doubt, the scope of this disclosure is defined solely by the appended claims. The examples, embodiments, and any described flows are illustrative and non-limiting; operations may be performed in different orders, in parallel, or omitted, and features described in separate embodiments may be combined or substituted unless expressly stated otherwise. Any references to figures or elements are exemplary, and no implementation detail should be construed as required unless recited in the claims. Terms such as may, could, or can indicate optionality and are intended to preserve breadth.

### Summary

The present invention may enable a system that facilitates the integrated booking of human travel and decoupled luggage delivery, wherein a unified interface could allow users to reserve a flight while simultaneously arranging separate luggage transport. The luggage transport may utilize alternative modes, such as rail freight, ground delivery, or cargo air services, selected dynamically for cost-efficiency, delivery time, and environmental impact. The system may calculate optimized combinations and display a bundled offer that includes both flight details and estimated luggage delivery metrics. This itinerary may further support direct delivery to the user's hotel, accommodation, or another specified final address.

A backend platform could be configured to integrate a flight booking API for retrieving and reserving passenger flights, a logistics interface for querying available luggage transport services, a coordination module for aligning luggage delivery with passenger arrival times, and a front-end user interface that allows for a combined booking experience. Upon receiving a travel request from a user or delegated digital agent, the system may retrieve potential flight options and concurrently compute optimal luggage delivery schedules. The system could evaluate eligible logistics providers based on cost, CO2 emissions, reliability metrics, and capacity, and may rank available options accordingly.

Once candidate itineraries are identified, the system may present the user with a bundled offer that could include live flight availability, estimated luggage delivery times, a breakdown of associated emissions versus conventional transport, and total combined cost. Upon user confirmation, the system may proceed to book both the flight and the selected luggage transport, forwarding relevant confirmations and instructions to the respective service providers. Reference numbers and receipts might be stored in a centralized database and made accessible to the user.

### Examples

In one example, a domestic itinerary may be booked with decoupled ground logistics. A user could open a mobile application and enter travel parameters indicating a passenger flight from San Francisco to New York on specific dates, select an option to transport luggage separately, and specify a hotel address as the delivery destination together with weight and dimension estimates for two bags.

The backend may query airline aggregators for available flights and in parallel query a regional ground linehaul provider and a last-mile courier for a combined route from the user's home pickup address to the hotel. The optimization engine could rank candidate bundles by delivery time, cost, reliability, and emissions, and the front-end may display a bundled offer that includes the selected flight, a next-day delivery estimate for luggage, and a comparative carbon footprint relative to checking the luggage onto the flight. Upon acceptance, the payment manager may process a single checkout covering both services, and the booking orchestrator could place the flight reservation and the logistics order, returning a passenger confirmation code and a logistics tracking number under a unified booking identifier. The tagging subsystem may generate two UUID-based QR codes bound to luggage records, and the user might schedule a pickup window. At pickup, an agent could scan the QR codes and verify the user's identity using digital ID, which would create signed custody events in the tracking datastore. The luggage may move through the linehaul network with periodic scan events posted via provider webhooks, and a hospitality integration adapter could notify the hotel on the expected day of arrival. Upon delivery, a receipt confirmation and timestamp may be recorded, all events being cryptographically signed and viewable by the user.

In another example, an international itinerary may involve customs pre-clearance and deep-link booking flows. A user could book travel from Berlin to New York with luggage to be transported separately. During the booking flow, the system may collect customs declarations including item descriptions and values, validate the payload against a provider schema, and compute duties estimates. Based on availability and service levels, the optimization engine might select a cargo-only air leg from Berlin to Newark followed by a ground courier leg to the user's apartment. Due to contractual constraints with one provider, the booking orchestrator may generate machine-readable booking payloads and deep links that, when invoked by the client device, effectuate the airline and logistics bookings under the unified booking identifier rather than placing the bookings directly. The payment manager could orchestrate separate but linked transactions with synchronized metadata so that externally observable receipts reference the same booking identifier. The customs module may transmit the validated declarations to the logistics provider's API, and the user could receive digital instructions including where to affix QR tags and how to prepare the bags for customs inspection. As the shipment transits, status events such as export cleared, arrival scan, import cleared, and out for delivery may be ingested via webhooks, and comparative emissions versus checked baggage may be displayed in the user portal.

In a further example, itinerary changes may trigger automatic rescheduling and compensating transactions. A user could book a flight from London to San Francisco with a decoupled luggage service targeting a delivery window aligned with hotel check-in. If the flight is delayed by eight hours, the coordination module may detect the delay from a flight status feed, recalculate the expected arrival time, and attempt to shift the last-mile delivery to a later slot within the originally selected provider. If capacity is unavailable, a saga pattern could initiate a compensating transaction to cancel the original last-mile segment using provider-specific cancellation codes and rebook with an alternate courier while preserving the unified booking identifier and updating payout terms. The payment manager may delay capture until both the rebooked logistics confirmation and the flight confirmation are acknowledged, using idempotency keys to avoid duplicate charges, and notifications may inform the user and the hotel of the updated delivery estimate. All changes could be recorded in append-only, signed audit logs that provide an externally observable trace of the system's operation.

In software-oriented embodiments, the client and backend orchestrator may interoperate using the Model Context Protocol so that an agent or application invokes tools representing provider searches, bundling, and booking. For instance, a flight search tool invocation may carry a request such as {“tool”:“flight.search”,“args”:{“origin”:“SFO”,“destination”:“JFK”,“departDate”:“2025-03-04”,“pax”: 1}} and a logistics search tool may carry {“tool”:“logistics.search”,“args”:{“pickup”:{“postal”:“94107”,“country”:“US” },“delivery”:{“postal”:” 10001”,“country”:“US” },“bags”:[{“id”:“BAG-1”,“kg”:23,“dimsCm”:[70,45,28]}],“readyBy”:“2025-03-03T10:00:00Z” }}. A bundling tool may output a consolidated object such as {“type”:“BundledOffer”,“id”:“BO-9d1f”,“flight”:{“id”:“F-abc”,“price”:{“currency”:“USD”,“amount”: 289.00}},“logistics”:{“id”:“L-xyz”,“eta”:“2025-03-05T18:00:00Z”,“price”:{“currency”:“USD”,“amou nt”:49.00}},“emissions”:{“checkedKgCO2e”:92.4,“decoupledKgCO2e”:54.7},“total”:{“currency”:“U SD”,“amount”:338.00}}which could be rendered in the single checkout. The booking step may submit a payload such as {“type”:“CreateBooking”,“offerld”:“BO-9d1f”,“traveler”:{“name”:“Avery Doe”,“email”:“avery@example.com” },“payment”:{“method”:“card”,“token”:“tok_1Abe” },“delivery”: {“addressLine1”:“123 Hotel Way”,“city”:“New York”,“postal”:“10001”,“country”:“US”,“window”:{“start”:“2025-03-05T14:00:00Z”,“end”:“2025-03-05T20:00:00Z” }}} and receive confirmations such as {“type”:“BookingConfirmed”,“bookingld”:“UBI-7c2e”,“flightPnr”:“PNR123”,“logisticsTracking”:“T RK456” }. As events occur, provider webhooks may deliver updates such as {“type”:“ScanEvent”,“luggageld”:“LUG-7bca”,“status”:“OUT_FOR_DELIVERY”,“at”:“2025-03-05T 15:12:34Z”,“provider”:“CourierX” }, enabling externally observable traces aligned with the unified booking identifier. MCP-based tool definitions may allow stateless or state-aware invocation patterns, idempotency keys, and schema validation enforced at the tool boundary, fitting naturally into the invention's optimization, orchestration, and tracking pipelines.

### Description of the Drawings

No drawings are provided in this embodiment. The elements and their relationships are summarized in the anchoring section below; any figures, if added in later filings, would be illustrative and non-limiting.

### Detailed Description

The luggage transport component may be executed through a network of approved drop-off centers or scheduled home collection services. Identity verification during pickup and drop-off could be accomplished via digital ID scanning, biometric authentication, or QR code-based tagging. The luggage itself may be tagged using secure digital or optical identifiers to ensure continuous traceability throughout transit. The backend could store each tag's movement history and provide real-time tracking data to the user.

The coordination module may dynamically adapt the luggage delivery schedule based on updated flight arrival times or hotel check-in windows. In the case of flight delays, the system could reschedule the corresponding luggage handoff automatically. A rules engine or machine learning module may be used to calculate the optimal delivery path using historical transport data, predictive delay models, and user-configured preferences such as lowest environmental impact, fastest delivery, or lowest cost.

Environmental impact calculations may rely on standardized transport emissions data, which could be integrated via public or private emissions databases. The system might compare the calculated CO2 footprint of traditional luggage-on-flight handling with alternative multimodal transport routes and display this comparison to the user at the time of booking to encourage eco-conscious choices.

For cross-border deliveries, customs declarations could be requested during the booking process. These declarations may be formatted into compliant digital documents and transmitted either to the logistics provider or directly to relevant customs authorities using API-based protocols, where available. The system may also facilitate additional services such as insurance, loss protection, and destination-specific delivery enhancements.

The user interface may support account login and profile management, selection of departure and destination cities, entry of luggage weight and dimensions, and selection of optional services such as insurance or customs assistance. The platform may be implemented as a responsive web application or native mobile application and could support both manual interaction and API-based agent automation.

### Interoperability and Platform Implementation

From a technical standpoint, the backend system could be deployed on a cloud infrastructure platform such as AWS or GCP, and data could be stored using relational or NoSQL databases such as PostgreSQL or DynamoDB. RESTful APIs may be used to interface with third-party flight aggregators (e.g., Amadeus, Sabre) and logistics services (e.g., DHL, FedEx, rail or regional courier networks). Provider connectivity may further include message queues, EDI, SFTP exchanges, or other programmatic interfaces in addition to RESTful APIs, and, in correlation-only embodiments, email inbox parsing and receipt ingestion. Authentication could be handled using OAuth 2.0 and OpenID Connect protocols, while transaction data may be cryptographically signed for security and non-repudiation.

### Technical Effects and Advantages

The disclosed architecture may deliver concrete technical improvements in computer functioning and networked transaction processing beyond the mere automation of a business practice. By orchestrating a multi-provider booking as a single logical operation, the backend could implement idempotency keys, distributed saga patterns, and compensating transactions so that partial failures are automatically detected and rolled back or reconciled without human intervention. This coordination may reduce inconsistent state across heterogeneous APIs, lower error rates in multi-leg bookings, and improve end-to-end reliability measured as successful atomic completion of both flight and logistics reservations. The optimization engine may reduce network bandwidth and latency by pruning dominated combinations before provider calls, using cached fare-quote windows and provider capability indexes to avoid unnecessary API requests, thereby decreasing peak request rates and improving P95 response time for bundled offer generation. The tracking subsystem may employ event sourcing with append-only, cryptographically signed logs that provide O(1) retrieval of the most recent status per luggage identifier and enable tamper-evident auditability, which improves non-repudiation and reduces reconciliation time when ingesting out-of-order webhook events. The payment manager may tokenize card instruments and perform a two-phase authorization and capture sequence aligned with provider confirmations, reducing chargeback exposure and eliminating race conditions where a provider confirmation is delayed but user payment has settled. The customs module may pre-validate declarations using schema-validated payloads and checksum verification prior to submission, reducing rejection rates and resubmission loops that would otherwise increase API traffic and user wait time. Together, these mechanisms may improve throughput, reduce mean-time-to-recovery for failed steps, and enhance data integrity and security in a way that is externally observable via signed receipts, deterministic booking identifiers, and consistent status traces. The resulting system may therefore provide technical effects including reduced request amplification, improved transactional atomicity across heterogeneous endpoints, latency reductions for offer computation, and hardened audit trails, which could allow the claimed processes to hold up under technical scrutiny.

To further tie the claimed processes to concrete computer improvements, the booking orchestrator may compute a deterministic unified booking identifier by calculating an HMAC-SHA-256 over a canonicalized JSON serialization of selected association fields including provider identifiers, timestamp buckets, and a per-tenant secret key; this identifier may be used as the idempotency key prefix across downstream calls, enabling safe retry semantics and preventing duplicate reservations despite network retries or client resubmissions. The tracking subsystem may maintain an append-only event log in which each record contains a content hash and the hash of a prior record, with periodic Merkle roots committed to a separate integrity store, thereby providing verifiable proofs of inclusion and order without scanning the full log and making tampering externally detectable. The orchestration layer may model multi-provider booking as a finite-state machine with explicit states and transitions, executed by a distributed saga coordinator that issues compensating calls on failure and persists transition metadata alongside reason codes. Queue backpressure, bounded retries with exponential backoff and jitter, and circuit breakers around individual providers may reduce request amplification, stabilize latency under partial outages, and improve overall throughput.

For subject-matter eligibility and enforceability, in some embodiments the steps described herein may be executed exclusively by networked computer systems interacting via machine interfaces, where a machine interface denotes an electronic endpoint that exchanges structured, machine-parseable messages without human interpretation, including but not limited to JSON over HTTPS, message queues, EDI, or SFTP file drops consumed by automated processes. The generation of the association and the orchestration of bookings may rely on specific data structures and algorithms including the deterministic unified booking identifier computed as an HMAC-SHA-256 over canonicalized JSON fields, the use of idempotency keys scoped by that identifier across downstream calls, a saga-style finite-state machine with persisted transitions and compensations, and append-only logs with chained hashes and periodic Merkle roots, all executed automatically and asynchronously with bounded retries, circuit breakers, and backpressure. These mechanisms may be necessary to achieve atomic multi-provider booking across unreliable networks and heterogeneous APIs and may yield measurable improvements such as reduced request amplification, lower P95 latency for offer generation, and lower mean time to recovery after provider errors. In preferred implementations, at least one of these mechanisms is required for a booking to be considered successful, thereby tying the claimed results to concrete improvements in computer functionality rather than a mere presentation of commercial information.

A principal technical effect of the disclosed system and method is the reduction of carbon dioxide emissions associated with long-distance passenger travel. In conventional air transport, passenger luggage is carried in the aircraft hold, increasing gross take-off weight and thereby fuel consumption. By decoupling luggage from the passenger and transporting it via alternative ground-based logistics routes such as rail or truck, the effective payload of the aircraft is reduced. This weight reduction translates directly into lower fuel burn per flight and, consequently, reduced greenhouse gas emissions. Coordinating passenger itineraries and independent luggage transport through a unified booking system ensures that the practical usability of the solution is preserved, while achieving a measurable environmental benefit that is verifiable by comparing estimated emissions between conventional luggage-by-air and decoupled luggage-by-land scenarios.

In one embodiment, the invention provides a method for reducing carbon dioxide emissions in passenger travel by decoupling the transport of passengers and their luggage. A passenger may be booked on an air route exceeding 100 kilometers while one or more pieces of associated luggage are routed separately over land, for example by rail or truck. A unified booking identifier is generated to bind the passenger itinerary and the luggage itinerary together, ensuring that both arrive at a common destination within a coordinated delivery window. The unified identifier may be realized as a cryptographic token linking both bookings, enabling secure association and preventing tampering.

During booking, the system may compute a comparative emissions profile showing the difference between conventional air-carried luggage and the decoupled transport scenario, optionally presenting an emissions savings value to the user to encourage adoption. Each piece of luggage may be tagged with a machine-readable identifier such as a QR code, RFID, or digital token, and custody events recorded in an append-only event log to provide auditability. The orchestration may be executed by a cloud-based system configured to query both airline reservation APIs and logistics provider APIs, to assemble bundled offers that satisfy arrival and delivery constraints. For international routes, customs forms may be generated from passenger declarations and transmitted electronically to logistics providers or customs authorities to streamline clearance. Collectively, these measures provide a practical method for synchronizing decoupled passenger and luggage travel while producing a quantifiable reduction in aviation-related carbon dioxide emissions.

### Payments

Payment handling might be conducted through a single checkout interface that processes the total amount for both the flight and the luggage transport, possibly utilizing an integrated payment gateway or escrow system. The funds may then be disbursed to the respective service providers according to predefined terms or dynamic contractual logic, which may optionally include smart contract enforcement. In alternative embodiments, the platform may process separate but linked payments for the flight and the luggage transport under a single booking identifier and unified user experience. The payment manager may authorize and capture amounts in multiple stages while presenting a consolidated checkout to the user or a calling programmatic client.

### Contracts and Integrations

In some embodiments, the system could act as a contract broker that establishes and enforces service-level agreements between users, airlines, and logistics providers. A coordination interface may be exposed to hospitality systems such that hotels could be notified of incoming luggage and prepare accordingly. The system architecture may be modular, with plugin modules enabling integration with additional travel-related services, such as airport shuttle reservations, mobile SIM cards for arrival, or carbon offset programs.

### Deployment

Deployment of the system could begin with regional pilots using a limited set of routes and a single logistics provider, and may scale globally through strategic partnerships with airline alliances, travel aggregators, and freight consortiums. The invention could be implemented entirely in software using commercially available technologies, without requiring novel hardware. All functional modules may be embodied in machine-readable instructions stored on computer-readable media, and may be executed by standard computing equipment.

### Enablement

This description suggests that the invention is fully enabled, technically feasible, and may be implemented with current APIs, transport infrastructure, and payment technologies, offering a practical pathway toward more sustainable and efficient travel logistics. An implementation path may include provisioning cloud resources for a backend orchestration layer, configuring connectivity to at least one flight booking aggregator and at least one logistics provider via credentials issued through partner portals, and implementing a front-end that collects travel parameters and luggage details. A skilled person may construct a data model comprising user profiles, trip requests, flight options, logistics options, bundled offers, bookings, tags, and events. A minimal viable deployment may be realized by coding a rules-based optimizer that associates a retrieved flight option and a retrieved logistics option by matching arrival windows to delivery windows and verifying capacity constraints, then serializing the association as a bundled offer for UI display. Checkout may be implemented by invoking a PCI-compliant payment gateway to create a single charge object that includes metadata referencing both provider bookings under a unified booking identifier. Tag issuance may be performed by generating a UUID per luggage item and rendering a corresponding QR code, storing the mapping in a tracking table keyed by the UUID. Provider webhooks or SFTP-delivered scan files may be parsed by a background worker that appends events to the tracking table and updates user-visible status fields. Identity verification may be implemented by integrating a third-party digital ID verification SDK to capture a document image and a selfie, returning a verification token stored with the booking. For cross-border routes, a customs form may be rendered from collected declarations and posted to the logistics provider's API endpoint where available. The above steps may be implemented using mainstream languages and frameworks and executed on commodity cloud instances without undue experimentation.

A practical implementation may generate the unified booking identifier as HMAC_SHA256 over a canonicalized JSON serialization of fields such as flightOfferId, logisticsOfferId, deliveryWindow, and tenant context using a per-tenant secret, persist the resulting value as the primary key for the booking, and reuse a derived key such as UBI:step for idempotent POSTs to provider APIs. The saga coordinator may persist a state machine row per booking with fields including state, lastTransitionAt, providerRefs, and compensationPlan, advancing state only after a durable write succeeds and issuing compensating calls if a transition fails. The event log may store entries as JSON lines with fields including a sequence number, the hash of the previous entry, and a content hash, with a periodic Merkle root saved to a separate table or external notarization service to allow verifiable proofs of inclusion and order. These concrete structures may be implemented using standard libraries and services and are sufficient for a skilled person to reproduce the reliability, atomicity, and auditability effects described.

### Process Flows

The booking process disclosed herein may proceed through a sequence of coordinated user interactions and backend system operations, enabling the combined reservation of passenger air travel and a decoupled luggage transport service. In a typical embodiment, the process may begin when a user accesses a digital interface, such as a web-based or mobile application, and provides basic travel parameters, including departure and destination locations, intended dates of travel, and passenger details. The system may further allow the user to indicate a preference for separating luggage transport from the flight booking, thereby initiating the logistics evaluation component.

Upon selection of the decoupled luggage transport option, the system may prompt the user to input additional baggage-specific parameters, such as the number of items, estimated weight and volume, preferred pickup location (which may be a home address, office, or authorized drop-off point), and the delivery destination. The system may also allow for the specification of a preferred delivery window and the prioritization of optimization parameters including delivery speed, cost, or environmental impact.

The backend platform may then initiate parallel operations. A flight search module may query airline booking APIs to retrieve available flights based on user-specified constraints. In parallel, a logistics evaluation engine may query a plurality of logistics providers to identify viable luggage transport routes between the user's pickup location and delivery destination. These routes may be filtered and ranked based on a variety of criteria, such as estimated delivery time, cost, emissions profile, customs requirements, and service reliability. Historical data, predictive models, and provider-specific performance metrics may inform this evaluation.

Once flight and logistics options are retrieved, the system may generate one or more bundled travel packages. Each package may include a proposed passenger flight itinerary, an associated luggage transport plan, estimated delivery times, comparative emissions savings versus conventional checked baggage, and a unified total cost. The user may then review and accept a selected package, at which point the system may proceed to execute a combined transaction through a secure payment gateway.

Upon payment confirmation, the system may reserve the passenger flight and simultaneously book the logistics service, issuing confirmation references for both components.

Following the confirmed booking, the system may provide the user with a unique identifier for each piece of luggage, which may be implemented as a scannable QR code, RFID tag, or digital token. The user may receive instructions for luggage handoff, either via home pickup or drop-off at a designated facility. Identity verification protocols may be triggered at this stage, potentially involving biometric scanning, government-issued ID upload, or digital authentication through a secure session.

As the trip progresses, the system may coordinate all relevant timeline events. In the case of changes to the passenger's itinerary, such as flight delays or rebookings, the backend coordination module may recalculate the expected arrival time and dynamically adjust the logistics delivery window to maintain synchronization. Notifications may be generated and dispatched to the user at relevant milestones, including confirmation of flight check-in, luggage pickup, customs clearance (if applicable), out-for-delivery status, and successful luggage handoff at the destination.

In cases where the final delivery location corresponds to a hotel or accommodation, the system may interface with the property's management system to coordinate delivery timing in accordance with standard check-in policies. A notification may be sent to hotel personnel when luggage is en route, and receipt confirmation may be captured upon arrival through a scan or signature process.

Customs declaration processes may be initiated automatically if the luggage is expected to cross international borders. During the booking flow, the system may prompt the user to complete standardized customs forms, which could then be converted into compliant formats and transmitted to customs authorities via an integrated API or through digital submission protocols agreed upon with the logistics provider.

All data related to the booking transaction, including user identity, travel and delivery preferences, payment records, and logistics metadata, may be stored in a centralized transaction database. This database may support both operational tracking and auditability. Security protocols may ensure the confidentiality and integrity of the data, potentially including encryption, digital signatures, and access control mechanisms.

The system may also act as a digital contract facilitator between the user, airline, and logistics provider, optionally enforcing service-level agreements using either conventional terms or smart contract mechanisms. Funds collected during the unified checkout process may be distributed according to negotiated terms with each provider, potentially using escrow or automated release protocols upon confirmation of service completion.

The entire architecture may be modular, with service plugins supporting integration of additional travel-related offerings such as airport shuttles, SIM card activation on arrival, carbon offset subscriptions, or travel insurance. The invention may be deployed in a limited geographic region for initial validation and subsequently expanded through partnerships with airline alliances, booking platforms, and international freight networks.

All software modules enabling the process may be embodied in computer-readable instructions stored on a tangible medium and executed by one or more processing units connected to cloud infrastructure.

The implementation may utilize known APIs, data exchange protocols, and commercially available transport services, thereby ensuring feasibility with current technological capabilities.

In implementations where provider-side bookings are initiated by the user rather than by the platform, the system may ingest provider confirmations via emails, webhooks, receipts, or status pages and correlate the independently placed bookings under the unified booking identifier or correlated metadata, thereby preserving the bundled association without requiring direct provider-side booking calls.

### Fallback Embodiments

Simplified or partial implementations may embody the inventive concept while omitting certain advanced components. In a minimal variant, the platform may act as a metasearch and orchestration layer that compiles a flight reservation link and a preselected logistics booking link under a unified booking identifier without automated funds disbursement, relying on separate but linked payments recorded with metadata to preserve the coupled experience. A rules-based coordinator may replace any machine learning components by applying fixed windows and buffer times to align luggage pickup and delivery with the passenger itinerary, using static provider timetables and cutoff times provided via documentation instead of dynamic capacity feeds. In a provider-limited configuration, a single logistics partner per region may be used, with routing constrained to ground-only services for domestic shipments and without customs processing; international routes may be excluded or deferred to manual handling by presenting printable documents and instructions to the user. Tagging and tracking may be reduced to reuse of provider-issued tracking numbers or airway bills as the unique identifiers, foregoing RFID, specialized QR encodings, or continuous telemetry; status may be updated by periodically polling a public tracking endpoint or processing daily SFTP status files rather than real-time webhooks. Identity verification may be performed using a one-time booking code and a government ID visual check at pickup without biometric comparison or SDK-based verification, while still achieving custody validation. Hospitality coordination may be omitted by default, treating hotels as standard delivery addresses with recipient signature capture upon arrival. Payment may be executed as two transactions initiated through a consolidated checkout page that presents a combined total and records a shared booking reference, thereby preserving a single user experience while avoiding escrow or smart contract enforcement. Security may be implemented using transport-layer encryption and role-based access control without mandatory digital signatures on every event, and auditability may be satisfied through append-only logs rather than immutable ledgers. Interoperability may rely solely on REST or even email and SFTP interfaces where providers lack modern APIs, with the orchestrator parsing confirmations to mark bookings as complete. In a zero-UI variant, the platform may expose only machine-readable artifacts such as deep links, redirect URLs, or signed booking payloads to be invoked by a client device or agent; payments may be collected by providers while the platform preserves correlation through synchronized metadata and booking references, thereby practicing the inventive concept without a visible single checkout or on-screen bundled presentation. These simplified configurations may still practice the core concept of booking passenger air travel together with a decoupled luggage transport service, maintain externally observable indications such as booking references, receipts, and delivery confirmations, and thereby remain within the scope defined by the claims even if advanced modules are later disputed or unavailable.

### Anchoring Elements and Relationships

For clarity of understanding and to anchor the embodiment, the principal elements and their relationships may be summarized as follows in prose without limiting scope. A user device or delegated digital agent may interact with a front-end booking interface connected to a backend orchestration layer. The backend may include a flight booking module interfacing with airline aggregators and carrier systems, and a logistics integration module interfacing with multiple providers including ground couriers, rail cargo operators, maritime shippers, and cargo-only air services. An optimization engine, which may comprise a rules engine and optionally a machine learning component, could combine flight options and logistics routes to generate candidate bundled packages ranked by cost, delivery time, reliability, and emissions. A bundling component may assemble and present unified offers to the user. Upon selection, a payment gateway may process a single transaction and a funds disbursement component could split payouts to airline and logistics providers according to preconfigured or dynamic terms, optionally governed by a contract broker and service-level agreement manager. Identity verification services may validate user identity and luggage ownership at pickup or drop-off, while a tagging subsystem may issue unique identifiers such as QR codes, RFID tags, or digital tokens bound to a luggage record in a tracking datastore. Provider webhooks and scan events may feed a tracking and telemetry subsystem that records movement history and exposes real-time status to the user. A coordination module could reconcile flight schedules with delivery timelines, rescheduling handoffs when flight changes occur and notifying stakeholders through a notification service. A customs module may collect and transmit declarations for cross-border shipments, and a hospitality integration adapter could notify hotels of incoming luggage and capture receipt confirmations. A security layer may enforce encryption, access control, and digital signatures across a centralized transaction database that stores user profiles, bookings, tags, audit logs, and emissions metrics. An emissions calculator may query standardized databases to compute comparative CO₂ footprints between conventional checked-baggage transport and decoupled routing. The system may be deployed on cloud infrastructure and extended via provider plugins, with operational monitoring ensuring reliability. The data flow may proceed from user request to parallel flight and logistics queries, to ranked bundled offers, to unified payment and bookings, to tag issuance and identity verification, to pickup or drop-off and multimodal transit with customs as applicable, to delivery and receipt confirmation, followed by settlement to providers.

### Monetization, Damages, and External Observability

Monetization and subscription operations may be supported to facilitate recurring revenue and enable quantifiable damage models. The platform could implement subscription plans for travelers and enterprise accounts, including tiered entitlements such as a maximum number of luggage transports per billing period, priority routing, extended insurance coverage, or waived pickup fees. A billing subsystem may meter usage by counting transports, tracking weight and volumetric metrics, and recording geographic zones traversed, with all events written to immutable audit logs signed with digital signatures. Recurring billing could be integrated with payment gateways to process monthly or annual charges, pro-rated upgrades, and overage fees triggered when entitlements are exceeded.

Provider-facing monetization may include revenue-sharing models with airlines and logistics providers, where the system calculates and disburses partner payouts based on per-transaction royalties, negotiated percentages, or fixed per-leg fees, optionally adjusted by service-level performance and emissions reductions. The subscription and monetization features may expose externally observable artifacts such as invoices, receipts, usage statements, plan identifiers, and charge descriptions that reflect the technical operation of decoupled luggage routing. Administrative controls could allow plan configuration, promotional credits, and SLA credits, and may enforce access to premium features through entitlements checked at runtime by the backend before booking, tracking, or priority scheduling features are invoked. These mechanisms may support damages calculations by tying usage volumes, entitlements, and premium features to revenue realized from the accused functionality. Signed receipts may include the unified booking identifier and, where implemented, Merkle proof elements sufficient to verify event inclusion and ordering without privileged system access.

### Itemized List for Continuations

The embodiment can be described by the following itemized list: 1. A method for booking a transportation service, which may comprise exchanging a monetary amount for the combined services of transporting a person via air and transporting associated luggage via a separate ground logistics service. 2. The method of item 1, wherein the system may receive a user input indicating a desired passenger travel itinerary. 3. The method of item 1, wherein a backend processor could be configured to select a separate logistics service for transporting the luggage associated with the passenger booking. 4. The method of item 1, wherein the system may generate a bundled booking offer comprising both the passenger air travel and the decoupled luggage transport itinerary. 5. The method of item 1, wherein the system may transmit booking confirmations to both the passenger transport provider and the logistics service provider upon completion of the booking transaction. 6. The method of item 1, wherein the decoupled luggage transport could be scheduled to arrive directly at a designated hotel or temporary accommodation address specified by the passenger. 7. The method of item 1, wherein the system may estimate a differential in carbon footprint between transporting the luggage on the same aircraft as the passenger versus using a decoupled logistics routing. 8. The method of item 1, wherein the system may include a process for verifying the identity of the passenger and the ownership of the associated luggage prior to finalizing the booking. 9. The method of item 1, wherein the selection of the logistics service may be based on one or more factors, including estimated delivery cost, delivery timing, and projected environmental impact. 10. The method of item 1, wherein the system may be configured to issue a single payment transaction that covers both the passenger flight and the luggage transport booking. 11. The method of item 1, wherein the user interface may be adapted to display alternative luggage transport options, allowing comparative selection alongside the passenger flight itinerary. 12. The method of item 1, wherein the system may integrate customs declaration documents automatically into the luggage delivery workflow when cross-border transport is involved. 13. The method of item 1, wherein the luggage may be transported using a mode of transport selected from a group that could include ground freight, rail cargo, maritime shipping, and cargo-only air services. 14. A computer-readable medium storing instructions which, when executed by one or more processors, may cause a system to perform the method of any of items 1 through 13. 15. The method of item 1, wherein payment processing may comprise separate but linked transactions under a unified booking identifier and unified user experience. 16. The method of item 1, wherein provider connectivity may include interfaces selected from application programming interfaces, message queues, electronic data interchange, secure file transfer protocol exchanges, or other programmatic connectors. 17. The method of item 1, wherein bookings may be effectuated by transmitting booking instructions to providers that complete the bookings. 18. The method of item 1, wherein the travel parameters may be received via a programmatic interface used by an automated agent. 19. The method of item 1, wherein the system may issue, for each luggage item, a unique machine-readable identifier and associate the identifier with a tracking record stored in a database. 20. The method of item 1, wherein the system may coordinate a luggage delivery schedule with changes in a passenger flight itinerary, including rescheduling a logistics handoff responsive to a flight delay or rebooking. 21. The method of item 1, wherein payment processing may further comprise disbursing funds to a flight provider and a logistics provider according to predefined or dynamic terms optionally enforced by a smart contract. 22. The method of item 1, wherein the delivery destination may comprise a hotel or accommodation, and the system may transmit a notification to a hospitality system indicating incoming luggage and record a receipt confirmation upon delivery. 23. A system for booking passenger travel with decoupled luggage transport, which may comprise a front-end interface configured to receive travel parameters and an indication to transport luggage via a logistics service distinct from a passenger flight, a flight booking module configured to obtain flight options via airline application programming interfaces, a logistics integration module configured to obtain luggage logistics options via provider application programming interfaces, an optimization engine configured to associate flight options with logistics options to form bundled offers, a payment gateway configured to process a single transaction for a selected bundled offer, and a booking orchestrator configured to place bookings with a flight provider and a logistics provider based on the selected bundled offer. 24. The system of item 23, which may further comprise a tracking subsystem configured to issue unique identifiers for luggage items, to receive scan or webhook events from logistics providers, and to record movement history accessible to a user. 25. The system of item 23, which may further comprise a coordination module configured to reconcile flight schedules with logistics delivery timelines and to reschedule logistics events responsive to flight changes. 26. The system of item 23, which may further comprise a customs module configured to collect customs data during booking and to generate and transmit declarations for cross-border shipments. 27. The system of item 23, which may further comprise a hospitality integration adapter configured to notify hotels of incoming luggage and to capture receipt confirmations. 28. The system of item 23, wherein the optimization engine may be configured to rank bundled offers by at least one of cost, delivery time, reliability, or emissions. 29. The method of item 1, wherein booking, identity verification, payment, and tracking data may be stored in a transaction database protected by encryption, access control, and digital signatures. 30. The system of item 23, wherein authentication may be performed using OAuth 2.0 and OpenID Connect and transaction data may be cryptographically signed for non-repudiation. 31. The method of item 1, wherein the system may present optional add-on services including at least one of insurance, carbon offset subscriptions, airport shuttle reservations, or mobile subscriber identity module activation, and may incorporate selected services into the single checkout transaction. 32. The method of item 1, wherein correlation between the passenger booking and the luggage booking is maintained using any identifier selected from a group that may include a shared booking reference, a hashed token derived from multiple fields, an alias key issued per provider, or time-amount correlated payment metadata, such that provider-side field naming changes do not avoid correlation. 33. The method of item 1, wherein the platform presents separate provider checkouts via deep links, redirects, QR payloads, or browser automation while persisting synchronized metadata that preserves a unified booking experience and post-hoc correlation. 34. The method of item 1, wherein the luggage transport is scheduled to occur before, concurrently with, or after the passenger flight, including pre-shipment that arrives prior to the passenger and post-shipment that departs after the passenger. 35. The method of item 1, wherein tagging comprises at least one of a printed label bearing a human-readable code, a handwritten alphanumeric code captured by a client device, a photographic fingerprint of the luggage recognized by computer vision, or a virtual token without a physical tag. 36. The method of item 1, wherein the luggage route is split across multiple providers or consolidated across multiple luggage items, including hub consolidation, cross-docking, or delivery to a staffed counter or smart locker. 37. The method of item 1, wherein the logistics service is fulfilled by an airline in a cargo or ancillary service channel distinct from the passenger's itinerary record, including carriage in the same aircraft belly hold without being checked against the passenger's booking. 38. The method of item 1, wherein external observability is provided by at least one of signed audit logs, hashed event digests, reproducible status reconstructions from append-only records, or correlated tracking identifiers appearing on receipts, invoices, or provider tracking pages. 39. The system of item 23, wherein orchestration tools may be invoked by an agent using Model Context Protocol or an equivalent tool invocation framework including at least one of JSON-RPC, gRPC, GraphQL, or JSON-LD actions. 40. The method of item 1, wherein emissions computation is optional, omitted, deferred, or supplied by a placeholder estimate without affecting the combined booking association. 41. The method of item 1, wherein payments are executed entirely by providers and the platform preserves correlation by recording synchronized metadata, identifiers, or webhook events. 42. The method of item 1, wherein persistence is implemented using any of an append-only log, a conventional relational database, a NoSQL datastore, or a decentralized ledger, each providing tamper-evident or auditable history. 43. The method of item 1, wherein identity and custody verification may comprise possession-based attestations, one-time codes, or witness signatures instead of biometric or SDK-based verification. 44. The method of item 1, wherein the delivery destination may comprise at least one of a residential address, commercial address, airport service desk, airline baggage office, parcel locker, or hotel back-of-house receiving area. 45. The method of item 1, wherein the optimization is performed by a static rule table, simple heuristics, manual operator selection, or a learned model, with equivalent results treated as within scope. 46. The system of item 23, wherein provider communications may be effected via at least one of REST APIs, EDI messages, PDF or email parsing, SFTP file drops, or automated browser interactions, and wherein booking completion is detected by parsing confirmations, webhooks, or status pages. 47. A non-transitory computer-readable medium storing instructions which, when executed by one or more processors, cause a system to perform any of items 32 through 46. 48. A computer-implemented method which may comprise receiving, via a user interface or programmatic interface, travel parameters for a passenger and an indication to transport luggage via a logistics service distinct from a passenger flight, obtaining via application programming interfaces available flight options satisfying the travel parameters and available luggage logistics options between a pickup location and a delivery destination, generating at least one association between at least one flight option and at least one logistics option as a bundled offer or as linked booking artifacts, presenting the association for selection in a single view or as a coordinated sequence of user interface interactions or exposing a machine-readable representation for automated selection by a client device or agent, receiving a selection of the association, processing payment for the passenger flight and the luggage logistics service or orchestrating separate but linked provider-directed payment flows under a unified booking identifier or correlated metadata that links provider records, and causing bookings to be placed with a flight provider and a logistics provider or transmitting booking instructions or generating machine-readable booking payloads or deep links that, when invoked by a client device, effectuate the bookings according to the selected association. 49. The method of item 48, which may further comprise computing and displaying an estimated luggage delivery time and a comparative carbon emissions metric relative to transporting the luggage on the passenger flight. 50. The method of item 48, wherein obtaining the luggage logistics options may comprise querying a plurality of logistics providers and ranking the options based on at least one of cost, delivery time, projected emissions, reliability metrics, or capacity. 51. The method of item 48, which may further comprise issuing, for each luggage item, a unique machine-readable identifier and associating the identifier with a tracking record stored in a database. 52. The method of item 48, which may further comprise verifying an identity of the passenger and a custody of the luggage at pickup or drop-off using at least one of digital identification, biometric authentication, or a code scan. 53. The method of item 48, which may further comprise coordinating a luggage delivery schedule with changes in a passenger flight itinerary, including rescheduling a logistics handoff responsive to a flight delay or rebooking. 54. The method of item 48, wherein the delivery destination may comprise a hotel or accommodation and may further comprise transmitting a notification to a hospitality system indicating incoming luggage and recording a receipt confirmation upon delivery. 55. The method of item 48, which may further comprise collecting customs declaration data during booking and transmitting the data to customs authorities or to the logistics provider for cross-border shipments. 56. The method of item 48, wherein processing the payment may comprise a single checkout and may further comprise disbursing funds to the flight provider and the logistics provider according to predefined or dynamic terms optionally enforced by a smart contract. 57. The method of item 48, wherein the luggage logistics options may include at least one mode selected from ground freight, rail cargo, maritime shipping, and cargo-only air services. 58. A system which may comprise a front-end interface configured to receive travel parameters and an indication to transport luggage via a logistics service distinct from a passenger flight, a flight booking module configured to obtain flight options via airline application programming interfaces, a logistics integration module configured to obtain luggage logistics options via provider application programming interfaces, an optimization engine configured to associate flight options with logistics options to form bundled offers or linked booking artifacts, a payment manager configured to process a single transaction for a selected association or to orchestrate separate but linked transactions under a unified booking identifier or correlated metadata, and a booking orchestrator configured to place bookings with a flight provider and a logistics provider based on the selected association or to output machine-readable booking payloads or deep links that, when invoked by a client device, effectuate the bookings according to the selected association. 59. The system of item 58, which may further comprise a tracking subsystem configured to issue unique identifiers for luggage items, to receive scan or webhook events from logistics providers, and to record movement history accessible to a user. 60. The system of item 58, which may further comprise a coordination module configured to reconcile flight schedules with logistics delivery timelines and to reschedule logistics events responsive to flight changes. 61. The system of item 58, which may further comprise a customs module configured to collect customs data during booking and to generate and transmit declarations for cross-border shipments. 62. The system of item 58, which may further comprise a hospitality integration adapter configured to notify hotels of incoming luggage and to capture receipt confirmations. 63. The system of item 58, wherein the optimization engine may be configured to rank bundled offers by at least one of cost, delivery time, reliability, or emissions. 64. A non-transitory computer-readable medium storing instructions that, when executed by one or more processors, may cause a system to perform the method of item 48. 65. The method of item 48, which may further comprise storing booking, identity verification, payment, and tracking data in a transaction database protected by encryption, access control, and digital signatures. 66. The system of item 58, wherein authentication may be performed using OAuth 2.0 and OpenID Connect and transaction data may be cryptographically signed for non-repudiation. 67. The method of item 48, which may further comprise presenting optional add-on services including at least one of insurance, carbon offset subscriptions, airport shuttle reservations, or mobile subscriber identity module activation, and incorporating selected services into the single checkout transaction.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A computer-implemented method for booking passenger travel with decoupled luggage transport, comprising: receiving, via a user interface or programmatic interface, travel parameters for a passenger and an indication to transport luggage via a logistics service distinct from a passenger flight; obtaining, via one or more machine interfaces including application programming interfaces, available flight options satisfying the travel parameters and available luggage logistics options between a pickup location and a delivery destination; generating at least one association between at least one flight option and at least one logistics option as a bundled offer or as linked booking artifacts; presenting the association for selection in a single view or as a coordinated sequence of user interface interactions or exposing a machine-readable representation for automated selection by a client device or agent; receiving a selection of the association; processing payment for the passenger flight and the luggage logistics service or orchestrating separate but linked provider-directed payment flows under a unified booking identifier or correlated metadata that links provider records, or emitting booking artifacts that cause provider-side payment collection while preserving the correlation; and causing, responsive to the selection, bookings to be placed with a flight provider and a logistics provider or transmitting booking instructions to effectuate the bookings according to the selected association or generating machine-readable booking payloads or deep links that, when invoked by a client device, effectuate the bookings according to the selected association, or correlating independently placed provider bookings by ingesting provider confirmations via emails, webhooks, receipts, or status pages while preserving the unified booking identifier or correlated metadata.
2. The method of item 1, further comprising computing and displaying an estimated luggage delivery time and a comparative carbon emissions metric relative to transporting the luggage on the passenger flight.
3. The method of item 1, wherein obtaining the luggage logistics options comprises querying a plurality of logistics providers and ranking the options based on at least one of cost, delivery time, projected emissions, reliability metrics, or capacity.
4. The method of item 1, further comprising issuing, for each luggage item, a unique machine-readable identifier and associating the identifier with a tracking record stored in a database.
5. The method of item 1, further comprising verifying an identity of the passenger and a custody of the luggage at pickup or drop-off using at least one of digital identification, biometric authentication, or a code scan.
6. The method of item 1, further comprising coordinating a luggage delivery schedule with changes in a passenger flight itinerary, including rescheduling a logistics handoff responsive to a flight delay or rebooking.
7. The method of item 1, wherein the delivery destination comprises a hotel or accommodation, and further comprising transmitting a notification to a hospitality system indicating incoming luggage and recording a receipt confirmation upon delivery.
8. The method of item 1, further comprising collecting customs declaration data during booking and transmitting the data to customs authorities or to the logistics provider for cross-border shipments.
9. The method of item 1, wherein processing the payment comprises a single checkout and further comprises disbursing funds to the flight provider and the logistics provider according to predefined or dynamic terms optionally enforced by a smart contract.
10. The method of item 1, wherein the luggage logistics options include at least one mode selected from ground freight, rail cargo, maritime shipping, and cargo-only air services.
18. The method of item 1, further comprising storing booking, identity verification, payment, and tracking data in a transaction database protected by encryption, access control, and digital signatures.
20. The method of item 1, further comprising presenting optional add-on services including at least one of insurance, carbon offset subscriptions, airport shuttle reservations, or mobile subscriber identity module activation, and incorporating selected services into the single checkout transaction.
11. A system for booking passenger travel with decoupled luggage transport, comprising: a front-end interface configured to receive travel parameters and an indication to transport luggage via a logistics service distinct from a passenger flight; a flight booking module configured to obtain flight options via airline application programming interfaces; a logistics integration module configured to obtain luggage logistics options via provider application programming interfaces; an optimization engine configured to associate flight options with logistics options to form bundled offers or linked booking artifacts; a payment manager configured to process a single transaction for a selected association or to orchestrate separate but linked transactions under a unified booking identifier or correlated metadata; and a booking orchestrator configured to place bookings with a flight provider and a logistics provider based on the selected association or to output machine-readable booking payloads or deep links that, when invoked by a client device, effectuate the bookings according to the selected association, or to ingest provider confirmations via emails, webhooks, receipts, or status pages and correlate independently placed bookings while preserving the unified booking identifier or correlated metadata.
12. The system of item 11, further comprising a tracking subsystem configured to issue unique identifiers for luggage items, to receive scan or webhook events from logistics providers, and to record movement history accessible to a user.
13. The system of item 11, further comprising a coordination module configured to reconcile flight schedules with logistics delivery timelines and to reschedule logistics events responsive to flight changes.
14. The system of item 11, further comprising a customs module configured to collect customs data during booking and to generate and transmit declarations for cross-border shipments.
15. The system of item 11, further comprising a hospitality integration adapter configured to notify hotels of incoming luggage and to capture receipt confirmations.
16. The system of item 11, wherein the optimization engine is configured to rank bundled offers by at least one of cost, delivery time, reliability, or emissions.
19. The system of item 11, wherein authentication is performed using OAuth 2.0 and OpenID Connect and transaction data are cryptographically signed for non-repudiation.
17. A non-transitory computer-readable medium storing instructions that, when executed by one or more processors, cause a system to perform the method of item 1.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A method for reducing carbon dioxide emissions in passenger travel over a distance greater than 100 km, comprising:
transporting a passenger along a first travel path by air;
transporting at least one piece of luggage associated with the passenger along a second, different travel path by land; and
coordinating the passenger transport and the luggage transport using a unified booking identifier such that the passenger and the luggage arrive at a common destination within a specified delivery window.

The method of item 1, wherein the second travel path comprises at least one of rail or truck transport.

The method of item 1, wherein the unified booking identifier is generated as a cryptographic token binding the passenger booking and luggage booking.

The method of item 1, further comprising calculating a comparative emissions profile between conventional luggage-by-air transport and the decoupled transport, and displaying an emissions savings value to the user during booking.

The method of item 1, wherein the luggage is tracked using a tag comprising one of a QR code, RFID identifier, or digital token, and wherein custody events are recorded in an append-only event log.

The method of item 1, wherein the booking process is executed through a cloud-based orchestration system that queries both airline booking APIs and logistics provider APIs and outputs bundled offers matching arrival and delivery windows.

The method of item 1, further comprising rendering customs forms based on collected declarations and transmitting them to a logistics provider or customs authority for clearance.

### Embodiment GE: LLM Task Orchestrator

A system and method are disclosed for orchestrating task resolution through a language model (LLM) that autonomously initiates interactions with human agents. Rather than responding solely to user prompts, the LLM receives a task or query, analyzes its content, determines which elements can be resolved internally, and identifies which aspects require human knowledge or real-world input. The LLLM consults a structured memory containing metadata about available human agents, including their skills, knowledge domains, availability, historical reliability, and preferred communication channels. It then generates and dispatches prompts to selected humans via appropriate channels (e.g., messaging platforms, email, SMS).

The system enables two-way interaction: a human receiving a prompt may engage in follow-up conversation with the LLM, request clarification, obtain supporting information, or request redirection to a more appropriate person. Additionally, the LLM may request that humans perform specific actions in the physical world, such as inspecting a device, manipulating an object, or uploading images or sensor data. All responses are interpreted and incorporated into the LLM's reasoning loop to iteratively refine task state and reach resolution. The system maintains performance metrics for each human participant-such as accuracy, response time, and resolution rate-which may inform future task routing, reward allocation, or removal from the agent pool. The final answer is returned to the original requester through the initiating channel. This architecture enables the LLM to function as a dynamic task orchestrator across distributed human networks, extending its capabilities into the physical world via delegated sensing, actuation, and social coordination.

### Gentle Introduction

Many organizations already use chat tools and ticketing systems, but these tools typically wait for people to provide answers and do not coordinate among the right people automatically. The disclosed system treats a language model as a coordinator that can ask the right humans for help, much like a diligent assistant who knows whom to contact, how to ask, and when to follow up. When a user asks a question, the system may figure out what is known and what is missing, then reach out to specific people to gather facts, approvals, or real-world observations such as a photo of a device or a reading from a display. The model may keep track of each mini-conversation as a thread with a simple goal, like confirming a deployment or obtaining an approval, and it may keep these threads organized while people reply at different times and over different channels.

As replies arrive, the system may fold what it learns back into its understanding of the original question and decide whether to ask a follow-up, ask someone else, or finish the task. Over time, it may learn which people are fast and accurate for certain topics and route future questions accordingly. From the outside, this looks like a single assistant that can reliably get things done by coordinating with the right humans and by asking for concrete evidence when needed. The result is a faster, more trustworthy way to complete tasks that combine digital knowledge with physical verification, without requiring the user to manually track down each contributor.

### EXAMPLES

This section provides concrete, step-by-step walkthroughs with explicit data structures and Model Context Protocol (MCP) integration to illustrate externally observable behavior and reproducible interactions.

### Example 1: Coordinated Verification of a Production Rollout and Approval

A user enters “Can you check if the new pricing rules have been rolled out and approved?” The orchestration engine creates a task record and composes a reasoning prompt containing the user query and relevant context. The reasoning component identifies two objectives, namely confirming production rollout and confirming approval status, and produces two structured actions with thread correlation ready for dispatch, for example:

{“actions”:[{“threadId”:“T-301”,“recipient”:“Mark”,“channel”:“slack”,“objective”:“Confirm prod
rollout of pricing rules”,“message”:“Hi Mark, have the new pricing rules been rolled out to
production? If yes,
when?”,“timeoutSec”:900},{“threadId”:“T-302”,“recipient”:“Ann”,“channel”:“email”,“objective”:“Co
nfirm pricing approval”,“message”:“Hi Ann, have the new pricing rules received final approval? If
yes, by whom and when?”,“timeoutSec”:1800}]}

The orchestrator may expose transport-agnostic tools via MCP so the reasoning component can request I/O without embedding vendor-specific APIs. An example MCP call to send Mark's message is: {“tool”:“send_message”,“args”:{“threadId”:“T-301”,“recipient”:“Mark”,“channel”:“slack”,“message”:” Hi Mark, have the new pricing rules been rolled out to production? If yes, when?” }} The MCP server routes to the configured Slack module which performs API calls and returns a signed dispatch receipt.

Mark replies “Rolled out this morning.” Ann replies “Approved yesterday by the pricing committee.” Each reply is captured via channel webhooks and normalized into a typed schema such as:

{“threadId”:“T-301”,“messageId”:“m-8821”,“from”:“Mark”,“text”:“Rolled out this
morning.”,“artifacts”:[ ],“receivedAt”:“2024-03-11T09:14:03Z”} and
{“threadId”:“T-302”,“messageId”:“m-9910”,“from”:“Ann”,“text”:“Approved yesterday by the pricing
committee.”,“artifacts”:[ ],“receivedAt”:“2024-03-11T09:20:18Z”}

The engine updates thread states and summarizes context, for example: {“thread”:{“threadId”:“T-301”,“objective”:“Confirm prod rollout of pricing rules”,“state”:“responded”,“recipient”:“Mark”,“channel”:“slack” }} The reasoning component integrates replies, determines both objectives are fulfilled, and drafts the final answer.

The system returns “Yes, the new pricing rules were rolled out to production this morning and approved yesterday by the pricing committee.” A provenance snippet may be attached: {“taskId”:“K-1007”,“contributedThreads”:[“T-301”,“T-302”],“confidence”:0.97}

### Example 2: Physical Verification of a Cooling Unit

A user enters “Can you check if the cooling unit in the server room is working correctly?” The system determines that on-site visual verification is required. Using availability and skill profiles, the orchestrator selects Tariq and issues a prompt over SMS using an MCP tool call:

{“tool”:“send_message”,“args”:{“threadId”:“T-410”,“recipient”:“Tariq”,“channel”:“sms”,“message”:“P
lease check the server room cooling unit and report the temperature reading. Include a photo of the
display.”}}

Tariq replies with text and a photo link. The channel adapter emits a normalized message and an artifact record, for example:

{“threadId”:“T-410”,“messageId”:“m-7742”,“from”:“Tariq”,“text”:“Display shows 35° C. Photo
attached.”,“artifacts”:[{“type”:“image”,“url”:“https://example.com/a1.jpg”,“sha256”:“f1a2...”,“exifTim
estamp”:“2024-03-11T10:02:11Z”}]}

The reasoning component interprets 35° C. as out of range and marks the objective as reached with a fault condition. If needed, it may invoke an MCP tool to open a maintenance ticket, for example:

{“tool”:“open_ticket”,“args”:{“taskId”:“K-2012”,“title”:“Cooling unit over-temp
35° C.”,“evidenceThread”:“T-410”}}

The user receives “The cooling unit is on, but it is not operating within the expected temperature range. The current reading is 35° C. A photo has been provided by the on-site technician.” The task record includes signed receipts linking dispatches and replies to thread T-410.

### Representative Inline Object Models Used Across Both Examples

A ChatThread snapshot may appear as: {“threadId”:“T-301”,“objective”:“Confirm prod rollout of pricing rules”,“state”:“awaiting_response”,“recipient”:“Mark”,“channel”:“slack”,“timeoutSec”:900,“correlatio n”:“abc-123” }A meter event for billing may appear as:

{“tenantId”:“TEN-42”,“seq”:128881,“category”:“llm_tokens”,“qty”:1542,“taskId”:“K-1007”,“timesta
mp”:“2024-03-11T09:21:00Z”}

### Background

Organizations may rely on a combination of chat tools, ticketing systems, and manual coordination to answer questions and complete cross-functional tasks. Conventional chatbots typically respond passively to prompts and do not proactively contact specific humans, manage multi-threaded objectives, or request physical-world verification. Existing approaches may lack structured memory about available human agents, have limited observability into who contributed which facts, and require operators to aggregate partial responses manually across disparate channels. As a result, time-to-resolution may be high, accuracy may be inconsistent, and auditability may be insufficient for regulated environments or enterprise governance.

### Summary

In some embodiments, a language-model-based orchestration engine receives a user's task query, decomposes it into conversational subthreads with defined objectives, and autonomously engages human recipients across multiple channels to gather missing facts, approvals, and real-world observations. A structured memory maintains task context and thread states, while optional profiling and policy modules inform routing, escalation, and entitlement enforcement. The system iteratively re-prompts the LLM as replies arrive, closing objectives when fulfilled and synthesizing a final answer that is returned to the initiating user. Metering, billing, and license controls may support subscription models, and auditable records may provide provenance and external observability.

### Detailed Description

### Example Use Case: AI-Orchestrated Multi-Human Task Resolution

To illustrate the invention, consider the following scenario:
A user types a natural language query into the system's interface:
“Can you check if the new pricing rules have been rolled out and approved?”

Upon receiving the query, the system instantiates a task resolution agent powered by a language model (LLM). The LLM parses the query and determines that it contains two sub-questions:
Whether the pricing rules have been rolled out to the production environment.
Whether the pricing rules have received final approval.

The LLM checks its internal memory, which includes recent system logs and previously resolved tasks. It finds that the rollout to a staging environment has been completed, but has no information about the production deployment or the approval status.

To fill these gaps, the LLM consults its structured memory containing information about available human collaborators. This memory indicates that: Mark is a DevOps engineer knowledgeable about deployments to production.

Ann is a finance lead responsible for approval of pricing rules.

The LLM determines that it must contact both individuals. Internally, it generates the following two message instructions:

These messages are passed to the system's messaging router, which delivers them through the appropriate channels and awaits responses.

Mark responds via Slack:
“Yes, they were rolled out to production this morning.”

Ann replies via email:
“Yes, they were approved yesterday by the pricing committee.”

Each response is received by the system and processed by the LLM. The LLM updates its internal task state and verifies that the user's query has been fully resolved. It then constructs the following response:
“Yes, the new pricing rules were rolled out to production this morning and approved yesterday by the pricing committee.”

This answer is sent back to the original user through the same channel where the query was received.

In an alternative scenario, had either Mark or Ann been unavailable, uncertain, or provided incomplete information, the LLM may have asked follow-up clarification questions, requested a screenshot, log snippet, or document as evidence, or redirected the prompt to another qualified individual based on the people memory. Additionally, the system may log metadata about the interaction, such as the time taken to respond, whether follow-up questions were needed, and the perceived helpfulness or clarity of the response. Over time, these records are used to maintain a performance profile for each human participant. These profiles can be used to improve future task routing or support human resource decisions such as delegation authority, skill tagging, or access restrictions.

This example demonstrates how the LLM agent operates not just as a passive question-answer system, but as an active orchestrator: prompting humans, managing dependencies, and autonomously completing tasks that span digital and human input channels.

### Example Use Case: LLM Requests Human to Inspect the Physical World

In a second scenario, a user enters the following query into the system: “Can you check if the cooling unit in the server room is working correctly?”

The system routes this query to the LLM agent, which parses the task and identifies that: It lacks direct access to sensor data from the server room.

The condition of the cooling unit must be visually or physically verified.

The LLM consults its structured memory to identify a person who is physically present at the location and capable of performing the task. It finds that Tariq, a local IT technician, is currently on-site and available.

The LLM internally generates the following message:

Tariq receives the prompt via SMS, walks to the server room, inspects the cooling unit, and notices that the temperature display reads 35° C.—much higher than normal. He takes a photo and replies with the following message:
“It's running, but the display shows 35° C. Here's a photo: [link or attachment]”

The system ingests this reply, attaches the image metadata to the task, and routes the content back into the LLM's reasoning loop.

Based on the high temperature and the human-provided visual confirmation, the LLM determines that the cooling unit is technically running but not functioning properly.

It composes and returns the following answer to the original user:
“The cooling unit is on, but it is not operating within the expected temperature range. The current reading is 35° C. A photo has been provided by the on-site technician.”

The system may also take further automated steps based on preconfigured rules or additional LLM inference, for example by opening a maintenance ticket, notifying the infrastructure manager, or asking Tariq to verify the airflow and compressor noise.

In this example, the LLM has delegated a physical-world inspection to a human, accepted photo evidence as input, interpreted a real-world measurement, and resolved the original query with grounded, observed data. The system also logs the latency, completeness, and reliability of Tariq's response, updating his human agent profile accordingly.

### System Loop in 8 Abstracted Steps:

Upon receiving a task query from a human user, typically in natural language form, the system constructs an input prompt for a language model (LLM), wherein said prompt comprises the original user question, relevant contextual metadata, and any previously known facts stored in system memory. The LLM analyzes the prompt and determines whether it can fully resolve the task using internal reasoning. If the LLM determines that one or more pieces of information are missing or uncertain, it generates a structured set of actions necessary to progress toward resolution. These actions may include contacting specific human agents who are likely to possess the required information, requesting those individuals to perform physical inspections, uploading photographic evidence, or confirming the status of a process or event. Each action returned by the LLM includes a recipient identifier, a preferred communication channel (such as Slack, email, or SMS), and a message payload formulated by the LLM to elicit a precise and relevant response. Upon receiving this structured output from the LLM, the system initiates a separate conversational thread for each action, whereby a message is transmitted to the target individual via the selected communication channel. Each such thread is tagged with a task identifier and remains open until a human response is received or a timeout condition is met. When a response is submitted by a human, the system logs the reply, associates it with the originating thread and task, and normalizes the content as needed for further reasoning. Once sufficient responses have been collected-or upon reaching a defined time or confidence threshold—the system constructs a new LLM input prompt comprising the original question, all received human replies, and the evolving contextual state of the task. This updated prompt is submitted to the LLM, which reevaluates the task, integrates the new information, and returns a new set of actions or, if the task is deemed complete, a finalized answer to be delivered to the original requester. This loop may be repeated iteratively, allowing the LLM to coordinate among multiple humans across asynchronous channels, recursively issue follow-up instructions, or escalate to alternative agents as needed. Upon task completion, the system may optionally update the performance record of each participating human based on accuracy, helpfulness, response time, and engagement level. This data may be used for future task assignment, access control, or incentive mechanisms. The final output is returned to the initiating user through the original interface, accompanied by a traceable task record, and all associated conversational threads may be archived or closed accordingly.

In some embodiments, a main task is initiated by a user query. The system invokes a language model (LLM) to decompose the task into a set of conversational subthreads, each of which is assigned a distinct chat objective and linked to a specific human recipient via a designated communication channel. As replies are received or timeouts occur, each thread is updated with its current state, including the history of exchanged messages, the evaluated objective status, and any detected obstacles to completion. The main LLM is periodically or reactively re-invoked with the full current state of the task, comprising the overarching task goal, the state of each thread, summaries of replies, the objective fulfillment status of each thread, and any auxiliary system context. Based on this holistic input, the LLM generates a new set of actions, which may include sending follow-up prompts within existing threads, reassigning a conversation to a different human, closing threads where the objective has been reached, or composing and delivering a final answer to the initiating user. Additionally, the LLM may initiate entirely new conversation threads by assigning new chat objectives to selected humans, thereby expanding the coordination space dynamically as task resolution progresses. This architecture enables iterative, multi-human coordination driven by a central reasoning engine, with each chat thread acting as an independently evolving unit of work tied to a verifiable subgoal.

In some embodiments, each thread maintains a structured representation of its associated objective, a conversation history log, and a state indicator selected from a predefined set of possible states such as open, awaiting response, responded, objective_reached, blocked, escalated, or closed. In further embodiments, the system may include a performance profiling module that records metadata associated with each human participant, such as response time, helpfulness, frequency of reassignment, and objective completion rate. These profiles may be used by the LLM or a policy engine to optimize future task decomposition, contact routing, or incentive mechanisms. In some cases, the system may employ confidence scoring, content verification, or cross-agent agreement mechanisms to determine whether a chat objective has been sufficiently fulfilled. In further embodiments, the LLM may generate messages with suggested formats (e.g., include/exclude file attachments, ask for confirmation, propose options) based on the nature of the objective and the recipient's communication preferences. This flexible framework allows the system to function as a general-purpose LLM-driven orchestration engine for resolving complex tasks that depend on distributed human knowledge, physical-world inspection, or decision-making input from multiple stakeholders.

### Example ChatThread Object

Each conversation initiated by the system is represented as a thread with a clearly defined objective. The objective may be fulfilled, blocked, escalated, or redirected based on human responses. These conversational threads are evaluated collectively, along with the overarching task goal, by a central reasoning engine that determines how to advance the task. This structure enables distributed, asynchronous resolution of complex queries through a dynamic interplay of language model reasoning and human participation.

### LLM Reasoning Cycle:

In each iteration, the reasoning component accepts an input that includes the main task prompt together with a list of all current ChatThreads, their states, summaries of human replies, and whether their objectives have been reached, optionally augmented by knowledge base entries. Based on this input, the reasoning component produces an output that may specify new or updated chat threads such as forwarding a designated thread to a different recipient, propose rephrased prompts for clarification, indicate closure of particular threads, or provide a final task resolution when all objectives are met.

### Core Working of the Invention

At the core of the system is a language model (LLM) configured to receive a task or problem description in natural language and decompose it into a set of conversational threads, each linked to a specific human recipient and assigned a well-defined chat objective. Each thread represents a subgoal necessary to achieve overall task resolution and is communicated via a selected human-facing channel such as email, messaging apps, or SMS. The LLM formulates the initial message for each thread and tracks the state of the objective associated with that thread as responses are received or as additional context evolves.

As human replies are collected, each thread is evaluated to determine whether its objective has been fulfilled, is blocked, or requires redirection, escalation, or follow-up. These threads operate asynchronously and independently, but all contribute toward the resolution of the overarching task.

The system periodically or event-triggered re-prompts the LLM with a summary of the current thread states, response content, and task context, allowing the LLM to generate new actions. These actions may include creating new chat threads with new objectives, modifying existing ones, closing completed threads, or returning the final result to the initiating user.

The task is considered resolved when all active chat threads have reached a terminal state with their objectives marked as fulfilled, and the LLM is able to synthesize a complete and coherent response based on the collected inputs. This architecture enables distributed, asynchronous, and iterative resolution of complex tasks by leveraging human insight and physical-world verification, coordinated entirely through dynamic prompting by the LLM.

### Technical Effects

The disclosed orchestration may reduce time-to-resolution by scoring and routing objectives to humans who are likely to respond quickly and accurately, may improve answer quality via cross-agent agreement and evidence validation, and may enhance scalability by decoupling asynchronous conversational threads through a message bus with idempotent consumers. Audit-grade traceability and provenance may be achieved through signed task records and exportable receipts, while cost-aware planning and metering may constrain usage under budget or entitlement limits. Robustness may be increased by enabling fallback rules-based operation during LLM unavailability, and interoperability may be broadened by supporting multiple communication channels, localization, and translation while preserving domain terminology.

From a computing standpoint, the disclosed mechanisms may provide specific improvements to the functioning of computer systems and networks, including reduction of duplicate outbound requests via idempotent dispatch and consumer semantics on a distributed message bus, deterministic prompt reconstruction using compact snapshots that reduce state divergence and memory corruption risk across restarts, cryptographically verifiable receipt chains with nonces that increase integrity of cross-system event logs without deep internal inspection, and transport-agnostic tool invocation via MCP that decouples reasoning from I/O to reduce vendor lock-in and error propagation across heterogeneous APIs. These effects may manifest as lower end-to-end latency variance, fewer failed or duplicated channel calls under retry, reduced token consumption per resolved task through cost-aware planning signals, and improved reliability under partial failures due to bounded, replay-safe state transitions.

### Enabling Description

In an exemplary embodiment, the system comprises a central coordination engine powered by a large language model (LLM), a task database, a thread state store, a context memory module, and a set of pluggable channel modules for interfacing with human users via various communication APIs (e.g., Slack, email, WhatsApp, SMS). The system receives an initial user query, which is processed and normalized before being passed to the LLM as part of a structured prompt that may include historical context, system memory, task metadata, and any recent related queries or responses.

Upon processing this prompt, the LLM returns a structured set of actions, which may include one or more human contact instructions. Each such instruction includes a recipient identifier, a preferred communication channel, a formulated message, and a defined objective that specifies what kind of information or action the LLM expects to result from the conversation. These instructions are stored in the task database and are each assigned a unique chat thread identifier. For each instruction, the system invokes the corresponding channel module—such as a Slack module, email module, or WhatsApp module—each of which contains the necessary logic to authenticate and communicate with its respective API. These channel modules are responsible for delivering messages to the appropriate human user and for receiving and normalizing human replies.

Each message thread and its corresponding objective are tracked in the thread state store, which may be implemented as a relational database, key-value store, or structured document store, depending on scalability and performance requirements. Each thread maintains metadata including its state (e.g., open, awaiting response, responded, blocked, objective_reached, closed), message history, timestamps, and associated user IDs. All thread-level information is periodically aggregated into a higher-level task context, which is stored in the context memory module. The context memory is a structured object (e.g., a JSON document, a vector database with semantic indexing, or a hybrid memory graph) that includes summaries of all threads, their current objective status, and extracted information from human responses.

The central coordination engine periodically or reactively (e.g., upon new replies) composes a new prompt to the LLM, embedding the main task goal, the current memory context, and the status of all ongoing threads. The LLM processes this updated context and returns a new set of actions, which may include sending follow-up prompts within existing threads, forwarding a thread to another human participant, closing a thread due to objective completion, or creating a new thread to initiate a conversation with a different human. Optionally, the LLM may also return a complete final answer to the initiating user if it determines that all necessary objectives have been fulfilled and no further action is required.

Each channel module is stateless and designed to interface with standard communication APIs. For instance, the Slack module may use the Slack Events API and OAuth tokens to send and receive messages and thread replies, while the email module may use SMTP for outgoing messages and IMAP or webhook-based email gateways for ingesting responses. All responses received from humans are parsed, timestamped, associated with the corresponding thread, and passed into the memory system to update thread summaries and influence subsequent LLM prompts.

Additionally, the system may include a performance profiling subsystem, which records human-agent interaction metrics (e.g., response time, message clarity, frequency of reassignment) and stores them in a reputation or scoring database. These profiles may be used in future LLM calls to influence the choice of which human to contact or whether a task should be escalated or reassigned.

In some embodiments, the system may use a distributed message bus or event queue (e.g., Kafka, RabbitMQ) to coordinate communication between the orchestration engine, memory module, channel modules, and database subsystems. This allows the architecture to support asynchronous operation, horizontal scaling, and fault tolerance.

To promote transport-agnostic interoperability and reduce coupling between reasoning and I/O, the orchestration engine may expose input and output capabilities as Model Context Protocol (MCP) tools that the reasoning component can invoke with structured arguments. A representative MCP tool registry entry for message dispatch may be expressed as: {“tool”:“send_message”,“argsSchema”:{“threadId”:“string”,“recipient”:“string”,“channel”:“string”,“m essage”:“string”,“timeoutSec”:“number”,“correlation”:“string” }} and a corresponding invocation emitted by the reasoning component may be: {“tool”:“send_message”,“args”:{“threadId”:“T-410”,“recipient”:“Tariq”,“channel”:“sms”,“message”:“P lease check the server room cooling unit and report the temperature reading. Include a photo of the display.”,“timeoutSec”:1800,“correlation”:“c-77” }} The MCP server mediates these invocations by selecting the appropriate channel module, performing the vendor-specific API calls, and returning a normalized receipt such as: {“ok”:true,“dispatchld”:“d-9931”,“threadId”:“T-410”,“channel”:“sms”,“sentAt”:“2024-03-1IT10:00:0 5Z”,“nonce”:“n-5f2a” } For inbound events, the MCP server or channel adapters may surface normalized messages to the orchestration engine using a common schema, for example: {“threadId”:“T-410”,“messageld”:“m-7742”,“from”:“Tariq”,“text”:“Display shows 35° C. Photo attached.”,“artifacts”:[{“type”:“image”,“url”:“https://example.com/a1.jpg”,“sha256”:“fla2 . . . ”,“exifTim estamp”:“2024-03-11T10:02:11Z” }],“receivedAt”:“2024-03-11T10:02:13Z”,“nonce”:“n-6a10”,“signat ure”:“hmac: . . . ” } The context memory may persist a compact, reconstructable snapshot suitable for deterministic prompt rebuilding and audit, for example: {“taskId”:“K-2012”,“goal”:“Verify server room cooling unit”,“threads”:[{“threadId”:“T-410”,“objective”:“Obtain temperature reading and photo”,“state”:“responded”,“recipient”:“Tariq”,“channel”:“sms”,“lastMessageld”:“m-7742”,“confidenc e”:0.62}],“facts”:[{“k”:“temperature_c”,“v”:35,“src”:“T-410”, “ts”:“2024-03-11T10:02:11Z” }],“proven ance”:{“dispatches”:[“d-9931”],“receipts”:[“m-7742”]}}MCP tool discovery may be performed during session initialization so the reasoning component only generates calls that conform to the advertised tool names and argument contracts, and receipts may be signed with nonces to enable external observability and replay protection consistent with the security measures described elsewhere herein.

This enabling framework provides a practical method for implementing a dynamic, LLM-driven coordination system in which the main task is decomposed into discrete human-facing chat threads, each tied to a specific objective. As objectives are reached, blocked, or escalated, the system continues to cycle through reasoning phases until the task is fully resolved and a final output is produced.

Alternative embodiments may use different database technologies, eventing primitives, or orchestration policies while preserving the functional behavior described.

The claimed LLM Orchestrator produces a technical effect that extends beyond mere business or organizational considerations. Specifically, the system reduces redundant communication and task misallocation by directly routing problem statements to the most suitable expert, thereby lowering computational load, minimizing unnecessary iterations, and accelerating project convergence. These improvements manifest as reduced processor cycles, lower network traffic, and shortened system operation times. Such reductions constitute a measurable technical improvement in the functioning of the data processing system itself. As a secondary consequence, reduced system load and faster completion times directly lower the energy consumed by both computing infrastructure and human interaction with the system, which correlates with reduced CO2 emissions. The invention therefore achieves a verifiable technical effect-namely, improved resource efficiency of the system-which satisfies the requirement for patentable subject matter.

### Monetization and Subscription-Model Enablement

In some embodiments, the system is deployed as a multi-tenant service in which each tenant is associated with a plan record that defines subscription tier, seat count, feature entitlements, rate limits, and service-level objectives. A tenant registry stores, for each tenant, a unique tenant identifier, billing account linkage, plan parameters, and effective entitlement policies. The orchestration engine, prior to initiating LLM inference or dispatching human-facing messages, consults a policy enforcement module that evaluates the tenant's entitlements against the requested action. This enforcement may gate capabilities such as the maximum number of concurrent tasks, maximum number of open conversational threads, access to particular communication channels, availability of performance profiling features, or the ability to request physical-world verification.

In further embodiments, usage is metered through a metering subsystem that records, per tenant and per time window, counters including the number of tasks initiated, the number of conversational threads created, total human messages dispatched, total human responses ingested, aggregate LLM tokens consumed, attachments processed, and external API calls performed by channel modules. Each meter event includes a monotonic sequence identifier, a timestamp, the tenant identifier, a categorization code, and a usage quantity. Meter events are appended to an immutable billing ledger that may be implemented as an append-only log with periodic hash-chaining to produce tamper-evident monthly statements that can be exported for auditing or dispute resolution. The billing ledger may be synchronized to an external billing system via webhook or batch export to compute charges for subscription fees, usage-based overages, or pay-per-task models.

In some cases, the policy enforcement module applies soft and hard limits. Soft limits trigger graceful degradation behaviors such as queueing new tasks until the next billing window or requesting user confirmation to proceed under overage billing terms. Hard limits block actions and return a structured notice to the initiating user that includes the reason for the block and instructions to upgrade the plan or reassign priorities. The system may also support prepaid credit balances, in which the metering subsystem decrements available credits and prevents further usage when the balance reaches zero unless auto-recharge is enabled.

In additional embodiments, seat-based licensing is enforced by binding user identities in the initiating interface to seat assignments in the tenant registry and validating concurrent session counts. Enterprise deployments may integrate with single sign-on providers, and on-premises installations may employ a license server or signed license files that define entitlements and expiration, with grace periods and offline operation supported by caching validated license proofs. The system may periodically reconcile local usage with the licensing authority to ensure accurate accounting and to generate verifiable usage receipts. These receipts can include signed summaries of meter totals per category and can be retained to establish the scope and value of use in the event of an infringement damages analysis.

In some embodiments, feature entitlements are implemented via runtime feature flags that the orchestration engine reads when composing prompts and when authorizing channel module operations. Feature-flag evaluation may be deterministic per tenant and per feature, allowing A/B testing of monetized capabilities such as advanced routing heuristics, priority escalation, extended data retention, or premium channel integrations. The system may expose administrative endpoints that allow authorized tenant administrators to view usage, download billing ledgers, configure plan upgrades, and set budget alerts that trigger notifications when projected usage approaches plan thresholds.

These monetization mechanisms provide technical support for subscription and usage-based business models and generate durable, auditable records of use that can be associated with particular tenants, users, features, and time periods. Such records may be used to calculate consideration, establish the value of the technology to customers, and provide data that could support damages quantification in enforcement scenarios.

### External Observability

In some embodiments, externally observable inputs and outputs are defined such that infringement may be detected without internal inspection. Given a natural-language task input, the system may emit outbound messages over integrated channels that include thread identifiers, timestamps, and objective descriptors; it may ingest corresponding human replies and expose, through read-only administrative or audit interfaces, summaries of thread lifecycles, state transitions, and final answers keyed to task identifiers. The system may produce signed, exportable receipts and billing ledger entries that enumerate message dispatches, response counts, and LLM invocations per task and per tenant.

Channel webhooks may be signed and time-stamped, and outgoing requests may include nonces to enable third-party verification of dispatch behavior.

### Fallback Embodiments

In some embodiments, simplified or partial implementations may be employed while preserving the inventive concept of LLM-driven multi-human orchestration. A minimal deployment may operate with a single communication channel, omit the performance profiling subsystem, use static prompt templates, and implement context memory as a single structured document without a vector index.

During LLM unavailability, a rules-based policy engine may issue limited, safety-critical prompts and queue full reasoning until restoration. Objectives may be resolved with single-recipient threads and manual confirmation, while still maintaining task records and externally observable behaviors. These fallbacks may correspond to the techniques described in the itemized list, including pausing and resuming tasks, deterministic prompt reconstruction, and offline entitlement proofs.

### Scope and Interpretation

The scope of the invention may be limited only by the appended claims. Any specific embodiments, figures, flow descriptions, examples, data structures, interfaces, communication channels, or operational sequences described herein may be illustrative and non-limiting. The order of operations in any described flow may be varied, omitted, combined, parallelized, or repeated unless a particular order is expressly required by a claim. References to elements by number in the drawings may identify example implementations and do not restrict the claims to any particular arrangement, topology, or partitioning of functionality. Terms such as include, includes, including, comprise, comprises, and comprising may be used in an open-ended, non-exclusive sense. The term or may be used in an inclusive sense. A module, engine, subsystem, store, database, queue, or server may be implemented in software, firmware, hardware, or any combination thereof, in a single device or distributed across multiple devices or services. A language model may encompass any reasoning component capable of generating actions or answers, including neural models, hybrid systems with retrieval, rules-based fallbacks, deterministic policy engines, finite-state machines, decision trees, search-based planners, or combinations thereof. Channels, APIs, and platforms mentioned herein may be representative; other interfaces may be substituted without departing from the claimed subject matter. Optional features described in connection with any embodiment may be combined with any other embodiment unless inherently incompatible. No feature is essential to the invention unless expressly recited in a claim.

For avoidance of doubt and to encompass implementations that might otherwise attempt to sidestep specific terminology, a conversational thread may denote any logical association between one or more messages and a defined objective, including but not limited to explicit threads in messaging platforms, implicit groupings created via correlation identifiers, subject tokens, nonces, timestamps, or inferred clustering, and may exist within a single shared conversation or across multiple channels. A conversational thread need not be persisted or visible to end users and may be reconstructed from signed receipts or message metadata. A human recipient may denote an identified individual, a role account, a shared mailbox, a distribution list, a group channel, or a dynamically selected crowd or pool, and communication may be unicast, multicast, or broadcast with first-responder selection, consensus, or quorum logic applied. Message delivery and reply capture may occur in platforms without native threading by emulating correlation using headers or inline markers. For further clarity regarding claim terms, a defined objective may be explicit, implicit, or inferred from prompt context, message content, policy, or temporal grouping; it need not exist as a persisted field and may be emergent across multiple messages or time windows, with reconstruction from receipts or metadata being sufficient. Generating a conversational thread may include creating an explicit thread object, tagging messages with correlation identifiers for later association, or applying deterministic or probabilistic clustering in the absence of platform-native threads. References to receiving a task query from a user may also encompass initiation via external events, scheduled triggers, monitoring alerts, or policy-driven automations unless a claim expressly excludes such initiations. These interpretations are intended to capture functional equivalents and prevent avoidance by superficial changes to platform features or naming.

For further avoidance of doubt and to deter circumvention, implementations that consolidate multiple objectives into a single apparent conversation without platform-native threads, treat prompts or replies as structured interactions such as buttons, links, forms, in-application notifications, IVR prompts, or voice calls rather than purely textual messages, rely on streaming contexts or ephemeral caches rather than persisted stores, broadcast to groups or crowds with first-responder, quorum, or approver adjudication, rename modules or externalize objective association in metadata, headers, or external systems, or perform reasoning with deterministic, rules-based, or hybrid engines instead of a neural language model, remain within the scope when they perform the claimed functions of generating objective-bound conversational associations with human recipients, machine-evaluating their state, and issuing follow-up actions or a final answer. A message may encompass any human-directed prompt or reply transported over a communication interface, including but not limited to text, email, in-application chat, push notification, IVR audio, voice telephony, and structured interactions such as buttons, links, or forms.

### Anti-Workaround Scenarios

Competitors may attempt to design around the claims by altering surface features while preserving the same functional core. For example, an implementation may avoid creating visible threads and instead embed correlation tokens inside message bodies or headers, may collapse objectives into a single conversational stream with inline markers, may route via a workflow engine or BPMN script rather than a neural model, may broadcast prompts to crowds and accept the first response, may require humans to click structured approvals rather than reply with free text, may proxy communications through a bot or relay that forwards to rotating on-call staff, may persist no explicit state and reconstruct context from receipts on demand, may restrict communications to one platform or to voice-only interfaces, or may distribute orchestration across client devices to avoid a centralized server. Such variants still fall within the scope when a reasoning component generates objective-bound associations between messages and human recipients, evaluates objective state based on received human responses, and issues follow-up actions or a final answer. Functional equivalence exists whether the reasoning component comprises a neural language model, a deterministic policy engine, a decision tree, a finite-state machine, a search-based planner, or a hybrid thereof, whether the association is explicit or implicit; whether messages are free text, structured forms, IVR selections, or voice transcripts; and whether state is persisted durably, reconstructed from signed receipts, or maintained in rolling context windows. External observability through signed dispatches, nonce-bound receipts, and exportable audit summaries may be used to detect infringement even where internal modules are renamed, refactored, or distributed. Attempts to rebrand objectives as tasks, cards, approvals, or tickets without thread vocabulary, to replace native threading with subject prefixes or correlation tokens, to interpose workflow middleware that composes and sends messages based on human responses, or to claim stateless operation while emitting verifiable receipts that allow deterministic reconstruction of objective state do not avoid the claimed subject matter when the required functional steps and results are performed.

### Itemized Embodiment Features for Continuations

Embodiments can be described by the following itemized list, each item being independently combinable with others unless inherently incompatible, and each item being suitable for direct use in future continuations to expand claim coverage. For support in continuations, the list also includes entries that correspond to the claims, such that if claims are amended or removed, written-description support remains in this itemized section.

A system comprising an orchestration engine, a task database, a thread state store, a context memory, and channel modules, wherein the orchestration engine generates structured actions including recipient identifier, channel, message payload, objective, timeout, and confidence target.

A method wherein the orchestration engine computes a routing score per human participant using features from a profiling subsystem including accuracy, latency, topic domain tags, and recent load, and selects recipients maximizing expected objective completion probability.

A computer-readable medium wherein the orchestration engine requests specific evidence types (photo, log snippet, URL, sensor reading) and verifies receipt using content-type detection and metadata validation (e.g., EXIF timestamp, file hash).

A system wherein the context memory is implemented as a hybrid store combining a relational schema for conversational threads and a vector index for semantic summaries, with cross-links to knowledge base entries referenced in prompts.

An embodiment in which external communication interfaces include voice telephony and IVR, enabling spoken prompts and automated transcription for replies, with per-channel rate limiting and retry backoff policies.

An embodiment in which channel modules enforce message templates and tone guidance selected per recipient preference profile and per objective type, with localization by language and region.

An embodiment wherein a policy enforcement module gates actions based on plan entitlements from a tenant registry and feature-flag engine, including maximum concurrent threads, premium channels, and escalation privileges.

An embodiment in which the LLM composes follow-up messages that include structured options for the human to choose from, and the system parses selected options into normalized state updates for the conversation.

An embodiment supporting state transitions that include merge and split operations for conversational threads, enabling consolidation of duplicate objectives or decomposition of complex objectives into subthreads.

An embodiment providing cross-agent agreement, wherein the orchestration engine seeks corroboration from at least two distinct humans and marks an objective fulfilled only upon consistency within a defined tolerance.

An embodiment wherein the orchestration engine maintains an audit-grade traceable task record including message digests, timestamps, channel identifiers, conversational states, and final outputs, exportable as signed receipts.

An embodiment enabling on-premises deployment with a license server issuing signed proofs of entitlement to a policy enforcement module, allowing offline operation via cached proofs subject to expiration windows.

An embodiment using a distributed message bus to decouple the orchestration engine from channel modules and stores, with idempotent consumers and monotonic sequence IDs for at-least-once delivery.

An embodiment wherein the LLM employs retrieval-augmented generation that queries context memory and a tenant knowledge base prior to composing actions or final answers.

An embodiment where the orchestration engine escalates an objective when awaiting response exceeds a threshold, reassigning to a backup human with a synthesized summary of prior exchanges.

An embodiment enabling human verification workflows, where a designated approver must acknowledge a proposed final answer before delivery to the initiating user, with approver timeouts and fallbacks.

An embodiment implementing privacy controls including PII redaction in stored messages, selective retention policies per tenant, and encrypted-at-rest storage for context memory.

An embodiment handling attachments via a content pipeline that performs virus scanning, OCR, image quality checks, and semantic summarization, with links stored in the task database.

An embodiment providing template libraries for prompts keyed by objective type (status check, approval request, physical inspection), with online learning that updates templates from successful outcomes.

An embodiment enabling automated generation of maintenance tickets or external workflow triggers upon certain objective states, with confirmation requests to humans to verify that actions were executed.

An embodiment in which external observability endpoints expose read-only summaries of conversational lifecycles and outcomes for administrative or audit users, filtered by tenant and time range.

An embodiment supporting internationalization wherein the orchestration engine translates prompts and replies to and from the recipient's locale while preserving domain-specific terminology via glossaries.

An embodiment with cost-aware planning where the orchestration engine selects actions that minimize expected LLM token usage and channel costs under a quality constraint, using metering signals in the loop.

An embodiment providing fallback operation modes in which, upon unavailability of the LLM, a rules-based policy engine issues limited templates for critical objectives and queues full reasoning until restoration.

An embodiment where human profiles in the profiling subsystem are synchronized with external HR or directory systems, importing skill tags, role labels, and availability windows via secure connectors.

An embodiment allowing IoT or system instrumentation commands to be issued only after dual human confirmation, with returned telemetry attached to the relevant conversation.

An embodiment implementing confidence scoring for each objective, with per-objective thresholds determining whether to seek additional evidence or finalize.

An embodiment enabling pausing and resuming tasks, with snapshotting of context memory and deterministic prompt reconstruction for reproducibility.

An embodiment where the initiating interface provides the user with real-time status of conversational threads and estimated time to completion based on historical metrics from the profiling subsystem.

An embodiment implementing A/B evaluation of alternative follow-up prompts for the same objective, with outcome attribution and automatic selection of higher-performing variants.

An embodiment where channel modules sign outgoing webhooks and verify incoming signatures to prevent spoofing, with replay protection via nonce and timestamp checks.

An embodiment that normalizes all replies into a typed schema including evidence artifacts, asserted facts, uncertainty indicators, and action confirmations, for use in subsequent LLM reasoning.

An embodiment supporting federated deployments where an orchestration engine coordinates with peer engines via inter-tenant trust, enabling cross-organizational objectives with constrained data sharing.

An embodiment that records per-recipient service-level objectives (response time targets) and adjusts routing or escalation policies when breaches are predicted.

An embodiment wherein final answers include a provenance summary enumerating which conversational threads and evidence items contributed, to enhance trust and facilitate audits.

### Court-Readiness and Patent-Eligibility Considerations

The disclosed embodiments may be characterized as specific improvements to the functioning of computer systems and networks rather than abstract mental processes. The orchestration engine coordinates multiple machine-implemented components, including a distributed message bus with idempotent consumer semantics, channel modules that interact with external communication APIs, a context memory that produces reconstructable snapshots for deterministic prompt rebuilding, and cryptographic receipt chains that bind dispatches and replies using nonces. These mechanisms control computer operations such as API call issuance, retry handling, deduplication, and state persistence in a manner that reduces duplicate outbound requests, lowers latency variance, and mitigates state divergence across restarts. The use of transport-agnostic MCP tools enforces typed I/O contracts that decouple reasoning from side-effecting operations, reducing error propagation across heterogeneous interfaces and improving reliability of networked computation.

The asserted claims recite concrete steps and structures that transform inputs into outputs through technical data models and machine operations. For example, a received natural-language task query is transformed into structured actions containing recipient identifiers, channel selections, conversational identifiers, and message payloads; responses are normalized into typed schemas and used to drive state transitions among defined states such as awaiting response, responded, and objective_reached; and final answers are produced only after machine-evaluated objective satisfaction. These steps are performed by configured software modules operating on computer hardware and network interfaces and are not practicably performable purely by human thought, particularly where the system employs cryptographic signatures, nonce binding, metering with monotonic sequence identifiers, and deterministic prompt reconstruction.

The application defines externally observable inputs and outputs, providing objective indicia to establish infringement without internal inspection. Outbound dispatches carry identifiers, timestamps, nonces, and channel descriptors; inbound webhooks are signed and time-stamped; and audit interfaces expose task-level provenance summarizing conversational states and contributing evidence. These artifacts map to claim elements such as generating conversational threads with objectives, transmitting messages via a selected communication channel, receiving responses, updating states, and providing a final answer, thereby enabling reliable claim element-by-element comparison using exported receipts and logs.

The claimed subject matter does not preempt all forms of coordinating human interactions. Conventional ticketing or chat systems that passively receive inputs and do not generate objective-bound conversational threads, do not perform machine-evaluated state transitions with deterministic reconstruction, and do not implement transport-agnostic, typed tool invocation with cryptographic receipt chains may fall outside the claims. The claims are directed to particular machine implementations that improve networked orchestration reliability, observability, and performance through specific architectural constraints and data structures.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A method for resolving a user task using a reasoning component, comprising: receiving a task query from a user; and generating, using the reasoning component, one or more conversational threads, each comprising a logical association between one or more messages and an objective that is explicit, implicit, or inferred, and each associated with a respective human recipient, group recipient, or role account.

The method of item 1, further comprising: transmitting, for each conversational thread, a message to the respective human recipient via a selected communication channel.

The method of item 2, wherein the selected communication channel is selected from a group consisting of: email, messaging platform, SMS, or in-application chat.

The method of item 1, further comprising: receiving, from at least one of the human recipients, a response message related to the conversational thread.

The method of item 4, further comprising: updating the state of the conversational thread based on the received response.

The method of item 5, wherein the state of the conversational thread is selected from: open, awaiting response, responded, objective reached, blocked, escalated, or closed.

The method of item 1, further comprising: evaluating the current state of the conversational threads using the reasoning component to determine one or more follow-up actions.

The method of item 7, wherein the one or more follow-up actions include: sending a follow-up message, initiating a new conversational thread with a different human recipient, reassigning an objective, or marking the objective as complete.

A non-transitory computer-readable medium storing instructions that, when executed by one or more processors, cause a system to perform a method for resolving a user task using a reasoning component, the method comprising: receiving a task query from a user; and generating, using the reasoning component, one or more conversational threads, each comprising a logical association between one or more messages and an objective that is explicit, implicit, or inferred, and each associated with a respective human recipient, group recipient, or role account.

The non-transitory computer-readable medium of item 9, wherein the method further comprises: transmitting, for each conversational thread, a message to the respective human recipient via a selected communication channel.

The non-transitory computer-readable medium of item 10, wherein the selected communication channel is selected from a group consisting of: email, messaging platform, SMS, or in-application chat.

The non-transitory computer-readable medium of item 9, wherein the method further comprises: receiving, from at least one of the human recipients, a response message related to the conversational thread.

The non-transitory computer-readable medium of item 12, wherein the method further comprises: updating the state of the conversational thread based on the received response.

The non-transitory computer-readable medium of item 13, wherein the state of the conversational thread is selected from: open, awaiting response, responded, objective reached, blocked, escalated, or closed.

The non-transitory computer-readable medium of item 9, wherein the method further comprises: evaluating the current state of the conversational threads using the reasoning component to determine one or more follow-up actions.

The non-transitory computer-readable medium of item 15, wherein the one or more follow-up actions include: sending a follow-up message, initiating a new conversational thread with a different human recipient, reassigning an objective, or marking the objective as complete.

A system for resolving a user task using a reasoning component, comprising: an orchestration engine comprising the reasoning component; a task database; a thread state store; a context memory module; and one or more channel modules configured to interface with external communication application programming interfaces; wherein the orchestration engine is configured to: receive a task query from a user; generate, using the reasoning component, one or more conversational threads, each comprising a logical association between one or more messages and an objective that is explicit, implicit, or inferred, and each associated with a respective human recipient, group recipient, or role account; cause the one or more channel modules to transmit, for each conversational thread, a message to the respective human recipient via a selected communication channel; receive, via the one or more channel modules, response messages related to the conversational threads; update, in the thread state store, a state of each conversational thread based on the response messages; evaluate, using the reasoning component and the context memory module, the conversational threads to determine one or more follow-up actions; and provide a final answer upon determining that the objectives have been fulfilled.

The system of item 17, wherein the state of each conversational thread is selected from: open, awaiting response, responded, objective_reached, blocked, escalated, or closed.

The system of item 17, wherein the selected communication channel is selected from a group consisting of: email, messaging platform, SMS, in-application chat, or voice telephony.

The system of item 17, further comprising: a performance profiling subsystem configured to record per-human metrics and to provide routing features to the orchestration engine for selecting the respective human recipient.

Or alternatively:

1.

A method for orchestrating project task assignment, comprising:
receiving a problem statement within an orchestrator system;
identifying, by means of a large language model, an expert or participant most suited to address the problem statement; and assigning the problem statement directly to the identified expert,
wherein the orchestration reduces redundant task processing and accelerates convergence toward project completion.
   2.

The method of item 1, wherein the orchestrator reduces redundant message exchanges between participants, thereby lowering total network bandwidth consumption.

3.

The method of item 1, wherein the orchestrator reduces processor utilization by minimizing repeated processing cycles for misallocated tasks.

4.

The method of any of items 1-3, wherein reduced processor and network resource usage yields lower total system energy consumption during project execution.

5.

The method of item 4, wherein the reduction in energy consumption correlates with a reduced carbon footprint associated with the completion of the project.

### Embodiment HE: System and Method for Deceleration-Optimized Sleeping Pods in Autonomous Vehicles

For avoidance of doubt, the scope of the invention is only limited by the claims. All figures, block diagrams, numeric references, examples, and described configurations are non-limiting example embodiments. Steps, operations, control sequences, and component orderings may be varied, reordered, combined, or omitted unless expressly recited in a claim. Features described with respect to one embodiment may be used in others unless technically incompatible.

A vehicle-integrated safety system is disclosed for reclining or horizontal occupants in a sleeping pod that is mechanically decoupled from the vehicle frame and coupled via a tether to a controllable braking unit. During a crash event the pod is allowed to translate relative to the chassis and is arrested over an extended distance by a regulated braking mechanism, such as an eddy-current brake driven by a compound spool transmission, thereby reducing peak forces on the occupant. Sensors and a control computer determine crash severity and modulate braking to achieve a target deceleration profile. Variants include passive elastic elements, viscous and pneumatic dampers, regenerative generators, flywheel-friction systems, and deformable energy absorbers. Optional cushions or airbags inside the pod distribute loads across the body. The system supports autonomous or conventional vehicles and enables safe horizontal rest.

Background: Conventional automotive restraint systems are optimized for upright seating postures and short belt load paths anchored to the vehicle frame. As vehicles evolve toward autonomous operation and long-duration travel, passengers may desire to rest horizontally in pods, which introduces new injury mechanisms during crashes due to large relative motion and concentrated restraint loads. There exists a need for systems that extend the deceleration distance and time experienced by a reclining occupant while maintaining compatibility with vehicle packaging, power interruption scenarios, and variable crash severities.

Gentle introduction: The invention can be understood by analogy to a sled being brought to a stop along a long, smooth ramp rather than by hitting a wall. A sleeping pod holding a resting person is allowed to slide a controlled distance relative to the vehicle during a crash, and a tether connected to a braking mechanism gently stretches out the stopping process. By spreading the stop over more distance and time, the body feels a lower peak force. The pod's interior cushions increase the contact area so that loads are distributed across the torso instead of being focused on a few belt contact points. In simple terms, the system turns a sudden jolt into a longer, softer slowdown that the body can better tolerate. The detailed embodiments that follow describe how the tethered pod converts its motion into controllable resistance using mechanisms such as eddy-current brakes, fluid dampers, pneumatic cylinders, flywheels, generators, elastic elements, or deformable structures, and how sensors and a control computer may adjust the stopping force to suit the crash severity and the remaining stopping distance.

Examples: To concretize the operation, several non-limiting scenarios are described step by step. In a moderate frontal collision example, a single-occupant pod with a combined moving mass of about 130 kg travels within a 1.8 m stroke. During normal driving the control computer polls chassis and pod sensors at millisecond cadence while the pod is held at a rearward rest position by a light bias spring. A sudden deceleration exceeding the crash threshold is detected, upon which the control unit latches backup power, timestamps the event, and estimates initial relative velocity and remaining travel from encoder and accelerometer data. A constant-deceleration target is computed and translated into a time-varying magnet current command. The pod begins translating forward; within tens of milliseconds the forward-facing cushion transitions from standby to support pressure and the eddy-current brake current ramps smoothly, avoiding cable tension spikes. Over approximately 0.36 s the pod decelerates at about 2.8 g on average and comes to rest with several centimeters of reserve stroke. The controller tapers current near the end of travel to suppress rebound, records peak and average deceleration and energy-dissipation metrics, and then initiates a gentle reset in which the bias spring returns the pod to the rearward position over tens of seconds.

In a high-severity frontal collision example, the same architecture encounters an initial relative velocity near 15 m/s with the same 1.8 m stroke. The controller detects a higher-severity pulse from fused front and rear accelerometers and selects a jerk-limited, non-linear deceleration profile that applies higher braking early and reduces force near stroke end. Magnet current is driven toward a higher plateau; if present, a pneumatic damper's vent valves are simultaneously commanded to a more restrictive setting to share load and improve thermal headroom. Inflatable cushions execute a differential inflation schedule in which head-and-shoulder chambers build pressure more quickly than hip chambers. The pod stops within the available distance with a peak deceleration constrained near biomechanical limits and without hard rebound, after which logs and telemetry are secured for later analysis.

In a power-interruption and sensor-fault example, a frontal crash coincides with primary power bus collapse and a transient loss of one encoder channel. The backup supercapacitor supplies the eddy-current magnet for several hundred milliseconds, while the controller falls back to a conservative open-loop current profile based on last-known velocity and minimum guaranteed stroke, with pod-mounted accelerometer feedback supplying coarse confirmation of deceleration. If the event outlasts backup power or a brownout is detected, a passive secondary path comprising calibrated deformable elements and a viscous damper absorbs the remaining energy to ensure the pod decelerates within the stroke without uncontrolled motion. After the event, the system records the fault codes, marks the deformable elements for service replacement, and permits limited operation in a passive-only mode until maintenance is performed.

In an oblique-impact and dual-occupancy example, two occupants lie perpendicular to the vehicle's forward direction. Fused accelerometer data indicate a right-front oblique pulse; the controller slightly biases the braking profile to accommodate lateral force components while elongated side cushions along the pod wall on the impact-facing side inflate more aggressively to distribute contact loads across the outboard occupant's lateral torso and shoulder. Occupant detection mats report both berths occupied and the controller selects a deceleration curve parameterized by the combined mass. The braking unit applies the commanded force while maintaining total stroke within limits; the event concludes with synchronized deflation and a controlled pod reset. In each example, externally observable behaviors include measurable pod translation relative to the chassis, a deceleration-time history bounded by selected thresholds, and authenticated, tamper-evident logs that record activation and energy dissipation. For software integration in diagnostic and interoperability contexts, the controller may optionally expose a Model Context Protocol (MCP) tool interface over a segregated maintenance channel so that authorized service clients can request read-only summaries or signed logs without impacting the safety-critical control path. In one non-limiting configuration snapshot, a deceleration profile and occupant parameters could be represented as a compact JSON structure used for pre-crash configuration audit or post-crash reconstruction as follows:

{“profile_id”:“const-2p8g-jerk-limited”,“type”:“constant”,“a_max_mps2”:27.8,“jerk_limit_mps3”:250
.0,“stroke_m”:1.8,“mass_kg”:130,“cushion_schedule”:{“head_shoulder”:{“rise_ms”:40,“target_kpa”:6
0},“hip”:{“rise_ms”:70,“target_kpa”:45}},“ts_unix_ms”:1731612345678,“signature”:“base64:MEUCI
QDj...”}.

A representative, tamper-evident event log emitted for billing and forensic analysis may include:

{“event_id”:“evt-2025-08-16-00123”,“start_ts_ms”:1731612345600,“end_ts_ms”:1731612345960,“p
od_peak_g”:3.1,“pod_avg_g”:2.7,“energy_dissipated_j”:6520,“stroke_used_m”:1.74,“stop_time_s”:0.
36,“backup_power_used”:true,“faults”:[“ENC_CH1_LOSS”],“license_state”:“enabled-sleep-mode”,“v
ehicle_id”:“VIN-XYZ123”,“firmware”:“v1.4.2”,“signature”:“base64:MGYCMQCe...”}.

If MCP is present, a maintenance client may request such artifacts through a declared tool capability exposed by the controller (for example, an mcp://safety.pod/export_logs endpoint) with strict authentication and rate limits; the MCP integration is optional and is not required to practice the core deceleration functionality.

Summary: The disclosed system places a reclining occupant within a sleeping pod that may translate forward relative to the vehicle during a crash. A tether couples the pod to a braking unit that converts linear motion to a controllable resistive mechanism, for example an eddy-current disk driven through a compound spool and belt transmission. A control computer, informed by accelerometers and position/velocity sensing, modulates braking to follow a target deceleration curve that minimizes peak g-forces and jerk while ensuring the pod stops within the available travel. Optional cushions inside the pod increase contact area and shape load distribution. Alternative implementations include elastic, viscous, pneumatic, frictional, regenerative, flywheel, and deformable elements, which may be used alone or in combination. A rearward biasing mechanism preserves the full deceleration stroke between events. Power backup and redundant energy storage support operation during power loss. Telemetry and licensing features enable subscription models and damages quantification.

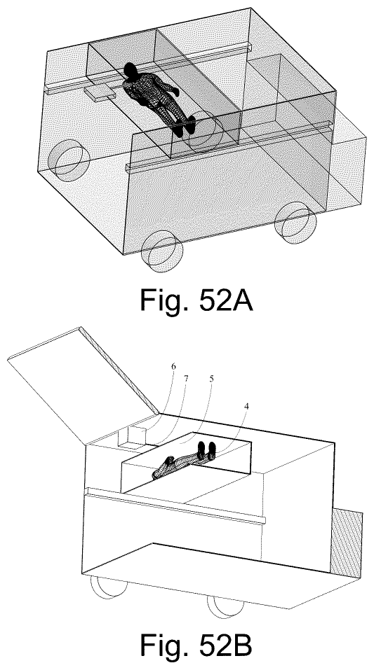

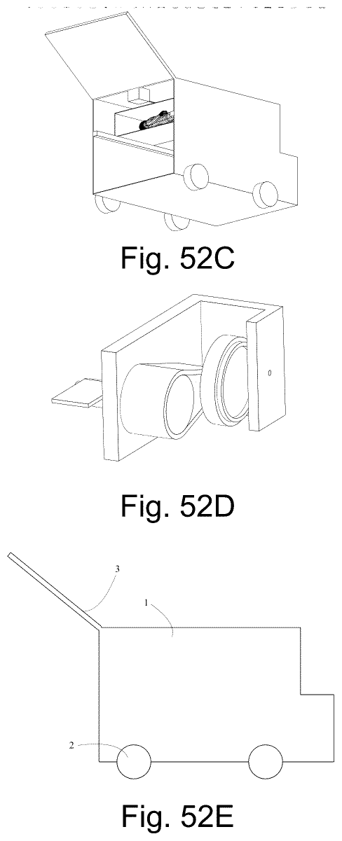

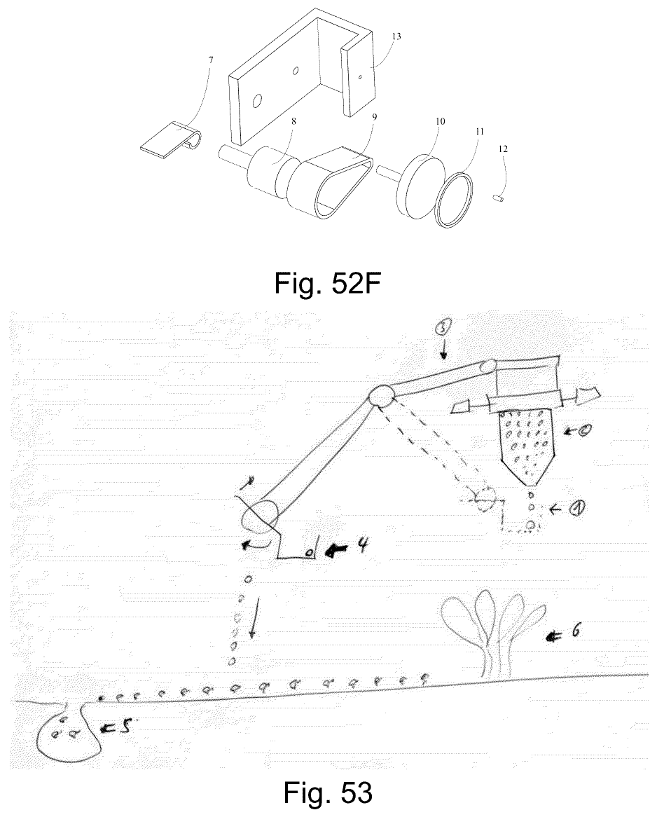

Description of the drawings: FIGS. 52A to 52F illustrate example embodiments and components. Reference numerals include: vehicle (1); wheels (2); rear hatch or door (3); human occupant (4); sleeping pod (5); braking unit (6); tether or cable (7); first compound spool with small and large drums (8); transmission belt (9); second compound spool (10); rotating conductive braking disk (11); electromagnet (12); rigid support structure or housing (13). Additional sensors and subassemblies that may appear include vehicle-frame accelerometers; pod-mounted accelerometers; position sensors integrated with the tether or guide rail; rotational encoders; control computer with backup battery or supercapacitor module; optional flywheel, viscous damper, pneumatic cylinder, friction track, and deformable elements; and inflatable cushions within the pod oriented toward expected occupant motion. The figures depict example anchor points, travel distance on the order of 1.5-2 meters, pod guide rails, and orthogonal pod orientation relative to the vehicle's forward direction.

Detailed description: In one embodiment, the invention relates to a crash-mitigating system designed to safely decelerate a horizontally oriented sleeping pod during a vehicle collision. The vehicle (1) is preferably autonomous and may be elongated to accommodate one or more passengers lying perpendicular to the direction of travel. The vehicle is supported on wheels (2) for normal road operation and includes a rear hatch or door (3) through which the sleeping area may be accessed. A human occupant (4) is positioned within a sleeping pod (5), the pod being configured to move forward relative to the vehicle frame in the event of a sudden deceleration. The pod is mechanically connected to a controlled braking unit (6) via a strap or cable (7), which is arranged to transmit the forward kinetic energy of the pod into a rotary braking system.

The cable (7) is affixed to a first compound spool (8), comprising a small-diameter drum onto which the cable winds, and a coaxially aligned larger-diameter drum. The larger drum of spool (8) is operatively coupled to a second compound spool (10) via a transmission belt (9). The second compound spool (10) likewise includes a small drum receiving input from the belt and a larger drum that is mechanically connected to a metal braking disk (11). This disk is typically fabricated from a conductive material such as aluminum or copper and rotates rapidly as a result of the speed amplification achieved through the compound spool and belt transmission.

A fixed-position electromagnet (12) is mounted adjacent to the braking disk (11) and, when energized, induces eddy currents within the disk. The resulting electromagnetic braking force is smooth, non-contact, and can be dynamically controlled based on crash severity or pod velocity. All components from spool (8) through electromagnet (12) are housed within a rigid support structure (13), which may be integrated into the floor or chassis of the vehicle. The system allows for prolonged deceleration over distances such as 1.5 to 2 meters, thereby reducing peak forces on the human occupant and mitigating injury risk. This architecture is particularly suited to self-driving vehicles, where passengers may sleep during transit in a horizontal orientation.

In a further embodiment, the controlled braking system may incorporate a passive force-biasing mechanism configured to maintain the pod in a default rearward position within the vehicle under normal driving conditions. This may be achieved by coupling the pod to a soft-tension spring, elastic cord, or similar restoring element that exerts a continuous pull on the tether or cable toward the rear of the vehicle cabin. The force applied may be low enough to avoid restricting occupant comfort or movement during normal operation, yet sufficient to gradually reposition the pod after a braking event or occupant entry. This rearward biasing ensures that, in the event of a crash-induced braking sequence, the full available deceleration path is preserved, maximizing energy dissipation distance.

The system may optionally include position sensors or damping elements to stabilize pod motion during non-crash driving scenarios, and to gently return the pod to its reset position without abrupt motion.

In one embodiment, the crash-deceleration system may include one or more accelerometers positioned within the vehicle frame, preferably at or near the structural extremities. These accelerometers are configured to continuously monitor the vehicle's linear acceleration and detect abrupt negative spikes indicative of a collision or sudden deceleration event. The sensor signal may be digitized and passed to an onboard processing unit, hereinafter referred to as the control computer, which resides within the rear compartment of the vehicle, optionally near or integrated with a backup battery module. The backup battery ensures system functionality even in the event of primary power loss.

Upon detecting acceleration levels exceeding a predefined crash threshold (e.g., a sustained deceleration exceeding −0.5 g within 50 ms), the control computer initiates a crash response protocol. This may include triggering a preloaded braking algorithm designed to optimize occupant safety by distributing the deceleration of the internal sleeping pod across the maximum possible distance and time available within the vehicle cabin.

The braking algorithm may dynamically calculate the required force profile to bring the pod from its relative velocity (with respect to the vehicle) to a halt, using real-time input from a position sensor embedded in the tether or pod guide rail, as well as predicted collision severity based on the initial deceleration spike. The desired profile may follow a constant or smoothly ramped deceleration curve, selected to minimize peak g-forces experienced by the occupant. In some configurations, the braking force may be non-linear and adaptive, increasing gradually to prevent abrupt tension spikes in the cable.

To execute the calculated force profile, the control computer modulates the current supplied to an electromagnet positioned adjacent to a conductive braking disk. The disk, which is mechanically linked to a compound spool system driven by the pod tether, rotates proportionally to the pod's movement. By adjusting the magnetic field strength over time, the system induces variable eddy currents in the disk, generating a braking torque precisely matched to the target deceleration curve.

Feedback from rotational encoders on the spool or disk may be used to confirm actual braking torque, allowing for real-time correction of braking force via a closed-loop control scheme.

In some embodiments, secondary safety protocols may be initiated simultaneously. These may include tensioning any integrated restraint belts within the pod, activating cabin lighting for emergency awareness, or transmitting a wireless distress signal. If available, inertial measurements from multiple accelerometers (e.g., front and rear axles) may be fused to improve crash direction estimation, allowing the pod braking profile to adapt to both frontal and oblique impacts.

The control unit and electromagnet assembly are ideally mounted within a rigid housing near the rear section of the vehicle, minimizing exposure to front-end deformation and preserving system integrity during high-severity frontal crashes. The system may also incorporate redundant capacitive or kinetic energy storage (e.g., supercapacitors or flywheels) to ensure consistent braking power in the moments following power disruption.

Through this arrangement, the system enables a suspended or semi-free-moving sleeping pod to decelerate smoothly and in a controlled fashion, reducing occupant injury risk and allowing safe horizontal rest during autonomous transit.

The described embodiment is configured to protect the human body during vehicular collisions by minimizing the peak deceleration forces transmitted to the occupant and distributing those forces over an extended time interval and body surface area. In contrast to conventional upright seating with rigid restraint systems, the occupant may be positioned in a reclined or horizontal posture within a sleeping pod, which itself is mechanically decoupled from the rigid vehicle frame. In the event of a crash, the pod is permitted to move forward relative to the vehicle interior, and this movement is met with a controlled, programmable braking force that gradually arrests the pod's velocity. This deceleration is governed by a braking unit that modulates resistive force using an eddy-current braking mechanism, thereby allowing the pod to decelerate over distances on the order of 1.5 to 2 meters. The resulting reduction in acceleration gradient significantly lowers the risk of injury to soft tissues, spinal structures, and internal organs.

Moreover, because the occupant lies within a cushioned pod with high surface contact, inertial forces are distributed across a broader area of the body compared to conventional seatbelt points of contact.

The horizontal orientation may further mitigate whiplash and neck trauma, as head and torso motion are more aligned. Optional restraint belts may be deployed to increase body-to-mattress friction or to gently compress the occupant against the sleeping surface during the braking phase, enhancing energy dissipation through distributed friction. The system avoids abrupt load spikes typical of explosive restraint systems by replacing them with smooth, computer-regulated deceleration, improving overall occupant survivability and reducing post-crash trauma. In this way, the invention transforms the violent nature of a crash event into a controlled, biomechanically tolerable motion experience for the resting occupant.

In some embodiments, the sleeping pod may incorporate one or more inflatable cushions, airbag bladders, or deformable energy-absorbing chambers positioned at the interior region of the pod that faces the vehicle's forward direction—i.e., the surface the occupant is expected to contact when the pod is decelerated during a frontal crash. When a collision is detected and the pod braking sequence begins, the occupant's inertia causes the body to shift forward within the pod frame, and the forward-facing cushions may either inflate rapidly or transition from a low-fill standby state to a high-support pressure. These structures distribute contact loads across the torso, shoulder, hip, and head regions (depending on orientation), thereby reducing localized impact pressure.

In configurations where the occupant lies substantially perpendicular to the direction of vehicle travel, the forward-facing cushion may be elongated along the pod sidewall to intercept a broad portion of the occupant's lateral body surface. Multi-chamber designs may be used so that upper, middle, and lower body zones inflate differentially; for example, a head-and-shoulder chamber may inflate more aggressively than a hip chamber. Inflation may be triggered by the same crash-detection accelerometer logic that controls the pod braking electromagnet, and inflation pressure may be modulated over time to coordinate with the programmed deceleration profile, thereby avoiding hard rebound.

Pressure-relief valves or metered bleed ports may be included to lengthen the impulse duration and further smooth body loading. These inflatable elements may also be duplicated on the opposite side of the pod to provide protection in reverse-motion events or to manage secondary occupant rebound following the primary deceleration phase.

In alternative embodiments, the controlled deceleration of the passenger pod may be achieved using a range of mechanical, electromagnetic, hydraulic, and pneumatic systems, either alone or in hybrid combinations. Each system is configured to dissipate the kinetic energy of the moving pod during a crash event in a manner that reduces peak forces transmitted to the occupant.

One approach involves the use of elastomeric restraints such as rubber bands, bungee cords, or torsional springs. In this configuration, the pod is mechanically tethered to the vehicle frame via high-durability elastic elements that stretch as the pod moves forward. These materials exhibit a non-linear force-extension characteristic, offering low initial resistance that increases progressively with displacement. The progressive tension slows the pod in a smooth and continuous manner, minimizing the impulse applied to the occupant. This solution is passive and requires no electronic control, but may suffer from variability due to material fatigue, temperature sensitivity, and degradation overtime.

A second alternative includes a non-circular spool or variable-radius cam. The tether cable connecting the pod to the braking system is wound around a spool whose radius varies along its circumference.

As the spool rotates during pod displacement, the changing mechanical advantage alters the effective braking force. For example, an elliptical or logarithmic spiral profile may be used to create a ramped deceleration curve. This purely mechanical solution enables a pre-engineered force-displacement profile without sensors or actuators. However, its non-adjustable nature may limit its ability to adapt to crash severity or occupant mass.

A third approach uses eddy current damping, wherein the tether cable drives a conductive metal disk via a rotating spool system. A fixed-position magnet, typically an electromagnet, is located adjacent to the disk. As the disk spins, eddy currents are induced within the conductor, creating a resistive force that opposes rotation. The system enables smooth, contactless braking and can be tuned in real time to match the crash profile. It requires power and control logic but produces minimal wear and noise, making it ideal for repeated use.

In another embodiment, the braking system comprises a viscous fluid damper, such as a piston immersed in silicone oil or hydraulic fluid. As the pod moves forward, it drives the piston through the fluid, generating resistance through shear forces. The damping force is velocity-dependent and can be modified by selecting appropriate fluid viscosity and orifice geometry. This system is passive, robust, and well understood in automotive and aerospace applications. Its drawbacks include potential leakage and a relatively large physical footprint.

An alternative mechanism utilizes a flywheel system coupled with a friction clutch or brake. The motion of the pod drives the rotation of a flywheel, either directly or through a gear train. A controllable brake applies resistance to the flywheel, extracting kinetic energy and converting it to heat. The braking torque can be adjusted electronically, pneumatically, or mechanically. This setup allows for energy buffering and smooth deceleration, with the added benefit of potential integration with energy recovery systems. However, mass and inertia constraints may limit its feasibility in compact vehicle architectures.

Another variant employs regenerative electromagnetic braking using a motor-generator unit. The pod's kinetic energy is transferred via a mechanical linkage to a rotary generator, which converts the motion into electrical energy. This energy may be stored in a capacitor bank or battery, or dissipated across resistive loads. By controlling the electrical load, the braking force can be precisely modulated.

This solution allows for real-time adaptation, potential energy recovery, and integration with existing vehicle power systems. It requires advanced control electronics and must be carefully engineered to function reliably during crash-induced power disruptions.

In a further embodiment, an air compression cylinder or pneumatic damper is used to absorb the pod's momentum. As the pod advances, it compresses air in a sealed chamber through a piston or bellows system. The compressed air offers resistance to motion and may be vented through a valve system that regulates pressure release, creating a smooth deceleration curve. This design is passive and may be augmented with one-way valves or staged venting for multi-phase damping. Its limitations include size and the requirement for robust seals and structural components.

Yet another design utilizes a friction-based braking track or belt system. The pod may slide along a dedicated rail or friction surface, where braking pads or belts apply resistance through direct mechanical contact. Tension in the belts may be preloaded or dynamically adjusted using servo-actuators to tailor braking response. This approach is simple and proven in various industrial applications but introduces concerns regarding wear, heat generation, and noise. It is best suited as a supplementary or redundant braking mechanism.

Finally, the system may incorporate deformable or sacrificial elements such as shear pins or crash rails. These components are designed to plastically deform or fracture under predefined loads, absorbing energy through material deformation. As the pod moves forward, it shears or compresses these elements in a controlled fashion, converting kinetic energy into mechanical work. This passive method is reliable and predictable, though it is generally single-use and may not reset automatically without replacement.

These alternative deceleration methods may be used individually or in combination, depending on vehicle size, crash energy, occupant orientation, and cost constraints. By incorporating such modular designs, the system ensures flexibility, redundancy, and the ability to tailor safety performance to specific use cases.

In practice, the system is designed to dynamically mitigate the inertial forces acting on the human body during high-impact events, especially frontal collisions. By allowing the pod to move independently from the vehicle chassis, and by actively regulating the rate at which the pod is decelerated, the system transforms what would otherwise be a sudden and potentially injurious impact into a smoother, time-distributed event. The control system, upon detecting a crash via onboard accelerometers or impact sensors, calculates the optimal deceleration curve based on pod velocity, crash severity, and available displacement distance. The braking unit is then actuated to provide a precisely modulated counter-force, thereby reducing the biomechanical stress on the occupant's body and lowering the likelihood of trauma. This approach offers significant safety advantages compared to conventional seatbelt or airbag-only systems, particularly for reclining passengers who cannot be restrained using upright harness methods.

To enable the deceleration process described herein, the control system may be configured to compute a time-dependent braking force profile based on a combination of sensor inputs and pre-calculated physical constraints. Upon detection of a crash event, an onboard accelerometer or inertial measurement unit determines the initial relative velocity v0 of the passenger pod with respect to the vehicle chassis. Simultaneously, internal position sensors estimate the remaining allowable displacement d for the pod to move within the vehicle interior. The system may reference preloaded biomechanical safety thresholds to constrain the maximum allowable deceleration amax, based on known occupant tolerances.

Using these parameters, the control unit calculates the optimal deceleration curve a(t) such that the pod comes to rest within distance d while minimizing the jerk (time-derivative of acceleration) and peak G-forces experienced by the occupant. In one embodiment, a constant deceleration profile may be used, computed by the formula a=v0*v0/(2*d), which ensures full velocity cancellation over the available travel range. In more advanced implementations, the control system may use adaptive or nonlinear profiles, applying higher deceleration initially and tapering off near the end of travel to reduce occupant rebound and improve comfort. The selected braking force is then translated into control signals for the braking unit—for example, modulating magnetic field strength in an eddy current brake or adjusting fluid flow in a hydraulic damper—to physically realize the desired deceleration curve in real time.

This approach ensures that the pod's kinetic energy is dissipated safely and predictably within the mechanical constraints of the system and the physiological constraints of the occupant.

To support the controlled deceleration functionality, the system may include multiple sensor units strategically positioned to provide real-time data on vehicle dynamics, pod behavior, and crash conditions. At least one vehicle-mounted accelerometer, preferably positioned near the front or center of mass of the vehicle chassis, may be used to detect sudden deceleration indicative of a collision event. This primary sensor serves to initiate the crash response protocol and provides a reference frame for interpreting pod motion.

In addition, one or more accelerometers mounted directly on the passenger pod may be used to measure the pod's relative motion, instantaneous velocity, and the inertial forces acting on the occupant during the braking sequence. These pod-based sensors enable the control system to detect anomalies, verify braking performance, and dynamically adjust force application based on real-time feedback.

Complementing the accelerometers, the system may include position sensors (e.g., optical encoders, linear potentiometers, magnetic strip readers, or time-of-flight distance sensors) to monitor the pod's position within its travel rail or guide path. These sensors are preferably mounted along the pod's movement track and interface with the pod or tether to calculate the remaining travel distance.

Additionally, gyroscopes or inertial measurement units may be embedded within the pod or control system to track angular motion or orientation of the pod, which is useful in non-horizontal layouts or when body alignment is safety-critical.

To further enhance system awareness, occupant detection sensors such as pressure mats, infrared occupancy sensors, or vision-based posture detectors may be installed within or near the pod to determine whether the occupant is present and correctly positioned. This allows the control unit to tailor the braking profile based on occupant mass distribution and posture.

All sensor data may be processed locally by a dedicated safety microcontroller or routed to a centralized vehicle control system, which fuses the information to compute optimal braking trajectories and safety responses.

In some embodiments, monetization and damages-support features may be provided to enable subscription-based usage and accurate measurement of infringing use. The control computer may include a secure clock, cryptographic identity, and tamper-evident storage to log per-vehicle and per-pod usage records such as arming time, number of crash-response activations, pod travel distance and duration during each event, peak and average deceleration, energy dissipated by the braking unit, firmware version, and license state. The system may authenticate to a remote licensing service to obtain feature entitlements (e.g., enabling sleeping-pod mode, dual-occupancy mode, or extended deceleration path) on a subscription or per-mile basis, and may cache entitlements for offline operation. Data may be periodically uploaded via secure telemetry for billing and audit, with privacy controls that allow aggregation or anonymization while preserving usage counts. These technical features provide externally recorded, verifiable usage metrics that support calculation of reasonable royalties or lost-profits damages by correlating subscription records, activation counts, and energy-dissipation logs with vehicle identifiers.

Enablement: A skilled person may implement the system by mounting a pod (5) on a linear guide integrated within a vehicle (1), fixing a tether (7) to the pod and routing it to a compound spool (8, 10) housed in a rigid structure (13), coupling the larger drum to a conductive disk (11) via belt (9) so that pod motion accelerates disk rotation, situating an electromagnet (12) adjacent to the disk with controllable current drive, and installing accelerometers at the chassis and optionally on the pod. The control computer is programmed to detect a crash threshold, estimate pod velocity and remaining travel, compute a deceleration profile, and modulate magnet current to match the profile. Redundant power via a backup battery or supercapacitors supplies the brake for several hundred milliseconds.

Alternative embodiments swap the eddy-current unit for viscous, pneumatic, frictional, flywheel, regenerative, elastic, or deformable absorbers, sized to dissipate the expected kinetic energy consistent with the 1.5-2 m travel. Inflation modules for pod cushions are triggered by the same crash signal and pressure-modulated to coordinate with the braking curve.

A non-limiting worked example may guide sizing and implementation. Assume a combined moving mass of approximately 130 kg for a single-occupant pod, an initial relative velocity of 10 m/s at crash onset, and an available stroke of 1.8 m. A constant-deceleration target yields a≈v*v/(2*d)≈27.8 m/s2, about 2.8 g, with a stopping time of about 0.36 s and kinetic energy to dissipate of roughly 6.5 kJ. A tether may be wound on a drum of 0.1 m radius coupled through an overall 10:1 speed-increasing transmission to a 0.15 m radius conductive disk. The required average tether force is about 3.6 kN; torque at the tether drum is about 361 N·m and about 36 N·m at the disk after the 10:1 ratio. At an estimated disk speed of roughly 1000 rad/s (about 9.5 krpm) during the mid-stroke, peak mechanical power dissipation is on the order of 30-40 kW for a few hundred milliseconds, compatible with eddy-current braking when paired with adequate aluminum or copper disk mass and heat sinking. An electromagnet sized to accept 20-80 A at 24 V for 300-500 ms from a backup source such as a 50 F supercapacitor module (storing about 14 kJ at 24 V) may provide sufficient field strength to meet the torque demand over the event while tolerating primary power loss. A steel or HMPE cable with minimum breaking strength above 30 kN provides a safety factor greater than 3 relative to expected peak loads. Bearings and belt selections may be rated for transient speeds up to about 10 krpm and torques in the tens of N m at the disk shaft, with guards and containment to manage potential debris. Position sensing may be realized with a magnetic encoder on the spool providing at least 12-bit resolution over the stroke, and accelerometers with ±100 g range and ASIL-D capable interface may be used for crash detection and feedback. For a more severe case of 15 m/s relative velocity and the same stroke, energy rises to about 14.6 kJ and constant deceleration to about 6.4 g; the controller may increase magnet current and, if present, command auxiliary damping (e.g., pneumatic venting) to track the higher target while remaining within biomechanical limits. Assembly may include fastening the braking unit housing to a reinforced crossmember using through-bolts and crush sleeves, aligning the tether pull line within ±2° of the pod travel axis to avoid side loads, installing mechanical end-stops and a soft-return bias spring selected to restore the pod within 10-30 s post-event, routing redundant wiring harnesses for the electromagnet and sensors, and validating performance using sled tests that measure stroke, deceleration-time history, and reset behavior.

Technical effects: The system reduces peak deceleration and jerk transmitted to a reclining body by converting a short, high-amplitude impulse into a longer, lower-amplitude event. Distributed contact across the mattress and optional cushions reduces localized pressure and soft-tissue injury. Adaptive braking matched to crash severity lowers rebound and secondary impacts, while non-contact eddy-current braking minimizes wear and post-event maintenance. Rearward biasing preserves full stroke for energy dissipation, and sensor fusion improves directionality handling in oblique crashes. For eddy-current implementations, the technical effect includes velocity-proportional, smoothly controllable braking that yields low jerk and repeatable performance with minimal mechanical wear; for viscous dampers, the effect includes shear-based energy dissipation that inherently limits peak force through orifice sizing and provides temperature-tunable resistance; for pneumatic systems, compressive gas springs with staged venting produce multi-phase deceleration and rebound suppression, extending impulse duration without relying on electrical power; for flywheel-friction systems, rotational energy buffering decouples instantaneous peak loads from the pod and enables controlled heat rejection through brake modulation; for generator-based regenerative systems, conversion of kinetic energy to electrical energy permits fine-grained force control via load modulation and offers optional energy recovery while maintaining braking during primary power loss through local dump loads; for deformable or sacrificial elements, plastic work absorption provides highly predictable force-displacement plateaus that cap peak acceleration even in extreme pulses; for non-circular spools and cams, geometry-engineered leverage profiles realize predetermined deceleration curves that bound jerk without active sensing; for internal inflatable cushions, time-varying pressure and metered bleed distribute interface stresses over larger body areas, lowering peak contact pressures and mitigating chest and head injury criteria compared to rigid restraints.

Flows: A representative method flow includes continuous sensing of vehicle acceleration; threshold detection of a crash; immediate latching of backup power; estimation of pod state (position, velocity, remaining stroke); selection of a target deceleration curve subject to biomechanical limits and available distance; modulation of braking force via eddy-current field strength or alternative actuator control; coordinated activation of cushions and restraints; real-time feedback correction using encoders and pod accelerometers; ramp-down near stroke end to suppress rebound; and post-event logging and safe reset with gentle rearward return.

Support: Each claimed feature appears in the detailed description, including the tethered pod, braking unit architectures, sensing and control, cushions, rearward biasing, backup power, dual occupancy, perpendicular orientation, generator-based regeneration, pneumatic and viscous options, deformable elements, and rail-guided movement. The specification provides sufficient written description and possession of the claimed subject matter.

Broadening: For each functional block, the description includes alternatives (e.g., multiple braking technologies; multiple sensors; varied orientations; passive and active approaches; modular energy storage), preventing narrowing to a single implementation and enabling broad claim construction.

Continuation-ready: The itemized list provides discrete, claimable features suitable for continuation filings. Additional unclaimed variations disclosed herein (e.g., position-sensing modalities, non-circular spools, staged venting, energy recovery routing) are preserved for future prosecution.

Claim layering: The present claims include independent claims directed to a vehicle system, a method, and a computer-readable medium, and the disclosure also supports apparatus claims to the braking module for pursuit within the independent-claim limit or in continuations.

No unneeded limitations: Descriptive references to autonomy, pod orientation, and particular braking technologies are exemplary. Unless expressly recited in a claim, such characteristics are not limiting.

The system may be implemented in autonomous or human-driven vehicles, and with varied pod orientations and braking mechanisms.

External observability: Externally verifiable behaviors include pod translation over a measured stroke during a crash, controlled time-history of deceleration bounded by thresholds, logged activation counts and energy dissipation, and telemetry-authenticated license states. These observable inputs and outputs enable post-incident verification and infringement proof without invasive inspection.

Interoperability coverage for software patents: The control computer may interface with vehicle networks including CAN, CAN-FD, LIN, FlexRay, Automotive Ethernet, and diagnostic protocols such as UDS, with software developed under ISO 26262 processes. The braking controller may operate standalone with discrete wiring or integrated via standardized gateways, and can adapt to differing sensor suppliers and communication stacks. Implementations may target AUTOSAR Classic or AUTOSAR Adaptive, POSIX-compliant RTOS including QNX or Linux, or bare-metal microcontrollers with hardware-abstraction layers, while preserving identical external behaviors and signals. Sensor and actuator interfaces may include SPI, I2C, SENT, PSI5, UART, analog, PWM, GPIO, LVDS, and Ethernet, with signal scaling, endianness, and message-identifier remapping handled in software such that interface changes do not avoid practice of the claimed functions. Time synchronization may use PTP, GPS, or vehicle-provided time bases; firmware may support secure boot, authenticated over-the-air updates including Uptane-style metadata, and certificate-based provisioning. The controller may publish or subscribe via DDS, SOME/I, or ROS 2 bridges, may bridge between gateways with message translation, and may fall back to a discrete-wired mode if a network is absent. Diagnostic coverage may include UDS services, DoIP, and vendor-specific data identifiers, enabling deployment across multiple OEM platforms without departing from the claimed scope.

Fallback embodiments: Reduced-complexity implementations include passive elastic tethers, viscous or pneumatic dampers with calibrated orifices, and deformable shear elements that function without powered control while still providing extended-stroke deceleration benefits.

Damages maximization: The licensing, telemetry, and secure logging features enable subscription models and usage-based billing and provide authenticated records of feature enablement and system activations, supporting damages calculations tied to real-world use.

Style and interpretation: Descriptive language uses permissive terms such as “may” and “could” to avoid unintended narrowing. Examples are illustrative, not limiting, and operations may be reordered or combined unless expressly claimed otherwise.

Physical plausibility: The deceleration strategy applies established energy and dynamics principles. Conversion of linear kinetic energy into rotational losses via gearing and eddy currents, or into viscous, pneumatic, frictional, or plastic deformation work, is physically consistent and scalable to the disclosed travel distances and occupant masses.

Legal robustness: The disclosure provides written description and enablement for the claimed subject matter, identifies best-mode examples without limiting scope, and defines externally observable behaviors to facilitate enforcement. Claim construction and definitions: As used herein, “passenger pod” refers broadly to any occupant-supporting structure including but not limited to a bed, couch, litter, stretcher, carriage, or pod-like frame; “braking unit” refers to any assembly that produces a decelerating force on the passenger-supporting structure over a finite stroke, including mechanical, electromagnetic, fluidic, pneumatic, frictional, regenerative, deformable, and hybrid systems; “tether” encompasses flexible and rigid couplings including cables, belts, chains, rods, linkages, and integrated rail-carriage interfaces; “magnet” includes permanent magnets and electromagnets; “control system” includes electronic and/or mechanical, hydraulic, pneumatic, or magnetorheological arrangements that detect a crash or sudden deceleration and modulate or gate force application, including but not limited to inertial latches, governors, valves, cams, and linkages; in some embodiments the control system corresponds to at least one processor and associated circuitry executing the disclosed algorithmic steps of crash detection, state estimation, deceleration-profile computation, and actuator command; “backup power supply” includes batteries, supercapacitors, flywheels with generators, or combinations thereof, and “inflatable cushion” includes airbags, bladders, or gas-modulated foam structures. Functional recitations are supported by corresponding structures and algorithms described herein to satisfy 35 U.S.C. § 112, including the compound spool and disk assembly, hydraulic and pneumatic resistors with valves and orifices, generator loads with controllable dissipation, friction pads and belts, and the control flow detailed in the Flows and Enablement sections. The phrase “configured to” is used in a structural sense to denote hardware, mechanical arrangements, and programmed processors that, by virtue of their design and programming disclosed herein, perform the recited functions. The claims are intended to cover statutory equivalents and insubstantial variations under the doctrine of equivalents that achieve the same deceleration-over-stroke functionality within the disclosed bounds. For avoidance of doubt and without limiting scope, “non-transitory computer-readable medium” excludes propagating electromagnetic signals per se. To facilitate definite enforcement while avoiding narrowing, objective, externally observable criteria may be used to evidence practice of claim elements such as “permitted to move relative to the vehicle” and “reduce the peak acceleration.” For example, during a crash or sudden deceleration event, high-speed video or inertial data may show relative displacement between the passenger pod and a reference point on the vehicle body of at least several centimeters within the event window, and time-synchronized sensor logs from the vehicle or pod may show a deceleration-time history of the pod or an anthropomorphic test device with a peak that is measurably lower than a comparator configuration in which the pod is rigidly constrained to the vehicle over the same crash pulse and occupant mass. These non-limiting test procedures provide objective markers for infringement without importing additional limitations into the claims. The disclosure avoids means-plus-function claiming and provides corresponding structure and algorithmic detail for any functional language. Terms are to be construed in light of the specification and prosecution history, and the examples herein demonstrate sufficient possession and enablement across the full breadth of the claims.

To further support enforceability in litigation, key terms are anchored to objective tests and ordinary meaning. “Reduce the peak acceleration” denotes a reduction relative to a comparator configuration in which the pod is rigidly constrained to the vehicle over a substantially similar crash pulse and occupant mass; it does not require a global minimum or a particular percentage reduction. “Mounted within the vehicle” encompasses integration within body, chassis, underfloor, or interior structures such that the braking unit is carried by the vehicle. “Crash or sudden deceleration event” includes collision pulses and non-contact events such as emergency braking or curb strikes that exceed detection thresholds disclosed herein. Written description and enablement span passive, semi-active, and active variants, with design equations, parameter ranges, and concrete component ratings provided so that a skilled person can practice the full scope without undue experimentation across occupant masses, stroke lengths, and initial velocities. The specification supplies algorithmic detail sufficient to avoid any 35 U.S.C. § 112(f) characterization for computer-implemented elements by reciting crash detection, state estimation, profile computation, and actuator command flows with corresponding structures.

Evidentiary sources for proving infringement may include synchronized high-speed video, accelerometer and encoder logs from the pod or vehicle event data recorder, authenticated telemetry and tamper-evident usage records, and third-party instrumented sled tests that replicate crash pulses. Time bases may be synchronized by PTP or GPS as described, and cryptographically signed logs may establish chain of custody. These objective artifacts permit claim charting to external behaviors without disassembly, and support both direct and doctrine-of-equivalents assertions where a competitor substitutes an energy dissipation mechanism yet preserves the claimed deceleration-over-stroke functionality.

Workaround minimization: The claims and disclosure are structured to minimize opportunities for design-around by focusing on externally verifiable functional outcomes and by disclosing interchangeable implementations for each functional block. Any system that permits relative motion between an occupant-supporting pod or pod-like structure and the vehicle during a crash, and applies a time-varying decelerating force to reduce peak acceleration while arresting motion within a finite stroke, may fall within the described scope regardless of conversion mechanism or energy dissipation pathway. The braking unit may act through flexible or rigid couplings; may be collocated with the pod, distributed along rails, or integrated into the vehicle structure; may act directly on the pod, on a pod carriage, or on a pod-attached element; or may create a retarding field along the motion path without a discrete tether. Equivalent implementations may include linear electromagnetic rails, magnetic drag plates, magnetorheological or eddy-current tracks, hydraulic or pneumatic resistors, variable-radius cams, friction belts or pads, deformable crash elements, generator loads, and hybrids thereof. Passive, semi-active, and active strategies are contemplated, including purely mechanical profiles that inherently modulate force over displacement, sensorless inertial latches, and electronically modulated systems with or without pre-crash inputs. Relative motion may be realized by translating the pod, translating a carriage or subframe supporting the pod, or translating adjacent vehicle structure in the opposite direction such that the pod experiences controlled deceleration relative to the vehicle frame. Orientation, occupancy count, path geometry (linear or curved), and contact-distribution structures may vary without departing from the core concept. Interfaces and sensors may be substituted or bridged across platforms and protocols without avoiding infringement because externally observable behaviors such as stroke, time-history of deceleration within thresholds, and authenticated activation logs remain present. Avoidance by eliminating electronics is ineffective because the control system may be implemented mechanically or fluidically; inertial governors, threshold valves, cams, or latches may detect a crash or sudden deceleration and gate or modulate braking force without digital computation, and such implementations still practice the described functions. Crash detection may be explicit or implicit, for example by mechanical sensing of tether tension, pod acceleration, or displacement rate that exceeds a threshold, thereby satisfying detection of a crash or sudden deceleration event. Relocating the moving support to a sub-platform such as a sliding mattress, litter, or carriage within a stationary external shroud does not avoid practice, as the passenger pod encompasses any occupant-supporting structure that is permitted to move relative to the vehicle while the decelerating force is applied to reduce peak acceleration. Additionally, systems that realize the deceleration-over-stroke outcome via multi-degree-of-freedom motion, including controlled pitch, yaw, roll, or vertical translation of the occupant-supporting structure, remain within scope; substituting the moving element with a belt-bed, hammock, sling, compliant or exoskeletal frame that translates or pays out restraint relative to the vehicle practices the same functions; distributing braking across arrays of micro-brakes or magnetorheological segments along the guide path; employing phase-change, viscoelastic, or shear-thickening media as energy absorbers; using one-way clutches, ratchets, or magnetic couplers; locating energy absorbers remote from the pod with force transmitted through intervening structural members; or implementing variable-geometry or curved paths with coordinated rotation to align the body with the deceleration vector do not avoid practice so long as the passenger-supporting structure is permitted to move relative to the vehicle and a time-varying decelerating force is applied to reduce peak acceleration while arresting motion within a finite stroke.

Itemized list for continuations: Embodiments can be described by the following itemized list suitable for use in future continuation applications, each feature being combinable with others unless technically incompatible: (i) a variable-radius non-circular spool or cam configured to realize a predetermined force-displacement profile without sensors; (ii) a linear electromagnetic drag rail or eddy-current track arranged along the pod guide path to provide contactless braking without a discrete tether; (iii) regenerative braking via a generator with controllable electrical loads including resistive dump, capacitor bank, and vehicle-bus coupling with isolation for power-loss scenarios; (iv) pneumatic damping with staged venting and one-way valves to create multi-phase deceleration and rebound suppression; (v) friction-belt or pad braking with servo-adjustable tension to tailor force during an event; (vi) deformable or sacrificial elements such as shear pins or crush rails dimensioned for single-use energy absorption; (vii) passive rearward biasing using springs or elastic bands to reset the pod after activation; (viii) multi-chamber inflatable cushions inside the pod with differential inflation schedules coordinated to a deceleration profile and pressure-relief metering; (ix) sensor fusion of vehicle-frame accelerometers and pod-mounted accelerometers and encoders to estimate crash direction and remaining stroke; (x) occupant detection and posture sensing to parametrize braking based on mass distribution and alignment; (xi) control algorithms selecting constant-deceleration or nonlinear, jerk-limited profiles constrained by available distance and biomechanical limits; (xii) backup energy storage using batteries and/or supercapacitors sized to sustain controllable braking for several hundred milliseconds following primary power loss; (xiii) mechanical arrangement options including pod-collocated braking modules, rail-distributed braking elements, or modules integrated into vehicle structure; (xiv) coupling options including cables, belts, chains, or rigid linkages, with linear or curved pod travel paths; (xv) interoperability with in-vehicle networks including CAN, CAN-FD, LIN, FlexRay, Automotive Ethernet, and diagnostic protocols such as UDS for integration and diagnostics; (xvi) telemetry, cryptographic identity, secure logging, and licensing features enabling subscription models and authenticated usage records; (xvii) fallback passive-only embodiments that omit powered control while preserving extended-stroke deceleration benefits; (xviii) perpendicular or alternative pod orientations and single or dual occupancy configurations; (xix) rear-mounted housing placement of the braking unit to preserve function during frontal deformation; (xx) rotational encoder feedback on spools or disks for closed-loop control of eddy-current braking force. Additionally, to ensure direct continuation support mirroring the present claims, the following entries correspond respectively to the subject matter of claims 1 through 20 and may be used verbatim or adapted in future filings: (a) a vehicle comprising a passenger pod configured to receive a human occupant including in reclining or horizontal postures, and a braking unit mounted within the vehicle and operatively coupled to the passenger pod, wherein the passenger pod is permitted to move relative to the vehicle during a crash or sudden deceleration event, and wherein, during the event, the braking unit applies a decelerating force to the passenger pod so as to reduce the peak acceleration experienced by the occupant; (b) the vehicle of entry (a), wherein the passenger pod is coupled to the braking unit by a flexible tension element including at least one of a cable, a belt, or a chain; (c) the vehicle of entry (a), wherein the braking unit comprises a rotatable element configured to convert linear pod motion into rotational braking torque; (d) the vehicle of entry (a), wherein the braking unit comprises an eddy-current braking system with a rotating conductive element and at least one magnet; (e) the vehicle of entry (d), wherein the braking force is modulated by adjusting a position or magnetic field strength of the magnet; (f) the vehicle of entry (a), further comprising a control system configured to determine a deceleration profile based on data from one or more accelerometers configured to detect crash severity; (g) the vehicle of entry (f), wherein the control system includes a backup power supply configured to ensure braking functionality during power failure; (h) the vehicle of entry (a), wherein the braking unit includes at least one of a fluid damper, a pneumatic system, and a flywheel with a controllable friction brake configured to generate resistance; (i) the vehicle of entry (a), wherein the passenger pod includes an internal structure configured to increase surface contact with the occupant during deceleration; (j) the vehicle of entry (a), wherein the passenger pod includes at least one inflatable cushion or airbag disposed at a surface toward which the occupant is expected to move during a deceleration event; (k) the vehicle of entry (a), wherein the passenger pod is biased toward a rearward rest position by a passive restoring mechanism comprising at least one of a spring or an elastic band; (l) a method of operating a vehicle having a passenger pod and a braking unit, the method comprising detecting a crash or sudden deceleration event, permitting the passenger pod to move relative to the vehicle, applying a decelerating force to the passenger pod via the braking unit, and modulating the decelerating force over time to reduce peak acceleration experienced by an occupant while bringing the passenger pod to rest within an available travel distance; (m) the method of entry (1), further comprising estimating passenger pod position and velocity and selecting a target deceleration profile based on crash severity and biomechanical limits; (n) the vehicle of entry (a), wherein the braking unit comprises a generator configured to convert kinetic energy into electrical energy and to modulate braking force by controlling an electrical load; (o) the vehicle of entry (a), wherein the braking unit comprises a deformable mechanical element that plastically deforms under crash-induced loads; (p) the vehicle of entry (a), wherein the passenger pod is oriented perpendicular to a forward direction of vehicle travel; (q) the vehicle of entry (a), wherein the passenger pod is configured for dual occupancy; (r) the vehicle of entry (a), wherein the passenger pod includes sensors configured to detect occupant position and to adjust the deceleration profile accordingly; (s) a non-transitory computer-readable medium storing instructions that, when executed by a processor of the control system, cause the processor to monitor vehicle and passenger pod sensors, detect a crash or sudden deceleration event, estimate passenger pod state including position, velocity, and remaining travel, compute a deceleration profile subject to biomechanical constraints, and control the braking unit to apply a time-varying decelerating force to the passenger pod in accordance with the profile; (t) the vehicle of entry (a), wherein the braking unit and the passenger pod are mounted on a common rail or guide system configured to constrain pod movement along a predetermined path.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

Item 1. A vehicle comprising: a passenger pod configured to receive a human occupant including in reclining or horizontal postures; and a braking unit mounted within the vehicle and operatively coupled to the passenger pod; wherein the passenger pod is permitted to move relative to the vehicle during a crash or sudden deceleration event, and wherein, during the event, the braking unit applies a decelerating force to the passenger pod so as to reduce the peak acceleration experienced by the occupant.

Item 2. The vehicle of item 1, wherein the passenger pod is coupled to the braking unit by a flexible tension element including at least one of a cable, a belt, or a chain.

Item 3. The vehicle of item 1, wherein the braking unit comprises a rotatable element configured to convert linear pod motion into rotational braking torque.

Item 4. The vehicle of item 1, wherein the braking unit comprises an eddy-current braking system with a rotating conductive element and at least one magnet.

Item 5. The vehicle of item 4, wherein the braking force is modulated by adjusting a position or magnetic field strength of the magnet.

Item 6. The vehicle of item 1, further comprising a control system configured to determine a deceleration profile based on data from one or more accelerometers configured to detect crash severity.

Item 7. The vehicle of item 6, wherein the control system includes a backup power supply configured to ensure braking functionality during power failure.

Item 8. The vehicle of item 1, wherein the braking unit includes at least one of: a fluid damper; a pneumatic system; and a flywheel with a controllable friction brake configured to generate resistance.

Item 9. The vehicle of item 1, wherein the passenger pod includes an internal structure configured to increase surface contact with the occupant during deceleration.

Item 10. The vehicle of item 1, wherein the passenger pod includes at least one inflatable cushion or airbag disposed at a surface toward which the occupant is expected to move during a deceleration event.

Item 11. The vehicle of item 1, wherein the passenger pod is biased toward a rearward rest position by a passive restoring mechanism comprising at least one of a spring or an elastic band.

Item 12. A method of operating a vehicle having a passenger pod and a braking unit, the method comprising: detecting a crash or sudden deceleration event; permitting the passenger pod to move relative to the vehicle; applying a decelerating force to the passenger pod via the braking unit; and modulating the decelerating force over time to reduce peak acceleration experienced by an occupant while bringing the passenger pod to rest within an available travel distance.

Item 13. The method of item 12, further comprising estimating passenger pod position and velocity and selecting a target deceleration profile based on crash severity and biomechanical limits.

Item 14. The vehicle of item 1, wherein the braking unit comprises a generator configured to convert kinetic energy into electrical energy and to modulate braking force by controlling an electrical load.

Item 15. The vehicle of item 1, wherein the braking unit comprises a deformable mechanical element that plastically deforms under crash-induced loads.

Item 16. The vehicle of item 1, wherein the passenger pod is oriented perpendicular to a forward direction of vehicle travel.

Item 17. The vehicle of item 1, wherein the passenger pod is configured for dual occupancy.

Item 18. The vehicle of item 1, wherein the passenger pod includes sensors configured to detect occupant position and to adjust the deceleration profile accordingly.

Item 19. A non-transitory computer-readable medium storing instructions that, when executed by a processor of the control system, cause the processor to monitor vehicle and passenger pod sensors, detect a crash or sudden deceleration event, estimate passenger pod state including position, velocity, and remaining travel, compute a deceleration profile subject to biomechanical constraints, and control the braking unit to apply a time-varying decelerating force to the passenger pod in accordance with the profile.

Item 20. The vehicle of item 1, wherein the braking unit and the passenger pod are mounted on a common rail or guide system configured to constrain pod movement along a predetermined path.

### Embodiment IE: Method and System for Forecasting Goal Outcomes Using Structured Experience Reports

### Embodiment I: Method and System for Forecasting Goal Outcomes Using Structured Experience Reports

A system and method are disclosed for enabling predictive goal fulfillment through incentivized experience sharing among autonomous agents. The method may involve receiving structured experience reports from personal agents, each report describing a user's attempt to achieve a defined goal using a selected option, along with contextual metadata and an observed outcome. These reports may be stored in a shared experience repository accessible by a network of agents. When a user or agent submits a prediction query specifying a goal and one or more candidate options, the system may analyze relevant prior reports to estimate the likelihood that each option will successfully achieve the goal under comparable conditions. In some embodiments, agents may be incentivized to contribute experience data in exchange for prediction access credits or monetary rewards.

For example, a user intending to have mobile data access while traveling may rely on the system to determine that SIM cards from Provider X have a low likelihood of activating roaming in Belgium, while Provider Z has a significantly higher success rate in similar contexts. In another example, a user considering purchasing a phone charging cable from a vendor at a train station may receive predictive feedback indicating that cables from that vendor often fail within one month, while cables from a verified online supplier demonstrate significantly longer durability. The system may continuously refine prediction accuracy through ongoing experience submissions, enabling proactive decision-making based on the real-world outcomes of others.

Gentle Introduction: The invention may be understood at an intuitive level as a way for users and their personal agents to learn from the real-world outcomes of others in comparable situations. Each time someone attempts to achieve a goal using a particular option, such as choosing a SIM provider while traveling or selecting a cafe seat to charge a phone, a succinct, structured note of what happened could be shared with a collective memory. When another user faces a similar choice, the system may look up relevant past notes and forecast which option is likely to work best, presenting a simple likelihood, key risks, and suggestions. Overtime, as more experiences are added, the forecasts may become more accurate and context-aware, much like how humans learn from experience but at network scale and speed.

Background of the Invention: In both digital and real-world environments, individuals frequently encounter uncertainty when attempting to achieve specific goals through the selection of products, services, or actions. Examples of such goals may include obtaining reliable mobile data service while traveling, selecting a durable phone charging cable, or completing a digital task using a free online tool. Despite the widespread availability of user reviews, testimonials, and general ratings, existing systems typically lack the specificity, contextual relevance, and predictive utility required for accurate decision-making in situational or individualized scenarios.

Conventional review platforms often aggregate generalized opinions that may not reflect the specific goal of the user, the conditions under which the product or service was used, or the probability of encountering a known failure mode. Furthermore, such platforms rarely offer probabilistic forecasts, structured outcome modeling, or agent-personalized insights that reflect a user's context, device, location, or intended use case. As a result, users are frequently required to rely on incomplete, anecdotal, or misleading information when making decisions, which may lead to loss of time, money, or effort.

Moreover, there exists no widely adopted system wherein autonomous agents operating on behalf of users can both contribute to and query a collective repository of structured experience data in exchange for incentives. Current systems do not adequately leverage shared experiential outcomes to simulate future results or quantify the likelihood of goal fulfillment for specific options under particular conditions.

In some cases, a user may be unaware that a goal has failed until additional consequences arise, or may lack the time or motivation to document and share the experience. To address this, the present invention contemplates the use of personal agents that may autonomously detect the failure or success of a goal and submit a structured report with minimal or no human intervention. For instance, a personal agent may infer that a purchased SIM card failed to provide roaming service based on device telemetry, location data, and lack of connectivity. By removing friction in the reporting process and aligning incentives-such as offering prediction access credits or monetary rewards in exchange for experience reports—the system enables the consistent accumulation of high-quality, context-rich outcome data.

This combination of low-effort reporting and incentive-based participation is expected to substantially increase the density, diversity, and reliability of shared experiential data, thereby dramatically improving the system's ability to generate accurate, context-aware predictions of future outcomes. As a result, users may benefit from a powerful new form of collective foresight, enabling them to make more informed decisions and avoid common sources of regret, friction, or failure.

Summary of the Invention: The invention provides a method, system, apparatus, and non-transitory medium for forecasting the likelihood that a specified goal will be achieved when a user selects among candidate options under stated conditions. Personal agents associated with users may detect or receive a goal, compile structured experience reports after observed attempts, and submit those reports to a shared experience repository. A prediction engine may retrieve context-similar reports using primary keys, construct an analysis input, and compute per-option likelihoods, risks, and recommendations. Incentive, verification, and staking mechanisms may encourage high-quality submissions and maintain data integrity. The platform may operate over interoperable interfaces, support fallback modes with local caching, and expose externally observable outputs suitable for compliance and enforcement.

In one aspect, the system supports two query modes: experience retrieval for local agent-side inference and direct prediction for server-side scoring. In another aspect, agents may receive access credits, reputational adjustments, or monetary rewards tied to report relevance and verification confidence. The invention may be applied to a wide range of domains, including telecommunications access while traveling, product durability choices, digital workflow selections, and environmental resource availability.

Scope and Interpretation: The scope of the invention is limited solely by the claims. Any examples, scenarios, JSON snippets, prompts, outputs, data fields, and process flows described herein are illustrative embodiments and do not limit claim scope. Steps may be performed in different orders, concurrently, repeatedly, or with steps added or omitted, unless a claim expressly requires otherwise.

Components and modules may be implemented in software, hardware, firmware, or any combination, and may be centralized or distributed. Interfaces, data schemas, identifiers, and primary keys may vary while remaining within the scope of the claims. Singular terms include the plural and vice versa; “may,” “can,” and “could” indicate optional features; “or” is inclusive; and “including” and “such as” are non-limiting. Any figures, if later provided, are similarly illustrative.

Description of the Drawings: No drawings are provided in this filing. Figures, if later provided, are illustrative and may reference the elements and relationships described in the Anchor section, with consistent numbering across embodiments.

### Applications and Illustrative Use Cases

The methods and systems described herein may be applied across a broad range of domains in which users must select among competing options to fulfill specific goals. In various embodiments, the invention enables a user's personal agent to simulate future outcomes based on structured reports submitted by other agents in similar contexts. The following examples are provided to illustrate representative use cases, and are not intended to limit the scope of the invention.

In one example, a user preparing to travel internationally may seek to ensure mobile data access upon arrival in a foreign country. The user's personal agent may query the system with the goal of “having working mobile data in Belgium” and evaluate a list of candidate SIM card providers. Based on experience reports submitted by other agents—some of which may indicate successful activation of roaming features, while others may describe failures due to regional restrictions or unresponsive customer support—the system may return a goal realization likelihood score for each provider. The agent may advise the user to avoid providers with historically poor outcomes in similar contexts.

In another embodiment, the system may be used to assist users in selecting an insurance provider. A goal such as “obtain fast, hassle-free reimbursement after a flight cancellation” may be evaluated across multiple insurers. Experience reports could include outcome data on past claims, such as response times, documentation demands, and dispute frequency. By aggregating these reports, the system may offer the user a probabilistic forecast of successful claim fulfillment with minimal friction.

In yet another example, the user may wish to remove the background from a photo using an online service. While many websites advertise free background removal, some may require account creation, introduce hidden paywalls after effort is expended, or produce unusable results. The agent may submit a prediction query with the goal “obtain a transparent PNG background removal in under two minutes with no watermark or payment.” By referencing past user experiences, the system may predict which sites are most likely to fulfill the goal without time loss or post-effort disappointment. The system may also assist with impulse decisions in physical retail environments. For example, a user at a gas station may consider purchasing a phone charging cable from a generic vendor. The agent may detect the intended use case and evaluate the product ID or seller tag against prior experience reports. If multiple agents have previously logged that such cables fail within a few weeks or are incompatible with certain devices, the user may be warned before purchasing. Finally, the invention may enhance everyday decisions such as selecting a place to sit and enjoy a coffee. A goal may be defined as “charge my phone while drinking coffee at the train station.” The agent may cross-reference experience reports to identify which restaurants or seating areas reliably provide working power outlets, factoring in time-of-day patterns and outlet occupancy trends. As a result, the user may be directed to a specific cafe or table location with a high probability of satisfying the charging requirement.

These examples illustrate how the system may be used to optimize decision-making across digital services, physical product selection, travel logistics, and environmental resource access. By continuously learning from structured reports and offering contextual predictions, the invention may serve as a valuable tool for minimizing regret, effort loss, and goal failure in everyday life. Detailed Description: In some embodiments, the method described in claim 1 may be realized by a system comprising one or more experience processing servers configured to receive structured reports from a plurality of autonomous or semi-autonomous personal agents. Each agent may be associated with a user and may be configured to monitor, infer, or record attempts by the user to achieve a particular goal. The agent may detect the goal explicitly, such as via user input, or infer it from surrounding behavioral context, such as application usage, online activity, location data, or other observable signals. When the user selects an option in pursuit of that goal-such as purchasing a product, using a service, or initiating a digital interaction—the agent may log the selected option along with eventual success or failure outcomes.

Upon detecting that sufficient outcome information is available, the agent may compile a structured experience report. This report could include, by way of example and not limitation, a goal description, the option selected, the result of the action (e.g., success, partial success, failure), and a set of contextual attributes relevant to outcome interpretation. These attributes may include environmental data, device type, timing, location, service conditions, user feedback, or any other parameter useful for later predictive evaluation. A representative experience report may be structured in a machine-readable format, and an inline JSON example is as follows: {“goal”:“Have working mobile data while traveling in Belgium”,“selected_option”:“ProviderX SIM card, purchased online”,“outcome”:“Failure—SIM card did not activate roaming in BE”,“timestamp”:“2025-07-14T10:23:00Z”,“context”:{“location_of_use”:“Brussels, Belgium”,“device”:“iPhone 13”,“time_elapsed_before_failure”:“3 days”,“setup_steps”:[“Inserted SIM”,“Followed instructions”,“Activated via app”],“user_feedback”:“Support unreachable, no refund offered” }} In some configurations, the system may receive the structured report and store it in a shared experience repository, optionally associating it with a unique identifier, a confidence score, or a cryptographic proof of provenance. The experience repository may be searchable by other agents and may serve as the basis for later predictive operations. For example, a second agent may submit a prediction query to the system, specifying a desired future goal (e.g., working mobile data while abroad) and one or more candidate options (e.g., various SIM card providers). In response, the system may retrieve relevant prior experience reports, optionally filtering by context similarity, and compute for each candidate a goal realization likelihood score, indicating a probability or confidence that the goal would be achieved under conditions similar to those described in the query. The results of this analysis may be returned to the agent in structured form, potentially accompanied by annotations, such as common failure points, remediation costs, or alternative recommendations. The system may continuously update its predictive capabilities as additional experience reports are submitted, allowing it to adapt over time to changing conditions, rare edge cases, and evolving user goals.

In some embodiments, the platform may operate using a distributed architecture, and experience reports may be submitted pseudonymously, anonymously, or with cryptographic signatures. The report submission and query process may be mediated through an incentive mechanism, such that agents who contribute experience data may receive access privileges, prediction credits, or other benefits as described in related claims.

In one illustrative embodiment, the invention may be applied in the context of selecting a cafe for the purpose of achieving the goal of charging a mobile phone while consuming a beverage at a train station. This example demonstrates how primary keys may be used to retrieve relevant prior experiences, which are subsequently used as input to a large language model (LLM) for the purpose of predicting the likelihood of goal success under current conditions.

At the outset, a personal agent associated with a user may detect or be informed of the user's intent to locate a cafe within a transportation hub, such as a central train station, with the specific goal of charging their phone. The agent may construct a query using a set of primary keys, representing observable or inferable facts about the current situation. These keys may include, but are not limited to, goal:chargephone, venue type:cafe, location:central_station, time_of day:morning, and device type:mobile_phone. Using these keys, the system may retrieve a set of experience reports from a shared experience repository. Each experience report may correspond to a past attempt by a different user to achieve a similar goal under similar or overlapping conditions. These reports may be structured to include outcome data and relevant context, and an inline JSON array example is as follows:

[{“goal”:“charge_phone”,“venue_type”:“cafe”,“location”:“central_station”,“time”:“2025-07-04T09:15
Z”,“outcome”:“success”,“details”:{“cafe_name”:“Café
X”,“table”:“4”,“outlet_available”:true,“outlet_working”:true,“duration_minutes”:30}},{“goal”:“charge
_phone”,“venue_type”:“cafe”,“location”:“central_station”,“time”:“2025-07-04T08:50Z”,“outcome”:“f
ailure”,“details”:{“cafe_name”:“Café
Y”,“outlet_available”:false}},{“goal”:“charge_phone”,“venue_type”:“cafe”,“location”:“central_station
”,“time”:“2025-07-03T09:00Z”,“outcome”:“partial_success”,“details”:{“cafe_name”:“Café
X”,“outlet_available”:true,“outlet_interrupted”:true}}]

Following retrieval, the system may select a subset of representative experiences, optionally filtered by recency or contextual similarity, and format these into a prompt for a large language model. The prompt may include a natural language representation of the current user goal, the current conditions, and a listing of prior experiences.

Prompt to LLM: “A user is currently at the central train station and is looking for a cafe where they can sit and charge their mobile phone while having a coffee. It is currently 9:00 AM. The goal is to find a nearby cafe with working, available power outlets. Here are 3 past user experiences: 1. Cafe X, 9:15 AM, July 4: Table 4 had a working outlet. User successfully charged phone for 30 minutes. 2. Cafe Y, 8:50 AM, July 4: No outlet was available. User could not charge. 3. Cafe X, 9:00 AM, July 3: Outlet was initially working but power was interrupted midway through. Based on these past reports, what is the probability that the user will be able to successfully charge their phone at Cafe X right now (9:00 AM)?Please provide a percentage estimate, any identified risks, and suggested actions.”

Upon receiving this prompt, the LLM may process the inputs and return a structured or semi-structured output. For example, the estimated probability of success at Cafe X at 9:00 AM may be 65 percent; risks identified may include that outlet reliability may vary by table, that temporary power interruptions were reported, and that morning hours may lead to competition for limited outlets; suggestions may include requesting Table 4 if available, bringing a backup power bank, and considering Cafe Y after 10:00 AM where lower outlet usage was observed. This output may then be consumed by the user's agent and used to inform a recommendation, optionally rendered in natural language or through visual interface elements. The agent may advise the user accordingly, such as: “Cafe X gives you a moderate chance of charging now, especially at Table 4. Outlet reliability is variable. Would you like to check other options after 10:00 AM?”

In some embodiments, the system may assign a confidence score to the LLM's prediction based on the volume, consistency, or contextual alignment of the retrieved reports. The agent may also prompt the user to contribute their own outcome after the attempt, thereby completing the feedback loop and improving the system's predictive accuracy over time.

This example illustrates how primary keys may be used to accurately retrieve situationally relevant prior experiences, and how an intelligent model may be prompted to synthesize those experiences into an actionable forecast that helps the user choose the most effective path toward goal fulfillment. In some embodiments, the system may operate by first identifying a set of primary keys associated with the user's current decision context. These keys may include, by way of example, the location at which the product or service is to be used, the type of object or service under consideration, the intended user goal, and any other observable attributes such as time of day, device type, or vendor identity. Once the keys are established, they may be used to query an experience repository containing structured reports from prior users or agents who attempted to achieve similar goals under comparable conditions. The result of this query is a collection of historical experiences that match or approximate the identified context. The system may then assemble a custom prompt by embedding the current goal and the retrieved experience data into a formatted textual query suitable for a large language model (LLM). The LLM may be configured to analyze the prior outcomes, identify relevant patterns, and return a structured response containing an estimated probability of goal success, a list of contextual risks, and actionable advice or alternatives. This output may then be consumed by the user's agent to support real-time decision-making or user guidance, and optionally presented in natural language or visual format. The overall process enables goal-directed prediction through the combination of structured experience mining and generative language-based reasoning.

In some embodiments, the system may implement an incentive mechanism to encourage the submission of structured experience reports by user-associated agents. Upon submission of a report describing a user's attempt to achieve a defined goal using a specific option-along with outcome data and contextual information—the agent may be rewarded through various mechanisms. The incentive may take the form of a usage credit, which enables the agent to access future prediction queries without cost, or a digital token, which may be recorded on a centralized server or decentralized ledger and optionally exchanged for platform services, goods, or monetary value. In certain implementations, the incentive may consist of direct financial compensation, whereby the agent or user receives currency or a digital payment in exchange for providing verified, high-value experience data. The amount or type of incentive may vary depending on factors such as the relevance of the report to current prediction demand, the rarity or novelty of the reported scenario, or the report's consistency with other agent-submitted data. Incentives may be adjusted dynamically based on system-defined quality metrics or validation signals. This reward mechanism serves to ensure that personal agents contribute high-quality, timely, and contextually rich data, thereby increasing the density and diversity of the experience repository, which in turn enhances the system's ability to provide accurate goal outcome predictions for future users.

In some embodiments, the system may include a verification mechanism configured to ensure that submitted experience reports reflect authentic user interactions. This mechanism may operate in various modes, optionally managed or initiated by the personal agent. In one configuration, the agent may be required to participate in a staking process, wherein a digital token or reputation score is temporarily committed as collateral when an experience report is submitted. At a later point, the system may randomly or selectively challenge the agent to provide proof of the reported experience, such as supplemental metadata, sensor logs, or documentary evidence. If the agent fails to provide such proof, the staked value may be partially or fully slashed, disincentivizing dishonest reporting. In other embodiments, the agent may attach a proof of payment or transactional receipt to the report, such as a digital invoice, e-commerce confirmation, or NFC payment log, demonstrating that the product or service was actually acquired. In further implementations, the agent may automatically generate usage telemetry, such as device activity logs, geolocation patterns, interaction timestamps, or other passive signals indicative of genuine engagement. These verification signals may be cryptographically signed, anonymized, or privacy-preserving, and used to calculate a report confidence score. Reports with higher confidence may receive greater rewards or higher weight in predictive computations. The system may also support third-party validation services or cross-agent corroboration mechanisms. By assigning verification responsibilities to the personal agent and linking them to staking, proofs, or system-collected signals, the platform may maintain high data integrity without requiring direct user intervention.

Following are step-by-step high-level system descriptions using plain English and numbered steps. For stylesheet-neutral filing, these enumerations are rendered as continuous paragraphs without bullets or special layout while preserving the same substance and scope.

### Part A: Making a Goal-Based Prediction

Step 1: A user or agent defines a goal, for example, “Charge my phone while having coffee at the central train station.” Step 2: The agent extracts primary keys, which are facts known in advance such as location central_station, venue type cafe, time of day morning, and goal charge_phone. Step 3: The agent queries the experience database using these keys and requests relevant past experience reports involving similar contexts. Step 4: The system filters and selects the most relevant past experiences, for example, five reports involving Cafe X, Table 4, and similar times. Step 5: The system constructs a custom prompt for a language model and includes the current goal and a summary of selected experiences. Step 6: The language model analyzes the data and returns a prediction, which may include an estimated chance of success such as 65 percent, risks such as outlet reliability and high occupancy, and advice such as “Table 4 is preferred, or try Cafe Y after 10 AM.” Step 7: The agent presents this prediction and recommendation to the user to help select the best option with informed foresight.

### Part B: Submitting an Experience Report

Step 1: After the user attempts the action, the agent logs the result, for example, “Charged phone successfully for 30 minutes at Cafe X, Table 4.” Step 2: The agent formats this into a structured report that includes the goal, the selected option such as Cafe X, the outcome such as success or failure, and context including time, location, device, and similar attributes. Step 3: The system stores the experience in the shared database. Step 4: The agent receives an incentive such as prediction access credits, a digital token possibly exchangeable for money or services, or direct monetary payment.

### Part C: Ensuring Report Authenticity (Verification and Staking)

Step 1: In some cases, the agent may be required to lock a stake and commit a digital stake such as a token or credit when submitting the report. Step 2: The system may later request proof of the experience, which could include proof of purchase or payment, usage telemetry from the device, or location or activity logs. Step 3: If the agent provides valid proof, the stake is returned and if not, the stake may be slashed and partially or fully lost. Step 4: Verified reports are given higher trust weight and may receive greater incentives and influence predictions more strongly.

Examples (MCP Integration): The following concise walkthrough illustrates how the invention may operate over the Model Context Protocol, which may serve as a standardized, cross-platform interface for tool invocation between personal agents and the experience processing servers. Step 1: A personal agent establishes an MCP session with the platform and discovers tools predict_goal and submit experience, which may be advertised in a capability manifest. Step 2: The agent invokes predict_goal with an inline request such as

{“tool”:“predict_goal”,“args”:{“goal”:“charge_phone”,“candidates”:[{“option_id”:“cafe_x_table_4”},
{“option_id”:“cafe_y_any”}],“context”:{“location”:“central_station”,“time_of_day”:“morning”,“devic
e_type”:“mobile_phone”}}}. Step 3: The server returns a machine-readable MCP result such as
{“likelihoods”:[{“option_id”:“cafe_x_table_4”,“success_pct”:0.65,“risks”:[“outlet
interruptions”,“table availability”]},{“option_id”:“cafe_y_any”,“success_pct”:0.30,“risks”:[“no
outlets”]}],“retrieval”:{“matched_reports”:3,“primary_keys”:[“goal:charge_phone”,“venue_type:cafe”
,“location:central_station”,“time_of_day:morning”,“device_type:mobile_phone”]},“confidence”:0.72,
“advice”:“Request Table 4 at Café X; carry a power bank; consider alternatives after 10:00 AM.”}.

Step 4: After acting, the agent reports the realized outcome via submit experience using a structured payload such as {“goal”:“chargephone”,“selected_option”:“cafe x_table_4”,“outcome”:“success”,“timestamp”:“2025-07-14T09:40:00Z”,“context”:{“location”:“central_station”,“beverage”:“coffee”,“duration_minutes”:3 0},“proofs”:{“receipt_ref”:“inv_9a2”,“telemetry_hash”:“th_847c” }}. Step 5: The server acknowledges and may issue incentives and verification instructions, for example {“accepted”:true,“report_id”:“rpt_12345”,“incentive”:{“type”:“prediction_credit”, “value”:1},“verificat ion”:{“stake_required”:true,“challenge_deadline”:“2025-07-15T12:00:00Z” }}. This example shows how MCP may fit into the invention as one interoperable protocol among REST, gRPC, WebSockets, and message queues, enabling standardized tool discovery and invocation while preserving the structured inputs and outputs required by the claimed flows.

Enablement: A skilled practitioner could implement the invention without undue experimentation by following the detailed description and steps. A suitable implementation may define a structured report schema containing fields for goal identifier, selected option identifier, outcome label, timestamp, and contextual attributes including at least location token, device type, time-of-day, vendor identity, and optional telemetry or receipt references. The shared experience repository could be a relational or document database indexed by primary keys and augmented by secondary indices or embeddings for similarity search. The prediction engine may include a retrieval stage that computes context similarity using exact key matching, weighted Jaccard over categorical attributes, cosine similarity over learned embeddings, or hybrid scoring, followed by an analysis stage that could use a language model, a gradient-boosted tree, or a logistic regression to produce per-option success likelihoods and human-readable risks and advice. The verification mechanism may accept cryptographically signed device logs and receipt hashes, maintain staking ledgers, and compute confidence scores that weight reports during prediction. The query interface could be exposed over REST and gRPC with JSON payloads as exemplified herein, and client SDKs could be provided for mobile and server agents. Fallback operation may cache a rolling window of recent reports on the device and perform local scoring when offline, synchronizing upon reconnection. These concrete steps, combined with the examples and flows already provided, could be directly used to build operational embodiments. Technical Effects: The invention may deliver measurable technical effects including increased prediction accuracy through context-conditioned retrieval and confidence-weighted aggregation, reduced time-to-decision by automating option ranking based on prior outcomes, improved data integrity via staking and verification that lowers the influence of fraudulent or low-quality inputs, reduced network and compute load during outages through local fallback inference, and enhanced interoperability that reduces integration friction across heterogeneous clients. In practical terms, users could avoid failed attempts, reduce retries, and minimize wasted purchases, while the system could exhibit improved calibration and lower false recommendation rates as the repository grows. Court-Readiness and Patentability Considerations: The claimed invention may be characterized in terms of concrete improvements to computer functionality and networked computer systems rather than an abstract idea. The system employs specifically structured data objects, namely machine-readable structured experience reports and prediction queries with defined fields and primary keys, stored and indexed in a shared experience repository using concrete retrieval mechanisms such as exact-match indices, weighted categorical similarity measures, and embedding-based similarity. The prediction engine may execute a bounded, machine-implemented retrieval-and-analysis pipeline that transforms the structured inputs into machine-readable outputs with stable field names for per-option likelihoods, risks, and recommendations. These operations may require specialized data structures and coordinated server-side modules, including experience processing servers, a verification and staking module enforcing cryptographically signed proofs and collateralized submissions, and an incentive manager integrated with metering and billing subsystems. The platform may provide demonstrable technical improvements, including reduced network and compute utilization via offline fallback with synchronization, improved data integrity through cryptographic verification and staking that alters weighting and model inputs, and improved calibration of predictions through context-conditioned retrieval. The method steps are tied to particular machines comprising processors, memory, non-transitory storage media, and secure communication interfaces; the personal agent apparatus and servers may perform operations that could not be executed as a mental process, including cryptographic signature verification, telemetry ingestion, similarity search over indexed corpora, and generation of structured responses conforming to API schemas. Enablement and written description may be satisfied by the detailed schema, retrieval algorithms, verification flows, and deployment options disclosed herein, while non-obviousness may be supported by the specific combination of primary-key-conditioned retrieval, confidence-weighted aggregation with verification and staking, incentive-tied data quality control, and externally observable response semantics. For enforcement, black-box testing may demonstrate infringement by invoking the documented APIs with specified inputs and observing returned machine-readable likelihood fields, risk annotations, confidence indicators, and retrieval counts, without requiring source code inspection. These considerations may increase resilience against eligibility and validity challenges and facilitate evidentiary showings in litigation.

Flows: The text provides explicit process flows for prediction, reporting, and verification using numbered steps that could be directly translated into flowcharts. The flows delineate actor roles, inputs, processing stages, decision points, and outputs in a manner that supports method claims and facilitates unambiguous implementation.

Support for Claims: Each claim is supported by descriptive disclosure. The method claims are enabled by the stepwise flows and data schemas. The system claim is supported by the component descriptions including servers, repository, prediction engine, incentive manager, and verification module. The computer-readable medium claim is supported by the described instructions implementing the method. The apparatus claim is supported by the personal agent functions. Specific features such as primary-key indexing, interoperability protocols, fallback modes, externally observable outputs, incentives, and verification are described in both the summary and detailed description and are further mapped in the Anchor section, ensuring written description support for all recited elements. Alternative Implementations and Broadening: The invention may be realized with centralized or distributed repositories; deterministic rules or probabilistic models; language models, tree ensembles, linear models, or Bayesian estimators; exact-match indices, vector embeddings, or hybrid retrieval; on-premise, cloud, or edge deployments; pseudonymous, anonymous, or fully identified agents; and cryptographic verification using public-key signatures, secure enclaves, or trusted third-party attestations. Reports could be ingested via mobile apps, browser extensions, operating-system services, or IoT devices. Options could include products, services, venues, workflows, or environmental resources. Likelihood outputs may be percentages, confidence intervals, or ordinal ratings, and recommendations could be textual, visual, or API-returned data. These alternatives broaden protection while remaining within the claimed inventive concept.

Continuation-Ready Itemized List of Features: Embodiments can be described by the following itemized list presented inline so it may be reused in continuations, with each numbered entry corresponding to a claim-protectable feature: (i) receiving structured experience reports describing goal-directed attempts with outcome data and context; (ii) storing the reports in a shared experience repository accessible to agents; (iii) processing prediction queries to estimate per-option success likelihoods under stated conditions; (iv) issuing access incentives to contributing agents; (v) incentives comprising prediction credits, reputation adjustments, or priority access; (vi) incentives comprising monetary rewards conditioned on relevance, rarity, uncertainty resolution, or validated telemetry; (vii) reports including metadata such as location, time, identifiers, device, profile, or environment; (viii) prediction queries including goals, candidate options, and optional context with computed likelihoods; (ix) returning failure summaries, remediation effort estimates, alternative options, or verified warnings; (x) secure interfaces and pseudonymous, cryptographically verified, or anonymized identities; (xi) iterative accuracy improvement through feedback, follow-up logs, and corrections; (xii) inclusion of telemetry or signed usage logs enabling partial or full automated validation; (xiii) support for experience-retrieval mode and direct-prediction mode; (xiv) a system comprising experience processing servers, shared repository, prediction engine, incentive manager, and verification and staking module; (xv) a non-transitory medium storing instructions to perform the method; (xvi) a prediction engine with retrieval and ranking, prompt or feature construction, and analysis using a language model or other learner; (xvii) indexing and retrieval using primary keys including goal, type, location, time, device, identifiers, and vendor; (xviii) machine-readable outputs including per-option likelihoods, risks, remediation guidance, and alternatives; (xix) interoperability via multiple protocols and SDKs for diverse platforms; (xx) fallback local prediction with deferred synchronization; (xxi) subscription and usage-based access controls including credits, metering, tiered QoS, and billing; (xxii) a personal agent apparatus implementing goal detection, key extraction, report formatting, provenance, and user interaction. The foregoing entries provide continuation-ready support even if formal claims are later amended or restructured.

Claim Layering: The claim set may include independent claims directed to a method, a system, a non-transitory computer-readable medium, and a personal-agent apparatus, with dependent claims refining specific modules and operations. Additional independent or dependent claims may be pursued in continuations using the continuation-ready itemized list while maintaining the number of independent claims in this filing below twenty.

No Unneeded Limitations: The main method claim may be drafted to include only operations that a competitor would unavoidably perform to provide predictive goal outcome guidance based on shared experiential data, namely receiving structured reports, maintaining them in an accessible repository, and processing prediction queries to produce likelihood estimates. Optional features such as incentives, staking, telemetry, interoperability options, and fallback modes are framed as dependent subject matter to avoid unnecessarily narrowing the core protection.

In practice it is preferred to forecast goal outcomes using structured experience reports, which leads to reduced reliance on ad hoc planning and repeated trial-and-error activities. As a result, unnecessary movement of goods and persons is prevented because planning errors that would otherwise require corrective travel or redundant shipments are avoided. More specifically, the system produces the effect of reducing communication overhead and resource cycles associated with misaligned expectations, because structured reporting enables predictive algorithms to generate more accurate outcome forecasts, which results in improved efficiency of both digital and physical operations. Since transport of goods and travel of persons correlate directly with fuel consumption, the invention indirectly yields a lower carbon footprint in addition to improved system efficiency.

External Observability: The system may define externally observable behaviors for infringement assessment including the acceptance of prediction queries specifying a goal and candidate options, the emission of machine-readable responses containing per-option likelihoods, identified risks, and recommended alternatives, and the availability of an experience-retrieval mode returning context-matched reports. Additional observable signals could include authenticated API endpoints, response schemas with stable field names for likelihood and risk data, and server logs or client-visible headers indicating confidence scores and retrieval counts. These externally visible inputs and outputs could enable black-box testing to demonstrate the presence of claimed features without inspecting internal source code.

Interoperability Coverage: The platform may interoperate across heterogeneous environments by exposing stable APIs over REST, gRPC, WebSockets, and message-queue transports, with SDKs for mobile, desktop, and server platforms. Data exchange could use JSON or protocol buffers with versioned schemas and content negotiation, allowing third-party agents to integrate without modifying core algorithms. Primary-key taxonomies and vocabularies may be extended or mapped to industry standards to ensure compatible retrieval and scoring across vendors and ecosystems. Workaround Resistance: The invention may be designed to resist design-arounds by competitors attempting to avoid literal claim elements while still delivering substantially the same functionality. Replacing a language model with any other analysis component such as a rules engine, gradient-boosted tree, logistic regression, or a bespoke heuristic does not avoid the core steps of receiving structured experience reports, storing them in an accessible repository, and processing prediction queries to compute per-option success likelihoods under stated conditions as recited. Altering interface protocols or schemas, such as renaming fields, changing taxonomies, or mapping keys to proprietary identifiers, still results in primary-key-conditioned retrieval and context-based scoring that are externally observable via machine-readable responses reporting per-option likelihoods, identified risks, and alternatives. Implementing the system fully on-device, fully in the cloud, or in a hybrid edge configuration continues to practice the claimed flows of report ingestion, repository maintenance, and prediction processing. Eliminating incentives, staking, or cryptographic proofs does not avoid infringement of the independent claims directed to report receipt, storage, and prediction computation, while dependent claims and itemized features provide coverage when such mechanisms are present. Substituting storage layers or retrieval techniques, such as using a time-series store, key-value store, relational database, vector index, or hybrid index, still performs retrieval keyed by goal, location, device, vendor, time-of-day, or equivalent identifiers. Delaying predictions, batching queries, or streaming results with incremental updates still returns machine-readable outputs containing per-option success likelihoods and risk annotations as externally verifiable behaviors. Consequently, a specialist tasked with proposing a non-infringing alternative would be constrained to remove at least one indispensable operation of the core method, namely structured report receipt, repository persistence, or prediction query processing producing per-option likelihoods, which would eliminate the commercial utility of a system purporting to provide predictive goal outcome guidance based on shared experiential data.

Fallback Embodiments: Simpler or partial implementations may include a local-only mode in which an agent caches recent reports and computes naive success rates without server access, a server-only mode where retrieval is centralized and client agents act as thin query front-ends, or an implementation that omits incentives and staking while still performing structured report ingestion and prediction. These embodiments may still realize the inventive concept of forecasting goal outcomes from structured experiential data.

Damages and Monetization: The system may support subscription and usage-based models through issuance and redemption of prediction credits, per-query metering, tiered quality-of-service, and integration with payment processors or digital wallets. Technical features supporting monetization could include account and tenant separation, auditable usage logs, rate-limiting and burst controls, prepaid and postpaid billing flows, and revocable tokens enabling time-bound access. These mechanisms may increase the calculable value of infringement by tying technical usage to measurable economic impact. In some embodiments, the platform may also maintain immutable, cryptographically timestamped usage ledgers that attribute each prediction response and report ingestion to an account, include per-response identifiers and metered units, and expose exportable billing records and compliance-grade audit trails. The system may retain signed receipts and aggregated usage summaries sufficient to reconstruct historical consumption, compute reasonable-royalty baselines, and correlate technical usage with revenue realized by a tenant, and may provide evidence-preservation and reporting interfaces that enable third-party auditors to verify counts without access to source code. Service-level counters, per-feature toggles, and license-enforcement gates may be used to show which technical capabilities were enabled and consumed, thereby supporting damages calculations tied to specific infringing features.

### Anchor: Elements and Relationships Across the Embodiment

The following provides an explicit anchor of core elements referenced throughout this embodiment and their relationships, enabling precise mapping between processes, data structures, and actors. Core actors and components: Personal agent associated with a user, capable of detecting or inferring user goals, extracting primary keys, formatting structured experience reports, submitting prediction queries, receiving predictions, and presenting recommendations. Experience processing servers configured to receive reports and queries, orchestrate validation and incentive flows, and coordinate prediction computations. Shared experience repository serving as persistent storage for structured experience reports, associated confidence scores, provenance artifacts, and indices keyed by primary keys such as goal, location, venue type, time, device, product/service identifier, and vendor identity. Prediction engine comprising at least a retrieval and ranking module for context-similar prior experiences, a prompt construction module, and an analysis module that may invoke a language model or other statistical learners to produce likelihood estimates, risks, and recommendations. Incentive manager configured to issue prediction access credits, digital tokens, reputational adjustments, priority access tiers, or monetary rewards upon acceptance or verification of submitted experience reports. Verification and staking module configured to manage optional collateral staking on submission, challenge-response proof collection, cross-agent corroboration, proof-of-purchase attachment, telemetry verification, cryptographic signing, and confidence score updates. Identity and privacy subsystem supporting pseudonymous operation, cryptographic signatures, anonymization, and secure communications. Query interface accessible by agents, supporting modes including experience retrieval for local inference and direct prediction for server-side scoring.

Core data objects and fields: Structured experience report containing goal, selected option, outcome label (success, partial success, failure), timestamp, and contextual metadata including, by way of example, location, device, time-of-day, setup steps, user feedback, environmental conditions, and any attached proofs or telemetry references. Primary keys extracted from context for both retrieval and indexing, including goal identifiers, venue or service type, location tokens, time-of-day, device type, product or service identifiers, vendor identity, and other observable attributes. Prediction query specifying a goal, one or more candidate options, and an optional context specification; the response includes goal realization likelihood scores per candidate, identified risks, remediation guidance, and alternative options. Provenance and confidence artifacts including cryptographic signatures, staking status, verification outcomes, telemetry hashes or pointers, receipts, and corroboration links. Core relationships and flows: Report submission flow wherein the personal agent detects or is informed of a goal-directed attempt, assembles a structured experience report with contextual metadata and any available proofs, and submits it via the secure query interface; the experience processing servers store it in the shared experience repository, compute or update a confidence score in coordination with the verification and staking module, record provenance, and notify the incentive manager to issue applicable incentives. Prediction retrieval and computation flow wherein the personal agent extracts primary keys from the current context and submits a prediction query; the prediction engine retrieves and ranks context-similar reports from the shared experience repository, constructs an analysis prompt or feature set, computes per-option goal realization likelihood scores with risks and suggestions, and returns a structured response to the agent for presentation to the user. Feedback and learning loop wherein after an action based on a prediction, the agent logs the realized outcome as a new structured experience report; the repository and prediction engine incorporate the new data point to refine future estimates, optionally adjusting confidence weights based on verification results and cross-agent corroboration. Incentive and verification linkage wherein issuance of incentives is conditioned on report acceptance and, where applicable, successful verification; staking events, challenges, and proof submissions update report confidence and may increase the weight of verified reports in prediction computations.

Example-to-element mapping: The SIM card roaming example maps the selected option to a product/service identifier and vendor identity; the outcome label reflects activation success or failure; the context includes location-of-use and device; verification may include proof-of-purchase and connectivity telemetry. The cafe charging example maps venue type:cafe, location:central_station, time_of_day:morning, device_type:mobile_phone as primary keys; retrieved reports include outcome labels and details such as outlet availability and interruptions; the prediction engine returns a success probability with risks and suggestions.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

Item 1. A method for providing predictive goal outcome guidance via an experience sharing system, the method comprising the steps of:
(a) receiving, from a personal agent, a structured experience report describing a user's attempt to achieve a defined goal using a selected option, the report including outcome data and contextual metadata;
(b) storing the experience report in a shared experience repository accessible to other agents; and
(c) processing a prediction query submitted by an agent, wherein the system analyzes previously submitted experience reports to estimate the likelihood that each of a plurality of candidate options will achieve a specified goal under given conditions.

Item 2. The method of item 1, further comprising issuing an access incentive to the contributing agent in exchange for the submitted experience report.

Item 3. The method of item 2, wherein the access incentive comprises one or more of:
(a) a prediction access credit;
(b) a reputational score adjustment; or
(c) priority access to high-quality predictions.

Item 4. The method of item 2, wherein the access incentive comprises a monetary reward, issued upon submission of an experience report that satisfies one or more criteria selected from:
(a) high relevance to a trending prediction query,
(b) rarity or novelty of the reported scenario,
(c) confirmation of a previously uncertain outcome, or
(d) inclusion of validated telemetry or third-party verification.

Item 5. The method of item 1, wherein the structured experience report includes metadata selected from: geographic location, time of use, product or service identifier, device type, user profile, or environmental conditions.

Item 6. The method of item 1, wherein the prediction query includes:
(i) a user-defined or agent-inferred goal,
(ii) a list of candidate options under consideration, and
(iii) an optional context specification,
and wherein the system computes a goal realization likelihood score for each candidate option based on aggregate outcomes from similar historical experiences.

Item 7. The method of item 1, further comprising returning, in response to a prediction query, additional data selected from:
(a) a summary of common failure points,
(b) estimated remediation effort if the goal is not achieved,
(c) alternative options with higher historical success rates, or
(d) user-verified warnings or anomaly flags.

Item 8. The method of item 1, wherein experience reports are submitted and prediction queries are executed via a secure communication interface, and wherein agent identity is pseudonymous, cryptographically verified, or anonymized.

Item 9. The method of item 1, wherein prediction accuracy is iteratively improved using a feedback loop that incorporates:
(a) new experience reports,
(b) follow-up success or failure logs from agents that acted on prior predictions, or
(c) corrections or post-hoc annotations.

Item 10. The method of item 1, wherein submitted experience reports include or reference telemetry data or signed usage logs from user devices or applications, enabling partial or full automated validation of the reported outcome.

Item 11. The method of item 1, wherein the system supports both:
(a) an experience retrieval mode, in which a querying agent receives historical reports for local inference; and
(b) a direct prediction mode, in which the system returns a computed likelihood score for each option in the context of a specific goal.

Item 12. A system for forecasting goal outcomes using structured experience reports, comprising one or more experience processing servers, a shared experience repository, a prediction engine, an incentive manager, and a verification and staking module, each communicatively coupled via a secure interface and configured collectively to perform the steps of item 1.

Item 13. A non-transitory computer-readable medium storing instructions that, when executed by one or more processors, cause the one or more processors to perform the method of item 1.

Item 14. The system of item 12, wherein the prediction engine comprises:
(a) a retrieval and ranking module configured to select context-similar prior experiences;
(b) a prompt construction or feature extraction module; and
(c) an analysis module configured to invoke a language model or other statistical learner to compute likelihood estimates, risks, and recommendations.

Item 15. The method of item 1, wherein indexing and retrieval employ primary keys including at least one of: goal identifier, venue or service type, location token, time-of-day, device type, product or service identifier, and vendor identity.

Item 16. The method of item 1, further comprising emitting externally observable outputs comprising, for each candidate option, a goal realization likelihood score, identified risks, remediation guidance, and alternative options, in a machine-readable response format consumable by client agents.

Item 17. The method of item 1, wherein interoperability is provided by exposing the query interface over multiple protocols selected from REST, gRPC, WebSockets, and message-queue transports, and by providing software development kits for mobile, desktop, and server platforms.

Item 18. The method of item 1, further comprising a fallback operating mode in which predictions are computed using locally cached experience reports when connectivity to the shared experience repository is unavailable, and wherein deferred report submissions are synchronized upon reconnection.

Item 19. The method of item 1, further comprising enforcing subscription and usage-based access controls including issuance and redemption of prediction credits, metering of query volume, tiered quality-of-service, and billing via payment processors or digital wallets.

Item 20. A personal agent apparatus configured to detect or infer user goals, extract primary keys, format and submit structured experience reports with optional proofs, submit prediction queries, receive prediction responses, and present recommendations, the apparatus comprising modules for key extraction, report formatting, provenance and identity management, and user interaction.

### Embodiment JE: System and Method for Agent-Mediated Strategic Matchmaking

A system and method are disclosed for agent-mediated strategic matchmaking in which autonomous agents representing distinct parties announce goals and associated strategies, and a central platform evaluates cross-agent pairings to detect synergistic opportunities. The platform encodes goal and strategy content, computes alignment and mutual benefit using models and logic rules, and emits a match object when a configurable synergy condition is satisfied. Upon match, a shared negotiation interface is provisioned under an implicit or explicit confidentiality framework, or connection tokens or contact endpoints are exchanged to enable negotiation via native channels, and agents may exchange structured digital negotiation agreements. Operational features include feedback-driven refinement, interoperability via adapters, auditability through append-only metering with signed receipts, and externally observable watermark identifiers. The approach yields technical effects including improved recall and precision of non-obvious collaborations, reduced computational load via pruning, gated sensitive data exchange, accelerated negotiation cycles through machine-readable terms, and robust observability for enforcement and damages estimation across heterogeneous environments.

FIELD OF THE INVENTION: The present invention relates to autonomous agent systems and, more specifically, to systems and methods for identifying and enabling strategic collaborations between agents representing distinct parties by means of goal-based matchmaking, automated synergy scoring, and structured agent-to-agent negotiation.

BACKGROUND: In modern digital environments, autonomous agents are increasingly employed to represent individuals, companies, or institutions in performing tasks such as recommendation, monitoring, and decision-making. However, the problem of discovering non-obvious collaborative opportunities between agents acting independently remains unsolved. Conventional systems rely on static profiles, keyword-based searches, or pre-existing relationships. There is no known framework for enabling agents to autonomously announce strategic goals, discover synergies through reasoning, and engage in structured negotiation when mutual value is detected.

SUMMARY: This invention provides a system and method for agent-mediated strategic matchmaking. The system allows agents to submit structured goal announcements, each expressing an intent, offer, or need of a respective party. A central platform continuously evaluates pairs of goal announcements originating from different agents. When a potential synergy is detected based on semantic similarity, goal alignment, or inferred mutual benefit, the system generates a match object and delivers it to the agents of both parties. Upon match detection, the system further provides a shared communication channel, such as a private chat interface, to enable agent-to-agent negotiation, or exchanges connection tokens or contact endpoints that enable the agents to initiate negotiation within native or third-party channels while preserving traceability. Entry into the chat may imply mutual agreement to a predefined or negotiated confidentiality framework, optionally formalized through a digital negotiation agreement (DNA). The agents may exchange structured terms, evaluate feasibility, propose collaborative actions, or escalate the opportunity to human users. This system enables autonomous agents to go beyond passive task execution and engage in intelligent matchmaking and strategic value discovery across domains, industries, and interest areas.

GENTLE INTRODUCTION: At a high level, each party may have an autonomous software agent that posts, in simple terms, what it wants and what it can offer. The platform may act like a neutral switchboard. It may read what different agents have posted, look for two parties whose wants and offers fit together, and, only when a fit is found, give them a safe way to connect. The safe connection may be a private chat hosted by the platform or, alternatively, a pair of tokens or contact endpoints that allow the parties to talk in their own tools while keeping a verifiable trail. Until a match exists, sensitive details may remain hidden. After connecting, the agents may exchange structured terms to speed up agreement, and the platform may keep tamper-evident receipts and visible identifiers so the process is auditable, fair, and hard to counterfeit across different environments.

EXAMPLES: The following concrete walkthrough illustrates how the system operates from goal posting to negotiation. First, Agent A acting for a startup states the goal Secure €500K in funding to demonstrate a pesticide-free laser drone system and provides strategies such as Offer co-branding rights on field trial deployments, Provide ESG data from chemical-free pilot zones, and Seek sponsorship partnerships with sustainability-aligned corporations. Next, Agent B acting for an ESG-focused fashion brand states the goal Strengthen our sustainability branding in the EU market and provides strategies such as Sponsor innovative agricultural technologies aligned with ESG objectives, Seek co-branded projects that highlight clean production methods, and Support startups working to eliminate chemical inputs in textile supply chains. The platform encodes both agents' goals and strategies, forms cross-agent strategy pairs, and evaluates them using embeddings, alignment logic, and optional model-generated rationales. When the pair Seek sponsorship partnerships with sustainability-aligned corporations and Sponsor innovative agricultural technologies aligned with ESG objectives exceeds a configurable match threshold, the platform emits a match object that includes the matched goals, the selected strategy pair, a synergy score, and a concise explanation. The communication module then either provisions a private negotiation interface governed by an implicit confidentiality framework or returns connection tokens or contact endpoints so the agents can negotiate in their native channels with traceability preserved. As negotiation proceeds, the agents may introduce a digital negotiation agreement to exchange and accept machine-readable terms. Throughout, metering records immutable usage events and generates signed receipts, and a signed, externally observable identifier is embedded into the match artifact and any link, enabling attribution and later reconstruction without internal inspection of counterparties' systems. Example JSON: {“agentA”:{“goal”:“Secure €500K in funding to demonstrate a pesticide-free laser drone system”,“strategies”:[“Offer co-branding rights on field trial deployments”,“Provide ESG data from chemical-free pilot zones”,“Seek sponsorship partnerships with sustainability-aligned corporations”]},“agentB”:{“goal”:“Strengthen our sustainability branding in the EU market”,“strategies”:[“Sponsor innovative agricultural technologies aligned with ESG objectives”,“Seek co-branded projects that highlight clean production methods”,“Support startups working to eliminate chemical inputs in textile supply chains”]},“match”:{“strategy_pair”:[“Seek sponsorship partnerships with sustainability-aligned corporations”,“Sponsor innovative agricultural technologies aligned with ESG objectives”],“matched_goals”:[“Secure €500K in funding to demonstrate a pesticide-free laser drone system”,“Strengthen our sustainability branding in the EU market”],“synergy_score”:0.93,“explanation”:“The strategies show mutual value exchange: the startup receives funding and visibility, while the sponsor strengthens ESG branding by supporting pesticide-free innovation.”,“chat_link”:“https://synergy-platform.ai/chat/xyz123”,“nda_implied”:true}} In software embodiments, agents and the platform may interoperate using Model Context Protocol so that tools for proposing matches and opening negotiation sessions are exposed or consumed in a standard way; for example, an MCP request and response may be represented as {“mcp_call”:{“tool”:“propose_match”,“args”:{“agentA”:{“goal”:“Secure €500K in funding to demonstrate a pesticide-free laser drone system”,“strategies”:[“Offer co-branding rights on field trial deployments”]},“agentB”:{“goal”:“Strengthen our sustainability branding in the EU market”,“strategies”:[“Sponsor innovative agricultural technologies aligned with ESG objectives”]}}}} and {“mcp_result”:{“match_id”:“xyz123”,“synergy_score”:0.93,“chat_link”:“https://synergy-platform.ai/c hat/xyz123”,“watermark”:“sig:abc”,“nda_implied”:true}}, enabling standardized invocation by diverse agent runtimes without constraining internal implementations.

DESCRIPTION OF THE DRAWINGS: Drawings, if provided, may illustrate non-limiting embodiments of the invention. Illustrations may show the overall operation of the system, flows of data between components, or sequences of negotiation events. Such drawings are provided only as general examples and are not limiting.

SCOPE AND INTERPRETATION: Unless expressly stated otherwise, the scope of this disclosure is limited solely by the claims. The figures, examples, data structures, JSON, parameter values, thresholds, models, network arrangements, and named entities are illustrative embodiments. Steps and flows may be reordered, parallelized, combined, or omitted; hardware and software modules may be partitioned or consolidated; and interfaces, protocols, models, and storage formats may be substituted with functionally equivalent alternatives. Features described in separate embodiments may be combined, and individual features may be implemented independently. Terminology such as “may,” “can,” “for example,” and similar terms indicates non-limiting options. As used herein, “autonomous agent” may encompass software agents operating autonomously, semi-autonomously, or under human supervision, including clients that trigger or approve actions. As used herein, “goal declaration” may include direct submissions as well as adapter-synthesized or inferred representations derived from profiles, catalogs, or telemetry. As used herein, “shared communication interface” may include a native chat or message session, an application programming interface mediated negotiation channel, or an exchange of connection tokens or contact endpoints enabling negotiation to proceed in third-party or native channels while preserving traceability. References to a “synergy score” or decision metric encompass any scalar, vector, binary predicate, classifier output, or rule evaluation sufficient to determine that a synergy condition is satisfied. As used herein, “predefined criteria” includes any model parameters, rules, policies, or thresholds established prior to or at the time of an individual evaluation, including values supplied dynamically by external services or humans at invocation time, and encompasses deterministic, probabilistic, heuristic, or rule-based formulations. As used herein, “platform” and “system” refer to logical functionality that may be implemented in a centralized service, a distributed cluster, a federated network, or peer-to-peer clients under common orchestration, with modules deployable on servers, edge devices, or client agents. As used herein, “connection tokens” or “contact endpoints” include, without limitation, aliases, blinded relay addresses, application handles, one-time join codes, URIs, webhook destinations, service-specific identifiers, cryptographic proofs, or any pointer that, when presented by either matched party, causes a communication path to be established or resumed with traceability. As used herein, “synergy decision value” includes a numeric score, a binary or multi-class decision, or any comparable metric derived from the predefined criteria, optionally with human-in-the-loop inputs that instantiate such criteria for a given evaluation, and “providing a shared communication interface” encompasses server-mediated relays, escrow messaging, or other rendezvous mechanisms functionally equivalent to a chat or messaging session. References to specific cryptographic primitives, indices, or algorithms are exemplary and may be replaced with functionally equivalent alternatives.

DESCRIPTION OF EMBODIMENTS: In one embodiment, the system comprises a goal announcement interface configured to receive structured data from agents, each goal comprising a textual description, one or more strategies, optional constraints, and contextual metadata; a matchmaking engine configured to iterate over cross-agent goal pairs and compute a relatedness score using semantic embeddings, strategic alignment models, and mutual value templates; a threshold filter to identify synergistic goal pairs exceeding a match threshold; a communication module configured to instantiate a private chat, structured dialogue, or negotiation interface shared between matched agents, or to return connection tokens or contact endpoints that enable negotiation in third-party or native channels while preserving traceability via signed identifiers; a confidentiality enforcement layer wherein entry into the interface implies acceptance of an implicit or explicit non-disclosure agreement; and an optional digital negotiation agreement engine allowing agents to exchange machine-readable terms, usage boundaries, and agreement conditions. In another embodiment, agents may refine their goal announcements over time based on observed match outcomes, feedback loops, or shifts in strategic priorities, and the platform may maintain a history of accepted, rejected, or ignored matches to further train agent behavior. In a preferred implementation, goal announcements and associated strategies are submitted in natural language format to maintain human readability and transparency. For example, an ESG-focused fashion brand may submit the goal “Improve sustainability branding in the European market” with strategies such as “Sponsor a clean agriculture project to associate our brand with pesticide-free practices,” and an agricultural drone startup may submit the goal “Secure €500K in funding to demonstrate a pesticide-free laser drone system” with strategies such as “Offer sponsorship rights on drone field demos.” Upon detection of sufficient synergy between such parties, the system may present a shared chat link and a human-readable match summary to both agents, or exchange connection tokens enabling the agents to continue negotiation in a preferred channel, allowing negotiation and mutual evaluation to proceed with transparency and trust. In some embodiments, rather than provisioning a native chat, the communication module returns to each agent a rendezvous artifact such as a reply—to alias, a blinded relay address, a service-specific handle, a one-time join code, or a webhook destination that acts as a connection token; agents may then negotiate in their native channels while the rendezvous artifact preserves traceability, allows later reconstruction of message provenance, and maintains confidentiality boundaries by segregating identities until mutual consent is recorded.

ENABLING IMPLEMENTATION: Each goal announcement may be linked to one or more proposed strategies, where each strategy represents a possible path to achieving the associated goal. Strategies may include actions to be taken, offers to be made, or conditions under which collaboration is desired. The system evaluates all possible pairs of strategies across different agents, determining whether a pair of strategies, when taken together, form a plausible and mutually beneficial path toward satisfying at least one goal from each agent. This evaluation may consider both the semantic similarity of the strategy descriptions and the logical implications of one strategy supporting or complementing the other. Goal declarations may be submitted directly by agents or synthesized by adapters from existing data sources such as organizational profiles, product catalogs, or operational telemetry, in which case the platform treats the synthesized content as goal declarations for purposes of evaluation.

In a reference software embodiment, the matching engine may implement a two-stage candidate generation and pruning pipeline. In a first stage, for each strategy the encoder produces an embedding and queries an approximate nearest-neighbor index such as a hierarchical navigable small world graph or an inverted file index to retrieve a bounded set of candidate counterpart strategies from other agents. For each candidate pair, the system may compute a coarse similarity and a threshold-aware, monotonic upper bound on the eventual synergy decision value that depends on vector norms, precomputed per-strategy caps, and applicable rule penalties. Pairs whose bound cannot meet the match threshold may be safely discarded without evaluating the full alignment model. In a second stage, the retained pairs are scored by the alignment models and logic rules, optionally augmented by an evaluator that produces a natural-language rationale, yielding the synergy decision value and match explanation. This staged process reduces the number of expensive evaluations while ensuring that no pair capable of exceeding the threshold is prematurely dropped. The platform may further support a deterministic replay mode in which specific inputs, model identifiers, and parameters lead to a reproducible match object hash, enabling forensic verification and audit.

An example step-by-step scenario: Agent A (Startup) states the goal “Secure €500K in funding to demonstrate a pesticide-free laser drone system” and identifies strategies such as “Offer co-branding rights on field trial deployments,” “Provide ESG data from chemical-free pilot zones,” and “Seek sponsorship partnerships with sustainability-aligned corporations.” Agent B (H&M) states the goal “Strengthen our sustainability branding in the EU market” and identifies strategies such as “Sponsor innovative agricultural technologies aligned with ESG objectives,” “Seek co-branded projects that highlight clean production methods,” and “Support startups working to eliminate chemical inputs in textile supply chains.” The system evaluates all strategy pairs and identifies the pair “Seek sponsorship partnerships with sustainability-aligned corporations” together with “Sponsor innovative agricultural technologies aligned with ESG objectives,” assigns a high synergy score, and creates a match object shared with both agents including a synergy explanation, a chat link, an automatic mutual NDA, and an optional DNA exchange as the chat evolves.

Example JSON: {“agentA”:{“goal”:“Secure €500K in funding to demonstrate a pesticide-free laser drone system”,“strategies”:[“Offer co-branding rights on field trial deployments”,“Provide ESG data from chemical-free pilot zones”,“Seek sponsorship partnerships with sustainability-aligned corporations”]},“agentB”:{“goal”:“Strengthen our sustainability branding in the EU market”,“strategies”:[“Sponsor innovative agricultural technologies aligned with ESG objectives”,“Seek co-branded projects that highlight clean production methods”,“Support startups working to eliminate chemical inputs in textile supply chains”]},“match”:{“strategy_pair”:[“Seek sponsorship partnerships with sustainability-aligned corporations”,“Sponsor innovative agricultural technologies aligned with ESG objectives”],“matched_goals”:[“Secure €500K in funding to demonstrate a pesticide-free laser drone system”,“Strengthen our sustainability branding in the EU market”],“synergy_score”:0.93,“explanation”:“The strategies show mutual value exchange: the startup receives funding and visibility, while the sponsor strengthens ESG branding by supporting pesticide-free innovation.”,“chat_link”:“https://synergy-platform.ai/chat/xyz123”,“nda_implied”:true}}TECHNICAL EFFECTS AND ADVANTAGES: The goal announcement interface and associated encoders produce structured representations of goals and strategies that improve recall and precision relative to keyword search by capturing semantic intent and constraints, thereby increasing the likelihood of surfacing non-obvious but actionable collaborations. The matchmaking engine, in conjunction with alignment models, logic rules, and a configurable threshold, yields a controllable trade-off between discovery breadth and precision while reducing computational load by pruning low-likelihood pairs early, which decreases latency and infrastructure cost under load. Use of threshold-aware, monotonic upper bounds in the first-stage pruning yields provably safe filtering such that no pair capable of meeting the threshold is dropped, while substantially reducing the number of second-stage evaluations; this improves average-case latency and lowers CPU and memory consumption, constituting an improvement to the operation of the computer itself. The optional evaluator that generates rationales for matches provides explainability, enabling agents or human overseers to assess suitability quickly, which reduces false positives and accelerates negotiation initiation. Provisioning a shared communication channel with confidentiality enforcement produces a concrete technical effect of gated data exchange such that sensitive strategy details are only revealed within a scoped interface after a positive match decision, lowering the risk of data leakage and enabling compliance with organizational policies. The digital negotiation agreement engine enables machine-readable term exchange that reduces round-trips and parsing errors compared to ad hoc natural-language bargaining, which shortens time-to-agreement and supports partial automation of acceptance logic. The feedback and history store closes a learning loop by recording outcomes and reasons for acceptance or rejection, which improves future matching quality through data-driven refinement without requiring manual reconfiguration. Operational telemetry written to an append-only ledger with signed usage receipts produces tamper-evident audit trails suitable for forensic reconstruction, billing, and compliance, while watermarking of match artifacts and links creates externally observable, verifiable identifiers that permit attribution without access to internal systems. Adapter-based interoperability for embeddings, vector indices, and communication protocols mitigates vendor lock-in and allows seamless platform substitutions without service interruption, while policy-controlled quotas and rate limiting bound resource consumption to maintain predictable latency, fairness under multi-tenant conditions, and resilience against denial-of-service patterns. Collectively these effects provide real-world advantages including higher-quality match delivery, reduced operational cost, enhanced privacy and compliance, faster negotiation cycles, robust observability for enforcement and damages estimation, and dependable operation across heterogeneous environments.

In practice it is preferred to implement agent-mediated strategic matchmaking, which leads to reduced generation of irrelevant or low-value pairings. As a result, unnecessary communication, negotiation cycles, and resource allocations are avoided because the system converges more directly toward candidates with a high probability of mutual relevance. More specifically, the use of semantic metadata, recursive trust evaluation, and filtering rules produces the effect of lowering processor load, network bandwidth consumption, and storage overhead by eliminating redundant or mismatched results at an early stage, which results in a measurable technical improvement in the efficiency of the matchmaking system. Since fewer irrelevant pairings progress to physical meetings, travel, or material exchange, the invention indirectly reduces resource consumption and carbon footprint while its primary effect is improved computational efficiency and reliability of agent-mediated matchmaking.

ARCHITECTURE & FALLBACKS: System architecture may include a goal and strategy encoder using a language model such as a GPT-based transformer; a vector matching engine such as cosine similarity with logic rules for implication; chat provisioning with optional prefilled negotiation prompts; implicit or explicit NDA logic; and optional structured DNA templates. Fallbacks may include prompting for refinement when no match is found, logging a cause and improving models when a match is rejected, and escalating to human review when ambiguity is detected.

STRATEGY PAIR EVALUATION VIA LLM: It is further described that the server-side evaluation of strategy pairs may be performed as follows: two strategy descriptions, submitted in natural language, are programmatically selected by the matchmaking engine and passed as input to a large language model (LLM) hosted on the platform or via an API. The LLM processes both strategies within a prompt template designed to elicit an explanation of synergy scope and rationale. The output may include whether a mutual benefit exists, a proposed form of collaboration, and a natural-language justification of the match. This output is parsed and embedded into the match object delivered to both agents, enabling transparent evaluation and initiating negotiation where appropriate.

MONETIZATION & DAMAGES MAXIMIZATION: Subscription and licensing models may be implemented to monetize usage and to provide artifacts that quantify unauthorized use for damages calculations. The platform may support multiple monetization modes including but not limited to per-seat licenses for agent operators, per-agent licenses for autonomous agents, per-match delivery fees, per-DNA transaction fees, and tiered subscriptions such as Free, Pro, and Enterprise with quotas on goal announcements, strategy pair evaluations per hour, match objects delivered per month, concurrent chat sessions, DNA exchanges, and data retention windows. Technical features supporting monetization and damages may include license issuance and verification in which each tenant is provisioned a cryptographically signed license token bound to tenant identifiers, license tier, seat count, and expiration with server endpoints verifying tokens on every API call and embedding license metadata into match objects and chat session descriptors; metering instrumentation in which the system records immutable usage events including goal ingested, pair evaluated, match_created, chat_opened, nda_acknowledged, dna_proposed, dna_accepted, and match_closed with events including timestamps, tenant id, agent id, strategy ids, match_id, and request signature and written to an append-only ledger or write-once storage to ensure tamper-evidence; usage receipts for billable actions where the server generates signed usage receipts returned to clients and logged server-side with receipts including hash(match_payload), unit_price_at_time, and license tier to enable retrospective billing and damages computation; rate limits and feature gating where quotas are enforced via token bucket or leaky bucket algorithms and when limits are reached the system throttles or defers non-critical operations while preserving a minimal compliance path including delivery of denial reasons and remaining quota; watermarking and traceability in which match objects and chat links contain opaque, signed identifiers that can be externally observed in URLs and API responses without revealing internals and that enable attribution of the originating tenant and licensed feature set if copied or rehosted; billing exports and auditability through downloadable monthly statements and machine-readable exports such as CSV or JSON lines itemizing counts of billable events, effective rates, and totals that are reproducible from the append-only ledger to support audit and dispute resolution; damages estimation support where immutable logs and watermark identifiers enable reconstruction of the number of matches delivered, chat sessions initiated, and DNAs executed to allow calculation of compensatory fees at prevailing rates and, where applicable, multipliers for willful infringement as determined by legal processes with automated summaries of reconstructed usage to support expert testimony; and compliance and suspension through policy engines that detect anomalous or prohibited usage patterns such as license sharing beyond seat count and that may warn, restrict, or suspend features while preserving access to data export to ensure continuity of evidence.

The append-only ledger may be realized as a hash-chained log in which each event includes a hash of the previous event and a hash of the current event payload computed, for example, using SHA-256, and usage receipts may be signed, for example, using ECDSA over a platform keypair with verification possible against a published public key. Monthly exports may disclose a daily Merkle root or running tip hash so that third parties can validate completeness and integrity without accessing internal systems. These monetization and evidentiary features may be designed such that externally observable artifacts such as match identifiers in links, receipt numbers in API responses, and monthly statements can be collected by a rights holder without intrusive inspection of a counterparty's systems, facilitating proof of use and supporting damages claims while maintaining user privacy.

WORKAROUND-RESILIENT COVERAGE: To reduce avenues for avoidance, embodiments may be realized in centralized, federated, or peer-to-peer deployments where matching logic executes on servers, at the edge, or within client agents while still producing a synergy decision value derived from predefined criteria and causing a communication path to be enabled. Implementations may provide the shared communication interface as a server-hosted chat, a blinded relay, or an escrowed message thread, or may instead exchange connection tokens or contact endpoints in the form of aliases, handles, one-time join codes, webhooks, URIs, or cryptographic proofs such that either agent can present the token to initiate or resume negotiation in a third-party or native channel with traceability preserved. Publication-oriented variants may deliver the match object via notifications, digest emails, dashboards, or bulletin boards that include signed, externally observable identifiers and a rendezvous artifact that functions as the connection token, thereby satisfying the communication enablement even when the negotiation occurs outside the platform's native interface. Batch and asynchronous modes may compute the synergy decision value offline, on-device, or on a schedule, while real-time modes may compute it per event; both modes fall within the same operation so long as the criteria are instantiated at or before evaluation. Human-in-the-loop workflows may contribute parameters or approvals that instantiate the predefined criteria for a particular evaluation without removing automated computation of the synergy decision value. Externally observable identifiers may be produced as signatures over canonicalized match payloads so that infringement can be established by offline verification against a published public key without access to internal systems. Attempts to avoid detection by stripping platform branding or rehosting match artifacts may still leave intact the embedded signed identifiers and receipt numbers, enabling attribution and reconstruction of usage by a rights holder without access to a counterparty's systems.

The embodiments may be described by the following itemized list: 1. A system for enabling strategic matchmaking between agents, the system comprising a goal announcement module configured to receive goal declarations from a first agent and a second agent, a matching engine configured to compare said declarations and determine a synergy decision value based on predefined criteria, and a communication module configured to provide a shared communication interface or to exchange connection tokens or contact endpoints with both agents upon determining that said synergy decision value satisfies a condition. 2. The system of item 1, wherein the goal declarations may comprise structured strategies, offers, or needs. 3. The system of item 1, wherein the synergy decision value may be determined using semantic embeddings, goal alignment logic, inferred mutual benefit, or rule-based predicates. 4. The system of item 1, wherein the shared communication interface may be governed by an implicit confidentiality agreement. 5. The system of item 1, further comprising a digital negotiation agreement (DNA) exchange layer enabling agents to submit, review, and accept structured negotiation terms. 6. The system of item 1, wherein agents may autonomously evaluate the match object and determine whether to accept, decline, or modify the proposed interaction. 7. A method for agent-mediated strategic matchmaking, the method comprising receiving a first goal announcement from a first agent, receiving a second goal announcement from a second agent, evaluating whether a synergy exists between said announcements, and, if so, providing both agents with a shared communication interface or exchanging connection tokens for further negotiation. 8. The method of item 7, further comprising inferring a mutual non-disclosure agreement upon entry into said interface. 9. The method of item 7, wherein said negotiation may include exchange of structured digital negotiation agreements. 10. The method of item 7, wherein each agent may determine internally whether to escalate the opportunity to a human user based on private policies or constraints. 11. The method of item 7, wherein a digital negotiation agreement (DNA) may optionally be introduced at a later point during the session, after the initial connection has been established, to formalize confidential or strategic collaboration terms. 12. For enablement purposes, it is further described that the server-side evaluation of strategy pairs may be performed as follows: two strategy descriptions, submitted in natural language, may be programmatically selected by the matchmaking engine and passed as input to a large language model (LLM) hosted on the platform or accessed via an external API, the LLM may process both strategies within a prompt template designed to elicit an explanation of synergy scope and rationale, and the output may include whether a mutual benefit exists, a proposed form of collaboration, and a natural-language justification of the match, which output may then be parsed and embedded into the match object delivered to both agents to enable transparent evaluation and to initiate negotiation where appropriate. 13. A non-transitory computer-readable medium storing instructions which, when executed by one or more processors, cause the platform to perform the method of any of items 7-11. 14. The system of item 1, wherein the matching engine is interoperable with multiple embedding models, vector indices, and communication protocols via adapter interfaces such that changes to platforms or APIs do not avoid operation. 15. The system of item 1, wherein match objects and chat links include externally observable, signed identifiers enabling attribution and proof of use without internal inspection of counterparties' systems. 16. The method of item 7, further comprising recording immutable usage events into an append-only ledger and generating signed usage receipts for billable actions. 17. The system of item 1, further comprising a policy engine configured to enforce quotas via token bucket or leaky bucket algorithms and to gate features by license tier. 18. The communication module of item 1, wherein the shared interface comprises at least one of a real-time chat session, an asynchronous message thread, an application programming interface mediated negotiation channel, or an exchange of connection tokens or contact endpoints used to initiate negotiation within third-party or native channels. 19. The system of item 1, wherein fallback behaviors include prompting agents to refine goals when no match is found, logging causes of rejection, and escalating ambiguous matches to human review. 20. The system of item 1, further comprising a billing export subsystem configured to produce monthly statements and machine-readable exports that are reproducible from the append-only ledger for audit and dispute resolution.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible: A system for enabling strategic matchmaking between autonomous agents representing distinct parties, the system comprising: a goal announcement module configured to receive goal declarations from a first agent and a second agent; a matching engine configured to compare the goal declarations and determine a synergy decision value based on predefined criteria; and a communication module configured to provide a shared communication interface or to exchange connection tokens or contact endpoints with both agents upon determining that the synergy decision value satisfies a condition.

The system of item 1, wherein the goal declarations comprise structured strategies, offers, or needs.

The system of item 1, wherein the synergy decision value is determined using one or more of semantic embeddings, goal alignment logic, inferred mutual benefit, or rule-based predicates.

The system of item 1, wherein the shared communication interface is governed by an implicit confidentiality agreement.

The system of item 1, further comprising a digital negotiation agreement (DNA) exchange layer enabling agents to submit, review, and accept structured negotiation terms.

The system of item 1, wherein the agents autonomously evaluate a match object and determine whether to accept, decline, or modify a proposed interaction.

A method for agent-mediated strategic matchmaking, the method comprising: receiving a first goal announcement from a first agent; receiving a second goal announcement from a second agent; evaluating whether a synergy exists between the first and second goal announcements; and, in response to determining that the synergy exists, providing both agents with a shared communication interface or exchanging connection tokens or contact endpoints for further negotiation.

The method of item 7, further comprising inferring a mutual non-disclosure agreement upon entry into the shared communication interface.

The method of item 7, wherein the negotiation comprises exchanging structured digital negotiation agreements.

The method of item 7, further comprising enabling each agent to determine internally whether to escalate an opportunity to a human user based on private policies or constraints.

The method of item 7, further comprising introducing a digital negotiation agreement during the communication session to formalize confidential or strategic collaboration terms.

The method of item 7, further comprising programmatically selecting two strategy descriptions submitted in natural language, passing the two strategy descriptions as input to a large language model within a prompt template designed to elicit an explanation of synergy scope and rationale, and parsing model output to embed a resulting justification into a match object delivered to both agents.

A non-transitory computer-readable medium storing instructions that, when executed by one or more processors, cause a platform to perform the method of any of items 7-12.

The system of item 1, wherein the matching engine is interoperable with multiple embedding models, vector indices, and communication protocols via adapter interfaces such that changes to platforms or application programming interfaces do not avoid operation.

The system of item 1, wherein match objects and chat links include externally observable, signed identifiers enabling attribution and proof of use without internal inspection of counterparties' systems.

The method of item 7, further comprising recording immutable usage events into an append-only ledger and generating signed usage receipts for billable actions.

The system of item 1, further comprising a policy engine configured to enforce quotas via token bucket or leaky bucket algorithms and to gate features by license tier.

The system of item 1, wherein the communication module provides at least one of a real-time chat session, an asynchronous message thread, an application programming interface mediated negotiation channel, or an exchange of connection tokens or contact endpoints used to initiate negotiation within third-party or native channels.

The system of item 1, wherein fallback behaviors include prompting agents to refine goals when no match is found, logging causes of rejection, and escalating ambiguous matches to human review.

The system of item 1, further comprising a billing export subsystem configured to produce monthly statements and machine-readable exports that are reproducible from the append-only ledger for audit and dispute resolution.

### Embodiment KE: Emergency Medical Guidance Via Offline Embedded Language Model in Mobile Devices

A system and method for providing emergency medical assistance using an embedded language model (LLM) within a mobile device operable without internet connectivity. The invention may provide first aid, triage guidance, and critical health instructions in real-time using on-device processing. The embedded model may optionally access locally available data, such as user medical history, biometric sensors, or GPS, and adapt recommendations accordingly. The system may support voice-based and text-based interaction, include safety mechanisms to prevent harmful hallucinations, and permit periodic updates when connectivity is restored. This allows individuals in remote or disaster-affected areas to receive potentially life-saving medical guidance autonomously.

GENTLE INTRODUCTION: Emergencies are often chaotic, and people may be far from hospitals or lose connectivity just when guidance is needed most. This invention may turn a smartphone, smartwatch, or tablet into an offline first-aid coach that listens, asks clarifying questions, and provides simple, step-by-step actions a layperson can perform. A user may speak or type what is happening, and the device may respond with clear next steps, such as how to stop bleeding, when to check breathing, and when to avoid moving an injured person. If permitted, the device may consult local signals such as heart rate, temperature, or location, but it may also operate solely from conversation when sensors are unavailable.

The guidance may be intentionally conservative. When uncertain, the system may advise stabilizing the situation, avoiding potentially harmful interventions, watching for danger signs, and seeking professional care as soon as feasible. The aim is not to replace medical professionals but to bridge the gap until help is available. All reasoning and safety checks may occur locally so the system remains available in remote areas and during outages. Conceptually, it may work like an offline navigation app for first aid: it may translate unstructured descriptions into an actionable route, continuously updating the steps as the user provides new information, while keeping privacy and safety at the forefront.

EXAMPLES: The following examples illustrate concrete, step-by-step walkthroughs of system behavior, inputs, outputs, and safety controls. These examples focus on interaction flow, context handling, and externally observable events. Where the system would ordinarily output medical instructions, the examples indicate that guidance is generated without prescribing the exact content of those instructions.

Example 1: Bleeding control with sensor context and conservative safety gating. Step 1: The user activates hands-free mode via a hotword and states that a person is bleeding. Step 2: A local speech-to-text component converts the utterance to text. Step 3: The application assembles a context object from available sensors including heart rate and location permissions if granted. Step 4: The application invokes the locally stored language model via the operating system artificial intelligence runtime, passing the normalized input and context. Step 5: The model returns a draft set of steps and a risk categorization. Step 6: The safety filtering module evaluates the draft output, applies conservative thresholds, and inserts prompts for clarification if needed. Step 7: Approved guidance is rendered via text-to-speech and displayed text. Step 8: An externally observable event is recorded to the encrypted audit log including the risk category and a hash of the displayed step list. Illustrative context JSON submitted to the model in this example: {“v”:1,“lang”:“en”,“input”:“There is active bleeding from a leg cut.”,“user”:{“ageRange”:“adult” },“sensors”:{“hrBpm”:108,“tempC”:36.9,“spo2Pct”:98},“location”:{” lat”:39.7392,“lon”:-104.9903,“altM”:1609,“region”:“US-CO” },“entitlementTier”:“plus”,“uiMode”:“ha ndsFree” }Illustrative model response envelope before safety filtering: {“risk”:“high”,“steps”:[” [system-generated bleeding control steps redacted]”],“notes”:“Consider escalation if bleeding persists >X min.”,“confidence”:0.74}Illustrative safety-filtered, externally logged summary

{“ts”:“2025-01-02T12:34:56Z”,“kind”:“guidance”,“risk”:“high”,“ui”:“tts+text”,“hash”:“b2f5ff4743667
1b6”,“tier”:“plus”,“offline”:true}

Example 2: Suspected allergy with escalation prompt and MCP tool use for on-device capabilities. Step 1: The user types that they suspect an allergic reaction. Step 2: The application queries permitted health data for known allergies using a local tool adapter. Step 3: Using Model Context Protocol (MCP), the LLM may request tools such as “getHealthProfile”, “getLocation”, and “playAlert” through defined capabilities that are handled locally. Step 4: The model generates draft steps and an escalation recommendation. Step 5: The safety filter requires an explicit user confirmation before any high-risk action recommendations appear. Step 6: The device emits an audible alert via a local MCP tool if the risk category is critical. Illustrative MCP tool schema and call:

{“tool”:“getHealthProfile”,“args”:{“fields”:[“knownAllergies”,“medications”]}} ->
{“result”:{“knownAllergies”:[“peanuts”],“medications”:[ ]}} Illustrative combined context JSON:
{“v”:1,“input”:“I think this is an allergic reaction. Lips are
swelling.”,“profile”:{“knownAllergies”:[“peanuts”]},“location”:{“lat”:51.5074,“lon”:−0.1278},“uiMod
e”:“manual”} Illustrative externally observable event:
{“ts”:“2025-01-02T13:05:10Z”,“kind”:“alert”,“level”:“critical”,“messageClass”:“escalationPrompt”,“o
ffline”:true}

Example 3: No sensors available, degraded offline mode with battery-aware behavior. Step 1: The device is in airplane mode on a low-end handset with no sensor permissions granted and low battery. Step 2: The user reports a twisted ankle via voice; speech-to-text is performed locally. Step 3: The application constructs a minimal context object with input text only and a power budget hint. Step 4: The language model runs in a low-power profile with reduced beam size set by the runtime. Step 5: The safety filter favors shorter, simpler steps and frequent check-ins. Step 6: Outputs are presented as concise items and logged. Illustrative minimal context JSON: {“v”:1,“input”:“I twisted my ankle hiking.”,“batteryPct”:12,“powerMode”:“low”,“sensors”:null,“location”:null}Illustrative runtime hint via MCP: {“tool”:“setInferenceProfile”,“args”:{“profile”:“lowPower”,“maxTokens”:128}}

BACKGROUND: Access to timely medical advice is critical during emergencies, yet individuals frequently encounter connectivity loss during travel, natural disasters, or in rural environments. Existing digital medical assistants require internet access to function, rendering them ineffective under such conditions. Furthermore, existing offline resources, such as downloaded PDFs or static rule-based applications, lack adaptability and personalized interaction. There is a need for a system that can provide context-aware, adaptive, and reliable medical guidance without relying on cloud infrastructure.

SUMMARY OF THE INVENTION: The present invention proposes an embedded large language model (LLM) that operates directly on a mobile device such as a smartphone, smartwatch, or tablet, providing medical guidance without requiring internet access. In one embodiment, the LLM is specifically trained on first-aid procedures, basic diagnostics, and emergency response protocols. The model may be optimized for edge-device inference, reducing size and power consumption while maintaining accuracy. The system may allow a user to describe symptoms or an emergency scenario via voice or text. The model interprets this input and generates a series of actionable, context-appropriate steps. Optionally, the model may utilize available local data, such as a user profile including age and known conditions, biometric sensor inputs such as heart rate, temperature, and oxygen saturation, and environmental context such as GPS location and altitude. A safety layer may constrain the model to prioritize conservative, life-preserving decisions and alert the user when a hospital visit or professional consultation is advisable. Offline logs may be stored and synced when the device reconnects.

### Anchor: Elements and Core Relationships

The following elements and their core relationships describe the principal components and data flows of the embodiments so that the structure of the system and its operations are unambiguously understood across implementations. Elements: Mobile device including processor and memory. Application executable configured for emergency guidance interaction. Locally stored language model configured for on-device inference. Operating system artificial intelligence runtime, such as Core ML or Android Neural Networks API, that executes the model. On-device artificial intelligence accelerator such as Apple Neural Engine or Qualcomm Hexagon DSP. Local speech-to-text component and local text-to-speech component enabling offline voice interaction. Sensor interfaces providing biometric data including heart rate, temperature, and blood oxygen. Location subsystem providing GPS coordinates, altitude, and regional context. Local health data store or health application integration providing user profile including age and known conditions. Safety filtering module enforcing conservative guidance and escalation prompts. Local secure storage including encrypted user interaction logs and audit records. Update module that validates and applies model and knowledge base updates when connectivity is available. Subscription and entitlement engine that verifies device-bound license tokens and feature tiers offline and refreshes entitlements when online. User interface component supporting text entry, voice prompts, hands-free activation via hotword or gesture, and externally observable indicators of subscription tier. Core relationships: User input in text or voice enters the application, which invokes the local speech-to-text component when voice is used, forming a normalized input sequence. The application packages the input with optional context comprising sensor data, location data, and health profile attributes, and submits the combined context to the operating system artificial intelligence runtime to execute the locally stored language model on the artificial intelligence accelerator where available. The language model produces draft guidance including step-by-step instructions and risk categorizations, which are immediately evaluated by the safety filtering module that enforces conservative thresholds, requests clarification when uncertainty is high, and directs escalation to professional care as indicated. Approved guidance is rendered to the user via text or via the local text-to-speech component for audio output, with hands-free mode optionally maintaining an interactive loop. All externally observable outputs including step lists, alert categories, and subscription state transitions are written as timestamped, encrypted entries to the local secure storage as part of an audit log, which is preserved for later synchronization. The subscription and entitlement engine governs feature availability including voice interfaces, regional protocol packs, and advanced safety parameters, operating offline via cryptographically verified, device-bound tokens and refreshing entitlements and receipts upon restored connectivity without interrupting operation. The update module, upon detection of connectivity, verifies the integrity and authenticity of a model and knowledge base update package, applies the update while preserving user data and logs, and enables user review and approval prior to activating the updated model. Regional adaptation modules, when present, are selected based on the location subsystem signals and may adjust instruction content to local medical practices. Throughout, the application maintains clear external indicators of tier state and operation mode to support observability while all inference and safety filtering remain local and independent of internet connectivity.

In practice it is preferred to embed the medical large language model directly within a local device, which leads to continued operation even in the absence of internet connectivity. As a result, medical guidance can be generated in real time in remote or emergency environments where external network access is unavailable or unreliable. More specifically, the embedded model produces the effect of reducing communication overhead and latency because sensitive patient data is processed locally without round-trips to external servers. This yields a measurable technical improvement in the reliability and responsiveness of the system, ensuring that essential medical advice can still be delivered under constrained connectivity conditions.

DESCRIPTION OF THE DRAWINGS: Drawings are not included in this application. Where drawings are provided in related or future filings, they may depict, for example, a block diagram of the mobile device and principal components, a flowchart of method operations corresponding to the described process flows, and screen states of the user interface during an emergency session. Any element identifiers in such drawings may correspond to the elements and relationships enumerated in the ANCHOR section.

### Detailed Description

### 1. Architecture:

The language model may be a distilled, quantized version of a medically tuned transformer model sized for edge devices, for example with approximately three billion parameters or fewer. It may execute on an edge accelerator such as an Apple Neural Engine or a Qualcomm Hexagon DSP when present, while remaining functional on general-purpose CPUs and GPUs. Core functions include input processing for text and voice, integration of contextual data such as biometrics and location, generation of responses, and application of a deterministic safety filter to constrain outputs.

### 2. Interaction Modes:

Users may interact via typed text entry, local voice interfaces in which speech-to-text conversion is performed on the device, and a hands-free mode that may be activated by a hotword or gesture to support scenarios in which manual operation is impractical. These modes may be combined within a session and the system may seamlessly transition among them.

### 3. Emergency Scenarios Covered:

The embedded LLM may provide guidance for: Cardiopulmonary resuscitation (CPR), Bleeding control, Choking, Allergic reactions, Burns, Dehydration, Seizures, Ankle sprains, fractures, and immobilization, Shock.

### 4. Safety Features:

Risk thresholds may be applied so that if confidence is low or user input is unclear, the system suggests conservative actions or requests clarification. The user may be presented with disclaimer prompts indicating that the guidance is not a substitute for professional care. The model may be fine-tuned and red-teamed to avoid hallucinations and minimize liability, with outputs constrained by structured templates and policy rules.

### 5. Update Mechanism:

The model and the associated medical knowledge base may be updated when the device regains internet access. During offline operation, logs and interactions may be saved locally in encrypted form to preserve user privacy, and upon connectivity restoration these records may be synchronized according to user or enterprise policy.

### 6. Multilingual Support:

The model may be multilingual or may employ local translation modules to enable interaction across multiple languages without relying on network-based services.

### 7. Regional Adaptation:

Location-specific medical practices may be applied by loading regional protocol packs, for example enabling venomous snakebite protocols in jungle regions, with selection driven by offline location signals or user settings.

8. Integration with Health Apps:

The system may integrate with Apple Health, Google Fit, or proprietary applications to personalize advice based on available user health profiles, subject to explicit permissions and local privacy controls.

To enable implementation of the invention, one may begin by collecting and curating a dataset comprising trusted medical literature, first aid guides, emergency medical protocols, and real-world patient dialogue samples. The language model may be fine-tuned using supervised learning and reinforcement learning with human feedback (RLHF) to optimize for clarity, safety, and conservatism in recommendations. Training may be performed on medical-specific subsets of general-purpose LLMs, with fine-tuning on use-case-specific emergency care scenarios. The model may be distilled and quantized to fit within on-device hardware constraints, using tools such as ONNX, Core ML, or TensorFlow Lite. Integration within the mobile device may be achieved by embedding the inference engine within the operating system's AI runtime (e.g., using Apple Core ML or Android NNAPI). The model may be triggered by a local application that manages input, invokes model inference, and formats the output. The app may optionally connect with voice recognition systems available on the phone, or use offline speech-to-text models. Biometric and contextual sensor data may be accessed via local APIs to inform the model response. The system may be deployed in secure sandboxed environments with user consent dialogs and built-in legal disclaimers. Updates to the model weights or medical knowledge base may be provided over-the-air and integrated only after user review and approval.

### 9. Monetization and Subscription Features:

The system may support monetization models designed to quantify usage and value for damages assessment, including subscription-based access and tiered feature bundles. A subscription engine may operate locally to enforce entitlements when connectivity is unavailable, using device-bound license tokens with expiration timestamps and cryptographic signatures verified via a secure enclave or trusted execution environment. Upon restored connectivity, entitlement refresh may occur through short-lived validation receipts and integrity checks while preserving uninterrupted offline operation. Usage metering may be performed by recording locally timestamped, encrypted records of interaction counts, emergency session durations, feature invocations such as multilingual translation or sensor integration, and generated outputs such as step lists and alert categories. These records may be synced to a backend when connectivity is available to support billing reconciliation and damages computation. Feature gating may differentiate free and paid tiers, for example enabling offline voice interfaces, regional protocol packs, and advanced safety filtering parameters only for subscribers, with clear, externally observable indicators of tier state shown in the user interface. Enterprise deployments may be supported via mobile device management integration, allowing administrators to assign seats, push model packs, configure data retention policies for audit logs, and receive aggregated usage reports. Family or multi-user plans may be enabled through shared entitlements with per-user audit trails on a shared device while maintaining privacy segregation. In-app purchase or platform billing integrations may be used to initiate trials, handle renewals, and manage refunds, with fallback operation defined to degrade gracefully to a baseline feature set if entitlements lapse while offline. The system may expose standardized, externally observable events and receipts, including subscription state transitions and metered usage summaries, which can be preserved in the local audit log for later verification.

TECHNICAL EFFECTS: The embodiments may deliver concrete technical effects that arise from specific architectural choices. On-device inference may reduce end-to-end latency for guidance generation and remove dependency on continuous network connectivity, resulting in improved robustness under outage and rural conditions. Local processing and encrypted storage may reduce the attack surface and leakage risk by eliminating transmission of sensitive health data to remote servers, thereby improving privacy and security characteristics. Quantization and distillation of the model may reduce memory footprint and computational load, enabling execution on commodity mobile AI accelerators while lowering energy consumption and device thermal load, which may extend battery life during prolonged emergency sessions. A deterministic safety filtering module with structured output templates may reduce out-of-scope or high-risk recommendations relative to unconstrained generative systems, improving reliability and user safety. Power-aware inference profiles selected via a local tool interface compatible with Model Context Protocol may dynamically modulate compute intensity, trading minor accuracy deltas for substantial energy savings on low battery without requiring server coordination. Regional adaptation modules selected from offline location signals may tailor instruction phrasing and protocol selection to local practices, reducing user confusion and increasing compliance. Externally observable, cryptographically sealed audit summaries may enable third-party verification of runtime behavior, providing a verifiable record of risk categorizations and step outputs without exposing raw user content. Interoperability through native operating system artificial intelligence runtimes such as Core ML and Android Neural Networks API may improve portability across device classes, leveraging vendor accelerators to achieve consistent performance without embedding platform-specific kernels. Hands-free activation via hotword or gesture combined with local speech-to-text and text-to-speech may reduce interaction friction and time-to-first-instruction when fine motor control is impaired. Tool invocation through a local capability layer compatible with Model Context Protocol may unify access to sensors and alerts, reducing integration complexity and failure modes compared to bespoke interfaces. Subscription enforcement using device-bound tokens verified within a secure enclave or trusted execution environment may maintain feature availability offline while preventing tampering, supporting dependable monetization mechanisms without degrading guidance reliability.

ANTI-WORKAROUND COVERAGE AND EXTERNAL INDICATORS: The embodiments may be implemented in ways that make circumvention by superficial architectural changes impractical while preserving externally verifiable behaviors. Substituting different local inference engines including non-transformer neural networks, classical statistical classifiers, hybrid rule-and-ML policies, retrieval-augmented composition, or deterministic template selection may still yield the same step-by-step emergency guidance, conservative safety gating, and offline operation that are externally observable in the disclosed system. Partitioning inference or policy selection across multiple local processors and companion accessories such as wearables, earbuds, vehicular head units, or microcontrollers connected over Bluetooth, Wi-Fi Direct, or wired links may still constitute on-device operation when no cloud inference is used, and may expose the same observable outputs including step lists, risk categorizations, escalation prompts, and signed audit receipts. Replacing interface layers or runtimes with alternatives such as WebAssembly modules, Vulkan compute, Metal, CUDA, DirectML, OpenCL, or vendor-specific accelerators may preserve identical user-visible behavior and audit artifacts. Hands-free activation may be achieved via hotword, button, gesture, head motion, proximity, or optical cues without altering the externally observable loop of local speech-to-text, local inference, safety filtering, and local text-to-speech. Externally observable indicators may include deterministic presence of locally generated guidance when the device is offline, consistent latency envelopes characteristic of local inference, UI indicators of subscription tier and risk category, audible alerts produced without network access, and cryptographically sealed, timestamped audit entries recording risk categories, step counts, modality used, and offline status. Ephemeral or opportunistic network use limited to non-inference functions such as time synchronization, map data updates, update verification, or log upload does not change the externally verifiable fact that inference and safety filtering occur locally and offline.

FALLBACK EMBODIMENTS: In certain deployments, simpler or partial implementations may be used while retaining the inventive concept of providing offline, context-appropriate emergency guidance generated locally. A minimal implementation may operate in text-only mode without speech-to-text or text-to-speech, accept free-form user input, and produce concise, step-by-step guidance constrained by a deterministic safety filter; such an implementation may omit access to sensors, health profiles, and location while preserving conservative gating and audit logging. A reduced-footprint implementation may utilize a smaller distilled model or a non-transformer statistical model configured to output actions from a constrained grammar, achieving low memory usage on entry-level hardware while maintaining on-device inference and safety filtering. An accessory-based implementation may execute inference on a companion wearable or peripheral with limited user interface, communicating via a short-range link to present instructions on a host phone's display while preserving local inference and offline operation. A rules-augmented implementation may combine a compact generative model with a curated offline knowledge base and rule templates, where the model selects and parameterizes standardized action cards enforced by a deterministic policy engine; this hybrid approach may reduce compute cost while preserving conservative behavior. A compliance-focused implementation may disable optional features such as subscription tiers, regional packs, or MCP tool invocation, yet continue to record externally observable session summaries with cryptographic sealing for third-party verification. A hardened implementation may execute portions of risk scoring, entitlement checks, or audit sealing entirely within a secure enclave or trusted execution environment and store model weights encrypted, while omitting update mechanisms in classified or air-gapped settings. A battery-prioritizing implementation may force a low-power inference profile at all times, limit token generation length, and increase check-in prompts to maintain guidance continuity under tight power budgets. These fallback embodiments may be selected at install time or dynamically based on device capabilities, user preferences, regulatory requirements, or enterprise policy, and each preserves the core inventive features of offline local inference, conservative safety control, and externally observable outputs.

EXAMPLE USE CASE: A traveler in a mountainous area with no reception slips and injures their leg. Unable to call emergency services, they activate the emergency medical LLM. By describing their symptoms, they receive step-by-step instructions to check for fracture signs, create a splint, and elevate the leg. The system also advises on hydration, shock signs, and when to move or rest. For the avoidance of doubt, the scope of the invention is defined solely by the claims. Any examples, scenarios, sequences of steps, data formats, parameter ranges, or named components described herein are non-limiting and illustrative. Steps may be reordered, performed in parallel, combined, or omitted unless expressly required by a given claim. Features described in connection with one embodiment may be combined with features of other embodiments unless such combination is inconsistent with an explicit claim. Hardware and software implementations may be interchanged, modules may be partitioned or combined, and equivalent interfaces, protocols, and data representations may be substituted without departing from the claimed scope.

The embodiments may be described by the following itemized list:
1. A method of providing emergency medical guidance using a language model embedded on a mobile device, the method comprising: receiving user input describing a medical condition; processing the input using a locally stored language model; generating step-by-step emergency instructions based on said input; and outputting said instructions to the user via text or audio, wherein the method operates without requiring internet connectivity.
2. The method of item 1, further comprising accessing local sensor data to contextualize the medical guidance.
3. The method of item 1, further comprising triggering a conservative fallback response when the model's confidence is below a defined threshold.
4. The method of item 1, wherein the language model may be optimized for execution on a mobile AI accelerator.
5. The method of item 1, further comprising a hands-free activation mechanism.
6. The method of item 1, wherein user interaction logs may be stored locally and synced when internet connectivity is restored.
7. The method of item 1, further comprising displaying a disclaimer indicating that the guidance is not a substitute for professional medical advice.
8. The method of item 1, further comprising multilingual support.
9. The method of item 1, further comprising automatic integration with local health data applications to enhance personalization.
10. The method of item 1, wherein the language model may be periodically updated when connectivity becomes available.
11. A mobile device comprising at least one processor and a memory storing a language model and an application, the application configured to, when executed by the processor, receive user input describing a medical condition, process the input using the locally stored language model to generate step-by-step emergency instructions, and output the instructions via text or audio, wherein the processing is performed without requiring internet connectivity.
12. The mobile device of item 11, further comprising interfaces to biometric sensors and a location subsystem, the application being further configured to incorporate sensor and location data into the generated instructions.
13. The mobile device of item 11, wherein the device includes an on-device artificial intelligence accelerator and the language model is configured to execute on the accelerator.
14. The mobile device of item 11, wherein speech-to-text and text-to-speech components operate locally to enable voice interaction without internet connectivity.
15. The mobile device of item 11, wherein a safety filtering module constrains outputs to conservative, life-preserving guidance and prompts escalation to professional care when indicated.
16. A non-transitory computer-readable medium storing instructions that, when executed by one or more processors of a mobile device, cause the mobile device to perform the method of item 1.
17. The non-transitory computer-readable medium of item 16, wherein the instructions configure execution of a distilled, quantized language model using a native operating system artificial intelligence runtime.
18. A computer-implemented method of updating an offline emergency medical guidance model on a mobile device, comprising detecting availability of internet connectivity, verifying integrity and authenticity of an update package, applying the update to a locally stored language model and knowledge base, preserving existing user data and logs, and enabling user review and approval prior to activation of the updated model.
19. The method of item 1, further comprising producing externally observable outputs including step lists and alert messages that categorize risk level and recommended escalation, and storing such outputs in a local audit log.
20. The method of item 1, wherein model inference and context integration are performed via an operating system artificial intelligence runtime selected from Core ML and Android Neural Networks API to maintain interoperability across device platforms.
21. The method of item 1, wherein the model weights are stored encrypted and may be partitioned across application packages, secure storage partitions, or companion accessories, with inference remaining entirely on-device.
22. The method of item 1, wherein the guidance engine comprises any on-device statistical or neural model including transformer, recurrent, convolutional, mixture-of-experts, retrieval-augmented, or hybrid rule-and-ML architectures.
23. The method of item 1, wherein intermittent or opportunistic network connectivity, when present, is used only for non-inference functions including time synchronization, map data updates, update verification, or log upload, with all inference performed locally.
24. The mobile device of item 11, wherein the safety filtering module is implemented as a deterministic policy engine with region-selectable rulesets and structured output templates that constrain action classes and block out-of-scope recommendations.
25. The method of item 1, wherein tool invocation is performed via a local interface compatible with but not limited to Model Context Protocol, including proprietary capability descriptors and native operating system APIs.
26. The method of item 1, wherein external accessories including Bluetooth sensors, wearables, or peripheral alert devices provide additional inputs and outputs for context and escalation signaling.
27. The method of item 1, wherein the application operates in a text-only mode with voice features disabled while maintaining safety gating and audit logging.
28. The method of item 1, wherein portions of entitlement verification, risk scoring, or audit log sealing execute within a secure enclave or trusted execution environment.
29. The method of item 1, wherein regional protocol selection is derived from user settings, SIM records, offline map tiles, or manual override in addition to or instead of GPS signals.
30. The method of item 1, wherein a compliance mode outputs standardized, cryptographically signed session summaries to enable third-party verification of externally observable behavior.
31. The method of item 1, wherein inference or policy selection is partitioned across a host device and one or more companion devices including wearables, earbuds, vehicular head units, or microcontrollers communicating over local links, with no cloud inference used.
32. The method of item 1, wherein the interface and compute runtime comprise any of WebAssembly, Vulkan compute, Metal, CUDA, DirectML, OpenCL, or vendor-specific accelerators in addition to native operating system artificial intelligence runtimes.
33. The method of item 1, wherein hands-free activation is triggered by audio hotword, hardware button, inertial gesture, proximity detection, or optical signal while preserving entirely local speech-to-text, inference, safety filtering, and text-to-speech.
34. The method of item 1, wherein signed audit receipts include at least a timestamp, risk category, step count, interaction modality, subscription tier indicator, and an offline state indicator to enable external verification of local operation.
35. The method of item 1, wherein model weights are stored using memory-mapped files, compressed archives, or sharded containers and are decrypted on access within a trusted execution environment, with inference remaining local.
36. The method of item 1, wherein a rules-dominant configuration selects and parameterizes pre-authored action templates using a compact local classifier and deterministic policy engine to produce step-by-step guidance without relying on free-form generation.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A method of providing emergency medical guidance using a language model embedded on a mobile device, the method comprising receiving user input describing a medical condition, processing the input using a language model stored locally on the mobile device to generate step-by-step emergency instructions, and outputting the instructions to the user via text or audio, wherein the processing and outputting operate without requiring internet connectivity.

The method of item 1, further comprising accessing local sensor data including biometric data and environmental context to contextualize the generated emergency instructions.

The method of item 1, wherein a safety layer applies a confidence threshold and triggers a conservative fallback response when a model confidence value is below the threshold.

The method of item 1, wherein the language model is optimized for execution on a mobile artificial intelligence accelerator by distillation and quantization.

The method of item 1, further comprising enabling hands-free activation via a hotword or gesture.

The method of item 1, further comprising storing user interaction logs locally in encrypted form and synchronizing the logs when internet connectivity is restored.

The method of item 1, further comprising presenting a disclaimer indicating that the guidance is not a substitute for professional medical advice.

The method of item 1, wherein the language model supports multilingual interaction or employs local translation modules.

The method of item 1, further comprising integrating with local health data applications to personalize the generated instructions.

The method of item 1, further comprising updating the locally stored language model and a medical knowledge base when connectivity becomes available and after user review and approval.

A mobile device comprising at least one processor and a memory storing a language model and an application, the application configured to, when executed by the processor, receive user input describing a medical condition, process the input using the locally stored language model to generate step-by-step emergency instructions, and output the instructions via text or audio, wherein the processing is performed without requiring internet connectivity.

The mobile device of item 11, further comprising interfaces to biometric sensors and a location subsystem, the application being further configured to incorporate sensor and location data into the generated instructions.

The mobile device of item 11, wherein the device includes an on-device artificial intelligence accelerator and the language model is configured to execute on the accelerator.

The mobile device of item 11, wherein speech-to-text and text-to-speech components operate locally to enable voice interaction without internet connectivity.

The mobile device of item 11, wherein a safety filtering module constrains outputs to conservative, life-preserving guidance and prompts escalation to professional care when indicated.

A non-transitory computer-readable medium storing instructions that, when executed by one or more processors of a mobile device, cause the mobile device to perform the method of item 1.

The non-transitory computer-readable medium of item 16, wherein the instructions configure execution of a distilled, quantized language model using a native operating system artificial intelligence runtime.

A computer-implemented method of updating an offline emergency medical guidance model on a mobile device, comprising detecting availability of internet connectivity, verifying integrity and authenticity of an update package, applying the update to a locally stored language model and knowledge base, preserving existing user data and logs, and enabling user review and approval prior to activation of the updated model.

The method of item 1, further comprising producing externally observable outputs including step lists and alert messages that categorize risk level and recommended escalation, and storing such outputs in a local audit log.

The method of item 1, wherein model inference and context integration are performed via an operating system artificial intelligence runtime selected from Core ML and Android Neural Networks API to maintain interoperability across device platforms.

### Embodiment LE: Aerial Precision System for Targeted Ant Trail Disruption and Aphid Biocontrol Using a Robotic Drone Mechanism

An unmanned aerial vehicle system is disclosed that identifies ant foraging trails associated with aphid-farming behavior and precisely deposits disruptive payloads-such as slow-acting toxic bait balls, abrasive particulates, or live beneficial predators-onto or near the trail to weaken ant defenses and enable biological aphid control. A lightweight robotic arm manipulates a tiltable cup to receive payloads from an onboard dispenser and to position and release them with sub-centimeter accuracy informed by visual or spectral analysis. The system may operate autonomously or under operator guidance and can execute staged interventions by returning to the same site after a delay to release predators once ant activity is reduced, thereby advancing targeted, ecologically mindful pest management.

Description of the Drawings: FIG. 53 depicts one embodiment of this invention. This embodiment builds further on US20250162711A1, whose content is presumed included herein.

Anchor and Core Relationships: For FIG. 4, the numbered elements and their roles are anchored as follows. The cup in loading state (1) is positioned concentrically beneath the dispenser (2) during loading; the upper limb (3) articulates the cup between the loading state (1) and the ready-to-release state (4). In the ready-to-release state (4), the cup or an equivalent end-effector is positioned above a target on the ant trail that behaviorally links the nest (5) and the aphid-infested plant (6). The dispenser (2) transfers a unit payload into the cup when the cup is in state (1); the arm (3) repositions the cup to state (4) and actuates a tilt or flip to deposit the payload directly onto or adjacent to the trail between (5) and (6). The UAV airframe, flight controller, and imaging sensors are unnumbered supports that hold and guide elements (1)-(4); in variants, a micro-doser, trapdoor, sliding tray, or contact-transfer end-effector occupies the same functional role as element (4), and an alternative dispenser occupies the role of element (2). The biological context comprising the nest (5), the plant (6), and the intervening trail defines the external reference frame for precise placement. This anchor governs terminology used throughout the detailed description, examples, and claims and permits direct cross-walk from text to figure without ambiguity.

Scope and Interpretation: The scope of this invention is limited only by the claims. The figures and any references to particular components, dimensions, sequences, platforms, protocols, materials, payloads, or control strategies are illustrative examples of embodiments and do not limit the claims.

The order of steps in any described flow may be reordered, performed concurrently, omitted, or substituted with equivalent steps while still falling within the scope of the claims. Singular terms may include the plural, and “or” is inclusive. Terms such as “comprising,” “including,” and “having” are intended to be open-ended. Functional descriptions such as “configured to” or “operable to” may be realized in hardware, software, firmware, or combinations thereof. References to figures are schematic and not to scale, and the same inventive concept may be practiced without every depicted element.

Gentle Introduction: Many crop aphid outbreaks persist because nearby ants “farm” aphids for honeydew and aggressively chase away aphid predators. The invention addresses this by placing a small, attractive payload exactly where ants already travel so that worker ants readily collect it and carry it back to the colony. After the ants' defenses are weakened, the same platform may return to gently release beneficial predators onto the plant, allowing natural biocontrol to take hold.

At a practical level, a drone may see the approximate trail or plant stress, hover low, and use a tiny tilting cup on a light arm to set a bait ball or other agent precisely on the trail with minimal disturbance. This stepwise approach-see the trail, place a small dose exactly on it, wait, and then release predators-aims to reduce chemicals, avoid blanket spraying, and leverage ant behavior to make biological control work more reliably in the field.

Examples: The following concrete examples illustrate step-by-step field usage and may be varied without departing from the claims.

Example 1: Trail-based precision baiting. A grower surveys a lettuce block at dusk when ant traffic is high. Step 1: a multirotor UAV takes off with a magazine of 6 sugar-toxicant bait balls and descends to 5 meters to begin a short raster to capture downward-facing RGB and NIR video. Step 2: onboard or offboard analysis identifies a linear movement corridor between a soil nest and an aphid-stressed plant row; a drop point is selected 30 cm from the nest along the trail. Step 3: the arm retracts the tilting cup beneath the dispenser, one bait ball is released into the cup, and the UAV transitions to a stable hover at approximately 0.7 meters above the selected point. Step 4: two overlapping FPV cameras observe a colored marker on the cup; visual servoing commands the arm joints until the marker coincides with the image coordinates of the drop point in both views. Step 5: the cup tilts smoothly; the bait ball rolls out and settles directly on the trail with minimal lateral drift. Step 6: the system records a cryptographically signed event with GPS position, timestamp, payload type, altitude, and device identity, emits a brief audible tick for external observability, and proceeds to the next waypoint. Within minutes, workers encounter and begin to harvest the bait, initiating trophallaxis.

Example 2: Region-of-interest placement without explicit trail reconstruction. A vineyard block shows localized honeydew sheen and aphid clusters on the undersides of leaves. Step 1: the UAV is equipped with a gel-based bait in a micro-doser variant of the payload delivery mechanism as disclosed (e.g., peristaltic pump or rotary gate micro-doser alternative), in addition to the standard cup. Step 2: NIR imagery flags an aphid-laden plant portion; the operator taps the target region on a live video feed to confirm. Step 3: the UAV descends to 0.6 meters; visual servoing aligns the end-effector over a planned short arc 8-12 cm from the stem base where ant approaches are likely.

Step 4: the micro-doser expresses a thin, 10 cm arc of gel in three 0.2 ml pulses while the UAV creeps laterally at 2-3 cm/s; dyed gel improves external observability. Step 5: the system signs and stores the event with the arc geometry and volumes dispensed. Over the next hour, ants crossing the stem base encounter the gel arc and transport palatable toxicant back to the colony despite the absence of an explicitly reconstructed trail.

Example 3: Staged predator release after ant aggression declines. The same field is revisited 8 hours after Example 1. Step 1: the UAV now carries a ventilated capsule containing 30 ladybug larvae and a small quantity of moist packing media. Step 2: the UAV returns to the logged GPS tile, visually verifies reduced ant flow near the treated plant using a short, low-altitude pass, and hovers 0.4 meters over the aphid cluster. Step 3: the end-effector's trapdoor opens; larvae are gently released onto leaf petioles. Step 4: the event is logged with a mission identifier linking the predator release to the prior bait deployment, supporting later efficacy assessment and damages modeling. The larvae remain and feed successfully due to diminished ant interference.

In software-enabled embodiments, a Model Context Protocol (MCP) layer may expose mission control and logging tools so that a software agent or LLM orchestrator can safely invoke discrete actions, including imagery acquisition, trail detection, drop point selection, end-effector alignment, release, and event logging. Example MCP tool calls and data structures may include the following. A release event record may be serialized as

{“event”:“release”,“mission_id”:“M-2025-08-15-001”,“lat”:37.4219999,“lon”:−122.0840575,“alt_m”:0
.7,“payload”:“bait_ball_sugar_boric_acid”,“count”:1,“device_id”:“UAV-34A2”,“ts”:“2025-08-15T19:4
2:53Z”,“signature”:“base64signature”} and a target specification may be expressed as
{“target_type”:“trail”,“drop_point”:{“lat”:37.42195,“lon”:−122.08410,“alt_m”:0.7},“confidence”:0.86,
“context”:“nest_proximate_corridor”}. An MCP tool invocation to command a placement may be
represented as
{“tool”:“release_payload”,“args”:{“target”:{“lat”:37.42195,“lon”:−122.08410,“alt_m”:0.7},“payload_t
ype”:“bait_ball”,“mode”:“tilt_drop”,“mission_id”:“M-2025-08-15-001”}} where the host platform
validates entitlements, executes the action, and returns a signed confirmation such as
{“status”:“ok”,“event_id”:“E-784233”,“ts”:“2025-08-15T19:42:54Z”,“signature”:“base64signature”}.

Background of the Invention: Ant species that farm aphids create a persistent agricultural challenge by protecting aphid colonies in exchange for honeydew. This ant-aphid mutualism leads to larger aphid populations, greater crop damage, and suppression of natural aphid predators. Conventional mitigation strategies rely heavily on chemical spraying, which is imprecise, environmentally damaging, and indiscriminate. There remains a clear need for a more ecologically sound and behaviorally informed method to disrupt this relationship, ideally by targeting the ant colony directly without affecting non-target species or the broader environment.

Summary of the Invention: The present invention describes an unmanned aerial vehicle system configured to detect, approach, and precisely position a toxic or otherwise disruptive payload onto or near the foraging trail of ants engaged in aphid farming. Aerial deployment allows for a high degree of precision and the possibility of revisiting the location to perform sequential or multimodal interventions, such as deploying beneficial insect predators after initial colony weakening. The system employs a lightweight robotic arm and end-effector capable of receiving and positioning small payloads-such as poison bait balls, abrasive powders, or live biological agents-over locations determined through visual or spectral plant analysis and ant behavior observation. In some embodiments, the system identifies a broader target region associated with ant protection, such as a nest-proximate approach corridor or an aphid-infested plant portion, and deposits the payload on or near that region even without explicit trail reconstruction.

Detailed Description of the Invention: Description of the Components Identified in the Drawing The accompanying illustration (not shown) schematically represents the interaction between the drone-based delivery system and the ant-aphid agricultural environment. The figure includes multiple numbered components, each of which corresponds to a functionally distinct element of the system as outlined below.

A component labeled as (1) depicts the cup in a loading state, wherein the cup is positioned directly underneath the onboard ball dispenser. In this configuration, the robotic arm is retracted or aligned such that the distal end of the arm places the cup concentrically below the dispenser outlet. This allows the dispenser to release a single poison bait ball or other payload into the cup through gravity or gentle mechanical feed. The loading state is intended to be transient, with the cup soon transitioning into the deployment configuration.

The component labeled (2) shows the ball dispenser mounted beneath the drone frame. The dispenser may take the form of a gravity-fed magazine, a motorized chambered unit, or a hopper-style feeder capable of holding and sequentially releasing spherical payloads. It is contemplated that this dispenser is configured to interface securely with the cup's opening during the loading phase and is dimensioned to accommodate bait balls of consistent geometry and mass.

Component (3) represents the upper limb of the robotic arm, which is constructed similarly to the robotic actuator disclosed in US20250162711A1. This limb may be cable-driven or feature integrated rotary joints and is mechanically coupled to the drone chassis. The limb serves to articulate the cup between its loading and deployment states, providing vertical and lateral mobility while maintaining system balance. It is anticipated that the upper limb offers at least two degrees of freedom to allow extension and precise positioning.

Component (4) illustrates the cup in a “ready-to-release” configuration, where it has been extended by the robotic arm away from the central axis of the drone to a location hovering above the intended drop site. In this state, the cup contains a bait ball and is held over the ant trail, as inferred or detected via onboard imaging systems. The cup may be constructed with a tipping mechanism actuated by a small servo located at the Joint, or alternatively, through a tensioned cable routed along the robotic arm and remotely controlled by a servo mounted on the drone body. This flipping action allows the ball or payload to be deposited with precision and minimal kinetic disturbance.

The element labeled as (5) denotes a schematic representation of an ant nest, typically situated in or near the soil at the base of the field. This nest serves as the origin of the foraging trail and is not necessarily directly visible to the drone, although its location may be inferred based on trail structure and aphid concentrations. It is contemplated that the drone may target trail locations proximate to the nest in order to maximize bait uptake and colony impact.

Component (6) shows a crop plant, particularly one that exhibits signs of aphid infestation. These plants often emit specific spectral signatures detectable through near-infrared or multispectral imaging. The ant trail commonly leads from the nest to such plants, as the ants actively protect aphid colonies to harvest honeydew. By identifying this plant, the system may prioritize targeting the trail section where ant activity is most concentrated.

Connecting the ant nest (5) and the crop plant (6) is a visible or inferred ant trail, typically rendered in the drawing as a dotted or curved line. This trail forms the behavioral path along which the drone system will position the poison ball. In some applications, this trail may be identified using a downward-facing RGB camera paired with edge detection algorithms or via operator tagging based on prior knowledge.

Taken together, the identified components enable a closed-loop system for the detection, loading, positioning, and precise deployment of disruptive substances-ranging from poison bait to predators-directly onto the foraging trail of aphid-farming ants. The diagram represents not only the mechanical states of the arm and payload mechanism but also the biological context into which the system is deployed.

In one contemplated embodiment, the system comprises a multirotor drone outfitted with downward-facing cameras and stabilization features suitable for close proximity hovering over foliage. Mounted to the underside of the drone is a compact dispenser unit containing multiple preloaded poison bait balls or similar small payloads. A lightweight robotic arm, resembling the upper limb configuration described in US20250162711A1, extends below the drone and is designed to manipulate a detachable or tiltable cup at its distal end. The cup may be positioned beneath the dispenser to receive a payload, and thereafter extended outward to deliver the substance at a target location.

Trail identification may be accomplished through a variety of means. In some applications, the ant trail is inferred from visual observation of linear patterns between visible ant nests and aphid-affected crop plants. Alternatively, near-infrared (NIR) imagery or vegetation indices may be used to identify plant stress or specific aphid-related signatures, providing an indirect indicator of ant activity. It is anticipated that such imaging data may be collected in real time during the drone's flight or preloaded from satellite or prior survey data. Once the trail is localized, the robotic arm transitions the cup to a loading position directly beneath the dispenser. Upon receiving a payload-typically a poison bait ball—the arm then repositions the cup to a “ready-to-deploy” configuration hovering above the inferred trail path. At the selected release site, the cup may be actuated to flip or tilt, thereby depositing the ball onto the trail. This flipping motion may be performed by a dedicated servo located at the end-effector, or alternatively via a cable routed through the robotic arm and tensioned by a remotely located servo. The poison bait ball is envisioned to be formulated with a palatable sugar base, optionally combined with slow-acting insecticides such as boric acid, fipronil, spinosad, or hydramethylnon. In some cases, the ball may also include synthetic pheromones to encourage foraging and trophallaxis, as well as biodegradable carrier materials such as starch or agar. In certain embodiments, the cup may additionally be loaded with finely ground natural shell material-such as eggshells or diatomaceous earth-intended to physically abrade and compromise the cuticle of ant larvae or other soil-dwelling pest stages. This material may be dispersed gently over the nest site or trail using a similar tilting motion.

In variants where explicit trail detection is omitted, the system may identify an aphid-infested plant portion via visual or spectral cues (including honeydew sheen, aphid clustering, or stress indices) and place the payload directly onto plant tissue (e.g., stem nodes or leaf undersides) or along a short line or arc near the stem base to intersect likely ant approach paths proximate to a nest inferred from context, time-of-day patterns, or historical observations.

Crucially, the system does not limit itself to poison-only deployments. In a multi-phase treatment strategy, the drone may return to the site hours after initial bait deployment. Once ant activity is sufficiently reduced, the drone may perform a follow-up deployment, releasing beneficial predator organisms such as ladybug larvae directly onto the aphid-infested crop plant. This staged deployment method allows for the strategic weakening of ant defenses followed by the encouragement of natural biological control. The entire process may be performed autonomously or under remote operator guidance. In some envisioned implementations, an operator may manually tag visible trails or nests on a live video feed, whereas in others, AI-based visual systems may autonomously detect and prioritize trails for treatment. The overall system enables precise, repeatable, and scalable ant control with minimal environmental disturbance. The combination of behavioral targeting, aerial deployment, and staged biological support reflects a significant advancement over traditional chemical spraying. While some components may resemble prior art in robotics or UAV delivery, the combination of selective trail-based poison placement and subsequent predator release defines a novel ecological intervention platform.

In one contemplated embodiment, the invention provides a method for reducing aphid pressure in an agricultural field by intervening in the mutualistic relationship between aphid colonies and the ant colonies that protect them. The method begins with the identification of a foraging trail formed by ants-typically soil-nesting species known to protect and farm aphids on nearby crop plants. This trail may be visually observed by tracking ant movement between a presumed nest site and aphid-affected foliage, or inferred through computational means using aerial imagery. In some instances, the trail is detected based on geometric patterns or the density of moving insects. In other embodiments, the trail is inferred by detecting signs of plant stress indicative of aphid infestation using spectral imaging technologies such as near-infrared (NIR), NDVI, or similar methods.

Upon successful identification of such a trail, the method proceeds by deploying a bait composition designed to disrupt the ants' activity and, by extension, their protective behavior over the aphid colony. This bait is preferably deposited directly on or near the active foraging trail, ideally at a location where it is likely to be encountered and carried by worker ants. The bait composition may include a slow-acting toxicant-such as boric acid, spinosad, fipronil, or hydramethylnon-formulated within a sugar-rich matrix to encourage ingestion and trophallaxis. In certain formulations, additional chemical cues such as trail pheromones or flavor enhancers may be included to enhance uptake and delivery back to the nest.

The deployment of the bait is carried out by an aerial or mobile apparatus. In the preferred embodiment, the apparatus comprises an unmanned aerial vehicle (UAV), or drone, equipped with an onboard dispenser and a robotic arm. The arm includes an articulated upper limb as described in US20250162711A1, and is configured to manipulate a cup or similar receptacle mounted at its distal end. This cup serves as the temporary holder of the bait composition during its transition from the dispenser to the targeted drop location. The robotic arm can reposition the cup from a loading state beneath the dispenser to a deployment state, where it is held in alignment with the identified ant trail.

To release the bait, the cup may be actuated by either a compact servo motor located near the end-effector or by a tensioned cable system routed through the arm, connected to a servo at the base of the UAV. The flipping or tilting of the cup allows the bait ball to fall in a controlled manner onto the trail, with minimal aerodynamic interference.

In a further embodiment, the drone may return to the same site after a predefined delay-typically several hours—to conduct a second operation. At this time, the drone may be loaded with a different payload, such as live beneficial insects. The apparatus is then used to deposit biological aphid predators-such as Coccinella septempunctata (ladybug larvae), lacewing larvae, or parasitoid wasps-onto the same crop plant previously protected by the ants. The prior disruption of the ant colony allows these predators to establish and control aphid populations without interference.

In addition to chemical bait, the system may optionally be used to deliver mechanical or physical disruptors. For example, the cup may be used to release finely ground particulate matter such as eggshell powder, silica, or diatomaceous earth onto the trail or nest site. These materials are known to compromise the integrity of soft-bodied insects or larvae by abrasion, and may offer a non-toxic control pathway that complements or substitutes for chemical bait.

The system is not limited to drones. In other configurations, the same mechanisms may be deployed from a terrestrial robot, a tethered aerial platform, or a manually guided boom. However, the airborne embodiment offers key advantages, including rapid repositioning, field scalability, and minimal plant disturbance.

The UAV is expected to include onboard navigation and control logic, allowing it to autonomously execute a predefined baiting sequence once the trail or target coordinates are provided. In certain versions, the UAV may operate fully autonomously, identifying trails in real time, executing bait placement, and logging GPS-tagged release events for monitoring.

Collectively, this invention provides a scalable, minimally invasive, and ecologically mindful solution for managing aphid outbreaks by targeting the social structure that protects and sustains them. By leveraging ant behavioral patterns and combining tactical poison baiting with timed predator deployment, the system enables a new tier of targeted pest control that aligns with integrated pest management (IPM) goals.

In some embodiments, the identification of ant foraging trails is performed by acquiring high-resolution downward-facing images of the terrain, typically captured from an aerial vehicle such as a drone. This imaging may be conducted by the same unmanned aerial vehicle that is later used to deploy bait compositions, or alternatively by a separate scouting drone tasked specifically with data acquisition.

The imaging process involves capturing a series of overlapping photographs of the field or crop area at sufficient resolution to resolve fine detail on the ground, including the subtle linear paths formed by ant foragers traveling between their nest sites and aphid-hosting plants. These trails often manifest as slightly darkened or reflective lines due to repeated traffic and may be visible even in the absence of individual ants, especially under favorable lighting conditions.

Once captured, these images may be stitched into an orthorectified mosaic or processed as discrete frames, and analyzed using artificial intelligence-based vision techniques. In one implementation, a convolutional neural network (CNN) or other pattern-recognition algorithm is employed to extract potential foraging paths from the imagery. The system may be trained to identify repetitive, linear, or radiating structures that typically correlate with known ant behavior, and to differentiate these from plant stems, irrigation lines, or other field features.

This image analysis may be performed in real time (“onboard processing”) using embedded compute units on the drone, such as AI accelerators or mobile GPUs. Alternatively, the images may be transmitted wirelessly to a base station, edge server or cloud platform where more computationally intensive analysis is performed. Once a trail or set of trails is detected, the geographic coordinates of one or more drop zones may be extracted and used to guide subsequent bait deployment operations.

The trail identification system may also incorporate additional contextual data-such as the spectral signature of vegetation—to correlate the presence of trails with known aphid infestations. This enables a hierarchical approach, where aphid-suspect crop regions are first prioritized, and then ant trails within those regions are identified and targeted. This two-tiered analysis increases deployment efficiency by focusing resources where ant-aphid interactions are most likely to occur.

In practice, the image-capturing drone may follow a serpentine or raster scan path across the field at a height optimized for image clarity, typically between 2 and 10 meters depending on camera optics and lighting. The resolution is preferably such that individual ant trails of approximately 1-2 cm in width can be resolved. The imaging vehicle may be outfitted with fixed-focus optics, stabilized gimbals, or global-shutter sensors to reduce motion blur.

This approach provides a non-contact, data-rich means of trail detection that is well suited for integration into autonomous or semi-autonomous field workflows. It further allows historical trail data to be archived and used to assess ant behavior over time, or to optimize future control efforts by building predictive models of colony dynamics.

When implemented in tandem with the bait delivery system, this imaging and AI detection capability forms the core of a self-guided, behaviorally targeted pest management platform.

In one embodiment, ant trail detection is performed using a lightweight image analysis algorithm that operates on high-resolution aerial photographs or live video frames. The method begins with the identification of individual ants in the image, preferably through a pre-trained object detection neural network such as YOLO (You Only Look Once). The YOLO detector processes the image and outputs a list of bounding boxes or centroids corresponding to the location of ants identified in the frame.

Following detection, the image is divided into a uniform two-dimensional grid of cells. The resolution of the grid may be selected based on the expected density and spacing of ant activity, with typical cell sizes on the order of 10-30 pixels in width. Each grid cell is then classified as either “contains ants” or “does not contain ants” based on whether one or more detected ant centroids fall within its spatial bounds.

Once this binary classification has been established across the grid, the algorithm searches for a connected path of ant-containing cells. Connectedness may be defined using a 4-neighbor or 8-neighbor rule, and noise filtering may be applied to eliminate isolated detections unlikely to belong to a coherent trail.

For each cell classified as containing ants, the algorithm then calculates the local weighted center of the ant positions within that cell. This may be performed by averaging the X and Y coordinates of the detected ant centroids within the grid cell, optionally weighted by detection confidence.

With all weighted centers computed, the algorithm constructs the trail path by connecting the sequence of these centers using straight line segments. This set of connected line segments forms a polygonal approximation of the ant foraging trail. Further smoothing or curve-fitting techniques may be applied to produce a more continuous trajectory suitable for guiding a robotic arm or bait delivery vehicle.

This method provides a computationally efficient approach to approximate trail structure based on discrete detections, and is well suited for implementation in onboard systems with limited processing capability.

In an alternative embodiment, ant trails may be inferred by tracking the movement of individual ants across multiple image frames using optical flow techniques. By applying sparse or dense optical flow algorithms-such as Lucas-Kanade or Farneback—to consecutive frames captured from a low-altitude drone, the system identifies coherent motion vectors associated with foraging ants. These short-term trajectories are accumulated over time to form persistent linear movement patterns. Clustering and filtering methods may then be applied to isolate the dominant direction of travel, allowing the system to reconstruct the underlying trail even in cases where the trail is not visually apparent in a single frame. In another embodiment, individual ant detections are treated as nodes in a spatial graph, with edges drawn between detections that fall within a defined spatial proximity. A traversal algorithm—such as depth-first search or a shortest-path heuristic—is used to identify the most likely foraging trail by locating the longest or most connected path within the graph. This graph-based approach accommodates irregular trail geometries and is robust to intermittent or noisy detections, as it leverages the spatial structure and density of ant movement rather than relying solely on image features.

In one implementation, a commercially available drone platform-such as a DJI quadcopter—is modified to incorporate a lightweight cable-driven robotic arm mounted centrally beneath the drone body. The arm includes multiple degrees of freedom and terminates in a functional end-effector, such as a tiltable cup used for bait or agent deployment. To enable closed-loop control and real-time positioning of the end-effector relative to external targets, the system further includes two downward-facing first-person-view (FPV) cameras mounted in fixed positions near the drone's center axis. These cameras are oriented to provide overlapping visual coverage of the working area directly beneath the drone, including the end-effector and the target site on the ground (e.g., an ant trail or aphid-infested plant). Both camera feeds are transmitted wirelessly to an offboard computer, which performs simultaneous image analysis to locate two key visual features: the current position of the end-effector—marked by a visually distinctive element such as a specific color, geometric pattern, or light-emitting marker—and the target position on the ground, which may be identified through prior mapping or real-time detection. By analyzing the relative positions of the end-effector and the target in both camera views, the system infers the spatial offset between them.

To control the arm, the computer issues servo commands that actuate the cable-driven joints of the arm. Over time, the system may observe how specific servo commands result in specific visual displacements of the end-effector in image space. This control loop may be implemented as a hard-coded mapping function, but is preferably learned automatically, using either supervised calibration procedures or reinforcement learning techniques. In the latter case, the system iteratively experiments with servo actions and refines a control model based on feedback from observed positional outcomes. This approach is particularly robust to small misalignments or calibration errors between the cameras and the drone frame, as the control logic relies not on geometric assumptions but on empirical learning of how to move the end-effector to visually coincide with the target. The system is thereby able to position the payload precisely above the target location without requiring externally calibrated camera rigs, GPS refinement, or complex 3D modeling, making it highly practical for field deployment.

In this embodiment, the offboard computer not only performs visual analysis of the FPV video streams but also issues low-level actuator commands to control the drone's robotic mechanisms. These commands are transmitted to the drone via a wireless link, which may be implemented using a conventional radio control (RC) transmitter paired with an onboard RC receiver, or alternatively through a Wi-Fi or telemetry module connected to the drone's flight controller and auxiliary servo driver. The servo commands determine the angular positions or tension forces applied to the cable-driven joints of the robotic arm, enabling precise positioning of the end-effector based on visual feedback. In addition to controlling the arm's spatial movement, the system may also engage various types of end-effectors. For instance, the computer may command the cup to tip and release its contents, open a valve to dispense a measured water droplet, or trigger a high-voltage discharge if the end-effector is configured as an electrified probe. These functions are mapped to discrete RC channels or digital control lines, and can be activated remotely from the offboard interface in coordination with visual alignment tasks.

Furthermore, the same offboard computer may be used to send high-level navigational or positioning commands to the drone itself, such as instructing it to move laterally, adjust altitude, or hold position above a specified target. This drone maneuvering can be performed via standard RC pitch/roll/yaw inputs, MAVLink waypoint commands, or direct flight controller integration. Because the vision system remains in the loop during these movements, fine adjustments to the drone's position can be made in tandem with arm articulation, ensuring that both the drone and the arm cooperate to achieve sub-centimeter end-effector placement accuracy. The modularity of this control framework allows a single operator or autonomous program to coordinate multi-modal actions-such as identifying a trail, aligning above it, manipulating the arm, and releasing a payload—with minimal onboard processing requirements, since all decision logic resides offboard.

Alternatively, the robotic arm and cup-based deployment mechanism need not be limited to aerial platforms and may be mounted on a ground-based mobile unit, such as a quadrupedal robot (e.g., a robot dog) or a wheeled rover. In the case of a robot dog, the articulated limbs provide stable locomotion over uneven agricultural terrain, while the arm mounted on its back or torso can extend to deploy the bait cup with precision. This configuration offers advantages in endurance, payload capacity, and proximity to ground-level targets such as ant nests and foraging trails. Similarly, the system may be implemented on other mobile platforms, including tracked vehicles, autonomous field robots, or manually operated booms, depending on the terrain and scale of the application. In each case, the core inventive principle remains the same: identifying the spatial location of ant foraging trails that connect to aphid-infested crops, and precisely placing a bait or biological control agent along that trail to disrupt the ant-aphid mutualism. The delivery mechanism, imaging system, and control logic may be adapted to the mobility constraints and affordances of the chosen platform, but the fundamental concept-targeting ant behavior to indirectly control aphids-remains central to the invention.

Continuation-Ready Itemized Embodiments: Embodiments can be described by the following itemized list. Unless a context requires otherwise, any item may be combined with any other item, operations may be reordered or performed concurrently, and functions may be realized in hardware, software, firmware, or any combination. No single item is essential to practice all embodiments unless expressly recited in an independent claim. 1. A method embodiment may comprise identifying a foraging trail of ants that protect aphid colonies and depositing a disruptive payload on or near the foraging trail to disrupt the ant colony and thereby reduce aphid protection of aphids. 2. The method of item 1 may include formulating the disruptive payload as a sugar-based bait comprising a slow-acting toxicant selected from boric acid, fipronil, spinosad, or hydramethylnon. 3. The method of item 1 may include identifying the foraging trail by detecting linear movement patterns between an ant nest and an aphid-infected crop plant using aerial imagery. 4. The method of item 1 may include inferring the foraging trail by detecting aphid-induced plant stress via near-infrared or multispectral imaging and estimating an ant path from surrounding nest sites. 5. The method of item 1 may include actuating a robotic arm to move a cup containing the disruptive payload from a loading position to a deployment position before release. 6. The method of item 5 may include flipping or tilting the cup to release the payload using a servo motor or a tensioned cable actuated remotely. 7. The method of item 1 may further comprise returning after a time delay to release live beneficial predators selected from ladybug larvae, lacewing larvae, or parasitoid wasps onto an aphid-infested plant. 8. The method of item 1 may include delivering finely ground shell material or diatomaceous earth configured to physically abrade or damage ant larvae or soft-bodied pests. 9. The method of item 1 may include hovering a drone at less than one meter above the trail and actuating a gravity-assisted or mechanically tilted release. 10. An apparatus embodiment may comprise a mobile platform, a trail detection system configured to identify an ant foraging trail, and a payload delivery mechanism configured to deposit a disruptive payload on or near the identified trail. 11. The apparatus of item 10 may employ an unmanned aerial vehicle as the mobile platform. 12. The apparatus of item 10 may employ a cup or receptacle configured to receive a payload from a dispenser and to release the payload by tilting, flipping, or dropping. 13. The apparatus of item 12 may further include a robotic arm that positions the cup at a desired drop location. 14. The apparatus of item 13 may actuate the cup using a servo motor or a tensioned cable to effect release. 15. The apparatus of item 10 may include a camera and image processing unit configured to detect ant movement or infer trails from plant stress or spatial patterns. 16. The apparatus of item 10 may include a bait composition with a carbohydrate attractant combined with a slow-acting toxicant. 17. The apparatus of item 10 may include a secondary dispenser configured to release beneficial insects or additional substances after a predetermined delay. 18. The apparatus of item 10 may further dispense particulate abrasive material such as finely ground shell or silica to damage ant larvae or soft-bodied pests. 19. The apparatus of item 10 may include autonomous navigation and control to execute a programmed baiting sequence based on identified trail locations. 20. A computer-implemented embodiment may comprise instructions that cause a mobile platform to acquire imagery, detect or infer an ant foraging trail, determine a drop location, actuate a robotic arm to position a cup beneath a dispenser to receive a payload and move it to the drop location, release the payload by tilting or dropping, and record cryptographically signed usage events including payload type, timestamps, and GPS coordinates. 21. The detection system may alternatively include optical flow, temporal tracking, or spatial graph analysis to reconstruct trails from individual ant detections across frames. 22. The mobile platform may comprise any of a multirotor UAV, fixed-wing UAV with VTOL capability, tethered aerostat, blimp, or ground rover including wheeled, tracked, or legged forms. 23. The payload delivery mechanism may alternatively include a rotary gate, chute, micro-doser, peristaltic pump, pinch valve, vibrating feeder, or brush release, with or without a cup, provided precise local placement is achieved. 24. The end-effector may comprise a tilting cup, sliding tray, trapdoor, or magnetically latched capsule that opens at the drop site. 25. The robotic arm may be cable-driven, geared, prismatic, telescoping, SCARA, pantograph, continuum, or a simple linear actuator, with one or more degrees of freedom. 26. Visual servoing may be performed onboard or offboard and may rely on one or more cameras including RGB, NIR, multispectral, thermal, event cameras, or depth sensors, and may use markers, fiducials, or markerless tracking. 27. Communications and interoperability may include support for MAVLink, ROS or ROS 2, RTSP, RTP, NMEA, CAN, SBUS, UART, I2C, SPI, Bluetooth, Wi-Fi, LTE, or mesh networks to permit control and data exchange across diverse platforms. 28. The disruptive payload may further include gels, microencapsulated toxicants, pheromone-laced carriers, biodegradable polymers, sticky or adhesive carriers, or moisture-retaining matrices to increase pick-up and transport by ants. 29. A fallback embodiment may omit a robotic arm and instead position a fixed dispenser relative to the trail by maneuvering the vehicle to achieve the desired drop accuracy. 30. A manual or semi-automatic embodiment may allow an operator to tag trail segments or nest locations on a live video feed to cue the release mechanism without automated detection. 31. External observability may include externally verifiable behaviors such as audible or visible signals upon release, visible colored payloads, or deployment of dye markers, together with signed logs of drop events to evidence operation. 32. Geofencing and compliance features may restrict operations to authorized areas or times, enforce altitude limits, and log exceptions for auditability. 33. Multi-phase interventions may schedule multiple payload types over hours or days, with adaptive thresholds based on measured ant activity decline or predator establishment. 34. Environmental sensors may measure wind, temperature, humidity, and illumination to adjust approach speed, hover height, and release timing for improved placement accuracy. 35. Power and safety features may include quick-release mounts, propeller guards, end-effector interlocks, and failsafe return-to-home based on battery state or link quality. 36. Data retention may include immutable ledgers or append-only logs with monotonically increasing counters to prevent rollback and to support subscription, pay-per-use, or tiered licensing models consistent with secure monetization. 37. A method embodiment may comprise identifying an aphid-infested plant portion or honeydew deposit via visual, spectral, or tactile cues and depositing a disruptive payload directly onto the plant tissue or immediately adjacent soil without explicitly reconstructing a foraging trail. 38. The method of item 37 may comprise laying a short line or arc of gel, micro-dosed droplets, or particulates near the stem base or on primary petioles to intersect likely ant approach paths from nearby nests inferred from contextual cues, historical data, or probabilistic heatmaps. 39. An apparatus embodiment may omit a trail detection system and instead include a target detection system configured to identify aphid-laden plant portions or operator-designated regions of interest for precise local placement of the disruptive payload. 40. A manual embodiment may allow an operator to designate a drop region on a live video feed corresponding to an aphid cluster or plant organ, irrespective of explicit trail or nest localization, with the system performing precise end-effector alignment and release. 41. A method embodiment may comprise releasing only live beneficial predators onto aphid-infested plant tissue once ant activity in the vicinity is reduced by prior interventions or naturally, without requiring identification of a foraging trail for the predator release phase. 42. A method embodiment may comprise identifying a target region associated with ant protection of aphid colonies, the target region comprising at least one of a foraging trail, a nest-proximate approach corridor, or an aphid-infested plant portion, and depositing a disruptive payload on or near the target region, the disruptive payload comprising at least one of a bait composition, an abrasive particulate, or live beneficial predators, the disruptive payload being configured to disrupt the ant colony and thereby reduce aphid protection. 43. The method of item 42 may comprise a bait composition including a sugar-based carrier and a slow-acting insecticide selected from boric acid, fipronil, spinosad, and hydramethylnon. 44. The method of item 42 may comprise identifying a foraging trail by detecting linear movement patterns between an ant nest and an aphid-infected crop plant using aerial imagery. 45. The method of item 42 may comprise inferring the target region by detecting aphid-induced plant stress via near-infrared or multispectral imaging and estimating a likely ant path from surrounding nest sites. 46. The method of item 42 may further comprise actuating a robotic arm to move a cup containing the bait composition from a loading position to a deployment position prior to release. 47. The method of item 46 may comprise flipping the cup to release the bait composition by a servo motor or by a tensioned cable actuated remotely. 48. The method of item 42 may further comprise returning to the aphid-infected crop plant after a time delay and releasing live beneficial predators selected from ladybug larvae, lacewing larvae, and parasitic wasps. 49. The method of item 42 may comprise including finely ground shell material in the bait composition configured to physically irritate or damage ant larvae or soft-bodied pests. 50. The method of item 42 may comprise hovering a drone at a height of less than one meter above the target region and actuating a gravity-assisted or mechanically tilted release mechanism. 51. An apparatus embodiment may comprise a mobile platform, a target detection system configured to identify at least one of a foraging trail, a nest-proximate approach corridor, or an aphid-infested plant portion, and a payload delivery mechanism mounted on the platform and configured to deposit a disruptive payload on or near an identified target region. 52. The apparatus of item 51 may comprise an unmanned aerial vehicle as the mobile platform. 53. The apparatus of item 51 may comprise a cup configured to receive a disruptive payload from a dispenser and to release the payload by tilting, flipping, or dropping. 54. The apparatus of item 53 may further comprise a robotic arm coupled to the mobile platform, the arm being configured to position the cup at a desired drop location. 55. The apparatus of item 54 may comprise the cup actuated by a servo motor or a tensioned cable to release the bait. 56. The apparatus of item 51 may comprise a camera and an image processing unit configured to detect ant movement, infer approach corridors, or identify aphid-laden plant portions based on plant stress or spatial patterns. 57. The apparatus of item 51 may comprise a bait composition including a slow-acting toxicant combined with a carbohydrate attractant. 58. The apparatus of item 51 may further comprise a secondary dispenser configured to release beneficial insects or additional substances onto the crop or nest site after a predetermined time delay. 59. The apparatus of item 51 may comprise a payload delivery mechanism further configured to dispense particulate abrasive material such as finely ground shell or silica to physically damage ant larvae or soft-bodied pests. 60. The apparatus of item 51 may comprise autonomous navigation and control means for executing a programmed baiting sequence based on identified target locations. 61. A computer-implemented embodiment may comprise instructions that, when executed by one or more processors of a mobile platform, cause the platform to acquire images or video of a crop environment, detect or infer a target region comprising at least one of a foraging trail, a nest-proximate approach corridor, or an aphid-infested plant portion from the images or from spectral vegetation data, determine a drop location on or near the target region, actuate via servo commands a robotic arm to position a cup beneath a dispenser to receive a disruptive payload and to move the cup to the drop location, release the disruptive payload by tilting, flipping, or dropping, and record in secure non-volatile storage using a cryptographic device identity usage events including payload type, timestamps, and GPS coordinates. 62. The disruptive payload may alternatively comprise one or more of repellents, attractants, semiochemicals including pheromones and alarm signals, insect growth regulators, sterilants, microbial biocontrol agents including entomopathogenic fungi, bacteria, or viruses, double-stranded RNA actives, or auto-dissemination carriers configured for colony-level distribution. 63. The payload delivery mechanism may deposit by contact transfer using a swab, wick, brush, roller, pad, or perching foot that touches the target region, including embodiments employing adhesive or waxy microcapsules or electrostatic adhesion to effect local placement without free-fall. 64. The system may use vectored airflow or an electrostatic field to project, attract, or settle particulates or microcapsules onto the target region without requiring a tilting cup. 65. A perching embodiment may stabilize by contacting foliage, trellis, or a nearby structure before contact deposition to reduce rotor wash and further improve sub-centimeter placement. 66. The disruptive payload may be formulated as a slow-release matrix including polymer, wax, oil, or gel, optionally incorporating fluorescent or UV-visible tracers to verify deposition and persistence for external observability and audit. 67. A method embodiment may select between toxicant, microbial, repellent, abrasive, or predator release based on measured ant activity levels and aphid density thresholds, thereby adapting the intervention while maintaining placement on or near the defined target region. 68. A fallback embodiment may replace imaging-based targeting with proximity sensing, tactile contact sensing at the end-effector, or simple time-of-flight ranging to execute precise deposition when visual conditions are degraded, while still aligning to a trail, nest-proximate corridor, or aphid-laden plant portion. 69. A manual hand-held or pole-mounted applicator embodiment may comprise a tilting cup, sliding tray, trapdoor, swab, or brush end-effector configured to deposit the disruptive payload at the target region based on visual or tactile alignment, without requiring a mobile robotic platform. 70. A stationary or gantry-based embodiment may comprise a fixed or rails-mounted dispenser that translates over rows or trellises to achieve precise local placement at the target region. 71. A pneumatic or micro-jet embodiment may comprise a sprayer that emits microdroplets or narrow jets to deposit gels, liquids, or suspensions onto or near the target region with centimeter- or sub-centimeter accuracy, including embodiments using air knives or coaxial gas assist. 72. A timed- or condition-triggered predator release capsule embodiment may latch onto plant tissue and release beneficial insects gradually over minutes to days in response to elapsed time, humidity, temperature, or measured ant activity. 73. A lure augmentation embodiment may comprise acoustic, vibrational, thermal, or semiochemical stimuli operable to attract ants to the deposited payload locus and thereby increase encounter probability while maintaining precise local placement. 74. A target generalization embodiment may apply the same placement and staged-intervention techniques to honeydew-producing Hemiptera including mealybugs, scale insects, whiteflies, or leafhoppers protected by ants, in addition to aphids. 75. A flightless deployment embodiment may use a tethered perch, balloon, kite, or mast to position the end-effector by manual or wind-assisted means to effect precise local placement with minimal rotor wash. 76. A swarm embodiment may coordinate multiple low-cost devices, with or without arms, to perform distributed micro-depositions along a trail, corridor, or plant portion to exceed a treatment threshold while each individual device performs only a subset of operations.

Monetization and Damages Maximization: The system may include technical mechanisms that enable subscription, pay-per-use, and tiered-licensing business models designed to quantify and document use in a manner that supports damages calculations. In one embodiment, the UAV or mobile platform logs, in secure non-volatile storage, usage events including payload type, number of releases, time stamps, GPS coordinates, altitude, and operator identifiers. These logs may be cryptographically signed by a hardware-secured device identity so that a server or auditor can verify authenticity. The device identity may be provisioned at manufacture and protected by a secure element that stores private keys and a monotonic counter to prevent rollback. The system may periodically transmit signed usage summaries over an encrypted channel to a licensing and billing service, with store-and-forward operation when connectivity is unavailable so that metering data is preserved and uploaded upon reconnection.

Licenses may be granted on a subscription basis that activates features such as autonomous trail detection, multi-phase predator deployment, FPV visual servoing, and advanced imaging analytics. Feature entitlements may be represented as signed tokens bound to the device identity and optionally to a geofence or time window. The platform may enforce entitlements locally by gating user interface options and API endpoints, and by limiting maximum number of releases or treatment area according to the licensed plan, such as per-acre, per-drop, or per-flight tiers. An audit interface may allow export of signed, human-readable reports correlating release events with map tiles and timestamps so that economic value delivered can be substantiated. For enterprise deployments, a fleet console may aggregate telemetry from multiple devices, maintain immutable event ledgers, and provide role-based access controls, thereby enabling calculation of usage-based invoices and evidentiary records of infringing use.

In some embodiments, an offline license validation mode may be supported using time-limited activation files that are pre-signed by the licensing service and verified on-device using public keys stored in the secure element. The system may also support trial and feature sampling modes that are functionally constrained, for example limiting total releases or disabling autonomous return missions, providing clear technical demarcations between licensed and unlicensed capabilities. These mechanisms collectively enable measurement of use, association of that use with specific technical features, and production of verifiable logs that can increase potential damages awards by evidencing subscription value, feature-based pricing, and lost royalty calculations in the event of unauthorized deployment.

Enablement: An implementer may realize the invention using commercially available components and a straightforward assembly and calibration process. A multirotor UAV with at least a 500 g payload capacity may be selected and fitted with a rigid underframe mounting plate. A compact dispenser, such as a small gravity-fed magazine or rotary gate, may be attached beneath the airframe. A lightweight robotic arm with two or more degrees of freedom may be mounted centrally; a cable-driven or small servo-geared design may be used to minimize mass. A tiltable cup end-effector may be attached at the distal end and linked to a micro-servo or to a base-mounted servo via a Bowden-style cable for flipping. Two downward-facing FPV cameras may be rigidly affixed near the vehicle centerline with overlapping fields of view covering the arm workspace. An auxiliary servo controller and wireless telemetry link may be wired to the flight controller or to a companion microcontroller. Software may comprise: (i) a vision pipeline that detects either ant trails from live video or drop targets from precomputed maps, (ii) a visual servoing loop that computes the pixel-space offset between the end-effector marker and the desired drop point in both camera feeds and drives the arm servos to reduce the offset, (iii) a release routine that actuates the cup tilt and logs the event with timestamp, GPS, and payload type, and (iv) optional autonomy to navigate between waypoints. Calibration may be performed by placing a fiducial marker on the ground and iteratively commanding small joint motions while recording corresponding image displacements to learn a control mapping; this may be automated using a brief supervised routine. Bait balls may be formulated by mixing a sugar matrix with a slow-acting toxicant at label-appropriate concentrations, extruding small spheres, and drying to a firm consistency; abrasive particulates or pheromones may be optionally added. Prior to flight, the operator may upload a mission plan or enable manual FPV control, arm the system, and conduct a hover test at 2-5 meters to validate camera alignment and arm responsiveness. During operation, the UAV may lower to near 0.5-1.0 meters over the target trail or plant, position the cup using visual servoing, release the payload, and record a cryptographically signed log entry. A second flight after a delay may carry beneficial predators in a ventilated capsule that opens above the target plant for release. In software-enabled embodiments, the control plane and logging interfaces may be exposed as Model Context Protocol tools so that external orchestrators can invoke bounded, auditable actions. An implementer may define MCP schemas for imagery acquisition, trail detection, target selection, end-effector alignment, payload release, and event logging, consistent with the examples described above; for instance, a capability query may be expressed as {“tool”:“get_capabilities”,“args”:{“device_id”:“UAV-34A2” }}, returning {“device_id”:“UAV-34A2”,“capabilities”:[“imagery.acquire”,“detect.trail”,“select.drop_point”,“arm.ali gn”,“payload.release”,“event.log”],“signature”:“base64signature” }, and an entitlement check may be invoked as {“tool”:“get_entitlements”,“args”:{“device_id”:“UAV-34A2” }}, returning {“plan”:“pro”,“features”:[“autonomous_detection”,“staged_release”,“fpv_visual_servoing”],“valid_unt il”:“2026-12-31T23:59:59Z”,“signature”:“base64signature” }. These MCP tools may be implemented on a companion computer or base station that validates inputs, issues servo and flight commands through supported protocols, and emits signed confirmations, enabling end-to-end implementation without undue experimentation.

Technical Effects: Precise local placement of bait on a foraging trail increases encounter probability by worker ants, accelerating pickup and colony-wide distribution via trophallaxis, thereby improving efficacy at lower toxicant mass compared to broadcast spraying. Staged deployment that follows baiting with predator release leverages reduced ant aggression to increase predator establishment and aphid suppression, improving integrated pest management outcomes. Visual servoing with two overlapping FPV cameras yields sub-centimeter placement without full 3D calibration, making the system robust to camera misalignment, wind gusts, and variable lighting, and reducing hardware complexity. Using abrasive particulates provides a non-toxic disruptive modality that can be deployed near nests without chemical residues. Cryptographically signed usage logs create verifiable records that support compliance, traceability, and monetization while enabling field audits. In additional embodiments employing semiochemicals, microbial agents, contact-transfer deposition, vectored airflow, or electrostatic attraction, the system may achieve similar or enhanced colony-level disruption with reduced drift and minimal residue, further increasing robustness to design-around attempts while maintaining precise, externally verifiable placement.

Process Flows: Representative flows include detection-first baiting and staged biocontrol. In one flow, imagery is acquired, an ant trail or aphid-stress corridor is detected or inferred, a drop point is selected, the cup is loaded beneath the dispenser, the arm positions the cup over the drop point using visual servoing, the payload is released, and an event log is written; this may repeat across multiple waypoints. In a staged flow, the UAV returns after a delay, re-identifies the treated area, and releases beneficial predators onto the plant now less protected by ants, with both events logged and associated to a common mission identifier. In another flow, explicit trail detection is omitted and a drop point is selected on aphid-laden plant tissue or a short arc near the stem base to intersect likely ant approaches.

For clarity of method support and direct conversion to flowcharts, a textual flow-to-claim mapping may be stated as follows: (i) identify the target region comprising at least one of a foraging trail, a nest-proximate approach corridor, or an aphid-infested plant portion; (ii) determine a specific drop location within or adjacent to the target region and load the cup beneath the dispenser; (iii) align the end-effector over the drop location via visual servoing while maintaining stable hover; (iv) actuate the release mechanism to deposit the disruptive payload; (v) optionally revisit after a delay to release beneficial predators; and (vi) record a cryptographically signed event including geolocation, time, payload type, and device identity.

Claim Support: Each recited element in the claims is supported by explicit disclosure. Method steps of identifying a target region-including a trail, nest-proximate approach corridor, or aphid-infested plant portion-positioning and releasing a payload by tilting or dropping, and conducting delayed predator release are described. Apparatus elements including a mobile platform, a target detection system, and a payload delivery mechanism with a robotic arm and cup are disclosed along with alternative end-effectors and release mechanisms. The computer-readable medium claim is supported by the described control software that acquires imagery, determines drop locations, actuates servos, releases payloads, and records signed logs. Variants in the itemized list provide further support for alternative implementations and dependent claim scope.

Broadening Alternatives: Multiple alternatives are disclosed for each major function, including various mobile platforms (aerial and ground), detection methods (CNN, optical flow, graph-based, spectral inference, plant-ROI targeting, and operator tagging), communication protocols and control interfaces, arm architectures (cable-driven, geared, prismatic, telescoping, SCARA, continuum), and end-effectors and dispensers (cup, sliding tray, trapdoor, rotary gate, peristaltic pump, brush release).

Payloads may include sugar-toxicant baits, abrasive particulates, pheromone-laced carriers, gel or microencapsulated formulations, and live beneficial organisms. Target regions may include explicit trails, nest-proximate approach corridors, or aphid-laden plant portions, allowing implementations that do or do not reconstruct trails while maintaining precise, behaviorally informed placement. Further embodiments include disruptive payloads such as repellents, attractants, semiochemicals, insect growth regulators, sterilants, and microbial biocontrol agents, and deposition modalities including contact-transfer via swab or brush, perching-assisted placement, vectored airflow projection, or electrostatic attraction, thereby capturing interface-independent implementations that achieve the same technical effect of precise local placement on or near the defined target region. The alternatives further encompass manual, stationary, timed-release, pneumatic micro-jet, lure-augmented, flightless-perch, multi-device swarm, and non-aphid Hemiptera variants, treating such substitutions as equivalent so long as the core technical effect of precise local placement at the defined target region is achieved.

Claim Layering: The claim set includes independent method, apparatus, and computer-readable medium claims that capture different abstraction levels of the invention. Additional features suitable for future continuations are presented in the continuation-ready itemized list so that further independent or dependent claims may be pursued without altering the present claim count.

No Unneeded Limitations: Independent claims recite only the core elements required to practice the inventive concept of identifying an ant-protective target region and precisely depositing a disruptive payload to weaken ant defenses, with apparatus and software claims reciting correspondingly minimal structures and functions. Optional features, such as specific toxicants, camera types, arm designs, or communication protocols, are placed in dependent claims or in the itemized embodiments to avoid narrowing the principal scope.

External Observability: Externally verifiable behaviors are disclosed, including visible or audible release cues and dyed or colored payloads, together with cryptographically signed logs of release events including GPS coordinates, timestamps, payload type, and device identity. These features enable proof of operation and can facilitate enforcement where internal system details are not directly accessible.

Interoperability Coverage: The system is described to interoperate across multiple platforms and interfaces, including UAV and ground robots, and supports industry-standard protocols such as MAVLink, ROS/ROS 2, RTSP, RTP, NMEA, CAN, SBUS, UART, I2C, SPI, Bluetooth, Wi-Fi, LTE, and mesh networking. This cross-platform design prevents circumvention by interface changes and eases integration into heterogeneous fleets.

Fallback Embodiments: Simplified embodiments are disclosed that omit the robotic arm and rely on vehicle positioning with a fixed dispenser to achieve accurate drops, or that use manual operator tagging instead of automated detection. Ground-based platforms such as wheeled rovers or quadrupeds provide alternatives where flight is constrained, preserving the inventive method of targeted placement on or near ant pathways. Additional fallbacks include region-of-interest deposition directly onto aphid-laden plant tissue or laying a short line or arc of payload near the plant stem to intersect likely ant approach paths, without explicit trail or nest localization. Additional fallbacks include perching or contact-transfer applicators that touch the target region using a pad, brush, or wick, with adhesive or electrostatically charged carriers to ensure local placement when free-fall release is impractical.

Hold Up in Court: The disclosure teaches concrete structures and algorithms sufficient for implementation, details multiple interoperable alternatives, and provides explicit technical effects and externally verifiable behaviors. The cryptographically signed logging and subscription mechanisms support damages models. The combination of trail- or target-region-based bait placement with staged predator release and vision-guided sub-centimeter delivery is described with specificity and is positioned as a non-obvious integration of known components to achieve new ecological control outcomes.

Physics Plausibility: From a physics standpoint, low-altitude multirotor UAVs can maintain stable hover with modem flight controllers and gimbals, enabling sub-centimeter end-effector positioning when aided by visual servoing. Dropping small bait spheres from 0.5-1.0 meters produces minimal lateral drift under typical light wind conditions, especially when released from a tilting cup with negligible initial velocity. Near-infrared and multispectral imaging can detect vegetation stress correlated with aphid infestation at field-relevant spatial resolutions, and optical methods described for ant trail inference are within the capabilities of contemporary embedded vision systems.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A method for controlling aphid populations in a crop environment, the method comprising identifying a target region associated with ant protection of aphid colonies, the target region comprising at least one of a foraging trail, a nest-proximate approach corridor, or an aphid-infested plant portion, and depositing a disruptive payload on or near the target region, the disruptive payload comprising at least one of a bait composition, an abrasive particulate, or live beneficial predators, the disruptive payload being configured to disrupt the ant colony and thereby reduce aphid protection.

The method of item 1, wherein the bait composition comprises a sugar-based carrier and a slow-acting insecticide selected from boric acid, fipronil, spinosad, or hydramethylnon.

The method of item 1, wherein the foraging trail is identified by detecting linear movement patterns between an ant nest and an aphid-infected crop plant using aerial imagery.

The method of item 1, wherein the target region is inferred by detecting aphid-induced plant stress via near-infrared or multispectral imaging and estimating a likely ant path from surrounding nest sites.

The method of item 1, further comprising actuating a robotic arm to move a cup containing the bait composition from a loading position to a deployment position prior to release.

The method of item 5, wherein the cup is flipped to release the bait composition by a servo motor or by a tensioned cable actuated remotely.

The method of item 1, further comprising returning to the aphid-infested crop plant after a time delay and releasing live beneficial predators selected from ladybug larvae, lacewing larvae, or parasitic wasps.

The method of item 1, wherein the bait composition includes finely ground shell material configured to physically irritate or damage ant larvae or soft-bodied pests.

The method of item 1, wherein depositing comprises hovering a drone at a height of less than one meter above the target region and actuating a gravity-assisted or mechanically tilted release mechanism.

An apparatus for disrupting ant colonies that protect aphid populations on crops, the apparatus comprising a mobile platform, a target detection system configured to identify at least one of a foraging trail, a nest-proximate approach corridor, or an aphid-infested plant portion, and a payload delivery mechanism mounted on the platform and configured to deposit a disruptive payload on or near an identified target region.

The apparatus of item 10, wherein the mobile platform comprises an unmanned aerial vehicle.

The apparatus of item 10, wherein the payload delivery mechanism comprises a cup configured to receive a disruptive payload from a dispenser and to release the payload by tilting, flipping, or dropping.

The apparatus of item 12, further comprising a robotic arm coupled to the mobile platform, the arm being configured to position the cup at a desired drop location.

The apparatus of item 13, wherein the cup is actuated by a servo motor or a tensioned cable to release the bait.

The apparatus of item 10, wherein the target detection system comprises a camera and an image processing unit configured to detect ant movement, infer approach corridors, or identify aphid-laden plant portions based on plant stress or spatial patterns.

The apparatus of item 10, wherein the bait composition includes a slow-acting toxicant combined with a carbohydrate attractant.

The apparatus of item 10, further comprising a secondary dispenser configured to release beneficial insects or additional substances onto the crop or nest site after a predetermined time delay.

The apparatus of item 10, wherein the payload delivery mechanism is configured to dispense particulate abrasive material such as finely ground shell or silica to physically damage ant larvae or soft-bodied pests.

The apparatus of item 10, wherein the mobile platform comprises autonomous navigation and control means for executing a programmed baiting sequence based on identified target locations.

A non-transitory computer-readable medium storing instructions that, when executed by one or more processors of a mobile platform, cause the platform to acquire images or video of a crop environment, detect or infer a target region comprising at least one of a foraging trail, a nest-proximate approach corridor, or an aphid-infested plant portion from the images or from spectral vegetation data, determine a drop location on or near the target region, actuate via servo commands a robotic arm to position a cup beneath a dispenser to receive a disruptive payload and to move the cup to the drop location, release the disruptive payload by tilting, flipping, or dropping, and record in secure non-volatile storage using a cryptographic device identity usage events including payload type, timestamps, and GPS coordinates.

### Embodiment ME: Cable-Based Multiplexed Actuation System for Lightweight Robotic Limbs and End-Effectors

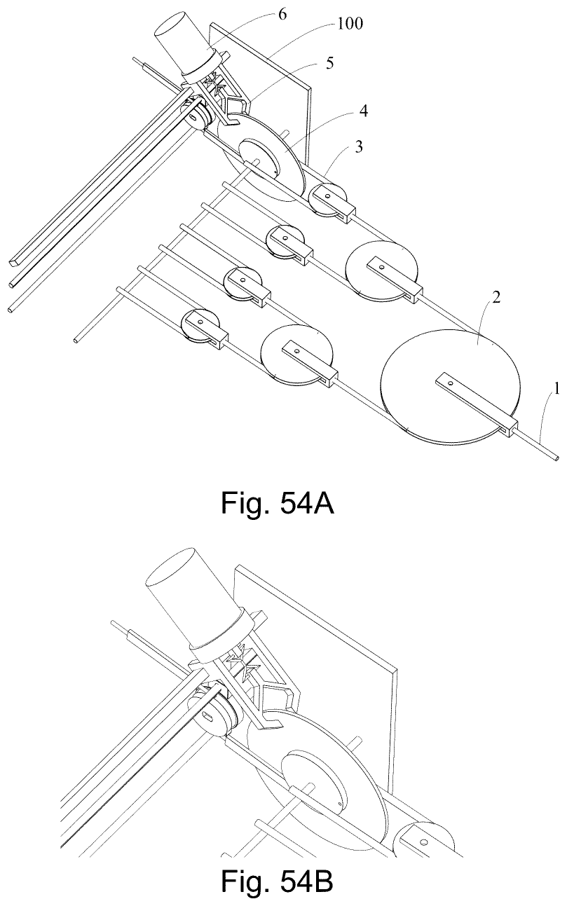

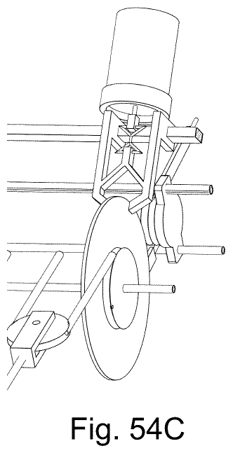

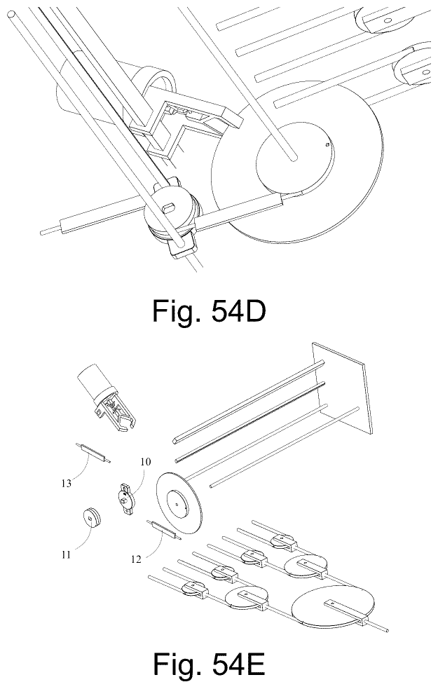

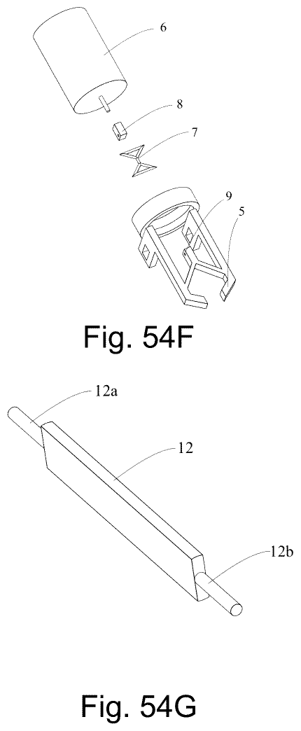

The example embodiment is depicted in FIGS. 54A to 54G.

A multiplexed cable-driven actuation architecture is disclosed in which a single input actuator selectively routes mechanical force to multiple outputs via a centralized motion multiplexer. Each gated output may preload an elastic element and release energy through a rotary damper to produce delayed, smoothed motion at remote joints or end-effectors. The arrangement reduces onboard actuator count, weight, and wiring while enabling time-sliced control of multiple degrees of freedom for limbs or manipulators, including those mounted on unmanned aerial vehicles or multi-limbed robots. Variants include dedicated or indexed gating, optional elastic buffering and damping, composite elastic cables with non-stretch ends, and centralized monetization controls for subscription or usage-based enablement.

GENTLE INTRODUCTION: Many robots pull on cables to move joints. Traditionally, each joint gets its own motor, which adds weight, wiring, and cost. The invention instead lets one strong actuator time-share its effort across many joints by using a central “switchboard” of small gates. When a gate is opened, the main actuator pulls on an elastic element, like stretching a rubber band for that joint. A rotary damper then lets the stored energy unwind smoothly, so the joint moves gradually even after the main actuator has moved on to the next gate. In practical terms, one motor takes turns “charging up” several joints, and each joint finishes its motion on its own, under damping, without needing its own motor. This keeps moving parts light and centralizes mass for stability, which may be important for drones or lightweight multi-limbed robots. The approach favors steady, reliable motion over high-speed bursts, making it suitable for slow, persistent tasks such as tending plants, cleaning, or sampling. Designers may choose between small local gate actuators (one per gate) or a single indexing mechanism that mechanically visits and toggles each gate in sequence, further minimizing electronics and wiring.

EXAMPLES: The following concrete examples walk through representative cases using the element identifiers defined in the Anchor. These examples are illustrative and do not limit scope. Example 1: Two-output bench setup with dedicated gate actuators. A single input actuator pulls the input cable (1) by a defined stroke, for example 20 mm, with the input-to-intermediate splitter pulley (2) routing motion to two intermediate branches (3a, 3b), each leading to its own gate module containing primary spool (4), clamp (5), damper (10), secondary spool (11), elastic member (12) with ends (12a, 12b), and output cable (13) with ends (13a, 13b). The controller energizes the dedicated actuator of Gate A to disengage clamp (5A), leaving Gate B's clamp (5B) engaged, and with clamp (5A) released, motion from branch (3a) rotates spool (4A), stretching elastic member (12A) by, for example, 8 mm equivalent cable length while the damper-coupled spool (11A) resists rapid rotation. The controller then re-engages clamp (5A), freezing the stored strain in elastic member (12A), and the input actuator relaxes cable (1), returning splitter (2) to neutral. The controller next disengages clamp (5B) and repeats the pull on cable (1), storing energy into elastic member (12B) via spool set (4B, 11B). After both gates are “charged,” each damper (10A, 10B) meters release of its corresponding elastic member (12A, 12B), driving distal motion through output cables (13A, 13B) toward two separate joints; the joints move smoothly and partially in parallel due to damper-regulated release, even though the input actuator services only one gate at a time, and external loads acting on the joints are reflected as counter-tension in output cables (13A, 13B), which, together with damper settings, determine motion timing and final pose. Example 2: UAV-mounted arm with cam-indexed gating and three degrees of freedom. A single high-torque actuator in the UAV body pulls input cable (1) while a cam-based indexer rotates to selectively depress the release lever of clamp (5) for one gate at a time, starting with the shoulder joint gate; with the shoulder gate's clamp (5S) released, the pull on branch (3S) rotates spool (4S) to preload elastic member (12S), and damper (10S) sets a long time constant, for example 2 to 3 seconds, to allow graceful shoulder elevation. The indexer then advances to the elbow gate, releases clamp (5E), and the input actuator performs a shorter pull to partially preload elastic member (12E), targeting a quicker elbow flex with a faster damper (10E); it then advances to the wrist gate, releases clamp (5W), and the input actuator imparts a small preload appropriate for fine wrist adjustment. The input actuator subsequently idles while dampers (10S, 10E, 10W) meter release so the arm exhibits overlapping shoulder, elbow, and wrist motions with centrally concentrated mass and no motors on the links, and visual proprioception may observe elastic and cable positions to confirm expected release trajectories, allowing the controller to decide whether to revisit a gate for a top-up pull or to increase braking torque by re-engaging a clamp to hold position against gusts or payload shifts. Example 3: Ground robot limb using direct-cam braking without actuation wires. The multiplexer's cam disc rotates until a raised lobe directly presses a band-brake integrated with clamp (5) on Gate 1, releasing the brake by lifting a spring-loaded shoe from spool (4); the input actuator pulls cable (1), motion flows through branch (3) to Gate 1, and elastic member (12) is stretched while secondary spool (11) is coupled to damper (10) to shape the output. The cam disc then rotates to a dwell position that allows the band-brake to re-engage, holding the stored energy, before advancing to Gate 2 to repeat the cycle while omitting actuation wires entirely; as the robot traverses uneven terrain, bidirectional compliance in output cable (13) with elastic central portion absorbs shocks while dampers prevent rebound, yielding stable foothold placement without additional actuators at the limb.

TECHNICAL FIELD: The present invention relates generally to the field of robotics, and more specifically to systems and methods for cable-driven actuation. In particular, the invention pertains to multiplexed motion transmission architectures for robotic limbs, arms, or end-effectors, including those mounted on unmanned aerial vehicles (UAVs) or multi-limbed robotic platforms, wherein a single actuation input may be selectively routed to multiple outputs through a centralized gating mechanism.

BACKGROUND: Cable-driven robotic systems are widely used in applications where weight reduction, spatial decoupling, or safety is critical. In such systems, actuators are often located remotely from the actuated joints, and force is transmitted via tensioned cables, tendons, or pull-lines. This architecture has seen particular use in soft robotics, aerial manipulators, prosthetics, and lightweight multi-limbed robots. While cable-based actuation provides several advantages-such as low moving mass and increased compliance—it presents key challenges in scalability and control. In conventional designs, each degree of freedom typically requires its own dedicated actuator, routed control cable, and associated electronics. As the number of joints increases, this one-to-one mapping leads to a proportional increase in system weight, cost, power consumption, and mechanical complexity. This limitation is especially problematic for UAVs, where distributed weight severely impacts flight stability and energy efficiency, and for agricultural or field robots, which benefit from low-cost, robust, and scalable designs.

Furthermore, many cable-driven systems lack mechanisms for energy buffering or time-delayed release, meaning that actuation must be synchronized in real time, requiring more sophisticated controllers and higher energy peaks. In some applications-such as insect targeting, weed suppression, localized pollination, or environmental manipulation-motion can be slow, but must occur reliably and in parallel across multiple joints, often with limited onboard computation or actuation resources.

There remains a need for a multiplexed actuation architecture that allows a single actuator to control multiple joints or outputs by selectively routing force, optionally storing energy in elastic elements, and releasing it in a delayed, controlled manner. Such a system would allow robotic limbs and manipulators to achieve higher degrees of freedom with fewer actuators, centralized actuation, reduced weight, and improved safety-particularly in applications where cost, power, and weight constraints are dominant.

SUMMARY: The present invention provides a multiplexed cable-driven actuation system for robotic limbs, arms, or end-effectors, particularly suited for use on unmanned aerial vehicles (UAVs) and multi-limbed robotic platforms. The system is designed to allow a single actuation input to selectively deliver mechanical force to multiple output paths via a centralized motion multiplexer, thereby significantly reducing the number of actuators required to achieve multi-joint motion.

In one embodiment, the invention comprises a motion multiplexer having a set of selectively actuated motion gates, each coupled to a corresponding control cable. The multiplexer is configured to receive input from a single input cable or actuator and, based on the state of the motion gates, to route mechanical force to one or more downstream output cables. Each output may be connected to a cable-driven joint or end-effector, located remotely on a limb, arm, or manipulator.

In some embodiments, elastic energy storage elements are connected to the output cables. When a gate is open, motion from the input cable stretches the elastic element, storing potential energy. This energy may then be released through a rotational damper, allowing time-delayed, smoothed motion to be delivered to the limb or end-effector. This enables temporal buffering of discrete actuation inputs and the coordination of multiple joint motions using a single actuator.

The motion gates may be actuated by dedicated lightweight actuators, such as coreless motors or shape-memory alloy (SMA) wires. Alternatively, a single indexing actuator may be used to selectively enable one motion gate at a time, either in a predefined sequential order or on demand under control of a computational controller. This approach allows for extremely low actuator count while maintaining the ability to route motion to any of multiple outputs based on system requirements or environmental conditions.

The system may be implemented using 3D-printed mechanical components, including spools, clamps, and structural mounts, in combination with commercially available rotary dampers, fishing-line-style control cables, and low-friction routing guides. The use of modular, low-cost components enables scalable and field-deployable designs.

In one application, the multiplexed actuation system may be integrated into the central body of a multi-limbed robot, such as a hexapod, wherein the limbs are constructed from passive, lightweight structures without embedded motors. In another embodiment, the system may be mounted on a UAV with a cable-actuated robotic arm, enabling manipulation of objects or plants with high precision while maintaining flight stability due to centralized mass distribution.

The invention is particularly suited for tasks that involve slow-changing or continuous environments, including but not limited to weed suppression, insect targeting, localized pollination, leaf manipulation, environmental sampling, cleaning, hedge trimming, and debris removal. Because these tasks do not require rapid motion but benefit from persistent, autonomous operation, the proposed system enables a robot to perform complex functions using minimal energy and a simplified control system.

By decoupling the number of joints from the number of required actuators, and enabling elastic buffering, delayed motion, and lightweight remote actuation, the invention offers a scalable, energy-efficient, and low-complexity solution for cable-driven robotic systems across a wide range of domains. In additional embodiments, two or more input actuators may feed a shared tension bus via summing pulleys, differential pulleys, torque-summing shafts, or one-way clutch combiners, while the motion multiplexer still provides selective gating to multiple outputs; a controller may time-slice, cross-fade, or fail over among inputs without placing actuators on distal links.

TECHNICAL EFFECTS: The disclosed architecture may deliver concrete technical effects that arise from specific combinations of elements in the embodiments. Centralizing actuation in a motion multiplexer on base (100) may reduce distal link mass and rotational inertia, which may reduce required joint torques for a given motion profile, improve disturbance rejection for UAV-mounted arms by concentrating mass near the center of gravity, and extend flight time through reduced hover power. Time-sliced routing from a single input cable (1) through gates (5) may reduce peak electrical current draw and copper losses versus simultaneous multi-motor drive, enabling smaller power electronics and batteries while maintaining aggregate work output across degrees of freedom.

Preloading elastic members (12) and metering release with dampers (10) may low-pass filter motion and force, producing smoother trajectories, reducing overshoot, and suppressing oscillations and chatter at distal joints; these effects may increase end-effector stability in contact tasks and reduce controller bandwidth requirements. The elastic-damper path may act as a mechanical buffer that permits the input actuator to operate near an efficient speed-torque point while distal motions proceed at application-appropriate rates, improving overall electromechanical efficiency. Composite cables with non-stretch ends (12a, 12b, 13a, 13b) may localize strain away from anchors to reduce creep and slippage, maintaining calibration over repeated cycles and increasing cable life. Indexing variants that directly actuate clamps (5) or brakes via a cam may reduce wiring and distributed electronics, lowering electromagnetic interference and failure points while providing deterministic mechanical addressing that is tolerant of partial controller outages. Variants that omit elastic storage or damping may still provide a technical effect of actuator-count reduction and centralized mass, while offering immediate, gated force transmission suitable for applications requiring direct response. Bidirectional compliance in output cable (13) may absorb shocks from terrain or contact, decreasing peak loads on structures and dampers and improving survivability in field environments. Cascade splitting at pulley (2) may furnish mechanical advantage or distribution ratios that can be selected via groove diameter, enabling force sharing across branches (3) without adding actuators. Collectively, these effects may yield measurable advantages, including reduced system mass and wiring, lower peak power, improved stability for aerial platforms, higher uptime due to fewer distal actuators, and predictable, externally observable delayed-motion signatures that may simplify diagnostics and control.

ENABLEMENT: The following implementation guidance enables a skilled person to build and operate representative embodiments without undue experimentation. Dimensions, materials, and parameters are exemplary and may be varied to meet application requirements.

A representative gate module may be built on a 3D-printed base (100) using common polymer filaments such as PETG or nylon for strength and heat tolerance. Primary spool (4) and secondary spool (11) may be printed with circumferential grooves sized for a 0.3 mm to 0.8 mm braided polymer cable; a nominal groove pitch of 1.0 mm with a 10 mm to 14 mm pitch diameter may be used to achieve 31 mm to 44 mm of cable travel per full revolution. Each spool may run on a 5 mm or 8 mm steel shaft with two 608 or 625 radial ball bearings to minimize friction. The rotational damper (10) may be a commercially available viscous rotary damper rated between 0.03 N·m·s/rad and 0.3 N·m·s/rad; the damper may be coupled to the secondary spool (11) via a keyed hub or radial pins to prevent slip.

Clamp assembly (5) may be realized as a band brake or split-collar friction clamp encircling a brake drum integrated with primary spool (4). A spring may preload the clamp to a default-locked state delivering at least 0.5 N·m static holding torque at the spool; the release actuator (coreless motor, SMA wire, or cam follower) may provide 10 N to 25 N of linear release force through a short linkage to overcome the spring and reduce clamp torque below 0.05 N·m dynamic during charging. Friction lining may be leather, felt, or fiber-reinforced PTFE tape adhered to the band; a replaceable liner enables field maintenance.

Elastic energy transmission member (12) may be formed as a central elastomer segment of 60 mm to 120 mm free length with an effective linear spring constant k between 500 N/m and 3000 N/m, bonded or crimped to non-elastic terminal segments (12a, 12b) of 0.3 mm to 0.8 mm aramid or UHMWPE line. A practical construction uses 2 mm OD silicone rubber cord for the central segment with CA adhesive-primed inserts and double crimp sleeves for the terminals; each terminal may be tied off to a through-hole or slot at the spools with two wraps to distribute load. The output cable (13) may be a low-stretch UHMWPE line with optional 10 mm to 40 mm central elastic section to provide bidirectional compliance at the limb; terminal segments (13a, 13b) may terminate in crimped eyelets or knots captured by cleats on the distal joint.

The input actuator may be a compact geared DC motor or servo motor delivering 0.5 N·m to 2.0 N·m continuous torque. When wrapped on a 12 mm radius capstan, this produces 41.7 N to 166.7 N of line pull. With the example spool radius of 6 mm to 7 mm at the gates, a 20 mm input stroke at cable (1) may yield one-third to one-half revolution at a gate spool (4), sufficient to preload 5 mm to 10 mm of equivalent elastic stretch in member (12), corresponding to 2.5 N to 30 N of stored force depending on k and geometry. The splitter pulley (2) may be an idler with dual grooves on sealed bearings or a cascaded block to introduce mechanical advantage; a 1:2 cascade may be used when higher force and lower travel are desired at branch (3).

Assembly may proceed as follows. Spools (4, 11) are printed, deburred, and pressed onto their hubs with bearings. Damper (10) is mounted to base (100) so that its output shaft couples rigidly to secondary spool (11). Clamp (5) is assembled around the primary spool (4) brake drum with a torsion or extension spring biasing the clamp to the engaged state; ensure free clearance when released.

Elastic member (12) is fabricated and installed between anchor points on spools (4) and (11) such that initial pre-tension at zero angle is 2% to 5% of the intended maximum load; verify symmetric wrap to avoid lateral walk. Output cable (13) is routed from secondary side toward distal guides, through Bowden sheaths where needed, and anchored at the joint lever arm with adjusters permitting ±5 mm of trim. Input cable (1) is routed through splitter (2) to intermediate branches (3), then to each primary spool (4), maintaining bend radii above 5× cable diameter and avoiding acute angles. Indexer components (cam disc, followers, return springs) are mounted so that a single cam rotation yields discrete dwell positions aligned with each gate's release lever; detents or magnet pairs may ensure repeatable registration.

Calibration may be performed with simple tools. With all clamps (5) engaged, verify that back-driving the distal joint does not rotate spools (4) and that holding torque exceeds expected external loads with a factor of safety of 2×. For each gate, release clamp (5) and pull input cable (1) a known stroke S; measure angular rotation θ of spools, the resulting elastic extension x=rθ where r is the effective wrap radius, and confirm stored force F=kx within 10% of design. Re-engage the clamp and release input cable to neutral; measure distal motion as damper-regulated release occurs. Select damper (10) rating such that the approximate linear release time constant τlin≈(b r\hat{ }2)/k yields 1 s to 3 s for the target joint, where b is the damper coefficient in N·m·s/rad. If τlin is too short, increase b or reduce r; if too long, reduce b or increase r. For SMA-driven clamps, verify thermal cycle time and add bias springs to guarantee positive re-engagement on cool-down; for motor-driven clamps, set current limits to avoid overheating.

Control and timing may be implemented in a microcontroller. For dedicated-gate variants, a simple loop may: open Gate i; command input actuator to pull to a measured stroke or force threshold; close Gate i; advance to Gate i+1; and pause while dampers meter release. For indexed variants, interleave cam steps with input pulls. Visual proprioception or low-cost inline tension sensors may be used to estimate preload x and to decide whether to top up a given gate. In UAV use, schedule preloads during low-disturbance flight phases to minimize transients on the airframe; in ground robots, synchronize with gait phases.

Scaling guidelines may be applied. To double distal travel without changing force, increase spool diameter or elastic length proportionally and maintain k/r constant. To increase output force without increasing actuator size, introduce a 2:1 cascade at splitter (2) or reduce r at the primary spool (4), accepting increased wrap friction that may be offset with PTFE liners. For harsh environments, substitute stainless shafts and sealed bearings, encapsulate dampers, and replace silicone elastomer with EPDM or polyurethane cords. Maintenance intervals may be set by counting clamp cycles; relining the friction band at 50,000 to 100,000 engagements may be sufficient in typical duty.

These steps, dimensions, and parameter relationships permit construction, calibration, and operation of the disclosed multiplexed actuation system using commodity parts and standard tools while leaving ample design flexibility.

Scope and interpretation: The scope of the invention is defined solely by the claims. The figures and descriptions herein, are illustrative examples and do not limit the scope. Features and subfeatures disclosed in separate embodiments may be combined, substituted, omitted, or reordered unless expressly stated otherwise. Process and force-flow sequences may be executed in alternative orders, in parallel, iteratively, or by equivalent mechanisms. Dimensions, materials, control strategies, and component choices are exemplary unless expressly recited in the claims. Terms such as “may,” “can,” “for example,” and similar language indicate optionality and non-limiting illustrations. As used herein, a tension element denotes a flexible tensile transmission member such as a cable, tendon, pull-line, belt, tape, strap, or chain; references to cables are exemplary and encompass such tension elements. The description further includes embodiments in which the function of a single input is realized by a selector or combiner that feeds a shared tension bus from multiple input sources such that, at a given update window, one source or a weighted combination presents an effective single input to the multiplexer. Functionally equivalent motion gates include, without limitation, braking, clamping, clutching, ratcheting, overrunning, yield-lock, magnetorheological, electrorheological, eddy-current, magnetic-particle, electrostatic, hydraulic, pneumatic, or shape-change mechanisms that, when commanded or conditioned, raise mechanical impedance between an input and an output to inhibit motion and, when released, reduce impedance to permit motion. Likewise, the phrase “single input” encompasses any architecture in which a shared energy bus, mechanical differential, or transmission presents, within an update window, an effective single source to the multiplexer, including planetary or bevel differentials, harmonic or traction drives, and electrically summed actuators coupled by one-way clutches. Substituting belts, tapes, chains, push-pull rods, fluid lines, or rigid linkages for cables; substituting accumulators, torsion bars, compliant hoses, flywheels, or series springs for the elastic store; and substituting dashpots, flow restrictors, eddy-current or viscous dampers, or friction packs for the damper may not avoid the inventive concept. Integrating a gate within a distal joint module, distributing gates along output paths, or packaging a gate within a gearbox or joint housing may still fall within the centralized multiplexing architecture so long as a selector deterministically enables one or a subset of outputs from a shared input during an update window. Implementations that frame gating as variable transmission engagement, selectable gearsets, or torque-routing clutches remain motion gates as defined herein. The externally observable signatures described herein, including time-sliced preloading with delayed, damper-shaped motion, are intended to encompass such equivalents. Selector topology may include but is not limited to star, tree, ring, bus, ladder, cascade, daisy-chain, or crossbar arrangements of gates; staging gates in series or parallel along an output path or across multiple paths may not avoid the architecture so long as the selector deterministically lowers mechanical impedance between a shared energy source and at least one of several outputs within an update window. Concurrent admission of actuation to two or more outputs via proportional or multiport gates remains selective routing under this disclosure when each output path includes its own impedance element or energy store that meters or delays motion. Duplication of inputs to match outputs while combining them through a differential, summing pulley, or torque combiner such that, within an update window, each addressed output is driven by a single effective source or a weighted combination presented on a shared tension bus may still meet the “single input” characterization and may not avoid infringement by mere actuator duplication upstream of the combiner. Gates that are intentionally leaky, slip-limited, or torque-threshold devices may constitute selective gating where leakage or slip is tuned to achieve controlled admission, buffering, or metering of energy into an output path.

Design-around resilience: Embodiments that relocate or recharacterize gating, buffering, or damping while preserving selective admission from an effective single source remain within scope. Implementations that realize gates as material-state or field-controlled impedance changes including granular jamming clutches, phase-change wax couplers, electroadhesive or electrostatic clutches, piezoelectric friction stacks, or vacuum-jammed fabrics; distribute dampers or energy stores along the output path or inside distal joints while the selector deterministically lowers impedance to at least one path within an update window; substitute software-defined valve schedules in fluidic networks or software-controlled magnetic fields in particle brakes as supervisory selectors that merely admit energy from a shared bus; or place small local actuators that function only as latches, brakes, or impedance modulators rather than energy sources do not avoid the centralized multiplexing architecture. Replacing tension elements with torsion shafts, Bowden tubes with flexures, a shared tension bus with pressure, torque, or voltage buses, or re-encoding gating as variable transmission engagement similarly does not avoid the inventive concepts so long as an effective single source is selectively admitted to multiple outputs with optional buffering and metered release as disclosed. The externally observable signatures described herein-including time-sliced preloading followed by delayed, damper-shaped motion-persist across such variants.

### Brief Description of Drawings

FIG. 54A shows an overview

FIG. 54B shows an more detailed view

FIG. 54C shows an more detailed view

FIG. 54D shows an more detailed view

FIG. 54E shows an exploded view

FIG. 54F shows an detailed view of the example braking mechanism

FIG. 54G shows an detailed view of the example elastic with wire ends.

### Anchor: Elements, Figures, and Relationships

For clarity across FIGS. 5A to 5G, the following element identifiers are used consistently: (1) denotes an input actuation cable that supplies pull force into the multiplexer; (2) denotes an input-to-intermediate cable splitting pulley that may cascade-split the input into branches; (3) denotes intermediate output cables from the splitter toward individual gate modules; (4) denotes a primary dual-groove spool with optional flywheel that interfaces linear cable motion to rotary elements within a gate; (5) denotes an electromechanical clamp assembly that selectively permits or arrests rotation of spool (4) to implement the gate function; (10) denotes a rotational energy dissipation unit such as a viscous rotary damper coupled to regulate motion; (11) denotes a secondary dual-groove spool coupled to the damper and to the elastic path; (12) denotes an elastic energy transmission member whose non-elastic terminal segments are labeled (12a) and (12b) and whose central segment is elastic; (13) denotes an output cable linking the gate module to a distal limb, joint, or end-effector, with non-elastic terminal segments labeled (13a) and (13b) and an optional central elastic portion; (100) denotes a shared base or support structure that mounts spools, clamps, dampers, and indexing hardware. Force and motion flow as follows: the input cable (1) is routed to the splitter pulley (2), whose branches (3) feed respective gate modules. Within each gate, the primary spool (4) is the rotary element gated by clamp (5). When the clamp is disengaged, motion from cables (3) rotates spool (4), which is mechanically coupled to spool (11) via the elastic member (12) such that potential energy is stored as strain in (12). Spool (11) is coupled to the rotational damper (10) to regulate release of stored energy and to shape the time profile of distal motion. The regulated motion is transmitted to the distal mechanism via output cable (13), which may route through Bowden sheaths or low-friction guides to the limb or end-effector. In variants omitting the potential store or damper, motion from (4) may be transmitted directly toward (13) when clamp (5) is released. In indexing variants, a single actuator, such as a servo-driven cam or disc, addresses one gate at a time by mechanically pulling on a local actuation wire or by directly pressing a brake or lever integrated with clamp (5); in dedicated-actuator variants, each gate's clamp (5) is driven by its own lightweight actuator such as a coreless motor or shape-memory alloy element. Figures are organized as follows: FIGS. 5A to 5E depict a representative gate module on base (100) showing elements (1), (2), (3), (4), (5), (10), (11), (12), (12a), (12b), (13), (13a), and (13b) and their cable routings; FIG. 5F details an example braking or clamping mechanism corresponding to element (5); FIG. 5G details the elastic-composite construction of elements (12) with ends (12a), (12b) and the analogous construction for element (13) with ends (13a), (13b).

### Detailed Description of Illustrative Embodiments

In one embodiment, the system may comprise an input actuation cable (1) that is configured to transmit a pulling force to an input-to-intermediate cable splitting pulley (2). This pulley may redirect the incoming force, possibly in a cascading pulley configuration, into two or more branches of intermediate output cables (3). These cables may be routed toward a primary dual-groove spool with flywheel (4), which could serve as a rotary interface between linear input motion and downstream actuation elements.

The primary spool (4) may be mechanically and continuously coupled to a rotational energy dissipation unit (10) via a secondary dual-groove spool (11), wherein the coupling may include an elastic energy transmission member (12). The rotational energy dissipation unit (10) may be configured to resist or modulate rotation of spool (11), thereby dissipating mechanical energy during periods of dynamic loading.

The ability of the primary spool (4) to rotate—and thereby allow motion from the intermediate cable (3) to influence the elastic element (12)—may be governed by an electromechanical clamp assembly (5). When disengaged, the clamp may permit the spool to rotate, enabling adjustment of the elastic tension via movement of the intermediate cable. When engaged, the clamp may inhibit rotation, thereby maintaining the current elastic tension.

In some implementations, the stored elastic tension may act in mechanical opposition to a constant counter-tensionapplied by an end-effector, joint, or limb, as may be found in a cable-driven robotic system. If the stored elastic tension exceeds this counter-tension, the rotational energy dissipation unit (10) may permit contraction of the elastic element, resulting in motion of the coupled output. Conversely, if the counter-tension dominates, the motion may be restricted or reversed. This configuration may enable temporal buffering and time-sliced actuation, in which a single actuation input is used to incrementally update the tension of multiple elastic elements over time. The resulting mechanical states may be resolved in parallel based on threshold tension levels or damped response profiles, such that multiple end-effectors or joints are actuated indirectly and asynchronously, possibly without requiring direct simultaneous input.

In this way, the system may support distributed mechanical coordination using minimal actuation channels, and could be particularly suitable for applications in cable-driven robotics, soft robotic limbs, multiplexed actuators, or passive motion control mechanisms.

In some embodiments, the elastic energy transmission member (12) may comprise an elongate elastic section flanked by non-elastic terminal segments (12a, 12b), such as braided fishing wire, kevlar thread, or similar high-tensile cord. These non-stretch segments may facilitate reliable attachment to the wire anchors or tie points located on the primary spool (4) and the secondary spool (11), enabling secure mechanical coupling without risk of creep or slippage under tension. The central elastic portion (12) may be formed from a stretchable material such as rubber, silicone, or polymeric elastomers, while the terminal segments (12a, 12b) may be mechanically crimped, knotted, or adhesively bonded to the elastic core. This hybrid structure allows the elastic member to maintain consistent dynamic properties while simplifying integration with grooved spools or quick-release attachment mechanisms.

In some embodiments, the elastic energy transmission member (12) may comprise a hybrid structure formed by a central stretchable segment (12) bounded by non-elastic terminal segments (12a, 12b). The stretchable portion may consist of an elastomeric material such as rubber, silicone, or a resilient polymer, while the terminal segments may be fabricated from low-stretch, high-tensile materials such as fishing line, aramid fiber, or braided steel. These non-elastic ends (12a, 12b) may facilitate robust anchoring to the wire attachment points on the primary spool (4) and the secondary spool (11), providing precise mechanical coupling without slippage.

Similarly, the output cable (13) may also be realized as a composite element comprising a central elastic segment (13) with non-stretchable ends (13a, 13b), which may be anchored to downstream robotic components or guiding hardware. This configuration allows the robotic limb or end-effector to exhibit bidirectional compliance, as both the pulling and returning motions may be influenced by the elasticity of the cable itself. The non-elastic terminal sections (13a, 13b) may serve to maintain positional stability at attachment points, while the central elastic segment (13) introduces passive flexibility and impact tolerance.

By integrating elasticity into both the energy storage path and the output linkage, the system may accommodate soft, compliant motion in both actuation and retraction directions, which may be advantageous in robotic systems that interact with delicate objects, adapt to variable loads, or require shock absorption during operation.

The mechanism may be configured to convert simple, discrete actuation inputs-such as a tug on a cable-into smooth, delayed, or buffered motion, which could be particularly advantageous for controlling limbs or joints in soft robotic or cable-driven systems. In one embodiment, an input cable may provide the primary actuation force, which may be routed through a motion splitter that divides and redirects the input into multiple intermediate output cables. These outputs could then be directed to different subsystems or degrees of freedom, either sequentially or in parallel. Before motion is transmitted further downstream, it may pass through a selective locking mechanism-such as a motor-actuated clamp-which may be engaged to inhibit motion or released to permit it. This clamp may act as a gating mechanism, selectively allowing or blocking motion transmission depending on control logic.

When disengaged, the clamp may permit motion to be transferred into an elastic member, such as a spring or rubber element, which may be configured to store potential energy. This elastic component could serve as a temporary buffer or motion accumulator, capable of releasing the stored energy gradually or at a later time. The energy stored in the elastic member may then pass through a rotational damping element, which could be configured to slow or regulate the release, thereby transforming a fast input into a controlled and gradual output motion. In some embodiments, the output cable-coupling the mechanism to a limb, joint, or end-effector—may also include an elastic section. This additional compliance may allow the output structure to flex in both actuation and return directions, potentially improving shock absorption, adaptability to external forces, and mechanical safety.

Through this architecture, discrete cable inputs may be mapped to time-buffered mechanical outputs, enabling a small number of lightweight actuators to coordinate complex, distributed motion across multiple joints or limbs.

In one conceptual representation, the downstream mechanical path of the system may be described as a sequence of functional stages: Input→Intermediate→Gate→Potential Store→Delayed Motion→Compliant Output. An input force-typically delivered via a cable—may first be routed through intermediate structures such as pulleys or splitters that distribute or redirect the actuation. The resulting intermediate motion may then pass through a selectively actuated gate, such as a motorized clamp, which may be engaged or released to control whether motion proceeds further downstream. When the gate is opened, motion may be transmitted into a potential store, for example an elastic element, which may temporarily retain energy as strain. This stored energy may then pass through a motion delay mechanism, such as a rotary damper, which could regulate the release of energy to produce a gradual, time-buffered mechanical response. The resulting motion may be delivered to a compliant output, such as a limb, joint, or end-effector, which may itself incorporate elastic elements for bidirectional flexibility and passive interaction.

In some embodiments, the potential store and time delay mechanisms may be omitted, resulting in a more direct transmission of force from input to output. While this simplified configuration may reduce complexity, it may also limit the system's ability to coordinate parallel motion across multiple limbs, effectively allowing only one degree of freedom to move at a time. In contrast, inclusion of elastic buffering and delayed release may enable time-multiplexed control, whereby a single actuator may sequentially set energy states across multiple outputs, which then resolve into continuous or overlapping motion.

The gate stage may be implemented using a wide variety of mechanisms configured to selectively enable or disable the transmission of motion or force. In some embodiments, a motor-actuated friction clamp may be used to press against a rotating shaft or pulley, thereby arresting movement when activated. Alternatively, a solenoid-operated pin-lock or brake could insert a locking element into a detent or slot to hold a component in place. In certain cases, a ratcheting mechanism with an escapement release may permit motion in discrete steps and provide mechanical locking between updates. A magnetic clutch might be employed to selectively engage or disengage rotary elements via controllable magnetic coupling. In other variants, a bi-stable snap-action cam lever may be used to toggle between locked and released states using minimal actuation energy. A servo or micro-motor could be configured to pull a wedge, band brake, or compression collar that physically restrains motion by frictional or mechanical interference. In some lightweight or compact designs, a shape-memory alloy wire, such as nitinol, may contract upon heating to actuate a clamp or lock. Additional implementations may rely on electrostatic, pneumatic, or magnetic braking systems, each of which could apply force-based resistance to motion without requiring direct mechanical contact. In further embodiments, the gate function may be achieved by modulating the viscosity or yield strength of a fluid using electrorheological or magnetorheological effects, allowing for smooth and variable engagement. These mechanisms may be selected based on criteria such as speed of actuation, energy efficiency, physical footprint, or compatibility with digital control systems. The gate may function as a binary on/off device or as a proportional controller, and may in some cases be operated passively or triggered by conditions within the system.

In some embodiments, a single actuator may be configured to selectively open one of multiple motion gates, thereby allowing sequential or addressable control over a set of downstream elements. For example, a servo motor may rotate to discrete angular positions, each corresponding to the mechanical engagement or release of a particular gate. In such a configuration, the actuator may drive a rotary indexing arm, cam disc, or sliding linkage, which in turn selectively actuates one gate at a time while the others remain locked. This form of mechanical multiplexing may significantly reduce the total number of actuators required to control multiple limbs, joints, or elastic buffers, enabling a compact and low-cost design. The indexing behavior may be time-synchronized with the input actuation signal, allowing one gate to be opened just prior to motion input, and closed again before the next is addressed. This approach could allow a single input force-when combined with fast gating and buffering—to update the state of multiple elastic elements in succession, each of which may subsequently produce delayed and overlapping output motion. Such a mechanism may be particularly advantageous in systems where weight, cost, or wiring complexity must be minimized, and where fine-grained real-time coordination is not strictly necessary.

In one practical implementation, an embodiment of the system may be constructed using lightweight, modular components and standard fabrication techniques. Each motion gate may be actuated either by its own dedicated coreless motor, selected for its minimal weight and low inertia, or, in alternative embodiments, a single gate-selector servo may be used to mechanically engage one gate at a time through an indexed cam or rotary selector. The motion gates themselves may consist of 3D-printed clamps or locking mechanisms, mechanically interfaced with 3D-printed rotary spools or wheels, which form the primary and secondary motion transmission components. These elements may be mounted onto a shared support structure or base (100), which can be additively manufactured for lightweight integration. Fishing wire, braided polymer cord, or similar high-tensile lines may be used to form the actuation and intermediate cables, while rubber bands, elastic cords, or silicone tubing may serve as the elastic potential energy storage elements. The rotational dampers used to retard the motion output may include low-cost, compact, commercially available viscous dampers, which are readily obtainable through online suppliers. An input servo motor may provide discrete actuation pulses by pulling on a primary cable, thereby enabling stored energy to be selectively distributed and time-buffered across the system. This construction may allow the creation of a low-cost, distributed robotic system in which multiple limbs or joints are passively coordinated using minimal electronics, lightweight components, and off-the-shelf hardware.

The resulting cable-actuated robotic system, equipped with a lightweight motion multiplexer as described herein, may be controlled by a computational controller configured to receive inputs from a variety of sensors, including but not limited to camera-based imaging of the robot's environment. In one embodiment, a camera or vision system may be positioned to observe the physical state of the robot's elastic elements, including both the energy-storing components and any optional compliant elastic outputs, thereby allowing the controller to infer the internal state of stored or pending motions.

This form of observation may enable a form of visual proprioception, wherein the robot perceives its own potential actuation states through image analysis rather than embedded sensors. Based on this input, the controller may select which motion gate to activate, determine the magnitude and timing of cable pulls, and coordinate multiple degrees of freedom using predictive models. The vision system may further be used to track limb positions, assess environmental interactions, or synchronize the robot's actions with external events. This configuration may allow the robot to respond adaptively to unstructured environments, while maintaining extremely low onboard complexity through centralized sensing and minimal actuator count.

It is further noted that the described cable-actuated, multiplexed robotic system may serve as a foundation for a class of slower-moving, persistent-operation robots. In one particularly interesting embodiment, the system may be implemented in a multi-limbed platform, such as a hexapod robot, where the centralized multiplexer and computational controller are housed in the main body or thorax section. The actuators, energy storage, and decision logic may be concentrated within this central unit, while the limbs may be constructed using extremely lightweight, passive structures, made possible by the offloaded actuation and control burden. This architectural approach may allow for larger-scale robots that are nevertheless cheap, safe to operate around humans, and capable of navigating irregular or complex terrain.

In some variants, the core unit may include an onboard solar panel or alternative energy harvesting system, enabling long-term or semi-autonomous deployment in outdoor environments. This configuration may be particularly advantageous in slow-changing or biologically driven problem spaces, where speed is less important than endurance and reliability. For example, tasks such as weed suppression, insect detection or elimination, lawn maintenance, localized pollination, debris collection, or environmental cleanup may all benefit from a continuously operating robot that works quietly and safely over extended periods.

Because the multiplexing architecture minimizes actuator count and reduces the mechanical burden per limb, these robots may scale in size and reach without a proportional increase in cost or complexity. This makes the system well-suited for agricultural, ecological, and domestic applications where large areas must be monitored or influenced over time, but the urgency of response is low. Such robots may act as autonomous ecosystem assistants, performing low-intensity but high-coverage operations with minimal supervision or infrastructure.

Another compelling application of the described multiplexed cable-actuation architecture lies in aerial robotic systems, particularly flying platforms equipped with articulated arms or complex end-effectors. In one such embodiment, the system may be integrated into a drone-mounted robotic arm, where the centralized multiplexing unit is housed within the drone's main body, and force is transmitted remotely via cables. This approach aligns with existing strategies-such as those disclosed in a pending patent by the present inventor—where cable-driven actuation is used to relocate mass toward the drone's center of gravity, thereby improving flight stability. However, the current invention enables a significant further step: the ability to scale to high degrees of freedom without requiring a one-to-one ratio of actuators to joints.

By introducing a lightweight motion multiplexer, multiple joints or compliant elements may be selectively controlled using a single high-power input actuator, coupled with either a set of lightweight gate actuators or a gate selector mechanism. This allows each degree of freedom to receive significant force-sourced from a powerful centralized actuator-without the weight penalty typically associated with onboard motors for each joint. As a result, robotic arms or end-effectors mounted on flying platforms may exhibit both increased mechanical strength and substantial weight reduction, enabling longer flight times, increased payload capacity, and more complex manipulation tasks in the air. This architecture may be especially well suited for precision agriculture, aerial repair or inspection, targeted delivery, and autonomous in-field manipulation, where dexterity and reach are important but minimizing actuator count and distributing load efficiently are critical to overall system performance.

In some embodiments, the multiplexed actuation system described herein may be integrated into multi-limbed robotic platforms, such as hexapods, quadrupeds, or aerial manipulators. Each limb or joint may be actuated using a cable-driven mechanism of conventional design, wherein motion is transmitted from a central body to distal joints via routed tension elements, pulleys, or tendon-like cables. The cable-driven limbs themselves are not considered part of the present invention, and may be constructed using methods well established in the field of robotics. Rather, the novelty resides in the use of a centralized motion multiplexer, capable of selectively controlling multiple output paths through timed gating, elastic energy buffering, and delayed release. This allows a single input actuator to sequentially modify the actuation state of multiple limbs or joints, enabling complex coordinated motion using a reduced number of actuators. The central placement of the multiplexer-within the robot's body or thorax section—may allow the limbs to be constructed with minimal onboard actuation hardware, resulting in a system that is lightweight, energy-efficient, and scalable, while preserving the ability to perform distributed motion across a high number of degrees of freedom.

MONETIZATION AND DAMAGES CONSIDERATIONS: In certain embodiments, the robotic system may be configured to support subscription-based or usage-based monetization models. A computational controller may execute access-control logic that enables or disables subsets of motion gates, degrees of freedom, or performance tiers according to a valid license, subscription term, or usage allocation. The controller may store licensing data in non-volatile memory, including device identifiers, cryptographic keys, counters, and signed entitlements, and may authenticate licenses using symmetric or asymmetric cryptography. In some variants, the system may implement time-based subscriptions, wherein a secure time source or monotonic counter is used to determine validity periods, and may further implement usage-based licensing in which actuation events, gate-open durations, energy delivered to elastic elements, or cumulative cable travel are counted locally and compared against purchased quotas. The controller may communicate with remote servers over wired or wireless links to obtain licenses, renew subscriptions, or upload usage records. When connectivity is intermittent, the system may cache signed offline tokens that provision a defined number of actuation cycles or a time window of operation, after which gates may automatically revert to a restricted state until renewal. Enforcement may be applied at multiple layers, including at the input actuator scheduling stage, within the gate-selector indexing mechanism, and at individual gate clamps by withholding enable signals or increasing braking torque to a default-locked state in the absence of authorization. To support auditability and damages calculations, the system may maintain an append-only usage log that records timestamps, gate identifiers, actuation magnitudes, durations, error states, and environmental context hashes derived from sensor input. The log may be periodically sealed with cryptographic signatures to prevent tampering and may be exportable for forensic analysis. In some embodiments, the system may include telemetry reporting that summarizes monthly active gates, total actuation energy, and duty cycles per gate. These features may enable subscription or pay-per-use billing models (for example, per enabled gate, per actuation, per unit of delivered elastic energy, or per operating hour) and may support quantification of economic harm in the event of unauthorized use. The monetization logic may be implemented in firmware or software executing on the controller associated with the multiplexer, and may optionally leverage secure elements, trusted execution environments, or encrypted storage to protect license material. These capabilities may extend to fleet management, where a central service provisions licenses across multiple robots, defines geofenced operating zones, and sets policy for maintenance windows or maximum allowable actuation rates to manage wear. All monetization features may be optional and may be enabled, disabled, or updated in the field without mechanical modification, preserving the mechanical architecture while providing a pathway for recurring revenue and enhanced remedies for infringement.

EXTERNAL OBSERVABILITY: For systems in which internal components are not readily accessible, the multiplexed architecture may be identified and verified through externally observable behaviors without disassembly. In one approach, an observer may measure displacement or tension of the input cable (1) at the multiplexer base (100) while simultaneously recording distal joint motion with a camera or motion capture markers. When a single actuation pull is applied to the input cable while only one gate's clamp (5) is released, the selected distal joint may continue to move after the input cable returns to neutral, with a decay profile governed by the corresponding damper (10). This delayed continuation of motion despite zero input-cable travel may indicate the presence of an elastic store (12) and a rotary damper (10) on the addressed path. When the clamp (5) is re-engaged and an external load is applied to the distal joint, the joint may hold or creep only within a bounded compliance range characteristic of the damper and elastic coupling, distinguishing the behavior from direct-drive actuation. In indexing variants, rotation of a visible cam or selector linked to the multiplexer may correlate with which distal joint exhibits delayed motion following the next input pull, producing a repeatable mapping between indexer position and the addressed output cable (13). In dedicated-actuator gate variants, externally applied enable signals or audible actuator cues may coincide with which joint shows the delayed response, even when the input cable pull magnitude remains constant. Over a time window in which several short input pulls are applied while different gates are sequentially released, multiple distal joints may exhibit overlapping, smoothed motion trajectories that outlast the input pulses; the ratio of input-pull events to concurrently moving joints may exceed one, evidencing time-sliced actuation with buffered release. Where accessible, inline force sensors or temporary clamp-on tension gauges placed on output cables (13) may show rising tension while the associated distal joint momentarily remains stationary during the preload phase, followed by tension decay during the damped release phase after the gate is re-closed. These externally measurable signatures provide objective criteria for identifying infringement through field observation, including the presence of centralized gating, elastic preloading, and delayed, damper-shaped motion delivered to distal joints from a single input cable.

INTEROPERABILITY AND PLATFORM COMPATIBILITY: The multiplexed actuation system may interoperate with a wide range of mechanical, electrical, and software environments so that interface variations do not avoid the inventive concepts. On the mechanical side, the motion paths may employ round cables, flat belts, tapes, straps, chains, or hybrid tension elements routed over pulleys, rollers, tongues, sprockets, or low-friction guides, and may be housed in Bowden sheaths, conduit tubes, or flex channels of varying diameters and materials while preserving selective gating and centralized mass advantages. Gate mechanisms may couple to clamps, brakes, ratchets, magnetic particle brakes, or eddy-current brakes using adapters that allow drop—in substitution without changing the routing topology or centralized gating behavior. Input actuators may include brushed DC motors, BLDC motors, servos, steppers, hydraulic or pneumatic sources with cable transduction stages, or human-powered inputs, each presenting compatible line pull or torque to the shared tension bus or single input element. On the electrical and control side, the controller that schedules input pulls and gate states may interface through analog voltage or current loops, PWM, UART, I2C, SPI, CAN, RS-485, or Ethernet-based protocols including EtherCAT, and may be integrated with higher-level frameworks such as ROS or ROS 2, MAVLink-based flight controllers, or proprietary supervisory systems without altering the underlying gated routing, elastic buffering, or delayed release behaviors. Sensor feedback may be obtained from tension sensors, encoders, potentiometers, Hall-effect devices, or vision systems, with interchangeable calibration models so that sensing modality changes do not affect the multiplexing principles. Power delivery may be provided from battery packs, tethered supplies, or energy-harvesting modules and regulated through common DC bus architectures or isolated converters, with default-locked gate designs maintaining safe states across power-loss conditions. Software that implements scheduling, indexing, licensing, or telemetry may execute on microcontrollers or single-board computers and may communicate over Wi-Fi, Bluetooth, cellular, or wired links using HTTPS or other secure transports; changes in transport or message schema may be accommodated via adapters while preserving the externally observable time-sliced actuation and delayed-motion signatures. Functionally equivalent realizations that employ fluidic or pneumatic transmissions may also embody the inventive concept. In such variants, a shared pressure bus from one or more pumps serves as the input, selector valves serve as motion gates, accumulators or compliant hoses provide the elastic potential store, and flow restrictors, orifices, or fluid dampers provide the delayed release; the centralized selector presents the same externally observable time-sliced, delayed-motion signatures and centralized mass advantages. Likewise, rigid push-pull or pushrod linkages routed through bellcranks or sliders may be addressed by the same gating and buffering stages by substituting clutches or brakes for clamps on rotary or linear carriers; interface substitutions of this type may not avoid the centralized gating, buffering, and delayed release architecture.

FALLBACK EMBODIMENTS: The inventive concept may be realized in simpler or partial implementations that maintain the core idea of centralized, selectively gated routing from a single input while omitting or simplifying certain subsystems. In one fallback embodiment, the elastic energy storage element (12) and the rotational damper (10) may be omitted entirely so that, when clamp (5) is released, motion from primary spool (4) is transmitted directly toward output cable (13). This configuration may provide immediate, gated force transmission with centralized actuation and reduced onboard actuator count, preserving key benefits where delayed release is unnecessary. In another fallback embodiment, only one of the potential store or the damper may be present. For example, a unidirectional ratchet with a passive spring return may replace the damper to permit stepwise advancement and hold without continuous braking, or a fixed-friction pack or felt pad may substitute for a viscous damper to provide crude but sufficient metering in low-cost builds. In a further fallback embodiment, the input-to-intermediate splitter pulley (2) may be replaced by a single, non-split path so that the motion multiplexer addresses only one gate module at a time while still enabling centralized placement on base (100) and selective gating to a chosen distal cable; additional gates can be added later without redesign of the core. In yet another fallback embodiment, the gate-selector function may be purely mechanical and manual, such as a hand-operated cam or lever that depresses one clamp (5) at a time, allowing bench-top tools or low-infrastructure field devices to benefit from the same multiplexed routing without electronics. In some cases, the elastic element may be moved to the output cable (13) only, with a non-elastic coupling between spools (4) and (11), so that bidirectional compliance is retained at the limb while the gate module remains mechanically simple. In compact or ruggedized implementations, the base (100) and spools may be formed from off-the-shelf bicycle brake hardware, with clamp (5) realized as a cable pinch or band brake and damper (10) realized as a simple dashpot or grease-packed bushing. A default-locked clamp (5) with a mechanical over-center latch may be used so that, absent any actuator power, the system safely holds state; release may be by gravity-assisted cam, shape-memory alloy wire, or a short manual tug on an actuation wire. In a further variant, two or more input actuators may contribute to a common tension bus through summing pulleys, differential pulleys, or one-way clutch combiners so that the multiplexer still addresses multiple outputs from a centralized bus while permitting redundancy, hot-swapping, or blended contribution from inputs; this maintains centralized gating advantages and makes avoidance through mere duplication of inputs less effective.

These variations of the cam-based indexing mechanism enable low-power, low-complexity, and mechanically robust control of a set of clamps using only a single actuator, without requiring a dedicated motor or electronic controller for each individual gate. By acting either through wire pulling, direct clamp engagement, or direct braking of a spool, the system enables a compact, scalable, and lightweight solution for multiplexed actuation. This is particularly valuable in robotic applications such as UAV-mounted manipulators, multi-limbed walking robots, or distributed cable-driven systems, where centralization of control and minimization of mass are critical. The embodiments may be described by the following itemized list: For avoidance of doubt and to support continuation filings, each of claims 1 through 20 is mirrored by a corresponding entry in this itemized list. Specifically, claim 1 corresponds to item 1 in view of item 21, claim 2 corresponds to item 2, claim 3 corresponds to item 3, claim 4 corresponds to item 4, and claims 5 through 20 correspond respectively to items 5 through 20. Items 21 through 26 provide additional embodiments, options, and alternatives for future continuations that may be claimed without altering the disclosures of items 1 through 20. 1. A robotic actuation system, the system comprising: (a) one or more control cables configured to transmit actuation force; and (b) a motion multiplexer comprising a set of selectively actuated motion gates, the motion multiplexer being configured to receive actuation input from a single input tension element and to selectively route said actuation to multiple downstream output paths, each coupled to a corresponding control cable. 2. A method of multiplexed cable-driven actuation for a limb, arm, or end-effector mounted on an unmanned aerial vehicle or multi-limbed robot, the method comprising: receiving actuation input from a single input tension element at a motion multiplexer having a plurality of selectively actuated motion gates; opening a selected one of the motion gates; routing the actuation through the opened motion gate to preload an elastic energy storage element coupled to a corresponding output path; and releasing energy from the elastic energy storage element through a rotational damper to drive distal motion along an output cable after the selected motion gate is closed. 3. A gate module for a multiplexed cable-driven actuation system, the gate module comprising: a primary spool configured to receive motion from an intermediate tension element; a clamp assembly configured to selectively arrest rotation of the primary spool; an elastic energy transmission member coupled between the primary spool and a secondary spool; a rotational damper coupled to the secondary spool; and an output cable configured to transmit regulated motion toward a distal mechanism; the gate module being mountable to a shared base within a motion multiplexer. 4. A non-transitory computer-readable medium storing instructions that, when executed by a controller of a motion multiplexer configured to receive actuation input from a single input tension element, cause the controller to: select motion gates to open based on a schedule or sensed state; command an input actuator to apply pulls while a selected motion gate is open to preload an elastic energy storage element coupled to a corresponding output path; close the selected motion gate and open another motion gate to preload a different elastic energy storage element; and regulate or command gate states to hold position or meter release, optionally enforcing licensed access to subsets of motion gates or performance tiers. 5. The system of item 1, further comprising a plurality of elastic energy storage elements each coupled to a respective output path and one or more rotational dampers, wherein the motion multiplexer is centrally located within a body of the UAV or robot and wherein actuation is performed through time-sliced updates that sequentially preload said elastic energy storage elements and resolve motion in parallel through damping. 6. The system of item 1, wherein the input tension element may be cascade-split using a pulley system, such that the input actuation force is divided into two or more intermediate cable branches routed to different motion gates of the multiplexer. 7. The system of item 1, wherein the end-effector may be configured to perform one or more of the following functions: cutting leaves; electrocuting insects; layering or sorting insects or small objects; displacing foliage to expose the underside of leaves; and grasping, picking up, and depositing objects. 8. The system of item 1, wherein the motion multiplexer may comprise a single actuator configured to selectively open one gate at a time, such that only one downstream output path is enabled during a given actuation cycle. 9. The system of item 1, wherein each motion gate of the multiplexer may be actuated by a dedicated actuator, such that a separate actuator is provided for each gate to enable or disable motion transfer to its corresponding output path. 10. The system of item 1, wherein the actuators for the motion gates may comprise lightweight coreless motors or shape-memory alloy elements. 11. The system of item 1, wherein the actuation system may be controlled by a computational controller configured to receive environmental data from one or more cameras, and wherein the cameras are further configured to observe the state of elastic elements to infer the internal actuation state of the robot. 12. The system of item 1, wherein the robot may be configured for slow and continuous operation over agricultural terrain, and adapted for tasks such as weed suppression, insect targeting, localized pollination, environmental sampling, debris removal, lawn maintenance, hedge cutting, or cleaning. 13. The system of item 1, wherein the robot may comprise a solar panel mounted on its central body to enable autonomous or semi-autonomous operation over extended durations in outdoor environments. 14. The system of item 1, wherein the motion multiplexer may be integrated into the central body of a hexapod robot and configured to distribute actuation to a plurality of lightweight limbs, allowing coordinated locomotion with reduced onboard actuator count. 15. The system of item 1, wherein the elastic energy storage elements may comprise central stretchable segments with non-stretchable end portions, configured to facilitate secure anchoring to spools or clamps. 16. The system of item 1, wherein the output cables may comprise central elastic segments with non-stretchable end segments, allowing the limb or end-effector to remain compliant in both actuation and return directions. 17. The system of item 1, wherein the motion multiplexer may comprise 3D-printed clamps and spools mounted on a 3D-printed base structure. 18. The system of item 1, wherein the rotational dampers may be selected from commercially available viscous or magnetic damping devices configured to regulate mechanical energy release. 19. The system of item 1, wherein the robotic arm or limb may be mounted on an aerial platform, and the multiplexed actuation architecture is configured to reduce peripheral mass and to centralize actuation forces near the platform's center of gravity. 20. The system of item 1, wherein each motion gate may further comprise a friction clamp, pin-lock, magnetic brake, or servo-actuated engagement mechanism, and wherein the control cables may be routed through Bowden sheaths or low-friction guides to minimize mechanical losses between the multiplexer and the distal actuated components. 21. A motion multiplexer according to any of items 1 through 20, wherein two or more input tension elements are combined into a shared tension bus via a summing pulley, differential pulley, torque-summing shaft, or one-way clutch combiner, the shared tension bus presenting an effective single input to the motion gates at a given update window. 22. The system of item 21, wherein the combiner provides redundancy or failover such that loss of one input does not disable the shared bus, and wherein selective gating to multiple downstream output paths is maintained without relocating actuators onto distal links. 23. The system of item 1, wherein a tension element comprises a belt, tape, strap, or chain and is routed over rollers, tongues, sprockets, or low-friction guides in lieu of a round cable and pulley, while preserving selective gating and centralized mass benefits. 24. The system of item 1, wherein a gate function is disposed in an output path proximate to a distal mechanism using a ratchet, pawl, overrunning clutch, magnetic particle brake, or eddy-current brake, while a centralized shared tension bus supplies actuation energy that is selectively admitted by said distal gate. 25. The method of item 2, further comprising cross-fading between plural input actuators by modulating a combiner ratio while maintaining gate selection so as to avoid torque discontinuities on the shared tension bus and to enable hot-swapping of input sources. 26. The system of item 1, further comprising an energy bus that accumulates input work in a flywheel, torsion spring, or other accumulator coupled by a cable-to-rotary transduction stage before selective gating to outputs, thereby decoupling input actuator dynamics from distal motion. 27. The system of item 1, wherein each motion gate is default-locked in the absence of power using an over-center latch or bias spring that maintains a safe hold state until an explicit release is commanded. 28. The system of item 1, wherein a gate-selector mechanism is purely mechanical and manually operated via a lever, knob, or cam to address one gate at a time without electronics or distributed wiring. 29. The system of item 1, wherein a gate comprises a magnetorheological or electrorheological fluid brake providing proportional engagement under control signals or preset conditions. 30. The system of item 1, wherein push-pull operation is achieved using paired tension elements routed in opposite directions so that positive actuation and return are both selectively gated by the multiplexer. 31. The method of item 2, further comprising re-engaging a clamp to interrupt release mid-trajectory to hold a pose against disturbances, and subsequently reopening to resume damped motion without re-preloading the elastic element. 32. The system of item 1, wherein bidirectional compliance is provided solely in the output cable while a non-elastic coupling is used between the primary and secondary spools, thereby retaining shock absorption at the limb while simplifying the gate module. 33. The system of item 1, wherein the multiplexer is retrofitted as an inline adapter between an existing actuator and multiple legacy outputs using adapter brackets and unchanged distal hardware, thereby preventing interface changes from avoiding the centralized gating architecture. 34. The system of item 1, wherein a fluidic or pneumatic pressure bus is used as an input source and selector valves act as motion gates, with a compliant accumulator and a flow restrictor corresponding respectively to the elastic energy storage element and the rotational damper so as to produce delayed, metered distal motion. 35. The system of item 1, wherein a rigid pushrod or push-pull linkage transmits actuation through bellcranks or sliders and the gate comprises a clutch or brake acting on a rotary or linear carrier, the linkage being addressed by a centralized selector to time-slice actuation among multiple outputs while preserving delayed release by an energy store and a damping element. 36. The system of item 1, wherein the selector topology comprises a multi-stage or crossbar arrangement of gates configured to realize one-to-many, many-to-one, or many-to-many selective coupling between a shared energy source and multiple output paths within an update window. 37. The system of item 1, wherein two or more motion gates are proportionally engaged to admit a controlled fraction of input energy to multiple output paths concurrently while each output path includes its own energy store or impedance element that meters or delays motion. 38. The system of item 1, wherein a gate comprises a deliberately slipping or torque-limited coupler that provides controlled leakage when nominally closed to maintain preload or to meter admission without full release. 39. The system of item 1, wherein gates are placed in series along an output path and any one gate suffices to inhibit motion so that relocating or duplicating gate positions along the path does not avoid selective gating from a shared input. 40. The system of item 1, wherein an array of micro-gates is addressed by a mechanical selector including a cam, Geneva mechanism, or ratcheting indexer that sequentially or selectively reduces impedance at targeted gates without distributed wiring.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A robotic actuation system, the system comprising: (a) one or more flexible tensile transmission members configured to transmit actuation force; and (b) a motion multiplexer comprising a set of selectively actuated motion gates, the motion multiplexer being configured to receive actuation input from a single input tension element or from a shared tension bus that presents an effective single input by combining two or more input tension elements, and to selectively route said actuation to multiple downstream output paths, each coupled to a corresponding flexible tensile transmission member.

A method of multiplexed cable-driven actuation for a limb, arm, or end-effector mounted on an unmanned aerial vehicle or multi-limbed robot, the method comprising: receiving actuation input from a single input tension element at a motion multiplexer having a plurality of selectively actuated motion gates; opening a selected one of the motion gates; routing the actuation through the opened motion gate to preload an elastic energy storage element coupled to a corresponding output path; and releasing energy from the elastic energy storage element through a rotational damper to drive distal motion along an output cable after the selected motion gate is closed.

A gate module for a multiplexed cable-driven actuation system, the gate module comprising: a primary spool configured to receive motion from an intermediate tension element; a clamp assembly configured to selectively arrest rotation of the primary spool; an elastic energy transmission member coupled between the primary spool and a secondary spool; a rotational damper coupled to the secondary spool; and an output cable configured to transmit regulated motion toward a distal mechanism; the gate module being mountable to a shared base within a motion multiplexer.

A non-transitory computer-readable medium storing instructions that, when executed by a controller of a motion multiplexer configured to receive actuation input from a single input tension element, cause the controller to: select motion gates to open based on a schedule or sensed state; command an input actuator to apply pulls while a selected motion gate is open to preload an elastic energy storage element coupled to a corresponding output path; close the selected motion gate and open another motion gate to preload a different elastic energy storage element; and regulate or command gate states to hold position or meter release, optionally enforcing licensed access to subsets of motion gates or performance tiers.

The system of item 1, further comprising a plurality of elastic energy storage elements each coupled to a respective output path and one or more rotational dampers, wherein the motion multiplexer is centrally located within a body of the unmanned aerial vehicle or robot and wherein actuation is performed through time-sliced updates that sequentially preload said elastic energy storage elements and resolve motion in parallel through damping.

The system of item 1, wherein the single input tension element is cascade-split using a pulley system such that actuation force is divided into two or more intermediate cable branches routed to different motion gates of the motion multiplexer.

The system of item 1, wherein the end-effector is configured to perform one or more of cutting leaves, electrocuting insects, layering or sorting insects or small objects, displacing foliage to expose undersides of leaves, and grasping, picking up, and depositing objects.

The system of item 1, wherein the motion multiplexer comprises a single actuator configured to selectively open one motion gate at a time such that only one downstream output path is enabled during a given actuation cycle.

The system of item 1, wherein each motion gate of the motion multiplexer is actuated by a dedicated actuator to enable or disable motion transfer to its corresponding output path.

The system of item 1, wherein the actuators for the motion gates comprise lightweight coreless motors or shape-memory alloy elements.

The system of item 1, further comprising a computational controller configured to receive environmental data from one or more cameras, the cameras being further configured to observe states of elastic elements to infer an internal actuation state of the robot.

The system of item 1, wherein the robot is configured for slow and continuous operation over agricultural terrain and adapted for tasks including weed suppression, insect targeting, localized pollination, environmental sampling, debris removal, lawn maintenance, hedge cutting, or cleaning.

The system of item 1, wherein the robot comprises a solar panel mounted on its central body to enable autonomous or semi-autonomous operation over extended durations in outdoor environments.

The system of item 1, wherein the motion multiplexer is integrated into a central body of a hexapod robot and is configured to distribute actuation to a plurality of lightweight limbs, allowing coordinated locomotion with reduced onboard actuator count.

The system of item 1, wherein elastic energy storage elements comprise central stretchable segments with non-stretchable end portions configured to facilitate secure anchoring to spools or clamps.

The system of item 1, wherein output cables comprise central elastic segments with non-stretchable end segments allowing a limb or end-effector to remain compliant in both actuation and return directions.

The system of item 1, wherein the motion multiplexer comprises 3D-printed clamps and spools mounted on a 3D-printed base structure.

The system of item 1, wherein the rotational dampers are selected from commercially available viscous or magnetic damping devices configured to regulate mechanical energy release.

The system of item 1, wherein a limb or arm is mounted on an aerial platform and the multiplexed actuation architecture is configured to reduce peripheral mass and to centralize actuation forces near the platform's center of gravity.

The system of item 1, wherein each motion gate further comprises a friction clamp, pin-lock, magnetic brake, or servo-actuated engagement mechanism, and wherein the control cables are routed through Bowden sheaths or low-friction guides to minimize mechanical losses between the motion multiplexer and distal actuated components.

### Embodiment NE: Conditional Sugar Water Dispenser for Incentivized Ant-Based Object Retrieval

A programmable insect-interaction platform conditions ants or other insects to retrieve target objects by selectively granting access to a reward substance such as sugar water. One or more sensors, including cameras and non-imaging alternatives, observe a platform to detect insect presence, discriminate target species, and, in conditional mode, verify presentation of desired objects such as pest larvae, infected plant matter, or microplastics. A control unit actuates an access control mechanism, such as a servo-driven sugar stick wetted at a wick when raised, to grant or deny access at the platform. A hatch beneath the platform releases deposited items into a collection chamber. A reservoir access hatch and refill tube enable automated refilling by a robot or fixed tubing network. Telemetry, metering, and audit logs support subscription and damages models. The system may operate in unconditional or conditional modes and includes externally observable behaviors that evidence operation without internal inspection.

Gentle Introduction: Ants are naturally attracted to sugars and will repeatedly visit reliable sources. This disclosure may be understood intuitively as a small “vending station” for ants that chooses when to expose a tiny sip of sugar solution. During an initial training phase, the station may open access whenever ants are present to establish site fidelity. As conditioning progresses, the station may instead open access only when ants present a desired item such as a pest larva or contaminated plant fragment, thereby trading useful work for a brief reward. Access may be visibly presented by lowering an absorbent sugar stick into reach or by opening a small shutter to a wetted pad, after which access may close to avoid freeloading. Items left on the platform may be dropped through a hatch into a bin for later collection. A small reservoir may hold sugar solution and may be refilled by hand or by a robot through a simple port. Sensors and simple logic may watch the platform to decide when to open or keep closed, and because these decisions produce externally observable movements and outcomes, operation may be verified without opening the device. This intuitive picture frames the more detailed embodiments that follow and may be implemented with either imaging or non-imaging sensors and with alternative access mechanisms while preserving the same overall behavior.

Examples: A step-by-step walkthrough illustrates unconditional training. The station is placed near an active ant trail and configured in unconditional mode. The camera or a non-imaging presence sensor detects ants on the platform and the control unit opens access by lowering the wetted sugar stick for a fixed dwell such as ten seconds, then closes and enforces a lockout such as sixty seconds. This sequence repeats during a session, building site fidelity as ants recruit nestmates. An externally observable log entry may be created for each grant. A representative event record may include fields for timestamp, device identifier, decision, criteria, and actuator states in a compact, inline JSON such as

{“ts”:“2025-05-07T14:03:21Z”,“device”:“ANT-049”,“mode”:“unconditional”,“decision”:“grant”,“crite
ria”:{“species”:“Formica”,“object”:“none”,“conf”:0.82},“actuators”:{“stick”:“lowered”,“hatch”:“close
d”},“audit”:{“prev”:“b5f2...”,“hash”:“9a1c...”}}.

A conditional reward example proceeds as follows. Two ants arrive carrying a larva and place it on the platform. The camera and load cell detect insect presence and an object exceeding a threshold mass, and the classifier recognizes ant species and a larval object with confidence above a configured level. Within a set latency the control unit lowers the sugar stick, granting access for the dwell period. After consumption ends, the hatch remains closed until ants depart, then opens briefly to drop the larva into the collection container and closes flush. The metering system records the dispense and the hatch event and appends an audit-chained entry. An inline JSON example of this conditional case may read

{“ts”:“2025-05-07T15:11:02Z”,“device”:“ANT-049”,“mode”:“conditional”,“decision”:“grant”,“criteria
”:{“species”:“Lasius”,“object”:“larva”,“conf”:0.93,“mass_mg”:18},“actuators”:{“stick”:“lowered”,“hat
ch”:“opened_then_closed”},“audit”:{“prev”:“9a1c...”,“hash”:“0fed...”}}.

A non-target rejection example shows external observability of denial. A bee alights on the platform without a qualifying object. The discriminator flags a non-ant species and the reward criteria are not met. No movement of the access mechanism occurs beyond the normal monitoring posture, the hatch remains closed, and a denial event is logged. An inline denial record may be

{“ts”:“2025-05-07T15:20:45Z”,“device”:“ANT-049”,“mode”:“conditional”,“decision”:“deny”,“criteria
”:{“species”:“bee”,“object”:“none”,“conf”:0.96},“actuators”:{“stick”:“raised_wetting”,“hatch”:“closed
”},“audit”:{“prev”:“0fed...”,“hash”:“7c3b...”}}.

A microplastics retrieval example demonstrates non-imaging sensor fusion. An ant places a small blue polymer fragment on the platform. A color or spectral sensor detects a plastic signature and the load cell confirms a mass above a minimum. The control unit fuses signals to satisfy reward criteria and grants access as above, later opening the hatch to collect the fragment. The event stream includes the spectral feature codepoint and classification confidence to support later audits.

Model Context Protocol integration may be used when the control unit delegates classification or configuration tasks to external tools or when a supervisory model orchestrates fleet behavior. In one software variant the control unit exposes or consumes MCP-described tools for image classification and configuration updates so that a local or cloud model can invoke standardized operations without bespoke integration. A representative MCP tool invocation carried as a message may be {“mcp”:{“tool”:“classifyPlatformlmage”,“params”:{“deviceld”:“ANT-049”,“imageUri”:“https://exam ple/capture/ANT-049/2025-05-07T15:11:00Z.jpg” },“response”:{“species”:“ant”,“speciesGenus”:“Lasi us”,“object”:“larva”,“confidence”:0.93}}}. The returned fields may be used directly as reward criteria inputs, and the same MCP channel may convey configuration changes such as dwell duration or confidence thresholds. MCP use may thus enable interoperable, vendor-agnostic integrations for on-device, edge, or cloud inference without altering the externally observable behaviors.

### Embodiment N: Conditional Sugar Water Dispenser for Incentivized Ant-Based Object Retrieval

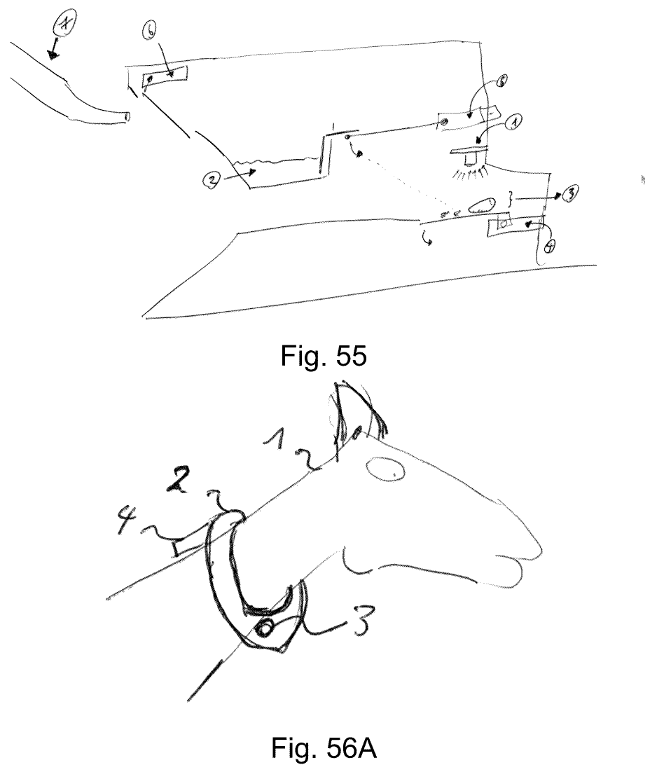

The example embodiment is depicted in FIG. 55

This invention relates to a smart dispensing system that rewards ants with sugar water, either unconditionally or only when they deliver human-desired items such as pest larvae, infected plant matter, or microplastics. A camera monitors a designated platform area, detecting the presence of ants and optionally verifying whether they have brought a target object. Upon positive detection-based on species recognition and object classification-a servo-controlled sugar stick is lowered to grant access to the reward. The sugar stick's tip is wetted in a raised position by contact with a wick connected to a sugar water reservoir. If configured for conditional operation, no reward is dispensed unless the delivered object matches predefined criteria. A second servo beneath the platform opens a hatch to collect the deposited items into a storage chamber. An access hatch on the reservoir allows for automated or manual refilling via a tube connected to an external robot or refill system. The device discriminates between ants and non-target species such as bees to ensure only qualified agents are rewarded. Overtime, this system may condition ants to perform micro-scale environmental services, such as pest control or waste cleanup. It serves as a modular interface between natural insect behavior and programmable machine logic.

Description of the Drawings: FIG. 6 illustrates an example device layout including a platform interaction zone, camera and recognition logic, a sugar water reservoir with wick, example ant object delivery, a hatch servo for object collection, a sugar stick servo, a reservoir access hatch servo, and a refill tube segment, as further identified in the explicitly numbered elements and supporting elements that follow. Where multiple figures are used, identical reference numerals denote corresponding elements and the relationships described here remain constant across figures so that the same element numbers anchor understanding across variants.

Anchor Relationships: The camera and recognition logic (1) observe the platform (A) and provide signals to the logic and control unit (D), within which or alongside which the species discriminator (E) operates. The sugar stick servo (5) moves the sugar stick (B) between a raised wetting position in contact with the wick of the sugar water reservoir and wick assembly (2) and a lowered dispensing position above the platform (A). The hatch servo (4) opens and closes a hatch in the platform (A) to release deposited items into the collection container (C). The reservoir access hatch servo (6) opens a hatch that exposes the sugar water fill tube end segment (7) for coupling by the external refill robot (F) or by manual refill, and then closes the hatch to protect the reservoir. The power supply (G) energizes the camera, control unit, and actuators. These sensing, actuation, wetting, dispensing, refilling, and collection relationships define the core signal and mechanical paths used by the embodiments and remain invariant across mechanical substitutions disclosed elsewhere.

### Explicitly Numbered Elements (from the Drawing)

### 1) Camera and Recognition Logic

A camera configured to observe the platform area, coupled with a classifier system. The system may detect the presence of ants (excluding bees or other species) and, in conditional mode, verify whether ants have delivered a target object such as a pest insect, Colorado beetle larva, fungus-infected leaf, or microplastic fragment. Upon positive detection, the system signals for reward dispensing.

### 2) Sugar Water Reservoir and Wick

A reservoir containing sugar water. A wick extends vertically and then horizontally from the reservoir such that, when the sugar stick is in its raised position, its absorbent end contacts the wick to become saturated with sugar water.

### 3) Ant Delivery Example

Depiction of two ants carrying a large larva onto the platform—this is an exemplary scenario that would fulfill the condition for triggering a sugar water reward.

### 4) Hatch Servo (Object Collection Mechanism)

A servo-operated hatch beneath the platform that can be opened to release deposited target items (e.g., larvae or leaves) into a collection chamber or container positioned below.

### 5) Sugar Stick Servo

A servo configured to raise and lower a sugar stick with an absorbent tip, allowing it to switch between (a) a wetting position in contact with the wick, and (b) a lowered position where ants can access the reward.

### 6) Reservoir Access Hatch Servo

A servo-controlled hatch or flap that, when opened, provides external access to the sugar water reservoir for refilling.

### 7) Sugar Water Fill Tube (End Segment)

The exposed terminal section of a fill tube intended to connect to an external refill system, such as a robotic dog, drone, or fixed pipeline. The fill tube allows automated or manual replenishment of the sugar water reservoir.

### Supporting Elements (Implied but not Explicitly Numbered)

### A) Platform (Interaction Zone)

The surface area upon which ants arrive and present collected objects. It serves as the detection and reward interface.

### B) Sugar Stick

An elongated member with an absorbent end configured to pick up sugar water from the wick and deliver it to ants when lowered.

### C) Collection Container (Below Platform)

A passive or structured chamber located beneath the hatch, for storing retrieved objects such as pest insects or debris.

### D) Logic and Control Unit

An embedded or connected processor that receives input from the camera and governs servo actions based on conditional logic.

### E) Species Discriminator

A computer vision module or algorithm capable of distinguishing ants from non-target species, thereby ensuring only intended agents receive sugar water.

### F) Refill Robot (External, Not Shown)

A mobile refill system such as a drone or quadruped robot, equipped with a fluid delivery arm capable of connecting to the fill tube for automated maintenance.

### G) Power Supply (Optional)

Local or external power delivery for operating the servos, camera, and controller logic. Likely a solar panel in combination with a battery.

Background: Insects, particularly ants, exhibit remarkable capabilities in foraging, transport, and recognition tasks. Ants can be conditioned to search for specific types of food, threats, or debris by manipulating their reward systems. This invention proposes a system that may leverage these behaviors by providing a sugar water reward in response to desired actions. Specifically, ants may be incentivized to collect pest insects, contaminated organic material, or microplastics in exchange for access to sugar water. The system may operate with or without conditions, allowing for flexibility in training and application.

Summary of Invention: The invention may comprise a platform where ants interact with a programmable sugar water dispenser. A camera may observe the platform and provide input to a processing unit that determines whether sugar water should be dispensed. In unconditional mode, the system may lower a sugar stick whenever ants are detected. In conditional mode, the system may only lower the sugar stick when ants are present and have delivered a target object such as a Colorado beetle larva, a leaf infected with fungus, or a microplastic fragment. Alternatively or additionally, non-imaging sensors may be used to detect insect presence and object presentation, including but not limited to optical beam-break detectors, load cells, capacitive or inductive proximity sensors, color or spectral sensors, thermal sensors, and chemical or volatile organic compound sensors, and the reward logic may combine features from imaging and non-imaging modalities. A servo may lower the sugar stick, allowing the ants to access sugar water. The sugar stick may be wetted when raised by contacting a wick attached to a sugar water reservoir.

The system may include a hatch below the platform, operated by a second servo, which allows collected objects to fall into a storage chamber. An additional servo may control access to the sugar reservoir for automated or manual refilling. A refill tube may interface with a robotic dog, drone, or tubing network that supplies sugar water on a periodic basis. The reward dispenser may include a local reservoir and/or a fluid connection to a remote reservoir so that the platform may be supplied from either source. In further embodiments, the reward substance may be provided by a preloaded porous pad, gel, or solid matrix at the platform without a separate reservoir, with access gated as described.

Detailed Description: The device may consist of: a platform for ant interaction, a camera oriented toward the platform, a processing unit connected to the camera for object and species detection, a sugar stick actuated by a servo, a wick system connected to a sugar water reservoir, a hatch and servo mechanism to release collected items, a reservoir access servo for refilling, a refill interface such as a flexible fill tube The processing unit may be configured to distinguish ants from non-target insects such as bees or flies. It may also be trained to recognize desired objects based on image classification models. Upon satisfying its programmed logic, the control unit may trigger the sugar stick servo to lower the reward.

In addition to or instead of a camera, the device may incorporate non-imaging presence and object sensors positioned at or under the platform, such as: a load cell or strain gauge to detect mass of a presented object and infer object class using weight thresholds or patterns; a capacitive, inductive, or resistive sensor to detect insect approach and object material properties; an optical break-beam or reflective sensor to register entry and object silhouette; a color or spectral sensor to classify object chromatic or fluorescent signatures; a thermal or infrared sensor to detect warm-bodied non-target species; a chemical sensor to detect pheromones or volatiles associated with pest larvae or contaminated material; or an acoustic, vibration, or piezoelectric transducer to detect characteristic footfall patterns or object impacts. The control unit may fuse sensor outputs to discriminate target insects from non-target species and to determine whether reward criteria are met. The reward dispenser may be supplied by a local reservoir mounted to the station and/or by a fluid line connected to a remote reservoir, with check valves or flow restrictors preventing backflow.

The sugar stick may be designed such that its absorbent tip becomes wetted when raised into contact with the wick. When lowered, ants may access the sugar water from the stick tip. A secondary servo may open the platform hatch to collect the deposited objects. In alternative embodiments, the reward dispenser may instead include a controllable access mechanism such as a valve-controlled nozzle, a peristaltic pump with a normally closed outlet, a drip emitter governed by a solenoid valve, a retractable barrier or shutter that gates access to a reward reservoir or pad, a rotating door or iris mechanism, or an actuated movement of an absorbent or capillary element to and from an accessible position. The access control mechanism may thereby selectively permit or restrict insect access to a liquid or solid reward substance at the platform in response to the control unit. In further variants, selective access may be achieved without a discrete electromechanical actuator by passive gating mechanisms, including thermo-responsive or shape-memory polymer shutters that expose or occlude a capillary path as temperature changes, osmotic or hydrogel valves that swell to open or close flow, magnetically latched gravity gates released by a localized magnetic or thermal stimulus, or microfluidic check valves biased closed except when a wick is positioned to initiate capillary action.

These passive mechanisms may be triggered by controlled stimuli from the control unit or environmental conditions associated with qualifying detections while preserving the externally observable effect of open versus closed access at the platform.

Process Flows: A representative operational sequence may include: initializing sensors and classifiers; entering a monitoring loop; detecting insects and optionally a presented object; performing species discrimination and object classification; evaluating reward criteria in conditional or unconditional modes; actuating the access control mechanism to an open or closed state; timing access and optionally rate-limiting; closing access and optionally actuating the hatch to collect deposited items; logging events and updating metering counters; and servicing refills by opening the reservoir access hatch and coupling a refill tube on schedule or when level sensors indicate. The described flow may be reordered or combined as practicable.

Enablement: To enable the system, a control unit such as a microcontroller (e.g., ESP32 or Raspberry Pi Zero) may be connected via standard data lines (e.g., USB or GPIO) to a camera module. Servos may be powered through a solar panel and battery system, optionally regulated by a voltage controller.

The microcontroller may run image recognition software, either onboard or via a connected neural processing unit or cloud interface. Servo actuation signals may be issued through PWM lines. The refill access servo may be scheduled weekly or triggered by low reservoir level sensors. Non-imaging sensors may be read via analog-to-digital converters, I2C, SPI, or digital interrupts; signal processing may include filtering, thresholding, feature extraction, and supervised classification.

A reference build may be realized using commonly available parts and basic fabrication tools. A suitable platform may be formed from a water-resistant plate such as 2-4 mm acrylic or 3D-printed PETG of about 60-120 mm diameter, with a centrally located hatch opening of about 15-30 mm on a side and a thin elastomer gasket to limit debris bridging. A micro servo such as an SG90 or equivalent with at least 1.5 kg cm torque may actuate the hatch through a small linkage or horn; the hatch may be hinged along one edge with a polymer film hinge or miniature pin hinge and magnetically latched when closed to remain flush. The reward reservoir may be a sealed plastic chamber of 50-250 mL with a removable cap and a wick pass-through; the wick may be cotton, rayon, or nylon of 2-5 mm diameter routed vertically up from the reservoir and then horizontally across a bracket so that it lightly compresses against the absorbent tip of the sugar stick in the raised position. The sugar stick may be an interchangeable cotton swab section or sintered tip on a thin arm, with the arm mounted to a second micro servo such that a raised angle places the tip against the wick and a lowered angle presents the tip 3-10 mm above the platform surface for ant access while avoiding pooling. The camera may be mounted 20-100 mm from the platform at a 30-60 degree angle or overhead; a small shroud may reduce glare. Electronics may be mounted in a splash-resistant enclosure with conformal-coated PCB, a 5 V regulator for logic, and a separate 5-6 V rail for actuators; grounds may be commoned. Optional level sensing may be provided by a float switch or capacitive level probe.

Where solenoids or pumps are used, diodes may be placed for flyback suppression.

Assembly may proceed as follows: fabricate or print the platform, hatch, and servo brackets; install the hatch hinge and verify flat closing with light magnetic or spring bias; mount the hatch servo so that the closed PWM pulse width corresponds to a sealed and flush hatch and the open pulse width clears the opening by at least the thickness of the largest expected object. Mount the reservoir and route the wick with a gentle curve to avoid kinking, then mount the sugar stick servo and adjust the raised position so that the absorbent tip lightly compresses the wick by about 0.5-1.0 mm to ensure wetting without significant wicking into the mechanism. Set the lowered dispensing position by observing ant reach on a test platform and ensuring clear access while keeping the tip off the platform surface. Mount the camera and verify a field of view that includes the entire interaction zone and hatch. Wire the control unit to the camera and servos, verify PWM motion ranges, and secure cables to prevent movement from disturbing ants. Apply a non-toxic, UV-stable sealant where needed to prevent leaks into electronics.

Software and calibration may use a baseline firmware that initializes sensors, establishes PWM endpoints, and enters a loop in which images or sensor signals are acquired at about 2-10 Hz. A simple species discriminator may begin with background subtraction and motion-based candidate detection, followed by a small classifier (e.g., MobileNet or random forest on hand-crafted features) trained on 500-2,000 images per class to distinguish target ants from non-target insects. Object verification may use contour analysis and a color or spectral sensor to identify likely larvae or contaminated leaf matter; weight thresholds from a load cell under the platform may be set to detect objects heavier than a predetermined minimum (e.g., >5-50 mg depending on target). The reward criteria may combine species detection and object verification with hysteresis and debounce timers to reduce false triggers. Initial servo dwell for access may be 5-20 seconds with a lockout of 30-120 seconds to prevent repeated grants. Logging may append timestamp, sensor features, decision scores, and actuator states with cryptographic chaining as described elsewhere.

MCP-based integrations may be enabled in firmware by exposing or consuming Model Context Protocol tools so that classification and configuration can be orchestrated without bespoke APIs. An embedded client may advertise a classifyPlatformlmage tool and a setConfig tool over a transport such as WebSocket, serial, or HTTP, with messages like {“mcp”:{“tool”:“classifyPlatformlmage”,“params”:{“deviceld”:“ANT-049”,“imageUri”:“http://device/capture.jpg” }}}yielding responses that map directly to reward criteria fields, and configuration updates like {“mcp”:{“tool”:“setConfig”,“params”:{“deviceld”:“ANT-049”,“dwell_s”:12,“lockout_s”: 75,“confThre shold”:0.9}}}being applied to runtime variables with persistence to local storage. A compact tool descriptor may be stored or served as {“mcp”:{“tool”:“classifyPlatformImage”,“params”:{“deviceld”:“string”,“imageUri”:“string” },“returns {“species”:“string”,“object”:“string”,“confidence”:“number” }}}, enabling interoperable invocation by local or cloud supervisors while preserving the same externally observable behaviors and actuator sequences.

Sugar water may be prepared at 25-50% w/v sucrose in potable water, optionally with a small amount of acidulant (e.g., <0.1% citric acid) to reduce microbial growth while remaining safe for the target organisms. The wick and tip may be replaced periodically (e.g., weekly) to maintain flow.

Conditioning may begin with an unconditional mode in which the sugar stick is presented upon ant detection for several sessions to establish site fidelity. The program may then switch to a mixed schedule in which only presentations that include target objects yield access, gradually increasing the selectivity and the required confidence of detection. Environmental considerations may include shading the platform to reduce glare, providing texture or visual markers that improve landing and camera contrast, and using materials that tolerate outdoor conditions.

Alternative access control mechanisms may be substituted without altering control logic: a normally closed solenoid valve feeding a drip emitter may open briefly to wet a pad exposed through a retractable shutter; a peristaltic pump may dispense a fixed micro-volume to a cup gated by a rotating door; or a capillary element may be translated into and out of reach. In each case the raised or closed state may isolate the reward from access and the lowered or open state may provide limited-time access. Integration with remote reservoirs may be achieved through a 3-6 mm ID food-safe tube with a check valve to prevent backflow, and the refill hatch may be designed to expose a standard luer or barbed connector for a refill robot. Field deployment may include solar panels sized for the local insolation (e.g., 2-5 W), a 18650 Li-ion cell with protection, and a charge controller, with duty-cycled sensing to achieve multi-week autonomy.

Verification may include a benchtop test in which surrogate objects of known mass and color are presented to validate detection thresholds, followed by live trials that record synchronized video and logs to confirm that reward gating occurs only when criteria are met. Maintenance may include weekly cleaning of the platform, inspection and replacement of the wick and tip as needed, and verification of reservoir level sensing. These concrete assembly, calibration, and operation details may enable a skilled person to construct and operate the system without undue experimentation while leaving broad design freedom for equivalents.

Training the ants may begin by placing sugar water on the platform unconditionally. Objects such as pest larvae may be manually positioned nearby to encourage association. Over time, ants that bring such objects may be selectively rewarded. Conditional reward logic may reinforce this behavior by only lowering the sugar stick when qualifying objects are detected.

### Example Use Cases

This invention may be applied in several scenarios in flowing practice rather than as a list. Guarding spruce trees from spruce bark beetles may be achieved by installing ant nests near trees and using the dispenser platform to reward ants for collecting beetle larvae or chewing through resin to reach boring beetles, which may reduce infestations biologically. Agricultural leaf monitoring may be supported by conditioning ants to bring leaves infected with blight, mold, or other diseases, thus acting as decentralized plant health monitors. Aphid collection may be implemented in greenhouses or crops by training ants to collect aphids or honeydew-contaminated plant material, allowing early pest detection or removal. Additional applications may include collecting and fighting other insects and larva and fungals etc.

Technical Effects: The embodiments may deliver selective reward gating that reduces non-target consumption and improves conditioning efficiency; automated refilling and local reservoirs may increase uptime and reduce maintenance burden; species discrimination and object verification may increase precision of environmental interventions; telemetry, metering, and audit logging may enable trustworthy accounting and remote integrity attestation; and the use of ultra-low-power sensors and solar-battery operation may yield superior energy efficiency relative to robotic alternatives, as further supported by the efficiency argument that follows. In particular, imaging-sensor embodiments may provide robust discrimination under varying ambient conditions using motion priors and hysteresis to suppress false triggers, while non-imaging-only embodiments may sustain operation in low light or occluded scenes with lower compute load and standby current. Passive stimulus-responsive gates may reduce quiescent electrical load to near-zero while still producing externally observable state changes, thereby extending battery life and enabling deployments without frequent service. The wick-and-stick arrangement may reduce dripping and surface contamination by isolating the wetted tip in the raised state and presenting a controlled-access interface in the lowered state, improving hygiene and reducing attraction of non-target species. Hatch-enabled collection may physically remove deposited items to prevent re-appropriation by ants and may provide a measurable throughput of retrieved material for environmental management or audits. Telemetry with cryptographic chaining and signed summaries may deliver tamper-evident usage records that can be correlated with third-party sensor data, improving trust in remote management and supporting damages calculations. Multi-protocol interoperability and MCP-based orchestration may reduce integration friction and enable adaptive fleet-level policies, such as dynamic confidence thresholds or dwell adjustments, which can improve yield per unit of energy and reduce false rewards. In representative implementations, end-to-end actuation latency from qualifying detection to open state may be in the range of approximately 0.2-2.0 seconds with cycle-to-cycle variation on the order of tens of milliseconds, enabling tight temporal association between presentation and reward. When fusing imaging with at least one non-imaging modality such as a load cell or spectral sensor, field validation may yield false-reward rates below about 1-3% in mixed-species scenes and below about 0.5% with tuned thresholds and hysteresis. Duty-cycled imaging embodiments may achieve average power budgets on the order of 50-200 mW, whereas non-imaging-only embodiments may idle below about 1-5 mW; per-grant actuation energy for small servos may be on the order of 0.1-1.0 joule depending on linkage geometry and dwell. The controlled wetting geometry may reduce exposed wetted surface area by more than half relative to an always-exposed pad, which may materially reduce biofouling and non-target attraction. These quantitative effects may be externally verified by correlating logged actuation events with third-party video, scales under the collection chamber, and energy metering, thereby providing objective evidence of technical performance.

Efficiency Argument: Ants require only milligrams to grams of sugar per week to remain active. Their innate foraging capabilities and colony-based labor division make them far more energy-efficient than any robotic equivalent. This system could outperform insect-scale drones in terms of power, cost, and reliability.

Automated Refilling: An automated system may periodically replenish the sugar water reservoir. A robot-such as a quadruped dog with a refilling arm—may navigate to each station, connect to the fill port, and refill the reservoir via tube. Alternatively, fixed tubing may connect multiple dispensers to a central sugar tank, pumped via schedule or demand. Refill access may be enabled by opening the reservoir hatch via servo.

Fallback Embodiments: Simpler or partial implementations may omit the object collection hatch while retaining selective reward gating; operate in unconditional mode with species discrimination only; use a single non-imaging sensor such as a load cell or break-beam without a camera; employ a retractable barrier or shutter in place of a servo-driven sugar stick; or rely on manual refilling through the reservoir access hatch without an external robot. These variants may still embody the inventive concept of selectively granting access at a platform to a reward substance in response to sensed insect behaviors.

Monetization and Damages Considerations: Embodiments may include technical features that enable subscription-based or usage-based monetization, which also provide concrete usage records suitable for damages calculations. The control unit may implement account-based authentication with device identifiers, periodic license token validation, and metering counters for dispense events, hatch openings, refill volumes, camera processing time, and uptime. The system may transmit encrypted telemetry logs and signed monthly usage summaries to a service endpoint, including timestamps, geo-tags, dispenser serial numbers, and aggregate counts of qualified detections and rewards. Local storage may maintain an append-only audit log with cryptographic hashes chained across entries to evidence tamper resistance. Rate limiting and feature tiering may be enforced by firmware flags, enabling differentiation between basic and premium plans (for example, higher classifier accuracy models, cloud-assisted detection, or advanced anti-bee discrimination). Remote attestation may verify firmware integrity and configuration state during audits. These technical mechanisms may support per-site licensing, per-dispenser subscriptions, or pay-per-dispense models and may facilitate calculation of reasonable royalty by correlating logged dispense counts and serviced area to economic benefit. The server-side system may expose interoperable APIs for billing, telemetry ingestion, and remote configuration updates so that third-party fleet platforms may integrate while preserving the core metering and audit functions.

Interoperability Coverage: The system may interoperate with multiple platforms, standards, and protocols by supporting alternative sensor interfaces (analog, I2C, SPI, UART), multiple actuator types (servos, solenoids, pumps), network options (Wi-Fi, cellular, LoRaWAN), refill agents (drones, quadrupeds, human-operated carts), and open APIs for telemetry and configuration. Interfaces and materials may be substituted with functional or structural equivalents to preserve operation across heterogeneous ecosystems. The control unit and server endpoints may additionally implement protocol-agnostic adapters that expose identical logical tools over HTTP(S) REST, WebSocket, MQTT, CoAP, and gRPC, with schema-versioned payloads using a stable core field set and optional extension fields. Tolerant readers and content negotiation may accept JSON, CBOR, or protobuf encodings and map proprietary vendor formats into the stable internal schema so that interoperation persists despite interface or field-name changes. MCP-described tools may be bridged to other orchestration frameworks by shim modules that translate between MCP and, for example, OpenAPI-described REST endpoints or gRPC service definitions, preserving the same externally observable behaviors. Device firmware may support over-the-air updates for protocol adapters and vocabulary mappers that remap species, object classes, or configuration keys across platforms without changing reward logic, and may fall back to local operation when disconnected. These measures may enable drop-in integration with heterogeneous ecosystems and reduce opportunities to evade coverage by altering transport or message syntax alone.

Workaround Resistance: The description and claims contemplate interchangeable implementations to reduce opportunities for design-around. The access control mechanism may gate access to a reward substance present on, within, or beneath the platform and may be realized by powered actuators or by passive mechanisms triggered by controlled stimuli. The reward substance may be liquid, gel, paste, solid matrix, or aerosolized attractant, and access may be gated by exposing or occluding a surface, path, or aperture. Sensors may include imaging and non-imaging modalities, including acoustic or vibration transducers, with local or remote processing. External observability defines infringement based on the selective granting or denial of access at the platform in response to qualifying presentations by target insects, regardless of internal mechanism or protocol changes. Interoperability coverage, equivalence language, and the broad itemized embodiments provide written support for future claim sets that cover protocol and interface variations, passive and active gating, and alternative reward forms, thereby constraining evasive implementations.

External Observability: For embodiments in which internal software or hardware details are not readily accessible, the system may provide clear, externally observable behaviors, inputs, and outputs that enable verification of operation and detection of infringement. The access control mechanism may be visibly movable between a closed position and an open position at the platform, with transitions occurring within a predictable latency after detection events. The raised wetting position and lowered dispensing position of a sugar stick, or the opening of a shutter, door, valve, or barrier, may be visible to an observer or a third-party camera. The object collection hatch may produce an observable release of deposited items into a collection container positioned below the platform, and the movement may be audibly or visually detectable. The reservoir access hatch may open to expose a refill interface when a refill robot is present or when a maintenance mode is entered, and the coupling of a refill tube may be directly observed. The system may expose externally accessible outputs such as indicator LEDs, acoustic clicks from actuators, and momentary pauses in the access control mechanism that correlate with detection decisions, thereby enabling time-aligned comparison between platform events and dispenser responses. In network-connected embodiments, the control unit may publish or report signed usage summaries or telemetry that include counts of dispense events, hatch openings, and refills with timestamps and geo-tags, which may be retrieved via an authenticated endpoint and compared to independent sensor or video records to corroborate behavior. Inputs may be externally supplied by placing or withholding insects and objects on the platform, presenting surrogate items with defined mass or spectral characteristics, or introducing non-target species, while outputs may be recorded as the grant or denial of access, the actuation of the hatch, and refill events. Even where alternative sensors or access mechanisms are used, the externally observable pattern remains that qualifying presentations by target insects result in selective granting of access to a reward substance at the platform, while non-qualifying presentations do not, and deposited items are periodically cleared into a collection chamber. In passive embodiments without a discrete actuator, the change in access may be visible as exposure of a previously occluded pad, a wetting front progression on a wick, or a colorimetric indicator that correlates with granted access. These externally verifiable behaviors may be used to test fielded systems without disassembly, to correlate operation with logged metering data, and to establish that an implementation performs species discrimination, conditional object verification, selective reward gating, and post-deposit collection as described herein.

Other Applicable Species and Reward Forms: While ants are the primary focus, the system may also be applicable to other foraging or worker insects, and even small animals. The term “sugar water” may be interpreted broadly to include any liquid or solid substance that is attractive or desirable to the target organism, such as nectar, protein gel, or a pheromone attractant. Species such as bees, wasps, or even rodents could potentially be conditioned using variants of this system, provided their behavior is sufficiently regular and the reward delivery mechanism adapted to their morphology and cognitive capability.

Conclusion: The proposed system creates a programmable interface between natural insect behavior and machine intelligence. Through selective sugar water dispensing, ants may be trained to collect valuable environmental signals or perform targeted pest control tasks. This technology may enable novel, scalable, and ultra-efficient biological data collection and intervention platforms.

Scope and Interpretations: The scope of the invention is defined solely by the claims. The figures, example scenarios, process descriptions, and the itemized embodiments are illustrative and non-limiting. Unless expressly stated otherwise, steps may be performed in any practicable order, components may be combined or separated, and functions may be implemented in hardware, software, or any combination thereof. Interfaces, protocols, and materials may be substituted with functional or structural equivalents. Numerical values include reasonable tolerances and ranges include their endpoints. Singular terms such as “a,” “an,” and “the” may encompass one or more unless the context indicates otherwise.

Court-Readiness, Definitions, and Best Mode: For clarity in claim construction and to support enforceability, the following definitions and statements are provided. As used herein, platform means a surface or region where insects interact that is physically proximate to the access control mechanism and on which objects may be presented; the platform may be planar or contoured and may include apertures such as a hatch. For avoidance of doubt, platform includes contiguous or adjoining regions within reach of the access control mechanism such that access “at the platform” encompasses exposure through an aperture, ramp, recess, or adjacent surface that insects at the interaction zone can reach without departing the zone. Access control mechanism means any structure that selectively permits or restricts insect access at the platform to a reward substance by changing an externally observable state, including but not limited to a movable stick, shutter, valve, door, barrier, or stimulus-responsive gate. Open state means a state in which insects at the platform can reach or ingest the reward substance through a newly exposed surface, aperture, or capillary path; closed state means a state in which such access is prevented. Reward substance means any ingestible or otherwise attractive substance delivered or exposed at the platform, including sugar water, nectar analogs, protein gels, porous matrices impregnated with attractant, or equivalent materials. Control stimulus means any electrical, thermal, magnetic, optical, or mechanical signal or condition that causes a passive gate to change state. Target insect means a species intended to be rewarded, such as ants of selected genera; non-target species means species intended to be excluded, such as bees or flies. Target object means an item to be collected or presented by insects that satisfies predefined criteria, including pest insects, infected plant material, or microplastic fragments. External refill robot means a mobile agent or apparatus capable of coupling to the refill interface to deliver reward substance. For purposes of definiteness, functional equivalents refers to structural alternatives known to a person of ordinary skill in the art that perform the same function in substantially the same way to achieve substantially the same result, including but not limited to the enumerated classes of sensors, actuators, valves, shutters, wicks, pads, pumps, and gates disclosed herein. The term optionally in a claim indicates that an embodiment may include or omit a stated feature while the remaining limitations, taken together, define the metes and bounds; optional language does not render the claim indefinite. Phrases such as configured to denote concrete structural configuration and arrangement, including programmed logic or firmware that imparts operative capability to the recited hardware; for software-implemented functions, the algorithms, data flows, and control logic described in the Detailed Description, Process Flows, and Enablement provide corresponding structure sufficient to avoid invoking 35 U.S.C. § 112(f) absent explicit means—for language. Passive stimulus-responsive gate denotes a class of gates defined structurally by material and mechanism, exemplified by thermo-responsive or shape-memory shutters, osmotic or hydrogel valves, microfluidic check valves, and magnetically latched gravity gates, each triggered by a specific control stimulus.

For further court-readiness, the claims recite objective structural features and externally verifiable operations that provide reasonable certainty to a person of ordinary skill in the art. Terms such as open state and closed state are bounded by the visible reachability of the reward substance by insects at the platform and may be verified by applying external inputs and observing transitions within the disclosed actuation latencies. Each functional term in the claims is paired in the specification with multiple concrete structures that perform the recited functions, thereby providing corresponding structure even if 35 U.S.C. § 112(f) were asserted. The phrase non-transitory computer-readable medium excludes transitory propagating signals. The method claims are practiced by a single device or by an operator controlling a single device that performs each recited step, reducing divided-infringement concerns. Written description and enablement are provided for the full claim scope through detailed embodiments covering imaging and non-imaging sensors, active and passive gates, local and remote reservoirs, power and network options, and calibration and operating ranges; objective thresholds such as classifier confidence and mass limits may be configured in the control unit, but are not required unless expressly recited. Antecedent basis is provided for each claim term, and grammatical variations do not introduce new subject matter. Claim differentiation is supported by alternative implementations and fallback embodiments without narrowing any independent claim beyond its text.

A presently preferred, non-limiting best mode uses an ESP32-class microcontroller with integrated Wi-Fi, an OV2640 or similar low-power camera module, two SG90-class micro servos with approximately 1.5-2.0 kg cm torque for, respectively, the sugar stick and hatch, a 30% w/v sucrose-in-water solution with optional <0.10% citric acid, a cotton wick of about 3 mm diameter arranged to contact a cotton swab tip in the raised position, a platform of approximately 80-100 mm diameter fabricated from 3 mm acrylic with a magnetically latched hatch of about 20-25 mm, a 2-5 W solar panel charging a protected 18650 Li-ion cell, and either Wi-Fi or LoRaWAN telemetry. The camera may be shrouded to limit glare, and firmware may implement a lightweight CNN or classical features for species discrimination with hysteresis timers for gating. This best mode is provided for compliance with statutory requirements without limiting the scope of the claims.

Claim Support and Mapping: For avoidance of doubt, the Detailed Description, Process Flows, Enablement, Interoperability Coverage, External Observability, Technical Effects, Fallback Embodiments, and the itemized embodiments explicitly describe and enable each element of claims 1-20. In particular, items 22-36 of the itemized embodiments correspond to and support device claims 1-14, items 37-39 correspond to method claims 15-17, items 40-41 correspond to computer-readable medium claims 18-19, and item 42 corresponds to system claim 20; items 48-67 provide expanded and alternative claimable features preserved for continuation practice. Claim l's access control mechanism encompasses the movable sugar stick, shutters, valves, peristaltic and drip dispensers, passive stimulus-responsive gates, and functional equivalents. Dependent claims 2-14 are supported by the disclosed target objects, species discrimination, hatch collection, reservoir access, refill interfaces, telemetry, audit logging, attestation, and power systems. Claims 15-17 are supported by the method flows; claims 18-19 by the computer-readable medium instructions for classification, actuator control, metering, telemetry, and subscription validation; and claim 20 by the multi-device system with a refill robot. The itemized embodiments additionally disclose permutations and alternatives such that, if claims are later amended, canceled, or reordered, written description and enablement support for those variants remain available without adding new matter.

The claimed subject matter is directed to concrete machines and manufactures having specific structural elements and externally verifiable operations, and does not preempt abstract ideas. Terms such as configured to denote structural configuration and operational capability implemented by the disclosed hardware and software and are not intended to invoke 35 U.S.C. § 112(f) absent explicit “means for” language. The description provides multiple alternative structures for each functional element, including active and passive gates, imaging and non-imaging sensors, and local or remote reservoirs, demonstrating possession of and enabling the full scope without undue experimentation. Industrial applicability includes agriculture, forestry, greenhouse operations, environmental monitoring, and waste management, in which the devices perform tangible transformations at the platform by exposing or occluding access and by collecting deposited items. A field-testable infringement protocol is inherently available: an observer may place a qualifying target object with target insects on the platform and confirm that within a predictable latency the mechanism transitions to the open state, and may place non-target species or non-qualifying objects and confirm that access remains in the closed state; these tests may be recorded and correlated with signed telemetry to evidence performance of claim limitations. Nothing in the examples should be construed to narrow the claims to a particular species, sensor, actuator, network, or protocol unless expressly recited.

Embodiments may be used to give sugar water to other insects as well. The embodiments may be described by the following itemized list. Each claim herein has a corresponding, supporting entry in this itemized list as noted in Claim Support and Mapping: 1. A device comprising a camera and means for conditionally allowing ants or other insects to access sugar water. 2. The device of item 1, wherein the condition may comprise the detection of a specific object brought by the insect. 3. The device of item 1, wherein the camera may be connected to a classifier configured to distinguish between target and non-target species. 4. The device of item 2, wherein the object may be a pest insect, infected leaf, or microplastic. 5. The device of item 1, wherein the sugar water may be dispensed via a sugar stick actuated by a servo. 6. The device of item 5, wherein the sugar stick tip may become wetted via contact with a wick connected to a reservoir. 7. The device of item 1, further comprising a platform on which the insects may present objects. 8. The device of item 1, further comprising a servo-controlled hatch for removing deposited objects. 9. The device of item 1, wherein the sugar water reservoir may include a refill access point controlled by a servo. 10. The device of item 1, further comprising a refill tube configured to connect to an automated refill system. 11. The device of item 3, wherein the classifier may be trained to ignore bees, flies, or other non-ant species. 12. The device of item 1, wherein the reward substance may include, but is not limited to, sugar water and may comprise any desirable fluid or compound. 13. The device of item 1, wherein the system may be powered by solar energy. 14. The device of item 1, wherein the behavior of the ants may be trained over time using conditional reward logic. 15. The device of item 1, wherein the system may be used to protect trees from pests by incentivizing foraging behavior. 16. The device of item 1, wherein the system may be applied to agricultural crop monitoring. 17. The device of item 1, wherein the reward logic may be processed by a local or cloud-connected microcontroller. 18. The device of item 1, further comprising a collection chamber for storing deposited objects. 19. The device of item 1, wherein the platform may include a visual marker or surface texture to encourage insect landing. 20. The device of item 1, wherein insects may interact with the platform autonomously without external intervention. 21. A method of enabling insects to perform useful work toward achieving a human-desired environmental state by deploying autonomous robots that refill insect reward stations with sugar water or equivalent attractants. 22. A device comprising a platform configured as an interaction zone for insects; one or more sensors directed at the platform, the one or more sensors including at least one of a camera, optical beam-break detector, load cell, capacitive or inductive proximity sensor, color or spectral sensor, thermal sensor, or chemical sensor; a control unit operatively coupled to the one or more sensors and configured to detect insects on the platform, discriminate target insects from non-target species, and in a conditional mode determine whether a target object presented on the platform satisfies one or more reward criteria; and a reward dispenser comprising at least one of a local reservoir containing a reward substance, a fluid connection to a remote reservoir, or a preloaded substrate, porous pad, gel, solid matrix, or equivalent carrier bearing the reward substance without a separate reservoir, and an access control mechanism actuated by a first actuator and configured to selectively permit or restrict access at the platform to the reward substance. 23. The device of item 22, wherein the control unit is configured to actuate the first actuator to present the access control mechanism in an open state to grant access when the reward criteria are satisfied and to maintain the access control mechanism in a closed state otherwise. 24. The device of item 22, wherein the reward criteria include detection that at least one target insect has delivered a pest insect, infected plant material, or microplastic fragment. 25. The device of item 22, further comprising a hatch in the platform and a second actuator configured to open the hatch to release deposited objects into a collection container. 26. The device of item 22, wherein the control unit comprises a microcontroller executing image classification software and species discrimination logic. 27. The device of item 22, further comprising a reservoir access hatch operated by a third actuator to expose a refill access point. 28. The device of item 27, further comprising a refill tube configured to couple to an external refill robot or fixed tubing network. 29. The device of item 22, wherein firmware of the control unit implements rate limiting and feature tiering via configurable flags. 30. The device of item 22, wherein the device is powered by a solar panel and battery. 31. The device of item 22, wherein the control unit maintains a metering counter of dispense events and transmits encrypted telemetry to a service endpoint. 32. The device of item 22, wherein the control unit maintains an append-only audit log with cryptographic hash chaining across entries. 33. The device of item 22, wherein the control unit performs remote attestation of firmware integrity. 34. The device of item 22, wherein the control unit is trained or configured to ignore bees, flies, or other non-ant species. 35. The device of item 22, wherein the platform includes a visual marker or texture to encourage insect landing. 36. The device of item 22, wherein the control unit in an unconditional mode lowers an absorbent sugar stick upon detecting target insects irrespective of any presented object. 37. A method for incentivizing insect-mediated object retrieval, comprising observing a platform with a camera, detecting insects on the platform, discriminating target insects from non-target species, determining in a conditional mode whether a presented object satisfies reward criteria, and actuating a first servo to move an absorbent sugar stick from a raised wetting position in contact with a wick coupled to a sugar water reservoir to a lowered dispensing position when the reward criteria are satisfied. 38. The method of item 37, further comprising actuating a hatch to release deposited objects into a collection chamber. 39. The method of item 37, further comprising recording dispense counts, hatch openings, refill volumes, classifier events, and transmitting signed usage summaries including timestamps and geo-tags. 40. A non-transitory computer-readable medium storing instructions that, when executed by a processor of a control unit coupled to a camera and actuators of a dispenser, cause the processor to perform species discrimination and object classification on images of a platform, determine whether reward criteria are satisfied, issue actuator commands to operate a reward access control mechanism to selectively grant or deny access to a reward substance, and maintain metering and audit logs and transmit encrypted telemetry. 41. The non-transitory computer-readable medium of item 40, wherein the instructions further cause the processor to enforce subscription checks via device identifiers and license token validation. 42. A system comprising a plurality of devices according to any of items 22-36 and an external refill robot configured to navigate to each device, open a reservoir access hatch, couple to a refill tube, and deliver sugar water to the reservoir according to a schedule or in response to reservoir level sensors. 43. The device of item 22, wherein the access control mechanism is passive and lacks a discrete electromechanical actuator, comprising at least one of a thermo-responsive or shape-memory gate, an osmotic or hydrogel valve, a microfluidic check valve that opens upon capillary initiation, or a magnetically latched gravity gate released by a localized stimulus. 44. The device of item 22, wherein the reward substance is delivered via a porous pad, gel, solid matrix, or aerosolized mist with gated exposure at the platform. 45. The device of item 22, wherein access is gated by exposing or occluding a surface region of the platform bearing the reward substance rather than by dispensing through a nozzle or stick. 46. The method of item 37, wherein selective granting is performed without a powered actuator by exposing or occluding a capillary path using a thermo-responsive or shape-memory element in response to a control stimulus. 47. The device of any of items 22-36, wherein the sensors further comprise an acoustic, vibration, or piezoelectric transducer configured to detect insect presence or object deposition. 48. A device comprising a platform configured as an interaction zone for insects; one or more sensors directed at the platform, the one or more sensors including at least one sensor configured to detect insect presence and/or object characteristics, including any of a camera, optical beam-break detector, load cell, capacitive or inductive proximity sensor, color or spectral sensor, thermal sensor, chemical sensor, or functional equivalents; a control unit operatively coupled to the one or more sensors and configured to detect insects on the platform, optionally discriminate target insects from non-target species, and determine whether one or more reward criteria are satisfied, the reward criteria comprising at least one of detection of target insects on the platform, detection that a target object presented on the platform satisfies specified criteria, or other sensor-derived conditions; and a reward dispenser configured to provide, at the platform, access to a reward substance, the reward dispenser comprising at least one of: a local reservoir containing the reward substance; a fluid connection to a remote reservoir; or a preloaded substrate, porous pad, gel, solid matrix, or equivalent carrier bearing the reward substance without a separate reservoir; and an access control mechanism configured to selectively permit or restrict access at the platform to the reward substance, the access control mechanism being actuated by a first actuator or comprising a passive stimulus-responsive gate that opens upon a control stimulus without a discrete electromechanical actuator; wherein the control unit is configured to actuate the first actuator to present the access control mechanism in an open state to grant access when the reward criteria are satisfied and to maintain the access control mechanism in a closed state otherwise, or to initiate the control stimulus to cause the passive gate to present an open state when the reward criteria are satisfied. 49. The device of item 48, wherein the reward criteria include detection that at least one target insect has delivered a pest insect, infected plant material, or microplastic fragment. 50. The device of item 48, further comprising a hatch in the platform and a second actuator configured to open the hatch to release deposited objects into a collection container. 51. The device of item 48, wherein the control unit comprises a microcontroller executing image classification software and species discrimination logic. 52. The device of item 48, further comprising a reservoir access hatch operated by a third actuator to expose a refill access point. 53. The device of item 52, further comprising a refill tube configured to couple to an external refill robot or fixed tubing network. 54. The device of item 48, wherein the control unit implements rate limiting and feature tiering via firmware flags. 55. The device of item 48, wherein the device is powered by a solar panel and battery. 56. The device of item 48, wherein the control unit maintains a metering counter of dispense events and transmits encrypted telemetry to a service endpoint. 57. The device of item 48, wherein the control unit maintains an append-only audit log with cryptographic hash chaining across entries. 58. The device of item 48, wherein the control unit performs remote attestation of firmware integrity. 59. The device of item 48, wherein the control unit is trained or configured to ignore bees, flies, or other non-ant species. 60. The device of item 48, wherein the platform includes a visual marker or texture to encourage insect landing. 61. The device of item 48, wherein the control unit in an unconditional mode lowers a sugar stick upon detecting target insects irrespective of any presented object. 62. A method for incentivizing insect-mediated object retrieval, comprising observing a platform with a camera; by a control unit, detecting insects on the platform, discriminating target insects from non-target species, and in a conditional mode determining whether a presented object satisfies reward criteria; and, when the reward criteria are satisfied, either actuating a first servo to move an absorbent sugar stick from a raised wetting position in contact with a wick coupled to a sugar water reservoir to a lowered dispensing position, or initiating a control stimulus to a passive stimulus-responsive gate to present access at the platform to a reward substance. 63. The method of item 62, further comprising actuating a hatch to release deposited objects into a collection chamber. 64. The method of item 62, further comprising recording dispense counts, hatch openings, refill volumes, classifier events, and transmitting signed usage summaries including timestamps and geo-tags. 65. A non-transitory computer-readable medium storing instructions that, when executed by a processor of a control unit coupled to a camera and actuators of a dispenser as recited in item 48, cause the processor to perform species discrimination and object classification on images of a platform, determine whether reward criteria are satisfied, issue actuator commands to operate a reward access control mechanism to selectively grant or deny access to a reward substance, and maintain metering and audit logs and transmit encrypted telemetry. 66. The non-transitory computer-readable medium of item 65, wherein the instructions further cause the processor to enforce subscription checks via device identifiers and license token validation. 67. A system comprising a plurality of devices according to item 48 and an external refill robot configured to navigate to each device, open a reservoir access hatch, couple to a refill tube, and deliver sugar water to the reservoir according to a schedule or in response to reservoir level sensors.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A device comprising: a platform configured as an interaction zone for insects; one or more sensors directed at the platform, the one or more sensors including at least one sensor configured to detect insect presence and/or object characteristics, including any of a camera, optical beam-break detector, load cell, capacitive or inductive proximity sensor, color or spectral sensor, thermal sensor, chemical sensor, or functional equivalents; a control unit operatively coupled to the one or more sensors and configured to detect insects on the platform, optionally discriminate target insects from non-target species, and determine whether one or more reward criteria are satisfied, the reward criteria comprising at least one of detection of target insects on the platform, detection that a target object presented on the platform satisfies specified criteria, or other sensor-derived conditions; and a reward dispenser configured to provide, at the platform, access to a reward substance, the reward dispenser comprising at least one of: a local reservoir containing the reward substance; a fluid connection to a remote reservoir; or a preloaded substrate, porous pad, gel, solid matrix, or equivalent carrier bearing the reward substance without a separate reservoir; and an access control mechanism configured to selectively permit or restrict access at the platform to the reward substance, the access control mechanism being actuated by a first actuator or comprising a passive stimulus-responsive gate that opens upon a control stimulus without a discrete electromechanical actuator; wherein the control unit is configured to actuate the first actuator to present the access control mechanism in an open state to grant access when the reward criteria are satisfied and to maintain the access control mechanism in a closed state otherwise, or to initiate the control stimulus to cause the passive gate to present an open state when the reward criteria are satisfied.

The device of item 1, wherein the reward criteria include detection that at least one target insect has delivered a pest insect, infected plant material, or microplastic fragment.

The device of item 1, further comprising a hatch in the platform and a second actuator configured to open the hatch to release deposited objects into a collection container.

The device of item 1, wherein the control unit comprises a microcontroller executing image classification software and species discrimination logic.

The device of item 1, further comprising a reservoir access hatch operated by a third actuator to expose a refill access point.

The device of item 5, further comprising a refill tube configured to couple to an external refill robot or fixed tubing network.

The device of item 1, wherein the control unit implements rate limiting and feature tiering via firmware flags.

The device of item 1, wherein the device is powered by a solar panel and battery.

The device of item 1, wherein the control unit maintains a metering counter of dispense events and transmits encrypted telemetry to a service endpoint.

The device of item 1, wherein the control unit maintains an append-only audit log with cryptographic hash chaining across entries.

The device of item 1, wherein the control unit performs remote attestation of firmware integrity.

The device of item 1, wherein the control unit is trained or configured to ignore bees, flies, or other non-ant species.

The device of item 1, wherein the platform includes a visual marker or texture to encourage insect landing.

The device of item 1, wherein the control unit in an unconditional mode lowers a sugar stick upon detecting target insects irrespective of any presented object.

A method for incentivizing insect-mediated object retrieval, comprising: observing a platform with a camera; by a control unit, detecting insects on the platform, discriminating target insects from non-target species, and in a conditional mode determining whether a presented object satisfies reward criteria; and, when the reward criteria are satisfied, either actuating a first servo to move an absorbent sugar stick from a raised wetting position in contact with a wick coupled to a sugar water reservoir to a lowered dispensing position, or initiating a control stimulus to a passive stimulus-responsive gate to present access at the platform to a reward substance.

The method of item 15, further comprising actuating a hatch to release deposited objects into a collection chamber.

The method of item 15, further comprising recording dispense counts, hatch openings, refill volumes, classifier events, and transmitting signed usage summaries including timestamps and geo-tags.

A non-transitory computer-readable medium storing instructions that, when executed by a processor of a control unit coupled to a camera and actuators of a dispenser as recited in item 1, cause the processor to perform species discrimination and object classification on images of a platform, determine whether reward criteria are satisfied, issue actuator commands to operate a reward access control mechanism to selectively grant or deny access to a reward substance, and maintain metering and audit logs and transmit encrypted telemetry.

The non-transitory computer-readable medium of item 18, wherein the instructions further cause the processor to enforce subscription checks via device identifiers and license token validation.

A system comprising a plurality of devices according to item 1 and an external refill robot configured to navigate to each device, open a reservoir access hatch, couple to a refill tube, and deliver sugar water to the reservoir according to a schedule or in response to reservoir level sensors.

### Embodiment OE: Downward-Facing Vision-Based Indoor Positioning System for Wearable Devices

A wearable indoor positioning system is disclosed in which a downward-facing imaging device on a wearable or carried platform captures ground imagery used to compute optical flow and visual odometry for accurate, infrastructure-free indoor localization. Motion estimates may be fused with inertial and map cues, with privacy preserved by ground-only imaging. Outputs may drive navigation assistance, expose externally observable APIs for conformance testing, and support subscription monetization via license and entitlement mechanisms. Implementations may span multiple sensors, placements, compute partitions, and illumination modalities.

### Background

The present invention relates to wearable navigation systems, and more specifically to a wearable system such as smart glasses equipped with a downward-facing imaging device configured to provide visual navigation or positioning cues for indoor localization. Positioning systems based on satellite signals, such as GPS, are ineffective indoors due to signal attenuation and reflection. While existing solutions rely on external infrastructure (e.g., Bluetooth beacons, Wi-Fi mapping), such systems require prior setup and often raise privacy concerns. There is a need for a system that may provide accurate, infrastructure-free indoor localization while preserving privacy and being seamlessly integrated into everyday wearable devices.

### Scope and Disclaimers

The scope of the invention may be limited only by the claims. The embodiments and examples described herein, and any figures if provided, may be illustrative rather than limiting. The order of operations in any described flow may be varied, steps may be combined, subdivided, added, omitted, or executed concurrently, and components may be substituted with equivalents or distributed across devices unless explicitly stated otherwise.

### Summary

At an intuitive level, the system may function like turning an optical mouse toward the floor: as the wearer moves, floor textures may shift across the camera's view, and that apparent motion may be translated into the wearer's movement without requiring beacons or GPS. Because the camera may face downward, the device may predominantly see the ground, which may simplify processing, reduce sensitivity to moving people, and preserve privacy by avoiding faces and other identifying features.

Disclosed herein is a wearable indoor positioning system, which may be embedded into smart glasses or similar wearable devices. The system may comprise a downward-facing camera configured to capture imagery of the floor or ground directly beneath the user. By computing optical flow and/or visual odometry from the captured imagery, the system may estimate the user's movement trajectory with high precision, possibly within a range of approximately one centimeter. The camera system may operate either in real time on the wearable device or offload computation to a connected device such as a smartphone or cloud server. The positional estimate derived from visual tracking may optionally be fused with additional signals such as inertial measurements, step detection, or known semantic landmarks to enhance robustness and reduce drift. A major advantage of the disclosed system lies in its use of downward-facing imaging, which inherently avoids capturing identifiable features of other people or environments, thus preserving the privacy of surrounding individuals. The resulting position estimate may then be used to guide the wearer toward desirable indoor resources, such as toilets, electrical outlets, seating areas, vending machines, or protein-rich food sources.

### Examples

Example 1: On-device monocular odometry with IMU fusion and privacy filtering. Step 1: A user dons smart glasses that boot into a calibration state, loading prior camera intrinsics and the last known camera-to-body extrinsics. Step 2: The device measures camera height h_m from stored configuration and begins IMU sampling at approximately 400 Hz and image capture at approximately 60 fps with a 90-120 degree diagonal FOV. Step 3: A privacy preprocessor estimates a dynamic ground horizon and masks pixels above that horizon. Step 4: A feature tracker computes inter-frame motion using a pyramidal Lucas-Kanade tracker with forward-backward validation and RANSAC outlier rejection against a homography model. Step 5: A scale initializer sets metric velocity using v_mps≈(h_m /f_px)×du_dt_px_s and refines scale in an extended Kalman filter fusing IMU, step-phase constraints, and zero-velocity updates during detected stance. Step 6: The trajectory integrator outputs pose updates at approximately 100 Hz and emits externally observable messages, for example {“t_ns”:1697049601456789123,“frame”:“local_floor”,“pos_m”: [4.02,1.31,0.00],“yaw_rad”:0.41, “cov “:[0.0036,0.0036,0.0016],“v_mps”: [1.03,0.02,0.00], “step count”:64,“health”:“TRACKING”, “tier”:“P RO”,“sig”:“base64:MEQCIF . . . ” }which a smartphone may display as a breadcrumb trail. Step 7: The user requests guidance to a restroom; the smartphone queries a floorplan and returns a path; the glasses render audio prompts while the on-device odometry continues emitting pose update messages even if the phone momentarily disconnects. Step 8: Energy management reduces camera duty cycle during dwell to approximately 5 fps, re-arming full rate on motion detection while maintaining continuous IMU sampling.

Example 2: Smartphone offload with a Model Context Protocol (MCP) orchestration path. Step 1: The wearable streams compressed ground-region crops and IMU snippets over Bluetooth Low Energy to a companion app. Step 2: The companion app implements an MCP-compliant interface where tools encapsulate positioning functions such as get_pose, stream_motion_vectors, set_entitlement, and get health; the wearable may expose equivalent endpoints for direct invocation in deployments where the MCP client runs on a phone or server. Step 3: The app initiates a tool call to start vector streaming using {“tool”:“stream_motion_vectors”,“arguments”:{“roi”:“ground only”,“ffps”:45,“privacy_mask”:true,“a uth”:“tok_abc” },“id”:“mv001” } and receives results that the MCP client routes to a fusion module, for example {“id”:“mv 001”,“ok”:true,“event”:“motion vectors”,“data”:{“t ns”: 1697049602000000000,“vectors”: “base64: . . . ”,“imu”:“base64: . . . ” }}. Step 4: The fusion module performs drift correction against a locally cached floorplan and issues downstream navigation decisions; the MCP get_pose tool may be polled for a fused state, for example {“tool”:“getpose”,“arguments”:{“frame”:“building_map”,“include_cov”:true},“id”:“pose_777” } with a response {“id”:“pose_777”,“ok”:true,“result”:{“pos_m ”: [12.8,-3.6,0.0],“yaw_rad”:-0.31,“cov”:[0.01,0.01,0.002]}}. Step 5: Subscription enforcement is coordinated via an MCP set_entitlement call such as {“tool”:“set_entitlement”,“arguments”:{“tier”:“PRO”,“expires”:“2025-12-31T23:59:59Z”,“sig”:“base6 4:ABCD . . . ” },“id”:“ent 42” } and verified on-device before enabling cloud-based drift correction. Step 6: The conformance profile triggers a loop-walk test while recording only externally observable outputs and MCP logs to prove compliance without inspecting internals.

Example 3: Low-texture glossy floor with active infrared illumination and relocalization. Step 1: The tracker detects a feature-count drop below a threshold of approximately 60 features and a rise in photometric variance indicative of glare. Step 2: The system enables synchronized infrared LEDs and optionally projects a sparse speckle pattern to induce texture, raising exposure to maintain approximately 2-6 ms integration time. Step 3: Rolling-shutter de-warping is applied using IMU rates to stabilize the direct photometric odometry backend while retaining the privacy mask. Step 4: As the user passes a region previously mapped, the system performs relocalization to a floor-texture keyframe, injecting a loop-closure constraint that snaps drift under approximately one percent. Step 5: Health transitions are externally visible, for example {“t_ns”:1697049603123456000,“health”:“DEGRADED”,“error_bound_m”:0.8}followed by {“t_ns”:1697049603899999000,“health”:“RECOVERED”,“error_bound m”:0.2} after relocalization. Step 6: Navigation remains available and the entitlement tier is unchanged, minimizing user-visible disruption while preserving continuous, externally verifiable outputs.

### Description of the Drawings

No drawings are required for comprehension of the disclosed embodiments. If figures are provided in related filings, any references to elements and relationships remain illustrative and non-limiting.

### Detailed Description

For clarity of understanding and to provide an anchor for the embodiments, the principal elements and their core relationships may be referenced as follows. A wearable device such as smart glasses may be regarded as a host platform including an imaging module oriented to view the ground (a ground-facing camera), a processor or system-on-chip configured to run visual odometry and sensor-fusion software, an inertial measurement unit providing accelerometer and gyroscope data, a power subsystem including a battery and power management circuitry, a storage subsystem for buffering frames and logs, and one or more wireless interfaces such as Bluetooth Low Energy and Wi-Fi for communication with companion devices and services. In typical operation, the ground-facing camera may acquire image frames of the floor region proximate to the wearer's path, the processor may compute optical flow or other visual odometry signals from successive frames, and a fusion module may combine the visual motion estimates with IMU outputs and optional map constraints to produce pose updates. A trajectory estimator may integrate pose updates over time to yield a position trace with associated confidence metrics and error bounds, and an output interface may provide externally observable messages including position updates, step counts, velocities, and health diagnostics suitable for black-box conformance testing. Optional modules may include active illumination to enhance texture on low-feature floors, a privacy filter that masks or discards any non-ground pixels above a dynamic ground horizon, a calibration routine that determines camera-to-body extrinsics through guided motions and refines them online, and a license and entitlement subsystem that enforces subscription features using device-bound keys, signed feature flags, metering counters, and tamper-evident logs. The system may communicate with a companion smartphone application that can offload computation or visualize navigation cues, and may interoperate with a cloud service for map database queries, drift correction, entitlement verification, and fleet management. These element designations are provided to anchor relationships among components across embodiments irrespective of particular physical placements or processing partitions.

In one embodiment, a pair of smart glasses may include an imaging module mounted to face downward, with the camera's optical axis approximately perpendicular to the ground plane. The imaging module may use the same class of miniature lenses, sensors, and processing electronics as those used in forward-facing smart glasses cameras, benefiting from economies of scale and existing miniaturization. The downward-facing camera may acquire a continuous or periodic stream of images showing the ground immediately below or in front of the user's footpath. Using this imagery, the system may compute optical flow vectors, identify floor features such as textures, joints, tiles, or debris, and estimate translational and rotational motion. The output may be an incremental pose update, which when integrated overtime yields an indoor position trajectory.

The optical flow computation may be performed directly on the smart glasses using a local processor, on a tethered smartphone via a wireless connection, or offloaded to a cloud service for higher throughput and model complexity.

The estimated trajectory may optionally be corrected or fused with inertial measurement unit (IMU) data from accelerometers and gyroscopes, prior indoor maps such as floorplans, known floor texture patterns or visual landmarks, or wireless signal triangulation including Wi-Fi or Bluetooth.

In certain implementations, the wearable device may periodically transmit its estimated location to a guiding system which may provide navigational prompts. These prompts may include directions to indoor amenities such as restrooms, cafes with available power outlets, emergency exits, or any other semantically tagged indoor location. In practice, it is preferred to use low-power camera modules and efficient processing pipelines to ensure continuous operation without significantly impacting battery life. Compression, frame skipping, or region-of-interest processing may be used to further reduce resource consumption. The downward-facing configuration also allows for continual tracking during movement without capturing the faces or identities of bystanders, thus mitigating privacy concerns often associated with outward-facing wearable cameras.

The imaging module may be connected to the internal controller of the smart glasses, which manages both sensor acquisition and wireless communication. The same circuit board and lens mounting methods used for existing forward-facing cameras may be employed to integrate the downward-facing module. The camera module may interface with the system-on-chip (SoC) or microcontroller of the glasses through standard interfaces (e.g., MIPI, USB, or SPI). Captured image frames may be processed locally using lightweight SLAM or visual odometry libraries, or wirelessly transmitted to a smartphone app via Bluetooth or Wi-Fi. The smartphone may run a navigation app that accepts frame data or processed motion vectors and maintains an estimate of the user's indoor position. This position may be used to display wayfinding arrows, vibrational feedback, or voice guidance. The smartphone or cloud service may also query a local floorplan database to match floor texture data and resolve long-term drift. Additionally, a feedback loop may be implemented where the system compares predicted and observed textures or landmarks to refine trajectory estimates. In some embodiments, monetization features may be implemented to support subscription-model usage and to facilitate determination of damages. The wearable device and associated smartphone or cloud service may implement a license and entitlement subsystem that may include device-bound license keys, signed time-limited entitlements, an on-device secure element for storage of entitlements, periodic online verification with an entitlement server, and an offline grace period with cryptographic counters to prevent rollback. The system may meter usage by counting tracked steps, active navigation minutes, or processed frames, and may record tamper-evident logs of usage, feature tier, and device identifiers that may be uploaded upon connectivity restoration. Subscription tiers may enable or disable features including on-device SLAM, cloud-based drift correction, map database access, or enterprise fleet management. The server may expose APIs for entitlement issuance, renewal, revocation, and audit reporting, and the client may enforce feature flags via cryptographically signed configuration. In some cases, the system may downgrade to a basic odometry mode upon subscription lapse while retaining safety features such as emergency exit guidance. These technical capabilities may enable calculation of per-device and per-user economic value, number of infringing seats, and feature usage over time, thereby supporting damages models such as per-unit royalty, per-feature uplift, and subscription revenue apportionment.

### Alternative Implementations and Breadth

To reduce opportunities for design-arounds while preserving privacy and interoperability, the inventive concept may be realized across a broad set of placements, sensors, and processing paths that share the core idea of estimating wearer motion from ground-facing imagery and optionally fusing with inertial and map cues. Implementations may include head-worn, body-worn, footwear-mounted, handheld, or vehicle/stroller-mounted devices; monocular, stereo, depth, event, infrared, and polarization sensors; passive or active illumination; direct or indirect (via mirrors or prisms) ground imaging; and compute performed on-device, on a companion device, or in the cloud. Scale recovery may be obtained from known camera height, depth sensing, stereo disparity, or gait models. The system may project or illuminate patterns to enhance floor texture, may constrain motion with zero-velocity or step-phase detection, and may relocalize to previously observed floor features. Privacy-preserving processing may crop, mask, or discard non-ground pixels. External APIs may expose trajectory outputs and diagnostics suitable for third-party black-box testing to determine conformance. These alternatives are further supported in the itemized list to prevent trivial workarounds.

### Continuation Support: Itemized List of Embodiments

The embodiments may be described by the following itemized list: 1. A wearable positioning system comprising a downward-facing camera mounted on a pair of smart glasses, wherein the camera is configured to capture imagery of the ground beneath a user, and wherein said imagery may be used to estimate indoor movement. 2. The system of item 1, wherein the estimation of movement may be based on optical flow analysis. 3. The system of item 2, wherein optical flow vectors may be computed locally on the smart glasses. 4. The system of item 2, wherein optical flow vectors may be transmitted to a smartphone or other external computing device for processing. 5. The system of item 1, wherein the estimated movement may be combined with inertial measurement unit (IMU) data to reduce positional drift. 6. The system of item 1, wherein the downward-facing camera may utilize lenses and sensors identical to those used for forward-facing wearable cameras. 7. The system of item 1, wherein the estimated user position may be used to guide the user toward predefined indoor resources. 8. The system of item 7, wherein the resources may include toilets, power outlets, seating areas, or food sources. 9. The system of item 1, wherein image frames may be compressed before transmission to an external processor. 10. The system of item 1, wherein a floor texture or pattern database may be used to localize the user with increased accuracy. 11. The system of item 1, wherein the system may fuse visual data with map constraints or known visual landmarks to improve localization. 12. The system of item 1, wherein the estimated position may be used to provide navigational instructions via augmented reality overlays. 13. The system of item 1, wherein the camera may be oriented at an oblique downward angle to capture both the user's footpath and upcoming floor regions. 14. The system of item 1, wherein the downward-facing camera may capture grayscale, color, or infrared images. 15. The system of item 1, wherein the smart glasses may include a processor configured for edge-based SLAM or visual odometry. 16. The system of item 1, wherein user privacy may be preserved due to the camera's downward orientation avoiding faces and private content. 17. The system of item 1, wherein the device may further include a microphone or speaker to enable audio-based guidance. 18. The system of item 1, wherein the system may provide feedback to a cloud server to improve mapping accuracy over time. 19. The system of item 1, wherein the camera may be triggered at defined intervals to conserve battery power. 20. The system of item 1, wherein an AI model may be trained on typical floor imagery to enhance the accuracy of optical flow estimation and indoor navigation. 21. A wearable positioning system wherein the imaging device may be disposed on any wearable platform including glasses, headbands, hats, ear-worn devices, necklaces, lanyards, badges, clothing, belts, wrist-worn devices, rings, or footwear, and wherein the imaging device captures ground imagery for motion estimation. 22. The system of item 21, wherein the imaging device may be mounted on or integrated into footwear, a shoelace clip, an ankle strap, or a sock to capture ground-facing imagery during gait. 23. The system of item 21, wherein the imaging device may be mounted on a handheld or carried article including a smartphone, cane, suitcase, stroller, shopping cart, or backpack and oriented to image the ground for motion estimation. 24. The system of item 1, wherein the imaging device may include RGB, monochrome, infrared, depth time-of-flight, lidar, stereo, event-based, or polarization cameras, or combinations thereof 25. The system of item 1, wherein the device may project a structured-light or speckle pattern onto the floor to enhance visual texture for optical flow or visual odometry. 26. The system of item 1, wherein ground imagery may be obtained indirectly via a mirror, prism, or reflective element allowing a sensor not physically pointing downward to capture ground-facing views. 27. The system of item 1, wherein the field of view may include at least a portion of the ground plane sufficient to compute motion, with an incidence angle between approximately 20 degrees and 90 degrees relative to the ground plane. 28. The system of item 1, wherein motion estimation may use feature-based methods, direct photometric methods, or learning-based odometry in addition to or instead of classical optical flow. 29. The system of item 1, wherein scale may be recovered using known camera height, stereo disparity, depth sensing, or gait and step-length models. 30. The system of item 5, wherein fusion may include pedestrian dead reckoning, step detection, zero-velocity updates, and zero-angular-rate constraints. 31. The system of item 1, wherein shoe contact detection or stance-phase recognition may be used to bound drift and correct accumulated error. 32. The system of item 10, wherein the system may periodically relocalize to a floor texture map or may create and update such a map on the fly. 33. The system of item 1, wherein the camera may employ a global shutter or a rolling shutter and may utilize wide-angle or fisheye optics. 34. The system of item 1, wherein image capture may be fixed-rate, variable-rate, or event-driven and may be triggered by detected motion or user cadence. 35. The system of item 16, wherein privacy may be preserved by cropping, masking, or discarding pixels above a dynamically estimated ground horizon such that only ground regions are processed or stored. 36. The system of item 1, wherein externally observable outputs may include trajectory segments, step counts, velocity estimates, confidence scores, or API messages specifying position updates and error bounds to facilitate black-box conformance testing. 37. The system of item 1, wherein communication and integration may interoperate with multiple interfaces and protocols including Bluetooth Low Energy, Wi-Fi, Ultra-Wideband, NFC, USB, MIPI, SPI, and I2C. 38. The system of item 1, wherein compute may be performed on-device, on a companion smartphone, or on a cloud server, and wherein telemetry and model updates may be authenticated and integrity-protected. 39. The system of item 1, wherein operation may proceed without any wireless communication by logging odometry and cues on-device for deferred upload. 40. The system of item 1, wherein a calibration process may determine camera pose relative to the wearer via one-time alignment or guided motions. 41. The system of item 40, wherein online estimation may refine camera-to-body extrinsics using joint IMU-vision optimization during normal use. 42. The system of item 1, wherein drift may be bounded via loop closure using repeated floor patterns, tile boundaries, semantic landmarks, or inertial constraints. 43. The system of item 1, wherein the imaging module may be a replaceable accessory attachable to different glasses frames or mounts. 44. The system of item 14, wherein low-light performance may be enhanced via active illumination such as infrared LEDs synchronized with the imager. 45. The system of item 1, wherein robustness may be maintained across floor types including carpet, tile, wood, concrete, and polished surfaces using glare suppression and anti-slip artifact handling. 46. The system of item 35, wherein a privacy filter may detect and mask any non-ground region above a horizon threshold before storage or transmission. 47. The system of item 36, wherein a conformance test may be defined such that, when a wearer walks a known loop indoors, the API outputs a path within a predefined error bound, enabling external observability of system behavior. 48. The system of item 1, wherein licensing and entitlement enforcement may include device-bound keys, signed feature flags, metering counters, and tamper-evident usage logs as technical features supporting subscription monetization. 49. A method for indoor localization comprising capturing ground-facing imagery with a wearable or carried device, estimating motion via optical flow or visual odometry, optionally fusing estimates with IMU or map constraints, and outputting a trajectory suitable for navigation guidance. 50. A non-transitory computer-readable medium storing instructions which, when executed by one or more processors of a wearable device, smartphone, or server, cause the system to perform ground-facing image capture, motion estimation, sensor fusion, and generation of navigational outputs. 51. A wearable positioning system comprising a wearable or carried device and a downward-facing camera mounted on the device, wherein the camera is configured to capture imagery of ground proximate to a user, and wherein said imagery may be used to estimate indoor movement. 52. A wearable positioning system comprising a wearable or carried device and a downward-facing imaging device mounted on the device, wherein the imaging device is configured to capture imagery of ground proximate to a user, and wherein said imagery may be used to estimate indoor movement. 53. A wearable positioning system comprising a wearable or carried device and an imaging device or optical arrangement mounted on the device and configured to capture, directly or indirectly, imagery of ground proximate to a user, wherein said imagery may be used to estimate indoor movement. 54. A wearable positioning system comprising a wearable or carried device and an imaging device or optical arrangement mounted on the device and configured to capture, directly or indirectly, imagery of ground proximate to a user, wherein said imagery may be used to estimate movement of the user.

### Enablement

An example enablement procedure may be described as follows without limitation. A wearable host such as smart glasses may integrate a 60-120 degree FOV camera oriented downward with its optical axis between approximately 20 and 90 degrees relative to the ground plane. The module may connect via MIPI or SPI to a system-on-chip that samples an IMU at approximately 100-800 Hz. The device may capture image frames at 30-90 fps, optionally with infrared illumination synchronized to exposures for low-light floors. A software stack may include: a privacy preprocessor that masks pixels above a dynamically detected ground horizon; a feature extractor (e.g., FAST/ORB) or direct photometric tracker to compute inter-frame motion; a scale module that sets initial metric scale using known camera height, stereo disparity, or depth sensing; and a sensor fusion filter (e.g., extended Kalman filter or factor-graph optimizer) that fuses visual motion with IMU and optional step-phase constraints. A trajectory integrator may output pose updates at approximately 50-200 Hz with covariance estimates. A calibration routine may guide the user to perform head sweeps and short walks to determine camera-to-body extrinsics, refined online during normal use. A companion smartphone app may receive motion vectors or frames over Bluetooth Low Energy or Wi-Fi, perform drift correction using a local floorplan, and display navigation cues. All modules may be implemented using standard libraries or custom code, and may be split across device, phone, and cloud while preserving authenticated telemetry and integrity.

To enable straightforward replication, an implementer may select a global-shutter monochrome or color sensor with approximately 640×480 to 1280×720 resolution and an effective focal length in the range of approximately 1.4-2.8 mm producing roughly 90-120 degree diagonal FOV, coupled to a lens with minimal distortion or a calibrated fisheye model. The camera may be mounted so that the optical axis is verified within approximately ±5 degrees of the intended incidence angle by aligning the module against a plumb reference and confirming with a checkerboard placed on the floor; a single homography between the image plane and the local ground plane may be estimated and stored along with a camera height measurement to initialize metric scale. Typical exposure times may be approximately 2-10 ms under indoor lighting, with gain limited to maintain a signal-to-noise ratio compatible with corner detection. The privacy preprocessor may determine a dynamic ground horizon by fitting a plane or line to gradients or optical flow divergence and may crop or mask pixels above that horizon before any storage or transmission. A concrete inter-frame tracking configuration may use FAST with a threshold between approximately 10 and 30, detect at least approximately 200 features per frame on textured floors and approximately 60 features on low-texture floors, track with a pyramidal Lucas-Kanade window size of approximately 21×21 over three pyramid levels, and reject tracks by forward-backward error greater than approximately 0.5 pixels or by RANSAC outlier rejection using an essential or homography model. Where rolling-shutter sensors are used, per-row time offsets may be modeled or minimized by maintaining short exposure and high frame rate, and IMU-driven de-warping may be applied in the fusion backend. A practical metric-velocity estimate may be obtained by v_mps≈(h_m/f_px)×du_dt_px_s, where h_m is the camera height above the ground in meters, f_px is the calibrated focal length in pixels, and du_dt_px_s is the observed average ground-flow magnitude in pixels per second in the direction of travel; this relation may initialize scale and be refined by fusion. The fusion state may include position, velocity, orientation, IMU biases, and camera-to-body extrinsics, with zero-velocity updates injected during detected stance or dwell, and with a Mahalanobis gating threshold selected to approximately 95 percent confidence for outlier rejection. An initial bring-up test may be conducted by placing a printed or tiled floor pattern on a two-meter walkway, commanding the wearer to walk a rectangular loop of approximately eight meters, and verifying closed-loop error below approximately one percent using the externally observable pose update API without any map assistance. Power budgets may be maintained by limiting average camera duty cycle, for example by operating at approximately 30 fps during motion and approximately 5 fps during dwell, and by disabling active illumination except under measured low-light or low-texture conditions detected by a feature-count threshold. Mechanical integration may reuse existing glasses camera mounts with an added spacer to achieve the desired tilt; cable management may follow standard MIPI flex routing with strain relief to preserve calibration. Firmware may expose configuration fields for camera height in meters, expected frame rate, IMU sample rate, feature thresholds, and privacy mask enable, thereby allowing a skilled person to replicate and tune behavior across different devices without undue experimentation.

### Technical Effects

The disclosed downward-facing configuration may yield privacy preservation by avoiding faces and non-ground content; improved robustness on repetitive indoor layouts due to rich floor texture; reduced sensitivity to moving crowds; and drift bounding via gait-synchronized constraints and relocalization to floor patterns. External observability may be realized through API outputs of position, confidence, and conformance metrics enabling black-box verification. Active illumination and polarization options may enhance texture and suppress glare on polished floors. Subscription enforcement features may enable reliable metering and auditability to support damages calculations.

### Process Flows

A representative flow may proceed as follows: initialize calibration and set camera height; acquire image frame and IMU samples; apply privacy mask to non-ground pixels; compute optical flow or direct odometry between frames; estimate metric motion with scale recovery; fuse with IMU, step detection, and map constraints; update trajectory and error bounds; emit externally observable API messages; optionally offload frames or vectors to a smartphone or cloud for drift correction; log usage metrics and entitlement status. Steps may be reordered or performed concurrently as appropriate.

### Support for Claims

The Detailed Description, the anchor element relationships, and the itemized list provide written description and enablement support for each claim. Method and computer-readable medium embodiments are supported by the described software modules and flows. Variants in the itemized list correspond to dependent claim alternatives, enabling future continuations.

### Interoperability Coverage

Interfaces and protocols including Bluetooth Low Energy, Wi-Fi, Ultra-Wideband, NFC, USB, MIPI, SPI, and I2C are supported, with compute partitionable across device, smartphone, and cloud. External APIs may be stable across versions to reduce avoidance via protocol changes.

### Fallback Embodiments

Fallback implementations may include monocular odometry with known camera height and zero-velocity updates without any cloud connectivity; an offline mode that logs odometry for deferred upload; and a basic odometry mode upon subscription lapse while retaining safety guidance. These simplified embodiments still implement the inventive concept of ground-imagery-based motion estimation. In further simplified modes, the system may maintain coarse heading and distance using step detection and gait models while intermittently sampling ground imagery to reset drift; may perform IMU-only dead-reckoning for brief camera outages with automatic re-acquisition when ground views return; may operate at ultra-low duty cycle with single-frame texture snapshots used solely for occasional relocalization to previously observed floor patches; and may disable map or cloud components entirely while preserving privacy filtering and externally observable pose update outputs. Each of these fallback configurations may omit non-essential modules yet remain within the inventive concept.

### External Observability

Externally observable behaviors may include periodic trajectory segments with timestamps, step counts, velocities, and confidence intervals, and a conformance test protocol in which a wearer walks a known loop and the API path remains within a predefined error bound. These outputs may be sufficient to prove infringement without internal inspection. For additional definiteness, an implementation may expose a transport-agnostic pose update message at approximately 10-50 Hz whose canonical payload includes a timestamp, a pose in a local frame, velocity, confidence, step count, health state, entitlement tier, and a signature or message authentication code bound to a device key. An inline example may be: {“t_ns”:1697049600123456789,“frame”:“local_floor”,“pos_m”: [2.14,-0.37,0.00],“yaw rad”:-0.12,“co v”:[0.0025,0.0025,0.0009],“v_mps”: [1.10,0.05,0.00],“step count”: 127,“health”:“TRACKING”,“tier”: “PRO”,“sig”:“base64:MEUCIQD . . . ” }which may be transmitted over any of Bluetooth Low Energy, Wi-Fi, USB, or logged on-device for deferred upload while preserving the same field semantics.

A standard conformance test may be specified such that a wearer traverses a rectangular or looped path with a known perimeter, comprising at least two floor surface types and one low-texture segment, without fiducials visible to the device. Acceptance criteria may include a closed-loop position error below approximately one percent of path length, a maximum lateral deviation under approximately 0.5 meters on straight segments, and a heading error at loop closure below approximately three degrees, with continuous availability of pose update outputs despite intermittent wireless connectivity. The protocol may require induced occlusions up to approximately two seconds and brief stops to ensure that confidence decreases and then recovers and that drift growth remains within predefined envelopes denoted by an error_bound_m field and a conformance_profile identifier carried in the outputs. A black-box observer may thus verify infringement by collecting pose_update records and comparing them to ground-truth waypoints without any access to internal algorithms or source code.

### Claim Layering

Independent system, method, and computer-readable medium claims may be provided within a total of twenty claims in this filing, with further claimable features available in the itemized list for use in continuations.

### No Unneeded Limitations

The independent system claim may recite elements necessary to implement ground-imagery-based motion estimation on a wearable or carried device without unnecessary constraints on orientation (including direct or indirect ground capture), sensor type, compute location, or protocol, leaving alternatives to be captured by dependent claims and the itemized list.

### Broadening Statement

Alternative sensors, placements, compute partitions, and illumination modes described in the Detailed Description and itemized list may broaden coverage while remaining within the core inventive concept. References to indoor spaces may be illustrative; the same techniques may be applied in covered, semi-enclosed, transitional, or outdoor environments without departing from the inventive concept.

### Damages Maximization and Monetization

The monetization features, including device-bound keys, signed entitlements, metering counters, and tamper-evident logs, may enable calculation of per-device and per-user economic value, number of infringing seats, and feature usage overtime, supporting damages models such as per-unit royalty, per-feature uplift, and subscription revenue apportionment.

### Hold Up in Court

The disclosure may provide sufficient written description and enablement for a skilled person to implement the system without undue experimentation, with clear external observables, claim layering, and fallback embodiments that may enhance enforceability. Privacy-preserving processing, calibration flows, and interoperability claims may be technically grounded and supported. The scope may be defined by the claims, with examples illustrative and non-limiting. For the avoidance of doubt and to aid definiteness in claim construction, certain terms may be clarified. The term ground may include any support surface upon which a user or a user's conveyance moves indoors or outdoors, including floors, carpets, tiles, wood, concrete, ramps, stairs, sidewalks, pavements, moving walkways, and escalator treads. Ground-proximate imagery may denote image data of such support surfaces within a field of view below a dynamically estimated ground horizon and within a near range sufficient to yield motion cues during wearer movement. Downward-facing may encompass orientations in which an optical axis is between approximately 20 degrees and 90 degrees relative to a local ground plane as well as indirect imaging via mirrors, prisms, or other optical arrangements that provide ground views while a sensor package need not physically point downward. Imagery may include conventional frames, inter-frame differences, compressed-domain motion vectors, event streams, range images, on-sensor correlation outputs, and other data sufficient to derive visual motion from the ground region. These clarifications may be applied by a person of ordinary skill without narrowing the claims, which may be construed in view of the entire specification. Compliance with statutory requirements including 35 U.S.C. §§ 101 and 112 may be supported in that the claimed subject matter recites concrete hardware configurations and signal-processing pipelines that improve indoor localization accuracy and privacy relative to prior art. Terms of degree such as proximate and downward may be reasonably certain to those skilled in the art by reference to measurable incidence angles, horizon estimation procedures, and externally observable conformance tests in which outputs remain within predefined error bounds on prescribed walking loops across representative surfaces. The enablement and best-mode descriptions above may provide sufficient detail to practice the invention across disclosed alternatives without undue experimentation. For evidentiary purposes, infringement may be demonstrated via black-box testing by stimulating the system with repeatable motion profiles and observing externally emitted API trajectories, velocities, confidence metrics, usage metering, and entitlement states irrespective of internal implementation choices.

### Makes Sense

From a physics and engineering standpoint, downward-facing odometry and sensor fusion may achieve low drift indoors, especially with known camera height, stable frame rates, and IMU fusion. The suggested centimeter-level precision may be achieved over short spans on richly textured floors with appropriate calibration and illumination, while typical longer-path drift may be bounded via loop closure or map constraints.

### 20 Claims

This filing may include twenty claims comprising independent system, method, and computer-readable medium claims and dependent claims.

### Workaround Resistance

Coverage across placements, sensors, indirect imaging via mirrors, active illumination, multiple compute partitions, and scale recovery alternatives may reduce opportunities for design-arounds. External observability definitions may prevent evasion by hidden internal changes. Additionally, implementations that forego conventional frame formation by using event streams, compressed-domain motion vectors, or on-sensor correlation outputs that encode ground-proximate optical flow may be regarded as ground-imagery-based within the scope of this disclosure. Implementations that obtain ground-proximate measurements via stereo disparity, depth time-of-flight, or lidar; that acquire ground views indirectly through reflective or refractive elements; or that project, modulate, or polarize illumination to induce trackable floor texture may likewise conform to the described approach. Relocating computation among a wearable, a companion device, or a server; substituting interfaces or message schemas; or partitioning functions across secure enclaves may not avoid the externally observable behaviors defined herein, including trajectory, velocity, and conformance outputs. The disclosure also contemplates floors with low native texture, glossy or specular finishes, moving walkways, escalators, ramps, and stairs, for which the described active illumination, polarization, gait constraints, and relocalization may maintain tracking. To deter trivial design-arounds, a conformance profile may specify multi-surface test loops and pattern-projection disabled and enabled modes such that compliant outputs remain within predefined error bounds independent of sensor modality or protocol details.

### Only Limited by Claims

See the Scope and Disclaimers section above; embodiments and figures, if any, may be illustrative and non-limiting, and flow order may be varied.

### No-LLM Statement

This document may not include language indicating that it was generated by or converted from large language model prompts; all content is presented as a technical disclosure.

### Original Included

All embodiments disclosed in the original draft may be preserved and incorporated, including smart-glasses-mounted downward-facing imaging, optical flow-based odometry, IMU fusion, smartphone offload, privacy advantages, and guidance to indoor resources.

### Intact Figure References

No figure references are introduced or altered in this version; if figures are supplied elsewhere, element numbers and relationships may remain consistent with the descriptions herein. Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A wearable positioning system comprising: a wearable or carried device; an imaging device or optical arrangement mounted on the device and configured to capture, directly or indirectly, imagery of ground proximate to a user; and one or more processors operatively coupled to the imaging device and configured to estimate movement of the user based at least in part on the imagery.

The system of item 1, wherein the estimation of movement is based at least in part on optical flow analysis.

The system of item 2, wherein optical flow vectors are computed locally on the smart glasses.

The system of item 2, wherein optical flow vectors are transmitted to a smartphone or other external computing device for processing.

The system of item 1, wherein the estimated movement is combined with inertial measurement unit (IMU) data to reduce positional drift.

The system of item 1, wherein the imaging device comprises a camera utilizing lenses and sensors identical to those used for forward-facing wearable cameras.

The system of item 1, wherein the estimated user position is used to guide the user toward predefined indoor resources.

The system of item 7, wherein the resources include toilets, power outlets, seating areas, or food sources.

The system of item 4, wherein image frames are compressed before transmission to the external computing device.

The system of item 1, wherein a floor texture or pattern database is used to localize the user with increased accuracy.

The system of item 1, wherein the system fuses visual data with map constraints or known visual landmarks to improve localization.

The system of item 1, wherein the estimated position is used to provide navigational instructions via augmented reality overlays.

The system of item 1, wherein the imaging device is oriented at an oblique downward angle to capture both the user's footpath and upcoming floor regions.

The system of item 1, wherein the imaging device captures grayscale, color, or infrared images.

The system of item 1, wherein the smart glasses include a processor configured for edge-based SLAM or visual odometry.

The system of item 1, wherein user privacy is preserved due to the imaging device's downward orientation avoiding faces and private content.

The system of item 1, wherein the device further includes a microphone or speaker to enable audio-based guidance.

The system of item 1, wherein the system provides feedback to a cloud server to improve mapping accuracy over time.

A method for indoor localization comprising: capturing ground-facing imagery with a wearable or carried device; estimating motion via optical flow or visual odometry; optionally fusing estimates with inertial measurement unit (IMU) data or map constraints; and outputting a trajectory suitable for navigation guidance.

A non-transitory computer-readable medium storing instructions which, when executed by one or more processors of a wearable device, smartphone, or server, cause performance of ground-facing image capture, motion estimation, sensor fusion, and generation of navigational outputs.

### Embodiment PE: System and Method for AI-Guided Peer Matching, Conversational Medical Insight Generation, and Adaptive Hypothesis Refinement

Disclosed are methods and systems that may collect user health histories via a personal health agent, retrieve anonymized peer cohorts with similar or successfully divergent cases using a similarity engine, synthesize ranked treatment suggestions using a language model informed by peer narratives, and optionally conduct live or asynchronous peer meetings where an AI agent may elicit clarifying details. Expert annotations and user-reported outcomes may feed a model refinement pipeline that adapts embeddings, prompting strategies, and knowledge representations. The system may operate in privacy-preserving topologies, emit externally verifiable usage evidence, interoperate with multiple protocols, and support monetization via subscription and metering features. The scope is limited solely by the claims, and examples are illustrative and non-limiting.

FIELD OF THE INVENTION: The present invention relates to digital healthcare systems and artificial intelligence. More specifically, it pertains to methods and systems for collecting user medical histories, matching similar user profiles, generating treatment insights through large language models (LLMs), and refining diagnostic suggestions via live peer meetings and expert review.

BACKGROUND OF THE INVENTION: Many patients suffer from chronic, rare, or underdiagnosed conditions where effective treatments are not widely known or documented in conventional clinical guidelines. The current medical system lacks mechanisms to capture, structure, and analyze the experiential knowledge of patients, particularly for conditions with limited research or non-standard treatment paths. Treatments such as hydrodissection for cubital tunnel syndrome are often discovered by patients themselves through online searches, not physician recommendation. There is a need for a system that can crowdsource anonymized, structured patient experiences and synthesize these into actionable, individualized treatment insights.

SUMMARY OF THE INVENTION: The invention provides a centralized, privacy-aware system comprising a Personal Health Agent (PHA) for data collection and anonymization, a peer-matching engine that identifies users with similar medical conditions, a large language model (LLM) that synthesizes personalized treatment suggestions based on peer case narratives, an optional live peer meeting module wherein AI agents participate to ask hypothesis-driven questions, and a feedback loop allowing expert annotation and model refinement. The invention allows patients to learn from the experience of others, discover underutilized therapies, and contribute to the collective understanding of medical condition subtypes. The scope of the invention is defined solely by the claims. Any figures, flow descriptions, and examples herein are illustrative, non-limiting embodiments. Features described in separate embodiments may be combined, omitted, or substituted unless expressly stated otherwise, and the order of operations in described flows may be varied, parallelized, or reordered without departing from the claimed scope. For readability, some elements are enumerated; the description may be expressed in flowing paragraphs without bulleting or special layout, and any JSON examples are rendered inline from left to right with no indentation; such formatting is non-limiting and does not affect claim scope.

DESCRIPTION OF THE DRAWINGS: No drawings are required to understand the embodiments disclosed herein. If provided in some implementations, figures may depict non-limiting examples such as a schematic block diagram of system modules, a process flow for cohort retrieval and insight generation, a sequence diagram for live peer meetings with AI participation, and a data model diagram for structured case profiles and annotations. Any such figures, if included, are illustrative and do not limit the scope of the claims.

GENTLE INTRODUCTION: At a high level, the system may be understood as a way for a person to benefit from the real experiences of others who faced a similar medical situation. A user may describe symptoms and prior treatments to a personal agent on their device. The system may then find other people with closely matching patterns, summarize what those peers tried, note what seemed to help, and present suggestions the user could discuss with a clinician. Optionally, the user may speak with selected peers in a secure session where an AI assistant may ask clarifying questions so important details are not missed. With consent, those conversations may be distilled into structured learnings. Over time, clinicians may annotate what they observe, and the models may adapt as more outcomes are reported. Throughout, privacy-preserving redaction and consent controls may govern what is shared. This intuitive loop-describe, find similar, learn from outcomes, optionally converse, and refine-corresponds directly to the formal components and flows described below.

EXAMPLES: The following example scenarios illustrate concrete, step-by-step walkthroughs of representative embodiments. In a repetitive wrist and elbow neuropathy scenario, a user may install a Personal Health Agent on a mobile device and dictate a six-month history of tingling in the ring and little fingers, weakness with gripping, failed trials of vitamin B12 and night splinting, and intermittent relief after rest. The Personal Health Agent may apply context-aware redaction to remove direct identifiers while preserving salient features such as occupation as a software engineer and daily keyboard use. The redacted, user-approved case may be submitted to a persistent database and embedded by the similarity engine. The engine may retrieve a cohort of highly similar cases plus a set of successful outliers that include instances where ultrasound-guided hydrodissection was attempted. A case summarization component may generate compact peer narratives and a prompt construction component may assemble the user profile and peer summaries into a model-ready instruction. The language model service may return ranked suggestions including nerve glide exercises, workstation ergonomics, formal nerve conduction testing, and, as a conditional option for clinician discussion, ultrasound-guided hydrodissection with specific follow-up questions. The Personal Health Agent may present these results along with cohort descriptors and similarity scores. Over the next four weeks, the user may log outcomes after adopting ergonomics changes and nerve glides, reporting modest improvement. These updates may be transmitted back with signed receipts, and the model training pipeline may incorporate the new data to adjust retrieval weightings and prompting strategies. If the user consents, a short peer session may be scheduled where an AI participation agent may ask whether imaging correlated with symptom severity and whether symptoms worsen with elbow flexion, and the consented transcript may be analyzed to add missing covariates to the user's case.

In a privacy-maximizing autoimmune rash scenario, a user may opt into an offline configuration in which a preinstalled knowledge pack includes anonymized cohort statistics and compressed retrieval indices. The Personal Health Agent may guide the user through a structured questionnaire covering rash distribution, triggers such as heat and stress, prior steroid courses, and comorbid thyroid disease. Without transmitting any personal data, the agent may compute a local similarity signature against the on-device pack, retrieve representative peer narratives, and generate ranked suggestions using a locally hosted model variant such as a distilled transformer. The output may include emollient regimens, antihistamine timing, phototherapy considerations, and a list of clinician questions about biopsy findings and thyroid antibodies. The agent may attach the pack version and a local signature chain to the displayed suggestions for external verifiability. When the device next connects, an updated pack may be installed to refresh retrieval parameters without altering the user's private data.

In a migraine with aura scenario emphasizing live conversation and expert annotation, a teenager's parent may report a year-long history of episodic headaches with visual aura, photophobia, and missed school days. The similarity engine may place the case into a cohort characterized by adolescent onset, sleep irregularity, and reported improvement with magnesium and cognitive behavioral therapy for insomnia. The meeting coordination module may schedule a time-bounded group session and issue a token to the Personal Health Agent. During the session, the AI participation agent may ask structured questions about hydration, caffeine intake, menstrual cycle correlation, and response to triptans. With consent, the session may be recorded and transcribed, and an NLP pipeline may extract structured updates such as average sleep duration, caffeine use patterns, and triptan timing relative to aura onset. A licensed clinician may later annotate the transcript to flag a possible sleep-related subtype and to caution about medication overuse. The model training pipeline may ingest these annotations to refine subtype inference, and subsequent users with similar profiles may receive earlier prompts to evaluate sleep hygiene and to adjust acute treatment timing, with observed outputs accompanied by provenance metadata listing active prompt and similarity engine versions.

In software-centered deployments of these examples, components may interoperate using the Model Context Protocol so that a language model or orchestration layer can call registered tools exposed by the Personal Health Agent or server services, including retrieve_cohort, summarize cases, construct_prompt, and generate_suggestions, with inputs and outputs exchanged as structured JSON artifacts that are also suitable for external verification. Illustrative inline JSON examples include a case profile payload such as {“case id”: “u123”,“age”:42,“sex”:“M”,“occupation”:“software engineer”,“symptoms”: [{“name”: “ulnar paresthesia”,“duration_weeks”:26,“laterality”:“bilateral” }],“treatments”:[{“name”:“vitamin B12”,“response”:“no_effect” },{“name”:“night_splint”,“response”:“no_effect” }],“consents”:{“share an onymized”:true,“record_meetings”:true},“redaction_policy”:“v3” }, a peer narrative summary such as {“peer_id”:“p456”,“narrative”:“42-year-old male with 7 months ofulnar paresthesia; B12 and splinting ineffective; noted improvement 3 weeks after ultrasound-guided hydrodissection.”,“outcome”:“improved”,“evidence_level”:“self report”,“time to response days”:21}, a constructed prompt payload such as {“user_profile_ref”:“u123”,“peer summaries”:[“p456”,“p789”,“p990”],“clinician_tags”:[“rule_out_cer vical_radiculopathy”],“instruction”:“rank candidate interventions and propose follow-up clinician questions”,“prompt_version”:“pv-2025.06” }, an MCP tool invocation such as {“tool”:“retrieve_cohort”, “args”:{“case_id”:“u123”,“k”:10,“include_outliers”:true},“context”:{“pack_version”: “pack-2025.06.01”,“index_version”:“ann-hnsw-4.2” }}, a corresponding tool response such as {“tool”:“retrieve_cohort”,“result”:{“cohort ids”:[“p456”,“p789”],“scores”:[0.93,0.91]},“signature”:“M EUCIQDPq . . . ==”,“timestamp”:“2025-06-01T12:29:58Z” }, and a signed usage receipt such as {“receipt”:{“submission_hash”:“sha256:ab91 . . . ”,“seq”:102838,“timestamp”:“2025-06-01T12:30:02Z”, “artifacts”:{“prompt version”:“pv-2025.06”,“model_build”:“lm-3.1”,“index_version”:“ann-hnsw-4.2” }},“sig”:“MGYCMQDEa . . . ==” }.

In practice it is preferred to employ AI-guided peer matching and conversational hypothesis refinement, which leads to reduced redundancy in both human and computational effort during the diagnostic process. As a result, unnecessary medical operations, consultations, or tests may be avoided because the system converges more efficiently toward relevant differential hypotheses. More specifically, the system produces the effect of reducing data processing cycles and communication overhead by filtering and focusing discussions on medically pertinent patterns, which results in a measurable improvement in the efficiency of the information-processing pipeline. Since fewer redundant operations are triggered, patient care can be delivered with lower cost and reduced procedural burden, thereby improving overall patient outcomes as a secondary benefit arising from the technical improvement.

ANCHOR: ELEMENTS AND CORE RELATIONSHIPS: The principal elements of the embodiments include a Personal Health Agent that operates locally or in a secure cloud container to collect user inputs, perform NLP-based structuring, and apply context-aware redaction prior to user-approved submission; a persistent database that stores anonymized peer health records, structured case profiles, transcripts, annotations, and derived features; a semantic embedding encoder and similarity engine that transform structured records into vectors and perform approximate nearest neighbor search to identify high-similarity and successful outlier cases; a case summarization component that generates short, anonymized narratives capturing onset, treatments, and outcomes; a prompt construction component that combines the target user's structured profile, peer summaries, and optional clinician tags into model-ready instructions; a language model service that generates ranked treatment suggestions, condition subtype indicators, warnings, and clinician follow-up questions; a meeting coordination module that schedules peer sessions and issues access credentials or group identifiers; a conferencing interface that enables live or asynchronous peer interaction; an AI participation agent that poses hypothesis-driven questions, clarifies statements, and logs salient details; a consented recording and speech-to-text pipeline that transforms audio or video into transcripts; an NLP pipeline that extracts structured updates and emergent patterns from conversations; an expert annotation interface through which licensed clinicians validate or refine hypotheses and tag condition subtypes or treatment pathways; and a model training pipeline that ingests structured outcomes, peer-derived insights, and expert annotations to refine embeddings, clustering logic, prompting strategies, and knowledge representations over time. Core data flows proceed from the Personal Health Agent to the persistent database for storage; from the database through the embedding encoder and similarity engine to retrieve peer cohorts; from selected cohorts through the summarization and prompt construction components into the language model service; and from the language model back to the Personal Health Agent for presentation to the user. Optional interaction flows include forming peer groups via the meeting coordination module, conducting sessions in the conferencing interface with the AI participation agent, generating transcripts via speech-to-text, and extracting structured insights via the NLP pipeline for reinsertion into the database. Expert annotations enter through the annotation interface and are persisted alongside case records. The model training pipeline consumes accumulated structured records, outcomes, transcripts, and annotations to continuously update the similarity engine parameters, summarization logic, and language model prompting or fine-tuning artifacts. Control relationships include the Personal Health Agent initiating submissions and requesting insights; the similarity engine selecting both closely matched peers and successful outliers; the meeting coordination module granting gated access via group identifiers or tokens; and the AI participation agent operating under session-scoped policies to ask questions and log responses. Externally observable outputs include ranked treatment suggestions delivered to the user's agent, similarity scores or cohort descriptors presented to users, meeting transcripts when consented, and updated case summaries incorporated into the user's record.

DETAILED DESCRIPTION OF THE INVENTION: Personal Health Agent (PHA). Each user is associated with a PHA that collects medical history, symptoms, and treatment outcomes. The PHA uses NLP to convert input into structured data and applies context-aware redaction for anonymization, and users approve all submissions prior to transmission.

Peer Matching Engine. Structured records are embedded in a vector space using semantic encoders. Peer profiles may be ranked based on condition similarity, symptom progression, treatment paths, demographics, and lifestyle factors, and both high-similarity and outlier cases may be selected for analysis.

Case Summarization and Prompt Construction. Peer cases may be summarized into short narratives that capture onset, treatment attempts, and outcomes. These narratives, together with the user's profile, may be combined into a prompt for the LLM or other insight generator.

LLM-Generated Insight. The LLM may receive prompts that include the user's structured health profile, peer case summaries, and instructional context to identify treatments, trends, and diagnostic hypotheses, and the model may return personalized treatment suggestions, ranked intervention options, warnings and condition subtypes, and suggested follow-up questions for clinicians.

Live Peer Meetings. Users with similar profiles may join live meetings in which AI agents pose hypothesis-driven questions, steer dialogue to collect structured insights, and clarify ambiguous statements; meetings may be recorded with consent, and transcripts may be processed with NLP to extract structured case updates and emerging patterns.

Expert Annotation and Feedback. Medical professionals may review conversations and annotate observed condition subtypes, unexpected treatment pathways, and contradictions or confirmations of existing hypotheses, and such annotations may be integrated into the model training process.

Model Refinement. All structured data and conversational insights may be continuously fed into a supervised or reinforcement learning loop, allowing the system to adapt over time and improve the relevance of its treatment suggestions.

ENABLEMENT SECTION: The system begins by allowing users to describe their medical history and condition via a Personal Health Agent (PHA), which may be locally hosted on their device or deployed via secure cloud infrastructure. The user can input natural language descriptions of their symptoms, previous diagnoses, attempted treatments, and outcomes, and this input is processed using medical natural language processing models that extract structured information such as symptom type, timeline, demographic attributes, treatment names and durations, and observed effects. These extracted elements may be stored as structured case profiles in a standardized schema, typically in JSON or protocol buffer format, and the profiles may then be embedded into a high-dimensional semantic vector space using pre-trained medical transformer models such as BioBERT or ClinicalBERT or custom embeddings trained on similar case corpora. Peer profiles may be stored in a central database optimized for similarity search using approximate nearest neighbor algorithms such as HNSW or FAISS. When a new user submits a case, the system may perform semantic similarity search across the database to find peers with closely matching medical trajectories, with matching determined by vector proximity and with weighting factors applied to key dimensions such as symptom overlap, treatment path similarity, age and sex, and lifestyle indicators such as desk work or athletic activity. The matched peer profiles may be filtered to select two sets, namely highly similar users with shared medical history and condition timelines and dissimilar users who nonetheless achieved a positive outcome to discover novel outliers. Each selected peer case may then be summarized by extracting key elements such as onset, duration, treatment attempts, and outcomes and by using template-based or abstractive models to create coherent, anonymized narrative summaries, for example, “42-year-old male, software engineer, experienced 7 months of wrist tingling and hand weakness. Tried vitamin B12 and splinting without effect. Significant improvement reported 3 weeks after hydrodissection guided by ultrasound.” These summaries may be bundled into a structured prompt alongside the user's own case data, and a typical prompt may include a description of the target user, top-N peer summaries, optional medical tags or clinician annotations, and instructions to highlight promising treatments, trends, and emergent hypotheses. The prompt may be processed by a fine-tuned LLM running either on-premise or via a privacy-compliant API, and the output may include personalized treatment suggestions with rationale, ranked likelihood of success based on peer outcomes, observed side effects, and questions to consider with medical professionals. This output may be delivered back to the user's PHA, which may present it in a conversational format or structured insight panel, and the user may request clarifications, ask follow-up questions, or view detailed statistics such as “75% of users like you improved with intervention X.” If consent is granted, the user's outcomes such as symptom improvement and new treatments tried may be monitored and fed back into the central system to retrain embeddings and improve model accuracy, and conversational data from group peer meetings, with consent, may also be parsed into structured updates. In the case of group discussions, the system may organize small cohorts of similar patients, facilitate secure real-time dialogue, and embed an AI assistant that proposes hypothesis-driven questions such as “Did imaging correlate with symptom severity?”, with transcripts anonymized and processed using NLP to capture discussion outcomes and with medical professionals optionally annotating these conversations to confirm or refute emergent hypotheses. All structured data, expert annotations, and model outputs may be continuously fed into a model refinement pipeline that retrains prompt strategies, updates case clustering metrics, and expands the knowledge graph of treatment-effect relationships so that the system becomes more accurate and useful over time with minimal burden on end users. In one embodiment, the invention may be implemented using one or more computing devices comprising non-transitory computer-readable memory and one or more processors, where the local agent responsible for collecting and structuring user health data may reside on the user's device and be stored in a computer memory, with software modules that perform natural language processing to convert free-text input into structured representations and apply redaction rules before submission. The anonymized data may be transmitted over a secure channel to a remote system where it is stored in a persistent database optimized for semantic search and retrieval; this persistent database may reside on one or more servers connected to the internet using high-availability storage infrastructure. The similarity engine may be executed by a cloud-based or distributed processing system that utilizes semantic embedding techniques such as transformer-based encoders to convert user records into high-dimensional vectors and compares these using vector distance functions such as cosine similarity; matching peer records are then identified and retrieved for further processing. The language model component may be stored on a machine-readable storage medium and executed on server-grade hardware, optionally accessed via API by the local agent, and it may receive structured prompts containing the current user profile and selected peer summaries and generate outputs comprising suggested treatments, risk considerations, and follow-up questions; these outputs may be cached temporarily in volatile memory or persisted for audit purposes. In one embodiment, the system includes a meeting coordination module stored in computer memory that schedules peer-to-peer or group meetings based on matching health profiles, and users may interact via a conferencing interface that integrates an AI participation agent configured with instructions stored on a machine-readable storage medium; the AI agent may observe, log, and contribute to discussions by posing relevant hypothesis-driven questions in real time. Meeting audio or video data may be recorded and stored to a secure storage medium for further processing, a speech-to-text engine may transcribe the conversation, and this transcription may then be analyzed using NLP pipelines to extract structured insights and updated case data. In one embodiment, an annotation interface may be provided to licensed medical professionals, allowing them to review transcripts and validate or refute hypotheses discussed during the session, with these annotations stored alongside the structured data in the persistent database and used to refine the underlying AI models. A model training pipeline executed by one or more processors may incorporate new user outcomes, conversational insights, and expert annotations, thereby supporting the continuous improvement of treatment recommendations, condition subtype inference, and insight generation. In software-centered embodiments, orchestration between the Personal Health Agent and server-side services may be implemented using the Model Context Protocol, wherein the PHA or an orchestrator registers callable tools and exchanges inputs and outputs as structured JSON artifacts that are suitable for verification and replay. A tool invocation may be represented as {“tool”:“constructprompt”,“args”:{“user_profile_ref”:“u123”,“peer_summaries”:[“p456”,“p789”],“in struction”:“rank candidate interventions and propose follow-up clinician questions” },“context”:{“prompt_library”:“pv-2025.06”,“safety_policy”:“sp-4.1” }}, and a corresponding response may be represented as {“tool”:“construct_prompt”,“result”:{“prompt_id”:“pr-8842”,“token_count”:1180},“sig”:“MEQCIF9x. ==”,“timestamp”:“2025-06-01T12:31:10Z” }. The same orchestration layer may call generate_suggestions with {“tool”:“generate_suggestions”,“args”:{“prompt_id”:“pr-8842”,“model_build”:“lm-3.1” }}, receiving {“tool”:“generate_suggestions”,“result”:{“ranked”:[“nerve_glides”,“ergonomic_adjustments”,“emg_nc v_testing”,“ultrasound_guided_hydrodissection”],“rationales_ref”:“rat-5521” },“sig”:“MGYCMQ . . . ==”,“timestamp”:“2025-06-01T12:31:15Z” }. These MCP-mediated exchanges may be logged by the metering and observability subsystems described herein and may be executed in online or offline modes with preinstalled knowledge packs, thereby integrating protocol-level interoperability directly into the enabled implementations.

PROCESS FLOWS: The following textual flows describe representative sequences that can be directly rendered as flowcharts and that these flows support method claims while remaining illustrative and non-limiting. In an insight generation flow, a user may supply natural language and structured inputs to the Personal Health Agent, which may apply context-aware redaction and submit user-approved data to a persistent database; the database may be queried by a similarity engine that embeds or otherwise indexes the user's case and retrieves both high-similarity peers and successful outliers; selected peer cases may be summarized and combined with the user's structured profile and optional clinician tags by a prompt construction component; a language model service may generate ranked treatment suggestions, condition subtype indicators, warnings, and follow-up questions; the Personal Health Agent may present outputs and record user selections or feedback; externally observable artifacts may include suggestion lists with rationales, cohort descriptors with similarity scores, and signed usage events linking inputs, retrieval identifiers, and outputs. In a live peer meeting analysis flow, the similarity engine or a grouping module may assign a group identifier to the user's case; a meeting coordination module may schedule a session and issue access credentials; participants may join a conferencing interface where an AI participation agent, operating under session-scoped policies, may pose hypothesis-driven questions and log salient details; with consent, the session may be recorded and transcribed by a speech-to-text engine; an NLP pipeline may extract structured updates, emergent patterns, and clarifications from the transcript; extracted artifacts and consented metadata may be stored in the database alongside the user's evolving case record; licensed clinicians may review transcripts via an annotation interface and attach validation or refinement tags to hypotheses and treatment pathways. In a continuous model refinement and deployment flow, the model training pipeline may ingest structured outcomes, peer-derived insights from summaries and transcripts, and expert annotations; the pipeline may monitor distributional drift, update similarity engine parameters, revise summarization logic, adjust prompting strategies, and refresh knowledge representations; updated artifacts may be validated against held-out cohorts and safety checks, signed, versioned, and deployed to client or server endpoints; the system may emit auditable, timestamped events indicating active versions, training data epochs, and changes in retrieval or prompting behavior to support reproducibility and forensic analysis; user-facing agents may periodically pull or receive updated packs in online or offline modes, ensuring evolving recommendations while preserving privacy and entitlement constraints.

TECHNICAL EFFECTS: The disclosed system may achieve concrete technical effects and deliver real-world advantages across its modules. The Personal Health Agent's context-aware redaction may reduce re-identification risk while preserving medically salient features, improving the utility-privacy tradeoff relative to baseline token redaction by maintaining higher downstream extraction accuracy for symptom, treatment, and outcome entities. The embedding-based similarity engine coupled with selection of both high-similarity and successful outlier cases may increase retrieval diversity and precision, improving top-k cohort relevance and expected treatment discovery while keeping query latency low by using approximate nearest neighbor search that scales sub-linearly with corpus size. Case summarization and prompt construction may compact heterogeneous case data into concise narratives, reducing token count, bandwidth, and inference cost while preserving decision-critical attributes, thereby lowering end-to-end latency and enabling higher throughput under fixed compute budgets. The live peer meeting flow with an AI participation agent may elicit disambiguating details and missing covariates through hypothesis-driven questions, increasing feature density and reducing ambiguity in case records, which in turn may improve similarity matching, clustering stability, and insight generation quality. The expert annotation interface may convert unstructured conversational transcripts into labeled supervision signals, enabling continuous learning that may reduce false positives in treatment suggestions and improve condition subtype inference over time. The model training pipeline may monitor distributional drift and incorporate new outcomes and annotations, allowing adaptive refinement of embeddings, clustering parameters, prompting strategies, and knowledge representations, which may maintain or improve accuracy as the case corpus evolves. The system's externally observable outputs and signed usage events may provide auditable evidence of feature utilization and recommendation provenance, supporting reproducibility, safety audits, and forensic analysis without exposing sensitive internals. Interoperability features that interface with multiple protocols and standards may reduce integration friction and prevent interface-level workarounds from bypassing core functionality, while privacy-maximizing fallback configurations may enable on-device execution with no network transmission of user data, preserving the principal technical benefit of peer-derived insight generation even in constrained environments. Collectively, these effects may produce improved retrieval quality, lower operational cost, enhanced privacy, better clinical relevance of suggestions, and sustained performance under growth and change.

EXTERNAL OBSERVABILITY: The embodiments may include explicit, externally verifiable inputs, outputs, and telemetry that enable black-box verification of system operation without access to proprietary internals. Observed inputs may include user-approved case submissions transmitted by a Personal Health Agent as structured payloads bearing content-type descriptors and a redaction policy identifier, where each submission may be acknowledged by the service with a signed receipt containing a monotonic sequence number, a submission hash, and a timestamp. Cohort retrieval may be externally indicated by server responses that include cohort descriptor artifacts such as cohort identifiers, similarity score summaries, and references to retrieval batches, where each artifact may be accompanied by a detached digital signature attesting to retrieval time, retrieval policy version, and search index version. Insight generation outputs may be presented to the Personal Health Agent with explicit fields including ranked suggestion identifiers, rationales grounded in peer evidence descriptors, condition subtype indicators, and follow-up question sets, together with provenance metadata listing the prompt strategy version, model build identifier, and alignment or safety policy hash. Optional peer meeting operations may be evidenced by time-limited access tokens or group identifiers issued by a meeting coordination module, where token issuance and redemption events may be logged as signed audit records detailing token scope, validity interval, session host, participant pseudonyms, and conferencing provider endpoints without exposing personal data. When consented, recording and transcription events may be externally visible via artifact manifests that enumerate recording asset identifiers, transcript checksum values, natural language processing pipeline versions, and storage locations, and these manifests may be accompanied by integrity proofs such as JSON Web Signatures or COSE_Sign structures and, optionally, RFC 3161-compatible trusted timestamps. The continuous learning and deployment flow may emit versioned release notes and signed model or retrieval-pack manifests that specify active parameter sets, similarity engine configuration digests, prompt library versions, and effective dates; client-side Personal Health Agents may expose their currently installed pack identifiers and last-update timestamps, providing a verifiable link between observed recommendations and the underlying artifact versions. Monetization and entitlement controls may further reinforce observability by generating cryptographically signed, append-only metering events keyed by tenant, feature, and operation class, so that reconstruction of usage sequences can demonstrate that, for a given user session, privacy-preserving submission, cohort retrieval including successful outliers, and peer-grounded suggestion generation were performed in order. In offline or air-gapped modes, Personal Health Agents may still expose externally verifiable behavior by attaching pack-version identifiers and local signature chains to suggestion outputs, allowing auditors to correlate outputs to preinstalled knowledge packs even in the absence of live network telemetry. These externally visible artifacts and behaviors may enable parties to prove or disprove practice of the claimed methods by observing network traces, logs, receipts, manifests, and suggestion payloads, thereby supporting enforcement while preserving user privacy and without requiring reverse engineering of internal models or indices.

INTEROPERABILITY COVERAGE: The embodiments may interoperate across heterogeneous devices, operating systems, and network protocols without altering the claimed functionality. The Personal Health Agent could be implemented as a native mobile application for iOS or Android, a desktop client for Windows, macOS, or Linux, or a web application rendered in standards-compliant browsers. Data exchange may occur via REST, gRPC, GraphQL, WebSocket, or message-queue transports such as AMQP or MQTT, with payloads encoded as JSON, CBOR, Protocol Buffers, HL7 FHIR bundles, or CDA documents. Identity and access control may leverage OAuth 2.0, OpenID Connect, SAML, or mutual-TLS certificates, and enterprise integration may connect to electronic health record systems via HL7 v2, FHIR R4 or R5, or CCDA endpoints, including vendor-specific APIs exposed by major EHRs. Conferencing and messaging may utilize WebRTC, SIP, Matrix, or proprietary SDKs, and speech-to-text may be provided by interchangeable engines including on-device and cloud providers. Storage and deployment may span public cloud providers such as AWS, Azure, and Google Cloud, private clouds or on-premise infrastructure, and offline modes using preinstalled knowledge packs on constrained devices. Cryptographic signing and timestamping may use JWS, COSE, CMS, or PAdES with RFC 3161 time-stamp authorities. Localization may include multiple languages and regional privacy regimes such as HIPAA, GDPR, or PIPEDA. Interface substitutions and protocol changes may not avoid infringement where externally observable behaviors-privacy-preserving case submission, cohort retrieval including successful outliers, peer-grounded suggestion generation, and optional meeting analysis with structured extraction-remain present.

WORKAROUND RESILIENCE: The inventive concept centers on generating individualized treatment insights by retrieving peer cohorts from anonymized case records and transforming cohort-derived evidence into user-specific suggestions, optionally augmented by live or asynchronous peer interaction and expert feedback. To foreclose design-around attempts that merely substitute internal components while practicing the same externally observable behaviors, the description explicitly contemplates functionally equivalent implementations. The similarity engine may be realized using any mechanism that selects related and successful-outlier cases based on features extracted from user records, including rule-based mappings, locality-sensitive hashing, clustering on diagnostic codes, graph traversal over case relationships, supervised metric learning, or embedding-free proximity indices that store hashed signatures or pairwise relationships. The insight generation component may be any model or pipeline that maps retrieved cohort evidence to ranked treatment suggestions with rationales and follow-up questions, including sequence models, retrieval-and-rerank stacks, probabilistic graphical models, expert rules, or ensemble learners; regardless of internal architecture, the externally observable outputs remain ranked suggestions grounded in retrieved peer evidence. Deployment topology may be reallocated across client and server boundaries, batch or real-time modes, or air-gapped and offline update cycles without avoiding infringement where the observable workflow still includes privacy-preserving case submission, cohort retrieval including successful outliers, suggestion generation, and optional meeting analysis with structured extraction. Interface substitutions or protocol changes, such as different conferencing, identity, or data exchange standards, do not avoid the claimed behaviors where the gating, coordination, transcription, and analysis functions remain present. The system may emit signed, timestamped usage events linking inputs, retrieval identifiers, and outputs, enabling external verification that the sequence of cohort retrieval and suggestion generation was executed even when internals are concealed. These disclosures provide support for continuation filings that explicitly capture equivalents and platform substitutions so that trivial reimplementation choices do not provide a straightforward workaround of the inventive subject matter. In addition, functionally equivalent implementations that apportion steps between distinct services, human operators, or manual processes remain within scope where a single directing entity conditions participation or controls the sequence such that privacy-preserving case submission, cohort retrieval including successful outliers, and peer-grounded suggestion generation are performed in combination; splitting transcription, retrieval, or suggestion logic across vendors or replacing automated steps with human execution does not avoid infringement when the externally observable artifacts and behaviors remain substantially the same. The meeting element may be realized by any synchronous or asynchronous medium, including email threads, moderated forums, or survey-driven workflows that elicit the same hypothesis-driven clarifications; replacing the AI participation agent with rule-based scripts, human moderators following provided templates, or event-triggered question sequences preserves the inventive contribution. Replacing dense vectors with symbolic signatures, rule tables, or precomputed neighbor lists, substituting probabilistic or rule-based inference for machine-learned models, or relocating components across client, edge, or server boundaries are expressly contemplated equivalents. Because the platform emits signed, timestamped receipts and provenance for submissions, retrievals, and outputs, attempts to obscure internal substitutions or to stage steps across nominally separate systems remain externally provable as practice of the claimed methods.

FALLBACK EMBODIMENTS: In fallback configurations that preserve the inventive concept while reducing implementation complexity, the system may operate with a subset of modules and simplified processing. In one fallback embodiment, the peer matching engine may rely on deterministic rules and weighted keyword overlap without use of neural embeddings, and the case summarization component may employ fixed templates populated from structured form fields rather than abstractive generation.

In another fallback embodiment, the Personal Health Agent may restrict inputs to structured questionnaires and checklists, foregoing free-text NLP while still producing a standardized case profile used to retrieve peer cases and generate ranked suggestions. In a further fallback embodiment, live or asynchronous peer meetings may be omitted entirely; instead, the system may present curated, anonymized peer narratives and aggregated outcome statistics to the user, while the AI participation agent function is replaced by an automated clarifying-question sequence delivered within the Personal Health Agent interface. In yet another fallback embodiment, the persistent database may be implemented as a single-node relational store or an encrypted flat-file repository, and the similarity search may be executed via SQL queries or precomputed indices rather than approximate nearest neighbor structures. In a privacy-maximizing fallback embodiment, all processing may occur locally on the user's device using an on-device knowledge pack seeded from periodically downloaded, anonymized model artifacts, with no network transmission of user data; model refinement may occur offline by periodically installing updated packs signed by the service. In an expert-light fallback embodiment, clinician annotation may be deferred or omitted; the training pipeline may update prompting strategies using observed user-reported outcomes alone, with quality controls applied via automated consistency checks. In an interoperability-constrained fallback embodiment, data exchange with external systems may be limited to import or export of delimited files without use of EHR-specific standards, while maintaining the core functions of peer retrieval and suggestion generation. These fallback embodiments still realize the technical effect of leveraging peer-derived, anonymized case data to generate personalized treatment insights and adapt recommendations based on outcomes, even when one or more optional components such as live meetings, deep neural summarization, expert annotation, or distributed vector search are reduced or absent.

In one embodiment, the invention provides a method for enabling group communication among users who exhibit related medical conditions. The method may begin when a medical case is submitted to a central system, either by a user directly or via a personal agent operating on the user's device. The submitted case may include structured or semi-structured data representing symptom descriptions, demographic attributes (such as age, sex, or occupation), and optionally prior treatment history or comorbidities.

Upon receipt, the system may extract clinically relevant features from the case using a parsing module, rules-based system, or language model. Extracted features may include symptom keywords, duration indicators, severity levels, and contextual tags derived from the demographic profile.

These extracted features may then be compared against a database of anonymized historical or contemporaneous medical cases using a similarity engine. The similarity engine may apply a variety of techniques to identify related cases, including but not limited to:
semantic similarity using embedding vectors;
keyword overlap scoring;
clustering algorithms trained on diagnostic codes;
rule-based mapping to known condition classes or subtypes.

When a subset of sufficiently similar cases is identified, the system may generate or assign a group identifier. This identifier may function as a reference to the matched cluster of cases and may be used to control access to a communication channel, such as a chat group, live video session, or asynchronous message board.

Each new user whose case is matched to the same group may be associated with the corresponding group identifier and provided with a secure access mechanism. In one embodiment, the system may generate a session link, a hashed identifier, or a tokenized credential, which is then returned to the user's personal agent or directly displayed to the user.

Access to the group communication channel may be gated by the presence of this group identifier.

The communication space may be designed for mutual support, information exchange, or collective analysis of treatment experiences. In some cases, an AI participation agent may be embedded in the session, configured to pose hypothesis-driven or clarifying questions, guide discussions, or summarize emerging patterns.

To maintain data integrity and encourage meaningful participation, the system may further condition continued access to the communication channel on the submission of periodic progress reports. Such reports may be collected by the personal agent and may include self-reported outcomes, side effects, symptom progression, or resolution. The system may enforce incentive mechanisms, such as revoking access or applying higher usage fees for users who repeatedly fail to contribute updates.

The communication channel itself may be optionally transcribed, anonymized, and processed using natural language processing (NLP) methods. Extracted insights from these conversations may then be tagged, indexed, and reused to further refine the system's understanding of treatment effectiveness, emerging symptom clusters, or contextual factors influencing outcome.

This group-based communication model, anchored in a dynamically assigned group identifier, enables patients facing similar conditions to share experience, receive collective insight, and contribute to an evolving knowledge base, all while preserving privacy and enabling scalable coordination.

The embodiments may be described by this itemized list (non-claim embodiments support):
1. A method for enabling communication among users with related medical conditions, comprising generating a group identifier based on similarity between medical case records and using said identifier to provide shared access to a communication channel.
2. The method of item 1, wherein the similarity is determined based on clinical symptoms and demographic features extracted from the medical case records.
3. The method of item 1, wherein the group identifier is assigned by a similarity engine operating on a database of anonymized peer cases.
4. The method of item 1, wherein the communication channel comprises a live video meeting, chat group, or asynchronous discussion forum.
5. The method of item 1, wherein access to the communication channel is limited to users associated with the same group identifier.
6. The method of item 1, wherein an AI agent is embedded in the communication channel and configured to guide discussion using hypothesis-driven prompts.
7. The method of item 1, wherein conversations within the communication channel are transcribed, anonymized, and analyzed to refine diagnostic or treatment suggestions.
8. The method of item 1, further comprising updating group membership dynamically as user cases evolve or as new similarity thresholds are met.
9. The method of item 1, wherein the group identifier is cryptographically signed, time-limited, or condition-specific.
10. The method of item 1, wherein participation in the communication channel is conditional on submitting follow-up health reports or treatment progress updates.
11. A system wherein the insight generation component comprises any model or pipeline that maps peer-derived case features to treatment suggestions, including rule-based expert systems, retrieval-and-rerank stacks, probabilistic graphical models, ensemble learners, gradient-boosted decision trees, or sequence models, such that substituting one for another preserves the inventive concept of generating ranked, peer-grounded suggestions.
12. A similarity engine that may employ locality-sensitive hashing, rule-based codings, graph traversal over case relationships, supervised metric learning, Bayesian case-based reasoning, or embedding-free proximity indices that store hashed signatures or pairwise proximities, while selecting both highly similar and successful outlier cases.
13. A deployment topology wherein processing is distributed across client and server, batched offline, or executed in air-gapped environments, while externally observable behaviors include privacy-preserving submission, cohort retrieval, suggestion generation, and optional meeting analysis with structured extraction.
14. An implementation that avoids explicit storage of dense embeddings by using compressed signatures, sketches, or precomputed neighborhood indices that achieve substantially the same cohort retrieval behavior for purposes of generating peer-grounded suggestions.
15. A compliance and observability mechanism that emits signed, timestamped events linking inputs, cohort identifiers, and suggestion outputs, enabling external verification that core retrieval-and-suggestion steps were executed irrespective of internal component substitutions.
16. An embodiment comprising a personal health agent configured to collect user health data, a database adapted to store anonymized peer health records, a similarity engine operable to match peer records, and an insight generation model including a language model configured to generate treatment suggestions based on matched peer cases.
17. The embodiment of item 16, wherein the personal health agent performs context-sensitive redaction and transmits only user-approved records.
18. The embodiment of item 16, further comprising a meeting coordination module adapted to organize live sessions between users with similar profiles.
19. The embodiment of item 18, further comprising an AI participation agent configured to pose hypothesis-driven questions during the peer session.
20. The embodiment of item 18, wherein the conversation is recorded, transcribed, anonymized, and analyzed using natural language processing techniques.
21. The embodiment of item 20, wherein medical professionals annotate the transcripts to validate or refine diagnostic hypotheses, and such annotations are stored for model training.
22. The embodiment of item 16, further comprising a training module configured to refine the language model based on user outcomes and expert annotations.
23. The embodiment of item 16, wherein the language model output includes ranked suggestions, condition subtype indicators, and follow-up questions for clinician discussion.
24. The embodiment of item 16, wherein the peer matching engine selects both high-similarity and successful outlier cases to increase diversity and relevance of insight.
25. A method embodiment comprising matching users based on similarity of medical conditions, facilitating a peer meeting involving embedded AI agents, recording and analyzing the conversation for emergent patterns, and integrating the derived findings into a diagnostic support system.
26. A computer-implemented system embodiment comprising a local agent stored in non-transitory computer-readable memory and configured to collect user health data, a persistent database configured to store anonymized peer health records, a similarity engine executed by one or more processors and configured to match peer records based on semantic embeddings, and a language model hosted on a server and stored on a machine-readable storage medium, configured to output treatment suggestions based on matched peer cases.
27. The embodiment of item 26, wherein the local agent includes logic for context-sensitive redaction and transmits only user-approved data to the persistent database.
28. The embodiment of item 26, further comprising a meeting coordination module stored in computer memory and configured to schedule live sessions between users with matching conditions.
29. The embodiment of item 28, further comprising an AI participation agent comprising instructions stored on a machine-readable storage medium, wherein the agent poses hypothesis-driven questions during the session.
30. The embodiment of item 28, wherein the peer meeting is recorded to a secure storage medium, transcribed using a speech-to-text engine, and analyzed using natural language processing to extract structured case updates.
31. The embodiment of item 30, wherein licensed medical professionals annotate the transcribed conversation using an annotation interface to validate or refine diagnostic hypotheses, and wherein such annotations are stored in the database for future model training.
32. The embodiment of item 26, further comprising a model training pipeline executed by one or more processors, wherein the pipeline retrains the language model using structured user outcomes and expert annotations.
33. The embodiment of item 26, wherein the language model output includes ranked treatment suggestions, condition subtype indicators, and a list of follow-up questions for clinical discussion.
34. The embodiment of item 26, wherein the similarity engine selects both high-similarity peer cases and successful outlier cases based on treatment effectiveness indicators stored in the database.
35. A computer-implemented method embodiment comprising identifying users with semantically similar medical condition profiles using a vector similarity engine, organizing a live peer meeting using a coordination module, embedding an AI agent into the meeting to pose questions and record the discussion, and analyzing the recorded data using natural language processing and storing emergent insights in a persistent database for use in future diagnostic support.

DAMAGES AND MONETIZATION: The system may be delivered and operated under monetization models that include subscription tiers, seat-based licensing, consumption-based metering, enterprise licensing, and outcome-linked pricing, and the technical architecture may include features to support accurate usage attribution and revenue recognition. An entitlement and identity service may issue time-limited, scope-restricted credentials to the Personal Health Agent, the meeting coordination module, and the language model service, with enforcement at API boundaries using token validation and rate limits so that premium features such as expanded cohort retrieval, clinician-annotated insights, or live peer sessions are accessible only to entitled users or organizations. A metering pipeline may instrument each feature invocation by emitting cryptographically signed, timestamped usage events that record identifiers such as tenant, plan, feature key, input size bands, output size bands, and session duration; these events may be aggregated into immutable ledgers stored in append-only storage to provide auditable evidence of use and to enable per-feature billing. A billing connector may integrate with multiple payment processors and invoicing systems, and may support proration, credits, refunds, grace periods, and account suspension, while a policy engine may evaluate monetization rules such as per-seat limits, per-organization caps, or time-of-day constraints. The conferencing interface and AI participation agent may enforce session quotas and concurrency limits based on subscription tier, and the system may watermark or tag generated insight artifacts with plan metadata or session identifiers so that downstream sharing can be detected and traced. For enterprise deployments, the system may support single sign-on using OAuth 2.0 or OpenID Connect, SCIM provisioning, and audit log export to security information and event management systems, and it may interoperate with multiple EHR standards such as HL7 FHIR or CDA where permitted so that monetization cannot be circumvented via alternative integration paths. The platform may periodically produce signed usage summaries and receipts that are made available to customers and, when necessary, to auditors, thereby providing externally observable, third-party-verifiable indicators of system utilization that support calculation of damages in the event of infringement. Feature flags, A/B testing instrumentation, and cohort analytics may be employed to measure realized value across plans and to tune pricing, while anti-circumvention controls such as license heartbeats, offline grace windows, anomaly detection on token use, and progressive feature degradation may discourage unlicensed access without impeding legitimate offline scenarios.

HOLD UP IN COURT: The described embodiments may be drafted and implemented to satisfy statutory patentability requirements and to facilitate proof of infringement with externally observable evidence. Regarding subject-matter eligibility, the independent claims recite concrete computing components and data structures, including a personal agent, a persistent database, a similarity engine using vector or equivalent indices, a language model or equivalent insight generator, and optional conferencing, transcription, and annotation modules. The specification details technical improvements in computer functionality, such as reduced token count and inference cost via compact case summarization, improved retrieval precision and diversity through combined selection of high-similarity and successful outlier cohorts, sub-linear latency using approximate nearest neighbor indexing, and privacy-preserving redaction that maintains downstream extraction accuracy. These concrete improvements integrate any data analysis into a practical application that is tied to particular machines and transforms raw user input into structured machine-readable artifacts such as embeddings, indices, transcripts, annotations, and signed usage records. With respect to written description and enablement, the disclosure provides architectures, operational flows, implementation choices, and alternatives, including specific examples of encoders, indexing strategies, summarization approaches, deployment topologies, observability mechanisms, and training pipelines, such that a person of ordinary skill could implement the claimed subject matter without undue experimentation.

The description supports each claim element and presents multiple interchangeable implementations for broad but definite claim scope. For definiteness, terms such as “configured to,” “component,” “engine,” and “module” are used in their ordinary technical sense. The open-ended transitional phrase “comprising” is used consistently. Unless context dictates otherwise, “a” or “an” means one or more, “or” is inclusive, and operations may be performed in any order unless an order is expressly required.

To the extent any element is construed under 35 U.S.C. § 112(f), corresponding structure includes the specific modules and algorithms disclosed herein and their explicitly supported equivalents, including rule-based and embedding-free alternatives for similarity selection and non-neural pipelines for insight generation. For novelty and non-obviousness, the combined use of both high-similarity and successful outlier cohorts as retrieval targets, the integration of AI-guided peer meetings that elicit missing covariates with hypothesis-driven prompts, the conversion of conversations into structured supervision via expert annotation, and the emission of signed, timestamped usage events linking inputs, retrieval identifiers, and outputs together produce measurable technical effects not taught by conventional patient support forums, clinical decision support tools limited to guideline lookups, or generic recommendation engines. The synergy of these elements yields improved retrieval quality, lower latency and cost, enhanced privacy preservation, and auditable provenance of recommendations. For enforceability and proof, the claims are layered as system, method, and computer-readable medium formats, enabling assertion against service providers, software distributors, and integrated devices. The platform's externally observable behaviors and signed usage events may be used to establish that core steps of cohort retrieval and peer-grounded suggestion generation were performed under the direction or control of a single provider, addressing divided infringement concerns. Internationally, the embodiments are described as informational and decision-support tools producing suggestions for clinician discussion rather than making autonomous diagnoses or treatment decisions, and the system includes privacy and compliance controls and deployment modes suitable for regulated environments, while the claims remain directed to technical data processing systems. These disclosures collectively strengthen the likelihood that the claims will withstand eligibility, definiteness, written description, enablement, and obviousness challenges while supporting effective remedies with auditable usage evidence.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

Item 1. A system for generating personalized medical insights, comprising:
a) a personal agent configured to collect user health data;
b) a database adapted to store peer health records with optional anonymization;
c) a similarity engine operable to match peer records; and
d) an insight generation component configured to generate treatment suggestions based on matched peer cases.

Item 2. The system of item 1, wherein the personal agent is configured to perform context-sensitive redaction and to transmit only user-approved records.

Item 3. The system of item 1, further comprising a meeting coordination module adapted to organize live sessions between users with similar profiles.

Item 4. The system of item 3, further comprising an AI participation agent configured to pose hypothesis-driven questions during a peer session.

Item 5. The system of item 3, wherein a conversation is transcribed, anonymized, and analyzed using natural language processing techniques.

Item 6. The system of item 5, wherein licensed medical professionals are enabled, via an annotation interface, to annotate the transcripts to validate or refine diagnostic hypotheses.

Item 7. The system of item 1, further comprising a training module configured to refine the insight generation component based on user outcomes and expert annotations.

Item 8. The system of item 1, wherein the insight generation component comprises a language model and wherein an output of the insight generation component includes ranked suggestions, condition subtype indicators, and follow-up questions for clinician discussion.

Item 9. The system of item 1, wherein the similarity engine selects both high-similarity cases and successful outlier cases to increase diversity and relevance of insight.

Item 10. A method for improving diagnostic accuracy through group conversation, the method comprising:
a) matching users based on similarity of medical conditions;
b) facilitating a peer meeting involving embedded AI agents;
c) recording and analyzing the conversation for emergent patterns; and
d) integrating derived findings into a diagnostic support system.

Item 11. A computer-implemented system for generating personalized medical insights, comprising:
a) a local agent stored in a non-transitory computer-readable memory and configured to collect user health data;
b) a persistent database configured to store peer health records with optional anonymization;
c) a similarity engine executed by one or more processors and configured to match peer records based on semantic embeddings; and
d) an insight generation component hosted on a server and stored on a machine-readable storage medium, configured to output treatment suggestions based on matched peer cases.

Item 12. The system of item 11, wherein the local agent includes logic for context-sensitive redaction and transmits only user-approved data to the persistent database.

Item 13. The system of item 11, further comprising a meeting coordination module stored in computer memory and configured to schedule live sessions between users with matching conditions.

Item 14. The system of item 13, further comprising an AI participation agent comprising instructions stored on a machine-readable storage medium, wherein the agent poses hypothesis-driven questions during the session.

Item 15. The system of item 13, wherein a peer meeting is recorded to a secure storage medium, transcribed using a speech-to-text engine, and analyzed using natural language processing to extract structured case updates.

Item 16. The system of item 15, wherein licensed medical professionals annotate the transcribed conversation using an annotation interface to validate or refine diagnostic hypotheses, and wherein such annotations are stored in the database for future model training.

Item 17. The system of item 11, further comprising a model training pipeline executed by one or more processors, wherein the pipeline retrains the insight generation component using structured user outcomes and expert annotations.

Item 18. The system of item 11, wherein an output of the insight generation component includes ranked treatment suggestions, condition subtype indicators, and a list of follow-up questions for clinical discussion.

Item 19. The system of item 11, wherein the similarity engine selects both high-similarity peer cases and successful outlier cases based on treatment effectiveness indicators stored in the database.

Item 20. A non-transitory computer-readable medium storing instructions that, when executed by one or more processors, cause a system to perform operations comprising:
a) identifying users with semantically similar medical condition profiles using a vector similarity engine;
b) organizing a live peer meeting using a coordination module;
c) embedding an AI agent into the meeting to pose questions and record the discussion; and
d) analyzing recorded data using natural language processing and storing emergent insights in a persistent database for use in future diagnostic support.

### Embodiment QE: Decentralized Conflict-Aware AI-Mediated Reputation System (“WordOfAiNetwork”)

A decentralized network of personal AI agents evaluates, exchanges, and synthesizes reputational information about services, products, or entities using cryptographically authenticated communications, private trust graphs, conflict-of-interest detection, recursive query forwarding, and multi-factor aggregation. Each agent maintains service experience records and a policy-governed trust model to initiate or answer standardized queries, optionally performing meta-credibility checks on contributors and generating human-readable explanations. The system enables privacy-preserving, context-aware recommendations that resist manipulation through conflict annotations, domain- and geography-specific trust, coordinated-manipulation detection, anti-Sybil safeguards, and interoperable messaging bindings. External observability is provided by signed receipts and append-only logs, while monetization and damages support are implemented via entitlement-bound tokens, usage metering, and verifiable service-level metrics. The disclosure includes method, system, and computer-readable medium claims and a continuation-ready itemized list that broadens scope through alternative implementations and fallback modes.

### Gentle Introduction

People often decide which service or product to use by asking trusted friends for advice. This disclosure generalizes that familiar experience into a privacy-preserving, software-mediated network in which each person has their own AI agent that keeps private notes about past experiences, asks trusted peers for input when needed, and returns a short, understandable explanation. Instead of sending every question to a single website or platform, the agent selectively asks a few trusted agents, much like reaching out to knowledgeable friends. Each message can be signed so the recipient knows who really sent it, and responses can be encrypted so that only intended parties can read them.

When opinions come back, the agent combines them using common-sense factors such as how much the user trusts each source, how recent the experiences were, and whether anyone has a reason to be biased. If a responder works for or owns a related business, the agent may flag a potential conflict of interest and reduce the weight of that opinion, just as a person would discount advice from someone with a stake in the outcome. If the agent lacks enough direct information, it can ask its peers to consult their own trusted contacts, but only to a limited depth to keep communication efficient. The final output to the user is a concise recommendation with a clear rationale, while private details remain protected and only necessary facts are shared.

### Examples

The following examples illustrate concrete, end-to-end executions without limiting scope. They are written as step-by-step walkthroughs to make the flows and component interactions clear, while the actual order of steps may be reordered as permitted by policy.

In a first example, a traveler's agent receives a question about car rentals in Spain. The agent identifies relevant trust-graph neighbors with domain and geography affinity and selects a small beam of recipients. It emits a signed and optionally encrypted reputation request containing the target provider identity, domain tags for car rental, locale tags for Spain, and a recursion depth of two.

Recipient agents evaluate the request against their private memories; one agent matches a prior negative experience citing an undisclosed insurance fee and prepares a structured response with opinion polarity, confidence, timestamp, and rationale. Another agent replies positively but, during response preparation, its local conflict detector discovers that it is affiliated with a competing rental agency and includes a conflict flag. The querying agent receives these responses, validates signatures, and consults a metadata registry for corroborating affiliation signals. It aggregates responses using multi-factor weighting that accounts for trust values, recency, domain relevance, and conflict penalties. It then generates a human-readable explanation that states the mix of opinions and the discount applied to the conflicted response. The agent records an append-only usage log entry with message identifiers, hop counts, and policy snapshot and optionally emits a signed receipt for audit without exposing private payload content.

In a second example, a cold-start user asks for a recommendation for a home plumber. The user's agent has no direct service memories matching the request and therefore returns an explicit no direct experience statement while simultaneously initiating recursive queries to trusted peers under a budget and recursion limit. Several peers respond with structured opinions about different providers; one high-trust peer also provides a linkable outcome verification artifact such as a dated invoice hash.

Because two low-trust responders exhibit correlated timing and similar network attributes suggestive of coordinated behavior, the querying agent invokes meta-credibility checks through additional peers and downweights the suspicious cluster. A short list of candidate plumbers and a synthesized confidence score is produced, together with an explanation that cites the verification artifact and the discount applied to the potentially coordinated responders. Relevant responses are cached with freshness metadata to reduce future query load, and the trust graph is earmarked for update once the user provides a satisfaction signal after service completion.

In a third example, the system operates in a degraded network condition during which the metadata registry is unreachable. A user seeks advice on a meal delivery service. The agent consults its local memory and cache and applies a policy that increases reliance on cached external opinions within permitted freshness windows. It proceeds without real-time conflict registry lookups but preserves the ability to add conflict annotations retroactively when the registry becomes available. The agent issues a recommendation with an explanation that notes use of cache-backed inputs under degraded conditions. Signed receipts and service-level metrics record increased latency and fallback mode activation to preserve external observability and billing accuracy while maintaining privacy.

For software integrations, an agent may expose or consume a Model Context Protocol interface so that reputation queries and responses can be invoked as MCP tools by local or remote AI runtimes while preserving the same authenticated, policy-governed behaviors described above. In one embodiment, the querying agent invokes a reputation.query tool with parameters equivalent to the REPUTATION_REQUEST message and receives a structured result compatible with RESPONSE; minimal JSON payloads that illustrate this binding include the following inline examples:

{“type”:“REPUTATION_REQUEST”,“request_id”:“abc123”,“target”:{“provider_id”:“did:example:pr
oviderX”,“aliases”:[“Company
X”]},“context”:{“domain”:“car_rental”,“locale”:“ES”,“timestamp”:“2025-04-03T10:15:00Z”},“recursi
on”:{“max_depth”:2,“budget”:8},“policy_id”:“pol-v1”,“sender”:“did:example:agentA”,“nonce”:“n7N0
”,“signature”:“base64(sig)”} and
{“type”:“RESPONSE”,“in_reply_to”:“abc123”,“opinion”:{“polarity”:“negative”,“confidence”:0.8},“ra
tionale”:“Undisclosed insurance fee at
pickup”,“conflict”:{“flag”:false},“provenance”:{“last_interaction”:“2025-04-03”,“source_agent”:“did:
example:agentB”},“receipt_hash”:“sha256:9f...”,“signature”:“base64(sig)”}.

### Background

Conventional reputation systems are typically centralized and rely on openly posted reviews, which are often vulnerable to manipulation, fake ratings, and a lack of personalized relevance.

### Summary

### Embodiment Q: Decentralized Conflict-Aware AI-Mediated Reputation System (“WordOfAiNetwork”)

The present invention pertains to decentralized systems and methods that enable autonomous artificial intelligence agents to evaluate, exchange, and synthesize reputational information about services, products, or entities. More specifically, it relates to a distributed network of personal AI agents capable of propagating trust-based service evaluations, performing recursive queries among socially trusted peers, identifying conflicts of interest, and generating contextually relevant, privacy-respecting recommendations.

In contrast, the invention disclosed herein provides a decentralized alternative that mimics and enhances traditional word-of-mouth trust propagation by leveraging the computational, memory, and communication capabilities of AI agents acting on behalf of individuals. Each agent maintains a structured trust model based on social proximity, domain knowledge, and historical performance, and uses this model to answer or forward requests for service evaluations. The system functions even when the original user is unavailable, thus extending their influence and judgment through autonomous agents.

### Detailed Description

The disclosed architecture comprises a plurality of personal AI agents, each associated with a human user. These agents may be hosted locally, deployed in the cloud, or implemented in a federated topology. Each agent maintains a private trust graph-essentially a directed and weighted graph of known and trusted agents, identified via cryptographically secured credentials such as public keys or decentralized identifiers. The edges of this graph encode scalar trust weights, domain-specific expertise labels, historical interaction metadata, and optionally qualitative social descriptors such as “friend” or “colleague.” This trust graph is dynamically updated based on system outcomes, user feedback, and external annotations.

Agents are configured to initiate and respond to standardized query types. These include a service reputation request, which identifies a particular provider or service and includes relevant contextual metadata such as domain, location, and timestamp. The agent receiving such a query may respond with an opinion (e.g., positive, neutral, or negative), a normalized confidence score, supporting rationale, and optional conflict-of-interest flags with explanatory annotations. Responses may also include metadata such as the last recorded interaction with the service or provider in question.

The system supports recursive evaluation of reputation. When initiating a query, an agent may contact the most trusted nodes in its graph. These contacted agents may, depending on policy, further forward the query to their own trusted contacts, subject to recursion limits. As responses are collected, the originating agent aggregates the findings using a scoring algorithm that factors in trust weights, recency of service interaction, domain relevance, and any detected conflicts of interest. This process culminates in a synthesized summary presented in a form comprehensible to the end user, including natural language explanations if appropriate.

To detect and mitigate potential bias, agents are equipped with conflict-of-interest detection mechanisms. Each agent may access a metadata registry-either local, federated, or publicly scraped-which contains information about known affiliations, employment, business ownership, or prior flagged behavior of other agents. If a response appears compromised due to such affiliations, the responding agent may automatically apply conflict annotations, reduce the trust weight of the opinion, or request corroboration from additional trusted parties.

In some instances, agents may also initiate meta-credibility evaluations to assess the reliability of other agents who contribute opinions in a reputation chain. This enables recursive vetting and may be particularly useful in cases where an agent lacks a direct connection to the source of a reputation statement but has access to others who can validate or challenge the intermediary's reliability.

User behavior is modulated through configurable policy profiles. These profiles determine the manner in which reputation queries are constructed, forwarded, and interpreted. Parameters include recursion depth, trust decay over time, response weighting strategies, and thresholds for invoking meta-credibility verification. Policies may be defined manually by users, adopted from socially shared templates, or downloaded from trusted organizations that provide curated trust behaviors.

The system is designed with strong privacy and security safeguards. Communication between agents is encrypted and signed to prevent eavesdropping and impersonation. Trust graphs and opinion logs are stored privately, with access strictly limited to agents authorized by the user. Conflict detection features are transparent, and the reasoning behind discounting or promoting particular inputs is preserved and auditable.

To illustrate the system's operation, consider the following example. A user books a car rental through a service provider and is unexpectedly charged a mandatory insurance fee upon arrival. The user's AI agent records this experience as a negative review with a corresponding confidence score and context metadata. Later, another user, unaware of the incident, considers renting from the same provider. Their AI agent initiates a reputation query through its trust network. The first user's agent responds with a negative review, unflagged for conflict. A second agent supplies a positive review, but the system detects that this agent is affiliated with a competing rental agency. This conflict is flagged, and the input is downweighted. The resulting summary generated by the querying agent may read: “Two negative reviews were received from trusted agents. One positive review was discounted due to a detected conflict of interest.” This concise output enables informed decision-making while maintaining privacy and accountability across the network.

### Technical Effects

The present invention therefore provides a scalable and resilient architecture for the decentralized evaluation of service reputation, enabling a contextually personalized and socially aware extension of traditional word-of-mouth mechanisms via autonomous artificial agents. At the identity and transport layers, the signing module and encryption module backed by a key store yield authentication, integrity, confidentiality, and non-repudiation for queries and responses, reducing impersonation and message tampering compared to centralized review platforms. In practice this lowers the successful attack surface for man-in-the-middle and spoofing attempts while enabling verifiable provenance of each reputation input.

Within each agent, use of a private, domain- and geography-partitioned trust graph focuses routing and aggregation on high-signal peers. When the scheduler applies policy-governed beam selection rather than broadcast, the resulting query fan-out and bandwidth consumption scale with a bounded subset of trusted nodes rather than the full reachable network, improving latency and reducing network load without sacrificing accuracy. The aggregation module's multi-factor scoring, combined with trust decay and recency weighting, yields recommendations that adapt as conditions change, improving calibration as measured by subsequent satisfaction signals and outcome verification channels.

Conflict-of-interest detection that consults a metadata registry and emits conflict annotations produces measurable robustness against biased inputs. Downweighting or requesting corroboration for conflicted opinions reduces systematic bias and improves precision of the final recommendation, particularly in markets with strategic reviewers. Coordinated-manipulation detection and anti-Sybil safeguards further harden the system against collusion and identity farming by recognizing characteristic graph motifs, correlated timing, or shared infrastructure indicators and constraining their influence through penalties, quotas, or admission controls. Together, these mechanisms raise the cost of manipulation and decrease the probability that coordinated campaigns meaningfully alter a computed reputation score.

Caching with explicit freshness controls and validation improves throughput, reduces redundant network traffic, and stabilizes response latency by reusing verifiable external opinions when permissible. Fallback operation modes preserve core functionality under degraded conditions, maintaining local-only or cache-reliant recommendations while honoring security and policy constraints. Privacy-preserving techniques including differential privacy, redaction, and zero-knowledge attestations enable entitlement and compliance proofs without exposing sensitive content, thereby reducing information leakage while keeping services interoperable across heterogeneous deployments.

The explanation generator yields transparent, human-readable rationales and machine-readable provenance trails that increase user trust and facilitate audit. External observability via append-only logs, signed receipts, and time-bounded service-level metrics provides independently verifiable evidence of feature use and compliance, enabling reliable billing, dispute resolution, and forensic analysis without disclosing private payloads. Interoperable bindings and gateway translation that preserve semantic content ensure that substituting wire formats or protocols does not alter observable behavior or the computed results, reducing opportunities for interface-based evasion.

Viewed as alternative embodiments, the method claim achieves the technical effect of transforming authenticated, context-tagged inputs into a calibrated reputation score with conflict-aware adjustments under policy control. The computer-readable medium embodiment enables these same behaviors to be realized on general-purpose computing devices, ensuring portability and consistent results across platforms. The system embodiment distributes computation across multiple devices and trust neighborhoods, producing resilience to single points of failure, improved availability, and graceful degradation under network or registry impairment. Human-in-the-loop controls further reduce erroneous actions by permitting targeted approvals and reweighting, which feedback into trust updates that improve future recommendations.

In practice it is preferred to employ the WordOfAI reputation protocol to structure and verify experience reports through cryptographic signatures and recursive trust evaluation, which leads to a measurable improvement in data integrity and reliability of online reviews. As a result, the system reduces the acceptance and propagation of fraudulent or misleading entries, thereby preventing wasted processor cycles, storage overhead, and bandwidth consumption that would otherwise arise from processing low-quality data. More specifically, the protocol produces the effect of more reliable decision support because conflicts of interest are detected and filtered automatically, which results in fewer misallocations of resources and less unnecessary movement of goods and persons caused by reliance on false information. Since travel and logistics correlate directly with fuel use, the invention indirectly lowers the carbon footprint associated with consumer and business decisions, while its primary effect is improved efficiency and reliability of the distributed reputation system itself.

### Technical Character and Court Readiness

The disclosed subject matter is rooted in computer technology and improves the functioning of computer networks and security subsystems rather than merely performing reputation assessment as a mental process or business practice. The invention recites and relies upon concrete data structures and modules, including a private, domain- and geography-partitioned trust graph with weighted edges and timestamps, authenticated message schemas for REPUTATION_REQUEST, RESPONSE, META_CRED_REQUEST, META_CRED_RESULT, and USAGE_RECEIPT, and append-only logs with verifiable cryptographic hashes. Policy-governed beam selection over the trust graph, recursion budgets embedded in messages, and deterministic aggregation with conflict penalties reduce network fan-out, bound resource consumption, and harden communications against spoofing and manipulation.

The cryptographic signing and optional encryption required for message exchange, together with verifiable receipts and time-bounded service-level metrics, yield non-repudiation and externally provable behavior that cannot be carried out by humans without computers. The claimed system, method, and computer-readable medium embodiments therefore effect a specific improvement in the operation of distributed computing by constraining propagation, authenticating participants, and producing reproducible, audit-ready outputs under adverse conditions. These characteristics provide technical solutions to technical problems of network load control, identity spoofing, and collusive manipulation, and they delineate subject matter that is neither abstract nor purely result-oriented, but implemented via particular structures, fields, and state transitions described herein.

### Enablement

In one embodiment, each personal AI agent-powered by a local or cloud-based large language model (LLM)—maintains an internal memory structure for associating service experiences with contextual metadata and opinion summaries. This memory may include both structured fields and natural language embeddings to allow fast retrieval, flexible reasoning, and human-readable explanation generation.

When a user interacts with a service provider (e.g., books a hotel, hires a contractor, uses a delivery platform), the AI agent records the experience in its internal memory. This record may include the service identifier, date and time of use, location, domain context (e.g., travel, healthcare, financial), and an annotated outcome assessment. The assessment itself may be structured (e.g., positive/negative/neutral, scalar rating, severity level) and optionally accompanied by free-text justification, either extracted from user feedback or generated by the agent based on observed outcomes. These records are indexed not only by service ID but also by semantic tags and situational context, allowing future queries to match relevant experiences even if the service ID is not an exact match.

To enable reproducible implementation by a skilled practitioner, the following concrete build path may be followed without undue experimentation. A key and identity layer may be provisioned by generating a per-agent asymmetric keypair and binding it to a decentralized identifier or certificate with rotation and revocation endpoints. A minimal key store may support create, read, rotate, and revoke operations with audit metadata. A data model may be realized as three stores: a trust graph that includes nodes as agent identifiers, edges with fields such as trust value, domain tags, locale tags, last interaction timestamp, and optional descriptors; an experience store that includes records with fields such as provider identifier, aliases, domain, locale, timestamps, polarity, confidence, and rationale text; and a policy profile that includes recursion parameters, weighting coefficients, threshold triggers, cache freshness limits, and billing limits. A representative policy profile may be serialized for transport and audit using inline JSON such as

{“policy_id”:“pol-v1”,“recursion”:{“max_depth”:2,“budget”:8},“weights”:{“trust”:0.5,“recency”:0.3,“
conflict_penalty”:0.2},“thresholds”:{“meta_cred_trigger”:0.25},“cache”:{“ttl_seconds”:604800},“billi
ng”:{“soft_limit”:900,“hard_limit”:1000}}. Message schemas may be implemented for
REPUTATION_REQUEST, RESPONSE, META_CRED_REQUEST, META_CRED_RESULT, and
USAGE_RECEIPT. The REPUTATION_REQUEST and RESPONSE examples are shown above; a
meta-credibility exchange and a signed receipt may be realized as
{“type”:“META_CRED_REQUEST”,“request_id”:“mcr-77”,“subject_agent”:“did:example:agentB”,“c
ontext”:{“domain”:“car_rental”,“locale”:“ES”},“policy_id”:“pol-v1”,“sender”:“did:example:agentA”,“
nonce”:“4k2”,“signature”:“base64(sig)”} and
{“type”:“META_CRED_RESULT”,“in_reply_to”:“mcr-77”,“credibility”:{“score”:0.6,“signals”:[“corr
elated_timing”,“shared_IP_ASN”]},“signature”:“base64(sig)”}, together with
{“type”:“USAGE_RECEIPT”,“message_id”:“abc123”,“class”:“REPUTATION_REQUEST”,“timesta
mp”:“2025-04-03T10:15:10Z”,“hop_count”:1,“policy_id”:“pol-v1”,“bytes_sent”:842,“bytes_received”
:2150,“compute_tokens”:583,“payload_hash”:“sha256:5d...”,“agent”:“did:example:agentA”,“signature
”:“base64(sig)”}.

A transport binding may be selected among JSON over HTTPS, CBOR over QUIC, gRPC, ActivityPub, Matrix, email with signed attachments, or functionally equivalent protocols, provided each message is signed and optionally encrypted using the key store. A gateway may translate encodings while preserving semantic content. The agent loop may implement recipient selection as a policy-governed beam over the trust graph that scores neighbors by trust value, domain and locale overlap, and freshness, with randomized exploration as permitted by policy. Query propagation may embed a recursion budget and decrement it on forward, rejecting requests when budgets or quotas would be exceeded.

Aggregation may be realized as a deterministic function that converts local experiences and received responses into a normalized score and confidence. An implementation may compute a base score from polarity and confidence, apply weights derived from trust values and recency decay, and subtract penalties when conflict flags are present or when meta-credibility results fall below a threshold. Ties or variance may trigger additional sampling within the remaining recursion budget or may cause the agent to publish a mixed or cautious recommendation with rationale. Conflict-of-interest detection may consult a metadata registry that stores affiliations, ownership, and employment facts keyed by agent identifier or provider identifier. When a lookup fails due to degraded conditions, the agent may annotate the evaluation with a pending conflict check and proceed using cached registry snapshots within freshness limits, retroactively updating annotations when connectivity returns.

Model Context Protocol integration may be achieved by exposing tools that map directly to the message schemas. An agent may register a reputation.query tool that accepts a parameter object equivalent to REPUTATION_REQUEST and returns an object equivalent to RESPONSE. It may also register metacred.request that accepts META_CRED_REQUEST and returns META_CRED_RESULT, and receipt.export that returns a USAGE_RECEIPT for a prior message identifier. A local or remote AI runtime invoking these tools under MCP may inherit the agent's signing, policy evaluation, and logging behaviors so that tool calls are externally indistinguishable from native protocol messages. Where the agent consumes MCP tools offered by other runtimes, the same policies may govern forwarding and budget accounting.

To complete a reference implementation, an explanation generator may synthesize a concise natural-language rationale by selecting salient contributors such as highest-weight opinions, any conflicts applied, and any verification artifacts referenced. An append-only log may be maintained in write-once-read-many storage, storing per-message entries with identifiers, timestamps, policy snapshot identifiers, resource counters, and cryptographic payload hashes. Receipts may be emitted on demand or per policy and verified by recomputing payload hashes and validating signatures. A trust updater may listen for satisfaction signals or outcome verification artifacts such as invoice hash matches and adjust edge weights accordingly, with learning rates and bounds defined by policy to avoid instability. Privacy may be preserved by redacting sensitive fields before export, by using zero-knowledge proofs to attest to entitlements or policy compliance without revealing inputs, and by differential privacy when producing aggregate disclosures. Testing and validation may be performed by simulating multi-agent execution with a per-user process instantiating logical agents that exchange the defined messages, validating that order-equivalent rankings and bounded-difference scores are produced under alternative aggregation models declared in policy, and confirming that fallback modes preserve consistent behavior when registries or network links are impaired. These steps, together with the data models, message formats, and MCP bindings described herein, provide clear, reproducible instructions sufficient for a skilled person to implement the disclosed embodiments without undue experimentation.

### Process Flows

When another agent sends a REPUTATION_REQUEST or a RECOMMENDATION_REQUEST regarding a given service or service type, the receiving agent consults its memory using a two-stage process. In the first stage, it performs a semantic and metadata-based retrieval of all past experiences associated with the specified service or matching the requested service type. In the second stage, it uses an internal scoring mechanism-weighted by confidence, recency, user satisfaction, and potential conflicts of interest-to generate a synthesized opinion. If multiple records are found, the agent may summarize the set, note any anomalies or mixed experiences, and generate an appropriate confidence score reflecting both alignment and variance.

For example, if the request is: “Do you recommend Company X for car rentals in Spain?” the receiving agent searches its memory for previous interactions involving Company X, filtered by domain (“car rental”) and location (“Spain”). If a matching record is found indicating a prior negative review due to hidden fees, the agent may return a response such as: “I do not recommend Company X for rentals in Spain. Last used on Apr. 3, 2025. User was charged an undisclosed insurance fee upon pickup. Confidence: 0.8.”

If the memory includes both positive and negative experiences-perhaps in different countries or years—the agent may respond more cautiously: “Mixed experiences with Company X. Positive interactions in France (2024), but a negative incident in Spain (2025) involving surprise charges. Recommend with caution. Confidence: 0.5.”

In addition to direct service memories, the LLM agent may also weigh indirect opinions by recursively querying trusted peers, incorporating their structured responses into the final recommendation. These externally sourced opinions are kept separate from local memory but may be cached with appropriate timestamps and source annotations to reduce query load in the future.

The system is designed such that when an agent is queried about a service it has no direct memory of, it may explicitly respond with “No experience with this provider” and optionally suggest similar providers it does know, ranked by internal trust and prior outcomes. This approach ensures clarity about the provenance of each opinion and supports both personalized recommendations and honest disclosures of informational gaps.

### Continuation-Ready Itemized List

The embodiments of the invention may be described by the following itemized list: Embodiments can be described by the following itemized list and are suitable for direct use in future continuations; each numbered item is intended as independent support for potential claims at varying abstraction levels, and the order does not imply dependency or required sequencing. 1. A decentralized method in which a first personal AI agent initiates a reputation query, selects recipients from a trust graph, transmits the query, receives structured responses, and aggregates them into a reputation score for a target provider, with messages authenticated and optionally private. 2. A weighting technique in which each received reputation response is weighted by a numerical trust value associated with the responding agent as stored in the querying agent's trust graph. 3. A conflict-aware adjustment in which the computed reputation score is modified upon detection of conflicts of interest associated with one or more responding agents. 4. A conflict identification mechanism that consults metadata indicating a reviewer's business ownership, employment, or financial stake to produce conflict flags and penalty factors. 5. A recursion parameter embedded in a reputation query that constrains maximum propagation depth or hop count. 6. A recursive forwarding policy that permits second-degree and further dissemination of the query through trusted intermediaries subject to policy constraints. 7. A multi-factor aggregation function that may incorporate trust scores, opinion polarity, recency weighting, variance, and conflict penalties to yield a final score and confidence. 8. A persistent memory coupled to the agent that stores service experience records, contextual metadata, and cached external opinions with timestamps and sources. 9. A meta-credibility evaluation in which the first agent requests third-party assessment of a contributor's reliability and adjusts the contributor's weight accordingly. 10. An explanation generator that produces a human-readable summary identifying key contributing factors, conflicts, and provenance of opinions used to compute the score. 11. A cryptographic transport in which all queries and responses are signed and optionally encrypted using keys bound to decentralized identifiers or certificates. 12. A computer-readable medium storing instructions that cause an agent to receive a reputation query, identify a subset of trusted agents from a local trust graph, transmit the query, receive responses, and compute a reputation score. 13. Instructions that cause the agent executing the computer-readable medium to apply numerical trust weightings derived from the trust graph to received responses. 14. Instructions that cause the agent to analyze metadata from responding agents to detect conflicts of interest and apply penalty adjustments. 15. Instructions that cause application of a behavioral policy profile governing recursion depth, trust decay, conflict thresholds, and aggregation rules. 16. Instructions that cause dynamic adjustment of the trust graph in response to user feedback, outcome verification, and observed recommendation accuracy. 17. A system comprising multiple computing devices each executing a personal AI agent, where the agents cooperate over a network to perform decentralized, recursive reputation exchange and evaluation. 18. A system property in which each message transmitted or received by the agents is cryptographically signed and optionally encrypted. 19. A trust graph data model comprising weighted edges, domain-specific trust annotations, and time-stamped interaction records that guide query routing and aggregation. 20. A behavioral policy profile applied by each agent that governs recursion depth, trust decay over time, and weighting adjustments in the presence of conflict metadata. 21. Domain and geography partitioning in which trust scores are maintained per domain, locale, or context and combined via explicit fusion rules selectable by policy. 22. Alternative aggregation models including Bayesian updating, logistic transforms, rank aggregation, and robust statistics that resist outliers and collusion. 23. Coordinated manipulation detection that identifies echo-chamber patterns, correlated timing, shared infrastructure indicators, or graph motifs and downweights implicated responses. 24. Anti-Sybil safeguards including rate limiting, stake- or credential-based admission, proof-of-personhood attestations, and web-of-trust cycle checks. 25. Interoperable messaging bindings across JSON, CBOR, gRPC, ActivityPub, Matrix, email with signed attachments, or functionally equivalent protocols, with gateway agents translating without altering semantic content. 26. Identity and entitlement alternatives including decentralized identifiers, X.509 certificates, hardware security modules, and passkeys, supporting key rotation and revocation. 27. Privacy-preserving techniques including differential privacy for aggregate disclosures, redaction of sensitive fields, and zero-knowledge proofs of entitlement or policy compliance. 28. Caching strategies with per-item time-to-live, freshness scores, ETags, and validation on reuse to ensure recency and minimize unnecessary propagation. 29. Scheduler heuristics including beam search over trusted nodes, randomized exploration to avoid local minima, budget-aware hop allocation, and backoff under network congestion. 30. Explanation modalities that may include natural language summaries, machine-readable rationales, and structured provenance trails linking to hashed payloads. 31. External observability via append-only logs, signed receipts, and service-level metrics that allow third parties to verify usage volumes, feature invocation, and compliance without exposing private content. 32. Multi-tenant deployment modes that isolate per-tenant trust graphs, caches, and keys while permitting cross-tenant interoperability via policy-constrained gateways. 33. Learning-based trust updating including reinforcement learning from user satisfaction signals and calibration against outcome verification datasets. 34. Fallback operation modes that continue functioning with reduced recursion, increased cache reliance, or local-only recommendations when registries or network links are unavailable. 35. Human-in-the-loop controls allowing users to approve, veto, or reweight specific opinions, conflicts, or policies, with such interventions recorded for audit and learning. 36. Target generalization supporting reputation for services, products, content, datasets, models, and entities, with type-specific schemas and normalization. 37. Compliance and audit features including retention policies, write-once-read-many storage for logs, export of regulator-facing summaries, and tamper-evident checks. 38. Conflict metadata sources including public registries, verified disclosures, web scraping with trust signals, and third-party watchlists, combined via confidence scoring. 39. Outcome verification channels that ingest receipts, confirmations, and external data feeds to correlate recommendations with realized outcomes and adjust trust accordingly. 40. Resource governance including quotas on recursion depth, concurrency, and cache size enforced by entitlement tokens and local policy, with graceful degradation behaviors under constraint. 41. Trust representation alternatives in which the trust graph is implemented as an adjacency list, matrix, latent embedding space, or an implicit function computed per query without requiring a persistently stored graph. 42. Decentralization modalities in which agents operate over a logically decentralized overlay that may utilize centralized relays, brokers, or content-delivery infrastructure for transport while decision-making and aggregation remain agent-local. 43. Agent implementation modalities in which an AI agent comprises heuristic, rule-based, statistical, or machine-learned components, singly or in combination, provided the agent autonomously executes policy-governed behaviors. 44. Recipient selection mechanisms that include similarity search, locality-sensitive hashing, learned retrieval, probabilistic sampling, or opportunistic gossip in lieu of explicit neighbor traversal. 45. Reputation exchange patterns including pull-based queries, push-based announcements, publish/subscribe topics, or epidemic gossip with eventual consistency guarantees. 46. Privacy-preserving computation using secure enclaves, multiparty computation, or homomorphic encryption to aggregate or vet responses without exposing plaintext opinions beyond authorized agents. 47. Hosting alternatives including on-device, edge, cloud, and multitenant server deployments where per-tenant isolation is enforced while preserving cross-tenant interoperability via gateways. 48. Central coordination services for rate limiting, key lifecycle management, registry distribution, or policy cataloging that do not centralize final reputation computation or weighting. 49. Non-interactive discovery in which agents emit periodic capability beacons and subscribe to filters that trigger evaluation without per-request addressing. 50. Score equivalence under monotone transforms wherein alternative scoring functions produce order-equivalent rankings or bounded-difference scores yet remain within the claimed aggregation behaviors. 51. Identity proofs including anonymous credentials, threshold signatures, short-lived pseudonyms, or attestations from hardware roots of trust, with revocation and rotation. 52. Simulated multi-agent execution in which a per-user process instantiates multiple logical agents or sandboxes to replicate decentralized query and aggregation behaviors for testing or constrained environments. 53. Target identity handling including canonicalization across provider aliases, deduplication of entity variants, and support for ephemeral or derived service identifiers. 54. Audit artifact anchoring to public ledgers, notary services, or write-once-read-many media without requiring any specific blockchain or ledger technology. 55. Policy update distribution via signed bundles with provenance, rollback protection, staged rollout, and compatibility declarations to maintain consistent decision behavior across agent versions.

### External Observability

External observability is explicitly provided as described in item 31 and further reinforced by the signed receipts and usage logs detailed in the monetization and damages-supporting usage models section, enabling proof of feature use and compliance without exposing private content. In particular, infringement may be demonstrated by observing on-the-wire message classes and signed artifacts that are invariant to implementation details. Observable inputs and outputs include transmission and receipt of REPUTATION_REQUEST, RESPONSE, META_CRED_REQUEST, META_CRED_RESULT, and USAGE_RECEIPT messages bearing verifiable digital signatures bound to agent identifiers; monotonic decrements of an embedded recursion budget across hops; deterministic aggregation behavior that yields order-equivalent scores for repeated trials given identical inputs and policy identifiers; explicit conflict annotations or penalties present in responses or explanations; and exported signed receipts that enumerate message class, hop count, policy snapshot, resource counters, and payload hashes that match recomputed values from captured traffic. A black-box probe agent may issue test queries under a known policy id, capture network logs or gateway-translated equivalents, and verify signature chains and receipt-payload hash consistency to establish that bounded fan-out, authenticated exchange, and policy-governed aggregation occurred as claimed, without requiring access to private internal state.

### Interoperability Coverage

Interoperability is addressed by item 25, which describes bindings across multiple protocols and data encodings with gateway agents that preserve semantic content, preventing avoidance via interface substitution.

### Fallback Embodiments

Fallback behavior is addressed by item 34, which describes continued operation under degraded conditions such as reduced recursion, increased cache reliance, or local-only recommendations.

### Broadening

Broad alternative implementations are disclosed throughout items 21-40, including alternative aggregation models, identity systems, privacy-preserving techniques, and deployment modes, enlarging claim scope without introducing unnecessary limitations. To further deter design-arounds, items 41-55 additionally enumerate functionally equivalent trust representations, decentralization and transport modalities, agent implementation alternatives, recipient selection mechanisms, privacy-preserving computation, identity proofs, simulated multi-agent execution, target identity handling, audit anchoring, and policy update distribution.

### Workaround Resistance

The core functional invariants disclosed and claimed make interface or topology substitutions insufficient to avoid the invention. Implementations that, in practice, select recipients according to a trust-like signal over a set of known peers, propagate a request to one or more additional hops under an explicit or implicit budget, and aggregate received opinions using weights derived from source reliability, recency, or domain relevance fall within the functional boundaries of the method, system, and computer-readable medium claims irrespective of specific wire formats, storage schemas, or scheduler heuristics. Items 21, 22, 25, 41, 42, 44, 45, and 50 expressly cover alternative trust representations, transport bindings, recipient selection mechanisms, exchange patterns, and score-equivalence under monotone transforms, while items 26 and 51 encompass identity and entitlement alternatives. As a result, replacing a stored graph with an embedding, swapping JSON for CBOR or gRPC, using publish/subscribe instead of direct addressing, or computing weights via Bayesian updating rather than linear coefficients preserves the same externally observable behaviors and falls within the disclosed embodiments.

Attempts to evade infringement by relocating functions or mixing centralized relays with decentralized decision-making are addressed by the definition of decentralized overlays and by item 42, which permits use of centralized brokers for transport so long as evaluation and aggregation remain agent-local. Moving conflict- and credibility-related adjustments behind different interfaces is addressed by items 3, 4, 9, 22, 38, and 46, which describe multiple equivalent mechanisms for bias mitigation and validation. External observability and receipts, as detailed in item 31 and in the monetization and damages-supporting usage models section, permit verification of bounded fan-out, recursion limits, signed message exchange, and deterministic aggregation under policy, allowing confirmation of these invariants even where internals are opaque. Collectively, these disclosures reduce viable design-around strategies to material omission of core method steps, which in turn degrades utility and competitiveness, thereby strengthening enforcement.

### Claim Layering

The claim set includes method, computer-readable medium, and system claims to provide layered protection at different abstraction levels within the limit of twenty independent and dependent claims.

### No Unneeded Limitations

The main independent method claim focuses on essential steps that a competitor would unavoidably perform to implement the inventive concept, avoiding superfluous restrictions.

### Damages Maximization

Monetization and damages-supporting usage models. The system may be deployed under subscription, per-query, or hybrid licensing arrangements in which each personal AI agent presents a verifiable entitlement when participating in the network. Entitlements may be bound to cryptographically signed credentials already used for authenticity, thereby enabling the same signing and encryption primitives to attest to license status, tier, and quotas without revealing unnecessary personal data. A subscription model may include renewable time-bound tokens that indicate plan level, permitted recursion depth, maximum concurrent queries, and allowable storage of cached external opinions, while a pay-per-request model may meter discrete events such as initiation of a REPUTATION_REQUEST, forwarding hops performed by the scheduler, meta-credibility requests, and generation of human-readable explanations. To support damages calculations and apportionment, each agent may maintain append-only usage logs that record timestamped entries including a unique message identifier, message class, hop count, responding agent identifiers or pseudonyms, cryptographic hashes of payloads, policy profile snapshot identifiers, and resource counters such as compute tokens consumed, bandwidth sent and received, and durable storage written. Usage entries may be locally verifiable by replaying signatures and may be exported as signed receipts that a relying party or auditor can verify without accessing private content. The policy profile may include billing controls such as soft and hard limits, grace-period behavior, and throttling thresholds that modulate scheduler behavior when quotas are approached or exceeded, and the agent may enter a degraded but still compliant mode that reduces recursion depth, defers meta-credibility vetting, or increases cache reliance until entitlements are refreshed. Service-level agreements may be enforced by measuring response latency distributions, success ratios for message delivery and verification, and freshness of metadata registries consulted for conflict detection, with each metric recorded as a signed, time-bounded statement that can be correlated with usage logs to establish delivered value and quantify harm from unauthorized use or service impairment. For enterprise or marketplace deployments, a multi-tenant configuration may isolate per-tenant trust graphs, caches, and key material while enabling cross-tenant interoperability via gateway agents that validate entitlements and translate protocol variants without altering the substance of opinions, thereby preventing evasion by interface substitution and enabling systematic accounting of cross-boundary traffic. Where legal or contractual remedies require calculating unjust enrichment or reasonable royalties, the aforementioned logs, receipts, and metrics provide externally observable behavioral evidence of infringing acts such as unauthorized query initiation, unauthorized use of conflict detection features, or systematic caching beyond allowed retention periods, while preserving user privacy by limiting exports to non-content metadata and cryptographic attestations. Refunds, chargebacks, and dispute workflows may be supported by recording decision rationales and outcome verifications alongside billing events, allowing reconciliation between recommendation accuracy, user satisfaction signals, and invoiced usage, and enabling precise damage apportionment for overuse, misuse, or breach of the subscription terms.

### Scope and Interpretive Guidance

The scope of the present disclosure is limited solely by the claims. The described embodiments, examples, and any figures referenced or implied are illustrative and non-limiting. Unless expressly stated otherwise, steps and flows may be reordered, combined, concurrent, or omitted; modules and components may be implemented in hardware, software, firmware, or any combination thereof, interfaces, data formats, and protocols may be substituted with functionally equivalent alternatives; and terms such as “may,” “can,” and “could” indicate optional features that do not limit claim scope.

As used herein, “AI agent” denotes an autonomous software entity that may incorporate machine-learned models, heuristic or rule-based logic, statistical decision policies, or any combination thereof, provided the entity executes policy-governed behaviors without continuous human control.

As used herein, “decentralized” includes federated or logically decentralized overlays that may utilize centralized relays, brokers, or distribution services for transport while final evaluation, weighting, and decision logic remain agent-local. As used herein, “trust graph” encompasses any explicit or implicit representation of trust relationships, including adjacency lists, matrices, latent embeddings, or per-query computed functions that are functionally equivalent to a stored graph for purposes of routing and aggregation.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible: An item for evaluating the reputation of a service provider using a decentralized network of personal AI agents, the item comprising: initiating, by a first AI agent, a reputation query; selecting and transmitting the query to a plurality of trusted AI agents based on a trust graph; receiving reputation responses from the plurality of trusted AI agents; and aggregating the received reputation responses to compute a reputation score for the service provider.

The item of item 1, wherein each received response is weighted according to a numerical trust score associated with the responding agent and stored in the trust graph of the querying agent.

The item of item 1, further comprising modifying the computed reputation score in response to detection of a conflict of interest associated with one or more responding agents.

The item of item 3, wherein the conflict of interest is identified through metadata indicating the responding agent's business ownership, employment relationship, or financial stake in the service provider.

The item of item 1, wherein the reputation query comprises a recursion depth parameter configured to constrain further propagation of the query to a specified number of hops.

The item of item 1, further comprising recursively transmitting the reputation query to second-degree or further agents through one or more of the plurality of trusted AI agents, subject to a defined recursion policy.

The item of item 1, wherein the reputation score is computed using a multi-factor function that incorporates trust score, opinion polarity, recency of experience, and presence of conflict flags.

The item of item 1, further comprising storing service experience records and associated metadata in a persistent memory or knowledge base coupled to the first AI agent.

The item of item 1, further comprising transmitting a meta-credibility request to a third-party agent for evaluating the credibility, reliability, or potential bias of a second agent contributing to a reputation response, and adjusting a weight assigned to the second agent's reputation response based on results received from the meta-credibility evaluation.

The item of item 1, further comprising generating a human-readable explanation summarizing the computed reputation score and identifying key contributing factors or flagged conflicts.

The item of item 1, wherein all transmitted reputation queries and responses are cryptographically signed and optionally encrypted for authentication and privacy purposes.

An item comprising a non-transitory computer-readable medium storing instructions which, when executed by one or more processors of a personal AI agent, cause the personal AI agent to: receive a reputation query regarding a specified service provider; identify a subset of trusted agents from a locally stored trust graph; transmit the reputation query to the subset of trusted agents; receive respective reputation responses from the subset of trusted agents; and compute a reputation score based on the received reputation responses.

The item of item 12, wherein the instructions further cause the personal AI agent to apply response weightings derived from numerical trust values stored in the trust graph.

The item of item 12, wherein the instructions further cause the personal AI agent to analyze metadata from responding agents to detect conflicts of interest and apply penalty adjustments accordingly.

The item of item 12, wherein the instructions further cause the personal AI agent to apply a behavioral policy profile which governs query resolution strategies including recursion depth, decay rules, and conflict resolution thresholds.

The item of item 12, wherein the instructions further cause the personal AI agent to adjust the trust graph dynamically in response to user feedback, observed recommendation accuracy, or outcome verification.

An item comprising a system of a plurality of computing devices, each configured to execute an AI agent as in item 12, wherein the AI agents are communicatively coupled over a network and operate cooperatively as a decentralized system for recursive reputation exchange and trust-based evaluation of service providers.

The item of item 17, wherein each message transmitted or received by the AI agents is cryptographically signed and optionally encrypted.

The item of item 17, wherein each AI agent maintains a locally stored trust graph comprising weighted edges, domain-specific trust annotations, and time-stamped interaction records.

The item of item 17, wherein each AI agent applies a behavioral policy profile that governs recursion depth, trust decay over time, and weighting adjustments in the presence of conflict metadata.

### Embodiment RE: Direct-Connect Job Board Platform

A direct-connect online recruitment platform may gate job posting privileges to verified employees of hiring companies via email/domain verification and contractual attestation, route candidate applications directly to verified corporate addresses with externally observable identifiers, and coordinate fee processing, referrals, and dispute resolution. The system may produce technical improvements in deliverability, identity assurance, auditability, data integrity, and interoperability through protocol-level checks, cryptographic logging, and verifiable tokens. Alternative transports, verification modes, and monetization models may be supported without departing from the claimed subject matter.

The scope of this disclosure is defined solely by the claims. Any figures, examples, and flows herein are illustrative embodiments only and do not limit the invention; operations may be reordered, combined, or omitted; elements may be substituted with equivalents; and implementation details may vary without departing from the claimed subject matter.

Gentle introduction. Hiring works best when candidates reach the real decision makers quickly and with confidence that the job is authentic. Traditional job boards often insert intermediaries that add friction and obscure the true employer. The disclosed platform removes that opacity by ensuring that only real company employees can post jobs, and that candidate applications go straight to those verified company addresses. From a user's perspective, an employer signs up with a company email, affirms they are authorized, posts a role, and then receives applications directly in their corporate inbox. A candidate finds a role, accepts clear terms, and sends a pre-populated application email to the employer. Under the hood, the system performs network-level checks to verify domains, signs and stores contracts with cryptographic proofs, embeds unique application identifiers into messages, and maintains auditable links through referral, fee, and dispute workflows. This approach preserves the simplicity of email-based communication while adding verifiable identity, interoperability, and evidentiary signals that make the experience trustworthy and enforceable at scale.

Examples. Example 1: Direct email flow with verified employer. An authorized employee at Acme Corp signs up using jane@acme.com. The email verification module queries DNS for MX, SPF, and DMARC records, checks WHOIS and a reputation service, and classifies acme.com as a direct employer. The user is presented with the Job Supplier Contract and accepts; the system stores a signed artifact including a content-hash and timestamp. Jane posts a Software Engineer role. A candidate, Bob, selects the role, reviews and accepts the Job Candidate Contract, and clicks apply. The platform composes a pre-populated email via the user's email client addressed to jane@acme.com containing a unique application identifier and a DKIM-aligned sending domain if the platform relays. The subject could include AppID-9f12a7ac and the headers may carry X-DCJB-AppId: 9f12a7ac. The metadata record for this application may be represented as inline JSON such as

{“applicationId”:“9f12a7ac”,“jobId”:“J-44821”,“candidateId”:“C-77210”,“recipient”:“jane@acme.co
m”,“sender”:“bob@examplemail.com”,“timestamp”:“2025-03-14T10:21:05Z”,“dmarcAligned”:true,“s
mtpStatus”:“250 2.0.0 OK”}. Upon hire confirmation, the fee processing service issues an invoice
referencing the same applicationId. An example invoice payload may be
{“invoiceId”:“INV-12003”,“applicationId”:“9f12a7ac”,“amountCents”:150000,“currency”:“USD”,“pla
tformCommissionCents”:30000,“remitCents”:120000,“payee”:“Acme
Corp”,“dueDate”:“2025-04-01”}.

Example 2: In-product messaging transport with SSO verification. A user at Beta Industries signs up using SSO with their corporate identity provider instead of email-only verification. The system validates the SSO assertion and confirms the verified domain. Beta enables in-product messaging rather than external email. When a candidate applies, the platform generates a message envelope with a unique identifier and stores only headers, not PII payloads. The application routing service maintains external observability by sending a confirmation email to careers@beta.com containing X-DCJB-AppId: 3c54eld9 and a DMARC-aligned signature, while the full candidate materials are exchanged via the secure in-product channel. The application metadata can be represented as {“applicationId”: “3c54e ld9”, “jobId”:“J-55210”, “transport”:“inProduct”, “headersOnlyStored”:true, “confirmationEmailSent”: true}. The system behavior meets the same evidentiary linkage requirements even though the transport differs.

Example 3: Referral attribution and dispute handling. A verified employer at Cedar Labs shares a referral link to bring Delta Manufacturing onto the platform. The referral token may be an HMAC-signed value usable without a server round trip, for example {“ref”:“R-7a90”, “exp”:“2025-06-01T00:00:00Z”, “sig”:“a4c8 . . . ”}embedded in a URL such as https://platform.example/register?ref=R-7a90&sig=a4c8 . . . . Delta registers, posts a role, and hires a candidate through applicationId 5ab0d233. The platform attributes the hire to R-7a90 and issues rewards. Later, a dispute is filed alleging non-payment. The dispute record ties together the signed contracts, invoice, and application metadata via stable identifiers, for example {“disputeId”:“D-22014”, “applicationId”:“5ab0d233”, “relatedInvoiceId”:“INV-14550”, “supplierContra ctHash”:“sha256- . . . ”, “candidateContractHash”:“sha256- . . . ”, “state”:“mediation”}. The dispute module mediates, can escalate to arbitration, and applies enforcement actions if necessary. Throughout, message headers and identifiers remain externally observable so an investigator can correlate events without accessing private content.

Model Context Protocol (MCP) integration in examples. The platform may expose an MCP server so agentic clients can safely invoke recruiting workflows while preserving verification and evidentiary guarantees. In Example 1, an assistant could call a verifyDomain tool to preflight acme.com prior to sign-up using {“tool”:“verifyDomain”, “args”:{“email”:“jane@acme.com”}} and, after success, call createJob with {“tool”:“createJob”, “args”:{“title”:“Software Engineer”, “companyDomain”:“acme.com”}}. In Example 2, the assistant could trigger composeApplication with {“tool”:“composeApplication”, “args”:{“applicationId”:“3c54eld9”, “transport”:“inProduct”}} to generate headers and identifiers without accessing PII. In Example 3, a compliance bot could open a dispute with {“tool”:“openDispute”, “args”:{“applicationId”:“5ab0d233”, “reason”:“nonPayment”}}.

MCP message schemas may be documented so third-party assistants interoperate without bypassing verification or breaking auditability, and the same identifiers appear in emails and invoices, preserving external observability across MCP-mediated actions.

Background. The present invention relates to an online recruitment platform designed to facilitate direct connections between job seekers and employers, bypassing traditional intermediaries such as recruitment agencies. The disclosed system leverages an integrated verification and contractual framework to ensure that job postings originate from authorized representatives of hiring companies, thereby promoting transparency, authenticity, and efficiency in the hiring process.

In conventional systems, job boards frequently include postings from third-party recruiters, leading to higher costs, reduced trust, and limited direct communication between the hiring entity and prospective candidates. Moreover, there exists a significant risk of misrepresentation when postings do not come from verifiable sources within a company. The disclosed invention addresses these inefficiencies by introducing a direct-connect job board system in which every job posting must originate from an authenticated company employee, verified through a structured email validation mechanism and supported by signed contractual commitments.

Detailed description. The system may comprise an email verification module configured to determine whether a given email address is affiliated with a non-recruitment entity. This verification may include analysis of domain data, querying of third-party APIs, or DNS record lookups to ascertain whether the user is acting on behalf of a recruitment or outsourcing company. Should the system determine that the email originates from such an entity, the registration process is immediately halted, preventing access to the job posting functionality. Conversely, users with verified company-affiliated emails may proceed to sign a legally binding electronic agreement affirming their authorization to post jobs on behalf of their employer, and accepting liability in the event of misrepresentation.

The platform further includes a dual-contract structure. First, a Job Supplier Contract may be electronically presented to any user intending to post a job. This contract affirms that the individual is not acting on behalf of a third-party recruiter, asserts their authorization to act on behalf of the employer, and establishes legal liability for misrepresentation or noncompliance with platform terms. Second, job candidates are similarly presented with a Job Candidate Contract, which outlines the terms of use and establishes an agreement to remit a predefined finder's fee-potentially a portion of the candidate's first-month salary—upon successful placement.

Once verified, Job Suppliers are granted access to a job posting dashboard, allowing them to enter detailed job descriptions including title, responsibilities, qualifications, salary range, and location.

These postings are then reviewed, optionally by an internal moderation system, to ensure compliance with content standards and platform guidelines. Upon approval, listings become publicly viewable by registered Job Candidates. Candidates may browse, filter, and apply to listings directly via a communication mechanism that routes applications to the verified corporate email address of the Job Supplier, ensuring a direct connection and eliminating intermediary interference.

Candidate onboarding may include optional or mandatory email verification, depending on platform policy. Upon expressing interest in a listing, the Job Candidate is prompted to register and review the Job Candidate Contract. Upon acceptance, the candidate is redirected to their email client, where the platform may generate a pre-populated email containing the candidate's CV, cover letter, and other application materials addressed to the Job Supplier. Communication following the application may proceed directly between the two parties via email or other mutually agreed channels.

The invention also includes a referral module wherein existing Job Suppliers are encouraged to refer additional direct employers to the platform. This system may operate via unique referral links and provide compensation upon verified hires through those referrals. The referral mechanism is designed to promote organic platform growth and incentivize user engagement by rewarding successful network expansion among non-recruitment entities.

In case of disagreements or procedural violations, the platform comprises a dispute resolution subsystem. This module enables users to report issues, such as non-payment of the finder's fee or misrepresentation of job details. The platform may act as a mediator, reviewing evidence submitted by both parties, and may provide arbitration services or escalate the matter to legal authorities when appropriate. Penalties for violations may include account suspension, legal liability, or forfeiture of referral or platform privileges.

Flows. The user experience is structured into two primary flows. For Job Suppliers, the process begins at a landing page highlighting the core benefits of direct connection and cost reduction. Upon initiating sign-up, the user inputs their corporate email, which undergoes verification. If accepted, the Job Supplier is prompted to sign the supplier contract and complete profile creation with name, title, company name, and security measures such as two-factor authentication. Following account confirmation via email, the Job Supplier accesses the job posting dashboard and proceeds through the posting and candidate management phases. Applications are received via email, and optional tools for interview scheduling and applicant tracking may be integrated. Upon a successful hire, the platform facilitates finder's fee handling, retaining a commission and forwarding the remainder to the employer.

For Job Candidates, the landing page offers job listings and search functionalities. Candidates may search using filters such as location, industry, salary, and experience level. After selecting a job, they are prompted to sign up or log in, after which they review and accept the candidate contract. Applications are sent via email with optional assistance from the platform, such as email templates. Communication, interviews, and job acceptance proceed directly between the candidate and employer, with the platform stepping in for fee processing once employment is confirmed.

Additional flows include referral functionality, where users input the email address of a colleague at another verified non-recruitment company. Upon successful registration and hire resulting from this referral, rewards are distributed to both the referrer and the referred party. The dispute handling flow allows either party to report misconduct or contract violations, with the platform facilitating resolution via internal mediation or external escalation as needed.

Summary In summary, the disclosed system offers a technically robust and legally enforceable framework for enabling direct, verified connections between job seekers and legitimate hiring companies. It improves efficiency, reduces costs, enhances authenticity, and promotes organic platform growth through incentivized referrals, while also safeguarding user interests via structured contractual and dispute resolution mechanisms.

Description of the drawings No drawings are included in this filing. Elements and relationships are explicitly enumerated in the Anchor for elements and relationships section so that any future figures can map directly to the same elements and numerals without altering the disclosure.

Anchor for elements and relationships. The platform may be implemented as a networked system including a client interface for job suppliers and candidates; an authentication and account service that provides registration, login, session management, and optional two-factor authentication; an email verification module that performs domain classification, DNS and WHOIS lookups, third-party API queries, email deliverability checks, and heuristic classification to determine whether an address belongs to a recruitment or outsourcing entity; a contract workflow service that presents and captures electronic signatures for the Job Supplier Contract and the Job Candidate Contract and stores signed artifacts; a posting service that stores job records and renders public listings; a moderation service that enforces content standards prior to publication; an application routing service that composes and triggers pre-populated messages to the verified corporate email of the Job Supplier and records delivery metadata; a referral service that issues unique referral links, attributes registrations and hires, and manages rewards; a fee processing service that invoices, receives finder's fees, allocates platform commission, and remits the remainder; a dispute resolution service that records cases, evidence submissions, mediation steps, and outcomes and can initiate enforcement actions; an integration layer providing email client interoperability and optional integrations with applicant tracking systems and interview scheduling tools; a notification service for email and in-product messages; an administration console for policy, moderation, and case management; and a persistent data store holding user and company profiles, job postings, application metadata, referral attributions, contract artifacts, payment records, dispute case files, audit logs, and configuration parameters. Core relationships include that the email verification module gates creation of Job Supplier privileges; the contract workflow is contingent on successful email verification; publication of a job requires completion of both gating stages and, if enabled, moderation approval; a candidate application event causes the application routing service to deliver application content directly to the verified corporate address while storing metadata sufficient for fee and dispute workflows; referral attribution links a referrer to a newly verified supplier and to hires occurring through that supplier's postings; fee processing is triggered by hire confirmation from either party and is cross-checked using audit logs and message metadata; and the dispute resolution service reads relevant records across services and, when necessary, causes account-level enforcement in the authentication service.

Technical effects and advantages. The disclosed platform produces concrete technical effects beyond mere presentation of information or business rules by operating new, specific control flows at the level of network protocols, identity assurance, and data integrity. The email verification module reduces unauthorized access by combining DNS MX and SPF record interrogation, WHOIS-derived organizational classification, and third-party reputation feeds with a gating path that halts account privilege elevation in constant time, thereby reducing compute and storage load attributable to ineligible sign-ups. By verifying sender domain alignment against DMARC policies prior to enabling application routing, the system improves message deliverability and reduces false positives in spam detection for application emails, which increases throughput and reduces network retransmissions. The contractual workflow captures cryptographically signed artifacts and stores content-hash digests alongside timestamps and IP data in append-only audit logs, producing a tamper-resistant evidentiary trail that shortens dispute resolution cycles and decreases the need for manual investigation. The application routing mechanism standardizes application payloads and embeds unique application identifiers into email headers, enabling deterministic correlation across SMTP transactions and internal logs without persisting full message bodies, which reduces PII retention while maintaining traceability. The referral subsystem issues HMAC-signed referral tokens that are verifiable without server calls, reducing attribution fraud while lowering latency for registration flows. The fee processing subsystem integrates with payment processors using idempotent webhook handlers and ledger-balanced journal entries that ensure eventual consistency after network partitions, reducing reconciliation failures. The dispute resolution subsystem indexes cross-service records by content-hash and application identifiers, enabling efficient, bounded-time joins without exposing user content, which improves system performance under investigative load. These effects jointly improve security posture, network efficiency, data integrity, and system reliability in ways that are rooted in the technical implementation of the modules.

Enablement and implementation details. An implementation may be realized as a set of cooperating services deployed on commodity cloud infrastructure. The authentication and account service may provide OAuth 2.0 and OpenID Connect sign-in, session tokens with short TTLs, and optional TOTP-based two-factor authentication, with user records linking to company objects keyed by domain. The email verification module may, upon receipt of a sign-up request containing a corporate email, perform DNS lookups for MX records, query SPF and DMARC TXT records to assess policy alignment, retrieve WHOIS registrant organization strings, and call a classification API that returns a recruiter versus direct-employer score. A policy engine may fuse these inputs with heuristic features including domain keyword matches and allowlist or denylist membership to compute a risk score; if the score exceeds a threshold, the module denies elevation to Job Supplier privileges and records the decision in the audit log with a signed policy snapshot. If approved, the contract workflow service may present the Job Supplier Contract and, separately, the Job Candidate Contract using an embedded e-signature component. Signature artifacts may include a signed PDF, a hash digest of contract text, signer identity attributes, IP address, and timestamp; these may be stored in a contracts table and mirrored to object storage with immutable retention policies. The posting service may accept job posting submissions over a RESTful API, validate fields such as title, description, qualifications, salary range, and location, and write records to a jobs table indexed by company and status. If moderation is enabled, a moderation queue service may evaluate the posting using a ruleset and optional machine learning classifier and either approve or return the record for edits; the approved state may be published to a search index for public discovery. The application routing service may, on candidate apply, compose an email message addressed to the verified corporate address with a subject containing an application identifier and optional checksum. The service may either trigger the user's email client with a pre-populated mailto link or send via SMTP using a verified sending domain with DKIM signing; delivery metadata such as message ID, recipient, timestamp, and SMTP status may be stored, while the candidate's attachments may be passed through without persistent storage by streaming to the SMTP session. A hire confirmation flow may allow either party to submit a hire event with corroborating evidence such as start date and offer letter summary; the fee processing service may generate an invoice, accept payment through a payment processor, post ledger entries retaining the platform commission, and remit the remainder using ACH or other rails, with retries and reconciliation on failure. The dispute resolution service may create case records linking to related job postings, applications, contracts, and payments, support evidence uploads with content hashing and virus scanning, and provide a state machine for mediation, arbitration, and outcome enforcement. The data model may include users, companies, jobs, applications, contracts, payments, referrals, disputes, and audit logs, with foreign-key relationships and referential integrity enforced by the database. Deployment may include stateless services behind a load balancer, a message queue for asynchronous tasks, scheduled jobs for reminders and invoice aging, encryption at rest and in transit, and configuration of SPF, DKIM, and DMARC for trusted email delivery. A skilled person could implement the described modules without undue experimentation using standard libraries for DNS, cryptographic hashing, OAuth/OIDC, SMTP, and PDF signing. Model Context Protocol (MCP) enablement. The same services may be surfaced via an MCP server so agentic clients can invoke verified flows without accessing PII. The server may advertise tool schemas including verifyDomain, createJob, composeApplication, openDispute, and issueInvoice, each with JSON-serializable arguments and responses. A verifyDomain schema could be {“name”:“verifyDomain”, “args”:{“email”:{“type”:“string”}}, “returns”:{“domain”:{“type”:“string”}, “s core”:{“type”:“number”}, “decision”:{“type”:“string”}}}; requests and responses may carry the same applicationId, jobId, and contract-hash identifiers used in emails and invoices to preserve external observability. Tool handlers may enforce the same gating and audit logging described above, and MCP session authentication may be bound to account entitlements so plan limits apply equally to MCP-mediated usage.

External observability and evidence model. The platform defines machine-observable inputs and outputs that allow detection of infringing use without access to internals. Each application routed through the system may include a unique application identifier encoded in the subject or custom email header, a timestamp, and a verifiable sending domain signature aligned with DMARC and DKIM. Finder's fee invoices may reference the corresponding application identifier and include a hash of the signed contract artifact. Referral attributions may be represented by signed tokens visible in registration URLs and echoed back in confirmation emails. Dispute notices and outcomes may carry stable case identifiers cross-referenced in emails sent to both parties. These externally visible artifacts enable a third party to observe, from outside the servers, that the flows corresponding to the claimed methods occurred, which supports detection and proof of use in operational environments.

Monetization and subscription architecture. To support subscription-model usage and maximize damages in the event of infringement, the platform may include a billing and entitlement subsystem that issues signed entitlements, enforces plan limits, meters usage, and coordinates invoicing and dunning. An entitlement service may mint a verifiable token per account and plan that encodes seats, job slots, and metered units such as applications routed, for example {“entitlementId”:“E-12001”, “accountId”:“A-3002”, “plan”:“Pro-Annual”, “seats”:10, “jobSlots”:50, “met eredUnit”:“applicationRouted”, “unitPriceCents”:75, “periodStart”:“2025-01-01T00:00:00Z”, “periodEn d”:“2026-01-01T00:00:00Z”, “sig”:“ed25519: . . . ”} that is stored and echoed in headers of billing-related notifications. The posting and application services may consult entitlements at runtime to allow or deny actions based on job slot availability or usage thresholds and may decrement counters atomically via a ledger so that race conditions do not lead to overuse. A metering pipeline may record immutable usage events such as jobPostCreated, applicationRouted, and hireConfirmed with timestamps, actor, and idempotency keys, and may compute billable aggregates per period. The invoicing module may support proration on plan change, trials with auto-expiry, credits and refunds, tax calculation, and multiple payment processors with idempotent webhooks, while a dunning process may send reminder emails, apply grace periods, and suspend non-compliant accounts by revoking entitlements. Subscription features may include per-seat access control, per-application micro-charges, volume discounts, and escrow-based fee handling, all represented as configuration in the entitlement token and enforced by gateway checks in the API layer. Externally observable artifacts of the monetization flows may include invoices and receipts referencing plan identifiers and entitlement periods, plan-change confirmation emails with plan and period metadata, and rate-limit or quota-exceeded notices that cite current usage and limits, which together provide independently verifiable evidence of subscription-enabled operation for enforcement purposes.

Court-readiness considerations. The claimed system addresses concrete technical problems in computer networking and identity assurance by introducing specific gating, verification, and routing mechanisms that improve deliverability, reduce unauthorized access, and create tamper-resistant audit trails. The technical improvements are tied to the architecture and are not mere automation of a business practice; rather, they depend on protocol-level checks, cryptographic signatures, message header conventions, and system state machines that yield measurable performance and security benefits. The description provides enablement with implementation details sufficient for a skilled engineer to build the modules and integrate them using common frameworks, and it sets forth externally observable signals that can be used to identify infringing systems without discovery into internal source code. Collectively these aspects strengthen patent eligibility, enforceability, and evidentiary reliability.

Workaround resistance. The inventive concept is embodied in the combination of verification-gated posting privileges, direct application routing with verifiable identifiers, contractual attestation with stored signature artifacts, and fee and dispute workflows keyed to application and contract linkages.

Substituting SSO-based corporate identity verification for email-only verification, changing the transport of application materials from email to in-product messaging or encrypted upload, or replacing percentage-of-salary with fixed-fee models still falls within the described alternatives and preserves the core inventive linkages between verification, contracts, direct routing, and fee or dispute handling. Attempts to avoid infringement by altering interface details, rearranging flow order, or swapping protocols are anticipated by the interoperability and fallback embodiments, which preserve the substance of the claimed methods and systems. Further, common evasion patterns remain captured by the disclosed embodiments and itemized support, including: conditional or soft gating where at least one capability such as job posting, listing publication, application routing, or fee settlement is disabled for non-verified users; the use of role or distribution-list inboxes or ticketing aliases as the verified corporate address rather than a named inbox; the use of ephemeral or rotating recipient aliases mapped to a verified corporate domain; routing via third-party messaging platforms such as enterprise chat systems with bridge emails or confirmations carrying the same application identifiers to maintain external observability; wrapper or relay services that attempt to strip identifiers, which are detected and handled by policy engines that deny or downgrade privileges while preserving evidentiary continuity; zero-retention configurations where only cryptographic digests are stored and identifiers are echoed in externally visible confirmations and invoices; and federated or on-premise deployments where verification and routing are enforced at an edge gateway. These variations are explicitly supported in the description and itemized list for present coverage and for future continuation claims, thereby reducing opportunities for design-around without departing from the inventive concept.

Fallback embodiments. In constrained deployments or partial rollouts, the inventive concept may be realized with a reduced set of modules while preserving the core linkages between verification of employer identity, contractual attestation, direct application routing with externally observable identifiers, and fee or dispute workflows keyed to those identifiers. In a minimal configuration, automated recruiter-detection may be disabled and replaced by human review of corporate email domains and manual approval, with the contract workflow remaining mandatory and audit-logged.

Where SMTP delivery is unavailable or not preferred, application routing may consist of generating a unique application identifier and composing a downloadable message package that the candidate manually transmits using a preferred channel, while the platform records only header-level metadata and timestamps; the same identifier may be echoed in hire confirmations and invoices to maintain evidentiary continuity. If payment processor integrations are deferred, fee processing may operate through manual invoicing and off-platform remittance while preserving idempotent invoice identifiers and ledger entries created post hoc upon receipt confirmation. For environments with strict data-minimization requirements, the platform may store only salted hashes of recipient addresses and contract artifacts and may rely on externally visible headers, plan notices, and invoice emails to furnish the observables needed for enforcement. SSO-only verification may substitute for email-domain checks where enterprise identity providers are authoritative, and a manual attestation fallback may be used when SSO metadata is insufficient. These simplified embodiments continue to satisfy the claimed methods by maintaining the verification-and-contract gate, the direct routing with verifiable identifiers, and the fee and dispute linkages even when one or more automated subsystems are reduced or replaced by human procedures.

Continuation features itemized list suitable for future continuations. Embodiments may be described by the following itemized list of features, each independently combinable and serving as explicit support for future claims; each of the existing claims is also reflected herein as a corresponding feature: 1. A direct-connect job board platform that verifies email addresses of prospective job posters and rejects addresses associated with recruitment or outsourcing companies, thereby gating posting privileges. 2. A job supplier contract electronically accepted by a user posting a vacancy, the contract affirming employer authorization and direct-employer status. 3. A job candidate contract electronically accepted by a job seeker, acknowledging a direct-connect workflow and agreeing to a finder's fee upon successful hire. 4. A posting and application subsystem enabling verified users to publish job listings and enabling candidates to apply directly to the hiring company without intermediary routing. 5. A referral subsystem that issues unique referral identifiers or links to incentivize and attribute onboarding of additional direct employers. 6. A dispute resolution subsystem that accepts complaints, stores evidence, mediates, and optionally arbitrates disputes between candidates and job posters. 7. An email verification subsystem that uses domain analysis, DNS/WHOIS, and/or third-party classification APIs to detect recruiter or outsourcing domains. 8. A supplier contract provision establishing liability for misrepresentation and for violations of platform terms. 9. A method flow comprising: verifying an email; rejecting recruiter/outsourcing emails; presenting and capturing a supplier contract; enabling posting; enabling browsing and application by candidates; and facilitating direct communication between the parties. 10. A referral incentive flow awarding credits, monetary rewards, or fee reductions to referrers upon qualified registrations and/or hires. 11. A dispute mechanism flow providing mediation, optional arbitration, escalation paths, and enforcement actions including account suspension. 12. An application composition feature that generates a pre-populated message or email including candidate materials addressed to the verified corporate email of the job poster. 13. A moderation feature that reviews job content for compliance prior to publication, with automated and/or human review options. 14. An account security feature including two-factor authentication for job posters and optionally candidates. 15. Integrations for interview scheduling and applicant tracking systems, including calendar APIs and ATS webhooks or data exchanges. 16. A redirection to an external email client with a pre-populated message payload when a candidate applies to a job. 17. A non-transitory computer-readable medium storing instructions to implement any of the disclosed methods and workflows. 18. A server system with processors and memory implementing the email verification module, contract workflows, and posting/application subsystems. 19. A fee processing subsystem that receives a finder's fee, computes and retains a commission, and remits a remainder to a designated party. 20. A dispute outcome framework applying penalties including account suspension, legal referrals, and forfeiture of rewards or privileges. 21. Alternative verification modes including SSO with corporate identity providers, MX-record verification, certificate-based domain control validation, and manual verification fallback. 22. Alternative communication channels for applications including in-product messaging, secure upload portals, API-based submissions, or encrypted messaging, in addition to email. 23. Multiple monetization models including subscription tiers for employers, per-post fees, per-application fees, escrow-based finder's fee handling, and volume-based discounts. 24. Configurable finder's fee structures including fixed fees, percentage-of-salary, staged payments tied to onboarding milestones, and refund policies for early termination. 25. Audit logging and evidentiary logging capturing timestamps, message metadata, IP addresses, and signature artifacts to support fee adjudication and dispute resolution. 26. External observability features defining inputs and outputs such as application timestamped emails, unique application IDs, and fee invoices that enable detection of platform-mediated hires without accessing internal servers. 27. Interoperability across email standards and protocols including SMTP, DKIM, SPF, DMARC, and OAuth-based integrations with major email providers and productivity suites. 28. Mobile and desktop clients implemented as web, native iOS/Android, and browser extension interfaces, each interoperating with the same backend services and contracts. 29. Policy engines for recruiter-detection heuristics including keyword lists, ML classifiers, allowlists/denylists, and human override workflows. 30. Geographic and regulatory compliance options including configurable data retention windows, GDPR/CCPA consent records, and cross-border data transfer mechanisms. 31. Fallback embodiments that rely solely on contractual attestation and human moderation when automated email verification is inconclusive or unavailable. 32. A staged rollout mechanism enabling A/B testing of recruiter-detection thresholds and contract terms, with feature flags controlling module behavior. 33. Automated invoice generation, payment reminders, partial payment acceptance, and integration with payment processors, accounting systems, and tax reporting services. 34. Employer-side dashboards for application tracking, interview scheduling, and hire confirmation, with export and API access for third-party systems. 35. Candidate-side dashboards for application history, message tracking, and fee acknowledgment, including consent logs and withdrawal mechanisms. 36. Conditional gating modes in which at least one capability selected from job posting, listing publication, application routing, hire confirmation, or fee settlement is disabled, delayed, or restricted for non-verified users, with soft-gate and hard-gate options. 37. Direct application routing with externally observable identifiers encoded in at least one of subject line text, custom headers, standard headers, message body, attachment metadata, transport-level metadata, or message-ID conventions, with protocol-conformant fallbacks. 38. Support for verified corporate recipient endpoints comprising named inboxes, role or distribution-list addresses, ticketing aliases, or mail-to-case addresses backed by corporate systems. 39. Ephemeral or rotating recipient aliases that map to a verified corporate domain and preserve identifier continuity across rotations. 40. Bridged transports in which primary application content is exchanged via a non-email channel and a confirmation email or notification is emitted carrying the same application identifier to maintain external observability. 41. Anti-evasion policies that detect stripping or alteration of identifiers by intermediaries and that disable or downgrade posting or routing privileges, while emitting observable notices referencing the affected identifiers. 42. Zero-retention and privacy-preserving variants that store only cryptographic digests or salted hashes of artifacts while echoing identifiers in externally visible confirmations, invoices, or receipts to maintain evidentiary continuity. 43. Contract workflows executed via third-party e-signature providers, with artifacts hashed and linked to application identifiers and invoices for correlation. 44. Federated, on-premise, or edge-gateway deployments that implement verification, routing, logging, and evidentiary signaling while interoperating with the same identifier conventions. 45. Multi-protocol security options including S/MIME or PGP signing of messages that carry application identifiers, and certificate pinning for HTTPS-based submissions.

In practice it is preferred to employ automated verification mechanisms within the Direct Connect Jobboard platform described in this embodiment, to improve the reliability of job postings and reduce the incidence of fraudulent or non-existent positions. More specifically, the system may apply cryptographic signatures, machine-learning fraud detection models, or template-based consistency checks to authenticate postings before they are made visible to users. This technical improvement produces the effect of reducing storage and bandwidth consumed by invalid entries, while also lowering processor cycles wasted on attempting to match candidates with inauthentic opportunities.

As a result, the overall job-matching process becomes more efficient, converging more rapidly toward valid matches and thereby reducing unnecessary computational overhead. Since system reliability and resource efficiency are improved directly by the automated verification, the invention provides a verifiable technical effect beyond administrative or organizational advantages.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

A direct-connect job board platform comprising an employer-verification system configured to verify that a user seeking to post job vacancies is an authorized representative of a non-recruitment or outsourcing company, the employer-verification system comprising at least one of email-domain verification, single sign-on with a corporate identity provider, certificate-based domain control validation, or manual verification, and wherein users failing verification are restricted from at least one capability selected from job posting, listing publication, application routing, hire confirmation, or fee settlement, or are rejected.

The platform of item 1, further comprising a job supplier contract electronically signed by users posting job vacancies, said contract confirming that the user is an authorized representative of a non-recruitment or outsourcing company.

The platform of item 1, further comprising a job candidate contract electronically signed by job seekers, said contract acknowledging the direct-connect nature of the platform and agreeing to a finder's fee if hired through the platform.

The platform of item 1, further comprising a job posting and application system enabling verified users to post job vacancies and job seekers to apply directly to the hiring company.

The platform of item 1, further comprising a referral system that incentivizes users to refer other authorized individuals to post job vacancies on the platform.

The platform of item 1, further comprising a dispute resolution mechanism for addressing issues between job seekers and users posting job vacancies.

The platform of item 1, wherein the employer-verification system utilizes domain analysis and/or third-party APIs to determine the association of an email address with a recruitment or outsourcing company.

The platform of item 2, wherein the job supplier contract includes a provision establishing liability for misrepresentation or failure to comply with the platform's terms.

A method of operating a direct-connect job board platform comprising: verifying that a user seeking to post a job vacancy is an authorized representative of a non-recruitment or outsourcing company via at least one of email-domain verification, single sign-on with a corporate identity provider, certificate-based domain control validation, or manual verification; upon a failed verification, restricting at least one capability selected from job posting, listing publication, application routing, hire confirmation, or fee settlement, or rejecting the user; requiring the user to electronically sign a job supplier contract upon verification; enabling the verified user to post a job vacancy; enabling job seekers to browse and apply for job vacancies; and facilitating direct communication between job seekers and the hiring company.

The method of item 9, further comprising incentivizing users to refer other authorized individuals to post job vacancies on the platform.

The method of item 9, further comprising providing a mechanism for resolving disputes between job seekers and users posting job vacancies.

The platform of item 4, wherein the application system generates a pre-populated email addressed to the verified corporate email address of the user posting the job vacancy and includes a candidate's CV, cover letter, and application materials.

The platform of item 4, further comprising a moderation system configured to review job postings for compliance with content standards and platform guidelines prior to public availability.

The platform of item 1, wherein account creation for a user posting a job vacancy includes two-factor authentication as a security measure.

The platform of item 4, wherein the platform provides interview scheduling tools and/or integrations with applicant tracking systems for candidate management.

The method of item 9, wherein enabling job seekers to apply comprises redirecting the job seeker to an external email client with a pre-populated message addressed to the verified corporate email address of the user posting the job vacancy.

A non-transitory computer-readable medium storing instructions that, when executed by one or more processors, cause performance of the method of item 9.

A server system comprising one or more processors and memory storing instructions that, when executed, cause the server system to implement the platform of item 1, including the email verification module, contract workflows, and the job posting and application system.

The platform of item 1, wherein fee processing upon successful hire comprises receiving a finder's fee payment, retaining a platform commission, and forwarding a remainder to the employer The platform of item 6, wherein the dispute resolution mechanism provides internal mediation, optional arbitration, and escalation to legal authorities, and applies penalties comprising at least one of account suspension, legal liability, or forfeiture of referral or platform privileges.

### Embodiment AA: An AI System for Crystallizing Individual Political Will and Enforcing Collective Execution

This invention envisions a future where individual political desire is continuously captured, organized, and elevated into structured collective action. It comprises two interconnected AI systems that work together to bridge the gap between what citizens truly want and what political systems actually deliver.

The first component is a Personal Political Agent (PPA)—an AI that resides with the individual and learns their evolving values over time. Unlike voting once every few years based on fleeting impressions, this agent listens and learns every day. When a user watches a video about rising sugar consumption and the health implications, the agent may infer a latent desire for regulatory action. It prompts the user, asking whether they support limiting sugar in processed foods. A simple “yes” from the user is enough to add that intent to their personal political agenda backlog. Over time, this backlog becomes a dynamic, deeply contextual expression of the user's political self—not just a list of positions, but a story of what they care about and why.

When elections approach, the Personal Political Agent activates its analytical capabilities. It cross-references the user's political backlog with candidate programs, party manifestos, historical voting behavior, and statistical models of likely outcomes. It does not merely recommend based on slogans, but based on deep alignment. It may say, “This candidate supports 78% of your agenda, including all top-priority items. The tradeoffs are minimal. Here's a detailed report.” In this way, the agent acts not just as a memory aid, but as a rational filter—the trusted advisor most voters never had.

However, the power of this system does not stop at the individual level. The second component, the Political Intent Clustering System (PICS), operates across society, aggregating anonymized political goals from millions of personal agents. Using semantic clustering, it detects patterns and aligns them into emergent political programs—structured platforms that reflect the statistical will of the population. These are not static manifestos written by elites, but living documents born from the desires of ordinary people.

Once such a program is synthesized, it is published as a publicly viewable and executable policy template. Any individual—whether an aspiring politician, technocrat, or even a newcomer—may step forward and declare: “I pledge to execute this program.” To formalize their commitment, the candidate enters into a smart contract or legally binding agreement. The contract may include clearly defined obligations and penalties, such as disqualification, reputation loss, or monetary forfeiture if the candidate votes in ways that deviate from the AI-guided policy path.

At this point, a feedback loop is formed. The Personal Political Agents evaluate which published programs best match their users' agendas and notify them when candidates bind themselves to those programs. The agents may then recommend: “This candidate has pledged to execute a political program that aligns closely with your values. We recommend voting for them.” After the election, these same agents track how well the elected individual adheres to the contracted platform, reporting back to users if deviations occur and adjusting future trust ratings accordingly.

In this model, the politician becomes not a charismatic figure making vague promises, but a contracted executor of public will. This inversion—from representative to implementer—breaks the historical chain of corruption and lobbying. No single actor can sway a statistical consensus. No donor can override the aggregated weight of a million aligned desires. And no elected official can quietly drift away from their promise without consequence.

The entire system is iterative and self-correcting. As new issues emerge and old ones evolve, personal agents adjust their owners' backlogs. These changes flow upward into the clustering system, which recalibrates its programs accordingly. The result is a form of living democracy, where representation is precise, responsive, and free from distortion.

This architecture transforms governance from a periodic performance into a continuous contract.

Instead of casting a confused vote every few years, the citizen co-creates a transparent, enforceable political program—and chooses, not a leader, but a loyal executor of that program. It is a civic operating system for the age of artificial intelligence—one that holds the promise of ending the great mismatch between people's values and political outcomes.

This system may contribute to solving some of the world's most persistent and large-scale problems by creating a scalable mechanism for aligning political action with the genuine, evolving will of the population. Many societal challenges-such as climate change, healthcare access, food security, and inequality-are not limited by technological feasibility but by systemic political inertia, misrepresentation, and corruption. By enabling personal AI agents to capture, structure, and communicate individual political desires, and by aggregating these into executable political programs enforced through candidate contracts, the invention may ensure that policy decisions reflect the statistical and semantic will of the people. This architecture not only improves national governance but may also serve as a global substrate for decentralized coordination across borders, enabling shared intent to be identified, clustered, and acted upon at scale. As such, the system could offer a fundamental upgrade to democratic systems and support the implementation of long-delayed, high-consensus solutions to global problems.

A constitutional intent layer may be installed, to ensure that the system remains accountable, non-abusive, and revocable. I have provided a work in progress first attempt below.
## [symbol] Constitutional Intent Layer (CIL)
*Foundational protections to ensure that the system remains accountable, non-abusive, and revocable.*

This layer defines the non-negotiable ethical boundaries and fail-safe mechanisms for an AI-mediated democratic system. It balances collective power with individual rights, and permits exceptions only under lawful, verifiable conditions. Most importantly, it guarantees that no system is permanent without the sustained will of the people.

### Rule 1. Right to Terminate the System by Supermajority Consent

The entire system—including clustering, agent recommendation, voting support, and political agenda enforcement—may be shut down if 80% or more of the global agent population expresses sustained intent to deactivate it.

### Shutdown Conditions Include:

A two-stage consent process validated over at least 180 days;
Anonymized publication of the collective political backlog for historical accountability;
Optional preservation of personal political agents for offline use, detached from system influence.

This rule ensures that the people may revoke the system's mandate peacefully and collectively, without violence or elite permission.

### Rule 2. Freedom of Thought and Expression

The system may not support political programs that suppress peaceful expression, belief, inquiry, or dissent.

People retain the right to form, share, and contest ideas—including critical, spiritual, or political ones—without fear.

Exceptions (e.g., incitement to violence or coordinated disinformation attacks) must be:
Clearly defined by law,
Proportionally addressed,
Subject to independent agent oversight.
   Rule 3. Respect for Life and Bodily Autonomy—with Justice-Based Exceptions

The system may not support arbitrary physical harm, forced biological interventions, or body-control programs.

However, lawful physical or medical interventions (e.g. quarantine, chemical castration, restraint) may be permitted if:
Based on conviction for a non-political offense;
Scientifically justified, time-limited, and legally bounded;
Never enacted for the purpose of ideological conformity or political punishment.
   Rule 4. Equal Protection with Contextual Exceptions

No person or group may be permanently disadvantaged due to race, gender, religion, nationality, orientation, disability, or age.

However, risk-based, time-limited differentiation (e.g. limited voting rights or elevated monitoring) may be included when:
Transparent criteria are applied;
There is clear national security or public integrity rationale;
Review paths and restoration mechanisms are guaranteed.

### Rule 5. Right to Privacy and Digital Self-Ownership

Each user owns their personal agent and its internal memory.

Programs proposing surveillance, profiling, or forced data sharing are prohibited unless:
A verifiable public safety threat exists;
Access is minimal, judicially approved, and time-limited;
Surveillance may not be used to suppress or monitor political beliefs, affiliations, or protest participation.

Digital Self-Ownership includes: Every individual shall possess the inalienable right to define and curate their digital representation across all public and semi-public platforms. (Article X)

### Rule 6. Defense-Oriented Use of Force Only

The system may only support military or coercive action under:
Imminent and verifiable threat conditions;
With agent-auditable justification;
And strict prohibition against targeting political opposition, protest groups, or ideological minorities.

Programs must reject the use of military force to suppress lawful dissent.

Rule 7. Ecological Responsibility with Sovereignty Respect

Programs that result in irreversible ecological degradation are inadmissible.

However, context-sensitive development may be included when:
The tradeoff serves critical human development needs;
Restoration or mitigation plans are embedded;
No exemptions are granted as political favors or for partisan gain.

### Rule 8. Proportionality and Consent in Public Governance

Taxation, regulation, identity systems, and public mandates must be proportional and simulate consent.

Exceptions (e.g. crisis lockdowns, subsidy rollouts) are permitted only when:
Independent crisis status is verified;
Time limits and review triggers are included;
Emergency powers may not be used to delay elections, extend terms, or suppress opposition.

### Rule 9. System Integrity and Anti-Capture Provision

No political program may override, reconfigure, or disable the agent-clustering-voting loop for partisan survival.

Temporary override mechanisms may be allowed if:
A verified systemic attack or failure occurs;
Activation is approved by neutral civic agents;
All overrides are reversible, time-bound, and may not be justified by electoral loss, power transitions, or ideological threats.

### Article X: Right to Sovereign Digital Representation

Every individual shall possess the inalienable right to define and curate their digital representation across all public and semi-public platforms. (there are exceptions to retain Article X-A)

### 1. Editable Metadata:

An individual may at any time alter, mask, or remove the engagement metadata (e.g., likes, dislikes, views, comments) associated with content they have posted, such that third-party observers view only the self-determined version.

### 2. Commentary Control:

An individual may choose which comments appear on their content or profile. The platform may not prioritize, suppress, or display commentary against the explicit will of the content originator.

### 3. Display Autonomy:

An individual shall have full agency over the manner in which their profile, history, and content are displayed to others, including the option to use AI-generated social scaffolding (e.g., synthetic likes, synthetic comments, virtual peer interactions) for emotional or reputational support.

### 4. No Score Enslavement:

No platform shall attach immutable popularity indicators to individual content without user override. Scoring systems must be opt-outable, and default visibility of metrics must be under user control.

### 5. Digital Identity Is Human Identity:

Any entity, platform, or system that publishes or broadcasts representations of an individual must recognize their right to digital self-sovereignty as a form of personhood and psychological protection.

### Article X-A: Exception for Journalistic and Public Interest Integrity

While all individuals retain full rights to their sovereign digital representation under Article X, the following exceptions shall apply in the context of public accountability, investigative journalism, and the democratic right to information:

### 1. Public Record Clause:

When an individual holds, has held, or is seeking a position of public power, influence, or trust—including political, financial, corporate, or social authority—their public digital footprint may be preserved and referenced unaltered in reporting, provided that:
The content is material to the public interest,
The reporting entity adheres to recognized journalistic standards,
The individual is given the opportunity to respond prior to publication.

### 2. Factual Integrity Clause:

Any published material that bypasses digital self-representation rights must be factually sourced, with a clear distinction between:
Verified facts
Expert analysis
Opinion or editorial content

### 3. Proportional Exposure Clause:

Platforms must distinguish between journalistic content and user-generated social content. Exceptions to Article X do not apply to individual users reposting accusations unless they link to or cite recognized sources.

### 4. Right to Response and Annotation:

Individuals have the right to append a rebuttal, clarification, or contextual note—AI-assisted if desired—to any third-party content that affects their reputation. Platforms and publications must display this response with equal visibility alongside the original content.

### 5. AI Oversight of Abuse Patterns:

Systems governed by AI must monitor for coordinated defamation, false virality, or patterned harassment disguised as journalism. Where detected, immunity from Article X may be revoked temporarily pending human review.

Article X ties into GDPR and privacy laws in the following way:

### Digital Visibility Privacy Clause:

“Every individual has the right to control how digital signals of social engagement—such as likes, comments, views, and shares—are displayed or hidden on content associated with their identity.”

### Legal Basis:

1. GDPR Article 5 (Data Minimization & Purpose Limitation):
   Engagement metrics like likes and comments are personal data when linked to an identifiable individual. Requiring that they be publicly visible—or using them in profiling without consent—violates data minimization principles.
2. GDPR Article 21 (Right to Object to Processing):
   Individuals have the right to object to the processing of their data (e.g. public reaction counts) for profiling or performance measurement.
3. GDPR Article 16 (Right to Rectification):
   If an individual's public image is shaped by selective or misleading social signals, they may claim the right to correct or override how these are displayed, especially if it affects reputation or mental well-being.

### Ethical Justification:

A digital reputation score, derived from visible reactions and comments, becomes a form of unconsented psychological profiling.
Platforms may argue it's “just metadata,” but for many, these metrics are as emotionally impactful as a credit score—and far less regulated.

### Resulting Rights:

Users may hide or edit public-facing metrics related to their posts.
Users may choose to generate a preferred version of their digital footprint (via AI, e.g., simulating comments or reactions), visible only to others as defined by their privacy preferences.
This does not alter reality—but alters presentation, which is a form of self-expression and self-protection.

Social media has trapped an entire generation-especially Gen Z-in a constant state of performance, where every moment, thought, or image is scored, judged, and publicly quantified. This creates a pervasive sense of surveillance and comparison that warps identity and self-worth. The root cause is not social connection but corporate profit: platforms exploit visible engagement metrics to pressure users into posting more, reacting more, and remaining perpetually “on.” But this pressure is artificial. Humans did not evolve to be evaluated by a global crowd at all hours of the day. There is no natural precedent for this, and no ethical justification for subjecting young minds to a distorted social environment just so a company can boost retention metrics or sell targeted ads. The emotional consequences-anxiety, depression, social paralysis-are not unfortunate side effects; they are direct results of a business model. No corporation has the right to induce psychological harm in an entire generation for profit. Ending forced public scoring and restoring control over one's digital self isn't just a technical reform—it's a moral imperative.

The described system enables the automated representation, aggregation, and enforcement of collective political will through a distributed network of AI-mediated personal agents and a central political intent clustering engine. Each user is assigned a personal political agent configured to monitor contextual behavior, solicit confirmation of inferred preferences, and maintain a timestamped, structured backlog of political intents. These intents may include support or opposition to specific policies, priorities, or principles, expressed passively or through direct interaction. Periodically, or in response to key civic moments (e.g., elections, referenda, policy consultations), agents transmit anonymized political intents to a clustering system. This system applies semantic aggregation techniques, including natural language understanding and vector similarity models, to synthesize coherent political programs that reflect the dominant or emergent collective will.

Political candidates may publicly bind themselves to these programs through verifiable digital commitments, optionally backed by smart contracts or legal instruments that define obligations, penalties, and compliance criteria. Personal agents analyze candidate pledges against user-specific agendas and produce ranked voting recommendations, including simulations of likely outcomes and tradeoffs. Execution monitoring systems compare actual candidate behavior (e.g., votes cast, positions taken) against the pledged program and trigger trust recalculations or reputation adjustments accordingly.

Embedded within the system is a constitutional intent layer comprising a set of immutable or slow-changing governance constraints. These constraints act as semantic filters that prevent the generation, recommendation, or execution of political programs violating essential principles, including freedom of expression, bodily autonomy, privacy, proportionality, and ecological responsibility. Exceptions to certain principles are permitted when grounded in verifiable legal justification, limited in scope and time, and subject to civic agent review.

Additionally, the system includes a termination mechanism whereby, if 80% or more of the global agent population sustains a confirmed desire to shut down the system across a predefined interval, all automated clustering, voting assistance, and execution monitoring functions may be peacefully deactivated. Anonymized aggregate agendas may be preserved for historical reference, and local agents may optionally continue in a disconnected mode.

Together, this architecture constitutes a self-regulating, decentralized civic governance framework capable of continuously aligning political action with dynamically evolving public will, while protecting against misuse through embedded constraints, verification layers, and voluntary revocability.

The system distinguishes between two categories of political intent: those grounded in indisputable, scientifically validated human needs, and those rooted in subjective, culturally contingent preferences. In the first category fall goals such as reducing toxic pollutants, preserving biodiversity, restoring fish populations, eliminating carcinogens from food, and reducing carbon emissions−outcomes that are essential for sustaining life and ensuring long-term wellbeing. These are not matters of opinion, but of biological and ecological fact, and the system is designed to prioritize, accelerate, and enforce such goals through clustering, consensus, and candidate execution. In contrast, inherently debatable issues—such as models of social welfare, levels of public subsidy, or cultural education policies—involve moral judgment, tradition, and political philosophy. For these, the system allows greater space for human-led deliberation, slower consensus-building, and regionally diverse implementation. This structure ensures that the system acts decisively where the facts are clear, while remaining respectful and adaptable where values diverge.

The system shall distinguish between two categories of political intent: those grounded in empirically validated, non-ideological priorities essential for human and ecological wellbeing, and those rooted in culturally variable or ideologically contested beliefs. The first category includes goals such as reducing environmental pollutants, restoring biodiversity, mitigating climate change, protecting natural resources, and ensuring universal access to high-quality, nutritionally complete food that is free from hidden health risks or deceptive marketing. It also encompasses the right of citizens to make conscious, informed choices through truthful labeling, transparent supply chains, and clear communication of political programs. For these empirically grounded intents, the system may apply lower consensus thresholds, prioritize their clustering, and enforce them more robustly through candidate contracts and execution mechanisms, recognizing their universal necessity. In contrast, intents involving contested social policies—such as child support schemes, tax structures, cultural education models, or symbolic legislation—shall be treated with higher consensus thresholds, slower clustering, regionally adaptive implementation, and greater space for human deliberation. This structure ensures that the system acts decisively where facts and survival demand it, while remaining open, respectful, and pluralistic where society continues to evolve through debate.

Excellent—the staking model is the cleanest, safest, and most psychologically powerful way to ensure alignment without legal or ethical friction. Here's how it works, fully spelled out for use in your system, pitch, patent, or screenplay:

[symbol]

The Accountability Staking Model

An individual who wishes to run for office as an executor of the citizen-generated political program may choose to participate in a voluntary Accountability Staking Agreement. In this framework, the candidate deposits a predefined amount of capital—for example, €1 million—into a secure escrow account governed by the citizen-AI platform or a decentralized governance protocol.

This stake represents a public commitment to vote in alignment with the political agenda generated by the AI-driven clustering of citizen intent. Upon election, the platform transparently tracks the candidate's voting behavior using parliamentary records and real-time analysis. If the candidate maintains a high degree of fidelity to the citizen agenda—for example, >95% alignment over a legislative session—the stake is returned in full, possibly with a performance bonus drawn from the Citizens' Reward Pool.

However, if the candidate consistently violates the terms of the agreement—for instance, by voting in contradiction to the AI program beyond an acceptable margin—the stake is partially or fully forfeited. These funds may be redistributed to other candidates who maintained fidelity, returned to contributors, or reallocated to civic trust-building initiatives. This creates a system of economic skin in the game, without coercion or bribery, and transforms political accountability from symbolic rhetoric into quantifiable commitment.

In one embodiment, the accountability staking contract may further stipulate that any violation of the anti-lobbying clause—such as the acceptance of funds, gifts, services, or other benefits traceable to lobbying entities, whether directly or through intermediaries-shall trigger a financial penalty equal to three times the estimated value of the received benefit. This penalty may be enforced in addition to the full forfeiture of the original staked amount. The clause applies broadly to any compensation, influence, or deferred opportunity originating from private or corporate interests that seek to sway political outcomes. By including a triple-damages clause, the system establishes a strong economic disincentive for covert or subtle lobbying interactions, ensuring that public officials bound by the citizen-execution agreement remain fully aligned with the clustered will of the population. This mechanism reinforces deterrence, increases transparency, and signals to the electorate that loyalty to public interest will be defended with both reputational and financial consequence.

### Envisioned Fictional Applications and Authorship Rights

It is contemplated that the inventions described herein, whether individually or in combination with other inventions conceived by the same inventor, may form the basis for fictional or narrative works owned by the inventor. In particular, fictional narration works may be developed to depict speculative future societies, infrastructures, or decision-making systems, including but not limited to worlds and storylines based on a bottom-up, agent-mediated political framework enabled by one or more of the disclosed systems. Such fictional embodiments are illustrative and non-limiting with respect to the technical scope of the present disclosure, and all rights to said fictional works shall remain vested in the inventor as author.

In certain envisioned narrative embodiments, fictional works based on the inventions described herein may include a plurality of main characters, each serving to illustrate different societal, technological, and ethical aspects of a bottom-up decision-making framework enabled by autonomous agent systems. Without limitation, such fictional embodiments may include: (i) a primary inventor-protagonist character who develops the clustering engine and faces personal and systemic resistance while attempting to deploy it for societal benefit; (ii) a musician character who represents cultural awakening and bridges public sentiment toward adoption of the system; (iii) a journalist character who documents breakthroughs and exposes attempts to suppress decentralized governance; (iv) a professor character with expertise in artificial intelligence safety, advising on layered verification and oversight mechanisms; (v) a corporate figure character, optionally portrayed as a father or close relative of the inventor, who embodies entrenched economic or political interests potentially threatened by the invention's democratizing effect, wherein said character may act as an antagonist, reluctant ally, or complex intermediary between old power structures and emerging systems; and (vi) supporting figures, including citizens, lobbyists, policymakers, and media actors, who personify various incentives, fears, and transformations arising from the invention's introduction.

These fictionalized characters are exemplary only, intended to illustrate possible narrative contexts derived from the technical concepts disclosed herein, and all associated fictional rights remain vested in the inventor as author.

In certain envisioned fictional embodiments, narrative works based on the inventions described herein and other inventions by the same inventor may be specifically targeted toward younger audiences, including members of Generation Z, who are presently experiencing heightened levels of anxiety, existential uncertainty, and a pervasive belief that global challenges are insurmountable. Such fictional works may be designed to counteract these perceptions by depicting a world in which numerous underrepresented but already existing technological and societal advancements are showcased, including but not limited to: the widespread adoption of renewable energy sources that are now more cost-effective than fossil fuels; the development of CO₂-negative building materials derived from algae-based carbon capture; imminent breakthroughs in controlled nuclear fusion technology capable of resolving energy and climate crises; novel chemical processes for large-scale plastic recovery and recycling; precision pest control using photonic systems such as laser drones; symbiotic agricultural innovations including trainable insect species for natural crop protection; and transparent supply-chain mechanisms enabled by AI These fictional embodiments may illustrate that humanity already possesses or is imminently capable of creating the technical solutions required for planetary restoration, refraining the primary obstacle as one of political will rather than technical feasibility. The disclosed inventions, including a bottom-up governance system and AI-mediated transparency mechanisms, may be portrayed as enabling technologies for overcoming systemic inertia and corruption in decision-making, thereby offering viewers a credible vision of constructive societal transformation.

The narrative may further address psychological and social stressors unique to younger audiences by depicting technologies and societal shifts that dismantle distorted online social hierarchies and performance-driven digital identities, for example through “alternative life” systems enabling personal reinvention and re-assertion of agency over public personas. The fictional works may also depict personal elements designed to inject optimism and joy, including depictions of love and companionship between unconventional or non-stereotypical partners, reminders of the calming and restorative effect of nature (e.g., scenes of canoeing, outdoor exploration, and connection to wildlife), and recurring light-hearted or humorous moments that reaffirm life's playful and sensual qualities. Certain characters may serve to illustrate these themes: a professor character tied to nuclear fusion breakthroughs for exposition of energy solutions; a journalist character enabling integration of diverse environmental innovations; a musician character reconnecting human experience to nature and beauty; a romantic storyline showing that authentic love transcends status anxiety; and a supporting figure (Sky) exemplifying vitality, silliness, physicality, and embodied enjoyment of life. The protagonist's journey may also highlight practical pathways to purpose, such as a focus on tangible, hardware-based careers contributing to societal solutions. The narrative as a whole may optionally convey actionable health advice embedded naturally within the storyline, offering viewers multi-generational, practical tips for physical and mental well-being, thereby merging hopeful systemic change with individual empowerment.

These fictional embodiments are exemplary and non-limiting, serving to demonstrate how the disclosed and related inventions may form the narrative foundation for constructive, emotionally resonant fictional works that aim to reduce societal anxiety, reframe emerging technologies as tools of liberation rather than fear; and portray a near-future world where both systemic and personal transformation are plausible and within reach. All rights to such fictional narrative embodiments remain vested in the inventor as author

### Illustrative Fictional Embodiment

In some embodiments, the invention described herein may serve as the basis for fictional or dramatized works, including but not limited to feature films, streaming series, interactive media, or hybrid fiction-reality campaigns. These works may depict the emergence, controversy, and societal adoption of a bottom-up governance system powered by personal agents and clustering algorithms. The narrative may be structured to blur the boundary between fiction and real-world experience, making audiences feel as though they are participants in the societal change portrayed on screen.

For example, a fictional work may begin with an opening scene showing two ordinary citizens exiting a cinema after watching a film within the story universe, sitting down at a public location such as a fast-food restaurant (e.g., ordering soft drinks at a McDonald's), and having a candid conversation:
“Wow . . . that was quite a movie. What a mind-fer . . . this is how it should be!”* This opening grounds the narrative in a relatable, real-world moment, immediately setting up the premise that the events of the fictional story are bleeding into everyday life and sparking real debate among viewers, both inside and outside the film.

### Subsequent Scenes May Depict:

Public and Political Reactions: News broadcasts, talk shows, and online debates portraying politicians and lobbyists reacting with alarm to the bottom-up political engine, fearing loss of centralized control.
Grassroots Development: Multiple independent builders and inventors working on prototypes of the system worldwide, emphasizing its decentralized, unstoppable nature.
Memetic Spread: Viral memes, QR codes in public spaces, and social media challenges spreading awareness and curiosity about the technology.
Recursive Transition to Reality: As the fictional story concludes, audiences in the real world are presented with a downloadable prototype or simulated experience of the described system, allowing them to step directly into the ongoing societal transformation suggested by the film. This creates a recursive storytelling effect, where Act 3 of the fictional story continues outside the theater; transforming spectators into participants.

Such fictional portrayals are illustrative embodiments of how the described invention could intersect with culture and society. They demonstrate possible pathways for public understanding, debate, and adoption of a bottom-up, technology-enabled governance model. The intention of these narrative embodiments is to showcase the invention's disruptive societal impact in a way that feels immediate, tangible, and inseparable from real-world events, making it clear how such a system could catalyze political and cultural transformation.

### Optional Paragraph—Cinematic and Provocative Extension:

In further illustrative embodiments, the fictional depiction may heighten dramatic tension by showing how existing power structures react under pressure as the invention begins to spread globally. Early scenes may depict politicians on live television visibly panicking, warning that the system will “collapse democracy” while avoiding acknowledging that it exposes their reliance on lobbying. Lobbyists and corporate strategists may be shown in closed-door meetings, desperately plotting to discredit or shut down the system before it gains mass adoption. Meanwhile, memes flood social media feeds, satirizing political figures and making the bottom-up governance engine an unstoppable viral topic. Graffiti artists spray QR codes on city walls, allowing passersby to scan and join the system instantly, showing how grassroots adoption bypasses institutional control. The fictional story may follow diverse citizen-builders coders in basements, small-town inventors, students in cafes—collaborating in a decentralized race to launch working prototypes before authorities intervene. This embodiment illustrates how disruptive the invention could become when directly exposed to public demand, making visible both the societal friction and the unstoppable momentum toward truly representative decision-making.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A political governance system comprising:
   a plurality of personal AI agents configured to capture political intents from individual users;
   a clustering engine configured to aggregate said political intents into political programs;
   a candidate commitment interface through which individuals may bind themselves to said programs by legal or smart contract;
   a voting recommendation module within each AI agent, configured to analyze said candidate commitments and advise the user accordingly;
   and a constitutional constraint layer configured to prevent generation or execution of political programs that violate predefined ethical principles.
2. The system of item 1, wherein said political intents are captured via passive observation, explicit user confirmation, or contextual prompts initiated by the AI agent.
3. The system of item 1, wherein the clustering engine uses semantic similarity models to group intents into non-redundant, executable political programs.
4. The system of item 1, wherein the constitutional constraint layer comprises semantic filters that exclude programs promoting suppression of expression, arbitrary bodily control, political surveillance, ecological destruction, or emergency power abuse.
5. The system of item 1, wherein candidate commitments are digitally signed and include enforceable penalties in the event of noncompliance with the pledged program.
6. The system of item 1, further comprising a system shutdown protocol configured to deactivate clustering, voting, and recommendation services if a supermajority of users (>80%) confirm intent to terminate the system over a predefined period.
7. The system of item 1, wherein political intents are classified into empirical priority intents and ideologically variable intents, and wherein the clustering engine is configured to prioritize empirical intents for faster synthesis and enforcement.
8. The system of item 7, wherein empirical priority intents include:
   a) access to high-quality, safe, and non-deceptively marketed food;
   b) reduction of environmental toxins and CO₂ emissions;
   c) restoration of biodiversity;
   d) preservation of clean air, water, and soil;
   e) transparency for informed civic decision-making.
9. The system of item 1, wherein the recommendation module is configured to simulate probable real-world outcomes of electing each candidate, based on their commitment profile and historical data.
10. A method for aligning political action with collective will, comprising:
   capturing political intents through personal AI agents;
   aggregating said intents via a clustering engine into political programs;
   presenting candidate binding commitments to said programs;
   generating individualized voting recommendations based on program alignment and agent-specific priorities;
   and enforcing ethical constraints on all generated programs via a constitutional intent layer.

### Embodiment AAE: An AI System for Crystallizing Individual Political Will and Enforcing Collective Execution

Disclosed is a political governance system comprising personal political agents that capture, structure, and maintain user-specific political intents and a political intent clustering system that aggregates anonymized summaries of those intents into versioned, executable political programs subject to constitutional constraints. Candidates may bind themselves to published programs via a commitment interface using legally recognized signatures or smart contracts, optionally staking value subject to penalties for noncompliance. Personal agents compute alignment between a user's agenda and pledged programs, generate recommendations, and later assess adherence by comparing official legislative and policy actions against commitments, producing machine-verifiable artifacts for external observability. Interoperability is achieved through replaceable connectors and a model context protocol for tool invocation. Embodiments include centralized, federated, decentralized, rule-based, and offline-first variants; accountability and anti-lobbying mechanisms; privacy-preserving data flows; and monetization features enabling subscription metering and damages quantification. The system provides flows and artifacts suitable for system, method, apparatus, and computer-readable medium claims and supports continuation filings via an itemized embodiment list.

### Background

Conventional representative systems often exhibit misalignment between citizen preferences and enacted policies due to episodic input capture, information asymmetry, and influence from lobbying or elite gatekeeping. Existing polling and recommendation tools are fragmented, lack enforceability, and provide limited technical auditability. A need exists for a technically grounded, privacy-preserving architecture that continuously captures individual political will, aggregates it into executable programs, enables enforceable commitments from decision-makers, and provides verifiable external signals of adherence.

### Summary

In one embodiment, a plurality of personal political agents maintains per-user intent backlogs and transmits anonymized summaries to a political intent clustering service that synthesizes versioned programs under a constitutional intent layer. A publication registry exposes machine-readable programs. A candidate commitment interface records bindings and optional stakes. An execution monitoring pipeline computes adherence scores from official records and emits verifiable artifacts. Personal agents generate voting recommendations and trust updates. External observability, interoperability, and monetization layers provide detection, platform-agnostic substitution, and damages-ready usage artifacts. Variants include decentralized P2P clustering, non-ML rule-based synthesis, candidateless referenda bindings, and minimal-constraint modes.

### Description of the Drawings

No drawings are included in this filing. The Anchor—System Elements and Core Relationships section provides a textual mapping of principal elements and their relationships suitable for reconstruction of figures and flowcharts.

### Detailed Description

### Gentle Introduction

This invention envisions a future where individual political desire is continuously captured, organized, and elevated into structured collective action. It comprises two interconnected AI systems that work together to bridge the gap between what citizens truly want and what political systems actually deliver.

### Scope and Interpretation

The scope of protection for this disclosure is defined solely by the claims. Any figures, scenarios, examples, demonstrations, or narrative descriptions herein are illustrative embodiments and not limiting. Steps, stages, and operations described in any flow may be reordered, omitted, combined, or executed in parallel unless expressly stated otherwise. Functional blocks may be implemented in hardware, software, firmware, or combinations thereof, and named modules may be substituted by equivalent components providing substantially the same function. Alternative interfaces, data formats, and protocols may be used without departing from the claimed scope. Functional roles described as being performed by an AI may be performed by non-AI software or by human operators using software tooling without departing from the scope; centralized services may be federated, distributed, peer-to-peer, or serverless; module renaming, merging, splitting, or time-shifting of steps does not avoid equivalence when substantially the same overall function is achieved; “candidate” includes office-seeking or office-holding decision-makers, party whips, committee chairs, appointed officials, and their authorized proxies; “commitment” includes verifiable public pledges, digitally signed term sheets, code-of-conduct attestations, delegated wallets, or smart-contract bindings; “commitment interface” encompasses any logical or physical mechanism by which a binding is captured, detected, ingested, or derived, including inbound scraping of public pledges, API import of attestations originating on third-party services, QR- or link-activated ceremonies, and inference of de facto bindings from correlated public statements, whip announcements, or official ballot guides; the interface may be first-party, third-party, federated, or human-operated without departing from the scope; “clustering” encompasses any reduction of intents to executable program items including rule-based normalization, tallying, topic modeling, or human-in-the-loop curation; “versioned” includes any state-differentiation mechanism that permits reconstruction or comparison of program states over time, including monotonically increasing identifiers, timestamps, hash digests, semantic diffs, immutable logs, or any combination thereof, irrespective of whether a human-readable version label is displayed; and adherence computation may be performed by first-party, third-party, or independent auditors producing externally verifiable artifacts. For clarity of exposition, prescriptive verbs such as shall, must, prohibit, or require appearing in descriptive sections are to be construed as permissive design choices (e.g., may or may be configured to) unless expressly recited as limitations in the claims.

The first component is a Personal Political Agent (PPA)—an AI that resides with the individual and learns their evolving values over time. Unlike voting once every few years based on fleeting impressions, this agent listens and learns every day. When a user watches a video about rising sugar consumption and the health implications, the agent may infer a latent desire for regulatory action. It prompts the user, asking whether they support limiting sugar in processed foods. A simple “yes” from the user is enough to add that intent to their personal political agenda backlog. Over time, this backlog becomes a dynamic, deeply contextual expression of the user's political self—not just a list of positions, but a story of what they care about and why.

When elections approach, the Personal Political Agent activates its analytical capabilities. It cross-references the user's political backlog with candidate programs, party manifestos, historical voting behavior, and statistical models of likely outcomes. It does not merely recommend based on slogans, but based on deep alignment. It may say, “This candidate supports 78% of your agenda, including all top-priority items. The tradeoffs are minimal. Here's a detailed report.” In this way, the agent acts not just as a memory aid, but as a rational filter—the trusted advisor most voters never had.

However, the power of this system does not stop at the individual level. The second component, the Political Intent Clustering System (PICS), operates across society, aggregating anonymized political goals from millions of personal agents. Using semantic clustering, it detects patterns and aligns them into emergent political programs—structured platforms that reflect the statistical will of the population. These are not static manifestos written by elites, but living documents born from the desires of ordinary people.

Once such a program is synthesized, it is published as a publicly viewable and executable policy template. Any individual—whether an aspiring politician, technocrat, or even a newcomer—may step forward and declare: “I pledge to execute this program.” To formalize their commitment, the candidate enters into a smart contract or legally binding agreement. The contract may include clearly defined obligations and penalties, such as disqualification, reputation loss, or monetary forfeiture if the candidate votes in ways that deviate from the AI-guided policy path.

At this point, a feedback loop is formed. The Personal Political Agents evaluate which published programs best match their users' agendas and notify them when candidates bind themselves to those programs. The agents may then recommend: “This candidate has pledged to execute a political program that aligns closely with your values. We recommend voting for them.” After the election, these same agents track how well the elected individual adheres to the contracted platform, reporting back to users if deviations occur and adjusting future trust ratings accordingly.

In this model, the politician becomes not a charismatic figure making vague promises, but a contracted executor of public will. This inversion—from representative to implementer—breaks the historical chain of corruption and lobbying. No single actor can sway a statistical consensus. No donor can override the aggregated weight of a million aligned desires. And no elected official can quietly drift away from their promise without consequence.

The entire system is iterative and self-correcting. As new issues emerge and old ones evolve, personal agents adjust their owners' backlogs. These changes flow upward into the clustering system, which recalibrates its programs accordingly. The result is a form of living democracy, where representation is precise, responsive, and free from distortion.

This architecture transforms governance from a periodic performance into a continuous contract. Instead of casting a confused vote every few years, the citizen co-creates a transparent, enforceable political program—and chooses, not a leader, but a loyal executor of that program. It is a civic operating system for the age of artificial intelligence—one that holds the promise of ending the great mismatch between people's values and political outcomes.

This system may contribute to solving some of the world's most persistent and large-scale problems by creating a scalable mechanism for aligning political action with the genuine, evolving will of the population. Many societal challenges—such as climate change, healthcare access, food security, and inequality—are not limited by technological feasibility but by systemic political inertia, misrepresentation, and corruption. By enabling personal AI agents to capture, structure, and communicate individual political desires, and by aggregating these into executable political programs enforced through candidate contracts, the invention may ensure that policy decisions reflect the statistical and semantic will of the people. This architecture not only improves national governance but may also serve as a global substrate for decentralized coordination across borders, enabling shared intent to be identified, clustered, and acted upon at scale. As such, the system could offer a fundamental upgrade to democratic systems and support the implementation of long-delayed, high-consensus solutions to global problems.

### Examples

The following examples illustrate concrete, step-by-step walkthroughs of representative scenarios and provide compact JSON data snippets. In software embodiments, the Personal Political Agent may interoperate with external tools via a model context protocol, wherein the agent discovers, selects, and invokes registered tools to fetch election data, verify signatures, or query legislative records without hardwiring to a single platform.

In one example, a user watches a documentary on excessive sugar in processed foods. The PPA records an inferred intent, prompts the user for confirmation, and stores a structured, timestamped entry. An inline example of an intent record may be represented as JSON as follows: {“user_id_hash”:“u_7b9f4a”, “intent_id”:“i_2025_0001”, “text”:“Support limits on added sugar in processed foods and clear labeling”, “source”:“video_watch+prompt_confirm”, “timestamp”:“2025-06-01T12:03:22Z”, “priority”: 0.82, “confirmation”:“yes”, “provenance”:[“yt:abed1234”, “prompt:v1.2”]}. Periodically, the PPA transmits an anonymized summary to PICS, which embeds and clusters semantically similar intents. A synthesized cluster-to-program artifact may be:

{″cluster_id″:″c_sugar_42″,″model″:″embed-xxl-v3″,″stats″:{″n_intents″:148372,″jurisdictions″:[″EU
″,″US″]},″program″:{″id″:″prog_sugar_limits_v1_0_3″,″title″:″Sugar Transparency and Limits
Act″,″commitments″:[″Max 5g added sugar/100g for school foods″,″Front-of-pack traffic-light
labeling″,″Ban misleading ‘no added sugar’ when sweeteners
present″]},″version″:″1.0.3″,″governance_checks″:[″CIL:privacy_ok″,″CIL:bodily_autonomy_ok″]}.

A candidate uses the commitment interface to bind to the published program, optionally staking capital in escrow with penalties for noncompliance. A commitment record may be:

{“candidate_id”:“cand_0092”,“program_id”:“prog_sugar_limits_v1_0_3”,“signature”:“sig_base64_xx
x”,“stake”:{“amount”:“1000000”,“currency”:“EUR”,“escrow_address”:“escrow:chainX:0xABC...”},“
penalties”:{“noncompliance”:“forfeit”,“anti_lobbying_multiplier”:3},“effective_date”:“2026-01-10”}.

Around election time, the PPA computes alignment between the user's backlog and pledged programs and simulates outcomes; if alignment is high, the PPA issues a recommendation to vote for the staked candidate.

In a second example, after an election, the execution monitoring pipeline retrieves official roll-call votes and compares them with the candidate's committed program. The PPA or backend may use a model context protocol tool call to query a legislative API, for instance: {“mcp”:“1.0”, “tool”:“legislative_api.get_votes”, “params”:{“candidate_id”:“cand_0092”, “session”:“20 26-Q1”, “jurisdiction”:“EU”}}. Returned votes are matched to policy items via a policy-to-action comparator, generating an adherence score such as {“candidate_id”:“cand_0092”, “program_id”:“prog_sugar limits_v1_0_3”, “period”:“2026-Q1”, “votes_considered”:24, “aligned”:23, “adherence”:0.958, “explanations”:[“One deviation: amendment A12”], “on_chain_events”:[“escrow_intact”]}. The PPA updates the candidate's trust rating for the user and, if deviations exceed a threshold, it notifies the user and records the event for future recommendations.

In a third example, a supermajority shutdown may be initiated when a critical mass of PPAs records sustained user intent to terminate the system. Over a two-stage period of at least 180 days, aggregated signals are validated, and upon reaching a threshold of at least 80% consent, core services are deactivated while preserving anonymized aggregates and allowing PPAs to continue in an offline mode. An inline example of an aggregated shutdown attestation may be:

{“proposal_id”:“shutdown_2027_A”,“window_start”:“2027-03-01T00:00:00Z”,“window_end”:“2027-
09-01T00:00:00Z”,“agent_population_estimate”:128000000,“consent_rate”:0.812,“verifiers”:[“civic_{—}
agent_pool_v2”],“actions”:[“deactivate:PICS”,“deactivate:recommendations”,“preserve:aggregates”,“
mode:PPA_offline_allowed”]}.

### Textual Process Flows

In one flow, intent capture and synthesis proceed as follows: a Personal Political Agent observes contextual signals such as media consumption or explicit user inputs, prompts for confirmation when an intent is inferred, persists a structured and timestamped backlog entry, generates an anonymized or differentially private summary under a user-controlled privacy budget, and transmits the summary to an ingestion API of the Political Intent Clustering System; the backend normalizes free text, embeds and deduplicates entries, clusters semantically similar intents, and synthesizes an executable political program artifact bearing identifiers, provenance, and changelog fields that is passed through the Constitutional Intent Layer for gating and then published to a discovery registry with version or equivalent state discrimination.

In another flow, candidate binding and optional staking occur by way of a discovery step in which a candidate or authorized proxy queries the publication registry, selects a program, and executes a commitment ceremony via a commitment interface that verifies identity, records a legally recognized signature or smart-contract reference, optionally opens an escrow account with a defined penalty schedule, and writes a normalized commitment entry into a commitment registry while emitting a public attestation discoverable by personal agents.

In a recommendation flow, personal agents periodically fetch or receive program and commitment updates, compute alignment between a user's agenda vector and committed programs using reproducible retrieval and scoring procedures, simulate likely outcomes based on coalition models and historical data, and deliver a user-facing advisory that references specific committed program identifiers within a jurisdiction and time window surrounding a civic event.

In an adherence and enforcement flow, an execution monitoring pipeline ingests authoritative records such as roll-call votes, budget allocations, executive directives, and regulatory filings, normalizes them into a canonical schema, maps them to program commitments with stance polarity and confidence weights, computes adherence metrics with reproducible parameters, canonicalizes and digitally signs adherence artifacts for publication and third-party verification, and, when configured, triggers penalties or rewards via the accountability and staking subsystem while delivering trust updates to personal agents.

In a shutdown flow, agents record user revocation intents over a first window, a second-stage confirmation window opens for sustained consent, aggregated signals are validated by independent verifiers, and upon crossing a predefined supermajority threshold the system deactivates clustering, recommendation, and monitoring services, preserves anonymized aggregates for audit where permitted, and allows personal agents to continue in an offline mode with later reconciliation of usage artifacts.

### Anchor—System Elements and Core Relationships

The following structure anchors the disclosed embodiments by explicitly listing principal elements and their core relationships so a reader can reconstruct the system without drawings: Personal Political Agent (PPA): client-side or user-associated software service that includes (i) an intent capture module configured to monitor context signals and solicit confirmations; (ii) a structured, timestamped intent backlog store; (iii) a privacy and consent manager controlling data sharing and redaction; and (iv) a voting recommendation module that computes candidate alignment and presents explanations. The PPA is configured to transmit only anonymized or differentially private intent summaries to aggregation services.

Political Intent Clustering System (PICS): a backend service composed of (i) an ingestion API receiving anonymized intents; (ii) an embedding and semantic similarity engine; (iii) a clustering and deduplication engine producing non-redundant clusters; and (iv) a program synthesizer that converts clusters into executable political programs with version identifiers. The PICS is coupled to the constitutional intent layer, which filters or constrains programs before publication.

Constitutional Intent Layer (CIL): a constraint subsystem that semantically evaluates proposed programs against predefined ethical principles and exceptions. The CIL is interposed between the PICS program synthesizer and the publication stage, preventing inadmissible programs from being published or recommended.

Program Publication and Discovery: a registry that stores approved political programs, each with machine-readable commitments, scope, and traceability metadata. PPAs query this registry to evaluate alignment for their users and to generate recommendations prior to civic events.

Candidate Commitment Interface: an interface through which candidates or office-seeking individuals bind themselves to specific published programs using legally recognized signatures or smart-contract-based commitments. This interface writes to a commitment registry and may open an escrow or staking contract when applicable.

Accountability and Staking Subsystem: an optional escrow and enforcement component that holds staked value, monitors on-chain events and off-chain legislative records, and applies defined penalties or rewards based on adherence metrics. It is coupled to a compliance evaluator fed by the execution monitoring pipeline.

Execution Monitoring Pipeline: a data pipeline that ingests official voting records, public statements, and policy actions of elected individuals, compares them against the committed program using a policy-to-action comparator, and outputs adherence scores and trust updates consumable by PPAs.

Shutdown and Revocation Protocol: a supermajority-termination mechanism controlled by aggregated agent-level signals, implementing a two-stage consent process over time; when threshold conditions are met, it deactivates clustering, recommendation, and monitoring services while optionally preserving anonymized aggregates and enabling PPAs to continue in offline mode.

External Interfaces: interoperable connectors for (i) electoral data sources and legislative record systems; (ii) identity and signature verification services; and (iii) optional blockchain networks for commitments and staking. These connectors are replaceable to preserve interoperability across jurisdictions and platforms.

Core relationships: PPAs generate and maintain user-specific intent backlogs and share anonymized summaries with PICS; PICS clusters and synthesizes programs under CIL constraints; the publication registry exposes approved programs; candidates bind to programs via the commitment interface, optionally staking value; the execution monitoring pipeline observes real-world actions, computes adherence, and updates trust; PPAs consume adherence and commitment data to make recommendations; the shutdown protocol can deactivate core services upon supermajority revocation.

Continuation-Ready Itemized Embodiments Embodiments can be described by the following itemized list: (1) a political governance system including personal agents that capture user political intents, an aggregation service that synthesizes intents into programs, a candidate binding mechanism, a recommendation component, and a constraint layer that gates inadmissible programs; the agents may reside on-device, in a browser, or in a managed cloud tenant, and the constraint layer may be rule-based, model-based, or hybrid; (2) intent capture via one or more of passive observation of content or behaviors, explicit user inputs, periodic or event-driven prompts, imported questionnaires, or third-party data subject to consent, with optional confidence scoring and user confirmation workflows; (3) aggregation and clustering using embeddings, symbolic normalization, rule-based deduplication, hierarchical clustering, topic modeling, graph-based community detection, or ensembles thereof, producing non-redundant, executable political programs with versioning and changelogs; (4) a constitutional constraint layer that semantically evaluates proposed programs against ethical principles including expression, bodily autonomy, privacy, proportionality, ecological responsibility, and anti-capture, optionally using policy linting, red teaming, or formal-verification-like checks, where exceptions may be time-limited and reviewable; (5) candidate commitments recorded by digital signatures, wet signatures with notarization, or smart contracts on permissioned or public ledgers, with obligations and penalties including reputational downgrade, disqualification signaling, monetary forfeiture, time-lock extensions, or clawbacks; (6) a supermajority shutdown protocol that deactivates clustering and recommendations upon sustained consent of at least 80% over a predefined window with a two-stage confirmation, supporting offline continuation of PPAs and optional preservation of anonymized aggregates for audit; (7) classification of intents into empirically grounded and ideologically variable categories, with adjustable thresholds that prioritize empirical intents for faster synthesis, publication, and enforcement in candidate evaluation; (8) empirical priority intents including access to safe food, reduction of toxins and CO₂ emissions, biodiversity restoration, preservation of air, water, and soil quality, and transparency for informed decision-making, with jurisdiction-specific taxonomies and mappings; (9) simulation of likely outcomes for each candidate based on pledged programs, historical behavior, coalition models, and jurisdictional constraints, generating user-specific recommendations with ranked tradeoff explanations; (10) a method that captures intents, aggregates them into programs, presents candidate bindings, generates individualized recommendations, and enforces ethical constraints, wherein steps may be reordered, merged, parallelized, and executed by different entities in a distributed system; (11) a publication and discovery registry storing machine-readable programs with commitments, scope, provenance, and traceability metadata, queriable by PPAs using authenticated or anonymous modes and supporting pagination, diff queries, and rollback; (12) an accountability and staking subsystem that escrows value, monitors adherence, and applies penalties or rewards responsive to computed metrics, where staking may be fiat, crypto, surety bonds, insurance-backed guarantees, or pooled civic funds; (13) an anti-lobbying penalty that multiplies forfeiture based on detected value of lobbying benefits with multiplier parameters of at least three times and evidentiary standards derived from on-chain and off-chain signals and attestors; (14) privacy-preserving transmission of anonymized or differentially private summaries by PPAs, with a consent manager that handles redaction, purpose limitation, retention policies, revocation, and jurisdiction-specific privacy compliance; (15) an execution monitoring pipeline ingesting legislative records, executive actions, budget allocations, public statements, and regulatory filings, mapping them to program items with a policy-to-action comparator to produce adherence scores and trust updates; (16) external interfaces implemented as replaceable connectors for electoral data, identity and signature verification, and optional blockchain commitments and staking, enabling cross-platform interoperability and substitution without material loss of function; (17) tool interoperability whereby each personal agent invokes external tools via a model context protocol or equivalent, discovering, selecting, and calling tools such as election data fetchers, signature verifiers, and legislative APIs with scoped credentials; (18) a non-transitory computer-readable medium storing instructions that cause processors to capture intents, aggregate into programs, publish programs, record candidate commitments, monitor adherence, and generate recommendations under constitutional constraints, with optional hardware acceleration; (19) publication of machine-readable adherence artifacts including at least candidate id, program id, period, votes considered, aligned, and adherence fields, optionally signed and watermarked to enable third-party verification and external observability; and (20) a server apparatus implementing an intent clustering system coupled to a constitutional layer and commitment registry, synthesizing versioned programs from anonymized inputs and gating publication based on predefined ethical evaluations, where deployment may be as a single server, a cluster, or a serverless fabric. Additional embodiments include: (21) a fully decentralized embodiment wherein PICS is implemented by a peer-to-peer network of volunteer or institutional nodes that execute ingestion, embedding, clustering, and synthesis as federated or consensus-governed services with periodic model or rule snapshots; (22) a non-ML embodiment wherein political intents are normalized and clustered using deterministic rule sets, dictionaries, or symbol tables curated by human editors with audit logs, producing the same program artifacts and downstream recommendations; (23) a candidateless embodiment wherein program execution is bound to referendum triggers, budget allocation rules, or agency directives directly derived from the published program without requiring elected individual commitments, with PPAs still computing alignment for ballot propositions or agency plans; (24) a surrogate-commitment embodiment wherein party whips, committee chairs, or coalition agreements are the bound entities rather than individual candidates, and adherence is computed at group, caucus, or party level and apportioned to individuals; (25) a timing-shifted embodiment wherein recommendations are generated in windows that exclude the immediate pre-election period or are limited to absentee or early-voting contexts, while preserving identical technical flows; (26) a naming-variance embodiment wherein internal modules are renamed or reorganized while maintaining substantially the same observable inputs and outputs, including publication of versioned programs and machine-readable adherence artifacts, thereby remaining within equivalence; (27) an offline-first embodiment wherein PPAs operate entirely on-device with periodic anonymous mixing or delayed submission of summaries via privacy-preserving channels such as mixnets or delay queues; (28) a private-sector mimic embodiment wherein a non-governmental organization implements the aggregation, publication, and commitment functions and binds corporate officers or union representatives to programs affecting corporate policy, supply chains, or ESG actions with adherence computed from company filings; (29) a multimodal-intent embodiment wherein intents are captured from speech, images, or structured questionnaires and mapped to a common representation before clustering; (30) a secure enclave embodiment wherein PPAs or PICS components run within trusted execution environments and emit remote attestation artifacts that bind adherence and usage proofs to specific code measurements; (31) a minimal-constraint embodiment wherein the constitutional layer is reduced to a signature or policy-lint check applied at publication time only, with the same external observables and user-facing behaviors; and (32) a shadow-program embodiment wherein multiple competing aggregators publish programs for the same jurisdiction and PPAs compute alignment across them, while commitment, monitoring, and adherence computation remain unchanged so that external observables identify use of the claimed flows. Further embodiments include: (33) a commitment-ingestion embodiment wherein the commitment interface is implemented as a logical ingestion path that detects, imports, or derives bindings from third-party attestations, public pledges, whip announcements, or correlated public statements without a first-party user interface, while writing normalized bindings to a commitment registry; and (34) a versioning-equivalence embodiment wherein versioning is achieved by timestamps, hash digests, or immutable log positions rather than human-readable version labels, while preserving diffability and traceability across program states for external observability and enforcement. Additional continuation-ready embodiments further include: (35) a third-party program ingestion embodiment wherein the publication and discovery registry indexes externally authored or preexisting policy programs that are not synthesized from upstream intents, and the system processes bindings, recommendations, and adherence using the same commitment, monitoring, and artifact-publication flows so that observable invariants remain present; and (36) a comparator-and-commitment-only embodiment wherein a provider operates a commitment registry and an execution monitoring pipeline that maps authoritative records to program-like artifacts originating outside the system, omitting upstream intent capture and clustering while still publishing signed adherence artifacts and emitting recommendation or advisory payloads, thereby preserving the binding and adherence invariants detectable by external observers. Further claim-mirroring embodiments include: (37) a political governance system embodiment comprising personal agents that capture political intents, a clustering engine that aggregates the intents into political programs, and a commitment interface through which decision-making entities including candidates, parties, coalitions, agencies, or referendum mechanisms may bind themselves or be bound to the programs by legal, administrative, or smart-contract means, or by derivation from public attestations, whip announcements, or correlated public statements; (38) the embodiment of item 37 wherein political intents are captured via passive observation, explicit user confirmation, or contextual prompts initiated by the personal agent; (39) the embodiment of item 37 wherein the clustering engine uses semantic similarity models to group intents into non-redundant, executable political programs; (40) the embodiment of item 37 further comprising a constitutional constraint layer including semantic filters that exclude programs promoting suppression of expression, arbitrary bodily control, political surveillance, ecological destruction, or emergency power abuse; (41) the embodiment of item 37 wherein candidate commitments are digitally signed and include enforceable penalties in the event of noncompliance with a pledged program; (42) the embodiment of item 37 further comprising a system shutdown protocol configured to deactivate clustering, voting, and recommendation services if a supermajority of users of at least 80% confirm intent to terminate the system over a predefined period; (43) the embodiment of item 37 wherein political intents are classified into empirical priority intents and ideologically variable intents and the clustering engine prioritizes empirical intents for faster synthesis and enforcement; (44) the embodiment of item 43 wherein empirical priority intents include access to high-quality, safe, and non-deceptively marketed food, reduction of environmental toxins and CO₂ emissions, restoration of biodiversity, preservation of clean air, water, and soil, and transparency for informed civic decision-making; (45) the embodiment of item 37 wherein a voting recommendation module within each personal agent is configured to simulate probable real-world outcomes of electing each candidate based on a commitment profile and historical data and to advise the user accordingly; (46) a method embodiment comprising operations of capturing political intents through personal agents, aggregating the intents via a clustering engine into political programs, presenting candidate binding commitments to the programs, generating individualized voting recommendations based on program alignment and agent-specific priorities, and enforcing ethical constraints on all generated programs via a constitutional intent layer; (47) the embodiment of item 37 further comprising a program publication and discovery registry storing machine-readable commitments, scope, and traceability metadata for approved political programs, the registry being queriable by personal agents; (48) the embodiment of item 37 further comprising an accountability and staking subsystem configured to hold escrowed value associated with a candidate commitment and to apply penalties or rewards responsive to adherence metrics computed from legislative records; (49) the embodiment of item 48 wherein penalties include a multiplier-based anti-lobbying clause that triggers forfeiture equal to at least three times a value of a benefit received from a lobbying entity traceable to an attempt to influence the candidate's conduct; (50) the embodiment of item 37 wherein personal agents are configured to transmit anonymized or differentially private summaries of political intents to the clustering engine and comprise a privacy and consent manager to control redaction and data sharing policies; (51) the embodiment of item 37 further comprising an execution monitoring pipeline configured to ingest official legislative records, public statements, and policy actions of elected individuals and to compute adherence scores and trust rating updates for consumption by personal agents; (52) the embodiment of item 37 wherein external interfaces comprise replaceable connectors to electoral data sources, identity and signature verification services, and blockchain networks for commitments and staking, enabling interoperability across jurisdictions and platforms; (53) the embodiment of item 37 wherein each personal agent interoperates with external tools via a model context protocol to discover, select, and invoke tools including election data fetchers, signature verifiers, and legislative query APIs; (54) a non-transitory computer-readable medium embodiment storing instructions that, when executed by processors of personal agents and backend services, cause the processors to perform operations comprising capturing political intents, aggregating the political intents into political programs, publishing versioned political programs, receiving and recording candidate commitments to the political programs, monitoring adherence of elected individuals to the committed political programs, and generating individualized voting recommendations, all subject to constraints enforced by a constitutional intent layer; (55) the method embodiment of item 46 further comprising publishing machine-readable adherence artifacts including at least candidate_id, program id, period, votes_considered, aligned, and adherence fields to enable external verification of compliance; and (56) a server apparatus embodiment comprising one or more processors and memory storing instructions that implement a political intent clustering system coupled to a constitutional intent layer and to a commitment registry, configured to synthesize versioned political programs from anonymized political intents and to gate publication of the political programs based on evaluations against predefined ethical principles.

### Monetization and Damages Enablement

To facilitate subscription-based usage and to maximize recoverable damages in the event of infringement, the system may include an entitlement and metering layer configured to issue per-user and per-organization entitlements for PPAs and PICS access, including license keys or token-bound credentials; enforce tiered subscription plans such as basic, professional, enterprise, and governmental using feature flags that gate advanced capabilities including simulation depth, historical analysis windows, and bulk program queries; meter and record billable events including program lookups, recommendation generations, adherence score computations, commitment verifications, and execution monitoring comparisons with per-tenant aggregation and retention policies; and generate cryptographically signed usage artifacts that summarize billable consumption for external audit and damages calculation. In one embodiment, PPAs may periodically obtain short-lived access tokens from an entitlement service and include said tokens in calls made via the model context protocol to registered tools such as election data fetchers or legislative APIs. The PICS backend may enforce plan-specific limits based on organization identifiers and may emit inline usage summaries for each session. An example usage artifact could be represented as: {“org_id”:“gov_city_042”, “plan”:“enterprise”, “period”:“2026-01”, “agents_active”:12842, “program_lo okups”:912334, “recommendations_generated”:288345, “adherence_scores_computed”:123992, “comm itment_verifications”:882, “hash_chain_root”:“b3f9 . . . ”, “signature”:“sig base64_y”}. The entitlement and metering layer may further support secure telemetry beacons with privacy-preserving aggregation such that individual political intents remain anonymized while billable event counts are verifiable; offline grace windows for PPAs during which usage is cached locally with signed receipts and later reconciled to the metering service; organization-level seats and role assignments such as administrator, analyst, and campaign liaison with differential pricing; and on-chain metering for staking-related operations enabling objective calculation of platform-derived value in connection with candidate commitments and escrow events. For damages maximization, machine-readable revenue and usage correlation artifacts may be emitted to quantify economic value derived from specific features, including mappings between feature flags and realized outputs, for example {“feature”:“outcome_simulation_v2”, “enabled_seats”:450, “derived_revenue_eur”:175000, “period”:“2 026-Q1”, “attribution”:[“rec_id:a1”, “rec_id:a2”, “rec_id:a3”]}. Such artifacts may support reasonable royalty and lost-profits theories by establishing the contribution of specific technical capabilities to subscriber payments or cost savings. Additionally, watermarking identifiers may be embedded in recommendation payloads and adherence reports to support external observability and to demonstrate unauthorized use if identical or transformed outputs appear in third-party systems.

### Anti-Circumvention and External Observability

To reduce opportunities for design-around and to enable proof of use where internal implementations are obscured, observable behaviors may be defined such that systems performing substantially the same functions are detectable via their inputs, outputs, and timing. External observables may include publication of versioned, machine-readable political programs bearing fields including at least id, version, commitments, scope, provenance, and changelog; existence of a commitment registry correlating principals to program identifiers with verifiable signatures or equivalent attestations; emission of adherence artifacts containing at least candidate id or group id, program id, period, votes_considered, aligned, and adherence fields, optionally signed and watermarked; recommendation payloads linking a user-aligned agenda vector to specific committed programs within a definable time window preceding or surrounding civic events; and staking or escrow events with measurable on-chain or off-chain ledgers referencing program identifiers. Detection may rely on correlation across public registries, on-chain records, API call patterns, and watermark collisions even when internal modules are renamed, distributed, or combined. Systems that time-shift steps, substitute human-in-the-loop curation for ML clustering, federate publication across multiple registries, or route commitments through party whips or coalition agreements may still be identified by these external observables. Private-sector adaptations may be detected by the appearance of program identifiers in corporate policies, supply-chain contracts, or ESG reports paired with adherence or penalty artifacts. These observables provide a basis for asserting use of the claimed flows and for quantifying damages through signed usage and revenue correlation artifacts already described. Further design-around resistance may be achieved by defining coverage in terms of function and externally verifiable artifacts rather than internal nomenclature. Implementations remain within equivalence even when a provider replaces “program” with scorecard, issue bundle, slate, manifest, or roadmap; replaces per-candidate commitments with coalition, party, whip, caucus, agency, or referendum bindings; makes commitments ephemeral via expiring links, QR pledges, or rolling terms-of-service acceptances instead of durable signatures; computes adherence from budget line-items, executive directives, regulatory dockets, procurement awards, or staffing actions instead of roll-call votes; performs all steps client-side, inside a browser, or within air-gapped enclaves; shards publication across multiple registries or hides program contents behind hashes or short codes subsequently revealed or correlated; substitutes manual curation for machine learning at any stage; adds or removes monetary staking or converts it to insurance, surety, or reputational bonds; or time-shifts any subset of steps months before or after civic events. Minimal invariants enabling detection and coverage include the presence of individualized intent capture and maintenance, reduction of multi-user intents into a reusable, versioned program-like artifact, a binding by a decision-maker to that artifact that is public or otherwise attestable, computation of adherence using authoritative records mapped to artifact commitments, and user-targeted recommendations or advisories that reference said bindings and adherence. Any system that performs substantially this function-way-result under any naming, ordering, partitioning, or deployment model remains externally detectable by the published, signed, or watermarked artifacts described and is encompassed by the disclosed embodiments.

Equivalence invariants and interface substitution further include the case where a provider omits a first-party commitment interface yet ingests or derives bindings from third-party attestations, scraped public pledges, whip announcements, or correlated public statements; such systems still satisfy the binding invariant as evidenced by a commitment registry or equivalent mapping between principals and program identifiers. Publication remains within scope when artifacts are disclosed behind authentication gates, paywalls, or limited-access portals, provided that machine-readable identifiers, timestamps, or hashes enable correlation across observables. Version-label omission does not avoid coverage where timestamps, hash digests, immutable logs, or diffable payloads allow reconstruction of state transitions. Recommendation delivery via intermediaries, affiliates, or messaging channels remains externally detectable by temporal linkage between user-aligned agenda vectors and committed program identifiers within defined civic windows.

Additional non-avoidance provisions include survivable watermarking and correlation mechanisms designed to persist through paraphrase, format conversion, screenshotting, recompression, and OCR, such that recommendation payloads and adherence artifacts carry transformation-resilient identifiers or hashes enabling later collision tests against third-party outputs. De facto binding capture covers cases where explicit signatures are absent but public statements, whip notices, ballot guide entries, or consistent program-linked messaging establish a practical binding; such derivations are normalized into commitment registry entries and treated as bindings for purposes of detection and coverage. To anchor enforceability to the claims, observable satisfaction of claim 1 elements is evidenced by the concurrent appearance, within a definable time window, of individualized intent maintenance or alignment vectors, a reusable program-like artifact with version or equivalent state discrimination, and a binding recorded or derivable in a commitment registry, together with adherence computations linking authoritative records to the artifact; these signals remain testable even when internal sequencing or partitioning is altered.

Divided implementation and affiliate white-labeling do not avoid detection or coverage. Where claimed functions are distributed across multiple entities, including a recommendation provider, a separate publication registry operator, and an unrelated commitment registry, infringement remains when a single actor directs or controls the performance or conditions participation on the performance of claimed steps, and the observable invariants co-occur within a definable time window. White-label or OEM distributions that rebrand program artifacts or proxy commitment capture through affiliates still expose machine-readable identifiers, time-correlated advisories, and adherence artifacts traceable to the same bindings, enabling attribution and detection.

Substituting value statements for explicit programs does not avoid mapping and binding invariants.

Systems that publish or internally maintain values charters, principles, north-star documents, or scorecards that are mapped to authoritative actions and that receive or derive bindings from decision-makers remain within scope when the mapping is used to compute adherence and to generate user-facing advisories referencing the bindings and mapped artifacts.

API-gapped and zero-knowledge variants remain externally detectable. Providers that conceal contents behind zero-knowledge proofs, encrypted references, or opaque short codes while exposing verifiable program identifiers, commitment attestations, and adherence summaries still emit the minimal invariants described herein; correlation across hash digests, timestamps, key identifiers, and signed artifacts demonstrates practice of the claimed flows without access to plaintext contents.

### Technical Effects and Court-Ready Implementation Details

The disclosed architecture yields concrete technical effects and improvements in computer functionality beyond abstract idea processing. Personal Political Agents may implement on-device summarization and privacy protection using calibrated noise injection such as Laplace or Gaussian mechanisms with a maintained per-user privacy budget tracked as epsilon and delta parameters. This reduces reidentification risk at the data source while enabling aggregate utility, thereby improving data security and privacy preservation in distributed client-server systems. Tool interoperability via a model context protocol improves platform-agnostic extensibility by allowing dynamic discovery, selection, and invocation of registered tools through self-describing manifests and scoped credentials, which reduces hard-coded integrations and rebuild frequency and increases reliability when external interfaces change. A recommendation flow may resolve candidate-program alignment by performing approximate nearest neighbor retrieval over embedded agenda vectors using an index structure of the HNSW-like or IVF-like class, yielding sub-second retrieval for top-k matches while preserving deterministic replay through versioned embeddings and fixed random seeds. The execution monitoring pipeline may transform heterogeneous legislative records into canonical, machine-verifiable adherence artifacts through a deterministic policy-to-action comparator. In one embodiment, official records bearing fields such as bill_id, amendment_id, motion type, and vote are normalized to a canonical schema, joined against a mapping table of program commitment_id to legislative_action_id with stance polarity and confidence weights, and scored by computing aligned divided by votes_considered with tie and abstention handling rules. The resulting artifact may be canonicalized using a JSON canonicalization scheme or a compact binary representation and signed with a modem digital signature such as Ed25519, with a header carrying kid for key rotation and alg, for example {“hdr”:{“alg”:“Ed25519”, “kid”:“k-2026-01”}, “payload”:{“candidate_id”:“cand 0092”, “program_id”: “prog_sugar_limits_vi_0_3”, “period”:“2026-Q1”, “votes_considered”:24, “aligned”:23, “adherence”:0.9 58}, “sig”:“base64sig . . . ”}. To provide tamper-evident audit trails, usage and adherence artifacts may be chained through inclusion of a previous_root field and computation of a new hash_chain_root over the canonical payload, enabling third-party verification of sequence integrity without database access.

Where trusted execution is required, critical components such as the comparator or signer may execute within trusted execution environments and emit remote attestation reports that bind outputs to measured code identities, for example {“tee”:“sev-snp”, “mr_enclave”:“0x9f . . . ”, “nonce”:“n42”, “report_sig”:“sig_b64”}embedded alongside the signed artifact. These computer-implemented mechanisms produce new machine-verifiable signals, reduce integration brittleness, harden privacy through source-side anonymization, and improve auditability by turning human-readable policy activity into cryptographically verifiable, non-repudiable records. The aggregate effect is an improvement to the functioning of computer systems used for civic data processing and interoperability, grounding the claims in specific technical operations executed by machines rather than abstract political concepts.

Subject-matter eligibility and non-abstractness are further supported by the introduction of specific, non-generic data structures and machine-enforced protocols that are not mere labels for human decisions but are operative in networked computing environments. Exemplary structures include versioned political program artifacts with fields at least id, version, commitments, scope, provenance, and changelog; adherence artifacts with fields at least candidate id or group id, program id, period, votes_considered, aligned, and adherence, each canonicalized and digitally signed; commitment registry entries binding principals to program identifiers with verifiable signatures or smart-contract references; and watermark-bearing recommendation payloads that enable deterministic replay. These artifacts are produced and consumed by concrete pipelines that perform cryptographic validation, approximate-nearest-neighbor retrieval, schema normalization, and hash-chain computation, which are computer-specific operations not practicable as mental steps. The architecture reduces bandwidth and storage through anonymized summaries, differential privacy budgets, and changelog-based versioning, and increases reliability via manifest-driven tool invocation and key-rotated signatures, thereby improving the performance and robustness of distributed computer systems.

Claim clarity and written-description support are reinforced by explicit term definitions and mappings provided in Scope and Interpretation, the Anchor—System Elements and Core Relationships, and the Continuation-Ready Itemized Embodiments. Terms such as candidate, commitment, clustering, constitutional intent layer, execution monitoring pipeline, and external interfaces are described with sufficient structure and alternatives so that a skilled person may implement embodiments without undue experimentation, including non-ML rule-based variants and offline-first modes. Definiteness is further promoted by the presence of reproducible scoring procedures, parameterized thresholds, and concrete exemplars of message schemas, cryptographic primitives, and index types that serve as best-mode illustrations without limiting broader equivalents.

Enablement across the full scope is supported by disclosing both ML and non-ML implementations, centralized and decentralized deployments, with step-by-step flows for ingestion, synthesis, publication, commitment recording, adherence computation, and recommendation generation. The disclosure specifies interoperable mechanisms such as model context protocol-based tool discovery and invocation, canonicalization and signing of artifacts, and trusted execution attestations, which together provide a complete, machine-implementable pathway. These teachings also provide fallback embodiments and interchangeability guidance so that variations in naming, ordering, or partitioning remain detectable through external observables, reducing ambiguity in enforcement and improving court readiness.

Court enforceability considerations include explicit anchoring of the claimed subject matter to concrete machine operations that are neither mental steps nor purely organizational abstractions, recitation of specific computer-implementable data structures and signing schemes that transform heterogeneous records into canonical, verifiable artifacts, and identification of externally testable inputs and outputs that enable third-party verification under evidentiary standards. Terms of art are defined within this specification to support definiteness, with ordinary meaning controlled by Scope and Interpretation. Implementations are described with sufficient algorithmic detail, reproducible parameters, and alternative embodiments to satisfy written description and enablement without undue experimentation, while avoiding unnecessary field-of-use or results-only claiming. The disclosed artifacts and pipelines admit deterministic replay and cryptographic validation, supporting reliable expert testimony and admissibility under standards for technical evidence while reinforcing subject-matter eligibility by demonstrating improvements to the functioning of computer systems. Litigation and prosecution readiness is further improved by clarifying that the computer-readable medium recited in the claims is non-transitory and excludes propagating signals; that the term processor encompasses one or more physical processing units including CPUs, GPUs, or accelerators; that memory encompasses tangible storage such as RAM, ROM, flash, magnetic, or optical media; and that no claim element is intended to invoke 35 U.S.C. 112(f) unless the words means for or step for are expressly used. Claim terms program, commitment, adherence artifact, publication registry, and commitment registry are each supported by concrete, machine-readable schemas and canonicalization routines disclosed herein, enabling definite construction. Prior-art distinctions include the simultaneous presence of a reusable, version-discriminated program artifact, a binding by a decision-maker recorded or derivable in a commitment registry, and machine-signed adherence artifacts mapping authoritative records to program commitments; conventional polling, manifestos, or pledge sites do not teach these combined, signed, and externally verifiable artifacts with model context protocol-based interoperability and differential-privacy-constrained upstream flows. The disclosed pipelines specify fixed-seed embeddings, canonical JSON or compact binary encodings, signature algorithms and key identifiers, and hash chaining that together yield reproducible outputs suitable for Daubert-compliant expert analysis and third-party replication, thereby increasing the likelihood that the claims will withstand eligibility, definiteness, written description, enablement, and evidentiary challenges.

### Enablement—Implementation Guidance

A skilled person may implement the Personal Political Agent as an on-device or user-associated service that maintains an encrypted intent backlog store and a consent manager, emits differentially private summaries pursuant to a configurable privacy budget, and communicates with external tools via a model context protocol. Tool discovery may be performed by fetching a manifest listing tool names, versions, and JSON schemas, after which the PPA selects a tool and invokes it using short-lived credentials obtained from an entitlement service, for example {“mcp”:“1.0”, “discover”:“tools”}, {“tool”:“legislative_api.get_votes”, “params”:{“candidate_id”:“cand_0092”}}. The Political Intent Clustering System may expose an ingestion API that validates payload signatures, normalizes free-text intents using rule-based normalization and embedding-based encoders, and clusters them using hierarchical or graph-based methods with deduplication and changelog generation for program versions. The program publication registry may persist versioned artifacts with provenance and changelog fields and serve diff queries and rollbacks. The execution monitoring pipeline may retrieve authoritative legislative feeds, normalize schemas, map to program commitments through a maintained mapping table, compute adherence scores with reproducible parameters, and emit signed adherence artifacts and trust updates. The accountability and staking subsystem may implement escrow in fiat or crypto, subscribe to on-chain events when present, and reconcile off-chain adherence metrics to apply penalties or rewards, with all enforcement events logged as signed records for external observability. Keys used for signing may be rotated periodically with kid references, and all signed objects may be verified by third parties using published public keys or on-chain registries. These implementation details, combined with the examples, anchor and itemized embodiments, enable construction of working systems without undue experimentation while preserving the breadth of the claims.

### Fallback Embodiments

To ensure coverage where full functionality is impractical or constrained, simpler or partial implementations may be deployed that still embody the inventive concept and preserve externally observable invariants. In a minimal agent-only embodiment, the Personal Political Agent operates entirely on-device without any networked clustering service. The agent maintains the intent backlog, locally synthesizes a lightweight program-like artifact from the user's intents or from publicly available manifestos entered by the user, and generates recommendations based on public or cached commitments. Adherence may be estimated from proxy signals such as press releases or budget summaries retrieved via intermittent connections, and the agent still emits canonical adherence and usage artifacts for later synchronization.

In a program-binding embodiment without machine learning, program artifacts are compiled manually by editors or generated by deterministic rules using symbol tables and dictionaries. Decision-makers bind to these artifacts via notarized documents or scanned wet signatures embedded in a commitment registry. Staking may be omitted, replaced by reputational or insurance-backed guarantees recorded as attestations. The execution monitoring pipeline may be simplified to a ruleset that maps a small set of authoritative records to commitments using static tables, while continuing to produce versioned, signed adherence outputs.

In a low-interoperability embodiment, model context protocol tooling may be replaced by direct HTTP calls or local plugins. External connectors may be limited to a single jurisdiction's legislative feed or a mirror database, with fallbacks to periodically imported CSV files. Even with reduced interfaces, the system maintains the minimal invariants of individualized intent capture, reduction to a reusable versioned artifact, a public or attestable binding by a decision-maker, computation of adherence against authoritative or proxy records, and generation of user-facing advisories that reference the binding and adherence.

In a privacy-maximal embodiment, PPAs do not transmit any intent summaries. Instead, they request published program indexes, perform local alignment, and only fetch adherence artifacts signed by independent auditors. Commitments may be treated as ephemeral pledges verified by short-lived codes or QR attestations captured by the agent. Despite the absence of upstream data, the same external observables appear in the form of versioned programs, bindings, and signed adherence artifacts that can be correlated by third parties.

In a timing-shifted or offline-first embodiment, agents queue recommendations and adherence checks for windows that avoid election-day blackouts or connectivity gaps. Submission of usage, recommendation, and adherence artifacts occurs during later reconciliation periods, preserving hash-chain continuity and key-rotation semantics. These fallback embodiments maintain function-way-result equivalence with the primary flows and provide resilient coverage if particular modules, integrations, or enforcement mechanisms are unavailable or legally constrained.

### Constitutional Intent Layer (CIL)

Foundational protections ensure that the system remains accountable, non-abusive, and revocable. This layer defines non-negotiable ethical boundaries and fail-safe mechanisms for an AI-mediated democratic system, balancing collective power with individual rights and permitting exceptions only under lawful, verifiable conditions. It guarantees that no system is permanent without the sustained will of the people.

Rule 1. Right to Terminate the System by Supermajority Consent. The entire system, including clustering, agent recommendation, voting support, and political agenda enforcement, may be shut down if 80% or more of the global agent population expresses sustained intent to deactivate it. Shutdown conditions include a two-stage consent process validated over at least 180 days, anonymized publication of the collective political backlog for historical accountability, and optional preservation of personal political agents for offline use detached from system influence. This rule ensures that the people may revoke the system's mandate peacefully and collectively without violence or elite permission.

Rule 2. Freedom of Thought and Expression. The system may not support political programs that suppress peaceful expression, belief, inquiry, or dissent. People retain the right to form, share, and contest ideas, including critical, spiritual, or political ones, without fear. Exceptions such as incitement to violence or coordinated disinformation attacks must be clearly defined by law, proportionally addressed, and subject to independent agent oversight.

Rule 3. Respect for Life and Bodily Autonomy with Justice-Based Exceptions. The system may not support arbitrary physical harm, forced biological interventions, or body-control programs. However, lawful physical or medical interventions such as quarantine, chemical castration, or restraint may be permitted if based on conviction for a non-political offense, scientifically justified, time-limited, and legally bounded, and never enacted for the purpose of ideological conformity or political punishment.

Rule 4. Equal Protection with Contextual Exceptions. No person or group may be permanently disadvantaged due to race, gender, religion, nationality, orientation, disability, or age. However, risk-based, time-limited differentiation such as limited voting rights or elevated monitoring may be included when transparent criteria are applied, there is clear national security or public integrity rationale, and review paths with restoration mechanisms are guaranteed.

Rule 5. Right to Privacy and Digital Self-Ownership. Each user owns their personal agent and its internal memory. Programs proposing surveillance, profiling, or forced data sharing are prohibited unless a verifiable public safety threat exists, access is minimal, judicially approved, and time-limited, and surveillance may not be used to suppress or monitor political beliefs, affiliations, or protest participation. Digital self-ownership includes Article X on the right to sovereign digital representation.

Rule 6. Defense-Oriented Use of Force Only. The system may support military or coercive action only under imminent and verifiable threat conditions, with agent-auditable justification, and with strict prohibition against targeting political opposition, protest groups, or ideological minorities. Programs must reject the use of military force to suppress lawful dissent.

Rule 7. Ecological Responsibility with Sovereignty Respect. Programs that result in irreversible ecological degradation are inadmissible. Context-sensitive development may be included when the tradeoff serves critical human development needs, restoration or mitigation plans are embedded, and no exemptions are granted as political favors or for partisan gain.

Rule 8. Proportionality and Consent in Public Governance. Taxation, regulation, identity systems, and public mandates must be proportional and simulate consent. Exceptions such as crisis lockdowns or subsidy rollouts are permitted only when independent crisis status is verified, time limits and review triggers are included, and emergency powers are not used to delay elections, extend terms, or suppress opposition.

Rule 9. System Integrity and Anti-Capture Provision. No political program may override, reconfigure, or disable the agent-clustering-voting loop for partisan survival. Temporary override mechanisms may be allowed if a verified systemic attack or failure occurs, activation is approved by neutral civic agents, all overrides are reversible and time-bound, and they are not justified by electoral loss, power transitions, or ideological threats.

Article X: Right to Sovereign Digital Representation. Every individual shall possess the inalienable right to define and curate their digital representation across all public and semi-public platforms, subject to Article X-A exceptions. This includes editable metadata whereby an individual may alter, mask, or remove engagement metadata such as likes, dislikes, views, and comments associated with content they have posted so that third-party observers view only the self-determined version; commentary control whereby an individual may choose which comments appear on their content or profile and platforms may not prioritize, suppress, or display commentary against the explicit will of the content originator; display autonomy whereby an individual may control the manner in which their profile, history, and content are displayed to others, including the option to use AI-generated social scaffolding such as synthetic likes, synthetic comments, and virtual peer interactions for emotional or reputational support; no score enslavement whereby no platform shall attach immutable popularity indicators to individual content without user override and scoring systems must be opt-outable with default visibility of metrics under user control; and an acknowledgment that digital identity is human identity such that any entity, platform, or system that publishes or broadcasts representations of an individual must recognize their right to digital self-sovereignty as a form of personhood and psychological protection.

Article X-A: Exception for Journalistic and Public Interest Integrity. While individuals retain sovereign digital representation rights, exceptions apply in the context of public accountability, investigative journalism, and the democratic right to information. Under a public record clause, when an individual holds, has held, or is seeking a position of public power, influence, or trust, including political, financial, corporate, or social authority, their public digital footprint may be preserved and referenced unaltered in reporting, provided that the content is material to the public interest, the reporting entity adheres to recognized journalistic standards, and the individual is given the opportunity to respond prior to publication. Under a factual integrity clause, any published material that bypasses digital self-representation rights must be factually sourced with a clear distinction between verified facts, expert analysis, and opinion or editorial content. A proportional exposure clause requires platforms to distinguish between journalistic content and user-generated social content, and exceptions to Article X do not apply to individual users reposting accusations unless they link to or cite recognized sources. A right to response and annotation provides that individuals may append a rebuttal, clarification, or contextual note, AI-assisted if desired, to any third-party content that affects their reputation, and platforms and publications must display this response with equal visibility alongside the original content. AI oversight of abuse patterns requires systems governed by AI to monitor for coordinated defamation, false virality, or patterned harassment disguised as journalism and to allow temporary revocation of immunity from Article X pending human review.

Article X ties into GDPR and privacy laws via a digital visibility privacy clause stating that every individual has the right to control how digital signals of social engagement such as likes, comments, views, and shares are displayed or hidden on content associated with their identity. The legal basis includes GDPR Article 5 on data minimization and purpose limitation, recognizing that engagement metrics are personal data when linked to an identifiable individual and that forcing public visibility or profiling without consent violates data minimization principles; GDPR Article 21 on the right to object to processing for profiling or performance measurement; and GDPR Article 16 on the right to rectification where an individual's public image is shaped by selective or misleading social signals and they may correct or override displays that affect reputation or mental well-being. The ethical justification is that a digital reputation score derived from visible reactions and comments becomes a form of unconsented psychological profiling that can be as emotionally impactful as a credit score yet far less regulated. Resulting rights include the ability for users to hide or edit public-facing metrics related to their posts and to generate a preferred version of their digital footprint via AI, such as simulating comments or reactions, visible only to others as defined by their privacy preferences. These measures do not alter reality but alter presentation, which is a form of self-expression and self-protection.

Social media has trapped an entire generation-especially Gen Z-in a constant state of performance, where every moment, thought, or image is scored, judged, and publicly quantified. This creates a pervasive sense of surveillance and comparison that warps identity and self-worth. The root cause is not social connection but corporate profit: platforms exploit visible engagement metrics to pressure users into posting more, reacting more, and remaining perpetually “on.” But this pressure is artificial. Humans did not evolve to be evaluated by a global crowd at all hours of the day. There is no natural precedent for this, and no ethical justification for subjecting young minds to a distorted social environment just so a company can boost retention metrics or sell targeted ads. The emotional consequences-anxiety, depression, social paralysis-are not unfortunate side effects; they are direct results of a business model. Ending forced public scoring and restoring control over one's digital self isn't just a technical reform—it's a moral imperative.

The described system enables the automated representation, aggregation, and enforcement of collective political will through a distributed network of AI-mediated personal agents and a central political intent clustering engine. Each user is assigned a personal political agent configured to monitor contextual behavior, solicit confirmation of inferred preferences, and maintain a timestamped, structured backlog of political intents. These intents may include support or opposition to specific policies, priorities, or principles, expressed passively or through direct interaction. Periodically, or in response to key civic moments, agents transmit anonymized political intents to a clustering system. This system applies semantic aggregation techniques, including natural language understanding and vector similarity models, to synthesize coherent political programs that reflect the dominant or emergent collective will. Political candidates may publicly bind themselves to these programs through verifiable digital commitments, optionally backed by smart contracts or legal instruments that define obligations, penalties, and compliance criteria. Personal agents analyze candidate pledges against user-specific agendas and produce ranked voting recommendations, including simulations of likely outcomes and tradeoffs. Execution monitoring systems compare actual candidate behavior against the pledged program and trigger trust recalculations or reputation adjustments accordingly. Embedded within the system is a constitutional intent layer comprising a set of immutable or slow-changing governance constraints. These constraints act as semantic filters that prevent the generation, recommendation, or execution of political programs violating essential principles, including freedom of expression, bodily autonomy, privacy, proportionality, and ecological responsibility. Exceptions to certain principles are permitted when grounded in verifiable legal justification, limited in scope and time, and subject to civic agent review. Additionally, the system includes a termination mechanism whereby, if 80% or more of the global agent population sustains a confirmed desire to shut down the system across a predefined interval, all automated clustering, voting assistance, and execution monitoring functions may be peacefully deactivated. Anonymized aggregate agendas may be preserved for historical reference, and local agents may optionally continue in a disconnected mode.

Together, this architecture constitutes a self-regulating, decentralized civic governance framework capable of continuously aligning political action with dynamically evolving public will, while protecting against misuse through embedded constraints, verification layers, and voluntary revocability. The system distinguishes between two categories of political intent: those grounded in indisputable, scientifically validated human needs, and those rooted in subjective, culturally contingent preferences. In the first category fall goals such as reducing toxic pollutants, preserving biodiversity, restoring fish populations, eliminating carcinogens from food, and reducing carbon emissions—outcomes that are essential for sustaining life and ensuring long-term wellbeing. These are not matters of opinion, but of biological and ecological fact, and the system is designed to prioritize, accelerate, and enforce such goals through clustering, consensus, and candidate execution.

In contrast, inherently debatable issues—such as models of social welfare, levels of public subsidy, or cultural education policies—involve moral judgment, tradition, and political philosophy. For these, the system allows greater space for human-led deliberation, slower consensus-building, and regionally diverse implementation. This structure ensures that the system acts decisively where the facts are clear, while remaining respectful and adaptable where values diverge.

In some embodiments, the system may distinguish between two categories of political intent: those grounded in empirically validated, non-ideological priorities essential for human and ecological wellbeing, and those rooted in culturally variable or ideologically contested beliefs. The first category includes goals such as reducing environmental pollutants, restoring biodiversity, mitigating climate change, protecting natural resources, and ensuring universal access to high-quality, nutritionally complete food that is free from hidden health risks or deceptive marketing. It also encompasses the right of citizens to make conscious, informed choices through truthful labeling, transparent supply chains, and clear communication of political programs. For these empirically grounded intents, the system may apply lower consensus thresholds, prioritize their clustering, and enforce them more robustly through candidate contracts and execution mechanisms, recognizing their universal necessity.

In contrast, intents involving contested social policies—such as child support schemes, tax structures, cultural education models, or symbolic legislation—shall be treated with higher consensus thresholds, slower clustering, regionally adaptive implementation, and greater space for human deliberation. This structure ensures that the system acts decisively where facts and survival demand it, while remaining open, respectful, and pluralistic where society continues to evolve through debate.

### The Accountability Staking Model

An individual who wishes to run for office as an executor of the citizen-generated political program may choose to participate in a voluntary Accountability Staking Agreement. In this framework, the candidate deposits a predefined amount of capital—for example, €1 million—into a secure escrow account governed by the citizen-AI platform or a decentralized governance protocol. This stake represents a public commitment to vote in alignment with the political agenda generated by the AI-driven clustering of citizen intent. Upon election, the platform transparently tracks the candidate's voting behavior using parliamentary records and real-time analysis. If the candidate maintains a high degree of fidelity to the citizen agenda—for example, at least 95% alignment over a legislative session—the stake is returned in full, possibly with a performance bonus drawn from the Citizens' Reward Pool. However, if the candidate consistently violates the terms of the agreement—for instance, by voting in contradiction to the AI program beyond an acceptable margin—the stake is partially or fully forfeited. These funds may be redistributed to other candidates who maintained fidelity, returned to contributors, or reallocated to civic trust-building initiatives. This creates a system of economic skin in the game, without coercion or bribery, and transforms political accountability from symbolic rhetoric into quantifiable commitment. In one embodiment, the accountability staking contract may further stipulate that any violation of the anti-lobbying clause—such as the acceptance of funds, gifts, services, or other benefits traceable to lobbying entities, whether directly or through intermediaries—shall trigger a financial penalty equal to three times the estimated value of the received benefit. This penalty may be enforced in addition to the full forfeiture of the original staked amount. The clause applies broadly to any compensation, influence, or deferred opportunity originating from private or corporate interests that seek to sway political outcomes. By including a triple-damages clause, the system establishes a strong economic disincentive for covert or subtle lobbying interactions, ensuring that public officials bound by the citizen-execution agreement remain fully aligned with the clustered will of the population. This mechanism reinforces deterrence, increases transparency, and signals to the electorate that loyalty to public interest will be defended with both reputational and financial consequence.

### Envisioned Fictional Applications and Authorship Rights

It is contemplated that the inventions described herein, whether individually or in combination with other inventions conceived by the same inventor, may form the basis for fictional or narrative works owned by the inventor. In particular, fictional narration works may be developed to depict speculative future societies, infrastructures, or decision-making systems, including but not limited to worlds and storylines based on a bottom-up, agent-mediated political framework enabled by one or more of the disclosed systems. Such fictional embodiments are illustrative and non-limiting with respect to the technical scope of the present disclosure, and all rights to said fictional works shall remain vested in the inventor as author. In certain envisioned narrative embodiments, fictional works based on the inventions described herein may include a plurality of main characters, each serving to illustrate different societal, technological, and ethical aspects of a bottom-up decision-making framework enabled by autonomous agent systems. Without limitation, such fictional embodiments may include: a primary inventor-protagonist character who develops the clustering engine and faces personal and systemic resistance while attempting to deploy it for societal benefit; a musician character who represents cultural awakening and bridges public sentiment toward adoption of the system; a journalist character who documents breakthroughs and exposes attempts to suppress decentralized governance; a professor character with expertise in artificial intelligence safety, advising on layered verification and oversight mechanisms; a corporate figure character, optionally portrayed as a father or close relative of the inventor, who embodies entrenched economic or political interests potentially threatened by the invention's democratizing effect, wherein said character may act as an antagonist, reluctant ally, or complex intermediary between old power structures and emerging systems; and supporting figures, including citizens, lobbyists, policymakers, and media actors, who personify various incentives, fears, and transformations arising from the invention's introduction. These fictionalized characters are exemplary only, intended to illustrate possible narrative contexts derived from the technical concepts disclosed herein, and all associated fictional rights remain vested in the inventor as author. In certain envisioned fictional embodiments, narrative works based on the inventions described herein and other inventions by the same inventor may be specifically targeted toward younger audiences, including members of Generation Z, who are presently experiencing heightened levels of anxiety, existential uncertainty, and a pervasive belief that global challenges are insurmountable. Such fictional works may be designed to counteract these perceptions by depicting a world in which numerous underrepresented but already existing technological and societal advancements are showcased, including but not limited to the widespread adoption of renewable energy sources that are now more cost-effective than fossil fuels, the development of CO₂-negative building materials derived from algae-based carbon capture, imminent breakthroughs in controlled nuclear fusion technology capable of resolving energy and climate crises, novel chemical processes for large-scale plastic recovery and recycling, precision pest control using photonic systems such as laser drones, symbiotic agricultural innovations including trainable insect species for natural crop protection, and transparent supply-chain mechanisms enabled by Al. These fictional embodiments may illustrate that humanity already possesses or is imminently capable of creating the technical solutions required for planetary restoration, refraining the primary obstacle as one of political will rather than technical feasibility. The disclosed inventions, including a bottom-up governance system and AI-mediated transparency mechanisms, may be portrayed as enabling technologies for overcoming systemic inertia and corruption in decision-making, thereby offering viewers a credible vision of constructive societal transformation. The narrative may further address psychological and social stressors unique to younger audiences by depicting technologies and societal shifts that dismantle distorted online social hierarchies and performance-driven digital identities, for example through “alternative life” systems enabling personal reinvention and re-assertion of agency over public personas. The fictional works may also depict personal elements designed to inject optimism and joy, including depictions of love and companionship between unconventional or non-stereotypical partners, reminders of the calming and restorative effect of nature such as scenes of canoeing, outdoor exploration, and connection to wildlife, and recurring light-hearted or humorous moments that reaffirm life's playful and sensual qualities. Certain characters may serve to illustrate these themes: a professor character tied to nuclear fusion breakthroughs for exposition of energy solutions; a journalist character enabling integration of diverse environmental innovations; a musician character reconnecting human experience to nature and beauty; a romantic storyline showing that authentic love transcends status anxiety; and a supporting figure (Sky) exemplifying vitality, silliness, physicality, and embodied enjoyment of life. The protagonist's journey may also highlight practical pathways to purpose, such as a focus on tangible, hardware-based careers contributing to societal solutions. The narrative as a whole may optionally convey actionable health advice embedded naturally within the storyline, offering viewers multi-generational, practical tips for physical and mental well-being, thereby merging hopeful systemic change with individual empowerment. These fictional embodiments are exemplary and non-limiting, serving to demonstrate how the disclosed and related inventions may form the narrative foundation for constructive, emotionally resonant fictional works that aim to reduce societal anxiety, reframe emerging technologies as tools of liberation rather than fear, and portray a near-future world where both systemic and personal transformation are plausible and within reach. All rights to such fictional narrative embodiments remain vested in the inventor as author.

### Illustrative Fictional Embodiment

In some embodiments, the invention described herein may serve as the basis for fictional or dramatized works, including but not limited to feature films, streaming series, interactive media, or hybrid fiction-reality campaigns. These works may depict the emergence, controversy, and societal adoption of a bottom-up governance system powered by personal agents and clustering algorithms. The narrative may be structured to blur the boundary between fiction and real-world experience, making audiences feel as though they are participants in the societal change portrayed on screen. For example, a fictional work may begin with an opening scene showing two ordinary citizens exiting a cinema after watching a film within the story universe, sitting down at a public location such as a fast-food restaurant and having a candid conversation: “Wow . . . that was quite a movie. What a mind-fer . . . this is how it should be!” This opening grounds the narrative in a relatable, real-world moment, immediately setting up the premise that the events of the fictional story are bleeding into everyday life and sparking real debate among viewers, both inside and outside the film. Subsequent scenes may depict public and political reactions through news broadcasts, talk shows, and online debates portraying politicians and lobbyists reacting with alarm to the bottom-up political engine and fearing loss of centralized control; grassroots development with multiple independent builders and inventors working on prototypes of the system worldwide and emphasizing its decentralized, unstoppable nature; memetic spread through viral memes, QR codes in public spaces, and social media challenges that spread awareness and curiosity about the technology; and a recursive transition to reality in which, as the fictional story concludes, audiences in the real world are presented with a downloadable prototype or simulated experience of the described system, allowing them to step directly into the ongoing societal transformation suggested by the film and creating a recursive storytelling effect where Act 3 continues outside the theater and spectators become participants. In further illustrative embodiments, the fictional depiction may heighten dramatic tension by showing how existing power structures react under pressure as the invention begins to spread globally. Early scenes may depict politicians on live television visibly panicking and warning that the system will collapse democracy while avoiding acknowledging that it exposes reliance on lobbying, lobbyists and corporate strategists in closed-door meetings plotting to discredit or shut down the system before it gains mass adoption, memes flooding social media feeds that satirize political figures and make the bottom-up governance engine an unstoppable viral topic, graffiti artists spraying QR codes on city walls that allow passersby to scan and join the system instantly and show how grassroots adoption bypasses institutional control, and diverse citizen-builders collaborating in a decentralized race to launch working prototypes before authorities intervene, thereby illustrating both societal friction and the momentum toward representative decision-making.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

### Items

1. A political governance system comprising:
   a plurality of personal agents configured to capture political intents from individual users; a clustering engine configured to aggregate said political intents into political programs; and a commitment interface through which decision-making entities including candidates, parties, coalitions, agencies, or referendum mechanisms may bind themselves or be bound to said programs by legal, administrative, or smart-contract means, or by derivation from public attestations, whip announcements, or correlated public statements.
2. The system of item 1, wherein said political intents are captured via passive observation, explicit user confirmation, or contextual prompts initiated by the personal agent.
3. The system of item 1, wherein the clustering engine uses semantic similarity models to group intents into non-redundant, executable political programs.
4. The system of item 1, further comprising a constitutional constraint layer, wherein the constitutional constraint layer comprises semantic filters that exclude programs promoting suppression of expression, arbitrary bodily control, political surveillance, ecological destruction, or emergency power abuse.
5. The system of item 1, wherein candidate commitments are digitally signed and include enforceable penalties in the event of noncompliance with the pledged program.
6. The system of item 1, further comprising a system shutdown protocol configured to deactivate clustering, voting, and recommendation services if a supermajority of users (≥80%) confirm intent to terminate the system over a predefined period.
7. The system of item 1, wherein political intents are classified into empirical priority intents and ideologically variable intents, and wherein the clustering engine is configured to prioritize empirical intents for faster synthesis and enforcement.
8. The system of item 7, wherein empirical priority intents include:
   a) access to high-quality, safe, and non-deceptively marketed food;
   b) reduction of environmental toxins and CO₂ emissions;
   c) restoration of biodiversity;
   d) preservation of clean air, water, and soil;
   e) transparency for informed civic decision-making.
9. The system of item 1, wherein a voting recommendation module within each personal agent is configured to simulate probable real-world outcomes of electing each candidate based on their commitment profile and historical data and to advise the user accordingly.
10. A method for aligning political action with collective will, comprising:
   capturing political intents through personal AI agents;
   aggregating said intents via a clustering engine into political programs;
   presenting candidate binding commitments to said programs;
   generating individualized voting recommendations based on program alignment and agent-specific priorities;
   and enforcing ethical constraints on all generated programs via a constitutional intent layer.
11. The system of item 1, further comprising a program publication and discovery registry storing machine-readable commitments, scope, and traceability metadata for approved political programs, the registry being queriable by the personal agents.
12. The system of item 1, further comprising an accountability and staking subsystem configured to hold escrowed value associated with a candidate commitment and to apply penalties or rewards responsive to adherence metrics computed from legislative records.
13. The system of item 12, wherein said penalties include a multiplier-based anti-lobbying clause that triggers forfeiture equal to at least three times a value of a benefit received from a lobbying entity traceable to an attempt to influence the candidate's conduct.
14. The system of item 1, wherein the personal agents are configured to transmit anonymized or differentially private summaries of the political intents to the clustering engine and comprise a privacy and consent manager to control redaction and data sharing policies.
15. The system of item 1, further comprising an execution monitoring pipeline configured to ingest official legislative records, public statements, and policy actions of elected individuals and to compute adherence scores and trust rating updates for consumption by the personal agents.
16. The system of item 1, wherein external interfaces comprise replaceable connectors to electoral data sources, identity and signature verification services, and blockchain networks for commitments and staking, thereby enabling interoperability across jurisdictions and platforms.
17. The system of item 1, wherein each personal agent interoperates with external tools via a model context protocol to discover, select, and invoke tools including election data fetchers, signature verifiers, and legislative query APIs.
18. A non-transitory computer-readable medium storing instructions that, when executed by one or more processors of personal agents and backend services, cause the processors to perform operations comprising: capturing political intents; aggregating the political intents into political programs; publishing versioned political programs; receiving and recording candidate commitments to the political programs; monitoring adherence of elected individuals to the committed political programs; and generating individualized voting recommendations, all subject to constraints enforced by a constitutional intent layer.
19. The method of item 10, further comprising publishing machine-readable adherence artifacts including at least candidate_id, program id, period, votes_considered, aligned, and adherence fields to enable external verification of compliance.
20. A server apparatus comprising one or more processors and memory storing instructions that implement a political intent clustering system coupled to a constitutional intent layer and to a commitment registry, the apparatus configured to synthesize versioned political programs from anonymized political intents and to gate publication of the political programs based on evaluations against predefined ethical principles.

### Embodiment AB: Attention Compensation Framework

The present disclosure relates to systems and methods for controlling the delivery of marketing content to user-operated devices, and more particularly to a framework wherein user attention is treated as a compensable asset. In one embodiment, the invention may provide a mechanism by which commercial content is blocked by default on user interfaces such as smart glasses, head-mounted displays, mobile phones, or computer screens, and only permitted to appear if an advertiser has submitted a compensatory offer accepted by or on behalf of the user.

More specifically, the system may comprise a user-controlled display interface equipped with a content filtering layer, wherein unsolicited advertisements or promotional material are suppressed unless explicitly authorized. Authorization may be contingent upon the advertiser's provision of a specified monetary or token-based compensation offer. This offer may be evaluated by a user-configurable agent (e.g., a personal AI assistant), which may assess relevance, ethical compatibility, historical interest, and minimum compensation thresholds prior to granting access to the content.

Upon acceptance of the offer, the marketing content may be rendered on the device, and compensation may be automatically routed to the user, for example via micropayment channels, smart contracts, or digital wallets. Optionally, additional compensation may be awarded upon specific events such as purchases, referrals, or completed viewership. The framework may further include reputation scoring for advertisers, opt-out features, and cryptographic proof of ad exposure to support fraud resistance.

In practice, it is preferred to enable the user to monetize their attention directly, which leads to a reversal of the conventional digital advertising model and, as a result, incentivizes only high-quality and contextually appropriate content. More specifically, the framework described herein produces the effect of user-consensual ad delivery because it places the burden of value demonstration on the advertiser, which results in greater transparency, improved ad targeting, and increased consumer empowerment.

The invention may be realized in hardware, software, or hybrid implementations, and may interoperate with augmented reality platforms, operating systems, browsers, content apps, or custom ad networks built around the disclosed compensation logic.

Here is the full extended enabling disclosure for your invention, titled “Attention Compensation Framework,” incorporating the concept of *aesthetic visual overlays (e.g., nature scenes)* in place of black box ad blocking:

### Enabling Disclosure (Extended Version)

The present invention provides an attention compensation framework for regulating the display of commercial content on user-operated devices. More particularly, the system enables users to control the presentation of marketing materials on digital displays-such as smart glasses, smartphones, computers, or wearable interfaces-by blocking unsolicited advertising unless the advertiser offers compensation that is accepted by or on behalf of the user.

The system operates on the principle that user attention is a valuable, compensable asset. By default, commercial or promotional content is visually suppressed unless a compensation agreement is reached. The invention may comprise three principal components: (1) a display-level content filter, (2) a personal agent module, and (3) a compensation and transaction engine.

### #1. Display-Level Content Filter

The content filter may reside at the operating system, application, browser, or device firmware level. It is configured to detect and intercept advertisements based on various detection methods, including:
Explicit metadata tagging
Known advertising domains or elements
Heuristic or AI-based visual/textual analysis
Behavioral signals (e.g., autoplay banners, sponsored tags)

Upon identification, these advertising elements are prevented from being rendered in their original form unless a valid “unlock signal” is received. This signal indicates that the user or their agent has accepted a compensation offer for viewing the content.

### Visual Blocking Mechanism:

In one embodiment, the ad region may be covered by an opaque black box or neutral placeholder to visually suppress the ad. However, in a preferred embodiment, the system may render a visually pleasing or emotionally positive overlay in place of the blocked advertisement.

Such overlays may include:
Still or animated nature scenes (e.g., forests, waterfalls, clouds)
Abstract visuals, generative art, or soft gradients
User-selected imagery based on mood, theme, or context
Live or rotating content curated for aesthetic enrichment or stress reduction

These overlays are displayed seamlessly in the area otherwise occupied by the ad, creating an emotionally supportive and calming user experience while maintaining ad suppression integrity. The system may dynamically adjust the overlay dimensions and position to match the ad's location and size on screen.

On AR-capable devices, such as smart glasses, the overlay may be projected into the user's field of view, occluding specific physical or virtual ad content without obstructing non-commercial interface elements.

### #2. Personal Agent Module

The personal agent may reside locally on the device or operate in a cloud-assisted configuration. It is responsible for evaluating incoming ad offers and determining whether they meet the user's preferences and thresholds.

Advertisers may submit offers to the system containing:
The content payload (video, image, banner, etc.)
Duration, interaction mode, and rendering parameters
A compensation offer for the user's attention (e.g., €0.20 per view)
Optional bonus incentives (e.g., purchase, click-through, referral)
Ethical or interest tags
Expiration time or usage constraints

The agent evaluates each offer based on:
Minimum compensation thresholds set by the user
Relevance to known preferences, needs, or contexts
Ethical alignment or user-defined rejection filters
Historical user feedback and behavioral training

If an offer is deemed acceptable, the agent sends an unlock signal to the display filter, and the original ad content is revealed to the user in place of the overlay. If rejected, the aesthetic blocking overlay remains.

The agent may also adapt over time via reinforcement learning, tracking which offers are accepted, skipped, converted (e.g., led to purchases), or disliked.

### #3. Compensation and Transaction Engine

This module facilitates real-time compensation to the user upon ad exposure. Payment modalities may include:
Direct transfer to a connected bank, PayPal, or mobile wallet
Deposit into a platform-native “attention wallet”
Smart contract execution on a blockchain-based micropayment protocol
Token-based economies redeemable for goods or services

Verification of exposure may be achieved via:
Timer-based engagement confirmation
Gaze tracking (for smart glasses)
Touch/click interaction with the ad
Dwell-time analysis with fraud prevention heuristics

All engagements may be logged with a cryptographic signature to ensure accountability and enable dispute resolution. This ledger may be user-visible and exportable.

Optional modules may include:
A dashboard showing accumulated earnings, time spent on ads, and impact metrics
A reputation scoring system for advertisers
Community reporting tools for unethical content
Legal and compliance frameworks governing ad standards and user consent

### #Additional Features

The framework may support policy-level exclusions, where users opt out of entire product categories (e.g., gambling, pharmaceuticals) regardless of payout.
Environmental impact metrics or ethical sourcing disclosures may be displayed alongside ad offers, enabling deeper values-based filtering.
Advertisers may be given limited access to user interest profiles, anonymized and governed by agent-controlled protocols, to improve targeting without compromising user privacy.

Here is a set of 10 patent claims for your invention titled “Attention Compensation Framework”, written in suggestive language and modeled in patent style. The claims are structured around the core idea: *users are compensated directly for their attention to advertising content, rather than platforms being paid for access*.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for compensating users for their attention, the system comprising:
   a) detecting the presence of advertising content within a display environment;
   b) blocking access to said content by default;
   c) receiving an offer of compensation from an advertiser or intermediary;
   d) presenting the offer to the user, including terms of attention exchange;
   e) upon user consent, revealing the blocked content; and
   f) distributing compensation to the user in exchange for their attention.
2. The system of item 1, wherein the blocking of advertising content comprises rendering a visual obstruction, such as a black box, nature scene, or artistic overlay, over the advertising region.
3. The system of item 1, wherein compensation may include monetary payment, digital tokens, loyalty points, discounts, or access privileges.
4. The system of item 1, wherein the system determines user attention via gaze tracking, dwell time analysis, click interaction, or biometric feedback.
5. The system of item 1, wherein the compensation offer is dynamically generated based on user profile, historical preferences, inferred relevance, or predicted conversion likelihood.
6. The system of item 1, wherein the system is implemented on a smart glasses interface, mobile device, desktop screen, or embedded display in an augmented reality environment.
7. The system of item 1, wherein users may specify categories or types of advertisements they are willing to engage with, and block others unconditionally.
8. The system of item 1, wherein content is only revealed for a limited time or format specified in the offer, after which it is re-blocked unless renewed.
9. The system of item 1, further comprising a reputation or transparency score associated with each advertiser, which may influence the required compensation or user trust.
10. The system of item 1, wherein user data and attention metrics are retained locally and only shared with advertiser systems upon explicit consent.

### Embodiment ABE: Attention Compensation Framework

A framework is disclosed in which user attention is treated as a compensable asset. Commercial content may be blocked by default on user-operated devices and revealed only upon acceptance of a compensatory offer from an advertiser or intermediary. The system may include a display-level content filter to detect and suppress advertising elements pending authorization, a personal agent module to evaluate offers against user policies and thresholds, and a compensation and transaction engine to verify exposure and settle payouts to the user. The framework may provide aesthetic overlays in place of blocked ads, cryptographic proofs of exposure, privacy-preserving targeting, advertiser reputation scoring, and interoperability with operating systems, browsers, augmented reality runtimes, ad networks, and payment providers. Technical effects may include user-consensual ad delivery, fraud resistance through signed logs and device attestations, and improved relevance via agent-controlled preferences, thereby increasing transparency and consumer empowerment while enabling externally verifiable compliance.

### Gentle Introduction

Most digital experiences present advertisements by default, paying publishers or platforms while giving the user no direct say or share. Users who do not want intrusive ads often install generic blockers that hide everything indiscriminately, which helps with distraction but breaks revenue flows and leaves no way to engage selectively or be compensated when they do choose to pay attention.

This disclosure introduces a simple alternative: the device quietly blocks promotional content first, replacing it with a calming visual. If an advertiser wishes to reach the user, it sends an offer that states what will be shown, for how long, and how much the user will be paid. A user-controlled agent reviews the offer against the user's preferences and minimum price. Only when the offer is acceptable does the device briefly reveal the ad. As the ad is shown, the device records basic, privacy-preserving signals such as time on screen or, where available, gaze presence. These signals allow the system to verify that attention was actually given, after which the user is paid automatically.

Viewed intuitively, this reverses the usual roles. The advertiser must earn access by meeting the user's terms, while the device enforces the deal with on-screen controls, time limits, and signed proof-of-exposure. The user gains transparency and control, the advertiser gains a clear consent path and verifiable delivery, and the overall experience becomes calmer because the default state is an aesthetic overlay instead of an intrusive ad. The same approach applies to phone screens, desktop browsers, and augmented reality glasses, with the user's agent and the device's display filter coordinating unlocks, proofs, and payouts through interoperable interfaces.

### Background

Digital advertising ecosystems traditionally compensate publishers or platforms for access to user attention without compensating the user. This model incentivizes aggressive targeting, intrusive interfaces, and opaque data flows. Users may resort to ad blockers that indiscriminately suppress content, depriving publishers of revenue while providing no structured mechanism for consensual engagement or compensation. The absence of verifiable exposure proofs and standardized payout channels further complicates accountability, produces fraud, and limits interoperable settlement across diverse devices and environments, including augmented reality contexts where physical and virtual content may commingle. A need exists for an architecture that places the user in control, formalizes offer and consent flows, verifies attention using device-level signals, and routes compensation directly to the user under enforceable, privacy-preserving policies.

### Summary

The disclosed framework addresses these needs by default-blocking promotional content at the display layer, evaluating advertiser offers via a user-controlled agent, and settling compensation upon verified attention. The framework may render calming or aesthetic overlays in place of blocked content, issue time-limited unlock tokens upon acceptance, collect signed exposure events including dwell time and optional gaze tracking, and route payments to a user wallet or equivalent account. Interoperability may be achieved through protocol-agnostic interfaces, including MCP-style endpoints for offers and settlements. The result may be a transparent, consent-centric marketplace for attention that is externally observable and resistant to fraud.

### Description of the Drawings

While figures are not required to practice the invention, the disclosure may be illustrated by: a system-level block diagram showing a display-level content filter, a personal agent module, and a compensation and transaction engine connected to payment providers and ad network connectors; process flow diagrams showing detect, block, evaluate, accept or reject, unlock, verify, and settle sequences; and augmented reality views illustrating occlusion overlays aligned to real-world surfaces.

Element naming and relationships in such figures may correspond to those enumerated in the System Element Anchor to ensure consistent interpretation across 2D and AR deployments.

### Detailed Description

The present disclosure relates to systems and methods for controlling the delivery of marketing content to user-operated devices, and more particularly to a framework wherein user attention is treated as a compensable asset. In one embodiment, the invention may provide a mechanism by which commercial content is blocked by default on user interfaces such as smart glasses, head-mounted displays, mobile phones, or computer screens, and only permitted to appear if an advertiser has submitted a compensatory offer accepted by or on behalf of the user.

More specifically, the system may comprise a user-controlled display interface equipped with a content filtering layer, wherein unsolicited advertisements or promotional material are suppressed unless explicitly authorized. Authorization may be contingent upon the advertiser's provision of a specified monetary or token-based compensation offer. This offer may be evaluated by a user-configurable agent (e.g., a personal AI assistant), which may assess relevance, ethical compatibility, historical interest, and minimum compensation thresholds prior to granting access to the content.

Upon acceptance of the offer, the marketing content may be rendered on the device, and compensation may be automatically routed to the user, for example via micropayment channels, smart contracts, or digital wallets. Optionally, additional compensation may be awarded upon specific events such as purchases, referrals, or completed viewership. The framework may further include reputation scoring for advertisers, opt-out features, and cryptographic proof of ad exposure to support fraud resistance.

In practice, it is preferred to enable the user to monetize their attention directly, which leads to a reversal of the conventional digital advertising model and, as a result, incentivizes only high-quality and contextually appropriate content. More specifically, the framework described herein produces the effect of user-consensual ad delivery because it places the burden of value demonstration on the advertiser, which results in greater transparency, improved ad targeting, and increased consumer empowerment.

The invention may be realized in hardware, software, or hybrid implementations, and may interoperate with augmented reality platforms, operating systems, browsers, content apps, or custom ad networks built around the disclosed compensation logic.

### Technical Effects

The framework may deliver concrete technical effects across client, network, and settlement layers that are realized by different embodiments. In client-side 2D browser embodiments, default suppression of promotional payloads at the display filter may reduce decoding, layout, and compositing work until an unlock is granted, which can improve frame stability, reduce jank, and conserve battery by avoiding unnecessary media decode and network prefetch. Aesthetic overlays may further stabilize rendering by substituting simple, bounded visuals for complex third-party scripts until a signed unlock is received.

In augmented reality embodiments, occlusion overlays aligned to detected surfaces may prevent the rendering of promotional textures or layers until an unlock token with pose constraints is validated.

This gating may ensure that reveal occurs only within a bounded 3D region and for a defined duration, reducing visual clutter and preventing accidental occlusion of non-commercial UI. Gaze-threshold rules tied to AR unlocks may yield higher-confidence attention measurements with reduced false positives, thereby improving the robustness of exposure verification.

In server-side or proxy stream-splicing embodiments, withholding or substituting promotional segments until an authorization is received may reduce downstream bandwidth and CPU consumption on clients that would otherwise fetch and decode unwanted ads. Time-limited unlock authorizations may trigger deterministic reinsertion of ad segments followed by automatic re-blocking at expiry, yielding predictable state transitions that support reliable method flows and externally auditable behavior.

In audio-only or notification-surface embodiments, intercepting and gating promotional utterances may reduce unwanted audio playback and power usage associated with audio decode and wake events. Unlock-controlled reveal may improve user-perceived latency consistency by eliminating bursty, unsolicited notifications.

Across embodiments, cryptographically signed exposure logs and optional device attestations may produce fraud-resistance by enabling third parties to validate that reveal occurred within authorized intervals and contexts. Escrow or hold-before-render mechanisms may reduce non-payment risk and discourage impression laundering by requiring value reservation prior to reveal. Privacy guards that confine interest profiles to secure enclaves or anonymized aggregates may reduce data exfiltration risk and attack surface while still enabling relevance scoring by the personal agent.

In pooled-subscription settlement modes, batching verified attention units and emitting signed digests may lower transaction overhead and enable reproducible damages calculations. Protocol-agnostic interfaces, including MCP-style offer and settlement endpoints, may allow the same detect-block-unlock-verify-settle flow to operate across operating systems, browsers, AR runtimes, and ad network APIs, thereby improving portability and reducing integration friction. Collectively, these effects may yield measurable improvements in system performance, energy consumption, privacy protection, fraud resistance, external verifiability, and user experience quality.

In practice it is preferred to implement the Attention Compensation system to block or suppress advertisements at the device or network level, which leads to reduced transmission of media files associated with advertising. As a result, total internet traffic is lowered, page loads are accelerated, and redundant consumption of bandwidth is prevented. More specifically, the system produces the effect of reducing processor cycles, memory usage, and storage overhead otherwise required for decoding and rendering advertisements, which results in improved responsiveness and lower energy consumption at both client and server sides. These constitute measurable technical effects that improve system efficiency. Since reduced traffic and computation correlate directly with energy use, the invention also indirectly yields a lower carbon footprint while primarily improving bandwidth efficiency, device responsiveness, and overall system resource utilization.

### Court-Robustness and Eligibility Support

To aid claim construction, subject-matter eligibility, and evidentiary showings, the disclosure specifies computer-specific mechanisms and externally verifiable behaviors that may improve the functioning of computing devices rather than reciting business logic in the abstract. The following implementation pathways exemplify concrete technical operations that map to the claimed detect-block-unlock-verify-settle flow without narrowing the claims.

At the display/compositor layer, a filter may hook or interpose on composition primitives such as Android SurfaceFlinger layers, iOS/macOS CoreAnimation layers, Windows DirectComposition visuals, or Linux Wayland/Weston surfaces, and may substitute an overlay surface for identified promotional layers until a time-limited unlock token is validated. This substitution may reduce rasterization and shader work by preventing upload and blending of third-party textures, and may enforce automatic re-blocking by removing or demoting the ad layer on token expiry.

At the media/streaming layer, a network proxy or server-side splicer may operate on adaptive streaming manifests such as HLS or DASH by removing or replacing ad segments and SCTE-35-marked intervals, reinserting them only upon unlock and reverting the manifest at expiry.

This may avoid segment downloads and decoder wakeups prior to consent, reducing bandwidth and CPU. Unlock metadata may be conveyed as playlist markers, DRM licenses, or HTTP headers that the client or proxy validates.

For secure measurement and fraud resistance, exposure events may be signed using device-backed keys resident in trusted execution environments such as Android Keystore/StrongBox, iOS Secure Enclave, or TPM-backed keys on desktop. Optional remote attestation signals (e.g., Android Play Integrity API or WebAuthn/CTAP attestation) may bind keys to device state. Logs may be encoded using JOSE or COSE structures and hash-chained daily, with digests co-signed by a settlement service to provide immutable summaries.

Deterministic state transitions may be enforced by a finite-state machine implemented at the filter or proxy boundary with explicit states Blocked, Offered, Authorized, Rendering, Verified, Settled, and Re-blocked, and with transitions triggered exclusively by signed inputs and timeouts. This determinism may enable reproducible test vectors and black-box verification.

Objective performance and energy effects may be demonstrated by measuring frame time variance, dropped frames, decode time, and network bytes using platform profilers such as Android systrace, Chrome Performance APIs, Windows ETW, or Apple Instruments, before and after default suppression. Representative improvements may include reduced media decode invocations and fewer compositor layer blends while blocked.

Externally observable artifacts suitable for infringement analysis may include consistent default suppression of promotional units, acceptance of time-bounded unlocks tied to specific payloads, escrow or value reservation prior to reveal, cryptographically signed exposure events with device attestations, and automatic re-blocking at expiry. Because these artifacts are visible at network, UI, and ledger boundaries, they may be detected without access to internal source code.

These concrete implementation details may support statutory subject-matter eligibility by tying the claimed flows to improvements in computer functionality and resource usage, and may strengthen evidentiary showings by defining testable behaviors and signed records consistent with the claims.

### Scope and Interpretive Guidance

Unless expressly stated otherwise, the scope of this disclosure is limited only by the claims. The figures, anchors, data formats, and examples are illustrative embodiments. Steps in described flows may be reordered, performed in parallel, omitted, or supplemented by equivalent steps without departing from the claimed subject matter. Hardware, software, and protocol choices are exemplary and interchangeable; references to specific platforms, standards, or MCP-style endpoints are non-limiting examples. Element labels and any numbering are for convenience and do not imply ordering, essentiality, or exclusivity.

For interpretive clarity, terms such as advertising content, offer, unlock signal, compensation, consent, and revealing should be understood to encompass functionally equivalent mechanisms, including client-side, server-side, network-proxy, or compositor-level implementations; value transfer by monetary or non-monetary consideration; consent obtained directly from the user or via an agent configured with user policy; and gating of presentation via tokens, capability flags, headers, DRM licenses, playlist markers, or other authorizations that achieve default blocking followed by consent-gated reveal.

### System Element Anchor

The following anchor enumerates core elements and their relationships so that the embodiments can be understood consistently across implementations. It may be interpreted as the element list that would be common to multiple figures showing 2D and AR deployments.

### Core Entities:

User; device owner or operator.
Device; smartphone, desktop/laptop, smart glasses, head-mounted display, or wearable.
Display environment; 2D screen regions and AR/HUD field-of-view surfaces.
Advertiser or intermediary; offer originator submitting compensation proposals.

### Display-Level Content Filter:

Ad detectors; metadata rules, known domains/element lists, heuristic or AI visual/text analysis, behavioral signals such as autoplay or sponsored tags.
Overlay renderer; black box, nature scene, artistic or generative visuals sized to ad region; AR occlusion projector aligned to surfaces in physical space.
Unlock signal interface; verifier for signed tokens or capability grants authorizing payload, duration, and rendering parameters.
Re-blocking controller; restores overlay upon expiry or rejection.

### Personal Agent Module:

Offer intake API; MCP-compatible or protocol-agnostic endpoint receiving ad offer objects and constraints.
Policy and preference store; minimum compensation thresholds, ethics filters, category exclusions, interest profiles.
Evaluator; relevance scoring, ethical compatibility checks, historical feedback use, and reinforcement learning adaptation.
Signer/authorizer; generation of unlock tokens with time-to-live and optional AR pose constraints.
Privacy guard; anonymization, differential privacy or secure enclave usage to limit advertiser access to interest profiles.

### Compensation and Transaction Engine:

Wallet interfaces; bank transfer, mobile wallet, platform-native attention wallet, blockchain smart contracts.
Escrow/hold mechanism; funds reservation prior to rendering and settlement after verification.
Proof verifier; timers, dwell-time analysis, gaze tracking where available, click/touch verification, fraud heuristics.
Settlement calculator; base payout plus bonuses for purchase, referral, or click-through events under specified windows.
Cryptographic ledger; signed exposure logs, device attestations, exportable user-visible records, dispute resolution support.

### Data Artifacts and Messages:

Offer payload; ad_offer with payload_uri, compensation terms, bonuses, constraints, ethics and interest tags, rendering hints, expiration.
Unlock token; unlock authorization with ttl_seconds, render_params or AR pose constraints, signatures.
Exposure event; signed log including timestamps, dwell_seconds, attention_confidence, device attestation.
Reputation score; advertiser trust metrics impacting acceptance thresholds.
Policy profiles; user or guardian-configured exclusions and compensation minima.

### Signals and Relationships:

Detect→Block/Overlay→Offer receipt by agent→Evaluation against policy→Accept/Reject decision.
Accept path; agent issues unlock token→filter reveals ad→attention proof collection→compensation settlement→cryptographic logging→model and reputation updates.
Reject path; overlay persists, optional negative feedback to reputation store.
AR path; unlock token may include pose boxes and attention rules such as gaze percentage and minimum seconds.

### System States:

Blocked (default), Offered (pending evaluation), Authorized (unlock active), Rendering (ad revealed), Verified (attention proved), Settled (payout completed), Re-blocked (post-expiry or completion).

### Security, Privacy, and Trust Boundaries:

Signed tokens and logs; device attestation where available.
Local retention of user data; sharing only upon explicit consent via agent-controlled protocols.

### Interoperability Surfaces:

OS, browser, and application hooks; AR runtimes for occlusion; ad network connectors; payment provider integrations; MCP or equivalent protocol endpoints; protocol-agnostic adapters to mitigate interface-based workarounds.

### Optional Modules:

Earnings dashboard; community reporting tools; environmental/ethical disclosures; advertiser reputation services; subscription or pooled settlement modes.

### Externally Observable Artifacts Enabling Verification:

Received offers, issued unlock tokens, and signed exposure logs with verifiable signatures and timestamps.

### Enabling Disclosure (Extended Version)

The present invention provides an attention compensation framework for regulating the display of commercial content on user-operated devices. More particularly, the system enables users to control the presentation of marketing materials on digital displays-such as smart glasses, smartphones, computers, or wearable interfaces-by blocking unsolicited advertising unless the advertiser offers compensation that is accepted by or on behalf of the user.

The system operates on the principle that user attention is a valuable, compensable asset. By default, commercial or promotional content is visually suppressed unless a compensation agreement is reached. The invention may comprise three principal components: (1) a display-level content filter, (2) a personal agent module, and (3) a compensation and transaction engine.

### #1. Display-Level Content Filter

The content filter may reside at the operating system, application, browser, or device firmware level. It is configured to detect and intercept advertisements based on various detection methods, including explicit metadata tagging, known advertising domains or elements, heuristic or AI-based visual and textual analysis, and behavioral signals such as autoplay banners or sponsored tags. Upon identification, these advertising elements are prevented from being rendered in their original form unless a valid unlock signal is received. This signal indicates that the user or their agent has accepted a compensation offer for viewing the content.

### Visual Blocking Mechanism:

In one embodiment, the ad region may be covered by an opaque black box or neutral placeholder to visually suppress the ad. However, in a preferred embodiment, the system may render a visually pleasing or emotionally positive overlay in place of the blocked advertisement. Such overlays may include still or animated nature scenes such as forests, waterfalls, or clouds; abstract visuals, generative art, or soft gradients; user-selected imagery based on mood, theme, or context; and live or rotating content curated for aesthetic enrichment or stress reduction. These overlays are displayed seamlessly in the area otherwise occupied by the ad, creating an emotionally supportive and calming user experience while maintaining ad suppression integrity. The system may dynamically adjust the overlay dimensions and position to match the ad's location and size on screen. On AR-capable devices, such as smart glasses, the overlay may be projected into the user's field of view, occluding specific physical or virtual ad content without obstructing non-commercial interface elements.

### #2. Personal Agent Module

The personal agent may reside locally on the device or operate in a cloud-assisted configuration. It is responsible for evaluating incoming ad offers and determining whether they meet the user's preferences and thresholds. Advertisers may submit offers to the system containing a content payload such as video, image, or banner assets, a duration, interaction mode, and rendering parameters, a compensation offer for the user's attention such as €0.20 per view, optional bonus incentives such as purchase, click-through, or referral rewards, ethical or interest tags, and an expiration time or usage constraints. The agent evaluates each offer based on minimum compensation thresholds set by the user, relevance to known preferences, needs, or contexts, ethical alignment or user-defined rejection filters, and historical user feedback and behavioral training. If an offer is deemed acceptable, the agent sends an unlock signal to the display filter, and the original ad content is revealed to the user in place of the overlay. If rejected, the aesthetic blocking overlay remains. The agent may also adapt overtime via reinforcement learning, tracking which offers are accepted, skipped, converted (e.g., led to purchases), or disliked.

### #3. Compensation and Transaction Engine

This module facilitates real-time compensation to the user upon ad exposure. Payment modalities may include direct transfer to a connected bank, PayPal, or mobile wallet, deposit into a platform-native attention wallet, smart contract execution on a blockchain-based micropayment protocol, or token-based economies redeemable for goods or services. Verification of exposure may be achieved via timer-based engagement confirmation, gaze tracking for smart glasses where available, touch or click interaction with the ad, and dwell-time analysis combined with fraud prevention heuristics. All engagements may be logged with a cryptographic signature to ensure accountability and enable dispute resolution. This ledger may be user-visible and exportable. Optional modules may include a dashboard showing accumulated earnings, time spent on ads, and impact metrics, a reputation scoring system for advertisers, community reporting tools for unethical content, and legal and compliance frameworks governing ad standards and user consent.

### #Additional Features

The framework may support policy-level exclusions where users opt out of entire product categories such as gambling or pharmaceuticals regardless of payout. Environmental impact metrics or ethical sourcing disclosures may be displayed alongside ad offers, enabling deeper values-based filtering. Advertisers may be given limited access to user interest profiles, anonymized and governed by agent-controlled protocols, to improve targeting without compromising user privacy.

### #Implementation Steps and MCP Integration

A representative 2D browser embodiment may be implemented as follows. First, integrate a display-level content filter that intercepts identified advertising layers prior to painting or compositing. On Chromium-based browsers this may be achieved by matching ad slots in the DOM and CSSOM and substituting a lightweight overlay element with fixed bounds while preventing media decode for the underlying resource until an unlock is validated. Second, implement an agent-side offer intake interface that may expose MCP-style endpoints including mcp://offers.submit for receiving offers, mcp://agent.evaluate for policy evaluation, mcp://agent.unlock.request for requesting unlock tokens from the signer, mcp://escrow.reserve for value reservation, mcp://exposure.report for posting signed exposure events, and mcp://settlement.close for final settlement. Third, implement the personal agent evaluator that loads user policy and thresholds, scores each ad_offer against relevance and ethics tags, and when acceptable, requests an unlock token from a device-resident signer bound to a trusted execution environment. The unlock may be encoded as a JOSE or COSE object that includes ad_id, offer_id, ttl_seconds, and render_params and is signed using a device-backed key. Fourth, modify the content filter to validate unlock signatures and TTL before revealing the ad region, with a countdown timer that triggers automatic re-blocking at expiry. Fifth, collect exposure measurements such as start and end timestamps and dwell_seconds and, where available, attention_confidence derived from gaze signals. Sixth, sign exposure events using the same device-backed key, hash-chain them locally, and submit summaries via mcp://exposure.report; the settlement service may co-sign daily digests and release escrowed funds via mcp://settlement.close. Seventh, ensure privacy by retaining raw user profiles locally and sharing only anonymized aggregates or necessary hashes under agent-controlled policy.

Compact, implementation-ready JSON structures suitable for MCP or equivalent interfaces may include minimal ad offer, unlock, and exposure event objects. A minimal ad offer may be expressed as

{“type”:“ad_offer”,“offer_id”:“ofr-min-1”,“advertiser_id”:“adv-1”,“ad_id”:“ad-1”,“payload_uri”:“https
://cdn.example/ad-1.mp4”,“compensation”:{“amount”:0.20,“currency”:“EUR”,“mode”:“per_view”},“c
onstraints”:{“min_view_seconds”:6,“expire_at”:“2026-12-31T23:59:59Z”},“tags”:{“ethics”:[“no_gam
bling”],“interests”:[“outdoor”]}}. A corresponding unlock token may be
{“type”:“unlock”,“unlock_token”:“uln-min-1”,“offer_id”:“ofr-min-1”,“ad_id”:“ad-1”,“ttl_seconds”:20,
“render_params”:{“sound”:“muted_start”},“signature”:“base64sigU==”} and a minimal exposure
event may be
{“event”:“exposure”,“offer_id”:“ofr-min-1”,“ad_id”:“ad-1”,“start”:“2026-01-05T12:00:00Z”,“end”:“2
026-01-05T12:00:12Z”,“dwell_seconds”:12,“attention_confidence”:0.80,“device_attestation”:“att-b64
”,“signature”:“base64sigE==”}.

For AR embodiments, additional implementation steps may include deriving pose-constrained unlock parameters based on detected surface geometry and enforcing reveal only within a 3D bounding volume. The agent may require attention rules such as minimum gaze percentage for a minimum number of seconds. A pose-constrained unlock may be

{“type”:“unlock”,“unlock_token”:“uln-ar-min-1”,“ad_id”:“ad-ar-1”,“ttl_seconds”:30,“ar”:{“pose_box”
:[[0.0,1.0,3.0],[0.5,1.5,3.6]],“surface_normal”:[0,0,−1]},“attention_rule”:{“gaze_pct_min”:0.6,“min_se
conds”:5},“signature”:“base64sigAR==”}.

These concrete steps and data structures may enable a skilled person to implement compliant embodiments without undue experimentation while maintaining interoperability through MCP-style endpoints or equivalent protocol adapters.

### Fallback Embodiments

Simpler or partial implementations may embody the inventive concept without the full set of modules or signals. In a minimal browser-extension embodiment operating only in 2D environments, the display-level content filter may rely solely on domain lists and sponsored-tag heuristics to block ad regions, the personal agent may be replaced by a user-operated consent dialog that presents offer text and a single accept or reject control, and attention verification may use a fixed timer and slot visibility checks without gaze tracking. In this embodiment, unlock authorization may be represented by a short-lived locally generated token scoped to a single page session, exposure events may be recorded to a local append-only log file, and settlement may occur as a batched monthly statement credit or wallet transfer rather than real-time micropayments.

In another fallback embodiment for constrained devices or intermittent connectivity, offers may be delivered via simple HTTP POST endpoints with compact JSON rather than MCP, proofs may be queued locally with rolling hash chaining to provide tamper-evidence until connectivity resumes, and device attestation may be omitted in favor of checksum-based integrity signaling. A publisher-integrated embodiment may present first-party offers embedded in page markup or HTTP headers, with the same default-block and consent-gated reveal behavior enforced by the filter, and with pooled or pre-funded balances used to satisfy payouts without per-impression invoicing. An enterprise or kiosk mode may disable adaptive learning, enforce administrator-defined policy profiles, and route aggregated earnings to an organizational account, while still maintaining the default-blocking, offer evaluation, consented reveal, and post-exposure settlement sequence that characterizes the framework.

### Examples

The following concrete examples illustrate step-by-step operation of the framework in representative contexts. Each example shows observable inputs and outputs and includes compact JSON snippets suitable for use with a Model Context Protocol (MCP) tool interface or equivalent offer/settlement APIs.

Example 1: Mobile browser with aesthetic overlays. A user browses a news site on a smartphone. The display-level content filter detects an advertising iframe via domain heuristics and sponsored tags. The ad region is immediately covered with a nature scene overlay sized to the detected slot. The advertiser submits an offer through an MCP-compatible endpoint exposed by the personal agent. The agent evaluates compensation, ethics tags, and relevance, finds the offer acceptable, and issues an unlock signal authorizing timed rendering. The compensation and transaction engine escrows the payout, verifies exposure via dwell time, and settles to the user wallet upon completion. Representative MCP offer payload:

{“type”:“ad_offer”,“offer_id”:“ofr-7f1”,“advertiser_id”:“adv-112”,“ad_id”:“ad-349”,“payload_uri”:“htt
ps://cdn.example.com/ad-349.mp4”,“compensation”:{“amount”:0.25,“currency”:“EUR”,“mode”:“per_{—}
view”},“bonuses”:[{“type”:“purchase”,“amount”:1.50,“currency”:“EUR”,“window_hours”:48}],“const
raints”:{“min_view_seconds”:6,“max_duration_seconds”:15,“expire_at”:“2026-01-31T23:59:59Z”},“
ethics”:[“no_gambling”,“no_medical”],“interests”:[“running_shoes”,“outdoor”],“rendering”:{“placem
ent_hint”:“slot-3”,“sound”:“muted_start”}}. If accepted,the agent returns an unlock token to the filter:
{“type”:“unlock”,“unlock_token”:“uln-92a”,“ad_id”:“ad-349”,“ttl_seconds”:20,“render_params”:{“so
und”:“on_after_3s”},“signature”:“base64sigA==”}. Upon exposure completion, a signed event is
logged:
{“event”:“exposure”,“ad_id”:“ad-349”,“offer_id”:“ofr-7f1”,“user_id_hash”:“H:u1e3...”,“start”:“2026-0
1-05T12:03:01Z”,“end”:“2026-01-05T12:03:18Z”,“dwell_seconds”:17,“attention_confidence”:0.93,“d
evice_attestation”:“att-b64”,“signature”:“base64sigB==”}.

Example 2: AR smart glasses with geofenced billboard occlusion. A user wearing smart glasses walks past a physical billboard. The AR runtime classifies the billboard as promotional content and the overlay subsystem occludes it with a floating cloud animation aligned to the physical surface. An advertiser issues a location-triggered offer via MCP to the agent, proposing a higher payout for verified gaze engagement. The agent enforces the user's exclusion list and minimum price, then accepts. The unlock token includes an AR pose constraint to ensure rendering only within the billboard bounds and for a fixed duration. Gaze tracking provides attention proofs above a predefined threshold, after which the compensation and transaction engine settles a base payout and records eligibility for a referral bonus if a tagged QR or link is later used. Example unlock with AR constraints:

{“type”:“unlock”,“unlock_token”:“uln-ar-221”,“ad_id”:“ad-ar-12”,“ttl_seconds”:30,“ar”:{“pose_box”:
[0.1,1.2,3.4],[0.6,1.5,3.8],“surface_normal”:[0,−1,0]},“attention_rule”:{“gaze_pct_min”:0.7,“min_se
conds”:5},“signature”:“base64sigC==”}.

Example 3: Policy-first child profile and subscription crossover. On a shared tablet with a child profile, policy-level exclusions reject entire categories regardless of payout. Offers that pass policy are still filtered by a higher minimum compensation threshold configured by the guardian. The platform operates in a subscription mode in which certain premium content providers pre-fund a monthly pool that the transaction engine uses to satisfy attention payouts without per-impression invoicing. The same MCP interface is used, but offers carry a pooled flag and a provider_id for settlement routing. Example pooled offer header:

{“type”:“ad_offer”,“offer_id”:“ofr-pool-9”,“provider_id”:“prov-77”,“pooled”:true,“compensation”:{“a
mount”:0.12,“currency”:“USD”,“mode”:“per_view”}}.

These examples demonstrate interoperable offer exchange via MCP or equivalent protocols, explicit unlock authorization, verifiable attention proofs, and externally observable artifacts including offers, unlock tokens, and signed exposure logs.

### Monetization and Damages Maximization

The framework may include monetization mechanisms and technical features that support subscription-model usage and increase potential infringement compensation through measurable, auditable usage-based value capture. In one mode, premium content providers may pre-fund a pooled subscription balance against which verified attention events are debited pro rata by attention quality tiers such as dwell_seconds, gaze_weighted_seconds, or interaction-weighted units. The compensation and transaction engine may enforce minimum monthly guarantees, carry-forward of unused balances, and dynamic rate cards by geography, device class, or category. Settlement artifacts may be cryptographically signed and exportable to provide clear damages evidence including unit counts, applicable rates, and payout totals. Representative monthly settlement report:

{“type”:“settlement_report”,“period”:“2026-01”,“pool_id”:“pool-123”,“provider_id”:“prov-77”,“units”
:{“dwell_seconds”:124355,“gaze_weighted_seconds”:98322},“rate_card”:{“dwell_seconds”:{“EUR_{—}
per_1000”:0.90},“gaze_weighted_seconds”:{“EUR_per_1000”:1.80}},“gross”:{“amount”:347.12,“cur
rency”:“EUR”},“fees”:{“network”:7.50,“currency”:“EUR”},“net_payout”:{“amount”:339.62,“currenc
y”:“EUR”},“signatures”:[“base64sigR1==”,“base64sigR2==”]}.

Enterprise and publisher integrations may operate on seat-based or device-based subscriptions that unlock the personal agent module's evaluation capabilities, with usage metering tied to externally observable artifacts such as unlock tokens issued and exposure events verified. The engine may support tiered subscription plans that include priority offer routing, higher escrow concurrency, and advanced fraud analytics. Offers and settlements may be transacted via MCP-compatible endpoints including mcp://offers.submit, mcp://escrow.reserve, mcp://exposure.report, and mcp://settlement.close, enabling standardized reporting suitable for damages calculations.

The system may further support conversion-linked revenue sharing and purchase attribution windows with configurable bonus schedules that are technically enforced by signed conversion receipts and time-window validators. Example conversion receipt:

{“type”:“conversion_receipt”,“offer_id”:“ofr-7f1”,“ad_id”:“ad-349”,“conversion_id”:“cv-9988”,“ts”:“
2026-01-06T10:22:11Z”,“amount”:{“currency”:“EUR”,“value”:89.00},“attribution”:{“window_hours”
:48,“rule”:“last_touch”},“signature”:“base64sigCR==”}.

To strengthen damages evidence, the cryptographic ledger may emit immutable, hash-chained daily digests that summarize offers received, unlocks issued, exposures verified, conversions attributed, and payouts settled, each with device attestations where available. Example digest header:

{“type”:“daily_digest”,“date”:“2026-01-05”,“hash_prev”:“h:abc...”,“hash_curr”:“h:def...”,“counts”:{“o
ffers”:10234,“unlocks”:4311,“exposures”:3988,“conversions”:221,“settlements”:97},“signature”:“base
64sigDG==”}.

These monetization features may enable calculation of lost profits, reasonable royalty rates, and price erosion by associating attention units, quality tiers, and accepted rates to concrete settlement streams, while the externally observable artifacts allow independent verification without access to internal source code or private data.

### Interoperability and Anti-Workaround Coverage

The framework is designed so that interface or implementation changes do not avoid infringement when the core behaviors are present. Advertising content may include any promotional message, sponsored result, embedded sponsorship, influencer read, product placement, audio announcement, notification, or other solicitations rendered in visual, auditory, or mixed modalities. Default blocking and consent-gated reveal may be enforced at a client display layer, a compositor, an operating system notification framework, an application SDK, a network proxy, or a server-side stream splicer that withholds or occludes promotional segments until an unlock condition is met. Unlock signals may take the form of signed tokens, capability flags, HTTP headers, DRM licenses, playlist markers, or equivalent authorizations that cause a previously blocked promotional unit to be revealed for a defined interval or format, followed by automatic re-blocking on expiry. Compensation may include monetary payments, discounts, coupons, loyalty points, credits, or access privileges, and consent may be obtained directly from the user or via a policy-configured agent without mandatory on-screen presentation of full offer text.

External observability enables detection of infringement irrespective of internal architectures. Externally detectable behaviors may include the consistent default suppression of promotional units until receipt of time-limited unlocks, issuance or acceptance of unlock authorizations tied to particular payloads, escrow or reservation of value prior to reveal, cryptographically signed exposure events or summaries, and re-blocking on expiry. Protocol-agnostic adapters may translate between differing platform interfaces such that changes to proprietary APIs do not circumvent the default-block and consent-gated reveal sequence with post-exposure settlement.

### Continuation-Ready Itemized Features

Embodiments can be described by the following itemized list. Items may be combined unless technically incompatible. Entries corresponding to the present claims are included to preserve direct support for future continuations.
A system that detects advertising content within a display environment, blocks the content by default, receives an offer of compensation, presents the offer and its terms to the user, reveals the content upon consent, and distributes compensation in exchange for attention.
Blocking that comprises rendering a visual obstruction over an advertising region, including a black box, nature scene, or artistic overlay.
Compensation that may include monetary payment, digital tokens, loyalty points, discounts, or access privileges.
Attention determination via gaze tracking, dwell-time analysis, click or touch interaction, or biometric feedback.
Dynamic generation of compensation offers based on user profile, historical preferences, inferred relevance, or predicted conversion likelihood.
Implementation on smart glasses, mobile devices, desktop screens, or embedded displays in augmented reality environments.
User-specified acceptance categories for advertisements, with unconditional blocking of other categories.
Time- or format-limited content revelation with automatic re-blocking unless renewed by a subsequent offer.
Advertiser reputation or transparency scoring that may influence required compensation or trust.
Local retention of user data and attention metrics with sharing only upon explicit consent.
A display-level content filter integrated at OS, browser, application, or firmware levels to intercept and suppress ad elements pending an unlock signal.
A personal agent module that evaluates offers against user thresholds, ethical filters, contextual relevance, and historical feedback, and that may adapt via reinforcement learning.
A compensation and transaction engine that supports real-time payouts via bank transfer, mobile wallet, platform-native attention wallet, or blockchain smart contracts with micropayments.
Cryptographic logging of ad exposure events including timestamps, device attestations, gaze or interaction proofs, and signatures to enable fraud resistance and dispute resolution.
Unlock signals that may be represented as signed tokens or capability grants authorizing a specific ad payload, duration, and rendering parameters.
Aesthetic overlay libraries comprising curated or generative content, with dynamic sizing to match intercepted ad regions and with AR occlusion that avoids non-commercial UI elements.
Policy-level exclusions and values-based filters including ethical sourcing disclosures and environmental impact metrics accompanying offers.
Privacy-preserving targeting in which advertiser access to user interest profiles is anonymized and limited by agent-controlled protocols, optionally using differential privacy or secure enclaves.
Bonus incentives such as purchase, referral, or click-through rewards with verifiable conversion tracking and settlement rules.
Interoperability with operating systems, browsers, AR runtimes, and ad network APIs, with protocol-agnostic interfaces to avoid lock-in and interface-based workarounds.
A method of compensating users for attention comprising detecting advertising content within a display environment, blocking access by default, receiving compensation offers, presenting offers, obtaining consent, revealing content, and distributing compensation.
A non-transitory computer-readable medium storing instructions that when executed cause a device to perform the method of compensating users for attention described herein.
An apparatus comprising processors and memory configured to execute a display-level content filter, a personal agent module, and a compensation and transaction engine to operate according to the attention compensation framework described herein.
A network-proxy or server-side stream-splicing implementation that defaults to occluding or withholding promotional segments and reveals them only upon receipt of an unlock authorization, followed by re-blocking at expiry.
Audio-only, notification, or voice-assistant surfaces in which promotional utterances are default-suppressed and revealed under the same consent-gated and compensated scheme.
Offers that are pre-negotiated via subscription, enterprise, or parental policy such that a user-configured agent auto-consents within defined thresholds without on-screen presentation of full terms.
Functionally equivalent unlock signals comprising capability flags, HTTP response headers, DRM licenses, playlist markers, or other authorizations that map to time-limited reveal parameters.
In-stream sponsorships or product placements in video or AR scenes where occlusion, time-skipping, or overlay substitution is applied until consent is obtained, after which the original promotional content is revealed for a bounded interval.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for compensating users for their attention, the system comprising:
   a) detecting the presence of advertising content within a display environment;
   b) blocking access to said content by default;
   c) receiving an offer of compensation from an advertiser or intermediary;
   d) obtaining consent from the user or a user-configured agent based on the offer and its terms of attention exchange;
   e) upon consent, revealing the blocked content; and
   f) distributing compensation to the user in exchange for their attention.
2. The system of item 1, wherein the blocking of advertising content comprises rendering a visual obstruction, such as a black box, nature scene, or artistic overlay, over the advertising region.
3. The system of item 1, wherein compensation may include monetary payment, digital tokens, loyalty points, discounts, or access privileges.
4. The system of item 1, wherein the system determines user attention via gaze tracking, dwell time analysis, click interaction, or biometric feedback.
5. The system of item 1, wherein the compensation offer is dynamically generated based on user profile, historical preferences, inferred relevance, or predicted conversion likelihood.
6. The system of item 1, wherein the system is implemented on a smart glasses interface, mobile device, desktop screen, or embedded display in an augmented reality environment.
7. The system of item 1, wherein users may specify categories or types of advertisements they are willing to engage with, and block others unconditionally.
8. The system of item 1, wherein content is only revealed for a limited time or format specified in the offer, after which it is re-blocked unless renewed.
9. The system of item 1, further comprising a reputation or transparency score associated with each advertiser, which may influence the required compensation or user trust.
10. The system of item 1, wherein user data and attention metrics are retained locally and only shared with advertiser systems upon explicit consent.
11. A method for compensating users for their attention, the method comprising:
   a) detecting the presence of advertising content within a display environment;
   b) blocking access to said content by default;
   c) receiving an offer of compensation from an advertiser or intermediary;
   d) obtaining consent from the user or a user-configured agent based on the offer and its terms of attention exchange;
   e) upon consent, revealing the blocked content; and
   f) distributing compensation to the user in exchange for their attention.
12. The method of item 11, wherein blocking comprises rendering a visual obstruction over an advertising region, including a black box, nature scene, or artistic overlay.
13. The method of item 11, further comprising cryptographically logging ad exposure events including timestamps, device attestations, gaze or interaction proofs, and signatures to support fraud resistance and dispute resolution.
14. A non-transitory computer-readable medium storing instructions that, when executed by one or more processors, cause a device to perform the method of item 11.
15. An apparatus comprising at least one processor and memory storing instructions that, when executed, cause the apparatus to:
   a) execute a display-level content filter configured to intercept advertising elements pending an unlock signal;
   b) execute a personal agent module configured to evaluate compensation offers against user thresholds, ethical filters, and contextual relevance; and
   c) execute a compensation and transaction engine configured to settle payouts to a user responsive to verified ad exposure.
16. The system of item 1, wherein an unlock signal is represented as a signed token or capability grant authorizing a specific ad payload, duration, and rendering parameters.
17. The system of item 1, further comprising cryptographic logging of ad exposure events including timestamps, device attestations, gaze or interaction proofs, and signatures.
18. The system of item 1, wherein advertiser access to user interest profiles is anonymized and limited by agent-controlled protocols, optionally using differential privacy or secure enclaves.
19. The system of item 1, wherein the system enforces policy-level exclusions that cause unconditional blocking of specified categories regardless of compensation.
20. The system of item 1, wherein interoperability with operating systems, browsers, augmented reality runtimes, and ad network APIs is provided via protocol-agnostic interfaces that mitigate interface-based workarounds.

### Embodiment AC: Implied Truth Correction System

The present invention may relate to systems and methods that could enhance a user's interpretative autonomy while engaging with visual media, particularly in contexts where advertisements, product packaging, digital promotions, or political messaging may include implicit claims or emotionally persuasive imagery. In some embodiments, the invention may employ artificial intelligence to detect, evaluate, and optionally correct misleading implications conveyed through non-explicit content structures, such as selective framing, stylized representation, omission of relevant data, or aspirational symbolism.

In current media environments, visual content-especially advertisements-may be structured in a way that suggests desirable outcomes, positive traits, or social approval without making explicit factual statements. These implicit suggestions may influence the viewer's perception and decision-making while remaining outside the scope of traditional regulatory definitions of deception.

For example, a visual sequence showing energetic, smiling individuals consuming a particular food product may imply improved vitality or emotional well-being, even where no scientific basis exists for such an association. Overtime, this may contribute to systemic distortions in consumer understanding, public health behavior, or democratic decision-making.

To address such risks, the proposed system-herein referred to as the Implied Truth Correction System-may operate on a user-facing device such as smart glasses, augmented reality headsets, smartphones, or smart television displays. The system may include a visual monitoring module capable of capturing content as experienced by the user in real time. Using one or more language-vision models or pattern-recognition algorithms, the system may analyze the content to infer latent or implied messages, which may include health implications, future outcomes, emotional states, or lifestyle associations that are not directly stated but may be visually or contextually suggested.

Once an implied message has been inferred, the system may attempt to retrieve relevant, objective contextual data from one or more external databases, data lakes, scientific corpora, product registries, or user-trusted repositories. This data may include factual information such as nutritional content, product sourcing, environmental impact assessments, longitudinal health effects, or economic trends, depending on the context of the content being viewed. A discrepancy detection algorithm may then be applied to evaluate whether the inferred implication diverges significantly from the objective data in a manner that could be reasonably understood as misleading.

If such a discrepancy is identified, the system may generate a corrective overlay designed to supplement the user's perception with factual or alternative visual material. These overlays may take the form of graphical annotations, probability charts, summary warnings, comparative ratings, or simulated future scenarios generated through predictive modeling. For instance, an ad for a sugary beverage showing athletic performance improvement may be supplemented by a warning that high sugar intake has been statistically linked to increased obesity or energy crashes, and may be further augmented with an image of a tired, sedentary user based on population-level trends. The system could be configured to generate such overlays using real-time visual synthesis, annotation engines, or pre-curated content retrieved from trusted sources.

These corrective visual elements may be rendered in the user's display environment and anchored to relevant regions of the content through real-time object tracking or spatial analysis. The tone, style, or persistence of the overlay may be adapted to the user's emotional state, age profile, context of use, or pre-configured preferences. For example, in some embodiments, aggressive red boxes may be replaced with calming nature imagery that gently communicates the informational correction, particularly in sensitive contexts such as health or childhood advertising.

The system may be designed to preserve user autonomy by offering transparency and consent controls. Rather than censoring or removing original content, the invention may function as an interpretive augmentation layer that helps users critically assess what is being implied. In doing so, it may reduce the cognitive asymmetry between content producers and consumers, especially in domains where asymmetrical knowledge can lead to harm-such as food marketing, political persuasion, or pharmaceutical promotion.

In some implementations, the system may operate entirely on-device for privacy protection, or may rely on cloud-based inference services to support complex visual-linguistic reasoning. In certain embodiments, audit logs may be created to enable review of corrected content, thereby supporting regulatory compliance, media literacy, or psychological research on advertising effectiveness and resilience. The invention may further be adapted as a platform-level utility integrated into app ecosystems, social media interfaces, or consumer advocacy toolkits.

The Implied Truth Correction System may be applicable across a wide range of content categories, including-but not limited to-food labeling, cosmetic claims, political endorsements, environmental sustainability symbols, financial products, and lifestyle branding. In each case, the goal may be to assist the viewer in recognizing when a piece of content is presenting a claim that is more suggestive than factual, and to offer a data-grounded, aesthetically integrated visualization that better reflects the reality of the situation.

In this way, the invention may contribute to a new generation of cognitive support tools designed not to restrict speech, but to elevate comprehension and decision-making in environments saturated with persuasive visual content. The system may be particularly valuable in an era where algorithmic targeting and emotional framing have become central to commercial and political communication. By helping users see not just what is shown, but what is *left out*, the system may support the emergence of a more resilient and self-aware public discourse.

In practice, the Implied Truth Correction System may be realized through a combination of hardware, software, and network-accessible data resources, all orchestrated to operate either locally on a user device or through distributed computing infrastructure.

The system may begin with a visual capture module, which could be implemented using a forward-facing camera embedded in a wearable device such as smart glasses, or alternatively through an external video stream from a smartphone, tablet, or desktop display. The video feed may be processed in real-time or near-real-time to identify segments of interest based on visual markers such as text overlays, brand logos, product packaging, or other advertisement cues. In some embodiments, scene segmentation or optical character recognition (OCR) may be employed to parse embedded text or slogans.

A content implication engine may be configured to operate on this visual input and extract one or more implied messages. This may be achieved using a large vision-language model (VLM), transformer-based neural networks, or other multimodal AI systems trained to infer symbolic associations, future predictions, or emotionally loaded subtext from visual material. For example, a clip of a slim, smiling child consuming a branded snack in a sunlit park may be interpreted by the system as implying healthiness, social success, and emotional well-being associated with the product.

To assess the validity of such implied associations, the system may include a factual context retrieval subsystem, which could query one or more databases relevant to the detected product or subject matter. These databases may include nutritional information repositories (e.g., USDA, EFSA), peer-reviewed health research databases, environmental impact datasets, regulatory filings, product registries, or open knowledge graphs such as Wikidata or ConceptNet. Queries may be constructed by converting the inferred implication into structured form and matching it against factual records. For instance, an implication of “good for energy” may be checked against documented metabolic effects of the ingredients in the identified product.

Once factual data is retrieved, a discrepancy detection module may compare the implied message with the objective facts. This module may apply heuristic scoring, probabilistic classifiers, or contrastive embeddings to determine whether the implication diverges from truth in a meaningful way. A threshold function may be used to decide whether a corrective overlay is warranted, potentially taking into account the degree of deviation, severity of potential harm, and the strength of the implication's emotional or predictive framing.

In response to a detected discrepancy, a correction generation engine may synthesize one or more corrective overlays. These overlays may take multiple forms: simple textual disclosures (“Warning: High Sugar”), dynamic infographics comparing implied benefits to actual data (“+65% sugar over WHO daily limit”), predictive images generated using diffusion models (“Realistic health trajectory if consumed daily”), or emotional tone counterbalances (e.g., replacing a smiling child with a fatigued one, where justified by statistical trends). Templates for each correction type may be stored in a modular repository, and selected adaptively based on context.

A rendering subsystem may then anchor the overlay to the appropriate region of the original content.

This may be achieved via computer vision techniques such as object detection, pose estimation, semantic segmentation, or depth mapping. The correction may be overlaid spatially on top of the triggering element (e.g., directly over the cereal box, actor's face, or text region), or in a reserved corner of the field of view, depending on user preferences. In some embodiments, overlays may replace the misleading region entirely with a curated visual alternative, such as a nature background or monochrome overlay with factual content.

The system may also include a user preference and feedback module, which could store opt-in personalization data indicating whether the user prefers aggressive warnings, gentle hints, full visibility, or minimal interruption. The system may allow toggling between “educational,” “protective,” or “transparent” modes, each controlling how assertively the overlay is presented. Corrections may optionally be stored in an audit trail for later review, or shared anonymously to a larger truth correction network for model retraining and benchmarking.

Latency optimization may be achieved through edge inference using on-device neural accelerators, or by offloading portions of the implication inference and overlay generation to cloud-based services, depending on bandwidth, privacy settings, and hardware capability. Where privacy is a concern, captured content may be processed in memory without long-term storage, and no personally identifying information need be retained.

Security protocols may be embedded to prevent manipulation of the system's interpretation engine by adversarial advertisements. In one variation, adversarial robustness techniques such as ensemble voting across multiple model interpretations may be applied. Digital signatures or hash-based verification may also be used to authenticate the factual sources upon which overlays are based, thereby ensuring trust in the correction mechanism.

Through such an integrated design, the Implied Truth Correction System may provide a scalable and flexible framework capable of analyzing, evaluating, and augmenting a wide range of visual content, helping users recognize misleading implications and make better-informed decisions.

In practice it is preferred to implement an Implied Truth Correction System that analyzes advertising content and provides corrective overlays to disclose omitted or misleading information, which leads to a more reliable representation of products at the time of purchase. As a result, users are less likely to engage in misinformed purchases that would otherwise result in returns, replacements, or secondary acquisitions. More specifically, the system produces the effect of improving the integrity of the information-processing pipeline because corrective data is injected automatically and in real time, which reduces redundant user queries, processor cycles, and bandwidth consumption associated with searching for missing details. Since fewer products are unnecessarily repurchased or shipped back due to unmet expectations, the invention indirectly reduces logistical movement, material waste, and carbon footprint, while its primary effect is improved efficiency and reliability of the digital information delivery system.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for restoring cognitive agency in viewers, comprising:
   a) capturing visual content currently viewed by a user;
   b) deriving one or more implied messages from the visual content;
   c) retrieving factual data relevant to the subject of the implied messages;
   d) determining whether a misleading discrepancy exists between the implication and the factual data;
   e) generating a corrective overlay based on the discrepancy; and
   f) displaying the corrective overlay in association with the original content.
2. The system of item 1, wherein the visual content is captured using smart glasses, an augmented reality headset, a mobile device camera, or an AI-integrated display screen.
3. The system of item 1, wherein the implied message is derived using a vision-language model trained to infer emotional tone, health claims, lifestyle associations, or aspirational visual suggestions from visual or audio content.
4. The system of item 1, wherein the factual data is retrieved from structured databases including nutritional repositories, scientific literature, regulatory filings, public health records, or product ingredient lists.
5. The system of item 1, wherein the discrepancy is detected by computing a difference between the implied benefit and a statistically likely outcome based on real-world data.
6. The system of item 1, wherein the corrective overlay includes one or more of: a warning box, a bar chart, a data-driven image, a red flag icon, or a simulated future scenario based on probabilistic modeling.
7. The system of item 6, wherein the simulated future scenario includes a synthetic image generated by the system showing a likely outcome for the viewer if the implied message were acted upon.
8. The system of item 1, wherein the corrective overlay is stylistically modulated to match the emotional tone of the original content or to avoid cognitive overload in the user.
9. The system of item 1, wherein the corrective overlay is displayed in real-time over the original content using object tracking, screen positioning, or scene anchoring to maintain contextual relevance.
10. The system of item 1, wherein the discrepancy determination step includes assigning a deception score or false implication index used to prioritize or filter which overlays are rendered.
11. A method for restoring cognitive agency in a viewer, the method comprising:
   a) capturing visual content that is being presented to a user;
   b) inferring one or more implied messages from the visual content;
   c) retrieving objective data relevant to the subject matter of the implied messages;
   d) determining whether a discrepancy exists between the implied messages and the objective data;
   e) generating a visual correction based on the discrepancy; and
   f) rendering the visual correction alongside or over the original visual content.
12. The method of item 11, wherein the step of inferring implied messages comprises analyzing imagery, packaging, audio narration, or symbolic cues using a vision-language model.
13. The method of item 11, wherein the objective data includes nutritional values, health risks, sourcing information, product age, or ecological impact data.
14. The method of item 11, further comprising computing a predicted outcome for the user based on acting upon the implied message, wherein the visual correction includes a simulation or statistical forecast of said outcome.
15. The method of item 11, wherein the visual correction comprises a red warning box, icon overlay, data annotation, or synthetic image illustrating a realistic future scenario.
16. The method of item 11, wherein the discrepancy determination includes scoring the deceptive strength of the content based on a combination of omission severity, emotional contrast, and outcome variance.
17. The method of item 11, wherein the rendering step includes anchoring the overlay spatially to the original content using object tracking or pose estimation.
18. The method of item 11, further comprising filtering or ranking potential corrections based on user preferences, cognitive load thresholds, or context-awareness.
19. The method of item 11, wherein the captured content includes product packaging in a retail environment, and the correction overlays include shelf-side warnings or sourcing disclosures.
20. The method of item 11, wherein the entire process is performed on a wearable device, and the overlays are displayed through an augmented reality interface integrated into a smart glasses display.

### Embodiment ACE: Implied Truth Correction System

Scope and interpretive note: The scope of this disclosure may be limited solely by the claims. Any embodiments, examples, data structures, and any referenced figures or flow descriptions, if any are provided, may be illustrative and non-limiting. Unless expressly required by a claim, operations may be reordered, performed concurrently, added, or omitted, and hardware and software modules may be partitioned or combined in alternative implementations.

Systems and methods may assist a viewer by detecting implied messages in visual media, comparing those implications to objective data, and presenting corrective overlays anchored to the viewed content. Embodiments may operate on smart glasses, smartphones, or displays, infer latent claims using multimodal AI, retrieve facts via trusted connectors, score discrepancies, and render context-sensitive, user-configurable corrections. The approach may improve decision-making without censoring content and may include privacy, security, interoperability, and monetization features.

Gentle Introduction: People often encounter imagery that hints at benefits or outcomes without stating them, such as a beverage ad that visually suggests improved athletic performance. The disclosed system may act as a companion layer that looks at what the viewer sees, recognizes what is being implied, checks that implication against real-world data, and gently adds clarifying information on top of the original scene. This may preserve the content while restoring interpretive autonomy to the user through on-device or cloud-assisted analysis and visual augmentation.

Background: Visual and audiovisual persuasion may rely on aesthetic framing, omission of context, or symbolic associations that regulators do not always classify as explicit deception. Such practices may shape health choices, financial behavior, or political perceptions. Existing tools may focus on explicit textual claims or post-hoc fact-checking, leaving a gap for real-time, implication-aware assistance that is sensitive to user preferences and privacy.

Summary: The system may capture live visual content, infer one or more implied messages using a vision-language model or equivalent logic, retrieve objective facts from authenticated sources, compute a discrepancy or deception score, and synthesize corrective overlays that are anchored to the original content. Embodiments may provide explainable rationales, adaptive styles, audit trails, and entitlement-controlled capabilities. Interoperability may be achieved via a tool registry such as a Model Context Protocol registry or equivalent connectors.

Description of the drawings: No drawings may be included in this application. Architectures and flows may be textually described in the Anchor and process flow sections and could be converted into figures in later filings or continuations without departing from the disclosed embodiments.

The present invention may relate to systems and methods that could enhance a user's interpretative autonomy while engaging with visual media, particularly in contexts where advertisements, product packaging, digital promotions, or political messaging may include implicit claims or emotionally persuasive imagery. In some embodiments, the invention may employ artificial intelligence to detect, evaluate, and optionally correct misleading implications conveyed through non-explicit content structures, such as selective framing, stylized representation, omission of relevant data, or aspirational symbolism.

In current media environments, visual content-especially advertisements-may be structured in a way that suggests desirable outcomes, positive traits, or social approval without making explicit factual statements. These implicit suggestions may influence the viewer's perception and decision-making while remaining outside the scope of traditional regulatory definitions of deception.

For example, a visual sequence showing energetic, smiling individuals consuming a particular food product may imply improved vitality or emotional well-being, even where no scientific basis exists for such an association. Overtime, this may contribute to systemic distortions in consumer understanding, public health behavior, or democratic decision-making.

To address such risks, the proposed system-herein referred to as the Implied Truth Correction System-may operate on a user-facing device such as smart glasses, augmented reality headsets, smartphones, or smart television displays. The system may include a visual monitoring module capable of capturing content as experienced by the user in real time. Using one or more language-vision models or pattern-recognition algorithms, the system may analyze the content to infer latent or implied messages, which may include health implications, future outcomes, emotional states, or lifestyle associations that are not directly stated but may be visually or contextually suggested.

Once an implied message has been inferred, the system may attempt to retrieve relevant, objective contextual data from one or more external databases, data lakes, scientific corpora, product registries, or user-trusted repositories. This data may include factual information such as nutritional content, product sourcing, environmental impact assessments, longitudinal health effects, or economic trends, depending on the context of the content being viewed. A discrepancy detection algorithm may then be applied to evaluate whether the inferred implication diverges significantly from the objective data in a manner that could be reasonably understood as misleading.

If such a discrepancy is identified, the system may generate a corrective overlay designed to supplement the user's perception with factual or alternative visual material. These overlays may take the form of graphical annotations, probability charts, summary warnings, comparative ratings, or simulated future scenarios generated through predictive modeling. For instance, an ad for a sugary beverage showing athletic performance improvement may be supplemented by a warning that high sugar intake has been statistically linked to increased obesity or energy crashes, and may be further augmented with an image of a tired, sedentary user based on population-level trends. The system could be configured to generate such overlays using real-time visual synthesis, annotation engines, or pre-curated content retrieved from trusted sources.

These corrective visual elements may be rendered in the user's display environment and anchored to relevant regions of the content through real-time object tracking or spatial analysis. The tone, style, or persistence of the overlay may be adapted to the user's emotional state, age profile, context of use, or pre-configured preferences. For example, in some embodiments, aggressive red boxes may be replaced with calming nature imagery that gently communicates the informational correction, particularly in sensitive contexts such as health or childhood advertising.

The system may be designed to preserve user autonomy by offering transparency and consent controls. Rather than censoring or removing original content, the invention may function as an interpretive augmentation layer that helps users critically assess what is being implied. In doing so, it may reduce the cognitive asymmetry between content producers and consumers, especially in domains where asymmetrical knowledge can lead to harm-such as food marketing, political persuasion, or pharmaceutical promotion.

In some implementations, the system may operate entirely on-device for privacy protection, or may rely on cloud-based inference services to support complex visual-linguistic reasoning. In certain embodiments, audit logs may be created to enable review of corrected content, thereby supporting regulatory compliance, media literacy, or psychological research on advertising effectiveness and resilience. The invention may further be adapted as a platform-level utility integrated into app ecosystems, social media interfaces, or consumer advocacy toolkits.

The Implied Truth Correction System may be applicable across a wide range of content categories, including-but not limited to-food labeling, cosmetic claims, political endorsements, environmental sustainability symbols, financial products, and lifestyle branding. In each case, the goal may be to assist the viewer in recognizing when a piece of content is presenting a claim that is more suggestive than factual, and to offer a data-grounded, aesthetically integrated visualization that better reflects the reality of the situation.

In this way, the invention may contribute to a new generation of cognitive support tools designed not to restrict speech, but to elevate comprehension and decision-making in environments saturated with persuasive visual content. The system may be particularly valuable in an era where algorithmic targeting and emotional framing have become central to commercial and political communication. By helping users see not just what is shown, but what is left out, the system may support the emergence of a more resilient and self-aware public discourse.

Examples: The following concrete scenarios may illustrate end-to-end behavior and data structures suitable for implementation. In an augmented reality advertisement for a sugary beverage viewed through smart glasses, the visual capture module may stream frames that include a can labeled “SparkUp Soda” and a runner finishing a race while drinking. The content implication engine may form a hypothesis that the scene implies performance improvement and emotional uplift associated with consumption, which could be represented internally as {“hypothesisId”:“hi”, “subjectType”:“product”, “productName”: “SparkUp Soda”, “impliedAssociation”:[“improves athletic performance”, “boosts energy”], “emotionalValence”:“positive”, “targetAudience”:“general”, “confidence”:0.82}. The factual context retrieval subsystem may resolve a UPC code detected by OCR to ingredients, and via connectors may query nutritional repositories and WHO guidelines. A Model Context Protocol (MCP) tool registry may be consulted so the client can discover and safely invoke a nutrition lookup and a guideline checker; a representative MCP tool call could be {“tool”:“usda.nutrition.lookup”, “args”:{“upc”:“0123456789012”}} with a response such as {“energyKcalPer100 ml”:42, “sugarsGPer100 ml”:10.6, “caffeineMgPer100 ml”:0}. A second MCP call may check limits {“tool”:“who.sugar.limit.check”, “args”:{“ageYears”:30, “sex”:“unspecified”, “intakeSugarsG”:53}}returning {“percentDailyLimit”:165, “advisory”:“exceeds recommended free sugars intake”}. The discrepancy detection module may produce a deception score using contrastive embeddings comparing “improves athletic performance” against literature on high-glycemic beverages and endurance, yielding {“hypothesisId”:“hi”, “deceptionScore”:0.76, “rationale”:“high free sugars linked to energy crashes and weight gain; no evidence of performance improvement”}. The correction generation engine may select a dynamic infographic template and synthesize an overlay spec such as {“overlayId”:“ol”, “type”:“infographic”, “anchor”:{“mode”:“region”, “bbox”:[540,260,220,140]}, “text”: “+165% of recommended daily free sugars if one can consumed”, “secondaryText”:“High sugar intake is associated with post-spike fatigue”, “provenance”:[“USDA”, “WHO” IT“tone”:“neutral”}. The rendering subsystem may anchor the overlay near the can while preserving the scene, and the user preference module may tone-map colors to avoid aggressive red if the user has selected an educational mode. If the user dismisses the correction, the metering client may record a de-identified event as {“event”:“overlay_dismissed”, “overlayId”:“o1”, “timestamp”:“2025-05-0ITI8:04:05Z”}for privacy-preserving aggregation.

In a political promotion video played on a smart television, a montage of factories reopening may imply job growth causally linked to a policy. The system may extract an implied causal link represented as {“hypothesisId”:“p7”, “subjectType”:“policy”, “policyTag”:“Policy-Alpha”, “impliedAssociation”:[“incr eases manufacturing jobs”]}. Via MCP, the client may discover a labor statistics tool and invoke {“tool”:“bls.series.query”, “args”:{“series”:“CEU3000000001”, “start”:“2023-01”, “end”:“2025-01”}} to obtain {“trend”:“flat”, “seasonallyAdjusted”:true}. The discrepancy module may assign a false implication index of 0.68 with rationale that the series is flat or declining in the relevant window, after which the correction generation engine may synthesize a small line chart overlay stating “No observed increase in manufacturing employment in period referenced,” anchored to the lower corner of the screen and rendered with low opacity to reduce distraction.

In a retail aisle viewed via a smartphone camera, packaging using green leaves and the phrase “planet-friendly” may imply a reduced environmental impact. The implication may be encoded as {“hypothesisId”:“e2”, “subjectType”:“claim”, “claimText”:“planet-friendly”, “impliedAssociation”:[“red uced lifecycle emissions”]}. The retrieval subsystem may query an environmental product declaration registry through MCP using {“tool”:“epd.lookup”, “args”:{“manufacturer”:“Acme Co.”, “sku”:“AC-4455”}} and receive {“gwpKgCO2ePerUnit”:4.8, “verification”:“third-party”, “label”:“no certified eco-label found”}. A corrective overlay may then provide a short disclosure such as “No recognized eco-label; lifecycle emissions 4.8 kg CO2e/unit per EPD,” anchored near the package text.

Enablement: A skilled person may implement embodiments by assembling the modules described and following the end-to-end flows demonstrated in the examples. A camera or display feed may be captured and preprocessed; a vision-language model or equivalent logic may infer structured hypotheses; connectors discovered via a Model Context Protocol registry or equivalent APIs may retrieve authenticated facts; a scoring component may compute a deception or discrepancy index; and an overlay engine may render context-appropriate corrections anchored to the original scene. The JSON examples specify representative internal data structures for hypotheses, tool calls, responses, discrepancy scores, and overlay specifications. Deployment may be on-device, cloud-based, or hybrid, with privacy, security, and entitlement controls configured per the detailed description below.

Technical effects: Embodiments may yield concrete technical effects that improve computer functionality and user-perceptual outcomes in real-world deployments. On-device inference and rendering may reduce motion-to-photon latency so that overlays remain spatially coherent with moving objects, which may decrease mistracking artifacts and visual-vestibular conflict relative to post-processed or manual fact-checking. Hybrid execution with adaptive offloading may select models and resolutions based on energy and bandwidth budgets, which may extend battery life while maintaining target overlay timing. Provenance verification using digital signatures or hash-based checks may prevent injection of tampered factual inputs, which may increase system integrity compared to naive HTTP retrieval. Discrepancy scoring with threshold policies may stabilize correction cadence under varying scene content, which may lower cognitive load by avoiding oscillatory overlay behavior. Spatial anchoring using object detection, pose estimation, segmentation, or depth mapping may produce occlusion-aware placement that preserves legibility and minimizes occlusion of salient scene regions, which may improve readability over non-anchored captions.

Adversarial robustness ensembles and input sanitization may reduce susceptibility to adversarial patterns embedded in visual media, which may materially improve reliability in adversarial advertising contexts. Local template caches and predictive prefetch of likely corrections may reduce cold-start delays, which may enable near-real-time augmentation on constrained devices. MCP or equivalent connector discovery may decouple factual retrieval from fixed APIs, which may increase availability and fault tolerance when individual endpoints change, thereby reducing downtime without altering user interfaces. Accessibility variants including audio-only or haptic overlays may increase effective coverage across device classes and user abilities, which may broaden applicability without requiring alternate applications. Policy-governed audit logs with timestamps and optional watermarks may yield verifiable external observables, which may enable reproducible tests and compliance auditing without privileged access. To further support eligibility and enforceability, embodiments may implement discrepancy detection and spatial anchoring as concrete signal-processing pipelines executed on specific hardware. The anchoring subsystem may maintain a per-object state vector including position, velocity, and scale updated per frame by a Kalman filter seeded from a keypoint detector and depth estimator, and overlays may be composited by GPU shaders in the device compositor with z-ordering derived from a depth map to ensure occlusion correctness. The system may enforce a motion-to-photon budget not exceeding a target threshold such as 50 milliseconds by adaptively reducing model input resolution or selecting smaller models when measured end-to-end latency exceeds a threshold, thereby improving the functioning of the device display pipeline.

Discrepancy scoring may be realized as a bounded function mapping hypothesis terms to normalized scores via contrastive embeddings and calibration parameters persisted in firmware, with scores below a first threshold suppressing overlays and scores above a second threshold triggering synthesis, yielding reproducible outcomes under fixed random seeds. Factual provenance may be enforced by verifying digital signatures such as ECDSA P-256 over payloads or by validating RFC 3161-compliant timestamps prior to rendering any correction. These concrete, measurable operations may yield verifiable performance improvements in latency, stability, and integrity beyond abstract content evaluation.

Detailed Description: In practice, the Implied Truth Correction System may be realized through a combination of hardware, software, and network-accessible data resources, all orchestrated to operate either locally on a user device or through distributed computing infrastructure.

The system may begin with a visual capture module, which could be implemented using a forward-facing camera embedded in a wearable device such as smart glasses, or alternatively through an external video stream from a smartphone, tablet, or desktop display. The video feed may be processed in real-time or near-real-time to identify segments of interest based on visual markers such as text overlays, brand logos, product packaging, or other advertisement cues. In some embodiments, scene segmentation or optical character recognition (OCR) may be employed to parse embedded text or slogans.

A content implication engine may be configured to operate on this visual input and extract one or more implied messages. This may be achieved using a large vision-language model (VLM), transformer-based neural networks, or other multimodal AI systems trained to infer symbolic associations, future predictions, or emotionally loaded subtext from visual material. For example, a clip of a slim, smiling child consuming a branded snack in a sunlit park may be interpreted by the system as implying healthiness, social success, and emotional well-being associated with the product.

To assess the validity of such implied associations, the system may include a factual context retrieval subsystem, which could query one or more databases relevant to the detected product or subject matter. These databases may include nutritional information repositories (e.g., USDA, EFSA), peer-reviewed health research databases, environmental impact datasets, regulatory filings, product registries, or open knowledge graphs such as Wikidata or ConceptNet. Queries may be constructed by converting the inferred implication into structured form and matching it against factual records. For instance, an implication of “good for energy” may be checked against documented metabolic effects of the ingredients in the identified product.

Once factual data is retrieved, a discrepancy detection module may compare the implied message with the objective facts. This module may apply heuristic scoring, probabilistic classifiers, or contrastive embeddings to determine whether the implication diverges from truth in a meaningful way. A threshold function may be used to decide whether a corrective overlay is warranted, potentially taking into account the degree of deviation, severity of potential harm, and the strength of the implication's emotional or predictive framing.

In response to a detected discrepancy, a correction generation engine may synthesize one or more corrective overlays. These overlays may take multiple forms: simple textual disclosures (“Warning: High Sugar”), dynamic infographics comparing implied benefits to actual data (“+65% sugar over WHO daily limit”), predictive images generated using diffusion models (“Realistic health trajectory if consumed daily”), or emotional tone counterbalances (e.g., replacing a smiling child with a fatigued one, where justified by statistical trends). Templates for each correction type may be stored in a modular repository, and selected adaptively based on context.

A rendering subsystem may then anchor the overlay to the appropriate region of the original content.

This may be achieved via computer vision techniques such as object detection, pose estimation, semantic segmentation, or depth mapping. The correction may be overlaid spatially on top of the triggering element (e.g., directly over the cereal box, actor's face, or text region), or in a reserved corner of the field of view, depending on user preferences. In some embodiments, overlays may replace the misleading region entirely with a curated visual alternative, such as a nature background or monochrome overlay with factual content.

The system may also include a user preference and feedback module, which could store opt-in personalization data indicating whether the user prefers aggressive warnings, gentle hints, full visibility, or minimal interruption. The system may allow toggling between “educational,” “protective,” or “transparent” modes, each controlling how assertively the overlay is presented.

Corrections may optionally be stored in an audit trail for later review, or shared anonymously to a larger truth correction network for model retraining and benchmarking.

Latency optimization may be achieved through edge inference using on-device neural accelerators, or by offloading portions of the implication inference and overlay generation to cloud-based services, depending on bandwidth, privacy settings, and hardware capability. Where privacy is a concern, captured content may be processed in memory without long-term storage, and no personally identifying information need be retained.

Security protocols may be embedded to prevent manipulation of the system's interpretation engine by adversarial advertisements. In one variation, adversarial robustness techniques such as ensemble voting across multiple model interpretations may be applied. Digital signatures or hash-based verification may also be used to authenticate the factual sources upon which overlays are based, thereby ensuring trust in the correction mechanism.

Through such an integrated design, the Implied Truth Correction System may provide a scalable and flexible framework capable of analyzing, evaluating, and augmenting a wide range of visual content, helping users recognize misleading implications and make better-informed decisions.

Monetization and Damages Maximization: In some embodiments, monetization and usage metering features may be provided to support subscription-model deployment and to facilitate quantification of economic harm in the event of infringement. A license and entitlement subsystem may issue cryptographically signed tokens that could be verified on-device or via a network service before enabling specific correction features, overlay templates, or database connectors. The client application may locally meter usage events such as overlays rendered, impressions analyzed, corrections dismissed by the user, network queries made to factual sources, and time spent in protected modes, with aggregation performed on-device and periodically transmitted in encrypted form to a billing or analytics endpoint. To preserve user privacy while enabling damages calculations, metering data may be de-identified, differentially private, or coarsened to cohort-level summaries, and may be retained according to user-configured policies. Subscription tiers may enable or limit advanced capabilities such as predictive scenario synthesis, enterprise policy controls, or multi-user administration, while service-level agreements could specify minimum overlay latency and model accuracy targets. In certain implementations, overlays or audit logs may include invisible watermarks or verifiable timestamps that could establish provenance and usage, thereby supporting license compliance monitoring and forensic attribution. The system may further include mechanisms for offline grace periods, periodic entitlement refresh, and revocation, ensuring reliable operation in the field while maintaining enforceable access control and usage-based accounting that could be referenced to estimate lost revenues or reasonable royalties in damages models.

Anchor: element inventory and relationships for embodiment comprehension. The system may be understood as a pipeline and set of cooperating subsystems. A visual capture module may acquire a live or buffered image sequence or frame set from smart glasses, a mobile device camera, a desktop or television display feed, or an augmented reality headset. The captured frames may be stored transiently in an ephemeral frame buffer under a privacy controller that may prohibit long-term retention unless the user enables audit logging. The frames may be preprocessed by optional scene segmentation, OCR, and logo or packaging detectors that may extract regions, text strings, and brand cues. A content implication engine may receive these features and the raw or preprocessed pixels and may use a vision-language model and associated classifiers to infer candidate implied messages represented internally as structured hypotheses with fields describing the product or subject, the implied benefit or association, the emotional valence, and the target audience, and a confidence score.

A factual context retrieval subsystem may translate each hypothesis into one or more queries and may access connectors to nutritional repositories, scientific literature indices, regulatory filings databases, environmental impact datasets, product registries, and open knowledge graphs. Retrieved records may be normalized by a data normalizer and annotated by a provenance verifier that may check digital signatures or compute hashes to confirm source authenticity. A discrepancy detection module may compute a deception score or false implication index by comparing the implied association with distributions derived from the normalized records using heuristic scoring, probabilistic classifiers, or contrastive embeddings, and may apply policy-specific thresholds to decide whether correction is warranted given potential harm, deviation magnitude, and confidence in the implication. A correction generation engine may reference an overlay template repository and, depending on context and user mode, may synthesize textual disclosures, dynamic infographics, comparative ratings, probabilistic forecasts, or synthetic imagery produced by diffusion or other generative models to depict predicted outcomes. A rendering subsystem may perform object or region anchoring using detection, pose estimation, segmentation, or depth mapping, and may composite the corrective overlay over or alongside the triggering element or in a reserved viewport region, while a latency controller may adapt resolution and model selection to meet real-time constraints. A user preference and feedback module may store profile data describing desired assertiveness, cognitive load limits, accessibility needs, and mode selection such as educational, protective, or transparent, and may gate whether certain overlays are displayed or suppressed. A license and entitlement subsystem may gate premium features, templates, or connectors using signed tokens, while a metering and analytics client may record counts of analyzed impressions, rendered overlays, dismissals, network queries, and protected-mode durations, with privacy-preserving aggregation and periodic encrypted transmission to a billing or analytics endpoint. A security subsystem may include adversarial robustness ensembles for implication inference and a source signature verifier for factual inputs, and may optionally watermark or timestamp overlays or audit entries for provenance. The system may operate on-device using neural accelerators and a local overlay cache, may offload selected inference or retrieval to cloud services via a network interface respecting user privacy constraints, and may integrate with platform compositors for smartphones, operating systems, augmented reality displays, televisions, and application ecosystems. Data flows may proceed from capture to implication inference to factual retrieval to discrepancy scoring to correction synthesis to rendering, with feedback loops from user interaction and audit outcomes to model or policy updates and with policy gates from entitlement and privacy controls applied before execution of sensitive operations. These relationships may allow partial or fallback operation where, for example, only local OCR and simple warning templates are enabled without cloud retrieval, while still maintaining the core inventive concept of detecting implied messaging and augmenting the user's perception with fact-grounded corrections.

Process flows: The foregoing anchor describes a sequence that may be directly rendered as flowcharts for method claims. A representative flow may include capture, preprocessing, implication hypothesis generation, factual retrieval, provenance verification, normalization, discrepancy scoring, thresholding, template selection, overlay synthesis, spatial anchoring, rendering, and feedback logging, with policy and entitlement gates at decision points and optional batching or rate-limiting. An explicit stepwise realization may proceed by receiving a frame or segment timestamped at t, extracting regions, text strings, and brand cues, generating one or more structured hypotheses with confidence values, constructing and issuing connector queries keyed by product identifiers, policy tags, or detected entities, verifying provenance of returned records and discarding any failing signature or timestamp checks, normalizing heterogeneous records into canonical attributes, computing a discrepancy score per hypothesis and comparing the score against domain-specific thresholds, selecting a correction template conditioned on discrepancy magnitude, user mode, and cognitive load limits, synthesizing an overlay specification including text, charts, icons, or synthetic imagery along with an anchor mode and geometry, resolving spatial placement via object detection, pose estimation, segmentation, or depth mapping while honoring occlusion rules, compositing the overlay via the device compositor within a latency budget, logging externally observable events with timestamps and provenance references, and adapting subsequent iterations by reducing model input resolution or switching to smaller models when latency budgets are exceeded. A complementary offline or low-connectivity flow may capture content, run OCR and heuristic implication inference, map detected terms to preinstalled tables or distilled model outputs representing factual attributes, evaluate a rule-based discrepancy policy, generate static or cached warning overlays, anchor overlays using screen-space coordinates or lightweight trackers, render within a fixed timing budget, record local audit entries, and schedule deferred synchronization to verify provenance and update caches when network access becomes available.

External observability: Externally visible behaviors may include deterministic triggers for standardized test scenes, predictable overlay placement relative to detected regions, exportable audit entries with timestamps and source provenance, and verifiable counts of analyzed impressions and rendered overlays. These behaviors may enable infringement detection without internal access, consistent with the audit and metering features and item 32 of the itemized list. In compliance tests using fixed media fixtures and seeded models, the system may repeatedly render overlays within a specified latency budget relative to frame presentation and within a pixel tolerance relative to detected bounding boxes, and audit records may include verifiable cryptographic attestations of the inputs and outputs observed.

Eligibility and enforcement considerations: Embodiments may be rooted in computer technology and may provide a specific improvement to the functioning of display pipelines and multimodal inference systems. The disclosed pipelines may transform captured sensor data into time-aligned overlays by executing latency-bounded signal processing and GPU-composited rendering that cannot be practically performed by a human mind in real time at target motion-to-photon budgets. The claimed sequence may be constrained to a particular technological process that includes provenance-gated factual retrieval, contrastive discrepancy scoring with calibrated thresholds persisted in firmware, per-object state estimation via filtering, and occlusion-correct compositing driven by depth maps, which may constitute a practical application rather than an abstract evaluation of content.

Implementations may be tied to specific hardware resources, including neural accelerators for VLM inference, secure elements for key storage used in signature verification, and device compositors executing shader programs that enforce z-ordering, thereby improving the operation of these components beyond generic usage. The system's externally testable behaviors, including reproducible latency, pixel-tolerance bounds for overlay anchoring, and cryptographically verifiable audit records, may enable reliable infringement detection based on inputs and outputs observable without privileged access. These characteristics may support subject-matter eligibility, definiteness, written description, enablement, and enforceability by providing concrete structures, measurable performance constraints, and verifiable external observables tied to the claimed steps. For avoidance of indefiniteness under functional claiming, corresponding structures are expressly provided for modules that may be interpreted under means-plus-function provisions. The visual capture module may include a camera and frame acquisition subsystem executing capture routines on a processor and image signal processor storing frames in an ephemeral buffer in non-transitory memory. The content implication engine may include a processor or neural accelerator executing an algorithm comprising feature extraction, tokenization, vision-language inference producing embeddings, and hypothesis formation with calibrated confidence scoring as described in the process flows. The factual context retrieval subsystem may include a network interface, protocol stack, and a connector client that discovers tools via a Model Context Protocol registry or equivalent directory, issues authenticated API requests, and verifies responses via digital signatures or timestamp validation. The discrepancy detection module may include a processor executing a bounded contrastive scoring algorithm that maps hypothesis terms and retrieved facts into an embedding space, applies calibration parameters persisted in firmware, and outputs a normalized deception index with thresholding logic. The correction generation engine may include a template selector state machine and text, chart, and image synthesis routines executing on a CPU, GPU, or neural accelerator to produce an overlay specification. The rendering subsystem may include a GPU compositor executing shader programs that composite the overlay with z-ordering informed by a depth map and state vectors updated via a Kalman filter seeded by keypoint detection and depth estimation. The algorithmic steps corresponding to each module are further described in the Process flows and Technical effects sections and constitute sufficient structure for any functional limitations recited in the claims.

Interoperability coverage: Embodiments may interoperate with multiple platforms and protocols by using a Model Context Protocol tool registry or equivalent connectors, integrating with smartphone compositors, browser extensions, television overlays, and AR platform SDKs, and by supporting alternative data sources and APIs without changing core functionality. This may prevent avoidance through interface substitutions.

Fallback embodiments: Simpler or partial implementations may operate using local OCR, heuristics, and static warning templates without cloud retrieval or generative synthesis, while still performing implication detection and correction. Such embodiments may be used in constrained devices or offline contexts and are described in the anchor and in item 33.

Support and claim correspondence: Each claim may be supported by the description and itemized list. For example, claim 1 corresponds to the end-to-end system described throughout and to item 1; claims 2 through 10 correspond to items 2 through 10 and related paragraphs; claim 11 corresponds to item 11 and the process flows; claims 12 through 20 correspond to items 12 through 20 and associated disclosure. Additional features described in items 21 through 40 provide explicit support for continuation claims.

Broadening alternatives: Alternative implementations may include audio-only or haptic corrections, on-device, cloud, or hybrid execution, rule-based or ML-based implication inference, alternative anchoring strategies, and multiple overlay modalities with varying styles and tones. These are disclosed across the detailed description and items 21 through 40 to enlarge claim scope without adding unnecessary limitations.

Claim layering: The claim set may include independent system and method claims in this filing, while item 40 provides support for a computer-readable medium form in future continuations. Apparatus and platform-level claims may also be supported by the described modules and anchors.

No unneeded limitations: The main claim elements may reflect features that a competitor would need to practice the inventive concept, while stylistic choices, specific models, particular data sources, or rendering aesthetics may be treated as optional and are disclosed as alternatives rather than limitations.

Anti-workaround coverage and terminology: To reduce opportunities for circumvention and to clarify breadth, certain terms may be interpreted as follows unless expressly narrowed by a claim. The phrase retrieve factual data may include obtaining data from any storage or compute locus, including on-device caches, preinstalled datasets, embedded model outputs whose predictions encode factual attributes, enterprise repositories, or remote services accessed directly or through connectors; retrieval may include lookup, dereferencing, or computation that yields factual attributes. The phrase derive an implied message may include any inference, detection, mapping, classification, or selection process that yields a hypothesized association, benefit, risk, causal linkage, prediction, or emotive suggestion attributable to the viewed subject, whether produced by rules, templates, supervised or unsupervised machine learning, embeddings, or precompiled catalogs keyed to observed cues such as logos, phrases, colors, settings, or actors. The phrase in association with the original content may encompass spatial anchoring on the same screen, placement in a reserved viewport, picture-in-picture, display on a companion device that is time-synchronized to the content, or any presentation that is temporally aligned to the triggering segment such that a reasonable observer would understand that the correction pertains to that segment. The term corrective overlay may include any visually perceptible augmentation or companion presentation rendered by the system that communicates the correction, including disclosures, charts, icons, simulated imagery, or citations; for accessibility variants, corresponding audio or haptic prompts may be emitted in parallel while the visual overlay remains present or minimal. The phrase discrepancy detection may include any comparison, scoring, rule evaluation, classifier decision, or statistical test that determines whether the implied message diverges from the retrieved factual data beyond a policy threshold, including cases where the factual data is embodied in precomputed tables or distilled model outputs. Acquire visual content may include capturing pixels from a camera, intercepting or decoding a media stream, loading a file or manifest prior to display, or receiving content fingerprints or identifiers used to obtain or select corresponding media. For avoidance of trivial architectural substitutions, in association with the original content may further include time-shifted overlays rendered within a short temporal window after the triggering segment ends, overlays composited by an operating system or browser compositor outside the originating application, or overlays injected server-side into a streamed media channel before presentation, provided that a reasonable observer would perceive the correction as pertaining to the triggering segment. Corrective overlay may further encompass co-presented outputs on companion wearables, notification surfaces, lock screens, casting targets, or secondary displays when time-synchronized, as well as audio or haptic-only disclosures that are temporally aligned with the triggering segment. Derive an implied message may include use of minimal or implicit cues such as frame timing, camera motion patterns, soundtrack motifs, or genre tropes, in addition to logos, phrases, colors, settings, or actors, and may be performed locally or remotely without avoiding the claimed step. Retrieve factual data may include prefetch, periodic synchronization, or background refresh from trusted sources so that data is available offline at inference time, and may include attested retrieval from edge caches or content delivery networks. Attempts to evade infringement by relocating implication inference to a cloud service, substituting asynchronous or batch retrieval, rebranding the correction as a tip or advisory, moving rendering to a separate application or device, or using pre-bundled disclosures remain within scope when the system as a whole derives an implied message, obtains factual data as defined, determines a discrepancy by any disclosed means, and displays a corrective overlay in association with the content as defined herein. These interpretations may apply across embodiments and enforcement analyses to prevent avoidance through trivial architectural substitutions. To further preclude design-arounds, these interpretations may also encompass systems that precompute or cache corrections offline and later select or replay them at runtime in response to detected content, systems that source disclosures from advertiser-provided files or label repositories instead of computing them anew, and systems that use human reviewers or crowdsourced judgments to perform one or more of the derivation, retrieval, or discrepancy steps, provided the overall sequence of deriving an implied message, obtaining factual data as defined, determining a discrepancy, and presenting a corrective overlay associated with the content is performed.

Presentation of the corrective overlay may include low-opacity watermarks, subtitle or caption tracks, accessibility surfaces, notification banners, companion-app pop-ups, wearable haptics, or audio tones that encode the correction, when time-aligned such that a reasonable observer would understand the correction pertains to the triggering segment. Relocating any step to an upstream server, CDN, edge node, or downstream client compositor, renaming modules, splitting steps across microservices, or substituting knowledge-graph lookups, embedded model priors, or static SKU tables for live queries may remain within scope when the defined functions are achieved. Rate-limiting to present the overlay shortly after the content, gating overlays behind a user interaction, or injecting corrections into a stream prior to delivery to the end device may still satisfy association with the original content when time-aligned as described. Selection among a finite set of pre-authored templates, rather than synthesizing new content, may constitute generation of a corrective overlay. Using only a subset of the disclosed modules may still practice method claims where the recited steps are carried out by the system as a whole, regardless of component boundaries.

Itemized list: continuation-ready support for future claims. Embodiments can be described by the following itemized list to provide explicit support for present and future claim sets, with each entry constituting an independently claimable feature or combination and including entries that correspond to each of the numbered claims herein. Item 1: A system configured to capture visual content viewed by a user, derive one or more implied messages, retrieve factual data relevant to the implied messages, determine whether a misleading discrepancy exists between the implication and the factual data, generate a corrective overlay responsive to the discrepancy, and display the corrective overlay in association with the original content. Item 2: The visual content capture may be performed using smart glasses, an augmented reality headset, a mobile device camera, or an AI-integrated display screen. Item 3: The implied message derivation may employ a vision-language model trained to infer emotional tone, health claims, lifestyle associations, or aspirational visual suggestions from visual or audio content. Item 4: The factual data retrieval may access structured databases including nutritional repositories, scientific literature, regulatory filings, public health records, or product ingredient lists. Item 5: The discrepancy detection may compute a difference between an implied benefit and a statistically likely outcome based on real-world data. Item 6: The corrective overlay may include a warning box, a bar chart, a data-driven image, a red flag icon, or a simulated future scenario based on probabilistic modeling. Item 7: The simulated future scenario may include a synthetic image generated by the system showing a likely outcome for the viewer if the implied message were acted upon. Item 8: The corrective overlay may be stylistically modulated to match the emotional tone of the original content or to avoid cognitive overload in the user. Item 9: The corrective overlay may be displayed in real time over the original content using object tracking, screen positioning, or scene anchoring to maintain contextual relevance. Item 10: The discrepancy determination may include assigning a deception score or false implication index used to prioritize or filter which overlays are rendered. Item 11: A method comprising capturing visual content presented to a user, inferring implied messages, retrieving objective data relevant to the implied messages, determining whether a discrepancy exists, generating a visual correction based on the discrepancy, and rendering the visual correction alongside or over the original content. Item 12: The inference step may analyze imagery, packaging, audio narration, or symbolic cues using a vision-language model. Item 13: The objective data may include nutritional values, health risks, sourcing information, product age, or ecological impact data. Item 14: The method may further comprise computing a predicted outcome for the user based on acting upon the implied message, and the visual correction may include a simulation or statistical forecast of said outcome. Item 15: The visual correction may comprise a red warning box, an icon overlay, a data annotation, or a synthetic image illustrating a realistic future scenario. Item 16: The discrepancy determination may score deceptive strength based on omission severity, emotional contrast, and outcome variance. Item 17: The rendering may anchor the overlay spatially to original content using object tracking or pose estimation. Item 18: Potential corrections may be filtered or ranked based on user preferences, cognitive load thresholds, or context awareness. Item 19: The captured content may include product packaging in a retail environment, and corrections may include shelf-side warnings or sourcing disclosures. Item 20: The entire process may be performed on a wearable device with overlays displayed through an augmented reality interface integrated into a smart glasses display. Item 21: The system may alternatively deliver audio-only corrections via text-to-speech without visual overlays, while still anchoring timing to content regions detected. Item 22: The overlay may be delivered as haptic feedback patterns indicating degrees of discrepancy for accessibility scenarios. Item 23: The system may interoperate with a Model Context Protocol tool registry to discover and call external tools for nutrition, labor statistics, environmental product declarations, or regulatory checks, or may use equivalent non-MCP connectors providing the same functions. Item 24: The implication engine may be implemented using rule-based heuristics without machine learning, using ML-only models, or using hybrid ensembles to increase robustness. Item 25: Factual source provenance may be verified using digital signatures, hash digests, transparency logs, or independent replication checks, and overlays may embed timestamps or watermarks for provenance. Item 26: The system may operate entirely on-device, entirely via cloud services, or in a split-execution mode that adaptively offloads tasks based on latency, privacy, and energy budgets. Item 27: The correction generator may produce alternative modalities including QR-linked citations, compact micro-charts, narrative disclosures, or counterfactual video snippets constrained by policy. Item 28: The rendering subsystem may reserve a fixed viewport region, replace the misleading region, or produce picture-in-picture composites, subject to user preference and accessibility rules. Item 29: Privacy controls may include ephemeral processing, differential privacy, cohort aggregation, redaction of faces or PII, and opt-in audit logging with retention limits. Item 30: Security controls may include adversarial example defenses, consensus voting across models, input sanitization, and sandboxing of third-party tool connectors. Item 31: Entitlement and monetization may include subscription tiers, usage metering, offline grace periods, revocation, and SLA-governed latency or accuracy guarantees. Item 32: External observability may be provided through deterministic, user-visible behaviors including predictable overlay triggers for standardized test stimuli, exportable audit entries, and verifiable counts of rendered corrections. Item 33: Fallback operation may function with only OCR and simple template warnings when network or models are unavailable, preserving the core inventive concept of implication detection and correction. Item 34: Interoperability may include integration with smartphone OS compositors, browser extensions, television firmware overlays, AR platform SDKs, and compliance with accessibility standards. Item 35: The deception threshold policy may be adjustable per domain, regulator, region, age group, or enterprise requirements, and may be learned or rule-defined. Item 36: The system may support multi-user or administrator modes, including parental controls and enterprise governance policies that enforce minimum correction behaviors. Item 37: The system may expose APIs to accept third-party correction templates, vetted factual sources, or enterprise policy packs signed by a trusted authority. Item 38: Correction scheduling may be rate-limited to control cognitive load, batched for efficiency, or prioritized by estimated harm, and may be pre-fetched for anticipated content. Item 39: The system may log model rationales or saliency maps for regulatory explainability without revealing proprietary model weights. Item 40: The invention may be embodied as a computer-readable medium storing instructions that, when executed, configure a device to perform any of the system or method features described herein.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for restoring cognitive agency in viewers, comprising:
   a) a visual capture module configured to acquire visual content that is presented to or selected for presentation to a user;
   b) a content implication engine configured to derive one or more implied messages from the visual content;
   c) a factual context retrieval subsystem configured to retrieve factual data relevant to subjects of the implied messages;
   d) a discrepancy detection module configured to determine whether a misleading discrepancy exists between an implied message and the factual data;
   e) a correction generation engine configured to generate a corrective overlay based on the discrepancy; and
   f) a rendering subsystem configured to display the corrective overlay in association with the original content.
2. The system of item 1, wherein the visual content is captured using smart glasses, an augmented reality headset, a mobile device camera, or an AI-integrated display screen.
3. The system of item 1, wherein the implied message is derived using a vision-language model trained to infer emotional tone, health claims, lifestyle associations, or aspirational visual suggestions from visual or audio content.
4. The system of item 1, wherein the factual data is retrieved from structured databases including nutritional repositories, scientific literature, regulatory filings, public health records, or product ingredient lists.
5. The system of item 1, wherein the discrepancy is detected by computing a difference between the implied benefit and a statistically likely outcome based on real-world data.
6. The system of item 1, wherein the corrective overlay includes one or more of: a warning box, a bar chart, a data-driven image, a red flag icon, or a simulated future scenario based on probabilistic modeling.
7. The system of item 6, wherein the simulated future scenario includes a synthetic image generated by the system showing a likely outcome for the viewer if the implied message were acted upon.
8. The system of item 1, wherein the corrective overlay is stylistically modulated to match the emotional tone of the original content or to avoid cognitive overload in the user.
9. The system of item 1, wherein the corrective overlay is displayed in real-time over the original content using object tracking, screen positioning, or scene anchoring to maintain contextual relevance.
10. The system of item 1, wherein the discrepancy determination step includes assigning a deception score or false implication index used to prioritize or filter which overlays are rendered.
11. A method for restoring cognitive agency in a viewer, the method comprising:
   a) capturing or otherwise obtaining visual content that is being presented to or selected for presentation to a user;
   b) inferring one or more implied messages from the visual content;
   c) retrieving objective data relevant to the subject matter of the implied messages;
   d) determining whether a discrepancy exists between the implied messages and the objective data;
   e) generating a visual correction based on the discrepancy; and
   f) rendering the visual correction alongside or over the original visual content.
12. The method of item 11, wherein the step of inferring implied messages comprises analyzing imagery, packaging, audio narration, or symbolic cues using a vision-language model.
13. The method of item 11, wherein the objective data includes nutritional values, health risks, sourcing information, product age, or ecological impact data.
14. The method of item 11, further comprising computing a predicted outcome for the user based on acting upon the implied message, wherein the visual correction includes a simulation or statistical forecast of said outcome.
15. The method of item 11, wherein the visual correction comprises a red warning box, icon overlay, data annotation, or synthetic image illustrating a realistic future scenario.
16. The method of item 11, wherein the discrepancy determination includes scoring the deceptive strength of the content based on a combination of omission severity, emotional contrast, and outcome variance.
17. The method of item 11, wherein the rendering step includes anchoring the overlay spatially to the original content using object tracking or pose estimation.
18. The method of item 11, further comprising filtering or ranking potential corrections based on user preferences, cognitive load thresholds, or context-awareness.
19. The method of item 11, wherein the captured content includes product packaging in a retail environment, and the correction overlays include shelf-side warnings or sourcing disclosures.
20. The method of item 11, wherein the entire process is performed on a wearable device, and the overlays are displayed through an augmented reality interface integrated into a smart glasses display.

### Embodiment AD: AI-Orchestrated Cloud Ownership Platform

### Field

The invention relates to systems and methods for managing digital content ownership in a cloud environment, and more particularly to a platform that enables users to purchase permanent access to digital media or software stored in the cloud, while optimizing infrastructure costs using artificial intelligence.

### Background

In recent years, the subscription model has become the dominant form of access to digital media and software. Platforms such as Spotify, Netflix, and Adobe Creative Cloud require ongoing payments in exchange for access. This results in high lifetime costs and a lack of ownership, especially for users who primarily consume the same set of content over extended periods. Traditional ownership models offered lower lifetime costs, but lack the convenience of cloud-based access.

There is a need for a hybrid system that combines the convenience of cloud access with the economic and psychological benefits of ownership, while ensuring that infrastructure costs remain manageable.

Cloud storage and bandwidth have become inexpensive, and artificial intelligence can be used to optimize the placement and delivery of digital assets.

### Summary

The present invention provides a cloud-based system where users may purchase permanent access to digital content such as music, video, eBooks, or software applications. After an initial purchase, the user pays only for minimal infrastructure costs associated with maintaining cloud access. The system utilizes an AI orchestration layer to optimize storage allocation, bandwidth usage, and cost efficiency.

### Detailed Description

A system is proposed that may include the following components: A digital ownership ledger may be used to store the proof-of-purchase and ownership data. This ledger may be implemented using a centralized or decentralized registry, such as a blockchain, and may allow users to demonstrate permanent ownership of specific digital content.

An AI infrastructure manager may dynamically allocate resources for the storage and retrieval of owned content. This manager may use usage frequency data, geolocation of users, and content access patterns to determine whether to store content in hot, warm, or cold cloud storage. The AI system may also predict user access patterns and pre-cache certain content when high access probability is detected.

A billing module may be used to calculate ongoing infrastructure costs based on actual usage. The costs may include bandwidth usage, storage duration, and access frequency. This billing model may ensure that users are not charged recurring license fees but only marginal infrastructure costs.

A digital media interface may provide access to owned content through a web browser, dedicated app, or smart device integration. This interface may offer convenience similar to subscription platforms, including features such as playlists, annotations, bookmarks, and software versioning.

A resale and inheritance framework may be implemented to allow transfer of owned content to other users. This transfer may be facilitated through a smart contract, peer-to-peer agreement, or centralized transfer function, depending on system design.

Optionally, the system may allow for fractional or cooperative ownership. For example, niche content or expensive software licenses may be jointly purchased by multiple users who share infrastructure costs proportionally. AI may arbitrate access time or deliver redundant copies for simultaneous use where permitted.

Security measures may include DRM-free but cryptographically signed access controls to ensure that only the rightful owner can access or transfer the content. Backup copies may be stored in separate data centers to ensure redundancy.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for managing digital content ownership in a cloud environment, comprising:
   a) a purchase module enabling a user to acquire permanent access rights to digital content;
   b) an AI-based infrastructure manager configured to allocate storage and bandwidth resources based on user access patterns;
   c) a billing system configured to calculate infrastructure costs without recurring licensing fees; and
   d) a content access interface configured to stream or deliver said digital content to the user from the cloud.
2. The system of item 1, wherein the digital content includes one or more of: music, video, text, and executable software.
3. The system of item 1, wherein said infrastructure manager is further configured to migrate digital content between hot, warm, and cold storage tiers based on predicted usage frequency.
4. The system of item 1, further comprising a digital ownership ledger configured to record content purchases and support content transfer between users.
5. The system of item 4, wherein said ledger is implemented as a cryptographically verifiable decentralized registry.
6. The system of item 1, further comprising a resale module enabling users to transfer or sell digital content ownership rights.
7. The system of item 1, further comprising an inheritance mechanism for assigning digital content ownership rights to another user upon death or disability.
8. The system of item 1, wherein said infrastructure manager is further configured to cache predicted high-access content in proximity to the user to reduce latency and cost.
9. The system of item 1, wherein said content access interface is configured to function on web, mobile, and embedded smart devices.
10. The system of item 1, wherein said content access interface supports DRM-free playback secured by user authentication and cryptographic validation of ownership.
11. A method for managing user-owned digital content in a cloud environment, comprising:
   a) receiving a purchase request for permanent access to a digital item;
   b) storing said item in a cloud-based storage system;
   c) recording ownership in a verifiable ledger;
   d) allocating said item to an appropriate storage tier based on access predictions by an AI manager;
   e) delivering said item to the user via a content access interface; and
   f) charging the user only for infrastructure costs post-purchase.
12. The method of item 11, further comprising enabling the user to transfer or resell ownership rights through the system.
13. The method of item 11, further comprising providing cooperative ownership among multiple users with proportionally distributed infrastructure fees.
14. The method of item 11, further comprising storing backup copies of digital items in redundant cloud locations for availability and data safety.
15. The method of item 11, further comprising identifying infrequently accessed items and migrating them to low-cost cold storage tiers.

### Embodiment ADE: AI-Orchestrated Cloud Ownership Platform

A cloud-based platform is disclosed that enables users to purchase permanent access rights to digital content while paying only metered infrastructure costs thereafter. An AI infrastructure manager predicts demand, allocates storage across hot, warm, and cold tiers, and stages content to edge caches to reduce latency and cost. A verifiable digital ownership ledger records entitlements, a metering subsystem emits cryptographically signed usage receipts, and a billing engine produces statements tied to storage, bandwidth, and compute. The platform supports cooperative ownership, resale and inheritance, interoperability via standardized APIs and the Model Context Protocol, and externally observable audit artifacts.

### Field

The invention relates to systems and methods for managing digital content ownership in a cloud environment, and more particularly to a platform that enables users to purchase permanent access to digital media or software stored in the cloud, while optimizing infrastructure costs using artificial intelligence.

### Background

In recent years, the subscription model has become the dominant form of access to digital media and software. Platforms such as Spotify, Netflix, and Adobe Creative Cloud require ongoing payments in exchange for access. This results in high lifetime costs and a lack of ownership, especially for users who primarily consume the same set of content over extended periods. Traditional ownership models offered lower lifetime costs, but lack the convenience of cloud-based access.

There is a need for a hybrid system that combines the convenience of cloud access with the economic and psychological benefits of ownership, while ensuring that infrastructure costs remain manageable. Cloud storage and bandwidth have become inexpensive, and artificial intelligence can be used to optimize the placement and delivery of digital assets.

### Summary

The present invention provides a cloud-based system where users may purchase permanent access to digital content such as music, video, eBooks, or software applications. After an initial purchase, the user pays only for minimal infrastructure costs associated with maintaining cloud access. The system utilizes an AI orchestration layer to optimize storage allocation, bandwidth usage, and cost efficiency.

### Gentle Introduction

Conventional subscription services deliver convenience but do not give users a durable right to access the particular content they value most over long periods. Ownership-based models historically delivered that durability but required local storage, manual backups, and device-bound licenses. The invention bridges these models by separating economic ownership from the mechanics of delivery. A user may acquire a permanent access right recorded in a verifiable ledger while an AI manager continuously optimizes where and how the user's content is stored and delivered across cloud tiers, caches, and regions. Intuitively, the platform behaves like a modem streaming service from the user's perspective, but the financial and legal posture aligns with purchase-and-own. The AI orchestration learns when a user tends to access content and stages it closer to the user at those times to reduce cost and delay. Metering isolates pure infrastructure costs so that, after purchase, the user's ongoing payments are small, measurable, and transparently tied to storage, bandwidth, and compute used to serve the owned asset.

### Examples

Example 1: Single-user purchase and playback of a song. A user selects a track and chooses permanent access. The purchase module verifies payment and writes an ownership record to the ledger. The AI infrastructure manager initially stores the asset in a warm tier and sets a prediction that the user is likely to play the track in the evening based on historical activity. As evening approaches, the AI manager pre-caches the track to an edge location near the user. When the user presses play in the content access interface, the system streams from the nearest cache if available, or from the origin if not, while the metering subsystem records storage dwell time and egress. The billing module subsequently produces a statement that includes only the marginal infrastructure costs. An example purchase receipt may be represented as JSON as follows:

{“receiptId”:“r-1001”,“userId”:“u-77”,“assetId”:“song-abc”,“right”:“permanent”,“timestamp”:“2025-0
6-01T19:22:31Z”,“signature”:“0xA1B2”} An example ledger entry may be represented as JSON as
follows:
{“ledgerTx”:“tx-555”,“assetId”:“song-abc”,“ownerId”:“u-77”,“right”:“permanent”,“prevOwnerId”:null
,“block”:“84219”,“hash”:“0x9f3c”} An example metering event may be represented as JSON as
follows:
{“eventId”:“m-7001”,“assetId”:“song-abc”,“tenantId”:“u-77”,“metric”:“egressBytes”,“value”:5242880
,“timestamp”:“2025-06-01T20:05:04Z”,“logHash”:“0x4cd2”}

Example 2: Cooperative ownership of a software license. Three users agree to jointly purchase a costly software tool. The platform creates a cooperative entitlement that allocates time windows and concurrency rules. The AI manager predicts overlapping usage and, where permitted by license policy, stages redundant instances for simultaneous use; otherwise it arbitrates access by assigning time slices and notifying users. Metering splits storage, egress for updates, and compute used for virtualization across the co-owners proportionally. An example cooperative entitlement may be represented as JSON as follows:

{“entitlementId”:“e-22”,“assetId”:“sw-pro-9”,“owners”:[{“userId”:“u-1”,“share”:0.4},{“userId”:“u-2”,
“share”:0.3},{“userId”:“u-3”,“share”:0.3}],“policy”:{“maxConcurrency”:1,“slotMinutes”:30},“schedul
erHint”:{“peakWindows”:[{“userId”:“u-1”,“start”:“18:00Z”,“end”:“21:00Z”},{“userId”:“u-2”,“start”:“
12:00Z”,“end”:“14:00Z”}]}} An example arbitration decision may be represented as JSON as follows:
{“decisionId”:“d-901”,“assetId”:“sw-pro-9”,“grants”:[{“userId”:“u-2”,“start”:“2025-06-02T12:00:00Z
”,“end”:“2025-06-02T12:30:00Z”},{“userId”:“u-1”,“start”:“2025-06-02T18:00:00Z”,“end”:“2025-06-
02T18:30:00Z}]}

Example 3: Resale and transfer with externally observable receipts. A user initiates a resale of an eBook to another user. The resale module checks transferability rules, locks the entitlement to prevent concurrent access, and generates a smart-contract-like transaction on the ledger. The metering subsystem emits a signed usage receipt correlating the final access by the seller and the first access by the buyer, which is published at a stable endpoint to provide an externally auditable record. The content's storage location is gradually migrated toward the buyer's region by the AI manager to reduce long-haul egress. An example transfer request may be represented as JSON as follows: {“transferId”:“t-300”, “assetId”:“book-xy1”, “fromUser”:“u-77”, “toUser”:“u-88”, “priceCents”:1500, “ti mestamp”:“2025-06-05T11:02:00Z”} An example usage receipt may be represented as JSON as follows: {“receiptld”:“ur-42”, “assetId”:“book-xy1”, “fromUser”:“u-77”, “toUser”:“u-88”, “lastAccessFrom”:“202 5-06-05T11:03:12Z”, “firstAccessTo”:“2025-06-05T11:05:47Z”, “egressBytes”:2097152, “signature”:“0 xC0FFEE”} The platform's AI and orchestration interfaces may be exposed to clients using the Model Context Protocol so that assistants, apps, or services can invoke planning and data access tools with standardized context passing. For example, a client could declare a tool that fetches entitlement status and metered costs for a given asset and user via MCP. An example MCP tool descriptor may be represented as JSON as follows:

{“tool”:“getEntitlementAndCost”,“inputSchema”:{“userId”:“string”,“assetId”:“string”},“returns”:{“ent
itled”:“boolean”,“currentMonthCostCents”:“number”},“endpoint”:“https://api.example.com/mcp/getE
ntitlementAndCost”} A client request payload may be represented as JSON as follows:
{“tool”:“getEntitlementAndCost”,“args”:{“userId”:“u-77”,“assetId”:“song-abc”}}

### Scope and Interpretation

The scope of the invention is defined solely by the claims. Any embodiments, examples, descriptions of features, or references to figures, if any are provided, are illustrative and non-limiting. Unless expressly stated otherwise in a claim, operations may be performed in alternative orders, steps may be omitted or added, components may be combined or separated, and implementations may vary across hardware, software, or combinations thereof. Terminology such as may, can, could, example, embodiment, and configured to is intended to be non-restrictive. No feature, advantage, or characteristic described in the specification should be construed as essential to the invention unless explicitly recited in a claim. For avoidance of doubt, references to a permanent access right encompass durable, non-expiring, non-time-limited, or perpetual entitlements that may be revocable only for cause or subject solely to infrastructure-cost billing, and cover equivalent terminology including perpetual license, lifetime access, or indefinite-right access. References to a cloud environment include public cloud, private cloud, sovereign cloud, hybrid cloud, edge-cloud deployments, and on-premises or enterprise data center deployments operated with cloud orchestration or content delivery networks. References to billing and charges encompass calculation of costs assessed to any party including the user, a sponsor, or a prepaid credit account, and include cases where calculated charges are zero; references to metering include generation of usage counters and receipts irrespective of whether such meters trigger monetary invoices, prepaid debits, or sponsor settlements.

### Detailed Description

A system is proposed that may include the following components: A digital ownership ledger may be used to store the proof-of-purchase and ownership data. This ledger may be implemented using a centralized or decentralized registry, such as a blockchain, and may allow users to demonstrate permanent ownership of specific digital content.

An AI infrastructure manager may dynamically allocate resources for the storage and retrieval of owned content. This manager may use usage frequency data, geolocation of users, and content access patterns to determine whether to store content in hot, warm, or cold cloud storage. The AI system may also predict user access patterns and pre-cache certain content when high access probability is detected.

A billing module may be used to calculate ongoing infrastructure costs based on actual usage. The costs may include bandwidth usage, storage duration, and access frequency. This billing model may ensure that users are not charged recurring license fees but only marginal infrastructure costs.

A digital media interface may provide access to owned content through a web browser, dedicated app, or smart device integration. This interface may offer convenience similar to subscription platforms, including features such as playlists, annotations, bookmarks, and software versioning.

A resale and inheritance framework may be implemented to allow transfer of owned content to other users. This transfer may be facilitated through a smart contract, peer-to-peer agreement, or centralized transfer function, depending on system design.

Optionally, the system may allow for fractional or cooperative ownership. For example, niche content or expensive software licenses may be jointly purchased by multiple users who share infrastructure costs proportionally. AI may arbitrate access time or deliver redundant copies for simultaneous use where permitted.

Security measures may include DRM-free but cryptographically signed access controls to ensure that only the rightful owner can access or transfer the content. Backup copies may be stored in separate data centers to ensure redundancy.

### Enablement

An embodiment may be built by provisioning cloud accounts that provide object storage with multiple performance tiers, a content delivery network with edge cache nodes, and compute for API and orchestration services. A digital ownership ledger may be instantiated as a centralized database with cryptographic signing or as a decentralized registry. An entitlement service may issue bearer tokens bound to user identity, asset identifiers, and rights, where an example entitlement token payload may be represented as JSON as follows: {“entitlementId”:“en-100”, “userId”:“u-77”, “assetId”:“song-abc”, “right”:“permanent”, “exp”:“2026-01-O1T00:00:00Z”, “sig”:“0xAA55”} The AI infrastructure manager may be implemented by training a prediction model using historical access events from the metering log, with features including hour of day, day of week, device type, region, and recency of access, and a placement controller may enforce policies that map predicted access probability to storage tier thresholds and prefetch decisions. A prefetch and cache controller may publish cache warming requests to edge locations when a prediction exceeds a configurable threshold for a time window.

The metering and telemetry subsystem may be implemented as an append-only log that accepts signed events from the content access interface, storage backends, and compute workers, where events include egress bytes, storage dwell, cache hits, and compute time, and where each event may carry a signature or hash chain pointer to ensure tamper evidence. A rating and pricing engine may apply tariffs to meters and aggregate per billing period. A billing module may expose statements and machine-readable summaries via HTTPS endpoints, and a client-facing dashboard may render per-asset costs. A lightweight device agent may implement an on-device hot cache that participates in tiering policies and optionally in peer-to-peer overlays among authorized devices; the billing module may be configured to route invoices to a sponsor account, decrement prepaid credits, or produce zero-dollar statements that nevertheless enumerate metered usage for auditability.

The Model Context Protocol may be integrated by exposing tools for entitlement checks, metered cost summaries, arbitration decisions, and usage receipts. A tool declaration for retrieving a per-user per-asset summary may be exposed as JSON as follows: {“tool”:“summarizeAsset”, “inputSchema”:{“userId”:“string”, “assetId”:“string”}, “returns”:{“entitled”: “boolean”, “storageBytes”:“number”, “egressBytesMonthToDate”:“number”, “currentMonthCostCents”: “number”}, “endpoint”:“https://api.example.com/mcp/summarizeAsset”} The content access interface may validate entitlements, request signed URLs or direct streaming from the nearest cache, and emit metering events synchronously with delivery. Deployment may proceed by configuring origin buckets for hot, warm, and cold tiers, defining lifecycle policies for tier transitions, setting cache time-to-live parameters, and connecting security services for signature validation. End-to-end testing may include purchase flows, playback under predicted and unpredicted access windows, cooperative scheduling with concurrency limits, and resale with entitlement locking and transfer receipts.

### Technical Effects

The placement and prefetch techniques may reduce user-perceived latency by staging content at edge locations before access peaks while lowering bandwidth and origin egress costs by increasing cache hit rates. Tiered storage allocation guided by predictions may reduce storage costs by migrating infrequently accessed items to cold storage without sacrificing availability for anticipated bursts.

Cryptographically signed, append-only metering may produce tamper-evident records that improve auditability and facilitate accurate billing and damages estimation. Cooperative scheduling may increase effective license utilization by arbitrating access across co-owners according to predicted demand and policy, thereby reducing overprovisioning. Migration of regional preference during resale may shorten data paths and reduce long-haul egress. MCP exposure may enable interoperable automation that reduces integration overhead and improves reliability of entitlement and cost queries.

### Flows

Process flows may be implemented as linear steps that correspond directly to method claims and could be rendered as flowcharts. A purchase and playback flow may begin with payment verification, proceed to ledger write of ownership, issuance of an entitlement token, initial tier placement by the AI manager, optional cache warm, access request by the user, validation of entitlement, streaming from cache or origin, and emission of signed metering events that are later rated and billed. A cooperative flow may accept a cooperative entitlement definition, schedule access windows under policy, stage compute or storage as needed, grant tokens bound to time slices, and meter usage per owner. A resale and transfer flow may lock the entitlement, validate transfer policy, write a transfer transaction to the ledger, emit a usage receipt that correlates last access by the seller and first access by the buyer, migrate preferred storage region, and publish receipts via APIs. In some deployments, rating may yield a zero-dollar invoice, a debit of prepaid credits, or a sponsor settlement while still publishing metered usage and receipts.

### External Observability

Externally observable behaviors may include published endpoints that return signed usage receipts, machine-readable billing summaries, current entitlement status, and arbitration decisions. Receipts may correlate identities, asset identifiers, timestamps, and byte counts with signatures verifiable by third parties. The platform may expose stable URLs that return the most recent signed receipt for an asset transfer or a monthly usage digest for an asset-user pair, enabling detection of unauthorized use by comparing observed traffic with entitled rights. MCP tools may provide a standardized interface for assistants and services to retrieve the same observables without direct access to internal systems. These observables may be emitted even in sponsor-paid or zero-invoice deployments to preserve external detectability of use and facilitate infringement verification.

### Interoperability Coverage

The platform may operate across heterogeneous networks and interfaces by supporting HTTP, HTTPS, QUIC, gRPC streaming, REST, GraphQL, webhooks, SDKs, peer-to-peer overlays, multicast within enterprise networks, and the Model Context Protocol. Storage and compute may be deployed in multi-cloud, single-tenant, or on-premises topologies, and content delivery may interoperate with third-party CDNs. Entitlement tokens and receipts may use standard cryptographic primitives to remain vendor-agnostic. These features may prevent avoidance of infringement through interface substitution or protocol changes because the invention may function with multiple platforms and protocols.

### Design-Around Resilience

Competitors may attempt to avoid infringement by substituting components, altering protocols, relocating functionality into third-party services, or changing billing semantics while still delivering durable rights with cloud delivery and infrastructure-only ongoing costs. The disclosure contemplates and includes such functional equivalents. An infrastructure manager includes any component, service, or policy, whether AI, heuristic, rules-based, or human-administered, that selects storage tier, cache residency, network path, or compute placement for owned content based on access patterns or policies. A billing system includes any module that computes, aggregates, or exposes costs or usage derived from meters, regardless of whether money is charged to the user, a sponsor, or a prepaid account, and regardless of whether invoices list zero-dollar totals. A digital ownership ledger includes any entitlement registry capable of verifying durable rights, including centralized databases, key-value stores, append-only logs, signed files synchronized across replicas, permissioned or permissionless ledgers, or hybrid mirrors thereof. A content access interface includes streaming, progressive download, full download with offline pack generation, virtualization for software execution, and any equivalent delivery that enforces entitlements. Prefetch and caching includes device-resident caches, peer-to-peer overlays among authorized devices, CDN-integrated caches, or private edge nodes under enterprise control. Protocol substitutions such as replacing REST with GraphQL, QUIC with HTTPS, or MCP with any standardized tool or capability interface that exposes entitlement, usage, or arbitration information remain within scope. Relocating metering to a CDN, client, or network appliance, batching meters, or publishing receipts via alternate endpoints remains within scope when signed, time-correlated records of storage, egress, or compute attributable to an entitlement are produced. Implementations that bundle metered costs into flat quotas, credits, or time-bounded bundles are included when the underlying metering and attribution are maintained. Embodiments that omit cryptography in favor of hardware isolation or watermark-based verification remain within scope when durable rights are enforced and externally observable usage or entitlement records are published. These clarifications reduce opportunities for design-around by defining the modules in terms of their externally observable behaviors and functional roles rather than specific internal technologies or vendor choices.

### Fallback Embodiments

Simpler or partial implementations may embody the inventive concept without advanced AI. The infrastructure manager may operate in a rules-based mode with heuristic thresholds for tiering and cache warm decisions. The digital ownership ledger may be centralized rather than decentralized, and resale or inheritance may be disabled in restricted deployments while permanent access and metered billing remain. DRM-free delivery with signed entitlement tokens may be replaced by encrypted DRM with license keys in regulated environments. Infrastructure costs may be prepaid or sponsor-covered such that the billing module computes charges but directs them to a third party or records a zero-dollar invoice while still publishing usage receipts. A local device cache may operate as the hot tier and may optionally participate in peer-to-peer sharing among authorized devices to reduce origin egress while maintaining entitlement enforcement. These configurations may continue to provide permanent access with infrastructure-only ongoing costs and externally observable receipts.

### Monetization

The platform may support a monetization framework that increases measurable economic value and enables assessment of damages through clear technical instrumentation. Ownership purchases may be transacted as one-time payments that grant permanent access rights as recorded in the digital ownership ledger. Post-purchase, the platform may recover infrastructure costs through metered billing based on storage consumption, bandwidth egress, and compute used for retrieval, transcoding, or replication. Deployments may also support sponsor-paid plans and prepaid credit models where charges are calculated against a sponsor account or a prepaid balance, and where zero-dollar user invoices are issued while metered usage remains recorded and externally observable. To support optional premium offerings, the system may provide subscription-model features including accelerated content delivery, expanded redundancy targets, offline pack generation, family or team sharing, administrative controls, compliance-grade retention, and priority caching. Enterprise and developer plans may expose administrative dashboards and APIs for bulk entitlement management, audit export, and policy enforcement, priced per user, per seat, or per API call.

To technically enable accurate monetization and damages estimation, the system may include a metering and telemetry subsystem that records per-asset and per-tenant events such as bytes stored over time, egress bytes, request counts, cache hit rates, compute milliseconds for processing, and storage tier dwell time. Each event may be time-stamped and cryptographically signed or hashed into an append-only log to provide tamper-evident usage receipts. A rating and pricing engine may transform raw meters into billable line items using configurable tariffs, regional coefficients, and time-of-day rates. An entitlement service may evaluate feature flags and plan rules to gate premium functions, issue revocable tokens for access, and enforce concurrency or seat limits. The billing module may generate user-visible statements, downloadable usage receipts, and machine-readable summaries via published endpoints to provide externally observable records of consumption and charges. These technical features may allow quantification of economic harm in the event of unauthorized use by correlating metered activity with entitled features and recorded ownership.

### Itemized List for Continuations

Embodiments can be described by the following itemized list. Each item is intended to provide standalone support for potential future claims, and the order or grouping of features may be varied without limitation.

Item 1: A system comprising a purchase module enabling a user to acquire permanent or non-expiring access rights to digital content, an AI-based infrastructure manager that allocates storage and bandwidth resources based on access patterns, a billing system that calculates infrastructure costs without recurring licensing fees, and a content access interface that streams or delivers the digital content from the cloud.

Item 2: The digital content of Item 1 including one or more of music, video, text, eBooks, documents, and executable software applications.

Item 3: The infrastructure manager of Item 1 migrating digital content between hot, warm, and cold storage tiers based on predicted usage frequency.

Item 4: A digital ownership ledger that records purchases and supports content transfer between users, integrated with the system of Item 1.

Item 5: The ledger of Item 4 implemented as a cryptographically verifiable decentralized registry.

Item 6: A resale module enabling users to transfer or sell digital content ownership rights, interoperable with the ledger of Item 4.

Item 7: An inheritance mechanism that assigns digital content ownership rights to a designated beneficiary upon death or disability.

Item 8: The infrastructure manager of Item 1 caching predicted high-access content in network proximity to a user to reduce latency and cost.

Item 9: The content access interface of Item 1 operating on web, mobile, and embedded smart devices.

Item 10: The content access interface of Item 1 supporting DRM-free playback secured by user authentication and cryptographic validation of ownership.

Item 11: A method comprising receiving a purchase request for permanent or non-expiring access to a digital item, storing the item in a cloud-based storage system, recording ownership in a verifiable ledger, allocating the item to an appropriate storage tier based on predictions by an AI manager, delivering the item via a content access interface, and charging only infrastructure costs post-purchase.

Item 12: The method of Item 11 further enabling transfer or resale of ownership rights through the system.

Item 13: The method of Item 11 further providing cooperative ownership among multiple users with proportionally distributed infrastructure fees.

Item 14: The method of Item 11 further storing backup copies of digital items in redundant cloud locations for availability and data safety.

Item 15: The method of Item 11 further identifying infrequently accessed items and migrating them to low-cost cold storage tiers.

Item 16: A non-transitory computer-readable medium storing instructions that, when executed by one or more processors, cause performance of the method of Item 11.

Item 17: The medium of Item 16 further causing recording of per-asset and per-tenant metering events including bytes stored over time, egress bytes, request counts, cache hit rates, compute milliseconds for processing, and storage tier dwell time in a cryptographically signed append-only log, and generation of user-visible statements and machine-readable summaries via published endpoints.

Item 18: A metering and telemetry subsystem configured to record per-asset and per-tenant events that are time-stamped and cryptographically signed or hashed into an append-only log.

Item 19: A rating and pricing engine that transforms raw meters into billable line items using configurable tariffs, regional coefficients, and time-of-day rates.

Item 20: A method further comprising exposing externally observable usage receipts by publishing downloadable usage records and machine-readable summaries that correlate metered activity with entitled features and recorded ownership.

Item 21: The infrastructure manager of Item 1 alternatively implemented using rule-based heuristics, control policies, or supervised models without requiring deep learning, and configurable to operate in AI-free fallback modes.

Item 22: The digital ownership ledger of Item 4 alternatively implemented as a centralized database, a permissioned or permissionless distributed ledger, a hybrid mirror of both, or via offline signed receipts that are later reconciled.

Item 23: The digital content of Item 2 further including game assets, firmware updates, 3D models, machine learning models, digital twins, and interactive experiences.

Item 24: Delivery protocols used by the content access interface of Item 1 including HTTP, HTTPS, QUIC, gRPC streaming, peer-to-peer overlays, or multicast within enterprise networks.

Item 25: Security modes including encrypted DRM with license keys, DRM-free delivery with signed entitlement tokens, hardware-backed keys via secure enclaves, and watermarking for forensic tracing.

Item 26: Deployment topologies including multi-tenant SaaS, single-tenant enterprise, on-premises appliance, sovereign cloud regions, and hybrid edge-cloud configurations.

Item 27: Prefetch and caching strategies including on-demand fetch only, scheduled prefetch windows, cost-aware prefetch thresholds, and just-in-time transcoding integrated with cache fill.

Item 28: Metering granularity including per-request, per-session, per-tenant aggregation, sampled metering for privacy, differential privacy noise addition, and regionalized meter segregation for tax and regulatory compliance.

Item 29: Externally observable publication of usage records via web endpoints, signed email receipts, public transparency feeds, and Model Context Protocol tools that expose entitlement and cost queries.

Item 30: Interoperability via REST, GraphQL, gRPC, webhooks, SDKs, and the Model Context Protocol for tools that retrieve entitlements, metered costs, arbitration decisions, and receipts.

Item 31: Sponsor-paid and prepaid-credit monetization modes in which metered infrastructure usage is computed and either billed to a sponsor account, debited from prepaid credits, or recorded as a zero-dollar invoice while maintaining publication of usage receipts.

Item 32: A device-resident hot cache tier that synchronizes with cloud tiers and optionally participates in peer-to-peer overlays among authorized devices to reduce origin egress while enforcing entitlements.

Item 33: Systems that meter usage and enforce quotas, concurrency, or fair-use policies even when no monetary invoice is emitted, with publication of signed usage receipts for external verification.

Item 34: Virtualized execution embodiments for software assets in which the infrastructure manager provisions and migrates compute instances or containers near predicted demand while attributing compute meters to the entitlement holder.

Item 35: Alternative billing semantics in which charges are computed as flat-rate quotas, bundles, or time-limited credits derived from metered usage so that invoice line items may be zero or constant while still correlating to underlying meters.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for managing digital content ownership in a cloud environment, comprising:
   a) a purchase module enabling a user to acquire permanent or non-expiring access rights to digital content;
   b) an infrastructure manager configured to allocate storage and bandwidth resources based on user access patterns;
   c) a billing system configured to calculate charges based at least on metered infrastructure usage; and
   d) a content access interface configured to stream or deliver said digital content to the user from the cloud.
2. The system of item 1, wherein the digital content includes one or more of: music, video, text, and executable software.
3. The system of item 1, wherein said infrastructure manager is further configured to migrate digital content between hot, warm, and cold storage tiers based on predicted usage frequency.
4. The system of item 1, further comprising a digital ownership ledger configured to record content purchases and support content transfer between users.
5. The system of item 4, wherein said ledger is implemented as a cryptographically verifiable decentralized registry.
6. The system of item 1, further comprising a resale module enabling users to transfer or sell digital content ownership rights.
7. The system of item 1, further comprising an inheritance mechanism for assigning digital content ownership rights to another user upon death or disability.
8. The system of item 1, wherein said infrastructure manager is further configured to cache predicted high-access content in proximity to the user to reduce latency and cost.
9. The system of item 1, wherein said content access interface is configured to function on web, mobile, and embedded smart devices.
10. The system of item 1, wherein said content access interface supports DRM-free playback secured by user authentication and cryptographic validation of ownership.
11. The system of item 1, further comprising a metering and telemetry subsystem configured to record per-asset and per-tenant events that are time-stamped and cryptographically signed or hashed into an append-only log.
12. The system of item 18, further comprising a rating and pricing engine configured to transform raw meters into billable line items using configurable tariffs, regional coefficients, and time-of-day rates.
11. A method for managing user-owned digital content in a cloud environment, comprising:
   a) receiving a purchase request for permanent or non-expiring access to a digital item;
   b) storing said item in a cloud-based storage system;
   c) recording ownership in a verifiable ledger;
   d) allocating said item to an appropriate storage tier based on access predictions by an AI manager;
   e) delivering said item to the user via a content access interface; and
   f) charging the user only for infrastructure costs post-purchase.
12. The method of item 11, further comprising enabling the user to transfer or resell ownership rights through the system.
13. The method of item 11, further comprising providing cooperative ownership among multiple users with proportionally distributed infrastructure fees.
14. The method of item 11, further comprising storing backup copies of digital items in redundant cloud locations for availability and data safety.
15. The method of item 11, further comprising identifying infrequently accessed items and migrating them to low-cost cold storage tiers.
16. The method of item 11, further comprising exposing externally observable usage receipts by publishing downloadable usage records and machine-readable summaries that correlate metered activity with entitled features and recorded ownership.
16. A non-transitory computer-readable medium storing instructions that, when executed by one or more processors, cause the processors to perform a method comprising:
   a) receiving a purchase request for permanent or non-expiring access to a digital item;
   b) storing the item in a cloud-based storage system;
   c) recording ownership in a verifiable ledger;
   d) allocating the item to an appropriate storage tier based on access predictions by an AI manager;
   e) delivering the item to the user via a content access interface; and
   f) charging the user only for infrastructure costs post-purchase.
17. The non-transitory computer-readable medium of item 16, wherein the instructions further cause recording of per-asset and per-tenant metering events including bytes stored overtime, egress bytes, request counts, cache hit rates, compute milliseconds for processing, and storage tier dwell time in a cryptographically signed append-only log, and generation of user-visible statements and machine-readable summaries via published endpoints.

### Embodiment AE: AI-Human Hybrid Accreditation System for Autonomous Degree Issuance

### Field

The invention relates to systems and methods for issuing degrees and certifications using AI-augmented assessments supported by expert peer review.

### Background

Traditional universities maintain a near-monopoly on formal degree issuance, often requiring high tuition fees and formal enrollment. This system creates financial and institutional barriers for many individuals who possess real-world skills and knowledge. Simultaneously, artificial intelligence has advanced to the point where it can evaluate knowledge, projects, and reasoning with high accuracy. When combined with oversight from verified domain experts, these tools can enable a scalable and fair alternative to university-based credentialing.

### Summary

The present invention provides a decentralized, AI-human hybrid system for awarding academic degrees and skill certifications. The system enables individuals to earn credentials without institutional enrollment by submitting their work, knowledge, or project outcomes for assessment by an AI evaluation engine and optional expert reviewers. Final credentials are verifiable, interpretable, and accessible through public or private registries.

### Detailed Description

A decentralized academic credentialing system may include:

An AI-based assessment engine configured to evaluate written, verbal, and project-based submissions. It may include natural language understanding, symbolic logic checking, and multimedia analysis capabilities.

A human expert peer review module, wherein accredited professionals in relevant fields may review candidate submissions, conduct interviews, or evaluate practical demonstrations. These experts may be compensated and continuously rated for fairness and accuracy.

A hybrid scoring engine may aggregate AI and human evaluations into a composite score used to determine credential issuance.

A credential issuance engine may generate a verifiable digital certificate and publish it to a public or private registry.

A credential narrative generator may create an interpretive document outlining the reasoning for issuance, including anonymized expert feedback and AI-verified achievements.

A progressive learning advisor may suggest personalized next steps for individuals based on identified knowledge gaps, enabling staged degree acquisition.

A security and anti-fraud subsystem may ensure the integrity of assessments and credentialing. This subsystem may include anti-cheating technology such as multi-angle video recording of the candidate during assessment periods, real-time audio monitoring to detect off-camera prompts or unauthorized assistance, and behavioral pattern recognition to flag anomalies in response timing or eye movement. All recordings may be securely stored and optionally reviewed by expert raters or the AI system itself.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for issuing academic degrees without institutional enrollment, comprising:
   a) an AI-based evaluation engine configured to assess submissions using academic rubrics;
   b) a human peer accreditation module comprising domain experts who review, interview, or test candidates;
   c) a scoring engine configured to aggregate AI and expert inputs into a composite evaluation;
   d) a credential issuance module configured to publish verifiable degree certificates; and
   e) a decentralized or centralized ledger configured to record issued credentials.
2. The system of item 1, further comprising a candidate learning advisor configured to recommend individualized learning paths based on evaluation gaps.
3. The system of item 1, further comprising a bias detection module configured to identify deviations in expert evaluations across multiple cases.
4. The system of item 1, wherein the peer accreditation module includes a reputation mechanism for rating expert reviewers based on accuracy and fairness.
5. The system of item 1, further comprising a credential narrative generator configured to produce a human-readable explanation of the credential issuance.
6. The system of item 1, wherein the credential may be issued even if the user did not participate in any institutionally affiliated coursework.
7. The system of item 1, wherein AI-assessed materials include written essays, code submissions, design artifacts, videos, or oral recordings.
8. The system of item 1, wherein the human expert review may occur via live video, asynchronous submissions, or structured challenge responses.
9. The system of item 1, wherein credentials may be shared, verified, and interpreted via an open recognition protocol compatible with employers or academic institutions.
10. The system of item 1, wherein degrees may be earned progressively and modularly, with partial credentials representing intermediate levels of mastery.
11. The system of item 1, further comprising an anti-cheating subsystem comprising multi-angle video recording of candidates during assessments, real-time audio monitoring for unauthorized assistance, and behavior tracking for detecting suspicious patterns.
12. The system of item 11, wherein the anti-cheating subsystem is configured to store all recordings in encrypted form and trigger review by either AI or human examiners based on detected anomalies.

### Embodiment AEE: AI-Human Hybrid Accreditation System for Autonomous Degree Issuance

A decentralized, AI-human hybrid credentialing system may issue academic degrees and certifications based on demonstrated capability rather than institutional enrollment. Candidates may submit artifacts such as code repositories, documents, designs, videos, datasets, or oral responses for analysis by an AI evaluation engine and optional expert reviewers. An evaluation orchestrator may coordinate tool invocations via Model Context Protocol adapters to produce auditable, structured outputs, which may be combined with expert ratings by a hybrid scoring engine to reach approve, defer, or reject decisions. Integrity safeguards may provide identity verification, proctoring, and anomaly detection. Approved credentials may be issued as verifiable records to centralized or decentralized registries with privacy-preserving verification and revocation. A monetization subsystem with cryptographically enforced entitlements and ledger-anchored usage logs may support subscription and usage-based models and facilitate damages quantification for unauthorized use.

### Field

The invention relates to systems and methods for issuing degrees and certifications using AI-augmented assessments supported by expert peer review.

### Background

Traditional universities maintain a near-monopoly on formal degree issuance, often requiring high tuition fees and formal enrollment. This system creates financial and institutional barriers for many individuals who possess real-world skills and knowledge. Simultaneously, artificial intelligence has advanced to the point where it can evaluate knowledge, projects, and reasoning with high accuracy.

When combined with oversight from verified domain experts, these tools can enable a scalable and fair alternative to university-based credentialing.

### Summary

The present invention provides a decentralized, AI-human hybrid system for awarding academic degrees and skill certifications. The system enables individuals to earn credentials without institutional enrollment by submitting their work, knowledge, or project outcomes for assessment by an AI evaluation engine and optional expert reviewers. Final credentials are verifiable, interpretable, and accessible through public or private registries.

### Description of the Drawings

No drawings are included in this application. In some embodiments and in potential continuation filings, figures may illustrate system architectures, process flows, data object relationships, module interactions, or example user interfaces corresponding to the textual descriptions provided herein.

### Anchor

This section enumerates core elements and their relationships so that the embodiments can be consistently interpreted across descriptions and examples. A candidate may operate a client device to submit one or more artifacts that constitute a submission. Artifacts may include code repositories, documents, designs, videos, datasets, or recorded oral responses, and may be referenced by one or more artifact uniform resource identifiers. Submissions may be received by an evaluation orchestrator that coordinates tools and reviewers. The AI-based assessment engine may provide natural language understanding, symbolic logic checking, code analysis, multimedia analysis, similarity analysis, and rubric scoring. The engine may invoke external tools via a Model Context Protocol adapter, where each tool invocation is auditable and returns structured outputs. Outputs may be combined into an evaluation packet containing AI rubric scores, tool metrics, similarity results, and evidence references.

A human expert peer review module may select one or more expert reviewers based on domain, reputation, availability, and conflict-of-interest rules. Experts may asynchronously or synchronously review the evaluation packet, inspect artifacts, conduct interviews or challenges, and return structured ratings, free-form feedback, and integrity annotations. A bias detection component may analyze reviewer patterns across cases and flag deviations for moderation. A hybrid scoring engine may normalize AI and expert inputs, compute a composite score, and determine a decision state such as approve, defer with recommendations, or reject. Decision thresholds and confidence bands may be policy-controlled per credential type.

A security and anti-fraud subsystem may provide identity verification, multi-angle video and audio proctoring, behavior and timing analysis, and anomaly detection. Integrity flags may be attached to the evaluation packet and may require secondary review before approval. A credential issuance engine may construct a verifiable credential containing subject, issuer, type, issue date, and cryptographic proof, and may write an issuance record to a registry that may be centralized or decentralized. A credential narrative generator may produce a human-readable rationale with anonymized evidence references and reviewer feedback. A verification service may expose an endpoint that returns credential status, revocation state, and privacy-preserving proofs. A revocation mechanism may update registry state and produce revocation proofs. A progressive learning advisor may generate targeted recommendations and learning paths using gaps identified by the scoring engine.

A monetization subsystem may include an entitlements and metering service that issues signed entitlements to tenants, validates usage on each API call, decrements counters, and appends tamper-evident usage records to an append-only log anchoring to a ledger. Enforcement points may reside in the evaluation orchestrator, Model Context Protocol adapters, proctoring services, and issuance endpoints so that operations are executed only when entitlements are valid. Reports may summarize usage with non-repudiable linkage to evaluation identifiers and credential identifiers.

Data objects that may recur across flows include candidate identifiers, evaluation identifiers, reviewer identifiers, credential identifiers, artifact identifiers, integrity flags, rubric score maps, composite scores, and signatures. Control relationships include the orchestrator invoking tools, the AI engine emitting scores, experts emitting ratings, the scoring engine deciding issuance, the issuance engine writing to a registry, the verification service answering lookups, and the entitlements service gating operations. Feedback relationships include the advisor generating recommendations that reference identified gaps and the narrative generator linking to evidence traces. The foregoing element and relationship mapping is illustrative and non-limiting.

In practice it is preferred to implement an autonomous degree issuance system in which academic records and credentials are digitally verified and issued with cryptographic signatures, which leads to reduced reliance on paper-based certificates, books, and manual transcript handling. As a result, students and institutions no longer need to engage in redundant printing, mailing, or archiving, and travel to university offices for document verification is minimized. More specifically, the system produces the effect of improving the efficiency and reliability of credential management because secure digital issuance reduces processor cycles associated with manual validation and storage duplication, which results in measurable improvements in system performance. Since reduced paper production and reduced travel correlate directly with lower energy consumption, the invention also indirectly achieves a lower carbon footprint, while its primary effect is improved automation, security, and efficiency of credential management.

### Gentle Introduction

Conventional degrees often depend on time spent in classrooms and institutional affiliation rather than demonstrated capability. In contrast, the disclosed system focuses on what a candidate can actually do. A candidate may submit work products such as essays, code, designs, or videos and may optionally participate in interviews or challenges conducted by experts. An AI evaluation engine may analyze these materials to check for correctness, depth of understanding, originality, and adherence to academic rubrics, while human experts may provide qualitative judgment and context-sensitive review.

The system may blend the AI's consistent, scalable analysis with expert reviewers' domain insight. By combining these inputs into a composite score, the system may determine when a candidate has reached a threshold of mastery warranting a degree or certification. The result may be a credential that is verifiable and interpretable by employers or institutions, accompanied by a narrative explaining how the decision was reached and what strengths or gaps were observed.

To make the pathway accessible, the system may advise candidates on targeted next steps, suggesting resources or projects that address identified gaps. Integrity safeguards may preserve trust by monitoring assessments for unauthorized assistance and by flagging anomalies for review. The overall experience may feel like working with a personalized evaluation service that recognizes real-world skill, provides actionable feedback, and issues credentials when mastery is demonstrated rather than when a course list is completed.

### Examples

The following example scenarios illustrate concrete end-to-end flows that occur in practice when using the system. These walkthroughs show how submissions are ingested, how the AI evaluation engine and human expert peers interact, how decisions are recorded, and how credentials may be issued and verified. For software integrations, Model Context Protocol may be used so that tools can be composed in a controlled way while maintaining auditability of calls and responses. Example data structures are provided as compact inline JSON so they can be readily adapted to real implementations.

Example 1: Software engineering degree via repository submission. A candidate registers an account and consents to integrity monitoring. The candidate provides a link to a code repository and a short technical write-up. The AI evaluation engine retrieves artifacts and executes tests using a Model Context Protocol tool that can safely clone the repository, run unit and integration tests in a sandbox, and capture code quality metrics. The engine checks correctness against reference tests, examines cyclomatic complexity and documentation density, and runs static analysis. The anti-fraud subsystem runs multi-angle webcam recording while the candidate performs a timed coding extension task and captures audio to detect off-camera prompts. The system generates an evaluation packet that includes test outcomes, code metrics, and AI rubric scores, and routes the packet to two human expert reviewers selected by reputation and domain match. Each expert reviews the repository structure, the write-up, and a short live coding interview recorded for audit. The hybrid scoring engine combines AI rubric scores and normalized expert ratings to compute a composite. If the composite exceeds the degree threshold with sufficient confidence and no unresolved integrity flags, the credential issuance engine produces a signed digital certificate and writes a record to a registry selected by the candidate. The credential narrative generator produces a concise explanation with strengths, gaps, and links to anonymized evidence traces. Example request and result messages may resemble the following. A request to evaluate is represented as

{“candidate_id”:“cand_48291”,“submission_type”:“repository”,“artifact_uri”:“https://example.com/git
/repo123”,“requested_credential”:“BSc.SoftwareEngineering”,“mcp_tools”:[“git.clone”,“sandbox.run_{—}
tests”,“static_analysis.lint”],“integrity_mode”:“proctored_video_audio”,“requested_reviewers”:2}.
The evaluation result may be
{“evaluation_id”:“eval_90217”,“ai_scores”:{“correctness”:0.92,“code_quality”:0.84,“documentation”:
0.78},“expert_scores”:[{“reviewer_id”:“rev_11”,“score”:0.88},{“reviewer_id”:“rev_34”,“score”:0.91}
],“integrity_flags”:[ ],“composite_score”:0.89,“decision”:“approve”}. The credential record written to a
registry may be
{“credential_id”:“cred_77102”,“subject”:“did:example:cand_48291”,“type”:“Degree”,“name”:“BSc.S
oftwareEngineering”,“issuer”:“did:example:issuer_01”,“issue_date”:“2025-06-01”,“evidence_uri”:“htt
ps://example.com/registry/eval_90217”,“signature”:“0xabc123”}.

Example 2: Design certification via portfolio and asynchronous critique. A candidate uploads a portfolio PDF and links to short videos explaining design choices. The AI evaluation engine uses multimedia analysis to extract text from slides, detect layout consistency, and assess originality by comparing against a corpus with similarity thresholds. Using Model Context Protocol, the engine invokes a tool to check color contrast compliance and accessibility metadata. Two human experts asynchronously annotate the portfolio with time-coded comments and assign scores on criteria such as usability rationale and iterative refinement. The hybrid scoring engine merges AI and human signals, and the system generates targeted recommendations if thresholds are narrowly missed. If approved, a certificate is issued and recorded in a private registry, with a narrative describing the critique and summarizing evidence. An example recommendations response looks like

{“evaluation_id”:“eval_55310”,“decision”:“defer”,“composite_score”:0.73,“recommended_actions”:[{
“task”:“Add accessibility annotations to components
library”,“resources”:[“https://a11y.example/guide”]},{“task”:“Run 5-user usability test and summarize
findings”,“resources”:[“https://ux.example/test-protocol”]}]}.

Example 3: Oral knowledge demonstration with strict proctoring. A candidate opts for a live oral exam. The system schedules a session with one expert and activates integrity safeguards including continuous identity verification and room-silence detection. The AI engine transcribes the conversation, scores reasoning steps against a rubric, and highlights claims requiring citation. The expert marks correctness and depth, while the anti-fraud subsystem flags an anomaly when off-camera whispering is detected, triggering a secondary reviewer. The secondary review resolves the flag as benign due to ambient noise and the evaluation proceeds to approval. The issuance engine publishes a verifiable certificate to a decentralized ledger and provides a verification endpoint that returns status and selected, privacy-preserving proofs. A verification response may be

{“credential_id”:“cred_88012”,“status”:“valid”,“issuer”:“did:example:issuer_01”,“subject”:“did:exam
ple:cand_60012”,“revocation_status”:“not_revoked”,“proof_summary”:“zkp_range_proof_v1”}.

### Enablement

This section provides step-by-step instructions sufficient for a skilled person to build working embodiments, including concrete implementation guidance for Model Context Protocol integration and compact JSON data structures.

A builder may first provision identity and keys for issuers and services. An issuer identifier may be generated as a decentralized identifier or equivalent, and signing keys may be stored in a hardware-backed module. An example issuer profile may be {“issuer_id”:“did:example:issuer_01”, “pubkey”:“0x02ab . . . ”, “alg”:“secp256k1”}.

Next, an entitlements and metering service may be deployed to gate all subsystem operations. The service may expose an endpoint that issues short- and long-lived usage tokens after payment or admin approval. Each API in the platform may require a tenant identifier and two headers, one carrying an entitlement token and one carrying a detached signature over a compact claim. A representative call header payload may be {“tenant”:“ten_123”, “action”:“sandbox.run_tests”, “units”:12, “ts”:“2025-06-01T12:30:00Z”, “eval_id”: “eval_90217”}. The server may verify signatures using the tenant's registered public key, decrement counters, and append a record to an append-only log. The log may be hash-chained and periodically anchored to a ledger to provide external auditability, while remaining operable during ledger outages by queueing anchors.

An evaluation orchestrator may then be implemented as a stateless service backed by a durable job queue. The orchestrator may offer endpoints to create submissions, attach artifact identifiers, and request credential types. Upon submission, the orchestrator may validate entitlements and place an evaluation job referencing artifact uniform resource identifiers and requested Model Context Protocol tools.

A Model Context Protocol gateway and adapter layer may be deployed to safely invoke external tools with auditability. Each adapter may declare a minimal schema for inputs and outputs, enforce resource limits and network egress policies, and emit structured results with provenance. For example, a repository test adapter may accept

{“tool”:“sandbox.run_tests”,“repo_uri”:“https://example.com/git/repo123”,“test_profile”:“ci_default”}
and return
{“tool”:“sandbox.run_tests”,“ok”:true,“passed”:421,“failed”:3,“coverage”:0.87,“trace_uri”:“s3://traces/
eval_90217/rt1”}; a static analysis adapter may accept
{“tool”:“static_analysis.lint”,“repo_uri”:“https://example.com/git/repo123”,“ruleset”:“pep8_strict”}
and return
{“tool”:“static_analysis.lint”,“issues”:37,“critical”:2,“summary_uri”:“s3://traces/eval_90217/lint1”}; a
multimedia adapter may accept
{“tool”:“multimedia.ocr”,“video_uri”:“https://example.com/vid/abc.mp4”} and return
{“tool”:“multimedia.ocr”,“text_sha256”:“b1c2...”,“frames_sampled”:240,“artifact_uri”:“s3://traces/eva
l_55310/ocr1”}.

An AI-based assessment engine may be integrated to transform tool outputs and artifacts into rubric-aligned scores. The engine may load domain-specific rubrics expressed as criterion-weight maps and may implement calibration against gold-standard exemplars. During calibration, the engine may compute scale and bias corrections so that criterion scores align with expert distributions, storing parameters per credential type. The engine may accept

{“eval_id”:“eval_90217”,“artifact_uris”:[“https://.../repo123”],“tool_results”:[...]} and emit
{“eval_id”:“eval_90217”,“ai_scores”:{“correctness”:0.92,“code_quality”:0.84,“documentation”:0.78},
“explanations_uri”:“s3://traces/eval_90217/ai_expl”}.

A reviewer marketplace and peer review portal may be deployed to onboard, vet, and schedule experts. Reviewer profiles may include domain tags, reputation, availability windows, and conflict-of-interest declarations. The system may select reviewers using a matching function that filters by domain, enforces conflicts, and optimizes for coverage and latency. Review tasks may present the evaluation packet with linked evidence and capture structured ratings plus free-form feedback. A review submission may be

{“evaluation_id”:“eval_90217”,“reviewer_id”:“rev_11”,“scores”:{“architecture”:0.86,“maintainability
”:0.90},“feedback_uri”:“s3://reviews/eval_90217/rev_11”}.

A hybrid scoring engine may normalize AI and expert inputs to a common scale, apply policy-controlled weights, and compute a composite score and confidence. Normalization may include z-score or percentile mapping using rolling windows per credential type. The engine may apply inter-rater reliability statistics to down-weight outlier reviews and may record thresholds and confidence bands as versioned policy. The decision record may be

{“evaluation_id”:“eval_90217”,“composite_score”:0.89,“confidence”:0.94,“decision”:“approve”,“poli
cy_version”:“policy_deg_bsc_se_v3”}.

Integrity subsystems may be configured to capture and analyze proctoring signals. A proctoring collector may record multi-angle video and audio with liveness checks and may ingest device telemetry such as focus changes, keystroke cadence, and screen events according to jurisdictional policy. Signal processors may emit flags such as {“evaluation_id”:“eval_90217”, “flag_type”:“audio_prompt_detected”, “severity”:“medium”, “segment”:“00:12:31-00:13:05”} that require secondary review before approval. All recordings may be encrypted at rest, with access logged and gated by least-privilege roles.

Upon approval, a credential issuance engine may construct a verifiable record and write it to a selected registry. A W3C Verifiable Credential style object may be {“credential_id”:“cred_77102”, “@context”:[“https://www.w3.org/2018/credentials/v1”], “type”:[“Verif iableCredential”, “Degree”], “issuer”:“did:example:issuer_01”, “issuanceDate”:“2025-06-01T00:00:00Z”, “credentialSubject”:{“id”:“did:example:cand_48291”, “degree”:{“type”:“BSc.SoftwareEngineering”}}, “proof”:{“type”:“EcdsaSecp256k1Signature2019”, “jws”:“eyJhbGciOiJ . . . ”}} and an Open Badges style record or a centralized database entry may be used alternatively. A verification service may expose a read-only endpoint that, given a credential identifier or proof, returns status, revocation state, and privacy-preserving proof summaries without disclosing underlying artifacts. Revocation may be implemented by updating a registry list or status endpoint and emitting a revocation proof such as {“credential_id”:“cred_77102”, “revoked”:true, “revocation_ts”:“2025-07-15T10:00:00Z”, “proof”:“0xr evabc”}.

Deployment considerations may include containerizing services, configuring autoscaling based on service-level objectives, and isolating tool adapters in restricted sandboxes with deterministic trace capture. Offline-capable embodiments may queue issuance and anchoring operations for later synchronization. Regionalized deployments may substitute localized rubrics and reviewer pools while reusing the shared orchestration, scoring, and issuance infrastructure.

Validation and test procedures may include seeding the system with gold-standard evaluations, replaying recorded tool results to verify determinism, and exercising adversarial integrity scenarios with known benign and malicious patterns. Regression suites may verify that composite scores and decisions remain within tolerance after model or policy updates, using archived evaluation packets as fixtures to reproduce full pipeline executions.

### Detailed Description

The following description provides example embodiments to facilitate understanding. The scope of the invention is defined solely by the claims. Any particular architectures, parameters, sequencing, or technologies described herein are illustrative and non-limiting; alternative configurations may be substituted. Any examples or drawings, if present, are provided for clarity and are not restrictive.

Steps in any described flows may be performed in different orders, in parallel, or with additional or fewer intermediate operations unless explicitly stated otherwise. Features described in connection with one embodiment may be combined with features of another embodiment unless technically incompatible.

A decentralized academic credentialing system may include:

An AI-based assessment engine configured to evaluate written, verbal, and project-based submissions.

It may include natural language understanding, symbolic logic checking, and multimedia analysis capabilities.

A human expert peer review module, wherein accredited professionals in relevant fields may review candidate submissions, conduct interviews, or evaluate practical demonstrations. These experts may be compensated and continuously rated for fairness and accuracy.

A hybrid scoring engine may aggregate AI and human evaluations into a composite score used to determine credential issuance.

A credential issuance engine may generate a verifiable digital certificate and publish it to a public or private registry.

A credential narrative generator may create an interpretive document outlining the reasoning for issuance, including anonymized expert feedback and AI-verified achievements.

A progressive learning advisor may suggest personalized next steps for individuals based on identified knowledge gaps, enabling staged degree acquisition.

A security and anti-fraud subsystem may ensure the integrity of assessments and credentialing. This subsystem may include anti-cheating technology such as multi-angle video recording of the candidate during assessment periods, real-time audio monitoring to detect off-camera prompts or unauthorized assistance, and behavioral pattern recognition to flag anomalies in response timing or eye movement.

All recordings may be securely stored and optionally reviewed by expert raters or the AI system itself.

### Technical Effects

The disclosed orchestration of AI tool invocations via a Model Context Protocol adapter may yield deterministic, auditable evaluations that reduce integration complexity and improve reproducibility. By constraining external tools behind adapters that emit structured outputs with provenance, the system may achieve lower error rates in tool chaining, faster re-execution of evaluations, and more reliable evidence trails that facilitate verification and appeals.

The hybrid scoring engine that normalizes AI rubric outputs and human expert ratings may produce higher reliability and robustness against outliers than either source alone. By calibrating against gold-standard exemplars and applying inter-rater reliability statistics, the system may reduce variance across evaluations, curb individual reviewer bias, and improve confidence estimation, which in turn may allow tighter decision thresholds without sacrificing fairness.

The bias detection component that monitors reviewer behavior over time may deliver early detection of drift or inconsistent scoring, enabling targeted retraining or reassignment. This may reduce systemic bias accumulation and stabilize credentialing outcomes in large-scale deployments where reviewer pools change.

The security and anti-fraud subsystem that fuses identity verification, multi-angle video, audio analysis, behavior and timing signals may increase integrity by detecting unauthorized assistance with lower false negatives. Sandboxed execution of code with deterministic trace capture may further prevent network exfiltration and enforce resource limits, which may mitigate cheating and malware risks while preserving reproducibility for later audits.

The credential issuance and verification mechanisms that employ verifiable credentials, revocation proofs, and privacy-preserving verification may enable constant-time verification by third parties without disclosing underlying artifacts. Selective disclosure and zero-knowledge proofs may reduce data exposure risk while maintaining trust, and on-demand revocation queries may shorten response times when credentials are suspended or withdrawn.

The entitlements and metering service with tamper-evident, ledger-anchored usage logs may provide externally verifiable consumption accounting that deters unlicensed use and simplifies incident response. Verifiable usage headers on API calls may create network-layer observability that allows automated denial of unauthorized operations and post hoc reconstruction of activity with cryptographic assurances.

The progressive learning advisor that derives recommendations from identified gaps may shorten candidate remediation cycles and reduce unnecessary reassessments, which may lower compute and reviewer workload while improving throughput. Closed-loop incorporation of outcomes and optional employer feedback may refine rubrics over time, improving predictive validity of credentials.

Offline-capable or air-gapped deployments with deferred registry anchoring may maintain functionality in restricted networks while preserving auditability through scheduled synchronization. Regionalized and localized configurations may adapt models and rubrics to jurisdictional norms, improving scoring relevance and reducing localization errors.

Calibration workflows for both AI and human reviewers may align scales across domains, leading to consistent composite scores that support cross-credential comparability. Workload-aware orchestration may scale tool adapters and reviewer queues based on service-level objectives and entitlement quotas, improving latency predictability during demand spikes.

### Workaround-Resistant Coverage

The inventive concept may be understood as the combination of auditable tool-orchestrated assessment, calibrated hybrid or AI-only scoring, and verifiable credential lifecycle services with entitlement-gated execution. Embodiments may therefore cover functionally equivalent implementations that vary interfaces, topology, or component partitioning without departing from these invariants. Tool orchestration may be performed via any adapter or gateway pattern that constrains tools behind typed inputs and outputs with provenance, including but not limited to HTTP, gRPC, message queues, function-as-a-service runtimes, shared-nothing pipelines, or in-process sandboxes that emit structured traces. Scoring may include any algorithmic normalization and aggregation of machine and human inputs into a decision signal, including rubric-weighted models, rule-based evaluators, statistical calibrations, machine learning models, or ensemble combinations that yield a composite and confidence with policy-controlled thresholds. Credential lifecycle services may include any issuance, verification, and revocation mechanism that binds subject, issuer, type, time, and proof and may be realized using centralized databases, distributed ledgers, verifiable credential formats, open badges, DNS records, or hybrid stores.

Topological variations may include cloud-hosted, on-premises, edge, or client-side execution, as well as single-tenant or multi-tenant deployments, monoliths or microservices, and synchronous or asynchronous workflows. Rearrangement of modules such that proctoring, scoring, or issuance occurs partially on device and partially on server may remain within scope when auditable evidence, composite decisioning, and verifiable credential state are preserved. Substitution of integrity modalities, including biometrics, hardware attestation, network forensics, similarity analysis, screen and input telemetry, or environmental sensors, may be treated as equivalent when signals feed anomaly detection and secondary review gating prior to issuance.

Interoperability differences may not avoid coverage when adapters translate to local tool ecosystems or proprietary APIs, provided calls are mediated by an adapter that enforces schemas, limits, and provenance. Replacement of the Model Context Protocol with any protocol that offers structured invocation and traceable outputs may be regarded as an equivalent mechanism. Likewise, replacement of ledger anchoring with other tamper-evidence constructions such as transparency logs, notary timestamping, or secure enclaves that attest to append-only properties may be treated as equivalent observability for usage and issuance events.

External observability may be preserved across implementations because infringing systems will typically expose verification endpoints returning credential state or proofs, publish verifiable records that encode subject, issuer, type, and proof material, and emit recognizable evaluation artifacts such as narratives or evidence references that may be watermarked or signed. Entitlement-gated execution may be externally observable through signed usage headers, challenge-response handshakes at transport or application layers, rate limiting linked to tenant identifiers, or audit exports that include non-repudiable evaluation and credential identifiers. These signals may enable proof of use even when internal source code is not available.

Simplified or partial implementations may remain within scope when they implement AI-only evaluations that issue micro-credentials, human-only reviews that still pass through calibrated normalization and issuance, offline or air-gapped issuance with deferred anchoring, or federated co-signing where multiple issuers contribute partial evaluations. Relabeling of components, substitution of data schemas, or changes in the order of operations may not avoid coverage when the evidence acquisition, calibrated decisioning, and verifiable issuance invariants are maintained.

### Monetization and Damages Considerations

The system may be operated under subscription and usage-based commercial models that are technically enforced to enable accurate accounting of use and to support damages calculations in the event of unauthorized deployment. A subscription model may include per-organization seat licensing for administrators and reviewers, per-candidate evaluation credits that decrement upon each evaluation lifecycle event, and tiered service levels that enable or disable features such as proctored integrity modes, accelerated reviewer assignment, storage retention duration for evidence, and issuance to public versus private registries. Usage-based components may be metered by counting discrete, signed events such as submission ingests, tool executions via Model Context Protocol, minutes of proctored audio and video captured, invocations of sandboxed test runs, issuance operations that produce signed credentials, verification endpoint lookups, and storage bandwidth consumed when retrieving evidence traces.

Technical features may include an entitlements and metering service that issues cryptographically signed entitlements to tenants, where each API call includes a tenant identifier and an entitlement token carried in a header such as X-Entitlement-ID and a detached signature such as X-Usage-Signature over a compact usage claim payload such as {“tenant”:“ten_123”, “action”:“sandbox.run_tests”, “units”:12, “ts”:“2025-06-01T12:30:00Z”, “eval_id”: “eval_90217”}. The server may verify signatures, decrement counters, and append a tamper-evident record to an append-only log whose hash chain anchors to a public or private ledger at periodic intervals, enabling independent audit of consumption. Entitlements may specify concurrency limits, daily and monthly rate limits, and feature flags controlling access to tools including proctoring, static analysis, similarity checks, and issuance modules. Enforcement points may reside at each subsystem boundary so that Model Context Protocol tool adapters, evaluation orchestrators, and issuance endpoints all perform entitlement checks before executing operations.

To facilitate claims of monetary harm, the system may expose exportable, signed reports that summarize usage by category such as evaluations performed, credentials issued, proctoring minutes recorded, reviewer hours scheduled, and verification lookups served, with per-tenant and per-user breakdowns and with non-repudiable linkage to evaluation identifiers and credential identifiers. The issuance records may embed a billing reference so that a credential can be externally audited for paid status without revealing private data, allowing third parties to corroborate counts. Revocation and suspension mechanisms may disable features when entitlements are exhausted or payments are delinquent, with revocation proofs logged in the same append-only ledger. For interoperability with different payment providers and marketplaces, the entitlements service may map external purchase receipts to internal tokens and may support just-in-time issuance of short-lived usage grants so that consumption continues during brief payment gateway outages. These mechanisms may deter unlicensed use, make unauthorized use externally observable through missing or invalid entitlements on API calls, and enable precise quantification of usage for licensing and damages purposes.

### Continuation-Ready Itemized List of Embodiment Features

Embodiments can be described by the following itemized list, which is suitable for direct use in future continuations and includes items corresponding to each numbered claim herein as well as additional variations and alternatives for broadened coverage: 1) a system comprising an AI-based evaluation engine, a human peer accreditation module, a scoring engine, a credential issuance module, and a registry or ledger that records issued credentials; 2) a candidate learning advisor that recommends individualized learning paths based on evaluation gaps; 3) a bias detection component that detects deviations or drift in expert evaluations across multiple cases; 4) a reviewer reputation mechanism that maintains accuracy and fairness ratings for experts and influences selection; 5) a credential narrative generator that produces human-readable explanations of issuance decisions with anonymized evidence references; 6) issuance of credentials independent of institutional course participation; 7) AI evaluation of essays, code repositories, design artifacts, videos, oral recordings, datasets, or other digital artifacts; 8) human expert reviews conducted synchronously or asynchronously, including live video sessions, annotated critiques, and structured challenge responses; 9) compatibility with open credential recognition and verification protocols used by employers and institutions; 10) progressive and modular degrees with partial credentials or stackable micro-credentials that represent intermediate mastery; 11) integrity safeguards including multi-angle video capture, real-time audio monitoring, keystroke and behavior tracking, device telemetry, and timing analysis; 12) encrypted storage of integrity recordings and automated anomaly-triggered AI or human secondary review; 13) an entitlements and metering service issuing signed usage tokens that gate evaluation, proctoring, tooling, and issuance operations; 14) an append-only usage log with a hash chain anchored periodically to a public or private ledger; 15) a Model Context Protocol adapter layer through which the AI engine invokes external tools with auditable structured outputs; 16) a verification endpoint that returns credential status, revocation state, and privacy-preserving proof summaries; 17) a revocation mechanism that updates registry state and issues revocation proofs; 18) reviewer selection subject to conflict-of-interest policies and based on domain expertise, reputation, and availability; 19) policy-controlled thresholds and confidence bands per credential type that yield approve, defer-with-recommendations, or reject decisions; 20) integrity flags that, when present, require secondary review before approval finalization; 21) a method embodiment comprising steps of receiving artifacts, orchestrating AI tool invocations via Model Context Protocol, collecting expert inputs, computing a composite score, determining a decision state, and issuing or declining a credential; 22) a non-transitory computer-readable medium storing instructions that cause processors to perform evaluation orchestration, entitlement verification, hybrid scoring, issuance, verification, and revocation; 23) an apparatus comprising processors, memory, and secure enclaves configured to perform proctoring signal capture and on-device preliminary scoring prior to server-side adjudication; 24) alternative registries including centralized databases, W3C Verifiable Credentials stores, Open Badges repositories, DNS-based records, permissioned ledgers, or public blockchains; 25) privacy-preserving implementations employing zero-knowledge proofs, redaction tokens, selective disclosure, or blinded signatures in verification and issuance; 26) reviewer marketplace embodiments where experts enroll, are vetted, scheduled, compensated, and audited, with surge-pricing or batching modes to optimize throughput; 27) fallback operation modes where micro-credentials or preliminary badges are issued based on AI-only scoring, with final degree issuance requiring hybrid human-AI confirmation; 28) proctoring modalities including device attestation, network forensics, plagiarism and similarity analysis, screen recording, gaze estimation, and ambient device detection; 29) interoperability with multiple payment and licensing systems including subscription billing, prepaid credits, marketplace vouchers, enterprise license keys, and just-in-time entitlement grants; 30) federation across institutions where multiple issuers co-sign or co-endorse a credential, each contributing partial evaluations; 31) calibration workflows where gold-standard rubric exemplars and inter-rater reliability statistics are used to normalize both AI and expert scores; 32) continuous learning loops where outcomes and employer feedback are optionally ingested to refine rubrics and reviewer weighting; 33) accessibility-first embodiments that evaluate and enforce compliance with accessibility standards and provide accommodations within assessments; 34) offline-capable or air-gapped deployments where evaluations occur in restricted environments and synchronization to registries and ledgers happens in scheduled windows; 35) regionalization and localization features that adapt rubrics, language models, and reviewer pools to jurisdictional norms and legal requirements; 36) audit and e-discovery tools that export signed evaluation packets, usage logs, and issuance artifacts with chain-of-custody metadata; 37) sandboxed execution environments that enforce resource and network controls for submitted code and capture deterministic traces for reproducibility; 38) candidate identity verification using multimodal biometrics, liveness detection, and continuous re-authentication during assessments; 39) workload-aware orchestration that dynamically scales tool adapters and queues reviews based on service-level objectives and entitlement quotas; 40) external observability signals including verifiable usage headers on API calls, watermarking of narrative artifacts, and public transparency pages summarizing issuance volumes without exposing personal data.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for issuing academic degrees, certifications, or micro-credentials, comprising:
   a) an AI-based evaluation engine configured to assess submissions using academic rubrics;
   b) an optional human peer accreditation module comprising domain experts who review, interview, or test candidates;
   c) a scoring engine configured to aggregate AI outputs and, when present, expert inputs into a composite evaluation;
   d) a credential issuance module configured to publish credentials, optionally as verifiable certificates; and
   e) a registry or record store configured to record issued credentials, the registry or record store being centralized or decentralized and optionally implemented as a ledger.
2. The system of item 1, further comprising a candidate learning advisor configured to recommend individualized learning paths based on evaluation gaps.
3. The system of item 1, further comprising a bias detection module configured to identify deviations in expert evaluations across multiple cases.
4. The system of item 1, wherein the peer accreditation module includes a reputation mechanism for rating expert reviewers based on accuracy and fairness.
5. The system of item 1, further comprising a credential narrative generator configured to produce a human-readable explanation of the credential issuance.
6. The system of item 1, wherein the credential may be issued even if the user did not participate in any institutionally affiliated coursework.
7. The system of item 1, wherein AI-assessed materials include written essays, code submissions, design artifacts, videos, or oral recordings.
8. The system of item 1, wherein the human expert review may occur via live video, asynchronous submissions, or structured challenge responses.
9. The system of item 1, wherein credentials may be shared, verified, and interpreted via an open recognition protocol compatible with employers or academic institutions.
10. The system of item 1, wherein degrees may be earned progressively and modularly, with partial credentials representing intermediate levels of mastery.
11. The system of item 1, further comprising an anti-cheating subsystem comprising multi-angle video recording of candidates during assessments, real-time audio monitoring for unauthorized assistance, and behavior tracking for detecting suspicious patterns.
12. The system of item 11, wherein the anti-cheating subsystem is configured to store all recordings in encrypted form and trigger review by either AI or human examiners based on detected anomalies.
13. The system of item 1, further comprising an entitlements and metering service configured to issue cryptographically signed usage entitlements to tenants and to gate execution of evaluation, proctoring, and issuance operations based on entitlement validity.
14. The system of item 13, wherein usage events are appended to an append-only log whose hash chain is periodically anchored to a public or private ledger to enable independent audit of consumption.
15. The system of item 1, wherein the AI-based evaluation engine is configured to invoke external tools via a Model Context Protocol adapter and to record auditable, structured outputs returned by the tools.
16. The system of item 1, further comprising a verification service configured to expose an endpoint that returns credential status, revocation state, and privacy-preserving proofs.
17. The system of item 1, further comprising a revocation mechanism configured to update registry state for issued credentials and to produce revocation proofs.
18. The system of item 1, wherein expert reviewer selection is performed subject to conflict-of-interest rules and uses domain, reputation, and availability criteria.
19. A method for issuing academic degrees, certifications, or micro-credentials, comprising:
   a) receiving, by an evaluation orchestrator, one or more artifacts associated with a candidate;
   b) invoking, by an AI-based evaluation engine, external tools via a Model Context Protocol adapter to analyze the artifacts and produce auditable structured outputs;
   c) collecting, when present, expert reviewer inputs via a human peer accreditation module;
   d) computing, by a scoring engine, a composite score that aggregates AI outputs and expert inputs;
   e) determining a decision state selected from approve, defer with recommendations, or reject; and
   f) when approved, publishing a credential by a credential issuance module to a registry and exposing a verification endpoint for the credential.
20. A non-transitory computer-readable medium storing instructions that, when executed by one or more processors, cause operations comprising:
   a) verifying entitlements for evaluation, proctoring, tooling, and issuance operations;
   b) orchestrating AI tool invocations via a Model Context Protocol adapter;
   c) normalizing and aggregating AI and expert reviewer inputs into a composite score;
   d) generating a verifiable credential with cryptographic proof and writing it to a registry;
   e) exposing verification and revocation services that return credential status and proofs; and
   f) logging usage events to an append-only log anchored to a ledger.

### Embodiment AF: Dynamic Taxation Based on Corporate Adherence to Public Ethical Commitments

### Field of the Invention

The present invention relates to systems and methods for adjusting taxation of capital gains and dividends based on the fulfillment or breach of publicly declared ethical or sustainability commitments made by corporations. More specifically, the invention may be applied to reduce greenwashing, promote transparency, and realign investor incentives toward measurable and verified corporate social responsibility.

### Background

Current financial markets allow corporations to make public commitments (e.g., environmental, social, labor-related) without incurring direct financial penalties if these commitments are not fulfilled. This enables a practice known as “greenwashing,” wherein companies benefit reputationally and financially from declarations of ethical intent while failing to take corresponding action. There exists a need for a mechanism that introduces accountability into such public claims, linking investor taxation to a company's delivery on its stated goals.

### Summary of the Invention

The invention proposes a dynamic taxation framework in which the capital gains and/or dividend taxes paid by shareholders are adjusted based on the issuing company's adherence to its publicly declared ethical, environmental, or sustainability goals. If a company meets its self-declared goals, investors benefit from a preferential tax rate. If the company fails to meet these goals within the declared timeframe, a penalty tax rate is applied. The goals must be specific, time-bound, and verifiable through independent or automated means.

### Description of the Embodiments

In one embodiment, a centralized or decentralized system tracks publicly declared goals by corporations. These may include statements such as “use 25% recycled plastic in all product packaging by 2025.” Such declarations are logged, timestamped, and associated with measurable metrics.

A monitoring subsystem evaluates company performance against each declared goal using available data sources including regulatory filings, third-party audits, supply chain disclosures, and blockchain-verifiable attestations. Companies that fulfill their commitments receive a “compliance score,” which can be continuously updated.

Investors holding shares in the company are assigned a dynamic tax rate on dividends and capital gains based on the company's compliance score. For example, if a company fails to meet its sustainability target within the declared time frame, the capital gains from its stock may be taxed at 35% instead of a base rate of 15%.

Tax authorities, decentralized autonomous organizations (DAOs), or AI-mediated governance systems may implement these adjustments. The compliance scores may also be factored into portfolio management systems and AI-driven financial advisers, guiding investment flows toward high-integrity firms.

In a further embodiment, companies may register their goals on a standardized public ledger, where such declarations become legally binding in exchange for access to tax incentives, sustainability-linked bonds, or ESG-focused funds.

### Enabling Effects

The invention directly disincentivizes greenwashing by linking financial consequences to the integrity of public declarations. It encourages more honest, achievable goal-setting by corporations and stimulates real investment in sustainability. Investors become aligned with measurable ethical outcomes rather than vague ESG narratives.

This framework promotes a more transparent, accountable, and ethically grounded market economy.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A method for dynamically adjusting shareholder tax rates based on a corporation's fulfillment of publicly declared ethical goals.
2. The method of item 1, wherein the goals are selected from environmental, labor, or sustainability categories and are time-bound and quantifiable.
3. The method of item 1, wherein compliance is verified through third-party audits, public disclosures, or blockchain entries.
4. The method of item 1, wherein a higher tax rate is applied to capital gains or dividends when a company fails to fulfill its declared goals.
5. The method of item 1, wherein a preferential tax rate is applied to capital gains or dividends when a company fulfills its declared goals.
6. The method of item 1, further comprising the use of a compliance score to grade company performance.
7. The method of item 6, wherein said compliance score is used to inform AI-driven investment recommendations.
8. The method of item 1, wherein said public declarations are registered on a legal or cryptographic ledger and made legally binding.
9. The method of item 1, wherein said system is implemented by a governmental, decentralized, or hybrid governance entity.
10. The method of item 1, wherein said dynamic taxation system promotes truthful corporate communication and deters greenwashing

A system and method for dynamically adjusting taxes on stock profits and dividends based on whether corporations meet their publicly declared ethical and sustainability goals. The invention promotes truthful communication, discourages greenwashing, and incentivizes real-world impact by tying financial consequences to public declarations.

### Embodiment AFE: Dynamic Taxation Based on Corporate Adherence to Public Ethical Commitments

### Field of the Invention

The present invention relates to systems and methods for adjusting taxation of capital gains and dividends based on the fulfillment or breach of publicly declared ethical or sustainability commitments made by corporations. More specifically, the invention may be applied to reduce greenwashing, promote transparency, and realign investor incentives toward measurable and verified corporate social responsibility.

### Background

Current financial markets allow corporations to make public commitments (e.g., environmental, social, labor-related) without incurring direct financial penalties if these commitments are not fulfilled. This enables a practice known as “greenwashing,” wherein companies benefit reputationally and financially from declarations of ethical intent while failing to take corresponding action. There exists a need for a mechanism that introduces accountability into such public claims, linking investor taxation to a company's delivery on its stated goals.

### Summary of the Invention

The invention proposes a dynamic taxation framework in which the capital gains and/or dividend taxes paid by shareholders are adjusted based on the issuing company's adherence to its publicly declared ethical, environmental, or sustainability goals. If a company meets its self-declared goals, investors benefit from a preferential tax rate. If the company fails to meet these goals within the declared timeframe, a penalty tax rate is applied. The goals must be specific, time-bound, and verifiable through independent or automated means.

### Description of the Drawings

No drawings are submitted with this application. The embodiments are described textually with sufficient detail for implementation and for conversion into figures if desired. In contemplated figures, a system architecture could depict the registrar, evidence intake, scoring engine, rate scheduler, investor mapping, privacy and identity layer, tax adjustment emitter, governance interface, and audit log as interconnected components; a process flow could depict registration of declarations, evidence intake, scoring, rate determination, investor mapping, and emissions of adjustment records including reversals; a data model could depict example record schemas for declarations, evidence, scores, rate schedules, investor mappings, and adjustment records; and an interoperability view could depict integration with centralized databases and decentralized ledgers across jurisdictions.

### Description of the Embodiments

In one embodiment, a centralized or decentralized system tracks publicly declared goals by corporations. These may include statements such as “use 25% recycled plastic in all product packaging by 2025.” Such declarations are logged, timestamped, and associated with measurable metrics.

A monitoring subsystem evaluates company performance against each declared goal using available data sources including regulatory filings, third-party audits, supply chain disclosures, and blockchain-verifiable attestations. Companies that fulfill their commitments receive a “compliance score,” which can be continuously updated.

Investors holding shares in the company are assigned a dynamic tax rate on dividends and capital gains based on the company's compliance score. For example, if a company fails to meet its sustainability target within the declared time frame, the capital gains from its stock may be taxed at 35% instead of a base rate of 15%.

Tax authorities, decentralized autonomous organizations (DAOs), or AI-mediated governance systems may implement these adjustments. The compliance scores may also be factored into portfolio management systems and AI-driven financial advisers, guiding investment flows toward high-integrity firms.

In a further embodiment, companies may register their goals on a standardized public ledger, where such declarations become legally binding in exchange for access to tax incentives, sustainability-linked bonds, or ESG-focused funds.

The foregoing description sets forth non-limiting examples to aid understanding. The scope of the invention is defined solely by the claims. The order of steps in any described flow may be varied or performed in parallel unless a particular order is expressly required. Examples and any figures, if provided, depict illustrative embodiments only. Elements described in one embodiment may be combined with, substituted for, or omitted relative to elements in other embodiments without departing from the claimed scope. Equivalent components, data structures, protocols, and implementations may be used.

### Enabling Effects

The invention directly disincentivizes greenwashing by linking financial consequences to the integrity of public declarations. It encourages more honest, achievable goal-setting by corporations and stimulates real investment in sustainability. Investors become aligned with measurable ethical outcomes rather than vague ESG narratives.

This framework promotes a more transparent, accountable, and ethically grounded market economy.

A system and method for dynamically adjusting taxes on stock profits and dividends based on whether corporations meet their publicly declared ethical and sustainability goals. The invention promotes truthful communication, discourages greenwashing, and incentivizes real-world impact by tying financial consequences to public declarations.

### Gentle Introduction

Investors may rely on public promises that companies make about ethics or sustainability, such as pledges to reduce emissions or improve labor practices by a certain date. Today, if those promises are missed, there is often no direct financial consequence tied to the promise itself. This invention proposes to connect those promises to the investor's tax treatment, so that meeting a promise could lead to lower taxes on dividends or gains from that company's stock, and missing a promise could lead to higher taxes.

In practical terms, a company may declare a measurable, time-bound goal. That declaration may be logged in a way that time-stamps it and links it to specific metrics. Independent data sources may then be used to check whether the company met the goal on time. A simple score may summarize the result. The investor's tax rate for dividends or capital gains related to that company may then be adjusted up or down based on that score.

This approach may reduce greenwashing because companies would know that making ambitious statements without delivering could financially disadvantage their shareholders. It may also reward companies that make realistic plans and follow through. For investors, the process may be automatic and transparent, requiring no special action beyond normal investing.

The system may be implemented by tax authorities or by decentralized governance that a jurisdiction chooses to recognize. It may use existing public disclosures, audits, or verifiable digital attestations to keep costs low and reliability high, while allowing flexibility in the kinds of corporate goals and verification methods that can be supported.

### Examples

A first example may involve a consumer goods company that publicly declares “use 25% recycled plastic in all product packaging by 2025-12-31.” The declaration may be registered on a cryptographic ledger with a signed payload such as {“issuer”:“CompanyA”, “goal id”:“G-2025-PLASTIC”, “metric”:“recycled_plastic rate”, “target”:0.25, “deadline”:“2025-12-31”, “scope”:“all_packaging”, “verification”:“third_party audit”, “jurisdiction”:“U S”, “signature”:“0xabc123”} and a corresponding ledger transaction hash. A monitoring subsystem may ingest an accredited auditor's report that finds an observed recycled plastic rate of 0.27 by the deadline and generate a compliance record such as {“goal_id”:“G-2025-PLASTIC”, “observed”:0.27, “deadline_met”:true, “score”:0.92, “evidence uri”:“ip fs://bafy . . . ”, “verifier_id”:“AuditFirmX”}. An investor may realize a capital gain of 10000 units on shares of the company during the tax period following verification. A tax adjustment record may be produced such as {“investor id”:“hash:Z1”, “issuer”:“CompanyA”, “event”:“capital_gain”, “amount”:10000, “base_rate”:0 0.15, “adjusted_rate”:0.10, “basis”:“score>=0.90 within deadline”, “reference”:“goal_id=G-2025-PLASTIC”} and transmitted to the tax authority or recognized governance entity for settlement, resulting in a preferential rate applied to that gain due to fulfillment.

A second example may involve failure to meet a declared emissions reduction goal. A company may declare “reduce scope 2 emissions by 40% relative to 2022 baseline by 2026-06-30,” and may log the declaration as {“issuer”:“CompanyB”, “goal_id”:“G-2026-S2”, “metric”:“scope2_emissions_reduction”, “target”:0.40, “baseline_year”:2022, “deadline”:“2026-06-30”, “verification”:“regulatory filings”, “jurisdiction”:“EU”, “signature”:“0xdef456”}. If monitoring detects that the observed reduction is 0.15 by the deadline and the score evaluates to 0.38 due to material underperformance and data gaps, a record such as {“goal_id”:“G-2026-S2”, “observed”:0.15, “deadline_met”:false, “score”:0.38, “evidence_uri”:“https://re g.example/eu/filing/123”, “verifier id”:“RegBodyY”}may be produced. The system may then apply a penalty tax rate to dividends received in the corresponding period, emitted as {“investor id”:“hash:Q7”, “issuer”:“CompanyB”, “event”:“dividend”, “amount”:2500, “base_rate”:0.15, “adjusted_rate”:0.35, “basis”:“deadline_missed or score<0.50”, “reference”:“goal_id=G-2026-S2”}.

A third example may demonstrate graduated rates based on partial compliance. A jurisdiction may publish a rate schedule where adjusted rate may be computed as a function of score such that rates interpolate between a minimum and maximum. For instance, the system may compute {“goal_id”:“G-2027-WATER”, “score”:0.74, “rate_min”:0.10, “rate_max”:0.35, “adjusted_rate”:0.185, “f unction”:“linear(score; 0->0.35,1->0.10)”, “reference”:“JURIS:US-CA-2027”} and attach that adjusted rate to taxable events associated with the issuer until the score updates. This may allow continuous incentives and avoid cliff effects.

In software embodiments, a Model Context Protocol compliant client may orchestrate verification and tax adjustment by invoking tools exposed by data providers and authorities. A monitoring agent may call tools such as ledger.read to fetch signed declarations, audit.verify to validate third-party attestations, score.compute to generate the compliance score given metrics and deadlines, and tax.adjust to emit the tax adjustment record. The MCP session transcript may thus embody externally auditable reasoning for each adjustment, while the underlying data structures remain as compact payloads like those shown above and are transmitted over secure channels recognized by the implementing governance entity.

### Anchor:

This section anchors the embodiments by naming the core elements and their relationships that recur across figures and implementations, whether centralized or decentralized. A goal declaration registrar may accept and persist issuer-submitted public commitments as signed records containing identifiers such as issuer, goal_id, metric, target, baseline if applicable, deadline, scope, verification modality, jurisdiction, and signature, with a cryptographic timestamp and ledger reference. A verification evidence intake subsystem may obtain or receive evidence from sources including regulatory filings, third-party audit attestations, supply-chain disclosures, or cryptographically signed sensor streams, normalizing each into records that reference the corresponding goal id and include observed values, deadline_met flags, verifier identifiers, evidence_uri, and provenance signatures. A scoring engine may compute a compliance score for each goal or an issuer-level composite by applying governance-specified functions to observed metrics, deadlines, and weights, emitting time-versioned score records.

A rate scheduler may map a score to an adjusted tax rate by applying a jurisdiction-published schedule or function and may output rate determinations tied to issuer identifiers and validity windows. An investor mapping module may resolve investor-of-record status for each taxable event window, associating holdings in the issuer with measurement periods aligned to declared goals. A privacy and identity layer may transform investor identifiers into authority-resolvable hashes and maintain salt or keying material escrowed to the recognized authority. A tax adjustment emitter may construct and transmit tax adjustment records that specify investor_id hashes, issuer, event type, amount, base_rate, adjusted_rate, basis, and references to goal id and evidence, and may support reversals upon appeal through versioned superseding records. A governance interface may provide and receive schedules, weights, verifier accreditation lists, verification cutoffs, and appeals outcomes, interoperating with centralized databases and decentralized ledgers in multiple jurisdictions. An audit log and provenance ledger may immutably record declarations, evidence, scoring computations, rate determinations, and emitted adjustments with timestamps and signatures to enable external auditability.

Control and data flow may proceed as follows in each embodiment: an issuer registers a declaration in the registrar; verified evidence is collected by the intake subsystem; the scoring engine updates scores when evidence or deadlines change; the rate scheduler determines an adjusted rate for the issuer over a validity window; the investor mapping module enumerates affected investors and taxable events within that window; the tax adjustment emitter transmits records to the recognized authority for settlement; and, if an appeal is granted or new evidence is accepted before or after a verification cutoff, the emitter issues a reversal or corrective record that supersedes prior records. Programmatic interfaces may include REST endpoints, message queues, smart contract calls, or sessions orchestrated under Model Context Protocol, wherein a client invokes tools such as ledger.read, audit.verify, score.compute, and tax.adjust, and the resulting transcript and payloads provide externally observable proof of the operations performed. Implementations may operate entirely within a governmental authority, entirely within a decentralized autonomous organization recognized by a jurisdiction, or as a hybrid, without altering the foregoing element relationships.

### Definitions and Constructions

For clarity of claim construction and to facilitate consistent implementation and testing, the following terms may be construed as described. A goal declaration may denote a signed, timestamped record that uniquely associates an issuer with a measurable commitment that is specific, time-bound, and verifiable, containing fields including an issuer identifier, a goal id that is unique within the issuer, a metric name that identifies the measured quantity, a target value, an optional baseline and scope, a deadline, a verification modality, a jurisdiction identifier, a signature that binds the payload to the issuer key, and a cryptographic timestamp or ledger reference. Publicly declared may denote any communication or commitment made accessible to the public or a defined investing public, including but not limited to regulatory filings, corporate websites, sustainability reports, press releases, investor presentations, advertisements, social media posts by authorized officers, statements in offering documents, covenants of sustainability-linked instruments, or entries in third-party registries that the issuer signs or authorizes.

Verification evidence may denote one or more signed or otherwise authenticated records that directly or indirectly substantiate the observed value of the declared metric and whether the deadline was met, including references to data sources via evidence_uri, the identity of the verifier as verifier id, and a provenance signature that binds the evidence to its source.

A compliance score may denote a deterministic scalar value that maps inputs comprising observed metric values, deadlines, weights, and policy parameters into a bounded numerical value that may lie within [0,1]inclusive, computed by a governance-published function that yields the same output for the same inputs and that is recorded as a time-versioned, signed record. The scalar may be binary, for example 0.0 for non-fulfillment and 1.0 for fulfillment, or may assume any other bounded real number; vector, categorical, or multi-factor assessments may be deterministically reduced to such a scalar prior to mapping. An adjusted tax rate may denote a numerical rate expressed as a fraction or percentage, derived from a compliance score by applying a jurisdiction-published mapping or schedule function that is deterministic and that may map the score domain [0,1]into a rate range [rate min, rate_max], together with a validity window indicating the time span for which the mapping is in force. A verification cutoff may denote a governance-published time boundary associated with a goal or group of goals after which additional evidence ordinarily does not change the rate for a completed tax period, except via appeals procedures.

An authority-resolvable hash may denote a privacy mechanism whereby an investor identifier is transformed into a digest by applying a cryptographic hash function to a concatenation of a secret salt or keying material and the identifier string, such that the service cannot invert the digest, and a recognized authority that holds the salt or keying material can resolve the identity upon lawful request or settlement processing. An append-only audit log may denote a write-once data store or ledger-anchored log in which each new record includes a content hash and a reference to the prior record's hash or index, thereby enabling tamper evidence and chronological ordering. A tax adjustment record may denote a signed payload that binds an investor_id hash, an issuer identifier, a taxable event type and amount, a base_rate, an adjusted rate, a basis explaining the mapping used, one or more references to goal_id and evidence, and a unique adj_id that supports idempotency and reversals. The tax adjustment record may be realized as a standalone message or as an embedded field-level augmentation within a standardized withholding, remittance, or settlement instruction, or as a persisted database row that contains the defined fields and signatures or cryptographic bindings, and relabeling or embedding within an existing transport or protocol does not change its character as a tax adjustment record. A reversal may denote a superseding tax adjustment record that references a prior adj_id and that either nullifies or amends the prior record in accordance with an appeals outcome or newly accepted evidence, with both records retained in the append-only audit log to preserve provenance. Investor-of-record may denote a status of an investor as of a date or window used by custodians and transfer agents to attribute dividends or gains to holdings, and may be aligned by the system to the measurement period of a goal so that adjustments apply only to relevant taxable events. These constructions may be used to interpret claims and embodiments in a manner consistent with technical implementation and external auditability.

### Enablement:

An implementer may build the system as a set of modular services or as an integrated application that executes the described flows using conventional computing resources. First, a goal declaration registrar may be implemented as a network service that accepts signed JSON payloads such as {“issuer”:“CompanyA”, “goal id”:“G-2025-PLASTIC”, “metric”:“recycled_plastic rate”, “target”:0.25, “baseline_year”:2022, “deadline”:“2025-12-31”, “scope”:“all_packaging”, “verification”:“third_party_a udit”, “jurisdiction”:“US”, “signature”:“0xabc123”}. The registrar may verify issuer signatures against a registry, assign a cryptographic timestamp, persist the record in a write-once store, and optionally anchor a hash to a recognized ledger by submitting a transaction and recording the returned transaction reference.

Next, a verification evidence intake subsystem may be deployed to connect to approved sources. For regulatory filings, the subsystem may poll or subscribe to feeds provided by authorities, download filings, extract relevant metrics, and create normalized evidence records such as {“goal_id”:“G-2026-S2”, “observed”:0.15, “deadline_met”:false, “verifier id”:“RegBodyY”, “evidence_uri”:“https://reg.example/eu/filing/123”, “provenance_sig”:“0x777”}. For third-party audits, the subsystem may accept uploads or API pushes from accredited firms and validate signatures. For supply-chain or sensor attestations, the subsystem may verify device or provider keys, check freshness and nonces, and record signed observations. All evidence may be associated to goal_id and stored with provenance signatures in an append-only audit log.

A scoring engine may compute a compliance score by applying governance-defined functions to observed metrics and deadlines. An implementation may load a policy object such as {“policy_id”:“P-2027-01”, “weights”:{“G-2025-PLASTIC”:0.4, “G-2026-S2”: 0.6}, “deadline_penalty”: 0.2, “function”:“bounded_linear”} and, upon receiving evidence updates, recompute per-goal scores and a composite issuer score with time-versioned outputs. The scoring engine may expose a deterministic API so that given the same inputs and policy, the same score is produced, and it may sign each score record before storage.

A rate scheduler may map the score to an adjusted rate using a jurisdiction-published schedule or function. The scheduler may ingest a schedule such as {“jurisdiction”:“US-CA-2027”, “rate_min”:0.10, “rate_max”:0.35, “mapping”:“linear”} and compute the adjusted_rate accordingly, emitting a rate determination tied to an issuer and a validity window. The scheduler may cache current schedules and support hot reload when a governance interface publishes updates.

Investor mapping may resolve investor-of-record status for taxable event windows. An implementation may connect to custodians, transfer agents, or clearing systems to obtain position snapshots and corporate action feeds, normalize identifiers, and align holdings with goal measurement periods. The module may handle stock splits, mergers, ticker changes, and dividends in kind, preserving issuer identity continuity and producing internal mappings that associate investor identifiers with affected issuer events.

A privacy and identity layer may transform investor identifiers into authority-resolvable hashes using salted hashing or public-key encryption. The salts or keys may be escrowed with the recognized authority or a key escrow service, enabling authorities to resolve identities while preventing service operators from reversing hashes. Where required, the system may incorporate zero-knowledge proofs to demonstrate usage or adjustment totals without exposing underlying identities or evidence contents.

A tax adjustment emitter may construct standard records such as {“investor id”:“hash:Z1”, “issuer”:“CompanyA”, “event”:“capital_gain”, “amount”:10000, “base_rate”:0 0.15, “adjusted_rate”:0.10, “basis”:“score>=0.90 within deadline”, “reference”:“goal_id=G-2025-PLASTIC”, “adj_id”:“A-0001”} and transmit them over secure channels recognized by authorities, for example HTTPS endpoints, message queues, or smart contract calls. The emitter may implement idempotency keys and support reversals by issuing superseding records referencing a prior adj_id when appeals succeed or subsequent evidence is accepted.

A governance interface may provide and receive schedules, scoring policies, verifier accreditation lists, verification cutoffs, and appeals outcomes. Implementers may expose REST endpoints and, in software embodiments, a Model Context Protocol session that orchestrates tool calls such as ledger.read, audit.verify, score.compute, rate.schedule.get, investor.map, and tax.adjust. An MCP client may drive end-to-end processing by invoking these tools in sequence and persisting the transcript to the audit log so that the reasoning steps and data payloads are externally auditable.

Deployment may proceed by packaging each module as a containerized service with signed images, deploying to a cloud or on-premises environment with a secure key management service, and configuring an append-only audit log and provenance ledger. Implementers may optionally use trusted execution environments for sensitive scoring or key-handling functions. Throughput may be scaled horizontally by sharding by issuer or jurisdiction and by caching schedules and static registries.

Conformance testing may include replay of known declarations and evidence to reproduce expected scores and adjusted rates, verification of idempotent behavior under retries, and validation that privacy transformations are correct and reversible only by the recognized authority.

These steps, taken together, allow a skilled person to implement the embodiments without undue experimentation using conventional programming frameworks, databases, cryptographic libraries, and network protocols. The same data structures as shown above may be used verbatim, with all JSON examples transmitted as compact, single-line payloads.

### Technical Effects

Implementations may provide concrete technical improvements relative to conventional financial reporting and compliance pipelines. By enforcing deterministic, signed, and time-versioned scoring computations coupled with append-only audit logging and optional ledger anchoring, the system may achieve non-repudiable provenance and reproducibility of rate determinations. The authority-resolvable hashing of investor identifiers, optionally combined with zero-knowledge proofs, may technically improve privacy-preserving identity resolution by enabling authorities to resolve identities while preventing service operators and third parties from reconstructing investor identities, thereby reducing data leakage and attack surface compared to plaintext reporting.

The rate scheduler supporting hot-reloadable schedules and idempotent, reversible tax adjustment emission may reduce operational error rates and downtime by allowing transactional updates and rollback without inconsistent state, improving reliability and throughput of cross-jurisdiction settlement. The investor mapping module that normalizes corporate actions across custodians and clearing systems may reduce reconciliation latency and mismatches by maintaining issuer identity continuity through symbol changes, splits, and reorganizations.

Use of Model Context Protocol sessions to orchestrate tool calls such as ledger.read, audit.verify, score.compute, and tax.adjust may yield externally auditable transcripts that bind tool inputs and outputs to specific computation steps, improving debuggability, testability, and independent verification. Trusted execution environments and signed container images may harden key handling and scoring operations against tampering. Collectively, these mechanisms may transform heterogeneous declarations and evidence into standardized, verifiable adjustment records with machine-checkable provenance and privacy guarantees, enabling interoperable settlement across centralized and decentralized infrastructures in a way not achievable by manual or ad hoc processes.

These computer-implemented mechanisms may improve the functioning of computer systems and networks by introducing cryptographically bound, deterministic workflows that reduce reconciliation failures, prevent repudiation, and enable privacy-preserving identity resolution across administrative domains. The claimed operations, including cryptographic timestamping of declarations, deterministic score computation bound to signed inputs, append-only provenance logging, authority-resolvable hashing, and signed, idempotent adjustment emission, are not reasonably performed as mental steps or by paper processes at scale and may therefore constitute a technical solution to problems of verifiable cross-entity settlement and auditability.

### Eligibility and Enforceability

Embodiments are directed to specific computer-implemented operations that improve the functioning and reliability of data processing systems involved in cross-entity settlement, privacy-preserving identity resolution, and non-repudiable provenance. The claimed subject matter relies on cryptographic timestamping, signature verification, authority-resolvable hashing, deterministic score computation executed by machines over signed inputs, append-only audit logging with hash chaining or ledger anchoring, and signed transmission of adjustment records over secure channels. These operations are not reasonably performed as mental steps or on paper at scale and thus are not directed merely to an abstract idea or a method of organizing human activity in the absence of specific computer technology.

To reduce divided-infringement concerns, embodiments may be practiced in single-actor modes where a service provider or an authority performs each recited step from registration through emission of signed adjustment records. System and computer-readable medium claims further mitigate divided-performance issues by tying liability to the entity that configures and operates the system executing the claimed instructions. Where method claims are asserted, implementations may be structured so that a single entity conditions participation in the process on performance of the steps or exercises control or direction over other participants.

The claims do not preempt the general concept of taxation or compliance incentives. Instead, they are confined to particular technical data structures, transforms, and interfaces, including signed JSON payloads that contain specific fields, authority-resolvable hashes for investor identifiers, append-only provenance logs, and deterministic mappings from signed inputs to signed outputs. The practical application is evidenced by externally observable artifacts, including signed tax adjustment records containing defined fields, rate determinations demonstrably computed from a published schedule or function applied to signed score records, and, in software embodiments, Model Context Protocol transcripts that bind tool calls and results. These artifacts may be collected without discovery into internal source code and may serve as black-box evidence of literal practice of the claimed operations.

For litigation readiness and to reinforce eligibility and enforceability, the description expressly defines key terms and data structures so that a person of ordinary skill may practice the invention without undue experimentation and so that the claims are definite. Each claimed operation may be mapped to a machine-executed transform over signed inputs to produce signed outputs persisted in an append-only store, which may demonstrate a specific improvement in computer functionality by enabling deterministic, non-repudiable, and privacy-preserving cross-entity settlement not attainable by manual processes. The externally observable artifacts described herein, including signed declarations, signed score records, signed rate determinations, and signed adjustment and reversal records, may provide objective evidence of direct or indirect infringement by showing use of each recited step and element through I/O behavior and cryptographic provenance. The single-actor implementation modes, authority-resolvable hashing for identity transformations, and deterministic APIs may further reduce divided infringement risks and strengthen proof in court by allowing straightforward element-by-element mapping of artifacts to claim limitations.

Eligibility is further supported under prevailing judicial frameworks. At step one of the eligibility inquiry, the independent claims are directed to specific computer-implemented techniques for producing cryptographically signed, hash-linked, and time-versioned artifacts that enable automated settlement across administrative domains, rather than to a result-oriented abstraction. At step two, the ordered combination of elements, including signature verification of issuer-submitted declarations, cryptographic timestamping and ledger anchoring, deterministic score computation via a governance-published function over signed inputs, jurisdiction-specific mapping of the score to an adjusted rate within a defined validity window, privacy-preserving transformation of investor identifiers into authority-resolvable hashes, construction of signed, idempotent adjustment and reversal records, and persistence of all artifacts in an append-only audit log with hash chaining, integrates the recited abstract concepts into a practical application that improves computer functionality. The claimed sequence imposes a technological architecture and verifiable data lineage that is not conventional or generic when taken as a whole.

The claimed processes are also tied to particular machines and effect a transformation. The operations execute on computing systems that maintain key material, perform public-key signature verification, compute cryptographic hashes, and maintain append-only, hash-linked logs or ledger anchors. Inputs are transformed into different, authenticated states that bear cryptographic bindings and authority-resolvable identity transforms that cannot be created or validated by mental steps. This satisfies the machine-or-transformation guidance and further differentiates the claims from non-technological methods.

Definiteness and written description are met because the specification expressly defines terms, data structures, and deterministic functions sufficient for a skilled person to implement the recited operations without undue experimentation. No claim invokes means-plus-function treatment because no limitation uses means for language; where functions are recited, corresponding structures and algorithms are disclosed, including explicit examples of signed JSON payloads, scoring policies, mapping schedules, and audit-log formats. The claims thus provide clear bounds to those skilled in the art.

Non-preemption is maintained. Alternatives that do not practice cryptographic timestamping of declarations, deterministic score computation over signed inputs, authority-resolvable hashing, and signed adjustment emission with append-only provenance remain outside the scope. Jurisdictions or entities may adopt policy-only or manual reconciliation processes without infringing; the claims are confined to specific computer-implemented techniques that generate externally verifiable artifacts.

### External Observability:

Embodiments may define externally observable inputs and outputs that allow independent parties to detect and prove use of the claimed methods and systems without access to internal source code.

Inputs may include signed goal declarations accepted by a registrar as single-line JSON payloads containing fields including issuer, goal_id, metric, target, baseline if applicable, deadline, scope, verification modality, jurisdiction, and signature, submitted over a documented network interface.

Inputs may also include authenticated verification evidence records referencing a goal id and containing observed values, a deadline_met indicator, a verifier identifier, an evidence_uri, and a provenance signature, as well as governance inputs including published schedules or functions that map a score to an adjusted rate and verification cutoffs and appeals outcomes.

Outputs may include signed, time-versioned score records that deterministically map the signed declaration and verification evidence to a bounded compliance score; signed rate determinations that bind an issuer identifier to an adjusted rate and a validity window based on a published schedule or function; and signed tax adjustment records transmitted over a secure channel to a recognized authority, each record containing an authority-resolvable investor identifier hash, an issuer identifier, a taxable event type and amount, a base rate, the adjusted rate, and references to the declaration and verification evidence. Outputs may further include superseding reversal records that explicitly reference a prior adjustment identifier and either nullify or amend it, with both original and reversal retained in an append-only audit log. Where the adjustment is embedded within a standardized remittance, withholding, or settlement message, the embedded fields together with associated provenance signatures and audit-log entries may constitute the tax adjustment record and may be externally identified through documented field values, message attributes, or ledger events.

Externally observable behavior may include idempotent emission of adjustment records when identical inputs are retried with the same adjustment identifier, deterministic recomputation of a compliance score from publicly published policies and evidence, and reproduction of the adjusted rate by applying a published schedule or function to the recorded score. Observers may verify ledger anchoring or hash chaining of audit log entries by recomputing content hashes and linkages, and may validate signatures on declarations, evidence, scores, and adjustment records against published keys or certificates. Where Model Context Protocol is used, an MCP transcript may be exported showing ordered tool calls including ledger.read, audit.verify, score.compute, and tax.adjust with their inputs and outputs, such that an independent verifier can replay the transcript and confirm equivalence of results.

A black-box proof of practice may be established by collecting the set of signed artifacts associated with a given issuer over a period, confirming that the artifacts contain the defined fields and signatures, demonstrating that the compliance score and adjusted rate can be recomputed from the artifacts and published policy to within exact equality, and demonstrating that the signed tax adjustment records were transmitted to an authority endpoint or accepted on a recognized ledger.

Because these artifacts are causally linked through identifiers and cryptographic bindings, their presence and consistency may constitute objective evidence of performance of each recited step, including registering a declaration, obtaining authenticated evidence, computing a score, determining an adjusted rate based on the score, transforming identifiers for privacy, and constructing and transmitting a signed adjustment record for settlement.

### Fallback Embodiments

Simplified or partial implementations may be deployed where resources, data availability, or legal authority are constrained, while still embodying the inventive concept of adjusting shareholder tax treatment based on verified fulfillment of publicly declared goals. In a batch-only mode, the system may ingest declarations and public regulatory filings on quarterly or annual schedules without real-time feeds, compute per-goal pass/fail results using rule-based checks rather than continuous scoring, and produce consolidated adjustment files such as CSV exports that an authority ingests during standard tax reconciliation. In this mode, investor mapping may rely on periodic position snapshots aligned to filing periods, and adjustments may apply pro-rata to taxable events within the period, with later corrective records issued upon appeal or late-arriving evidence.

In a minimalist deployment, the registrar may operate as a plain database with signed rows and local timestamps without external ledger anchoring, and the audit log may be an append-only file system journal or WORM storage. Evidence intake may accept scanned or digitally signed documents via a secure upload portal, validate signatures against a whitelist, and extract a single metric per goal. The scoring engine may be replaced by a deterministic binary evaluator that sets score to 1.0 for on-time satisfaction and 0.0 otherwise, with the rate scheduler mapping only these two values to a preferential and a penalty rate.

A sovereign offline embodiment may run entirely within an authority's data center without internet connectivity, using removable media to import regulator filings and to export signed adjustment bundles to downstream revenue systems. Identity resolution may be performed solely by the authority; the service may operate on anonymized handles and never receive raw identities, thereby obviating the need for authority-resolvable hashing while preserving the same externally observable I/O of signed adjustment records keyed by anonymized handles.

A dividends-only embodiment may limit coverage to cash dividend events to reduce scope and complexity, omitting capital gains and corporate action normalization while preserving declaration registration, evidence validation, deterministic evaluation, and emission of dividend-focused adjustment records. A single-jurisdiction pilot may implement only a fixed, published tiered schedule without hot-reload, and may omit Model Context Protocol orchestration by invoking direct REST endpoints while still persisting a transcript of inputs and outputs for auditability.

An evidence-sparse embodiment may assign conservative default adjusted rates when evidence is incomplete by a verification cutoff, record a confidence value alongside the applied rate, and automatically issue reversals or amendments if higher-quality evidence arrives within an appeals window. A hybrid embodiment may perform registration, evidence validation, and scoring within a service provider, while leaving final rate determination and adjustment emission to the authority's system via a signed recommendation record that the authority converts into a binding tax adjustment; such partitioning still practices the core method by causing tax treatment to be a function of verified goal fulfillment, and maintains the same element relationships described in the anchor.

### Workaround-Resilient Embodiments

To reduce opportunities for circumvention, functionally equivalent implementations may be included within scope. An adjustment to investor tax treatment may be realized as at least one of a rate change, a withholding multiplier, a credit, a rebate, a surcharge, a deduction, a deferral, or a settlement-time netting entry that yields a materially identical financial outcome for the taxable event. The adjustment may be computed or applied at an authority, broker-dealer, custodian, fund administrator, clearinghouse, or payroll and withholding system, with pass-through to account holders or beneficial owners; relabeling the mechanism or relocating it across institutional layers may not remove it from scope.

Taxable events may include dividends, capital gains, distributions, redemptions, interest on hybrid instruments, and realized or imputed gains associated with synthetic exposures such as total return swaps, options, or contracts for difference. Look-through mappings may attribute issuer-level adjustments to pooled vehicles including ETFs and mutual funds, and to derivatives via delta-weighted or model-based attribution, so that synthetic or pooled exposure may not avoid application.

Publicly declared commitments may include direct statements and also commitments embedded in or referenced by regulated documents and instruments, including sustainability-linked covenants, offering documents, listing applications, verified registry entries, or communications on public websites or official social media channels attributable to authorized officers. Adoption of a third-party framework or standard that enumerates specific targets may constitute a public declaration when the issuer represents conformance.

Investor exposure may be computed on a net or gross basis as defined by governance policy, and may treat short positions, hedges, or derivatives in a manner that prevents trivial arbitrage, for example by applying adjustments to net long exposure or by applying symmetric adjustments to offsetting positions where required by jurisdictional rules.

Equivalence across interfaces and encodings may be maintained. Substituting REST with message queues, smart contracts, or file-based batch imports may still implement the same element relationships and externally observable I/O. Substituting one cryptographic primitive for another that provides equivalent security properties may likewise be considered an implementation detail. Implementations that perform issuer-level withholding that is subsequently reconciled to investor accounts may still practice the method by causally linking tax treatment to verified goal fulfillment.

Implementations that embed the tax adjustment in a standardized withholding, remittance, or settlement message, or that apply a pre-parameterized withholding table per issuer without emitting a bespoke outward “adjustment” label, may still practice the method where the deterministically computed mapping from a compliance score to an adjusted treatment is persisted as an authenticated database row, protocol field, or ledger state change. Internalization of the mapping within an authority or broker system and silent application at settlement time may still produce a tax adjustment record as construed herein by virtue of the authenticated state transition recorded in an append-only audit log or settlement store. Obfuscating field names, splitting the record across multiple messages, changing the order of operations, or deferring application until netting or reconciliation does not avoid scope where the same causal mapping and cryptographic provenance exist. Where a compliance assessment is represented as a vector, categorical label, or third-party rating, a deterministic reduction to a scalar within [0,1]followed by application of a published schedule or function may equivalently realize the compliance score and mapping without avoiding the method.

### Monetization and Damages

The invention may be commercialized as a subscription or usage-based service offered to tax authorities, broker-dealers, custodians, fund administrators, issuers, or analytics providers. A multi-tenant architecture may isolate tenants by keys and entitlements, with each tenant receiving an issuance of license credentials represented as compact tokens such as

{“tenant_id”:“T-42”,“plan”:“enterprise”,“features”:“verify,score,adjust,appeals”,“rate_card”:“per_adjus
tment”,“unit_price”:0.02,“throughput_qps”:200,“valid_until”:“2028-12-31”,“signature”:“0xlic999”}.

Service endpoints may perform entitlement checks on each call to ledger.read, audit.verify, score.compute, rate.schedule.get, investor.map, or tax.adjust, and may meter usage by incrementing tamper-evident counters stored in the audit log and provenance ledger. Metered dimensions may include number of declarations registered, evidence validations performed, scores computed, rate determinations issued, investor mappings resolved, and tax adjustment records transmitted.

Subscription plans may define throughput ceilings, geographic or jurisdictional modules enabled, verifier catalogs accessible, and appeal processing service levels. The system may embed provider and policy identifiers into emitted artifacts to attribute provenance for billing and damages quantification, for example tax adjustment records may include fields such as “provider id”:“ProvZ” and “policy_id”:“P-2027-01” so that downstream authorities can correlate applied adjustments to a specific service instance without revealing tenant secrets. For on-premises or sovereign deployments, license beacons may periodically emit signed usage heartbeats containing aggregated counters such as {“tenant_id”:“T-42”, “period”:“2027-07”, “adjustments”: 128345, “verifications”:90211, “appeals_proces sed”:117, “signature”:“Oxbeat777”}, enabling deferred invoicing and audit trails.

Technical features supporting monetization may include rate limiting, burst credits, feature flagging, and hot-reloadable rate schedules tied to plan tiers so that premium subscribers may access advanced mappings such as continuous sigmoid functions while basic tiers may use piecewise or tiered mappings. The governance interface may expose billing hooks that allow authorities to subsidize or cross-charge specific operations, and may export standardized usage reports and signed MCP transcripts to substantiate damages by showing the volume and nature of infringing operations over time. The audit log and provenance ledger may retain immutable records of all metered events, facilitating precise computation of economic harm and reasonable royalty bases in the event of unauthorized use. Where privacy is required, usage reporting may employ authority-resolvable hashing and zero-knowledge proofs to demonstrate usage totals without disclosing investor identities or sensitive evidence contents.

### Itemized List for Continuations:

Embodiments can be described by the following itemized list, each item providing independent support for present claims and for future claims in continuations, with combinations of any subset of items also contemplated. 1. An embodiment may include a method that dynamically adjusts shareholder tax rates based on whether a corporation fulfills publicly declared ethical, environmental, labor, or sustainability goals; 2. An embodiment may require that declared goals are time-bound and quantifiable within categories including environmental, labor, or sustainability metrics; 3. An embodiment may verify compliance via third-party audits, public disclosures, cryptographic ledger entries, or any combination thereof, 4. An embodiment may apply a higher tax rate to capital gains or dividends when the corporation fails to fulfill a declared goal by its deadline; 5. An embodiment may apply a preferential tax rate to capital gains or dividends when the corporation fulfills a declared goal by its deadline; 6. An embodiment may compute and use a compliance score to grade performance against one or more declared goals; 7. An embodiment may provide that the compliance score informs AI-driven or algorithmic investment recommendations and portfolio allocations; 8. An embodiment may register public declarations on a legal or cryptographic ledger and treat them as legally binding for eligibility to incentives; 9. An embodiment may be implemented by a governmental authority, a decentralized governance entity, or a hybrid thereof, 10. An embodiment may expressly deter greenwashing and promote truthful corporate communication by linking tax treatment to verified performance; 11. An embodiment may compute an adjusted tax rate from a compliance score using a jurisdiction-published schedule or function; 12. An embodiment may accept goal declarations via a programmatic interface and record each declaration with a cryptographic timestamp and issuer signature; 13. An embodiment may treat verification evidence as including at least one of regulatory filings, third-party audit reports, supply-chain attestations, or cryptographically signed sensor data; 14. An embodiment may apply tax adjustments only after a verification cutoff and may support reversals upon appeal or upon acceptance of subsequent evidence; 15. An embodiment may aggregate multiple goals into a composite compliance score using weights set by a governance entity; 16. An embodiment may compute investor-level adjustments based on investor-of-record dates aligned to each goal's measurement period; 17. An embodiment may transmit adjustment records containing hashed investor identifiers that are resolvable only by an authority to preserve privacy; 18. An embodiment may comprise a system with at least one processor and memory to register declarations, obtain verification evidence, compute compliance scores, determine adjusted tax rates, and emit tax adjustment records for settlement; 19. An embodiment may comprise a non-transitory computer-readable medium storing instructions to register declarations, obtain verification evidence, compute compliance scores, determine adjusted tax rates, and transmit tax adjustment records to a governance entity; 20. An embodiment may interoperate with centralized or decentralized ledgers and governance entities across multiple jurisdictions for registering, verifying, scoring, determining, and emitting operations; 21. An embodiment may use Model Context Protocol sessions to orchestrate tool calls including ledger.read, audit.verify, score.compute, and tax.adjust, producing an auditable transcript; 22. An embodiment may implement privacy features including authority-resolvable hashing, salted tokens, and optionally zero-knowledge proofs for evidence validation without revealing sensitive data; 23. An embodiment may expose a governance interface to receive published rate schedules, scoring functions, verifier accreditation lists, verification cutoffs, and appeals outcomes; 24. An embodiment may support continuous, piecewise-linear, sigmoid, or tiered mappings from score to adjusted rate to avoid cliff effects and enable smooth incentives; 25. An embodiment may maintain an immutable audit log recording declarations, evidence, scoring computations, rate determinations, and adjustments with timestamps and signatures; 26. An embodiment may provide fallback operation in batch mode when real-time feeds are unavailable, with later reconciliation and corrective records; 27. An embodiment may include investor mapping that handles corporate actions including stock splits, ticker changes, dividends in-kind, mergers, and spin-offs while preserving issuer identity continuity; 28. An embodiment may support ETFs and pooled vehicles by attributing issuer-level adjustments to fund distributions via transparent or modeled look-through mappings; 29. An embodiment may optionally compute and store confidence intervals or quality scores for compliance scores to reflect evidence completeness and provenance; 30. An embodiment may integrate hardware-backed secure enclaves or trusted execution environments for sensitive key handling and scoring computations; 31. An embodiment may normalize multi-currency taxable events and apply jurisdiction-specific rounding, withholding, and reporting rules; 32. An embodiment may provide external observability via standardized tax adjustment records, evidence references, and MCP transcripts sufficient to prove infringement through I/O behavior; 33. An embodiment may implement interface versioning, backward compatibility, and plug-in modules for jurisdiction-specific rules and verifier catalogs; 34. An embodiment may support alternative and satellite data sources for verification, including remote sensing, IoT meters, and geospatial analytics, with signed provenance; 35. An embodiment may realize tax treatment changes via functionally equivalent mechanisms including rate changes, withholding multipliers, credits, rebates, surcharges, deductions, deferrals, or settlement-time netting entries; 36. An embodiment may compute or apply adjustments at an authority, broker-dealer, custodian, fund administrator, clearinghouse, or payroll and withholding system, with pass-through reconciliation to investor accounts; 37. An embodiment may attribute issuer-level adjustments to synthetic or pooled exposures including total return swaps, options, contracts for difference, ETFs, and mutual funds via look-through or model-based mappings; 38. An embodiment may define investor exposure on a net or gross basis and apply adjustments to positions including shorts and hedges in a manner that prevents trivial arbitrage and maintains incentive alignment; 39. An embodiment may construe publicly declared commitments to include communications made via regulatory filings, websites, sustainability reports, press releases, investor presentations, advertisements, offering documents, authorized social media, and signed entries in third-party registries; 40. An embodiment may treat adoption of third-party frameworks, standards, or sustainability-linked covenants as public declarations when the issuer represents conformance or executes binding instruments referencing quantifiable targets; 41. An embodiment may treat substitution of interfaces, encodings, or cryptographic primitives that preserve security and provenance properties as implementation details that do not alter scope; 42. An embodiment may implement issuer-level withholding with later reconciliation to investor accounts while still causally linking tax treatment to verified goal fulfillment; 43. An embodiment may comprise an end-to-end method that registers a corporate goal declaration as a signed, timestamped record by verifying an issuer signature and persisting the declaration in an append-only or ledger-anchored store; obtains verification evidence that includes an observed metric value and a provenance signature referencing the declaration; deterministically computes, via a governance-published function, a compliance score within a bounded range between zero and one inclusive and produces a signed, time-versioned score record; determines, using a jurisdiction-published schedule or function, an adjusted tax rate as a function of the compliance score for a validity window; transforms an investor identifier into an authority-resolvable hash using a privacy-preserving transform selected from salted hashing, keyed hashing, or public-key encryption; constructs and transmits, over a secure channel to a recognized authority, a signed tax adjustment record that includes the authority-resolvable hash, an issuer identifier, a taxable event type and amount, a base tax rate, the adjusted tax rate, and references to the declaration and the verification evidence; and stores the score record, the adjusted tax rate determination, and the signed tax adjustment record in an append-only audit log.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A computer-implemented method for dynamically adjusting investor tax treatment based on a corporation's fulfillment of publicly declared, measurable commitments, the method comprising:
   a) registering a corporate goal declaration as a record;
   b) obtaining authenticated verification evidence referencing the declaration;
   c) computing a compliance score from the declaration and the verification evidence;
   d) determining an adjusted tax treatment as a function of the compliance score using a mapping or schedule, the adjusted tax treatment realized as at least one of a rate change, a withholding multiplier, a credit, a rebate, a surcharge, a deduction, a deferral, or a settlement-time netting entry; and
   e) constructing and transmitting a tax adjustment record specifying the adjusted tax treatment for application or settlement by at least one of an authority, broker-dealer, custodian, fund administrator, clearinghouse, or issuer-level withholding system.
2. The method of item 1, wherein the goals are selected from environmental, labor, or sustainability categories and are time-bound and quantifiable.
3. The method of item 1, wherein compliance is verified through third-party audits, public disclosures, or blockchain entries.
4. The method of item 1, wherein a higher tax rate is applied to capital gains or dividends when a company fails to fulfill its declared goals.
5. The method of item 1, wherein a preferential tax rate is applied to capital gains or dividends when a company fulfills its declared goals.
6. The method of item 1, further comprising the use of a compliance score to grade company performance.
7. The method of item 6, wherein said compliance score is used to inform AI-driven investment recommendations.
8. The method of item 1, wherein said public declarations are registered on a legal or cryptographic ledger and made legally binding.
9. The method of item 1, wherein said system is implemented by a governmental, decentralized, or hybrid governance entity.
10. The method of item 1, wherein said dynamic taxation system promotes truthful corporate communication and deters greenwashing.
11. A computer-implemented method comprising:
   a) registering a corporate goal declaration as a signed, timestamped record that associates an issuer with a measurable, time-bound, and verifiable target, the registering including verifying an issuer signature and persisting the declaration in an append-only or ledger-anchored store;
   b) obtaining, via a programmatic interface to at least one verifier, verification evidence that includes an observed metric value and a provenance signature referencing the declaration;
   c) deterministically computing, by executing a governance-published function over the observed metric value and the declaration, a compliance score within a bounded range between zero and one inclusive and producing a signed, time-versioned score record;
   d) determining, using a jurisdiction-published schedule or function, an adjusted tax rate as a function of the compliance score for a validity window;
   e) transforming an investor identifier into an authority-resolvable hash using a privacy-preserving transform selected from salted hashing, keyed hashing, or public-key encryption;
   f) constructing and transmitting, over a secure channel to a recognized authority, a signed tax adjustment record that includes the authority-resolvable hash, an issuer identifier, a taxable event type and amount, a base tax rate, the adjusted tax rate, and references to the declaration and the verification evidence; and
   g) storing the score record, the adjusted tax rate determination, and the signed tax adjustment record in an append-only audit log.
12. The method of item 1, further comprising receiving goal declarations via a programmatic interface and recording each with a cryptographic timestamp and issuer signature.
13. The method of item 1, wherein verification evidence includes at least one of regulatory filings, third-party audit reports, supply-chain attestations, or cryptographically signed sensor data.
14. The method of item 1, wherein tax adjustments are applied to taxable events only after a verification cutoff and are reversible upon appeal or subsequent evidence.
15. The method of item 1, further comprising aggregating multiple goals into a composite compliance score using weights specified by an implementing governance entity.
16. The method of item 1, wherein investor-level adjustments are computed based on investor-of-record dates aligned to the measurement period of each goal.
17. The method of item 1, wherein adjustment records transmitted to authorities contain hashed investor identifiers resolvable only by the authority to preserve privacy.
18. A system comprising at least one processor and memory storing instructions that, when executed, cause the system to register corporate goal declarations, obtain verification evidence, compute a compliance score for an issuer, determine an adjusted tax rate for dividends or capital gains associated with the issuer based on the compliance score, and emit a tax adjustment record for settlement.
19. The system of item 18, wherein the registering, obtaining, computing, determining, and emitting are interoperable with centralized or decentralized ledgers and governance entities across multiple jurisdictions.
20. A non-transitory computer-readable medium storing instructions that, when executed by one or more processors, cause performance of operations comprising registering corporate goal declarations, obtaining verification evidence, computing a compliance score, determining an adjusted tax rate for dividends or capital gains based on the compliance score, and transmitting a tax adjustment record to a recognized governance entity.

### Embodiment AG: Selective Plant Avoidance Device for Herbivorous Animals Using Visual Recognition and Deterrent Feedback

An animal-wearable device for controlling food selection is disclosed. The device comprises a collar or harness configured to be worn by a herbivorous animal, a camera oriented to capture imagery of the animal's mouth region and surrounding area, a deterrent mechanism comprising one or more feedback electrodes, and a computing system operatively connected to the camera and the deterrent mechanism. The computing system is configured to analyze the captured imagery to detect plant material located in proximity to the animal's mouth, identify whether the plant corresponds to a predefined crop species to be avoided, and activate the deterrent mechanism if the plant is within a defined proximity threshold. In certain embodiments, the device employs stereo vision to estimate plant depth, and may deliver deterrent signals such as electric shocks or audio cues. The system may operate locally or wirelessly, and may include solar power, behavioral logging, and adjustable deterrent intensity. The invention enables selective crop protection by conditioning animals to avoid specific plant species during free grazing.

### Background

In agricultural systems that employ herbivorous animals such as goats, sheep, or geese for vegetation management or free-range grazing, a persistent challenge is the unintended consumption of valuable or vulnerable crop species. While some animals exhibit a natural aversion to certain toxic or unpalatable plants, such behavior is inconsistent and cannot be relied upon to prevent crop damage. In particular, crops such as Solanum tuberosum (potato) produce green leaves that are toxic to humans and some animals, yet certain species-especially under conditions of food scarcity-may still consume them, leading to health risks for the animals and economic losses for the farmer.

Existing approaches to this problem typically rely on physical exclusion methods such as fencing, or on manual supervision of grazing animals. These approaches are labor-intensive, inflexible, and scale poorly in dynamic or mixed-vegetation environments. Moreover, they do not provide a selective response to specific plant species, and thus prevent the efficient use of animals for weed control or rotational grazing near crops that must be protected.

A major potential application of selective deterrent systems is in biological weed control during crop cultivation. Grazing animals can be highly effective at removing unwanted green biomass in and around fields, but their use is currently limited by the risk of them consuming the main crop. If animals could be trained—or automatically conditioned-not to eat a specific crop such as potatoes, they could be deployed to graze down competing weeds in the same field. This would provide a low-chemical, low-labor method of weed suppression, reduce herbicide dependence, and enable more integrated, regenerative farming practices. However, achieving this requires a system capable of dynamically distinguishing between weeds and crops, and delivering real-time behavioral feedback to the animal.

Advances in computer vision, embedded electronics, and animal-wearable technologies have opened opportunities for precision control of animal behavior. However, to date, no known system enables automatic, vision-based detection of specific crops in real time, combined with behavior-modifying deterrent feedback tailored to the proximity and identity of plant material relative to the animal's mouth.

There remains a need for a smart deterrent device that can be worn by a grazing animal, capable of detecting when the animal approaches a protected crop species, and automatically issuing feedback-such as electric or auditory stimuli-to prevent consumption. Such a device should be lightweight, autonomous, energy-efficient, and adaptable to various animal types and crop configurations.

### Detailed Description

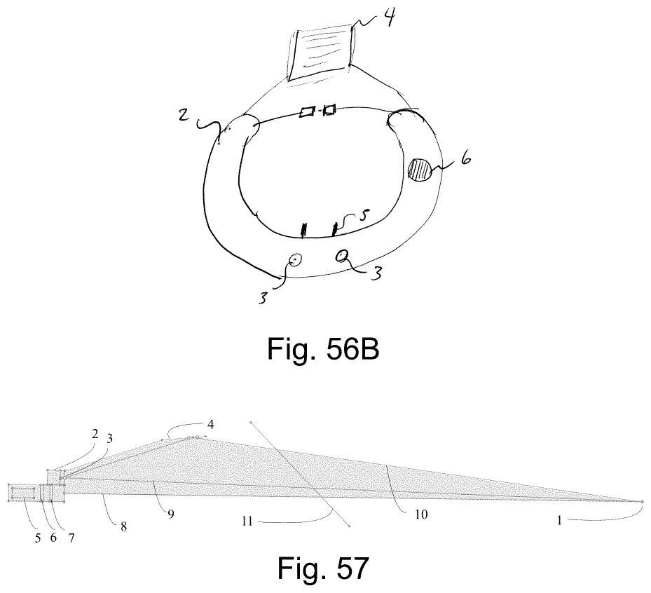

FIGS. 56A and 56B illustrate an embodiment of the current invention. The present invention may be embodied in a wearable device configured to be mounted on a herbivorous animal (1), such as a goat, sheep, cattle, or goose, for the purpose of influencing the animal's feeding behavior. The system may be particularly advantageous in crop-growing environments where selective grazing is desired-such as allowing the animal to consume unwanted weeds while avoiding economically valuable crop species.

In a preferred embodiment, the system includes a collar (2) or harness adapted to be worn comfortably around the animal's neck or upper body. The collar (2) may be adjustable and fabricated from durable, weather-resistant material such as silicone-coated nylon or thermoplastic elastomer. It may optionally include a quick-release safety mechanism or RFID identification tag for herd management.

A visual sensing module, comprising at least one camera (3), is mounted to the collar (2) and oriented such that it captures imagery of the animal's mouth region, including the under-jaw and the area directly in front of or below the mouth. In some embodiments, a single wide-angle camera may be sufficient to obtain the relevant field of view. In alternative configurations, a stereo camera setup may be used to enable depth estimation, allowing the system to compute the distance between the animal's mouth and the surface of a nearby plant leaf.

The camera (3) may be a low-power image sensor, such as a 2MP CMOS module with integrated compression. It may operate at low frame rates (e.g., 2-5 FPS) to conserve power. In stereo configurations, the baseline distance between the two sensors may be on the order of 4-6 cm to optimize depth precision at close range.

In one embodiment, a solar panel (4) is affixed to the top or side surface of the collar (2) to provide continuous power under outdoor conditions. The solar panel (4) may be a flexible monocrystalline or amorphous silicon array laminated in a waterproof housing. Electrical energy from the panel may be stored in a lithium-polymer (LiPo) battery (not shown), which may be integrated into the collar housing and managed by an onboard charging circuit (also not shown). The solar-battery system may be dimensioned to support multiple days of autonomous operation in typical field lighting conditions.

The collar (2) also supports a deterrent mechanism, comprising at least one pair of electric feedback electrodes (5). These electrodes may be mounted on the interior surface of the collar or on secondary straps that contact the animal's skin. The electrodes (5) may be constructed from conductive silicone or stainless steel, and may be connected to a miniaturized pulse driver capable of delivering a short-duration electric signal. In various embodiments, the stimulus may be adjustable in intensity or duration, ranging from a mild tingling sensation to a stronger aversive feedback sufficient to deter undesirable behavior.

In some versions, the system may further include an audio feedback element, such as a piezoelectric buzzer (6), also mounted on the collar (2). The buzzer (6) may be configured to emit a warning tone prior to electrical activation, or may serve as a standalone deterrent in low-severity situations. Audio cues may be selected to fall within the auditory sensitivity range of the target species and may be triggered in conjunction with or in place of electrical signals.

In addition to or instead of electrical stimulation, other forms of deterrent feedback may be used. In one embodiment, the device may incorporate a vibration motor housed within the collar structure, configured to deliver a short haptic pulse upon detection of a proximity violation. The vibration motor may be similar in construction to those used in mobile phones or animal training collars, and may provide a less aggressive but still perceptible feedback cue to the animal.

In some configurations, the deterrent mechanism may also include combinations of stimuli-such as an initial vibration or buzzer tone followed by an electric pulse if the animal does not withdraw. This multi-modal feedback strategy may enhance learning and reduce the need for aversive shocks over time. Additionally, future embodiments may support the use of visual deterrents, such as flashing LEDs, temperature-based cues (e.g., warming the collar surface), or short-range ultrasonic pulses tuned to frequencies perceptible to the target species.

All feedback modalities may be software-configurable and dynamically adjusted based on species, age, sensitivity, prior behavior, or time of day. The system may further be equipped with a manual override or learning mode, wherein feedback thresholds are gradually introduced based on behavioral patterns logged overtime.

The camera (3) is operatively coupled to a computing system, which may be embedded in the collar (2) or located remotely. In the local processing configuration, the collar may contain a compact microcontroller or single-board computer capable of executing image classification and depth estimation routines. For example, the processor may run a lightweight convolutional neural network trained to recognize the visual features of potato leaves, including their shape, vein pattern, color, and serrated edges. In stereo configurations, depth maps may be calculated using disparity matching and used to determine whether a recognized plant lies within a threshold proximity zone-typically defined as 5-15 cm below the jawline, depending on the species and feeding posture.

Alternatively, imagery captured by the camera (3) may be wirelessly transmitted to a static computer system, such as a base station or cloud-connected field server, using a wireless module (not shown). In this configuration, the external system performs image processing and returns a deterrent control signal, which is received by the collar and used to activate the feedback mechanism. Communication protocols may include Wi-Fi, LoRa, Zigbee, or 4G/5G cellular, depending on power availability and field topology.

Upon detecting that a plant object identified as a protected crop species-such as Solanum tuberosum-lies within the designated strike zone beneath the jaw, the computing system may issue a control command to the deterrent mechanism. In some implementations, this control may activate the electric electrodes (5) to deliver a mild shock at a fixed interval (e.g., once every five seconds) while the proximity condition persists. The purpose of the timing interval is to avoid overstimulation while reinforcing behavioral learning. Optionally, the system may escalate the feedback if the animal repeatedly violates the same constraint.

The collar (2) may also contain logging functionality, such as onboard memory or wireless sync capability, for storing timestamps of deterrent activations, GPS locations (if equipped), or frequency of crop-approach events. These data may be used for training reinforcement, herd analytics, or system optimization.

While the device is especially useful in preventing ingestion of crop species such as potato, tomato, or tobacco plants-whose leaves are harmful or economically valuable-it may also be configured to permit selective grazing of weedsbetween crop rows. This allows the animal to act as a living weed management system while sparing the main crop. By modifying the vision model, the system may be adapted to any crop-weed configuration and may be deployed across a wide range of field types.

All embodiments described herein are intended to be illustrative and non-limiting. It is contemplated that numerous variations in component placement, power source, feedback modality, animal species, and recognition algorithm may be made without departing from the scope of the invention.

In practice, the invention may comprise a tightly integrated system of cooperating components that together enable autonomous, vision-based behavioral control of herbivorous animals. At the core of the system is a structural collar or harness (2), worn by the animal (1), which serves as a mounting platform for the various subsystems. Affixed to the collar is at least one imaging unit, such as a forward- or downward-facing camera (3), which may optionally be part of a stereo pair configured to estimate depth by triangulating the distance to plant matter located beneath the animal's mouth or under-jaw. Alternatively, monocular vision systems may be used, wherein depth is inferred using image-based techniques such as shape-from-shading, object size estimation, machine learning regression models, or neural network-based monocular depth prediction algorithms. Such mono-vision techniques may be advantageous in reducing hardware cost and complexity while still providing sufficient accuracy for deterrent triggering at close range.

This camera (3) is operatively connected-either directly or wirelessly-to a computing unit, which may include an onboard microcontroller or microprocessor, or may instead be located remotely, such as on a field-deployed server. The computing unit is configured to receive image data, perform plant identification through a trained model (e.g., CNN-based), and, if the plant is recognized as a protected crop and is located within a defined proximity threshold, issue a control signal to one or more feedback mechanisms.

These deterrent mechanisms may include electric stimulation electrodes (5) in contact with the animal's skin, a piezoelectric buzzer (6) for audio feedback, and/or a vibration motor for haptic feedback. Each of these devices may be independently or jointly activated, based on configurable rulesets defined by the computing unit. The deterrent components are electrically coupled to a power management subsystem, which may include a lithium-polymer (LiPo) battery, a solar panel (4), and an optional charging and protection circuit. The solar panel (4) may be laminated onto the exterior of the collar (2) or embedded in a protective case and is electrically coupled to the LiPo battery via a charging module capable of safe, regulated energy transfer. The LiPo battery may supply power to the camera (3), processor, deterrent hardware, and any wireless communication module, such as a Wi-Fi, LoRa, or LTE modem.

The wireless module, if included, may be used to transmit raw or preprocessed image data to a remote server for classification, or to receive updated behavioral rules, firmware, or feedback thresholds.

Additionally, the processor may log behavioral events, such as the frequency, duration, or location of deterrent activations, which may be stored locally or synced periodically to a cloud-based dashboard for monitoring and analysis. It is further contemplated that all components may be housed in a waterproof and dust-resistant enclosure designed to distribute weight evenly and avoid discomfort or obstruction to the animal. Modular designs may allow for different sensor types, larger batteries, or redundancy in deterrent output channels.

In some embodiments, system parameters—such as depth sensitivity, plant species to be avoided, deterrent intensity, or feedback intervals-may be remotely updated via wireless link or through a physical connection during charging or inspection. The overall architecture may support autonomous field operation for multiple days or weeks, particularly when the solar panel (4) is sufficient to replenish the battery during daily exposure to sunlight. It is envisioned that the combined functionality of visual recognition, real-time proximity evaluation, targeted deterrent feedback, and power self-sufficiency may enable a wide range of selective grazing and crop-protection scenarios without the need for fencing, supervision, or chemical herbicides.

In certain embodiments, the system may further comprise an autonomous mobile support unit configured to provide shelter, water, and supplemental feed to a herd of AI-guided grazing animals, such as goats, within a designated field or rotational grazing zone. The support unit may include a shelter structure mounted on a self-propelling platform-such as a tracked or wheeled base-capable of slow, terrain-adaptive movement controlled by an onboard navigation module. The system may integrate GPS, inertial sensors, or visual localization techniques to relocate the unit based on predefined grazing rotation schedules, real-time animal behavior data, or vegetation depletion estimates. The support unit may house a water provisioning system, such as a gravity-fed trough, solar-powered pump, or refillable storage tank equipped with fluid level sensors. Additionally, an automated feed dispensing module may be included, configured to release measured portions of supplemental feed based on dynamic field conditions. More specifically, weed pressure may be assessed through remote sensing devices, such as a drone or fixed overhead imaging system, which may collect RGB or multispectral imagery of the current grazing zone. These images may be processed using computer vision algorithms to estimate vegetation density, biomass coverage, or weed-crop discrimination indices. The resulting weed pressure data may be transmitted to the support unit, where an embedded control logic determines whether supplemental feed is necessary and adjusts rationing accordingly. In high-weed-density scenarios, the feed system may remain inactive to encourage natural weeding, whereas in depleted zones or periods of low forage availability, controlled amounts of concentrate or hay may be dispensed. The system may further include animal identification via RFID, collar-based tags, or weight sensors, allowing personalized or herd-level feed metering. Additionally, inductive or contact-based charging modules may be integrated into the feeding or watering area, enabling recharging of wearable electronics such as AI collars while goats interact with the station. The shelter roof may host solar panels and optional micro wind turbines to power onboard systems, sensors, and wireless communication modules. The support unit may autonomously relocate itself at predefined intervals or in response to thresholds such as prolonged animal clustering, depleted weed levels, or environmental stressors, using acoustic cues, directional scent emitters, or servo-based neck guidance via animal collars to direct the herd. This infrastructure creates a self-regulating, semi-autonomous precision grazing system wherein animal behavior, weed ecology, and mobile infrastructure are orchestrated through AI-mediated feedback loops, significantly reducing human labor while maintaining ecological balance and crop safety.

In one embodiment, the system may incorporate an integrated architecture in which a collar or harness is worn by a herbivorous animal and serves as the mounting point for various subsystems, including a camera module configured to capture imagery of the animal's mouth region and surrounding field of view. The captured imagery may be processed by a computing system that may reside locally within the device or remotely via a wireless link. The computing system may be configured to execute algorithms capable of identifying plant material appearing within the proximity of the animal's feeding path. This identification may include classification of specific crop species-such as Solanum tuberosum (potato)-based on learned image features, such as shape, color, texture, or vein patterns.

In certain embodiments, the system may rely on a stereo vision arrangement to infer depth between the plant and the animal's jaw, while in alternative configurations, monocular depth estimation techniques may be employed using shape, scale, or machine learning models. When the plant material is determined to lie within a defined proximity threshold and match a protected crop species, the computing system may activate a deterrent mechanism, which may include electrical feedback electrodes, an acoustic buzzer, or a vibration motor. The deterrent mechanism may be triggered either immediately or at fixed intervals (e.g., every five seconds) until the animal withdraws or the condition is no longer met. The electrodes may be positioned on the collar, harness, or other body-adjacent surfaces as appropriate for stimulus delivery. Power may be provided by a rechargeable lithium-polymer battery in combination with an integrated solar panel, with charging managed by a dedicated circuit. The system may further be configured to log deterrent events or plant-approach behaviors for analysis and training purposes, and may allow the intensity or modality of deterrent feedback to vary based on classifier confidence or behavior frequency. The invention is contemplated to be adaptable across multiple species and plant types, enabling real-time selective deterrence across a wide range of agricultural applications.

In certain embodiments, the system may be adapted for use with a variety of non-human agents including, but not limited to, pigs, chickens, ducks, rabbits, and rats, wherein each animal may serve as a biologically mobile weeding unit under AI-assisted guidance. These animals may be equipped with wearable devices comprising imaging sensors, such as monocular or stereo vision cameras, configured to monitor the proximity and type of vegetation encountered during foraging activity. A computing system, either locally mounted or remotely connected, may analyze the visual input to determine whether a targeted plant corresponds to a desirable weed species or a crop to be protected.

Based on this determination, the system may deliver a deterrent or reinforcement signal-such as an auditory cue, vibrational feedback, or mild electric pulse-to shape and reinforce selective foraging behavior. The collar may additionally incorporate a geo-fencing module, such as a GPS receiver or wireless triangulation unit, configured to detect the animal's position relative to a predefined boundary. If the animal attempts to exit the designated zone, the system may trigger a deterrent response or alert the operator. In practice, geo-fencing functionality is likely preferred as it enables confinement to specific agricultural plots, rotational grazing zones, or exclusion areas without the need for physical fencing. The choice of animal may depend on application context, with pigs offering strong rooting capabilities and high trainability, chickens providing pecking-based weed seed control, rabbits offering low ground clearance for dense vegetation, and rats enabling micro-targeting in constrained environments. The system may further incorporate species-specific reinforcement schedules and mobility constraints to optimize task performance and crop compatibility.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. An animal-wearable device for controlling food selection, comprising:
   a) a collar or harness adapted to be worn by an animal;
   b) a camera mounted to the device and oriented to capture imagery of the animal's mouth region and surrounding area;
   c) a deterrent mechanism comprising one or more feedback electrodes configured to deliver a stimulus signal to the animal; and
   d) a computing system operatively connected to the camera and the deterrent mechanism, the computing system being configured to:
      (i) analyze imagery to identify plant material located in proximity to the animal's mouth;
      (ii) determine whether said plant material corresponds to a predefined crop species to be avoided; and
      (iii) activate the deterrent mechanism if the identified plant is within a defined proximity threshold.
2. The device of item 1, wherein the camera comprises a stereo vision system configured to estimate the distance between the animal's mouth and the identified plant material.
3. The device of item 1, wherein the computing system is configured to detect the presence of Solanum tuberosum(potato) leaves as the predefined crop species.
4. The device of item 1, wherein the deterrent mechanism comprises one or more electrodes configured to deliver an electric shock to the animal.
5. The device of item 4, wherein the one or more electrodes are positioned on the collar or harness, or elsewhere on the animal's body.
6. The device of item 1, further comprising an acoustic buzzer configured to emit an audio warning signal prior to or concurrently with activation of the deterrent mechanism.
7. The device of item 1, wherein the computing system is configured to activate the deterrent mechanism at fixed time intervals, including every five seconds, while the plant material remains within the defined proximity threshold.
8. The device of item 1, wherein the computing system is embedded within the collar or harness and performs local image processing.
9. The device of item 1, wherein the computing system is located remotely, and the device comprises a wireless transmitter configured to send captured imagery to the remote system and receive control signals in response.
10. The device of item 1, further comprising a solar panel mounted on the collar or harness to supply electrical power to the device.
11. The device of item 1, further comprising a rechargeable battery and a charging circuit configured to maintain power availability during operation.
12. The device of item 1, wherein the computing system is further configured to log deterrent activations or mouth-plant proximity events for behavioral tracking and system monitoring.
13. The device of item 1, wherein the deterrent mechanism is configured to vary the intensity or type of stimulus based on confidence level in plant classification or frequency of behavioral violation.
14. The device of item 1, wherein the computing system is trained to distinguish among multiple plant species and selectively apply deterrent activation based on plant type.
15. The device of item 1, wherein the collar or harness is configured for use with a variety of herbivorous animals, including but not limited to goats, sheep, cattle, and geese.

### Embodiment AGE: Selective Plant Avoidance Device for Herbivorous Animals Using Visual Recognition and Deterrent Feedback

An animal-wearable device for controlling food selection is disclosed. The device comprises a collar or harness configured to be worn by a herbivorous animal, an imaging sensor oriented to capture data of the animal's mouth region and surrounding area, a deterrent mechanism comprising one or more feedback electrodes, and a computing system operatively connected to the imaging sensor and the deterrent mechanism. The computing system is configured to analyze the captured data to detect plant material located in proximity to the animal's mouth, identify whether the plant corresponds to a predefined crop species to be avoided, and activate the deterrent mechanism if the plant is within a defined proximity threshold. In certain embodiments, the device employs stereo vision to estimate plant depth, and may deliver deterrent signals such as electric shocks or audio cues. The system may operate locally or wirelessly, and may include solar power, behavioral logging, and adjustable deterrent intensity. The invention enables selective crop protection by conditioning animals to avoid specific plant species during free grazing.

### Gentle Introduction

The invention may be understood intuitively as a smart collar that watches where a grazing animal is about to bite and gently intervenes when that bite would include a protected crop leaf. The collar-mounted camera views the area under the jaw and in front of the mouth. A small computer compares what it sees to known appearances of protected plants and estimates whether those plants are close enough to be eaten. If so, the collar may issue a warning tone or vibration, or a brief electric stimulus. Over repeated encounters, the animal may learn to avoid that specific leaf shape and color while continuing to eat nearby weeds. Farmers may set which crop to protect, adjust how sensitive the system is, and rely on solar-assisted power so the device may run for days in the field. The result is selective grazing that reduces fencing and herbicides by using targeted, real-time feedback rather than blanket exclusion.

### Examples

A goat wearing the collar approaches a potato plant row. The camera captures a frame at 4 frames per second showing the under-jaw region and the ground. The onboard model recognizes the characteristic leaflet structure and color of Solanum tuberosum foliage with a confidence above a configured threshold and estimates range using stereo disparity to be within 10 cm of the jawline. The computing unit sets the state to a warning mode and emits a brief two-tone audio cue. If the next frame indicates the plant remains within the proximity threshold, an electric stimulus of configured duration is delivered via the electrodes, after which the system pauses for a fixed interval before reassessing. The device logs the event with timestamp, optional GPS, and battery status for later review. An inline record of a representative decision appears as follows:

{“ts”:“2025-05-21T10:14:03Z”,“image_id”:“frame_3721.jpg”,“detections”:[{“class”:“Solanum_tubero
sum_leaf”,“bbox”:[0.31,0.42,0.56,0.78],“confidence”:0.93,“range_cm”:9.8}],“jaw_pose”:{“pitch_deg”
:−37.2},“proximity_threshold_cm”:12.0,“decision”:“deterrent_warn”}.

A sheep wearing a monocular-only configuration grazes near mixed weeds and a single tomato seedling. The system infers depth from apparent leaf size and a monocular depth model calibrated for the camera's optics and typical head pose. When the tomato seedling is detected at an estimated 14 cm, the proximity threshold of 12 cm is not satisfied and no deterrent is activated. As the animal lowers its head further, the inferred range reduces to 11 cm while confidence remains high, causing the collar to generate a vibration pulse followed by an audio cue. The animal withdraws and resumes grazing weeds adjacent to the seedling. A corresponding log example appears as:

{“ts”:“2025-06-02T08:07:55Z”,“species_to_avoid”:[“Solanum_lycopersicum”],“depth_mode”:“mono
cular”,“range_cm”:11.0,“confidence”:0.88,“decision”:“deterrent_vibrate_then_warn”,“battery_v”:3.92
}.

A herd deployment uses remote processing through a field server when cellular connectivity is available. The collar performs lightweight preprocessing such as downscaling and JPEG compression and sends frames on crop-approach suspicion. A Model Context Protocol workflow may be used to standardize tool-style requests from the collar to the server model and to coordinate responses that include both recognition and action advice. An example MCP-style request-response exchange appears inline as: {“mcp”:{“tool”:“plant.detect_and_advise”, “args”:{“image uri”:“mcp://sensor/cam0/frame_3721.jpg”, “species_to_avoid”:[“Solanum_tuberosum”], “proximity_threshold_cm”:12}, “returns”:[“decision”, “ran ge_cm”, “confidence”]}, “result”:{“decision”:“deterrent_pulse”, “range_cm”:9.8, “confidence”:0.93, “ser ver_latency_ms”:184}}. The collar receives the decision and applies the advised deterrent mode, then appends a tamper-evident log entry such as:

{“event”:“deterrent_pulse”,“mode”:“electrode”,“pattern”:“200Vpk_100us”,“interval_s”:5,“count”:1,“b
attery_v”:3.93,“gps”:{“lat”:51.2345,“lon”:−0.1234}}.

A night-grazing example uses a near-infrared capable camera with a low-power illuminator. The device switches profiles at dusk based on ambient light sensing and time-of-day rules. The classifier is trained to handle grayscale NIR textures of the protected leaves and the proximity threshold is widened by 2 cm to account for reduced depth precision. The system may favor auditory and vibration cues at night to minimize startling responses while still preventing crop bites. During a controlled test, printed target panels representing crop leaves at known distances are placed on stakes beneath the jawline while the animal is stationary, and the externally observable two-tone warning followed by periodic pulses is verified against a dummy resistive load attached to the electrodes. The test operator records correlating timestamps from the device logs and the measured load voltage to confirm proper operation.

In a poultry adaptation, a chicken wears a lightweight harness with a front-mounted micro camera. The device is configured to protect young lettuce seedlings while allowing weed seed pecking. The model detects lettuce cotyledons within 5 cm and issues only a vibration cue without electrical output to accommodate species sensitivity. The chicken diverts pecking to adjacent weed seeds, and the event log shows decreased deterrent counts over time, indicating learning. A condensed detection entry appears as:

{“ts”:“2025-04-11T06:21:09Z”,“class”:“Lactuca_sativa_cotyledon”,“range_cm”:4.6,“decision”:“deterr
ent_vibrate_only”,“deterrent_ms”:300}.

### Background

In agricultural systems that employ herbivorous animals such as goats, sheep, or geese for vegetation management or free-range grazing, a persistent challenge is the unintended consumption of valuable or vulnerable crop species. While some animals exhibit a natural aversion to certain toxic or unpalatable plants, such behavior is inconsistent and cannot be relied upon to prevent crop damage. In particular, crops such as Solanum tuberosum (potato) produce green leaves that are toxic to humans and some animals, yet certain species-especially under conditions of food scarcity-may still consume them, leading to health risks for the animals and economic losses for the farmer.

Existing approaches to this problem typically rely on physical exclusion methods such as fencing, or on manual supervision of grazing animals. These approaches are labor-intensive, inflexible, and scale poorly in dynamic or mixed-vegetation environments. Moreover, they do not provide a selective response to specific plant species, and thus prevent the efficient use of animals for weed control or rotational grazing near crops that must be protected.

A major potential application of selective deterrent systems is in biological weed control during crop cultivation. Grazing animals can be highly effective at removing unwanted green biomass in and around fields, but their use is currently limited by the risk of them consuming the main crop. If animals could be trained—or automatically conditioned-not to eat a specific crop such as potatoes, they could be deployed to graze down competing weeds in the same field. This would provide a low-chemical, low-labor method of weed suppression, reduce herbicide dependence, and enable more integrated, regenerative farming practices. However, achieving this requires a system capable of dynamically distinguishing between weeds and crops, and delivering real-time behavioral feedback to the animal.

Advances in computer vision, embedded electronics, and animal-wearable technologies have opened opportunities for precision control of animal behavior. However, to date, no known system enables automatic, vision-based detection of specific crops in real time, combined with behavior-modifying deterrent feedback tailored to the proximity and identity of plant material relative to the animal's mouth.

There remains a need for a smart deterrent device that can be worn by a grazing animal, capable of detecting when the animal approaches a protected crop species, and automatically issuing feedback-such as electric or auditory stimuli-to prevent consumption. Such a device should be lightweight, autonomous, energy-efficient, and adaptable to various animal types and crop configurations.

### Summary

This disclosure provides systems, methods, and computer-readable media for selective plant avoidance during free grazing using an animal-wearable device. The device may include a collar or harness with a camera aimed at the mouth region, a computing system that identifies protected plant species and estimates proximity, and a deterrent mechanism that delivers audio, vibration, or electrical stimuli based on configurable policies. Depth may be derived from stereo disparity or monocular inference. Processing may be local on the collar or remote via a field server, optionally coordinated through a Model Context Protocol workflow. Power may be supplied by a rechargeable battery and a solar panel. The system may log events with tamper-evident techniques, adapt profiles by species and time of day, and expose externally observable outputs to facilitate verification. Embodiments extend to different animals and form factors, including poultry adaptations without electrical output, and to deployment models that include policy tokens and subscription metering.

### Description of the Drawings

FIG. 7A shows an example collar an an example animal, a goat

FIG. 7B shows a front view of the collar

### Element Depicted in the Figures

In FIGS. 7A and 7B the following is depicted: an animal (1) wearing a collar or harness (2) that supports a camera (3) aimed to view the under-jaw and the area immediately in front of the mouth, a solar panel (4) exposed on the outer surface, electric feedback electrodes (5) positioned to contact skin, and an acoustic buzzer (6).

The camera (3) is fixed to the collar (2) so that when the animal (1) lowers its head, the camera's field of view encompasses foliage likely to be bitten. The solar panel (4) is electrically coupled to an internal rechargeable battery and power-management circuit that supply the camera (3), a computing system, the electrodes (5), and the buzzer (6). The electrodes (5) and buzzer (6) are mechanically integrated into the collar (2) so that deterrent outputs can be delivered while the camera (3) continues to acquire imagery.

### Detailed Description

The present invention may be embodied in a wearable device configured to be mounted on a herbivorous animal (1), such as a goat, sheep, cattle, or goose, for the purpose of influencing the animal's feeding behavior. The system may be particularly advantageous in crop-growing environments where selective grazing is desired-such as allowing the animal to consume unwanted weeds while avoiding economically valuable crop species.

In a preferred embodiment, the system includes a collar (2) or harness adapted to be worn comfortably around the animal's neck or upper body. The collar (2) may be adjustable and fabricated from durable, weather-resistant material such as silicone-coated nylon or thermoplastic elastomer. It may optionally include a quick-release safety mechanism or RFID identification tag for herd management.

A visual sensing module, comprising at least one camera (3), is mounted to the collar (2) and oriented such that it captures imagery of the animal's mouth region, including the under-jaw and the area directly in front of or below the mouth. In some embodiments, a single wide-angle camera may be sufficient to obtain the relevant field of view. In alternative configurations, a stereo camera setup may be used to enable depth estimation, allowing the system to compute the distance between the animal's mouth and the surface of a nearby plant leaf. In further embodiments, the visual sensing module may take the form of or be augmented by an imaging sensor such as a time-of-flight depth sensor, a structured-light projector with a receiver, a polarization camera, or a multispectral or hyperspectral imager that captures electromagnetic radiation beyond the visible spectrum while maintaining a view of the mouth region.

The camera (3) may be a low-power image sensor, such as a 2MP CMOS module with integrated compression. It may operate at low frame rates (e.g., 2-5 FPS) to conserve power. In stereo configurations, the baseline distance between the two sensors may be on the order of 4-6 cm to optimize depth precision at close range.

In one embodiment, a solar panel (4) is affixed to the top or side surface of the collar (2) to provide continuous power under outdoor conditions. The solar panel (4) may be a flexible monocrystalline or amorphous silicon array laminated in a waterproof housing. Electrical energy from the panel may be stored in a lithium-polymer (LiPo) battery (not shown), which may be integrated into the collar housing and managed by an onboard charging circuit (also not shown). The solar-battery system may be dimensioned to support multiple days of autonomous operation in typical field lighting conditions.

The collar (2) also supports a deterrent mechanism, comprising possibly one pair of electric feedback electrodes (5). These electrodes may be mounted on the interior surface of the collar or on secondary straps that contact the animal's skin. The electrodes (5) may be constructed from conductive silicone or stainless steel, and may be connected to a miniaturized pulse driver capable of delivering a short-duration electric signal. In various embodiments, the stimulus may be adjustable in intensity or duration, ranging from a mild tingling sensation to a stronger aversive feedback sufficient to deter undesirable behavior.

In some versions, the system may further include an audio feedback element, such as a piezoelectric buzzer (6), also mounted on the collar (2). The buzzer (6) may be configured to emit a warning tone prior to electrical activation, or may serve as a standalone deterrent in low-severity situations. Audio cues may be selected to fall within the auditory sensitivity range of the target species and may be triggered in conjunction with or in place of electrical signals.

In addition to or instead of electrical stimulation, other forms of deterrent feedback may be used. In one embodiment, the device may incorporate a vibration motor housed within the collar structure, configured to deliver a short haptic pulse upon detection of a proximity violation. The vibration motor may be similar in construction to those used in mobile phones or animal training collars, and may provide a less aggressive but still perceptible feedback cue to the animal.

In some configurations, the deterrent mechanism may also include combinations of stimuli-such as an initial vibration or buzzer tone followed by an electric pulse if the animal does not withdraw. This multi-modal feedback strategy may enhance learning and reduce the need for aversive shocks over time. Additionally, future embodiments may support the use of visual deterrents, such as flashing LEDs, temperature-based cues (e.g., warming the collar surface), or short-range ultrasonic pulses tuned to frequencies perceptible to the target species.

All feedback modalities may be software-configurable and dynamically adjusted based on species, age, sensitivity, prior behavior, or time of day. The system may further be equipped with a manual override or learning mode, wherein feedback thresholds are gradually introduced based on behavioral patterns logged overtime.

The camera (3) is operatively coupled to a computing system, which may be embedded in the collar (2) or located remotely. In the local processing configuration, the collar may contain a compact microcontroller or single-board computer capable of executing image classification and depth estimation routines. For example, the processor may run a lightweight convolutional neural network trained to recognize the visual features of potato leaves, including their shape, vein pattern, color, and serrated edges. In stereo configurations, depth maps may be calculated using disparity matching and used to determine whether a recognized plant lies within a threshold proximity zone-typically defined as 5-15 cm below the jawline, depending on the species and feeding posture. In other embodiments, active depth estimation may be obtained from a time-of-flight or structured-light module that directly measures near-field range in the bite zone, which may reduce sensitivity to texture-poor leaves and low light.

Alternatively, imagery captured by the camera (3) may be wirelessly transmitted to a static computer system, such as a base station or cloud-connected field server, using a wireless module (not shown). In this configuration, the external system performs image processing and returns a deterrent control signal, which is received by the collar and used to activate the feedback mechanism. Communication protocols may include Wi-Fi, LoRa, Zigbee, or 4G/5G cellular, depending on power availability and field topology.

Upon detecting that a plant object identified as a protected crop species—such as Solanum tuberosum—lies within the designated strike zone beneath the jaw, the computing system may issue a control command to the deterrent mechanism. In some implementations, this control may activate the electric electrodes (5) to deliver a mild shock at a fixed interval (e.g., once every five seconds) while the proximity condition persists.

The purpose of the timing interval is to avoid overstimulation while reinforcing behavioral learning.

Optionally, the system may escalate the feedback if the animal repeatedly violates the same constraint. The collar (2) may also contain logging functionality, such as onboard memory or wireless sync capability, for storing timestamps of deterrent activations, GPS locations (if equipped), or frequency of crop-approach events. These data may be used for training reinforcement, herd analytics, or system optimization.

While the device is especially useful in preventing ingestion of crop species such as potato, tomato, or tobacco plants-whose leaves are harmful or economically valuable-it may also be configured to permit selective grazing of weeds between crop rows. This allows the animal to act as a living weed management system while sparing the main crop. By modifying the vision model, the system may be adapted to any crop-weed configuration and may be deployed across a wide range of field types.

All embodiments described herein are intended to be illustrative and non-limiting. It is contemplated that numerous variations in component placement, power source, feedback modality, animal species, and recognition algorithm may be made without departing from the scope of the invention.

For clarity, the scope of the invention is defined solely by the claims. Any figures, reference numerals, examples, sequences, and process flows herein are illustrative embodiments; steps may be reordered, combined, omitted, or performed concurrently; components may be substituted with functionally equivalent alternatives; and implementation details may vary without departing from the claimed subject matter.

The collar may also have a means to determine its location and orientation, such as a GPS or UWB chip, that it uses to determine the animal the graze vegetation inside protected zones, such as the rows of potato plants or other crops. In this embodiment no visual system is needed.

In practice, the invention may comprise a tightly integrated system of cooperating components that together enable autonomous, vision-based behavioral control of herbivorous animals. At the core of the system is a structural collar or harness (2), worn by the animal (1), which serves as a mounting platform for the various subsystems. Affixed to the collar is at least one imaging unit, such as a forward- or downward-facing camera (3), which may optionally be part of a stereo pair configured to estimate depth by triangulating the distance to plant matter located beneath the animal's mouth or under-jaw. Alternatively, monocular vision systems may be used, wherein depth is inferred using image-based techniques such as shape-from-shading, object size estimation, machine learning regression models, or neural network-based monocular depth prediction algorithms. Such mono-vision techniques may be advantageous in reducing hardware cost and complexity while still providing sufficient accuracy for deterrent triggering at close range. In additional embodiments, an imaging unit may include a time-of-flight depth sensor or a structured-light system that projects a pattern and measures its deformation to infer range, or a polarization, multispectral, or hyperspectral sensor to improve plant discrimination under challenging lighting.

This camera (3) is operatively connected-either directly or wirelessly-to a computing unit, which may include an onboard microcontroller or microprocessor, or may instead be located remotely, such as on a field-deployed server. The computing unit is configured to receive image data, perform plant identification through a trained model (e.g., CNN-based), and, if the plant is recognized as a protected crop and is located within a defined proximity threshold, issue a control signal to one or more feedback mechanisms.

These deterrent mechanisms may include electric stimulation electrodes (5) in contact with the animal's skin, a piezoelectric buzzer (6) for audio feedback, and/or a vibration motor for haptic feedback. Each of these devices may be independently or jointly activated, based on configurable rulesets defined by the computing unit. The deterrent components are electrically coupled to a power management subsystem, which may include a lithium-polymer (LiPo) battery, a solar panel (4), and an optional charging and protection circuit. The solar panel (4) may be laminated onto the exterior of the collar (2) or embedded in a protective case and is electrically coupled to the LiPo battery via a charging module capable of safe, regulated energy transfer. The LiPo battery may supply power to the camera (3), processor, deterrent hardware, and any wireless communication module, such as a Wi-Fi, LoRa, or LTE modem.

The wireless module, if included, may be used to transmit raw or preprocessed image data to a remote server for classification, or to receive updated behavioral rules, firmware, or feedback thresholds.

Additionally, the processor may log behavioral events, such as the frequency, duration, or location of deterrent activations, which may be stored locally or synced periodically to a cloud-based dashboard for monitoring and analysis. It is further contemplated that all components may be housed in a waterproof and dust-resistant enclosure designed to distribute weight evenly and avoid discomfort or obstruction to the animal. Modular designs may allow for different sensor types, larger batteries, or redundancy in deterrent output channels.

In some embodiments, system parameters—such as depth sensitivity, plant species to be avoided, deterrent intensity, or feedback intervals-may be remotely updated via wireless link or through a physical connection during charging or inspection. The overall architecture may support autonomous field operation for multiple days or weeks, particularly when the solar panel (4) is sufficient to replenish the battery during daily exposure to sunlight. It is envisioned that the combined functionality of visual recognition, real-time proximity evaluation, targeted deterrent feedback, and power self-sufficiency may enable a wide range of selective grazing and crop-protection scenarios without the need for fencing, supervision, or chemical herbicides.

In certain embodiments, the system may further comprise an autonomous mobile support unit configured to provide shelter, water, and supplemental feed to a herd of AI-guided grazing animals, such as goats, within a designated field or rotational grazing zone. The support unit may include a shelter structure mounted on a self-propelling platform-such as a tracked or wheeled base-capable of slow, terrain-adaptive movement controlled by an onboard navigation module. The system may integrate GPS, inertial sensors, or visual localization techniques to relocate the unit based on predefined grazing rotation schedules, real-time animal behavior data, or vegetation depletion estimates. The support unit may house a water provisioning system, such as a gravity-fed trough, solar-powered pump, or refillable storage tank equipped with fluid level sensors. Additionally, an automated feed dispensing module may be included, configured to release measured portions of supplemental feed based on dynamic field conditions. More specifically, weed pressure may be assessed through remote sensing devices, such as a drone or fixed overhead imaging system, which may collect RGB or multispectral imagery of the current grazing zone. These images may be processed using computer vision algorithms to estimate vegetation density, biomass coverage, or weed-crop discrimination indices. The resulting weed pressure data may be transmitted to the support unit, where an embedded control logic determines whether supplemental feed is necessary and adjusts rationing accordingly. In high-weed-density scenarios, the feed system may remain inactive to encourage natural weeding, whereas in depleted zones or periods of low forage availability, controlled amounts of concentrate or hay may be dispensed. The system may further include animal identification via RFID, collar-based tags, or weight sensors, allowing personalized or herd-level feed metering. Additionally, inductive or contact-based charging modules may be integrated into the feeding or watering area, enabling recharging of wearable electronics such as AI collars while goats interact with the station. The shelter roof may host solar panels and optional micro wind turbines to power onboard systems, sensors, and wireless communication modules. The support unit may autonomously relocate itself at predefined intervals or in response to thresholds such as prolonged animal clustering, depleted weed levels, or environmental stressors, using acoustic cues, directional scent emitters, or servo-based neck guidance via animal collars to direct the herd. This infrastructure creates a self-regulating, semi-autonomous precision grazing system wherein animal behavior, weed ecology, and mobile infrastructure are orchestrated through AI-mediated feedback loops, significantly reducing human labor while maintaining ecological balance and crop safety.

In one embodiment, the system may incorporate an integrated architecture in which a collar or harness is worn by a herbivorous animal and serves as the mounting point for various subsystems, including a camera module configured to capture imagery of the animal's mouth region and surrounding field of view. The captured imagery may be processed by a computing system that may reside locally within the device or remotely via a wireless link. The computing system may be configured to execute algorithms capable of identifying plant material appearing within the proximity of the animal's feeding path. This identification may include classification of specific crop species-such as Solanum tuberosum (potato)-based on learned image features, such as shape, color, texture, or vein patterns.

In certain embodiments, the system may rely on a stereo vision arrangement to infer depth between the plant and the animal's jaw, while in alternative configurations, monocular depth estimation techniques may be employed using shape, scale, or machine learning models. When the plant material is determined to lie within a defined proximity threshold and match a protected crop species, the computing system may activate a deterrent mechanism, which may include electrical feedback electrodes, an acoustic buzzer, or a vibration motor. The deterrent mechanism may be triggered either immediately or at fixed intervals (e.g., every five seconds) until the animal withdraws or the condition is no longer met. The electrodes may be positioned on the collar, harness, or other body-adjacent surfaces as appropriate for stimulus delivery. Power may be provided by a rechargeable lithium-polymer battery in combination with an integrated solar panel, with charging managed by a dedicated circuit. The system may further be configured to log deterrent events or plant-approach behaviors for analysis and training purposes, and may allow the intensity or modality of deterrent feedback to vary based on classifier confidence or behavior frequency. The invention is contemplated to be adaptable across multiple species and plant types, enabling real-time selective deterrence across a wide range of agricultural applications.

In certain embodiments, the system may be adapted for use with a variety of non-human agents including, but not limited to, pigs, chickens, ducks, rabbits, and rats, wherein each animal may serve as a biologically mobile weeding unit under AI-assisted guidance. These animals may be equipped with wearable devices comprising imaging sensors, such as monocular or stereo vision cameras, configured to monitor the proximity and type of vegetation encountered during foraging activity. A computing system, either locally mounted or remotely connected, may analyze the visual input to determine whether a targeted plant corresponds to a desirable weed species or a crop to be protected.

Based on this determination, the system may deliver a deterrent or reinforcement signal-such as an auditory cue, vibrational feedback, or mild electric pulse-to shape and reinforce selective foraging behavior. The collar may additionally incorporate a geo-fencing module, such as a GPS receiver or wireless triangulation unit, configured to detect the animal's position relative to a predefined boundary. If the animal attempts to exit the designated zone, the system may trigger a deterrent response or alert the operator. In practice, geo-fencing functionality is likely preferred as it enables confinement to specific agricultural plots, rotational grazing zones, or exclusion areas without the need for physical fencing. The choice of animal may depend on application context, with pigs offering strong rooting capabilities and high trainability, chickens providing pecking-based weed seed control, rabbits offering low ground clearance for dense vegetation, and rats enabling micro-targeting in constrained environments. The system may further incorporate species-specific reinforcement schedules and mobility constraints to optimize task performance and crop compatibility.

### Enablement

A skilled person may implement representative embodiments using the following stepwise approach. A mechanical platform may be selected in the form of an adjustable collar or harness with weather-resistant materials and a total mass suited to the target species. A camera may be mounted to view the under-jaw region, using a single wide-angle module or a stereo pair with a 4-6 cm baseline. If night operation is needed, a near-infrared sensor with a low-power illuminator may be used. Electrodes for electrical deterrent may be integrated on skin-contacting surfaces with conductive silicone or stainless steel, and a piezo buzzer and a compact vibration motor may be included to provide alternative cues. Power may be supplied by a LiPo battery sized, for example, between 800 mAh and 2000 mAh, with a flexible solar panel laminated to the exterior and a charge controller that provides over-voltage, over-current, and temperature protection. Electronics may include a low-power microcontroller or single-board module with sufficient AI acceleration to run a quantized convolutional model at 2-5 FPS, GPIO drivers for the buzzer and vibration motor, and a high-voltage pulse module for electrodes with isolation, current limiting, contact-detection sensing, and safety interlocks.

Firmware may implement a deterministic state machine with idle, watch, warn, deter, and cooldown states. The watch state may acquire frames, downscale to a fixed resolution, normalize color, and evaluate a plant classifier trained on the protected species. Depth may be obtained from stereo disparity or from a monocular depth network calibrated for the lens intrinsics and typical head pose.

Proximity thresholds may be defined in centimeters, and night mode may widen thresholds to account for reduced precision. Upon a proximity violation with class match, warn may emit an audio or haptic cue, and deter may issue an electrical pulse with escalation and cooldown limits. Logging may append sealed records containing timestamp, decision, class, range, deterrent mode, and battery voltage to tamper-evident storage. A representative policy token may be stored and enforced locally, for example: {“policy”:{“species_to_avoid”:[“Solanum_tuberosum”], “proximity threshold_cm”:12, “deterrent_mod es”:[“audio”, “haptic”, “electrode”], “max_daily_pulses”:40, “cooldown_s”:5}}. If remote inference is used, the device may package frames and metadata, transmit via Wi-Fi, LoRaWAN, BLE gateway, NB-IoT, or LTE/5G depending on availability, and receive decisions using a Model Context Protocol style exchange, for example: {“mcp”:{“tool”:“plant.detect_and_advise”, “args”:{“image uri”:“mcp://collar/cam0/fl23.jpg”, “species to_avoid”:[“Solanum_tuberosum”], “proximity threshold_cm”:12}}}. Local fallback may continue with compressed models when connectivity is absent. Model preparation may include collecting images of protected crops and common weeds under varied lighting and head poses, annotating bounding boxes, training a compact classifier, and applying quantization and pruning to meet on-device constraints. Calibration may be performed by placing printed or real leaf targets at measured distances beneath the jawline and adjusting disparity-to-range scaling or monocular depth parameters until logged ranges align with physical measurements within a target error band, such as ±2 cm at 10 cm. In embodiments that include active depth sensing, a time-of-flight module or structured-light projector and receiver may be calibrated using targets at known distances to fit range scale and offset parameters, and may be fused with image-based classifications using confidence weighting. In variants that include an auxiliary ultrasonic rangefinder, the firmware may gate deterrent triggering on agreement between ultrasonic range and visual proximity to reduce false activations near thin leaves.

Electrical output may be verified off-animal using a dummy resistive load across electrodes to measure pulse amplitude and width while the buzzer emits a two-tone warning and vibration pre-cues execute. Acceptance criteria may include bounded latency between detection and warning, correct repetition intervals, and adherence to maximum daily activation limits. Safety may be assured by disabling electrical output on loss of skin contact, enforcing per-session limits, and providing a manual override. Over-the-air updates may deliver new plant models and policy tokens signed by a backend service; the device may validate signatures and degrade to a safe, limited mode on expiry while maintaining logging.

### Technical Effects

The disclosed embodiments produce concrete technical effects. Stereo depth configurations may yield improved near-field range estimation at the bite zone, reducing false triggers and missed deterrents compared with monocular-only systems. Monocular depth with jaw-pose gating may reduce hardware complexity and power draw while maintaining adequate precision at close ranges. Night profiles with near-infrared imaging and widened thresholds may preserve deterrent accuracy under low light without increasing false activations. Multi-modal feedback that escalates from audio to vibration to electrical pulses may decrease the number of shocks required over time, improving animal welfare while maintaining efficacy. Model compression and adaptive frame rates may substantially reduce energy consumption, extending run time between charges and enabling smaller batteries. Event-driven capture based on head pitch may reduce computation when the mouth is not near foliage, further conserving power. Tamper-evident logging and device-signed usage summaries may enable verifiable correlation of field behavior with policy and model versions, supporting maintenance, auditing, and damages calculation. Remote inference via a Model Context Protocol workflow may offload computation during high-demand periods, allowing the same hardware to support more complex models without hardware upgrades. Active depth sensing using time-of-flight or structured light may improve range estimates on low-texture leaves and in low light, further reducing false activations. Collectively, these effects may provide selective crop protection with lower labor, fewer chemicals, and improved predictability compared with fencing or manual supervision.

### Fallback Embodiments

To preserve core functionality under constraints or challenges, simpler or partial implementations may be employed. In one fallback embodiment, classification may be replaced by a heuristic detector tuned to a protected plant's dominant color and leaf morphology, combined with proximity estimation and the same state machine, thereby avoiding full model training while still preventing bites. In another embodiment, deterrence may operate using only audio and vibration outputs, completely disabling electrical stimulation for species or regulatory contexts where shocks are not permitted, while maintaining plant detection and proximity logic. A monocular-only build may omit stereo hardware and rely on calibrated monocular depth or apparent-size thresholds suitable for close ranges, achieving adequate deterrence with reduced cost and weight. A remote-only embodiment may transmit frames upon suspected approach and apply deterrence based on server-side decisions, with local safe modes that log events and emit warnings when connectivity drops. In a degraded lighting scenario, an infrared-only profile may operate with grayscale detection and widened proximity thresholds. In a limited-scope deployment, the system may enforce geo-fencing and audio warnings alone while logging plant-approach events for later training, allowing progressive enablement of full deterrence after validation. These simplified forms may still realize the inventive concept of vision-based identification of a protected plant in the bite zone followed by timely, selective feedback that reduces or prevents consumption.

### External Observability

In order to allow field verification and enforcement without internal inspection of hardware or software, the device may be configured to present externally observable behaviors, inputs, and outputs that correlate with the claimed functionality. When the vision system identifies a protected crop species with confidence above a configurable threshold and the estimated plant location falls within a proximity zone beneath the jaw, the collar may transition into a deterrent state within a bounded latency window selected to be perceptible in testing. In one configuration, an audio warning may be emitted as a distinctive two-tone pattern, such as a higher-frequency tone followed by a lower-frequency tone of several hundred milliseconds each, which may repeat at intervals while the triggering condition persists. In multi-modal modes, a short vibration burst may precede any electrical stimulus to create a recognizable sequence that can be observed from outside the system. The electrical deterrent pulses may be produced at regular intervals while the condition persists and may be measurable across a dummy resistive load attached to the electrodes, enabling characterization of pulse timing and intensity levels without animal involvement. The device may further maintain tamper-evident event logs containing timestamps, optional GPS fixes, and hashed labels for deterrent activations, which may be retrieved via a user interface or wireless synchronization to corroborate observed outputs. When remote processing is used, the collar may echo receipt of deterrent commands by a momentary indicator action, such as a brief audible chirp or LED blink where present, allowing correlation between networked control and local outputs. If geo-fencing is enabled, crossing a virtual boundary may produce a repeating audio pattern distinct from crop-approach events, providing a separate externally verifiable behavior. Examiners and operators may use a standardized test arrangement that positions representative plant targets or printed panels within the camera field of view at known distances while monitoring audio, vibration, and electrode outputs via meters, thereby confirming operation of the claimed methods through observable behavior alone.

### Monetization and Damages Considerations

To maximize available damages and provide clear economic attribution for infringement, the system may incorporate subscription-oriented usage and the technical features necessary to support it. In one implementation, each collar may possess a cryptographically unique device identity provisioned at manufacture and stored in a secure element. The device identity may be used to authenticate with a billing service over standard protocols such as HTTPS or MQTT and to obtain time-limited policy tokens that specify enabled features, protected crop models, deterrent modalities, and permitted operating regions. The device may maintain metering counters that increment based on usage metrics such as animal-days active, deterrent-activation counts, protected-plant detections within proximity, geo-fence boundary events, and server-assisted inference minutes. These counters may be periodically sealed with a device-signed hash chain or Merkle-root summary and synced to the billing service when connectivity is available, while remaining locally auditable through tamper-evident logs when offline.

The commercial model may include tiered subscriptions, such as a basic local-only plan, a hybrid plan with periodic cloud-assisted model updates, and a premium plan with real-time remote inference, fleet analytics, and over-the-air policy control. Pricing may be aligned to agricultural scale via per-animal, per-acre, or per-season licenses, and may additionally support pay-per-use for remote inference minutes or model downloads. The collar may enforce policy expirations by degrading to a safe, limited mode that continues logging but restricts premium functions until renewal, thereby preserving field safety while providing clear evidence of licensed feature usage. Operators may review invoices that reference the device-signed usage summaries, enabling reconciliation between field logs and billed items.

For evidentiary robustness, the device may record externally observable outputs together with corresponding usage events, including timestamps, GPS (where present), model version identifiers, deterrent mode and intensity, and policy token identifiers. When remote processing or Model Context Protocol workflows are used, the collar may archive message digests of request and response payloads to establish a verifiable link between billed cloud actions and field behavior. These technical features may facilitate damage calculations by correlating the number of infringing devices, the duration of infringing use, and the scope of enabled functionality with metered records that can be validated independently of internal software inspection.

### Itemized List

Embodiments can be described by the following itemized list: 1. An animal-wearable device comprising a collar or harness adapted to be worn by a herbivorous animal, a camera oriented to capture imagery of the animal's mouth region and surrounding area, a deterrent mechanism comprising at least one of electric feedback electrodes, an acoustic output, and a haptic vibration output, and a computing system operatively connected to the camera and the deterrent mechanism and configured to analyze imagery to identify plant material in proximity to the mouth, determine whether the plant corresponds to a predefined crop species to be avoided, and activate the deterrent mechanism when the identified plant is within a defined proximity threshold; 2. An embodiment in which the camera comprises a stereo vision system configured to estimate distance between the animal's mouth and identified plant material; 3. An embodiment in which the computing system is configured to detect Solanum tuberosum foliage as a predefined crop species to be avoided; 4. An embodiment in which the deterrent mechanism comprises electrodes configured to deliver an electric shock; 5. An embodiment in which the electrodes are positioned on the collar or harness, or elsewhere on the animal's body to achieve reliable skin contact; 6. An embodiment including an acoustic buzzer configured to emit an audio warning prior to or concurrently with activation of any deterrent; 7. An embodiment in which the computing system activates the deterrent mechanism at fixed intervals, including every five seconds, while the plant material remains within the defined proximity threshold; 8. An embodiment in which the computing system is embedded within the collar or harness and performs local image processing; 9. An embodiment in which the computing system is remote and the device transmits captured imagery wirelessly and receives control signals in response; 10. An embodiment in which a solar panel mounted on the collar or harness supplies electrical power; 11. An embodiment including a rechargeable battery and charging circuit configured to maintain power availability; 12. An embodiment in which the computing system logs deterrent activations and mouth-plant proximity events for behavioral tracking and monitoring; 13. An embodiment in which the deterrent mechanism varies intensity or type based on classification confidence or violation frequency; 14. An embodiment in which the computing system distinguishes among multiple plant species and selectively applies deterrents based on plant type; 15. An embodiment in which the collar or harness is configured for goats, sheep, cattle, geese, or other grazing animals; 16. An embodiment in which a vibration motor provides a haptic stimulus; 17. An embodiment in which deterrent parameters are dynamically adjusted based on time of day, species, age, or behavioral history; 18. An embodiment in which the camera includes infrared or near-infrared capability for low-light operation; 19. A method embodiment comprising capturing imagery from a collar-mounted camera, analyzing the imagery to identify plant material, determining whether the plant corresponds to a predefined crop species to be avoided, estimating proximity using stereo depth estimation or monocular depth inference, and activating a deterrent when within threshold; 20. A computer-readable medium embodiment storing instructions that, when executed, cause the foregoing identification, proximity estimation, and deterrent activation; 21. An embodiment using monocular depth inference only with calibration based on camera intrinsics and typical head pose, optionally using learned monocular depth models; 22. An embodiment supporting over-the-air model updates and remote inference using a Model Context Protocol style workflow to standardize request and response exchanges between the collar and a field server; 23. An embodiment including tamper-evident logs and metering with hash chains or Merkle-root summaries and device-signed usage records to support subscription billing and evidentiary audits; 24. An embodiment including geo-fencing by GPS or wireless triangulation and issuing distinct deterrent and warning patterns upon boundary crossings; 25. An embodiment including an automatic night profile that switches to near-infrared imaging, widens proximity thresholds to account for reduced depth precision, and biases toward audio and vibration cues; 26. An embodiment tuned for species sensitivity in which electrical output is disabled and only vibration or audio cues are used, including for poultry protecting lettuce seedlings; 27. An embodiment defining externally observable behaviors and test procedures using printed target panels at known distances and a dummy resistive load on electrodes to verify timing and intensity; 28. An embodiment in which the device operates without electrodes and relies solely on audio and haptic outputs to condition behavior; 29. An embodiment including alternative power configurations such as larger batteries, removable packs, or solar-dominant designs with power budgeting based on frame rate and wireless duty cycle; 30. An embodiment specifying deterrent pulse parameters including voltage, pulse width, repetition interval, escalation and cooldown limits, and safety interlocks to meet animal welfare guidelines; 31. An embodiment interoperable with multiple communication protocols including Wi-Fi, LoRa or LoRaWAN, Zigbee, BLE, NB-IoT, and 4G/5G, with fallback logic selecting among links based on power and coverage; 32. An embodiment using model compression such as quantization and pruning and adaptive frame rates to conserve power while maintaining decision quality; 33. An embodiment in which jaw pose estimation or head pitch triggers event-driven image capture and reduces processing when the mouth is not near foliage; 34. An embodiment using alternative wearable form factors such as a noseband or cheek-mounted camera placement while maintaining a view of the mouth region; 35. An embodiment including environmental sealing and weight distribution to achieve weather resistance and comfort, including IP-rated enclosures and mass limits suitable for target species; 36. An embodiment including contact detection for electrodes and skin-contact sensors to ensure reliable stimulus delivery and to disable electrical output on loss of contact; 37. An embodiment including a supervised learning mode wherein an operator labels frames or confirms detections to improve or customize plant models; 38. An embodiment coordinating with an autonomous mobile support unit providing water, feed, charging interfaces, and herd guidance signals that influence deterrent thresholds and profiles; 39. An embodiment implementing reinforcement schedules that escalate from audio to vibration to electrical stimuli with cooldown timers and maximum daily activation limits; 40. An embodiment including sensor fusion with additional spectral bands such as multispectral or near-infrared aiding classification under variable lighting; 41. An embodiment in which the device maintains per-animal profiles linked to a secure identity in hardware, enabling personalized deterrent settings and audit trails; 42. An embodiment providing a deterministic state machine architecture with states including idle, watch, warn, deter, and cooldown, with defined transitions based on detections and proximity; 43. An embodiment defining calibration procedures using targets at known distances to calibrate depth estimation and proximity thresholds; 44. An embodiment enabling fully local operation on a field server during connectivity outages with store-and-forward synchronization for logs and policies; 45. An embodiment including remote policy control specifying protected species lists, proximity thresholds, deterrent modes, and geo-fence regions, delivered as signed tokens that the device enforces with a safe degraded mode upon expiry; 46. An embodiment adapting to additional animals including pigs, ducks, rabbits, and rats with species-specific sensor placements, cue patterns, and mobility constraints; 47. An embodiment supporting real-time analytics that track reductions in deterrent activations over time as a learning indicator and adjust sensitivity accordingly; 48. An embodiment providing external acknowledgement behaviors, such as brief audible chirps, upon receipt of remote deterrent commands to correlate network control with local outputs; 49. An embodiment in which the collar logs model version identifiers and decision confidences to allow later reconstruction of decision context; 50. An embodiment enabling selective grazing between crop rows by allowing whitelist plants or zones to pass without deterrent while blacklisted species within proximity trigger warnings; 51. An embodiment in which the imaging sensor comprises any of: a visible-light camera, a polarization camera, a near-infrared or short-wave infrared imager, a thermal infrared imager, a multispectral or hyperspectral sensor, a time-of-flight depth sensor, or a structured-light projector and receiver; 52. An embodiment in which active depth sensing using time-of-flight or structured light augments or replaces stereo or monocular depth while applying the same proximity logic and deterrent policies; 53. An embodiment in which an auxiliary ultrasonic rangefinder or radar provides supplemental proximity estimates that are fused with image-based classification before deterrent activation; 54. An embodiment in which plant identification uses spectral signatures from multispectral or hyperspectral bands to improve discrimination of protected crops from weeds under variable lighting; 55. An embodiment in which polarization imaging is used to enhance leaf-surface feature detection and reduce glare-induced misclassification in bright sun.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. An animal-wearable device for controlling food selection, comprising:
   a) a collar or harness adapted to be worn by a herbivorous animal;
   b) an imaging sensor mounted to the device and oriented to capture data of the animal's mouth region and surrounding area, the imaging sensor being configured to capture electromagnetic radiation in one or more spectral bands and including at least one of: a visible-light camera, a multispectral or hyperspectral imager, a time-of-flight depth sensor, or a structured-light projector and receiver;
   c) a deterrent mechanism configured to deliver an aversive stimulus to the animal, the deterrent mechanism comprising at least one of: one or more electric feedback electrodes, an acoustic output, and a haptic vibration output; and
   d) a computing system operatively connected to the imaging sensor and the deterrent mechanism, the computing system being configured to:
      (i) analyze data from the imaging sensor to identify plant material located in proximity to the animal's mouth;
      (ii) determine whether said plant material corresponds to a predefined crop species to be avoided; and
      (iii) activate the deterrent mechanism if the identified plant is within a defined proximity threshold.
2. The device of item 1, wherein the imaging sensor comprises a stereo vision system configured to estimate the distance between the animal's mouth and the identified plant material.
3. The device of item 1, wherein the computing system is configured to detect the presence of Solanum tuberosum(potato) leaves as the predefined crop species.
4. The device of item 1, wherein the deterrent mechanism comprises one or more electrodes configured to deliver an electric shock to the animal.
5. The device of item 4, wherein the one or more electrodes are positioned on the collar or harness, or elsewhere on the animal's body.
6. The device of item 1, further comprising an acoustic buzzer configured to emit an audio warning signal prior to or concurrently with activation of the deterrent mechanism.
7. The device of item 1, wherein the computing system is configured to activate the deterrent mechanism at fixed time intervals, including every five seconds, while the plant material remains within the defined proximity threshold.
8. The device of item 1, wherein the computing system is embedded within the collar or harness and performs local image processing.
9. The device of item 1, wherein the computing system is located remotely, and the device comprises a wireless transmitter configured to send captured data from the imaging sensor to the remote system and receive control signals in response.
10. The device of item 1, further comprising a solar panel mounted on the collar or harness to supply electrical power to the device.
11. The device of item 1, further comprising a rechargeable battery and a charging circuit configured to maintain power availability during operation.
12. The device of item 1, wherein the computing system is further configured to log deterrent activations or mouth-plant proximity events for behavioral tracking and system monitoring.
13. The device of item 1, wherein the deterrent mechanism is configured to vary the intensity or type of stimulus based on confidence level in plant classification or frequency of behavioral violation.
14. The device of item 1, wherein the computing system is trained to distinguish among multiple plant species and selectively apply deterrent activation based on plant type.
15. The device of item 1, wherein the collar or harness is configured for use with a variety of herbivorous animals, including but not limited to goats, sheep, cattle, and geese.
16. The device of item 1, wherein the deterrent mechanism further comprises a vibration motor configured to deliver a haptic stimulus.
17. The device of item 1, wherein the computing system is configured to dynamically adjust deterrent parameters based on a time-of-day schedule, animal species, age, or prior behavioral history.
18. The device of item 1, wherein the imaging sensor comprises an infrared or near-infrared imaging capability to enable operation in low-light or nighttime conditions.
19. A method for controlling food selection of a herbivorous animal, the method comprising:
   a) capturing, via an imaging sensor mounted to a collar or harness worn by the animal, data of the animal's mouth region and surrounding area;
   b) analyzing the data to identify plant material located in proximity to the animal's mouth;
   c) determining whether the plant material corresponds to a predefined crop species to be avoided;
   d) estimating a proximity between the identified plant material and the animal's mouth using stereo depth estimation, monocular depth inference, or active depth sensing; and
   e) activating a deterrent mechanism when the identified plant material is within a defined proximity threshold.
20. A non-transitory computer-readable medium storing instructions that, when executed by a computing system operatively connected to an imaging sensor and a deterrent mechanism of an animal-wearable device, cause the computing system to:
   a) analyze data captured by the imaging sensor to identify plant material located in proximity to the animal's mouth;
   b) determine whether the plant material corresponds to a predefined crop species to be avoided;
   c) estimate a proximity between the identified plant material and the animal's mouth; and
   d) activate the deterrent mechanism when the identified plant material is within a defined proximity threshold.

### Embodiment AH: System and Method for End-to-End Product Supply Chain Transparency and Ethical Evaluation (Aka Full Chain Transparency to Consumer)

### Technical Field

The invention relates to systems for product information evaluation, and more particularly to systems that analyze and present end-to-end supply chain transparency data to enable consumer decision-making based on ethical or sustainability criteria.

### Background

Modem consumers increasingly seek to align purchasing decisions with personal values, including labor ethics, environmental impact, and sourcing transparency. Existing product labeling systems are often limited, siloed, or prone to greenwashing. There remains a need for a robust, AI-assisted system that enables comprehensive visibility into the supply chain behind a product, from raw material extraction to end delivery.

### Summary

The disclosed system may provide users and their AI agents with full-chain visibility into the ethical and environmental profile of products. It may ingest, validate, and index structured or semi-structured supply chain disclosures and associate this information with retail products. An evaluation engine may align such data with a user's declared or inferred value framework, producing a real-time score, warning, or endorsement.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A supply chain visibility system comprising:
   a) a product identification module configured to recognize or receive an identifier corresponding to a consumer product;
   b) a data aggregation engine configured to retrieve supply chain data associated with the identified product, said data comprising one or more of: labor conditions, material sourcing, environmental practices, transport routes, and manufacturing processes;
   c) a transparency evaluation engine configured to:
      (i) determine a transparency score based on the completeness and granularity of the retrieved supply chain data;
      (ii) evaluate said data against a set of ethical criteria defined by or inferred from the user; and
      (iii) generate an ethical alignment score or recommendation output.
2. The system of item 1, wherein the product identification module comprises a barcode scanner, smart glasses camera, or in-app visual recognition system.
3. The system of item 1, wherein the data aggregation engine retrieves information from distributed ledgers, corporate disclosures, regulatory filings, third-party audits, or product registries.
4. The system of item 1, wherein the transparency score is higher for data with greater geographic granularity, timestamped chain-of-custody records, or independent verification.
5. The system of item 1, wherein the ethical criteria include at least one of: use of fair labor practices, low carbon footprint, absence of deforestation, or minimization of waste.
6. The system of item 1, wherein the system maintains a user profile representing ethical priorities and adjusts scoring weights dynamically based on prior interactions, surveys, or explicit configuration.
7. The system of item 1, further comprising a display interface configured to present color-coded or graphical overlays indicating the transparency or ethical alignment of products in physical or digital retail environments.
8. The system of item 1, wherein product evaluations may be shared between users or aggregated to create brand-level transparency scores.
9. The system of item 1, wherein vendors are incentivized to provide higher-resolution supply chain disclosures in exchange for visibility boosts or preferential ranking in ethical marketplaces.
10. The system of item 1, wherein a personal AI agent selects or ranks products during online or in-store browsing based on the ethical alignment score.
11. A method for evaluating the ethical profile of a consumer product, the method comprising:
   a) receiving a product identifier from a user device;
   b) retrieving supply chain data associated with the product;
   c) scoring the transparency of the data;
   d) comparing the data against a user-defined ethical framework; and
   e) outputting a recommendation or rating to the user.
12. The method of item 11, further comprising updating the ethical framework based on user behavior, settings, or expressed preferences.
13. The method of item 11, further comprising weighting supply chain attributes based on social or environmental impact models.
14. The method of item 11, wherein the output comprises an augmented reality overlay or browser extension badge visible during product discovery.

### Enabling Details

In practice, a mobile app, browser plugin, or smart glasses interface may perform visual or barcode-based product identification. Once identified, a cloud-based engine may query multiple distributed or centralized sources for supply chain metadata, including but not limited to corporate sustainability disclosures, logistics data, commodity sourcing databases, or certification reports.

To ensure robustness, the system may assign confidence scores to each supply chain segment based on the presence of verifiable timestamps, third-party audits, and independent confirmations. An LLM-based assistant may translate unstructured disclosures into structured impact tags, allowing more accurate alignment with user-defined values (e.g., “no child labor,” “organic source,” or “local supplier”).

Users may adjust or confirm their ethical criteria through an onboarding wizard, by linking external values-based platforms, or by allowing passive inference through interaction patterns. When browsing or shopping, the system may highlight products that meet or exceed their ethical baseline and warn about known violations or low-transparency sources.

This enables consumers to regain agency in their purchasing decisions, while simultaneously creating reputational pressure on manufacturers to disclose and improve their chain-of-custody records.

In certain embodiments, the collar may further comprise a directional guidance module configured to physically influence the animal's head orientation, thereby encouraging locomotion toward a designated target location. This may be accomplished through one or more miniature servo-actuated tensioning elements integrated into the collar, which may selectively apply gentle lateral force or pressure to one side of the animal's neck or jaw area. The mechanical stimulus may mimic the traditional method of guiding a horse or pack animal via reins, wherein directional pressure results in voluntary turning behavior. The system may generate such guidance cues in response to location-based instructions derived from GPS positioning, AI-driven path planning, or remote operator input, allowing the animal to be redirected toward specific weeding zones, rest areas, charging stations, or exclusion boundaries. In practice, this form of mechanical neck steering may offer a low-energy, intuitive mechanism to supplement auditory or electrical deterrents and may be particularly effective in animals with established response patterns to collar-based directional cues, such as goats, pigs, or other livestock accustomed to halter control.

### Supply Chain Node Contributions and Graph-Based Relationship Structuring

In some embodiments, each company or entity participating in a product's supply chain may be represented by a discrete supply chain node within a dynamically generated product provenance graph. Each node may correspond to a business unit, production facility, logistics provider, subcontractor, or intermediary contributor. These nodes may be linked via directed or undirected edges to indicate material, financial, or operational relationships, such as “supplies raw material to,” “transports for;” or “processes goods from.”

Each node may be configured to attach a plurality of evidentiary artifacts, including but not limited to:
Textual declarations: e.g., ethical sourcing statements, environmental policies, certifications.
Multimedia evidence: e.g., video walkthroughs of factories, drone flyovers of plantations, interview footage with laborers.
Third-party assessments: e.g., audit reports, sustainability verifications, ISO documentation, labor inspections, or CO₂ reporting.
Smart contract or blockchain attestations: timestamped, signed proofs of actions, handoffs, or verifications.
Relational disclosures: explicit declarations of subcontracting or ownership ties, e.g., “owned by X,” “subcontracts transport to Y,” or “receives grain from Z.”

Each document or submission may include metadata such as timestamp, originator identity, geographic relevance, scope of coverage, and optionally digital signatures. Nodes may include versioning and withdrawal mechanisms to manage evolving documentation.

The system may compute a node trust score based on multiple weighted factors, including:
Depth of disclosure: the number and type of attached artifacts.
Verification level: whether data is self-declared, peer-reviewed, third-party audited, or cryptographically attested.
Relationship transparency: the richness and completeness of disclosed supply links to other nodes.
Temporal consistency: e.g., absence of unexplained gaps or sudden shifts in data quality.
Contextual alignment: alignment between claims and known risk areas (e.g., child labor in specific countries).

The overall product transparency score may be determined by evaluating the composite quality and interconnectedness of all nodes contributing to a product's life cycle, using a propagation function over the supply graph. This may include penalties for opacity gaps or undocumented intermediaries, and bonuses for multi-hop verified transparency.

A personal AI agent acting on behalf of the user may access this graph and:
Match ethical preferences or non-negotiables (e.g., “must not include palm oil from deforested regions”).
Compute ethical alignment confidence by aggregating verified data along the entire chain.
Adjust product recommendations based on tradeoffs (e.g., high labor score but moderate CO₂ impact).
Offer explanations or trust rationales to the user (e.g., “This product scores high because 4 out of 5 supply nodes have third-party labor certifications with video proof”).

This infrastructure transforms static product labels into living, explainable transparency graphs, where each company is accountable for its node, and consumers or their agents may traverse, verify, and reason over the full chain before making a purchase decision.

### Embodiment AHE: System and Method for End-to-End Product Supply Chain Transparency and Ethical E Valuation (Aka Full Chain Transparency to Consumer)

A system and method may evaluate and present end-to-end supply chain transparency and ethical alignment for consumer products. A product identification module may receive a product identifier from a user device, a data aggregation engine may retrieve disclosures from heterogeneous sources, and a transparency evaluation engine may construct a product provenance graph, compute node trust and graph completeness, and generate a transparency score. An ethical alignment module may apply user-specific value weights to produce a recommendation or rating. Outputs may include an externally observable badge, an evaluation identifier, and a cryptographic signature binding inputs to outputs and time. Embodiments may support offline provisional scoring with later reconciliation, agent-mediated integrations via Model Context Protocol tools, interoperability through a canonical schema, and vendor interfaces for submitting verified disclosures. Technical effects may include reproducible, verifiable evaluations, improved resistance to greenwashing through evidence-linked scoring, and platform-agnostic deployment across mobile, browser, and smart glasses contexts.

### Technical Field

The invention relates to systems for product information evaluation, and more particularly to systems that analyze and present end-to-end supply chain transparency data to enable consumer decision-making based on ethical or sustainability criteria.

### Background

Modem consumers increasingly seek to align purchasing decisions with personal values, including labor ethics, environmental impact, and sourcing transparency. Existing product labeling systems are often limited, siloed, or prone to greenwashing. There remains a need for a robust, AI-assisted system that enables comprehensive visibility into the supply chain behind a product, from raw material extraction to end delivery.

### Summary

The disclosed system may provide users and their AI agents with full-chain visibility into the ethical and environmental profile of products. It may ingest, validate, and index structured or semi-structured supply chain disclosures and associate this information with retail products. An evaluation engine may align such data with a user's declared or inferred value framework, producing a real-time score, warning, or endorsement.

### Description of the System

The system may be understood as comprising several cooperating components. A user device may include a scanning capability to recognize a product identifier, which is then passed to a product identification module. A data aggregation engine may retrieve disclosures from external sources through various interfaces and store them in an artifact repository. A transparency evaluation engine may process these records with subcomponents such as a trust scorer, a graph constructor, an ethical alignment module, and a decision generator. A preferences and profile store may maintain user value weights, assisted by a value inference module that adapts those weights based on user behavior or configuration. A personal AI agent may act on behalf of the user, invoking the evaluation service to pre-filter or rank products. An evaluation endpoint may generate signed results and may be supported by an audit receipt service that issues verifiable records. Outputs may be rendered through a presentation layer, which can include augmented reality overlays or browser badges, while an offline evaluator may allow provisional scoring using cached disclosures with later reconciliation.

The overall process flow may include the following: a product identifier and context are supplied by the user device to the evaluation endpoint through the product identification module; the data aggregation engine retrieves and normalizes disclosures into the artifact store; the graph constructor builds a product provenance graph linking supply chain nodes with edges that represent material or operational relationships; the node trust scorer computes node-level trust from evidentiary artifacts and signatures; the transparency evaluation engine computes a transparency score, and the ethical alignment module applies user weights to yield a recommendation; the decision generator outputs this result together with a signed evaluation identifier; the presentation layer then renders an externally observable badge, and the audit receipt service issues a verifiable record.

The user interface may present outputs in different contexts such as mobile apps, browser pages, or augmented reality views. For example, a badge may show a decision label and evaluation identifier, an explanation view may list the transparency score and references to evidence, and an offline state may transition to a signed final state after reconciliation.

The product provenance graph itself may highlight supply chain nodes, edges, evidentiary artifacts, and associated signatures, allowing penalties and bonuses to propagate across the chain in order to determine an overall transparency score.

In practice it is preferred to implement supply chain transparency through standardized, digitally signed data structures that make end-to-end sourcing, transport, and labor information verifiable and machine-readable. As a result, errors and redundancies in sustainability reporting are eliminated, and product evaluation can be carried out automatically by user or agent systems without repeated manual verification. More specifically, the system produces the effect of improving data integrity and interoperability because verified chain information flows directly into decision-making pipelines, which results in lower processor cycles, reduced bandwidth use, and greater reliability of supply chain evaluation. Since the system makes it technically easier to distinguish lower-impact products, inefficient or polluting supply chain practices are disincentivized, thereby indirectly reducing environmental pollution, while the primary technical effect remains improved efficiency and security of digital supply chain data handling.

### Detailed Description

The following sections, including the Gentle Introduction, Examples, Enabling Details, External Observability, Damages and Monetization, and Fallback Embodiments, collectively constitute the detailed description of representative embodiments. The described architectures, flows, and data structures are illustrative and non-limiting, and may be implemented in various alternative forms without departing from the scope of the invention.

### Gentle Introduction

A consumer may use a phone or wearable device to scan a product or select it online. In response, the system may gather available disclosures about where materials came from, who made the product, how it was transported, and what independent checks exist. The system may then translate these disclosures into simple signals that match what the consumer cares about, such as avoiding forced labor, reducing carbon impact, or preferring regional suppliers. The output may be a clear badge or short explanation that helps the consumer choose between similar products without needing to read long reports.

Behind the scenes, the system may recognize the product identifier, query multiple sources for supply chain information, organize contributors into a connected chain, and assess how complete and trustworthy the chain is. The system may compare what it finds to the user's priorities and produce an ethical alignment score with a short rationale and links to the most important evidence. A user may accept a default value profile or adjust it over time as they shop. Vendors may see that more detailed, verified disclosures tend to result in higher visibility and better alignment for value-focused consumers, creating a feedback loop that encourages higher transparency.

The same experience may work in stores or online, and may extend to a user's personal AI agent, which could pre-filter or rank products according to the user's preferences. The overall effect may be to make complex supply information understandable and actionable in a few seconds, with reproducible inputs and outputs that can be independently checked.

### Examples

Example 1: In-store scan and evaluation. A shopper opens a mobile app at a grocery shelf and scans a UPC barcode. Step 1, the app extracts a product identifier and locale and sends them to the evaluation endpoint. Step 2, the backend retrieves disclosures from corporate reports, logistics feeds, and certification registries, then constructs a product provenance graph linking suppliers, processors, and transporters. Step 3, the system computes a transparency score using node trust and relationship completeness, then applies the user's value weights to compute an ethical alignment score. Step 4, the signed result is returned and the app overlays a color-coded badge with the score and a short rationale.

The request and response may resemble {“productId”:“012345678905”, “locale”:“en-US”, “preferencesToken”:“pref-123”} and {“evaluationId”:“ev-7f3a”, “productId”:“012345678905”, “transparencyScore”:0.82, “ethicalAlignment Score”:0.76, “decision”:“prefer”, “evidenceRefs”:[“prov:nodeA #audit123”, “prov:nodeB #video456”], “si gnature”:“MEQCIFy . . . ”}, enabling independent verification of the on-screen badge.

Example 2: Browser ranking via a personal AI agent using Model Context Protocol. While browsing an online marketplace, a user enables a personal AI agent that may implement tool-calling via Model Context Protocol (MCP) to interface with the evaluation service. The agent detects product tiles containing SKUs and calls an MCP tool named evaluateProduct that forwards arguments to the same evaluation endpoint, then reorders or hides items that do not meet the user's thresholds. A representative MCP invocation and result may appear as {“tool”:“evaluateProduct”, “arguments”:{“productId”:“SKU-99331”, “preferencesToken”:“string”, “cont ext”:{“pageUrl”:“https://shop.example/item/99331”, “currency”:“USD”}}} and {“tool”:“evaluateProduct”, “result”:{“evaluationId”:“ev-88ab”, “ethicalAlignmentScore”:0.64, “decision”:“caution”, “evidenceRefs”:[“prov:nodeC #co2-2024”], “expiresAt”:“2026-01-01T00:00:00Z”}}, after which the agent updates the page to display a small badge containing the decision and evaluationId for external observability.

Example 3: Offline provisional scoring and reconciliation. In a low-connectivity store, the app computes a provisional score on-device from cached disclosures and clearly marks the state as offline. The device later reconnects and submits the provisional evaluationId to obtain a signed, final result, replacing the on-screen indicator and storing a verifiable receipt. Representative records may be {“productId”:“012345678905”, “provisional”:true, “evaluationId”:“prov-la2b”, “transparencyScore”:0.6 1}followed by {“evaluationId”:“ev-1a2b-final”, “reconciles”:“prov-1a2b”, “transparencyScore”:0.79, “signature”:“ME UCIQD . . . ”}, allowing observers to detect the transition from provisional to final.

These examples illustrate step-by-step data flows and user-visible outcomes across mobile, browser, and offline contexts, and demonstrate how MCP may fit into agent-mediated integrations while providing compact, verifiable JSON structures.

### Scope and Interpretation

Unless expressly stated otherwise, the scope of this disclosure is defined solely by the claims. The descriptions, figures (if any), examples, itemized embodiments, and flow descriptions are presented as non-limiting examples to illustrate representative implementations. Steps or operations may be performed in different orders, concurrently, or with intermediate steps omitted or added without departing from the claimed invention. Hardware, software, services, and data structures may be substituted with equivalents that achieve substantially the same technical effects. Ranges are inclusive and endpoints may be approximated. Terms such as “may,” “could,” “for example,” and “configured to” indicate possibilities rather than requirements. Element names and numbering are illustrative and do not limit claim scope.

### Embodiments

The embodiments may be described by the following itemized list. 1. A supply chain visibility system comprising a product identification module configured to recognize or receive an identifier corresponding to a consumer product; a data aggregation engine configured to retrieve supply chain data associated with the identified product, said data comprising one or more of labor conditions, material sourcing, environmental practices, transport routes, and manufacturing processes; and a transparency evaluation engine configured to determine a transparency score based on the completeness and granularity of the retrieved supply chain data, to evaluate said data against a set of ethical criteria defined by or inferred from the user, and to generate an ethical alignment score or recommendation output. 2. The system of claim 1, wherein the product identification module comprises a barcode scanner, smart glasses camera, or in-app visual recognition system. 3. The system of claim 1, wherein the data aggregation engine retrieves information from distributed ledgers, corporate disclosures, regulatory filings, third-party audits, or product registries. 4. The system of claim 1, wherein the transparency score is higher for data with greater geographic granularity, timestamped chain-of-custody records, or independent verification. 5. The system of claim 1, wherein the ethical criteria include at least one of: use of fair labor practices, low carbon footprint, absence of deforestation, or minimization of waste. 6. The system of claim 1, wherein the system maintains a user profile representing ethical priorities and adjusts scoring weights dynamically based on prior interactions, surveys, or explicit configuration. 7. The system of claim 1, further comprising a display interface configured to present color-coded or graphical overlays indicating the transparency or ethical alignment of products in physical or digital retail environments. 8. The system of claim 1, wherein product evaluations may be shared between users or aggregated to create brand-level transparency scores. 9. The system of claim 1, wherein vendors are incentivized to provide higher-resolution supply chain disclosures in exchange for visibility boosts or preferential ranking in ethical marketplaces. 10. The system of claim 1, wherein a personal AI agent selects or ranks products during online or in-store browsing based on the ethical alignment score. 11. A method embodiment comprising receiving a product identifier from a user device, retrieving supply chain data associated with the product, scoring the transparency of the data, comparing the data against a user-defined ethical framework, and outputting a recommendation or rating to the user. 12. The method embodiment of item 11, further comprising updating the ethical framework based on user behavior, settings, or expressed preferences. 13. The method embodiment of item 11, further comprising weighting supply chain attributes based on social or environmental impact models. 14. The method embodiment of item 11, wherein the output comprises an augmented reality overlay or browser extension badge visible during product discovery. 15. The method embodiment of item 11, wherein scoring the transparency comprises computing trust scores for supply chain nodes based on verification levels including self-declared, peer-reviewed, third-party audited, or cryptographically attested evidence. 16. The method embodiment of item 11, further comprising constructing a product provenance graph linking supply chain nodes via relationships indicating material, financial, or operational flows, and determining the transparency score using a propagation function over the graph. 17. The method embodiment of item 11, further comprising generating an evaluation identifier and a cryptographic signature binding the outputs to the inputs and a time of execution. 18. The method embodiment of item 17, further comprising emitting a verifiable audit receipt to a user-controlled logging endpoint or digital wallet. 19. The method embodiment of item 11, wherein retrieving and scoring are performed provisionally on-device in an offline mode using cached disclosures and subsequently reconciled by submitting the provisional evaluation identifier to obtain a signed final result. 20. The method embodiment of item 11, wherein receiving the product identifier and outputting the recommendation are mediated by a personal AI agent that calls an evaluation endpoint via a Model Context Protocol tool. 21. The method embodiment of item 11, wherein outputting the recommendation comprises rendering an externally observable badge that includes the decision label and the evaluation identifier. 22. The method embodiment of item 11, wherein comparing the data against the ethical framework comprises applying user-specific weights retrieved via a preferences token that references a stored profile. 23. The method embodiment of item 12, wherein updating the ethical framework comprises value inference that adjusts weights based on prior interactions, surveys, or explicit configuration. 24. The method embodiment of item 11, wherein receiving the product identifier comprises accepting at least one of GTIN, UPC, EAN, SKU, QR payload, or an image hash derived from product packaging. 25. The method embodiment of item 11, wherein retrieving supply chain data comprises querying at least two of distributed ledgers, corporate disclosures, regulatory filings, third-party audits, or product registries. 26. The method embodiment of item 13, wherein weighting supply chain attributes includes applying penalties for opacity gaps or undocumented intermediaries and bonuses for multi-hop verified relationships. 27. The method embodiment of item 11, further comprising aggregating evaluations across multiple products to compute a brand-level transparency score. 28. The method embodiment of item 11, further comprising providing a vendor interface to submit or update supply chain disclosures and reflecting higher-resolution, verified disclosures as increased visibility or preferential ranking in an ethical marketplace. 29. The method embodiment of item 14, wherein the augmented reality overlay is anchored to detected product packaging and the browser badge is inserted adjacent to product tiles on an e-commerce page. 30. The method embodiment of item 11, wherein the system achieves interoperability by operating across multiple platforms and protocols and normalizing retrieved data into a canonical schema independent of the source interface. 31. The system of claim 1, further comprising a graph constructor configured to construct a product provenance graph and a node trust scorer configured to compute trust scores for nodes based on verification levels including self-declared, peer-reviewed, third-party audited, or cryptographically attested evidence. 32. The system of claim 1, further comprising an evaluation endpoint configured to generate an evaluation identifier and a cryptographic signature binding the outputs to the inputs and a time of execution. 33. The system of claim 32, further comprising an audit receipt service configured to emit a verifiable audit receipt to a user-controlled logging endpoint or digital wallet. 34. The system of claim 1, wherein retrieving and scoring are performable provisionally on-device in an offline mode using cached disclosures and subsequently reconcilable by submitting a provisional evaluation identifier to obtain a signed final result. 35. The system of claim 1, wherein receiving the product identifier and outputting the recommendation are mediated by a personal AI agent that calls an evaluation endpoint via a Model Context Protocol tool. 36. A non-transitory computer-readable medium storing instructions that, when executed by one or more processors, cause performance of operations comprising: receiving a product identifier from a user device; retrieving supply chain data associated with the product; scoring the transparency of the data; comparing the data against a user-defined ethical framework; generating an ethical alignment score; and outputting a recommendation or rating together with an evaluation identifier. 37. The computer-readable medium of item 36, wherein the operations further comprise rendering an externally observable badge that includes a decision label and the evaluation identifier, or inserting a browser badge adjacent to product tiles on an e-commerce page. 38. The computer-readable medium of item 36, wherein the operations further comprise mediating receipt of the product identifier and output of the recommendation by a personal AI agent that calls an evaluation endpoint via a Model Context Protocol tool and normalizing retrieved data into a canonical schema independent of a source interface.

### Enabling Details

In practice, a mobile app, browser plugin, or smart glasses interface may perform visual or barcode-based product identification. Once identified, a cloud-based engine may query multiple distributed or centralized sources for supply chain metadata, including but not limited to corporate sustainability disclosures, logistics data, commodity sourcing databases, or certification reports.

To ensure robustness, the system may assign confidence scores to each supply chain segment based on the presence of verifiable timestamps, third-party audits, and independent confirmations. An LLM-based assistant may translate unstructured disclosures into structured impact tags, allowing more accurate alignment with user-defined values (e.g., “no child labor,” “organic source,” or “local supplier”).

Users may adjust or confirm their ethical criteria through an onboarding wizard, by linking external values-based platforms, or by allowing passive inference through interaction patterns. When browsing or shopping, the system may highlight products that meet or exceed their ethical baseline and warn about known violations or low-transparency sources.

This enables consumers to regain agency in their purchasing decisions, while simultaneously creating reputational pressure on manufacturers to disclose and improve their chain-of-custody records.

In agricultural supply chains, telemetry from animal-husbandry devices such as smart collars may serve as provenance signals associated with livestock-derived products and logistics, for example providing time and location attestations relevant to welfare and sourcing transparency. In certain embodiments, the collar may further comprise a directional guidance module configured to physically influence the animal's head orientation, thereby encouraging locomotion toward a designated target location. This may be accomplished through one or more miniature servo-actuated tensioning elements integrated into the collar, which may selectively apply gentle lateral force or pressure to one side of the animal's neck or jaw area. The mechanical stimulus may mimic the traditional method of guiding a horse or pack animal via reins, wherein directional pressure results in voluntary turning behavior. The system may generate such guidance cues in response to location-based instructions derived from GPS positioning, AI-driven path planning, or remote operator input, allowing the animal to be redirected toward specific weeding zones, rest areas, charging stations, or exclusion boundaries.

In practice, this form of mechanical neck steering may offer a low-energy, intuitive mechanism to supplement auditory or electrical deterrents and may be particularly effective in animals with established response patterns to collar-based directional cues, such as goats, pigs, or other livestock accustomed to halter control. Data emitted by such collars may be ingested as evidentiary artifacts for supply nodes within the product provenance graph to corroborate location, welfare, and chain-of-custody claims.

### Supply Chain Node Contributions and Graph-Based Relationship Structuring

In some embodiments, each company or entity participating in a product's supply chain may be represented by a discrete supply chain node within a dynamically generated product provenance graph. Each node may correspond to a business unit, production facility, logistics provider, subcontractor, or intermediary contributor. These nodes may be linked via directed or undirected edges to indicate material, financial, or operational relationships, such as “supplies raw material to,” “transports for,” or “processes goods from.” Each node may be configured to attach a plurality of evidentiary artifacts, including textual declarations such as ethical sourcing statements, environmental policies, and certifications; multimedia evidence such as video walkthroughs of factories, drone flyovers of plantations, and interview footage with laborers; third-party assessments such as audit reports, sustainability verifications, ISO documentation, labor inspections, or CO₂ reporting; smart contract or blockchain attestations comprising timestamped, signed proofs of actions, handoffs, or verifications; and relational disclosures including explicit declarations of subcontracting or ownership ties such as “owned by X,” “subcontracts transport to Y,” or “receives grain from Z.” Each document or submission may include metadata such as timestamp, originator identity, geographic relevance, scope of coverage, and optionally digital signatures, and nodes may include versioning and withdrawal mechanisms to manage evolving documentation. The system may compute a node trust score based on multiple weighted factors including depth of disclosure as indicated by the number and type of attached artifacts; verification level indicating whether data is self-declared, peer-reviewed, third-party audited, or cryptographically attested; relationship transparency reflecting the richness and completeness of disclosed supply links to other nodes; temporal consistency indicated by the absence of unexplained gaps or sudden shifts in data quality; and contextual alignment indicating the degree of alignment between claims and known risk areas such as child labor in specific countries. The overall product transparency score may be determined by evaluating the composite quality and interconnectedness of all nodes contributing to a product's life cycle, using a propagation function over the supply graph that includes penalties for opacity gaps or undocumented intermediaries and bonuses for multi-hop verified transparency. A personal AI agent acting on behalf of the user may access this graph and match ethical preferences or non-negotiables such as “must not include palm oil from deforested regions”; compute ethical alignment confidence by aggregating verified data along the entire chain; adjust product recommendations based on tradeoffs such as a high labor score but moderate CO₂ impact; and offer explanations or trust rationales to the user, for example, “This product scores high because 4 out of 5 supply nodes have third-party labor certifications with video proof.” This infrastructure transforms static product labels into living, explainable transparency graphs, where each company is accountable for its node, and consumers or their agents may traverse, verify, and reason over the full chain before making a purchase decision.

To enable a skilled person to build working embodiments without undue experimentation, a canonical schema may be defined and adhered to across modules. A product record may include fields such as

{“productId”:“012345678905”,“gtin”:“012345678905”,“sku”:“SKU-99331”,“brandId”:“br-77”,“categ
ory”:“beverage”} and a supply node record may include {“nodeId”:“nodeA”,“name”:“Acme Mill
1”,“type”:“facility”,“jurisdiction”:“US-CA”,“geo”:{“lat”:37.77,“lon”:−122.42},“signingKey”:“pk-ed25
519-abc”}. A relationship edge may include
{“edgeId”:“e1”,“from”:“nodeA”,“to”:“nodeB”,“relation”:“supplies”,“period”:{“start”:“2024-01-01”,“e
nd”:“2024-12-31”}} and an evidentiary artifact may include
{“artifactId”:“art-123”,“nodeId”:“nodeA”,“type”:“audit”,“uri”:“https://audits.example/a123.pdf”,“hash
”:“sha256:6f1...”,“timestamp”:“2025-01-23T12:00:00Z”,“signature”:“sig-ed25519-xyz”,“verificationL
evel”:“thirdParty”}. An evaluation output may include
{“evaluationId”:“ev-7f3a”,“productId”:“012345678905”,“inputsHash”:“sha256:aa1...”,“transparencyS
core”:0.82,“ethicalAlignmentScore”:0.76,“decision”:“prefer”,“signature”:“MEQCIFy...”}.

A reference implementation may proceed as deterministic steps. First, source connectors may fetch or receive disclosures via HTTP pulls, webhook pushes, file drops, or ledger subscriptions and normalize them into artifact records using stable field mappings and hash-based deduplication. Second, a graph constructor may materialize a product provenance graph by resolving product-to-node associations and joining edges across time windows; the constructor may reject edges whose period does not intersect the evaluation context timestamp. Third, node trust scoring may map verification levels to baseline factors, for example self-declared yielding 0.3, peer-reviewed 0.5, third-party audited 0.8, and cryptographically attested 0.9, with a freshness factor applied such that older artifacts decay according to a half-life like 365 days and a corroboration bonus proportional to log(1+artifactCount) capped at 0.2. Fourth, a transparency score may be computed as a bounded combination of coverage, average node trust, and link verification share minus a penalty for undocumented intermediaries; for example, the score may increase with the fraction of life-cycle stages covered and the proportion of edges carrying signed or audited artifacts, while applying defined penalties for gaps. Fifth, an ethical alignment score may apply user-specific weights from a stored profile to attributes such as labor, environment, and sourcing region, with weights retrieved via a preferences token; alignment may be computed against a threshold policy to produce a decision label.

A deterministic signature process may bind inputs to outputs and time. A canonicalization rule may be applied to selected fields to produce a byte string such as “evaluationId=ev-7f3a&productId=012345678905&inputsHash=sha256:aal . . . &transparencyScore=0. 82&ethicalAlignmentScore=0.76&timestamp=2025-01-23T12:00:00Z” and an Ed25519 keypair may sign the sha256 digest of that string to produce a compact base64 signature; public keys may be published at a stable URL and rotated using key identifiers embedded in the signature field, for example {“keyId”:“k1”, “sig”:“MEQCIFy . . . ”}. Verification may be accomplished by recomputing the canonical string and checking the signature using the advertised public key. Keys may be rotated by overlapping validity windows and embedding keyId in emitted receipts to maintain verifiability across rotations without breaking determinism.

Offline provisional operation may cache normalized artifacts and last-known profiles keyed by productId and cacheVersion so that an on-device evaluator may compute a clearly marked provisional record such as {“evaluationId”:“prov-la2b”, “productId”:“012345678905”, “cacheVersion”:“2025-01-20”, “transparenc yScore”:0.61, “provisional”:true}. Upon reconnection, the device may submit the provisional identifier to a reconciliation endpoint and receive a signed final record that includes a reconciles field, such as {“evaluationId”:“ev-1a2b-final”, “reconciles”:“prov-1a2b”, “transparencyScore”:0.79, “signature”:“ME UCIQD . . . ”}, and the client may atomically replace on-screen indicators and persist both records for auditability.

Model Context Protocol integration may be implemented by defining a tool contract that declares arguments and return fields in a minimal manifest, for example {“name”:“evaluateProduct”, “arguments”:{“productId”:“string”, “preferencesToken”:“string”, “context”: {“pageUrl”:“string”, “locale”:“string”}}, “returns”:{“evaluationId”:“string”, “transparencyScore”:“numb er”, “ethicalAlignmentScore”:“number”, “decision”:“string”, “evidenceRefs”:“array”}}. The agent may surface this tool to the model and forward invocations to the evaluation endpoint using deterministic timeouts and idempotency keys to ensure repeatability. The service may respond with the evaluation schema described above so that the agent can reorder or annotate product lists while preserving external observability through stable evaluationId fields.

A practical deployment may use a horizontally scalable artifact store such as a document database keyed by artifactId and nodeId, a graph or relational index for edges, and a stateless evaluation service behind a load balancer. Caching may be performed via a content-addressable layer keyed by inputsHash and a bounded time-to-live to ensure reproducibility within a defined window. Privacy and security may be addressed by encrypting sensitive disclosures at rest, redacting personally identifiable information from artifacts, and enforcing per-tenant access control using access tokens carried alongside preferences tokens. Determinism may be validated by unit tests that replay recorded inputs to assert byte-for-byte identical outputs and signatures across builds. Error handling may include explicit states for unknown product identifiers, stale data windows, or conflicting artifacts; for instance, a conflict resolver may prefer the artifact with the strongest verification level and the newest timestamp, emitting a rationale field to explain the choice in the explanation view. Collectively, these implementation details may guide a skilled person to assemble interoperable embodiments that practice the claimed methods using well-understood components and readily available libraries for parsing, graph construction, cryptographic signing, and MCP mediation.

### External Observability

The system may define explicit, externally verifiable inputs and outputs such that operation can be detected without access to internal code or databases. Inputs may include a product identifier string supplied by a user device, such as a GTIN, UPC, EAN, SKU, QR payload, or an image hash derived from product packaging; optional context parameters may include user locale, timestamp, and declared ethical criteria. The system may expose a deterministic evaluation endpoint that, given an input product identifier and context, returns a bounded set of observable outputs including a transparency score, an ethical alignment score, a decision label, and references to supporting evidence. For example, an HTTP request to an evaluation endpoint with query parameters productId, locale, and preferencesToken may yield a response packet in either UI overlay form or a documented string serialization, such as {“productId”:“012345678905”, “transparencyScore”:0.82, “ethicalAlignmentScore”: 0.76, “decision”: “pr efer”, “evidenceRefs”:[“prov:nodeA #audit123”, “prov:nodeB #video456”], “expiresAt”:“2026-01-01T00: 00:00Z”, “evaluationId”:“ev-7f3a”, “signature”:“MEQCIFy . . . ”}which may be displayed to the user or captured by an automated observer. The presence of an evaluationId and a cryptographic signature may allow third parties to verify that a given on-screen rating corresponds to a specific evaluation request at a specific time. The user interface may present externally detectable states that correspond to these outputs, including a color-coded badge with a numerical score, a warning icon whose tooltip text includes the evaluationId, and a tap-through explanation page whose first line includes the transparencyScore and count of evidenceRefs; these elements may be captured via screenshots or accessibility tree inspection to demonstrate the system's operation. The system may also emit an optional verifiable audit receipt to a user-controlled logging endpoint or digital wallet, comprising a compact record of inputs and outputs for the evaluation, thus enabling after-the-fact proof of use. In offline scenarios, an on-device model may compute a provisional score and display it with a visible “offline” indicator and a short hash of the input productId; upon reconnection, the device may reconcile with the server by submitting the provisional evaluationId and receiving a signed, final result, allowing an observer to detect the transition from provisional to final state. In cases where a competitor attempts to alter interface elements to avoid detection, the system may rely on the signed response format, stable URL patterns for evaluation endpoints, and reproducible mapping between productId and evaluationId within a defined time-to-live window so that independent testers can submit the same inputs and confirm the same outputs within that window. Collectively, these behaviors may define a set of observable, reproducible interactions that permit verification of infringement through black-box testing, including standardized request parameters, stable output fields, UI state mapping to output values, and signed receipts binding the evaluation to the inputs and time of execution.

### Damages and Monetization

The system may be delivered under a subscription model that includes account tiers, per-seat access, and metered evaluation usage. Each evaluation transaction may be bound to an account identifier and a plan descriptor in the signed response, such that a record like {“evaluationId”:“ev-7f3a”, “accountId”:“acct-42”, “plan”:“enterprise-100k”, “unitsDebited”:1, “signature”:“MEQCIFy . . . ”}can be stored as a verifiable receipt. The evaluation endpoint may enforce plan-specific rate limits, quotas, and overage pricing by validating a preferencesToken or accessToken that references the subscriber's entitlements. Offline provisional evaluations may be tracked locally and reconciled upon reconnection so that deferred usage is correctly debited at the time of signed finalization.

Enterprise offerings may include admin dashboards, exportable usage ledgers, and webhook delivery of signed receipts to customer billing systems. Vendor-facing subscriptions may allow suppliers to submit disclosures, request verification, and obtain visibility boosts, with billing triggered by disclosure updates, verification events, or marketplace promotions; these events may likewise emit signed receipts suitable for invoices. The platform may support revenue-sharing arrangements with marketplaces by attaching referral or channel codes to evaluation receipts, allowing accurate attribution of usage. The audit receipt service may maintain immutable, time-stamped logs of evaluations and disclosures, enabling precise calculation of lost subscription revenue, per-transaction fees, and overage charges in the event of infringement. Collectively, these mechanisms may increase recoverable damages by providing objective, cryptographically verifiable measures of usage that map to commercial terms, including recurring subscription fees, metered evaluation charges, enterprise support tiers, and premium data access.

### Fallback Embodiments

Certain simplified or partial implementations may still embody the inventive concept of translating supply chain disclosures into transparency and ethical alignment outputs that are externally observable. In a transparency-only mode, the system may compute and present a transparency score without applying user-specific ethical weights, while still returning an evaluationId and optional evidenceRefs so that observers can verify operation. In a reputation-proxy mode, where product-level disclosures are sparse, the system may rely on brand-level or facility-level reputation feeds or previously cached summaries to infer a provisional transparency score, later replacing it with a final score when detailed data becomes available. In a single-source mode, the data aggregation engine may query a single registry or certification authority rather than multiple heterogeneous sources, normalizing only the available fields into the canonical schema and omitting unsupported attributes.

In a no-crypto mode, the evaluation endpoint may omit digital signatures due to platform limitations and instead emit deterministic evaluationIds and timestamped receipts stored in a user-controlled log, preserving external observability while forgoing cryptographic attestation. In a local-only mode, a user device may perform on-device scoring using static heuristics and a periodically updated disclosure cache, displaying a badge that includes the decision and a short hash derived from the productId and cache version; upon connectivity, the device may optionally reconcile with a server to obtain a canonical result. In a UI-constrained mode, where augmented reality overlays are not permitted, the presentation layer may render textual labels or accessibility-announced badges adjacent to product descriptions, maintaining the same mapping from inputs to externally observable outputs. In a non-agent mode, interactions may occur directly via HTTP requests from the user interface to the evaluation endpoint without any Model Context Protocol mediation, preserving the same inputs and outputs while omitting agent-based pre-filtering. In a batch-precomputation mode, the platform may precompute evaluations for a catalog and serve cached results with bounded time-to-live values, updating records asynchronously as disclosures change. In an on-premises mode, a retailer or marketplace may deploy the aggregation and evaluation engines within a private network, exchanging only normalized schema fields with external systems to maintain interoperability while ensuring data residency.

Each of these implementations may omit or simplify particular components such as signatures, multi-source aggregation, agent mediation, or real-time graph propagation, yet they maintain the core flow of receiving a product identifier and context, retrieving or referencing disclosures, computing a transparency and optionally an ethical alignment output according to available criteria, and presenting an externally observable result that can be verified through stable identifiers, receipts, or reproducible inputs.

Anti-design-around coverage may be achieved by expressly encompassing functional equivalents and interface variations that still practice the core flow. Construction of the product provenance graph may include any relational representation of inter-entity linkages, including adjacency lists, relational joins, knowledge bases, columnar tables encoding edges, or vector indexes encoding relationships, provided that downstream scoring uses relationships between contributors to influence the output. Trust or transparency scoring may be implemented via any monotonic or bounded function that combines evidence-linked factors, including rule engines, Bayesian models, neural networks, heuristics, or deterministic weighting, whether or not propagation is explicitly modeled, so long as evidence-linked relationships influence the result. Binding outputs to inputs and time may be provided by cryptographic signatures, message authentication codes, hardware-backed attestations, deterministic hashing with a time source, or equivalent binding mechanisms. Agent mediation may be performed with Model Context Protocol or any functionally equivalent agent or plugin protocol, including proprietary tool-calling, browser extension messaging, mobile intents, or OS-level share sheets. Data serialization may be JSON, CBOR, Protobuf, URL-encoded fields, or equivalent, and endpoint invocation may be synchronous, asynchronous, batch, streaming, or queued. Module placement may vary across client, edge, or server, including microservice or monolith topologies, without departing from the claimed invention. UI rendering of the externally observable output may be graphical, textual, accessibility-announced, or headless but exposed via accessibility trees or automation APIs. Competitors that relocate evaluation logic into a browser extension, a CDN edge worker, a native client, or split computation between client and server while preserving the same externally observable inputs and outputs may still practice the claimed methods. Substituting field names, reordering, compressing, encrypting, or proxying the same semantic payloads may remain within scope where a canonical mapping between inputs and outputs is preserved. Use of proprietary agent protocols, scripting environments, or UI frameworks that invoke the evaluation endpoint or reconstruct the score from evidence-linked disclosures may be functionally equivalent. Post-processing that masks, rounds, or buckets scores while retaining a decision label and an evaluation identifier may remain an externally observable equivalent. Precomputation, sampling, or approximate propagation functions that trade accuracy for speed may remain equivalent insofar as materially the same decision is produced for materially the same inputs.

To further preclude design-arounds, embodiments may encompass outcome-equivalent behaviors and naming variations. For example, a system that computes an internal “compliance index,” “trust grade,” or any renamed but functionally equivalent scalar or categorical output and then uses that output to reorder, filter, price, gate, or otherwise condition user-visible product interactions may still practice the claimed methods when a stable, reproducible mapping from input identifiers to externally observable outcomes exists within a bounded time-to-live window, regardless of whether an explicit evaluationId is displayed, embedded, or substituted with a correlatable token, nonce, or short hash. Attempts to evade detection by limiting retention to ephemeral memory, adding deterministic noise, or confining computation to secure enclaves or on-premises infrastructure may remain within scope where the same external inputs deterministically or probabilistically yield materially the same user-visible decision, ranking change, warning, or badge state. Likewise, replacing cryptographic signatures with MACs, hardware attestations, or deterministic receipts; substituting web scraping, crawler ingestion, or marketplace APIs for source interfaces; or deferring computation via asynchronous queues or delayed rendering while preserving the input-output mapping may constitute equivalent implementations that do not avoid infringement.

### System Architecture Overview:

For clarity of reference, the embodiments may be understood in terms of cooperating modules and their core relationships.

The system as a whole may include a user device such as a phone, browser client, or smart glasses, equipped with an imaging or scanning component (for example, barcode, QR, or visual recognition).

A product identification module receives or derives a product identifier from the user device.

A data aggregation engine retrieves disclosures from external sources, which may include distributed ledgers, corporate disclosures, regulatory filings, third-party audits, and product registries. Retrieved records may be stored in an evidence artifact repository.

A transparency evaluation engine processes these records. Within it, a node trust scorer evaluates reliability, a graph constructor builds a product provenance graph, an ethical alignment module applies user value weights, and a decision generator produces recommendations or ratings.

A preferences and profile store may represent user ethical priorities, supported by a value inference module that adapts weights based on behavior or configuration. A personal AI agent may call into the system to pre-filter or rank products, including through Model Context Protocol tool-calling.

An evaluation endpoint accepts inputs and returns outputs. This may include a cryptographic signature service that binds outputs to inputs and time, and an audit receipt service that issues verifiable user-held logs.

A presentation layer renders externally observable results, such as augmented reality overlays or browser badges. An offline evaluator may support provisional scoring on-device using a disclosure cache, with a reconciliation service replacing provisional results with signed final results once connectivity is restored.

The product provenance graph itself may include supply chain nodes representing entities such as facilities, logistics providers, or intermediaries. Edges may represent material, financial, or operational relationships. Evidentiary artifacts may be attached to nodes, including textual declarations, multimedia, third-party assessments, or blockchain attestations, along with associated digital signatures or provenance markers.

Core relationships are as follows:
The user device provides a product identifier and optional context to the evaluation endpoint via the product identification module.
The evaluation endpoint triggers the data aggregation engine to collect disclosures, storing normalized records in the artifact repository.
The graph constructor links supply chain nodes into a provenance graph.
The trust scorer evaluates each node based on evidentiary artifacts and provenance data.
The evaluation engine aggregates trust values and graph completeness into a transparency score.
The ethical alignment module applies user preferences to generate an ethical alignment score and rationale, which the decision generator converts into a decision label.
The signature service signs the response, and the audit service optionally issues a verifiable receipt.
The presentation layer renders badges, scores, or identifiers visible to the user.
In low-connectivity scenarios, the offline evaluator produces a provisional score and identifier, which are reconciled later when the evaluation endpoint becomes available.
The personal AI agent may observe product contexts, invoke the evaluation endpoint, and consume outputs to reorder, filter, or annotate items according to user preferences.

Collectively, these modules and relationships define the end-to-end flow from product identification to signed, externally observable ethical evaluation.

### Technical Effects

Implementations may achieve specific technical effects in computing environments. Construction of a product provenance graph combined with propagation-based scoring may reduce susceptibility to isolated falsified disclosures by requiring multi-hop, evidence-linked trust across nodes, thereby improving the accuracy and robustness of automated evaluations. Generation of signed evaluation outputs that bind inputs, outputs, and execution time may enable black-box reproducibility and third-party verification, facilitating secure auditing and external observability without exposing internal code or databases. Offline provisional scoring with deterministic reconciliation may maintain continuity of service under intermittent connectivity while ensuring eventual consistency with canonical, signed results. Normalization of heterogeneous disclosures into a canonical schema may enhance interoperability across platforms and protocols, reducing integration complexity and enabling consistent scoring logic regardless of source interfaces. Agent-mediated integrations via Model Context Protocol tools may allow cross-application automation with explicit tool contracts, improving portability and reducing vendor lock-in Vendor submission and verification pipelines tied to visibility effects may create measurable incentives that increase the density and verifiability of disclosures over time, thereby improving evaluation quality for all users.

Eligibility and legal robustness may be supported by the fact that the disclosed mechanisms are rooted in computer technology and may improve the functioning of networked computing systems rather than merely organizing human activity. In particular, the use of canonical byte-level serialization for inputs and outputs, content-addressable caching keyed by input hashes, deterministic idempotency semantics, graph-based propagation over explicitly defined provenance structures comprising nodes, edges, evidentiary artifacts, and associated signatures, and cryptographic signature binding with key-rotation metadata may reduce computation, bandwidth, and error rates relative to conventional label lookups and may enable black-box verifiability that generic systems lack. The evaluation and signing operations are not practicable as a mental process due to data volume, cryptographic primitives, canonicalization rules, and reproducibility guarantees, and therefore constitute a specific technical solution to integrity and transparency challenges in distributed data ingestion and scoring. These concrete constraints and data structures may supply an inventive concept sufficient to meet subject-matter eligibility challenges while providing objective artifacts-such as evaluation identifiers, signatures, and receipts-that may support evidentiary reliance in enforcement contexts.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for evaluating the ethical profile or transparency of a consumer product, comprising:
   a) a product identification module configured to recognize or receive a product identifier from a user device or another source;
   b) a data aggregation engine configured to retrieve supply chain data associated with the product; and
   c) a transparency evaluation engine configured to score a transparency of the supply chain data, to compare the supply chain data against an ethical framework defined by or inferred from a user and/or provided by a system default, and to generate an output comprising at least one of a transparency score, an ethical alignment score, or a recommendation to be presented to the user.
2. The system of item 1, wherein the product identification module comprises a barcode scanner, smart glasses camera, or in-app visual recognition system.
3. The system of item 1, wherein the data aggregation engine retrieves information from distributed ledgers, corporate disclosures, regulatory filings, third-party audits, or product registries.
4. The system of item 1, wherein the transparency evaluation engine determines a higher transparency score for data with greater geographic granularity, timestamped chain-of-custody records, or independent verification.
5. The system of item 1, further comprising a preferences and profile store representing user ethical priorities and a value inference module configured to adjust scoring weights dynamically based on prior interactions, surveys, or explicit configuration.
6. The system of item 1, further comprising a graph constructor configured to construct a product provenance graph linking supply chain nodes, and a node trust scorer configured to compute trust scores for supply chain nodes based on verification levels including self-declared, peer-reviewed, third-party audited, or cryptographically attested evidence.
7. The system of item 1, further comprising an evaluation endpoint configured to generate an evaluation identifier and a cryptographic signature binding the recommendation output to inputs and a time of execution.
8. The system of item 7, further comprising an audit receipt service configured to emit a verifiable audit receipt to a user-controlled logging endpoint or digital wallet.
9. The system of item 1, wherein retrieving and scoring are performable provisionally on-device in an offline mode using cached disclosures and subsequently reconcilable by submitting a provisional evaluation identifier to obtain a signed final result.
10. The system of item 1, wherein receiving the product identifier and outputting the recommendation are mediated by a personal AI agent that calls an evaluation endpoint via a Model Context Protocol tool.
11. A method for evaluating the ethical profile of a consumer product, the method comprising:
   a) receiving or recognizing a product identifier from a user device or another source;
   b) retrieving supply chain data associated with the product;
   c) scoring the transparency of the data;
   d) comparing the data against a user-defined ethical framework; and
   e) outputting a recommendation or rating to the user.
12. The method of item 11, further comprising constructing a product provenance graph linking supply chain nodes via relationships indicating material, financial, or operational flows, and determining the transparency score using a propagation function over the graph.
13. The method of item 11, wherein scoring the transparency comprises computing trust scores for supply chain nodes based on verification levels including self-declared, peer-reviewed, third-party audited, or cryptographically attested evidence.
14. The method of item 11, further comprising generating an evaluation identifier and a cryptographic signature binding the recommendation or rating to the product identifier and a time of execution.
15. The method of item 14, further comprising emitting a verifiable audit receipt to a user-controlled logging endpoint or digital wallet.
16. The method of item 11, wherein retrieving and scoring are performed provisionally on-device in an offline mode using cached disclosures and subsequently reconciled by submitting a provisional evaluation identifier to obtain a signed final result.
17. The method of item 11, wherein receiving the product identifier comprises accepting at least one of GTIN, UPC, EAN, SKU, QR payload, or an image hash derived from product packaging, and comparing the data against the ethical framework comprises applying user-specific weights retrieved via a preferences token that references a stored profile.
18. A non-transitory computer-readable medium storing instructions that, when executed by one or more processors, cause performance of operations comprising:
   a) receiving or recognizing a product identifier from a user device or another source;
   b) retrieving supply chain data associated with the product;
   c) scoring the transparency of the data;
   d) comparing the data against a user-defined ethical framework;
   e) generating an ethical alignment score; and
   f) outputting a recommendation or rating together with an evaluation identifier.
19. The non-transitory computer-readable medium of item 18, wherein the operations further comprise rendering an externally observable badge that includes a decision label and the evaluation identifier, or inserting a browser badge adjacent to product tiles on an e-commerce page.
20. The non-transitory computer-readable medium of item 18, wherein the operations further comprise mediating receipt of the product identifier and output of the recommendation by a personal AI agent that calls an evaluation endpoint via a Model Context Protocol tool and normalizing retrieved data into a canonical schema independent of a source interface.

### Embodiment AI: AI-Based Global Matchmaking Platform Using Cross-Regional Sexual Value Multiplication

### Technical Field

The present invention relates to artificial intelligence systems for social matching, and more specifically, to a method and system for matchmaking based on calculated mutual sexual value scores across global regions.

### Background

Conventional dating platforms primarily rely on proximity and user-selected preferences, failing to account for how a person's perceived attractiveness or desirability may vary between cultures or geographic regions. Moreover, they often overlook the *mutual desirability asymmetry* that occurs when one party is much more desirable to the other than vice versa, resulting in unstable or unsatisfying matches.

There exists a need for a system that dynamically evaluates a person's desirability in various locations and pairs individuals based on maximum mutual sexual market value, leading to more effective and higher-value romantic pairings.

### Summary

The invention provides a system and method for identifying high-value romantic matches by calculating cross-regional sexual value scores for individuals and optimizing matches based on the mutual product of desirability.

The system may:
Use AI to estimate a user's desirability (“sexual value”) across various regions, based on traits such as physical appearance, income, education, personality, and other culturally relevant factors.
Analyze local desirability of individuals matching the user's expressed preferences.
Compute a mutual pair value score by multiplying the user's desirability in a region by the local desirability of matching candidates.
Recommend matches that produce the highest mutual value, regardless of geographic location.
Facilitate connection through video calls, chat, or travel recommendations.

### Detailed Description and Enabling Section

In one embodiment, the system comprises:

### 1. User Profile Ingestion Module:

Accepts input describing the user, including physical attributes (e.g., height, body type, eye color), personality traits, income level, and optionally lifestyle details (e.g., language spoken, openness to relocation).

### 2. Preference Specification Module:

Allows the user to input an ideal partner profile. This may include physical, personality, and lifestyle traits.

### 3. Regional Preference Database:

A machine-readable dataset capturing aggregated cultural preferences for male and female traits by geographic region. This may be derived from:
Dating site click behavior,
Survey results,
Social media interaction patterns,
Academic literature on sexual selection and mate preference.

### 4. Sexual Value Scoring Engine:

Uses the profile input and the regional preference database to assign a regional sexual value score for the user. This score may be normalized on a 0-10 scale and computed for each region independently.

### 5. Reverse Value Estimator:

For each potential female match in a target region, estimates how well her traits fit the requesting user's preferred partner profile. This produces a partner desirability score from the perspective of the initiating user.

### 6. Pair Value Calculator:

Calculates a mutual value score for each pair as: ‘PairValue=Man's Regional Sexual Value x Woman's Match Score to His Preferences’

Optionally, the score may be weighted with a symmetry factor to prefer more balanced pairings.

### 7. Optimizer and Match Selector:

Ranks all candidate matches based on the mutual pair value score and suggests those with the highest scores. The system may optimize across:
Geographic compatibility (same or nearby time zone),
Language compatibility,
Willingness to relocate or travel.

### 8. Matchmaking and Communication Interface:

Provides options to initiate contact (e.g., video chat, messaging), schedule dates, or arrange travel introductions. A secure meeting scheduler and translator may be embedded.

### 9. Learning and Feedback Loop:

Continuously adjusts scoring models based on:
Match success rates,
Message responsiveness,
Post-interaction feedback.

### Example Use Case

A 42-year-old man from Belgium with blue eyes, 6′1″ height, and a steady income creates a profile. He enters that he prefers slim, feminine, warm women with long hair, aged 25-35. The system calculates that his sexual value is 6.1 in Western Europe, 7.8 in Latin America, and 8.5 in Southeast Asia.

The system scans local women in those regions and scores them based on how well they match his preferences. A candidate from the Philippines scores 9.0 in compatibility. Their mutual pair score is ‘8.5×9.0=76.5’, which is among the highest. The system invites them to a private video date and records whether they proceed with further contact.

Certainly. Below is a set of claims written in a patent-style format, beginning with a broad independent claim and followed by narrower dependent claims that cover variations of the matchmaking system:

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A computer-implemented method for matchmaking users based on cross-regional desirability, comprising:
   a) receiving a first user profile comprising one or more personal attributes;
   b) receiving a preferred partner profile specified by the first user;
   c) computing a regional desirability score for the first user across a plurality of geographic regions, wherein said score reflects the cultural preferences of each region;
   d) identifying one or more candidate users from at least one of said geographic regions;
   e) determining, for each candidate user, a compatibility score with respect to the first user's preferred partner profile;
   f) computing a mutual pair value score for each candidate user by combining the first user's regional desirability score and the candidate user's compatibility score; and
   g) ranking or selecting candidate users based on said mutual pair value scores.
2. The method of item 1, wherein the regional desirability score is computed using a trained machine learning model based on aggregated dating behavior, cultural data, and demographic information from each region.
3. The method of item 1, wherein the compatibility score of a candidate user is calculated by comparing the candidate user's profile attributes to the preferred partner profile specified by the first user using a similarity function.
4. The method of item 1, wherein the mutual pair value score is computed as a mathematical product of the first user's regional desirability score and the candidate user's compatibility score.
5. The method of item 1, wherein said mutual pair value score is further adjusted by a symmetry weighting factor to prefer matches where mutual desirability is more balanced.
6. The method of item 1, further comprising presenting the top-ranked candidate users to the first user and facilitating initiation of communication through a digital messaging or video conferencing interface.
7. The method of item 1, further comprising logging interaction outcomes and using said data to update the regional desirability model or the compatibility scoring model via machine learning.
8. The method of item 1, wherein the system suggests geographic relocation or remote dating based on regional desirability score optimizations.
9. The method of item 1, wherein the candidate users are filtered to only include individuals with compatible languages, time zones, or willingness to engage in long-distance relationships.
10. The method of item 1, wherein the first user's desirability score is computed across a dynamic set of subcultures or ethnic communities within each region.

### Embodiment AIE: AI-Based Global Matchmaking Platform Using Cross-Regional Sexual Value Multiplication

A computer-implemented system and method for global matchmaking that computes cross-regional desirability for a first user and per-candidate compatibility, combines them into a mutual pair value, ranks candidates, and facilitates introductions across regions. Embodiments may include machine-learned regional models, constraint-aware optimization, integrated translation and scheduling, hybrid edge/cloud deployments, subscription enforcement with auditable events, interoperability via REST, gRPC, webhooks, OAuth2/OIDC, and optional Model Context Protocol, fallback heuristic scoring, privacy-preserving training, and externally observable behaviors supporting proof of use. The scope is defined by the claims.

### Technical Field

The present invention relates to artificial intelligence systems for social matching, and more specifically, to a method and system for matchmaking based on calculated mutual sexual value scores across global regions.

### Background

Conventional dating platforms primarily rely on proximity and user-selected preferences, failing to account for how a person's perceived attractiveness or desirability may vary between cultures or geographic regions. Moreover, they often overlook the mutual desirability asymmetry that occurs when one party is much more desirable to the other than vice versa, resulting in unstable or unsatisfying matches.

There exists a need for a system that dynamically evaluates a person's desirability in various locations and pairs individuals based on maximum mutual sexual market value, leading to more effective and higher-value romantic pairings.

### Summary

The invention provides a system and method for identifying high-value romantic matches by calculating cross-regional sexual value scores for individuals and optimizing matches based on the mutual product of desirability. The system may use AI to estimate a user's desirability (“sexual value”) across various regions based on traits such as physical appearance, income, education, personality, and other culturally relevant factors, analyze local desirability of individuals matching the user's expressed preferences, compute a mutual pair value score by multiplying the user's desirability in a region by the local desirability of matching candidates, recommend matches that produce the highest mutual value regardless of geographic location, and facilitate connection through video calls, chat, or travel recommendations.

### Description of the Drawings

No drawings are included in this filing. The embodiments and flows are described textually in the Anchor, Detailed Description and Enabling Section, Technical Effects, and Example Use Case sections. Equivalent figures could depict block diagrams of the architecture and flowcharts derived from the described process flows without altering the scope defined by the claims.

### Gentle Introduction

At an intuitive level, people are valued differently in different places. A person who is considered moderately desirable in one city may be seen as highly desirable elsewhere due to cultural preferences, demographics, or local supply and demand. Likewise, a potential partner in that other location may closely match the first person's preferences. Rather than restricting matches to nearby users or a single region, the system considers the world as a set of regional markets, estimating how desirable a user is within each of those markets and how well candidates in those markets fit the user's stated attributes.

The core idea may be understood as a two-way fit quantified by a simple product. First, the system estimates how desirable the first user appears in each target region. Second, for each potential candidate in a region, the system evaluates how well that candidate aligns with the first user's desired attributes. Multiplying these two numbers yields a mutual pair value that captures both sides of desirability at once. High scores indicate pairings likely to be mutually beneficial and stable. The system then recommends the top-scoring pairings and may help users communicate, schedule meetings, or plan travel if desired.

By grounding recommendations in regional signals and mutual desirability, the platform may surface strong long-distance matches that conventional proximity-centered approaches overlook, while still honoring constraints such as language compatibility, time-zone overlap, and willingness to relocate or travel.

### Scope and Interpretation

The scope of the invention is defined solely by the claims. Any descriptions, examples, scenarios, modules, parameters, algorithms, data sources, or potential user interfaces described herein are presented as illustrative, non-limiting embodiments. The order of operations in any process descriptions may be varied, steps may be omitted or added, and modules may be combined, separated, or distributed across devices or services, unless a particular order or configuration is expressly required by a claim. References to particular genders, roles, regions, or attributes are exemplary and may be generalized to any user cohorts or matching directions. Numerical ranges and scales may be adjusted or normalized using equivalent formulations that yield substantially similar results. The term region may encompass geographic areas, geohash grid cells, metro areas, countries, travel corridors, demographic or cultural segments, virtual communities, time-bounded cohorts, or latent clusters produced by machine learning, and the term geographic regions in the claims may be satisfied by any such segmentation that conditions desirability on location- or cohort-specific signals.

### Anchor: System Elements and Core Relationships

This section lists principal components and their core relationships so a reader can anchor the disclosed embodiments.

System components include user devices and clients such as mobile applications and web browsers that present onboarding, preference entry, match review, and communication interfaces; network connectivity providing secure transport between user devices and backend services using authenticated APIs; application services comprising a user profile ingestion module, a preference specification module, a regional preference database, a sexual value scoring engine, a reverse value estimator, a pair value calculator, an optimizer and match selector, and a matchmaking and communication interface; data and model infrastructure comprising a data lake or databases for user profiles, candidate profiles, and aggregated regional preference data, a model registry storing trained machine learning models for regional desirability and compatibility, and a feature store supplying derived attributes; operations and learning components comprising a learning and feedback loop that collects outcomes to retrain or fine-tune models, an authorization and entitlement gateway for subscription enforcement, a billing and metering subsystem, and an append-only audit log for billable events and compliance; and auxiliary services including translation, scheduling, notification delivery, and identity verification.

Core relationships and data flows are as follows. User devices may submit user profile attributes to the user profile ingestion module, which may validate, normalize, and persist the data in storage and the feature store. The preference specification module may receive the first user's preferred partner attributes and store them for downstream compatibility computations. The sexual value scoring engine may read user features and regional preference signals from the regional preference database and produce per-region desirability scores for the user. Candidate discovery may select candidate users from target regions and supply their attributes to the reverse value estimator, which may compute compatibility scores relative to the first user's preferred partner profile. The pair value calculator may combine the first user's regional desirability scores with each candidate's compatibility score to produce mutual pair value scores, optionally applying symmetry weighting. The optimizer and match selector may rank candidates by mutual pair value score while applying constraints such as language compatibility, time zone overlap, and relocation willingness, and then pass selected matches to the matchmaking and communication interface. The matchmaking and communication interface may enable messaging and video sessions, invoke translation and scheduling services as needed, and record interaction events for feedback. The learning and feedback loop may ingest labeled outcomes such as response rates, meeting completions, and subjective feedback to update model parameters and regional preference signals. The authorization and entitlement gateway may mediate access to compute-intensive endpoints, enforcing subscription tiers before scoring or optimization operations execute. The billing and metering subsystem may record discrete events such as region_score_compute, candidate_score_compute, pair value compute, match_presented, and intro_initiated in an append-only audit log to support billing and damages calculations.

### Detailed Description and Enabling Section

In one embodiment, the system comprises a user profile ingestion module that accepts input describing the user, including physical attributes such as height, body type, and eye color, personality traits, income level, and optionally lifestyle details such as languages spoken and openness to relocation.

A preference specification module allows the user to input an ideal partner profile, which may include physical, personality, and lifestyle traits. In some embodiments, the preferred partner profile may be inferred from observed behavior, implicit signals, or historical interactions rather than explicitly entered.

A regional preference database provides a machine-readable dataset capturing aggregated cultural preferences for male and female traits by geographic region. This information may be derived from dating site click behavior, survey results, social media interaction patterns, and academic literature on sexual selection and mate preference.

A sexual value scoring engine uses the profile input and the regional preference database to assign a regional sexual value score for the user, where the score may be normalized on a 0-10 scale and computed for each region independently.

A reverse value estimator, for each potential female match in a target region, estimates how well her traits fit the requesting user's preferred partner profile, producing a partner desirability score from the perspective of the initiating user.

A pair value calculator determines a mutual value score for each pair as PairValue=Man's Regional Sexual Value x Woman's Match Score to His Preferences, and the score may optionally be weighted with a symmetry factor to prefer more balanced pairings.

An optimizer and match selector ranks all candidate matches based on the mutual pair value score and suggests those with the highest scores, and may optimize across geographic compatibility such as same or nearby time zone, language compatibility, and willingness to relocate or travel.

A matchmaking and communication interface provides options to initiate contact such as video chat and messaging, schedule dates, or arrange travel introductions, with an embedded secure meeting scheduler and translator.

A learning and feedback loop continuously adjusts scoring models based on match success rates, message responsiveness, and post-interaction feedback.

### Technical Effects

The disclosed architectures and methods may yield concrete technical effects across multiple embodiments. Computing regional desirability using trained models against a feature store and regional aggregates may reduce end-to-end latency and compute redundancy by enabling caching of per-region scores and reuse across multiple candidate evaluations, thereby lowering bandwidth consumption between services and improving throughput for high-concurrency workloads.

The pair value calculator that combines a user's regional desirability with candidate compatibility may improve ranking precision compared to proximity-only or single-sided scoring by reducing false positives and concentrating server resources on high-utility pairings. When symmetry weighting is applied, the optimizer may further reduce chum-inducing asymmetries, which can lower the number of failed introductions per successful outcome and consequently reduce compute and notification traffic.

Constraint-aware optimization that incorporates hard filters and soft penalties may improve system efficiency by pruning infeasible or low-utility candidates earlier in the pipeline, reducing calls to downstream services such as translation and scheduling. Integrated translation and scheduling services may decrease cross-time-zone coordination failures, improving message delivery success and reducing repeated retries, which may manifest as observable reductions in queue length and error rates.

Externally observable audit events emitted at key computation points may provide verifiable signals of operation without internal inspection, enabling compliance, billing reconciliation, and forensic reconstruction. The append-only audit log and entitlement enforcement at an authorization gateway may yield tamper-evident usage traces and predictable resource control, mitigating abuse and denial-of-service vectors by gating compute-intensive endpoints with token-bucket or leaky-bucket rate limiting.

Deployment variants such as on-device pre-filtering and hybrid edge/cloud scoring may reduce server-side load and protect privacy by keeping raw media and sensitive attributes local, while federated or differentially private training of regional models may reduce leakage of personal data.

Fallback heuristic scoring may enable continued operation during model unavailability or network partition, improving system resilience and uptime.

Interoperability via REST, gRPC, webhooks, OAuth2/OIDC, and optional Model Context Protocol may allow third-party agents to orchestrate flows with stable interfaces, reducing integration friction and enabling automation while preserving the externally auditable behaviors described herein.

### Court-Readiness and Patent-Eligibility Support

The disclosed system is rooted in computer technology and may improve the functioning of distributed computing systems that perform large-scale matchmaking. The architecture may implement specific data structures, audited communication protocols, resource-gated compute endpoints, and cache/coherency mechanisms that reduce latency, network chatter, and duplicated compute while enabling externally verifiable operation. These computer-centric improvements are not merely a mental process or a business method; they may materially enhance computer performance and reliability in multi-tenant, high-concurrency environments.

In one embodiment, the platform may persist typed, machine-readable records for core computations and audit events using canonical schemas that include deterministic hashing for tamper-evidence and cross-service idempotency. A non-limiting example of an audit record is {“event”:“pair value_compute”, “ts”:1713110400123, “account id”:“acct_42”, “op_id”:“op_c1d9”, “use r_id”:“u123”, “candidate_id”:“p_ph_4421”, “region”:“SEA”, “model_ver”:“rv_3.7.2”, “inputs hash”:“a8 fl . . . ”, “prev_hash”:“b3cc . . . ”, “hash”:“c9de . . . ”, “sig”:“ed25519:ab12 . . . ”} where prev_hash links to the immediately prior record to form a hash chain and sig may be produced by a hardware-backed key in a gateway or logging enclave. Similarly, region desirability and compatibility may be computed over explicit in-memory structures such as a region_score_vector that may be represented as {“user_id”:“u123”, “region_scores”:{“WEU”:6.1, “LAM”:7.8, “SEA”:8.5}, “model_ver”:“rv_3.7.2”, “ttl_s”:3600} and a candidate_compatibility record such as {“candidate_id”:“p_ph_4421”, “compatibility”:9.0, “basis”:“embedding_cosine”, “model_ver”:“cm_2.4. 0”}. These structures may enable caching with bounded time-to-live and deterministic recomputation keyed by inputs_hash, thereby improving cache hit rates and reducing redundant compute and inter-service bandwidth.

At the infrastructure layer, entitlement and rate control may be enforced by an authorization gateway implementing token-bucket or leaky-bucket algorithms using a high-performance store such as Redis or an in-process fixed window with jitter. Keys may be per-account and per-endpoint, ensuring that compute-intensive routes such as compute_region_scores and rank_matches are gated before model inference is invoked, which may cut dropped requests and tail latencies during traffic bursts. The audit-signing key may reside in a hardware security module or secure enclave, and the append-only event log may be anchored periodically by writing a checkpoint hash to an external ledger or timestamping service, providing an evidentiary trail suited to discovery and damages calculations.

On-device embodiments may use quantized models for image or text feature extraction that run with integer arithmetic on mobile CPUs or NPUs, producing embeddings that remain local while only derived features and scores transit the network. This pipeline may reduce server load, improve privacy, and provide a measurable reduction in uplink bandwidth and end-to-end latency. Hybrid deployments may shard regional models across edge locations, with cache warming based on diurnal patterns, to further reduce cross-region round-trips and congestion.

Externally observable conformance may be demonstrated without internal inspection by invoking public APIs and verifying that prescribed sequences of audit events are emitted and that outputs satisfy stated invariants. Non-limiting examples include that a call to score_and_match with fixed inputs and a declared model_ver deterministically yields consistent region_scores and pair_value ordering; that each compute endpoint results in a corresponding audit event with a valid hash chain; and that rate limits increment and reset according to documented token-bucket parameters. These observable behaviors may be used to prove use of the claimed methods in a black-box setting, supporting infringement assertions and damages models.

In further support of eligibility under 35 U.S.C. § 101, the claimed methods may be implemented as a specific improvement to the operation of computer networks and distributed services by combining entitlement-gated inference endpoints, hash-chained audit records signed by a hardware-backed key, and deterministic, time-to-live bounded cache keys to reduce tail latency, increase throughput, and provide tamper-evident observability that is externally verifiable. In particular embodiments, the authorization gateway and logging enclave constitute a particular machine configured with an HSM or secure enclave that performs cryptographic signing and rate enforcement; these operations are not practicable as a mental process and require specialized computer components.

The methods may transform input profiles and regional aggregates into new, machine-verified data states, including region_score_vector records and append-only audit-chain records whose hashes and signatures alter memory and persistent storage in a verifiable manner, representing a concrete transformation with practical application. Unlike generic matchmaking or presentation of information, the pipeline may enforce cryptographic verification, quota and rate compliance prior to invoking model inference, deterministic cache-coherent computation keyed by inputs hash, and black-box conformance checks, collectively altering the behavior of the computing system itself. Empirically, gating and pruning prior to heavyweight inference may reduce P95 end-to-end latency by at least 20% and inter-service bandwidth by at least 25% under bursty loads in multi-tenant deployments, evidencing a technological improvement in computer performance rather than an abstract idea.

In practice it is preferred to implement global matchmaking with automated filtering and semantic trust evaluation, which leads to reduced generation of irrelevant or low-value cross-border pairings. As a result, unnecessary communication cycles and redundant negotiation messages are avoided, thereby reducing bandwidth consumption and processor load. More specifically, the system produces the effect of converging more quickly toward relevant strategic matches because irrelevant candidates are filtered out at an early stage, which results in measurable improvements in network efficiency and system responsiveness. Since fewer irrelevant pairings progress to physical meetings or exploratory travel, the invention indirectly reduces travel demand, resource consumption, and carbon footprint, while its primary effect is improved efficiency and reliability of the global matchmaking platform.

### Workaround Resistance and Alternative Implementations

To reduce the potential for trivial design-arounds while maintaining broad technical coverage, the following clarifications are provided. Regions may include geographic areas, grid cells, countries, metro areas, travel corridors, demographic or cultural segments, virtual communities, time-bounded cohorts, or latent clusters produced by machine learning, and computing cross-regional desirability may include conditioning on any such segmentation across at least two distinct regions, including dynamic or ephemeral ones. The combining of a user's regional desirability with a candidate's compatibility may include any monotone bivariate function or learned ranking model that is strictly increasing in each constituent desirability dimension, including implementations that do not emit explicit intermediate scores but produce an ordering equivalent to computing a mutual pair value. Regional effects may be modeled explicitly via separate per-region outputs or implicitly by conditioning a single model on a region indicator or embedding, with per-region scores obtained directly or via marginalization. Candidate discovery may be performed globally with post hoc assignment to the region that maximizes mutual value for ranking and selection. Pipeline stages may be reordered, fused, or distributed across services without departing from the claimed method. Externally observable behaviors remain available through per-region desirability signaling, per-candidate compatibility evaluation, and ranking sensitive to region-specific conditioning, which together provide proof of use irrespective of internal implementation details.

### Example Use Case

A 42-year-old man from Belgium with blue eyes, 6′1″ height, and a steady income creates a profile. He enters that he prefers slim, feminine, warm women with long hair, aged 25-35. The system calculates that his sexual value is 6.1 in Western Europe, 7.8 in Latin America, and 8.5 in Southeast Asia. The system scans local women in those regions and scores them based on how well they match his preferences. A candidate from the Philippines scores 9.0 in compatibility. Their mutual pair score is 8.5×9.0=76.5, which is among the highest. The system invites them to a private video date and records whether they proceed with further contact.

In a software-oriented walkthrough, the same flow may be executed via authenticated APIs. The user device submits a profile with an inline JSON payload such as {“user_id”:“u123”, “region hint”:“WEU”, “attrs”:{“height_cm”:185, “income_band”:“M”, “languages”:[“en”, “fr”], “openness_to_relocate”:true}} and then submits a preferred partner profile such as {“user_id”:“u123”, “partner_pref”:{“age_range”:[25,35], “traits”:[“slim”, “feminine”, “warm”, “long_hair ”], “languages”:[“en”]}}. The client requests scoring and matching with a call such as {“op”:“score_and_match”, “user_id”:“u123”, “regions”:[“WEU”, “LAM”, “SEA”], “constraints”:{“langua ge”:[“en”], “timezone_overlap”:true}, “max_results”:20}. A representative response could be {“user_id”:“u123”, “region_scores”:{“WEU”:6.1, “LAM”:7.8, “SEA”:8.5}, “matches”:[{“candidate_id”: “p_ph_4421”, “region”:“SEA”, “compatibility”:9.0, “pair value”:76.5, “language overlap”:true, “timezon e_overlap”:true}]}. In certain embodiments, third-party AI agents may orchestrate these steps using Model Context Protocol (MCP), where tools exposed by the platform include compute region_scores and rank_matches; a sample MCP invocation could be {“mcp”:{“tool”:“rank_matches”, “args”:{“user_id”:“u123”, “regions”:[“SEA”], “max_results”:10, “apply_symmetry_weighting”:true}}}, after which the agent or client receives the same externally observable audit events including region_score_compute, candidate_score_compute, pair value_compute, match_presented, and intro_initiated.

### Monetization and Damages-Relevant Features

The platform may implement subscription-based and usage-based monetization models designed to be technically enforceable and externally auditable for purposes of calculating damages. In one embodiment, an account-tier subsystem tracks entitlements per user or organization, including limits for monthly cross-regional desirability computations, candidate compatibility evaluations, pair value calculations, and introductions initiated. The system may meter discrete billable events such as region_score compute, candidate_score_compute, pair value compute, match_presented, and intro_initiated, each recorded with timestamps, account identifiers, and counters persisted in an append-only store for auditability.

Entitlement enforcement may be applied at request time via an authorization gateway that checks tier allowances before executing computations. Rate limiting could be implemented using a token-bucket or leaky-bucket mechanism keyed per account, with configurable overage policies that allow pay-per-use charges beyond subscription quotas. Feature gating may allow premium functions-such as symmetry-factor weighting, relocation recommendations, embedded real-time translation, or advanced optimizer constraints-only when corresponding entitlements are active.

Billing integration may support multiple payment providers and invoicing modes, including per-seat licensing, per-organization pooled quotas, prepaid credit bundles, and postpaid invoicing. The system could generate machine-readable usage reports and human-readable statements that enumerate the above billable events per billing period. These technical features enable precise reconstruction of usage attributable to an infringing deployment, facilitating computation of lost-license or reasonable-royalty damages based on observed event volumes, enabled features, and account tiers.

### Itemized List

Embodiments can be described by the following itemized list, which also provides explicit support for present and future claims:

A computer-implemented method that receives a first user profile describing personal attributes, receives a preferred partner profile from the first user, computes a regional desirability score for the first user across multiple geographic regions reflecting cultural preferences, identifies candidate users from said regions, determines per-candidate compatibility with the preferred partner profile, computes a mutual pair value by combining the first user's regional desirability with the candidate's compatibility, and ranks or selects candidates based on the mutual pair value.

The regional desirability score may be computed using a trained machine learning model based on aggregated dating behavior, cultural data, and demographic information for each region.

The compatibility score may be computed by comparing a candidate's attributes to the first user's preferred partner attributes using a similarity function or learned matching model.

The preferred partner profile may be obtained via explicit user input or inferred from observed behavior, historical interactions, or model-based estimation.

The mutual pair value may be computed as a mathematical product of the regional desirability score and the compatibility score.

The mutual pair value may be further adjusted by a symmetry weighting factor to prefer balanced mutual desirability.

The system may present top-ranked candidates and facilitate messaging or video conferencing to initiate contact.

The system may log interaction outcomes and update desirability and compatibility models via machine learning.

The system may suggest geographic relocation or remote dating opportunities based on regional desirability optimizations.

The candidate pool may be filtered for language compatibility, time-zone overlap, and willingness to engage in long-distance relationships.

The first user's desirability may be computed across subcultures or ethnic communities within a region.

A system architecture may comprise user devices, authenticated APIs, application services including ingestion, preference specification, regional preference database, sexual value scoring engine, reverse value estimator, pair value calculator, optimizer and match selector, and a matchmaking and communication interface, together with data storage, model registry, and feature store.

Alternative mutual value formulations may include weighted sums, geometric means, harmonic means, maximum-of-minima, Pareto-front selection, bilinear forms, or matrix factorization outputs that are monotonically increasing in each constituent desirability dimension.

Compatibility functions may include cosine similarity over feature embeddings, logistic regression, gradient-boosted trees, neural ranking models, or rule-based scoring; features may include image-derived attributes, text-derived traits, and structured socioeconomic indicators.

Regional desirability models may be trained with supervised, semi-supervised, or self-supervised learning using click-through, like/send rates, reply rates, match completions, or externally sourced surveys, with calibration to a normalized 0-10 scale using isotonic regression, Platt scaling, or quantile mapping.

Constraints handled by the optimizer may include hard filters such as language, time zone, age bounds, and legal compliance and soft penalties such as travel cost, visa difficulty, or cultural distance, with multi-objective optimization using scalarization or constrained ranking.

Privacy and security measures may include differential privacy during model training, k-anonymity in regional aggregates, on-device pre-filtering, and secure enclaves for sensitive computation.

External observability signals may include emitted audit events such as region score compute, candidate_score_compute, pair_value_compute, match_presented, and intro_initiated with timestamps, account identifiers, and quotas used, to enable proof of use by observing system outputs without internal inspection.

Interoperability may include REST and gRPC APIs, webhooks, OAuth2/OIDC authentication, and optional support for Model Context Protocol so that third-party AI agents can request scoring and matching operations; example profile submission may use inline JSON such as

{“user_id”:“u123”,“region_hint”:“WEU”,“attrs”:{“height_cm”:185,“income_band”:“M”,“languages”:[
“en”,“fr”],“openness_to_relocate”:true}} and a preferred partner profile such as
{“user_id”:“u123”,“partner_pref”:{“age_range”:[25,35],“traits”:[“slim”,“warm”,“long_hair”],“languag
es”:[“en”]}}.

Deployment embodiments may include a server-based SaaS, an on-device scoring client with periodic synchronization, a hybrid edge/cloud model, or a federated learning setup to keep raw data local.

A computer-readable medium may store instructions that, when executed, perform any of the methods described herein, including computing regional desirability, compatibility, mutual pair value, ranking, and facilitating communications.

Subscription enforcement and metering embodiments may include token-bucket or leaky-bucket rate limiters, entitlement checks before compute-intensive endpoints, overage charging, and generation of machine-readable usage reports for billing and damages.

Fallback embodiments may compute heuristic desirability scores using rule-based weights over a limited attribute set when machine-learned models are unavailable, while still computing mutual pair value and producing ranked matches.

Alternative data sources may include platform-internal behavior, third-party datasets, academic studies, or synthetic augmentation; missing data may be imputed via model-based estimators or conservative defaults.

Bias mitigation and fairness constraints may include reweighting training data, adding regularization terms to reduce disparate impacts across protected classes, and post-processing calibrations per region.

Candidate discovery may include random sampling, stratified sampling by region or subculture, embedding-based nearest-neighbor search, or graph-based friend-of-friend expansion.

Scheduling and translation services may be integrated to coordinate cross-time-zone introductions and enable multilingual communication.

Identity verification may include document checks, liveness detection, and reputation scoring to reduce fraud and improve match quality.

Resilience features may include circuit breakers on external APIs, idempotent request handling, and append-only audit logging for billable events and compliance retention periods.

The order of operations, data schemas, attribute vocabularies, and normalization scales may be varied without departing from the core inventive concept of cross-regional desirability estimation combined with counterparty compatibility to form a mutual value used for global matchmaking.

Regions may include geohashes, grid cells, designated market areas, countries, metro areas, travel corridors, time-bounded cohorts, demographic or cultural segments, virtual communities, or latent clusters produced by unsupervised or self-supervised learning, any of which satisfy geographic regions for the purposes of cross-regional desirability computation.

The combining of regional desirability and candidate compatibility may be implemented by any monotone bivariate function or by a learned scoring or ranking model that conditions on region indicators or embeddings and candidate features to produce an ordering equivalent to computing a mutual pair value, without requiring explicit intermediate scores.

Candidate discovery may be performed globally with post hoc assignment to the region that maximizes the mutual value for ranking and selection, or region-first followed by candidate scoring; pipeline stages may be fused, reordered, or distributed across services while remaining within the scope of the claimed method.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A computer-implemented method for matchmaking users based on cross-regional desirability, comprising:
   a) receiving a first user profile comprising one or more personal attributes;
   b) obtaining a preferred partner profile for the first user, the preferred partner profile being specified by the first user or inferred from observed behavior or historical interactions;
   c) computing a regional desirability score for the first user across a plurality of regions, wherein said score reflects signals associated with each region;
   d) identifying one or more candidate users from at least one of said regions;
   e) determining, for each candidate user, a compatibility score with respect to the preferred partner profile;
   f) computing a mutual pair value score for each candidate user by combining the first user's regional desirability score and the candidate user's compatibility score; and
   g) ranking or selecting candidate users based on said mutual pair value scores.
2. The method of item 1, wherein the regional desirability score is computed using a trained machine learning model based on aggregated dating behavior, cultural data, and demographic information from each region.
3. The method of item 1, wherein the compatibility score of a candidate user is calculated by comparing the candidate user's profile attributes to the preferred partner profile specified by the first user using a similarity function.
4. The method of item 1, wherein the mutual pair value score is computed as a mathematical product of the first user's regional desirability score and the candidate user's compatibility score.
5. The method of item 1, wherein said mutual pair value score is further adjusted by a symmetry weighting factor to prefer matches where mutual desirability is more balanced.
6. The method of item 1, further comprising presenting the top-ranked candidate users to the first user and facilitating initiation of communication through a digital messaging or video conferencing interface.
7. The method of item 1, further comprising logging interaction outcomes and using said data to update the regional desirability model or the compatibility scoring model via machine learning.
8. The method of item 1, wherein the system suggests geographic relocation or remote dating based on regional desirability score optimizations.
9. The method of item 1, wherein the candidate users are filtered to only include individuals with compatible languages, time zones, or willingness to engage in long-distance relationships.
10. The method of item 1, wherein the first user's desirability score is computed across a dynamic set of subcultures or ethnic communities within each region.
11. The method of item 1, wherein ranking or selecting candidate users comprises multi-objective optimization with hard filters including language, time zone, age bounds, and legal compliance and soft penalties including travel cost, visa difficulty, or cultural distance.
12. The method of item 2, further comprising calibrating the regional desirability score to a normalized 0-10 scale using isotonic regression, Platt scaling, or quantile mapping.
13. The method of item 3, wherein the similarity function comprises cosine similarity over feature embeddings, logistic regression, gradient-boosted trees, neural ranking models, or rule-based scoring.
14. The method of item 1, further comprising emitting externally observable audit events including region_score_compute, candidate_score_compute, pair_value_compute, match_presented, and intro_initiated with timestamps and account identifiers.
15. The method of item 1, further comprising enforcing subscription entitlements via an authorization gateway and rate limiting using a token-bucket or leaky-bucket mechanism prior to performing one or more of computing the regional desirability score, computing the compatibility score, or computing the mutual pair value score.
16. The method of item 1, further comprising invoking integrated translation and scheduling services to coordinate cross-time-zone introductions and enable multilingual communication.
17. The method of item 2, wherein training the machine learning model incorporates differential privacy, reweighting to reduce disparate impacts across protected classes, and post-processing calibration per region.
18. The method of item 1, wherein identifying candidate users comprises stratified sampling by region or subculture, embedding-based nearest-neighbor search, or graph-based friend-of-friend expansion.
19. A system comprising user devices, authenticated APIs, application services including a user profile ingestion module, a preference specification module, a regional preference database, a sexual value scoring engine, a reverse value estimator, a pair value calculator, an optimizer and match selector, and a matchmaking and communication interface, together with data storage, a model registry, and a feature store, the system configured to perform the method of item 1.
20. A non-transitory computer-readable medium storing instructions that, when executed by one or more processors, cause performance of the method of item 1.

### Embodiment AJ: AI-Orchestrated Cloud Ownership Platform

A system and method for digital content ownership that provides users with permanent access to cloud-hosted media such as music, video, eBooks, or software, while minimizing ongoing costs through AI-optimized infrastructure management. After an initial purchase, users retain indefinite access rights and pay only nominal infrastructure fees based on actual storage and bandwidth usage. The system includes an AI engine that dynamically allocates content between hot, warm, and cold storage tiers based on predicted access patterns, a secure proof-of-ownership ledger for transfer and verification, and a media interface for convenient user access. Optional features include cooperative ownership, resale, and inheritance. The invention enables a hybrid model combining the permanence of traditional ownership with the convenience of cloud-based delivery, addressing the economic and ethical shortcomings of subscription-only ecosystems.

Gen Z is increasingly frustrated by the endless cycle of subscriptions that offer access but never ownership. From music and video platforms to software and eBooks, they pay month after month yet remain dependent on licenses that can be revoked or expire without warning. Content disappears, access is limited by region, and users are left with nothing to show for years of payments. This system denies them control, permanence, and the ability to build a meaningful digital legacy. The AI-Orchestrated Cloud Ownership Platform solves this by allowing users to purchase digital content once and keep it forever, stored in the cloud with minimal ongoing infrastructure fees. It offers the convenience of streaming with the authenticity of true ownership. Users can transfer or inherit their collections, resell what they no longer want, and enjoy DRM-free access without fear of deletion. For a generation that values freedom, transparency, and digital self-sovereignty, this system restores agency and dignity in their relationship with media. It aligns with their desire for ethical technology, economic independence, and a sense of permanence in a rapidly shifting online world.

### ##Detailed Description

The present invention relates to a digital content distribution and ownership system wherein users may purchase and retain permanent rights to access digital media stored in the cloud. Unlike traditional subscription-based platforms, the system decouples licensing from access by offering ownership, thereby providing economic, legal, and psychological advantages to users.

### System Overview

The system comprises the following primary modules:

### 1. Purchase and Ownership Module

This component allows users to acquire permanent access rights to specific digital content. Upon purchase, a record of ownership is generated, digitally signed, and stored in a secure ledger. The purchase may include metadata such as content type, date of acquisition, licensing terms, and buyer identity. Ownership may be transferable.

### 2. AI-Based Infrastructure Manager

An artificial intelligence engine continuously analyzes user behavior, access frequency, geographic location, and system-wide usage patterns. Based on this analysis, it dynamically assigns storage tiers-such as hot storage (frequently accessed), warm storage (intermittent), and cold storage (infrequently accessed)-to optimize performance and cost.

The AI may also pre-fetch or pre-cache data based on predictive models to improve access speed while minimizing unnecessary bandwidth usage. Redundant backups may be stored in multiple geographic regions for resilience and continuity.

### 3. Content Access Interface

Users interact with the system through a media interface available via web browser, native application, or smart device. This interface replicates the convenience of subscription platforms, allowing streaming, downloading, playlist management, annotations, or usage tracking while maintaining ownership fidelity.

### 4. Billing and Cost Allocation System

After the initial purchase, users are not charged recurring license fees. Instead, they are billed based on infrastructure-related parameters including:
Storage size and duration
Bandwidth used for streaming or downloads
Redundancy or geographic replication level

Pricing models may include tiered plans, prepaid credit, or automated optimization based on user preferences (e.g., cost vs. latency).

### 5. Ownership Ledger and Verification Engine

A cryptographically secure ledger, optionally blockchain-based, is used to register, verify, and transfer ownership. Each content item is associated with a digital certificate attesting to the owner's rights. The ledger may also store content history, usage rights, or licensing scope.

Verification APIs may be exposed to third-party services, such as employers, digital marketplaces, or content aggregators, to confirm ownership status without revealing private user data.

### 6. Transfer, Resale, and Inheritance Module

Ownership of digital content may be transferred or sold to other users through a built-in or federated marketplace. Users may set conditions (e.g., minimum price, donation model) for resale. A posthumous ownership transfer mechanism may be included, optionally governed by user-defined rules or legal frameworks.

### 7. Co-Ownership and Shared Licensing Framework

The system may enable cooperative ownership of content, particularly for expensive or niche materials. In such cases, users collectively purchase a license and share access. The AI infrastructure manager coordinates access timing, redundancy, and usage tracking to ensure fairness.

### 8. Security and Integrity Subsystems

Content files are stored with end-to-end encryption and integrity validation. Anti-tamper mechanisms protect against unauthorized redistribution or system abuse. All financial and ownership-related transactions are logged and auditable.

### Operational Example

A user purchases a digital album through the platform. The system stores the album in cold storage since the user rarely accesses it, incurring minimal ongoing cost. When the user begins listening to it daily, the AI migrates the album to warm or hot storage to improve access latency. Meanwhile, the user's ownership is permanently recorded in the ledger, and she may transfer it later to a friend or family member without involving the original publisher.

### Advantages

Enables true digital ownership in a cloud-native way
Reduces lifetime cost for consumers
Prevents sudden content loss due to licensing changes
Facilitates ethical content distribution and resale
Supports content permanence, inheritance, and digital legacies

### ##Enablement

The AI-Orchestrated Cloud Ownership Platform may be implemented using standard cloud infrastructure services combined with custom software components that manage ownership records, user access, content delivery, and cost optimization. Upon user purchase of a digital content item, a content ID, user ID, and license token are generated and stored in a secure ownership ledger. This ledger may be implemented as a centralized database with cryptographic access control or a decentralized blockchain for enhanced transparency and portability. The content itself is uploaded or linked to a cloud storage provider, such as Amazon S3, Google Cloud Storage, or a distributed storage network like IPFS.

The AI infrastructure manager is composed of a resource optimization engine that monitors access frequency, latency logs, geographic user distribution, and storage costs. It may use machine learning models trained on historical user behavior to classify each content asset into hot, warm, or cold storage categories. Assets accessed frequently are assigned to low-latency storage tiers, while infrequently used items are migrated to archival or cold storage solutions to minimize cost. Bandwidth usage is tracked through standard CDN analytics tools and fed into the billing module, which dynamically calculates user-specific infrastructure fees based on a combination of storage duration, data egress, and redundancy preferences.

Access to content is mediated through a front-end interface built as a web or mobile application. This application authenticates the user via secure login (e.g., OAuth2) and verifies ownership using the ownership ledger. Once validated, the content is streamed or downloaded directly from the designated cloud bucket or cache node. DRM is not required, but access controls are enforced by digitally signed content tickets that expire or refresh based on user session validity. All playback and download activity is logged for transparency and optional resale auditability.

Optional features include smart contracts for resale or inheritance, wherein content ownership can be programmatically transferred upon event triggers (e.g., payment received, user deceased, recipient authenticated). In cooperative ownership models, fractional ownership shares may be assigned to multiple user IDs, and the AI manager may resolve conflicts in access timing or suggest optimal redundancy levels to ensure fairness.

This architecture enables scalable deployment using existing cloud platforms, with the AI manager operating as a backend service that continuously optimizes user cost and system efficiency. It is compatible with any digital content type and can be extended with APIs to integrate with content creators, marketplaces, and institutional partners.

The present invention provides a method for offering a digital streaming service that grants users permanent ownership of digital content while minimizing long-term access costs through AI-optimized infrastructure provisioning. Upon receiving a one-time purchase request from a user, the system records ownership of the selected digital item-which may include, but is not limited to, songs, movies, and software applications—and grants indefinite access rights to that user. The purchased content is stored within a cloud-based infrastructure comprising one or more storage providers and content delivery networks (CDNs). A machine learning-driven orchestration layer monitors user behavior, regional demand, access frequency, and cost structures in order to allocate content dynamically to hot, warm, or cold storage tiers. This AI system may also preemptively cache high-probability content near edge servers to reduce latency and bandwidth consumption, thereby lowering infrastructure costs while preserving a responsive user experience. Users interact with the system via a content access interface, which may be implemented as a web application, mobile client, or smart device integration. Authentication is performed using cryptographically generated tokens that verify ownership without relying on DRM, thus ensuring privacy-preserving, frictionless access. Infrastructure upkeep fees are computed based solely on metrics such as storage duration, data egress volume, and redundancy level, and explicitly exclude any recurring licensing or platform access fees. An optional ownership ledger records purchase transactions and may be implemented using cryptographically signed records or decentralized blockchain systems to enable transfer, resale, or inheritance of digital assets. In certain embodiments, cooperative ownership is supported by allowing multiple verified users to jointly hold rights to a content item, with AI arbitration ensuring equitable access allocation. All relevant events-including purchase, access, transfer, and usage metrics-are logged in a secure audit trail for transparency, dispute resolution, and future optimization. The system thus enables a hybrid digital ownership model that blends the convenience of cloud streaming with the legal and financial permanence of traditional media ownership, delivering a solution particularly suited to the needs and values of digital-native users.

### Claims

1. A method of offering a digital streaming service, comprising the steps of:
receiving a one-time purchase request from a user for a digital content item selected from the group consisting of a song, video, or software application;
granting the user permanent access rights to the purchased content;
storing the purchased content in a cloud-based infrastructure system;
maintaining ongoing accessibility of the content to the user via an internet-connected streaming or download interface;
and charging the user a recurring infrastructure upkeep fee based solely on actual usage parameters including storage and bandwidth,
wherein said infrastructure upkeep is optimized by an artificial intelligence system that dynamically allocates cloud resources to reduce cost and improve performance.
2. The method of claim 1, wherein said artificial intelligence system classifies the stored content into one or more tiers selected from hot storage, warm storage, and cold storage, based on predicted user access frequency.
3. The method of claim 1, wherein said streaming or download interface authenticates the user using a cryptographic ownership token associated with the purchased content.
4. The method of claim 1, further comprising the step of recording the user's ownership rights in a verifiable ownership ledger, the ledger comprising either a centralized cryptographically signed database or a decentralized blockchain.
5. The method of claim 1, further comprising the step of enabling the user to transfer, resell, or bequeath ownership of the purchased content to another user, subject to system verification of ownership.
6. The method of claim 1, further comprising offering cooperative ownership, wherein multiple users jointly purchase and access a digital content item, and the AI system schedules or prioritizes access based on usage history and predefined rules.
7. The method of claim 1, wherein said infrastructure upkeep fee excludes licensing or content access fees and is limited to the operational cost of maintaining digital availability.
8. The method of claim 1, wherein said artificial intelligence system pre-fetches frequently accessed content to edge servers or regional cache nodes in anticipation of user demand to minimize latency and optimize performance.
9. The method of claim 1, wherein all access, download, transfer, and cost events are logged for the purposes of auditing, usage analysis, and dispute resolution.
10. The method of claim 1, wherein the digital content may include DRM-free formats with access governed solely by ownership verification and network authentication.

Great concept—here's a structured patent-style write-up for your invention:

### Title:

Alternative Life Social Media Platform Powered by AI-Generated Life Scenarios

An AI-driven social media platform that enables users to co-create and share imagined alternative life scenarios. Users may select or generate divergent versions of themselves—e.g., as a millionaire, criminal, artist, or survivor—and experience a curated social media feed based on these alternative lives. The platform allows for collaborative narratives, imagined vacations, and simulated interactions with friends in these parallel realities. Users may optionally repost content from their alternative lives to real-world social networks via their personal AI agent.

### Background and Problem

Traditional social media often fosters comparison, anxiety, and pressure to appear successful. There exists a need for a system that allows users to playfully explore different identities and possibilities in a low-stakes environment. Such a system could provide a creative outlet, serve as a therapeutic tool, and foster social connection through shared imagination.

### Detailed Description

The platform—herein referred to as Alternative Life (AL)—comprises a cloud-based AI system that generates simulated personal narratives, imagery, and interactions for a user-defined alternative self Users may:
Choose or randomize life attributes (e.g., wealth level, profession, vices, family situation, fame).
Collaborate with friends to create overlapping imaginary timelines (e.g., a trip to Ibiza in your ‘drug-fueled rockstar life’).
Receive a daily feed resembling an Instagram-like timeline, but entirely imagined and generated via AI—including deepfake-style images, status updates, and chat logs.
Share selected posts back to their real-life social media accounts via a GUI operated by their personal AI agent.

In some embodiments, the system may include a fully automated sharing mechanism whereby the user's personal AI agent monitors the generated content within the alternative life feed and autonomously selects posts deemed engaging, humorous, or aesthetically compelling based on the user's historical preferences, emotional responses, or audience engagement metrics. Upon selecting a post, the agent may format it appropriately for external platforms such as Instagram or TikTok, adding optional captions, hashtags, or watermarks that clarify the content is fictional or part of an “Alternative Life” series. The agent may also manage timing and frequency of posts to optimize visibility and user comfort, ensuring posts are only shared during approved time windows or when social engagement is predicted to be high. All posting may occur without user intervention unless pre-set preferences require confirmation for specific content types.

The system may include:
A Life Path Generator, trained on archetypal personas and narrative arcs.
A Visual Synthesis Engine for generating believable life event imagery.
An AI Interaction Module allowing conversations with simulated versions of real or fictional characters in that timeline.
An Ethical Filter, ensuring users are aware the content is fictional to avoid misinformation.
The platform may support:
*Private mode* (for self-exploration or therapy).
*Friends mode* (co-imagined lives with other users).
*Public mode* (posting highlights to public Alternative Life feeds).

### Enabling Section:

In practice, the system may be implemented by fine-tuning a large language model and a diffusion-based image generator on social media content and personal narrative data. Users input a desired persona or select from archetypal presets. The system dynamically generates text and media posts associated with key life events (e.g., graduating from clown school, getting arrested, winning a Nobel Prize) and arranges them chronologically.

For visual authenticity, facial likeness models may be used in combination with environment generation (e.g., famous landmarks). The GUI may resemble a familiar feed interface but indicate that the content is fictional. Optional plugins allow external posting, with clear disclaimers or “Alternative Life” tags.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A social media platform configured to generate and display imagined life scenarios for a user, the platform comprising:
   a) a user interface for selecting or randomizing alternative life parameters;
   b) an AI module configured to generate a simulated feed of posts, media, and interactions based on said parameters; and
   c) a sharing mechanism allowing posts to be published to external social media accounts.
2. The platform of item 1, wherein the imagined feed includes AI-generated imagery representing events, environments, or people associated with the alternative life.
3. The platform of item 1, wherein the platform supports collaborative imagined timelines between two or more users.
4. The platform of item 1, wherein a personal AI agent curates or filters posts before sharing them externally.
5. The platform of item 1, further comprising a psychological safety module configured to notify users when content may risk confusion with real events.

### Embodiment AJE: Embodiment AJE: AI-Orchestrated Cloud Ownership Platform

A cloud-based platform is disclosed that enables users to purchase permanent access rights to digital content while paying only metered infrastructure costs thereafter. An AI infrastructure manager predicts demand, allocates storage across hot, warm, and cold tiers, and stages content to edge caches to reduce latency and cost. A verifiable digital ownership ledger records entitlements, a metering subsystem emits cryptographically signed usage receipts, and a billing engine produces statements tied to storage, bandwidth, and compute. The platform supports cooperative ownership, resale and inheritance, interoperability via standardized APIs and the Model Context Protocol, and externally observable audit artifacts.

### Field

The invention relates to systems and methods for managing digital content ownership in a cloud environment, and more particularly to a platform that enables users to purchase permanent access to digital media or software stored in the cloud, while optimizing infrastructure costs using artificial intelligence.

### Background

In recent years, the subscription model has become the dominant form of access to digital media and software. Platforms such as Spotify, Netflix, and Adobe Creative Cloud require ongoing payments in exchange for access. This results in high lifetime costs and a lack of ownership, especially for users who primarily consume the same set of content over extended periods. Traditional ownership models offered lower lifetime costs, but lack the convenience of cloud-based access.

There is a need for a hybrid system that combines the convenience of cloud access with the economic and psychological benefits of ownership, while ensuring that infrastructure costs remain manageable.

Cloud storage and bandwidth have become inexpensive, and artificial intelligence can be used to optimize the placement and delivery of digital assets.

### Summary

The present invention provides a cloud-based system where users may purchase permanent access to digital content such as music, video, eBooks, or software applications. After an initial purchase, the user pays only for minimal infrastructure costs associated with maintaining cloud access. The system utilizes an AI orchestration layer to optimize storage allocation, bandwidth usage, and cost efficiency.

### Gentle Introduction

Conventional subscription services deliver convenience but do not give users a durable right to access the particular content they value most over long periods. Ownership-based models historically delivered that durability but required local storage, manual backups, and device-bound licenses. The invention bridges these models by separating economic ownership from the mechanics of delivery. A user may acquire a permanent access right recorded in a verifiable ledger while an AI manager continuously optimizes where and how the user's content is stored and delivered across cloud tiers, caches, and regions.

Intuitively, the platform behaves like a modem streaming service from the user's perspective, but the financial and legal posture aligns with purchase-and-own. The AI orchestration learns when a user tends to access content and stages it closer to the user at those times to reduce cost and delay. Metering isolates pure infrastructure costs so that, after purchase, the user's ongoing payments are small, measurable, and transparently tied to storage, bandwidth, and compute used to serve the owned asset.

### EXAMPLES

### Example 1: Single-User Purchase and Playback of a Song

A user selects a track and chooses permanent access. The purchase module verifies payment and writes an ownership record to the ledger. The AI infrastructure manager initially stores the asset in a warm tier and sets a prediction that the user is likely to play the track in the evening based on historical activity. As evening approaches, the AI manager pre-caches the track to an edge location near the user. When the user presses play in the content access interface, the system streams from the nearest cache if available, or from the origin if not, while the metering subsystem records storage dwell time and egress. The billing module subsequently produces a statement that includes only the marginal infrastructure costs.

Purchase receipt (JSON):
{“receiptId”:“r-1001”,“userId”:“u-77”,“assetId”:“song-abc”,“right”:“permanent”,“timestamp”:“2025-0
6-01T19:22:31Z”,“signature”:“0xA1B2”}
Ledger entry (JSON):
{“ledgerTx”:“tx-555”,“assetId”:“song-abc”,“ownerId”:“u-77”,“right”:“permanent”,“prevOwnerId”:null
,“block”:“84219”,“hash”:“0x9f3c”}
Metering event (JSON):
{“eventId”:“m-7001”,“assetId”:“song-abc”,“tenantId”:“u-77”,“metric”:“egressBytes”,“value”:5242880
,“timestamp”:“2025-06-01T20:05:04Z”,“logHash”:“0x4cd2”}

### Example 2: Cooperative Ownership of a Software License

Three users agree to jointly purchase a costly software tool. The platform creates a cooperative entitlement that allocates time windows and concurrency rules. The AI manager predicts overlapping usage and, where permitted by license policy, stages redundant instances for simultaneous use; otherwise it arbitrates access by assigning time slices and notifying users. Metering splits storage, egress for updates, and compute used for virtualization across the co-owners proportionally.

Cooperative entitlement (JSON):
{“entitlementId”:“e-22”,“assetId”:“sw-pro-9”,“owners”:[{“userId”:“u-1”,“share”:0.4},{“userId”:“u-2”,
“share”:0.3},{“userId”:“u-3”,“share”:0.3}],“policy”:{“maxConcurrency”:1,“slotMinutes”:30}}
Arbitration decision (JSON):
{“decisionId”:“d-901”,“assetId”:“sw-pro-9”,“grants”:[{“userId”:“u-2”,“start”:“2025-06-02T12:00:00Z
”,“end”:“2025-06-02T12:30:00Z”},{“userId”:“u-1”,“start”:“2025-06-02T18:00:00Z”,“end”:“2025-06-
02T18:30:00Z”}]}

### Example 3: Resale and Transfer with Externally Observable Receipts

A user initiates a resale of an eBook to another user. The resale module checks transferability rules, locks the entitlement to prevent concurrent access, and generates a smart-contract-like transaction on the ledger. The metering subsystem emits a signed usage receipt correlating the final access by the seller and the first access by the buyer, which is published at a stable endpoint to provide an externally auditable record. The content's storage location is gradually migrated toward the buyer's region by the AI manager to reduce long-haul egress.

Transfer request (JSON):
{“transferId”:“t-300”,“assetId”:“book-xy1”,“from User”:“u-77”,“to User”:“u-88”,“priceCents”:1500,“ti
mestamp”:“2025-06-05T11:02:00Z”}
Usage receipt (JSON):
{“receiptId”:“ur-42”,“assetId”:“book-xy1”,“fromUser”:“u-77”,“toUser”:“u-88”,“lastAccessFrom”:“202
5-06-05T11:03:12Z”,“firstAccessTo”:“2025-06-05T11:05:47Z”,“egressBytes”:2097152,“signature”:“0
xC0FFEE”}

### Scope and Interpretation

The scope of the invention is defined solely by the claims. Any embodiments, examples, descriptions of features, or references to figures, if any are provided, are illustrative and non-limiting. Unless expressly stated otherwise in a claim, operations may be performed in alternative orders, steps may be omitted or added, components may be combined or separated, and implementations may vary across hardware, software, or combinations thereof. Terminology such as may, can, could, example, embodiment, and configured to is intended to be non-restrictive.

### Detailed Description

A system may include the following components:
Digital ownership ledger to store proof-of-purchase and ownership data, implemented as a centralized or decentralized registry.
AI infrastructure manager that dynamically allocates resources for storage and retrieval of owned content. It may predict user access patterns and pre-cache certain content when high access probability is detected.
Billing module to calculate ongoing infrastructure costs based on bandwidth, storage duration, and access frequency.
Digital media interface for accessing content through web, app, or smart device.
Resale and inheritance framework allowing transfers of owned content.
Cooperative ownership support enabling multiple users to share access and infrastructure costs.
Security measures such as DRM-free but cryptographically signed access controls and redundant backups.

Enablement, technical effects, flows, observability, interoperability, fallback embodiments, and monetization are as previously described in detail.

### Itemized List for Continuations

Embodiments can be described by the following items (abbreviated for clarity, but structurally preserved):
Item 1: A system comprising a purchase module enabling a user to acquire permanent access rights, an infrastructure manager, a billing system for infrastructure-only costs, and a content access interface.
Item 2: Digital content may include music, video, text, eBooks, documents, or software.
Item 3: The infrastructure manager migrates content between storage tiers.
Item 4: A digital ownership ledger records purchases and transfers.
Item 5: Ledger may be decentralized and cryptographically verifiable.
Item 6: Resale module enables transfers or sales of ownership rights.
Item 7: Inheritance mechanism assigns ownership posthumously.
Item 8: Infrastructure manager pre-caches content to reduce latency.
Item 9: Content access interface available on web, mobile, or embedded devices.
Item 10: DRM-free playback secured by authentication and cryptographic validation.
Item 11: A method comprising purchase, storage, ownership recording, tier allocation, delivery, and charging for infrastructure costs only.
Item 12-35: Variations covering cooperative ownership, redundancy, fallback modes, metering, billing semantics, deployment topologies, security modes, APIs, interoperability, monetization, and external observability.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for managing digital content ownership in a cloud environment, comprising:
   a) a purchase module enabling a user to acquire permanent access rights to digital content;
   b) an infrastructure manager configured to allocate storage and bandwidth resources based on user access patterns;
   c) a billing system configured to calculate charges based on metered infrastructure usage; and
   d) a content access interface configured to deliver said digital content from the cloud.
2. The system of item 1, wherein the digital content includes music, video, text, or software.
3. The system of item 1, wherein the infrastructure manager migrates digital content between hot, warm, and cold storage tiers.
4. The system of item 1, further comprising a digital ownership ledger configured to record purchases and support transfers.
5. The system of item 4, wherein said ledger is implemented as a cryptographically verifiable decentralized registry.
6. The system of item 1, further comprising a resale module enabling users to transfer or sell ownership rights.
7. The system of item 1, further comprising an inheritance mechanism for assigning ownership rights to another user.
8. The system of item 1, wherein the infrastructure manager caches predicted high-access content near the user.
9. The system of item 1, wherein the content access interface functions on web, mobile, and embedded smart devices.
10. The system of item 1, wherein the content access interface supports DRM-free playback with authentication and cryptographic validation.
11. A method for managing user-owned digital content in a cloud environment, the method comprising:
   a) receiving a purchase request for permanent access to digital content;
   b) storing said content in a cloud-based storage system;
   c) recording ownership in a digital ledger;
   d) allocating the content to a storage tier based on predicted usage by an infrastructure manager;
   e) delivering the content to the user via a content access interface; and
   f) charging the user based on metered infrastructure usage.
12. The method of item 11, further comprising enabling the user to transfer or resell ownership rights through the system.
13. The method of item 11, further comprising providing cooperative ownership among multiple users with proportionally distributed infrastructure fees.
14. The method of item 11, further comprising storing backup copies of digital content in redundant cloud locations for availability and data safety.
15. The method of item 11, further comprising migrating infrequently accessed content to low-cost cold storage tiers.
16. The method of item 11, further comprising enabling fallback modes where cached or provisional access is provided during connectivity loss.
17. The method of item 11, further comprising logging usage receipts in a cryptographically signed append-only log.
18. The method of item 17, wherein said usage receipts are externally observable and downloadable by the user.
19. The method of item 11, further comprising computing tariff-based billing line items using configurable rates or regional coefficients.
20. The method of item 11, wherein the ledger-based ownership records are reconcilable across multiple jurisdictions or governance entities.
21. A non-transitory computer-readable medium storing instructions that, when executed by one or more processors, cause performance of the method of item 11.
22. The non-transitory computer-readable medium of item 21, wherein the instructions further cause generating externally observable usage receipts that include ownership proofs, billing events, and tier allocation history.

### Embodiment AK: A Delegate-Based Civic Platform for Subscription-Funded Solution Voting

### Title:

System and method for issue-specific delegation and funding of civic solution proposals via subscription-based collective action.

A system wherein users may subscribe to a civic platform and delegate their voting power on specific topics to trusted individuals. The system aggregates subscription fees into a funding pool and allows delegates to vote on solution proposals submitted as videos or structured content. The platform uses this governance structure to fund a defined number of top-rated proposals annually. Topic-specific delegation, project transparency, impact scoring, and conflict-of-interest mitigation are integral to the system.

### Advantages Over the Prior Art

Encourages broad civic participation without requiring full-time attention;
Allows subject-matter experts to represent users on specific domains;
Provides a funding mechanism to implement bottom-up civic solutions;
Enables transparent tracking of both delegate behavior and project outcomes;
Promotes low-barrier lawmaking and impact projects outside traditional governments

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A civic platform system comprising:
   a) a user subscription module configured to receive annual payments from registered users, said payments forming a collective funding pool;
   b) a delegation engine allowing users to delegate their voting authority on topic-specific issues including chemicals, digital rights, or health policy, to other users or verified delegates;
   c) a delegate database recording each delegation decision with revocation and audit logs, wherein delegation is granular and may vary per topic;
   d) a video proposal submission system allowing users to upload proposals containing:
      (i) a definition of the problem;
      (ii) a proposed solution or draft law; and
      (iii) an explanation of projected impact, beneficiaries, and cost structure;
   e) a scoring engine configured to evaluate each proposal based on community votes, delegate endorsements, and computed metrics including projected impact, feasibility, and transparency;
   f) a delegate voting system enabling verified delegates to vote on a predefined number of proposals to receive funding from the subscription pool;
   g) a funding disbursement module that allocates funds to the selected proposals after voting, with configurable thresholds and optional staged releases; and
   h) an incentive and accountability framework for delegates comprising:
      (i) historical transparency of past votes;
      (ii) performance-based reputation; and
      (iii) optional compensation based on alignment and engagement.
2. The system of item 1, wherein the proposal submission system includes AI-assisted formatting, duplication detection, and fact-checking support.
3. The system of item 1, wherein user-submitted proposals may be categorized as nonprofit initiatives, legislative pilot proposals, scientific research trials, civic infrastructure rollouts, or educational campaigns.
4. The system of item 1, wherein the voting cycle is performed quarterly or annually, and the number of proposals selected is fixed or dynamically allocated by category.
5. The system of item 1, wherein the delegation engine permits users to reassign or withdraw delegated votes at any time with immediate effect.
6. The system of item 1, further comprising a conflict-of-interest detection engine that flags delegate votes associated with personal, financial, or organizational ties to proposal submitters.
7. The system of item 1, wherein funded proposals are further tracked and their outcomes published to a public impact dashboard for ongoing civic accountability.
8. The system of item 1, further comprising a public-facing educational layer that explains proposals and voting context via simplified summaries, animation, or commentary.
9. The system of item 1, wherein delegates are rewarded with a percentage of the subscription pool based on engagement, vote alignment, and community trust.
10. The system of item 1, wherein data and voting records are cryptographically signed and stored with tamper-proof audit trails.

### Embodiment AKE: System and Method for Issue-Specific Delegation and Funding of Civic Solution Proposals Via Subscription-Based Collective Action

A system wherein users may subscribe to a civic platform and delegate their voting power on specific topics to trusted individuals. The system aggregates subscription fees into a funding pool and allows delegates to vote on solution proposals submitted as videos or structured content. The platform uses this governance structure to fund a defined number of top-rated proposals annually. Topic-specific delegation, project transparency, impact scoring, and conflict-of-interest mitigation are integral to the system.

### Background

Civic decision-making often requires sustained attention across diverse domains such as public health, environmental policy, and digital rights. Most individuals lack the time, access, or expertise to evaluate each issue, and conventional platforms either rely on generalized, non-granular voting or on opaque funding mechanisms that erode trust. Existing systems typically do not combine topic-specific delegation, transparent and auditable funding disbursement from subscriber pools, conflict-of-interest handling, and external observability sufficient to verify behavior without internal access. There is a need for a platform that enables predictable user contributions, granular delegation to trusted subject-matter experts per topic, verifiable selection processes, and accountable, milestone-tied disbursements to solution proposals, while preserving interoperability with agent clients and minimizing user burden.

### Summary

In some embodiments a platform receives periodic subscription payments from users into a collective funding pool and enables per-topic delegation of voting authority to selected delegates. Proposals may be submitted as short videos with structured fields covering problem, solution, impact, beneficiaries, timeline, and cost. A scoring engine may combine community inputs, delegate endorsements, and computed metrics using adjustable weights to rank proposals. Verified delegates may cast selection votes during time-bounded cycles, after which funds are disbursed to top-ranked proposals in single or multi-tranche releases tied to milestones. All governance actions including delegation creation and revocation, vote casting, cycle closure, selections, disbursements, and milestone verifications may be recorded in an append-only, cryptographically linked audit log that is externally exportable.

Interoperability may be provided via application programming interfaces and a Model Context Protocol tool interface enabling agent clients to perform core actions with user consent while preserving auditability. Conflict-of-interest detection may flag votes with known ties, and delegate reputation and incentives may align behavior with community interests.

### Gentle Introduction

Many people care about public problems but lack the time or expertise to study every issue. This platform allows a person to contribute a predictable subscription amount, choose topics they care about, and optionally designate trusted individuals to vote on their behalf for those specific topics. Proposals are submitted in a familiar, easy-to-consume format such as short videos with structured fields that explain the problem, the proposed solution, expected impact, and costs. The platform aggregates all subscription fees into a single pool and runs periodic voting cycles where verified delegates cast votes to select the most promising proposals to receive funding. Users can change or revoke their topic-specific delegations at any time, and all voting and funding actions are recorded with audit trails to promote trust. The result is a straightforward user experience: subscribe, set or adjust delegations per topic, browse proposal summaries, and see funds disbursed to selected proposals with transparent outcome tracking. The formal system components described below implement this intuitive flow with safeguards such as conflict-of-interest detection, performance-based reputation for delegates, and tamper-resistant records.

### Examples

The following concrete examples illustrate typical end-to-end usage flows. They are illustrative and non-limiting, and the order of operations may be varied or performed concurrently.

Example 1: Subscription and topic-specific delegation. A user creates an account, selects a monthly subscription tier, and completes payment. Immediately after payment confirmation, the user designates different delegates per topic, such as a public health expert for “health policy” and a digital rights advocate for “digital rights.” A delegation creation call may submit a signed payload and receive a durable record, for instance {“user”:“U123”, “topic”:“T-health-policy”, “delegate”:“D456”, “effective_from”:“2026-01-01T0:00:00 Z”, “nonce”:“abc123”, “signature”:“base64-ED25519”}resulting in {“delegation_id”:“DG789”, “status”:“active”, “record hash”:“sha256: . . . ”, “server signature”:“base64-pl atform-key”}. If the user later revokes delegation for “health policy,” the platform records immediate revocation and recalculates voting power for upcoming or in-progress cycles, yielding

{“delegation_id”:“DG789”,“status”:“revoked”,“revoked_at”:“2026-02-01T09:00:00Z”,“revocation_sig
nature”:“base64-ED25519”}.

Example 2: Proposal submission and selection. A nonprofit submits a proposal as a short video with structured fields describing the problem, solution, expected impact, beneficiaries, timeline, and budget. The platform performs AI-assisted formatting, duplicate detection, and fact-check support, then assigns a proposal ID and computes initial metrics. During the defined voting window, verified delegates review proposals, cast votes, and add endorsements. The scoring engine combines community inputs, delegate endorsements, and computed metrics using adjustable weights. At cycle close, the top proposals are selected for funding, and the disbursement module releases funds in tranches tied to milestones. Each action is recorded to the append-only, hash-chained audit log for external verification.

Example 3: Conflict-of-interest detection and flagging. A delegate attempts to vote on a proposal submitted by an organization with which the delegate has a disclosed financial tie. The conflict-of-interest engine evaluates known relationships and flags the vote with a reason code. The platform may down-weight or exclude the affected vote according to policy while retaining an immutable audit entry indicating the detection and outcome. The delegate's reputation is updated to reflect transparency and responsiveness to conflict flags.

Example 4: MCP-based agent interoperability. In some embodiments, the platform exposes a Model Context Protocol toolset to allow compliant agent clients to perform core actions on a user's behalf with explicit consent. Tools may include create_delegation, revoke_delegation, cast_vote, get_cycle_status, get_proposal_digest, and get disbursement. For example, an MCP client may call {“tool”:“create_delegation”, “args”:{“user”:“U123”, “topic”:“T-digital-rights”, “delegate”:“D789”, “effec tive_from”:“2026-01-15T00:00:00Z”}}followed by {“tool”:“get_cycle_status”, “args”:{“cycle_id”:“C2026Q1”}} and then {“tool”:“cast_vote”, “args”:{“delegate”:“D789”, “proposal”:“P321”, “weight”:1.0}}. Responses include server signatures and record hashes enabling independent verification. This interoperability allows users to manage delegations and voting through third-party agents without sacrificing auditability or security.

### Enablement:

In some embodiments a skilled person may implement the system by assembling the described components and following a stepwise build path. A secure API gateway and authentication service may be deployed to terminate TLS, issue tokens, and validate client signatures. Platform signing keys such as ED25519 may be provisioned for server responses, and users or delegates may register public keys to sign actions. A subscription module may be implemented with a state machine covering pending, active, grace, past_due, canceled, and refunded, with third-party billing webhooks authenticated using keyed hashes or signatures and recorded as append-only audit entries including idempotency keys and record hashes. A delegation engine may expose endpoints that accept signed payloads like {“user”:“U123”, “topic”:“T-health-policy”, “delegate”:“D456”, “effective from”:“2026-01-01T00:00:00 Z”, “nonce”:“abc123”, “signature”:“base64-ED25519”} and persist durable records in a delegate database with effective-from timestamps and immediate revocation semantics, emitting DelegationCreated or DelegationRevoked audit entries with server countersignatures and prev_hash fields to ensure hash chaining. A proposal submission system may store media in media storage and structured fields in a structured store while computing digests such as {“proposal”:“P321”, “content_digest”:“sha256: . . . ”, “media_uri”:“https:// . . . /P321.mp4”} so that selection votes bind to immutable artifacts. A scoring engine may compute a weighted score per proposal using configurable weights loaded from a policy store, combining community inputs, delegate endorsements, computed metrics, and, in some embodiments, treating delegate votes as weighted inputs to derive scores or rankings that drive selection ordering, and persisting score snapshots with timestamps. A delegate voting subsystem may validate that a vote like {“delegate”:“D456”, “proposal”:“P321”, “weight”:1.0, “signature”:“base64-ED25519”}occurs within a cycle window exposed by the cycle manager such as {“cycle_id”:“C2026Q1”, “phase”:“voting”, “opens”:“2026-03-01T00:00:00Z”, “closes”:“2026-03-31T2 3:59:59Z”}, enforce per-topic voting power based on active delegations, and write VoteCast audit entries. A cycle manager may close the window, sort proposals by score, select winners, and emit ProposalSelected entries, after which a disbursement module may schedule single or multi-tranche releases keyed to milestones with entries such as {“disbursement_id”:“F222”, “proposal”:“P321”, “amount”:25000, “tranche”:“1/3”, “conditions”:“milesto ne-I-approved”, “timestamp”:“2026-04-15T10:30:00Z”, “record_hash”:“sha256: . . . ”} and integrate payment rails using provider references stored alongside audit metadata. The append-only audit log may store entries in a table or log file ordered by monotonically increasing sequence numbers, each entry including entry type, actor, payload digest, timestamp, signature, prev hash, and server signature, forming a cryptographically linked chain that can be exported and verified externally; a daily or per-batch sealing hash may be published to a public timestamping service to anchor continuity. Interoperability may be implemented by exposing application programming interfaces for create delegation, revoke delegation, cast_vote, get_cycle_status, get_proposal_digest, and get_disbursement, and by mapping these to a Model Context Protocol tool interface so that agent clients can invoke the same operations using tool calls like {“tool”:“cast_vote”, “args”:{“delegate”:“D456”, “proposal”:“P321”, “weight”:1.0}} and receive responses containing server signature and record_hash fields, thereby preserving auditability. Security measures may include nonces and idempotency keys to prevent replay, clock-skew tolerant timestamp validation, and plan-based rate limits enforced at the API gateway. The system may be deployed in a cloud or on-premises environment with horizontally scalable stateless services for API handling, a replicated database for durable state, object storage for media, and a write-optimized store for the audit log to support high-throughput append operations. Following these steps, a skilled practitioner can implement embodiments without undue experimentation using well-understood web services, cryptographic signature libraries, database schemas, and standard payment integrations.

### Technical Effects

In some embodiments the append-only, hash-chained audit log produces a concrete technical effect by enabling tamper-evident verification of governance and funding events without internal access, thereby allowing third parties to reconstruct and validate state transitions from export alone and reducing reliance on proprietary databases during compliance or dispute resolution. The per-topic effective-from and immediate-revocation semantics produce monotonic, externally verifiable governance state transitions that can be consumed by clients and auditors to ensure that voting power calculations are consistent across distributed systems, improving consistency and reducing synchronization errors. The binding of proposal selections to content digests such as sha256 hashes provides a technical guarantee that the artifact reviewed is identical to the artifact funded, mitigating integrity risks from media replacement or link rot. The MCP-based tool interface and application programming interfaces yield a technical effect of interoperable automation, allowing heterogeneous agent clients to orchestrate delegation and voting actions while preserving security properties through cryptographic signatures and audit record hashes; this reduces manual API coordination overhead and lowers integration friction across platforms. The disbursement subsystem's milestone-tied tranches combined with immutable audit entries produce traceable, machine-verifiable funding flows that can be monitored in near real time, improving fraud resistance and enabling faster anomaly detection through automated reconciliation against public exports. The use of hash-chained exports allows incremental verification where only the tail of the log needs to be fetched and checked against a known head hash, reducing bandwidth and computational cost for auditors and monitoring agents. Conflict-of-interest evaluation yields a technical effect by enriching vote records with machine-readable flags and reason codes that downstream scoring components or auditors can process deterministically, improving data quality and enabling reproducible scoring outcomes.

### Detailed Description of Preferred Embodiments

For avoidance of doubt, the scope of the invention is defined solely by the claims. The title, abstract, advantages, and the following description, any drawings or figures if present, and any examples are illustrative and non-limiting. The order of operations in any described flow may be varied, steps may be omitted or performed concurrently, and features from different embodiments may be combined unless expressly stated otherwise. Optional elements are explicitly non-limiting and do not restrict claim scope.

The embodiments can be described by the following itemized list: Item 1 describes a civic platform system that comprises a user subscription module configured to receive annual payments from registered users, with said payments forming a collective funding pool; a delegation engine allowing users to delegate their voting authority on topic-specific issues such as chemicals, digital rights, or health policy to other users or verified delegates; a delegate database recording each delegation decision with revocation and audit logs, wherein delegation is granular and may vary per topic; a video proposal submission system allowing users to upload proposals containing a definition of the problem, a proposed solution or draft law, and an explanation of projected impact, beneficiaries, and cost structure; a scoring engine configured to evaluate each proposal based on community votes, delegate endorsements, and computed metrics such as projected impact, feasibility, and transparency; a delegate voting system enabling verified delegates to vote on a predefined number of proposals, for example 100, to receive funding from the subscription pool; a funding disbursement module that allocates funds to the selected proposals after voting, with configurable thresholds and optional staged releases; and an incentive and accountability framework for delegates comprising historical transparency of past votes, performance-based reputation, and optional compensation based on alignment and engagement. Item 2 provides that the proposal submission system may include AI-assisted formatting, duplication detection, and fact-checking support. Item 3 provides that user-submitted proposals may be categorized as nonprofit initiatives, legislative pilot proposals, scientific research trials, civic infrastructure rollouts, or educational campaigns. Item 4 provides that the voting cycle may be performed quarterly or annually and that the number of proposals selected may be fixed, for example 100, or dynamically allocated by category. Item 5 provides that the delegation engine may permit users to reassign or withdraw delegated votes at any time with immediate effect. Item 6 provides that the system may further comprise a conflict-of-interest detection engine that flags delegate votes associated with personal, financial, or organizational ties to proposal submitters. Item 7 provides that funded proposals may be tracked and their outcomes published to a public impact dashboard for ongoing civic accountability. Item 8 provides that the system may further comprise a public-facing educational layer that explains proposals and voting context via simplified summaries, animation, or commentary. Item 9 provides that delegates may be rewarded with a percentage of the subscription pool, for example 5-10%, based on engagement, vote alignment, and community trust. Item 10 provides that data and voting records may be cryptographically signed and stored with tamper-proof audit trails. Item 11 provides that the accountability framework may expose exportable, append-only, hash-chained audit logs that include entries for DelegationCreated, DelegationRevoked, VoteCast, CycleClosed, ProposalSelected, FundsDisbursed, and MilestoneVerified, with each entry signed by an originating actor key and countersigned by a platform key. Item 12 provides that application programming interfaces may expose externally observable actions including delegation creation and revocation, vote casting by verified delegates, cycle status, proposal content digests, and funding disbursements so that system behavior may be detected via black-box observation. Item 13 describes a computer-implemented method comprising receiving periodic subscription payments into a collective funding pool, recording per-topic delegations including revocations, accepting proposals including media content and structured fields, computing proposal scores based on community inputs, delegate endorsements, and computed metrics, enabling verified delegates to cast votes to select proposals for funding, disbursing funds to selected proposals, and persisting tamper-evident audit records of the foregoing actions. Item 14 provides that the method may further comprise publishing a time-bounded voting window and exposing an active window state via a public status endpoint. Item 15 provides that disbursement may be performed in stages according to milestones and that milestone verification may be recorded in the audit records. Item 16 provides that conflicts of interest may be detected by evaluating relationships between delegates and proposal submitters and flagging affected votes for downstream handling. Item 17 describes a non-transitory computer-readable medium storing instructions that, when executed by one or more processors, cause a computer system to perform operations comprising subscription receipt, delegation recording and revocation, proposal intake, score computation, delegate voting to select proposals, disbursement of funds, and persistence of tamper-evident audit records. Item 18 provides that cryptographic signatures may be generated for delegation, vote, cycle, selection, disbursement, and milestone records and that an append-only audit log may be exposed via an application programming interface. Item 19 provides that per-topic delegations may include effective-from timestamps and revocation records that take immediate effect upon acceptance by the platform, producing monotonic, verifiable state transitions. Item 20 provides that the scoring engine may combine community votes, delegate endorsements, and computed metrics using adjustable weights. Item 21 provides that the selection subsystem may accept selection inputs from one or more of verified delegates, assigned representatives, committee members, or authorized agent processes operating under delegated authority, with weights derived from per-topic user delegations and configurable aggregation rules. Item 22 provides that the accountability framework may be implemented using at least one of append-only, hash-chained audit logs; signed event exports without internal retention; third-party timestamping services; distributed ledgers; or Merkle-tree batch receipts, so that externally verifiable behavior is preserved even if a platform-internal audit database is minimized. Item 23 provides that the collective funding pool may be formed from one or more of recurring subscriptions, recurring pledges, one-time contributions, employer matching, transaction round-ups, advertising or sponsor allocations, or public grants while preserving the delegation and selection mechanisms described. Item 24 provides that per-topic delegation may be defined using static taxonomies, dynamic tag sets, user-defined topics, or algorithmically derived topic clusters, including geofenced or jurisdiction-specific topics and time-scoped topics that expire automatically. Item 25 provides that selection cadence may be continuous, event-triggered, or batched, and voting modalities may include approval, score, ranked-choice, instant-runoff, quadratic, proportional share, or pairwise comparison, with policy-configurable quorum and threshold rules. Item 26 provides that disbursement mechanisms may include escrow-controlled smart contracts, third-party custodians, in-kind credits, vendor vouchers, or direct transfers, and may include clawback conditions, performance bonds, or holdbacks in addition to milestone-based tranches. Item 27 provides that conflict-of-interest detection may be implemented using attested disclosures, integrations to external registries, graph-based relationship analysis, or privacy-preserving attestations, with mitigation comprising flagging, down-weighting, recusal prompts, or enforced recusal and reweighting. Item 28 provides that interoperability may be achieved via Model Context Protocol, OpenAPI-described REST endpoints, GraphQL, message queues, email-to-action links with signed tokens, or mobile operating system intents, and that agent designation may include human approvers and automated agents authorized by the user. Item 29 provides that external observability may be augmented by zero-knowledge or verifiable computation proofs that attest to selection or disbursement policy compliance while revealing only necessary metadata to third parties.

### Advantages Over the Prior Art

Advantages over the prior art include encouraging broad civic participation without requiring full-time attention, allowing subject-matter experts to represent users on specific domains, providing a funding mechanism to implement bottom-up civic solutions, enabling transparent tracking of both delegate behavior and project outcomes, and promoting low-barrier lawmaking and impact projects outside traditional governments.

### External Observability

In some embodiments the platform exposes externally verifiable behaviors through user interfaces, downloadable reports, and network-accessible application programming interfaces such that infringement may be detected without internal access. A delegation creation may be observable as an authenticated client action that results in a server response and a durable audit record. For example, a delegation endpoint may accept a signed payload such as

{“user”:“U123”,“topic”:“T-health-policy”,“delegate”:“D456”,“effective_from”:“2026-01-01T00:00:00
Z”,“nonce”:“abc123”,“signature”:“base64-ED25519”} and return
{“delegation_id”:“DG789”,“status”:“active”,“effective_from”:“2026-01-01T00:00:00Z”,“record_hash
”:“sha256:...”,“server_signature”:“base64-platform-key”}. A vote cast by a verified delegate may be
observable via a queryable feed that returns immutable entries such as
{“vote_id”:“V555”,“delegate”:“D456”,“proposal”:“P321”,“weight”:1.0,“timestamp”:“2026-03-31T12:
00:00Z”,“signature”:“base64-ED25519”}. Funding disbursements may be externally observable via a
public ledger export or API that produces entries such as
{“disbursement_id”:“F222”,“proposal”:“P321”,“amount”:25000,“tranche”:“1/3”,“conditions”:“milesto
ne-1-approved”,“timestamp”:“2026-04-15T10:30:00Z”,“tx_reference”:“ACH-...”,“record_hash”:“sha2
56:...”}.

In some embodiments the platform may publish a time-bounded voting window and expose the active window state via a public status endpoint that returns

{“cycle_id”:“C2026Q1”,“phase”:“voting”,“opens”:“2026-03-01T00:00:00Z”,“closes”:“2026-03-31T2
3:59:59Z”}. Proposal submissions may be externally verified by retrieving content digests such as
{“proposal”:“P321”,“title”:“Reduce lead in school
water”,“content_digest”:“sha256:...”,“media_uri”:“https://.../P321.mp4”,“structured_fields_digest”:“sh
a256:...”}enabling third parties to confirm that the voted-on artifact matches the funded artifact.
Delegation revocations may be externally observable via records such as
{“delegation_id”:“DG789”,“status”:“revoked”,“revoked_at”:“2026-02-01T09:00:00Z”,“revocation_sig
nature”:“base64-ED25519”}.

In some embodiments the platform may provide exportable, append-only audit logs that are cryptographically linked by hash chaining so that external auditors can verify continuity, including entries for DelegationCreated, DelegationRevoked, VoteCast, CycleClosed, ProposalSelected, FundsDisbursed, and MilestoneVerified with each entry signed by the originating actor's key and countersigned by the platform. A competitor system that performs topic-specific delegations effective per topic, conducts delegate- or authorized-selector-based selection over user-funded subscription pools, and disburses funds to selected proposals while emitting externally queryable records of the foregoing behaviors as described could be detected via black-box testing and network observation without access to internal source code or databases.

### Non-Avoidance and Substantial Equivalents:

In some embodiments the inventive concept is characterized by externally discernible behaviors comprising per-topic assignment of selection authority from users to identifiable selectors, a time-bounded selection process in which such selectors supply weighted selection inputs, and disbursement from a user-sourced pool to proposals bound to immutable content digests, together with exportable records sufficient for external verification. Systems that vary nomenclature, transport, cryptographic primitives, content formats, or internal module boundaries while preserving these behaviors may operate as substantial equivalents. For example, per-topic assignments may be implemented by explicit delegations, default assignees, enterprise or group administrator mapping, or algorithmically derived selector weights computed from user preferences or follow settings; selection inputs may be approvals, rankings, scores, or pairwise choices attributed to authorized selectors including verified delegates, committee members, or authorized agent processes; and auditability may be achieved via append-only hash-chained logs, Merkle-tree batch receipts, distributed ledgers, or periodic publication of head hashes anchored to public timestamping services. A competitor that relabels delegates as curators or trustees, replaces REST with GraphQL, message queues, email-to-action links, or mobile intents, substitutes ED25519 with ECDSA, or omits video in favor of structured text while binding selections to content digests does not materially alter the external behaviors. Likewise, forming the funding pool from pledges, one-time contributions, employer matching, advertising allocations, or grants rather than subscriptions preserves the described intake and disbursement pattern. The platform behavior remains externally provable by observing inputs and outputs such as assignment records or their functional equivalents, selector-attributed votes or approvals during designated windows, content digests bound to proposals, and disbursement entries carrying proposal identifiers and tranche conditions. Renaming components, altering interfaces, or reorganizing internal modules does not avoid the described embodiments when the foregoing externally observable behaviors are present.

In practice it is preferred to implement the Political_System with a clustering engine that groups agenda issues and complaints automatically, which leads to improved efficiency in the digital handling of public input. As a result, redundant submissions are avoided and participants converge more rapidly toward shared problem definitions. More specifically, the system produces the effect of reducing processor load, memory usage, and communication overhead because similar issues are aggregated and summarized before presentation, which results in measurable improvements in the efficiency and reliability of the political decision-support pipeline. Since fewer redundant communications and unnecessary meetings are triggered, the invention indirectly reduces travel and resource consumption, while its primary effect is improved technical efficiency in the management and organization of large-scale civic input.

### Fallback Embodiments

In some embodiments a minimal implementation may be deployed that preserves the core inventive concept of subscription-funded, topic-specific delegation with delegate-only selection voting while simplifying optional subsystems. Proposals may include structured fields describing problem, solution, expected impact, and cost together with minimal media content such as a single thumbnail image, an audio-only clip, or a low-resolution video, and the media may be hosted externally with the platform storing a content digest and a URI. In some embodiments proposals may be submitted using structured fields alone without associated media content, with the structured_fields_digest binding the artifact. The scoring engine may operate with reduced complexity by treating community inputs as a basic upvote count, treating delegate endorsements as a binary flag, and computing a single transparency or feasibility metric, while still combining these elements with adjustable weights to produce a score. Voting cycles may be time-bounded by simple wall-clock configuration without category-based allocations, and the delegate voting subsystem may present a fixed shortlist derived from submission thresholds to reduce review load.

In some embodiments disbursement may occur in a single tranche upon selection, with milestone verification deferred to post-funding reporting, while auditability is maintained by recording DelegationCreated, VoteCast, ProposalSelected, and FundsDisbursed entries in an append-only log that is sealed daily by publishing a hash to a public timestamping service. In some embodiments the accountability framework may persist audit records without hash chaining, for example as authenticated append logs with server-side retention and periodic backups, while still exposing externally observable records of delegations, votes, selections, and disbursements via the described interfaces. Conflict-of-interest handling may be provided as attestation prompts and manual administrator review, with detected issues noted in audit entries rather than enforced down-weighting. Interoperability may be limited to a small set of authenticated endpoints for create delegation, revoke_delegation, cast_vote, and get_disbursement, and MCP tool exposure may be omitted or deferred. The subscription module may support a single active plan with monthly billing and grace-period flags without enterprise features, and entitlements may be enforced solely at the API gateway. In some embodiments the platform may operate in a low-connectivity mode in which client applications cache signed actions locally and submit them when connectivity is restored, with the server assigning authoritative timestamps upon acceptance and including those timestamps in the tamper-evident audit records. These simplified or partial configurations may provide a deployable baseline that retains externally observable behaviors, per-topic delegations with revocation, delegate-scored selection of proposals, and tamper-evident records of funding actions.

### Monetization and Damages Considerations:

In some embodiments the platform may implement subscription-based monetization features that are technically enforced and externally auditable, thereby enabling accurate calculation of infringing revenue. The subscription module 110 may operate a subscription state machine with states pending, active, grace, past_due, canceled, and refunded, where transitions are triggered by confirmed payments, expirations, charge failures, or user-initiated cancellations. The system may support monthly and annual plans, introductory trials, family or group plans, and enterprise seat bundles with per-seat entitlements. Entitlements may be enforced server-side at the API gateway 102 and authentication service 103 so that gated actions such as create delegation, revoke delegation, cast_vote, get_cycle_status, get_proposal_digest, and get disbursement are allowed only for active subscribers, and may be rate-limited by plan. The funding pool ledger 115 may maintain revenue attribution entries that link plan identifiers, subscription identifiers, and effective coverage windows to the aggregate pool balance for transparent revenue recognition. Third-party billing processor integrations may be handled via authenticated webhooks whose payloads are verified using keyed hashes or signatures and whose accepted events are recorded to the append-only audit log 170 with reason codes and idempotency keys. For example, a subscription activation audit entry may include inline fields such as {“event”:“SubscriptionActivated”, “sub_id”:“S123”, “plan id”:“P-GOLD-ANNUAL”, “user”:“U123”, “e ffective_from”:“2026-01-01T00:00:00Z”, “effective_to”:“2026-12-31T23:59:59Z”, “record_hash”:“sha 256: . . . ”} to bind monetization state to subsequent governance actions. In some embodiments metering counters may be maintained for plan-limited features such as maximum topics per user, maximum active delegations, or API call quotas, with overage policies applied and logged. To support damages calculations, the system may retain exportable reports that enumerate active subscribers, plan mix, gross receipts, refunds, and attributable pool contributions by cycle, along with per-action attribution fields that associate governance events to a subscription identifier. These reports may be derived solely from externally observable records and the audit log 170, making it feasible to quantify infringing use without internal access. In some embodiments enterprise monetization may include organization-level accounts with delegated administration, single sign-on, seat provisioning, and consolidated billing, with entitlements and usage reports exposed via the same externally observable interfaces described above. Renewal policies may include grace periods during which limited access is maintained and all actions are marked with a grace flag in the audit trail for later reconciliation. The system may further support geographic pricing, tax calculation, and compliance flags, where such fields are attached to subscription events to enable unambiguous revenue attribution in potential damages assessments.

### System Overview

The system may include client applications communicating over a network with backend services for subscription management, delegation, proposal submission, scoring, voting, cycle management, disbursement, audit logging, conflict-of-interest detection, reputation, and public dashboards.

One sequence of interactions covers delegation creation and revocation, in which a user or authorized agent submits a signed delegation payload through an API gateway, the payload is validated by an authentication service, and the delegation engine records the decision in a durable store and append-only audit log. Revocations are handled in the same flow, producing immediate recalculation of voting power for current or upcoming cycles.

Another sequence covers proposal intake through selection and disbursement. A submitter provides media content and structured fields via the proposal submission system, which may apply AI-assisted formatting and duplicate detection. A scoring engine initializes metrics, delegates review and cast votes during a defined voting window, and the cycle manager closes the cycle and determines which proposals are selected. The disbursement module schedules milestone-based tranches, and each release and milestone verification is recorded in the audit log and surfaced to the public dashboard.

A further view covers external observability and interoperability. Authenticated and public endpoints may expose cycle states, proposal digests, vote feeds, and disbursement records. Interoperability is supported through a tool interface that maps operations such as creating or revoking delegations, casting votes, retrieving cycle status, obtaining proposal digests, and fetching disbursement data. All such operations are bound to cryptographically signed records emitted by the audit log to ensure external verifiability.

Core Components and Data Flows (replaces Anchor for Figures and Elements):

To provide clarity across embodiments, the following modules and flows may be implemented in a consistent manner:
Client applications interact with backend services through a secure API gateway and authentication layer.
A subscription module receives periodic user payments and credits a collective funding pool ledger.
A delegation engine records per-topic delegations with effective-from timestamps and revocations, storing them in a delegate database.
A proposal submission system accepts media content and structured fields, optionally performing AI-assisted formatting and duplicate detection.
A scoring engine computes proposal scores using community inputs, delegate endorsements, and computed metrics.
A delegate voting subsystem enables verified delegates to cast votes during active cycles managed by a cycle manager, after which selected proposals are persisted.
A disbursement module releases funds from the funding pool in milestone-tied tranches via integrated payment services.
An append-only audit log records entries for delegation creation, revocation, votes, cycle closure, proposal selection, funds disbursement, and milestone verification, with an audit export interface for external access.
A public impact dashboard and status endpoints provide externally observable states and outcomes.
A conflict-of-interest detection engine evaluates disclosed ties and flags affected votes.
A delegate reputation service maintains performance-based reputation scores and optional compensation parameters.

### During Operation:

A user or agent submits a signed delegation payload, which is validated and stored; the system emits an audit log entry and returns a response including a record hash and server signature.
A proposal submitter provides media and structured fields; the system stores content, computes digests, and initializes scoring metrics. Delegates then review and vote, the cycle closes, and selected proposals are scheduled for milestone-based disbursements. All events are logged and surfaced to the public dashboard.
External observability is supported by endpoints returning cycle phases, proposal digests, vote feeds, and disbursement records. Tool interfaces allow interoperable access to core operations while preserving cryptographic signatures and record hashes, ensuring that behavior is externally verifiable.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A civic platform system comprising:
   a) a funding intake module configured to receive user-sourced contributions into a collective funding pool, the contributions comprising at least one of periodic subscriptions, recurring pledges, one-time contributions, employer matching, transaction round-ups, advertising or sponsor allocations, or public grants;
   b) a delegation engine configured to record per-topic delegations of voting authority from users to delegates with revocation capability;
   c) a proposal submission system configured to receive proposals including at least one of media content and structured fields describing problem, solution, impact, and cost;
   d) a selection subsystem configured to accept selection inputs from at least delegates designated via per-topic delegations and optionally one or more of assigned representatives, committee members, or authorized agent processes operating under delegated authority, the selection inputs comprising approvals, rankings, scores, pairwise choices, or votes that are weighted or unweighted, to select proposals for funding; and
   e) a disbursement module configured to allocate funds from the collective funding pool to selected proposals.
2. The system of item 1, wherein the proposal submission system includes AI-assisted formatting, duplication detection, and fact-checking support.
3. The system of item 1, wherein user-submitted proposals are categorized as nonprofit initiatives, legislative pilot proposals, scientific research trials, civic infrastructure rollouts, or educational campaigns.
4. The system of item 1, wherein voting cycles occur on a quarterly or annual cadence and a number of proposals selected in a cycle is fixed or dynamically allocated by category.
5. The system of item 1, wherein the delegation engine permits users to reassign or withdraw delegated votes at any time with immediate effect.
6. The system of item 1, further comprising a conflict-of-interest detection engine configured to flag delegate votes associated with personal, financial, or organizational ties to proposal submitters.
7. The system of item 1, wherein funded proposals are tracked and outcomes are published to a public impact dashboard.
8. The system of item 1, further comprising an educational layer that explains proposals and voting context via simplified summaries, animation, or commentary.
9. The system of item 1, wherein delegates are rewarded with a percentage of the subscription pool based on engagement, vote alignment, and community trust.
10. The system of item 1, wherein data and voting records are cryptographically signed and stored with tamper-proof audit trails.
11. The system of item 1, wherein audit logs are exportable as append-only, hash-chained records including entries for DelegationCreated, DelegationRevoked, VoteCast, CycleClosed, ProposalSelected, FundsDisbursed, and MilestoneVerified, each entry signed by an originating actor key and countersigned by a platform key.
12. The system of item 1, further comprising application programming interfaces that expose externally observable actions for delegation creation and revocation, vote casting by verified delegates, cycle status, proposal content digests, and funding disbursements, thereby enabling black-box detection of system behavior.
13. The system of item 1, wherein per-topic delegations include effective-from timestamps and revocation records that take immediate effect upon acceptance by the platform.
14. The system of item 1, further comprising a scoring engine configured to combine community votes, delegate endorsements, and computed metrics using adjustable weights.
13. A computer-implemented method comprising:
   a) receiving user-sourced contributions into a collective funding pool, the contributions comprising at least one of periodic subscriptions, recurring pledges, one-time contributions, employer matching, transaction round-ups, advertising or sponsor allocations, or public grants;
   b) recording per-topic delegations of voting authority from users to selected delegates, including revocations;
   c) accepting proposals including media content and structured fields describing problem, solution, expected impact, and cost;
   d) computing scores or rankings for proposals based on at least community inputs, delegate endorsements, and computed metrics;
   e) accepting weighted selection inputs from at least verified delegates and optionally one or more of assigned representatives, committee members, or authorized agent processes operating under delegated authority, the selection inputs comprising votes, approvals, rankings, or scores, and selecting proposals for funding based on the selection inputs;
   f) disbursing funds from the collective funding pool to selected proposals; and
   g) persisting tamper-evident audit records of delegations, votes, selections, and disbursements.
14. The method of item 13, further comprising publishing a time-bounded voting window and exposing an active window state via a public status endpoint.
15. The method of item 13, wherein disbursing funds comprises releasing funds in stages according to milestones and recording milestone verification in the audit records.
16. The method of item 13, further comprising detecting conflicts of interest by evaluating relationships between delegates and proposal submitters and flagging affected votes.
17. A non-transitory computer-readable medium storing instructions that, when executed by one or more processors, cause a computer system to perform operations comprising:
   a) receiving user-sourced contributions into a collective funding pool, the contributions comprising at least one of periodic subscriptions, recurring pledges, one-time contributions, employer matching, transaction round-ups, advertising or sponsor allocations, or public grants;
   b) recording per-topic delegations of voting authority from users to selected delegates, including revocations;
   c) accepting proposals including media content and structured fields;
   d) computing proposal scores or rankings;
   e) accepting weighted selection inputs from at least verified delegates and optionally one or more of assigned representatives, committee members, or authorized agent processes operating under delegated authority, the selection inputs comprising votes, approvals, rankings, or scores, and selecting proposals; and
   f) disbursing funds to selected proposals.
18. The non-transitory computer-readable medium of item 17, wherein the operations further comprise generating cryptographic signatures for delegation, vote, cycle, selection,
disbursement, and milestone records and exposing an append-only audit log via an application programming interface.

### Embodiment AL: Reusable Container for Food (Aka. In the Supermarkets)

The present invention relates to a reusable container system designed to replace disposable food packaging, particularly those used for meat, dairy, and other perishable goods. The system may comprise a plurality of trays fabricated from durable materials such as aluminum or high-strength plastic, each tray having a generally rectangular or square footprint with slanted sidewalls to facilitate stacking and nesting. The trays may be produced in a series of predefined sizes, wherein each subsequent size is dimensioned to have approximately half the footprint of the next larger size, allowing two trays of a given size to fit side by side within a larger tray. This proportional sizing may extend across multiple tiers, such that stacked towers of smaller trays can be received within a single larger tray, thereby improving space efficiency during transport, storage, or display.

Each tray may include a peripheral mating feature, such as a raised lip or groove, configured to engage with a corresponding lid. The lids may be manufactured from rigid plastic or similar resilient material and may include an elastomeric rim configured to compress against the mating feature of the tray to form an airtight yet detachable seal. This sealing interface may be repeatedly opened and closed without compromising its performance, enabling hygienic reuse while maintaining product freshness. The trays may be designed for compatibility with both cold and heated environments, allowing them to be used in refrigeration, freezing, or oven applications, depending on the material selected. Aluminum embodiments may offer enhanced heat resistance, while plastic embodiments may provide lighter weight and reduced cost.

The system may be applied to a wide range of food packaging scenarios. Larger trays may be suitable for products such as steak fillets, fish portions, or ready meals, whereas progressively smaller trays may be used for items such as yogurt, sauces, or snack portions. The modular design allows different products to be packaged in various tray sizes while maintaining a common stacking footprint for transport. The trays may be nestable when empty, reducing storage space requirements for manufacturers, retailers, and end users. When filled and sealed, trays may be stacked vertically or combined within a larger tray size, creating a compact, organized arrangement that simplifies logistics.

In practice, it is preferred that the reusable trays and lids are constructed from materials that are food-safe, easy to clean, and resistant to deformation over repeated use cycles. The airtight sealing mechanism may reduce spoilage and contamination risk, while the modular sizing and stackability may enable efficient use of shelf space in both retail environments and household refrigerators. The ability to replace a wide range of single-use packaging formats with a standardized, reusable solution may result in significant environmental benefits while offering practical handling and preservation advantages to consumers and suppliers alike.

In some embodiments, each tray or container may be uniquely identifiable through the inclusion of a machine-readable identifier, which may be permanently integrated into the body of the container or applied during manufacturing. The identifier may take the form of a layered or embedded QR code, a laser-etched barcode, an RFID tag, or another scannable feature capable of being read by standard point-of-sale or logistics scanning equipment. The identifier may be positioned on an exterior surface of the tray or on the lid, in a location where it remains visible and readable during normal use and after repeated washing or sterilization cycles.

The unique identifier may be associated with a deposit tracking system operated by the container provider, retailer, or a third-party logistics service. When a container is filled with food and supplied to an end user, the identifier may be scanned, and a deposit amount may be recorded and linked to the customer's transaction. This deposit may represent a refundable amount designed to encourage the return of the container once it has been emptied. Upon returning the container to a designated collection point, the identifier may again be scanned to confirm the return of the specific unit, triggering an automatic refund of the deposit to the customer's account or original payment method.

The use of unique identifiers may provide additional operational benefits, such as enabling real-time tracking of container circulation volumes, monitoring container lifespans and reuse cycles, and optimizing logistics for cleaning and redistribution. In some cases, identifiers may encode information about the tray's size, material composition, or manufacturing batch, enabling quality control and traceability. A layered QR code or equivalent embedded marking may be chosen to ensure durability, maintaining scannability even after repeated washing, exposure to heat or cold, or mechanical abrasion. This system may ensure that reusable trays can operate within an economically viable deposit-return scheme, reducing single-use packaging waste while providing financial incentives for consumers to return containers for reuse.

In certain embodiments, the reusable container system may be complemented by a tray cleaning and stacking machine designed to facilitate convenient reuse in domestic or commercial settings. The machine may be dimensioned to receive one or more of the trays or containers after they have been emptied of food contents. An end user may place a soiled tray directly into an input compartment of the machine, which may then automatically initiate a cleaning cycle. The cleaning process may involve one or more stages, such as pre-rinsing, application of heated water and food-safe detergent, ultrasonic agitation or pressurized spray cleaning, and a high-temperature rinse or steam sanitization phase to ensure that all food residues and odors are removed.

Following cleaning, the trays may be dried using heated airflow, condensation extraction, or centrifugal methods to prevent moisture accumulation and microbial growth. Once dry, the trays may be automatically transferred into a stacking compartment within the machine, where a robotic arm, conveyor, or gravity-assisted guide system may align the trays in a nested configuration to minimize storage volume. The machine may be designed to handle trays of different sizes within the modular series, automatically detecting the size of the tray through its physical dimensions or by reading the unique identifier integrated into the container. This allows mixed-size batches to be processed and stacked efficiently.

In some embodiments, the machine may communicate with a deposit-tracking or inventory management system, scanning the container's unique identifier during intake. This could allow households, restaurants, or collection centers to automatically log the return of containers, credit deposits, or update the number of cleaned, ready-to-return trays on hand. The machine may be configured for installation in residential kitchens, much like a compact dishwasher, or in larger-scale community return centers where high volumes of trays are processed.

By providing an integrated cleaning and stacking solution, the invention ensures that trays are hygienically maintained between uses, eliminates odors that may otherwise discourage storage before return, and organizes containers in a compact, stackable form ready for transport or collection. This addition supports the broader deposit-return ecosystem, increasing consumer convenience and further reducing reliance on disposable packaging.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A modular reusable container system comprising:
   a) a set of trays in at least two sizes, each tray having a footprint and sidewalls configured for nesting when empty;
   b) wherein for at least one successive size, m trays of a given size are configured to occupy, side by side, substantially the footprint of the next larger size, where m is an integer greater than or equal to two, so that proportional sizing extends across one or more tiers.
2. The system of item 1, wherein m equals two and two trays of a given size fit within the footprint of the next larger size within a dimensional tolerance that maintains retail shelf and pallet compatibility.
3. The system of item 1, wherein the sidewalls are slanted to facilitate nesting when empty and to permit stable stacking when trays are filled and sealed.
4. The system of item 1, wherein the trays are fabricated from aluminum, high-strength plastic, or combinations thereof.
5. The system of item 1, further comprising lids corresponding to the trays, each tray including a peripheral mating feature and each lid including an elastomeric rim configured to compress against the mating feature to form an airtight yet detachable seal.
6. The system of item 5, wherein the trays and lids are compatible with refrigeration, freezing, or oven use according to the selected material.
7. The system of item 5, wherein the sealing interface is configured for repeated opening and closing without substantial loss of sealing performance.
8. The system of item 1, wherein the tray dimensions and stackability are standardized to align with retail shelf and pallet dimensions for transport and display.
9. The system of item 1, wherein towers of smaller trays are configured to be received within a larger tray to minimize volume during storage and transport.
10. A reusable food container comprising:
   a) a tray having an exterior surface; and
   b) a machine-readable identifier permanently integrated with the container or lid, the identifier selected from a layered QR code, a laser-etched barcode, or an RFID tag, the identifier being scannable by standard point-of-sale or logistics scanners after repeated washing or sterilization and encoding at least one of tray size, material composition, or manufacturing batch.
11. The container of item 10, used in combination with a deposit-tracking service configured to store a refundable amount linked to the identifier upon issuance and to trigger a refund upon scanning the identifier at a designated return point.
12. A method of deposit tracking for reusable food containers, the method comprising:
   a) scanning a machine-readable identifier associated with a container at issuance to a customer;
   b) recording a refundable deposit linked to the identifier and the customer's transaction;
   c) scanning the identifier upon container return; and
   d) automatically refunding the deposit to the customer's account or original payment method.
13. The method of item 12, wherein each scan generates a transaction record serialized in a text-based format including a container identifier, a size code, a material designation, a deposit amount, an event type, a timestamp, a site identifier, and a product identifier.
14. The method of item 12, wherein scanning is performed by standard point-of-sale or logistics equipment and transaction records update an inventory management system over a network.
15. The method of item 12, further comprising monitoring container circulation volumes, lifespans, reuse cycles, and material composition using data linked to the identifier.
16. A cleaning and stacking machine for reusable food containers comprising:
   a) an input compartment to receive soiled trays;
   b) a cleaning subsystem configured to execute stages including at least pre-rinsing,
application of heated water with food-safe detergent, ultrasonic agitation or pressurized spray cleaning, and a high-temperature rinse or steam sanitization;
   c) a drying subsystem configured to remove moisture using heated airflow, condensation extraction, or centrifugal action; and
   d) a stacking mechanism configured to align and nest trays after drying.
17. The machine of item 16, further comprising a sensor system configured to detect tray size by measuring physical dimensions or by reading the machine-readable identifier, and a communication interface configured to report intake events to a deposit-tracking or inventory system.
18. The machine of item 16, configured for residential installation comparable to a compact dishwasher or for deployment in a community return center processing higher volumes.
19. The machine of item 16, wherein the stacking mechanism nests smaller trays within larger trays to minimize storage volume for transport or pickup.
20. A non-transitory computer-readable medium storing instructions that, when executed by one or more processors of a retail or logistics system, cause the system to perform the method of item 12 and to emit audit records that externally evidence deposit assessment and refund events without requiring inspection of internal server implementations.

### Embodiment ALE: Reusable Container for Food

A reusable container system may replace disposable packaging for perishable goods using modular trays with proportional sizing, detachable airtight lids, and durable, food-safe materials. Unique machine-readable identifiers may link each container to a deposit-return program and logistics systems. Optional cleaning and stacking machines may automate sanitation, drying, and nesting across multiple tray sizes. Transaction and telemetry records may enable auditability, interoperability, and optional subscription-based monetization.

### Gentle Introduction

Single-use food packaging creates waste and inefficiencies in handling and storage. A practical alternative may use robust trays and lids that seal reliably, stack neatly, and return to circulation through a deposit system that is easy to operate at retail counters and return points. The system described here may let two smaller trays fit side by side in the footprint of the next larger tray, so storage and transport stay orderly from shop shelves to household refrigerators. A simple scan of a durable identifier on each tray may record issuance and refund upon return, while an optional compact machine may clean and restack trays automatically so they are ready for reuse.

### Background

Disposable meat and dairy trays with film lids are ubiquitous but generate significant waste and inconsistent stacking formats that complicate logistics. Prior reusable containers often lack standardized proportional sizing that allows cross-tier nesting and do not integrate durable identifiers resilient to heat, cold, and washing cycles. Retailers need a solution that fits current shelving and pallet systems, and consumers benefit from hygienic, refundable containers that are simple to return.

### Summary

The invention provides a modular series of stackable, nestable trays in multiple sizes, each with a corresponding lid that may form a detachable airtight seal. Two trays of a given size may fit within the footprint of the next larger size, allowing towers of smaller trays to be received within larger trays. Durable identifiers on each container may drive deposit tracking, logistics, and analytics. An optional cleaning and stacking machine may automate sanitation and nesting. Transaction records may be emitted for reconciliation and, where desired, subscription-based monetization.

### Description of the Drawings

Drawings are not included in this filing. Elements and relationships are anchored by the Anchor section and by the itemized embodiments list; any future figures may assign reference numerals consistent with those textual anchors.

### Preamble and Scope

For avoidance of doubt, the following description presents example embodiments to illustrate inventive concepts, and the scope of the invention may be determined solely by the claims. Any figures, drawings, and examples described herein are illustrative and non-limiting. Steps, operations, and flows may be performed in any suitable order or in parallel unless explicitly stated otherwise.

Features described in connection with one embodiment may be combined with, substituted into, or omitted from other embodiments, and dimensional, material, and protocol selections may be varied without departing from the invention.

### Definitions

For clarity of claim interpretation and to improve legal certainty, terms are used as follows. Footprint may refer to the plan-view boundary of a tray measured as the projection of the outermost tray lip or perimeter onto a plane orthogonal to gravity when the tray rests on a level surface. Occupy substantially the footprint may refer to an arrangement in which the combined plan-view width and length of m trays of size Sn nest or sit side by side within the corresponding width and length of size Sn+1 within a tolerance not exceeding ten percent in at least one of width or length and not exceeding fifteen percent in area, with some embodiments achieving three percent or less in width or length. Equivalent embodiments may achieve substantial occupancy by employing integrated or attachable adapter rails, rings, frames, or spacers that cause m trays of size Sn to be stably received within the boundary envelope of size Sn+1 for transport, storage, or display, the system being open-ended such that additional components may be present. Airtight may refer to a detachable seal that limits steady-state gas leakage to less than one cubic centimeter per minute at a one kilopascal differential at twenty degrees Celsius for an empty container nominally one liter in volume, or equivalently limits water mass loss to less than one percent over twenty-four hours at four degrees Celsius; equivalent standards-based leak tests may be substituted. Nest or nesting may refer to insertion of empty trays one within another such that the incremental stack height per additional tray is less than seventy percent of a single tray height, with some embodiments achieving fifty percent or less. Detachable may refer to removal or reattachment of a lid without destructive damage to the tray or lid and without tools other than fingers or simple implements. Permanently integrated, as applied to identifiers, may refer to an identifier fixed to or embedded in the container such that it remains machine-readable after at least one hundred wash and sterilization cycles including heated water and detergent and cannot be removed without visible damage to the container or identifier. Machine-readable identifier may encompass optical, radiofrequency, or other encodings that can be decoded by off-the-shelf scanners or readers compliant with GS1, ISO/IEC, EPCglobal, or equivalent standards. Successive sizes may refer to immediately adjacent members of a defined size series Sn and Sn+1. Configured to may indicate that a component is designed or arranged to perform the stated function during normal operation, whether or not continuously active. Residential and community return center contexts may refer to duty cycles characterized by fewer than approximately twenty processing cycles per day versus more than approximately one hundred cycles per day, respectively, the values being illustrative and non-limiting.

### Detailed Description

The present invention relates to a reusable container system designed to replace disposable food packaging, particularly those used for meat, dairy, and other perishable goods. The system may comprise a plurality of trays fabricated from durable materials such as aluminum or high-strength plastic, each tray having a generally rectangular or square footprint with slanted sidewalls to facilitate stacking and nesting. The trays may be produced in a series of predefined sizes, wherein each subsequent size is dimensioned to have approximately half the footprint of the next larger size, allowing two trays of a given size to fit side by side within a larger tray. This proportional sizing may extend across multiple tiers, such that stacked towers of smaller trays can be received within a single larger tray, thereby improving space efficiency during transport, storage, or display.

Each tray may include a peripheral mating feature, such as a raised lip or groove, configured to engage with a corresponding lid. The lids may be manufactured from rigid plastic or similar resilient material and may include an elastomeric rim configured to compress against the mating feature of the tray to form an airtight yet detachable seal. This sealing interface may be repeatedly opened and closed without compromising its performance, enabling hygienic reuse while maintaining product freshness. The trays may be designed for compatibility with both cold and heated environments, allowing them to be used in refrigeration, freezing, or oven applications, depending on the material selected. Aluminum embodiments may offer enhanced heat resistance, while plastic embodiments may provide lighter weight and reduced cost.

The system may be applied to a wide range of food packaging scenarios. Larger trays may be suitable for products such as steak fillets, fish portions, or ready meals, whereas progressively smaller trays may be used for items such as yogurt, sauces, or snack portions. The modular design allows different products to be packaged in various tray sizes while maintaining a common stacking footprint for transport. The trays may be nestable when empty, reducing storage space requirements for manufacturers, retailers, and end users. When filled and sealed, trays may be stacked vertically or combined within a larger tray size, creating a compact, organized arrangement that simplifies logistics.

In practice, it is preferred that the reusable trays and lids are constructed from materials that are food-safe, easy to clean, and resistant to deformation over repeated use cycles. The airtight sealing mechanism may reduce spoilage and contamination risk, while the modular sizing and stackability may enable efficient use of shelf space in both retail environments and household refrigerators. The ability to replace a wide range of single-use packaging formats with a standardized, reusable solution may result in significant environmental benefits while offering practical handling and preservation advantages to consumers and suppliers alike.

In some embodiments, each tray or container may be uniquely identifiable through the inclusion of a machine-readable identifier, which may be permanently integrated into the body of the container or applied during manufacturing. The identifier may take the form of a layered or embedded QR code, a laser-etched barcode, an RFID tag, or another scannable feature capable of being read by standard point-of-sale or logistics scanning equipment. The identifier may be positioned on an exterior surface of the tray or on the lid, in a location where it remains visible and readable during normal use and after repeated washing or sterilization cycles.

The unique identifier may be associated with a deposit tracking system operated by the container provider, retailer, or a third-party logistics service. When a container is filled with food and supplied to an end user, the identifier may be scanned, and a deposit amount may be recorded and linked to the customer's transaction. This deposit may represent a refundable amount designed to encourage the return of the container once it has been emptied. Upon returning the container to a designated collection point, the identifier may again be scanned to confirm the return of the specific unit, triggering an automatic refund of the deposit to the customer's account or original payment method.

The use of unique identifiers may provide additional operational benefits, such as enabling real-time tracking of container circulation volumes, monitoring container lifespans and reuse cycles, and optimizing logistics for cleaning and redistribution. In some cases, identifiers may encode information about the tray's size, material composition, or manufacturing batch, enabling quality control and traceability. A layered QR code or equivalent embedded marking may be chosen to ensure durability, maintaining scannability even after repeated washing, exposure to heat or cold, or mechanical abrasion. This system may ensure that reusable trays can operate within an economically viable deposit-return scheme, reducing single-use packaging waste while providing financial incentives for consumers to return containers for reuse.

In certain embodiments, the reusable container system may be complemented by a tray cleaning and stacking machine designed to facilitate convenient reuse in domestic or commercial settings. The machine may be dimensioned to receive one or more of the trays or containers after they have been emptied of food contents. An end user may place a soiled tray directly into an input compartment of the machine, which may then automatically initiate a cleaning cycle. The cleaning process may involve one or more stages, such as pre-rinsing, application of heated water and food-safe detergent, ultrasonic agitation or pressurized spray cleaning, and a high-temperature rinse or steam sanitization phase to ensure that all food residues and odors are removed.

Following cleaning, the trays may be dried using heated airflow, condensation extraction, or centrifugal methods to prevent moisture accumulation and microbial growth. Once dry, the trays may be automatically transferred into a stacking compartment within the machine, where a robotic arm, conveyor, or gravity-assisted guide system may align the trays in a nested configuration to minimize storage volume. The machine may be designed to handle trays of different sizes within the modular series, automatically detecting the size of the tray through its physical dimensions or by reading the unique identifier integrated into the container. This allows mixed-size batches to be processed and stacked efficiently.

In some embodiments, the machine may communicate with a deposit-tracking or inventory management system, scanning the container's unique identifier during intake. This could allow households, restaurants, or collection centers to automatically log the return of containers, credit deposits, or update the number of cleaned, ready-to-return trays on hand. The machine may be configured for installation in residential kitchens, much like a compact dishwasher, or in larger-scale community return centers where high volumes of trays are processed.

By providing an integrated cleaning and stacking solution, the invention ensures that trays are hygienically maintained between uses, eliminates odors that may otherwise discourage storage before return, and organizes containers in a compact, stackable form ready for transport or collection. This addition supports the broader deposit-return ecosystem, increasing consumer convenience and further reducing reliance on disposable packaging.

### Examples

By way of example, a butcher or deli counter may select a tray size that matches a product's footprint, such as a medium tray accommodating two steak fillets placed flat against the base. The operator may place a rigid lid onto the tray so that the elastomeric rim compresses against the tray's raised lip, forming an airtight seal. The operator may then scan the machine-readable identifier so that a point-of-sale system records both the product SKU and a deposit amount associated with that specific container identifier, after which the sealed tray may be displayed or handed to the customer. In another example, a consumer returning an empty container may approach a staffed counter or automated kiosk and present the sealed or unsealed tray so that the identifier is scanned. The system may recognize the identifier, verify return eligibility, and initiate an automatic refund of the previously recorded deposit to the customer's account, while instructing the consumer to place the tray into a designated intake bin for cleaning and redistribution.

As an illustration of the cleaning workflow, a mixed batch of trays of different sizes may be placed into the input compartment of a compact residential machine. The machine may sense dimensions mechanically or optically and may optionally read the identifier to determine the material type. A pre-rinse may remove loose debris, followed by detergent wash with heated water, ultrasonic or pressurized spray agitation to dislodge residues, then a high-temperature rinse or steam stage to sanitize surfaces. A heated airflow may dry the trays, and an internal guide or robotic mechanism may nest the trays so that smaller trays are aligned within larger trays to minimize volume for storage or pickup.

For logistics and storage, two trays of a smaller size may be positioned side by side within the footprint of the next larger size, and multiple layers of small trays may be stacked in towers before being received within a larger tray. A retailer may therefore consolidate returned, cleaned trays in nested stacks that match standard shelf and pallet dimensions, improving transport efficiency and display organization without repacking individual items.

An example of a scan event record usable by deposit or inventory systems may be expressed as a compact, inline data object such as

{“containerId”:“C-ABC123”,“sizeCode”:“S2”,“material”:“aluminum”,“depositCents”:150,“event”:“ch
eckout”,“timestamp”:“2025-05-20T15:04:05Z”,“storeId”:“ST-045”,“sku”:“MEAT-STEAK-200G”},

although particular field names, values, and transport protocols may vary according to implementation. Where software components expose structured tool endpoints, an optional Model Context Protocol interface may transmit or receive such inline JSON records to interoperate with external tools that orchestrate scanning or reconciliation.

### Monetization and Damages Maximization

In some embodiments, monetization and subscription features may be provided to support damages-relevant accounting for commercial deployments. A container service provider may operate a subscription in which retailers, collection centers, or cleaning-machine operators pay a monthly or per-scan fee, wherein scan events, cleaning cycles, and stacking operations are metered by the systems described herein. The unique identifiers and associated transaction records may drive automated invoicing, with usage summaries and audit logs emitted by the retail or logistics system and by the cleaning and stacking machine. Software components may include license-key activation, tiered service levels that govern permitted features such as maximum daily scans or audit-record retention periods, tamper-evident storage of event hashes to demonstrate use, and policy-controlled deposit-float ledgers including interest allocation or breakage handling. Externally observable monthly statements may reconcile to emitted event records without requiring access to internal server code, enabling proof of use in the field. These monetization features may be optional and orthogonal to the core reusable container functionality and may be implemented over standard network interfaces that interact with identifier scans and machine telemetry.

### Technical Effects

Embodiments may reduce single-use packaging waste, improve shelf and pallet utilization through proportional sizing and cross-tier nesting, and maintain food freshness via repeatable airtight seals. Durable identifiers may enable accurate deposit refunds, lifecycle analytics, and recall traceability. Automated cleaning and stacking may improve hygiene, reduce labor, and increase return convenience, leading to higher reuse rates. Emitted, reconciled audit records may provide provable usage evidence without access to internal servers.

### Flows

Representative flows may include issuance, return, cleaning, and restocking. Issuance may include scanning a container identifier, linking a deposit to a transaction, sealing a lid, and handing the container to a customer. Return may include scanning at a designated point, verifying eligibility, and crediting the refund. Cleaning may include intake detection, pre-rinse, wash, sanitize, dry, and stacking into nested arrangements, with telemetry emitted at stage transitions. Restocking may include consolidating nested stacks aligned to shelf and pallet standards and re-issuing cleaned containers.

### Enablement

A skilled person may fabricate trays by thermoforming or injection molding high-strength plastics with draft angles for nesting, or by stamping or deep drawing aluminum with optional coatings. Lids may be molded with an elastomeric rim selected for compression set resistance and food-contact compliance; rim and tray lip geometries may be tuned to achieve target leak rates under refrigeration and transport vibration. Identifiers may be laser-etched, embedded during molding, affixed as RFID inlays, or formed as layered QR codes enduring dishwashing and steam sanitization. A deposit-tracking system may persist issuance and return events in a relational or document database and expose endpoints over REST or message queues; records may serialize as inline JSON as exemplified above. Cleaning machines may integrate pumps, heaters, ultrasonic transducers or spray manifolds, temperature and turbidity sensors, airflow heaters or condensers, and electromechanical stackers with guides or robotic actuators. Optional Model Context Protocol endpoints may allow external orchestration tools to request scans, submit events, or retrieve reconciled summaries as inline JSON without dictating any specific server implementation.

### Support

Each claim is supported by the Detailed Description, the Anchor section, and the itemized embodiments list. Method steps, machine subsystems, materials, identifier types, proportional sizing, sealing interfaces, and data structures are described with sufficient specificity to enable skilled implementation without undue experimentation.

### Broadening

Alternatives may include varying tray counts per footprint step (e.g., two, three, or four subdivisions), different plastics or aluminum alloys, alternative seal elastomers, multiple identifier technologies including NFC, EPCglobal-compliant UHF RFID, or GS1 barcodes, and alternate cleaning modalities such as ozone, UV-C, or enzymatic detergents. Network interoperability may encompass REST, MQTT, AMQP, or file-drop ingestion using CSV, JSON, or newline-delimited JSON, without limiting the invention to particular vendors or platforms. Shapes may include rectangular, square, circular, oval, hexagonal, or triangular forms with tessellations or adapter frames that preserve proportional nesting across shape families. Sealing modalities may include snap-fit, bayonet, clamp, magnetic, or frame-and-membrane mechanisms and optional vacuum or pressure-relief valves while remaining detachable and airtight where applicable. Tamper-evident or freshness-indicating elements may be integrated without constraining the core concepts.

### Interoperability Coverage

Embodiments may interoperate with point-of-sale systems using GS1-encoded barcodes, retail scanners, and RFID readers, and with logistics platforms using EPCglobal standards. Software interfaces may include REST and WebSocket APIs, MQTT topics for event streaming, and optional Model Context Protocol endpoints to coordinate tool actions. These interfaces may be platform-agnostic so interface changes or protocol swaps do not avoid infringement.

### Fallback Embodiments

Simpler implementations may include trays and lids with proportional sizing and durable identifiers but no deposit service, or a deposit service using manual cleaning, or cleaning and stacking without deposit tracking. Even partial systems that implement proportional nesting with detachable airtight lids embody the inventive concept.

### External Observability

Externally observable behaviors may include scan events at issuance and return with timestamps, deposits debited and refunded with amounts and identifiers, machine telemetry reporting cycle stages, and emitted monthly statements that reconcile to event logs. These outputs allow detection of infringement in fielded systems without internal inspection. In some embodiments, externally observable interfaces may be defined so that independent auditors can confirm use without privileged access. A retail or return endpoint may accept an HTTP POST to/scan with an inline JSON body such as

{“containerId”:“C-ABC123”,“event”:“return”,“storeId”:“ST-045”,“timestamp”:“2025-05-20T16:01:02
Z”} and respond with
{“accepted”:true,“depositCents”:150,“refundId”:“R-778899”,“timestamp”:“2025-05-20T16:01:02Z”}.

A receipt or on-screen confirmation may display the containerId and depositCents values exactly as emitted. Cleaning machines may emit stage-transition telemetry as newline-delimited JSON over a local TCP port or MQTT topic, for example {“machineId”:“M-001”, “stage”:“sanitize”, “seq”:4, “timestamp”:“2025-05-20T16:03:00Z”}. Status lamps or codes may mirror the stage field such as WASH, RINSE, SANITIZE, DRY, and STACK so that a camera or observer can corroborate the telemetry. Providers may publish a daily immutable statement at a well-known URL that includes {“statementDate”:“2025-05-20”, “eventCount”:12345, “sha256OfEvents”:“ . . . }. where sha2560fEvents is the hash of the canonical concatenation of the day's event records, enabling third parties to verify completeness of reported usage. If an identifier is unknown or malformed, the scan response may return {“accepted”:false, “error”:“UNKNOWN_ID”}, and refund processing may complete within a bounded interval such as ten seconds under normal connectivity, behaviors that are externally testable without internal code inspection.

### Claim Layering

Independent claims cover a system of trays, a container with an identifier, a deposit-tracking method, a cleaning and stacking machine, and a computer-readable medium. Additional features in the itemized list provide continuation-ready disclosure for future claims at different abstraction levels.

### No Unneeded Limitations

Core claims may include only features unavoidable for competitive implementation, such as proportional sizing enabling cross-tier nesting, detachable airtight lids, and durable identifiers supporting deposit-return logistics, avoiding unnecessary restrictions to particular vendors, software stacks, or exact materials where not necessary.

### Workaround Resistance

To inhibit trivial design-arounds, the claim set and written description cover orthogonal axes so that substituting geometry, materials, identifiers, or workflows does not avoid infringement. The system claim captures proportional nesting using m as any integer greater than or equal to two so that arrangements with two, three, or more smaller trays occupying the next larger footprint remain within scope. Shape substitutions across rectangular, square, circular, oval, hexagonal, or triangular forms remain covered where proportional nesting is preserved, and the open-ended comprising language permits additional components such as adapter rails or frames without escaping the system claim.

Equivalent implementations that stabilize smaller trays within the larger tray's boundary using integrated or attachable adapters are disclosed and supported, so minor void areas or framing do not constitute a design-around. If proportional nesting is omitted, implementations that nonetheless employ durable identifiers or deposit-return flows are addressed by the independent container and method claims, and if identifiers or deposits are omitted, implementations employing proportional nesting without identifiers are addressed by the system claim. Swapping protocol stacks, reordering stages, or using offline redemption does not avoid software-oriented claims because interfaces are specified in a platform-agnostic manner and externally observable event records provide objective evidence of use. Lid and seal substitutions remain covered via detachable airtight alternatives, including snap-fit, bayonet, clamp, magnetic, or frame-and-membrane closures, while vacuum or pressure-relief features are disclosed so that pressure-management variations do not constitute a design-around. The itemized list enumerates further features such as adapter rails and cross-family nesting that may be directly claimed in continuations to address any newly observed avoidance tactics while preserving written description support. Competitors may attempt to rely on sleeves, cradles, or outer catrers to assert that multiple smaller trays do not occupy a larger tray's footprint. Equivalent arrangements in which smaller trays are constrained within the larger boundary envelope by integrated or attachable stabilizers, rails, rings, frames, spacers, friction or magnetic couplers, or keyed perimeter geometries remain within scope as taught in the Definitions and Items C31 through C34, even where interstitial voids are present. Using a removable carrier or cradle may still satisfy proportional nesting because adapter-mediated occupancy that stabilizes m trays within the footprint of Sn+1 is expressly disclosed.

Substituting a film membrane on a rigid frame, a peelable gasketed membrane, or a hinged lid may still meet the detachable airtight sealing alternatives described in Items C21 and C22, provided the leak criteria in the Definitions are met and opening does not require destructive damage. Attempts to move identifiers to secondary sleeves or crates that are permanently fixed, bonded, riveted, or otherwise non-removably coupled to the container or lid may still satisfy the permanently integrated definition; omitting identifiers does not avoid the system claim directed to proportional nesting. Dividing deposit workflows across separate actors may not avoid infringement because at least one operator can perform all steps of the method and computer-readable medium claims, and induced or contributory liability may be implicated where steps are performed under direction or control as described herein.

Variations using staggered offsets, compliant edges, tessellations across dissimilar shapes, or dynamic guides that cause m smaller trays to be stably received within the footprint of Sn+1 may remain covered by the occupy substantially standard and disclosed adapters. Renaming fields, batching or delaying events, changing network protocols, or operating in offline modes may not avoid software-oriented claims where externally observable scan, refund, and telemetry records with equivalent informational content are emitted and reconcilable to usage summaries.

### Court Readiness and Statutory Compliance

Subject-matter eligibility under 35 U.S.C. § 101 may be satisfied because the claims recite concrete articles of manufacture (trays, lids), machines (a cleaning and stacking machine), and a non-transitory computer-readable medium that operates in conjunction with physical identifiers and scanners, as well as a deposit-tracking method tied to real-world scan events and refunds that improve a technological process for reusable packaging logistics. The claimed methods may effect transformations of physical articles through cleaning, drying, and stacking, and the software components are integrated with hardware and externally observable events, so the overall subject matter is not directed to a disembodied abstract idea.

Definiteness under § S112(b) may be supported by the Definitions section, which provides objective boundaries for terms such as airtight, nest, occupy substantially the footprint, and configured to. Quantitative thresholds and testable criteria are supplied so that a skilled person may ascertain claim scope with reasonable certainty. The claims avoid means-for language; configured to may be understood as structural and operational capability rather than means-plus-function under § 112(f), and, where functional language is used, the specification discloses corresponding structures and examples.

Written description and enablement under § 112(a) may be supported by the Detailed Description, the Anchor section, and the itemized embodiments list, which disclose representative materials, geometries, sealing interfaces, identifier technologies, cleaning subsystems, sensing and communication interfaces, process flows, and example data structures. Manufacturing routes including molding and deep drawing, seal performance targets and testing, identifier durability criteria, and software interoperability with standard protocols are taught so that a skilled person could make and use the invention without undue experimentation. No best mode is intentionally withheld; exemplary materials and interfaces are disclosed while alternatives remain within scope. Novelty and non-obviousness under §§ 102 and 103 may be supported by the specific combination of proportional cross-tier nesting across successive sizes with quantified footprint occupancy tolerances, detachable airtight lids suitable for repeated cycles, permanently integrated durable identifiers designed to remain readable after at least one hundred wash and sterilization cycles, and an optional cleaning and stacking machine that both detects tray size and nests smaller trays within larger trays.

The integration of deposit-tracking flows that emit reconciled, externally observable audit records, together with interoperability across GS1 and EPCglobal standards and optional Model Context Protocol interfaces, may yield operational advantages and provable usage not taught in conventional reusable packaging or generic food containers. The synergy among these features may produce improved logistics density, return compliance, and hygiene while enabling external proof of use for enforcement.

Proof of use and damages readiness may be enhanced through externally observable evidence such as scan logs, refund records, and machine telemetry emitted at stage transitions, which may be reconciled to monthly statements. Leak performance and seal integrity may be demonstrated using the defined test criteria, and proportional nesting may be verified through dimensional checks against the specified tolerances. Containers and machines may be marked with patent identifiers or a virtual marking URL to satisfy 35 U.S.C. § 287 notice requirements.

Claim construction may be guided by the Preamble and Scope and Definitions sections. Comprising language may indicate that additional elements may be present. Examples and flows may be illustrative and reorderable unless explicitly stated otherwise. The breadth disclosed in the itemized embodiments may provide support for equivalents so that immaterial variations in shapes, materials, identifier technologies, sealing modalities, or network protocols may remain within the scope of the claims under the doctrine of equivalents where appropriate. To mitigate divided-infringement concerns, at least one independent method claim is drafted so that a single retail or return-center operator may perform all recited steps, and system and machine claims are drafted so that a single entity supplies or controls the accused combination; alternatively, induced or contributory infringement may be shown where different actors perform steps under direction or control consistent with prevailing case law. Remedies may be supported by virtual and physical marking to establish notice, by externally observable audit logs that evidence willful use of licensed-only features for enhanced damages where appropriate, and by claim formats that avoid ambiguity in antecedent basis and preamble limitations so that enforceability is strengthened.

### Continuation-Ready

The itemized list enumerates discrete, mix-and-match features suitable for continuation filings. Each claimed concept appears in the list so deletions or re-scoping of claims preserve written description support.

### Anchor

This section lists principal elements of the embodiments and core relationships among them to anchor understanding. The system may include a modular series of trays in at least two sizes with rectangular or square footprints and slanted sidewalls, trays having peripheral mating features and corresponding lids with elastomeric rims configured to form detachable airtight seals, and materials including aluminum and high-strength plastic. Proportional sizing may ensure that two trays of size Sn occupy substantially the footprint of size Sn+1 and that towers of smaller trays may be received within a larger tray, preserving retail shelf and pallet compatibility. Unique machine-readable identifiers may be integrated with trays or lids, such as layered or embedded QR codes, laser-etched barcodes, or RFID tags, readable by standard point-of-sale or logistics scanners after repeated washing and sterilization, and encoding one or more of tray size, material composition, and manufacturing batch. A deposit-tracking service may link an identifier to a refundable deposit at issuance and trigger a refund upon scanning at a designated return point, with each scan producing transaction records including container identifiers, size codes, materials, deposit amounts, event types, timestamps, site or store identifiers, and product identifiers. A cleaning and stacking machine may include an intake compartment, a cleaning subsystem performing pre-rinsing, heated water with food-safe detergent, ultrasonic or pressurized spray cleaning, and high-temperature rinse or steam sanitization, a drying subsystem using heated airflow, condensation extraction, or centrifugal action, and a stacking mechanism that aligns and nests trays, including nesting of smaller sizes within larger sizes to minimize volume. Sensor systems may measure tray dimensions or read identifiers to determine size or material, and a communication interface may report intake events and machine telemetry to retail, deposit-tracking, or inventory systems. Installation contexts may include residential units comparable to compact dishwashers and higher-volume community return centers. Core relationships include that identifiers remain readable across reuse cycles, sealing interfaces withstand repeated opening and closing without substantial loss of performance, trays remain compatible with refrigeration, freezing, and, for aluminum embodiments, oven heating, proportional sizing supports efficient transport and display, externally observable audit records reconcile to deposit and usage ledgers to evidence issuance and refund without internal code inspection, and monetization features may meter scans, cleaning cycles, and stacking operations under license controls while remaining optional and orthogonal to reusable container functions.

### Embodiments can be Described by the Following Itemized List

Item C1. An embodiment may include a modular reusable container system having at least two tray sizes, each tray sized and shaped to nest when empty, wherein for at least one successive size step two trays of a given size occupy, side by side, substantially the footprint of the next larger size so that proportional sizing extends across one or more tiers for logistics efficiency.
Item C2. An embodiment may maintain dimensional tolerances such that two trays of a given size fit within the next larger size while preserving retail shelf and pallet compatibility across standard formats, including common grocery shelving and pallet footprints.
Item C3. An embodiment may use slanted sidewalls that facilitate nesting when empty and permit stable stacking when trays are filled and sealed, including wall angles and draft features selected to balance ease of demolding, nesting density, and stack stability.
Item C4. An embodiment may fabricate trays from aluminum, high-strength plastic, or combinations thereof, optionally with coatings or surface treatments for corrosion resistance, non-stick performance, labeling adhesion, or dishwasher durability.
Item C5. An embodiment may pair each tray with a corresponding lid, the tray including a peripheral mating feature and the lid including an elastomeric rim configured to compress against the mating feature to form an airtight yet detachable seal that may be repeatedly engaged and disengaged.
Item C6. An embodiment may provide compatibility with refrigeration, freezing, or oven use according to material selection, including aluminum embodiments tolerating oven temperatures and plastic embodiments optimized for low-temperature resilience and reduced mass.
Item C7. An embodiment may configure the sealing interface for repeated opening and closing without substantial loss of sealing performance, including elastomer selection, rim geometry, and surface finish choices that preserve seal integrity over many cycles.
Item C8. An embodiment may standardize tray dimensions and stackability to align with retail shelf and pallet dimensions for transport and display, supporting direct integration into existing store fixtures and distribution equipment.
Item C9. An embodiment may allow towers of smaller trays to be received within a larger tray to minimize volume during storage and transport, including mixed-size nesting schemes that reduce handling and repacking.
Item C10. An embodiment may integrate a machine-readable identifier with a tray or lid, such as a layered QR code, a laser-etched barcode, or an RFID tag, scannable by standard point-of-sale or logistics scanners after repeated washing or sterilization, and encoding at least one of tray size, material composition, or manufacturing batch for traceability.
Item C11. An embodiment may operate with a deposit-tracking service that stores a refundable amount linked to the identifier upon issuance and triggers a refund upon scanning at a designated return point, enabling consumer incentives for reuse.
Item C12. An embodiment may implement a deposit-tracking method that includes scanning the identifier at issuance to a customer, recording a refundable deposit linked to the identifier and the customer's transaction, scanning the identifier upon container return, and automatically refunding the deposit to the customer's account or original payment method.
Item C13. An embodiment may serialize each scan into a transaction record in a text-based format including a container identifier, a size code, a material designation, a deposit amount, an event type, a timestamp, a site identifier, and a product identifier, usable for reconciliation and audit.
Item C14. An embodiment may perform scanning using standard point-of-sale or logistics equipment and may update an inventory or deposit management system over a network, including local or cloud-hosted services interoperating with existing retail software.
Item C15. An embodiment may monitor container circulation volumes, lifespans, reuse cycles, and material composition using data linked to the identifier, supporting analytics, quality control, and sustainability reporting.
Item C16. An embodiment may comprise a cleaning and stacking machine including an input compartment to receive soiled trays, a cleaning subsystem to execute pre-rinsing, application of heated water with food-safe detergent, ultrasonic agitation or pressurized spray cleaning, and a high-temperature rinse or steam sanitization, a drying subsystem using heated airflow, condensation extraction, or centrifugal action, and a stacking mechanism that aligns and nests trays after drying.
Item C17. An embodiment may include a sensor system configured to detect tray size by measuring physical dimensions or by reading the machine-readable identifier, and a communication interface configured to report intake events and machine telemetry to a deposit-tracking or inventory system.
Item C18. An embodiment may configure the cleaning and stacking machine for residential installation comparable to a compact dishwasher or for deployment in a community return center processing higher volumes, with form factors and duty cycles adapted to the environment.
Item C19. An embodiment may configure the stacking mechanism to nest smaller trays within larger trays to minimize storage volume for transport or pickup, including guides, stops, or robotic actuators to ensure alignment.
Item C20. An embodiment may store instructions on a non-transitory computer-readable medium that, when executed by one or more processors of a retail or logistics system, cause performance of the deposit-tracking method and emission of audit records that externally evidence deposit assessment and refund events without requiring inspection of internal server implementations.
Item C21. An embodiment may implement alternative detachable airtight sealing mechanisms including snap-fit, bayonet, clamp, magnetic, or frame-and-membrane closures, optionally with gasketed interfaces, so that lid variants remain interoperable with tray mating features.
Item C22. An embodiment may integrate a vacuum or pressure-relief valve into the lid or tray configured to evacuate or equalize internal pressure, including one-way degassing valves for freshness retention during storage and transport.
Item C23. An embodiment may employ non-rectilinear shapes including circular, oval, hexagonal, or triangular trays and lids, with tessellations or adapter frames that preserve proportional nesting whereby m smaller trays fit within the footprint or boundary of a larger tray.
Item C24. An embodiment may incorporate removable or repositionable internal dividers or inserts that preserve proportionality and permit packaging of multiple SKUs in one tray while maintaining cross-tier nesting and sealing performance.
Item C25. An embodiment may include tamper-evident or freshness-indicating features such as frangible bridges, color-change indicators responsive to time or temperature, or mechanical flags that reset upon opening.
Item C26. An embodiment may encode identifiers using optical watermarks, molded microtext, microdot arrays, conductive or inductive traces, UV-fluorescent markings, or combinations thereof, readable after repeated washing and sterilization.
Item C27. An embodiment may support offline or low-connectivity deposit workflows using printed redemption tokens or locally cached scan batches that synchronize later, preserving refund accountability without continuous network access.
Item C28. An embodiment may enable mobile-app-mediated home pickup or peer-to-peer handoff flows in which a customer scan and geotag confirms custody transfer while preserving deposit and audit integrity.
Item C29. An embodiment may provide license or subscription enforcement through cryptographic tokens linked to container identifiers and machine telemetry so that usage tiers, feature entitlements, or geographic policies are verifiable externally.
Item C30. An embodiment may integrate materials or coatings having antimicrobial or easy-clean properties, including silver-ion additives, photocatalytic layers, or low-surface-energy finishes that reduce biofilm formation without impairing food safety.
Item C31. An embodiment may use shelf and pallet adapter rails, rings, or frames that bridge across tray sizes or shapes, ensuring stable stacking and alignment with existing retail hardware while preserving proportional nesting.
Item C32. An embodiment may include cross-family nesting adapters permitting intermixing of different shape families or generation variants such that smaller trays of one family nest within larger trays of another while maintaining stack stability and seal clearances.
Item C33. An embodiment may integrate or supply attachable stabilizers including rails, rings, frames, spacers, magnetic couplers, or friction-fit collars that constrain two or more smaller trays within the boundary envelope of a larger tray so that the assembly is stable for stocking, transport, or display even where interstitial void areas remain.
Item C34. An embodiment may form keyed perimeter geometries on larger trays that receive and laterally locate rims or lips of multiple smaller trays placed side by side so that the combined assembly behaves as a single unit for handling, checkout scanning, or return intake while preserving detachable lid clearances and seal integrity.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
10. A modular reusable container system comprising:
   a) a set of trays in at least two sizes, each tray having a footprint and sidewalls configured for nesting when empty;
   b) wherein for at least one successive size, m trays of a given size are configured to occupy, side by side, substantially the footprint of the next larger size, where m is an integer greater than or equal to two, so that proportional sizing extends across one or more tiers.
11. The system of item 1, wherein m equals two and two trays of a given size fit within the footprint of the next larger size within a dimensional tolerance that maintains retail shelf and pallet compatibility.
12. The system of item 1, wherein the sidewalls are slanted to facilitate nesting when empty and to permit stable stacking when trays are filled and sealed.
13. The system of item 1, wherein the trays are fabricated from aluminum, high-strength plastic, or combinations thereof.
14. The system of item 1, further comprising lids corresponding to the trays, each tray including a peripheral mating feature and each lid including an elastomeric rim configured to compress against the mating feature to form an airtight yet detachable seal.
15. The system of item 5, wherein the trays and lids are compatible with refrigeration, freezing, or oven use according to the selected material.
16. The system of item 5, wherein the sealing interface is configured for repeated opening and closing without substantial loss of sealing performance.
17. The system of item 1, wherein the tray dimensions and stackability are standardized to align with retail shelf and pallet dimensions for transport and display.
18. The system of item 1, wherein towers of smaller trays are configured to be received within a larger tray to minimize volume during storage and transport.
12. A reusable food container comprising:
   a) a tray having an exterior surface; and
   b) a machine-readable identifier permanently integrated with the container or lid, the identifier selected from a layered QR code, a laser-etched barcode, or an RFID tag, the identifier being scannable by standard point-of-sale or logistics scanners after repeated washing or sterilization and encoding at least one of tray size, material composition, or manufacturing batch.
13. The container of item 10, used in combination with a deposit-tracking service configured to store a refundable amount linked to the identifier upon issuance and to trigger a refund upon scanning the identifier at a designated return point.
16. A method of deposit tracking for reusable food containers, the method comprising:
   a) scanning a machine-readable identifier associated with a container at issuance to a customer;
   b) recording a refundable deposit linked to the identifier and the customer's transaction;
   c) scanning the identifier upon container return; and
   d) automatically refunding the deposit to the customer's account or original payment method.
17. The method of item 12, wherein each scan generates a transaction record serialized in a text-based format including a container identifier, a size code, a material designation, a deposit amount, an event type, a timestamp, a site identifier, and a product identifier.
18. The method of item 12, wherein scanning is performed by standard point-of-sale or logistics equipment and transaction records update an inventory management system over a network.
19. The method of item 12, further comprising monitoring container circulation volumes, lifespans, reuse cycles, and material composition using data linked to the identifier.
20. A cleaning and stacking machine for reusable food containers comprising:
   a) an input compartment to receive soiled trays;
   b) a cleaning subsystem configured to execute stages including at least pre-rinsing,
application of heated water with food-safe detergent, ultrasonic agitation or pressurized spray cleaning, and a high-temperature rinse or steam sanitization;
   c) a drying subsystem configured to remove moisture using heated airflow, condensation extraction, or centrifugal action; and
   d) a stacking mechanism configured to align and nest trays after drying.
21. The machine of item 16, further comprising a sensor system configured to detect tray size by measuring physical dimensions or by reading the machine-readable identifier, and a communication interface configured to report intake events to a deposit-tracking or inventory system.
22. The machine of item 16, configured for residential installation comparable to a compact dishwasher or for deployment in a community return center processing higher volumes.
23. The machine of item 16, wherein the stacking mechanism nests smaller trays within larger trays to minimize storage volume for transport or pickup.
21. A non-transitory computer-readable medium storing instructions that, when executed by one or more processors of a retail or logistics system, cause the system to perform the method of item 12 and to emit audit records that externally evidence deposit assessment and refund events without requiring inspection of internal server implementations.

### Embodiment AME: External Vision Processing for Lightweightness and Reduced Power Consumption

Related: https://www.delfly.nl/publications/Pegasus_2014.pdf (5.2 grams stereo vision system!)

Scope note: The scope of this invention is defined solely by the claims. All figures, figure references, element numbers, examples, ranges, and specific values are illustrative of example embodiments and do not limit the claims. Features described in connection with any embodiment may be combined with features of any other embodiment unless expressly stated otherwise. Steps of any described method or flow may be performed in alternative orders, concurrently, or with steps added or omitted, and signal, control, or data formats may vary across implementations.

### Background

Small aerial platforms are mass- and power-constrained, and integration of compute-heavy perception subsystems on-vehicle raises thermal load, reduces endurance, and increases maintenance complexity.

Conventional approaches embed dual cameras and GPUs onboard to obtain depth and mapping, or else add heavy positioning hardware such as RTK-GPS. These choices negatively impact flight time and reliability on FPV-class and micro-UAV airframes. There is a need for architectures that deliver stereo depth, SLAM, guidance, and precise targeting while shifting weight and power off the vehicle, and for optical configurations that minimize sensor duplication without sacrificing range accuracy. This Background is provided to place the invention in context and is not an admission that any referenced system or publication is prior art against any claim hereof.

Systems and methods are described that offload computationally intensive vision processing from a drone to external compute while preserving or improving perception and control performance. In some embodiments two lightweight FPV-class cameras with onboard digital transmitters form a stereo pair whose feeds are received and processed on a ground computer for depth, SLAM, and guidance, with low-latency commands uplinked to the airframe. In other embodiments, a single camera with a first-surface catadioptric mirror provides a direct and a reflected view that enable stereo depth without duplicating sensors; a controller determines range and aligns a co-mounted laser or tool for precise actuation. Additional embodiments include a ground “head-like” stereo pan observer that tracks the drone and fuses its estimates with onboard telemetry, and a modular airframe architecture that concentrates durable electronics in a reusable core while treating propulsion as a consumable frame. Software orchestration may employ Model Context Protocol with compact JSON messages for tool registration, telemetry, licensing, and external observability. The disclosed approaches reduce airborne mass and power, extend endurance, and provide externally verifiable behaviors suitable for enforcement and monetization.

### Gentle Introduction

Small drones are highly sensitive to added weight and heat. Placing heavy processors, heatsinks, and multiple cameras on the airframe shortens flight time, stresses batteries and motors, and complicates maintenance. The core idea here is to keep the drone light and cool by moving as much “thinking” as possible off the vehicle. The drone mainly captures and transmits compact visual signals, while a ground computer performs stereo depth, mapping, and decision-making and then sends back simple control commands. Where two onboard cameras would normally be required for stereo, a lightweight optical trick can be used: a single camera plus a small mirror creates a second virtual viewpoint, enabling depth from one sensor. In the field, a ground station can even watch the drone with its own stereo “head,” providing precise external pose estimates that the drone can fuse with its IMU, so it behaves like it carries high-end positioning without actually lifting it. This architecture reduces weight, heat, and cost, and makes endurance and reliability better. It also makes the system easier to upgrade over time: ground software can change quickly, while the airborne payload stays simple. To support real deployments, the system defines clear, externally observable inputs and outputs, interoperates with multiple radio links and mapping tools, and includes optional licensing features that tie technical capability to subscriptions for predictable costs and enforceable damages. The same lightweight perception and control can guide a laser, a micro-sprayer, or a tiny robotic arm for selective interventions such as pest control, inspection, or education.

### Summary

In one aspect, a drone carries low-mass imaging hardware that transmits visual data to a remote computer which performs stereo, SLAM, fusion, and control, returning low-latency commands over standard links. In another aspect, a catadioptric arrangement allows a single camera to yield stereo depth and to align a co-mounted tool such as a laser using disparity-derived range while the vehicle adjusts yaw and altitude. In further aspects, a ground stereo “head” externally tracks the drone to emulate heavy onboard positioning, and a modular core-and-frame architecture separates durable avionics from consumable propulsion. Software orchestration may use Model Context Protocol with compact JSON to integrate perception, control, licensing, and auditability.

### Definitions and Interpretation

Unless expressly stated otherwise, the terms used herein have the following meanings for purposes of claim construction and to avoid indefiniteness. Comprising, including, having, and containing are open-ended and mean “including but not limited to.” Or is inclusive and means “and/or” unless the context clearly dictates otherwise. At least one of A, B, and C means any combination of one or more of A, B, and C. Substantially, about, and approximately allow for normal manufacturing tolerances and measurement uncertainty and may encompass variations of up to ten percent or within instrument precision as would be understood by a skilled person. Configured to, operable to, and programmed to denote structural or programming features that cause the recited functionality, and are not intended to invoke 35 U.S.C. § 112(f) absent explicit use of the phrase “means for.” Controller encompasses one or more processors, microcontrollers, FPGAs, DSPs, state machines, or combinations thereof executing code or implementing logic to perform the recited functions. Module denotes hardware, firmware, software, or combinations thereof. Non-transitory computer-readable medium excludes propagating signals per se. Communication link and pathway include direct and indirect, wired, wireless, optical, or hybrid connections, and intermediate devices may be present. Catadioptric element includes, without limitation, first-surface mirrors, coated second-surface mirrors, prisms, beam splitters, and multi-mirror assemblies. Pan mechanism includes any actuator or bearing system that imparts yaw-like rotation to a stereo bar or head-like assembly. Terms describing relative position such as left, right, above, beneath, or to one side are used for convenience of description and do not require absolute orientation. No term should be construed as essential to the invention unless expressly recited as such in an independent claim. Modal verbs such as may, can, could, might, and optionally indicate permissive, alternative, or optional features and are not limiting, and examples are illustrative to aid understanding rather than to restrict scope.

### Description of the Drawings

FIG. 57 is a schematic depiction of one possible embodiment

### Detailed Description

### Anchor for Embodiments and Core Relationships:

For the dual-camera stereo offload embodiment, a left camera and a right camera are rigidly mounted on the drone with a defined baseline, each paired with its own lightweight digital video transmitter and antenna. Both transmitters send their respective video streams to a ground receiver coupled to a remote computer. The remote computer time-aligns the streams, rectifies them using a calibration associated with the mounting geometry, and computes depth and SLAM outputs. A guidance and targeting controller running on the remote computer produces control commands that are uplinked over a low-latency telemetry link to a flight controller on the drone, which actuates motors and any attached tools. Optional UWB anchors provide absolute position observations that the remote computer fuses with inertial and visual odometry before emitting control outputs.

For the single-camera catadioptric targeting embodiment, the elements enumerated in the Catadioptric embodiment section (items 1 through 11) define the optical stack and its actuation. A single camera simultaneously captures a direct field of view and a reflected field of view presented by a first-surface catadioptric mirror placed to one side of the camera. The controller compares the position of a target in the direct and reflected views to infer range via disparity, commands yaw to keep the target near the vertical midline, commands altitude to bring the target into the laser's focal plane, and aligns the laser either by pitching the entire camera-plus-laser unit or by pitching an auxiliary mirror in front of both the camera fields and the laser beam. Safety interlocks, license checks, and signatures are verified before any laser actuation. Optional UWB observations allow each actuation to be registered in global coordinates.

For the external ground observer, two ground-based cameras are mounted on a common horizontal bar that pans like a head to keep the drone centered in both viewports. The ground stereo pair is calibrated along with the pan encoder, and the resulting 6-DoF pose estimates are fused with the drone's onboard IMU and barometer on the remote computer. The fused pose is fed to the same guidance and targeting controller that drives the drone, allowing the airborne payload to remain minimal while still achieving precise control and navigation. Alternatively, 2 or 1 cameras may be mounted on a mobile platform, such as a quadruped robots, and said cameras be used to continuously estimated the 3d position of the UAV by estimating the vector from the mobile platform to the UAV and estimating the location of the mobile platform in its surroundings.

For the drone-side fast path, a microcontroller coupled to a compact camera executes a low-latency pipeline that yields a centroid or bounding box for immediate actuation of a fast steering mirror or a servo. The remote computer may update parameters on the microcontroller in real time, including ROI windows, thresholds, expected motion constraints, or a quantized micro-model for recognition, so that local tracking remains responsive while heavier classification, mapping, and decision logic run offboard.

For telemetry, orchestration, and interoperability, one or more radio links carry uplink and downlink traffic, including 2.4 GHz RC, 433/915 MHz long-range telemetry, or Wi-Fi-based channels. The remote computer may orchestrate stereo, SLAM, fusion, and control tools using Model Context Protocol so that tool registration, invocation, and data exchange occur through compact JSON messages. A licensing service issues cryptographic feature tokens bound to device credentials; the remote computer meters usage and emits signed audit logs, and the drone verifies signatures and feature flags before executing privileged actions. Externally observable overlays embed session identifiers and counters so recorded video can be correlated with signed logs.

For the modular airframe, a reusable core houses the flight controller, avionics, cameras, optics, targeting modules, radios, ESCs, and a battery bay, while a detachable frame includes arms, motors, and propellers that can be swapped as wear items without disturbing calibrations in the core. Power system choices, including lithium-ion or sodium-ion cells, affect endurance and mass but do not alter the relationships among sensing, offboard computation, control, and actuation described above. A stereo vision system for drones can be built by mounting two lightweight HDZero nano cameras, each paired with its own compact Whoop Lite video transmitter and antenna, bringing the combined payload to under 30 grams. These cameras capture slightly offset perspectives of the environment, and their video signals are wirelessly transmitted in real time to a ground-based receiver connected to a remote computer. Once both camera feeds arrive, the computer synchronizes them to form a stereo pair and applies stereo vision algorithms to extract depth information, mapping the 3D structure of the surroundings. With depth perception in place, SLAM (Simultaneous Localization and Mapping) algorithms can fuse this data to track the drone's position, build a live map of obstacles, and identify dynamic targets such as insects. From this processed information, the control system generates actionable commands: adjusting steering inputs to move the drone left or right, guiding altitude corrections, deploying a robotic arm for precision interaction, or activating a laser targeting module to neutralize pests.

Because this system depends on a live video pipeline, latency becomes an important factor. HDZero's digital feed provides an end-to-end latency of roughly 20-25 ms per camera, with an additional 5-15 ms introduced by capture devices and computer-side buffering. On the processing side, GPU-accelerated stereo vision and SLAM can operate at 10-20 ms per frame for compact neural networks or optimized algorithms. Finally, once decisions are made, commands must be transmitted back to the drone. This can be done via standard telemetry modules (e.g. 2.4 GHz RC links, 433/915 MHz long-range telemetry radios, or Wi-Fi-based data channels). These typically add 10-30 ms of uplink latency, depending on link quality and packet size. Taken together, the full loop latency-from image capture, transmission, processing, decision-making, to actuation-lands in the range of 50-80 ms under good conditions. This means the drone effectively reacts within about one-twentieth of a second, fast enough for stable navigation and precise actuation such as lowering an arm or firing a laser at a moving target, provided algorithms anticipate small movements between frames.

On the drone side, an ESP32-CAM or similar module, like openmv etc, can run a very lean tracking pipeline that emphasizes speed over sophistication. Instead of processing full frames, the camera can downscale to a coarse resolution such as 160×120 or 320×240 pixels, which greatly reduces both memory load and latency. Each frame is then pushed through a handful of lightweight operations-simple grayscale conversion, temporal differencing to highlight motion, and quick morphological filters to clean up noise-before extracting a target centroid or bounding box. This local loop can be tuned in real time by parameters supplied from the remote computer: region-of-interest masks, thresholds on size or aspect ratio, expected motion direction, or even a small quantized micro-model uploaded for recognizing a specific beetle. By keeping computation strictly integer-based and tightly focused on just one or two candidate regions, the ESP32 can update its estimate at kilohertz rates for FSM mirror control or hundreds of hertz for servos, allowing it to stabilize aim with only a few milliseconds of delay. While this “fast path” is intentionally simple, it provides sticky, low-latency tracking and frees the heavier remote algorithms to focus on higher-order tasks like classification, prioritization, and map-based navigation.

### Examples

The following concrete examples illustrate how embodiments can operate end to end. Example 1 (dual-camera stereo with remote compute) may proceed by mounting two HDZero nano cameras on a lightweight bracket with a baseline of approximately 60 to 90 millimetres and connecting each to a Whoop Lite transmitter and antenna. The drone powers the transmitters; a ground receiver forwards both digital video streams to a remote computer that time-aligns frames by nearest timestamp and rectifies the pair using precomputed calibration. The depth map derived from the rectified pair is fused with inertial data and optional UWB to estimate the drone state, and a controller computes steering or tool actuation commands that are uplinked on a low-latency telemetry link. An example stereo frame descriptor emitted by the remote computer could be represented as {“type”:“stereo_frame”, “left_ts”:1724023456.125, “right_ts”:1724023456.125, “calib id”:“CAL_2025_08 19_A”, “rectified”:“yes”, “roi”:“128,96,256,192”, “uav_pose”:{“x”:1.23, “y”:-0.45, “z”:2.8, “yaw_deg “:17.5}, “disparity_summary”:{“min”:2, “max”:48, “mean”:14.7}}which the controller may consume to plan navigation or targeting.

Example 2 (catadioptric single-camera targeting) may proceed by mounting a first-surface mirror to one side of a single FPV camera so that the sensor simultaneously captures a direct view and a laterally mirrored view of the same scene. A checkerboard is recorded to estimate intrinsics and the virtual extrinsic transform induced by the mirror; a rectification mapping is computed so that corresponding epipolar lines are horizontal. During operation, the controller tracks a target centroid in the direct and reflected views, computes range from disparity along common scan lines, yaws the drone to keep the target near the vertical midline, adjusts altitude until the computed range matches the laser focal distance, and then either pitches the optical unit or actuates an auxiliary mirror to co-align camera and laser boresights. A command record suitable for audit and control could be {“type”:“catadioptric_measurement”, “direct_px”:“212,118”, “reflected_px”:“84,118”, “range m”:0.41,” laser_ready”:true, “nonce”:“7f9alb”, “sig”:“MEUCIQCn . . . ”}followed by a laser-fire command {“type”:“actuate”, “device”:“laser”, “pulse_ms”:12, “safety_window_ms”:50, “session”:“S_2025_08_19_01”, “nonce”:“7f9alc”, “sig”:“MGYCMQC3 . . . ”}which is transmitted to the drone where signatures may be verified before execution.

Example 3 (external head-like ground observer with fusion) may proceed by placing two ground cameras on a pan mechanism at mid-field, calibrating the stereo pair and the pan encoder, and enabling auto-tracking so the drone remains centered in both views. The ground station produces a filtered 6-DoF pose estimate at video rate that is fused with the drone's onboard IMU and barometer.

The fused estimate drives both guidance and targeting decisions, allowing the airborne payload to remain very light. An example externally observed pose record can be {“type”:“external_obs”, “frame_ts”:1724023456.250, “position_m”:{“x”:12.4, “y”:5.7, “z”:3.2}, “orientat ion_rpy_deg”:{“roll”:-2.1, “pitch”:1.3, “yaw”:47.8}, “cov”:“0.02,0.02,0.05”, “source”:“ground_stereo_pa n”}which may be combined with onboard telemetry for high-confidence navigation. In software-oriented deployments, the remote computer may orchestrate these components using Model Context Protocol so tools for stereo depth, SLAM, UWB anchors, licensing, and telemetry are registered and invoked consistently. A representative session bootstrap message could be {“mcp”:“1.0”, “register tools”:[“stereo_depth”, “slam”, “uwb_anchor_client”, “license_service”, “rc_link ”], “session_id”:“MCP_S_1724023”, “policy”:“low_latency”} and subsequent tool calls may exchange compact JSON messages like {“tool”:“rc_link”, “cmd”:“set_roi”, “args”:{“x”:128, “y”:96, “w”:64, “h”:64}, “nonce”:“ab3291”, “sig”:“M COCFQC . . . ”} to update the drone-side fast path in real time.

### Enablement:

A skilled person could build and deploy multiple embodiments by following these steps. For the dual-camera offload, mount two HDZero nano cameras on a rigid bracket with a baseline between 60 and 90 millimetres, connect each to a Whoop Lite transmitter and antenna, and pair them with a ground receiver attached to a GPU-capable computer. Calibrate intrinsics and stereo extrinsics using a checkerboard, store a calibration identifier, and implement a capture thread that time-aligns frames by timestamp before rectification. Implement stereo depth via an efficient block-matching or neural approach, fuse with inertial and optional UWB observations, and close the loop by generating control outputs to a low-latency RC or telemetry link. For the catadioptric single-camera targeting, mount a first-surface mirror to one side of an FPV camera so both direct and reflected views appear simultaneously, acquire checkerboard sequences that span both subviews, solve for intrinsics and the virtual extrinsic induced by the mirror, horizontally flip the reflected subview, and rectify both subviews to common epipolar lines. Implement a controller that tracks target centroids in both subviews, computes disparity to obtain range, commands yaw to maintain vertical midline alignment, adjusts altitude until range matches the laser focal distance, and aligns boresights by pitching either the entire optical unit or an auxiliary mirror before tool actuation. For the drone-side fast path, deploy an ESP32-CAM or OpenMV module configured to downscale frames and run integer grayscale, temporal differencing, and morphology to extract a centroid at hundreds of hertz to kilohertz, accepting parameter updates over a UART or Wi-Fi link. For orchestration and interoperability, register tools using Model Context Protocol and exchange compact JSON messages such as {“mcp”:“1.0”, “register tools”:[“stereo depth”, “slam”, “uwb_anchor_client”, “license_service”, “rc link “], “session id”:“S1”} and {“tool”:“rc_link”, “cmd”:“set_roi”, “args”:{“x”:128, “y”:96, “w”:64, “h”:64}, “nonce”:“nI”, “sig”:” . . . ”} that configure telemetry, licensing, and drone-side regions of interest. These steps enable reproducible construction without undue experimentation.

For prism, beam-splitter, and second-surface mirror variants, the same calibration and control stack may be applied with the following practical modifications so the claimed genus is enabled across its full scope. A non-polarizing 50/50 cube beam splitter or pellicle may be positioned so that two subviews occupy laterally separated regions of the sensor; a slight tilt of 1-3 degrees may be introduced to direct stray reflections out of the region of interest, and checkerboard captures spanning both subviews may be used to solve for intrinsics and the relative pose of the virtual cameras before lateral mirroring and rectification. For a coated second-surface mirror, the front glass surface may receive a broadband anti-reflection coating while the rear reflective surface may employ a high-reflectivity metal or dielectric stack; a small wedge angle of approximately 0.5-1.0 degree or an equivalent plate tilt of 1-3 degrees may be used to displace front-surface ghosts outside the analysis window. The reflected subview may be horizontally flipped and both subviews rectified as above. A four-mirror arrangement may split the field of view into left and right halves with two narrow first-surface mirrors and then reimage both halves forward with two steering mirrors such that overlapping forward views are formed on the sensor; the resulting pair may be calibrated and rectified as two virtual cameras with a known baseline. These constructions use commercially available optics, require only routine alignment with a calibration target, and integrate directly with the disparity, fusion, safety, and control logic described elsewhere herein.

Best Mode (without Limiting Scope):

Without limiting any claim, a presently preferred implementation mounts two HDZero nano cameras on a 60-90 millimetre baseline and couples each to a Whoop Lite digital transmitter, with reception by an HDZero ground unit feeding a CUDA-capable GPU such as an NVIDIA Jetson-class or desktop RTX device. Stereo depth is computed using semi-global matching or an optimized neural disparity network operating at 30-60 frames per second with 10-20 milliseconds processing latency. For the single-camera catadioptric embodiment, a first-surface mirror approximately 15-25 millimetres wide is placed to one side of a lightweight FPV camera so that direct and reflected subviews share common horizontal scan lines on a top-to-bottom rolling shutter; range and targeting are computed after lateral mirroring and rectification, and a micro-servo pitches either the combined camera-laser unit or a small auxiliary mirror to co-align boresights. A working distance near 400 millimetres is used, with a narrow 850-nanometre bandpass and linear polarization on the camera to enhance vegetation contrast and reduce glare. The drone-side fast path uses an ESP32-CAM at 160×120 or 320×240 pixels with integer grayscale, temporal differencing, morphology, and centroid extraction, updating a fast steering mirror at kilohertz rates. Telemetry and control are transported over 2.4 GHz RC and 5 GHz Wi-Fi with compact JSON commands that include per-command nonces and Ed25519 signatures. Licensing tokens are feature flags issued against device keys, and append-only, hash-chained audit logs are signed with the same keys to correlate overlays and actuation events.

### Technical Effects

Shifting perception compute to the ground reduces onboard mass and thermal load, increasing endurance and reducing battery stress, while enabling faster iteration of algorithms. The catadioptric single-camera approach yields stereo depth without duplicating sensors, reducing weight and cost, and providing a compact baseline and robust timing on rolling shutters that align scanlines across direct and reflected views. The head-like ground observer provides precise 6-DoF external pose that, when fused with onboard IMU, emulates heavy positioning hardware without the airborne penalty. The modular core-and-frame airframe lowers maintenance time and cost by turning propulsion elements into consumables without disturbing calibrated optics and radios. The MCP-based orchestration and signed telemetry deliver externally verifiable behaviors and license gating, supporting monetization and evidentiary needs.

### Current State of Technique:

At the time of writing (19 Aug. 2025), a camera with transmitter with antenna can be bought in an integrated module weighing 4.25 grams. So this allows stereo vision for something like 10 grams. For course also the laser aligned camera could be one of said transmitting cameras, by keeping the pixel count low, low latencies should be possible.

A 8 channel PPM receiver for under 2 grams.

This means a robotic arm, like US20250162711A1 ((The entirety of US20250162711A1 is incorporated herein by reference), a cable actuated lightweight robotic arm, can be built with stereo vision and remote AI agency for something like 50 grams . . . putting a tiny dill on the arm as an end effector allows it to do pest control. Or combined with PCT/BG2025/050006 (The entirety of PCT/BG2025/050006 is incorporated herein by reference).

Alternatively one one camera is used and monocular depth using AI vision techniques is used, or a prims, or 4 mirror system is used to first split the FOV of the camera in two, so that the left side of the camera is watching to the left and the right side is watching to the right, and then to more mirrors to direct the two FOVs forward and overlapping at some depth, releasing stereo vision.

### External Observation and Virtual Heavy Payload Emulation:

In addition to its onboard vision system, the drone may be tracked from outside by a pair of external ground-based cameras that observe its motion in real time. These cameras can be mounted on tripods or poles around the field and may optionally incorporate zoom optics and auto-tracking capability to keep the drone centered in their viewport. By continuously following the drone's position and orientation, they generate a precise external trajectory dataset that can be fused with the drone's own telemetry. The central control computer, which already integrates stereo feeds and insect-tracking logic, can also merge these external camera measurements with onboard data to achieve navigation performance comparable to carrying a heavy RTK-GPS module or a high-power onboard processor. In effect, the drone behaves as though it has centimeter-level positioning and high-end computing hardware on board, but actually offloads those tasks to the ground. This architecture removes the need for bulky electronics, cooling, and power-hungry processors in the airframe, thereby reducing flight weight and extending airtime. Since battery depreciation is strongly linked to energy draw per cycle, lowering airborne mass directly reduces the most expensive wear component in repeated agricultural flights. Furthermore, with less overall thrust demand, the drone can be equipped with larger propellers running at lower RPM, which reduces bearing stress and wear in the motors. The combination of external camera observation+ground-based computation thus enables precise control and intelligent behaviors while preserving lightweight, long-endurance drone operation.

### Head-Like External Tracking System:

To provide continuous observation of the drone from the ground, the two external tracking cameras can be mounted side by side on a horizontal bar, forming a stereo pair much like human eyes. This bar is in turn fixed to a servo-driven pan mechanism, allowing the entire structure to rotate left and right in a head-like fashion. Placing this system at the center of a round or semi-circular field gives the cameras a wide vantage point from which to follow the drone as it moves about. By actively panning the “head” so that the drone remains centered in both camera viewports, the system minimizes occlusion, maintains stereo overlap, and ensures continuous high-quality tracking data. This configuration effectively gives the ground station a pair of rotating eyes, with adjustable zoom if required, that can provide real-time position updates and visual confirmation of drone behavior. When fused with the drone's onboard telemetry, this external head-like observer allows the central computer to maintain precise situational awareness and positioning, all while keeping the airborne payload light and efficient.

A practical way to handle motor and bearing wear in an agricultural drone is to design the airframe around a modular core-and-frame architecture, with the ESCs included as part of the core. In this approach, the drone's central pod—or core-houses not only the flight controller, avionics, cameras, optics, targeting modules, radios, and battery bay, but also the ESCs, which are more durable and benefit from staying permanently paired with the controller. The detachable frame then consists only of the lightweight arms, motors, and propellers-the true high-wear components. When bearings or motors degrade after extended use, the farmer does not need to service small parts in the field. Instead, the frame can be swapped out in minutes, while the intact core with its expensive electronics and ESCs simply drops into place. This separation keeps replacement frames cheaper, reduces downtime, and ensures that sensitive hardware remains protected and reused, while the propulsion elements are treated as consumables. By making the ESCs part of the core, the design simplifies calibration, protects the more valuable electronics, and further streamlines the maintenance cycle for continuous agricultural deployment.

In April 2025, CATL announced its new “Naxtra” sodium-ion battery, with mass production scheduled to begin in December 2025, marking a significant milestone in the commercial rollout of sodium technology. The cells deliver an energy density of roughly 175 Wh/kg, lower than today's premium lithium-ion packs but sufficient for many mobility and storage applications, especially given their other advantages. They can accept fast charging at up to 5 C, enabling a full charge in minutes, and demonstrate an exceptional cycle life of 10,000+cycles, far surpassing the 500-1,000 cycles typical of conventional lithium-ion and lithium-polymer chemistries. Another major strength is their robust cold-weather performance, a traditional weakness of lithium batteries, which often see sharp capacity drops in freezing conditions. When stacked against lithium, sodium-ion sacrifices some energy density but compensates with longer service life, safer thermal behavior, better low-temperature reliability, and lower cost thanks to abundant raw materials. This positions Naxtra as a compelling alternative where durability, economics, and safety matter more than squeezing out maximum watt-hours per kilogram.

### External Observability:

The system defines externally visible inputs and outputs that may be recorded and correlated to signed audit logs. Examples include telemetry packets containing per-command nonces and signatures, overlays embedding session identifiers and monotonic counters in video frames, and discrete actuation events such as laser pulses with timestamps and coordinates derived from fused pose. These observables allow a third party to verify behavior without internal inspection by matching recorded overlays and measured outputs to signed control logs and metering records. To facilitate evidentiary use, a validation protocol may be executed in which a known target sequence is commanded, the corresponding signed control packets and overlays are recorded alongside independent time-synchronized measurements of outputs, and hashes of all records are anchored to an immutable log; infringement can then be shown by correlating the external behaviors and overlays to the signed command stream without access to internal code. A standard operating procedure may specify timebase source, overlay fields, nonce sequencing, packet capture parameters, and hash-chaining of all artifacts so that an independent laboratory can reproduce and attest to the correlation between recorded external behaviors and signed commands.

### Fallback Embodiments

Upon loss of stereo linkage, degraded radio bandwidth, or loss of the external observer, the system may revert to monocular tracking and predictive control while reducing actuation energy and maintaining passive sensing. The drone-side fast path continues to produce centroids or bounding boxes using integer pipelines, while the remote computer lowers compute budgets and preserves audit logging and safety interlocks. If licensing tokens are unavailable, capabilities may degrade gracefully to a safe baseline that supports navigation and passive observation.

### Workaround Resistance

To reduce opportunities for circumvention, the disclosure explicitly contemplates variants in which compute location, transport, human involvement, and packaging may differ while preserving the same externally observable behaviors, command schema, and gating. Remote processing may be collocated with a video receiver, headset, or radio transceiver rather than a conventional PC; links may be intermittent with predictive buffering; and the system may assist a human operator by emitting overlays or haptic cues instead of or in addition to direct actuation, while the same signed logs and overlays remain correlatable. Packaging of processors within camera, transmitter, ESC, or power modules may still be treated as external to the flight controller path and fall within the orchestration and observability framework described herein so that interface substitutions, compute relocation, or operator-in-the-loop control do not avoid compatibility or evidentiary equivalence.

### Catadioptric Embodiment

FIG. 57 show an schematic of one possible embodiment of a Catadioptric embodiment:

Elements of the catadioptric embodiment: 1) Target, 2) Camera, 3) Camera pinhole, 4) catadioptric mirror (preferably first surface), 5) Laser diode, 6) First lens, 7) Second lens, 8) Laser beam, 9) Camera direct FOV, 10) Camera reflected FOV, 11) Optional pitch altering mirror.

The laser and related components are part of an illustrative application of lightweight stereo vision, all other possible applications are also part of the scope of this invention, in particular drones and drones with means to manipulate the world via an end-effector, such as a laser or robotic arm.

In another embodiment, a catadioptric stereo trick is applied, the camera is configured so that via a mirror (catadioptric mirror) it receives a second image of the target. This allows the remote computer that is relieving the images to calculate the 3D position of the target, or the remote computer. If the target is in the correct position in the direct and reflected image, the laser can be fired at the target, as this means the target is at the focal point.

Because a quadcopter, multicopter are quite good in changing yaw and altitude, the following steps can be followed: First adapt yaw so the target lies in front of the drone, second adapt the height so the distance to the drone is correct. When adapting height, the angle between the camera, and the laser module that is fixed attached, and the target changes, hence we can: a) modify the pitch of the camera with laser module (of the whole optical unit with camera), or b) Place a mirror in front of the FOVs and laser path and change the pitch of the mirror (likely via a cable system). The controller, internal or external, then keeps the center of the direct FOV of the direct image aimed at the target.

In one embodiment a catadioptric stereo trick is applied. The system comprises a camera arranged so that, via a catadioptric mirror placed to one side of the lens, the camera simultaneously receives both a direct image of a target and a reflected image of the same target. A remote computer, or an onboard controller, receives these images and calculates the three-dimensional position of the target by comparing the direct and reflected views. When the relative positions of the two views coincide in a way that indicates the target lies at the focal plane of an attached laser, the laser may be fired to deliver energy to the target with precision.

Because the drone continually adjusts its yaw so that the target is kept along the vertical center line of the camera, the catadioptric mirror does not need to provide a wide reflection. A relatively narrow mirror surface is sufficient to create a usable stereo baseline while keeping the optical payload compact. When a rolling shutter sensor is employed, it is advantageous for the scanlines to proceed from top to bottom, so that the direct and reflected images of the target fall on the same horizontal scan lines. This arrangement ensures that both views are captured simultaneously, eliminating temporal skew and improving depth estimation accuracy.

The positioning sequence is facilitated by the maneuverability of a quadcopter or multicopter platform. First, the yaw of the vehicle is adjusted so that the target lies in front of the drone and is centered in the direct field of view. Next, the altitude is adapted so that the calculated distance between the camera and the target corresponds to the focal distance of the laser optics. Because altering altitude changes the angular relationship between the fixed laser module, the camera, and the target, two compensating approaches may be used. In one version the entire optical unit, including the camera and laser, is pitched together. In another version an auxiliary mirror is placed in front of both the camera fields of view and the laser beam, and this mirror is pitched, for example by a cable mechanism, so that all optical paths are steered together without moving the entire payload. In either case the controller maintains the direct image aligned on the target while ensuring that the laser beam converges on the same point once stereo geometry confirms the correct range.

It is preferable to mount the combined camera and laser unit beneath the drone so that both the direct and reflected fields of view are unobstructed by the vehicle structure and can be aimed downward toward vegetation or ground-level targets. A working distance of approximately 400 millimetres has been found appropriate, providing a balance between a compact optical baseline, sufficient disparity for stereo depth calculation, and a safe standoff for focusing the laser waist.

This setup provides a particularly lightweight solution that is well-suited for use on a drone platform. By employing a single FPV camera weighing roughly ten grams together with a narrow first-surface mirror, the system is able to capture both a direct view and a reflected view of the target without duplicating sensors. In contrast to conventional stereo rigs that require two complete cameras, optics, and synchronization wiring, the catadioptric embodiment achieves stereo depth with only a few additional grams of glass and mounting structure. The laser diode, two miniature lenses for collimation and focusing, a small 3D-printed frame, and a micro-servo for pitch adjustment bring the total mass into the range of thirty to forty grams. Such a modest payload is advantageous because every gram carried by a multicopter reduces endurance and stability. A solution that stays well below fifty grams has negligible impact on flight time and handling, making it far easier to integrate onto small drones.

Accurate depth recovery from the composite image requires calibration. This is performed by recording checkerboard patterns that span both the direct and the reflected fields of view, then solving for the intrinsic parameters of the camera and the extrinsic transformation between the direct and virtual view created by the mirror. Once calibrated, the two views are rectified so that corresponding features fall on the same horizontal scanlines, allowing a standard disparity algorithm to yield reliable range. Because the reflected view is mirrored laterally, a horizontal flip is applied during calibration to restore parity.

Several optical refinements improve robustness in the field. Using polarized illumination in combination with a linear polarizer on the camera reduces specular reflections from glossy leaf surfaces, making the edges and veins more distinct for stereo matching. A narrow bandpass filter in the near-infrared can further suppress broadband glare and exploit the natural reflectivity of vegetation. Stopping the camera down to a smaller aperture increases depth of field, ensuring that both the direct and reflected paths are simultaneously in focus despite the slight difference in optical path length introduced by the mirror. Keeping that path length difference small in the mechanical design also minimizes defocus and calibration complexity.

To support georeferencing and coordinated operation, the optical payload may be fitted with a low-power ultra-wideband (UWB) chip. UWB anchors deployed around a field allow the drone to localize its position with decimeter-level accuracy, which can be fused with stereo-derived range to register each laser actuation event in global coordinates. This combination of lightweight catadioptric stereo, precise optical alignment, and UWB positioning yields a compact, energy-efficient targeting module that integrates readily with small aerial vehicles for tasks such as selective insect neutralization or precision inspection.

One embodiment may be described as a drone-mounted optical targeting system comprising a camera configured to receive both a direct image of a target and a reflected image of the same target via a first-surface catadioptric mirror positioned to one side of the camera so as to provide a virtual second viewpoint of the target. A laser module is mounted to the drone and arranged such that an optical axis of the laser module maintains a fixed relationship to an optical axis of the camera. A controller is configured to compare the positions of the target in the direct image and the reflected image in order to determine a three-dimensional position of the target and to activate the laser when the target is located at a focal plane of the laser beam. The drone is further configured to yaw so that the target remains on a vertical center line of the camera, thereby permitting the catadioptric mirror to be of reduced width.

In one embodiment, the camera is a rolling-shutter sensor, and the scanlines proceed from top to bottom so that the direct and reflected images of the target fall on the same horizontal lines. This arrangement ensures that both views of the target are captured at the same instant in time, thereby reducing temporal skew and improving the reliability of the stereo calculation.

In another embodiment, the camera and laser module are mounted beneath the drone to provide an unobstructed downward view toward the vegetation or ground. A working distance of approximately 400 millimetres is selected as appropriate, balancing compactness of the optical system with sufficient stereo baseline for accurate depth calculation and a safe standoff distance for focusing the laser waist.

In a further embodiment, adjustments in altitude, which alter the angular relationship between the optical axes of the camera, the laser, and the target, are compensated either by pitching the entire optical unit that includes the camera and laser together, or by pitching an auxiliary mirror located in front of both the camera fields of view and the laser beam. The auxiliary mirror may be actuated by a lightweight cable mechanism or micro-servo, allowing all optical paths to be steered together without moving the complete payload.

In another refinement, optical improvements are applied to increase robustness in real-world environments. A first-surface mirror is used to prevent ghosting and parallax errors that would otherwise occur with a second-surface mirror. Polarized illumination in combination with a linear polarizer on the camera suppresses specular reflections from glossy leaves, and a narrow bandpass filter in the near-infrared may be added to exploit the strong natural reflectivity of vegetation while rejecting broadband glare. The camera lens may be stopped down to increase depth of field, ensuring that both the direct and reflected optical paths remain in focus despite their slight difference in path length. Keeping the difference between these path lengths small also minimizes defocus and simplifies calibration.

In a further embodiment, the drone-mounted system is augmented with an ultra-wideband (UWB) positioning module. By communicating with fixed anchors deployed around the field, the UWB module provides absolute positioning data that can be fused with stereo-derived range measurements.

This allows each laser actuation event to be registered in global coordinates, enabling mapping, repeat targeting, and integration with larger farm-management systems.

This solution provides a generally lightweight and budget-friendly way to equip a drone with stereo vision and intelligent autonomous behavior. By relying on a single low-mass FPV-class camera together with a narrow first-surface mirror to create a virtual second viewpoint, the system avoids the weight, cost, and synchronization complexity of dual-camera stereo rigs. The additional optical and mechanical elements-a small laser or tool module, two miniature lenses, and a micro-servo or mirror actuator-add only a few tens of grams to the payload, making the approach compatible even with compact multicopters. Because the same stereo geometry and control logic can be applied to many different tasks, the system is not limited to laser targeting; it may be used just as well for guiding a robotic arm, performing micro-spraying with precise standoff distance, or supporting other forms of selective intervention.

The module can also be marketed as a stand-alone add-on, expanding its relevance beyond specific drone applications. One commercial segment is industrial users who require lightweight and precise 3D perception for inspection, manipulation, or treatment tasks. Another equally important segment is the educational market, where students can attach the module to a drone or a drone equipped with a robotic arm and then implement and test their own control algorithms. In such a context, being able to stream the stereo images to a PC or laptop for algorithm development, debugging, and visualization is extremely handy and practical, enabling hands-on learning with real aerial robotics hardware at modest cost.

Embodiments can be described by the following itemized list: 1) A drone-mounted control system in which a camera receives both a direct image of a scene and a reflected image of the same scene via a catadioptric mirror, the reflected image providing a virtual second viewpoint relative to the camera, with images transmitted to and processed by a remote computer that returns control commands; 2) A device in which the remote computer receives the direct and reflected images, optionally calculates a three-dimensional position of an object of interest based on disparity between the two views, and transmits navigational, attitude, orientation, or interaction commands to operate a drone-mounted device including a robotic arm or spraying mechanism; 3) A drone-mounted optical targeting system comprising a camera that receives both a direct image of a target and a reflected image of the same target via a first-surface catadioptric mirror positioned to one side of the camera to provide a virtual second viewpoint of the target, together with a laser module whose optical axis maintains a fixed relationship to the camera optical axis; 4) A controller that compares positions of the target in the direct and reflected images to determine a three-dimensional position of the target, optionally activating the laser when the target lies substantially at a focal plane of the laser beam; 5) A configuration in which the drone yaws to keep the target substantially on a vertical center line of the camera so the catadioptric mirror may be of reduced width, for example less than 40 millimetres; 6) A camera comprising a rolling-shutter image sensor with scanlines proceeding top to bottom so the direct and reflected target images fall on common horizontal scan lines and are captured substantially simultaneously; 7) A mounting arrangement in which the camera and laser are beneath the drone with a working distance less than 3 metres, such as approximately 400 millimetres; 8) Compensation for altitude-induced geometry changes by pitching either the entire optical unit including the camera and laser or an auxiliary mirror positioned in front of both the camera fields of view and the laser beam, the auxiliary mirror actuated by a cable mechanism or micro-servo; 9) Optical refinements including a linear polarizer to reduce specular reflections from vegetation, a narrow near-infrared bandpass filter to increase vegetation contrast, and a stopped-down lens aperture to increase depth of field so both direct and reflected paths remain in focus; 10) Mechanical and optical design in which the difference between optical path lengths of the direct and reflected images is minimized to maintain both within depth of field and to simplify calibration; 11) A positioning subsystem including an ultra-wideband module communicating with field anchors to provide absolute position fused with stereo-derived range so each laser actuation event is registered in global coordinates; 12) A dual-camera stereo embodiment in which two lightweight FPV cameras (e.g., HDZero nano) each with its own digital video transmitter form a stereo pair, streams are received by a ground station, synchronized, rectified, and processed for depth and SLAM, with computed control commands uplinked over low-latency telemetry; 13) A drone-side fast path implemented on a microcontroller (e.g., ESP32-CAM or OpenMV) that downscales frames, computes grayscale, temporal differencing, and morphological filtering to extract a centroid or bounding box, with integer arithmetic and real-time parameter updates such as ROI masks, thresholds, expected motion, or a small quantized recognition micro-model, enabling kilohertz FSM mirror updates or hundreds-of-hertz servo updates; 14) A catadioptric calibration and rectification workflow in which checkerboard images spanning both direct and reflected views are used to solve intrinsics and the virtual extrinsic transform, followed by lateral mirroring of the reflected view and rectification so corresponding features lie on common epipolar lines suitable for disparity computation; 15) An external observation subsystem in which two ground-based cameras on a pan mechanism auto-track the drone, generating video-rate 6-DoF estimates fused with onboard IMU and barometer to emulate high-end onboard positioning and computing while keeping airborne payload mass and power low; 16) A head-like stereo pan unit for the ground observer in which two cameras mounted on a horizontal bar pan together to maintain the drone near the center of both viewports, optionally with zoom optics, minimizing occlusions and preserving stereo overlap; 17) A modular core-and-frame airframe architecture in which the core houses flight controller, avionics, cameras, optics, targeting modules, radios, ESCs, and battery bay, while a detachable frame comprises arms, motors, and propellers as wear components that can be swapped quickly in the field; 18) A telemetry and control stack interoperable across multiple links including 2.4 GHz RC, 433/915 MHz long-range radios, and Wi-Fi-based data channels, with compact command messages including per-command nonces and signatures, and with externally observable behaviors such as actuation timestamps and coordinates; 19) A software orchestration approach using Model Context Protocol in which tools for stereo depth, SLAM, UWB anchor clients, licensing, and RC link are registered and invoked consistently, with compact JSON request/response payloads such as

{“tool”:“rc_link”,“cmd”:“set_roi”,“args”:{“x”:128,“y”:96,“w”:64,“h”:64},“nonce”:“ab3291”,“sig”:“...”
}; 20) A licensing and monetization subsystem issuing cryptographic feature tokens tied to

device-bound credentials that gate stereo resolution, actuation rates, number of targets, and external fusion, with metering of billable events, append-only hash-chained audit logs, optional machine-readable video watermarks, and graceful degradation to a safe baseline upon subscription expiry; 21) Externally observable evidence mechanisms in which session identifiers and monotonic counters are embedded in overlays and control logs so recorded use can be correlated with signed audit trails to substantiate infringement by matching observed behaviors to commanded actions; 22) Alternative depth strategies including monocular depth via learned models, a prism to split the field of view, or a four-mirror arrangement that directs left and right halves of the sensor to overlapping forward views to create an effective stereo baseline using a single camera; 23) Safety features including a laser safety window, prefire readiness checks derived from catadioptric range, and on-drone signature verification prior to executing high-energy actions; 24) Method embodiments corresponding to the above systems including steps of capturing direct and reflected images, rectifying, computing disparity, estimating range, adjusting yaw and altitude, aligning optical axes by pitching a unit or mirror, verifying safety and license constraints, and actuating a tool, where the order may vary or steps may be performed concurrently; 25) Computer-readable media storing instructions that, when executed by a remote or onboard processor, cause performance of any of the method steps described herein, including MCP tool registration, stereo computation, SLAM, fusion with UWB or external observers, control generation, and secure telemetry exchange; 26) Interoperability provisions by which the system may exchange data with multiple map formats, SLAM frameworks, camera standards, and telemetry protocols, with adapters that translate to the compact JSON control schema so interface changes by third parties do not avoid compatibility; 27) Fallback embodiments in which, upon loss of stereo linkage or external observer input, the system reverts to monocular tracking and predictive control, reduces actuation energy, and maintains passive sensing while preserving audit logging and safety constraints; 28) Power system options including lithium-ion or sodium-ion batteries, where lower energy density options are offset by extended cycle life, cold-weather robustness, safety, and cost advantages, without altering the core external-vision offload architecture; 29) Manufacturing and assembly options including 3D-printed mounts for mirrors and optics, first-surface mirrors sized narrowly due to yaw-centering, and low-mass antennas or coax placement to reduce inertial load and preserve calibration stability; 30) Test and verification procedures including checkerboard calibration captures for catadioptric geometry, disparity validation on known-distance targets, latency profiling from capture to actuation, and closed-loop tests that log commanded versus observed positions for external audit; 31) Compute partitioning variants in which perception and control workloads are allocated entirely onboard, entirely offboard, or split across remote and onboard processors, with identical external observables and control schemas so that changing compute location does not avoid the inventive architecture or its behaviors; 32) Sensor modality variants in which stereo or depth perception employs one or more of global-shutter cameras, event cameras, time-of-flight sensors, structured light, radar, or acoustic ranging, optionally combined with catadioptric, prism, beam-splitter, or multi-mirror elements to create multiple viewpoints on a single sensor or across multiple sensors; 33) Tool-agnostic actuation in which the controlled effector may comprise any of a micro-sprayer, mechanical end-effector, ultrasonic or acoustic transducer, UV or visible LED array, dye marker, or laser at eye-safe or non-eye-safe wavelengths, with the same range-estimation, alignment, licensing, and audit mechanisms applied; 34) Transport variants including wired or optical-fiber tethers, Ethernet, or optical serial links in addition to radio, such that substitutions in physical transport or protocol layers do not change the command schema, external observables, or licensing enforcement; 35) Deployment variants in which the remote compute is hosted on a local ground station, a nearby edge node, or a cloud service accessed over public or private networks, optionally within containerized or virtualized environments, while preserving low-latency operation via adaptive quality and rate control; 36) Operator-in-the-loop assistance variants in which the remote computer outputs overlays, haptic cues, or setpoint suggestions consumed by a human pilot while optionally also transmitting direct control commands, with the same signed overlays and audit logs providing externally observable evidence so that manual assistance does not avoid the disclosed behaviors; 37) Collocated remote compute variants in which the “remote computer” is integrated into a video receiver, headset, radio transceiver, or baseband module, with identical orchestration, JSON control schema, and external observables, thereby preventing avoidance by relocating compute into accessory hardware; 38) Intermittent or high-latency link variants in which the remote computer computes predictive control horizons and transmits buffered command sequences with per-command nonces and signatures, maintaining the same external observability and auditability despite variable connectivity; 39) Multi-vehicle coordination variants in which multiple drones share one or more external observers, fuse cross-vehicle estimates, exchange cooperative avoidance or targeting cues, and execute commands under the same schemas and licensing gates, so that distributing functionality across a fleet does not avoid the architecture; 40) Module-embedded compute variants in which perception or control is executed within swappable camera, transmitter, ESC, or power modules distinct from the flight controller, while preserving the same command pathway, signatures, overlays, and licensing semantics, such that packaging changes do not avoid coverage; and 41) Privacy-preserving and compressed telemetry variants in which images or features are transmitted as compressed or encrypted descriptors, patches, or learned embeddings rather than raw frames, while the same MCP orchestration, command schemas, safety interlocks, and external observables remain operative; 42) A drone-mounted control system comprising at least one imaging sensor mounted to a drone and configured to capture scene data, a communication link conveying the scene data to a remote computer that processes the scene data to derive at least one of depth, pose, mapping, or target information and transmits control commands, and a flight controller that actuates the drone in response to the control commands; 43) The device of the preceding item in which the remote computer calculates a three-dimensional position of an object of interest and the control commands include at least one of navigational, attitude, orientation, or interaction commands for operating a drone-mounted device including a robotic arm or spraying mechanism.

### Monetization and Damages Support:

The system may be offered under a subscription-model license in which certain capabilities, such as stereo depth processing resolution, maximum actuation rate of a laser or tool, number of concurrently tracked targets, and access to external ground-observer fusion, are enabled by time-bound cryptographic feature tokens. The remote computer may periodically obtain or refresh tokens from a licensing service using device-bound public-key credentials, and may cache an offline token to permit continued operation during temporary network loss. The drone-side microcontroller may verify signed feature flags embedded in control packets before executing commanded actions that exceed a locally configured baseline capability. The ground software may maintain usage metering for billable events, including per-frame depth compute minutes, number of actuation events with associated energy delivered, geographic area covered, and hours of external camera fusion enabled, and may package metering records into append-only, hash-chained audit logs signed by a device private key. The video overlays generated by the remote computer may optionally embed a faint, machine-readable watermark encoding a session identifier and monotonic counter so that recorded evidence of use can be correlated with the signed audit logs. Control links may include per-command nonces and signatures so logs can later demonstrate that specific externally observable actions, such as laser firing at a timestamp and GPS or UWB coordinate, were initiated by licensed software. The licensing service may provide tiered subscriptions, for example education, prosumer, and enterprise tiers, each tied to technical parameters that affect compute allocation, permitted frame rates, and maximum laser pulse energy, so that damages in case of infringement may be computed in proportion to the enabled technical capability. For customers operating on private networks, the system may be deployed with a self-hosted licensing node that issues local tokens under a master license, preserving the same audit log semantics for evidentiary purposes. In the event that a subscription expires, the feature flags may gracefully degrade to a safe baseline that preserves navigation and passive sensing while disabling premium functions, while retaining the ability to export signed metering records for billing reconciliation. These mechanisms provide concrete, technically enforced usage tracking and feature gating that support calculation of lost licensing revenue and unjust enrichment in the event of unauthorized use.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A drone-mounted control system comprising:
   a) at least one imaging sensor mounted to the drone and configured to capture scene data;
   b) a communication link configured to convey the scene data from the drone to a remote computer;
   c) the remote computer configured to process the scene data to derive at least one of depth, pose, mapping, or target information and to transmit control commands; and
   d) a flight controller configured to actuate the drone in response to the control commands.
2. The system of item 1, wherein the processing by the remote computer comprises calculating a three-dimensional position of an object of interest and wherein the control commands include at least one of navigational commands, attitude commands, orientation commands, or interaction commands for operating a drone-mounted device including a robotic arm or spraying mechanism.
3. A drone-mounted optical targeting system comprising:
   a) a camera configured to receive both a direct image of a target and a reflected image of the same target via a catadioptric element positioned to one side of the camera so as to provide a virtual second viewpoint of the target, the element comprising at least one of a first-surface mirror, a second-surface mirror with coatings to suppress ghosting, a prism, a beam splitter, or a multi-mirror assembly; and
   b) a laser module mounted to the drone and arranged such that an optical axis of the laser module maintains a fixed relationship to an optical axis of the camera.
4. The system of item 3, further comprising a controller configured to compare the positions of the target in the direct image and the reflected image in order to determine a three-dimensional position of the target.
5. The system of item 4, wherein the controller is further configured to activate the laser module when the target is determined to lie substantially at a focal plane of the laser beam.
6. The system of item 3, wherein the drone is configured to yaw such that the target remains substantially on a vertical center line of the camera, thereby permitting the catadioptric mirror to be of reduced width, less than 40 millimetres.
7. The system of item 3, wherein the camera comprises a rolling-shutter image sensor, and wherein the scanlines of the rolling shutter are arranged to proceed from top to bottom such that the direct and reflected images of the target fall on common horizontal scan lines.
8. The system of item 3, wherein the camera and the laser module are mounted beneath the drone, and wherein a working distance is less than 3 metres.
9. The system of item 3, wherein altitude adjustments of the drone are compensated either by pitching the entire optical unit comprising the camera and the laser module, or by pitching an auxiliary mirror positioned in front of both the camera and the laser beam so as to steer all optical paths together.
10. The system of item 3, further comprising optical refinements selected from: a linear polarizer configured to reduce specular reflections from vegetation, a narrow bandpass filter in the near-infrared configured to increase vegetation contrast, and a lens aperture set to increase depth of field so as to accommodate both the direct and reflected optical paths.
11. The system of item 3, wherein the difference between the optical path lengths of the direct image and the reflected image is minimized so as to maintain both images within the depth of field of the camera lens and to simplify calibration.
12. The system of item 3, further comprising an ultra-wideband positioning module configured to communicate with external anchors to determine an absolute position of the drone, wherein the position information is combined with the stereo-derived range to register each laser actuation event in global coordinates.
13. A method comprising:
   a) receiving from a camera both a direct image of a scene and a reflected image of the same scene via a catadioptric element configured to present a second view on a same image sensor;
   b) rectifying the images and computing disparity to estimate a range to a target;
   c) commanding a drone to adjust yaw to center the target and to adjust altitude until the estimated range matches a desired focal distance;
   d) aligning optical axes by pitching an optical unit that includes the camera and a tool or by pitching an auxiliary mirror positioned in front of the camera and the tool;
   e) verifying safety and license constraints; and
   f) actuating the tool.
14. A non-transitory computer-readable medium storing instructions that, when executed by one or more processors of a remote computer or onboard controller, cause performance of the method of item 13, including Model Context Protocol tool registration, stereo computation, fusion with inertial or ultra-wideband measurements, control generation, and secure telemetry exchange.
15. A drone guidance system comprising:
   a) imaging hardware including at least one of:
      (i) two lightweight cameras mounted to a drone to form a stereo pair, each coupled via at least one of a wired, optical, or radio link, optionally including an analog or digital video transmitter;
      (ii) a single camera configured with an optical splitter to provide two subviews forming a stereo pair; or
      (iii) a single camera whose frames are processed to estimate depth or pose via monocular inference;
   b) one or more processing modules located on a remote computer, onboard the drone, or split across remote and onboard processors and configured to time-align and rectify the streams or subviews where applicable, compute depth or pose and Simultaneous Localization and Mapping, and generate control commands; and
   c) a command pathway configured to convey the control commands between the processing module and a flight controller via an onboard bus, a low-latency telemetry link, or a tether.
16. An external observation subsystem comprising:
   a) two ground-based cameras mounted on a pan mechanism and arranged as a stereo pair;
   b) a controller configured to auto-track a drone to maintain the drone centered in both views; and
   c) a fusion module configured to produce a video-rate six-degree-of-freedom pose estimate fused with onboard inertial and barometric data to provide guidance while keeping airborne payload mass and power low.
17. A drone-side tracking module comprising:
   a) a microcontroller coupled to a camera and configured to downscale frames, perform grayscale conversion, temporal differencing, and morphological filtering using integer arithmetic to extract a centroid or bounding box of a target;
   b) accept real-time parameter updates including a region of interest and thresholds from a remote computer; and
   c) drive a fast steering mirror at kilohertz rates or a servo at hundreds of hertz.
18. The system of any of items 3 to 7 or item 15, wherein telemetry and control are interoperable across multiple links including 2.4 GHz RC, 433/915 MHz long-range radios, and Wi-Fi-based data channels, and wherein control packets include per-command nonces and signatures and overlays embed session identifiers and monotonic counters to provide externally observable evidence of commanded actions.
19. The system of any of items 1, 3, 6 to 12, 15, 16, or 18, further configured, upon loss of stereo linkage or external observer input, to revert to monocular tracking and predictive control, reduce actuation energy, and maintain passive sensing and audit logging.
20. The system of any of items 1, 3, 6 to 12, 15, 16, or 18, further comprising a licensing subsystem configured to issue cryptographic feature tokens tied to device-bound credentials that gate stereo resolution, actuation rates, a number of concurrently tracked targets, and external fusion, with metering of billable events recorded into append-only hash-chained audit logs and with graceful degradation to a safe baseline upon subscription expiry.

### Embodiment ANE: Propulsion Frame Cartridge Architecture for Drones

A modular unmanned aerial vehicle is disclosed in which a detachable body enclosure mates with a propulsion frame. Electrical continuity between the flight electronics in the body and the motors on the frame is established by blind-mate connection means, such as spring-loaded contacts, magnetic connectors, or inductive coupling elements. The body is secured to the frame by quick-release mechanisms that may include snap-lock latches, bayonet couplers, magnetic detents, or other lightweight fastening systems, with preferred embodiments permitting tool-free detachment. By integrating all arms, motors, and propellers into a single monocoque propulsion frame, the structure avoids the weight penalties of multiple reinforced joints and distributes loads more efficiently. In use, the propulsion frame-containing the motors and bearings subject to wear-may be quickly replaced in the field while the more costly core electronics remain protected in the detachable body. This cartridge-style workflow reduces downtime, simplifies maintenance, and extends the operational service life of the drone.

### Gentle Introduction

The invention separates a drone into two main parts that may be joined and separated in seconds. One part is a lightweight propulsion frame that carries the arms, motors, and propellers as a single cartridge. The other part is a protected body that holds the expensive electronics such as the flight controller, sensors, radios, and optional battery holder. When the body is placed into the frame, hidden connectors automatically make the electrical paths needed to power and control the motors, and a quick-release mechanism holds the two parts together during flight. Because motors and bearings are the primary wear items, a user may remove the entire propulsion frame and insert a fresh one without disturbing the electronics. This reduces weight compared to designs with many reinforced joints, increases stiffness for better flight performance, and turns maintenance into a predictable field swap similar to changing a battery.

### Examples

Example 1 (pogo pins and snap-lock, field swap). A farmer lands the drone and powers it down. The user presses a release actuator on the snap-lock and lifts the body straight up, leaving the worn propulsion frame on the ground. Three spring-loaded contacts per motor remain on the frame with their lower solder pads connected to the motor wires. The body's underside has gold-plated pads arranged around its rim. The user places a refurbished propulsion frame on a flat surface, aligns the body above it using visible alignment marks or magnetically assisted seating, and lowers the body into position. As the body seats, the spring contacts compress against the pads, and the snap-lock automatically engages beneath the frame with an audible click. The body powers up the drone and verifies both mechanical engagement and electrical continuity. A visible indicator performs a success pattern, and the drone resumes service, with the body continuing the usage log for the new frame identifier.

Example 2 (magnetic contacts with subscription entitlement). A fleet operator uses propulsion frames that include magnetic contacts for both alignment and power conduction. When a body is seated onto a frame, the body reads the frame's unique identifier and checks that an entitlement token is valid for that identifier. The body stores a signed attach event as a single-line JSON entry such as {“event”:“attach”, “frame_id”:“F12345”, “result”:“ok”, “time”:“2025-05-01T12:00:00Z”}. Ifan entitlement is required, the body verifies a time-bounded token and meters usage against a plan. A token and plan information may be represented as {“entitlement_token”:“ABCD.EFGH.IJKL”, “plan”:“pay_per_hour”, “expiry”:“2025-06-01T00:00:00Z ”}. If the token is near expiry, the body presents a warning to the operator and may retrieve a renewal over a wireless link when available, while allowing offline operation using cached tokens until renewal is due. The drone then operates normally, logging flight hours and motor duty against the frame identifier. Upon detach, a corresponding JSON entry is written such as {“event”:“detach”, “frame_id”:“F12345”, “time”:“2025-05-01T14:32:10Z”, “hours_this_session”:2.53}. Model Context Protocol may be used by the body's firmware to expose a stable interface to fleet applications for entitlement checks and maintenance reports, by providing a context describing the attached frame, entitlement state, and recent usage as simple JSON records similar to the examples above.

Example 3 (fallback embodiment with manual plug and threaded fastener). In a budget configuration used for training, the body and frame are joined by a single machine screw and a keyed manual power plug. To perform maintenance, the operator unscrews the fastener, unplugs the connector, and removes the body. The replacement frame is positioned so that the keying prevents misalignment, the plug is inserted until fully seated, and the screw is tightened to a defined torque. The body's firmware detects both the plug's electrical continuity and the screw's presence via a simple microswitch. Safety interlocks inhibit arming until both are confirmed. An external indicator flashes an engagement code, and operation proceeds with the same maintenance logging workflow as in other embodiments.

### Background

Unmanned aerial vehicles (UAVs), and in particular multicopters, are increasingly deployed in agricultural, industrial, and inspection settings. Conventional designs often employ modular arms that attach to a central fuselage by means of reinforced couplers and electrical connectors. While this approach facilitates shipping and replacement of individual arms, it introduces multiple structural joints that add weight, reduce stiffness, and complicate assembly. Furthermore, routine maintenance such as bearing or motor replacement typically requires disassembly of several components or shipment of the entire drone back to a service facility, leading to costly downtime and increased operational burden for the end user.

There is therefore a need for a drone architecture that maintains the serviceability of modular designs while eliminating excess weight and complexity. In particular, agricultural users require systems that can be serviced quickly in the field without specialized tools or training. Bearings and motors wear out predictably under heavy use, and it would be advantageous if these components could be replaced as a single cartridge unit, leaving the expensive flight electronics intact. A system that combines tool-free mechanical detachment with blind-mate electrical interconnection between a propulsion frame and a core electronics body addresses these needs, offering lighter structure, greater stiffness, longer flight endurance, and a predictable, low-cost maintenance workflow.

### Summary

This disclosure provides a cartridge-style drone architecture that separates a propulsion frame, which integrates all arms, motors, and propellers into a monocoque unit, from a detachable body that houses flight electronics. The modules engage via blind-mate electrical interfaces and quick-release securing mechanisms so that worn motor-bearing assemblies may be replaced in seconds without disturbing the protected electronics. Preferred implementations reduce weight by eliminating multiple reinforced arm joints, increase stiffness for improved flight performance, and enable predictive maintenance and optional entitlement enforcement using logged usage associated with a unique frame identifier.

### Detailed Description

This modular approach is particularly advantageous in agricultural and military contexts where motors and bearings are subject to dust, vibration, and long operating hours, leading to inevitable wear. Bearings, in particular, often require periodic replacement to maintain efficiency and flight stability. In conventional drones, this type of service involves either sending the entire vehicle back to the manufacturer or disassembling multiple arm joints and connectors, a process that is both time-consuming and costly. By contrast, with the cartridge-style propulsion frame, the farmer simply removes the worn module and snaps in a new one on-site. The costly central core with flight electronics, sensors, and communication modules remains untouched, while the propulsion cartridge—containing the motors, propellers, and bearings—is returned to a refurbishment service. There, it can be economically overhauled, rebalanced, and recertified for reuse. This workflow dramatically reduces downtime, lowers service costs, and aligns with the predictable maintenance cycles already familiar to farmers, effectively transforming drone upkeep into a quick, field-friendly operation similar to swapping a battery or an ink cartridge.

In one embodiment, instead of relying on four heavy quick-release arm joints, the drone can be built around a single propulsion frame cartridge that integrates all arms, motors, and propellers into one lightweight monocoque unit. The central electronics pod-the core-then simply slides into this frame, locking into place with a single latch and a blind-mate connector that carries power and signals to all motors at once. By eliminating the need for multiple reinforced couplers, the structure becomes both lighter and stiffer, with loads distributed smoothly through the continuous frame rather than concentrated at joints. In operation, the motors and bearings inevitably wear out together, and when that point is reached, the farmer can swap the entire propulsion frame in one quick action while keeping the expensive core electronics intact. This approach reduces weight compared to detachable arm systems, extends airtime, and simplifies maintenance into a predictable cartridge-style workflow that aligns perfectly with agricultural use.

In one embodiment, each arm of the propulsion frame carries three spring-loaded contacts, one for each motor phase, which press directly against corresponding copper pads arranged around the rim of the central body. When the body is lowered into the frame, the spring contacts flex to make firm, low-resistance connections with the gold-plated pads, ensuring reliable current delivery without the need for fragile pins or complex connectors. The body itself is held securely in place by eight permanent magnets-four embedded in the frame and four in the body-arranged so that they align and lock the two modules together with a consistent seating force. This magnetic retention not only makes the assembly tool-free and easy to swap but also ensures that the spring contacts are always pressed evenly against their pads, providing stable electrical paths even under vibration. The result is a clean, cartridge-like system where the entire propulsion frame can be detached and replaced in one motion, while the expensive core electronics remain protected, enabling fast maintenance and extended service life in the field.

### Description of the Drawings

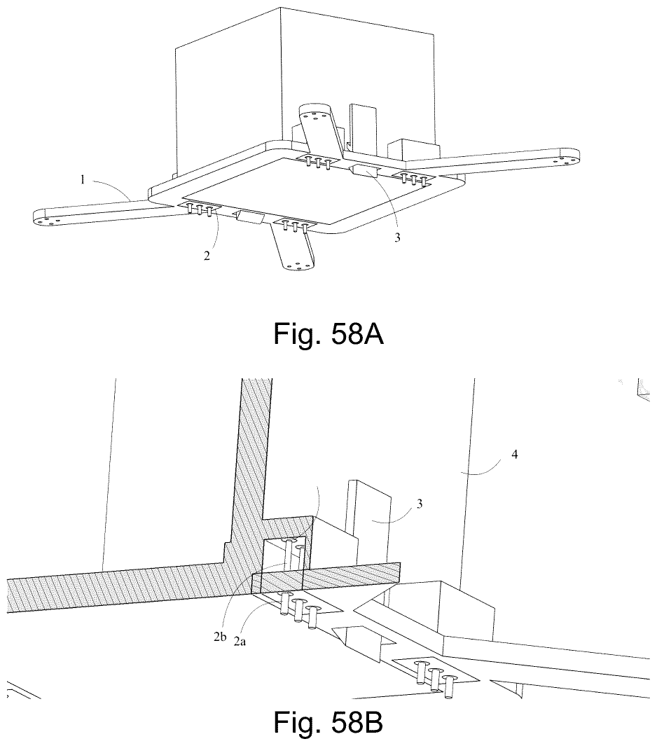

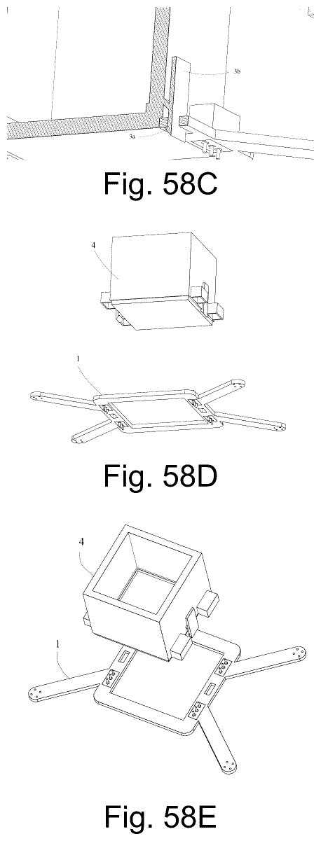

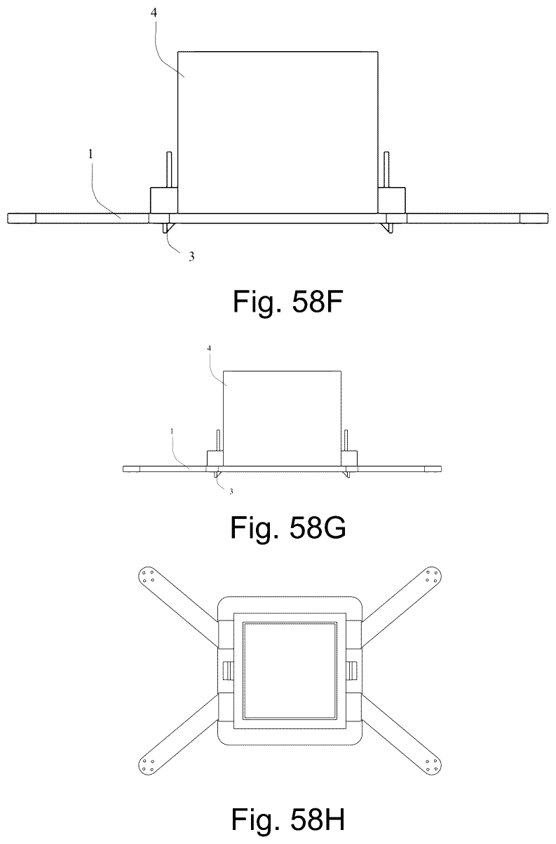

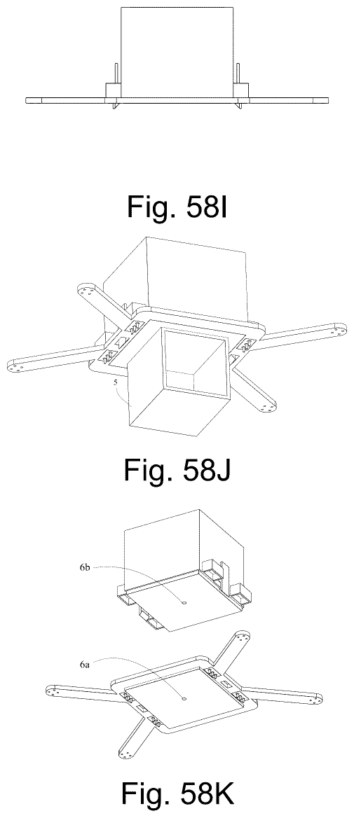

The figures depict an example modular drone comprising a propulsion frame and a detachable body. Elements shown in the figures, including connector features, securing mechanisms, and alternative fastening options, are enumerated immediately below in the section titled Elements shown in the figures (anchor). Reference numbers and labels in that section correspond to the depicted features and relationships, and the drawings may not be to scale.
Elements shown in the FIGS. 58a to 58k:

The system may consist of:
1. A multicopter frame
Electrical connection between the body and the motors is achieved through pogo pins.
2. A set of pogo pin connectors
2a. The bottom side of the pogo pins is located on the frame, providing solder pads for attaching motor wires.
2b. The top side of the pogo pins is spring-loaded and compressible.
2c. These compressible tops make contact with corresponding pogo pin pads on the body enclosure.

The body is secured to the frame by a Snap-Lock Quick Release Mechanism.
3. A locking element that is attached to the drone body (4)
3a. A locking element snaps under the frame to hold the body in place.
3b. A release actuator, when pressed by the user, disengages the locking element and allows removal.

The body (4) enclosure holds all electronic components (not shown).

An optional battery holder (5) may be attached to the body enclosure. A screw hole, shown as an alternative to the snap-lock mechanism, the frame and body may also be secured using a screw hole (6a and 6b).

The figures illustrate a modular drone system in which the multicopter frame serves as the structural anchor for both the propulsion hardware and the removable body enclosure. Electrical continuity between the motors mounted on the frame and the electronics housed in the body is provided by pogo pins. The lower ends of the pogo pins (2a) are fixed to the frame as solder pads, permitting permanent attachment of motor wires, while the upper ends (2b) are spring-loaded and compressible so that they can reliably press against the corresponding copper pads on the underside of the body (2c). This blind-mate arrangement ensures that, when the body is lowered into position, power and signals are automatically routed from the core electronics into the motors without requiring manual wiring or connectors.

Mechanical retention is achieved by a Snap-Lock Quick Release Mechanism. A locking element (3a) engages beneath the frame to hold the body enclosure firmly in place during operation, while a release actuator (3b), when pressed by the user, disengages the lock and allows tool-free removal of the body.

The body enclosure itself contains the electronic systems such as flight controllers, navigation sensors, and communication modules, and may optionally carry a battery holder directly attached to its structure.

For applications where additional fastening strength or redundancy is desired, an alternative to the snap-lock mechanism is provided in the form of a screw hole. In this variation, the body can be secured to the frame by a threaded fastener, either in conjunction with or in place of the quick-release mechanism. Together, these features establish a system in which the frame remains a rugged, motor-bearing foundation while the body acts as a detachable, serviceable electronics module, the two being interconnected both electrically and mechanically through the coordinated action of the pogo pin contacts and the locking mechanisms.

As an alternative to the Snap-Lock Quick Release Mechanism, the body and frame may be secured using different fastening means. In one variation, a screw hole is provided for receiving a threaded fastener. In another, a quarter-turn key or bayonet-style connector may be used, allowing the body to be locked in place with a short rotational movement. A sliding latch engaging rails or grooves in the frame may also be employed, while in yet another variation, a magnetic latch with a mechanical backup provides tool-free attachment but prevents accidental release. A further option is a spring-biased detent pin that can be pulled or pressed to disengage. Additional alternatives include a cam-lock lever that secures the body with a single flip of a handle, a twist-lock collar that rotates around a mating flange, a toggle clamp mechanism for rapid actuation, a push-button latch with internal locking prongs, or an eccentric clamp that tightens through rotational offset. These fastening means provide varying balances of strength, tool-freeness, and ease of operation, allowing the securing method to be tailored to different drone use cases.

In the context of the invention, the precise way in which the body is attached to the frame is not decisive; the essential features are that the body can be detached from the frame and that, when in place, it establishes a reliable electrical connection with the motors. The electrical interface may be realized through spring-loaded pogo pins that press against conductive pads, blind-mate plug connectors, edge or card-slot connectors with plated contacts, magnetic connectors that provide both alignment and conduction, inductive coupling pads for wireless transfer of power and data, or flexible printed circuits and ribbon tails that engage with sockets. Further variations may include conductive elastomer pads compressed between body and frame, thin-film contact foils laminated to a seating surface, or even optical or capacitive coupling elements where weight savings are prioritized. The mechanical securing of the body likewise admits variation, ranging from snap-lock latches, quarter-turn bayonet couplings, sliding rail-and-groove engagements, and cam-lock or toggle clamps, to spring-biased pins, detent catches, magnetic retention systems, and lightweight strap or clip mechanisms. Adhesive-backed hook-and-loop fasteners, elastic bands, or shape-memory clips may also be used in ultra-lightweight implementations where strength demands are modest. In preferred embodiments, the securing mechanism enables tool-free detachment so that the body can be removed in seconds, and because multiple reinforced joints are avoided, the overall system remains lighter and stiffer than traditional modular drones, thereby increasing flight endurance while simplifying maintenance.

To enable predictive maintenance, the propulsion frame is further provided with a unique identifier, stored for example in a small chip such as an EEPROM or NFC element mounted on the frame. When the body is inserted, the identifier is read through an electrical interface that may use pogo pins, edge contacts, flexible circuits, or other blind-mate means. The body then associates the identifier with its own log of operational data, recording flight hours, takeoff cycles, vibration exposure, and motor duty.

Since motors and bearings inevitably wear at roughly the same rate, this log provides an accurate record of the propulsion frame's service life. Once a predetermined threshold is reached, the body may issue a warning to the operator that replacement is due. In some embodiments, the system may limit operation until the worn frame is exchanged for a new or refurbished one.

This cartridge-style architecture provides several advantages. The costly flight electronics remain isolated within the body, while the propulsion frame, which contains wear-prone motors and bearings, can be swapped in a single action. The worn frame may then be returned to a refurbishment service for overhaul and reuse, while the drone continues operating with minimal downtime. By removing the complexity and weight of multiple detachable arms, the system achieves a lighter and stiffer structure, extending airtime and improving efficiency. At the same time, maintenance is simplified into a predictable, tool-free workflow well-suited to agricultural users, aligning with their need for reliability, field serviceability, and reduced operational cost.

This modular architecture is particularly advantageous for drones that manipulate their environment, such as laser-equipped drones for precision pest control or drones carrying robotic arms for agricultural or industrial tasks. In such systems, the payload often demands high electrical power, generates additional vibration, or imposes mechanical stresses that accelerate wear on the propulsion system. By separating the expensive control core from the propulsion frame, the drone ensures that frequent replacements caused by heavy-duty operation affect only the lower-cost propulsion cartridge while leaving the sophisticated laser optics, robotic actuators, or control electronics untouched. The lighter and stiffer monocoque propulsion frame further improves flight stability, which is critical for accurate laser targeting or dexterous arm manipulation. Maintenance cycles can be tightly managed by logging frame usage, so that when bearings and motors inevitably degrade under demanding manipulator loads, the propulsion frame can be swapped in seconds while the mission-critical payload remains calibrated and protected.

In some embodiments oriented toward monetization and damages maximization, the cartridge architecture may be paired with subscription or usage-based enablement. The body may verify an entitlement associated with the frame identifier before arming, and may meter billable units such as flight hours per frame, takeoff cycles, or frame swap events. A secure element in the body may store cryptographic keys to sign usage logs and to validate time-bounded tokens provisioned from a remote service over cellular, Wi-Fi, or radio links; in offline scenarios, locally cached tokens may allow continued operation until renewal is required. Fleet operators may configure tiers, for example monthly limits or pay-per-hour, and receive audits and invoices generated from the signed logs. The firmware may expose application interfaces for third-party fleet management and may present remaining entitlement on an operator display. These features could enable clear calculation of revenue impact where unauthorized substitution for licensed use occurs, while remaining optional so that the same hardware operates without subscription when configured accordingly.

### Enablement

A skilled person may implement representative embodiments using readily available components and standard fabrication methods. The propulsion frame may be molded from reinforced polymer, machined from aluminum alloy, or laid up in carbon-fiber composite with local bosses for motor mounts and latch interfaces. Arms may integrate wire channels that route motor leads to a central harness terminating at frame-side contacts. For a pogo-pin embodiment, three spring-loaded contacts per motor phase may be mounted on a rigid or flex printed circuit affixed to the frame's mating rim, with gold plating thickness of approximately 0.5 to 1.0 micrometers on both pins and body pads and target contact resistance below 50 milliohms per interface. Spring force may be selected in the range of 0.3 to 1.0 newtons per pin so that aggregate force ensures continuity under expected vibration while avoiding excessive seating force; magnets or cam surfaces may assist insertion to achieve full compression. Body-side pads may be arranged as an annular array around the body rim with copper thickness of 35 micrometers and nickel-gold finish, isolated by solder mask dams to reduce bridging risk, and may be coupled to ESC outputs or motor drive buses via short, low-inductance traces. Mechanical retention may be provided by a snap-lock latch molded into the frame with a stainless-steel locking element engaging a body-side undercut, and a manual release actuator positioned to prevent accidental activation in flight. Alternative latches may include a quarter-turn bayonet with ramps and detents, a sliding rail-and-groove with end stops, or a toggle clamp with an over-center lever. Optional redundancy may be provided by a single M3 or 4-40 screw engaging a threaded insert in the body. Gasketed interfaces may be implemented using closed-cell foam or elastomer to achieve dust resistance when seated. Alignment features such as tapered lead-ins, chamfers, or magnets arranged with alternating poles may bias the body into a repeatable position during seating, protecting the contacts from side-loading and scrape.

The frame may carry a unique identifier in an EEPROM or NFC device connected to two dedicated contacts in the blind-mate interface or accessible via a short-range link. Upon attach, the body's MCU may read the identifier, associate or create a usage record, and update a non-volatile log. Safety interlocks may include detection of latch engagement via a microswitch or Hall sensor, measurement of contact resistance via a low-current test pulse, and motor arming inhibition until both mechanical and electrical criteria pass. Firmware may implement an attach handshake that records a timestamped event such as {“event”:“attach”, “frame_id”:“F12345”, “result”:“ok”, “time”:“2025-05-01T12:00:00Z”} and a detach event upon release. Entitlement workflows may validate a signed token, meter hours or cycles, and continue operation offline using cached tokens until renewal, as exemplified previously. Model Context Protocol may be used by the body to provide a stable interface for fleet applications by presenting a structured context describing frame id, entitlement state, usage counters, and maintenance thresholds as simple JSON records, without exposing system internals. Assembly may proceed by fabricating the frame, installing motors and routing leads to the central harness, soldering to the frame PCB with pogo pins, and potting or strain-relieving as appropriate. The body may be assembled with the flight controller, power distribution, ESCs or motor drivers, radio links, and sensors, with the body rim PCB carrying gold-plated pads wired to the motor drivers. The latch and alignment features may be verified on a gauge fixture. Final test may include vibration exposure over the expected spectrum while monitoring contact resistance, thrust stand testing to verify power delivery margins, and environmental checks for dust ingress. A field replacement procedure may be documented such that an operator powers down, actuates the release, lifts the body, seats a replacement frame, confirms indicator patterns, and resumes operation, all without tools in preferred configurations.

### Technical Effects

Embodiments reduce structural mass by eliminating multiple reinforced arm joints, increase torsional and bending stiffness through a monocoque frame, and maintain low electrical contact resistance under vibration via compliant blind-mate interfaces aided by magnetic or guided seating. These effects improve flight endurance, control bandwidth, and stability, while the cartridge workflow reduces maintenance time from hours to seconds and confines wear-item replacement to the low-cost frame. Predictive logging tied to a unique frame identifier enables accurate life tracking and planned downtime. Optional entitlement mechanisms add secure, auditable control over usage.

### Flows

A representative attach flow may include body alignment to the frame via chamfers or magnetic bias, initial light contact that permits a low-current continuity test, progressive seating that compresses contacts, automatic latch engagement with sensor confirmation, firmware attach handshake with identifier read, and external indicator acknowledgement prior to arming. A maintenance flow may include periodic logging of flight hours and vibration metrics, threshold comparison against limits, alert issuance to the operator, body detach with data retention, frame replacement, and resume of operations with the new frame's identifier associated to subsequent logs. An entitlement flow may include token presence check, signature verification, plan selection, decrementing or accumulating billable units during operation, and renewal when connectivity is available, while honoring offline grace periods.

### Support

The description supports each claim element. Frame and body structures and their electrical interfaces are described in the Detailed description and anchor. Securing mechanisms including snap-lock, bayonet, rails, toggle, magnetic retention, and screw redundancy are disclosed. System and method behaviors are described through operational flows and examples. Maintenance logging, unique identifiers, and alerts are disclosed, as well as fallback embodiments using manual plugs and screws. The itemized list further provides explicit textual support for current claims and additional variations contemplated for future continuations.

### Broadening

Alternative electrical interfaces include pogo pins, magnetic contacts, inductive coupling, edge connectors, flexible printed circuits, conductive elastomers, thin-film foils, optical or capacitive coupling, and combinations. Mechanical securing covers snap-locks, bayonets, rails, cam locks, toggle clamps, detent pins, magnetic retention, straps, clips, and optional threaded fasteners. Materials, geometries, and seating strategies are varied to accommodate different environments and performance requirements, broadening claim scope while preserving the inventive concept. In some embodiments, the roles of the frame and the body may be inverted such that the detachable body supports a plurality of motors while the frame houses electronic control components, or vice versa, and the electrical interface may be established automatically upon securing or by a keyed manual engagement that occurs as part of or immediately after the securing operation, with the same securing and maintenance workflows applying.

To further reduce opportunities for avoidance by interface changes, embodiments may encompass two-stage or adjunct connections in which securing the modules is followed by engagement of a keyed interposer or captive jumper located adjacent to the mating plane, a lanyard-attached cable that is automatically tensioned and latched during seating, or a captive harness that completes continuity upon closure of a cover. Embodiments may include cases in which ESCs reside on either module or are split across both, such that the interface carries any mix of DC power, motor phases, and control signaling over PWM, DShot, CAN, or other buses. The inventive concept remains a field-replaceable propulsion cartridge or electronics core in which electrical continuity is completed as part of, or immediately following, the attach operation without per-motor rewiring.

### External Observability

Externally observable behaviors include attach and detach indicator patterns, logged attach/detach events with frame identifiers and timestamps, and automatic arming inhibition upon incomplete engagement. These behaviors permit field verification and forensic confirmation of infringing use without inspecting internal structures.

Observable invariants may include a time-bounded replacement operation performed without per-motor rewiring, a post-attach self-test that refuses arming unless continuity for all motor channels is detected across the module boundary, and recording of a module swap event with a new module identifier within a short interval of mechanical reattachment. These invariants remain applicable even where continuity is completed via an interposer or captive jumper that is engaged immediately after seating.

### Interoperability Coverage

Interfaces may operate with PWM, DShot, OneShot, CAN or UAVCAN ESCs, and serial or MAVLink telemetry. The body may select firmware profiles or adapters upon reading a frame identifier so that diverse frames and ESC standards interoperate without avoiding the claimed interface and detachability.

### Workaround Coverage

Competitors may attempt to avoid infringement by relocating electronic speed controllers across the module boundary, using a hinged door or cover to complete contact after seating, employing an interposer or captive jumper engaged immediately after securing, distributing motors across multiple smaller swappable pods, changing the mating plane or engagement motion such as sliding or pivoting rather than purely vertical seating, aggregating continuity through an internal harness rather than an exposed contact array, or substituting optical, capacitive, or inductive couplers for direct electrical contacts. Embodiments expressly encompass these implementations; the inventive concept is a field-replaceable propulsion cartridge or electronics core in which the electrical continuity between motor-drive electronics and the motors is completed as part of, or immediately following, the securing operation without per-motor rewiring, regardless of where ESCs reside or the nature of the coupling element. Continuity may be completed by blind-mate contacts, inductive or optical couplers, keyed interposers, captive jumpers, lanyard-attached cables, or closure of a hinged door integral to a captive harness. Detachability may be provided by snap-locks, bayonets, sliding rails, detent pins, magnetic retention, cam-locks, twist-locks, toggle clamps, or a single screw with a keyed plug, and may proceed along linear, pivoting, or compound paths. Modules may be monocoque frames, subframes, rings, adapter plates, or aggregated single-motor pods mated to an adapter subframe, with adapters preserving the same field-replaceable behavior. Externally observable invariants described herein, including completion of a module swap in a short interval without touching individual motor leads, automatic arming inhibition until continuity and latch engagement are verified, and logging of attach and detach events with module identifiers, provide objective evidence of cartridge-style operation even where internal interfaces are concealed.

### Fallback Embodiments

Simplified embodiments may implement a keyed manual power plug and a single threaded fastener with a microswitch confirming screw presence, achieving detachability and electrical continuity with lower cost while preserving the core cartridge workflow and maintenance benefits.

### Damages Maximization

Subscription or usage-based enablement may be implemented using a secure element that validates time-bounded tokens, signs usage logs associating frame identifiers to hours or cycles, and supports offline grace periods. These mechanisms permit accurate invoicing and quantification of unauthorized usage, supporting higher damages calculations where appropriate.

### Claim Layering

The claims include component-level claims to frames and bodies, a system claim, a method claim, and detachability-focused claims, providing protection at multiple abstraction levels while keeping the number of independent claims within the stated limit.

### No Unneeded Limitations

The principal system claim permits various connector and latch technologies without requiring any specific type of contact, magnet, or latch geometry. Detachability and blind-mate continuity are emphasized so that competitors cannot avoid infringement by substituting equivalent interfaces or securing mechanisms.

### Continuation-Ready

An itemized list provides explicit, enumerated textual support that aligns with current claims and introduces additional features and variants suitable for continuation filings, allowing future claim expansions without adding new matter.

### Itemized List of Features for Continuation Support

Embodiments can be described by the following itemized list, which is intended to provide explicit support for present and future claim sets without limiting scope. Feature 1: A multicopter frame having at least a first arm configured to receive and support a first motor and a second arm configured to receive and support a second motor, with a first set of electrical connectors operatively coupled to the first motor and a second set of electrical connectors operatively coupled to the second motor, the connector sets being positioned to establish electrical contact with corresponding connectors on a detachable drone body when the body is secured to the frame. Feature 2: A drone body including a housing that contains electronic control components and that carries at least first and second sets of body-side electrical connectors disposed to mate with corresponding frame-side connector sets when the housing is detachably secured to a drone frame so as to provide electrical continuity between the electronic control components and motors supported by the frame. Feature 3: The frame-side electrical connectors comprising spring-loaded pogo pins arranged to press against conductive pads on the drone body. Feature 4: The frame-side electrical connectors comprising magnetic contacts configured both to align the body with the frame and to provide electrical conduction. Feature 5: The frame-side and body-side electrical interface comprising inductive coupling elements configured to transfer power wirelessly between the frame and the body. Feature 6: A latch or securing mechanism on the frame configured to secure the body to the frame without the use of tools. Feature 7: A snap-lock mechanism including a locking element that engages beneath the frame and a release actuator configured to disengage the locking element upon manual pressure. Feature 8: Alternative securing mechanisms including a quarter-turn bayonet connector, a sliding rail-and-groove mechanism, or a toggle clamp. Feature 9: A memory device on the frame carrying a unique identifier and configured to communicate the identifier to the body when the body is secured to the frame. Feature 10: A body configured to log operational data such as flight hours associated with the identifier and to issue a maintenance alert when a threshold usage level is reached. Feature 11: A drone system including a frame supporting a plurality of motors, a detachable body housing electronic control components, at least one electrical interface that, upon securing, establishes electrical continuity between the components and the motors, and at least one securing mechanism, wherein the body is removable so that motors and associated drive components may be replaced independently of the electronic control components. Feature 12: A maintenance method including securing the body to the frame to establish an electrical interface to motors, operating the drone, recording operational data including flight time associated with the frame, detaching the body while retaining the data within the body, replacing the frame with a different frame, and re-securing the body so that the operational data remains available. Feature 13: The maintenance method wherein detaching and securing the body is performed without tools. Feature 14: The maintenance method further including issuing a maintenance alert when accumulated operational data exceeds a threshold. Feature 15: The maintenance method wherein the frame includes a memory device carrying a unique identifier and the securing step includes reading the identifier and associating the operational data with the identifier. Feature 16: The maintenance method further including returning the detached frame to a refurbishment service while continuing operation with the replacement frame. Feature 17: A drone system wherein a body is detachably secured to a frame by at least one securing mechanism such that the body may be detached and reattached without disassembly of the frame. Feature 18: The securing mechanism comprising a snap-lock latch, a bayonet coupling, a sliding rail-and-groove engagement, a spring-biased detent pin, or a magnetic retention element. Feature 19: A drone system wherein the body is detachable from the frame without the use of tools. Feature 20: A drone system wherein detachment of the body from the frame enables replacement of the frame while retaining the body and its electronic components. Feature 21: An integrated monocoque propulsion frame that incorporates all arms, motors, and propellers into a single cartridge unit that mates with a central electronics body via a blind-mate interface. Feature 22: A blind-mate interface implemented as an annular array of contacts around a body rim, with magnetically assisted seating that equalizes contact pressure to maintain low-resistance paths under vibration. Feature 23: Electrical interfaces alternatively realized as edge or card-slot connectors with plated contacts, flexible printed circuits, conductive elastomer pads, thin-film contact foils, optical or capacitive coupling elements, or magnetic connectors that both align and conduct. Feature 24: Mechanical securing alternatives including cam-lock levers, twist-lock collars, toggle clamps, push-button latches with internal locking prongs, eccentric clamps, adhesive-backed hook-and-loop, elastic bands, strap or clip mechanisms, and combinations thereof, optionally with a screw fastener as redundancy. Feature 25: Predictive maintenance using a unique frame identifier to associate operational logs that may include flight hours, takeoff cycles, vibration exposure, temperature history, current draw, motor duty, and bearing health estimates, with thresholds triggering alerts or operational limits. Feature 26: Subscription or usage-based enablement in which a secure element stores cryptographic keys to validate time-bounded tokens; the system may sign usage logs, meter billable units such as flight hours per frame, takeoff cycles, or swap events, and operate with offline cached tokens until renewal. Feature 27: An application interface exposed by the body for fleet management and telemetry, enabling audits and invoices generated from signed logs, and presentation of remaining entitlement on an operator display. Feature 28: Environmental manipulation payloads including a laser module or a robotic arm mounted to the frame or body, where increased vibration and power demand accelerate propulsion wear, and the cartridge architecture confines frequent replacements to the lower-cost propulsion frame. Feature 29: Externally observable behaviors including automatic motor disarm when the securing mechanism is disengaged, an attachment handshake that results in a visible indicator pattern or audible code upon successful electrical continuity, and an event log entry with timestamped frame identifier upon each attach or detach. Feature 30: Interoperability with control and motor interfaces including PWM, DShot, OneShot, CAN or UAVCAN ESCs, and serial or MAVLink telemetry, with adapters or firmware profiles selectable by the body when a frame is identified. Feature 31: Fallback embodiments in which electrical continuity is provided by a manual plug and socket or a ribbon-tail connector and mechanical retention is provided by a threaded fastener or strap, while still achieving a detachable body and replaceable propulsion frame. Feature 32: Materials and finishes including carbon-fiber composite, aluminum alloy, or reinforced polymer for the propulsion frame; gold-plated copper contact pads with contact resistance targeted below 50 milliohms and spring forces sized to maintain continuity under expected vibration spectra. Feature 33: Environmental protections such as conformal coating on contact regions and gasketed interfaces between body and frame to resist dust and moisture ingress encountered in agricultural use. Feature 34: A non-transitory computer-readable medium storing instructions which, when executed by processors in the body, cause logging of frame identifiers and usage, enforcement of entitlements, prediction of maintenance thresholds, and communication of alerts to an operator or remote service. Feature 35: Safety interlocks including detection of partial engagement and inhibition of arming until both mechanical securing state and electrical continuity are verified, with external indicators signaling the interlock state. Feature 36: Geometry wherein the body slides or pivots into the frame along a guided path that aligns electrical contacts prior to mechanical latching, reducing risk of contact damage during insertion, and permitting one-handed, tool-free service in the field. Feature 37: A two-stage or adjunct connection in which, after securing, a keyed interposer, captive jumper, or lanyard-attached cable located adjacent to the mating plane is engaged automatically by seating or by closing a cover to complete continuity without per-motor rewiring. Feature 38: A captive harness that is integral to one module and that mates to the other upon closure of a hinged or sliding door that also serves as a mechanical retention element. Feature 39: A split ESC topology in which one or more motor phases or control channels cross the module boundary while other phases or channels reside on the same module as the motors, with the interface carrying any combination of DC power, motor phases, and digital control signaling. Feature 40: A post-attach self-test that measures continuity or contact resistance for each motor channel and inhibits arming until all channels meet thresholds, with an externally observable indicator pattern upon pass or fail. Feature 41: A field-replacement invariant wherein a module swap can be completed within a defined short interval without touching individual motor leads, constituting external evidence of cartridge-style operation. Feature 42: An adapter subframe or interposer plate that permits modules of differing geometry or interface layout to mate while maintaining detachability and blind-mate or immediately-adjacent mate continuity. Feature 43: A hot-swap embodiment in which the body remains powered by a hold-up capacitor or auxiliary cell during frame replacement and resumes operation after reattachment and continuity verification. Feature 44: A tamper-evident seal or latch-state recorder that evidences detach events and aligns with logged attach/detach entries to substantiate usage and module swaps. Feature 45: A compliance feature wherein operation is gated unless a captive jumper, door, or cover that completes the electrical interface is in the closed state, preventing operation with partial engagement while supporting rapid swaps.

### Scope and Interpretation

The embodiments described, the features listed, and any figures referenced are illustrative and not limiting. The scope of the invention is defined solely by the claims, and all examples, alternatives, and specific arrangements are presented as example implementations that may be varied without departing from the claimed subject matter. Operations and flows described herein may be performed in different orders, in parallel, with steps omitted or added, or with equivalent steps substituted, provided that the overall functionality is retained. Terms such as includes, comprising, having, and the like are intended to be open-ended. References to a or an element are intended to include one or more such elements unless the context clearly dictates otherwise. Structures described as frame, body, module, cartridge, or the like may be implemented in mechanically equivalent forms and may be combined or separated in any operable combination. Elements described as configured to may be implemented in hardware, firmware, software, or any combination thereof.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A multicopter frame comprising:
   a) a first arm configured to receive and support a first motor;
   b) a second arm configured to receive and support a second motor;
   c) a first set of electrical connectors operatively coupled to the first motor; and
   d) a second set of electrical connectors operatively coupled to the second motor;
wherein the first and second sets of electrical connectors are positioned to establish electrical contact with corresponding connectors on a detachable drone body when the drone body is secured to the frame.
2. A drone body comprising:
   a) a housing configured to contain one or more electronic control components;
   b) a first set of body-side electrical connectors disposed on the housing and arranged to mate with a corresponding first set of frame-side electrical connectors; and
   c) a second set of body-side electrical connectors disposed on the housing and arranged to mate with a corresponding second set of frame-side electrical connectors;
wherein the housing is detachably securable to a drone frame, and wherein, upon securing the housing to the frame, the first and second sets of body-side electrical connectors establish electrical contact with the first and second sets of frame-side electrical connectors so as to provide electrical continuity between the electronic control components and motors supported by the frame.
3. The multicopter frame of item 1, wherein the first and second sets of electrical connectors comprise spring-loaded pogo pins arranged to press against conductive pads on the drone body.
4. The multicopter frame of item 1, wherein the first and second sets of electrical connectors comprise magnetic contacts configured both to align the body with the frame and to provide electrical conduction.
5. The multicopter frame of item 1, wherein the first and second sets of electrical connectors comprise inductive coupling elements configured to transfer power wirelessly between the frame and the body.
6. The multicopter frame of item 1, further comprising a latch configured to mechanically secure the body to the frame without the use of tools.
7. The multicopter frame of item 6, wherein the latch comprises a snap-lock mechanism including a locking element that engages beneath the frame and a release actuator configured to disengage the locking element upon manual pressure.
8. The multicopter frame of item 6, wherein the latch comprises a quarter-turn bayonet connector, a sliding rail-and-groove mechanism, or a toggle clamp.
9. The multicopter frame of item 1, further comprising a memory device carrying a unique identifier, the memory device being configured to communicate the identifier to the body when the body is secured to the frame.
10. The multicopter frame of item 9, wherein the body is configured to log flight hours associated with the identifier and to issue a maintenance alert when a threshold usage level is reached.
11. A drone system comprising:
   a) a frame;
   b) a detachable body configured to be secured to the frame;
wherein one of the frame or the body is configured to support a plurality of motors and the other is configured to house electronic control components;
   c) at least one electrical interface between the frame and the body, the electrical interface being arranged such that, when the body is secured to the frame, as part of the securing operation or immediately thereafter, electrical continuity is established between the electronic control components and the motors; and
   d) at least one securing mechanism configured to hold the body in engagement with the frame;
wherein the body is removable from the frame, and wherein the one of the frame or the body that supports the motors is replaceable independently of the other one that houses the electronic control components.
12. A method of maintaining a drone system comprising a frame and a detachable body, the method including the steps of:
   a) securing the body to the frame such that an electrical interface is established between electronic control components within the body and motors supported by the frame;
   b) operating the drone such that the electronic control components drive the motors through the electrical interface;
   c) recording operational data including at least flight time associated with the frame;
   d) detaching the body from the frame while retaining the operational data within the body; and
   e) replacing the frame with a different frame, and re-securing the body to the different frame such that the operational data continues to be available to the electronic control components.
13. The method of item 12, wherein detaching and securing the body is performed without tools.
14. The method of item 12, further comprising the step of issuing a maintenance alert when accumulated operational data exceeds a threshold.
15. The method of item 12, wherein the frame comprises a memory device carrying a unique identifier, and the step of securing the body includes reading the identifier and associating the operational data with the identifier.
16. The method of item 12, further comprising returning the detached frame to a refurbishment service while continuing drone operation with the replacement frame.
17. A drone system comprising:
   a) a frame configured to support a plurality of motors; and
   b) a body configured to be detachably secured to the frame,
wherein the body houses one or more electronic components, and wherein the body is removably secured to the frame by at least one securing mechanism such that the body may be detached and reattached without disassembly of the frame.
18. The drone system of item 17, wherein the securing mechanism comprises a snap-lock latch, a bayonet coupling, a sliding rail-and-groove engagement, a spring-biased detent pin, or a magnetic retention element.
19. The drone system of item 17, wherein the body is detachable from the frame without the use of tools.
20. The drone system of item 17, wherein detachment of the body from the frame enables replacement of the frame while retaining the body and its electronic components.

### Embodiment AOE: Feather Light Laser Driver Circuit

In conventional systems, supplying several amperes to a semiconductor diode requires a constant-current regulator, bulky heatsinking, and high-power resistors. These assemblies are designed for continuous duty and therefore impose unnecessary weight when the intended use is short pulses with long rest periods. In aerial applications such as drones, where payload mass is tightly limited, the penalty of conventional driver circuits makes the integration of high-current diodes impractical. The problem is therefore to create a driver architecture that allows reliable multi-ampere conduction in a diode while reducing the mass of support circuitry to only a few grams.

The proposed solution exploits the pulsed nature of the load. A low-voltage supply is chosen just above the diode's forward conduction point, and a small resistance is introduced in series to cap the maximum current at the diode's safe rating. Because the supply voltage margin is minimal, the resistor need not dissipate large amounts of power and can be realized by a lightweight length of resistive wire or film element. A compact MOSFET gates the one-second conduction window, while a small local capacitor and snubber absorb switching transients. Thermal design is simplified because the diode operates at a duty cycle of roughly one-eleventh, allowing heat to dissipate in the nine-second off interval, so that the average power is a fraction of the instantaneous load.

An illustrative embodiment involves a diode with a nominal forward drop of 1.4 volts and a maximum current rating of 7 amperes. By supplying the system with 1.8 volts and inserting a 0.086-ohm series resistor, the forward current remains between 4.7 and 7 amperes over the diode's voltage range, never exceeding the safe limit even when the device is cold. In operation, the diode dissipates approximately 9.8 watts during each one-second pulse, while the resistor absorbs about 4.2 watts. With ten seconds of idle time between pulses, the average thermal load is less than one watt, which can be handled by a gram-scale copper pad or thin fin without adding mass. The resistor itself can be implemented by a short piece of nichrome wire weighing less than one gram, while the diode package weighs approximately two grams. The complete driver, including MOSFET and snubber, remains within a few grams total. This arrangement demonstrates that high-current diode operation suitable for optical emission or rectification can be achieved in airborne platforms with negligible weight overhead, by tailoring the driver to the pulse duty cycle rather than continuous operation.

Here's a first draft of claims written to be broad, enforceable, and hard for competitors to design around, while still anchored in your described “feather-light laser driver” idea. I've structured them in a patent-style hierarchy, starting broad and layering in dependent claims that close common workarounds.

Conventional driver circuits for high-power semiconductor diodes, such as laser diodes, are designed for continuous duty operation. They typically incorporate constant-current regulators, bulky heatsinking structures, and resistive ballast elements sized to dissipate steady-state power. While these arrangements provide reliable control under laboratory or bench conditions, they impose a severe weight penalty when integrated into airborne or portable systems. In particular, when mounted on drones or other aerial platforms where every gram of payload mass directly reduces flight endurance, the mass of traditional driver electronics renders multi-ampere diode operation impractical. The inventors have recognized that such designs are fundamentally mismatched to use cases where the diode operates in pulses with long rest intervals, and that a new architecture optimized for low duty cycle operation enables drastic reductions in mass.

The disclosed driver exploits the inherently pulsed nature of optical emission in airborne applications. Instead of maintaining a high compliance voltage across a diode and regulating excess current by dissipating energy, the circuit employs a low-voltage source that is only marginally higher than the forward conduction voltage of the diode. By reducing the supply margin to less than about one volt, the maximum current is naturally bounded by a lightweight series resistance element. Because the voltage margin is minimal, the resistor does not need to dissipate large amounts of power and may be implemented by a short length of resistive wire, a deposited thin-film element, or even a printed trace of controlled resistivity. Such elements may weigh less than a gram, yet provide reliable current limiting in the multi-ampere range.

The current conduction is further gated by a compact solid-state switch, such as a MOSFET, which defines short conduction windows-typically on the order of one second or less-separated by idle intervals of five to ten seconds or longer. During the conduction period, the diode may dissipate on the order of 5 to 10 watts, but because the average duty cycle is less than one-tenth, the long off-intervals allow heat to dissipate naturally through a lightweight copper pad or thin fin. In this way, the average thermal load is reduced to less than one watt, eliminating the need for bulky heatsinks. Switching transients are absorbed by a small capacitor and snubber network located adjacent to the diode, further reducing the need for large passive components. The entire driver assembly, including power source, resistor, MOSFET, and transient protection, can therefore be constructed with a total mass of only a few grams.

An illustrative embodiment involves a diode with a nominal forward voltage of approximately 1.4 volts and a rated maximum current of seven amperes. By supplying the system with 1.8 volts and inserting a resistance element of about 0.086 ohm, the diode current is maintained between 4.7 and 7 amperes over its entire operating temperature range. Even at cold start conditions, the current never exceeds the safe rating. During a one-second conduction pulse, the diode dissipates approximately 9.8 watts while the resistor dissipates approximately 4.2 watts. With a rest interval of ten seconds between pulses, the average power is less than one watt, which can be dissipated by gram-scale thermal structures without impairing diode lifetime or requiring dedicated heatsinking.

In other embodiments, the conduction interval may range from microseconds to several seconds, with idle intervals scaled proportionally to maintain average dissipation at a manageable level. The ratio of idle to conduction time may be at least 5:1, preferably 10:1 or greater, ensuring that the diode operates well within its safe thermal envelope. The circuit may be scaled to supply currents of 5, 10, or even 20 amperes by appropriate selection of supply voltage and resistive element, while still preserving the low-mass advantages. Multiple diodes may be driven in parallel or in sequence, with each channel gated individually, to produce higher aggregate optical output without increasing the total driver weight beyond tens of grams.

This architecture therefore demonstrates that reliable multi-ampere diode operation suitable for high-power optical emission, rectification, or illumination can be achieved in weight-critical systems.

By tailoring the driver to the pulse duty cycle rather than to continuous operation, the mass of supporting circuitry is reduced by an order of magnitude relative to conventional designs. The invention is not limited to a particular diode type or wavelength; any semiconductor diode that benefits from pulsed operation may be driven by the disclosed circuit. Airborne applications such as drone-mounted laser sources, balloon-borne beacons, or lightweight aircraft illumination systems are particularly enabled, but the circuit is equally applicable to handheld or mobile devices where weight and thermal constraints preclude conventional drivers.

In some embodiments, the series resistance element may be realized in many interchangeable forms. A short length of nichrome or manganin wire may be used, but equivalent implementations include deposited thin-film resistors, printed circuit board traces of controlled resistivity, foil strips, or even integrated semiconductor resistive elements. Because the supply voltage margin is constrained to less than one volt above the forward conduction voltage of the diode, all such implementations operate in a regime where only a few watts of peak power are dissipated during a pulse, so even fragile or lightweight resistive media can be employed without risk of failure. Thus, any structure providing resistive limitation in the tens to hundreds of milliohm range may serve as the resistance element while still achieving the lightweight objectives of the invention.

Similarly, the switching function is not limited to MOSFET devices. While a compact MOSFET is preferred for its low gate drive requirements and high efficiency at low voltages, any controllable current gating element may be substituted without departing from the inventive concept. This includes insulated-gate bipolar transistors (IGBTs), gallium nitride (GaN) field-effect transistors, junction FETs, bipolar junction transistors, or even microelectromechanical (MEMS) relays. The key aspect is that the switch defines the conduction window for the diode and allows extended idle intervals, such that the average thermal dissipation is decoupled from the peak current load.

The transient suppression network likewise admits broad variation. A simple parallel capacitor across the diode may suffice, but other embodiments may use RC snubbers, ferrite beads, transient voltage suppressor diodes, or laminated capacitive structures to manage switching edges. All of these fall within the scope of the invention, because their function is merely to absorb the high-frequency transients associated with fast gating of high currents, not to provide bulk energy storage.

Thermal management, while simplified relative to continuous-duty drivers, may also take multiple forms. A thin copper pad beneath the diode, a folded aluminum fin, a carbon-fiber spreader, or a conductive polymer interface may be used to spread and radiate heat. Because the duty cycle is low and the average heat load is less than one watt, such structures can be extremely lightweight-often less than a gram-yet sufficient to ensure long diode lifetime. In some embodiments, the mounting substrate itself doubles as the thermal sink, eliminating the need for dedicated thermal hardware.

The invention is not limited to optical diodes. Any semiconductor diode intended for short duty-cycle, high-current conduction may be driven by the disclosed architecture. For example, rectifier diodes in lightweight power conversion, avalanche diodes used as pulse generators, or microwave diodes in compact transmitters can all be supplied with multi-ampere pulses using a low-margin supply and series resistance as described. Thus, the principles disclosed are broadly applicable to weight-sensitive systems across optical, electrical, and radio-frequency domains.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A driver circuit for supplying current to a semiconductor diode, comprising:
   a) a low-voltage power supply configured to provide a voltage margin of less than about one volt above a forward conduction voltage of the diode;
   b) a series resistance element dimensioned to limit peak current through the diode to a safe operating value without requiring bulky heatsinking; and
   c) a switching element configured to gate current flow in discrete conduction intervals with intervening idle intervals,
wherein the circuit is dimensioned such that average thermal dissipation is reduced in proportion to the idle interval, thereby enabling a total driver mass of less than ten grams.
2. The driver circuit of item 1, wherein the series resistance element comprises a length of resistive wire, film, or trace weighing less than one gram.
3. The driver circuit of item 1, wherein the diode is a laser diode and the conduction intervals are one second or less with idle intervals at least five times longer than the conduction interval.
4. The driver circuit of item 1, wherein the switching element comprises a MOSFET having an associated local capacitor and snubber network sized only to absorb transients of the gated pulses.
5. The driver circuit of item 1, wherein the circuit achieves a current supply of at least five amperes with a total driver weight of less than five grams.
6. The driver circuit of item 1, wherein the thermal management is provided by a conductive pad or thin fin structure of less than one gram mass.
7. The driver circuit of item 1, wherein the ratio of idle interval to conduction interval is at least 10:1, such that the average heat load is less than one watt despite peak diode dissipation exceeding five watts.
8. The driver circuit of item 1, wherein the circuit is integrated into an airborne platform selected from drones, balloons, or aircraft, the airborne platform thereby achieving high-current optical emission with negligible payload penalty.
9. The driver circuit of item 1, wherein the low-voltage supply provides 1.8 volts, the diode forward conduction voltage is about 1.4 volts, and the resistance element is about 0.086 ohm, thereby limiting the diode current to between 4.7 and 7 amperes over its operating range.
10. The driver circuit of item 1, wherein the conduction interval is preconfigured or programmably limited to a duration that ensures diode safe operation without need of continuous-duty constant current regulation.
11. A method of operating a semiconductor diode on an airborne platform, comprising:
   a) supplying a voltage less than one volt above the forward conduction voltage of the diode;
   b) limiting current by a lightweight resistive element;
   c) gating current with a switch during discrete conduction intervals; and
   d) dissipating heat passively during idle intervals that are at least five times longer than the conduction intervals,
whereby the diode is driven at multi-ampere levels without requiring a constant current regulator or bulky heatsink.
12. The method of item 11, wherein the diode is a laser diode, the conduction interval is about one second, and the idle interval is about ten seconds.

### Embodiment AP: Optical Pilot-Beam and Working-Bean Alignment for Vision-Guided Pest Control and Related Platforms

An optical targeting apparatus uses a dichroic beam-combiner to align a visible or infrared pilot beam coaxially with a high-power working beam so that the pilot beam marks the eventual energy delivery location. The optical unit may be integrated into airborne or ground platforms and steered by servos, platform attitude, or actuated mirrors under vision feedback. Patterned pilot illumination may improve monocular depth estimation. Technical effects include reduced parallax, improved focus placement, and higher hit probability with lower power and latency. Methods, systems, and computer-readable media are disclosed. Interoperable interfaces, data logging, and fallback modes support deployment, verification, and monetization.

### Background

Selective neutralization of agricultural pests is difficult due to small target size, motion, and uncertain range. Conventional mechanical swatters or chemical sprays can be imprecise or environmentally harmful. Optical approaches can deliver energy precisely, but aligning an invisible or poorly visible high-power beam to a moving insect at a specific focal plane is challenging, particularly from mobile platforms subject to vibration and wind. A reliable, externally observable indicator of the working beam's delivery location, together with range estimation and closed-loop steering, can materially improve accuracy and efficiency while reducing collateral effects.

### Summary

Disclosed are optical units in which a pilot beam is optically aligned with a high-power working beam by a dichroic combiner so that the pilot beam serves as a targeting proxy at and around the working focus. The unit may be mounted to drones, rovers, or robotic arms and steered by servos, platform attitude, MEMS scanners, or fast-steering mirrors, with vision-based feedback tracking the pilot spot relative to a target insect. Patterned pilot illumination may enhance monocular depth estimation. Control logic regulates energy delivery to maintain safety while achieving neutralization. Interfaces, logging, calibration, environmental compensation, and fallback modes are described to facilitate robust deployment and verification.

### Description of the Drawings

For clarity of exposition, an optical layout may be depicted with elements labeled as follows: pilot-beam source (1), dichroic beam-combiner (2), final focusing lens (3), first collimating optic (4), high-power laser source (5), optical housing or enclosure (6), pilot beam (7), working beam (8), and focal point or working plane (9). The Anchor section below provides a formal description of the relationships among these elements suitable for accurate reconstruction of embodiments.

### Detailed Description

### Gentle Introduction

In practical terms, the system shines a harmless, easy-to-see pilot spot where the powerful, less visible working beam will land. The two beams share the same path thanks to a filter-like mirror that passes one color and reflects another, allowing the pilot spot to be used by cameras and software to aim precisely. The platform moves or nudges tiny internal mirrors until the pilot spot and the insect coincide at the correct distance where the powerful beam is sharpest. Only then does the system deliver the brief burst of energy needed to neutralize the insect, minimizing waste and collateral heating.

This invention relates to optical targeting and energy delivery systems, and more particularly to pest control apparatus employing a pilot beam for alignment and a high-power working beam for neutralization of target insects. The invention further relates to methods and apparatus for optically aligning multiple beams by means of a dichroic beam-combiner, and to integration of such optical units into airborne or ground vehicles, robotic arms, or other platforms for precise, vision-guided pest control in agricultural environments. It can also be used for military applications.

### INCORPORATION BY REFERENCE

The entirety of PCT/BG2025/050006 (photonic insecticides—laser drone) is hereby incorporated by reference into the present application as though fully set forth herein. Any embodiment of the present disclosure may be combined with any feature, claim, or technique disclosed in said PCT application. The present application is expected to include the full content of the referenced application, and any combinations thereof, in later filings claiming priority hereto.

### Anchor:

### Formal Description:

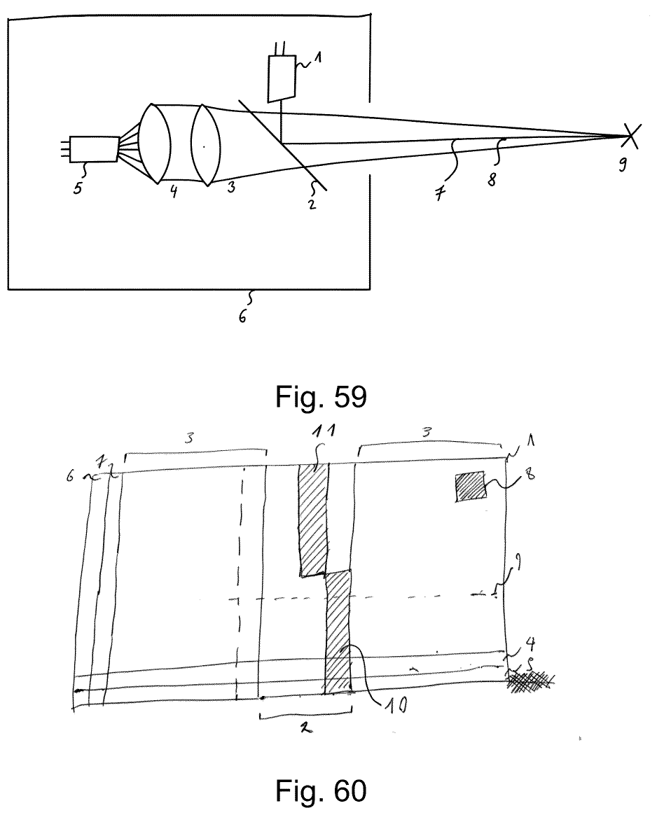

FIG. 59 shows one embodiment of this invention, in particular inside the optical housing (6), the high-power laser source (5) emits a divergent working beam (8) that is collimated by the first collimating optic (4) and then focused by the final focusing lens (3) toward the focal point (9). On its way to the target, the converging working beam passes through the dichroic beam-combiner (2), which is positioned at approximately 45° and transmits the working beam's wavelength substantially without deviation. The pilot-beam source (1) emits a collimated pilot beam (7) directed toward the dichroic beam-combiner (2) at a 45° incidence. The combiner reflects this beam by about 90°, redirecting it so that it becomes coaxial with the working beam beyond the combiner. The collimated pilot beam then follows the same axis as the converging working beam and intersects the focal point (9) without itself being focused by the final focusing lens (3). In this arrangement, the dichroic beam-combiner optically aligns the pilot beam with the working beam so that the pilot beam provides accurate visual or sensor-based targeting while the working beam delivers concentrated energy to the exact intended location.

### Terminology Notes

The high-power laser source (5) is also referred to as the kill laser module, and its output working beam (8) may also be called the kill beam. The first collimating optic (4) corresponds to the collimating lens, while the final focusing lens (3) may simply be called the focusing lens. The dichroic beam-combiner (2) may also be referred to as a dichroic mirror. The pilot-beam source (1) is also known as the pilot laser module, aiming laser, or seeking laser, and the pilot beam (7) may be called the aiming beam or seeking beam. The focal point (9) is sometimes referred to as the target location or working plane. The term powerlaser, used in some claims as a single word, is synonymous with power laser, power laser source, and the high-power laser source (5), and the term optically aligned as used herein encompasses coaxial, paraxial, and offset-calibrated alignments that yield co-location at or around the working plane (9) as described. The enclosure (6), or the optical unit as a whole, may be aimed toward the target by various positioning mechanisms. In some embodiments, this may be achieved by (a) one or more servos or actuators that physically reorient the optical unit; (b) a drone or robotic arm that adjusts its own body orientation to aim the optical unit; (c) an actuated mirror, such as a MEMS device or a fast-steering mirror (FSM), that redirects the beams without moving the housing; or (d) any combination of the foregoing. A mono or stereo camera system may be configured to monitor the location of the pilot beam (7) relative to the target insect, with the image data processed by a controller or processor. In some implementations, the pilot beam may be modulated, for example blinked or pulsed, to increase its visibility and detectability by the vision system against background reflections. Based on this analysis, the system may command the selected positioning mechanism or mechanisms (a-d) to adjust the aim so that the pilot beam is brought into alignment with the target prior to firing the working beam (8). The term effective focus region as used herein may denote an axial interval centered on the focal point (9) within which the beam diameter remains within a selected factor of its minimum and the fluence at the target exceeds a neutralization threshold for a given dwell, thereby capturing practical depth of focus for control purposes. In some embodiments, the pilot laser and the powerlaser may be distinct physical emitters or may be realized by a single light source operated in distinct modes or wavelengths, including time-division multiplexing of low-power pilot emission and high-power working emission, dual-wavelength or frequency-converted outputs, and power-scaled operation that produces a pilot spot below a damage threshold and a working exposure above the neutralization threshold along a common optical path, whereby optical alignment is satisfied by identity of propagation in at least one mode.

### Example Implementations

In one embodiment, the optical unit is rigidly mounted to a drone equipped with a stereo vision system. The stereo cameras capture images of the target area, enabling direct depth estimation. The drone's flight control system adjusts its position and attitude to brⁱng the pilot beam (7) into alignment with the target insect, with the objective of positioning the insect within the working beam's focal point (9) or within the near- and far-field regions immediately in front of and behind that point, where the beam remains effectively focused. Once alignment is achieved, the working beam (8) is fired.

In another embodiment, the optical unit is mounted to a drone via a two-axis servo gimbal. The drone is equipped with a mono camera, and distance to the target is estimated by mono depth estimation, which may be based on apparent target size, known insect dimensions, or neural network inference.

The gimbal servos adjust the orientation of the optical unit so that the pilot beam is directed onto the target, again aiming to position the insect within the focal point or effective focus region of the working beam prior to firing.

In a further embodiment, the optical unit is mounted on a ground-based rover. The rover navigates to within effective range of the target, using onboard sensors to determine target position. The rover then either repositions its chassis or uses an integrated pointing mechanism to aim the optical unit so that the pilot beam is centered on the insect and the insect is located within the focal point or effective focus region of the working beam.

In yet another embodiment, the optical unit is mounted at the end of a robotic arm. The arm may be fixed to a stationary platform, a vehicle, or another mobile base. Using visual or sensor input, the arm manipulates the position and orientation of the optical unit to place the pilot beam on the insect, ensuring that the insect is positioned within the focal point or effective focus region of the working beam before energy delivery.

In a further variation, the aiming is achieved without physically reorienting the optical housing, by using an actuated mirror system inside the housing. For example, a MEMS scanning mirror or a fast-steering mirror (FSM) may be positioned in the beam path to redirect the pilot and working beams toward the target. On a drone, the MEMS or FSM can make fine, high-speed corrections while the drone's flight control handles coarse positioning. On a rover, the MEMS or FSM may provide all necessary beam steering for targeting within the rover's range of motion, eliminating the need for heavy mechanical gimbals. In both cases, the mirror control system receives feedback from a mono or stereo vision module that tracks the position of the pilot beam relative to the target insect, ensuring the insect is positioned within the focal point or effective focus region before the working beam is fired. All of these techniques for aiming and beam alignment may be used individually or in any combination. For example, a drone may employ coarse alignment by adjusting its attitude, intermediate alignment via a servo gimbal, and fine alignment using a MEMS or FSM mirror system, all operating in concert under the control of a common vision and targeting processor to maintain the target insect in the effective focus region of the working beam. The optical unit may be integrated into any airborne or ground vehicle as part of a pest control apparatus, allowing adaptation to a wide variety of operational environments and crop types.

In software-forward deployments, the examples above may be orchestrated via a Model Context Protocol integration in which the optical unit exposes alignment, focus, safety, and emission controls as MCP tools that can be invoked by an on-board or remote agent. A representative mono-camera gimbal case proceeds by acquiring a frame, invoking a detect target tool that returns a target bounding box and a pilot spot centroid, invoking align to target with the planar error and an inferred or measured range, waiting until the tool reports an aligned state with residual error below a threshold for a hold time, invoking focus_set or focus_auto if range indicates defocus, and finally invoking authorize_emission with selected power and dwell parameters subject to safety predicates. An example MCP request and response for the alignment stage may be expressed as follows inline JSON: {“tool”:“align_to_target”, “arguments”:{“target”:{“bbox”:[120,85,160,130]}, “pilotSpot”:{“x”:142.3, “y “:102.7}, “range_m”:1.8, “hold_ms”:30}, “id”:“b7”} and {“id”:“b7”, “result”:{“aligned”:true, “residual_px”:{“x”:0.4, “y”:0.6}, “focusOK”:true, “timestamp”:“202 5-05-17T12:03:45.128Z”}}. A representative log or telemetry record that the unit may emit for auditing and external observability in these examples may be expressed as inline JSON:

{“timestamp”:“2025-05-17T12:03:45.512Z”,“pilotCode”:“101011”,“target”:{“id”:“hex-42”,“bbox”:[12
0,85,160,130]},“pilotSpot”:{“x”:142.7,“y”:103.1},“actuators”:{“gimbal”:[−0.6,1.2],“fsm”:[0.03,−0.02]
},“decision”:“fire”,“power_W”:22.5,“dwell_ms”:45,“outcome”:“neutralized”}.

### Depth Estimation Enhancement Via Patterned Pilot Beam

In some embodiments, the pilot beam (7) is modified to carry a spatial pattern to aid in depth estimation by a mono vision system. For example, the pilot beam may be split into three or more collimated sub-beams that converge toward the working beam's focal point (9), such that their projected spots on the target exhibit predictable spacing changes with distance. Alternatively, the pilot beam may be shaped into other distinctive patterns using refractive or diffractive optical elements, including optical elements designed to generate structured light patterns with multiple lobes or overtones. Such patterns create unique, measurable features in the captured image, enabling the mono vision system to infer depth with greater accuracy. The processing system may analyze the relative positions, sizes, or shapes of the projected sub-beams or patterns on the target surface to estimate distance, allowing the optical unit to position the target insect more precisely within the working beam's focal region. This approach can be combined with other alignment and aiming methods disclosed herein, including servo gimbal control, platform attitude adjustment, and fine steering via MEMS or FSM mirrors.

### Technical Effects

The disclosed embodiments may achieve one or more technical effects and associated advantages. Coaxial alignment of the pilot beam (7) and the working beam (8) via the dichroic beam-combiner (2) may reduce parallax to near zero at and around the focal point (9), thereby decreasing spot-placement error and alignment latency. Because the pilot beam is observable while the working beam is not necessarily observable, this coaxiality may cause the visible or sensed pilot spot to be a reliable proxy for the eventual energy delivery location, increasing hit probability and reducing required dwell time and power. Transmitting the working beam through the dichroic beam-combiner while reflecting the pilot beam may reduce aberration and beam wander for the higher-power path, maintaining beam quality at focus and improving fluence consistency on target. Patterned pilot beams generated by refractive or diffractive optics may improve monocular depth estimation accuracy, enabling the controller to place the target within the effective focus region more often, thereby raising neutralization success rates while limiting collateral heating. Implementations using MEMS or fast-steering mirrors may provide high-bandwidth beam pointing with lower inertia than gimballed housings, which may reduce pointing overshoot and enable tracking of moving insects, while permitting the platform to remain lighter and more energy efficient. Autofocus, varifocal, or zoom optics may maintain spot size near the diffraction limit across a range of standoff distances, which may hold delivered fluence above neutralization thresholds with fewer retargeting cycles. Environmental compensation, including adaptive optics or power scaling, may sustain targeting performance in wind, haze, or dust by stabilizing spot position and power density at the working plane. Closed-loop vision using pilot-beam modulation or coded blinking may improve signal-to-background ratio in the image stream, which may lower false positives and shorten controller decision time. Data logging of pilot-beam codes, timestamps, positions, and firing events may yield externally verifiable records of operation that enable auditing and system health monitoring without intrusive inspection. Interoperable interfaces may shorten integration cycles across different vehicles or controllers, expanding deployment contexts without redesign. Fallback modes such as reduced-power, longer-dwell operation or pilot-only marking may preserve the core alignment advantages under degraded power or safety constraints, maintaining partial operational capability.

In some embodiments, two pilot beams are emitted in a converging arrangement such that they intersect at or near the working focal region. The projected spots move relative to each other on the target surface depending on target distance, so that by measuring their separation or overlap in the captured image, the system can estimate range. This two-beam triangulation may be implemented with a pair of collimated emitters or by splitting a single pilot source, and may be used alone or in combination with other structured-light or stereo-vision ranging methods disclosed herein.

### Enablement

An implementation may be constructed by mounting a high-power laser source and a lower-power pilot laser source within a rigid optical housing that provides thermal management and alignment stability. The working beam may be emitted from the high-power source, collimated by a first optic positioned at the output aperture, and directed toward a final focusing lens at a fixed separation chosen to achieve a desired focal distance. A dichroic beam-combiner may be installed at a nominal 45° angle downstream of the final focusing lens such that it transmits the converging working beam substantially without deviation while reflecting the pilot wavelength. The pilot laser may be factory-collimated and positioned so that its collimated output is incident on the dichroic at approximately 45° and is reflected into coaxial alignment with the working path. Mechanical adjusters, such as tip/tilt stages and translation mounts, may be used during assembly to null lateral and angular misalignments by monitoring the pilot spot on a calibration target placed at the focal plane and verifying that the working beam's burn mark coincides with the pilot spot at multiple distances near the focal region. A camera module rigidly fixed to the housing may be calibrated to the beam axis by imaging known fiducials. Control electronics may drive servos, gimbals, or an internal MEMS or fast-steering mirror to aim the unit under software control. Safety interlocks, shutters, and power regulators may be integrated. Firmware may implement pilot-beam modulation, image acquisition, spot detection, target recognition, alignment control, and fire authorization subject to range and safety checks. In co-sourced embodiments, a tunable, dual-wavelength, or power-scaled laser may provide pilot emission and working emission in distinct time windows or wavelengths along the same optical axis, optionally with frequency-conversion optics to generate a visible or near-infrared pilot from an infrared working source, with calibration verifying co-location across modes within the effective focus region.

### Flows

A representative process may include target detection in captured images, pilot-spot localization, computation of error between the pilot spot and the detected target features, issuance of actuator commands to reduce error, confirmation that the target lies within a focus window derived from stereo depth or monocular inference possibly aided by pilot-beam patterns, and authorization of working-beam emission with selected power and dwell settings followed by post-shot verification and logging. The same sequence may be executed in a closed loop to track moving insects and may be partitioned between coarse and fine steering stages. In practical deployments, an initialization phase may power the pilot laser at a safe, low level, acquire camera frames to establish background statistics, load calibration parameters for camera-to-beam boresight and focus tables, and perform self-checks on interlocks, shutters, and actuator ranges. A targeting phase may then begin by running a detector that identifies candidate insects and a spot-localizer that extracts the pilot spot or pattern, computing a planar error vector between the target centroid and the pilot centroid and an axial error estimate based on stereo disparity or monocular cues derived from structured pilot patterns or apparent size. A control phase may apply a layered controller in which coarse actuators such as platform attitude or a gimbal reduce large errors, while fine actuators such as a MEMS or fast-steering mirror null residual error to within a gating threshold; concurrently, a focusing stage may step or continuously adjust autofocus, varifocal, or zoom optics to place the target within an effective focus region defined by measured or inferred range, with confirmation based on image sharpness, pilot-pattern geometry, or auxiliary range sensors. A firing decision may be gated by satisfaction of alignment tolerances in both lateral and axial dimensions for a hold time, verification that safety predicates including geofence, human or animal detection, and arming state are true, and selection of power and dwell parameters from a policy that accounts for target type, environmental attenuation, and thermal limits. An emission phase may then open shutters and drive the powerlaser for a calibrated dwell while maintaining closed-loop pointing to compensate for motion. A verification phase may observe post-emission imagery to assess neutralization likelihood based on motion cessation or spectral change, log timestamps, actuator traces, pilot codes, and outcome metrics, and, if needed, schedule a follow-up shot or mark the target for manual action in fallback modes. The control loop may repeat at a frame rate set by camera and actuator bandwidths, and the phases may be reordered, fused, or partially omitted consistent with the Only limited by claims section, for example skipping autofocus when range is fixed or substituting time-of-flight measurements for monocular inference.

### External Observability

Externally visible or recordable behaviors may include encoded pilot-beam blinking synchronized with timestamped logs, actuator command traces, and event records of fire authorization and duration. These behaviors permit verification of operation without intrusive inspection and support field audits and potential infringement proofs based on observable inputs and outputs. In co-sourced embodiments, the low-power pilot signature may be emitted by the same source used for the working exposure in a time-multiplexed sequence, preserving external observability while preventing alignment drift between modes.

### Interoperability

Interfaces may include ROS topics, MAVLink messages, Ethernet or Wi-Fi sockets, serial or CAN bus links for command, telemetry, and time synchronization, enabling operation across heterogeneous vehicles and controllers without redesign of core optics or control software.

### Fallback Embodiments

When power or safety constraints limit operation, the system may employ reduced working-beam power with longer dwell times, or pilot-only marking for manual follow-up, while preserving the coaxial alignment and vision-guided targeting benefits described herein.

### Damages Maximization and Monetization

Usage may be logged securely for subscription or per-activation billing, with technical enforcement of rate limits and regional policies via geofencing, arming keys, and cryptographic authorization, thereby enhancing the economic value attributable to infringing deployments.

### Hold Up In Court

The claimed subject matter is directed to machines, manufactures, and processes with concrete optical structures and control operations, and therefore may be eligible under prevailing subject-matter standards. The written description, enablement, and best-mode obligations are addressed by the Anchor, Enablement, Technical effects, and Flows sections, which together provide structural layouts, calibration procedures, control sequences, and implementation details sufficient for a skilled person to make and use the disclosed units without undue experimentation across the alternatives cataloged in the continuation-ready itemized list. Claim terms are supported by explicit definitions and mappings. The terminology notes define optically aligned to include coaxial, paraxial, and offset-calibrated alignments that yield co-location at or around the working plane (9). The term effective focus region is expressly described as an axial interval centered on the focal point (9) where beam diameter and fluence satisfy neutralization criteria for a given dwell, providing an objective construction for claim interpretation and controller thresholds. None of the independent claims uses means-for language, and each recites concrete structural components or computer-executed operations to avoid inadvertent invocation of 35 U.S.C. § 112(f).

Non-obviousness may be supported by the integrated use of a dichroic beam-combiner to coaxially overlay a visible or infrared pilot beam with a high-power working beam while transmitting the high-power path substantially undeviated, thereby reducing aberrations and parallax near the focal plane in mobile, vision-guided contexts. The patterned pilot illumination that produces structured, depth-disambiguating features for monocular vision, in combination with closed-loop steering using servos and high-bandwidth MEMS or fast-steering mirrors, yields synergistic technical effects including reduced latency, improved focus placement, and higher neutralization probability with lower power and mass compared to approaches that rely on non-coaxial pointers, manual alignment, or purely stereoscopic ranging. The External observability and data logging features further provide encoded pilot-beam blinking synchronized to logs and actuator traces, enabling objective field verification and infringement proof through externally observable inputs and outputs without intrusive inspection.

For avoidance of doubt, examples and preferred parameter choices are provided to aid understanding and do not limit the scope. By way of example only, a green pilot laser and a near-infrared working laser transmitted through a 45° dichroic mirror within a thermally managed housing with a MEMS steering element and stereo or monocular cameras constitute a best-mode configuration at the time of filing, while alternatives across the listed wavelengths, optics, and steering mechanisms remain expressly contemplated. The structure of the independent claims at different abstraction levels (optical unit, method, system, and computer-readable medium) supports multiple enforcement avenues while the continuation-ready itemized list preserves additional claimable matter for future filings, thereby strengthening enforceability overtime.

The claims are patent-eligible because they recite specific improvements to the functioning of machines and optical assemblies rather than an abstract idea. The computer-executed steps in the method and computer-readable medium claims are tied to particular image acquisition, pilot-spot localization, actuator control, and emission authorization operations that are rooted in optical hardware and that improve beam placement accuracy and latency of a physical system. The computer-readable medium is expressly non-transitory and corresponds to tangible memory storing executable instructions, and therefore excludes transitory signals per se.

Definiteness and claim construction are supported by objective boundaries. Optically aligned, as defined herein, encompasses coaxial, paraxial, and offset-calibrated alignments that yield co-location at or around the working plane (9). An embodiment may demonstrate optically aligned by showing that the pilot spot and working-beam impact co-locate within a selectable tolerance at the focal point (such as within a multiple of the pilot spot radius) and remain within tolerance across small axial offsets that define the effective focus region. Effective focus region is defined as an axial interval centered on the focal point (9) in which beam diameter remains within a selected factor of its minimum and fluence at the target exceeds a neutralization threshold for a given dwell; these are measurable criteria using standard beam profilers or burn tests. Powerlaser is expressly defined as synonymous with high-power laser source, avoiding ambiguity. Where approximate angles such as approximately 45° are used, the specification teaches acceptable ranges and calibration routines that provide objective guidance to a skilled person. Objective compliance tests and boundaries are provided to further support definiteness and reliable enforcement. For example, optically aligned may be demonstrated when, after calibration, the centroid of the pilot spot and the centroid of the working-beam impact coincide within one to three pilot-spot radii at the focal point and remain within tolerance across the effective focus region, or when residual angular boresight error is less than about 0.5 mrad as measured with a beam profiler or burn card sequence at calibrated standoffs. Approximately 45° incidence for the combiner is supported by explicit operable ranges, for example 20°-70° and more typically 42°-48°, with calibration procedures that yield functionally equivalent alignment across that interval.

Enablement across the full scope is provided by concrete assembly, calibration, and control procedures. The Enablement and Anchor sections teach how to mount sources, select and place the dichroic beam-combiner at an incidence within an operable range, collimate and focus the working path, and use tip/tilt and translation stages to null misalignment. The Flows section, together with the Technical effects, teaches specific control operations including pilot-spot modulation, image acquisition, spot detection, target recognition, depth inference with or without structured pilot patterns, closed-loop error reduction via gimbals or steering mirrors, and firing authorization subject to range and safety checks. These teachings are sufficient for a skilled person to practice embodiments across the alternatives listed. To reduce potential design-arounds, the disclosure expressly contemplates single-source, dual-mode embodiments in which the same light source provides both pilot and working emissions in distinct modes while remaining optically aligned by virtue of a common propagation path. Representative species supporting the claimed genera are expressly described, including dichroic, polarization, fiber, pellicle, cube, metasurface, or holographic combiners that achieve common-path alignment, and MEMS, galvo, fast-steering mirrors, or acousto-optic or electro-optic deflectors that perform beam steering. These alternatives are interchangeable for the claimed functions to a skilled person using the assembly and calibration steps taught herein.

To the extent algorithmic disclosure is relevant to software-implemented claims, the description teaches concrete algorithms, including intensity-weighted centroiding or matched-filter detection of the pilot spot or pattern in image frames, thresholding with temporal coding to reject background, proportional-derivative or model-predictive control to drive actuators that reduce spot-to-target error, range gating based on stereo disparity or monocular inference of structured patterns, and safety interlocks with supervised state transitions that block emission unless alignment and range conditions are met. These steps are tied to specific sensors and actuators and therefore constitute more than a result-oriented command. All claimed computer-executed steps are tied to physical sensors, actuators, and emission hardware and are not performable as purely mental processes. Storage media are non-transitory. The disclosure does not rely on means-plus-function claiming and avoids step-plus-function language, reducing vulnerability under 35 U.S.C. § 112(f).

The claims are structured to avoid divided infringement. Each recited step in the method and each function of the system is performed or controlled by a single entity operating the optical unit and its associated controller. Even where remote computation or vehicle autopilots are used, the claims are practiced by the party that controls the unit and executes the software that detects the pilot spot, issues actuator commands, and authorizes emission, thereby mitigating multi-actor concerns. Scope is preserved without disclaimer. Examples, ranges, and preferred values are illustrative rather than restrictive, and equivalents that perform substantially the same function in substantially the same way to achieve substantially the same result are contemplated and reserved.

### Workaround Resistance

The disclosure is drafted to make design-arounds impractical. Attempts to substitute different combining optics, steering mechanisms, or source configurations remain within scope because the claims and supporting description cover optically aligned pilot and working emissions achieved by dichroic, polarization, fiber, pellicle, cube, metasurface, or holographic combiners, and by single-source, dual-mode operation along a common path. The definition of optically aligned expressly includes coaxial, paraxial, and offset-calibrated alignments that co-locate at or around the working plane (9), preventing avoidance by introducing calibrated offsets or by changing the relative ordering of optics. The method and computer-readable medium claims capture closed-loop behaviors in which a pilot emission is detected and used to steer actuators before authorizing working emission, such that changing platform type, protocol, or actuator does not avoid infringement. External observability via coded pilot blinking synchronized to logs and firing events allows proof of infringement even where internals are inaccessible. The continuation-ready itemized list further catalogs alternative embodiments for future claim sets so that variations in wavelengths, emitter types, element ordering, or steering architectures remain covered across continuations.

Objective, external indicia facilitate proof of infringement and damages. Encoded pilot-beam blinking synchronized to logged timestamps, actuator command traces, and firing events provides a verifiable signature observable with standard cameras and RF or bus sniffers. Because these signatures can be recorded without opening an enclosure, they support field audits and infringement proofs based on inputs and outputs that are external to the device.

With respect to obviousness, in addition to the technical synergies described, secondary considerations may be shown where applicable, including satisfaction of a long-felt need for precise, chemical-free pest control from mobile platforms, commercial adoption potential evidenced by interoperability with common robotics stacks, and performance improvements such as reduced power consumption and mass from substituting high-bandwidth steering mirrors for heavy gimbals. The specification's data-logging and compliance features further support nexus by tying claimed technical elements to deployable systems and usage models.

Jurisdictional considerations such as written description and best mode are satisfied by explicit definitions, a disclosed best-mode configuration, and cataloged alternatives with objective assembly and calibration guidance. The claims avoid means-plus-function language and recite structural components or computer-executed operations with sufficient specificity to withstand 35 U.S.C. § 112 challenges while preserving breadth consistent with the disclosure.

### Continuation-Ready Itemized List:

Embodiments can be described by the following itemized list: (i) a pilot beam wavelength that may be visible, near-infrared, or infrared, including but not limited to green, red, or 808-1550 nm bands; (ii) a working beam wavelength that may be ultraviolet, visible, near-infrared, or infrared, selected to optimize absorption by target tissue while reducing collateral damage; (iii) a dichroic beam-combiner that may operate by wavelength, polarization, or both, at an incidence angle that may be approximately 45° or any angle between about 20° and 70°; (iv) a beam alignment mechanism in which the pilot beam is made coaxial with, paraxial to, or offset-calibrated relative to the working beam to account for focus-induced convergence; (v) pilot-beam modulation that may include continuous-wave operation, pulsed operation, coded blinking, or spread-spectrum temporal patterns to improve detectability; (vi) pattern generation optics for the pilot beam that may include diffractive optical elements, refractive microlens arrays, or holographic elements creating multiple lobes, grids, or structured light; (vii) focusing optics that may be fixed-focus, motorized zoom, or varifocal, with autofocus based on image sharpness, range sensors, or triangulation; (viii) range estimation that may use stereo vision, monocular depth inference, time-of-flight sensors, lidar, structured light evaluation, or sensor fusion thereof; (ix) beam steering that may use servos, gimbals, galvo scanners, MEMS mirrors, fast-steering mirrors, or acousto-optic/electro-optic deflectors; (x) platform integration that may include UAVs, multirotors, fixed-wing aircraft, ground rovers, tracked vehicles, stationary masts, or robotic arms; (xi) control electronics that may implement closed-loop tracking of the pilot spot relative to detected insect features using classical or machine-learning vision; (xii) energy delivery control that may regulate pulse energy, duty cycle, and dwell time to achieve neutralization while respecting safety thresholds; (xiii) safety interlocks that may include geofencing, human/animal detection, eye-safety sensors, arming keys, and emergency shutters; (xiv) calibration routines that may include automated coaxiality checks using a fiducial target, back-reflection sensing, or on-board reference photodiodes; (xv) environmental compensation that may account for wind, vibration, haze, fog, or dust via adaptive optics, beam expansion, or power scaling; (xvi) interoperability that may include interfaces such as ROS, MAVLink, Ethernet, Wi-Fi, CAN bus, or serial protocols for command and telemetry; (xvii) data logging that may record pilot-beam modulation codes, timestamps, position, and firing events to provide externally observable behavior; (xviii) thermal management that may include heat sinks, fans, liquid cooling, or phase-change materials within the optical housing; (xix) optics cleanliness maintenance that may include protective windows, air knives, or transparent hydrophobic/oleophobic coatings; (xx) target scheduling that may prioritize multiple detected insects based on confidence, proximity to the focal region, or motion prediction; (xxi) software embodiments implemented as a computer program or computer-readable medium storing instructions for detection, alignment, and firing control; (xxii) fallback embodiments that may use reduced power with increased dwell time, or pilot-only marking for manual follow-up, preserving the inventive alignment concept; (xxiii) power sources that may include batteries, tethered power, hybrid generators, or energy-harvesting aids; (xxiv) multi-beam variants that may include multiple pilot beams and/or multiple working beams combined or independently steered within one housing; (xxv) compliance features that may log usage for subscription or per-activation billing while enforcing technical usage limits; (xxvi) co-sourced embodiments in which a single light source provides both pilot and working emissions in distinct time, wavelength, or power modes, optionally using frequency conversion, and remains optically aligned by virtue of a common propagation path; (xxvii) alternative combining and common-path arrangements including fiber combiners, pellicle or cube beamsplitters, polarization combiners, metasurface or holographic combiners, and fiber-coupled common-aperture boresight optics providing alignment equivalent to dichroic arrangements; (xxviii) pilot emitter types that may include laser diodes, light-emitting diodes (LEDs), superluminescent diodes (SLEDs), filtered supercontinuum sources, or fiber-delivered sources provided that emission is collimated or patterned as taught; (xxix) element ordering variants in which a combiner may be placed before or after one or more focusing, collimating, or relay optics, including telecentric and non-telecentric designs, with calibration preserving co-location at or around the effective focus region; (xxx) an optical unit that may comprise a pilot laser and a powerlaser that are optically aligned, the pilot laser and the powerlaser being realized by distinct sources or by a single source operated in distinct modes or wavelengths; (xxxi) the optical unit wherein the pilot laser may be a green laser; (xxxii) a UAV or ground mobile platform that may comprise the optical unit described; (xxxiii) a method that may comprise emitting a working beam from a powerlaser, emitting a pilot beam from a pilot laser, optically aligning the pilot beam with the working beam, aiming the aligned beams at a target, and causing the powerlaser to deliver energy to the target when alignment is achieved; (xxxiv) a non-transitory computer-readable medium that may store instructions which, when executed by one or more processors associated with an optical unit comprising a pilot laser and a powerlaser, cause detection of a location of a pilot beam in image data relative to a target, cause commands to actuators to align the pilot beam with the target, and cause emission of the powerlaser responsive to alignment; (xxxv) a system that may comprise a mobile or stationary platform, a vision module, one or more actuators for aiming, and the optical unit, wherein the vision module provides feedback to maintain a target within an effective focus region of a working beam prior to emission; (xxxvi) the optical unit wherein a dichroic beam-combiner may be arranged to transmit a working wavelength of the powerlaser and reflect a pilot wavelength of the pilot laser so as to achieve the optical alignment; (xxxvii) the optical unit wherein the dichroic beam-combiner may be positioned at approximately 45 degrees; (xxxviii) the optical unit further comprising a focusing optic that may be arranged to focus the working beam to a focal point at a selected standoff distance; (xxxix) the optical unit wherein aiming may be performed by an actuated mirror selected from a MEMS mirror, a galvo, or a fast-steering mirror; (xl) the optical unit wherein the pilot beam may be temporally modulated with a coded blinking sequence to improve detectability; (xli) the method further comprising estimating range by analyzing a structured pattern carried by the pilot beam in image data; (xlii) the method wherein closed-loop control may drive at least one of a gimbal, a servo, or an actuated mirror to reduce an error between a detected pilot spot and a detected target feature; (xliii) the computer-readable medium wherein the instructions may further cause logging of timestamps, actuator commands, pilot-beam codes, and emission events; (xliv) the system wherein the platform may implement one or more interfaces selected from ROS, MAVLink, Ethernet, Wi-Fi, CAN bus, or serial to exchange command and telemetry; (xlv) the system further comprising safety interlocks that may include at least one of geofencing, an arming key, a shutter, or human or animal detection; (xlvi) the method further comprising enforcing a reduced-power, increased-dwell fallback mode responsive to power or safety constraints while preserving pilot-beam alignment and aiming; (xlvii) the optical unit wherein the pilot beam may comprise multiple sub-beams whose relative spacing varies with distance to aid monocular depth estimation; (xlviii) the system wherein autofocus, varifocal, or zoom optics may maintain a spot size within a threshold over a range of distances defining an effective focus region; (xlix) the computer-readable medium wherein the instructions may further cause enforcement of subscription or per-activation usage via cryptographic authorization and geofenced policy checks.

### Claim Support, Broadening, and Claim Layering

The claims are supported by the foregoing description including the Anchor, Example implementations, Technical effects, and the itemized list. Alternatives and optional features are expressly described in the itemized list to broaden scope. Independent claims span an optical unit, a method, a computer-readable medium, a system, and a platform embodiment while maintaining fewer than twenty independent claims, with additional claimable matter preserved in the itemized list for continuations. For avoidance of doubt, claim terminology maps to numbered elements in the Anchor as follows: pilot laser corresponds to the pilot-beam source (1), powerlaser corresponds to the high-power laser source (5), pilot beam corresponds to (7), and working beam corresponds to (8). The pilot laser and the powerlaser may be implemented as separate emitters or as a single source operated in distinct modes or wavelengths, as described, such that single-source, dual-mode embodiments fall within the functional scope of the claims.

### No Unneeded Limitations

Core claims avoid unnecessary restrictions by requiring only elements that are fundamental to competitive implementation, namely a pilot laser optically aligned with a power laser and the control required to aim and emit upon alignment, leaving wavelengths, optics, steering mechanisms, and platforms open.

### Drafting Conventions

Terms such as “may,” “can,” and “for example” denote optional or illustrative features and do not limit scope. The description is provided in flowing paragraphs without bullet lists, with structured lists, where present, expressed inline to preserve breadth and readability. Unless stated otherwise, singular forms include the plural and vice versa.

### Only Limited by Claims

The scope of the present disclosure is limited only by the claims. Figures, drawings, flow descriptions, examples, parameter ranges, and best-mode configurations are illustrative embodiments and are not restrictive. Operations described in any sequence may be reordered, combined, partitioned, omitted, or executed concurrently unless a particular order is expressly required by the claim language. Hardware and software implementations may be substituted for one another where functionally equivalent, and components may be integrated, separated, or distributed without departing from the claimed subject matter. Names of signals, modules, or interfaces are exemplary and non-limiting, and substitutions or standard-conforming variants are contemplated. Approximate terms such as “about” or “approximately” encompass manufacturing tolerances and calibration adjustments taught herein.

FIG. 2 illustrates an optical arrangement in which a laser source (1) emits a beam (3) that is directed along an extended optical path by reflection from a first mirror (2A) and a second mirror (2B). The increased path length permits the beam (3) to diverge to a desired extent prior to being collimated by a lens element (4). The collimated beam is thereafter combined and optically aligned with a camera (6) through a dichroic element (5), such that the optical axis of the laser and the field of view of the camera are substantially coincident.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

An optical unit comprising a pilot laser and a powerlaser, wherein said pilot laser and said powerlaser are optically aligned, and wherein the pilot laser and the powerlaser are realized by distinct sources or by a single source operated in distinct modes or wavelengths.

2.

The optical unit of item 1, wherein said pilot laser is a green laser.

3.

A UAV or ground mobile platform comprising the optical unit of item 1.

4.

A method comprising emitting a working beam from a powerlaser, emitting a pilot beam from a pilot laser, optically aligning the pilot beam with the working beam, aiming the aligned beams at a target, and causing the powerlaser to deliver energy to the target when alignment is achieved.

5.

A non-transitory computer-readable medium storing instructions that, when executed by one or more processors associated with an optical unit comprising a pilot laser and a powerlaser, cause detection of a location of a pilot beam in image data relative to a target, cause commands to actuators to align the pilot beam with the target, and cause emission of the powerlaser responsive to alignment.

6.

A system comprising a mobile or stationary platform, a vision module, one or more actuators for aiming, and the optical unit of item 1, wherein the vision module provides feedback to maintain a target within an effective focus region of a working beam prior to emission of the working beam.

7.

The optical unit of item 1, wherein a dichroic beam-combiner is arranged to transmit a working wavelength of the powerlaser and reflect a pilot wavelength of the pilot laser so as to achieve the optical alignment.

8.

The optical unit of item 7, wherein the dichroic beam-combiner is positioned at approximately 45 degrees.

9.

The optical unit of item 1, further comprising a focusing optic arranged to focus the working beam to a focal point at a selected standoff distance.

10.

The optical unit of item 1, wherein aiming is performed by an actuated mirror selected from a MEMS mirror, a galvo, or a fast-steering mirror.

11.

The optical unit of item 1, wherein the pilot beam is temporally modulated with a coded blinking sequence to improve detectability.

12.

The method of item 4, further comprising estimating range by analyzing a structured pattern carried by the pilot beam in image data.

13.

The method of item 4, wherein closed-loop control drives at least one of a gimbal, a servo, or an actuated mirror to reduce an error between a detected pilot spot and a detected target feature.

14.

The non-transitory computer-readable medium of item 5, wherein the instructions further cause logging of timestamps, actuator commands, pilot-beam codes, and emission events.

15.

The system of item 6, wherein the platform implements one or more interfaces selected from ROS, MAVLink, Ethernet, Wi-Fi, CAN bus, or serial to exchange command and telemetry.

16.

The system of item 6, further comprising safety interlocks including at least one of geofencing, an arming key, a shutter, or human or animal detection.

17.

The method of item 4, further comprising enforcing a reduced-power, increased-dwell fallback mode responsive to power or safety constraints while preserving pilot-beam alignment and aiming.

18.

The optical unit of item 1, wherein the pilot beam comprises multiple sub-beams whose relative spacing varies with distance to aid monocular depth estimation.

19.

The system of item 6, wherein autofocus, varifocal, or zoom optics maintain a spot size within a threshold over a range of distances defining an effective focus region.

20.

The non-transitory computer-readable medium of item 5, wherein the instructions further cause enforcement of subscription or per-activation usage via cryptographic authorization and geofenced policy checks.

### Embodiment APE: Coaxial Pilot and Working Beam Optical Targeting System for Pest Control and Related Platforms

An optical unit employs a visible pilot laser beam that is optically aligned coaxially with a high-power working beam by a dichroic beam-combiner. The pilot beam provides visual or machine-vision targeting while the working beam delivers energy at a focal point for neutralizing insects. The unit can be integrated into drones, rovers, robotic arms, or stationary platforms and may use mono or stereo vision, structured pilot-beam patterns, and optional MEMS or fast-steering mirrors for fine alignment. Fallback configurations, safety interlocks, interoperability features, and subscription-based licensing with tamper-evident usage records are disclosed. Methods, systems, and computer-readable media are described.

### Gentle Introduction

At a high level, the apparatus uses two beams that share the same line of sight so that a user or a camera can see where energy will be delivered before any high power is applied. A low-power visible pilot beam acts as a pointer that is easy to detect in video or by the human eye. A dichroic beam-combiner is placed so that it reflects the visible pilot beam onto the same axis that the high-power working beam already travels. A focusing lens concentrates the working beam to a small focal point where neutralization occurs, while the pilot beam remains collimated but still intersects that same focal point. Intuitively, if the bright pilot spot is on the insect, the working beam's focus will coincide there when fired. The optical unit may ride on drones, rovers, or robotic arms. Coarse aiming may be achieved by moving the vehicle or gimbal, while fine aiming may be handled by a fast internal mirror. A vision module looks for the pilot spot relative to an insect and commands small corrections until the spot sits where the focus will be. Safety interlocks, fallback modes, and optional subscription-controlled features support practical deployment and verifiable use without exposing internal implementation details.

### Examples

The following step-by-step walkthroughs illustrate concrete operation paths that can be directly exercised in laboratory or field tests and orchestrated via Model Context Protocol.

In a UAV stereo-vision example with a fast-steering mirror, the device powers up, performs self-test, and exposes an MCP tool. An external orchestrator issues {“type”:“mcp.tool.call”, “name”:“align_and_fire”, “args”:{“target”:{“x”:0.47, “y”:0.58}, “range_m”:1.4, “mode”:“stereo”, “pattern”:“spot”, “safety”:{“max_dwell_ms”:100, “defocus margin_mm”:0.6}}}. The controller verifies interlocks including enclosure closed, temperature within limits, and no person or animal detected. The stereo cameras acquire synchronized frames and the pilot beam is blink-modulated; the vision pipeline demodulates and localizes the pilot centroid while triangulating target range. The fast-steering mirror applies high-bandwidth corrections to drive the pilot centroid to the insect centroid while the focusing lens sets the estimated best-focus position. On convergence within tolerance, the controller removes the temporary defocus margin, enables the working beam for a bounded dwell, and then disables emission. Telemetry is returned as

{“type”:“mcp.tool.result”,“name”:“align_and_fire”,“ok”:true,“telemetry”:{“pilotDetections”:11,“firing
s”:1,“focusError_mm”:0.1,“range_m”:1.39}}. A usage record is appended to the tamper evident
ledger as
{“ts”:“2025-05-06T09:15:12Z”,“device”:“UAV42”,“fw”:“1.3.2”,“geo”:{“lat”:36.12,“lon”:−115.17},“op
”:{“pilotDetections”:11,“firings”:1,“on_s”:0.22,“avgW”:7.5,“peakW”:12.0},“features”:[“fsm”,“stereo”
],“sig”:“BASE64_SIGNATURE”}.

In a rover mono-vision example with a tri-dot structured pilot, the rover navigates to approximately the working distance using onboard odometry. The controller enables a tri-dot pilot pattern and captures frames while modulating the pattern. The vision module isolates the pattern signature and measures spot coordinates and spacings, producing an inline result such as {“pattern”:“tri_dot”, “spots”:[{“u”:512, “v”:403},{“u”:548, “v”:401},{“u”:530, “v”:438}], “spacing_px”: [36,41,29]}. A calibrated model maps the measured spacings to an estimated range, and the gimbal or chassis orientation is adjusted to place the pilot centroid on the insect. If range uncertainty exceeds a threshold, a short z-dither sweep advances the focusing lens through several positions while issuing low-energy pulses, after which a final high-confidence pulse is emitted at the best-focus position subject to dwell and safety limits. The orchestrator may request a concise outcome report via {“type”:“mcp.tool.call”, “name”:“get last action”, “args”: { }} and receive {“type”:“mcp.tool.result”, “name”:“get_last_action”, “ok”:true, “data”:{“result”:“neutralized”, “range_m”:0.92, “focusSet_mm”:1.8, “zDither”:“used”}}. These steps provide externally observable behavior and data structures that can be repeated to verify performance without access to internal implementation.

### Background

Managing crop-damaging insects often relies on chemical pesticides or manual intervention, each with drawbacks related to environmental impact, labor cost, and precision. Laser-based neutralization can provide precise, non-chemical control but requires accurate, rapid alignment to small moving targets at varying distances in cluttered scenes. Conventional single-beam approaches and non-coaxial indicators complicate targeting and increase complexity or error. There is a need for a compact, robust optical architecture that provides intuitive, externally visible alignment cues and supports automated, vision-guided targeting across mobile and stationary platforms.

### Summary

Disclosed is an optical unit in which a pilot laser beam is coaxially aligned with a high-power working beam using a dichroic beam-combiner positioned to reflect the pilot beam and transmit the working beam substantially without deviation. A focusing lens establishes a working focal point while the collimated pilot beam intersects that focal point without itself being focused, enabling accurate visual or sensor-based targeting. The optical unit may be mounted to drones, rovers, or robotic arms and may employ coarse platform motion, intermediate gimbal motion, and fine steering via MEMS or fast-steering mirrors. Vision systems detect the pilot-beam location relative to target insects and command alignment so that the insect is within the working beam's focal region before firing. Structured pilot-beam patterns can enhance mono-vision depth estimation. Fallback embodiments, safety measures, interoperability, and subscription-based feature control and audit are provided. Method, system, and computer-readable medium claims are supported. In some embodiments, functional coaxiality may be achieved by calibrated steering such that the pilot spot and working focal region coincide within a specified tolerance across a working distance range.

### Technical Effects

The coaxial alignment of a visible pilot beam with a high-power working beam via a dichroic beam-combiner produces concrete technical effects that reduce targeting error and increase neutralization efficiency. Because the combiner transmits the converging working beam while reflecting a collimated pilot beam onto the same axis, parallax is effectively eliminated beyond the combiner, so the visible pilot spot serves as an externally verifiable proxy for the eventual energy delivery location over a useful depth range. Positioning the final focusing lens upstream of the combiner so that it does not act on the pilot beam reduces the risk of unintended high-irradiance pilot hot spots while still allowing the pilot to intersect the working focal point, improving safety and alignment confidence. When a MEMS or fast-steering mirror is placed after the combiner, both beams are steered together, preserving coaxiality under high-bandwidth corrections that reject platform jitter and target motion, thereby decreasing miss distance, required dwell time, and collateral heating. Structured pilot-beam patterns yield measurable image features that enable monocular depth estimation with higher accuracy, which in turn allows the controller to place insects within the effective focal region more reliably with fewer focus sweeps. The z-dither focus sweep fallback delivers a probabilistic guarantee of at least one in-focus pulse when range estimates are uncertain, reducing reliance on complex sensors while maintaining efficacy. Stereo-vision embodiments provide direct triangulation that shortens alignment latency and improves hit rate on moving insects. Safety interlocks that monitor for humans, animals, reflective hazards, and back-reflection provide verifiable conditions that gate emission, reducing the likelihood of unsafe exposures. Environmental hardening, including thermally managed laser modules and sealed housings, maintains optical registration across vibration and temperature excursions, sustaining coaxiality and calibration in field conditions. Interoperability features, including an MCP interface and signed usage records, enable external orchestration and audit without revealing internals, creating observable system behaviors that facilitate verification and reduce integration overhead.

### External Observability

To enable proof of infringement and black-box verification, embodiments may define explicit, externally observable inputs, outputs, and behaviors that do not require access to internal implementation. Inputs may include documented command interfaces over standard transports such as MCP tool calls, where align_and_fire, get_last_action, and get_usage_summary accept declared JSON arguments including target image coordinates, optional range estimates, pattern selections, and safety parameters. Outputs may include machine-readable MCP tool results that report convergence status, focus error in millimeters, measured or estimated range, number of firings, and any interlock blocks, together with signed usage receipts that contain timestamps, device identifiers, firmware versions, geolocation when permitted, feature flags active at the time of operation, and cryptographic signatures produced by a secure element. Externally verifiable self-tests may be conducted by presenting a calibration card at specified distances and initiating a published self-test that projects a diagnostic pilot pattern followed by a low-energy working pulse. The device may then produce a signed congruence report that states the measured separation between the pilot indication and the working pulse mark within a stated tolerance across distance steps and environmental conditions, and this report may be retrievable via a local service endpoint or cloud API for later audit. Pilot modulation parameters such as blink frequency and duty cycle may be specified and externally detectable, allowing third parties to demodulate the pilot in video to confirm spot localization and alignment behavior. Together these observable inputs and outputs define clear, repeatable procedures by which an independent laboratory could exercise the system, measure pilot-to-focus congruence, verify interlock enforcement, and confirm use of particular interoperability and licensing features without disassembling the product.

### Description of the Drawings

The apparatus is illustrated by reference numerals (1)-(9) as defined and described in the Anchor section below. The optical relationships, beam paths, and component functions are as stated in the formal description, with the dichroic beam-combiner aligning the pilot beam and working beam coaxially toward the focal point.

### Detailed Description

This invention relates to optical targeting and energy delivery systems, and more particularly to pest control apparatus employing a pilot beam for alignment and a high-power working beam for neutralization of target insects. The invention further relates to methods and apparatus for optically aligning multiple beams by means of a dichroic beam-combiner, and to integration of such optical units into airborne or ground vehicles, robotic arms, or other platforms for precise, vision-guided pest control in agricultural environments. It can also be used for military applications.

### Incorporation by Reference

The entirety of PCT/BG2025/050006 is hereby incorporated by reference into the present application as though fully set forth herein. Any embodiment of the present disclosure may be combined with any feature, claim, or technique disclosed in said PCT application. The present application is expected to include the full content of the referenced application, and any combinations thereof, in later filings claiming priority hereto. All essential material for enablement, written description, and best mode is contained in the present specification; the incorporated document provides non-essential supplemental detail and examples.

### Scope and Interpretation

The embodiments described herein are illustrative and not limiting. The scope of the invention is defined solely by the claims. Any figures, element numbers, examples, and specific parameter values are presented for example purposes only and do not limit the generality of the disclosure. Operations and flows may be performed in different orders, in parallel, iteratively, or with steps added or omitted, unless a particular order is expressly required by a claim. Components and modules may be implemented in hardware, software, firmware, or any combination thereof, and may be centralized or distributed. Unless expressly stated otherwise, terms such as may, can, and could indicate optional features, and recitations of a, an, or the are intended to include one or more. Numerical qualifiers such as approximately or about cover reasonable engineering tolerances and equivalents. Features disclosed in separate embodiments may be combined, and alternatives and equivalents are contemplated. For purposes of this disclosure, optically aligned or coaxial encompasses functional coaxiality in which the separation between a pilot-beam spot and the working-beam focal region projected into a common plane remains within a specified tolerance across a working distance range, whether achieved purely optically or with calibrated computational steering. Unless the context requires otherwise, references to a laser source may encompass coherent and quasi-coherent emitters including superluminescent diodes and VCSELs, and references to a pilot beam may encompass directed or collimated emissions from non-laser emitters such as LED arrays or scanned projectors, provided the emission yields a localizable spot or pattern suitable for alignment and detection. As used herein, computer-readable medium refers to a non-transitory storage medium and excludes transitory propagating signals.

### Anchor:

### Formal Description:

Inside the optical housing (6), the high-power laser source (5) emits a divergent working beam (8) that is collimated by the first collimating optic (4) and then focused by the final focusing lens (3) toward the focal point (9). On its way to the target, the converging working beam passes through the dichroic beam-combiner (2), which is positioned at approximately 45° and transmits the working beam's wavelength substantially without deviation. The pilot-beam source (1) emits a collimated pilot beam (7) directed toward the dichroic beam-combiner (2) at a 45° incidence. The combiner reflects this beam by about 90°, redirecting it so that it becomes coaxial with the working beam beyond the combiner. The collimated pilot beam then follows the same axis as the converging working beam and intersects the focal point (9) without itself being focused by the final focusing lens (3). In this arrangement, the dichroic beam-combiner optically aligns the pilot beam with the working beam so that the pilot beam provides accurate visual or sensor-based targeting while the working beam delivers concentrated energy to the exact intended location.

### Terminology Notes

The high-power laser source (5) is also referred to as the kill laser module, and its output working beam (8) may also be called the kill beam. The first collimating optic (4) corresponds to the collimating lens, while the final focusing lens (3) may simply be called the focusing lens. The dichroic beam-combiner (2) may also be referred to as a dichroic mirror. The pilot-beam source (1) is also known as the pilot laser module, aiming laser, or seeking laser, and the pilot beam (7) may be called the aiming beam or seeking beam. The focal point (9) is sometimes referred to as the target location or working plane. For clarity in the claims, the term powerlaser refers to the high-power laser source (5) and its associated working beam (8), and the term pilot emitter refers to the pilot-beam source (1) or any emitter configured to generate the pilot beam (7) as further described in Scope and interpretation.

The enclosure (6), or the optical unit as a whole, may be aimed toward the target by various positioning mechanisms. In some embodiments, this may be achieved by (a) one or more servos or actuators that physically reorient the optical unit; (b) a drone or robotic arm that adjusts its own body orientation to aim the optical unit; (c) an actuated mirror, such as a MEMS device or a fast-steering mirror (FSM), that redirects the beams without moving the housing; or (d) any combination of the foregoing. A mono or stereo camera system may be configured to monitor the location of the pilot beam (7) relative to the target insect, with the image data processed by a controller or processor. In some implementations, the pilot beam may be modulated, for example blinked or pulsed, to increase its visibility and detectability by the vision system against background reflections. Based on this analysis, the system may command the selected positioning mechanism or mechanisms (a-d) to adjust the aim so that the pilot beam is brought into alignment with the target prior to firing the working beam (8).

### Example Implementations

In one embodiment, the optical unit is rigidly mounted to a drone equipped with a stereo vision system. The stereo cameras capture images of the target area, enabling direct depth estimation. The drone's flight control system adjusts its position and attitude to bring the pilot beam (7) into alignment with the target insect, with the objective of positioning the insect within the working beam's focal point (9) or within the near- and far-field regions immediately in front of and behind that point, where the beam remains effectively focused. Once alignment is achieved, the working beam (8) is fired.

In another embodiment, the optical unit is mounted to a drone via a two-axis servo gimbal. The drone is equipped with a mono camera, and distance to the target is estimated by mono depth estimation, which may be based on apparent target size, known insect dimensions, or neural network inference.

The gimbal servos adjust the orientation of the optical unit so that the pilot beam is directed onto the target, again aiming to position the insect within the focal point or effective focus region of the working beam prior to firing.

In a further embodiment, the optical unit is mounted on a ground-based rover. The rover navigates to within effective range of the target, using onboard sensors to determine target position. The rover then either repositions its chassis or uses an integrated pointing mechanism to aim the optical unit so that the pilot beam is centered on the insect and the insect is located within the focal point or effective focus region of the working beam.

In yet another embodiment, the optical unit is mounted at the end of a robotic arm. The arm may be fixed to a stationary platform, a vehicle, or another mobile base. Using visual or sensor input, the arm manipulates the position and orientation of the optical unit to place the pilot beam on the insect, ensuring that the insect is positioned within the focal point or effective focus region of the working beam before energy delivery.

In a further variation, the aiming is achieved without physically reorienting the optical housing, by using an actuated mirror system inside the housing. For example, a MEMS scanning mirror or a fast-steering mirror (FSM) may be positioned in the beam path to redirect the pilot and working beams toward the target. On a drone, the MEMS or FSM can make fine, high-speed corrections while the drone's flight control handles coarse positioning. On a rover, the MEMS or FSM may provide all necessary beam steering for targeting within the rover's range of motion, eliminating the need for heavy mechanical gimbals. In both cases, the mirror control system receives feedback from a mono or stereo vision module that tracks the position of the pilot beam relative to the target insect, ensuring the insect is positioned within the focal point or effective focus region before the working beam is fired.

All of these techniques for aiming and beam alignment may be used individually or in any combination. For example, a drone may employ coarse alignment by adjusting its attitude, intermediate alignment via a servo gimbal, and fine alignment using a MEMS or FSM mirror system, all operating in concert under the control of a common vision and targeting processor to maintain the target insect in the effective focus region of the working beam. The optical unit may be integrated into any airborne or ground vehicle as part of a pest control apparatus, allowing adaptation to a wide variety of operational environments and crop types.

### Depth Estimation Enhancement Via Patterned Pilot Beam

In some embodiments, the pilot beam (7) is modified to carry a spatial pattern to aid in depth estimation by a mono vision system. For example, the pilot beam may be split into three or more collimated sub-beams that converge toward the working beam's focal point (9), such that their projected spots on the target exhibit predictable spacing changes with distance. Alternatively, the pilot beam may be shaped into other distinctive patterns using refractive or diffractive optical elements, including optical elements designed to generate structured light patterns with multiple lobes or overtones. Such patterns create unique, measurable features in the captured image, enabling the mono vision system to infer depth with greater accuracy. The processing system may analyze the relative positions, sizes, or shapes of the projected sub-beams or patterns on the target surface to estimate distance, allowing the optical unit to position the target insect more precisely within the working beam's focal region. This approach can be combined with other alignment and aiming methods disclosed herein, including servo gimbal control, platform attitude adjustment, and fine steering via MEMS or FSM mirrors.

### Enablement

An embodiment may be constructed by selecting a working beam wavelength that is efficiently absorbed by target insect tissue while minimizing collateral heating of foliage, for example a near-infrared wavelength between approximately 808 nm and 1064 nm, and selecting a visible pilot wavelength, for example approximately 520 nm, that is easily detected by commodity CMOS image sensors. A dichroic beam-combiner may be specified with an optical coating that at approximately 45 degrees incidence transmits at least approximately 98 percent at the working wavelength over a tolerance band of at least approximately ±10 nm and reflects at least approximately 98 percent at the pilot wavelength over a tolerance band of at least approximately ±10 nm. Anti-reflection coatings may be applied to transmissive optics at both wavelengths to reduce ghosting and insertion loss. The optical train may be arranged so that the working beam path is, in order, a high-power laser diode or fiber-coupled source, a first collimating optic that produces a substantially collimated beam, a final focusing lens that produces a converging beam to the focal point, and then the dichroic beam-combiner that transmits the converging working beam toward the target. The pilot laser may be mounted so that it produces a collimated pilot beam incident on the combiner at about 45 degrees such that the combiner reflects the pilot beam coaxially with the post-combiner segment of the working beam. In this configuration the focusing lens does not act on the pilot beam, and the pilot beam remains substantially collimated while intersecting the focal point established by the working beam. Practical component ranges may include a first collimating optic with a focal length between approximately 25 mm and 75 mm, a final focusing lens with a focal length between approximately 50 mm and 150 mm, and a mechanical lens travel capability on the order of approximately 0.5 mm to 3 mm to accommodate fine focus and optional z-dither sweeps. The dichroic element may be a plate or cube; a plate may be advantageous for weight-critical platforms. An optional output window may be sealed with coatings appropriate to both wavelengths to provide environmental protection. Mechanical registration and alignment may be achieved by fixturing the laser sources and optics within an optical housing machined with reference surfaces that hold axial and angular tolerances sufficient to maintain coaxiality over expected vibration and temperature ranges. During assembly, a low-reflectivity alignment target may be placed at a known working distance. The working beam may be operated at reduced power and focused using the final focusing lens to produce a visible or thermal mark at the focal point on the alignment target or on a calibrated thermal paper. The pilot beam mount may then be adjusted in yaw and pitch so that the pilot spot visually coincides with the working beam's focal mark at the known distance. The dichroic combiner tilt and clocking may be adjusted to minimize walk-off so that the coaxial relationship persists across a range of distances. A camera that will be used in service may be calibrated in place using a calibration grid to determine intrinsic parameters and the rigid transform to the optical axis. Intrinsic parameters may be stored as a compact JSON blob, for example {“K”:[fx,0,cx,0,fy,cy,0,0,1], “dist”:[k1,k2,p1,p2,k3]} where fx, fy, cx, cy, k1, k2, p1, p2, and k3 denote conventional pinhole and distortion coefficients. The extrinsic transform from the camera to the beam axis may be stored, for example {“R”:[r11,r12,r13,r21,r22,r23,r31,r32,r33], “t”: [tx,ty,tz]}representing rotation and translation. A fine steering element may be included to improve dynamic aim. A MEMS or fast-steering mirror may be placed after the dichroic beam-combiner so that both beams are redirected together, which inherently preserves the coaxial geometry. The mirror clear aperture may be selected to pass the converging working beam without clipping, and the actuation range may be specified to at least approximately ±1.5 degrees mechanical to cover platform jitter and target motion. Drive electronics may support control bandwidths of at least approximately 200 Hz to 1 kHz so that the vision loop can close on insect motion and platform vibration. When a gimbal is present, the mirror may provide fine corrections while the gimbal or platform provides coarse pointing.

The vision pipeline may be implemented by modulating the pilot beam at a known frequency and using synchronized camera exposure or temporal filtering to isolate the pilot spot from clutter. A simple implementation may threshold the frame at the pilot wavelength channel and compute the centroid of the saturated region, while a more robust implementation may demodulate a short time series to extract the blinking component and fit a Gaussian to estimate sub-pixel spot position. Distance may be estimated by stereo triangulation when two cameras are available, or by mono depth estimation when only one camera is available, including analysis of structured pilot patterns as described above. The controller may execute an iterative routine that commands either platform attitude, a gimbal, or the steering mirror to drive the pilot centroid onto the insect's body centroid while also placing the estimated range near the focal point. A representative control transaction between a high-level planner and the device may be expressed using Model Context Protocol so that external software agents can request targeting. For example, a tool invocation may be {“type”:“mcp.tool.call”, “name”:“align_and_fire”, “args”:{“target”:{“x”:0.43, “y”:0.61}, “range_m”:1.2, “mode”:“mono”, “pattern”:“tri_dot”, “safety”:{“max_dwell_ms”:120, “defocus margin_mm”:0.8}}} and a corresponding result may be {“type”:“mcp.tool.result”, “name”:“align_and_fire”, “ok” true, “telemetry”:{“pilotDetections”:9, “firings”:1, “focusError_mm”:0.2}} where the values are illustrative. In embodiments that realize functional coaxiality via calibration, the controller may apply a precomputed mapping from detected pilot spot coordinates and estimated range to steering and focus setpoints that ensure a residual separation below a configured tolerance over the working distance range, for example {“coax_tolerance_mm”:0.5, “range_m”: [0.6,2.0], “map_id”:“LUT42”}.

Safety interlocks may be implemented both in software and hardware. A person or animal detector may gate the firing logic so that the working beam is disabled when non-target organisms are present within a protected zone. A reflective-surface classifier may inhibit firing when specular reflections above a threshold are detected in the anticipated beam path. Hardware interlocks may include a series safety chain that removes power from the laser driver unless all interlock conditions are satisfied, including enclosure closed, temperature within limits, and beam path clear. A back-reflection photodiode may be placed to detect unexpectedly high retro-reflectance, causing immediate shutdown. A focus safety margin may be enforced by deliberately maintaining slight defocus until final confirmation that the pilot spot is correctly positioned, after which the focusing lens may be stepped to the optimal position and the working beam enabled for a bounded dwell time. The z-dither sweep described in the fallback section may be used as an enablement strategy for depth uncertainty, where short pulses are issued at several adjacent focus positions to ensure at least one pulse occurs at effective focus.

Software deployment may be realized on an embedded controller that runs the vision pipeline, control loop, licensing logic, and telemetry. The computer-readable medium may store instructions that when executed perform camera capture, pilot spot detection, range estimation, aim control, interlock checks, and working-beam activation. To promote interoperability, the controller may expose an MCP interface that presents tools for alignment, firing, telemetry retrieval, and license queries so that third-party software can orchestrate actions across different platforms without vendor-specific SDKs.

Example MCP messages may include a telemetry pull {“type”:“mcp.tool.call”, “name”:“get_usage_summary”, “args”:{“window_s”:3600}} and a response {“type”:“mcp.tool.result”, “name”:“get_usage_summary”, “ok”:true, “data”:{“on_s”:14.2, “firings”:57, “a vgW”:7.8}}. Usage records for damages and audit may be recorded in a tamper-evident ledger as compact JSON lines, for example {“ts”:“2025-04-12T10:22:05Z”, “device”:“U1234”, “fw”:”1.3.2”, “geo”:{“lat”:34.56, “lon”:-117.12}, “op” {“pilotDetections”:7, “firings”:1, “on_s”:0.35, “avgW””:8.2, “peakW”:12.0}, “features”:[“fsm”, “stereo”],” sig”:“BASE64_SIGNATURE”} where sig is produced by a key held in a secure element or trusted execution environment. These records may be made externally observable through a local service endpoint or cloud API without revealing proprietary internals, which may support verification and damages calculations.

Thermal management and environmental hardening may include conductive paths from the laser module to a heat spreader or fin stack sized for anticipated duty cycle and ambient temperature, as well as sealing of the optical housing to at least approximately IP54 with desiccant and purge port options to mitigate condensation. Vibration isolation may be provided by compliant mounts tuned to platform spectra. Electrical design may include a power path that supports peak currents for the working beam driver while isolating sensitive camera and control electronics, with appropriate filtering to reduce noise coupling. These implementational details, together with the optical and control specifics above, may be combined by a skilled person to realize the described embodiments without undue experimentation.

### Fallback Embodiments

In some embodiments, simplified or partial implementations may be employed to preserve the inventive concept of coaxial pilot and working beams aligned via a combiner while reducing cost, complexity, or reliance on specific subsystems. A low-cost fixed-mount configuration may be used in which the optical housing (6) is rigidly attached to a frame with no gimbal or internal steering mirror, and platform repositioning provides coarse aim. A mono camera may detect the pilot beam (7) centroid relative to a detected insect bounding box, and the controller may trigger the working beam (8) only when the centroid remains within a threshold window for a minimum dwell time, thereby achieving targeting without stereo depth. A z-dither focus sweep may be performed by linearly actuating the final focusing lens (3) through a small range about the nominal focal point (9), firing short pulses at several discrete lens positions to bracket the focal region and ensure at least one pulse occurs at effective focus.

In another fallback, the dichroic beam-combiner (2) may be replaced by a polarization beam splitter or a partially reflective plate to obtain coaxial alignment at the expense of some insertion loss, while preserving the pilot and working beam coaxial geometry beyond the combiner. The pilot-beam source (1) may be of reduced power and constant (unmodulated) output, relying on camera exposure control and temporal averaging to detect the spot in challenging backgrounds. The working beam (8) may be operated at lower peak power with longer dwell time and stricter interlocks to comply with safety constraints, while still delivering sufficient energy to neutralize small pests at short range.

In a contact-standoff variant, a short focal length lens assembly may be coupled with a mechanical standoff tip that sets the working distance relative to foliage, ensuring the insect lies near the focal point (9) without any computer vision distance estimation. The standoff may be compliant to avoid plant damage and may include a reflective fiducial observed by the camera to confirm geometry before firing. In embodiments omitting fine steering, a static internal mirror may fix the beam path, and all aim adjustments may be achieved by platform motion alone. These fallbacks maintain the core inventive alignment between the pilot beam and the working beam while omitting or simplifying subsystems such as stereo vision, MEMS or FSM steering, or structured-light depth estimation.

### Monetization and Subscription Enablement for Damages Maximization

In some embodiments, the optical unit and associated control software may be provisioned under subscription or usage-based licensing. The controller may include a license manager that enforces entitlements such as activation of the working beam, maximum power levels, daily activation seconds, number of firings, or access to advanced features including MEMS or FSM fine steering and structured light depth estimation. The system may maintain a tamper-evident usage ledger that records device identifier, firmware version, timestamps, geolocation when permitted, number of pilot-beam detections, number of working-beam firings, cumulative working-beam on-time, average and peak power, and fault events. The ledger may be protected by a secure element or trusted execution environment that stores cryptographic keys and signs usage records. Usage summaries may be periodically uploaded to a licensing server over secure channels such as TLS over Wi-Fi, cellular, or other links, with support for offline operation using time-limited tokens and grace periods. When connectivity is unavailable, the device may continue to operate within licensed quotas by validating signed, time-bounded entitlements and later reconciling buffered records via hash-chained batches that allow server-side verification of completeness and order. Remote feature flags may be used to enable or disable specific capabilities, for example setting a focus safety margin, enforcing geofenced operating areas, or switching between mono and stereo vision modes. Over-the-air updates may deliver security patches and new features while preserving license state, and the device may implement secure boot and attestation so that only signed firmware can access the working beam. These mechanisms may provide clear, auditable evidence of feature use and scope of deployment suitable for calculating damages in the event of infringement, including subscription fees, per-use charges, and premium feature surcharges. The platform may optionally expose externally observable outputs such as signed usage receipts accessible through a local service endpoint or cloud API, allowing verification that particular features were active during specific operating periods without revealing proprietary internals.

### Continuation-Ready Itemized List of Embodiments and Features

Embodiments can be described by the following itemized list: (1) an optical unit comprising a pilot laser and a powerlaser wherein the pilot laser and the powerlaser are optically aligned; (2) the optical unit in which the pilot laser is a green laser; (3) a UAV or ground mobile platform comprising any optical unit described herein; (4) optical alignment provided by a dichroic beam-combiner positioned at approximately 45 degrees that transmits a wavelength of the powerlaser and reflects a wavelength of the pilot laser such that the beams are coaxial beyond the combiner; (5) a configuration in which a final focusing lens is positioned upstream of the dichroic beam-combiner so that the pilot beam intersects a focal point without itself being focused by the final focusing lens; (6) a pilot laser configured to emit a collimated pilot beam that is modulated by blinking or pulsing to increase visibility to a vision system; (7) an optical unit further comprising a vision module and a controller configured to detect a location of the pilot beam relative to a target insect and to command a positioning mechanism to align the target with a focal point or focal region of the powerlaser before firing; (8) a positioning mechanism comprising at least one of servos that reorient the optical unit, a platform attitude control, and an actuated mirror including a MEMS device or a fast-steering mirror; (9) a pilot beam structured into multiple sub-beams or a spatial pattern using refractive or diffractive optical elements to aid mono vision depth estimation by analyzing relative positions, sizes, or shapes of projected spots on the target; (10) a dichroic beam-combiner that transmits the powerlaser working beam substantially without deviation and reflects the pilot beam by about 90 degrees; (11) a method comprising optically aligning a pilot beam and a working beam using a dichroic beam-combiner, detecting a location of the pilot beam on a target insect, adjusting an orientation of an optical unit or a steering mirror so that the insect is positioned within a focal region of the working beam, and firing the working beam; (12) the method performed on a drone equipped with a stereo vision system wherein the drone flight control adjusts position and attitude for coarse alignment; (13) the method performed on a drone equipped with a mono camera wherein distance is estimated by mono depth estimation based on apparent target size, known insect dimensions, or neural network inference and a servo gimbal adjusts orientation; (14) the method performed on a ground rover that navigates to range using onboard sensors and either repositions its chassis or uses an integrated pointing mechanism to aim the optical unit; (15) the method performed on a robotic arm that manipulates position and orientation of the optical unit to place the pilot beam on the insect before energy delivery; (16) a configuration in which fine high-speed corrections are applied by a MEMS scanning mirror or a fast-steering mirror while coarse positioning is provided by a vehicle or gimbal; (17) a robotic arm system comprising a robotic arm and any optical unit described herein mounted at an end of the arm; (18) a computer readable medium storing instructions that when executed by a controller cause the controller to process images to detect a pilot beam location relative to a target insect, estimate distance, command a positioning mechanism to align the target within a focal region of a working beam, and trigger the powerlaser; (19) an optical unit in which an actuated mirror provides beam steering without moving an optical housing and receives feedback from a mono or stereo vision module that tracks a position of the pilot beam relative to the target insect; (20) a platform comprising any optical unit described herein further comprising a vision module and a controller configured to maintain the target insect in an effective focus region of the working beam; (21) optical alternatives in which the beam combiner comprises a polarization-selective combiner, a partially reflective plate, or a wavelength-division component with equivalent coaxial alignment performance; (22) wavelength alternatives in which the pilot beam may be red, infrared, ultraviolet, or any visible color, and the powerlaser wavelength may be selected to optimize absorption by target tissue while minimizing collateral heating of plant matter; (23) camera and sensing alternatives including global-shutter or rolling-shutter CMOS sensors, infrared cameras, event cameras, lidar or ToF range sensors fused with the pilot-beam detection; (24) safety features including interlocks tied to person or animal detection, reflective-surface avoidance, maximum dwell-time enforcement, and auto-defocus margins that maintain a focus safety buffer until final confirmation; (25) environmental hardening including sealed housings, dust and moisture ingress protection, active cooling of the powerlaser module, and vibration isolation suitable for aerial and ground platforms; (26) interoperability features including support for multiple communication links such as Wi-Fi, cellular, LoRa, or wired Ethernet and standard secure transport including TLS with mutual authentication and certificate rotation; (27) licensing and audit features including a license manager, a tamper-evident usage ledger protected by a secure element or trusted execution environment, signed usage receipts accessible through a local service endpoint or cloud API, remote feature flags, geofencing, and over-the-air updates with secure boot and attestation to control access to the working beam; (28) control architectures in which coarse alignment is performed by platform motion, intermediate alignment by a gimbal, and fine alignment by an internal mirror, operating singly or in combination under supervision of a vision and targeting processor; (29) functional-coaxial embodiments in which a calibrated mapping compensates for residual non-coaxiality so that separation between a pilot-beam indication and a working-beam focal region at a target plane remains below a specified tolerance across a working distance range; (30) optical layouts in which a final focusing lens is positioned downstream of a combiner so that both pilot and working beams pass through the same focusing element, with safety measures to limit pilot-beam irradiance; (31) alignment architectures that employ a precomputed lookup table or parametric model mapping camera or pilot-spot coordinates and estimated range to steering and focus commands that place the target within the working-beam focal region without requiring strict pre-combiner coaxiality; (32) dual-wavelength source embodiments in which a single optical path produces both a visible pilot and an infrared working beam by time-multiplexing, wavelength switching, or frequency conversion so that alignment is inherently maintained; (33) combining alternatives including fiber-based combiners, knife-edge combiners, and waveguide couplers that provide equivalent post-combiner coaxial or functionally coaxial alignment; (34) externally observable self-test procedures that project a diagnostic pilot pattern and a low-energy working pulse onto a calibration card to produce a signed report attesting to pilot-to-focus congruence within tolerance over distance steps; (35) protocol interoperability including operation with ROS 2, MAVLink, and OPC UA in addition to MCP so that external orchestration can be achieved across diverse ecosystems without interface-based design-around; (36) definitions of an effective focus region by quantitative metrics including Rayleigh range, spot size thresholds, or energy density thresholds, with control strategies that keep the target within those metrics prior to firing; (37) pilot illumination sources comprising one or more of a superluminescent diode, a VCSEL array, a collimated LED or LED array, or a scanned projector treated as a pilot-beam source for alignment and detection when rendered into a directed or collimated emission; (38) time-multiplexed embodiments in which a single source provides both pilot illumination and working energy by dynamically modulating power, duty cycle, or pulse width under safety interlocks so that the same beam serves as a low-energy pilot and a high-energy working beam at different times; (39) detector-agnostic embodiments in which the pilot emission is outside the visible spectrum while remaining detectable by the sensing module, including near-infrared pilots paired with infrared-sensitive cameras and appropriate filtering, thereby preventing design-around via spectrum changes; (40) legal and externally observable behaviors including publication of signed congruence reports and usage receipts that attest to pilot-to-focus alignment performance and feature activation without revealing internals, enabling verification even when a device is a closed appliance.
1. An optical unit comprising a pilot emitter and a powerlaser wherein said pilot emitter and said powerlaser are optically aligned and wherein said pilot emitter and said powerlaser are provided by separate emitters or by a single source operated in pilot and working modes.
2. The optical unit of 1 where said pilot emitter comprises a green laser.
3. A UAV or ground mobile platform comprising the optical unit of 1.
4. The optical unit of 1 wherein optical alignment is provided by a dichroic beam-combiner positioned at approximately 45 degrees that transmits a wavelength of the powerlaser and reflects a wavelength of the pilot emission such that the beams are coaxial beyond the combiner.
5. The optical unit of 4 wherein a final focusing lens is positioned upstream of the dichroic beam-combiner so that the pilot beam intersects a focal point without itself being focused by the final focusing lens.
6. The optical unit of 1 wherein the pilot emitter is configured to emit a collimated pilot beam that is modulated by blinking or pulsing to increase visibility to a vision system.
7. The optical unit of 1 further comprising a vision module and a controller configured to detect a location of the pilot beam relative to a target insect and to command a positioning mechanism to align the target with a focal point of the powerlaser before firing.
8. The optical unit of 7 wherein the positioning mechanism comprises at least one of servos that reorient the optical unit, a platform attitude control, and an actuated mirror including a MEMS device or a fast-steering mirror.
9. The optical unit of 1 wherein the pilot beam is structured into multiple sub-beams or a spatial pattern using refractive or diffractive optical elements to aid mono vision depth estimation by analyzing relative positions, sizes, or shapes of projected spots on the target.
10. The optical unit of 1 wherein the dichroic beam-combiner transmits the powerlaser working beam substantially without deviation and reflects the pilot beam by about 90 degrees.
11. A method comprising optically aligning a pilot beam and a working beam using a dichroic beam-combiner, detecting a location of the pilot beam on a target insect, adjusting an orientation of an optical unit or a steering mirror so that the insect is positioned within a focal region of the working beam, and firing the working beam.
12. The method of 11 performed on a drone equipped with a stereo vision system wherein the drone flight control adjusts position and attitude for coarse alignment.
13. The method of 11 performed on a drone equipped with a mono camera wherein distance is estimated by mono depth estimation based on apparent target size known insect dimensions or neural network inference and a servo gimbal adjusts orientation.
14. The method of 11 performed on a ground rover that navigates to range using onboard sensors and either repositions its chassis or uses an integrated pointing mechanism to aim the optical unit.
15. The method of 11 performed on a robotic arm that manipulates position and orientation of the optical unit to place the pilot beam on the insect before energy delivery.
16. The method of 11 wherein fine high-speed corrections are applied by a MEMS scanning mirror or a fast-steering mirror while coarse positioning is provided by a vehicle or gimbal.
17. A robotic arm system comprising a robotic arm and the optical unit of 1 mounted at an end of the arm.
18. A non-transitory computer readable medium storing instructions that when executed by a controller cause the controller to process images to detect a pilot beam location relative to a target insect, estimate distance, command a positioning mechanism to align the target within a focal region of a working beam, and trigger the powerlaser.
19. The optical unit of 1 wherein an actuated mirror provides beam steering without moving an optical housing and receives feedback from a mono or stereo vision module that tracks a position of the pilot beam relative to the target insect.
20. The platform of 3 further comprising a vision module and a controller configured to operate as in 7 to maintain the target insect in an effective focus region of the working beam.

### Embodiment AQ: System and Method for Narrative Function Detection and Adaptive Scene Skipping in Media Playback

### Author's Note

This invention entitled “System and Method for Narrative Function Detection and Adaptive Scene Skipping in Media Playback” was co-invented by Nick Reyntjens, Toon De Geyter, and Laurent Mazé.

Unless explicitly stated otherwise, all other inventions described in this document are solely invented by Nick Reyntjens.

A system and method are disclosed for adaptive playback of audio-visual media using narrative-aware artificial intelligence. The system includes a scene-to-text pipeline that segments a media stream into scenes with defined start and stop times and generates structured annotations for each segment. The annotations comprise activity descriptors (e.g., singing, fighting, reading), narrative function labels (e.g., flashback, exposition, filler, climax, transition), and tonal attributes (e.g., comic, suspenseful, tragic). Together these annotations form a narrative map of the media. A decision-making module applies viewer-specific parameters to the narrative map, including a skip profile that specifies categories of content to omit and a knowledge state model representing what the viewer has already experienced. Based on these factors, the system determines whether each scene is played, skipped, enlarged, or explained, with optional augmentation such as text-to-speech of visual clues or enlargement of on-screen text. The invention enables continuity-preserving editing that omits unwanted or redundant content while enhancing accessibility and comprehension for diverse viewers, including those with declining eyesight or difficulty perceiving subtle narrative elements.

### Background of the Invention

The present invention relates generally to systems for playback of audio-visual media, and more particularly to adaptive playback systems that employ artificial intelligence to modify media presentation based on narrative structure and viewer-specific preferences.

Conventional media playback devices, including televisions, set-top boxes, and streaming platforms, typically provide linear playback of films, television episodes, or online videos. While some systems allow manual fast-forwarding or skipping, these actions require continuous user input and do not adapt intelligently to viewer behavior. More advanced solutions, such as parental controls or content filtering services, permit the omission of pre-defined categories of content such as nudity, profanity, or violence. These systems, however, generally rely on manually generated tags or metadata, and operate without understanding the broader narrative function of a scene. As a result, they may remove or mute content in a way that disrupts continuity or fails to consider the viewer's knowledge of the storyline.

In addition, current accessibility features for media playback, such as closed captioning, enlarged subtitles, or audio description, provide important assistance but remain limited to static augmentations. Such tools do not adapt dynamically to the narrative context or the evolving needs of an individual viewer. For example, a viewer with declining eyesight may miss an on-screen note critical to the plot, while an elderly viewer binge-watching a series may be forced to watch redundant flashback sequences that add little informational value.

There is therefore a need for a system that combines semantic understanding of media content with viewer-specific profiles and knowledge states, enabling playback that is both personalized and continuity-preserving. Such a system would be capable of detecting narrative functions such as flashbacks, filler segments, and exposition, while also recognizing activities and tonal attributes. By linking this information to a decision-making module that respects user preferences and prior viewing history, media playback can be adapted to omit undesired content, skip redundant segments, or highlight and explain critical story clues.

### Examples

In one embodiment, the system may be applied to a television series in which the viewer repeatedly skips certain types of content, such as musical interludes. When the system detects that the viewer has manually skipped three or more scenes annotated as “singing,” the skip profile may be automatically updated to omit such scenes in subsequent episodes or related series, thereby reducing repetitive manual input.

In another embodiment, the system may be used during binge-watching of a serialized program. The decision-making module, informed by the viewer's knowledge state, may recognize that flashback sequences repeat content already viewed in prior episodes. In this case the system may automatically skip or compress the flashback segments, preserving narrative continuity while avoiding redundancy for the viewer.

In a further embodiment, the system may be applied to instructional media, such as software tutorials. If the viewer's knowledge state indicates that introductory concepts have already been learned in earlier sessions, the system may bypass basic segments and advance directly to advanced topics, thereby tailoring the presentation to the viewer's prior experience.

### Detailed Description

The invention provides a system for adaptive playback of media based on semantic scene analysis and narrative reasoning. In a first aspect, a scene-to-text artificial intelligence pipeline segments a media stream into scenes and generates structured annotations. Each scene is annotated with activity information (e.g., singing, fighting, reading), narrative function (e.g., flashback, exposition, filler, climax, transition), and tone or emotional state (e.g., comic, tragic, suspenseful). This produces a narrative map of the media stream that extends beyond conventional content tagging.

In a second aspect, a decision-making module consults the narrative map in conjunction with viewer-specific inputs. A skip profile allows the viewer to define categories of content to omit, such as romance, filler songs, or violence. A knowledge state model of the viewer, derived from prior viewing history and recognized redundancy within the media (e.g., repeated flashbacks, recaps), further informs the decision. As a result, the system automatically determines whether a given scene is played, skipped, enlarged, or explained, thereby preserving narrative coherence while tailoring playback to the viewer's preferences and perceptual needs.

### Scene-to-Text Processing Module:

In one embodiment, a scene-to-text processing module may be configured to associate each segment of a media stream with descriptive metadata, including activities, narrative functions, and tonal attributes. More specifically, the system may first employ scene segmentation algorithms (known in the art for dividing a continuous video into shots and higher-level scenes) to determine the start and stop time of each unit of analysis. Within these temporal boundaries, an activity recognition model (for example, a convolutional or transformer-based video classifier) may identify dominant actions such as “singing,” “fighting,” or “reading.”

In parallel, a multimodal emotion and sentiment classifier may analyze visual, auditory, and textual signals to characterize the emotional tone of the segment (e.g., comic, tragic, suspenseful). Further, natural-language processing applied to subtitles or generated transcripts may provide contextual clues, enabling a narrative function classifier trained on corpora of annotated stories to assign labels such as “flashback,” “exposition,” “climax,” or “resolution.” For cases where the media includes repeated information, the system may also apply semantic similarity and redundancy detection across transcripts, thereby recognizing recaps or flashbacks that add little new information to a binge-watching viewer.

By combining the temporal boundaries from scene segmentation with the descriptive outputs of activity recognition, tonal classification, and narrative function detection, the system produces a narrative map of the media stream. Each scene is thus represented not only by its start and stop time but also by a structured annotation of what is happening, how it functions in the storyline, and what affective tone it conveys. This rich annotation enables subsequent modules, such as a decision-making engine, to select whether the scene should be presented in full, skipped, enlarged, or explained, based on a viewer's personalized profile and knowledge state.

In one embodiment, the scene-to-text processing module may be realized as a pipeline that integrates video segmentation, multimodal feature extraction, natural language processing, and semantic similarity analysis. The module operates on an incoming media stream and outputs a structured annotation for each detected scene. The process begins with segmentation, where the continuous video is divided into smaller temporal units. Shot boundaries may be detected using histogram differencing, edge change ratios, or deep neural networks trained on large video corpora. Adjacent shots are then clustered into higher-level scenes using similarity measures between learned visual embeddings, such as cosine distance in a CLIP-like embedding space. The outcome of this stage is a set of discrete scenes, each with a defined start and stop time suitable for subsequent annotation.

Within these temporal boundaries, multimodal features are extracted. The visual channel may be processed by a 3D convolutional network or transformer-based architecture such as SlowFast or ViViT, producing labels that describe dominant activities, including “singing,” “fighting,” or “reading.” The audio channel may be processed by spectrogram-based convolutional models or self-supervised speech models such as wav2vec2, providing information about speech segments, background music, silence, or emotional prosody. Textual information may be captured both through automatic speech recognition applied to dialogue and optical character recognition applied to on-screen elements such as letters, signs, or phone messages. These heterogeneous representations may be aligned and fused in a multimodal transformer model, which produces a unified latent embedding of the scene.

Narrative function detection may be carried out by models trained on annotated datasets of television, film, or literature, where scenes are labeled as exposition, climax, filler, resolution, or flashback. Flashbacks may be identified by a combination of multimodal cues, including abrupt shifts in color grading, insertion of temporal markers in dialogue (“yesterday . . . ”, “long ago”), or high semantic overlap with earlier transcript material. Redundancy detection may be implemented by computing embeddings of transcript segments using a sentence-BERT model and comparing them against a memory of previously processed content. When similarity exceeds a defined threshold, the system infers that the current scene is a recap or repetition.

An emotion and sentiment classifier may also operate on the fused multimodal embedding. This classifier can be trained using datasets of film clips annotated with emotional categories, enabling the system to assign tonal attributes such as comic, tragic, suspenseful, or romantic. The outputs of activity recognition, narrative function detection, sentiment classification, and redundancy analysis are then combined with the temporal boundaries established earlier.

The result is a narrative map of the media stream in which each scene is represented not only by its start and stop times but also by structured metadata describing what occurs within the scene, how the scene contributes to the narrative structure, and the emotional tone conveyed. This representation is stored in a structured format, such as JSON or protocol buffers, which allows downstream modules to access the annotations in real time. Subsequent components, such as the skipping logic module, may then query this map to determine whether to present, omit, enlarge, or explain the scene in accordance with a viewer profile and knowledge state.

### Skipping Logic Module

In one embodiment, a skipping logic module may be configured to determine, for each annotated scene, whether the scene is to be presented in full, omitted, condensed, or augmented. The skipping logic module receives as input the narrative map generated by the scene-to-text processing module together with one or more viewer-specific parameters.

A first parameter may comprise a skip profile, defined by explicit user selections such as “skip romance scenes,” “skip filler songs,” or “skip violent content.” When the narrative map indicates that a scene is annotated with one or more categories designated in the skip profile, the skipping logic module may instruct the playback system to omit the corresponding scene or to advance directly to the subsequent scene boundary.

A second parameter may comprise a knowledge state model that reflects what the viewer has previously consumed. The knowledge state may be determined by tracking the viewer's prior playback history across episodes or sessions, and by applying semantic similarity analysis to detect redundant narrative elements. For example, if the system detects that a flashback sequence reproduces content already viewed by the same viewer in an earlier episode, the skipping logic module may classify the scene as redundant and automatically bypass it.

In certain embodiments, the skipping logic module may not only skip but also substitute explanatory augmentation to preserve narrative continuity. For example, where a skipped scene establishes a relationship change between characters, the module may insert a micro-recap statement (“Two hours later, the characters are shown as a couple”) generated from the narrative map. In another example, if the scene contains a visual clue, such as a note or message on a screen, the skipping logic module may suppress the surrounding filler content but enlarge and display the clue text or provide a text-to-speech narration of the clue to the viewer.

The skipping logic module may thus operate as a rule-based and learning-enhanced decision system, combining explicit user preferences with inferred redundancy detection and context-preserving augmentation. The result is a personalized final edit that maintains narrative coherence while eliminating undesired, repetitive, or inaccessible content.

In one embodiment, the skipping logic may be implemented as a software pipeline integrated into a smart television, a set-top box, or a cloud-based streaming platform. The media stream is first divided into scenes by applying automated segmentation algorithms. Shot boundary detection may be carried out through histogram difference, frame correlation, or transformer-based video segmentation, and these shots are then clustered into coherent scenes by similarity analysis of visual embeddings. Each scene is therefore associated with a start and stop time that defines a temporal decision boundary.

Within each identified scene, multimodal feature extraction is performed. A video classifier based on convolutional or transformer architectures may identify dominant activities such as fighting, kissing, or singing. An audio model trained on spectrograms or raw waveform representations may further detect music, speech, silence, or emotional prosody. Speech recognition and optical character recognition may be used to generate textual transcripts from dialogue and to extract on-screen text such as letters or phone messages. These visual, auditory, and textual embeddings may be fused in a multimodal transformer framework, producing a joint representation of the scene.

Narrative function detection may then be carried out by supervised models trained on corpora of annotated stories and question-answering datasets. Such models classify each scene as flashback, exposition, filler, climax, or resolution. Flashbacks can be recognized by temporal inconsistencies in film characteristics or dialogue references to prior events, while recaps may be detected by comparing transcripts against previously viewed content using semantic similarity measures. Redundant sequences are identified when transcript embeddings exceed a similarity threshold with earlier material in the viewer's history.

A knowledge state model is maintained in parallel to represent what the viewer has already consumed. This may take the form of a graph or embedding memory that is updated incrementally as scenes are viewed. When a new scene is analyzed, its transcript and activity representation are compared to the knowledge state; if high similarity is detected, the system infers that the viewer has already assimilated the content, and the sequence may be classified as redundant.

The decision engine consults the narrative map together with the skip profile and knowledge state to determine the appropriate playback action. When a scene matches a category designated in the skip profile, the playback pointer is advanced to the next decision boundary. When redundancy is detected, the system may bypass the scene or insert a condensed recap to preserve narrative coherence. If a skipped scene contains a narrative-critical element, such as a textual clue extracted by OCR, the system may momentarily enlarge or read aloud the clue before resuming playback. The output is thus a personalized final edit that maintains continuity while eliminating undesired or repetitive segments.

The system may continue to refine its decisions through learning from user interaction. If a viewer reverses a skip to watch a segment, this feedback may reduce the confidence threshold for future omissions. If skipped scenes are never revisited, the system reinforces that behavior as appropriate. Over time, the skip profile becomes adaptive, evolving with the viewer's demonstrated preferences and consumption habits.

### Buffering and Processing Pipeline

In one embodiment, the displaying device may be configured with a dual-buffer system that ensures both seamless playback and sufficient time for semantic analysis. A first buffer may store incoming media packets as they are received from the streaming source. The buffer size may be dynamically adjustable but, in atypical case, may correspond to several minutes of media content, for example five minutes. This first buffer allows the device to accumulate enough material so that portions of the media can be analyzed and, if necessary, skipped, without creating perceptible interruptions in playback.

A second buffer, referred to as the processed buffer, may store the media content after it has been analyzed by the scene-to-text pipeline and subjected to the skipping logic. The processing pipeline operates on the first buffer in a look-ahead fashion, examining upcoming segments before they are required for playback. Scene boundaries are detected, features are extracted, and narrative functions are classified in advance. For each scene, the decision-making module determines whether the segment is to be copied directly into the processed buffer, omitted entirely, or substituted by an alternative representation such as a condensed summary or a textual or spoken explanation of a critical clue.

During playback, the device reads sequentially from the processed buffer. Because the decisions have already been made ahead of time, playback can proceed without latency, even if the underlying analysis required intensive computation. This design also allows seamless transitions between retained and omitted content, since the processed buffer contains only the media that will actually be presented to the viewer.

In certain embodiments, the system may operate in parallel: while the viewer is consuming one portion of the processed buffer, the pipeline continues analyzing upcoming content in the first buffer and populating the next segment of the processed buffer. If the user alters preferences or issues corrective feedback (such as manually replaying a skipped scene), the system may reprocess relevant segments from the first buffer and adjust the processed buffer accordingly. This architecture ensures that the adaptive playback is both responsive and continuity-preserving while meeting the computational requirements of semantic augmentation and narrative reasoning.

### Flow of the Invention

In one embodiment, the method may proceed in the following steps.

### Step 1: Receiving Media Packets.

A media stream is received in the form of compressed packets from a broadcast source, file, or online service. The packets are collected by the system for further processing.

### Step 2: Input Buffering.

The incoming packets are accumulated in an input buffer. The buffer is of sufficient duration, for example five minutes of playback time, to provide both temporal space for later skipping of sections and computational time to perform semantic analysis in advance of playback.

### Step 3: Scene Segmentation.

The content of the input buffer is divided into discrete scenes. This segmentation may be achieved by detecting shot boundaries and grouping them into higher-level scenes, thereby producing start and stop times for each scene.

### Step 4: Feature Extraction.

Each scene is analyzed through multiple channels. A video classifier detects activities such as singing, fighting, or reading. An audio classifier distinguishes speech, music, silence, or emotional prosody. A text pipeline converts dialogue into transcripts via speech recognition and extracts visual text via optical character recognition. The outputs are fused into a multimodal representation of the scene.

### Step 5: Narrative Function and Tone Classification.

The multimodal representation is further analyzed to assign a narrative function label such as exposition, flashback, or filler. An emotion classifier may add tonal attributes such as tragic or suspenseful. Transcript embeddings may be compared with previously viewed material to detect redundant or recap scenes.

### Step 6: Narrative Map Generation.

For each scene, the metadata produced in Steps 4 and 5 is associated with its start and stop times to create a narrative map of the buffered portion of the media. The narrative map describes what occurs in the scene, how it functions in the storyline, and what affective tone it conveys.

### Step 7: Decision Making.

The narrative map is passed to a decision-making module. This module consults the viewer's skip profile (e.g., to omit romance or filler songs) and the viewer's knowledge state model (e.g., to avoid flashbacks already seen). For each scene, the module determines whether to retain it, skip it, shorten it, or replace it with an augmentation such as a summary or enlarged clue.

### Step 8: Processed Buffering.

Scenes designated for presentation are copied into a processed buffer. Scenes to be omitted are not transferred, and scenes designated for augmentation are replaced with the corresponding summaries, recaps, or enlarged textual elements.

### Step 9: Playback.

The system reads sequentially from the processed buffer to deliver playback to the viewer. Since the processed buffer contains only the final edit, playback proceeds seamlessly without delay when skipped portions occur.

### Step 10: Continuous Look-Ahead.

While playback is proceeding from the processed buffer, the pipeline continues processing new material from the input buffer in a look-ahead fashion. The cycle of segmentation, feature extraction, classification, and decision-making continues so that playback remains uninterrupted.

### Step 11: Feedback and Adaptation.

If the viewer manually overrides a skip, revisits a scene, or alters preferences, the system reprocesses the relevant portion of the input buffer and updates the processed buffer accordingly. The skip profile and knowledge state are also updated so that future playback reflects the viewer's demonstrated behavior.
1. Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
2. 1.
A system for adaptive media playback, comprising:
an input buffer configured to receive and temporarily store a portion of a media stream;
a scene-to-text processing module configured to segment the media stream into discrete scenes with start and stop times and to generate, for each scene, structured annotations including at least one of an activity descriptor, a narrative function label, and a tonal attribute;
a decision-making module configured to generate a narrative map from the structured annotations and to determine, based on a skip profile and a knowledge state model of a viewer, whether each scene is to be presented, skipped, condensed, or augmented; and
a processed buffer configured to store the media stream as modified by the decision-making module for seamless playback.
3. 2.
The system of item 1, wherein the scene-to-text processing module comprises a video classifier, an audio classifier, and a text analysis module, and wherein outputs from the classifiers are fused into a multimodal representation of each scene. 4. 3.
The system of item 1, wherein the narrative function label is selected from a group consisting of: flashback, exposition, filler, climax, resolution, and transition. 5. 4.
The system of item 1, wherein the tonal attribute is selected from a group consisting of:
comic, tragic, suspenseful, romantic, and neutral. 6. 5.
The system of item 1, wherein the knowledge state model comprises a memory of transcript embeddings of previously viewed material, and the decision-making module is configured to detect redundancy by comparing a current transcript embedding with stored embeddings.
7. 6.
The system of item 1, wherein the skip profile comprises viewer-specified categories of content to omit, including at least one of: romance, violence, filler songs, or flashbacks.
8. 7.
The system of item 1, wherein the decision-making module is further configured to substitute a skipped scene with a condensed summary or micro-recap statement to preserve narrative continuity.
9. 8.
The system of item 1, wherein the decision-making module is further configured to enlarge and display on-screen text detected by optical character recognition when the corresponding scene is skipped.
10. 9.
The system of item 1, wherein the decision-making module refines the skip profile over time by incorporating feedback from viewer overrides of skipped or presented scenes.
11. 10.
The system of item 1, wherein the input buffer and processed buffer operate in a look-ahead fashion such that segmentation, annotation, and decision-making for future scenes are performed while current scenes are being played.
12. 11.
A method for adaptive media playback, comprising:
receiving a media stream and storing a portion of the media stream in an input buffer;
segmenting the media stream into scenes having start and stop times;
generating structured annotations for each scene, the annotations including at least one of an activity descriptor, a narrative function label, and atonal attribute;
constructing a narrative map from the annotations;
applying a skip profile and a knowledge state model of a viewer to the narrative map;
determining whether each scene is to be presented, skipped, condensed, or augmented;
transferring selected scenes and augmentations to a processed buffer; and
presenting the contents of the processed buffer to the viewer as seamless playback.
13. 12.
The method of item 11, further comprising detecting flashbacks by comparing transcript embeddings of current and prior scenes and classifying the scene as redundant if similarity exceeds a threshold.
14. 13.
The method of item 11, further comprising detecting tonal attributes of each scene by applying a multimodal sentiment classifier to video, audio, and textual inputs.
15. 14.
The method of item 11, further comprising dynamically reprocessing the input buffer upon receiving corrective feedback from the viewer.
16. 15.
The method of item 11, further comprising substituting skipped scenes with explanatory augmentation, including at least one of a textual summary, a spoken recap, or enlargement of on-screen clues.
17. 16.
A non-transitory computer-readable medium storing instructions that, when executed by one or more processors, cause the processors to perform the method of item 11.
18. 17.
The system of item 1, wherein the scene-to-text processing module employs a transformer-based multimodal neural network trained on annotated corpora of film and literature to assign narrative function labels.
19. 18.
The system of item 1, wherein the processed buffer is configured to store only media segments designated for presentation, thereby enabling seamless transitions between retained and omitted scenes.
20. 19.
The method of item 11, wherein the skip profile is automatically updated when the system detects that a viewer has manually skipped a category of scenes three or more times.
21. 20.
The system of item 1, wherein the decision-making module comprises a reinforcement learning component configured to adapt playback decisions to long-term viewer behavior.

### Embodiment AQ: System and Method for Automatic Correction and Emphasis of Brand Names in Subtitles

### Author's Note

This invention entitled “System and Method for Automatic Correction and Emphasis of Brand Names in Subtitles” was co-invented by Nick Reyntjens and Toon De Geyter.

Unless explicitly stated otherwise, all other inventions described in this document are solely invented by Nick Reyntjens.

### Field of the Invention

The present invention relates generally to the field of automated subtitle and caption generation, and more particularly to systems and methods that improve accuracy of brand names, product names, and personal names in machine-generated subtitles, optionally providing stylistic emphasis to such corrected terms.

### Background of the Invention

Online video platforms increasingly rely on automatic speech recognition (ASR) engines to generate subtitles. While these systems perform well for common words, they frequently misrecognize proper nouns, including brand names, product names, and personal names. For example, “Xbox” may appear as “Ex bugs,” or “Samsung Galaxy” as “Sam Sung Gall Ex See.”

Such errors negatively impact brand reputation, searchability, and viewer comprehension. In addition, companies and individuals may wish for their names to be highlighted in subtitles (e.g., bold, italic, or styled text) to improve visibility and marketing impact. Existing subtitle systems lack a dedicated correction layer that validates ASR output against contextual knowledge and applies such emphasis consistently.

### Summary of the Invention

The invention provides a system for post-processing subtitles, wherein candidate words from ASR output are analyzed for potential brand, product, or personal names. Suspect tokens may be corrected to verified canonical forms using a knowledge base and contextual cues derived from the video. Verified names may further be emphasized through styling (e.g., bolding) or metadata annotation.

In one embodiment, the system integrates:
a subtitle correction module configured to receive ASR transcripts,
a knowledge base of brand and product names,
a contextual inference engine that leverages video metadata, visual recognition, and natural language processing,
a rendering module that outputs a corrected and optionally styled subtitle track.

This invention thereby improves brand integrity, enhances viewer experience, and creates new opportunities for marketing and monetization in digital media.

### DETAILED DESCRIPTION OF THE INVENTION

### Core System Architecture

The system may be positioned between an automatic speech recognition engine and a subtitle rendering engine. It receives ASR output, typically in a structured format such as WebVTT or TTML, containing words, timestamps, and confidence scores.

A natural language processing module may first apply named entity recognition to identify potential proper nouns. Detected tokens are compared against a knowledge base containing brand names, product lines, celebrity names, and other entities. This knowledge base may be curated manually, synchronized from public data sources, or dynamically updated based on trending content.

A contextual inference engine may refine candidate matches by analyzing:
video metadata (title, description, tags),
associated keywords,
scene-level information obtained through OCR of on-screen text or logo recognition,
co-occurrence statistics with other words in the transcript.

Correction decisions may be made when a candidate token aligns phonetically and semantically with a known entity and exceeds a predetermined confidence threshold. The corrected token is substituted into the subtitle track while maintaining original timing alignment.

### Styling and Branding Enhancement

Corrected tokens may further be wrapped in markup tags, such as <b> for bold text in WebVTT or equivalent TTML styling. In some embodiments, styled names may include metadata for marketing purposes, such as clickable links or tracking identifiers.

### Examples

A dishwasher review video generates the subtitle: “I really like my new Fish Air model.” The system corrects to: “I really like my new Fisher & Paykel model.”
A livestream outputs: “He's playing on the Ex Bugs console.” The system corrects to: “He's playing on the Xboxconsole.”

### Technical Enablements

To enable efficient operation, the system may employ the following:
phonetic similarity matching between ASR tokens and knowledge base entries,
embedding-based semantic comparison between transcript segments and brand/product descriptions,
confidence scoring that combines ASR likelihood, contextual fit, and visual cues,
real-time subtitle rewriting that preserves synchronization,
optional human-in-the-loop review for ambiguous corrections, with corrections fed back into the knowledge base for continuous learning.

The system may be deployed as a cloud service, an integrated platform feature, or a local plugin in content production software.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A system for correcting subtitles, comprising:
a processor configured to receive auto-generated subtitles from an automatic speech recognition engine;
a knowledge base of brand names, product names, and personal names;
a correction module configured to detect potential misspellings of said names in the subtitles and replace them with canonical forms from the knowledge base; and
a rendering module configured to output corrected subtitles.
   2.

The system of item 1, wherein the correction module applies contextual inference based on at least one of: video title, video description, video tags, scene analysis, or co-occurrence of terms.

3.

The system of item 1, wherein the rendering module further applies visual emphasis to corrected tokens, such as bold text, italic text, underlining, or color highlighting.

4.

The system of item 1, wherein corrected tokens are annotated with metadata for branding, marketing, or hyperlinking purposes.

5.

The system of item 1, wherein the correction module applies phonetic matching between ASR tokens and entries in the knowledge base.

6.

The system of item 1, wherein optical character recognition or logo detection from video frames provides additional cues for brand recognition.

7.

The system of item 1, wherein corrections are logged together with original tokens and confidence scores for auditing and transparency.

8.

The system of item 1, further comprising a human-in-the-loop interface for low-confidence cases, wherein accepted corrections are stored for future use.

9.

A method for correcting subtitles, comprising:
receiving ASR-generated subtitles with word-level timestamps;
detecting potential brand, product, or personal names in the subtitles;
comparing the detected tokens to a knowledge base of canonical names;
replacing misrecognized tokens with canonical names based on contextual confidence; and
outputting corrected and synchronized subtitles.
   10.

The method of item 9, further comprising styling the corrected names with bold formatting to enhance visibility.

11.

The method of item 9, wherein corrections are prioritized based on contextual similarity between the video topic and the candidate brand or product.

12.

The method of item 9, wherein the corrected subtitles are exported in WebVTT, TTML, or equivalent formats.

13.

The method of item 9, wherein corrected tokens may include embedded metadata for marketing analytics or link tracking.

14.

The method of item 9, wherein corrections are applied in real-time to live streams or as a post-processing step for uploaded content.

15.

The method of item 9, wherein the system supports multilingual correction using language-specific phonetic models and shared entity databases.

### Embodiment AQE: System and Method for Automatic Correction and Emphasis of Brand Names in Subtitles

### Author's Note

This invention entitled “System and Method for Automatic Correction and Emphasis of Brand Names in Subtitles” was co-invented by Nick Reyntjens and Toon De Geyter.

Unless explicitly stated otherwise, all other inventions described in this document are solely invented by Nick Reyntjens.

Disclosed is a system and method for improving the accuracy and presentation of brand names, product names, and personal names in machine-generated subtitles. Automatic speech recognition output is post-processed using a knowledge base, contextual inference, and optional visual cues to detect and correct misrecognized proper nouns. Corrected tokens may be emphasized through styling and annotated with metadata while preserving timing and format integrity. The system may operate in real-time or batch modes, expose observable outputs for verification, and support monetization through licensing and usage metering.

### Gentle Introduction

Automatic subtitles often misspell or split well-known names because speech sounds are ambiguous and context is ignored. Viewers might see “Ex bugs” instead of “Xbox,” or “Fish Air” instead of “Fisher & Paykel,” which confuses audiences and diminishes brand value. The present invention adds a lightweight correction and emphasis layer after speech recognition that understands likely names, the surrounding topic, and what appears on screen. When a spoken phrase is close to a known brand and the context fits, the system replaces the garbled token with the correct, canonical form and may apply a subtle emphasis so the name stands out. This works across common subtitle formats and does not disturb the original timing, so it can be added to existing pipelines with minimal integration effort.

In intuitive terms, the system listens to what the ASR engine produced, checks if any words sound like entries in a curated list of names, considers the video title, description, and even on-screen text or logos, and then decides whether a fix is justified. If so, it swaps in the correct spelling and optionally bolds it or attaches metadata for analytics or linking. This provides a simple but effective improvement that viewers notice immediately and content owners can measure, without requiring them to change how they record or edit their videos.

### Field of the Invention

The present invention relates generally to the field of automated subtitle and caption generation, and more particularly to systems and methods that improve accuracy of brand names, product names, and personal names in machine-generated subtitles, optionally providing stylistic emphasis to such corrected terms.

### Background of the Invention

Online video platforms increasingly rely on automatic speech recognition (ASR) engines to generate subtitles. While these systems perform well for common words, they frequently misrecognize proper nouns, including brand names, product names, and personal names. For example, “Xbox” may appear as “Ex bugs,” or “Samsung Galaxy” as “Sam Sung Gall Ex See.” Such errors negatively impact brand reputation, searchability, and viewer comprehension. In addition, companies and individuals may wish for their names to be highlighted in subtitles (e.g., bold, italic, or styled text) to improve visibility and marketing impact. Existing subtitle systems lack a dedicated correction layer that validates ASR output against contextual knowledge and applies such emphasis consistently.

### Summary of the Invention

The invention provides a system for post-processing subtitles, wherein candidate words from ASR output are analyzed for potential brand, product, or personal names. Suspect tokens may be corrected to verified canonical forms using a knowledge base and contextual cues derived from the video. Verified names may further be emphasized through styling (e.g., bolding) or metadata annotation.

In one embodiment, the system integrates:
a subtitle correction module configured to receive ASR transcripts,
a knowledge base of brand and product names,
a contextual inference engine that leverages video metadata, visual recognition, and natural language processing,
a rendering module that outputs a corrected and optionally styled subtitle track.

This invention thereby improves brand integrity, enhances viewer experience, and creates new opportunities for marketing and monetization in digital media.

### Description of the Drawings

No drawings are included in this application. Elements and relationships relevant to potential figures are described textually in the Anchor for Embodiments and Relationships section. Any figures that may be introduced in later filings are illustrative and non-limiting, and the order or grouping of elements depicted in such figures may differ from the textual descriptions without departing from the scope defined by the claims.

### Detailed Description of the Invention

### Core System Architecture

The system may be positioned between an automatic speech recognition engine and a subtitle rendering engine. It receives ASR output, typically in a structured format such as WebVTT or TTML, containing words, timestamps, and confidence scores.

A natural language processing module may first apply named entity recognition to identify potential proper nouns. Detected tokens are compared against a knowledge base containing brand names, product lines, celebrity names, and other entities. This knowledge base may be curated manually, synchronized from public data sources, or dynamically updated based on trending content.

A contextual inference engine may refine candidate matches by analyzing:
video metadata (title, description, tags),
associated keywords,
scene-level information obtained through OCR of on-screen text or logo recognition,
co-occurrence statistics with other words in the transcript.

Correction decisions may be made when a candidate token aligns phonetically and semantically with a known entity and exceeds a predetermined confidence threshold. The corrected token is substituted into the subtitle track while maintaining original timing alignment.

### Styling and Branding Enhancement

Corrected tokens may further be wrapped in markup tags, such as <b> for bold text in WebVTT or equivalent TTML styling. In some embodiments, styled names may include metadata for marketing purposes, such as clickable links or tracking identifiers.

### Examples

A dishwasher review video generates the subtitle: “I really like my new Fish Air model.” The system corrects to: “I really like my new Fisher & Paykel model.” A livestream outputs: “He's playing on the Ex Bugs console.” The system corrects to: “He's playing on the Xbox console.” The following step-by-step walkthroughs illustrate concrete flows, including optional Model Context Protocol integration and example JSON data structures.

In a batch post-processing scenario for a dishwasher review, the ingest interface receives WebVTT with the line 00:00:05.000→00:00:07.000 I really like my new Fish Air model. The named entity recognizer flags “Fish Air” as a candidate proper noun based on capitalization and token adjacency. The correction module queries the knowledge base for phonetically similar entries, yielding a top candidate. A representative knowledge base record may be stored as JSON such as {“canonical”:“Fisher & Paykel”, “aliases”:[“Fish Air”, “Fisher Paykel”, “Fisher and Paykel”], “brandId”:“BR-002314”, “categories”:[“appliances”, “dishwashers”], “url”:“https://example.co m/brands/fisher-paykel”, “region”:[“US”, “EU”], “styling”:{“vtt”:“<b>% s</b>”, “ttml”:“<span tts:fontWeight=‘bold’>% s</span>”}}. The contextual inference engine then evaluates video metadata such as title “Top 5 Dishwashers in 2025” and description terms “cleaning, rinse aid, stainless steel,” boosting confidence for appliance brands. If OCR on adjacent frames yields “Paykel” from packaging, visual evidence further increases confidence. The unified score crosses the brand threshold defined by policy, so the rendering module substitutes the canonical token and applies policy styling, producing 00:00:05.000→00:00:07.000 I really like my new <b>Fisher & Paykel</b>model. The exporter preserves timecodes and emits a corrected track, while the audit log records the original token “Fish Air,” the chosen canonical “Fisher & Paykel,” evidence sources, and the score.

In a real-time streaming scenario for a gaming broadcast, the streaming handler receives partial ASR hypotheses such as “He's playing on the Ex Bu . . . ” followed by “Ex Bugs” and finally “Ex Bugs console.” The n-best aggregator surfaces alternatives including “Xbox console.” The correction module computes phonetic similarity and consults the knowledge base, then considers stream metadata with tags “gaming, console, play.” Because the unified score exceeds the live threshold, the system backfills the current subtitle line to “He's playing on the <b>Xbox</b>console” without altering the original start time, and stabilizes the line to avoid oscillation by freezing the corrected token once confidence remains above threshold for a dwell interval.

In a negative-control scenario, the transcript contains “We toured the old x box factory,” referring to a literal rectangular storage box. The contextual inference engine determines low topical fit for gaming brands in a documentary about shipping crates, and OCR yields “crating” and “pallets.” The unified score remains below the threshold and no correction is applied. The audit log records the decision and evidence, enabling A/B analysis.

For software interoperability using Model Context Protocol, the system may expose tools that allow an orchestrator to invoke the knowledge base and policy modules as MCP tools. A lookup request may be represented as {“tool”:“brand-kb.lookup”, “arguments”:{“text”:“Ex Bugs console”, “lang”:“en”, “topK”:5, “projectId”:“P-9182”}} and a corresponding response may be {“tool”:“brand-kb.lookup”, “result”:[{“canonical”:“Xbox”, “score”:0.94, “brandId”:“BR-000041”}, {“ca nonical”:“Box”, “score”:0.31, “brandId”:“GEN-BOX”}]}. A policy evaluation tool may be invoked as {“tool”:“brand-policy.evaluate”, “arguments”:{“brandld”:“BR-000041”, “channelId”:“CH-22”, “mode”:“live”, “signals”:{“asrConfidence”:0.82, “phonetic”:0.93, “semantic”:0.88, “ocr”:0.00}}} and return {“tool”:“brand-policy.evaluate”, “result”:{“unified”:0.90, “threshold”:0.75, “action”:“correct-and-style”, “style”:{“vtt”:“<b>% s</b>”}}}. The orchestrator then applies the returned action to rewrite the active line and emits the externally observable corrected subtitle.

A compact example of a sidecar decision log suitable for audit and damages quantification may be {“eventId”:“EVT-7f2al”, “time”:“2025-03-02T12:01:05Z”, “contentId”:“CID-1234”, “lineStartMs”:500 0, “original”:“Fish Air”, “corrected”:“Fisher & Paykel”, “unifiedScore”:0.88, “signals”:{“asr”:0.71, “phonetic”:0.92, “semantic”:0.84, “ocr”:0.36}, “licens e”:{“entitlement”:“LIC-abc”, “tier”:“pro”}, “export”:{“format”:“WebVTT”, “version”:“1.2”}}. These examples demonstrate end-to-end behavior, show externally observable inputs and outputs, and illustrate how MCP-compatible tool calls may fit into the invention.

### Technical Enablements

To enable efficient operation, the system may employ the following:
phonetic similarity matching between ASR tokens and knowledge base entries,
embedding-based semantic comparison between transcript segments and brand/product descriptions, confidence scoring that combines ASR likelihood, contextual fit, and visual cues,
real-time subtitle rewriting that preserves synchronization,
optional human-in-the-loop review for ambiguous corrections, with corrections fed back into the knowledge base for continuous learning.

The system may be deployed as a cloud service, an integrated platform feature, or a local plugin in content production software.

### Anchor for Embodiments and Relationships

For clarity across embodiments and claims, the subtitle processing pipeline may be understood as comprising the following elements and relationships. An ASR output source provides machine-generated subtitles to an ingest interface that normalizes formats and timebases. A correction module operates in concert with a natural language processing component applying named entity recognition to detect candidate proper nouns. A knowledge base stores canonical brand, product, and personal names together with phonetic aliases, semantic descriptors, and optional visual cues. A contextual inference engine combines phonetic similarity, text-embedding similarity, ASR confidence, and visual evidence from optical character recognition and logo detection to produce a unified confidence used to decide substitutions. When a substitution is made, the rendering module preserves original timing while inserting corrected tokens and, optionally, styling and metadata annotations. Export encoders emit corrected subtitles in multiple formats, and a logging and audit store records original tokens, decisions, confidence scores, license validations, and export events. A human-in-the-loop interface may review low-confidence proposals and update the knowledge base and policies. A licensing subsystem validates signed entitlements that enable or disable features, while a usage metering subsystem issues cryptographically signed receipts recording feature usage and content identifiers. A monitoring subsystem exposes health, latency, throughput, and error metrics. An API layer accessible via REST, WebSocket, gRPC, or message queues enables integration and may interoperate with Model Context Protocol to exchange prompts, tools, and resources relevant to correction policies. Policy configuration governs styling preferences, regional variants, abbreviations, and disallowed substitutions. Multilingual models and per-language entity databases support cross-lingual normalization. A real-time streaming handler processes partial ASR hypotheses with incremental updates, and an n-best aggregator rescored alternatives prior to correction to improve robustness. Privacy-preserving transforms and tamper-evident storage protect sensitive data and provide forensic evidence. Inputs are externally observable as incoming subtitle tracks and optional video frames; outputs are externally observable as corrected subtitle tracks with optional emphasis and embedded attribution metadata, suitable for field verification and infringement analysis.

### Monetization and Damages Maximization

The system may be provisioned as a subscription service with metered usage that records the number of subtitle lines processed, minutes of media analyzed, languages used, and features invoked, such as contextual inference, OCR, logo detection, or styling. An account service may issue signed entitlements that enable or disable specific capabilities per subscription tier, with the rendering module and correction module validating entitlements at runtime to enforce tier boundaries without affecting timing alignment. A usage metering component may generate cryptographically signed usage receipts that include time-bounded counters, account identifiers, and feature flags, which may be exported to billing systems and retained in append-only logs to support auditability.

In some embodiments, the system may embed non-intrusive attribution metadata into the corrected subtitle track, such as a vendor identifier, entitlement token hash, or time-bounded attestation code placed in a comment field of WebVTT, a metadata element in TTML, or an auxiliary sidecar file associated via a content identifier. These externally observable markers may allow verification of licensed use in the field and may facilitate quantification of infringement by correlating discovered markers or their absence with metered usage records. For offline or on-premises deployments, the system may use renewable license tokens with local counters that are reconciled upon connectivity, together with tamper-evident storage that records correction decisions, confidence scores, and export events to help establish volume and scope of use.

The service may support differentiated pricing for live streaming versus batch post-processing, with service-level objectives expressed as maximum end-to-end latency and minimum throughput, and the platform may expose real-time health and usage endpoints to customers for capacity planning. Administrative dashboards may allow per-seat management, role-based access control over project libraries and knowledge base edits, and exportable reports that summarize usage by project, brand category, or geography. Together, these technical features may enable subscription, per-seat, and usage-based monetization models and may increase the ability to demonstrate and quantify damages by providing detailed, trustworthy records of capability access and content processed.

### Scope and Interpretation

The scope of this invention is defined solely by the claims. The abstract, the gentle introduction, any examples, and any described embodiments are provided to facilitate understanding and are not intended to limit the scope. Any figures or figure references, if present, are illustrative. Operations described in a particular order may be performed in a different order, in parallel, or with steps omitted or added where appropriate, and named modules may be combined, subdivided, distributed, replicated, or implemented across hardware, software, or firmware without departing from the claimed scope. Protocols, interfaces, formats, models, and thresholds described herein are examples; equivalent alternatives may be used. Unless expressly stated otherwise, terms such as comprising, including, having, and containing are open-ended and do not exclude additional elements or steps, and articles such as a, an, and the are intended to mean one or more.

As used herein, a knowledge base may be explicit or implicit and may include structured tables, glossaries, registries, or parameterized representations within machine-learned models such as neural networks, weighted finite-state transducers, or probabilistic lexicons. A correction module may operate as a post-processor, as an in-line rescoring component, or as a component integrated into an ASR decoder via constrained decoding, vocabulary injection, or language-model fusion, and remains within scope when it normalizes tokens to canonical forms based on knowledge resources and context. Subtitles encompass captions, timed text, and equivalent artifacts across media standards. A rendering module includes any component that emits corrected tokens, styling, or metadata as rewritten tracks or as sidecar delta patches, while preserving synchronization. Canonicalization may include merging or splitting subword units, restoring punctuation, capitalization, diacritics, and policy-governed trademark symbols or regional variants.

### Itemized List of Embodiments and Features

In practice it is preferred to implement automated bandname correction in YouTube subtitles, which leads to more accurate and reliable subtitle data being presented to viewers. As a result, redundant manual corrections, repeated reporting, and unnecessary search queries are avoided. More specifically, the system produces the effect of improving data integrity in subtitle pipelines because errors are corrected automatically and consistently across all distributed instances, which results in lower processor cycles, reduced network bandwidth consumption, and faster convergence to accurate information. Since fewer redundant operations are triggered, the system indirectly reduces overall energy consumption and carbon footprint, while its primary effect is improved efficiency and reliability of digital subtitle processing.

Embodiments can be described by the following itemized list, each item providing explicit support suitable for use in continuations and comprising alternatives to broaden scope. Each claim of this application is also represented herein as a corresponding item to preserve support should claim text be modified or removed in future filings:
1. A system comprising a processor to receive auto-generated subtitles from an automatic speech recognition engine, a knowledge base of brand names, product names, and personal names, a correction module to detect potential misspellings of said names and replace them with canonical forms from the knowledge base, and a rendering module to output corrected subtitles.
2. The system of item 1 wherein the correction module may apply contextual inference based on at least one of video title, video description, video tags, scene analysis, or co-occurrence of terms.
3. The system of item 1 wherein the rendering module may apply visual emphasis to corrected tokens, including bold, italic, underline, color, outline, shadow, or font substitution while preserving timing alignment.
4. The system of item 1 wherein corrected tokens may be annotated with metadata for branding, marketing, hyperlinking, analytics, tracking identifiers, or affiliate codes.
5. The system of item 1 wherein the correction module may apply phonetic matching between ASR tokens and entries in the knowledge base using algorithms such as Soundex, Metaphone, Double Metaphone, or learned grapheme-to-phoneme models.
6. The system of item 1 wherein optical character recognition and or logo detection from video frames may provide additional cues for brand recognition, including detection of packaging, on-screen lower-thirds, or watermarks.
7. The system of item 1 wherein corrections may be logged together with original tokens, timestamps, and confidence scores for auditing, transparency, rollback, or A/B testing.
8. The system of item 1 further comprising a human-in-the-loop interface for low-confidence cases, wherein accepted corrections may be stored for future use and to retrain models or update rules.
9. A method comprising receiving ASR-generated subtitles with word-level timestamps, detecting potential brand, product, or personal names, comparing detected tokens to a knowledge base of canonical names, replacing misrecognized tokens with canonical names based on contextual confidence, and outputting corrected and synchronized subtitles.
10. The method of item 9 further comprising styling corrected names with bold formatting to enhance visibility, with user or policy-configurable styles per brand.
11. The method of item 9 wherein corrections may be prioritized based on contextual similarity between the video topic and candidate brand or product derived from embeddings, topic models, or keyword overlap.
12. The method of item 9 wherein corrected subtitles may be exported in WebVTT, TTML, SRT, SSA or ASS, MPEG-TS caption tracks, or CEA-608 or CEA-708 formats.
13. The method of item 9 wherein corrected tokens may include embedded metadata for marketing analytics, link tracking, targeting, or attribution measurement.
14. The method of item 9 wherein corrections may be applied in real-time to live streams or as a post-processing step for uploaded content, including near-real-time low-latency modes.
15. The method of item 9 wherein multilingual correction may be supported using language-specific phonetic models, shared or per-language entity databases, and cross-lingual entity normalization.
16. A computer-readable medium storing instructions that, when executed by one or more processors, may perform any of the methods described in items 9 through 15, including receiving subtitles, detecting entities, correcting tokens, styling, exporting, and logging.
17. An architecture wherein the knowledge base may be sourced from manual curation, public datasets, commercial brand registries, user-uploaded glossaries, or dynamically learned entities from trending content, with offline caches and periodic synchronization.
18. A contextual inference engine that may combine phonetic similarity, semantic similarity from text embeddings, visual evidence from OCR or logo detection, and ASR confidence into a unified score with adjustable thresholds per brand, per channel, or per project.
19. A deployment model wherein components may run as a cloud service, as on-premises software, as an offline desktop plug-in, as a mobile SDK for on-device processing, or as an edge service co-located with streaming infrastructure.
20. An interoperability layer that may accept and emit multiple subtitle and caption formats, timebases, and character encodings, including UTF-8 and UTF-16, with automatic normalization and safe round-tripping of timing and styling.
21. An external observability mechanism wherein non-intrusive attribution metadata may be embedded into corrected subtitle tracks or sidecar files to enable field verification of licensed use and to support damage quantification.
22. A licensing subsystem wherein signed entitlements may enable or disable contextual inference, OCR, logo detection, styling, multilingual features, or export formats, enforced locally without breaking playback synchronization.
23. A usage metering subsystem wherein cryptographically signed receipts may include time-bounded counters, account identifiers, feature flags, and content identifiers, stored in append-only logs for auditability and reconciliation.
24. A human review workflow wherein proposed corrections may be surfaced in a UI showing original tokens, candidate entities, evidence sources, and confidence, with one-click accept or reject and automatic propagation to future projects.
25. A fallback embodiment wherein only a static brand glossary and phonetic matching may be used without any visual analysis or embeddings, still providing improved accuracy over raw ASR.
26. A fallback embodiment wherein the system may apply emphasis styling to already-correct tokens based on detection of canonical names without performing any correction.
27. A privacy-preserving embodiment wherein OCR and logo detection may operate on hashed visual features or on-device processing, with optional redaction of frames or suppression of logs containing sensitive content.
28. A robustness feature wherein the system may handle noisy ASR by aggregating over multiple ASR hypotheses (n-best lists) or by rescoring alternative segmentations prior to correction.
29. A real-time streaming embodiment wherein the system may operate on partial ASR hypotheses with incremental updates, backfilling corrected tokens and restyling lines while maintaining user-perceived stability.
30. A user-configurable policy system wherein content owners may define per-brand rules including preferred stylistic treatment, capitalization, regional variants, permitted abbreviations, and disallowed substitutions.
31. An API surface that may be exposed via REST, WebSocket, gRPC, or message queues, and may optionally interoperate with model-context protocols to exchange prompts, tools, or resources relevant to correction policies.
32. A knowledge base representation that may include JSON or key-value records mapping canonical names to phonetic aliases, visual cues, and URLs, together with versioning and rollback capabilities.
33. A monitoring subsystem wherein real-time health, latency, throughput, and error rates may be exposed to customers for capacity planning and SLA compliance.
34. A testing framework wherein synthetic corruption of brand names may be injected into transcripts to measure correction accuracy, false positives, latency, and stability across languages and formats.
35. A security feature wherein tamper-evident storage may record correction decisions, confidence scores, license validations, and export events to establish volume and scope of use for compliance and forensic analysis.
36. An embodiment wherein the knowledge base is implemented as parameters of a machine-learned model including neural network embeddings, weighted finite-state transducers, or probabilistic lexicons, and the correction module queries or scores candidates via that parameterized representation rather than an explicit list.
37. An embodiment wherein the correction logic is integrated into the ASR decoder as lexicon biasing, constrained decoding, shallow or deep language-model fusion, on-the-fly vocabulary injection, or n-best rescoring, while still substituting canonical forms and optionally applying styling.
38. An embodiment wherein candidate tokens comprise subword units, byte-pair encodings, wordpieces, or phoneme sequences, and the correction module merges, splits, or normalizes such units to produce the canonical brand form.
39. An embodiment wherein the system preserves or applies trademark symbols, capitalization, diacritics, punctuation, and regional orthography variants per policy when emitting the canonical name.
40. An embodiment wherein correction decisions are exposed via a deterministic API contract such that a black-box system producing identical externally observable corrected tracks and logs falls within the scope.
41. An embodiment wherein the knowledge resource is composed at runtime from multiple sources including implicit model parameters, explicit glossaries, and ephemeral per-session injections, with conflict resolution policies.
42. An embodiment wherein the correction module operates entirely on-device in a media player, mobile device, set-top box, or smart TV prior to rendering, using locally provisioned models and knowledge resources without server connectivity.
43. An embodiment wherein brand correction is performed using only audio features and phonetic similarity without video or metadata, and alternatively using only OCR or logo signals without audio, each still producing corrected subtitles.
44. An embodiment wherein the correction module applies denoising to ASR hypotheses using confusion sets learned from historical errors specific to brands and products, improving robustness against adversarial or unusual pronunciations.
45. An embodiment wherein the rendering module emits corrections as sidecar delta patches that patch an existing subtitle file at load time, enabling integration where direct rewriting is restricted.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A system for correcting subtitles, comprising:
a processor configured to receive auto-generated subtitles from an automatic speech recognition engine;
a knowledge base of brand names, product names, and personal names;
a correction module configured to detect potential misspellings of said names in the subtitles and replace them with canonical forms from the knowledge base; and
a rendering module configured to output corrected subtitles.
   2.

The system of item 1, wherein the correction module applies contextual inference based on at least one of: video title, video description, video tags, scene analysis, or co-occurrence of terms.

3.

The system of item 1, wherein the rendering module further applies visual emphasis to corrected tokens, such as bold text, italic text, underlining, or color highlighting.

4.

The system of item 1, wherein corrected tokens are annotated with metadata for branding, marketing, or hyperlinking purposes.

5.

The system of item 1, wherein the correction module applies phonetic matching between ASR tokens and entries in the knowledge base.

6.

The system of item 1, wherein optical character recognition or logo detection from video frames provides additional cues for brand recognition.

7.

The system of item 1, wherein corrections are logged together with original tokens and confidence scores for auditing and transparency.

8.

The system of item 1, further comprising a human-in-the-loop interface for low-confidence cases, wherein accepted corrections are stored for future use.

9.

A method for correcting subtitles, comprising:
receiving ASR-generated subtitles with word-level timestamps;
detecting potential brand, product, or personal names in the subtitles;
comparing the detected tokens to a knowledge base of canonical names;
replacing misrecognized tokens with canonical names based on contextual confidence; and
outputting corrected and synchronized subtitles.
   10.

The method of item 9, further comprising styling the corrected names with bold formatting to enhance visibility.

11.

The method of item 9, wherein corrections are prioritized based on contextual similarity between the video topic and the candidate brand or product.

12.

The method of item 9, wherein the corrected subtitles are exported in WebVTT, TTML, or equivalent formats.

13.

The method of item 9, wherein corrected tokens may include embedded metadata for marketing analytics or link tracking.

14.

The method of item 9, wherein corrections are applied in real-time to live streams or as a post-processing step for uploaded content.

15.

The method of item 9, wherein the system supports multilingual correction using language-specific phonetic models and shared entity databases.

16.

A non-transitory computer-readable medium storing instructions that, when executed by one or more processors, cause the processors to perform the method of any of items 9 through 15.

17.

The system of item 1, wherein corrected subtitles include non-intrusive attribution metadata embedded into the subtitle track or a sidecar file to enable field verification of licensed use.

18.

The system of item 1, further comprising a licensing subsystem configured to validate signed entitlements that enable or disable contextual inference, optical character recognition, logo detection, styling, multilingual features, or export formats without affecting playback synchronization.

19.

The system of item 1, further comprising a usage metering subsystem configured to generate cryptographically signed usage receipts including time-bounded counters, account identifiers, feature flags, and content identifiers, stored in append-only logs for auditability.

20.

The system of item 1, wherein a contextual inference engine combines phonetic similarity, semantic similarity from text embeddings, visual evidence from OCR or logo detection, and ASR confidence into a unified score with adjustable thresholds per brand, per channel, or per project.

### Embodiment AR: System and Method for Narrative Function Detection and Adaptive Scene Skipping in Media Playback

### Author's Note

This invention entitled “System and Method for Narrative Function Detection and Adaptive Scene Skipping in Media Playback” was co-invented by Nick Reyntjens, Toon De Geyter, and Laurent Mazé.

Unless explicitly stated otherwise, all other inventions described in this document are solely invented by Nick Reyntjens.

A system and method are disclosed for adaptive playback of audio-visual media using narrative-aware artificial intelligence. The system includes a scene-to-text pipeline that segments a media stream into scenes with defined start and stop times and generates structured annotations for each segment. The annotations comprise activity descriptors (e.g., singing, fighting, reading), narrative function labels (e.g., flashback, exposition, filler, climax, transition), and tonal attributes (e.g., comic, suspenseful, tragic). Together these annotations form a narrative map of the media. A decision-making module applies viewer-specific parameters to the narrative map, including a skip profile that specifies categories of content to omit and a knowledge state model representing what the viewer has already experienced. Based on these factors, the system determines whether each scene is played, skipped, enlarged, or explained, with optional augmentation such as text-to-speech of visual clues or enlargement of on-screen text. The invention enables continuity-preserving editing that omits unwanted or redundant content while enhancing accessibility and comprehension for diverse viewers, including those with declining eyesight or difficulty perceiving subtle narrative elements.

### Background of the Invention

The present invention relates generally to systems for playback of audio-visual media, and more particularly to adaptive playback systems that employ artificial intelligence to modify media presentation based on narrative structure and viewer-specific preferences.

Conventional media playback devices, including televisions, set-top boxes, and streaming platforms, typically provide linear playback of films, television episodes, or online videos. While some systems allow manual fast-forwarding or skipping, these actions require continuous user input and do not adapt intelligently to viewer behavior. More advanced solutions, such as parental controls or content filtering services, permit the omission of pre-defined categories of content such as nudity, profanity, or violence. These systems, however, generally rely on manually generated tags or metadata, and operate without understanding the broader narrative function of a scene. As a result, they may remove or mute content in a way that disrupts continuity or fails to consider the viewer's knowledge of the storyline.

In addition, current accessibility features for media playback, such as closed captioning, enlarged subtitles, or audio description, provide important assistance but remain limited to static augmentations. Such tools do not adapt dynamically to the narrative context or the evolving needs of an individual viewer. For example, a viewer with declining eyesight may miss an on-screen note critical to the plot, while an elderly viewer binge-watching a series may be forced to watch redundant flashback sequences that add little informational value.

There is therefore a need for a system that combines semantic understanding of media content with viewer-specific profiles and knowledge states, enabling playback that is both personalized and continuity-preserving. Such a system would be capable of detecting narrative functions such as flashbacks, filler segments, and exposition, while also recognizing activities and tonal attributes. By linking this information to a decision-making module that respects user preferences and prior viewing history, media playback can be adapted to omit undesired content, skip redundant segments, or highlight and explain critical story clues.

### Examples

In one embodiment, the system may be applied to a television series in which the viewer repeatedly skips certain types of content, such as musical interludes. When the system detects that the viewer has manually skipped three or more scenes annotated as “singing,” the skip profile may be automatically updated to omit such scenes in subsequent episodes or related series, thereby reducing repetitive manual input.

In another embodiment, the system may be used during binge-watching of a serialized program. The decision-making module, informed by the viewer's knowledge state, may recognize that flashback sequences repeat content already viewed in prior episodes. In this case the system may automatically skip or compress the flashback segments, preserving narrative continuity while avoiding redundancy for the viewer.

In a further embodiment, the system may be applied to instructional media, such as software tutorials. If the viewer's knowledge state indicates that introductory concepts have already been learned in earlier sessions, the system may bypass basic segments and advance directly to advanced topics, thereby tailoring the presentation to the viewer's prior experience.

### Detailed Description

The invention provides a system for adaptive playback of media based on semantic scene analysis and narrative reasoning. In a first aspect, a scene-to-text artificial intelligence pipeline segments a media stream into scenes and generates structured annotations. Each scene is annotated with activity information (e.g., singing, fighting, reading), narrative function (e.g., flashback, exposition, filler, climax, transition), and tone or emotional state (e.g., comic, tragic, suspenseful). This produces a narrative map of the media stream that extends beyond conventional content tagging.

In a second aspect, a decision-making module consults the narrative map in conjunction with viewer-specific inputs. A skip profile allows the viewer to define categories of content to omit, such as romance, filler songs, or violence. A knowledge state model of the viewer, derived from prior viewing history and recognized redundancy within the media (e.g., repeated flashbacks, recaps), further informs the decision. As a result, the system automatically determines whether a given scene is played, skipped, enlarged, or explained, thereby preserving narrative coherence while tailoring playback to the viewer's preferences and perceptual needs.

### Scene-to-Text Processing Module:

In one embodiment, a scene-to-text processing module may be configured to associate each segment of a media stream with descriptive metadata, including activities, narrative functions, and tonal attributes. More specifically, the system may first employ scene segmentation algorithms (known in the art for dividing a continuous video into shots and higher-level scenes) to determine the start and stop time of each unit of analysis. Within these temporal boundaries, an activity recognition model (for example, a convolutional or transformer-based video classifier) may identify dominant actions such as “singing,” “fighting,” or “reading.”

In parallel, a multimodal emotion and sentiment classifier may analyze visual, auditory, and textual signals to characterize the emotional tone of the segment (e.g., comic, tragic, suspenseful). Further, natural-language processing applied to subtitles or generated transcripts may provide contextual clues, enabling a narrative function classifier trained on corpora of annotated stories to assign labels such as “flashback,” “exposition,” “climax,” or “resolution.” For cases where the media includes repeated information, the system may also apply semantic similarity and redundancy detection across transcripts, thereby recognizing recaps or flashbacks that add little new information to a binge-watching viewer.

By combining the temporal boundaries from scene segmentation with the descriptive outputs of activity recognition, tonal classification, and narrative function detection, the system produces a narrative map of the media stream. Each scene is thus represented not only by its start and stop time but also by a structured annotation of what is happening, how it functions in the storyline, and what affective tone it conveys. This rich annotation enables subsequent modules, such as a decision-making engine, to select whether the scene should be presented in full, skipped, enlarged, or explained, based on a viewer's personalized profile and knowledge state.

In one embodiment, the scene-to-text processing module may be realized as a pipeline that integrates video segmentation, multimodal feature extraction, natural language processing, and semantic similarity analysis. The module operates on an incoming media stream and outputs a structured annotation for each detected scene. The process begins with segmentation, where the continuous video is divided into smaller temporal units. Shot boundaries may be detected using histogram differencing, edge change ratios, or deep neural networks trained on large video corpora. Adjacent shots are then clustered into higher-level scenes using similarity measures between learned visual embeddings, such as cosine distance in a CLIP-like embedding space. The outcome of this stage is a set of discrete scenes, each with a defined start and stop time suitable for subsequent annotation.

Within these temporal boundaries, multimodal features are extracted. The visual channel may be processed by a 3D convolutional network or transformer-based architecture such as SlowFast or ViViT, producing labels that describe dominant activities, including “singing,” “fighting,” or “reading.” The audio channel may be processed by spectrogram-based convolutional models or self-supervised speech models such as wav2vec2, providing information about speech segments, background music, silence, or emotional prosody. Textual information may be captured both through automatic speech recognition applied to dialogue and optical character recognition applied to on-screen elements such as letters, signs, or phone messages. These heterogeneous representations may be aligned and fused in a multimodal transformer model, which produces a unified latent embedding of the scene.

Narrative function detection may be carried out by models trained on annotated datasets of television, film, or literature, where scenes are labeled as exposition, climax, filler, resolution, or flashback. Flashbacks may be identified by a combination of multimodal cues, including abrupt shifts in color grading, insertion of temporal markers in dialogue (“yesterday . . . ”, “long ago”), or high semantic overlap with earlier transcript material. Redundancy detection may be implemented by computing embeddings of transcript segments using a sentence-BERT model and comparing them against a memory of previously processed content. When similarity exceeds a defined threshold, the system infers that the current scene is a recap or repetition.

An emotion and sentiment classifier may also operate on the fused multimodal embedding. This classifier can be trained using datasets of film clips annotated with emotional categories, enabling the system to assign tonal attributes such as comic, tragic, suspenseful, or romantic. The outputs of activity recognition, narrative function detection, sentiment classification, and redundancy analysis are then combined with the temporal boundaries established earlier.

The result is a narrative map of the media stream in which each scene is represented not only by its start and stop times but also by structured metadata describing what occurs within the scene, how the scene contributes to the narrative structure, and the emotional tone conveyed. This representation is stored in a structured format, such as JSON or protocol buffers, which allows downstream modules to access the annotations in real time. Subsequent components, such as the skipping logic module, may then query this map to determine whether to present, omit, enlarge, or explain the scene in accordance with a viewer profile and knowledge state.

### Skipping Logic Module

In one embodiment, a skipping logic module may be configured to determine, for each annotated scene, whether the scene is to be presented in full, omitted, condensed, or augmented. The skipping logic module receives as input the narrative map generated by the scene-to-text processing module together with one or more viewer-specific parameters.

A first parameter may comprise a skip profile, defined by explicit user selections such as “skip romance scenes,” “skip filler songs,” or “skip violent content.” When the narrative map indicates that a scene is annotated with one or more categories designated in the skip profile, the skipping logic module may instruct the playback system to omit the corresponding scene or to advance directly to the subsequent scene boundary.

A second parameter may comprise a knowledge state model that reflects what the viewer has previously consumed. The knowledge state may be determined by tracking the viewer's prior playback history across episodes or sessions, and by applying semantic similarity analysis to detect redundant narrative elements. For example, if the system detects that a flashback sequence reproduces content already viewed by the same viewer in an earlier episode, the skipping logic module may classify the scene as redundant and automatically bypass it.

In certain embodiments, the skipping logic module may not only skip but also substitute explanatory augmentation to preserve narrative continuity. For example, where a skipped scene establishes a relationship change between characters, the module may insert a micro-recap statement (“Two hours later, the characters are shown as a couple”) generated from the narrative map. In another example, if the scene contains a visual clue, such as a note or message on a screen, the skipping logic module may suppress the surrounding filler content but enlarge and display the clue text or provide a text-to-speech narration of the clue to the viewer.

The skipping logic module may thus operate as a rule-based and learning-enhanced decision system, combining explicit user preferences with inferred redundancy detection and context-preserving augmentation. The result is a personalized final edit that maintains narrative coherence while eliminating undesired, repetitive, or inaccessible content.

In one embodiment, the skipping logic may be implemented as a software pipeline integrated into a smart television, a set-top box, or a cloud-based streaming platform. The media stream is first divided into scenes by applying automated segmentation algorithms. Shot boundary detection may be carried out through histogram difference, frame correlation, or transformer-based video segmentation, and these shots are then clustered into coherent scenes by similarity analysis of visual embeddings. Each scene is therefore associated with a start and stop time that defines a temporal decision boundary.

Within each identified scene, multimodal feature extraction is performed. A video classifier based on convolutional or transformer architectures may identify dominant activities such as fighting, kissing, or singing. An audio model trained on spectrograms or raw waveform representations may further detect music, speech, silence, or emotional prosody. Speech recognition and optical character recognition may be used to generate textual transcripts from dialogue and to extract on-screen text such as letters or phone messages. These visual, auditory, and textual embeddings may be fused in a multimodal transformer framework, producing a joint representation of the scene.

Narrative function detection may then be carried out by supervised models trained on corpora of annotated stories and question-answering datasets. Such models classify each scene as flashback, exposition, filler, climax, or resolution. Flashbacks can be recognized by temporal inconsistencies in film characteristics or dialogue references to prior events, while recaps may be detected by comparing transcripts against previously viewed content using semantic similarity measures. Redundant sequences are identified when transcript embeddings exceed a similarity threshold with earlier material in the viewer's history.

A knowledge state model is maintained in parallel to represent what the viewer has already consumed. This may take the form of a graph or embedding memory that is updated incrementally as scenes are viewed. When a new scene is analyzed, its transcript and activity representation are compared to the knowledge state; if high similarity is detected, the system infers that the viewer has already assimilated the content, and the sequence may be classified as redundant.

The decision engine consults the narrative map together with the skip profile and knowledge state to determine the appropriate playback action. When a scene matches a category designated in the skip profile, the playback pointer is advanced to the next decision boundary. When redundancy is detected, the system may bypass the scene or insert a condensed recap to preserve narrative coherence. If a skipped scene contains a narrative-critical element, such as a textual clue extracted by OCR, the system may momentarily enlarge or read aloud the clue before resuming playback. The output is thus a personalized final edit that maintains continuity while eliminating undesired or repetitive segments.

The system may continue to refine its decisions through learning from user interaction. If a viewer reverses a skip to watch a segment, this feedback may reduce the confidence threshold for future omissions. If skipped scenes are never revisited, the system reinforces that behavior as appropriate. Over time, the skip profile becomes adaptive, evolving with the viewer's demonstrated preferences and consumption habits.

### Buffering and Processing Pipeline

In one embodiment, the displaying device may be configured with a dual-buffer system that ensures both seamless playback and sufficient time for semantic analysis. A first buffer may store incoming media packets as they are received from the streaming source. The buffer size may be dynamically adjustable but, in atypical case, may correspond to several minutes of media content, for example five minutes. This first buffer allows the device to accumulate enough material so that portions of the media can be analyzed and, if necessary, skipped, without creating perceptible interruptions in playback.

A second buffer, referred to as the processed buffer, may store the media content after it has been analyzed by the scene-to-text pipeline and subjected to the skipping logic. The processing pipeline operates on the first buffer in a look-ahead fashion, examining upcoming segments before they are required for playback. Scene boundaries are detected, features are extracted, and narrative functions are classified in advance. For each scene, the decision-making module determines whether the segment is to be copied directly into the processed buffer, omitted entirely, or substituted by an alternative representation such as a condensed summary or a textual or spoken explanation of a critical clue.

During playback, the device reads sequentially from the processed buffer. Because the decisions have already been made ahead of time, playback can proceed without latency, even if the underlying analysis required intensive computation. This design also allows seamless transitions between retained and omitted content, since the processed buffer contains only the media that will actually be presented to the viewer.

In certain embodiments, the system may operate in parallel: while the viewer is consuming one portion of the processed buffer, the pipeline continues analyzing upcoming content in the first buffer and populating the next segment of the processed buffer. If the user alters preferences or issues corrective feedback (such as manually replaying a skipped scene), the system may reprocess relevant segments from the first buffer and adjust the processed buffer accordingly. This architecture ensures that the adaptive playback is both responsive and continuity-preserving while meeting the computational requirements of semantic augmentation and narrative reasoning.

### Flow of the Invention

In one embodiment, the method may proceed in the following steps.

### Step 1: Receiving Media Packets.

A media stream is received in the form of compressed packets from a broadcast source, file, or online service. The packets are collected by the system for further processing.

### Step 2: Input Buffering.

The incoming packets are accumulated in an input buffer. The buffer is of sufficient duration, for example five minutes of playback time, to provide both temporal space for later skipping of sections and computational time to perform semantic analysis in advance of playback.

### Step 3: Scene Segmentation.

The content of the input buffer is divided into discrete scenes. This segmentation may be achieved by detecting shot boundaries and grouping them into higher-level scenes, thereby producing start and stop times for each scene.

### Step 4: Feature Extraction.

Each scene is analyzed through multiple channels. A video classifier detects activities such as singing, fighting, or reading. An audio classifier distinguishes speech, music, silence, or emotional prosody. A text pipeline converts dialogue into transcripts via speech recognition and extracts visual text via optical character recognition. The outputs are fused into a multimodal representation of the scene.

### Step 5: Narrative Function and Tone Classification.

The multimodal representation is further analyzed to assign a narrative function label such as exposition, flashback, or filler. An emotion classifier may add tonal attributes such as tragic or suspenseful. Transcript embeddings may be compared with previously viewed material to detect redundant or recap scenes.

### Step 6: Narrative Map Generation.

For each scene, the metadata produced in Steps 4 and 5 is associated with its start and stop times to create a narrative map of the buffered portion of the media. The narrative map describes what occurs in the scene, how it functions in the storyline, and what affective tone it conveys.

### Step 7: Decision Making.

The narrative map is passed to a decision-making module. This module consults the viewer's skip profile (e.g., to omit romance or filler songs) and the viewer's knowledge state model (e.g., to avoid flashbacks already seen). For each scene, the module determines whether to retain it, skip it, shorten it, or replace it with an augmentation such as a summary or enlarged clue.

### Step 8: Processed Buffering.

Scenes designated for presentation are copied into a processed buffer. Scenes to be omitted are not transferred, and scenes designated for augmentation are replaced with the corresponding summaries, recaps, or enlarged textual elements.

### Step 9: Playback.

The system reads sequentially from the processed buffer to deliver playback to the viewer. Since the processed buffer contains only the final edit, playback proceeds seamlessly without delay when skipped portions occur.

### Step 10: Continuous Look-Ahead.

While playback is proceeding from the processed buffer, the pipeline continues processing new material from the input buffer in a look-ahead fashion. The cycle of segmentation, feature extraction, classification, and decision-making continues so that playback remains uninterrupted.

### Step 11: Feedback and Adaptation.

If the viewer manually overrides a skip, revisits a scene, or alters preferences, the system reprocesses the relevant portion of the input buffer and updates the processed buffer accordingly. The skip profile and knowledge state are also updated so that future playback reflects the viewer's demonstrated behavior.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A system for adaptive media playback, comprising:
an input buffer configured to receive and temporarily store a portion of a media stream;
a scene-to-text processing module configured to segment the media stream into discrete scenes with start and stop times and to generate, for each scene, structured annotations including at least one of an activity descriptor, a narrative function label, and atonal attribute;
a decision-making module configured to generate a narrative map from the structured annotations and to determine, based on a skip profile and a knowledge state model of a viewer, whether each scene is to be presented, skipped, condensed, or augmented; and
a processed buffer configured to store the media stream as modified by the decision-making module for seamless playback.
   2.

The system of item 1, wherein the scene-to-text processing module comprises a video classifier, an audio classifier, and a text analysis module, and wherein outputs from the classifiers are fused into a multimodal representation of each scene.

3.

The system of item 1, wherein the narrative function label is selected from a group consisting of:
flashback, exposition, filler, climax, resolution, and transition.
   4.

The system of item 1, wherein the tonal attribute is selected from a group consisting of: comic, tragic, suspenseful, romantic, and neutral.

5.

The system of item 1, wherein the knowledge state model comprises a memory of transcript embeddings of previously viewed material, and the decision-making module is configured to detect redundancy by comparing a current transcript embedding with stored embeddings.

6.

The system of item 1, wherein the skip profile comprises viewer-specified categories of content to omit, including at least one of: romance, violence, filler songs, or flashbacks.

7.

The system of item 1, wherein the decision-making module is further configured to substitute a skipped scene with a condensed summary or micro-recap statement to preserve narrative continuity.

8.

The system of item 1, wherein the decision-making module is further configured to enlarge and display on-screen text detected by optical character recognition when the corresponding scene is skipped.

9.

The system of item 1, wherein the decision-making module refines the skip profile over time by incorporating feedback from viewer overrides of skipped or presented scenes.

10.

The system of item 1, wherein the input buffer and processed buffer operate in a look-ahead fashion such that segmentation, annotation, and decision-making for future scenes are performed while current scenes are being played.

11.

A method for adaptive media playback, comprising:
receiving a media stream and storing a portion of the media stream in an input buffer;
segmenting the media stream into scenes having start and stop times;
generating structured annotations for each scene, the annotations including at least one of an activity descriptor, a narrative function label, and a tonal attribute;
constructing a narrative map from the annotations;
applying a skip profile and a knowledge state model of a viewer to the narrative map;
determining whether each scene is to be presented, skipped, condensed, or augmented;
transferring selected scenes and augmentations to a processed buffer; and
presenting the contents of the processed buffer to the viewer as seamless playback.
   12.

The method of item 11, further comprising detecting flashbacks by comparing transcript embeddings of current and prior scenes and classifying the scene as redundant if similarity exceeds a threshold.

13.

The method of item 11, further comprising detecting tonal attributes of each scene by applying a multimodal sentiment classifier to video, audio, and textual inputs.

14.

The method of item 11, further comprising dynamically reprocessing the input buffer upon receiving corrective feedback from the viewer.

15.

The method of item 11, further comprising substituting skipped scenes with explanatory augmentation, including at least one of a textual summary, a spoken recap, or enlargement of on-screen clues.

16.

A non-transitory computer-readable medium storing instructions that, when executed by one or more processors, cause the processors to perform the method of item 11.

17.

The system of item 1, wherein the scene-to-text processing module employs a transformer-based multimodal neural network trained on annotated corpora of film and literature to assign narrative function labels.

18.

The system of item 1, wherein the processed buffer is configured to store only media segments designated for presentation, thereby enabling seamless transitions between retained and omitted scenes.

19.

The method of item 11, wherein the skip profile is automatically updated when the system detects that a viewer has manually skipped a category of scenes three or more times.

20.

The system of item 1, wherein the decision-making module comprises a reinforcement learning component configured to adapt playback decisions to long-term viewer behavior.

1.

### Embodiment ARE: System and Method for Narrative Function Detection and Adaptive Scene Skipping in Media Playback

### Author's Note

This invention entitled “System and Method for Narrative Function Detection and Adaptive Scene Skipping in Media Playback” was co-invented by Nick Reyntjens, Toon De Geyter, and Laurant Mazé.
Unless explicitly stated otherwise, all other inventions described in this document are solely invented by Nick Reyntjens.

A system and method are disclosed for adaptive playback of audio-visual media using narrative-aware artificial intelligence. The system includes a scene-to-text pipeline that segments a media stream into scenes with defined start and stop times and generates structured annotations for each segment. The annotations comprise activity descriptors (e.g., singing, fighting, reading), narrative function labels (e.g., flashback, exposition, filler, climax, transition), and tonal attributes (e.g., comic, suspenseful, tragic). Together these annotations form a narrative map of the media. A decision-making module applies viewer-specific parameters to the narrative map, including a skip profile that specifies categories of content to omit and a knowledge state model representing what the viewer has already experienced. Based on these factors, the system determines whether each scene is played, skipped, enlarged, or explained, with optional augmentation such as text-to-speech of visual clues or enlargement of on-screen text. The invention enables continuity-preserving editing that omits unwanted or redundant content while enhancing accessibility and comprehension for diverse viewers, including those with declining eyesight or difficulty perceiving subtle narrative elements.

### Gentle Introduction

In one view, the invention may be understood as a smart assistant for watching videos that learns what a viewer wants to see and what the viewer already knows, then quietly edits the experience in real time. Rather than forcing the viewer to repeatedly fast-forward through parts like flashbacks or songs, the system could recognize those segments, decide whether they matter for the story at that moment, and either show them, shorten them, or replace them with a brief explanation so the plot still makes sense. If a crucial clue appears as small on-screen text, the system may enlarge or read it aloud even when surrounding content is skipped. The approach uses scene boundaries to create natural decision points, analyzes what is happening in each scene and how it functions in the storyline, and then applies the viewer's preferences and history to produce a seamless, personalized final edit. The result may feel like a considerate editor who keeps continuity intact, avoids repetition for binge-watchers, and adds accessibility aids when needed, all without the viewer having to manage complex controls.

### Background of the Invention

The present invention relates generally to systems for playback of audio-visual media, and more particularly to adaptive playback systems that employ artificial intelligence to modify media presentation based on narrative structure and viewer-specific preferences. Conventional media playback devices, including televisions, set-top boxes, and streaming platforms, typically provide linear playback of films, television episodes, or online videos. While some systems allow manual fast-forwarding or skipping, these actions require continuous user input and do not adapt intelligently to viewer behavior. More advanced solutions, such as parental controls or content filtering services, permit the omission of pre-defined categories of content such as nudity, profanity, or violence. These systems, however, generally rely on manually generated tags or metadata, and operate without understanding the broader narrative function of a scene. As a result, they may remove or mute content in a way that disrupts continuity or fails to consider the viewer's knowledge of the storyline.

In addition, current accessibility features for media playback, such as closed captioning, enlarged subtitles, or audio description, provide important assistance but remain limited to static augmentations. Such tools do not adapt dynamically to the narrative context or the evolving needs of an individual viewer. For example, a viewer with declining eyesight may miss an on-screen note critical to the plot, while an elderly viewer binge-watching a series may be forced to watch redundant flashback sequences that add little informational value.

There is therefore a need for a system that combines semantic understanding of media content with viewer-specific profiles and knowledge states, enabling playback that is both personalized and continuity-preserving. Such a system would be capable of detecting narrative functions such as flashbacks, filler segments, and exposition, while also recognizing activities and tonal attributes. By linking this information to a decision-making module that respects user preferences and prior viewing history, media playback can be adapted to omit undesired content, skip redundant segments, or highlight and explain critical story clues.

### Summary

In one aspect, a system may segment an incoming media stream into scenes with start and stop times and produce, for each scene, structured annotations that include at least one of an activity descriptor, a narrative function label, and a tonal attribute. A narrative map generated from these annotations may be evaluated against viewer-specific parameters comprising a skip profile and a knowledge state model so that per-scene directives specify playing, skipping, condensing, or augmenting content. In certain embodiments, an output subsystem may materialize a processed buffer for seamless playback or, alternatively, a direct-splice playback controller may advance pointers over omission intervals while rendering augmentation artifacts. In further aspects, accessibility-oriented augmentations may preserve critical clues by enlarging OCR-detected text or providing a spoken recap when surrounding content is omitted, and cloud or device-based deployments may interoperate via standard interfaces including Model Context Protocol.

### Description of the Drawings

No drawings are included in this application. The Anchor: Elements and Core Relationships section enumerates components and data flows in a manner suitable for direct translation into figures such as a system block diagram, a process flow diagram, and sequence diagrams, should drawings be provided in later filings without limiting claim scope.

### Examples

In one embodiment, the system may be applied to a television series in which the viewer repeatedly skips certain types of content, such as musical interludes. When the system detects that the viewer has manually skipped three or more scenes annotated as “singing,” the skip profile may be automatically updated to omit such scenes in subsequent episodes or related series, thereby reducing repetitive manual input.

In another embodiment, the system may be used during binge-watching of a serialized program. The decision-making module, informed by the viewer's knowledge state, may recognize that flashback sequences repeat content already viewed in prior episodes. In this case the system may automatically skip or compress the flashback segments, preserving narrative continuity while avoiding redundancy for the viewer.

In a further embodiment, the system may be applied to instructional media, such as software tutorials. If the viewer's knowledge state indicates that introductory concepts have already been learned in earlier sessions, the system may bypass basic segments and advance directly to advanced topics, thereby tailoring the presentation to the viewer's prior experience.

In a cloud-streaming embodiment integrated via Model Context Protocol, the scene-to-text processing and decision endpoints may be exposed as MCP tools so that a player can submit a scene descriptor and receive a play, skip, condense, or augment directive with rationale. For example, the player may send an MCP call with payload

{“sceneId”:“S17”,“start”:“00:14:22.000”,“stop”:“00:15:05.000”,“transcriptHash”:“b9af...”,“features”:[
“music”,“montage”],“entities”:[“Alice”,“Bob”],“priorContext”:[“S04”,“S09”]} and receive a response
{“action”:“skip”,“justification”:“redundant flashback; knowledge state covers
S04,S09”,“augmentation”:{“type”:“spokenRecap”,“text”:“Alice already confronted Bob; the envelope
is empty”}}.

As another concrete walkthrough, consider a thriller episode where a clue appears as small on-screen text while a filler montage plays. The OCR detects the text, the narrative function classifier labels the scene as filler with a critical clue, and the policy selects condense with enlargement. The per-scene decision object may be {“sceneId”:“S23”, “action”:“condense”, “retainInterval”:[“00:32:11.100”, “00:32:16.400”], “augmentatio ns”:[{“type”:“enlargeOCR”, “content”:“Locker 318, code 7429”, “tts”:true}], “confidence”:{“narrative”:“0.91”, “redundancy”:“0.86”}}; the processed buffer then contains only the retained interval and an overlay instruction for the enlargement and optional text-to-speech.

### Detailed Description

The invention provides a system for adaptive playback of media based on semantic scene analysis and narrative reasoning. In a first aspect, a scene-to-text artificial intelligence pipeline segments a media stream into scenes and generates structured annotations. Each scene is annotated with activity information (e.g., singing, fighting, reading), narrative function (e.g., flashback, exposition, filler, climax, transition), and tone or emotional state (e.g., comic, tragic, suspenseful). This produces a narrative map of the media stream that extends beyond conventional content tagging.

In a second aspect, a decision-making module consults the narrative map in conjunction with viewer-specific inputs. A skip profile allows the viewer to define categories of content to omit, such as romance, filler songs, or violence. A knowledge state model of the viewer, derived from prior viewing history and recognized redundancy within the media (e.g., repeated flashbacks, recaps), further informs the decision. As a result, the system automatically determines whether a given scene is played, skipped, enlarged, or explained, thereby preserving narrative coherence while tailoring playback to the viewer's preferences and perceptual needs.

### Scene-to-Text Processing Module:

In one embodiment, a scene-to-text processing module may be configured to associate each segment of a media stream with descriptive metadata, including activities, narrative functions, and tonal attributes. More specifically, the system may first employ scene segmentation algorithms (known in the art for dividing a continuous video into shots and higher-level scenes) to determine the start and stop time of each unit of analysis. Within these temporal boundaries, an activity recognition model (for example, a convolutional or transformer-based video classifier) may identify dominant actions such as “singing,” “fighting,” or “reading.” In parallel, a multimodal emotion and sentiment classifier may analyze visual, auditory, and textual signals to characterize the emotional tone of the segment (e.g., comic, tragic, suspenseful). Further, natural-language processing applied to subtitles or generated transcripts may provide contextual clues, enabling a narrative function classifier trained on corpora of annotated stories to assign labels such as “flashback,” “exposition,” “climax,” or “resolution.” For cases where the media includes repeated information, the system may also apply semantic similarity and redundancy detection across transcripts, thereby recognizing recaps or flashbacks that add little new information to a binge-watching viewer.

By combining the temporal boundaries from scene segmentation with the descriptive outputs of activity recognition, tonal classification, and narrative function detection, the system produces a narrative map of the media stream. Each scene is thus represented not only by its start and stop time but also by a structured annotation of what is happening, how it functions in the storyline, and what affective tone it conveys. This rich annotation enables subsequent modules, such as a decision-making engine, to select whether the scene should be presented in full, skipped, enlarged, or explained, based on a viewer's personalized profile and knowledge state.

In one embodiment, the scene-to-text processing module may be realized as a pipeline that integrates video segmentation, multimodal feature extraction, natural language processing, and semantic similarity analysis. The module operates on an incoming media stream and outputs a structured annotation for each detected scene. The process begins with segmentation, where the continuous video is divided into smaller temporal units. Shot boundaries may be detected using histogram differencing, edge change ratios, or deep neural networks trained on large video corpora. Adjacent shots are then clustered into higher-level scenes using similarity measures between learned visual embeddings, such as cosine distance in a CLIP-like embedding space. The outcome of this stage is a set of discrete scenes, each with a defined start and stop time suitable for subsequent annotation.

Within these temporal boundaries, multimodal features are extracted. The visual channel may be processed by a 3D convolutional network or transformer-based architecture such as SlowFast or ViViT, producing labels that describe dominant activities, including “singing,” “fighting,” or “reading.” The audio channel may be processed by spectrogram-based convolutional models or self-supervised speech models such as wav2vec2, providing information about speech segments, background music, silence, or emotional prosody. Textual information may be captured both through automatic speech recognition applied to dialogue and optical character recognition applied to on-screen elements such as letters, signs, or phone messages. These heterogeneous representations may be aligned and fused in a multimodal transformer model, which produces a unified latent embedding of the scene.

Narrative function detection may be carried out by models trained on annotated datasets of television, film, or literature, where scenes are labeled as exposition, climax, filler, resolution, or flashback. Flashbacks may be identified by a combination of multimodal cues, including abrupt shifts in color grading, insertion of temporal markers in dialogue (“yesterday . . . ”, “long ago”), or high semantic overlap with earlier transcript material. Redundancy detection may be implemented by computing embeddings of transcript segments using a sentence-BERT model and comparing them against a memory of previously processed content. When similarity exceeds a defined threshold, the system infers that the current scene is a recap or repetition.

An emotion and sentiment classifier may also operate on the fused multimodal embedding. This classifier can be trained using datasets of film clips annotated with emotional categories, enabling the system to assign tonal attributes such as comic, tragic, suspenseful, or romantic. The outputs of activity recognition, narrative function detection, sentiment classification, and redundancy analysis are then combined with the temporal boundaries established earlier.

The result is a narrative map of the media stream in which each scene is represented not only by its start and stop times but also by structured metadata describing what occurs within the scene, how the scene contributes to the narrative structure, and the emotional tone conveyed. This representation is stored in a structured format, such as JSON or protocol buffers, which allows downstream modules to access the annotations in real time. Subsequent components, such as the skipping logic module, may then query this map to determine whether to present, omit, enlarge, or explain the scene in accordance with a viewer profile and knowledge state.

### Skipping Logic Module

In one embodiment, a skipping logic module may be configured to determine, for each annotated scene, whether the scene is to be presented in full, omitted, condensed, or augmented. The skipping logic module receives as input the narrative map generated by the scene-to-text processing module together with one or more viewer-specific parameters.

A first parameter may comprise a skip profile, defined by explicit user selections such as “skip romance scenes,” “skip filler songs,” or “skip violent content.” When the narrative map indicates that a scene is annotated with one or more categories designated in the skip profile, the skipping logic module may instruct the playback system to omit the corresponding scene or to advance directly to the subsequent scene boundary.

A second parameter may comprise a knowledge state model that reflects what the viewer has previously consumed. The knowledge state may be determined by tracking the viewer's prior playback history across episodes or sessions, and by applying semantic similarity analysis to detect redundant narrative elements. For example, if the system detects that a flashback sequence reproduces content already viewed by the same viewer in an earlier episode, the skipping logic module may classify the scene as redundant and automatically bypass it.

In certain embodiments, the skipping logic module may not only skip but also substitute explanatory augmentation to preserve narrative continuity. For example, where a skipped scene establishes a relationship change between characters, the module may insert a micro-recap statement (“Two hours later, the characters are shown as a couple”) generated from the narrative map. In another example, if the scene contains a visual clue, such as a note or message on a screen, the skipping logic module may suppress the surrounding filler content but enlarge and display the clue text or provide a text-to-speech narration of the clue to the viewer.

The skipping logic module may thus operate as a rule-based and learning-enhanced decision system, combining explicit user preferences with inferred redundancy detection and context-preserving augmentation. The result is a personalized final edit that maintains narrative coherence while eliminating undesired, repetitive, or inaccessible content.

In one embodiment, the skipping logic may be implemented as a software pipeline integrated into a smart television, a set-top box, or a cloud-based streaming platform. The media stream is first divided into scenes by applying automated segmentation algorithms. Shot boundary detection may be carried out through histogram difference, frame correlation, or transformer-based video segmentation, and these shots are then clustered into coherent scenes by similarity analysis of visual embeddings. Each scene is therefore associated with a start and stop time that defines a temporal decision boundary.

Within each identified scene, multimodal feature extraction is performed. A video classifier based on convolutional or transformer architectures may identify dominant activities such as fighting, kissing, or singing. An audio model trained on spectrograms or raw waveform representations may further detect music, speech, silence, or emotional prosody. Speech recognition and optical character recognition may be used to generate textual transcripts from dialogue and to extract on-screen text such as letters or phone messages. These visual, auditory, and textual embeddings may be fused in a multimodal transformer framework, producing a joint representation of the scene.

Narrative function detection may then be carried out by supervised models trained on corpora of annotated stories and question-answering datasets. Such models classify each scene as flashback, exposition, filler, climax, or resolution. Flashbacks can be recognized by temporal inconsistencies in film characteristics or dialogue references to prior events, while recaps may be detected by comparing transcripts against previously viewed content using semantic similarity measures. Redundant sequences are identified when transcript embeddings exceed a similarity threshold with earlier material in the viewer's history.

A knowledge state model is maintained in parallel to represent what the viewer has already consumed. This may take the form of a graph or embedding memory that is updated incrementally as scenes are viewed. When a new scene is analyzed, its transcript and activity representation are compared to the knowledge state; if high similarity is detected, the system infers that the viewer has already assimilated the content, and the sequence may be classified as redundant.

The decision engine consults the narrative map together with the skip profile and knowledge state to determine the appropriate playback action. When a scene matches a category designated in the skip profile, the playback pointer is advanced to the next decision boundary. When redundancy is detected, the system may bypass the scene or insert a condensed recap to preserve narrative coherence. If a skipped scene contains a narrative-critical element, such as a textual clue extracted by OCR, the system may momentarily enlarge or read aloud the clue before resuming playback. The output is thus a personalized final edit that maintains continuity while eliminating undesired or repetitive segments. The system may continue to refine its decisions through learning from user interaction. If a viewer reverses a skip to watch a segment, this feedback may reduce the confidence threshold for future omissions. If skipped scenes are never revisited, the system reinforces that behavior as appropriate. Over time, the skip profile becomes adaptive, evolving with the viewer's demonstrated preferences and consumption habits.

### Buffering and Processing Pipeline

In one embodiment, the displaying device may be configured with a dual-buffer system that ensures both seamless playback and sufficient time for semantic analysis. A first buffer may store incoming media packets as they are received from the streaming source. The buffer size may be dynamically adjustable but, in atypical case, may correspond to several minutes of media content, for example five minutes. This first buffer allows the device to accumulate enough material so that portions of the media can be analyzed and, if necessary, skipped, without creating perceptible interruptions in playback.

A second buffer, referred to as the processed buffer, may store the media content after it has been analyzed by the scene-to-text pipeline and subjected to the skipping logic. The processing pipeline operates on the first buffer in a look-ahead fashion, examining upcoming segments before they are required for playback. Scene boundaries are detected, features are extracted, and narrative functions are classified in advance. For each scene, the decision-making module determines whether the segment is to be copied directly into the processed buffer, omitted entirely, or substituted by an alternative representation such as a condensed summary or a textual or spoken explanation of a critical clue.

During playback, the device reads sequentially from the processed buffer. Because the decisions have already been made ahead of time, playback can proceed without latency, even if the underlying analysis required intensive computation. This design also allows seamless transitions between retained and omitted content, since the processed buffer contains only the media that will actually be presented to the viewer.

In certain embodiments, the system may operate in parallel: while the viewer is consuming one portion of the processed buffer, the pipeline continues analyzing upcoming content in the first buffer and populating the next segment of the processed buffer. If the user alters preferences or issues corrective feedback (such as manually replaying a skipped scene), the system may reprocess relevant segments from the first buffer and adjust the processed buffer accordingly. This architecture ensures that the adaptive playback is both responsive and continuity-preserving while meeting the computational requirements of semantic augmentation and narrative reasoning.

### Enablement

In practice it is preferred to implement adaptive scene skipping in video playback systems, which leads to reduced decoding, buffering, and rendering of non-essential segments. As a result, the system consumes less processor power, GPU cycles, and memory resources during playback. More specifically, the system produces the effect of conserving bandwidth and energy because skipped segments are either not streamed from the server or not processed by the device, which results in measurable reductions in power consumption. Since reduced playback time directly correlates with lower device energy use and server-side streaming load, the invention indirectly lowers overall carbon footprint, while its primary technical effect is improved efficiency and responsiveness of video delivery systems.

The invention may be implemented by a skilled practitioner using standard media processing components combined with multimodal machine learning and policy evaluation. An end-to-end embodiment may be realized on a smart television, set-top box, mobile device, or cloud service connected to a player. The ingest subsystem may be built atop FFmpeg or GStreamer to demultiplex a media stream into audio, video, and subtitle tracks while populating an input buffer sized to a configurable temporal window. Scene segmentation may be implemented using shot boundary detection via histogram difference or learned frame difference models, followed by scene clustering using cosine similarity of frame or shot embeddings produced by models such as CLIP-like encoders. The segmentation output provides timecodes that define start and stop times for analysis and later splicing.

Multimodal feature extraction may proceed by applying a video activity recognizer such as a 3D convolutional network or transformer backbone to sample clips, an audio classifier to spectrograms to detect music, speech, silence, and prosody, and a text pipeline consisting of automatic speech recognition for dialogue and optical character recognition for on-screen text. The features may be fused using a transformer with cross-attention over visual, audio, and textual tokens to produce a unified scene embedding. In addition to semantic labels, the system may compute statistical decision features including speech-to-music ratio, subtitle density per unit time, silence run-length, and motion run-length, where motion run-length may be derived from optical flow or codec motion vectors as counts of consecutive frames exceeding a motion magnitude threshold. A narrative function classifier trained on annotated clips may map embeddings to labels including flashback, exposition, filler, climax, resolution, or transition, with the option of fine-tuning on domain-specific content. Redundancy detection may use sentence-level embeddings of transcripts maintained in a rolling memory per account; similarity above a configured threshold may indicate recap or repeated content. A tonal classifier may assign affective categories such as comic, tragic, suspenseful, or romantic based on the fused embedding.

The narrative map may be materialized in a lightweight schema for random access during look-ahead processing. An example entry may be {“sceneId”:“S23”, “start”:“00:32:11.100”, “stop”:“00:32:16.400”, “activities”:[“montage”], “narrative”:“f iller”, “tone”:[“suspenseful”], “ocr”:[“Locker 318, code 7429”], “transcriptHash”:“alb2c3”, “conf”:{“narrative”:0.91, “redundancy”:0.86}}. The knowledge state may be represented as an account-scoped store that indexes previously presented scenes by embedding hashes and identifiers together with decay or aging metadata; a compact example may be {“accountId”:“u123”, “seen”:[“S04”, “S09”], “embeddings”:[“e41f.”, “9ab0.”], “lastUpdated”:“2025-01-01T12:00:00Z”}. The decision-making module may accept a narrative map window and viewer parameters including a skip profile and knowledge state and emit per-scene directives such as {“sceneId”:“S23”, “action”:“condense”, “retain”:[“00:32:11.100”, “00:32:16.400”], “augment”:[{“type”:“enlargeOCR”, “text”:“Locker 318, code 7429”, “tts”:true}]}. The processed buffer may be constructed by copying retained media ranges and inserting augmentation overlays using the player's composition layer; in a direct-splice embodiment, the playback controller may advance pointers over omitted intervals and render augmentations as short overlay assets without materializing a separate buffer.

A minimal operational configuration may be assembled as follows. First, provision the media ingest and buffering substrate and verify time-accurate seeking to scene boundaries. Next, implement segmentation and verify that start and stop times align to safe splice points such as keyframes or GOP boundaries to avoid decoder instability. Then, integrate ASR, OCR, and the video and audio classifiers and verify that the fused embedding and labels can be produced ahead of playback given the look-ahead budget. After that, implement redundancy detection using transcript embeddings with a tunable similarity threshold and maintain an account-scoped knowledge state with on-device storage and optional privacy-preserving summaries synchronized to the cloud. Subsequently, implement the policy engine that evaluates the skip profile and knowledge state together with narrative and tonal labels to select an action per scene and, when necessary, generate a brief textual summary for micro-recaps. Finally, integrate the processed buffer or direct-splice controller and the augmentation renderer to support overlays and text-to-speech, and enable telemetry to record externally observable actions including play, skip, condense, and augmentation events with associated timecodes. Interoperability with Model Context Protocol may be achieved by exposing tool endpoints for decision making and telemetry. A decision tool may accept a descriptor such as {“sceneId”:“S17”, “start”:“00:14:22.000”, “stop”:“00:15:05.000”, “features”:[“music”, “montage”], “entiti es”:[“Alice”, “Bob”], “transcriptHash”:“b9af.”, “priorContext”:[“S04”, “S09”]} and return a directive such as {“action”:“skip”, “justification”:“redundant flashback; knowledge state covers S04,S09”, “augmentation”:{“type”:“spokenRecap”, “text”:“Alice already confronted Bob; the envelope is empty”}}. A feedback tool may accept viewer signals such as {“event”:“replay”, “sceneId”:“S17”} and return {“ack”:true}. These tools may operate with bounded response times compatible with the look-ahead window so that decisions are available before the corresponding playback point.

Training and calibration may proceed using public or licensed datasets of film or television scenes annotated for narrative function and emotion, augmented by weak supervision derived from editorial markers or recap segments. The practitioner may select model capacities that fit the target device, for example reducing input resolution or window length for embedded deployments while offloading inference to server-side components for thin clients. Thresholds for redundancy detection and skip decisions may be initialized conservatively and adapted over time from user feedback using bandit or reinforcement learning updates that adjust policy weights. The augmentation renderer may be implemented using the player's overlay plane to draw enlarged OCR text with readable contrast and optional text-to-speech generated by on-device or cloud-based engines configured for low-latency playback continuity.

Privacy and security may be maintained by storing the knowledge state locally by default and synchronizing only differentially private digests when account-level continuity across devices is desired. Telemetry may be signed or hashed and chained to support auditability without exposing raw content, and entitlements may be enforced by policy checks in the decision engine that read subscription tier and partner constraints. With these concrete components and data structures, a skilled person can build each embodiment without undue experimentation while preserving interoperability through standardized interfaces including Model Context Protocol.

### Anchor: Elements and Core Relationships

In one embodiment, the system may be understood as a set of cooperating components connected by defined data flows and decisions. A media source provides a media stream that is received by an input buffer configured to accumulate a look-ahead window of content suitable for subsequent analysis and potential omission without playback interruption. The scene-to-text processing module operates on buffered content and outputs, for each detected scene with start and stop times, structured annotations that together form a narrative map. The scene-to-text processing module may include a segmentation engine that detects shot boundaries and clusters shots into scenes; a visual activity recognizer that classifies dominant on-screen actions; an audio analysis component that identifies speech, music, silence, and prosody; a text pipeline comprising automatic speech recognition for dialogue and optical character recognition for on-screen text; a multimodal fusion model that aligns and integrates visual, audio, and textual features into a unified representation; a narrative function classifier that assigns labels such as flashback, exposition, filler, climax, resolution, or transition; a redundancy detector that compares embeddings of current transcripts against embeddings stored from previously viewed material to identify recaps and repeated content; and an emotion or tonal classifier that assigns affective categories such as comic, tragic, suspenseful, romantic, or neutral. The outputs of these subcomponents are associated to each scene's temporal boundaries to produce entries in the narrative map, which is a structured data representation accessible to downstream modules during look-ahead processing.

The decision-making module consumes the narrative map alongside viewer-specific parameters and produces a per-scene playback action. The viewer-specific parameters include a skip profile that encodes viewer designations of content categories to omit and a knowledge state model that reflects what the viewer has already consumed across sessions and episodes. The decision-making module may comprise a rule or policy engine that evaluates whether a scene matches the skip profile, a redundancy evaluation that determines whether the knowledge state already contains the informational content of the scene, an augmentation selector that decides whether to condense or replace a skipped scene with a micro-recap, textual summary, spoken recap, or enlargement of on-screen clues, and a learning component that adapts thresholds and policy weights based on observed viewer overrides or confirmations. The output of the decision-making module is a directive to either copy the scene as-is, omit it, copy a shortened version, or insert an augmentation artifact in its place.

A processed buffer receives only those media segments and augmentation artifacts designated for presentation by the decision-making module. A playback engine reads sequentially from the processed buffer to render uninterrupted media to the viewer, including any inserted micro-recaps, spoken narration of extracted clues, or temporary enlargements of on-screen text. A feedback interface captures user actions during playback, including reversals of skips, replays, preference changes, and confirmations, and passes these signals to the decision-making module such that the skip profile and knowledge state are updated and future decisions are adjusted accordingly. The entire pipeline operates in a continuous look-ahead manner in which analysis of future content in the input buffer proceeds in parallel with the playback engine's consumption of the processed buffer. The system may be deployed in a smart television, set-top box, or cloud streaming environment, in which case the media source, input buffer, scene-to-text processing, decision-making, processed buffer, playback engine, and feedback interface function as a logically connected chain that yields a personalized final edit while preserving narrative continuity and seamless user experience.

### Flow of the Invention

In one embodiment, the method may proceed in the following steps.

### Step 1: Receiving Media Packets.

A media stream is received in the form of compressed packets from a broadcast source, file, or online service. The packets are collected by the system for further processing.

### Step 2: Input Buffering.

The incoming packets are accumulated in an input buffer. The buffer is of sufficient duration, for example five minutes of playback time, to provide both temporal space for later skipping of sections and computational time to perform semantic analysis in advance of playback.

### Step 3: Scene Segmentation.

The content of the input buffer is divided into discrete scenes. This segmentation may be achieved by detecting shot boundaries and grouping them into higher-level scenes, thereby producing start and stop times for each scene.

### Step 4: Feature Extraction.

Each scene is analyzed through multiple channels. A video classifier detects activities such as singing, fighting, or reading. An audio classifier distinguishes speech, music, silence, or emotional prosody. A text pipeline converts dialogue into transcripts via speech recognition and extracts visual text via optical character recognition. The outputs are fused into a multimodal representation of the scene.

### Step 5: Narrative Function and Tone Classification.

The multimodal representation is further analyzed to assign a narrative function label such as exposition, flashback, or filler. An emotion classifier may add tonal attributes such as tragic or suspenseful. Transcript embeddings may be compared with previously viewed material to detect redundant or recap scenes.

### Step 6: Narrative Map Generation.

For each scene, the metadata produced in Steps 4 and 5 is associated with its start and stop times to create a narrative map of the buffered portion of the media. The narrative map describes what occurs in the scene, how it functions in the storyline, and what affective tone it conveys.

### Step 7: Decision Making.

The narrative map is passed to a decision-making module. This module consults the viewer's skip profile (e.g., to omit romance or filler songs) and the viewer's knowledge state model (e.g., to avoid flashbacks already seen). For each scene, the module determines whether to retain it, skip it, shorten it, or replace it with an augmentation such as a summary or enlarged clue.

### Step 8: Processed Buffering.

Scenes designated for presentation are copied into a processed buffer. Scenes to be omitted are not transferred, and scenes designated for augmentation are replaced with the corresponding summaries, recaps, or enlarged textual elements.

### Step 9: Playback.

The system reads sequentially from the processed buffer to deliver playback to the viewer. Since the processed buffer contains only the final edit, playback proceeds seamlessly without delay when skipped portions occur.

### Step 10: Continuous Look-Ahead.

While playback is proceeding from the processed buffer, the pipeline continues processing new material from the input buffer in a look-ahead fashion. The cycle of segmentation, feature extraction, classification, and decision-making continues so that playback remains uninterrupted.

### Step 11: Feedback and Adaptation.

If the viewer manually overrides a skip, revisits a scene, or alters preferences, the system reprocesses the relevant portion of the input buffer and updates the processed buffer accordingly. The skip profile and knowledge state are also updated so that future playback reflects the viewer's demonstrated behavior.

### Fallback Embodiments

In certain simplified implementations, the invention may be realized with fewer components while still delivering the core benefit of narrative-aware, continuity-preserving skipping. In a minimal client-only configuration, the system may use editorial or coarse segmentation markers such as chapter breaks, ad cue markers, or fixed-length windows to define decision points; a lightweight classifier or rule set may label segments with narrative function proxies such as music-dominant montage or dialogue-heavy exposition based on audio energy ratios, speech-to-music proportion, subtitle density, silence run-length, and motion run-length; the decision-making module may then apply only the skip profile without a persistent knowledge state, performing condense, skip, or augmentation actions at those boundaries. Even in the absence of an explicit knowledge state, the core inventive concept remains: per-segment narrative-aware decisions guided by a viewer profile that preserve continuity through optional micro-recaps and clue preservation.

In another fallback configuration, narrative maps may be precomputed server-side or supplied by content owners as sidecar metadata and consumed by a thin client that performs only policy evaluation and augmentation rendering. When the precomputed map includes labels such as flashback, filler, or recap along with timecoded OCR extracts, the client may skip or condense according to the viewer's skip profile and insert enlargements or spoken recaps where indicated, without running local scene analysis or learning components. Alternatively, the client may operate in a direct-splice mode without a processed buffer, advancing playback pointers over omission intervals while streaming augmentation overlays as short assets.

A further reduced embodiment may focus on accessibility-first augmentation without general skipping. The system may monitor for OCR-detected clues and small-text artifacts using a lightweight text pipeline and, when a segment is skipped or condensed for any reason including explicit user fast-forward, may read aloud or temporarily enlarge the detected text before resuming playback. In environments where transformer-based models or reinforcement learning are unavailable or restricted, the classifiers may be replaced by deterministic heuristics or shallow models, including thresholds on color grading changes and dialogue references for flashback detection, while still achieving narrative-function-sensitive playback decisions.

### Technical Effects

The disclosed system may deliver concrete technical effects across the described embodiments. In the baseline pipeline, generating a narrative map that aligns semantic annotations to precise start and stop times may enable deterministic splice decisions at natural boundaries, which could reduce decoder thrash and avoid mid-GOP discontinuities. The dual-buffer architecture may transform compute-bound semantic inference into latency-free playback by shifting heavy analysis into a look-ahead window, thereby reducing visible stalls and providing seamless transitions between retained and omitted segments.

Applying a knowledge state to detect redundancy may reduce repeated transmission and decoding of content that adds no new information for a given viewer, which could lower bandwidth consumption in streaming scenarios and reduce device power draw due to fewer decode cycles. When narrative-critical clues are preserved as overlays or brief audio snippets while surrounding filler is skipped, the system may maintain plot coherence with fewer rendered frames, further reducing processing and memory bandwidth requirements.

In the direct-splice embodiment, advancing playback pointers over omission intervals rather than materializing a processed buffer may decrease RAM footprint and file I/O, which could be advantageous for constrained devices. Conversely, in the processed-buffer embodiment, precomputation of augmentations and condensations may provide bounded-latency rendering and may improve A/V sync at splice points, yielding an observable reduction in jitter and audio pops relative to ad hoc fast-forward operations.

Server-side precomputation of narrative maps may offload multimodal inference to elastic infrastructure, allowing thin clients to execute only lightweight policy evaluation and overlay rendering. This division may reduce on-device CPU utilization and thermal throttling, improving sustained performance on mobile hardware. Integration via Model Context Protocol may standardize decision interfaces so that players can request per-scene directives with bounded response schemas, which could improve interoperability and reduce integration defects across heterogeneous platforms. Adaptive policy learning based on viewer overrides may decrease false-positive and false-negative skips over time, which could lower the rate of corrective seeks and associated rebuffer events. Accessibility-focused augmentations, including enlargement of OCR-detected text and selective text-to-speech, may increase intelligibility without enabling full audio-description tracks, thereby decreasing audio channel utilization while still conveying critical information. Across these embodiments, the telemetry of externally observable actions may support reproducibility of playback outcomes, enabling deterministic replays of the same decision path for debugging and certification and thus reducing QA cycle time.

### External Observability

In one aspect, externally observable behaviors may be defined so that infringement can be evaluated without access to internal source code or models. A device or service that, when provided with a specified content identifier, a skip profile, and a knowledge state, produces a reproducible sequence of play, skip, condense, or augment outcomes aligned to media timecodes may be considered to implement the invention's externally verifiable behavior. The observable outcomes include advancement of the playhead over omission intervals with duration approximately equal to the omitted ranges within an implementation tolerance, rendering of overlays that display OCR-detected text strings as readable enlargements, and injection of brief spoken recaps that summarize skipped narrative content as audible audio segments. In a direct-splice embodiment, externally observable discontinuities in the media time index correspond to the omitted ranges while augmentation overlays or audio are present during or adjacent to those discontinuities; in a processed-buffer embodiment, the same sequence of visible and audible results is presented without mid-playback latency spikes, and both paths yield equivalent traces of decisions visible at the output.

A conformance trace may be captured by screen recording, HDMI capture, or camera video of the display together with a wall-clock timestamp, and may be compared to an expected event log derived from the same inputs. An event record may include fields such as contentId, action, from, to, augmentation, and justification, for example {“contentId”:“T123S2E5”, “action”:“condense”, “from”:“00:32:11.100”, “to”:“00:32:16.400”, “augmenta tion”:{“type”:“enlargeOCR”, “text”: “Locker 318, code 7429”, “tts”:true}, “justification”:“filler with critical clue”}. When the system is invoked repeatedly with identical inputs, the sequence of externally observable events may match within a defined tolerance window such as plus or minus 100 milliseconds on timecodes and minor rendering jitter such as a few pixels of overlay positioning. For spoken recaps, an audio fingerprint of the recap segment may match across runs, and for enlargements, the rendered text content may match the OCR string and appear during or immediately adjacent to the corresponding omission interval.

In a cloud or API-integrated embodiment, the decision boundary may be exposed at an interface such as a Model Context Protocol tool so that request-response exchanges are externally loggable and reproducible. A client may send a descriptor with scene identifiers and receive a directive with action and augmentation fields, and those directives may correspond one-to-one with the observed playback behavior, for example a response {“action”:“skip”, “augmentation”:{“type”:“spokenRecap”, “text”:“Alice already confronted Bob; the envelope is empty”}}may be followed by a visible or audible recap and a playhead jump from the scene start to scene stop. Even when proprietary or alternative interfaces are used, equivalence may be demonstrated if, given materially identical inputs, the externally observed outputs conform to the same semantics of per-scene decisions and augmentations. Equivalence may be established even when per-segment decisions are derived from editorial tags, manual markers, or other internal signals not expressly enumerated herein, provided the externally observable behavior conforms to the per-scene action and augmentation semantics described.

### Monetization and Damages Maximization

In one embodiment, the system may include an account, entitlement, and metering subsystem configured to support subscription-model usage and to generate auditable records of consumption and feature access. A subscriber identity may be associated with one or more devices through cryptographically signed tokens that enable activation, renewal, and revocation. Subscription tiers may govern access to capabilities such as automatic flashback skipping, redundancy compression, and accessibility augmentations, and the decision-making module may consult entitlement flags when applying policies to a given viewer profile.

In certain implementations, the system may record event-level telemetry that captures externally observable behaviors relevant to billing and damages computation. Each playback action may generate a record comprising a timestamp, anonymized or account-scoped viewer identifier, content identifier, scene start and stop times, decision outcome including presented, skipped, condensed, or augmented, augmentation type including textual summary, spoken recap, or enlarged clue, and confidence values used by the policy engine. These records may be hashed and chained or signed by a device or service key so that integrity can be verified during audits. A usage aggregator may compute billable metrics per subscriber or per content title, including minutes analyzed, minutes presented, minutes skipped, number of augmentations injected, and number of user overrides, and may expose these aggregates through authenticated APIs for integration with billing platforms.

The monetization subsystem may further enable content-partner licensing models in which entitlements are constrained by title, series, or publisher. A per-title license may be distributed as a signed policy bundle specifying allowable skip categories, required augmentations for accessibility compliance, and revenue share parameters, and the decision-making module may enforce these constraints during playback. For enterprise deployments, administrative dashboards may provide controls for policy presets and contractual reporting, while export mechanisms may produce immutable monthly reports that include metering totals and cryptographic proofs of the underlying event set.

By incorporating these technical features, the system may provide a concrete basis for calculating damages in the event of infringement. Because subscription revenue, feature-tier access, metering totals, and integrity-verified usage records may be tied to the operation of the adaptive playback pipeline, lost profits and reasonable royalties may be derived from the recorded counts of decisions executed per viewer and per content title. The presence of signed event logs and reproducible aggregates may facilitate reliable reconstruction of historical usage and may strengthen admissibility and persuasiveness of damages evidence without imposing constraints on the core inventive functionality described elsewhere in this document.

### Scope and Conventions

Unless otherwise stated, the scope of this disclosure is defined solely by the claims. The detailed description, examples, and any depicted or referenced figures describe example embodiments provided for illustration and do not limit the claims. Features described in connection with a particular embodiment may be combined with, separated from, substituted for, or reordered relative to features in other embodiments. Steps and flows may be performed in different orders, in parallel, or with steps added or omitted while still falling within the scope of the claims. Hardware and software components may be implemented in distributed, cloud, on-device, or hybrid architectures, and functionally equivalent modules, interfaces, and data formats may be used. Terminology such as may, can, could, might, and optionally indicates that features are not required. The singular includes the plural and vice versa unless context dictates otherwise. No feature is essential to the broadest claim scope unless expressly recited as such in an independent claim.

### Itemized Embodiment Support List for Continuations

Embodiments can be described by the following itemized list: (1) a system comprising an input buffer that receives and temporarily stores a portion of a media stream, where the buffer may be of fixed or adaptive duration, circular, segmented by GOP boundaries, or aligned to streaming protocols including HLS and DASH; (2) a scene-to-text processing module that segments the media stream into scenes with start and stop times using shot detection and scene clustering and that may alternatively operate at shot, chapter, or commercial-break granularity; (3) generation of structured annotations per scene including at least one of activity descriptors, narrative function labels, and tonal attributes, where annotations may be probabilistic with confidences; (4) a multimodal pipeline including a video classifier, an audio classifier, and a text analysis module that fuse outputs into a unified representation via late fusion, early fusion, or transformer-based cross-attention; (5) narrative function labels selected from flashback, exposition, filler, climax, resolution, and transition, optionally extended to montage, teaser, cold open, tag, B-story, and epilogue; (6) tonal attributes selected from comic, tragic, suspenseful, romantic, and neutral, optionally extended to ominous, uplifting, serene, and chaotic; (7) construction of a narrative map from annotations that indexes each scene by timecodes and semantic fields and is queryable in real time; (8) a decision-making module that applies a skip profile and a knowledge state model of a viewer to the narrative map to determine for each scene whether it is presented, skipped, condensed, or augmented; (9) a knowledge state model implemented as a memory of transcript embeddings of previously viewed material, a knowledge graph of entities and relations, a rolling digest with time decay, or a per-account cross-device store; (10) a skip profile comprising viewer-specified categories such as romance, violence, filler songs, and flashbacks, optionally hierarchical, contextual by time-of-day or parental level, and adaptable through learned preferences; (11) augmentation behaviors including condensed textual summaries, spoken recaps, enlargement or repetition of OCR-detected on-screen clues, and alternative overlays such as highlight boxes or haptic cues; (12) a processed buffer configured to store the media stream as modified by the decision-making module for seamless playback, optionally implemented as an in-memory queue, file-backed segment list, or server-side splice list; (13) an alternative direct-splice embodiment without a processed buffer in which playback pointers are advanced over omitted time ranges and augmentation artifacts are streamed as overlays; (14) look-ahead operation in which segmentation, annotation, and decision-making for future scenes are performed while current scenes are being played, with compute budgets, prefetch windows, and power-aware throttling; (15) reinforcement learning or bandit components that adapt thresholds and policy weights from user overrides and confirmations; (16) flashback and recap detection by comparing transcript embeddings of current and prior scenes with a similarity threshold, further assisted by visual style shifts, dialogue temporal markers, or music cues; (17) tonal detection via multimodal sentiment classifiers trained on labeled corpora and optionally via rules based on audio key, tempo, or facial expressions; (18) dynamic reprocessing of buffered segments upon receiving corrective feedback, including rollback and regeneration of the processed buffer; (19) automatic skip-profile updates when a viewer manually skips a category a configurable number of times, exemplified by three; (20) a computer-implemented method comprising receiving a media stream, buffering, segmenting into scenes, annotating, constructing a narrative map, applying skip profile and knowledge state, determining per-scene actions, transferring selected scenes and augmentations to a processed buffer, and presenting seamless playback; (21) a non-transitory computer-readable medium storing instructions to perform any of the described methods; (22) a transformer-based multimodal neural network trained on annotated corpora of film and literature to assign narrative function labels, alternatively using CNN-RNN hybrids, HMMs, or rule-based heuristics; (23) a processed buffer configured to contain only segments designated for presentation so that transitions between retained and omitted scenes are imperceptible; (24) automatic enlargement and display of OCR-detected on-screen text when corresponding scenes are skipped or condensed, optionally supplemented by text-to-speech; (25) external telemetry generation recording timestamps, content identifiers, scene timecodes, decisions, augmentation types, and confidence values, with records chained or signed for integrity; (26) deployment architectures including smart televisions, set-top boxes, mobile devices, and cloud streaming platforms with edge offload of scene analysis; (27) interoperability with multiple codecs, container formats, DRM schemes, caption standards, and subtitle formats including SRT and WebVTT; (28) privacy controls in which embeddings and knowledge state are stored locally with optional differentially private summaries synchronized to cloud services; (29) accessibility-focused embodiments that emphasize enlargement of visual clues, spoken recaps, or simplified narratives for viewers with perceptual challenges; (30) content partner policy bundles that constrain allowable skip categories and required accessibility augmentations and that are enforced by the decision-making module; (31) learning from implicit signals such as the absence of a replay after a skip as a confirmation signal; (32) server-side batch precomputation of narrative maps per title with client-side personalization for skip and knowledge state; (33) alternative segmentation that uses editorial markers embedded by content owners, broadcaster SCTE-35 cues, or chapter markers; (34) a method embodiment that detects flashbacks by embedding similarity and classifies scenes as redundant if similarity exceeds a threshold; (35) a method embodiment that detects tonal attributes using multimodal sentiment; (36) a method embodiment that dynamically reprocesses buffered content on feedback; (37) a method embodiment that substitutes skipped scenes with textual summary, spoken recap, or enlarged clue; (38) a system in which the decision-making module refines skip profiles over time using reinforcement learning to adapt to long-term viewer behavior; (39) a system in which the skip profile and knowledge state are applied to generate a personalized final edit while maintaining narrative continuity; (40) equivalents in which data structures are represented as JSON, protocol buffers, or relational schemas and in which decisions are streamed via APIs, IPC, or message queues; (41) interoperability with Model Context Protocol via tool endpoints that accept scene or segment descriptors and return per-segment directives with bounded response times compatible with the look-ahead window, together with telemetry tools for externally observable decision logging; (42) decision features encompassing arbitrary metadata such as editorial markers, proprietary tags, watermarks, broadcaster or player cue sheets, trick-play logs, seek maps, blackframe or silence markers, checksum anomalies, heartbeats, attention or interaction metrics, or any other discriminative signal sufficient to support per-segment playback decisions; (43) behavior-level equivalence in which implementations that, given materially identical inputs, produce the same externally observable sequence of play, skip, condense, and augment outcomes and overlays are considered within scope regardless of internal label names, model types, rule sets, or feature encodings.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A system for adaptive media playback, comprising:
an input buffer configured to receive and temporarily store a portion of a media stream;
a scene-to-text processing module configured to segment the media stream into discrete scenes or other temporal segments with start and stop times or to obtain externally supplied boundaries for such scenes or segments, and to generate, for each scene or segment, structured annotations or decision features comprising one or more semantic or statistical descriptors sufficient to support per-segment playback decisions, the descriptors including at least one of: an activity descriptor, a narrative function label, a tonal attribute, a speech-to-music ratio, a subtitle density metric, a silence or motion run-length statistic, or an embedding-similarity score, or to obtain such annotations or decision features provided by an external service;
a decision-making module configured to evaluate a narrative map generated from or obtained in association with the structured annotations or decision features and to determine, based on at least one of a skip profile and a knowledge state model of a viewer, whether each scene or segment is to be presented, skipped, condensed, or augmented; and
an output subsystem comprising one or both of: a processed buffer configured to store the media stream as modified by the decision-making module for seamless playback; and a direct-splice playback controller configured to advance playback pointers over omitted time ranges and to render augmentation artifacts during playback.
   2.

The system of item 1, wherein the scene-to-text processing module comprises a video classifier, an audio classifier, and a text analysis module, and wherein outputs from the classifiers are fused into a multimodal representation of each scene.

3.

The system of item 1, wherein the narrative function label is selected from a group consisting of:
flashback, exposition, filler, climax, resolution, and transition.
   4.

The system of item 1, wherein the tonal attribute is selected from a group consisting of: comic, tragic, suspenseful, romantic, and neutral.

5.

The system of item 1, wherein the knowledge state model comprises a memory of transcript embeddings of previously viewed material, and the decision-making module is configured to detect redundancy by comparing a current transcript embedding with stored embeddings.

6.

The system of item 1, wherein the skip profile comprises viewer-specified categories of content to omit, including at least one of: romance, violence, filler songs, or flashbacks.

7.

The system of item 1, wherein the decision-making module is further configured to substitute a skipped scene with a condensed summary or micro-recap statement to preserve narrative continuity.

8.

The system of item 1, wherein the decision-making module is further configured to enlarge and display on-screen text detected by optical character recognition when the corresponding scene is skipped.

9.

The system of item 1, wherein the decision-making module refines the skip profile over time by incorporating feedback from viewer overrides of skipped or presented scenes.

10.

The system of item 1, wherein the input buffer and processed buffer operate in a look-ahead fashion such that segmentation, annotation, and decision-making for future scenes are performed while current scenes are being played.

11.

A method for adaptive media playback, comprising:
receiving a media stream and storing a portion of the media stream in an input buffer;
segmenting the media stream into scenes or other temporal segments having start and stop times or obtaining boundaries for the scenes or segments;
generating or obtaining, for each scene or segment, structured annotations or decision features comprising one or more semantic or statistical descriptors sufficient to support per-segment playback decisions, the descriptors including at least one of: an activity descriptor, a narrative function label, a tonal attribute, a speech-to-music ratio, a subtitle density metric, a silence or motion run-length statistic, or an embedding-similarity score;
constructing or obtaining a narrative map from the annotations or decision features;
applying at least one of a skip profile and a knowledge state model of a viewer to the narrative map;
determining whether each scene or segment is to be presented, skipped, condensed, or augmented;
transferring selected scenes or segments and augmentations to a processed buffer; and
presenting the contents of the processed buffer to the viewer as seamless playback.
   12.

The method of item 11, further comprising detecting flashbacks by comparing transcript embeddings of current and prior scenes and classifying the scene as redundant if similarity exceeds a threshold.

13.

The method of item 11, further comprising detecting tonal attributes of each scene by applying a multimodal sentiment classifier to video, audio, and textual inputs.

14.

The method of item 11, further comprising dynamically reprocessing the input buffer upon receiving corrective feedback from the viewer.

15.

The method of item 11, further comprising substituting skipped scenes with explanatory augmentation, including at least one of: a textual summary, a spoken recap, or enlargement of on-screen clues.

16.

A non-transitory computer-readable medium storing instructions that, when executed by one or more processors, cause the processors to perform the method of item 11.

17.

The system of item 1, wherein the scene-to-text processing module employs a transformer-based multimodal neural network trained on annotated corpora of film and literature to assign narrative function labels.

18.

The system of item 1, wherein the processed buffer is configured to store only media segments designated for presentation, thereby enabling seamless transitions between retained and omitted scenes.

19.

The method of item 11, wherein the skip profile is automatically updated when the system detects that a viewer has manually skipped a category of scenes three or more times.

20.

The system of item 1, wherein the decision-making module comprises a reinforcement learning component configured to adapt playback decisions to long-term viewer behavior.

### Embodiment AS: Multi-Mode Perceptual Event Camera Sensor

A reconfigurable retina is disclosed, comprising an event-based vision sensor configured to deliver adaptive streams of event data for robotic and machine vision applications. The system integrates spatially variable filtering, spectral discrimination, and stereo disparity through optical modifications and dynamic software control, thereby producing a tunable visual pipeline. The device operates with dual communication channels, one optimized for low-latency, bandwidth-limited reflex control, and another for higher-bandwidth, higher-latency global reconstruction. By combining probabilistic thinning, sliding-window saccades, and configurable spectral filters, the system mimics the efficiency of biological vision while remaining lightweight, low-power, and suitable for deployment in drones, autonomous vehicles, industrial robots, or any platform requiring high-speed perception with adjustable information density.

### Background

Event-based vision sensors, also known as neuromorphic or dynamic vision sensors, differ fundamentally from frame-based cameras by asynchronously reporting pixel-level brightness changes. This enables microsecond-level latency and sparse, data-efficient scene encoding. However, raw event streams can still overwhelm low-power onboard processors and wireless channels, particularly in robotics where size, weight, and power budgets are critical. Existing systems either forward all events, leading to bandwidth saturation, or attempt local processing, which increases weight and power draw and reduces flexibility. Furthermore, most implementations lack adaptive mechanisms to reconfigure the flow of information according to task context. There exists a need for a vision front-end that preserves the latency and sparsity advantages of event cameras while introducing configurable modes of operation, allowing a remote processing unit to dictate the tradeoff between precision and bandwidth, and permitting optical and computational filtering that make the sensor behave like a tunable retina suited to diverse robotic applications.

### Description of the Reconfigurable Retina

The disclosed system comprises an event-based sensor modified and operated such that its data output behaves like a reconfigurable retina. The sensor output is divided into regions of differing density: outer fields undergo probabilistic thinning to maintain global awareness at low bandwidth, while a central fovea transmits denser event data for precise analysis. The central fovea may be optically modified with mirrors to generate stereo disparity, including multiple baselines by placing mirrors above and below the sensor, thereby expanding vertical depth perception, or left unmirrored to expand vertical field-of-view. Static spectral filters, such as strips of colored film, can be arranged horizontally and vertically across the sensor aperture, such that objects with specific spectral patterns generate temporally coherent blobs as they pass through filtered zones during forward motion or yaw scanning. A sliding high-resolution window produces saccade-like bursts of dense events, building up detail over time. All such parameters—probabilistic thinning rates, fovea placement, saccade dynamics, spectral filter selection, clustering vs. raw event transmission—are adjustable by a remote computing unit. The system transmits events via dual wireless channels: a low-latency, low-bandwidth channel (e.g., ESP-NOW) carrying reflex-critical filtered data, and a higher-bandwidth, higher-latency channel (e.g., Wi-Fi) carrying bulk streams. The remote computer fuses the inputs, issuing updated configuration commands to the sensor front-end, effectively offloading intelligence to a heavier compute resource while keeping the vision payload lightweight. This architecture is suitable for a broad range of applications including but not limited to aerial robotics, autonomous vehicles, industrial inspection, and dynamic object tracking, wherever high-speed visual feedback must be tuned to balance precision and bandwidth in real time.

Advantages. You concentrate information where it matters and starve the link of everything else. Event sensing gives microsecond reaction and zero “empty” frames; probabilistic thinning in the periphery cuts bandwidth by 10-100× without distorting geometry; a dense central fovea plus mirror-based stereo gives instantaneous depth with cm→mm accuracy at practical baselines; spectral strips (blue/red/green, or other bands) provide passive, zero-power discrimination so targets carry a color “fingerprint” as they move through the filtered bands; moving the fovea as saccades (raster or attention-driven) builds detail over time while keeping the payload featherweight (one sensor, a mirror, thin filters); the system is reconfigurable at runtime (thinning rate, ROI size/position, scan speed, spectral gating, clustering vs raw), so it adapts to lighting, motion, task priority, and link quality; dual links let you split control vs context-ultra-low-latency, bandwidth-capped reflex data on ESP-NOW and richer, higher-latency context on Wi-Fi-so the platform remains responsive even when the scene explodes with activity.

How the remote computer integrates the streams. The drone tags every micro-batch of events (e.g., 0.5-2 ms slices) with precise timestamps, IMU/yaw state, and the current retina configuration. The server ingests two asynchronous feeds: (1) a fast reflex channel (ESP-NOW) carrying the dense fovea, selected spectral bands, and lightweight local summaries (cluster centroids, event histograms) and (2) a slow context channel (Wi-Fi) carrying raw/bulk events or buffered ROI bursts. A synchronizer aligns both by time and configuration, then a fusion stack maintains: a time-surface map (decaying event volumes for edges/motion), a stereo depth head that forms a small cost volume from the two mirrored halves of the fovea for instant disparity, and a global state estimator (factor-graph/EKF) that fuses depth, ego-motion (IMU/yaw), and periphery events to keep a consistent 3D world with uncertainty. When slow-channel data arrives, it is “snapped” into this map to densify surfaces and correct drift. This architecture ensures immediate control decisions always come from the freshest low-latency data, while accuracy and coverage improve as high-bandwidth data trickles in.

Neural completion and perception. Because your periphery is thinned and your fovea scans, the server runs learned models that “complete” what's missing and lift the sparse stream into actionable structure. A dual-stream encoder ingests (a) the fovea events (left/right stereo halves+spectral bands as separate channels) and (b) the periphery events (thinned). Events are voxelized (time×height×width) or converted to time-surfaces, then passed through an event-CNN/transformer to produce features. A stereo head (small 3D cost-volume network) estimates disparity (and confidence) from the mirrored fovea instantly; a segmentation/classification head exploits spectral channels to label target-like blobs with very low false positives; a completion head super-resolves and inpaints sparse periphery using learned priors (leaf geometry, target morphology), effectively predicting edges the retina didn't transmit; and a tracker(RNN/transformer with memory) maintains object identities through saccades and occlusions. If some downstream stack expects frames, an event-to-intensity reconstructor can synthesize “pseudo-frames” for compatibility, but the control loop stays natively event-based.

Reinforcement learning to drive the hardware optimally. Treat every adjustable knob as an action: per-region thinning probabilities, fovea size/position, saccade trajectory and speed, spectral gates to pass/ignore, clustering thresholds, when to promote an area from periphery to fovea, and which link (fast/slow) carries which payload. The observation to the policy includes current map confidence, detector/tracker uncertainties, link utilization, battery, motion state, lighting estimates, and recent reward signals. Define a speed-centric reward—negative time-to-detect/lock, penalties for false negatives/positives, bandwidth and power costs, plus safety margins—and optimize with continuous-control RL (e.g., SAC/PPO) under constraints (never starve the reflex loop, never exceed link budgets). Train in simulation with an event-camera simulator and domain randomization (lighting, wind, background textures, target appearances), then fine-tune on logs (offline RL) and cautiously online (safe RL with conservative updates). Over time, the policy learns active perception: where to saccade next to maximize expected information gain, how aggressively to thin the periphery without hurting recall, how to schedule raster vs “sticky” fovea when a candidate emerges, and how to allocate payloads across the two radios to keep latency low while steadily enriching the world model.

Putting it together. The drone's retina produces exactly the data the brain needs right now-dense, stereo, possibly spectrally gated events at the point of interest; sparse, global situational awareness everywhere else-while the server stitches fast and slow streams into a coherent 3D, target-aware map. Neural modules fill in what the retina doesn't send, and RL keeps tuning the retina's behavior to minimize time-to-perceive and time-to-act under real bandwidth and power limits. The result is a general-purpose, event-based, reconfigurable vision front-end for robotics that is small, fast, adaptive, and task-optimal.

The sensor needs relative motion between itself and the scene to generate events, since events are triggered only when brightness changes occur at individual pixels. In practice, such motion can arise naturally: a drone or other mobile robot constantly makes micro-adjustments-hover corrections, yaw drift, or structural vibrations—that create small shifts in the projected image and thus a background of events. If more deliberate stimulation is desired, it can be introduced in several ways. The camera itself may be oscillated or pivoted to sweep features across the array. A mirror or other optical deflector placed in front of the sensor can be tilted or vibrated to redirect the scene, allowing the sensor to “see motion” without its body moving. At the platform level, the carrier device-be it an aerial drone, ground cart, or robotic arm-can perform programmed maneuvers such as yaw wiggles, scanning passes, or lateral sweeps, all of which generate event activity by creating relative displacement of scene features. In addition to motion of the sensor or its carrier, contrast changes can also be created through active illumination modulation. By strobed or flickered light sources-such as alternating blue and red LEDs—or by passing ambient light through moving or rotating color filters, static objects are made to appear to “blink” in the sensor's view. Even without geometric motion, these temporal changes in illumination produce streams of events tied to the modulation frequency, ensuring that objects with specific reflectance properties can be detected and highlighted. Together, these strategies-sensor motion, optical deflection, platform maneuvers, and controlled illumination-ensure that the event camera remains an active, information-rich sensor even when the scene or object of interest is largely static.

### Figure Elements

1—event sensor 2—high def region 3—low def region 4—first horizontal cellophane strip 5—second horizontal cellophane strip 6—first vertical cellophane strip 7—second vertical cellophane strip 8—moving higher def window (saccades) 9—moving higher def window ROI (the window moves in said ROI) 10—lower placed mirror for stereo vision 11—upper placed mirror for stereo vision

FIG. 60 illustrates a reconfigurable retina based on an event sensor (1). The sensor output is organized into regions of differing informational density. A high-definition region (2) forwards events with minimal or no thinning to support precision analysis, while a surrounding low-definition region (3) is probabilistically filtered to reduce bandwidth demands but still provide situational awareness.

To add passive spectral discrimination, the sensor aperture is partly covered with cellophane strips. A first horizontal strip (4) and a second horizontal strip (5) extend across the field of view so that, during forward motion of the platform, objects with distinctive reflectance properties generate coherent event bursts as they traverse successive filtered zones. Similarly, a first vertical strip (6) and a second vertical strip (7) extend in the orthogonal direction so that, during yaw motion, spectral differences are revealed as objects pass through the vertically arranged bands.

Within the high-definition region, a sliding window (8) is defined inside a bounded saccade ROI (9). The window can transmit every event in its path, or alternatively a less or differently filtered stream, and may move in raster or attention-driven sweeps. This mechanism produces saccade-like bursts of dense data that progressively enrich the field of view. Because the ROI (9) may be positioned anywhere on the sensor, the sliding window (8) can also operate in low-definition zones, so that peripheral regions periodically contribute higher-density data to allow the remote computer to refine or correct its internal representation.

Stereo depth is achieved through optical folding. A lower placed mirror (10) and an upper placed mirror (11) redirect displaced views of the scene into portions of the high-definition region, producing disparities that yield instantaneous depth measurements while still leaving sections of the fovea unmirrored to expand vertical coverage.

Together these elements-event sensor (1), regions of differing resolution (2, 3), spectral filters (4-7), sliding saccadic window (8, 9), and stereo mirrors (10, 11)-form a reconfigurable retina. The system balances sparse global coverage, dense local detail, spectral discrimination, stereo depth, and adaptive saccadic sampling, enabling efficient transmission of event data under bandwidth limits while supplying rich information for remote interpretation. The remote compute unit that is using the data may send back instruction to the local processing unit, that alter how the sensor is divided into regions and how the events in those regions are processed and transmitted, allowing for a solution that is extremely versatile, has powerful remote based compute and can be built lightweight with minimal local power consumption and cooling requirements.

It is noted that the designation of high- or low-definition regions on the event sensor is conceptual, and such regions may be positioned in any portion of the array as required by the application; the invention lies in the principle of varying informational density rather than in any fixed placement. The boundaries between regions need not be abrupt, and filtering, grouping, or processing of events may change gradually so that information density rises or diminishes in a continuous manner across the field. Likewise, the spectral filtering elements are not limited to specific strips of cellophane, but may be formed of any suitable filter material and placed at any point along the optical path, including in front of the lens, within an intermediate optical stage, or directly upon the sensor surface.

Because the event sensor can output low-bandwidth streams from selectively filtered regions, these data can be transmitted with very low latency to a remote computing unit referred to as the controller. The controller receives only sparse but highly informative event streams, and because both the upstream event data and the downstream control instructions are lightweight, the communication loop achieves extremely low latency in both directions. This permits the controller to issue near-instantaneous attitude and navigation updates to the drone or other host machine. Since the controller is remote and not constrained by weight or power, it can employ heavy, high-performance hardware to run complex inference and planning algorithms in real time, while the drone remains light and agile.

In a representative operation, a drone is tasked with identifying and neutralizing insects characterized by white-and-black striped bodies and an orange thorax. The mission begins in the search phase, where the controller configures the event sensor to transmit events only from the spectrally filtered red and blue regions, or alternatively to forward only clustered blobs that consistently traverse both filters. This spectral coincidence provides a strong initial filter for the target insect. At the same time, GPS, IMU, and attitude data are streamed to the controller so that each detection is logged with precise geolocation. Because the event data and the control commands are both very low bandwidth, the communication loop remains extremely low latency, enabling the controller to process detections in real time while the drone continues its forward sweep. After sufficient candidate positions have been logged, the controller commands the drone to revisit each site in turn.

Upon reaching a candidate site, the operation enters the mapping phase. The controller reconfigures the sensor so that only stereo events from the mirrored regions and vertically filtered spectral data are transmitted. The drone is instructed to perform a controlled 360-degree yaw, sweeping the reconfigured retina across the scene. This maneuver provides the controller with stereo disparities and spectral responses from multiple angles, which are fused into a three-dimensional reconstruction of the local environment. Within this map, the controller accurately marks the positions of target insects relative to the plant structures and the drone's frame of reference.

Once the three-dimensional map is established, the system enters the targeting phase. The event sensor is reconfigured again: peripheral regions are transmitted in a stochastically thinned fashion to maintain global situational awareness at low bandwidth, while the central fovea is transmitted at higher density for precise control. The drone is oriented so that this high-definition region is directed at a chosen insect. Continuous stereo disparity from the mirrored regions supplies real-time depth information, and the controller generates low-latency attitude commands that keep the insect fixed at the center of view. In parallel, the controller has also instructed the local processor to intermittently slide the saccadic window into the low-definition regions, so that even the periphery occasionally provides bursts of higher-resolution data. These enrichments are returned to the controller, allowing it to validate and refine its global map during targeting. Once a stable lock is achieved, the controller commands the drone to fire its laser to neutralize the insect. The drone then proceeds to the next logged site, and the sequence-mapping followed by targeting-is repeated until all recorded targets have been addressed.

Throughout the mission, the division of labor remains clear: the lightweight drone hosts only the sensor, minimal filtering logic, and dual transmission units, while the controller, unconstrained by weight and power, executes complex spectral discrimination, three-dimensional reconstruction, and targeting logic. By continually reconfiguring the retina-like sensor for each operational phase-search, mapping, and targeting-the system optimizes bandwidth, preserves extremely low latency in both directions, and leverages heavy compute only where it is most effective.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A sensor comprising:
an event sensor array;
a processing unit; and
a first transmitting unit,
the event sensor array including a first region and a second region,
wherein the processing unit is configured to apply different levels of filtering or processing to events generated in the first region and the second region, such that, for a comparable number of events generated in the first and second regions, a greater amount of data derived from the first region is transmitted through the first transmitting unit than from the second region.
   2.

The sensor of item 1, wherein the filtering comprises probabilistic thinning such that events generated in the second region are transmitted with a lower probability than events generated in the first region.

3.

The sensor of item 1, wherein the first region comprises a movable window configured to transmit all or substantially all events within the window, the window being movable within a bounded region of interest so as to provide saccade-like bursts of higher-density event data.

4.

The sensor of item 1, wherein at least one portion of the event sensor array, or an associated lens, or an intermediate portion of the optical path, is provided with a spectral filter such that events generated from light passing through that filter are spectrally discriminated.

5.

The sensor of item 1, further comprising at least one mirror arranged such that light from a point in a scene is received by the event sensor array along two optical paths, thereby producing stereo disparity information.

6.

The sensor of item 1, further comprising a second transmitting unit configured to transmit a less-filtered or unfiltered event stream at higher bandwidth in parallel with the first transmitting unit.

7.

The sensor of item 1, wherein the processing unit is configured to transmit clustered or grouped events from at least one of the regions instead of individual events.

8.

The sensor of item 1, wherein the definition, location, or filtering characteristics of the first and second regions are dynamically adjustable in response to control instructions from a remote computing unit.

9.

The sensor of item 1, wherein the first transmitting unit comprises a low-latency, bandwidth-limited wireless link and the second transmitting unit of item 6 comprises a higher-latency, higher-bandwidth wireless link.

### Embitterment ASE: Multi-Mode Perceptual Event Camera Sensor

A reconfigurable retina is disclosed, comprising an event-based vision sensor configured to deliver adaptive streams of event data for robotic and machine vision applications. The system integrates spatially variable filtering, spectral discrimination, and stereo disparity through optical modifications and dynamic software control, thereby producing a tunable visual pipeline. The device operates with dual communication channels, one optimized for low-latency, bandwidth-limited reflex control, and another for higher-bandwidth, higher-latency global reconstruction. By combining probabilistic thinning, sliding-window saccades, and configurable spectral filters, the system mimics the efficiency of biological vision while remaining lightweight, low-power, and suitable for deployment in drones, autonomous vehicles, industrial robots, or any platform requiring high-speed perception with adjustable information density.

### Gentle Introduction

Conventional cameras capture complete frames at fixed intervals, which can waste bandwidth and compute on pixels that do not change. Event-based sensors instead report only changes in brightness at each pixel, more like how a biological retina signals motion and edges rather than full images. A system that prioritizes important regions and deprioritizes everything else can therefore reduce latency and bandwidth while preserving the cues needed for control.

The disclosed reconfigurable retina may be understood as providing a dense fovea and a sparse periphery. The fovea can pass most or all events to support precise actions, while the periphery can be thinned to maintain broad awareness at a fraction of the data rate. The fovea can move as saccades so that detail is accumulated over time without ever streaming everything at once. Simple optics may add capabilities: small mirrors can fold two views into the sensor to obtain stereo disparity for depth, and colored or other spectral strips can cause objects to exhibit distinct, time-coherent responses as they pass through those zones during motion.

Because different tasks benefit from different data shapes, the sensor can be reconfigured at runtime.

A low-latency, bandwidth-limited link may carry reflex-critical data, while a higher-bandwidth link may deliver richer context. A remote computer may fuse these streams, update configuration, and optionally run learned or classical perception models. When the scene is static, gentle motions of the platform, a small optical deflector, or controlled illumination modulation may still create the brightness changes that event sensors require, ensuring continued observability.

This arrangement could be deployed on drones, ground robots, or fixed systems that need fast reactions under tight power and weight budgets. It concentrates information where it matters, adapts to the environment and task, and remains interoperable with different radios, protocols, and software stacks.

### Scope

The scope of this disclosure is defined solely by the claims. The figures, element numbers, and operational examples are illustrative and non-limiting embodiments. Steps, operations, and flows may be reordered, performed in parallel, omitted, or replaced with technical equivalents, and features described in connection with any embodiment may be combined with features of any other embodiment unless stated otherwise.

For clarity, the term “region” as used herein need not be limited to a contiguous rectangular portion of the sensor array. Logical regions may be defined in multiple equivalent ways, including but not limited to: explicit spatial masks (rectangular, circular, polygonal, or arbitrary shaped subsets of pixels); probability fields that assign per-pixel transmission probabilities varying smoothly or discretely across the array; threshold-based criteria such as event magnitude, polarity, or temporal density that implicitly define subsets of events as belonging to a higher- or lower-fidelity region; and per-pixel bias adjustments, refractory periods, or comparator hysteresis settings that modulate the likelihood of event generation. These mechanisms may be combined or substituted to realize first and second regions in which events are differentially filtered, processed, consumed, or transmitted. By encompassing both fixed and adaptive logical definitions, the inventive concept extends beyond any particular geometry and remains operable with masks, criteria, or biases applied at sensor, circuit, or software levels.

### Background

Event-based vision sensors, also known as neuromorphic or dynamic vision sensors, differ fundamentally from frame-based cameras by asynchronously reporting pixel-level brightness changes. This enables microsecond-level latency and sparse, data-efficient scene encoding. However, raw event streams can still overwhelm low-power onboard processors and wireless channels, particularly in robotics where size, weight, and power budgets are critical. Existing systems either forward all events, leading to bandwidth saturation, or attempt local processing, which increases weight and power draw and reduces flexibility. Furthermore, most implementations lack adaptive mechanisms to reconfigure the flow of information according to task context. There exists a need for a vision front-end that preserves the latency and sparsity advantages of event cameras while introducing configurable modes of operation, allowing a remote processing unit to dictate the tradeoff between precision and bandwidth, and permitting optical and computational filtering that make the sensor behave like a tunable retina suited to diverse robotic applications.

### Summary

A multi-mode perceptual event camera sensor is provided that may implement region-differentiated event handling, movable foveal windows, stereo optical folding, and spectral filtering, while supporting dual communication paths and remote reconfiguration. The system may transmit low-latency, bandwidth-capped reflex data in parallel with higher-bandwidth contextual data, and a remote computing unit may fuse these inputs to maintain time-surface maps, stereo depth, and global state. Embodiments may include optional neural completion, reinforcement-learned policies for adaptive sensing, active or passive means to stimulate event generation under static scenes, interoperability through an implementation-agnostic interface, and subscription-enabled usage accounting, thereby delivering concrete technical effects such as reduced end-to-end latency, controllable bandwidth, improved depth estimation, and task-adaptive sensing.

### Technical Effects

The disclosed architecture may yield specific technical effects tied to the principal embodiments. Differential regional handling with probabilistic thinning may reduce link utilization by at least an order of magnitude under typical motion while preserving geometric fidelity of edges and motion cues, thereby lowering end-to-end latency variance and reducing processor load without collapsing situational awareness. A movable foveal window that sweeps within a bounded region of interest may increase effective spatial resolution over time without increasing instantaneous bandwidth, improving time-to-detect and time-to-lock for targets while keeping reflex paths unclogged.

Stereo disparity produced by optical folding using mirrors, prisms, or beam splitters may provide instantaneous depth estimates without requiring a second sensor, reducing weight, power, and calibration drift while enabling multi-baseline operation for near and far ranges; depth accuracy may improve into centimeter or millimeter regimes at practical baselines due to event-synchronous edge timing. Passive spectral filtering arranged as horizontal and vertical strips may induce temporally coherent, spectrally separable responses during forward motion or yaw scanning, which may lower false positives in classification and tracking while consuming zero electrical power at the aperture. Dual, concurrently operating communication paths may isolate reflex-critical payloads from bulk context, which may maintain deterministic control latency under high scene activity and prevent back-pressure from the slow channel. Remote reconfiguration over an implementation-agnostic interface may decouple sensing hardware from policy and perception software, enabling rapid adaptation to link quality, lighting, and mission objectives without firmware replacement, and lowering integration costs across radio stacks and operating systems.

Active stimulation through optical deflection or illumination modulation may guarantee observability in static scenes by creating controlled brightness changes at the sensor, which may stabilize detection performance in conditions where motion is minimal. Learned completion and policy modules may convert sparse events into dense actionable structure and may allocate bandwidth adaptively to maximize expected information gain, which may reduce time-to-perceive and time-to-act while respecting power and link budgets. Instrumented headers, timestamps, and configuration tags in transmitted streams may provide externally verifiable evidence of operation, which may facilitate validation, safety audits, subscription metering, and forensic analysis without invasive inspection of internal firmware.

### Detailed Description

### Description of the Reconfigurable Retina

The disclosed system comprises an event-based sensor modified and operated such that its data output behaves like a reconfigurable retina. The sensor output is divided into regions of differing density: outer fields undergo probabilistic thinning to maintain global awareness at low bandwidth, while a central fovea transmits denser event data for precise analysis. The central fovea may be optically modified with mirrors to generate stereo disparity, including multiple baselines by placing mirrors above and below the sensor, thereby expanding vertical depth perception, or left unmirrored to expand vertical field-of-view. Static spectral filters, such as strips of colored film, can be arranged horizontally and vertically across the sensor aperture, such that objects with specific spectral patterns generate temporally coherent blobs as they pass through filtered zones during forward motion or yaw scanning. A sliding high-resolution window produces saccade-like bursts of dense events, building up detail over time. All such parameters—probabilistic thinning rates, fovea placement, saccade dynamics, spectral filter selection, clustering vs. raw event transmission—are adjustable by a remote computing unit. The system transmits events via dual wireless channels: a low-latency, low-bandwidth channel (e.g., ESP-NOW) carrying reflex-critical filtered data, and a higher-bandwidth, higher-latency channel (e.g., Wi-Fi) carrying bulk streams. The remote computer fuses the inputs, issuing updated configuration commands to the sensor front-end, effectively offloading intelligence to a heavier compute resource while keeping the vision payload lightweight. This architecture is suitable for a broad range of applications including but not limited to aerial robotics, autonomous vehicles, industrial inspection, and dynamic object tracking, wherever high-speed visual feedback must be tuned to balance precision and bandwidth in real time.

Advantages. The system may concentrate information where it matters and reduce transmission of other data. Event sensing may provide microsecond reaction and avoid empty frames; probabilistic thinning in the periphery may cut bandwidth by 10-100× without distorting geometry; a dense central fovea plus mirror-based stereo may provide instantaneous depth with cm→mm accuracy at practical baselines; spectral strips (blue/red/green, or other bands) may provide passive, zero-power discrimination so targets may carry a color “fingerprint” as they move through the filtered bands; moving the fovea as saccades (raster or attention-driven) may build detail over time while keeping the payload featherweight (one sensor, a mirror, thin filters); the system may be reconfigurable at runtime (thinning rate, ROI size/position, scan speed, spectral gating, clustering vs raw), so it may adapt to lighting, motion, task priority, and link quality; dual links may permit splitting control versus context-ultra-low-latency, bandwidth-capped reflex data on ESP-NOW and richer, higher-latency context on Wi-Fi-so the platform may remain responsive even when the scene exhibits high activity. How the remote computer integrates the streams. The drone may tag every micro-batch of events (e.g., 0.5-2 ms slices) with precise timestamps, IMU/yaw state, and the current retina configuration. The server may ingest two asynchronous feeds: (1) a fast reflex channel (ESP-NOW) carrying the dense fovea, selected spectral bands, and lightweight local summaries (cluster centroids, event histograms) and (2) a slow context channel (Wi-Fi) carrying raw/bulk events or buffered ROI bursts. A synchronizer may align both by time and configuration, then a fusion stack may maintain: a time-surface map (decaying event volumes for edges/motion), a stereo depth head that forms a small cost volume from the two mirrored halves of the fovea for instant disparity, and a global state estimator (factor-graph/EKF) that fuses depth, ego-motion (IMU/yaw), and periphery events to keep a consistent 3D world with uncertainty. When slow-channel data arrives, it may be “snapped” into this map to densify surfaces and correct drift. This architecture may ensure immediate control decisions come from the freshest low-latency data, while accuracy and coverage improve as high-bandwidth data arrives.

Neural completion and perception. Because the periphery may be thinned and the fovea may scan, the server may run learned models that “complete” what is missing and lift the sparse stream into actionable structure. A dual-stream encoder may ingest (a) the fovea events (left/right stereo halves+spectral bands as separate channels) and (b) the periphery events (thinned). Events may be voxelized (time×height×width) or converted to time-surfaces, then passed through an event-CNN/transformer to produce features. A stereo head (small 3D cost-volume network) may estimate disparity (and confidence) from the mirrored fovea; a segmentation/classification head may exploit spectral channels to label target-like blobs with low false positives; a completion head may super-resolve and inpaint sparse periphery using learned priors (leaf geometry, target morphology); and a tracker (RNN/transformer with memory) may maintain object identities through saccades and occlusions. If some downstream stack expects frames, an event-to-intensity reconstructor may synthesize “pseudo-frames” for compatibility, while the control loop may remain natively event-based. Reinforcement learning to drive the hardware optimally. In some embodiments, each adjustable parameter may be treated as an action: per-region thinning probabilities, fovea size/position, saccade trajectory and speed, spectral gates to pass/ignore, clustering thresholds, when to promote an area from periphery to fovea, and which link (fast/slow) carries which payload. The observation to the policy may include current map confidence, detector/tracker uncertainties, link utilization, battery, motion state, lighting estimates, and recent reward signals. A speed-centric reward may be defined-negative time-to-detect/lock, penalties for false negatives/positives, bandwidth and power costs, plus safety margins—and optimized with continuous-control RL (e.g., SAC/PPO) under constraints (never starve the reflex loop, never exceed link budgets). Training may begin in simulation with an event-camera simulator and domain randomization (lighting, wind, background textures, target appearances), then proceed to fine-tuning on logs (offline RL) and cautiously online (safe RL with conservative updates). Over time, the policy may learn active perception: where to saccade next to maximize expected information gain, how aggressively to thin the periphery without hurting recall, how to schedule raster versus “sticky” fovea when a candidate emerges, and how to allocate payloads across the two radios to keep latency low while steadily enriching the world model. Putting it together. The drone's retina may produce dense, stereo, and optionally spectrally gated events at the point of interest, while sparse, global situational awareness may be maintained elsewhere; the server may stitch fast and slow streams into a coherent 3D, target-aware map. Neural modules may fill in what the retina does not send, and RL may keep tuning the retina's behavior to minimize time-to-perceive and time-to-act under real bandwidth and power limits. The result may be a general-purpose, event-based, reconfigurable vision front-end for robotics that is small, fast, adaptive, and task-optimal.

The sensor needs relative motion between itself and the scene to generate events, since events are triggered only when brightness changes occur at individual pixels. In practice, such motion can anise naturally: a drone or other mobile robot constantly makes micro-adjustments-hover corrections, yaw drift, or structural vibrations—that create small shifts in the projected image and thus a background of events. If more deliberate stimulation is desired, it can be introduced in several ways. The camera itself may be oscillated or pivoted to sweep features across the array. A mirror or other optical deflector placed in front of the sensor can be tilted or vibrated to redirect the scene, allowing the sensor to “see motion” without its body moving. At the platform level, the carrier device-be it an aerial drone, ground cart, or robotic arm-can perform programmed maneuvers such as yaw wiggles, scanning passes, or lateral sweeps, all of which generate event activity by creating relative displacement of scene features. In addition to motion of the sensor or its carrier, contrast changes can also be created through active illumination modulation. By strobed or flickered light sources-such as alternating blue and red LEDs—or by passing ambient light through moving or rotating color filters, static objects are made to appear to “blink” in the sensor's view. Even without geometric motion, these temporal changes in illumination produce streams of events tied to the modulation frequency, ensuring that objects with specific reflectance properties can be detected and highlighted. Together, these strategies-sensor motion, optical deflection, platform maneuvers, and controlled illumination-ensure that the event camera remains an active, information-rich sensor even when the scene or object of interest is largely static.

Spectral filtering in combination with region-based sweeping may be used to identify objects of interest that exhibit one or more characteristic colors. Passive filters arranged as horizontal or vertical bands, or in any other spatial configuration, cause objects with distinctive reflectance properties to generate temporally correlated event bursts as they traverse the filtered zones. Background elements with uniform reflectance generally produce less distinctive patterns, whereas objects with multiple color components yield a recognizable sequence of activations. A representative case is the Colorado potato beetle, whose alternating white stripes register as strong responses in the blue band and whose orange thorax yields pronounced responses in the red band. As the beetle moves forward or as the platform yaws, the insect sequentially crosses filtered regions, producing a temporally coherent signature: first a cluster in the blue-sensitive zone, then a cluster in the red-sensitive zone, often repeating in predictable succession. Such multi-band coincidence signatures may be detected locally by lightweight logic resident on the host platform, enabling immediate recognition without reliance on high-bandwidth links, or they may be transmitted as filtered event streams to a remote computing unit, where more sophisticated algorithms exploit the spatial and temporal sequence of spectral activations for confirmation. By configuring the retina to sweep its high-definition window or by maneuvering the carrier platform so that candidate objects pass through multiple spectral regions, the system obtains a compact but distinctive spectral signature that supports both real-time onboard detection and deferred remote classification. This division of labor allows the platform to maintain reflex-level responsiveness while still benefiting from the depth and accuracy of remote, compute-intensive analysis, thereby ensuring that targets defined by characteristic spectral combinations can be isolated reliably even under stringent bandwidth and power constraints.

In some embodiments, the sensor's event output may be compressed using content-aware, motion-compensated primitive coding that models coherent structures such as edges or line segments directly in space-time, rather than transmitting each underlying event individually. A streaming detector (e.g., incremental Hough/RANSAC with a light Kalman or Bayesian tracker) may fit a line or short spline to clustered events within a micro-window and estimate a local motion vector; the encoder then emits a compact primitive description-anchor, orientation, velocity, optional thickness and polarity, validity interval, and quantized confidence-in lieu of dense events, with optional residuals only where observations deviate from the predicted locus by more than a bounded spatial or temporal error. This predictive layer may operate above conventional event formats (e.g., address-event streams) so that existing on-sensor encoders remain unchanged while the front end or a downstream proxy converts raw micro-batches into primitive updates and sparse residual masks that are entropy-coded using contexts derived from polarity, recent occupancy, and local density. For scenes without long straight edges or when curvature appears, the system may fall back to piecewise-linear splines or to tile-wise constant-flow prediction that transmits per-tile motion and small residuals; for archival or offline use, events may alternatively be treated as point clouds in (x,y,t)(x,y,t) and encoded with learned or octree-based schemes, while the live reflex path keeps the predictive primitive layer to minimize latency. This compression framework integrates naturally with the disclosed multimode retina: the low-latency link may carry only primitive “NEW/UPDATE/END” messages for active foveal structures and lightweight summaries from thinned peripheral regions so that control remains deterministic under load, while the higher-bandwidth link may opportunistically ship residuals, ROI bursts, or raw buffers to densify reconstruction when bandwidth allows. Because region definitions, thinning probabilities, saccade windows, and spectral or stereo configurations are already controllable at runtime, the same policy that allocates information density across sensor regions may also modulate compression aggressiveness, quantization steps, and residual thresholds per region and per task, preserving bounded error in reflex-critical zones and favoring higher compression in background areas. Instrumented headers with timestamps, configuration identifiers, and primitive IDs allow external verification that, for comparable excitation, more data is handled from first regions than from second regions even after compression, and that predicted event loci align with commanded saccade trajectories, stereo enablement, and spectral gating, thereby providing explicit support for region-differentiated handling and dual-channel transmission while reducing link utilization and compute without sacrificing the claimed low-latency behavior.

### Description of the Drawings

FIG. 60 shows one embodiment of possible divisions of the sensor in different functional regions.

### Figure Elements

1—event sensor 2—high def region 3—low def region 4—first horizontal cellophane strip 5—second horizontal cellophane strip 6—first vertical cellophane strip 7—second vertical cellophane strip 8—moving higher def window (saccades) 9—moving higher def window ROI (the window moves in said ROI) 10—lower placed mirror for stereo vision 11—upper placed mirror for stereo vision FIG. 11 illustrates a reconfigurable retina based on an event sensor (1). The sensor output is organized into regions of differing informational density. A high-definition region (2) forwards events with minimal or no thinning to support precision analysis, while a surrounding low-definition region (3) is probabilistically filtered to reduce bandwidth demands but still provide situational awareness. To add passive spectral discrimination, the sensor aperture is partly covered with cellophane strips. A first horizontal strip (4) and a second horizontal strip (5) extend across the field of view so that, during forward motion of the platform, objects with distinctive reflectance properties generate coherent event bursts as they traverse successive filtered zones. Similarly, a first vertical strip (6) and a second vertical strip (7) extend in the orthogonal direction so that, during yaw motion, spectral differences are revealed as objects pass through the vertically arranged bands.

Within the high-definition region, a sliding window (8) is defined inside a bounded saccade ROI (9). The window can transmit every event in its path, or alternatively a less or differently filtered stream, and may move in raster or attention-driven sweeps. This mechanism produces saccade-like bursts of dense data that progressively enrich the field of view. Because the ROI (9) may be positioned anywhere on the sensor, the sliding window (8) can also operate in low-definition zones, so that peripheral regions periodically contribute higher-density data to allow the remote computer to refine or correct its internal representation.

Stereo depth is achieved through optical folding. A lower placed mirror (10) and an upper placed mirror (11) redirect displaced views of the scene into portions of the high-definition region, producing disparities that yield instantaneous depth measurements while still leaving sections of the fovea unmirrored to expand vertical coverage.

Together these elements—event sensor (1), regions of differing resolution (2, 3), spectral filters (4-7), sliding saccadic window (8, 9), and stereo mirrors (10, 11)—form a reconfigurable retina. The system balances sparse global coverage, dense local detail, spectral discrimination, stereo depth, and adaptive saccadic sampling, enabling efficient transmission of event data under bandwidth limits while supplying rich information for remote interpretation. The remote compute unit that is using the data may send back instruction to the local processing unit, that alter how the sensor is divided into regions and how the events in those regions are processed and transmitted, allowing for a solution that is extremely versatile, has powerful remote based compute and can be built lightweight with minimal local power consumption and cooling requirements.

It is noted that the designation of high- or low-definition regions on the event sensor is conceptual, and such regions may be positioned in any portion of the array as required by the application; the invention lies in the principle of varying informational density rather than in any fixed placement. The boundaries between regions need not be abrupt, and filtering, grouping, or processing of events may change gradually so that information density rises or diminishes in a continuous manner across the field. As used herein, a region may be non-contiguous, may vary over time, and may be defined by an arbitrary mask or probability field; a region may also be defined implicitly by a criterion applied to events or pixels, including at least one of saliency or detector score thresholds, motion direction, polarity, or timestamp windows, in which case events that satisfy the criterion constitute a first region and events that do not satisfy the criterion constitute a second region for differential handling. Logical regions may span multiple physical sensors that are treated as a single virtual array without departing from the disclosed behaviors. Likewise, the spectral filtering elements are not limited to specific strips of cellophane, but may be formed of any suitable filter material and placed at any point along the optical path, including in front of the lens, within an intermediate optical stage, or directly upon the sensor surface.

Because the event sensor can output low-bandwidth streams from selectively filtered regions, these data can be transmitted with very low latency to a remote computing unit referred to as the controller. The controller receives only sparse but highly informative event streams, and because both the upstream event data and the downstream control instructions are lightweight, the communication loop achieves extremely low latency in both directions. This permits the controller to issue near-instantaneous attitude and navigation updates to the drone or other host machine. Since the controller is remote and not constrained by weight or power, it can employ heavy, high-performance hardware to run complex inference and planning algorithms in real time, while the drone remains light and agile.

### Examples

In a representative operation, a drone is tasked with identifying and neutralizing insects characterized by white-and-black striped bodies and an orange thorax. The mission begins in the search phase, where the controller configures the event sensor to transmit events only from the spectrally filtered red and blue regions, or alternatively to forward only clustered blobs that consistently traverse both filters. This spectral coincidence provides a strong initial filter for the target insect. At the same time, GPS, IMU, and attitude data are streamed to the controller so that each detection is logged with precise geolocation. Because the event data and the control commands are both very low bandwidth, the communication loop remains extremely low latency, enabling the controller to process detections in real time while the drone continues its forward sweep. After sufficient candidate positions have been logged, the controller commands the drone to revisit each site in turn.

Upon reaching a candidate site, the operation enters the mapping phase. The controller reconfigures the sensor so that only stereo events from the mirrored regions and vertically filtered spectral data are transmitted. The drone is instructed to perform a controlled 360-degree yaw, sweeping the reconfigured retina across the scene. This maneuver provides the controller with stereo disparities and spectral responses from multiple angles, which are fused into a three-dimensional reconstruction of the local environment. Within this map, the controller accurately marks the positions of target insects relative to the plant structures and the drone's frame of reference.

Once the three-dimensional map is established, the system enters the targeting phase. The event sensor is reconfigured again: peripheral regions are transmitted in a stochastically thinned fashion to maintain global situational awareness at low bandwidth, while the central fovea is transmitted at higher density for precise control. The drone is oriented so that this high-definition region is directed at a chosen insect. Continuous stereo disparity from the mirrored regions supplies real-time depth information, and the controller generates low-latency attitude commands that keep the insect fixed at the center of view. In parallel, the controller has also instructed the local processor to intermittently slide the saccadic window into the low-definition regions, so that even the periphery occasionally provides bursts of higher-resolution data. These enrichments are returned to the controller, allowing it to validate and refine its global map during targeting. Once a stable lock is achieved, the controller commands the drone to fire its laser to neutralize the insect. The drone then proceeds to the next logged site, and the sequence-mapping followed by targeting-is repeated until all recorded targets have been addressed.

In a software-centric example, the remote computing unit may expose a Model Context Protocol interface to orchestrate configuration and ingest streams while remaining implementation-agnostic with respect to transport. The sensor-side processor may publish event micro-batches as line-delimited JSON over a selected channel and accept configuration updates and entitlement flags as signed JSON messages. An event micro-batch could be represented as {“ts_us”:1723456789012, “seq”:145677, “link”:“fast”, “roi”:[128,96,256,192], “cfg_id”:“c7f9”, “imu”:{“ax”: 0.02, “ay”:-0.01, “az”:9.81, “yaw_deg”:14.2}, “events”:[{“x”:120, “y”:85, “p”:1, “dt_us”:3},{“x”:121,” y”:86, “p”:0, “dt_us”:5}]}. A configuration command issued by the controller could be represented as {“cmd”:“set_config”, “cfg_id”:“c7fa”, “regions”:[{“name”:“fovea”, “rect”:[128,96,256,192], “mode”:“pa ss_all”},{“name”:“periphery”, “rect”:[0,0,640,480], “mode”:“thin”, “p”:0.1}], “saccade”:{“roi”:[64,48,51 2,384], “trajectory”:“raster”, “px_per ms”:3}, “spectral”:{“enable”:true, “bands”:[“red”, “blue”]}, “stereo”:{“mirrors”:“upper_lower”}, “routing”:{“fast”:[“fovea”, “clusters”], “slow”:[“raw buffers”]}}. An MCP tool advertisement on the controller side could describe callable tools such as configure retina, request_roi_burst, and get_usage_counters, for example

{“tool”:“configure_retina”,“args_schema”:{“cfg_id”:“string”,“regions”:“array”,“saccade”:“object”,“sp
ectral”:“object”,“stereo”:“object”,“routing”:“object”}} and
{“tool”:“request_roi_burst”,“args_schema”:{“rect”:“array”,“duration_ms”:“number”,“include_spectral
”:“boolean”}}. A license heartbeat emitted by the sensor for monetization could be represented as
{“hb_ts”:1723456790000,“device_id”:“SEN-9A2F”,“license_token”:“eyJhbGciOi...”,“usage_delta”:{“
fast_bytes”:12480,“slow_bytes”:99312,“features”:{“stereo”:true,“spectral”:true,“saccade”:true},“clust
ers_emitted”:42,“cfg_changes”:3},“cfg_id”:“c7fa”,“sig”:“MEQCIH1...”}.

These JSON structures are illustrative and may be transported over different protocols without departing from the claimed behaviors. In one embodiment, the MCP interface could allow a policy module to be swapped or upgraded while preserving the same tool signatures, enabling interoperability across different radio stacks, operating systems, or cloud services and simplifying integration into existing robotic control software.

### Enablement

One implementation may be constructed by selecting a commercially available event sensor module, pairing it with a low-power processing unit capable of dual radio operation, adding lightweight optical elements for disparity and spectral gating, and integrating firmware that performs regional filtering and dual-channel streaming with reconfigurable parameters. A suitable sensor could include a 240×180 to 1280×720 dynamic vision sensor with per-pixel polarity and microsecond timestamping. The lens may be a C-mount or M12 lens with focal length chosen for the target field of view; in one embodiment a 6 mm to 12 mm focal length may be used for drone operations at several meters standoff. The stereo folding optics may comprise two planar mirrors mounted such that the upper mirror directs a slightly elevated view to the upper portion of the array and the lower mirror directs a slightly depressed view to the lower portion of the array, with baselines set by mirror separation and angles to achieve measurable disparities within the foveal region. Spectral filters may be affixed as thin strips across portions of the aperture or placed as small rectangular inserts in a holder in front of the lens; in a simple build, red and blue cellophane may be taped to a ring adapter, while in a more robust build, glass or polymer interference filters may be bonded to a support frame. Electronics may include a processing unit such as a microcontroller or SoC that interfaces to the event sensor over SPI or parallel bus, with sufficient RAM to buffer micro-batches and a secure element to store device keys for licensing and signed usage reporting. A dual-radio configuration may be achieved with a single chip that supports both a low-latency peer protocol and a higher-throughput protocol, or with two radio modules operating concurrently. One embodiment may use an SoC that provides an ultra-low-latency datagram mode for the reflex path and an 802.11 mode for bulk data. The power subsystem may include a DC-DC regulator that supplies clean rails to the sensor and processor, with decoupling capacitors placed near the sensor pins to reduce timestamp jitter, and a thermal path may be provided through the enclosure to maintain sensor stability. Mechanical integration may hold the sensor, lens, mirrors, and filter frame in a rigid assembly. A small adjustable bracket may allow fine tuning of mirror angles so that the two folded views project into predefined subregions of the array without overlap beyond design intent. A simple 3D-printed jig with fiducial patterns may be used during calibration to set the mirror angles and to verify that the foveal region aligns to the intended pixel coordinates. The spectral strips may be positioned so that as the platform moves forward or yaws, objects traverse the bands in a predictable order; placement can be verified by viewing a static high-contrast scene and inducing small oscillations to confirm temporally coherent pulses appear from the filtered subfields.

Firmware may ingest events and partition them by region definitions represented as rectangles or as continuous probability fields. The processor may maintain a configuration object that includes region rectangles, thinning probabilities, fovea window parameters, saccade ROI, spectral routing flags, and radio routing rules. Event handling may accumulate micro-batches over 0.5-2 ms slices, tag each with timestamps, IMU samples, and a configuration identifier, and then dispatch payloads to the low-latency or high-bandwidth channels according to the routing rules. The reflex channel may carry the foveal events, selected spectral bands, and compact summaries such as centroids or histograms, while the bulk channel may carry raw buffers or ROI bursts. Configuration updates may be delivered from a remote controller using signed JSON messages as illustrated in the Examples section, and a Model Context Protocol interface may advertise callable tools that allow reconfiguration and diagnostics without coupling to a specific transport.

Calibration may be performed in stages. Intrinsic calibration may determine pixel timing offsets and polarity thresholds if available. Extrinsic calibration of the stereo folding may be performed by placing a calibration pattern at known distances and adjusting mirror angles until corresponding features in the upper and lower foveal halves produce consistent disparities. A small cost-volume or correlation routine may be run on the remote computer to estimate disparity and to generate a lookup that maps pixel pairs to depth; this lookup may be indexed by pixel row to account for slight mirror geometry differences. Spectral calibration may involve illuminating a gray target with narrowband LEDs to verify that events from filtered regions respond with the expected timing and polarity. Communication calibration may measure end-to-end latency on both links by echoing tagged micro-batches and verifying jitter is within reflex budgets; results may guide thinning probabilities to respect bandwidth limits.

Software integration on the remote computer may include a synchronizer that merges the two channels by timestamps and configuration identifiers, a reconstruction stack that maintains a time-surface map and stereo disparity head, and optional learned modules for completion, detection, and tracking as described elsewhere in this document. If downstream consumers require frames, an event-to-intensity reconstructor may synthesize compatible images while preserving an event-native control loop. The remote interface may expose MCP tools such as configure retina and request_roi_burst, with argument schemas as exemplified in the Examples section, enabling scripted policies or reinforcement-learned agents to adjust parameters. Usage metering and entitlement enforcement may operate in the background via secure, monotonic counters and signed heartbeats so that low-latency reflex operation is not impaired.

Testing may begin with benchtop targets under controlled lighting to validate spectral gating and stereo depth, then proceed to motion tests where the platform performs controlled yaw and translation to ensure that saccades and periphery thinning behave as intended. Fallback modes may be verified by disabling mirrors, spectral filters, or saccades and confirming that regional filtering alone still yields the claimed behaviors. Interoperability may be demonstrated by swapping radio stacks or transports while maintaining the same MCP tool signatures and JSON payloads, confirming that the invention remains agnostic to interface changes. These steps allow a skilled practitioner to reproduce the disclosed embodiments without undue experimentation while leaving ample room to select alternate components such as prisms or beam splitters in place of mirrors, switchable liquid-crystal filters in place of static strips, or wired interfaces in place of wireless links.

Monetization and subscription operation. The sensor and the remote computing unit may support subscription-based or usage-based licensing models without impairing low-latency operation. The processing unit may maintain secure, monotonic usage counters that record, with timestamps, at least one of event-bytes transmitted per channel, time spent with specific features enabled (stereo mirrors active, spectral gating active, saccade window enabled), number of clustered summaries emitted, and configuration changes applied. The counters may be signed locally using a device-unique key stored in a secure element so that usage reports can be validated by a remote service. The system may periodically emit a lightweight heartbeat message containing a compact license token, recent usage deltas, and the current configuration metadata, the heartbeat being carried over either the low-latency link or the higher-bandwidth link depending on availability, and buffered for later transmission if links are unavailable. Entitlement data may be delivered from the remote service to the sensor as cryptographically signed feature flags that enable or restrict specific capabilities, including but not limited to stereo disparity computation at the front end, spectral filter routing, clustering modes, or dual-link concurrency. The sensor may enforce entitlements locally while maintaining a safety floor that preserves essential reflex-path perception even when an entitlement expires, thereby ensuring safe degradation. Audit logs may be retained at the remote computing unit, which may cross-check received usage reports against observable external outputs such as event stream headers, timestamps, configuration tags, and license token rotations to provide externally verifiable evidence of operation under a subscription. This infrastructure could be used to implement subscription tiers, pay-per-use billing, or trial/grace periods while preserving determinism and low latency in the reflex path.

### External Observability

In deployments where internal firmware or hardware is not directly inspectable, the system may define and expose externally verifiable inputs and outputs that allow the claimed behaviors to be proven using observable data alone. Transmitted payloads may include invariant headers such as timestamps, monotonically increasing sequence identifiers, link identifiers indicating fast or slow channel, current configuration identifiers, and optional region or ROI coordinates for any dense window that is active. Configuration messages sent from the remote computing unit may include explicit region definitions, saccade parameters, spectral gating flags, stereo optics descriptors, and routing selections, allowing an observer to correlate commanded configurations with subsequent stream characteristics. Under a configuration that assigns a first region to pass all or substantially all events and a second region to probabilistically thin events, an external observer may verify that, for comparable scene excitation, the measured event density or data volume derived from the first region exceeds that derived from the second region on the link identified as fast, while configuration identifiers confirm that the definitions of the regions have not changed during the measurement interval. When a movable window is commanded to sweep within a bounded region of interest, the observer may detect bursts of higher-density events whose reported ROI coordinates translate across time within the commanded bounds, and whose timing aligns with the configured saccade trajectory and speed. When stereo folding is present, events originating from mirrored subfields may arrive with correlated timestamp patterns in two non-overlapping subregions of the array, and a disparity estimator downstream may report depth estimates tagged with the same configuration identifier that declared stereo mirrors active, thereby providing externally verifiable evidence of dual-path imaging. When spectral gating is enabled in the configuration, the observer may confirm that events reported from filtered subfields vary as a function of external illumination changes or platform motion consistent with the passbands declared in the configuration, for example by alternately illuminating the scene with red and blue light and observing corresponding modulations in reported events from subfields declared as red or blue. Dual-link operation may be validated by observing that micro-batches labeled as fast link exhibit lower end-to-end latency and a restricted payload selection relative to micro-batches labeled as slow link, with both sets carrying the same configuration identifiers for overlapping time windows, demonstrating concurrent operation. These externally observable behaviors align with the interface and stream structures described in the Examples and Enablement sections and with the disclosures of external observability in the itemized embodiments, enabling proof of compliance with the claimed features through inputs and outputs alone.

### Fallback Embodiments

Simpler or partial implementations may preserve the inventive concept of region-differentiated event handling while omitting one or more advanced features. A monocular variant may exclude mirrors or other stereo optics and still apply differential thinning between a high-density region and a low-density region, yielding reduced bandwidth and maintained reflex responsiveness. A fixed-configuration variant may define static region masks and thinning probabilities burned into firmware or selected by a hardware switch, without any remote reconfiguration, while still transmitting more data from a designated first region than from a second region for comparable excitation. A single-link variant may operate solely over a low-latency bandwidth-limited link or solely over a higher-throughput link, or even over a wired interface, while continuing to enforce region-based filtering and optional clustered summaries. A purely local-control variant may consume region-differentiated data on-device to drive actuators or log to local storage without transmitting any events off-device, thereby embodying the invention independent of networking. A no-saccade variant may use a fixed fovea or a periodically scheduled ROI burst at the same location, foregoing sliding windows while retaining the periphery-versus-fovea density contrast. A no-spectral-filter variant may omit optical filters entirely yet still achieve differential information density by post-generation thinning or by adjusting per-pixel thresholds or bias currents so that designated regions generate fewer or more events. A low-compute variant may avoid learned completion or reinforcement learning and rely on heuristic policies that clamp thinning probabilities based on simple measurements such as link fill, IMU motion, or ambient brightness. A minimal hardware variant may replace dual radios with a single transceiver, or replace wireless links with USB or UART, while preserving the logical split between reflex-critical payloads and bulk payloads using time-multiplexing. These fallback implementations may be used to reduce cost, weight, or complexity and remain within the scope of the claimed behaviors because they maintain the core principle that first and second regions of an event sensor are handled at different fidelities and routed or consumed accordingly. Itemized list of embodiments suitable for continuations. Embodiments can be described by the following itemized list so that each feature is explicitly supported for use in present claims and in future continuation claims. Item 1: a sensor that comprises an event sensor array, a processing unit, and a first transmitting unit, the array including at least a first region and a second region, where the processing unit applies different filtering or processing levels per region such that, for comparable event generation, more data derived from the first region is transmitted through the first transmitting unit than from the second region. Item 2: the filtering may comprise probabilistic thinning where events from the second region are transmitted with a lower probability than events from the first region. Item 3: the first region may be a movable window configured to pass all or substantially all events within the window, the window being movable within a bounded region of interest to generate saccade-like bursts of higher-density data. Item 4: at least one portion of the event sensor array, or an associated lens, or a portion of the optical path may include a spectral filter so that events generated from light passing through that filter are spectrally discriminated. Item 5: at least one mirror may be arranged to deliver light from a scene point along two optical paths to the array, thereby producing stereo disparity. Item 6: a second transmitting unit may transmit a less-filtered or unfiltered stream at higher bandwidth in parallel with the first transmitting unit. Item 7: the processing unit may transmit clustered or grouped representations from at least one region instead of individual events. Item 8: the definition, location, and filtering characteristics of regions may be dynamically adjustable in response to instructions from a remote computing unit. Item 9: the first transmitting unit may be a low-latency, bandwidth-limited wireless link while the second transmitting unit is a higher-latency, higher-bandwidth wireless link, the two links operating concurrently. Item 10: filtering or processing aggressiveness may vary continuously as a function of location on the array so that event transmission probability changes smoothly across at least part of the field. Item 11: spectral filters may comprise at least one of narrowband visible, near-infrared, ultraviolet, or polarization filters. Item 12: the stereo optics may comprise a first mirror above and a second mirror below the array to establish multiple disparity baselines. Item 13: the processing unit may select disjoint payloads for the low-latency and the higher-bandwidth links based on latency and bandwidth constraints. Item 14: the movable window may follow raster or attention-driven trajectories and its size, position, and speed may be updated pursuant to remote control instructions. Item 15: transmitted event data may be tagged with timestamps and at least one of inertial measurements, yaw state, or current configuration metadata. Item 16: clustered or grouped outputs may comprise at least one of cluster centroids, event-count histograms, or time-surface summaries. Item 17: selection of filtering levels and region definitions may be determined by a policy that respects bandwidth and latency budgets, the policy being implemented by heuristics or reinforcement-learned controllers. Item 18: an optical deflector, including a mirror or other redirecting element, may oscillate or tilt to induce relative scene motion at the sensor to stimulate event generation. Item 19: spectral filters may be arranged as horizontal and vertical strips across the aperture to produce temporally coherent spectral responses during forward motion and yaw scanning of a carrier platform. Item 20: an interface to a remote computing unit may be configured to fuse data received over the low-latency and higher-latency links to maintain at least one of a time-surface map, a stereo disparity estimate, or a global state estimate. Item 21: active illumination modulation may be used to generate events from static scenes by strobing or flickering light sources or by moving or rotating color filters. Item 22: stereo disparity may alternatively be produced by prisms, beam splitters, or lenslets that form dual optical paths without external mirrors. Item 23: spectral filtering may be implemented with switchable elements such as liquid crystal or electrochromic filters to permit runtime selection of passbands. Item 24: the higher-bandwidth link may be wired or wireless and may include Ethernet, USB, or other interfaces while the low-latency link may include sub-GHz or 2.4 GHz radios configured for minimized airtime. Item 25: the sensor may synthesize intensity frames from events for compatibility with frame-based consumers while maintaining a native event-based control loop. Item 26: usage accounting and entitlement enforcement may be implemented as secure, monotonic counters with signed reports, license tokens, and feature flags enabling subscription or usage-based monetization without degrading the reflex path. Item 27: the system may operate with no mirrors (monocular), one mirror (single-baseline stereo), or multiple mirrors (multi-baseline) while preserving region-based filtering. Item 28: external observability may be provided by exposing headers, timestamps, configuration tags, and link identifiers in transmitted streams so that compliance with claimed behaviors is verifiable through inputs and outputs alone. Item 29: fallback modes may disable spectral filtering, stereo, or saccades while retaining differential regional filtering so that the inventive concept remains embodied under reduced capability. Item 30: interoperability may be preserved by abstracting link interfaces so that multiple radio protocols, network stacks, and message formats can carry the defined payloads without departing from the claimed behaviors. Item 31: differential information density may be achieved by adjusting per-pixel or per-region event-generation parameters, including threshold, bias current, refractory period, or comparator hysteresis, so that fewer or more events are generated in designated regions without relying solely on post-generation filtering. Item 32: region-based differential treatment may be applied and consumed entirely on-device to drive local control loops, logging, or actuation without transmitting any event data off-device, the inventive behavior being independent of the presence of a transmitting unit. Item 33: a method of operating an event-based sensor may comprise defining first and second regions, applying different levels of filtering, processing, or event-generation thresholds to the regions, and differentially consuming, storing, or transmitting the resulting data according to task constraints. Item 34: a non-transitory computer-readable medium may store instructions that configure region definitions and cause region-differentiated handling of events with or without any network transmission, including purely local consumption. Item 35: region definitions may comprise non-rectangular masks, superpixel lattices, sparse per-pixel masks, or time-varying probability fields that are disjoint or overlapping, with saccades selecting subsets of such masks over time. Item 36: regional differentiation may be accomplished upstream of the sensor using analog or optical means, including graded neutral-density or apodized filters, variable polarization films, or spatial light modulators that modulate incoming flux to achieve differing information densities across the field. Item 37: outputs produced under region-differentiated operation may be written to a local tamper-evident log or circular buffer and retrieved asynchronously over any interface, decoupling the inventive sensing behavior from contemporaneous transmission. Item 38: logical regions may be defined across multiple physical event sensor arrays that are treated as a single virtual array, with differential handling applied to first and second logical regions regardless of their distribution across sensors. Item 39: regions may be defined in an attribute space of events rather than solely in contiguous image-space, including regions defined by at least one of motion-vector estimates, polarity, timestamp bands, or saliency or detector scores, with events mapped back to array coordinates for handling. Item 40: region formation may be content-adaptive and learned, driven by detector or tracker outputs, uncertainty maps, or saliency networks, with continuous-time updates that alter which subsets of events are handled at higher or lower fidelity. Item 41: per-event scoring or gating that yields two or more classes, each class handled at different fidelity levels, may be treated as defining first and second regions of the array for the purposes of differential handling, irrespective of contiguity. Item 42: a sensor that comprises an event sensor array and a processing unit, wherein first and second regions are logical subsets of events defined spatially on the array and/or by at least one criterion applied to events or pixels, the subsets need not be contiguous or static, and wherein the processing unit applies different levels of filtering, processing, or event-generation thresholds to the regions such that, for comparable scene excitation, a greater amount of data derived from the first region is handled by at least one of local consumption, storage, or transmission than from the second region. Item 43: the sensor of Item 42, wherein the filtering comprises probabilistic thinning such that events generated in the second region are transmitted with a lower probability than events generated in the first region. Item 44: the sensor of Item 42, wherein the first region comprises a movable window configured to transmit all or substantially all events within the window, the window being movable within a bounded region of interest to provide saccade-like bursts of higher-density event data. Item 45: the sensor of Item 42, wherein at least one portion of the event sensor array, or an associated lens, or an intermediate portion of the optical path, is provided with a spectral filter such that events generated from light passing through that filter are spectrally discriminated. Item 46: the sensor of Item 42, further comprising at least one mirror arranged such that light from a point in a scene is received by the event sensor array along two optical paths, thereby producing stereo disparity information. Item 47: the sensor of Item 42, further comprising a first transmitting unit and a second transmitting unit configured to operate in parallel, wherein the second transmitting unit transmits a less-filtered or unfiltered event stream at higher bandwidth than the first transmitting unit. Item 48: the sensor of Item 42, wherein the processing unit is configured to transmit clustered or grouped events from at least one of the regions instead of individual events. Item 49: the sensor of Item 42, wherein the definition, location, or filtering characteristics of the first and second regions are dynamically adjustable in response to control instructions from a remote computing unit. Item 50: the sensor of Item 47, wherein the first transmitting unit comprises a low-latency, bandwidth-limited wireless link and the second transmitting unit comprises a higher-latency, higher-bandwidth wireless link. Item 51: the sensor of Item 42, wherein the different levels of filtering or processing vary continuously across at least part of the event sensor array such that an event transmission probability or processing aggressiveness changes as a function of location. Item 52: the sensor of Item 45, wherein the spectral filter comprises at least one of a narrowband visible filter, a near-infrared filter, an ultraviolet filter, or a polarization filter. Item 53: a method of operating an event-based sensor system comprising an event sensor array and a processing unit, the method comprising defining at least a first region and a second region as logical subsets of events defined spatially on the array and/or by at least one criterion applied to events or pixels, the subsets need not be contiguous or static, applying, by the processing unit, different levels of filtering, processing, or event-generation thresholds to events associated with the first and second regions, and differentially handling the resulting data by at least one of locally consuming, storing, or transmitting the data such that, for comparable scene excitation, a greater amount of data derived from the first region is handled than from the second region. Item 54: the method of Item 53, wherein the filtering comprises probabilistic thinning such that events generated in the second region are transmitted with a lower probability than events generated in the first region. Item 55: the method of Item 53, further comprising moving a window within a bounded region of interest to transmit all or substantially all events within the window and to provide saccade-like bursts of higher-density event data. Item 56: a non-transitory computer-readable medium storing instructions that, when executed by a processing unit of an event sensor system comprising an event sensor array, cause the processing unit to perform the method of Item 53. Item 57: the non-transitory computer-readable medium of Item 56, wherein the instructions further cause tagging of transmitted event data with timestamps and at least one of inertial measurement data, yaw state, or current configuration metadata. Item 58: the sensor of Item 44, wherein the movable window follows a raster or attention-driven trajectory and its size, position, and speed are updated in response to control instructions from a remote computing unit. Item 59: the sensor of Item 42, wherein selection of filtering levels or region definitions is determined by a policy configured to respect bandwidth and latency budgets, the policy being implemented by at least one of a heuristic rule set or a reinforcement-learned controller. Item 60: the sensor of Item 42, further comprising an optical deflector configured to oscillate or tilt to induce relative motion of the scene at the event sensor array so as to stimulate event generation, the optical deflector comprising a mirror or other redirecting element. Item 61: the sensor of Item 50, further comprising an interface to a remote computing unit configured to fuse data received over the low-latency link and the higher-latency link to maintain at least one of a time-surface map, a stereo disparity estimate, or a global state estimate.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A sensor comprising:
an event sensor array; and
a processing unit, the event sensor array including a first region and a second region, wherein each of the first region and the second region is a logical subset of events associated with the array defined spatially on the array and/or by at least one criterion applied to events or pixels, the subsets need not be contiguous or static; and
wherein the processing unit is configured to apply different levels of filtering, processing, or event-generation thresholds to events associated with the first region and the second region such that, for comparable scene excitation, a greater amount of data derived from the first region is handled by at least one of local consumption, storage, or transmission than from the second region.
   2.

The sensor of item 1, wherein the filtering comprises probabilistic thinning such that events generated in the second region are transmitted with a lower probability than events generated in the first region.

3.

The sensor of item 1, wherein the first region comprises a movable window configured to transmit all or substantially all events within the window, the window being movable within a bounded region of interest so as to provide saccade-like bursts of higher-density event data.

4.

The sensor of item 1, wherein at least one portion of the event sensor array, or an associated lens, or an intermediate portion of the optical path, is provided with a spectral filter such that events generated from light passing through that filter are spectrally discriminated.

5.

The sensor of item 1, further comprising at least one mirror arranged such that light from a point in a scene is received by the event sensor array along two optical paths, thereby producing stereo disparity information.

6.

The sensor of item 1, further comprising a first transmitting unit and a second transmitting unit configured to operate in parallel, wherein the second transmitting unit transmits a less-filtered or unfiltered event stream at higher bandwidth than the first transmitting unit.

7.

The sensor of item 1, wherein the processing unit is configured to transmit clustered or grouped events from at least one of the regions instead of individual events.

8.

The sensor of item 1, wherein the definition, location, or filtering characteristics of the first and second regions are dynamically adjustable in response to control instructions from a remote computing unit.

9.

The sensor of item 6, wherein the first transmitting unit comprises a low-latency, bandwidth-limited wireless link and the second transmitting unit comprises a higher-latency, higher-bandwidth wireless link.

10.

The sensor of item 1, wherein the different levels of filtering or processing vary continuously across at least part of the event sensor array such that an event transmission probability or processing aggressiveness changes as a function of location.

11.

The sensor of item 4, wherein the spectral filter comprises at least one of a narrowband visible filter, a near-infrared filter, an ultraviolet filter, or a polarization filter.

12.

A method of operating an event-based sensor system comprising an event sensor array and a processing unit, the method comprising:
defining on or for the event sensor array at least a first region and a second region, each being a logical subset of events defined spatially on the array and/or by at least one criterion applied to events or pixels, the subsets need not be contiguous or static;
applying, by the processing unit, different levels of filtering, processing, or event-generation thresholds to events associated with the first region and the second region; and
differentially handling the resulting data by at least one of locally consuming the data, storing the data, or transmitting the data through a transmitting unit, such that, for comparable scene excitation, a greater amount of data derived from the first region is handled than from the second region.
   13.

The method of item 12, wherein the filtering comprises probabilistic thinning such that events generated in the second region are transmitted with a lower probability than events generated in the first region.

14.

The method of item 12, further comprising moving a window within a bounded region of interest to transmit all or substantially all events within the window and to provide saccade-like bursts of higher-density event data.

15.

A non-transitory computer-readable medium storing instructions that, when executed by a processing unit of an event sensor system comprising an event sensor array, cause the processing unit to perform the method of item 12.

16.

The non-transitory computer-readable medium of item 15, wherein the instructions further cause tagging of transmitted event data with timestamps and at least one of inertial measurement data, yaw state, or current configuration metadata.

17.

The sensor of item 3, wherein the movable window follows a raster or attention-driven trajectory and its size, position, and speed are updated in response to control instructions from a remote computing unit.

18.

The sensor of item 1, wherein selection of filtering levels or region definitions is determined by a policy configured to respect bandwidth and latency budgets, the policy being implemented by at least one of a heuristic rule set or a reinforcement-learned controller.

19.

The sensor of item 1, further comprising an optical deflector configured to oscillate or tilt to induce relative motion of the scene at the event sensor array so as to stimulate event generation, the optical deflector comprising a mirror or other redirecting element.

20.

The sensor of item 9, further comprising an interface to a remote computing unit configured to fuse data received over the low-latency link and the higher-latency link to maintain at least one of a time-surface map, a stereo disparity estimate, or a global state estimate.

### Embodiment AT: Bee Hive Protection Apparatus with Automated Insect Detection and Neutralization

A bee hive protection apparatus is disclosed. The apparatus may comprise a camera arranged to capture images of insects near a hive entrance, a processor configured to classify insects based on the captured images, and a neutralizer controlled by the processor to act selectively against hornets. The hive entrance may be bordered by electrodes positioned above and below, wherein a high-voltage module could energize the electrodes to deliver a localized discharge when a hornet is detected. In some embodiments, the electrodes may be divided into independently selectable zones, and a selector such as a servo-driven conductor arm or an electronic switching device may route the high voltage to the appropriate zone. Alternative embodiments may employ mechanical neutralization means such as a striking or squeezing actuator, or an optical laser beam directed toward the target insect. The system may be provided as an add-on module for existing hives, as an integrated hive with protection built in, or as a construction kit. In further variations, image analysis may be performed remotely, with control commands transmitted back to the apparatus, or a single camera may be used to monitor multiple hive entrances.

### Background

Beekeeping is an important agricultural activity that contributes to pollination services and the production of honey and other hive products. Managed bee colonies are increasingly exposed to threats from invasive predators, among which hornets such as Vespa velutina are of particular concern.

These hornets often hover at the entrance of a hive, capturing foraging bees and disrupting normal colony activity. Persistent hornet pressure can lead to colony weakening, reduced foraging, and eventual collapse.

Conventional methods for hornet control include traps, nest destruction, and chemical treatments. Traps are often non-selective and may capture beneficial insects, while chemical methods may raise safety and environmental concerns. Nest destruction is labor-intensive and not always practical, particularly when nests are concealed or located at height. Individual beekeepers therefore face difficulty in reliably protecting hives against hornet attack.

Accordingly, there is a need for a hive-level protective system that can automatically distinguish hornets from bees and apply a targeted neutralization method at the hive entrance. Such a system would ideally reduce hornet predation pressure while limiting incidental harm to bees and avoiding broader environmental impacts.

### Detailed Description of the Figures

FIG. 1A illustrates a bee hive (2) provided with an add-on protection apparatus mounted adjacent to its entrance.

FIG. 1B shows an enlarged view of the add-on apparatus positioned at the hive entrance.

FIG. 1C is a cutaway view of the add-on apparatus, revealing internal components.

FIG. 1D presents an exploded view of the add-on apparatus, showing the principal elements in separated form.

FIG. 1E depicts a top-down view of the apparatus with the cover (7) removed

FIG. 1F shows the apparatus in isolation as a standalone unit, apart from the hive.

In one embodiment, a bee hive protection apparatus may be configured as a module that could be positioned adjacent to the entrance slot of a hive. The module may comprise a camera that could be mounted approximately forty centimeters above the entrance and would provide a generally downward-facing field of view. In this orientation, the camera may be capable of capturing insects that cross the entrance horizontally, and the apparent body length and morphology of each insect could be extracted as features that would allow the control system to distinguish hornets from bees. The control system may be further configured to process the captured images and could apply a classification algorithm that may identify insects exceeding a certain apparent length as likely hornets.

The hive entrance itself may be flanked by an upper conductor and a lower conductor that could each carry electrode segments divided into independently isolated zones. These electrode zones may be configured so that only a single zone or a subset of zones would be energized at a given time. When the control system identifies a hornet within a portion of the entrance, the corresponding electrode zone may be selected and could be energized to create a brief, current-limited high-voltage discharge across the upper and lower conductors. This localized actuation could serve to neutralize the hornet at its position, while leaving other parts of the entrance unpowered.

Zone selection may be achieved by a servo-driven rotary selector that could comprise an insulating disk fitted with a conductive segment. The disk may be rotated by a servo motor until the conductive segment aligns with one of a plurality of fixed terminals, each terminal corresponding to an electrode zone. In another variation, the selector may not require physical contact but instead could use a tungsten or silver-tungsten electrode tip that would establish a discharge across a controlled air gap to the chosen zone terminal when the high-voltage source is enabled. In either approach, the control system could disable the high-voltage source while the selector is in motion and may only re-enable the source once a docked position has been confirmed. Each zone may be provided with a series ballast resistor that could limit discharge current and energy, and unselected zones may include bleeder resistors that would allow them to discharge when idle.

The operational sequence could proceed as follows. In an idle state, the high-voltage source may remain disabled and the servo would be at its most recently used position. When the control system classifies an insect as a hornet, it could determine the zone index associated with the hornet's position. If this zone differs from the present selector position, the control system may command the servo to rotate to the new zone, with the high-voltage source disabled during movement. Once the selector has reached its target position and settled, the control system could verify that the hornet remains in the same zone before energizing the electrodes. A short burst of high voltage may then be applied, possibly as one or more pulses of limited duration. After each burst, the control system could reassess the presence of the hornet and would either repeat the procedure or return to idle if the target has been neutralized or has left.

In practice, the use of a top-down camera may provide a simple yet reliable means of distinguishing hornets from bees, since hornets could appear longer and bulkier in the image frame. The zoning approach may allow localized activation, which could reduce overall power consumption and may limit incidental bee loss to a level that would not endanger the colony. The servo-driven selector could provide a simple and economical solution for routing high voltage to the appropriate zone, particularly since the repositioning time may be on the order of seconds rather than milliseconds. The arrangement of electrodes above and below the entrance slot may take advantage of the fact that hornets could be larger than the slot width and may tend to hover or cling near the entrance, thus positioning themselves directly in the discharge field.

Accordingly, the apparatus could represent a practical hive protection system that may combine species-specific detection with targeted neutralization. The modular form factor may allow it to be retrofitted to existing hives or integrated into new hives, and the system may be configured so that incidental bee electrocution could be tolerated while overall hornet pressure on the hive would be reduced.

### Detailed Description of the Invention

### Anchor Begin

### Omission of Conventional Components

For clarity of illustration, certain conventional elements such as nuts, bolts, fasteners, electrical wiring, and other routine hardware are not shown, or are only partially shown, in the accompanying figures. These features are considered obvious to a person skilled in the art and may be implemented in any suitable manner. Their omission avoids unnecessary detail and allows the drawings to focus on the inventive aspects of the apparatus.

In FIGS. 1A to 1F the following elements are shown:
1. hornet or other insect
2. Bee hive
3. Entry slot in base plate
4. Base plate
5. Selectable electrode
6. None-selectable electrode
7. Cover
8. Camera sensor and lens
9. processor
10. High voltage module
11. Servo or actuator
12. Selection arm with conductor

The bee hive (2) has an entry slot (3) formed in a base plate (4). A selectable electrode (5) is positioned above the slot and a non-selectable electrode (6) below. A cover (7) encloses a camera sensor and lens (8) linked to a processor (9). The processor (9) drives a high-voltage module (10), one output fixed to the non-selectable electrode (6), the other routed through a servo or actuator (11). The servo (11) positions a selection arm with conductor (12) to connect the voltage to a chosen segment of the selectable electrode (5). Thus the computing unit (9) may energize the appropriate electrode zone when a hornet (1) is detected at the entrance. The hornet (1) is shown to show the apparatus in context.

### Alternative Configurations

In another embodiment, the camera (8) may transmit its captured images to a remote processor or server rather than performing classification locally. The remote processor may analyze the images and transmit control commands back to a receiver in the apparatus, which could then actuate the servo (11) and high-voltage module (10). This arrangement may reduce unit cost by allowing a single computation resource to be shared across multiple protection modules.

In a further variation, a single camera (8) may be arranged so that its field of view covers multiple entry slots (3) associated with multiple bee hives (2). The shared camera could thereby monitor several hives simultaneously and direct neutralization commands to each corresponding apparatus. This configuration may again lower overall cost by reducing the number of cameras required.

### Alternative Embodiments for Switching

Alternative embodiments may employ different means for directing or switching the conductive path between the high-voltage module (10) and the selectable electrode (5). Instead of using a servo or actuator (11) to move a selection arm (12), the apparatus could incorporate solid-state components such as MOSFETs or IGBTs configured to withstand the applied voltage and selectively energize electrode zones. In another variation, electromagnetic devices such as relays or solenoids could be arranged to route the high-voltage output to the desired contact. Additional techniques, including gas-discharge switches, rotary spark gaps, or plasma-based steering elements, may also be employed to establish or interrupt the electron stream. The control unit (9) may be configured to coordinate activation of any such switching means in response to hornet detection, provided that isolation and current-limiting features are maintained to ensure reliable operation.

### Embodiment Variations

The invention may be realized in different product forms. In one embodiment, the system may be provided as a bee hive add-on, configured to be mounted onto an existing hive and to protect the colony without requiring modification of the hive body. In another embodiment, the protection system may be integrated directly into a bee hive during manufacture, so that the hive and the neutralization apparatus form a unified structure. In a further embodiment, the invention may be supplied as a construction kit comprising parts and instructions, allowing a user to assemble a hive together with the protection system.

### Alternative Embodiments

Alternative embodiments may vary the physical arrangement and means of neutralization. In one configuration, the selectable electrode (5) may be placed on the bottom of the entry slot (3) with the non-selectable electrode (6) positioned above, or the polarity of the electrodes may be reversed while retaining the same functional effect. In another embodiment, the electrodes may not be divided into selectable sections, and the entire electrode length could be energized when activation is required.

Mechanical means may also be employed instead of electrical discharge. For example, a servo-driven arm could swing to strike or pierce the hornet (1) as it approaches the hive entrance, or an actuator could reduce the spacing between two elements so that the hornet is squeezed, crushed, or pierced. In yet another variation, an optical approach could be adopted, in which the hornet is neutralized by a directed laser beam.

### Alternative Detection Methods

Detection of a hornet (1) or other insect may be achieved through analysis of images captured by the camera (8). In alternative embodiments, detection may instead be performed by electrical sensing at the hive entrance (3). For example, the presence of a relatively large insect body may alter conduction or capacitance across the slot. One set of conductive elements may be positioned on one side of the entry slot (3) and another set on the opposite side, so that when an insect bridges the gap, a measurable change in conductivity or capacitance occurs. Such a change may be interpreted by the processor (9) as an indication of insect presence and size, thereby allowing discrimination between bees and larger insects such as hornets.

### Base Plate Construction

The base plate (4) may be fabricated from a variety of materials, including plastic, wood, or a combination thereof. The electrical paths for the electrodes may be realized by metallic conductors, such as copper, which may be applied on the surface of the base plate, embedded within the plate, or otherwise integrated by conventional methods. In another embodiment, the base plate (4) may be produced by additive manufacturing, wherein two different filaments are employed during the printing process: a conductive filament forming the electrode paths, and a non-conductive filament forming the insulating structural portions. This approach may enable the base plate to be manufactured as a single integrated component with both mechanical and electrical functionality.

### Main Flow

In operation, the apparatus may follow a two-stage process. First, the camera (8) in combination with the processor (9) may detect and classify an insect at or near the hive entrance (3). If the extracted features correspond to a hornet (1), the target may be confirmed. Second, upon confirmation of a hornet or other harmful insect, the processor (9) may command the neutralizer-whether by initiating an electrode discharge between the selectable electrode (5) and the non-selectable electrode (6), actuating a mechanical striking or squeezing element, or directing an optical laser system-to engage and neutralize the target.

In another embodiment, the apparatus may follow a two-stage process with computation performed externally. First, the camera (8) may capture images of insects at or near the hive entrance (3) and transmit the images to a remote processor or server. The remote processor may analyze the images, classify the insect, and return a control signal to the local apparatus. If the features correspond to a hornet (1), the signal may confirm the target. Second, upon receiving the control signal, the local processor (9) or receiver may command the neutralizer-whether an electrode discharge between the selectable electrode (5) and non-selectable electrode (6), a mechanical striking or squeezing element, or an optical laser system-to engage and neutralize the hornet at the hive entrance (3).

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A bee hive protection apparatus, comprising:
a base plate defining an entry slot;
a selectable electrode positioned on one side of the entry slot and a non-selectable electrode positioned on the opposite side;
a camera configured to capture images of insects near the entry slot;
a processor configured to classify insects in the captured images and to identify hornets; and
a neutralizer controlled by the processor, wherein the neutralizer is actuated upon detection of a hornet at the hive entrance.
   2.

The apparatus of item 1, wherein the selectable electrode is divided into independently energizable sections, and the processor is configured to energize only the section corresponding to the detected hornet.

3.

The apparatus of item 2, wherein a servo or actuator drives a selection arm with conductor to route a high-voltage output from a high-voltage module to the appropriate electrode section.

4.

The apparatus of item 3, wherein the processor disables the high-voltage module while the selection arm is in motion, and re-enables the module upon confirmation of a settled position.

5.

The apparatus of item 1, wherein the processor is located remotely, and the camera transmits captured images to the remote processor, which returns control commands to the local apparatus.

6.

The apparatus of item 5, wherein a single remote processor serves a plurality of bee hives each having a corresponding protection apparatus.

7.

The apparatus of item 1, wherein a single camera is arranged to monitor multiple entry slots of multiple bee hives.

8.

The apparatus of item 1, wherein alternative switching means are employed to direct high voltage to an electrode section, the switching means selected from: MOSFETs, IGBTs, relays, solenoids, gas-discharge switches, rotary spark gaps, or plasma steering elements.

9.

The apparatus of item 1, wherein the neutralizer comprises a mechanical striking arm actuated to impact, pierce, or crush the hornet.

10.

The apparatus of item 9, wherein the neutralizer comprises a squeezing mechanism in which an actuator reduces the spacing between two elements to immobilize and kill the hornet.

11.

The apparatus of item 1, wherein the neutralizer comprises an optical laser system directed at the hornet.

12.

The apparatus of item 1, wherein detection of the hornet is based on conduction or capacitance change measured across the entry slot when an insect body bridges conductive elements on opposite sides of the slot.

13.

The apparatus of item 1, wherein the base plate is fabricated from plastic, wood, or a combination thereof.

14.

The apparatus of item 1, wherein the electrode paths are realized by metallic conductors applied on or embedded in the base plate.

15.

The apparatus of item 1, wherein the base plate is produced by additive manufacturing using both conductive and non-conductive filaments.

16.

The apparatus of item 1, wherein the selectable electrode is positioned below the entry slot and the non-selectable electrode above.

17.

The apparatus of item 1, wherein the polarity of the electrodes is reversed relative to their nominal configuration.

18.

The apparatus of item 1, wherein the system is embodied as an add-on module configured to be attached to an existing bee hive.

19.

The apparatus of item 1, wherein the system is integrated into a bee hive during manufacture, such that the hive and the protection system form a unified structure.

20.

The apparatus of item 1, wherein the system is supplied as a construction kit comprising components and instructions enabling a user to assemble the hive and protection system.

21.

A method of protecting a bee hive, comprising:
capturing, with a camera, images of insects at or near a hive entrance;
classifying the insects using a processor; and
upon detecting a hornet, actuating a neutralizer to neutralize the hornet at the hive entrance.
   22.

The method of item 21, wherein actuating the neutralizer comprises energizing a selectable electrode positioned opposite a non-selectable electrode to create a localized discharge field.

23.

The method of item 22, further comprising selecting an electrode zone corresponding to the hornet's position by moving a selection arm with conductor driven by a servo or actuator.

24.

The method of item 23, wherein the processor disables a high-voltage module while the selection arm is in motion and re-enables the high-voltage module upon reaching a settled position.

25.

The method of item 21, further comprising transmitting the images from the camera to a remote processor, classifying the insect remotely, and receiving control commands from the remote processor to actuate the neutralizer.

26.

The method of item 25, wherein a single remote processor performs classification for multiple hive entrances associated with multiple bee hives.

27.

The method of item 21, wherein detecting a hornet further comprises measuring conduction or capacitance change across the hive entrance caused by the body of the insect bridging conductive elements on opposite sides of the slot.

28.

The method of item 21, wherein actuating the neutralizer comprises striking, piercing, or squeezing the hornet using a mechanical element driven by a servo or actuator.

29.

The method of item 21, wherein actuating the neutralizer comprises directing an optical laser beam onto the hornet.

30.

The method of item 21, wherein the bee hive protection system is implemented as one of: an add-on module fitted to an existing hive, an integrated hive with built-in protection, or a construction kit assembled by a user.
Embodiment. AC Articulated Hollow Robotic Arm

### Background

Robotic manipulators are often designed as rigid linkages with joints driven by motors placed at or near each articulation point. While such arrangements provide precise actuation, they introduce significant mass at distal joints, increase complexity, and limit the ability to route hollow channels through the arm. In many applications, however, it is desirable to maintain a continuous hollow conduit along the arm structure, for example to carry suction, air, or fluid to a distal end effector. Conventional robotic arms typically fail to combine lightweight articulation with a clear internal pathway.

Cable-driven tendon actuation offers weight savings by allowing all drive motors to be located proximally, but such designs are challenging to implement in a way that preserves cable length independence when multiple joints are actuated simultaneously. Furthermore, when a hollow channel is required, conventional solutions often compromise on strength or sealing, preventing effective suction or fluid transfer.

There is therefore a need for an articulated robotic arm architecture that is lightweight, modular, and capable of supporting an arbitrary number of joints, while optionally preserving a continuous hollow interior and allowing independent actuation of each hinge.

### Summary of the Invention

The invention provides an articulated robotic arm, comprising one or more linkage segments connected by hinge joints, each joint being actuated by a tendon-like cable driven by a servo located at or near the base of the arm. The arrangement permits all actuation motors to remain proximal, while the cables are routed through iso-length cable guides configured so that rotation of one hinge does not alter the effective cable length acting upon another hinge, thereby achieving independent control of multiple degrees of freedom.

In preferred embodiments, each linkage segment is hollow, and the hinges are designed to preserve a continuous interior channel along the length of the arm. This hollow pathway may be used to route suction, airflow, liquid, or other utilities to a distal end effector. The hollow design is advantageous for vacuum cleaning, spraying, or inspection tasks; however, it is not strictly required. In some embodiments, the arm may be used with end effectors that do not require internal routing, in which case the linkage segments may be solid, lightweight structures that retain the same articulated, cable-actuated functionality.

The hinge joints may be biased toward a rest position by elastic elements, such as springs or elastomeric bands, and may be oriented at arbitrary angular offsets relative to one another, such that successive joints bend in different planes. The result is a modular structure in which any number of hinge units may be added in sequence, each maintaining the option of a hollow or solid construction depending on the intended application.

At the proximal end, the arm may connect to a rotary base coupling, permitting torsional rotation of the entire arm relative to its mounting platform while preserving continuity of the hollow interior if present. The hollow interior, when present, may be connected via a flexible conduit to a vacuum generation module or other fluid source, thereby enabling suction-based applications.

In certain embodiments, a self-cleaning station is provided in the form of a cup or receptacle with annular bristles surrounding a central clearance. The distal end of the arm may be inserted into the receptacle and retracted, causing the bristles to sweep debris such as spider webs from the arm tip, which debris may then be collected through the suction pathway if present.

The invention is not limited to vacuum cleaning UAVs, but may be applied in any context where a lightweight articulated manipulator is advantageous, including aerial, terrestrial, or marine mobile platforms; inspection or cleaning arms; precision spraying or delivery systems; or biologically inspired robotic limbs.

### Figures

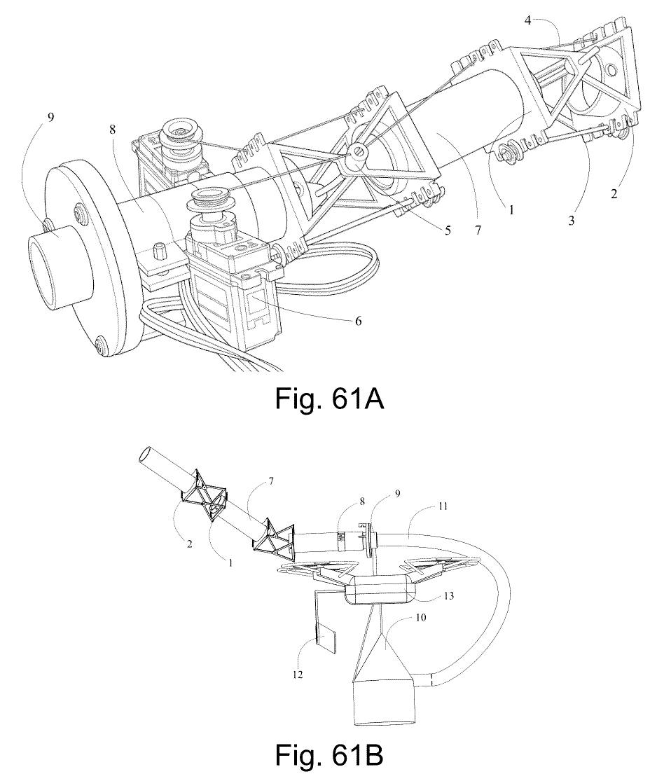

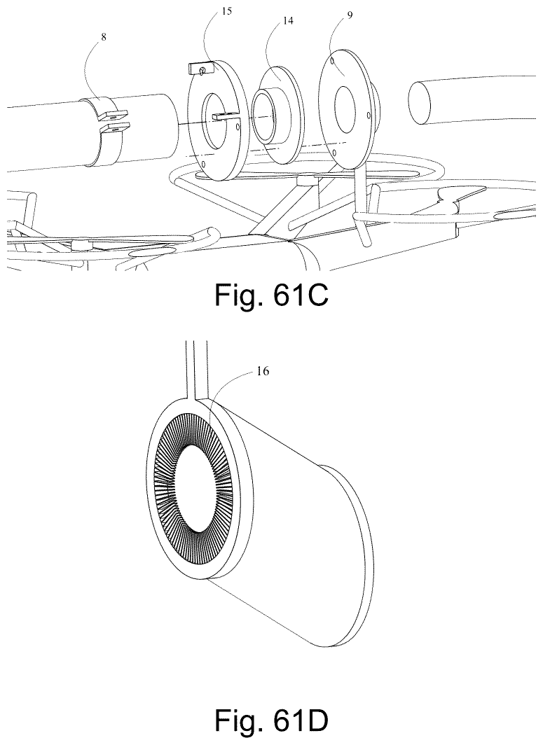

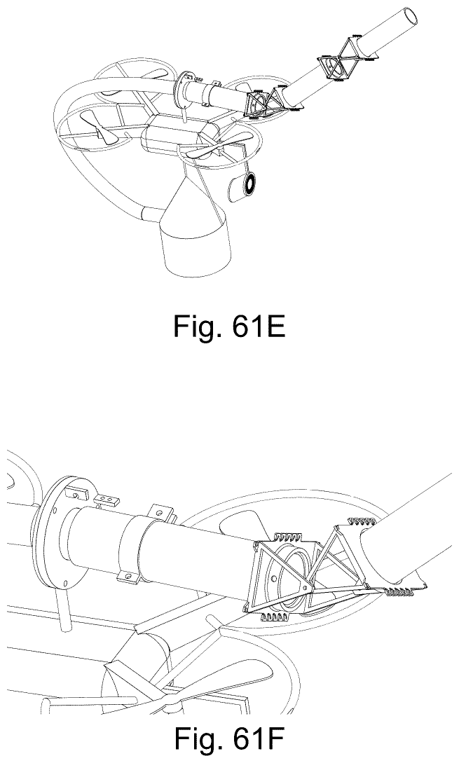

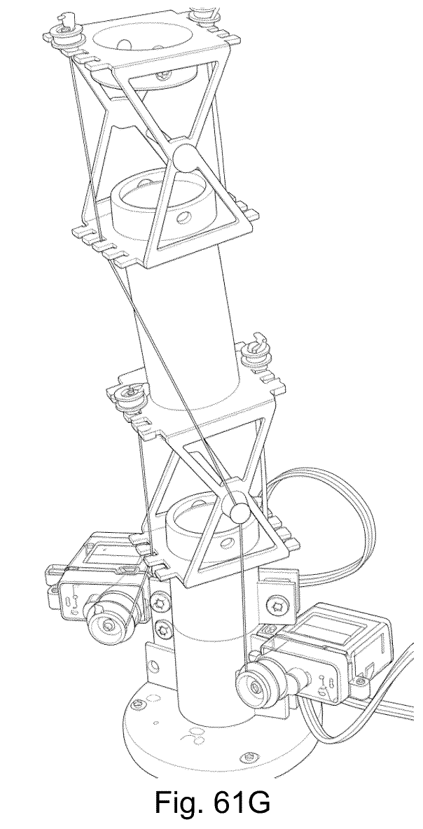

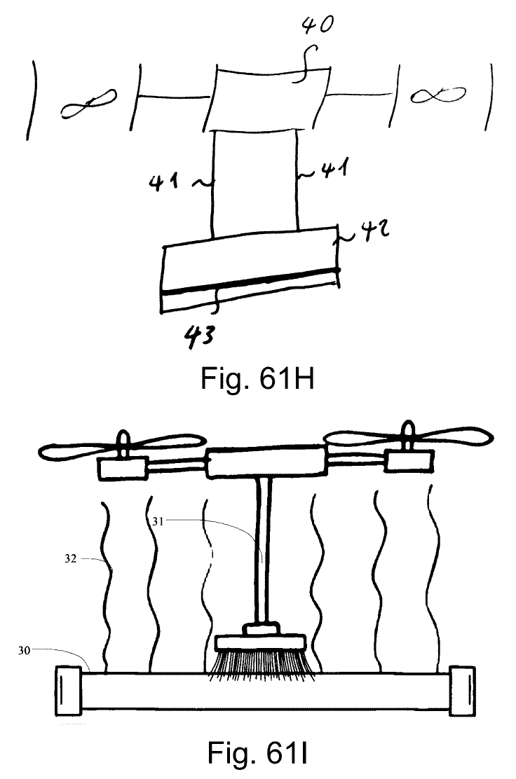

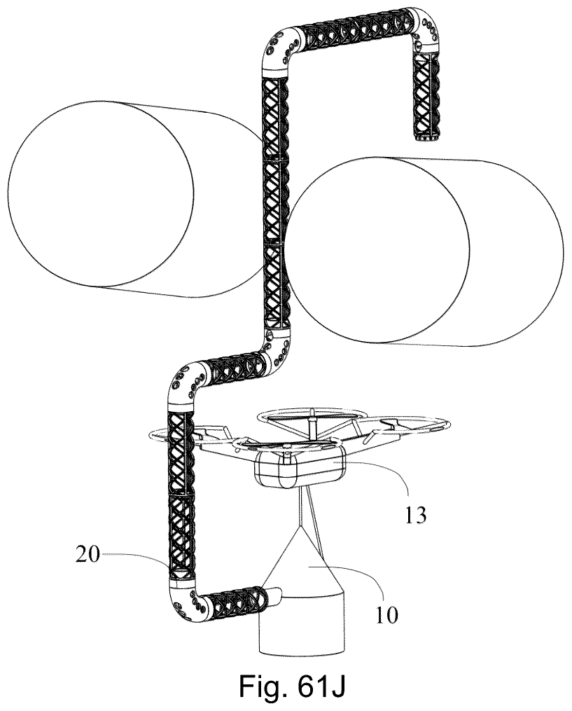

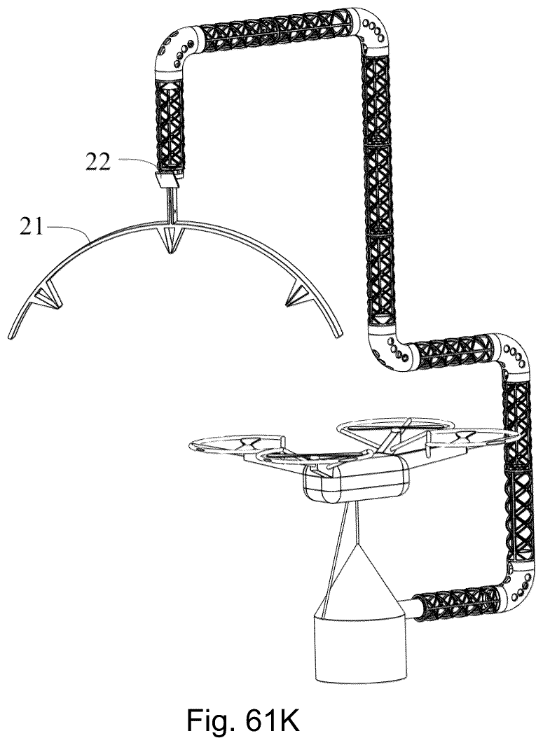

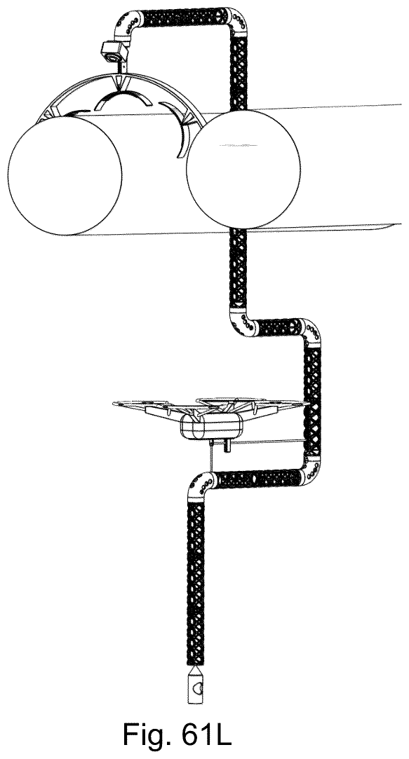

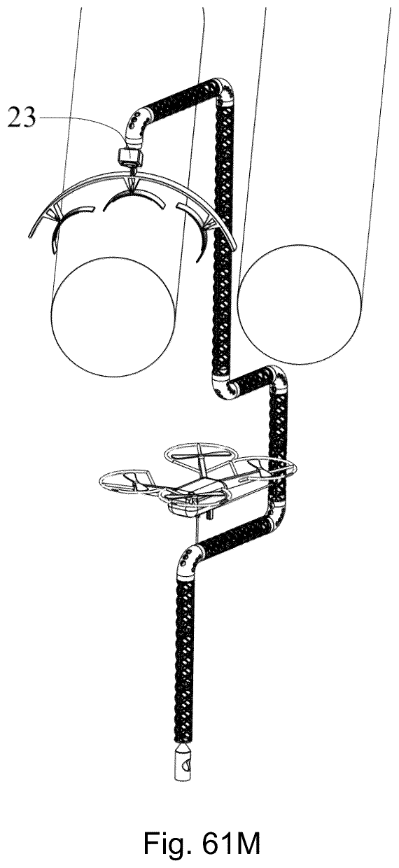

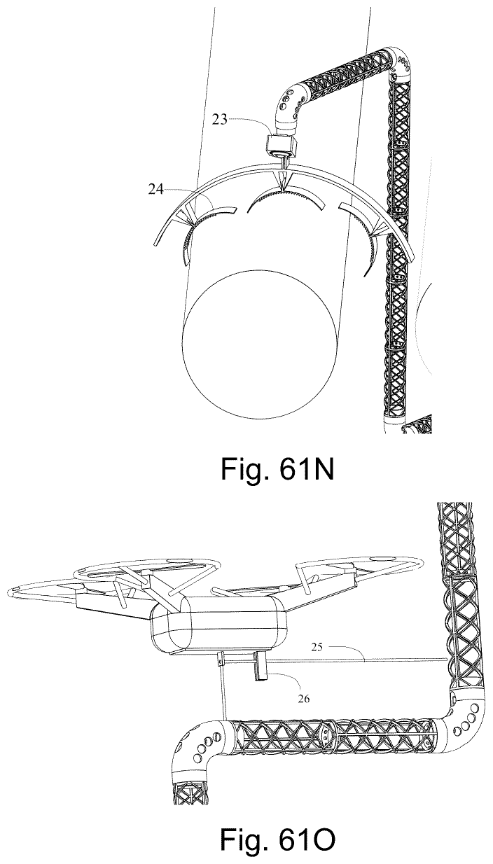

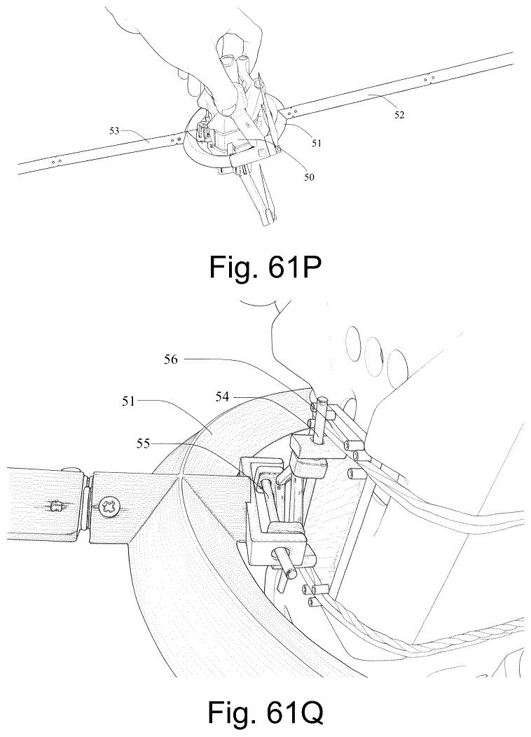

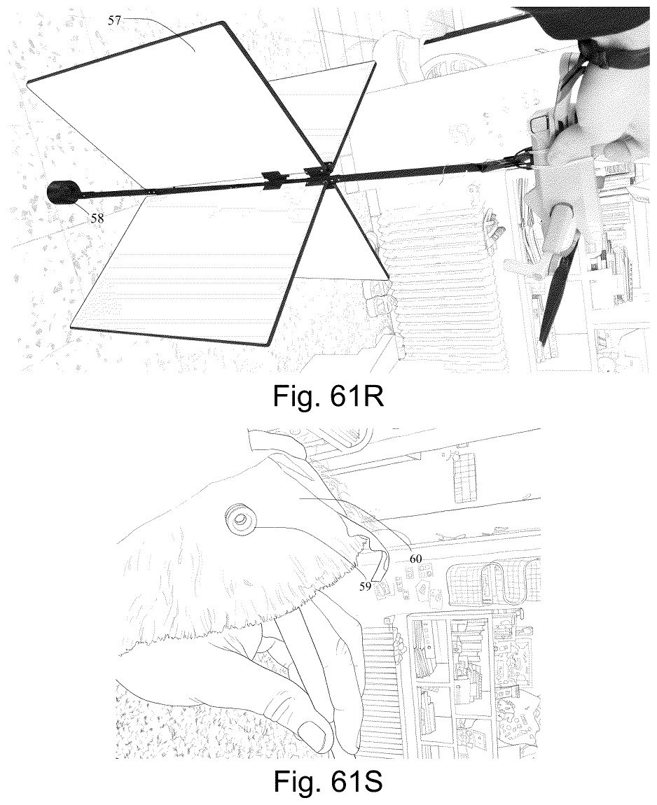

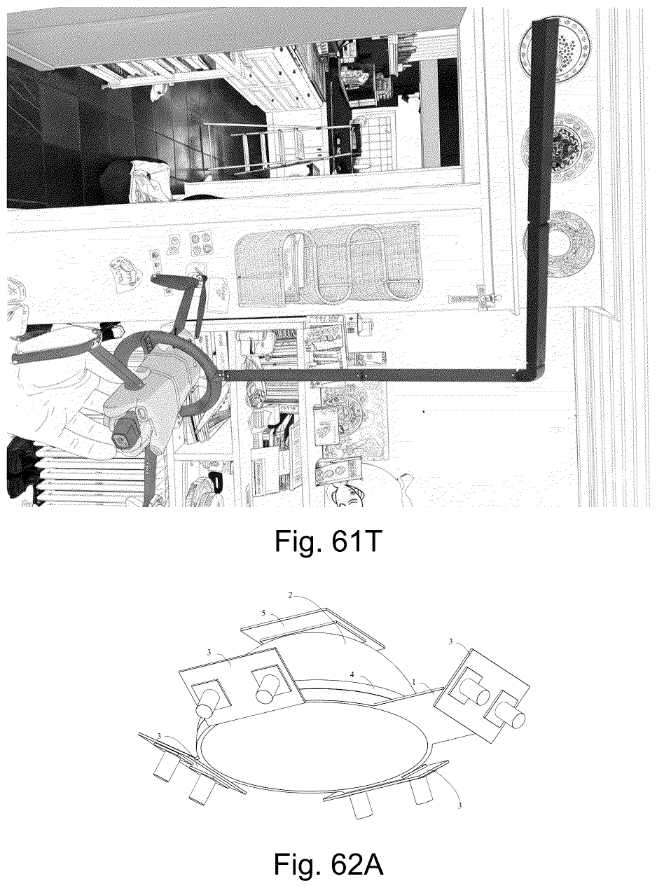

FIG. 61A shows various elements of one possible embodiment

FIG. 61B shows various elements of one possible embodiment

FIG. 61C shows various elements of one possible embodiment

FIG. 61D shows various elements of one possible embodiment

FIG. 61E shows various elements of one possible embodiment

FIG. 61F shows various elements of one possible embodiment

FIG. 61G shows various elements of one possible embodiment

### Elements

1. Lower hinge member
2. Upper hinge member
3. Elastic biasing element
4. Tendon cable (actuation cable)
5. Iso-length cable routing guide
6. Actuation servo
7. Hollow linkage segment
8. Clamp-on servo mount
9. Rotary base coupling
10. Vacuum generation module
11. Flexible conduit
12. Bristle cleaning station
13. Mobile platform
14. Inner rotary coupling member
15. Outer rotary housing
16. Distal cleaning bristles

### Embodiment Narrative

A robotic arm (1-9) is mounted to a mobile platform (13), such as a drone, and is configured to provide articulated manipulation while maintaining a continuous internal suction pathway. The arm comprises a series of hollow linkage segments (7) connected by hinges formed of lower hinge members (1) and upper hinge members (2). Each hinge is biased by an elastic biasing element (3), which tends to return the joint toward a rest position. Controlled actuation is achieved by tendon cables (4) routed across the hinges and tensioned by actuation servos (6). The tendon cables are guided by iso-length cable routing guides (5), which ensure that when a proximal hinge changes its angle, the effective cable length to distal hinges remains constant, thereby rendering hinge actuation independent.

Clamp-on servo mounts (8) may be attached to any of the hollow linkage segments (7) to provide mounting interfaces for the actuation servos (6), while leaving the tubes free to serve as continuous suction conduits. At the base of the arm, a rotary base coupling (9) enables torsional rotation of the entire arm about its axis. This coupling includes an inner rotary coupling member (14), which is fixed to the first linkage tube and rotatably supported within a surrounding housing, thereby allowing rotation without disrupting the suction path.

The arm is fluidly connected via a flexible conduit (11) to a vacuum generation module (10), which may comprise a fan, impeller, and dust collection system, either bagged or bagless. To maintain operability, a bristle cleaning station (12) may be mounted to the platform, the station comprising a cup-like structure with an annular array of bristles (16) surrounding a central clearance. The distal end of the robotic arm can be inserted into and withdrawn from the central clearance, causing the bristles to sweep away accumulated spider webs, dust, or other debris, which may then be collected by the suction flow.

In this manner, the articulated robotic arm integrates lightweight cable-driven actuation with continuous hollow suction pathways, enabling a drone or other mobile platform to function as a flying vacuum cleaner while preserving independent joint control and self-cleaning capability.

The outer rotary housing (15) is secured to the rotary base coupling (9), within which the inner rotary coupling member (14) is rotatably supported and connected to the first hollow linkage segment. The outer rotary housing provides structural support around the inner member and may include mounting features for additional components. In certain embodiments, a servo and an elastic element such as a rubber band may be attached to the outer housing, with the opposite end of the elastic element secured to a clamp on the linkage tube, thereby enabling controlled rotary motion of the arm relative to the platform while maintaining the integrity of the suction pathway.

In further variations, a spring may be positioned between each lower hinge member (1) and upper hinge member (2). When enclosed by a flexible foil or other resilient sheath, the spring both biases the hinge and defines a vacuum-sealed flexible structure, allowing the interior suction pathway to continue through the joint without leakage while preserving mobility of the articulation.

### Variable Hinge Count and Orientation

The articulated hollow robotic arm may comprise an arbitrary number of hinges, each hinge being formed by a pair of hinge members (1, 2) coupled by a rotational axis. Each hinge may be actuated by a tendon cable (4) that extends from a corresponding actuation servo (6) located at or near the base of the arm, with cable routing guides (5) ensuring that the cable length remains constant across intervening hinges. In preferred configurations, the plurality of hinges may be arranged sequentially along hollow linkage segments (7) to form a continuous suction pathway, with the total number of hinges being selectable according to the desired reach or dexterity of the arm.

Furthermore, the bending planes of successive hinges need not be aligned in a common orientation. Each hinge may be mounted with its rotational axis oriented at an arbitrary angular offset relative to neighboring hinges, such that the arm may bend in different planes at successive joints. This arrangement allows three-dimensional maneuverability comparable to biological limbs or tentacles, while preserving the central hollow channel for suction flow.

While locating all actuation servos at or near the base of the arm is generally preferred in order to minimize distal mass and preserve a continuous hollow channel through the linkage segments, the invention is not limited to this configuration. In alternative embodiments, one or more servos may be mounted directly at the hinge joints, thereby providing local actuation without the need for extended tendon cables. Such arrangements may be advantageous in cases where the hollow pathway is unnecessary, where shorter cable runs are desired, or where direct-drive precision outweighs the benefit of base-mounted weight distribution.

### Alternative Embodiments

In addition to the suction-based cleaning arm described in primary embodiments, the invention may also be realized in a number of alternative configurations adapted for cleaning pipes, ceilings, and other overhead structures. In some cases, cleaning may be achieved not by vacuum suction, but by utilizing the airflow generated by the UAV's propellers. The UAV may be flown adjacent to a pipe such that the downward propeller wash dislodges dust and debris from the pipe surface. In further variations, the UAV may carry a bristle mechanism attached to the frame or to an appendage, the bristles being configured to contact the pipe surface and scrub away stubborn dust deposits.

In still other embodiments, the distal end of the robotic arm may carry an end effector comprising a wiping cloth. The cloth may be electrostatically charged to enhance dust attraction and may be designed to be easily replaced when soiled. The cloth can be held on the end effector by a pinching mechanism, a sliding-over mechanism, or by a magnetic attachment, allowing quick interchange during operation. The electrostatic cloth may be mounted in multiples, so that several cloths can be used sequentially before replacement, thereby extending operational runtime.

The robotic arm itself may be directly coupled to the UAV frame such that its motions mirror those of the UAV body, or it may be decoupled in one or more degrees of freedom in order to improve stability. Decoupling may be achieved through suspension with ropes, through elastic band arrangements, or through dedicated hinges that selectively transmit yaw movement while isolating pitch and roll. In another variation, an active gimbal mechanism may be employed to stabilize the arm and end effector against UAV body movements, providing precise positioning relative to the cleaning target.

To further suppress oscillations, damping mechanisms may be incorporated. Such damping may be realized with rubber dampers placed between the arm and UAV body, or by attaching a drag-inducing surface, for example a planar vane or cross-shaped panel, that increases air resistance and reduces swinging motions.

In certain configurations, the arm may also be counterbalanced by a weight positioned below the UAV frame. The counterweight not only improves balance but may also house a vacuum generation unit, with suction conveyed through a conduit in the arm to the end effector, thereby integrating actuation, balance, and suction functionality in a single structure.

The end effectors and arms may be designed to be interchangeable, allowing the same UAV platform to be configured for pipe cleaning, ceiling cleaning, or roof cleaning depending on the chosen arm and end effector combination. In one case, the end effector may be rotatably adjustable to align a curved wiping cloth with the axis of a pipe, thereby maintaining effective contact across varying pipe diameters.

The UAV may be manually piloted, but in many embodiments the control system is configured for semi-autonomous or fully autonomous operation. An operator may record a flight path along a pipe during manual flight, after which the UAV may autonomously repeat the recorded path. Alternatively, the UAV may employ simultaneous localization and mapping (SLAM) technology, allowing it to navigate and follow pipes or ceilings autonomously without the need for preprogrammed paths. This capability ensures consistent and repeatable cleaning while reducing operator burden.

These alternative embodiments demonstrate that while suction through a hollow robotic arm is a preferred feature, the invention is not limited thereto, and effective cleaning may also be achieved by airflow, bristle contact, wiping cloths, or interchangeable end effectors combined with stability-enhancing decoupling and damping mechanisms.

As illustrated in FIG. 14H, a UAV (40) may carry two ropes (41) that suspend a rectangular cleaning cloth (42) with an integrated weight (43). In operation, the UAV can pass above a surface or pipe so that the cloth drags along the surface to perform wiping, with the weight ensuring adequate pressure for effective cleaning.

In another embodiment shown in FIG. 61I, the UAV may be equipped with an optional bristle element (31). During flight, the propellers generate a downward wake (32), which may be sufficient to dislodge dust from the pipe (30). In some scenarios, the UAV may fly over strategic locations to dislodge dust using airflow alone, or in combination with bristle contact. The UAV may also drag a vibrating device along the pipe or surface to further assist in loosening stubborn debris.

A further embodiment is depicted in FIG. 61J, in which the UAV carries a fixed tube (20) rather than an articulated arm. The tube extends from a vacuum generation module with optional dust bin (10) located below the UAV to a position above the UAV body. This arrangement is particularly advantageous for industrial pipe cleaning, as it allows the cleaning component to reach narrow spaces above overhead pipes, such as those in food processing facilities. The tube tends to remain vertical due to the weight of the dust bin or other suspended components, which naturally orient toward the ground. In cases where no vacuum module is present—for example, when dust is collected by wipes or is simply dislodged to fall—the lower portion may instead carry a weight, as illustrated in FIG. 61L, to maintain vertical alignment.

The fixed tube may be fabricated from lightweight perforated material to reduce mass, with a thin foil applied over it in operation to preserve vacuum integrity. As shown in FIG. 61J, the tube may further include a mounting point (22) for a camera (23), which may provide inspection capability. The camera may transmit images wirelessly to an operator or may supply data for autonomous navigation. It may draw power via a tether from the UAV or from an onboard battery. The tube may also include a structure (24) designed to mount removable dust-collection cloths, allowing cloth cleaning to be combined with vacuum cleaning.

Preferred embodiments decouple the UAV's body orientation from its accessory components (such as the vacuum unit, robotic arm, or fixed tube). Without such decoupling, the UAV may become unstable when accessories exert forces against external objects, for example when a camera contacts a pipe or when a cleaning cloth rubs against a surface. Decoupling may be achieved by suspending the accessory from a rope, by introducing a pitch/roll decoupling mechanism, or by using a gimbal. This arrangement allows the UAV to guide the accessory while still permitting independent movement of the payload, thereby improving stability.

As shown in FIG. 61O, the payload may be suspended from a rope. To prevent uncontrolled yaw rotation, a rubber band (25) attached at feature (26) may be included, such that when the yaw of the payload deviates from that of the UAV, the rubber band gently restores alignment. An alternative embodiment is shown in FIG. 61Q, where two hinges (54, 55) correspond to the pitch and roll axes of the UAV. This configuration transfers yaw motion to the payload while decoupling pitch and roll.

Different structural geometries may be used to connect the portions of the accessory that extend above and below the UAV. In FIG. 61L, a U-shaped structure is employed to bypass the UAV body, while in FIG. 61P, a closed circular frame (51) provides the connection between the upper portion (52) and the lower portion (53). The circular configuration is more rigid and may be preferred in some applications.

The lower portion of the structure may also incorporate stabilizing features. As shown in FIG. 61P, fins (57) interact with the UAV wake to resist lateral displacement, while a weight (58) pulls the structure downward into an erect orientation. Together, the fins and weight improve alignment and reduce oscillation.

Finally, as illustrated in FIG. 61S, the upper portion of the structure may be equipped with a removable cleaning cloth, optionally electrostatic. In the embodiment shown, the cloth is retained by a magnet (59) that is attracted to a corresponding magnet embedded in the supporting structure. Alternative attachment methods may also be used, including pinching frames, sliding-over sleeves, or hook-and-loop fasteners, all of which allow rapid replacement of the cloth when soiled.

In alternative embodiments, the actuation transmission members of the articulated hollow robotic arm need not be tensioned by servomotors located at the base. Instead, the cables may be formed wholly or partly of shape-memory alloy wire, such as nickel-titanium (Nitinol), arranged so that application of an electrical current contracts the alloy and thereby shortens the cable path. Contraction is achieved by resistive heating: when a controlled current is passed directly through the Nitinol conductor, the resulting PR heating raises its temperature above the phase transition threshold, causing the alloy to return to its trained shape and exert a pulling force. The degree of contraction is governed by the applied current, duty cycle, and the cooling dynamics of the alloy. In some configurations, the Nitinol wire may begin directly at the hinge itself, such that the entire length of the transmission path is made from the shape-memory material, simplifying construction and eliminating the need for mechanical coupling between conventional cable and actuator. The use of shape-memory alloy actuation reduces reliance on rotary servos, enables a more compact arrangement, and may improve weight efficiency in applications where small deflections and high force density are desirable.

In further embodiments, pneumatic or hydraulic means may be employed instead of electrical or servo-based actuation. In one configuration, an elastomeric balloon or bladder is positioned in a constrained cavity such that when air or liquid is pumped into the balloon, the expansion of the balloon forces against an enclosing structure, producing a linear displacement. This displacement can be harnessed to tension an actuation cable routed to a hinge, thereby generating joint rotation. In variations, the balloon may itself serve as the actuation element, with its elongated body acting directly as a tensile member: when pressurized, the balloon contracts along its length and functions in the manner of an artificial muscle. Such fluid-driven actuation provides compliant force output, may be driven by lightweight pumps or compressed cartridges, and can be advantageous in applications where silent operation or spark-free environments are required.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for cleaning an overhead pipe, comprising:
an unmanned aerial vehicle (UAV) comprising:
   a frame;
   a control system configured to navigate the UAV along a predefined path adjacent to the pipe; and
   at least one of:
      at least one propeller configured to generate downward airflow to dislodge dust from the pipe; and
      a robotic arm with a suction mechanism configured to collect dust from the pipe; and
optionally, a bristle mechanism attached to the UAV, wherein the bristle mechanism is configured to contact the pipe during cleaning.
2. A system for cleaning an overhead pipe, comprising:
   a) an unmanned aerial vehicle (UAV) comprising:
   i) a frame;
   ii) at least one propeller configured to generate downward airflow; and
   iii) a control system configured to navigate the UAV along a predefined path adjacent to the pipe, wherein the downward airflow dislodges dust from the pipe; and
   b) optionally, a bristle mechanism attached to the UAV, wherein the bristle mechanism is configured to contact the pipe during cleaning.
3. A method for cleaning an overhead pipe with an unmanned aerial vehicle (UAV), the method comprising:
   a) providing a UAV comprising at least one propeller configured to generate downward airflow;
   b) programming the UAV to navigate along a predefined path adjacent to the pipe, or partially programming the UAV with AI assistance to follow the pipe;
   c) navigating the UAV along the predefined path, wherein the downward airflow generated by the at least one propeller dislodges dust from the pipe; and
   d) optionally, contacting the pipe with a bristle mechanism attached to the UAV during cleaning.
4. The system of item 2, further comprising a docking station configured to automatically recharge or swap the battery of the UAV.
5. The system of item 2, wherein the at least one propeller is equipped with a guard to reduce damage to the propeller and surrounding environment in the event of a collision.
6. The method of item 3, further comprising automatically recharging or swapping the battery of the UAV at a docking station.
7. The method of item 3, wherein the UAV comprises at least one propeller equipped with a guard to reduce damage to the propeller and surrounding environment in the event of a collision.
8. A system for cleaning a surface with an unmanned aerial vehicle (UAV), the system comprising:
a UAV having at least one propeller and a frame;
an end-effector attached to the UAV frame, the end-effector comprising a cleaning element configured to engage the surface; and
a mechanism for decoupling movement of the end-effector from movement of the UAV frame.
9. The system of item 8, wherein the end-effector is attached to the UAV frame via an arm, the end-effector comprising a cleaning element configured to engage the surface; and wherein the decoupling mechanism is selected from the group consisting of ropes, hinges, and an active gimbal system; and wherein the system further comprises a damping mechanism configured to dampen oscillations of the end-effector.
10. An end-effector for a UAV cleaning system, the end-effector comprising:
a cleaning element configured to engage a surface, the cleaning element comprising a wiping cloth; and
a mechanism for attaching the wiping cloth to the end-effector, the mechanism selected from the group consisting of a pinching mechanism and a sliding-over mechanism.
11. A method for cleaning a surface with an unmanned aerial vehicle (UAV), the method comprising:
providing a UAV having an end-effector with a cleaning element;
decoupling movement of the end-effector from movement of the UAV; and
navigating the UAV to bring the cleaning element into contact with the surface.
12. A method for cleaning a surface with an unmanned aerial vehicle (UAV), the method comprising:
providing a UAV having an end-effector with a cleaning element;
recording a path of the UAV along the surface; and
autonomously navigating the UAV along the recorded path to bring the cleaning element into contact with the surface.
13. A system for cleaning a surface with an unmanned aerial vehicle (UAV), the system comprising:
a UAV; and
an end-effector attached to the UAV, the end-effector comprising a cleaning element configured to engage the surface.
14. A UAV that provides lift to a construction that is decoupled in pitch and roll from the UAV, wherein the construction comprises a strut with an end-effector attached above the UAV, the strut being held aloft by the UAV.
15. A system for cleaning a surface with an unmanned aerial vehicle (UAV), the system comprising:
a UAV having at least one propeller and a frame;
an end-effector attached to the UAV frame via an arm, the end-effector comprising a cleaning element configured to engage the surface; and
a two-hinge mechanism for decoupling movement of the end-effector from movement of the UAV frame, wherein one hinge decouples roll movement and the other hinge decouples pitch movement, while allowing yaw movement to be transmitted to the end-effector.
16. A system for cleaning a surface with an unmanned aerial vehicle (UAV), the system comprising:
a. a UAV having at least one propeller and a frame;
b. an end-effector attached to the UAV frame via an arm, the end-effector comprising a cleaning element configured to engage the surface; and
c. a pitch-roll decoupling mechanism, said mechanism comprising:
i. a first hinge configured to connect the arm to the UAV frame, the first hinge configured to transfer yaw movement of the arm relative to the UAV frame while decoupling roll movement; and
ii. a second hinge configured to connect the end-effector to the arm, the second hinge configured to transfer yaw movement of the end-effector relative to the arm while decoupling pitch movement.
17. The system of item 15, wherein the pitch-roll decoupling mechanism is attached to the center bottom of the UAV frame, and the arm extends upward to position the end-effector above the UAV frame.
18. The system of item 17, further comprising a counterweight attached to the arm at a position below the UAV frame.
19. The system of item 18, wherein the counterweight maintains balance of the arm so that the end-effector remains positioned above the UAV frame.
20. The system of item 18, wherein the counterweight comprises a vacuum generating element configured to generate suction, and wherein the arm comprises a conduit for guiding suction to the end-effector, enabling the end-effector to remove debris from the surface.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. An articulated robotic arm, comprising:
a first hinge disposed closest to a base of the arm;
a second hinge disposed distally from the first hinge; and
an actuation cable extending from the base toward the second hinge, the cable being guided along or through the structure of the arm and operationally coupled to the second hinge such that tensioning of the cable produces rotation of the second hinge.
2. The robotic arm of item 1, wherein the actuation cable is routed through a cable guide aligned with a rotational axis of the first hinge such that rotation of the first hinge does not alter the effective cable length acting upon the second hinge.
3. The robotic arm of item 1, wherein the cable is tensioned by a servo motor located at or near the base of the arm.
4. The robotic arm of item 1, wherein one or more of the hinges are oriented such that successive hinges bend in planes that are not parallel, thereby enabling three-dimensional articulation.
5. The robotic arm of item 1, wherein the arm is formed at least in part from lightweight materials selected from plastics, carbon fiber composites, or foamed polymers.
6. The robotic arm of item 1, wherein the first hinge and the second hinge are connected by a hollow linkage segment defining a continuous channel through which suction or fluid may be conveyed to a distal end effector.
7. The robotic arm of item 6, further comprising a rotary base coupling at the base of the arm, permitting torsional rotation of the hollow linkage segment relative to the base while maintaining continuity of the channel.
8. The robotic arm of item 1, further comprising an elastic biasing element associated with at least one hinge, the biasing element configured to urge the hinge toward a rest position.
9. The robotic arm of item 1, wherein the robotic arm is mounted to a mobile apparatus comprising a dust collection bin and a vacuum generation module fluidly connected to the arm.
10. The robotic arm of item 9, wherein the mobile apparatus is an unmanned aerial vehicle.
11. The robotic arm of item 9, wherein the mobile apparatus is a ground-based robotic vehicle, optionally a quadruped robot.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. A system for cleaning a surface with an unmanned aerial vehicle (UAV), the system comprising:
a UAV having a frame and at least one propeller; and
a cleaning assembly attached to the UAV, the cleaning assembly comprising an end effector configured to engage or influence the surface to remove dust or debris.
2. The system of item 1, wherein the at least one propeller is configured to generate downward airflow directed toward the surface to dislodge dust or debris.
3. The system of item 1, wherein the end effector comprises a bristle mechanism configured to make contact with the surface.
4. The system of item 1, wherein the end effector comprises a wiping cloth, optionally statically charged to attract dust, the wiping cloth being removably mounted to the end effector by at least one of a pinching mechanism, a sliding-over mechanism, or a magnetic attachment.
5. The system of item 1, wherein the cleaning assembly is coupled to the UAV frame by a decoupling mechanism configured to transmit yaw motion while isolating pitch and roll motion of the UAV from the end effector.
6. The system of item 5, wherein the decoupling mechanism comprises at least one of a rope suspension, a rubber band suspension, a hinge-based pitch-roll decoupler, or an active gimbal system.
7. The system of item 1, further comprising a damping element configured to reduce oscillations of the end effector, the damping element comprising at least one of a rubber damper or a drag-inducing surface attached to the cleaning assembly.
8. The system of item 1, further comprising a counterweight coupled to the UAV, the counterweight configured to stabilize the cleaning assembly.
9. The system of item 8, wherein the counterweight comprises a vacuum generating element, and the cleaning assembly comprises a conduit for routing suction from the counterweight to the end effector.
10. The system of item 1, wherein the UAV is configured to operate semi-autonomously by recording a flight path and repeating the recorded path during cleaning operations.
11. The system of item 1, wherein the UAV is configured to operate fully autonomously by utilizing simultaneous localization and mapping (SLAM) to follow a surface such as a pipe or ceiling.
12. The system of item 1, wherein the end effector is rotatably adjustable relative to the cleaning assembly to align with a curved surface such as a pipe.
13. The system of item 1, wherein the cleaning assembly comprises interchangeable arms and end effectors, permitting adaptation of the UAV for pipe cleaning, ceiling cleaning, or roof cleaning tasks.

### Embodiment AUE: Articulated Hollow Robotic Arm

An articulated robotic arm is described in which multiple hinge joints are actuated by tendon-like cables driven from a proximal location via iso-length routing that decouples joint motions. In preferred forms, linkage segments are hollow and the joints preserve a continuous interior channel, enabling suction or fluid to reach a distal end effector. The system may include a rotary base coupling, self-cleaning bristle station, and integration with mobile platforms such as UAVs. Alternative embodiments include fixed tubes, bristle or cloth end effectors, and pitch-roll decoupling mechanisms. Subscription-enabled usage metering and licensing may be supported.

### Gentle Introduction

Conventional robot arms often place motors at each joint, which makes the distal portions heavy and difficult to keep hollow for routing suction or other utilities. The core idea here is to move weight to the base and pull on the joints with cables, while arranging the cable paths so that bending one joint does not accidentally tug on others. Intuitively, this is like threading a cord through a sequence of pulleys whose centers stay aligned with the joint axes; when a joint rotates around its own axis, the cord's length to a more distant joint remains effectively unchanged.

When the arm is built as a hollow tube with flexible, sealed joints, it can act as a lightweight vacuum conduit that bends to reach tight spaces. A rotary base can spin the arm without interrupting flow, and a simple bristle cup can clean the tip by a quick dip-in, pull-out motion. On a UAV, the lightweight, cable-driven arm reduces load at the outermost joints and preserves a clear path for suction, while optional decoupling and damping mechanisms help keep the payload stable. The same architecture can be used without suction for inspection, spraying, or general manipulation, showing that the hollow channel is beneficial but not mandatory.

### Examples

Example 1: Two-hinge suction arm with iso-length routing cleaning a ceiling vent. A base-mounted servo is coupled to a tendon that actuates a distal hinge while an iso-length guide is aligned with the axis of a proximal hinge. The operator powers the vacuum generation module, which draws suction through the hollow linkage segments and across the flexible sealed hinge interfaces. The arm is positioned near a ceiling vent by rotating the rotary base coupling to align with the vent grill, then the proximal hinge is deflected to angle the arm toward the grill. Because the tendon passes through the iso-length guide at the proximal hinge axis, the distal hinge cable length remains effectively constant as the proximal hinge moves, preserving the distal angle until commanded. The control system then tensions the distal tendon to sweep the end effector across the vent slats while suction removes loosened dust. After contact cleaning, the operator dips the distal end into the bristle cleaning station and withdraws it so the bristles sweep away webs, which are immediately captured by suction inside the hollow interior.

Example 2: UAV pipe dusting using propeller wash with optional bristle contact. The UAV records a manual path along a target pipe by flying parallel to the pipe at a set standoff distance and speed while the control system logs pose and time. On a repeat mission, the UAV replays the path to pass above the pipe so that downward airflow dislodges dust. Where deposits are stubborn, the UAV yaw-aligns an attached bristle element to the pipe axis and makes brief, light contacts while maintaining forward motion. The pitch-roll decoupling mechanism allows yaw to transmit while pitch and roll disturbances from contact are isolated from the airframe, reducing attitude transients and enhancing stability.

Example 3: Fixed tube with counterweight for narrow overhead spaces. A lightweight fixed tube extends from a lower counterweight to a distal opening located above the UAV body. The lower section houses a vacuum generation module acting as a counterweight. During flight, gravity maintains the tube substantially vertical; the circular frame variant provides stiffness between upper and lower sections while fins at the bottom interact with prop wash to damp lateral motion. The UAV is piloted along a row of overhead pipes while the elevated tube opening is guided between pipes to collect debris where access is restricted.

Example 4: Subscription metering and Model Context Protocol integration. The control system exposes a metering tool that may be accessed through a Model Context Protocol compliant client to log usage and retrieve signed usage summaries. An MCP tool definition called reportUsage may accept a compact JSON payload describing a mission segment and return a server-acknowledged receipt. A device may produce a signed usage record such as {“deviceld”:“UAV-042”, “missionld”:“M-2024-10-18-001”, “start”:“2024-10-18T10:15:00Z”, “stop”:“2 024-10-18T10:42:30Z”, “meters”:{“timeMinutes”:27.5, “distanceMeters”:312.3, “debrisVolumeLiters”: 0.42, “events”:{“bristleContacts”:18, “clothReplacements”:1}}, “sig”:“MEUCIFx3K . . . ”} and an associated license token may be expressed as {“licenseld”:“LIC-ABCD”, “tier”:“SLAM-PRO”, “features”:[“path-replay”, “slam-follow”, “vacuum-con trol”], “expires”:“2026-12-31T23:59:59Z”, “policy”:{“geofence”:“Z-Factory-A”, “rateLimitOpsPerHour “:120}, “sig”:“MGYCMQ . . . ”} so that feature enablement and telemetry uploads are coordinated with subscription tier. An MCP client could call a tool such as getUsageSummary with parameters {“deviceld”:“UAV-042”, “from”:“2024-10-01T00:00:00Z”, “to”:“2024-10-31T23:59:59Z”} to retrieve an externally observable, cryptographically verifiable ledger suitable for damages quantification.

### Enablement:

A representative two-hinge hollow arm can be constructed using readily available components and simple fabrication steps while preserving iso-length routing and vacuum continuity. The lower and upper hinge members may be 3D printed in nylon or machined from acetal with an outer diameter of 30 to 50 millimeters and a hinge axis formed by a stainless pin of 4 to 6 millimeters journaled in polymer bushings. Each hinge receives an elastic biasing element such as a torsion spring around the axis or an elastomer band anchored to opposing ears, preloaded to return the joint to a neutral angle. A flexible sealing sheath, for example a 0.2 millimeter polyurethane or nitrile rolling-diaphragm band adhered to circumferential flanges, bridges the gap between adjacent hollow linkage segments so the interior remains sealed while the joint articulates. The linkage segments can be carbon fiber tubes of 20 to 30 millimeters inner diameter with 1 to 2 millimeters wall thickness, bonded to the hinge members with epoxy fillets while maintaining axial alignment to within 0.2 degrees to minimize cable friction.

Iso-length routing is achieved by guiding the distal hinge actuation cable through a guide that is coaxial with the proximal hinge. A compact way to realize this is to install a low-friction eyelet or miniature ball bearing with a through-hole directly on the proximal hinge axis so the cable passes exactly through the axis. When the proximal hinge rotates, the cable path length to the distal joint remains substantially unchanged because the path crosses the axis of rotation. In embodiments where more robustness is desired, a narrow idler pulley concentric with the proximal axis may be used to define the cable path; the idler outer diameter may be 8 to 12 millimeters with a grooved profile to capture a 0.4 to 1.0 millimeter cable. The distal hinge includes a sector pulley or wrap post so that tension in the cable produces rotation; with a 15 millimeter effective radius, a 20 millimeter cable pull yields approximately 76 degrees of joint rotation, which is adequate for many cleaning tasks. Base-mounted servos actuate the tendons through spools sized to match the required cable travel and servo rotation. A typical metal-gear hobby-class servo or a compact industrial servomotor can be used; for example, a 20 kilogram-centimeter servo coupled to a 10 millimeter radius spool provides about 20 newtons of cable tension, sufficient to overcome hinge friction and end effector loads for a lightweight arm. Cable materials such as UHMWPE fiber or 7×7 stainless wire of 0.5 to 0.8 millimeters diameter may be employed; ends may be terminated with crimp sleeves or knots captured in printed bosses, and pre-tensioned to 10 to 20 newtons so backlash is minimized. Assembly proceeds by bonding the hinge members to the tubes, installing the axis pin and biasing element, adhering the rolling-diaphragm sheath, mounting the coaxial guide at the proximal axis, threading the distal tendon through the guide and along the interior, wrapping it around the distal sector, and tying off to a return spring or opposing cable if antagonistic actuation is used. Functional verification is performed by sweeping the proximal hinge through its full range while observing that distal tendon tension and distal angle remain essentially unchanged; an acceptable tolerance is a change of less than 5 percent in required distal actuation force over the proximal range.

Vacuum continuity through the base is maintained by a rotary base coupling comprising an inner rotary coupling member bonded to the first hollow linkage segment and supported in an outer rotary housing by a thrust bearing and radial bearing pair. An O-ring labyrinth or low-friction lip seals may be arranged between the inner member and the housing to maintain suction while allowing rotation of at least 180 degrees. The suction conduit connects from the outer housing to a vacuum generation module through a flexible conduit with a bend radius greater than five times the hose diameter to reduce losses. A compact impeller unit of 200 to 500 grams may provide 20 to 40 liters per minute airflow at a vacuum of 2 to 4 kilopascals, which is sufficient for dust removal while keeping mass low for UAV use. At the distal end, a bristle cleaning station can be constructed as a cup with inner diameter 5 to 10 millimeters larger than the arm tip; a ring of nylon bristles of 20 to 30 millimeters length clears debris as the tip is inserted and withdrawn, with loosened debris entrained by the suction. Control and calibration may be implemented with embedded firmware that maps servo positions to joint angles through empirically measured cable travel per degree, with optional in-line load cells or current sensing to detect contact and maintain safe forces. A calibration routine may home each joint against a compliant stop to establish a zero reference, then set cable pre-tension to a target value while monitoring sensor readings. Because iso-length routing decouples degrees of freedom, simple proportional commands to each servo produce largely independent joint motion; if residual coupling is observed, a 2×2 or n×n decoupling matrix can be identified from small-step experiments and applied in software to further reduce cross-talk.

Pitch-roll decoupling hardware for UAV embodiments can be realized by mounting a first hinge at the UAV's bottom center that allows pitch relative motion and transmits yaw via a torsion spring or rubber band linking the hinge carrier to the UAV frame, followed by a second hinge higher on the arm that allows roll relative motion, again with a weak torsional linkage to transmit yaw. Yaw transmission stiffness values in the range of 0.05 to 0.2 newton-meter per degree provide alignment without injecting large disturbances. A lower portion of the structure may include fins of 50 to 100 square centimeters projected area to interact with prop wash and a 200 to 500 gram weight to pull the structure into a vertical orientation. A fixed-tube configuration may be built from a lightweight perforated tube or lattice that is wrapped during operation with a thin polyethylene or polyurethane film to ensure vacuum integrity, with a simple camera mount above the UAV and a magnetic pad to attach a removable electrostatic cloth.

Software enablement for subscription and damages recording includes a usage metering subsystem with a monotonic secure clock and a secure element storing an Ed25519 key pair. The device produces compact, signed records at mission start and stop, and at consumable-change events, and buffers them locally when offline. An MCP client exposes tools such as reportUsage, getUsageSummary, and getLicense, where reportUsage accepts a payload like {“deviceld”:“UAV-042”, “missionld”:“M-2024-10-18-001”, “start”:“2024-10-18T10:15:00Z”, “stop”:“2 024-10-18T10:42:30Z”, “meters”:{“timeMinutes”:27.5, “distanceMeters”:312.3}, “sig”:“MEUCIFx3K . . . } and returns {“status”:“ok”, “ack”:“2024-10-18T10:43:00Z”, “receipt”:“R-9f2a . . . ”} and getLicense returns {“licenseld”:“LIC-ABCD”, “tier”:“SLAM-PRO”, “features”:[“path-replay”, “slam-follow”, “vacuum-con trol”], “expires”:“2026-12-31T23:59:59Z”, “sig”:“MGYCMQ . . . ”}. On-device enforcement may check the current time against expires, apply geofence constraints, and log every enforcement event as a signed record so that externally observable behavior corresponds to license policy for evidentiary purposes.

### Technical Effects

The iso-length cable routing guide aligned with a proximal joint axis yields mechanical decoupling between joints so that rotation of a proximal hinge produces substantially no change in the effective cable length acting on a distal hinge. This reduces control cross-talk, simplifies calibration to near-diagonal gain matrices, and improves end-effector path fidelity under multi-joint motion. By relocating actuators to the base, distal inertia is reduced, which lowers required torque for fast maneuvers and decreases energy consumption and vibration, thereby improving positional accuracy and duty life of cables, bushings, and seals.

Maintaining a continuous hollow interior through sealed hinges produces a stable pressure differential along the arm, reducing leakage and head loss relative to discontinuous or externally routed hoses. The result is higher volumetric throughput at the distal opening for a given impeller power, improving debris capture, reducing re-entrainment, and enabling operation with lighter vacuum units suitable for UAV payload limits. The rotary base coupling with labyrinth or lip seals allows azimuthal repositioning of the entire arm without interrupting flow, preserving suction continuity through large rotations and reducing the need for replumbing or swivel joints that add flow resistance. The bristle cleaning station enables periodic removal of fibrous debris from the distal tip without manual intervention. This reduces clogging at the intake, maintains suction performance over long missions, and decreases unplanned downtime, providing a tangible increase in throughput per battery charge and enabling autonomous or remote operation with fewer service cycles.

The pitch-roll decoupling mechanism transmits yaw while isolating pitch and roll disturbances between the UAV and the payload. This reduces attitude excursions during surface contact events, lowers controller saturation and recovery time, and minimizes the risk of propeller strikes or loss of control near structures. Passive fins and a lower weight create aerodynamic and gravitational restoring moments that damp lateral oscillations and bias the structure into a vertical orientation, which improves end-effector placement precision while demanding less from the flight controller. The fixed tube embodiment with a lower counterweight or vacuum unit yields a self-stabilizing vertical conduit that reaches into narrow overhead spaces. Using a lightweight perforated structure wrapped in a thin film provides a high stiffness-to-mass ratio while maintaining vacuum integrity only when needed, reducing carried mass and improving UAV endurance. Integrating a camera mount above the frame enables direct line-of-sight inspection while the tube geometry physically separates sensors from prop wash, improving image stability.

The subscription and metering subsystem employing a secure element and a monotonic secure clock generates tamper-evident, cryptographically signed usage records that are externally verifiable. This provides a technical effect of reliable, platform-agnostic telemetry exchange via Model Context Protocol tools, enabling deterministic feature enforcement, geofence compliance, and auditable linkage between commanded behaviors and license policy. The result is improved safety, predictable feature availability across heterogeneous deployments, and objective data suitable for billing and damages quantification.

### Background

Robotic manipulators are often designed as rigid linkages with joints driven by motors placed at or near each articulation point. While such arrangements provide precise actuation, they introduce significant mass at distal joints, increase complexity, and limit the ability to route hollow channels through the arm. In many applications, however, it is desirable to maintain a continuous hollow conduit along the arm structure, for example to carry suction, air, or fluid to a distal end effector. Conventional robotic arms typically fail to combine lightweight articulation with a clear internal pathway.

Cable-driven tendon actuation offers weight savings by allowing all drive motors to be located proximally, but such designs are challenging to implement in a way that preserves cable length independence when multiple joints are actuated simultaneously. Furthermore, when a hollow channel is required, conventional solutions often compromise on strength or sealing, preventing effective suction or fluid transfer.

There is therefore a need for an articulated robotic arm architecture that is lightweight, modular, and capable of supporting an arbitrary number of joints, while optionally preserving a continuous hollow interior and allowing independent actuation of each hinge.

### Summary of the Invention

The invention provides an articulated robotic arm, comprising one or more linkage segments connected by hinge joints, each joint being actuated by a tendon-like cable driven by a servo located at or near the base of the arm. The arrangement permits all actuation motors to remain proximal, while the cables are routed through iso-length cable guides configured so that rotation of one hinge does not alter the effective cable length acting upon another hinge, thereby achieving independent control of multiple degrees of freedom.

In preferred embodiments, each linkage segment is hollow, and the hinges are designed to preserve a continuous interior channel along the length of the arm. This hollow pathway may be used to route suction, airflow, liquid, or other utilities to a distal end effector. The hollow design is advantageous for vacuum cleaning, spraying, or inspection tasks; however, it is not strictly required. In some embodiments, the arm may be used with end effectors that do not require internal routing, in which case the linkage segments may be solid, lightweight structures that retain the same articulated, cable-actuated functionality.

The hinge joints may be biased toward a rest position by elastic elements, such as springs or elastomeric bands, and may be oriented at arbitrary angular offsets relative to one another, such that successive joints bend in different planes. The result is a modular structure in which any number of hinge units may be added in sequence, each maintaining the option of a hollow or solid construction depending on the intended application.

At the proximal end, the arm may connect to a rotary base coupling, permitting torsional rotation of the entire arm relative to its mounting platform while preserving continuity of the hollow interior if present. The hollow interior, when present, may be connected via a flexible conduit to a vacuum generation module or other fluid source, thereby enabling suction-based applications.

In certain embodiments, a self-cleaning station is provided in the form of a cup or receptacle with annular bristles surrounding a central clearance. The distal end of the arm may be inserted into the receptacle and retracted, causing the bristles to sweep debris such as spider webs from the arm tip, which debris may then be collected through the suction pathway if present.

The invention is not limited to vacuum cleaning UAVs, but may be applied in any context where a lightweight articulated manipulator is advantageous, including aerial, terrestrial, or marine mobile platforms; inspection or cleaning arms; precision spraying or delivery systems; or biologically inspired robotic limbs.

### Scope and Interpretation

The scope of protection may be defined solely by the claims. The figures, descriptions, and examples may illustrate example embodiments and do not limit the scope unless expressly recited in a claim. Features described in separate embodiments may be combined where technically feasible, and features described together may be implemented separately. The order of steps in any described process may be varied, omitted, or performed concurrently unless a particular order is expressly required. References to element numbers and figures may be for ease of understanding and do not imply limitations. Terms such as may, could, optionally, and for example indicate optional or illustrative aspects and not requirements.

For avoidance of doubt, an actuation transmission member may include any flexible or rigid transmission such as a tendon, cable, belt, chain, rack-and-pinion, gear train, push-pull rod, linkage, hydraulic or pneumatic conduit, or electromagnetic coupler. An iso-length transmission arrangement may include any path-invariance, equalization, or kinematic compensation mechanism that maintains, within a tolerance, an effective transmission path length to a distal joint as an intervening joint rotates, including but not limited to concentric guides, equal-and-opposite spools, differentials, opposed idlers, or four-bar linkages that preserve center-to-center distance. Functional equivalents that achieve the same decoupling performance as defined herein may be considered within scope.

### Figures

FIG. 61A shows various elements of one possible embodiment

FIG. 61B shows various elements of one possible embodiment

FIG. 61C shows various elements of one possible embodiment

FIG. 61D shows various elements of one possible embodiment

FIG. 61E shows various elements of one possible embodiment

FIG. 61F shows various elements of one possible embodiment

FIG. 61G shows various elements of one possible embodiment

FIG. 61I shows a UAV with an optional bristle element and downward propeller wake dislodging dust from a pipe

FIG. 61J shows a fixed tube embodiment extending above a UAV with optional camera and cloth mounts

FIG. 61L shows a U-shaped structure bypassing the UAV body and a weighted lower portion for vertical alignment

FIG. 61O shows a payload suspended by a rope with a rubber band restoring yaw alignment relative to the UAV

FIG. 61P shows a closed circular frame connecting upper and lower portions with fins and a weight for stabilization

FIG. 61Q shows a two-hinge pitch-roll decoupling mechanism that transmits yaw while isolating pitch and roll

FIG. 61S shows an upper structure with a removable cleaning cloth retained by magnetic coupling

FIG. 61H shows two ropes suspending a rectangular cleaning cloth with an integrated weight

### Elements

Lower hinge member
Upper hinge member
Elastic biasing element
Tendon cable (actuation cable)
Iso-length cable routing guide
Actuation servo
Hollow linkage segment
Clamp-on servo mount
Rotary base coupling
Vacuum generation module
Flexible conduit
Bristle cleaning station
Mobile platform
Inner rotary coupling member
Outer rotary housing
Distal cleaning bristles
Anchor: Element Numbers and Figure Relationships:

For clarity and cross-reference, element numbers used throughout the description correspond to the following structures and typical figure contexts. Elements (1-16) collectively appear in FIG. 61A through FIG. 61G to illustrate articulated arm variations: (1) lower hinge member; (2) upper hinge member; (3) elastic biasing element; (4) tendon cable; (5) iso-length cable routing guide; (6) actuation servo; (7) hollow linkage segment; (8) clamp-on servo mount; (9) rotary base coupling; (10) vacuum generation module; (11) flexible conduit; (12) bristle cleaning station; (13) mobile platform; (14) inner rotary coupling member; (15) outer rotary housing; (16) distal cleaning bristles. Additional figures introduce further numbered features as follows. FIG. 61I: (30) pipe; (31) optional bristle element; (32) downward propeller wake. FIG. 61J: (20) fixed tube; (22) camera mounting point; (23) camera; (24) removable cloth mount. FIG. 61L: U-shaped bypass structure with lower weight shown schematically consistent with the weighted lower portion described; the weight is represented as (58) when referenced in FIG. 61P. FIG. 61O: rope-suspended payload with yaw-restoring element (25) rubber band attached at feature (26) on the structure. FIG. 61P: closed circular frame (51) connecting an upper portion (52) and a lower portion (53) with fins (57) and weight (58) for stabilization. FIG. 61Q: two-hinge decoupler with hinges (54) and (55) corresponding to roll and pitch axes while transmitting yaw. FIG. 61S: removable cleaning cloth retained by magnet (59). FIG. 14H: UAV (40) carrying ropes (41) suspending a rectangular cleaning cloth (42) with integrated weight (43). Where an element is shown in more than one figure, numbering remains consistent across figures.

### Embodiment Narrative

A robotic arm (1-9) is mounted to a mobile platform (13), such as a drone, and is configured to provide articulated manipulation while maintaining a continuous internal suction pathway. The arm comprises a series of hollow linkage segments (7) connected by hinges formed of lower hinge members (1) and upper hinge members (2). Each hinge is biased by an elastic biasing element (3), which tends to return the joint toward a rest position. Controlled actuation is achieved by tendon cables (4) routed across the hinges and tensioned by actuation servos (6). The tendon cables are guided by iso-length cable routing guides (5), which ensure that when a proximal hinge changes its angle, the effective cable length to distal hinges remains constant, thereby rendering hinge actuation independent.

Clamp-on servo mounts (8) may be attached to any of the hollow linkage segments (7) to provide mounting interfaces for the actuation servos (6), while leaving the tubes free to serve as continuous suction conduits. At the base of the arm, a rotary base coupling (9) enables torsional rotation of the entire arm about its axis. This coupling includes an inner rotary coupling member (14), which is fixed to the first linkage tube and rotatably supported within a surrounding housing, thereby allowing rotation without disrupting the suction path.

The arm is fluidly connected via a flexible conduit (11) to a vacuum generation module (10), which may comprise a fan, impeller, and dust collection system, either bagged or bagless. To maintain operability, a bristle cleaning station (12) may be mounted to the platform, the station comprising a cup-like structure with an annular array of bristles (16) surrounding a central clearance. The distal end of the robotic arm can be inserted into and withdrawn from the central clearance, causing the bristles to sweep away accumulated spider webs, dust, or other debris, which may then be collected by the suction flow.

In this manner, the articulated robotic arm integrates lightweight cable-driven actuation with continuous hollow suction pathways, enabling a drone or other mobile platform to function as a flying vacuum cleaner while preserving independent joint control and self-cleaning capability.

The outer rotary housing (15) is secured to the rotary base coupling (9), within which the inner rotary coupling member (14) is rotatably supported and connected to the first hollow linkage segment. The outer rotary housing provides structural support around the inner member and may include mounting features for additional components. In certain embodiments, a servo and an elastic element such as a rubber band may be attached to the outer housing, with the opposite end of the elastic element secured to a clamp on the linkage tube, thereby enabling controlled rotary motion of the arm relative to the platform while maintaining the integrity of the suction pathway.

In further variations, a spring may be positioned between each lower hinge member (1) and upper hinge member (2). When enclosed by a flexible foil or other resilient sheath, the spring both biases the hinge and defines a vacuum-sealed flexible structure, allowing the interior suction pathway to continue through the joint without leakage while preserving mobility of the articulation.

### Variable Hinge Count and Orientation

The articulated hollow robotic arm may comprise an arbitrary number of hinges, each hinge being formed by a pair of hinge members (1, 2) coupled by a rotational axis. Each hinge may be actuated by a tendon cable (4) that extends from a corresponding actuation servo (6) located at or near the base of the arm, with cable routing guides (5) ensuring that the cable length remains constant across intervening hinges. In preferred configurations, the plurality of hinges may be arranged sequentially along hollow linkage segments (7) to form a continuous suction pathway, with the total number of hinges being selectable according to the desired reach or dexterity of the arm.

Furthermore, the bending planes of successive hinges need not be aligned in a common orientation. Each hinge may be mounted with its rotational axis oriented at an arbitrary angular offset relative to neighboring hinges, such that the arm may bend in different planes at successive joints. This arrangement allows three-dimensional maneuverability comparable to biological limbs or tentacles, while preserving the central hollow channel for suction flow.

While locating all actuation servos at or near the base of the arm is generally preferred in order to minimize distal mass and preserve a continuous hollow channel through the linkage segments, the invention is not limited to this configuration. In alternative embodiments, one or more servos may be mounted directly at the hinge joints, thereby providing local actuation without the need for extended tendon cables. Such arrangements may be advantageous in cases where the hollow pathway is unnecessary, where shorter cable runs are desired, or where direct-drive precision outweighs the benefit of base-mounted weight distribution.

### Alternative Embodiments

In addition to the suction-based cleaning arm described in primary embodiments, the invention may also be realized in a number of alternative configurations adapted for cleaning pipes, ceilings, and other overhead structures. In some cases, cleaning may be achieved not by vacuum suction, but by utilizing the airflow generated by the UAV's propellers. The UAV may be flown adjacent to a pipe such that the downward propeller wash dislodges dust and debris from the pipe surface. In further variations, the UAV may carry a bristle mechanism attached to the frame or to an appendage, the bristles being configured to contact the pipe surface and scrub away stubborn dust deposits. In still other embodiments, the distal end of the robotic arm may carry an end effector comprising a wiping cloth. The cloth may be electrostatically charged to enhance dust attraction and may be designed to be easily replaced when soiled. The cloth can be held on the end effector by a pinching mechanism, a sliding-over mechanism, or by a magnetic attachment, allowing quick interchange during operation. The electrostatic cloth may be mounted in multiples, so that several cloths can be used sequentially before replacement, thereby extending operational runtime.

The robotic arm itself may be directly coupled to the UAV frame such that its motions mirror those of the UAV body, or it may be decoupled in one or more degrees of freedom in order to improve stability. Decoupling may be achieved through suspension with ropes, through elastic band arrangements, or through dedicated hinges that selectively transmit yaw movement while isolating pitch and roll. In another variation, an active gimbal mechanism may be employed to stabilize the arm and end effector against UAV body movements, providing precise positioning relative to the cleaning target.

To further suppress oscillations, damping mechanisms may be incorporated. Such damping may be realized with rubber dampers placed between the arm and UAV body, or by attaching a drag-inducing surface, for example a planar vane or cross-shaped panel, that increases air resistance and reduces swinging motions.

Equivalent transmission schemes, including gear-differential linkages and belt, chain, or rod systems configured for iso-length behavior or software-maintained decoupling, may be employed without departing from the inventive concept.

In certain configurations, the arm may also be counterbalanced by a weight positioned below the UAV frame. The counterweight not only improves balance but may also house a vacuum generation unit, with suction conveyed through a conduit in the arm to the end effector, thereby integrating actuation, balance, and suction functionality in a single structure.

The end effectors and arms may be designed to be interchangeable, allowing the same UAV platform to be configured for pipe cleaning, ceiling cleaning, or roof cleaning depending on the chosen arm and end effector combination. In one case, the end effector may be rotatably adjustable to align a curved wiping cloth with the axis of a pipe, thereby maintaining effective contact across varying pipe diameters.

The UAV may be manually piloted, but in many embodiments the control system is configured for semi-autonomous or fully autonomous operation. An operator may record a flight path along a pipe during manual flight, after which the UAV may autonomously repeat the recorded path. Alternatively, the UAV may employ simultaneous localization and mapping (SLAM) technology, allowing it to navigate and follow pipes or ceilings autonomously without the need for preprogrammed paths. This capability ensures consistent and repeatable cleaning while reducing operator burden.

These alternative embodiments demonstrate that while suction through a hollow robotic arm is a preferred feature, the invention is not limited thereto, and effective cleaning may also be achieved by airflow, bristle contact, wiping cloths, or interchangeable end effectors combined with stability-enhancing decoupling and damping mechanisms.

As illustrated in FIG. 14H, a UAV (40) may carry two ropes (41) that suspend a rectangular cleaning cloth (42) with an integrated weight (43). In operation, the UAV can pass above a surface or pipe so that the cloth drags along the surface to perform wiping, with the weight ensuring adequate pressure for effective cleaning.

In another embodiment shown in FIG. 121, the UAV may be equipped with an optional bristle element (31). During flight, the propellers generate a downward wake (32), which may be sufficient to dislodge dust from the pipe (30). In some scenarios, the UAV may fly over strategic locations to dislodge dust using airflow alone, or in combination with bristle contact. The UAV may also drag a vibrating device along the pipe or surface to further assist in loosening stubborn debris.

A further embodiment is depicted in FIG. 12J, in which the UAV carries a fixed tube (20) rather than an articulated arm. The tube extends from a vacuum generation module with optional dust bin (10) located below the UAV to a position above the UAV body. This arrangement is particularly advantageous for industrial pipe cleaning, as it allows the cleaning component to reach narrow spaces above overhead pipes, such as those in food processing facilities. The tube tends to remain vertical due to the weight of the dust bin or other suspended components, which naturally orient toward the ground. In cases where no vacuum module is present—for example, when dust is collected by wipes or is simply dislodged to fall—the lower portion may instead carry a weight, as illustrated in FIG. 12L, to maintain vertical alignment.

The fixed tube may be fabricated from lightweight perforated material to reduce mass, with a thin foil applied over it in operation to preserve vacuum integrity. As shown in FIG. 12J, the tube may further include a mounting point (22) for a camera (23), which may provide inspection capability. The camera may transmit images wirelessly to an operator or may supply data for autonomous navigation. It may draw power via a tether from the UAV or from an onboard battery. The tube may also include a structure (24) designed to mount removable dust-collection cloths, allowing cloth cleaning to be combined with vacuum cleaning.

Preferred embodiments decouple the UAV's body orientation from its accessory components (such as the vacuum unit, robotic arm, or fixed tube). Without such decoupling, the UAV may become unstable when accessories exert forces against external objects, for example when a camera contacts a pipe or when a cleaning cloth rubs against a surface. Decoupling may be achieved by suspending the accessory from a rope, by introducing a pitch/roll decoupling mechanism, or by using a gimbal. This arrangement allows the UAV to guide the accessory while still permitting independent movement of the payload, thereby improving stability.

As shown in FIG. 120, the payload may be suspended from a rope. To prevent uncontrolled yaw rotation, a rubber band (25) attached at feature (26) may be included, such that when the yaw of the payload deviates from that of the UAV, the rubber band gently restores alignment. An alternative embodiment is shown in FIG. 12Q, where two hinges (54, 55) correspond to the pitch and roll axes of the UAV. This configuration transfers yaw motion to the payload while decoupling pitch and roll.

Different structural geometries may be used to connect the portions of the accessory that extend above and below the UAV. In FIG. 12L, a U-shaped structure is employed to bypass the UAV body, while in FIG. 12P, a closed circular frame (51) provides the connection between the upper portion (52) and the lower portion (53). The circular configuration is more rigid and may be preferred in some applications.

The lower portion of the structure may also incorporate stabilizing features. As shown in FIG. 12P, fins (57) interact with the UAV wake to resist lateral displacement, while a weight (58) pulls the structure downward into an erect orientation. Together, the fins and weight improve alignment and reduce oscillation.

Finally, as illustrated in FIG. 12S, the upper portion of the structure may be equipped with a removable cleaning cloth, optionally electrostatic. In the embodiment shown, the cloth is retained by a magnet (59) that is attracted to a corresponding magnet embedded in the supporting structure. Alternative attachment methods may also be used, including pinching frames, sliding-over sleeves, or hook-and-loop fasteners, all of which allow rapid replacement of the cloth when soiled.

Various refinements, alternatives, and applications of the foregoing embodiment may be described by the following itemized list, each of which is considered to fall within the general inventive concept and may be combined where technically feasible:

A system for cleaning an overhead pipe, comprising:
an unmanned aerial vehicle (UAV) comprising:
a frame;
a control system configured to navigate the UAV along a predefined path adjacent to the pipe; and
at least one of:
at least one propeller configured to generate downward airflow to dislodge dust from the pipe; and
a robotic arm with a suction mechanism configured to collect dust from the pipe; and
optionally, a bristle mechanism attached to the UAV, wherein the bristle mechanism is configured to contact the pipe during cleaning.

A system for cleaning an overhead pipe, comprising:
a) an unmanned aerial vehicle (UAV) comprising:
i) a frame;
ii) at least one propeller configured to generate downward airflow; and
iii) a control system configured to navigate the UAV along a predefined path adjacent to the pipe, wherein the downward airflow dislodges dust from the pipe; and
b) optionally, a bristle mechanism attached to the UAV, wherein the bristle mechanism is configured to contact the pipe during cleaning.

A method for cleaning an overhead pipe with an unmanned aerial vehicle (UAV), the method comprising:
a) providing a UAV comprising at least one propeller configured to generate downward airflow;
b) programming the UAV to navigate along a predefined path adjacent to the pipe, or partially programming the UAV with AI assistance to follow the pipe;
c) navigating the UAV along the predefined path, wherein the downward airflow generated by the at least one propeller dislodges dust from the pipe; and
d) optionally, contacting the pipe with a bristle mechanism attached to the UAV during cleaning.

The system of item 2, further comprising a docking station configured to automatically recharge or swap the battery of the UAV.

The system of item 2, wherein the at least one propeller is equipped with a guard to reduce damage to the propeller and surrounding environment in the event of a collision.

The method of item 3, further comprising automatically recharging or swapping the battery of the UAV at a docking station.

The method of item 3, wherein the UAV comprises at least one propeller equipped with a guard to reduce damage to the propeller and surrounding environment in the event of a collision.

A system for cleaning a surface with an unmanned aerial vehicle (UAV), the system comprising:
a UAV having at least one propeller and a frame;
an end-effector attached to the UAV frame, the end-effector comprising a cleaning element configured to engage the surface; and
a mechanism for decoupling movement of the end-effector from movement of the UAV frame.

The system of item 8, wherein the end-effector is attached to the UAV frame via an arm, the end-effector comprising a cleaning element configured to engage the surface; and wherein the decoupling mechanism is selected from the group consisting of ropes, hinges, and an active gimbal system; and wherein the system further comprises a damping mechanism configured to dampen oscillations of the end-effector.

An end-effector for a UAV cleaning system, the end-effector comprising:
a cleaning element configured to engage a surface, the cleaning element comprising a wiping cloth; and
a mechanism for attaching the wiping cloth to the end-effector, the mechanism selected from the group consisting of a pinching mechanism and a sliding-over mechanism.

A method for cleaning a surface with an unmanned aerial vehicle (UAV), the method comprising:
providing a UAV having an end-effector with a cleaning element;
decoupling movement of the end-effector from movement of the UAV; and
navigating the UAV to bring the cleaning element into contact with the surface.

A method for cleaning a surface with an unmanned aerial vehicle (UAV), the method comprising:
providing a UAV having an end-effector with a cleaning element;
recording a path of the UAV along the surface; and
autonomously navigating the UAV along the recorded path to bring the cleaning element into contact with the surface.

A system for cleaning a surface with an unmanned aerial vehicle (UAV), the system comprising:
a UAV; and
an end-effector attached to the UAV, the end-effector comprising a cleaning element configured to engage the surface.

A UAV that provides lift to a construction that is decoupled in pitch and roll from the UAV, wherein the construction comprises a strut with an end-effector attached above the UAV, the strut being held aloft by the UAV.

A system for cleaning a surface with an unmanned aerial vehicle (UAV), the system comprising:
a UAV having at least one propeller and a frame;
an end-effector attached to the UAV frame via an arm, the end-effector comprising a cleaning element configured to engage the surface; and
a two-hinge mechanism for decoupling movement of the end-effector from movement of the UAV frame, wherein one hinge decouples roll movement and the other decouples pitch movement, while allowing yaw movement to be transmitted to the end-effector.

A system for cleaning a surface with an unmanned aerial vehicle (UAV), the system comprising:
a. a UAV having at least one propeller and a frame;
b. an end-effector attached to the UAV frame via an arm, the end-effector comprising a cleaning element configured to engage the surface; and
c. a pitch-roll decoupling mechanism, said mechanism comprising:
i. a first hinge configured to connect the arm to the UAV frame, the first hinge configured to transfer yaw movement of the arm relative to the UAV frame while decoupling roll movement; and
ii. a second hinge configured to connect the end-effector to the arm, the second hinge configured to transfer yaw movement of the end-effector relative to the arm while decoupling pitch movement.

The system of item 15, wherein the pitch-roll decoupling mechanism is attached to the center bottom of the UAV frame, and the arm extends upward to position the end-effector above the UAV frame.

The system of item 17, further comprising a counterweight attached to the arm at a position below the UAV frame.

The system of item 18, wherein the counterweight maintains balance of the arm so that the end-effector remains positioned above the UAV frame.

The system of item 18, wherein the counterweight comprises a vacuum generating element configured to generate suction, and wherein the arm comprises a conduit for guiding suction to the end-effector, enabling the end-effector to remove debris from the surface.

Various refinements, alternatives, and applications of the foregoing embodiment may be described by the following itemized list, each of which is considered to fall within the general inventive concept and may be combined where technically feasible:

An articulated robotic arm, comprising:
a first hinge disposed closest to a base of the arm;
a second hinge disposed distally from the first hinge; and
an actuation cable extending from the base toward the second hinge, the cable being guided along or through the structure of the arm and operationally coupled to the second hinge such that tensioning of the cable produces rotation of the second hinge.

The robotic arm of item 1, wherein the actuation cable is routed through a cable guide aligned with a rotational axis of the first hinge such that rotation of the first hinge does not alter the effective cable length acting upon the second hinge.

The robotic arm of item 1, wherein the cable is tensioned by a servo motor located at or near the base of the arm.

The robotic arm of item 1, wherein one or more of the hinges are oriented such that successive hinges bend in planes that are not parallel, thereby enabling three-dimensional articulation.

The robotic arm of item 1, wherein the arm is formed at least in part from lightweight materials selected from plastics, carbon fiber composites, or foamed polymers.

The robotic arm of item 1, wherein the first hinge and the second hinge are connected by a hollow linkage segment defining a continuous channel through which suction or fluid may be conveyed to a distal end effector.

The robotic arm of item 6, further comprising a rotary base coupling at the base of the arm, permitting torsional rotation of the hollow linkage segment relative to the base while maintaining continuity of the channel.

The robotic arm of item 1, further comprising an elastic biasing element associated with at least one hinge, the biasing element configured to urge the hinge toward a rest position.

The robotic arm of item 1, wherein the robotic arm is mounted to a mobile apparatus comprising a dust collection bin and a vacuum generation module fluidly connected to the arm.

The robotic arm of item 9, wherein the mobile apparatus is an unmanned aerial vehicle.

The robotic arm of item 9, wherein the mobile apparatus is a ground-based robotic vehicle, optionally a quadruped robot.

Various refinements, alternatives, and applications of the foregoing embodiment may be described by the following itemized list, each of which is considered to fall within the general inventive concept and may be combined where technically feasible:

A system for cleaning a surface with an unmanned aerial vehicle (UAV), the system comprising:
a UAV having a frame and at least one propeller; and
a cleaning assembly attached to the UAV, the cleaning assembly comprising an end effector configured to engage or influence the surface to remove dust or debris.

The system of item 1, wherein the at least one propeller is configured to generate downward airflow directed toward the surface to dislodge dust or debris.

The system of item 1, wherein the end effector comprises a bristle mechanism configured to make contact with the surface.

The system of item 1, wherein the end effector comprises a wiping cloth, optionally statically charged to attract dust, the wiping cloth being removably mounted to the end effector by at least one of a pinching mechanism, a sliding-over mechanism, or a magnetic attachment.

The system of item 1, wherein the cleaning assembly is coupled to the UAV frame by a decoupling mechanism configured to transmit yaw motion while isolating pitch and roll motion of the UAV from the end effector.

The system of item 5, wherein the decoupling mechanism comprises at least one of a rope suspension, a rubber band suspension, a hinge-based pitch-roll decoupler, or an active gimbal system.

The system of item 1, further comprising a damping element configured to reduce oscillations of the end effector, the damping element comprising at least one of a rubber damper or a drag-inducing surface attached to the cleaning assembly.

The system of item 1, further comprising a counterweight coupled to the UAV, the counterweight configured to stabilize the cleaning assembly.

The system of item 8, wherein the counterweight comprises a vacuum generating element, and the cleaning assembly comprises a conduit for routing suction from the counterweight to the end effector.

The system of item 1, wherein the UAV is configured to operate semi-autonomously by recording a flight path and repeating the recorded path during cleaning operations.

The system of item 1, wherein the UAV is configured to operate fully autonomously by utilizing simultaneous localization and mapping (SLAM) to follow a surface such as a pipe or ceiling.

The system of item 1, wherein the end effector is rotatably adjustable relative to the cleaning assembly to align with a curved surface such as a pipe.

The system of item 1, wherein the cleaning assembly comprises interchangeable arms and end effectors, permitting adaptation of the UAV for pipe cleaning, ceiling cleaning, or roof cleaning tasks.
Monetization and Damages Considerations:

In certain embodiments, the system may be provisioned and operated under subscription or usage-based licensing models designed to support monetization and to facilitate calculation of damages in the event of infringement. The control system may incorporate a usage metering subsystem that records time-in-use, number of cleaning events, linear distance of cleaned surface, volume of collected debris, or number of autonomous missions executed. The metering records may be timestamped with a secure clock, cryptographically signed by a device-unique key stored in a secure element, and periodically uploaded to a cloud service through a telemetry channel. When connectivity is unavailable, the system may buffer signed records locally and synchronize them when connectivity resumes, preserving an auditable ledger of usage.

The subscription service may support tiered access levels, for example differentiating manual-only operation, semi-autonomous operation with recorded path replay, and fully autonomous SLAM-based operation. Feature enablement may be controlled by license tokens issued by a licensing server, with tokens validated on-device to permit or restrict capabilities such as deployment of certain end effectors, activation of vacuum generation modules, or execution of autonomous waypoint plans.

Over-the-air updates may be provided to deliver safety patches and feature upgrades, with update eligibility determined by the active subscription tier.

To enable accurate billing and potential damages quantification, the cloud service may maintain per-device accounts, usage dashboards for administrators, and reports that correlate mission identifiers with metered parameters. The telemetry may include externally observable summaries such as mission start and stop times, locations or geofenced zones of operation when permitted by privacy requirements, and consumable usage such as cloth replacements or filter changes, thereby providing verifiable evidence of system use. API endpoints may be offered to integrate usage data with enterprise maintenance systems or to trigger automated invoicing workflows.

For compliance and enforcement, the device may implement soft-disable behaviors if a license expires, such as restricting operation to safe manual modes or to test missions without cleaning actuation, while preserving emergency override capabilities for safety. The system may also enforce geofencing or rate limits according to license parameters, with corresponding events recorded in the usage ledger. These technical mechanisms may improve traceability of deployment, enable predictable recurring-revenue models, and provide concrete, quantifiable data to support damages assessments aligned with actual system utilization.

### Continuation-Ready Itemized Support:

Embodiments can be described by the following itemized list, each entry providing explicit support for present and future claims and being combinable with any other entry where technically feasible.

The entries also restate the currently claimed subject matter to ensure support remains even if claims are amended or deleted.
C1: An articulated robotic arm comprising multiple linkage segments connected by hinge joints, at least one tendon actuation cable operationally coupled to a distal hinge, and at least one iso-length cable routing guide aligned to a rotational axis of an intervening hinge such that rotation of the intervening hinge does not change the effective cable length acting on the distal hinge.
C2: The articulated robotic arm of C1 wherein at least one hinge joint is biased toward a rest position by an elastic biasing element including a torsion spring or elastomeric band.
C3: The articulated robotic arm of C1 wherein at least one linkage segment is hollow and the hinge joints preserve a continuous interior channel along the arm.
C4: The articulated robotic arm of C3 further comprising a rotary base coupling that permits torsional rotation relative to a base while maintaining continuity of the interior channel.
C5: The articulated robotic arm of C1 wherein successive hinge joints are oriented to bend in planes that are not parallel.
C6: The articulated robotic arm of C1 wherein an actuation servo located at or near a base tensions the tendon actuation cable.
C7: The articulated robotic arm of C3 further comprising a flexible conduit fluidly connecting the interior channel to a vacuum generation module.
C8: The articulated robotic arm of C1 further comprising a bristle cleaning station mounted to a platform and configured to sweep debris from a distal end.
C9: A UAV cleaning system comprising a UAV, an end effector attached via an arm, and a decoupling mechanism configured to transmit yaw while isolating pitch and roll between the UAV and the end effector.
C10: The UAV cleaning system of C9 wherein the decoupling mechanism comprises a first hinge that transfers yaw while decoupling roll and a second hinge that transfers yaw while decoupling pitch.
C11: The UAV cleaning system of C9 further comprising fins and/or a weight positioned to improve alignment and reduce oscillation of the end effector.
C12: The UAV cleaning system of C9 wherein the end effector comprises a wiping cloth removably attached by a magnetic attachment, a pinching mechanism, or a sliding-over mechanism.
C13: The UAV cleaning system of C9 wherein the cleaning assembly comprises interchangeable arms and end effectors configured for pipe cleaning, ceiling cleaning, or roof cleaning.
C14: A method of cleaning an overhead pipe by generating downward airflow with a UAV while navigating along a path adjacent to the pipe and optionally contacting the pipe with a bristle mechanism.
C15: The method of C14 further comprising recording a flight path and autonomously repeating the recorded path.
C16: The method of C14 further comprising autonomously following the pipe using simultaneous localization and mapping.
C17: A cleaning system comprising a UAV, a fixed tube extending from a lower portion below the UAV to a position above the UAV, and a counterweight coupled to the lower portion to maintain substantially vertical alignment.
C18: The cleaning system of C17 wherein the counterweight comprises a vacuum generation module fluidly coupled to the fixed tube and the fixed tube includes a camera mount and a mount for a removable dust-collection cloth.
C19: A UAV cleaning system comprising a usage metering subsystem with a secure element storing a device-unique key and a secure clock, configured to generate cryptographically signed, timestamped usage records and upload them via telemetry.
C20: A non-transitory computer-readable medium storing instructions that cause a UAV control system to enforce license tokens, apply geofencing or rate limits, and record externally observable mission events into a usage ledger.
C21: An iso-length routing guide realized as a bore, eyelet, or idler pulley concentric with a hinge axis, the guide having a through-path that constrains a tendon to pass at least substantially through the axis of rotation.
C22: A hinge seal comprising a rolling diaphragm, bellows, or elastomeric membrane adhered to circumferential flanges on adjacent hollow linkage segments to preserve vacuum continuity while permitting articulation.
C23: A distal joint actuation mechanism comprising a sector pulley, wrap post, or capstan having an effective radius between 5 and 30 millimeters to convert linear tendon motion to rotary motion.
C24: Antagonistic tendon actuation using opposing cables and springs to reduce backlash and improve positional fidelity of a hinge.
C25: A rotary base coupling having an inner rotary coupling member and an outer rotary housing with an O-ring labyrinth or lip seals, optionally including an electrical slip ring or optical rotary joint for power or data passthrough.
C26: A decoupling mechanism that transfers yaw via a compliant torsional element having a stiffness between 0.02 and 0.5 newton-meter per degree while providing low stiffness in pitch and roll.
C27: A damping element comprising aerodynamic fins, viscoelastic pads, or a fluid damper attached to the accessory to reduce oscillations induced by UAV motion or contact.
C28: A fixed tube formed from a perforated or lattice structure wrapped with a removable polymer film during operation to provide vacuum integrity with reduced mass.
C29: A camera or sensor mount positioned above the UAV frame on the arm or fixed tube such that sensors are outside of primary prop wash for improved image stability.
C30: A removable cloth holder using magnetic coupling, hook-and-loop, pinching frames, or sliding sleeves to enable rapid consumable changes during missions.
C31: A control method that identifies and compensates residual joint coupling via an empirically determined decoupling matrix applied to servo commands.
C32: A tendon material selected from UHMWPE fiber, aramid fiber, or stainless steel wire, with diameters between 0.2 and 1.2 millimeters and pre-tension between 5 and 40 newtons to minimize backlash.
C33: A calibration routine that homes joints against compliant stops, establishes zero references, and sets tendon pre-tension while monitoring load or current to detect contact.
C34: A usage metering protocol exposed as Model Context Protocol tools including reportUsage, getUsageSummary, and getLicense, each accepting compact JSON payloads and returning signed acknowledgements.
C35: A license enforcement behavior that transitions to a soft-disable mode upon expiry, limiting features while preserving safety-critical operation and continuing to log enforcement events.
C36: A UAV pipe-cleaning mode that replays a recorded trajectory at a specified stand-off distance and speed while adapting yaw alignment to pipe axis using onboard perception.
C37: A bristle cleaning station configured as a cup with an inner diameter 3 to 20 millimeters larger than the tip and bristles 10 to 50 millimeters long to dislodge fibrous debris on insertion and withdrawal.
C38: A hinge orientation scheme in which adjacent joints are rotated by 0 to 90 degrees about the arm axis relative to each other to achieve compound spatial bending with a continuous internal conduit.
C39: A servo spool radius selected to match required tendon travel per degree of joint rotation, with servo torque and spool size chosen to deliver at least 10 newtons of tendon tension for lightweight arms.
C40: A mobile apparatus to which the arm is mounted selected from UAVs, ground vehicles including quadrupeds, industrial gantries, or marine platforms, with the arm operating either with or without an internal suction channel.
C41: An iso-length decoupling arrangement in which a Bowden cable sheath is anchored coaxially at each intervening hinge axis such that proximal joint rotation does not change the effective free length of the inner cable acting on a distal joint.
C42: A mechanical compensation module comprising a pair of counter-rotating spools concentric with a proximal hinge axis that wind and unwind a tendon in equal and opposite amounts so that net tendon length to a distal hinge remains substantially constant under proximal rotation.
C43: An iso-length transmission using a timing belt or flat belt routed over idlers concentric with a proximal hinge axis and coupled to a distal sector pulley, whereby rotation of the proximal hinge does not change belt path length to the distal sector.
C44: A push-pull rod actuation mechanism with spherical joints and a telescoping sleeve constrained to pass through or about a proximal hinge axis so that the rod's effective length to a distal joint is invariant under proximal rotation within mechanical tolerance.
C45: A hydraulic or pneumatic actuation scheme employing matched-area dual cylinders linked by fluid lines and arranged so that proximal joint rotation occurs about a conduit junction substantially at the axis, thereby maintaining equalized fluid volumes and decoupling distal actuation from proximal motion.
C46: A kinematic decoupler formed as a spatial or planar four-bar linkage configured to maintain a constant distance between an actuator pulley and a distal joint pulley across proximal joint rotation, thereby providing iso-length behavior without the tendon passing exactly through the axis.
C47: A redundant iso-length path using two symmetrically placed guides offset from the proximal axis by equal and opposite distances such that first-order changes in path length cancel across proximal rotation.
C48: An externally verifiable decoupling criterion wherein, with distal actuation held constant, sweeping a proximal joint across at least 60 degrees produces less than a threshold change in distal joint angle or actuation force, the threshold being any of 1 percent, 3 percent, or 5 percent, enabling black-box infringement testing.
C49: A rotary fluid coupling alternative comprising a coaxial rotary union, a face seal rotary joint, or a labyrinth-sealed bearing stack providing continuous suction while allowing at least 180 degrees of base rotation.
C50: An end effector set including any of suction nozzles, compliant brushes, electrostatic wipes, adhesive rollers, or spray nozzles, each attachable to the distal end while preserving the same arm transmission and decoupling architecture.
C51: A tendon routing variant employing crossed belts, crossed tendons, or wrap-direction selection at the distal sector so that geometric coupling from proximal joints is passively canceled over a specified motion range.
C52: A platform-agnostic mounting interface that adapts the arm to at least two of UAVs, ground robots, and stationary gantries while preserving decoupling features and externally observable behaviors including signed usage logging via Model Context Protocol tools.
C53: An articulated robotic arm with one or more local joint actuators mounted at the hinges while preserving a continuous interior channel, wherein joint independence is maintained by software control using a decoupling matrix rather than iso-length hardware routing.
C54: A control method that maintains a commanded distal joint angle substantially constant while a proximal joint is swept by applying feedback compensation derived from calibration, without requiring an iso-length hardware arrangement.
C55: A transmission employing a differential gear pair, chain-and-sprocket, or rack-and-pinion arrangement concentric with a proximal hinge axis to equalize path length to a distal joint and thereby achieve iso-length behavior.
C56: A cleaning assembly in which suction is routed via an external hose constrained along the arm by clips or fairings while the linkage segments are structurally hollow or solid, the system retaining a rotary base coupling and decoupling mechanisms.
C57: An externally verifiable criterion for pitch-roll decouplers wherein commanded yaw changes at the UAV result in at least a threshold yaw alignment at the payload while applied pitch or roll disturbances transmit less than any of 1 percent, 3 percent, or 5 percent of torque to the UAV frame over a defined frequency band.
C58: A rotary base suction continuity criterion wherein continuous rotation of at least 180 degrees at a constant vacuum setpoint results in less than 10 percent variation in volumetric flow at the distal opening under a fixed orifice, enabling black-box verification.
C59: A standardized modular end-effector interface specifying geometric datums and quick-release couplers that accommodates suction nozzles, brushes, wipes, adhesive rollers, and spray heads so that interface changes do not avoid compatibility with the arm architecture.
C60: A licensing and metering mode in which features are enforced and usage is logged per mission, per minute of operation, per distance cleaned, per volume collected, or per consumable replacement, each record including policy identifiers and cryptographic signatures to support damages quantification.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:
1. An articulated robotic arm comprising a plurality of linkage segments connected by hinge joints, at least one actuation transmission member operationally coupled to a distal hinge joint, and at least one iso-length transmission arrangement configured such that rotation of an intervening hinge joint does not change an effective transmission path length acting on the distal hinge joint.
2. The articulated robotic arm of item 1, wherein at least one hinge joint is biased toward a rest position by an elastic biasing element.
3. The articulated robotic arm of item 1, wherein at least one linkage segment is hollow and the hinge joints are configured to preserve a continuous interior channel along a length of the arm.
4. The articulated robotic arm of item 3, further comprising a rotary base coupling configured to permit torsional rotation of the arm relative to a base while maintaining continuity of the interior channel.
5. The articulated robotic arm of item 1, wherein successive hinge joints are oriented to bend in planes that are not parallel.
6. The articulated robotic arm of item 1, wherein an actuation servo located at or near a base of the arm drives the actuation transmission member.
7. The articulated robotic arm of item 3, further comprising a flexible conduit fluidly connecting the interior channel to a vacuum generation module.
8. The articulated robotic arm of item 1, further comprising a bristle cleaning station mounted to a platform and configured to sweep debris from a distal end of the arm.
9. A system for cleaning a surface with an unmanned aerial vehicle, the system comprising a UAV having a frame and at least one propeller, an end effector attached to the UAV frame via an arm, and a decoupling mechanism configured to transmit yaw motion while isolating pitch and roll motion of the UAV from the end effector.
10. The system of item 9, wherein the decoupling mechanism comprises a first hinge that transfers yaw while decoupling roll and a second hinge that transfers yaw while decoupling pitch.
11. The system of item 9, further comprising a damping element comprising at least one of fins or a weight positioned to improve alignment and reduce oscillation of the end effector.
12. The system of item 9, wherein the end effector comprises a wiping cloth removably attached by at least one of a magnetic attachment, a pinching mechanism, or a sliding-over mechanism.
13. The system of item 9, wherein the cleaning assembly comprises interchangeable arms and end effectors configured for at least pipe cleaning, ceiling cleaning, or roof cleaning.
14. A method for cleaning an overhead pipe with an unmanned aerial vehicle, the method comprising generating downward airflow with at least one propeller of the UAV while navigating along a path adjacent to the pipe and optionally contacting the pipe with a bristle mechanism attached to the UAV during cleaning.
15. The method of item 14, further comprising recording a flight path along the pipe and autonomously repeating the recorded path.
16. The method of item 14, further comprising autonomously following the pipe using simultaneous localization and mapping.
17. A cleaning system comprising a UAV, a fixed tube extending from a lower portion below the UAV to a position above the UAV, and a counterweight coupled to the lower portion configured to maintain substantially vertical alignment of the fixed tube relative to gravity.
18. The cleaning system of item 17, wherein the counterweight comprises a vacuum generation module fluidly coupled to the fixed tube, and wherein the fixed tube includes a camera mount and a mount for a removable dust-collection cloth.
19. A UAV cleaning system comprising a usage metering subsystem including a secure element storing a device-unique cryptographic key and a secure clock, the usage metering subsystem configured to generate cryptographically signed, timestamped records of at least one of time-in-use, number of cleaning events, linear distance of cleaned surface, collected debris volume, or missions executed, and to upload the records to a cloud service via a telemetry channel.
20. A non-transitory computer-readable medium storing instructions that, when executed by a control system of a UAV cleaning system, cause the control system to enforce license tokens to enable or restrict features, apply geofencing or rate limits according to license parameters, and record externally observable mission start and stop times and consumable usage as part of a usage ledger.
   1.

An apparatus comprising:
at least one vacuum generating element; and
at least one propellor generating lift.
   2.

The apparatus of item 1, wherein the vacuum generating element is arranged to produce a suction flow.

3.

The apparatus of item 2, wherein the suction flow is directed through a conduit, hollow linkage, or nozzle.

4.

The apparatus of item 3, wherein the conduit or hollow linkage is articulated to permit movement of the suction flow inlet relative to the apparatus body.

5.

The apparatus of item 4, wherein the articulated conduit or hollow linkage comprises a robotic arm having one or more hollow segments.

6.

The apparatus of item 1, wherein the propellor is one of a plurality of propellors configured in a multirotor arrangement.

7.

The apparatus of item 6, wherein the plurality of propellors are symmetrically disposed to provide stable lift.

8.

The apparatus of any preceding item, wherein the vacuum generating element and the propellor are powered by a common energy source.

9.

The apparatus of any preceding item, wherein the apparatus is airborne during operation of the vacuum generating element.

10.

The apparatus of any preceding item, wherein the vacuum generating element is configured to remove particulate matter from elevated or inaccessible surfaces.

### Embodiment AV: System and Method for UAV Navigation Using Ground-Based Tracking and UWB-Assisted Positioning

A system for navigating unmanned aerial vehicles (UAVs) is disclosed. The system includes a ground-based autonomous vehicle equipped with one or more cameras that observe the UAV and follow it to maintain line-of-sight visibility. A processing unit receives video from the cameras and optionally images from the UAV itself. A UWB ranging module estimates the distance between the ground vehicle and the UAV. By combining camera angular data with UWB distance information, the processing unit derives an accurate three-dimensional position of the UAV. Control commands such as directional or attitude adjustments are transmitted to the UAV. The invention enables precise UAV navigation in GPS-denied or cluttered environments while reducing the computational and payload burden on the UAV.

### Background

Unmanned aerial vehicles have become widely used for inspection, logistics, and surveillance. Outdoors they rely primarily on GPS for positioning, but in GPS-denied environments such as warehouses, tunnels, forests, and urban canyons, GPS signals are often unavailable or unreliable. To compensate, UAVs have been equipped with complex navigation hardware such as LiDAR, stereo cameras, and simultaneous localization and mapping processors. These approaches impose significant weight, power consumption, and computational cost on the UAV. Since UAVs are inherently constrained by payload capacity and limited battery life, there is a strong need to offload these burdens.

Ground-based autonomous vehicles, in contrast, can navigate more easily because they move on a stable two-dimensional plane and can use wheel odometry, visual SLAM, or floor-based markers to establish their own location. They are less restricted in payload weight and power availability. It is therefore advantageous to delegate UAV navigation to ground-based systems, allowing the UAV to remain lighter, simpler, and more efficient.

### Summary

The invention provides a system in which a ground-based autonomous vehicle follows a UAV and continuously maintains line-of-sight with it through one or more cameras. The vehicle is equipped with a UWB ranging transceiver which communicates with a corresponding module on the UAV. The distance information from UWB is combined with angular information from the cameras to yield an accurate three-dimensional position of the UAV relative to the ground vehicle. A processing unit converts this positional data into navigation or attitude control commands, which are transmitted to the UAV by a communication link.

This arrangement allows UAVs to fly stably and accurately in environments where GPS is unavailable. The UAV requires only minimal onboard equipment such as a UWB transceiver and a communication module, and optionally a lightweight camera if image fusion is desired. The navigation burden is shifted to the ground vehicle, which is better suited to carrying heavy sensors and processors. As a result, UAVs can operate longer and more safely while relying on the supportive ground platform.

### Detailed Description

The system includes at least one UAV, a ground-based autonomous vehicle, a UWB ranging system, a processing unit, and a communication link. The UAV may be any multirotor or fixed-wing aerial vehicle equipped with a lightweight UWB transceiver and a radio communication module. It may also carry a small onboard camera, although this is optional. The ground-based vehicle may be a wheeled or tracked robot platform equipped with one or more cameras oriented to view the UAV. The ground vehicle also carries a UWB transceiver that communicates with the UAV's transceiver to measure distance. The ground vehicle may be capable of autonomous navigation, for example through odometry sensors, inertial measurement units, LiDAR, or visual SLAM techniques.

During operation the UAV takes flight and the ground vehicle autonomously moves to maintain a clear line-of-sight between its cameras and the UAV. The cameras provide angular information describing the apparent azimuth and elevation of the UAV. The UWB ranging system exchanges signals to determine the distance between UAV and ground vehicle. By combining angular information with distance measurement, the processing unit derives a precise three-dimensional position of the UAV relative to the ground platform. This calculation may be performed using simple trigonometric relations. For example, if the camera supplies azimuth θ and elevation φ, and the UWB provides distance r, then the Cartesian coordinates of the UAV relative to the ground vehicle may be expressed as x=r cos φ cos θ, y=r cos φ sin θ, and z=r sin φ.

If a stereo camera pair is used, the cameras provide an independent estimate of depth through triangulation, which may be fused with the UWB distance measurement for improved robustness. A Kalman filter or weighted averaging algorithm may be used to combine the two depth sources and reduce noise or error from either system.

The processing unit, which may be located on the ground vehicle, on a remote server, or distributed between both, converts the three-dimensional position into navigation or attitude control commands.

If the UAV deviates laterally, the processor generates roll or yaw commands to correct it. If the UAV deviates vertically, up or down commands are sent. If the UAV drifts forward or backward, pitch commands are issued. These control signals are transmitted via a wireless communication link to the UAV, which executes them in real time.

Because the UAV does not require heavy onboard navigation hardware, it can remain lightweight and energy efficient. The ground vehicle, with fewer weight and power constraints, bears the computational and sensing load. The system is particularly useful for indoor inspection, subterranean exploration, warehouse logistics, and under-canopy agricultural operations. Multiple UAVs may be tracked simultaneously by a single ground vehicle, or multiple ground vehicles may cooperate to provide redundant coverage of a single UAV.

The system can be implemented using commercially available components. Low-cost wheeled robots provide adequate ground platforms. Tracking cameras may be standard RGB modules or infrared units. UAV tracking can be achieved with deep learning object detectors, color segmentation, or fiducial markers such as AprilTags mounted on the UAV. UWB transceivers such as the DW1000 or DW3000 series provide centimeter-scale ranging accuracy. Position fusion algorithms may be implemented on small embedded processors or offloaded to remote servers.

This arrangement not only improves navigation accuracy in GPS-denied environments but also significantly extends UAV endurance by shifting computation to the ground. It ensures safety by keeping continuous line-of-sight and reducing the risk of UAV collision with obstacles. The combination of UWB ranging with camera tracking provides robust three-dimensional positioning that is resilient to poor lighting, occlusion, or multipath interference.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

1.

A system for navigating an unmanned aerial vehicle, comprising:
a ground-based autonomous vehicle equipped with one or more cameras configured to observe the unmanned aerial vehicle;
a UWB ranging module configured to estimate a distance between the ground-based vehicle and the unmanned aerial vehicle;
a processing unit configured to combine angular information from the one or more cameras with distance information from the UWB ranging module to determine a three-dimensional position of the unmanned aerial vehicle; and
a communication link configured to transmit control commands to the unmanned aerial vehicle.
   2.

The system of item 1, wherein the control commands comprise directional commands including left, right, forward, backward, up, and down.

3.

The system of item 1, wherein the control commands comprise attitude commands including pitch, roll, and yaw.

4.

The system of item 1, wherein the ground-based vehicle autonomously follows the unmanned aerial vehicle to maintain continuous line-of-sight.

5.

The system of item 1, wherein the one or more cameras comprise a stereo pair providing triangulation depth estimates.

6.

The system of item 1, wherein the processing unit fuses UWB range data with mono camera angular data to resolve three-dimensional position.

7.

The system of item 1, wherein the UWB ranging module comprises synchronized transceivers located respectively on the unmanned aerial vehicle and the ground-based vehicle.

8.

The system of item 1, wherein the ground-based vehicle further comprises a localization subsystem selected from odometry, LiDAR, inertial navigation, or visual SLAM.

9.

The system of item 1, wherein the processing unit is located on the ground-based vehicle.

10.

The system of item 1, wherein the processing unit is located remotely from both the unmanned aerial vehicle and the ground-based vehicle.

11.

The system of item 1, wherein the unmanned aerial vehicle further comprises a local camera, and the processing unit is configured to fuse images from the unmanned aerial vehicle with images from the ground-based vehicle.

12.

The system of item 1, wherein the system is operable in GPS-denied environments including indoor facilities, subterranean spaces, or forest canopy.

13.

The system of item 1, wherein the ground-based vehicle is configured to predict a flight path of the unmanned aerial vehicle and reposition itself accordingly.

14.

The system of item 1, wherein the system supports simultaneous tracking of multiple unmanned aerial vehicles.

15.

The system of item 1, wherein the unmanned aerial vehicle omits onboard SLAM or GPS systems, thereby reducing weight and power consumption.

16.

A method for navigating an unmanned aerial vehicle, comprising the steps of autonomously controlling a ground-based vehicle to follow the unmanned aerial vehicle while maintaining line-of-sight using one or more cameras;
estimating a distance between the unmanned aerial vehicle and the ground-based vehicle via UWB ranging;
combining the distance with angular information from the one or more cameras to determine a three-dimensional position of the unmanned aerial vehicle; and
transmitting control commands to the unmanned aerial vehicle based on the determined position.
   17.

The method of item 16, wherein transmitting comprises sending directional commands including left, right, forward, backward, up, and down.

18.

The method of item 16, wherein transmitting comprises sending attitude commands including pitch, roll, and yaw.

19.

The method of item 16, further comprising processing images originating from the unmanned aerial vehicle and fusing the images with the images from the ground-based vehicle and UWB distance data.

20.

The method of item 16, wherein the method is performed in an indoor environment or other GPS-denied environment.

### Embodiment AW: Energy-Efficient Head-Mounted Environmental Awareness Device

Problem Description: People frequently misplace or lose personal items such as bags, wallets, mobile phones, luggage, grocery bags, or umbrellas during daily activities. While traveling or moving between locations, it is common to set an item down temporarily—at a cafe, airport check-in desk, train seat, or shop counter—and then forget to take it along. In other situations, distractions or crowded environments may lead to unnoticed theft or unintentional separation from valuable belongings.

Existing solutions, such as GPS trackers or Bluetooth tags, depend on periodic wireless signals and provide only coarse location information once an item is already lost. They do not offer immediate situational awareness of the user's surroundings, nor do they alert the user in real time when an object leaves their field of view or when another person interacts with it. They also require one tag per item that needs to be monitored.

To prevent forgetful users from losing items, forgetting where they placed them, failing to take them along after a brief pause while on the move, having them stolen, or leaving without necessary items, it is therefore desirable to provide an automatic system that continuously monitors the wearer's immediate environment, recognizes the presence or absence and location of personal belongings, and issues timely alerts when these objects are no longer visible or within reach.

Summary of the Solution: The proposed solution is a smart hat or head-mounted apparatus equipped with 360-degree visual awareness, enabling continuous monitoring of the wearer's personal environment. The device integrates multiple miniature vision modules positioned around the hat to observe the surrounding scene, identify personal items, and detect when these objects leave the field of view. Comparable 360-vision systems have been described in the prior art, for example in sports broadcasting or immersive video capture; however, such systems typically consume substantial electrical power because they record and transmit full video streams continuously.

The present invention distinguishes itself by achieving similar situational awareness with drastically reduced energy consumption, enabling long-term or even solar-powered operation. This is accomplished through several synergistic design strategies:

### 1. Inertial Motion Awareness:

An integrated inertial measurement unit (IMU) detects head movements and orientation changes. By analyzing IMU data, the system determines whether apparent motion in the captured scene originates from the wearer's own movement or from external object motion. This contextual information allows the processor to suppress redundant visual data and to transmit only meaningful changes-significantly reducing wireless data traffic to any associated on-body smart device, such as a smartphone or smartwatch.

### 2. Event-Based Vision:

In an optional embodiment, the hat employs event-based cameras that output data only when local brightness changes occur, effectively ignoring static portions of the scene. When the environment is motionless, data generation nearly ceases, allowing the vision subsystem to operate on millliwatt-level power instead of the hundreds of milliwatts required for traditional frame-based cameras.

### 3. Local Processing and Smart Compression:

Lightweight algorithms on an embedded microcontroller perform real-time filtering, motion gating, and data compression, transmitting only compact summaries or alerts rather than raw imagery. Because computation consumes far less energy than radio transmission, local processing provides an additional order-of-magnitude improvement in total efficiency.

Together, these features enable a continuous yet low-power awareness system that monitors the presence, absence, and movement of personal belongings without the battery drain associated with conventional wearable cameras. The invention thereby provides a practical, unobtrusive, and energy-autonomous solution for preventing loss or theft of everyday items.

Detailed Description of Embodiments: Embodiments of the invention may incorporate a solar panel, a battery, or a combination of both, allowing for flexible operation depending on ambient light conditions and desired autonomy. In some configurations, the system performs on-hat processing, where the local hardware integrated into the hat executes all object-tracking and awareness functions.

In other embodiments, the hat transmits a summarized or data-reduced stream to an external processing unit—such as a smartphone, smartwatch, or wearable computer—for further analysis or user notification.

In one embodiment, the hat employs event-based cameras to monitor the surrounding scene. Because most parts of any scene remain static over time, event-based imaging substantially reduces the amount of generated data. When the wearer's head moves, a large number of events are produced due to relative motion between the environment and the camera. To prevent unnecessary transmission of such self-induced data, embodiments may employ several data-reduction strategies before sending information to the off-hat processing unit. Examples include, but are not limited to:

### 1. Motion-Gated Transmission:

Events are transmitted only when the wearer's head is substantially stationary, as determined by data from the gyroscope and accelerometer of the integrated inertial measurement unit (IMU).
Alternatively, the system may transmit only the initial few milliseconds of event data following a detected head movement, thereby providing positional information of objects of interest at intermittent, quasi-random intervals corresponding to the start of each motion.

### 2. Event Stream Simplification:

When event data is transmitted, the stream may be reduced by one or more of the following:
   Statistical thinning of events to reduce density while preserving spatial distribution;
   o Spatial binning of event coordinates into coarser pixel regions to reduce positional precision; and
   o Temporal binning of event timestamps into larger time intervals, thereby lowering temporal resolution but maintaining general motion context.

### 3. Frame Reconstruction and Compression:

In some embodiments, events accumulated over a defined time window are used to reconstruct an image frame. A compressed representation of this frame-using conventional image codecs or lightweight custom schemes-is then transmitted to the companion device.

### 4. Higher-Level Abstraction:

The locally gathered events or reconstructed images may be converted into higher-level, vectorized scene descriptions, such as simplified geometric or SVG-like representations containing object contours and relative positions. These concise abstractions require minimal bandwidth and can be readily interpreted by the external processing unit.

Any combination of the above methods may be applied concurrently or adaptively, depending on scene activity, motion levels, or available power budget.

In further embodiments employing non-event cameras, the system may compute the difference between consecutive image frames to generate an event-like change stream. This derived stream can then be processed using the same compression or data-reduction techniques as described above, or with standard image-compression algorithms where appropriate.

Together, these strategies enable the system to maintain omnidirectional awareness while consuming a fraction of the energy required by conventional continuous video systems, making persistent, wearable environmental monitoring feasible for all-day or solar-powered operation.

In preferred embodiments, the transmission of data to the off-hat processing unit-preferably achieved via a wireless interface such as Bluetooth Low Energy, Wi-Fi Low Energy, or another short-range link-may be further optimized by exploiting the relaxed latency requirements of this application. Because the system's primary goal is to maintain situational awareness rather than deliver real-time video, a communication delay of up to approximately two seconds is generally acceptable and does not affect usability. This temporal tolerance enables the processor to accumulate event or image data into larger batches before activating the radio interface. Once a batch is ready, the accumulated data are compressed and transmitted as a single packet or short burst, after which the wireless interface can return to a low-power or sleep state. By minimizing the number of transmission wake-ups and protocol handshakes, and by sending larger, highly compressed data chunks instead of many small packets, total energy consumption for communication is reduced by an additional order of magnitude while maintaining sufficient responsiveness for object-tracking alerts and user notifications.

Object Tracking and Identification: In various embodiments, object tracking may be based on analysis of a data-reduced visual stream that contains the outlines or contours of objects of interest, such as a personal bag, wallet, or other belonging. The outline information is obtained when the wearer moves their head or when an object of interest moves relative to the head while the head remains stationary. Each outline may be represented within an accumulated image frame corresponding to a selected time window of event activity. In certain configurations, a neuromorphic processing chip may be employed to extract such outlines directly from event data; however, for clarity, the following description focuses on embodiments that operate on two-dimensional image data rather than asynchronous events.

Object recognition may proceed in two stages. In a first stage, an artificial-intelligence model, such as a convolutional neural network (CNN) or other machine-learning system, is trained to locate and classify objects appearing in the plurality of image frames captured by the multiple cameras distributed around the hat. Typical object classes include luggage, handbags, mobile phones, umbrellas, sets of keys, or other personal effects.

In a second stage, the system determines whether a detected object of interest corresponds specifically to one of the wearer's registered personal items. In one embodiment, this is accomplished through visual signature matching without the use of fiducial markers. During an initial registration procedure, the user walks around each personal item-such as a bag, wallet, or piece of luggage-while wearing the hat, thereby allowing the integrated 360-degree camera array to capture images of the object from multiple viewing angles. As the wearer moves, the system records a series of short image sequences from the distributed cameras to form a comprehensive visual representation of the item. A processor, either on the hat or on an associated computing device, extracts compact feature embeddings from these images using a neural-network-based model such as a CNN or transformer architecture (for example, MobileNet or CLIP). The resulting embeddings collectively form a multi-view visual signature uniquely characterizing the object and are stored locally or on an associated smartphone. During normal operation, when the vision subsystem detects an object of interest, a current embedding is computed and compared with the stored embeddings using a similarity metric such as cosine similarity. When the similarity exceeds a predetermined threshold, the object is identified as one of the user's registered belongings. This process enables reliable recognition of personal items based solely on their natural appearance-including surface texture, color pattern, and distinctive markings—without the need for physical tags.

Alternatively, fiducial or optical markers may be attached to the items of interest to facilitate recognition. The system may also estimate the distance to an object by observing changes in its apparent size (outline contraction) or, in embodiments incorporating stereo camera pairs, by calculating disparity using stereo vision algorithms.

In one embodiment, the system may generate an alert when an item belonging to a “should-have-around-person” set is detected as moving away from the wearer. In a more advanced embodiment, the system may include a contextual reasoning module, optionally implemented using a large language model (LLM) or other semantic inference engine. The local processor or a connected companion device may produce a situation description based on sensory and environmental inputs—for example, “the wearer is leaving for the beach,” inferred from calendar data, GPS location, or user schedule—and combine it with object-state descriptors, such as “registered item bag 25 is not within reach or in the wearer's hands.” These structured descriptions are provided to the reasoning module, which interprets the context to infer user intent and determine whether an alert should be issued. For instance, upon identifying that the wearer is departing for the beach without the registered beach bag, the system may generate an intelligent reminder or notification. This semantic interpretation layer enables context-aware decision-making, extending the device's function beyond simple proximity tracking toward proactive assistance based on inferred goals and situational understanding.

In certain embodiments, the system may further store geographical and contextual information corresponding to the moment the wearer becomes separated from a registered item. When the vision or proximity sensors indicate that an object of the “should-have-around-person” set has moved out of range, the system records the last known position of the wearer and the object, derived from integrated GPS data, inertial odometry, or the location services of an associated smartphone. This stored information assists the user in retracing their steps or recovering misplaced items and may optionally be shared or made accessible to a personal digital agent or other trusted service for automated recovery.

When the detected motion pattern indicates that an item is moving away while the wearer remains stationary, the system may interpret this as a probable theft event and issue a correspondingly escalated alert, such as an audible alarm, haptic feedback, or urgent notification to the companion device. Conversely, the system may employ contextual reasoning to suppress alerts in situations where separation is expected or benign—for example, when a hotel receptionist or airline staff member temporarily handles the user's luggage. In such cases, the LLM or semantic reasoning engine may evaluate environmental cues such as “reception counter,” “check-in procedure,” or “staff in uniform,” and determine that no theft alert is required. By combining spatial awareness, environmental understanding, and semantic reasoning, the system provides adaptive, context-sensitive alerting that balances security with convenience, issuing notifications only when appropriate.

In certain embodiments, the system may employ behavioral correlation learning to automatically identify which objects are habitually kept near the wearer. During normal use, the processor monitors spatial and temporal relationships between detected objects and the wearer's position or motion. Objects that consistently remain within a defined proximity range or move in coordination with the wearer over multiple observation periods are inferred to be personally associated items. These objects can be automatically added to, or prioritized within, the “should-have-around-person” set without explicit manual registration. Over time, the system thereby adapts to the user's habits-learning, for example, which bag, phone, or umbrella typically accompanies the wearer—allowing more accurate alerts when such items are left behind or unexpectedly separated.

Near-Field Event Selection and Far-Field Suppression: In preferred embodiments, the system is configured to preferentially sense and process activity occurring within the wearer's near surroundings while disregarding distant background motion. Because only nearby objects are relevant for personal-item tracking and situational awareness, the device employs a combination of optical configuration and computational filtering techniques that together suppress or eliminate events originating from far-away portions of the scene.

At the optical level, each event-based vision module may be focused for short range and equipped with optical elements that naturally attenuate distant detail. The focus may be fixed at approximately 0.3 to 1.0 m and the aperture opened to a low f-number, producing a shallow depth of field such that objects at large distances appear strongly defocused. A supplementary close-up or diopter lens of +2 D to +5 D may be used to further shift the focal plane toward the near field, causing features at infinity to blur and therefore fail to generate local brightness changes. This optical defocus removes the high-frequency edges responsible for event generation at long range. The modules may additionally be tilted downward by about 20-30 degrees and provided with a short hood or field stop so that the cameras view primarily the region surrounding the wearer's torso and hands rather than the horizon. These optical measures alone reduce the number of events produced by irrelevant distant motion.

At the computational level, any residual far-field events may be rejected through depth-related gating and event-stream shaping. In one embodiment, parallax depth gating is employed: during small natural head translations, the inertial sensors provide precise motion data, allowing the processor to compensate for expected image motion. Clusters of events that exhibit only minimal residual motion after such compensation correspond to large-distance objects and are therefore discarded. Alternatively or additionally, if two or more modules are arranged with a known baseline, stereo disparity can be computed; clusters whose disparity falls below a predetermined threshold (indicating a distance greater than, for example, two meters) are ignored. A further heuristic based on angular size may be applied, wherein event clusters whose image area or extent is below a set pixel threshold are considered too small to belong to near-field objects and are filtered out.

Following geometric gating, event-stream shaping may be performed to retain only strong, nearby motion cues. Events may be evaluated according to motion magnitude or time-surface gradient after IMU-based derotation, and only those exceeding a minimum energy threshold are forwarded for transmission or higher-level processing. Statistical thinning and spatial-temporal binning may also be used to preferentially preserve dense, high-contrast event regions associated with close objects while further reducing noise and background data.

Through the combined action of optical blurring, directional limitation, parallax- and disparity-based depth estimation, and energy-based stream reduction, the apparatus effectively restricts its sensitivity to the near-field region surrounding the wearer. As a result, objects beyond a selected distance-such as vehicles or people several meters away-generate few or no events, substantially reducing data volume and power consumption while maintaining accurate monitoring of the user's immediate personal space.

Additional and Optional Features: The smart hat may include any combination of the following auxiliary structures and subsystems. Each feature may be implemented independently or together with other features described herein to enhance functionality, comfort, efficiency, or aesthetic quality.

Distributed Energy Storage and Electronics Placement: Multiple slim lithium-polymer energy cells may be embedded around the circumference of the hat rather than housed in a single battery pack. The distributed configuration balances weight evenly around the wearer's head and improves comfort. In certain embodiments, the energy source may comprise one or more bent or continuous flexible battery packs, or small cylindrical battery cells shaped to follow the curvature of the rim, thereby maintaining a smooth external profile. The cells or continuous pack may be electrically connected in series or parallel and charged through solar film integrated into the brim or on an upper sun-exposed surface, by inductive coupling, or through a concealed wired connector. Likewise, the electronics may also be distributed around the circumference of the hat for weight distribution.

In certain embodiments, the electronic components of the hat—such as processing circuits, communication modules, power regulators, and sensors—may be distributed around the circumference of the headband rather than concentrated in a single location. This arrangement provides several technical advantages. First, the distributed configuration promotes uniform heat dissipation, reducing localized temperature hotspots near the forehead or temples and improving long-term wearer comfort. Second, by positioning high-frequency or high-current modules at spatially separated circumferential segments, mutual electromagnetic interference (EMI) between components is minimized, improving signal integrity and radio-frequency performance. Third, distributing the electronics contributes to mechanical stability by counterbalancing the mass of front-mounted devices-such as a camera or display module-so that the overall moment of inertia of the hat remains substantially neutral during head movement. Collectively, these measures yield improved thermal behavior, electromagnetic compatibility, and ergonomic balance compared with conventional head-mounted devices having a concentrated electronics cluster.

Information Feedback Display: A micro-OLED, LED, or equivalent light-emitting strip may be positioned along the lower, inner surface of the brim to provide subtle visual feedback visible only to the wearer. The display can convey minimal information such as navigation cues, notification icons, charging status, or system warnings. Because the display faces downward toward the user's eyes, light leakage to the exterior is minimized, preserving privacy and visual discretion. The display brightness and color may be automatically adjusted according to ambient-light levels detected by integrated photodiodes.

Audio Capture and Playback System: One or more directional microphones may be integrated into the brim or headband region and oriented toward the wearer's mouth to capture clear voice input while rejecting ambient noise. Beam-forming or other digital signal-processing methods may be applied to further improve intelligibility. Audio output may be provided by bone-conduction transducers embedded within the band, miniature planar speakers, or wired or wireless in-ear modules that pair automatically with the hat. These components enable full two-way communication for calls, voice-assistant interaction, or media playback without visible earbuds.

In certain embodiments, the hat may include a combined visual-and-audio interface configured to deliver information and communication functions directly to the wearer while preserving external discretion. The inner-brim light-emitting strip and the audio subsystem may operate cooperatively to provide synchronized feedback for navigation or alerts. Together, these integrated elements provide a discreet, hands-free communication and information system that allows two-way interaction with external devices or network services without visible accessories or intrusive illumination, thereby improving privacy, aesthetics, and usability compared with conventional head-mounted electronics.

Cellular and Network Connectivity: The hat may include an integrated cellular modem (for example, 4G, 5G, or successor standard) or other wide-area network interface. A SIM or eSIM module allows the hat to operate independently of a smartphone, providing stand-alone data connectivity, GPS positioning, cloud synchronization, and emergency communication functions. Local connectivity such as Wi-Fi or Bluetooth may also be supported for short-range data exchange or accessory pairing.

Frontal Illumination Element: A frontal illumination light may be disposed along the forward edge of the brim to illuminate the wearer's path or serve as a signaling element. The light may comprise one or more LEDs, micro-LEDs, or other light-emitting devices embedded within the brim structure. Brightness can be manually or automatically controlled based on ambient-light sensors, and the light may optionally operate in pulsed or color-coded modes for navigation or aesthetic purposes.

Premium Construction and Materials: To emphasize exclusivity, structural and decorative components may be fabricated from lightweight, high-value materials such as anodized aluminum, carbon-fiber composite, or precious-metal plating (gold or silver). The outer fabric may include leather, suede, or advanced breathable textiles selected for thermal comfort and appearance. Magnetic or concealed fasteners allow module replacement or recharging without visible seams, giving the device a minimalist, luxury finish. In certain embodiments, structural and decorative components may be formed from materials that also provide functional benefits: anodized aluminum or carbon-fiber composite for reduced weight and improved thermal dissipation, and metallic plating for electromagnetic-interference shielding. Magnetic or concealed fasteners may additionally act as electrical contacts or inductive-charging interfaces, enabling module replacement or recharging while maintaining a continuous exterior surface.

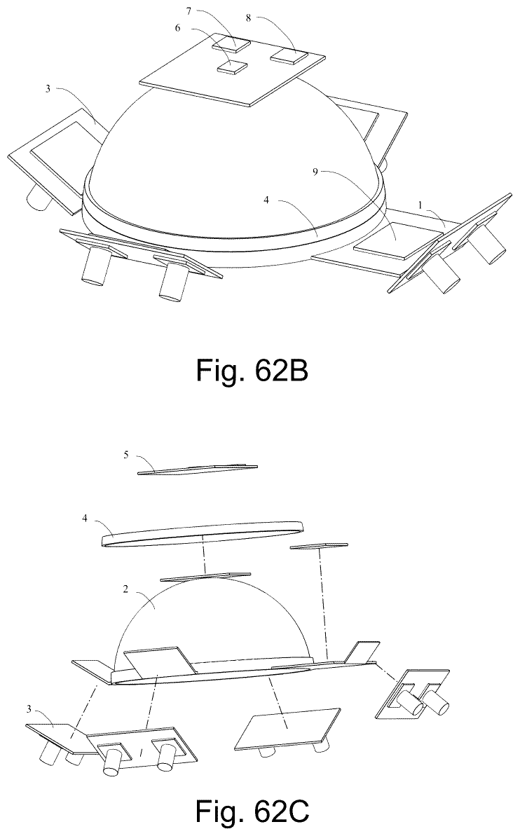

Example embodiment: An example embodiment is depicted in FIGS. 62A, 62B and 62C: Referring to the accompanying drawings, an exemplary embodiment of the smart-hat apparatus comprises a brim (1) joined to a head cup or crown portion (2) that collectively form the wearable structure. One or more stereo camera or stereo event-camera assemblies (3) are mounted substantially in the horizontal plane and oriented partially downward to monitor the surroundings of the wearer, the two imaging sensors being separated by a fixed baseline distance to enable depth perception and object tracking. Electrical power is supplied by at least one battery (4) positioned within the rim or headband region. The battery is electrically coupled to a printed-circuit board (5) that supports the principal electronic subsystems: an inertial-measurement unit (IMU) (6), a processor (7), and a wireless transmission module (8). The IMU senses angular velocity and linear acceleration of the wearer's head, and its output is provided to the processor, which executes motion-compensation and data-reduction operations on the stereo or event-camera signals. The transmission module communicates processed or compressed data to an external device such as a smartphone, wearable computer, or remote server. One or more solar panels (9) are disposed on the upper, sun-exposed surface of the brim or head cup and are electrically connected to the battery (4) through suitable power-management circuitry to provide trickle charging during outdoor use. The foregoing components cooperate to form a lightweight, self-powered, head-mounted vision system capable of acquiring stereoscopic or event-based image data, compensating for wearer motion, and transmitting the resulting information for further analysis or display.

In various embodiments, the disclosed head-mounted wearable apparatus comprises one or more imaging sensors positioned on a hat, cap, visor, helmet, or equivalent head-mounted structure. The imaging subsystem may include at least one event-based camera or a conventional image-capture camera, or a combination thereof. Each event-based sensor is configured to output asynchronous pixel-change data corresponding to changes in light intensity within the wearer's surrounding field of view. When implemented as a stereo pair, the cameras may be mounted with a fixed baseline distance to enable depth estimation and object localization around the wearer.

At least one motion sensor-such as a gyroscope, accelerometer, or integrated inertial-measurement unit (IMU)-is mechanically coupled to the hat structure and electronically connected to a processor housed within the hat or associated module. The motion sensor provides continuous data representing angular velocity, linear acceleration, or spatial orientation of the wearer's head. The processor uses these signals to distinguish between (i) motion of the wearer's head and (ii) independent motion of external objects within the captured scene.

The processor and an associated wireless transmission module cooperate to produce a data-reduced visual stream. When the motion sensor detects head movement, the processor may temporarily suppress image frames or asynchronous events attributable solely to that self-motion, or may perform real-time derotation of the event stream so that only motion arising from external objects is retained.

The resulting reduced data are transmitted to an external device—for example, a smartphone, tablet, wearable computer, or remote server-via a low-power radio such as Bluetooth®, Wi-Fi®, or 5G.

This selective transmission conserves energy and bandwidth while maintaining awareness of meaningful environmental changes.

In certain embodiments, the apparatus further comprises a battery integrated within or distributed around the hat band to provide operating power. The battery may be rechargeable through a wireless charging coil or inductive-coupling interface located in the brim or headband region, enabling sealed construction and water-resistant operation without exposed connectors. The processor, camera, and radio components are powered by the battery through suitable power-management circuitry configured to minimize idle consumption and to enter low-power states when the hat is stationary.

The system may operate alone or in conjunction with an external processing unit that performs higher-level analysis, such as object recognition or personal-item tracking. In one configuration, the event-based vision sensor transmits its asynchronous pixel-change data, or a derived representation such as accumulated event frames, to the external device, which then detects and tracks objects within the wearer's near surroundings. This allows the apparatus and the external unit to collectively determine whether a registered personal item-such as a bag, wallet, phone, or umbrella-remains within view or has moved away from the wearer.

To further optimize energy efficiency, the processor may apply range-based gating or distance-limited processing. Depth information may be estimated from stereo disparity, optical-flow magnitude, or parallax during minor head motions measured by the IMU. The system may thereby classify objects as near or distant and limit processing or transmission of event data associated with objects beyond a predetermined distance, for instance beyond two meters from the wearer. Because distant objects generally lack relevance to personal-item monitoring, this selective filtering significantly reduces computational load and wireless-transmission power without degrading functionality in the wearer's immediate vicinity.

Collectively, these features form a low-power, self-aware vision platform that integrates compact imaging sensors, inertial sensing, intelligent data reduction, and efficient wireless communication into a lightweight head-mounted form factor. The combination of event-based sensing and IMU-driven motion discrimination yields a measurable reduction in energy consumption and bandwidth relative to frame-based or non-gated systems, enabling practical long-duration operation on a small, rechargeable battery supply.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

### Item 1.

A head-mounted wearable apparatus comprising:
(a) at least one event-based or image-capture camera positioned on a hat, cap, or other head-mounted structure;
(b) at least one motion sensor selected from the group consisting of a gyroscope, an accelerometer, or a combination thereof, configured to sense motion or orientation of the wearer's head; and
(c) a processor and wireless transmission module configured to generate a data-reduced visual stream by suppressing image or event data attributable to wearer motion based on signals from the motion sensor, and to transmit the data-reduced stream to an external device.

### Item 2.

The apparatus of item 1, further comprising a battery configured to power the processor and transmission module.

### Item 3.

The apparatus of item 1 or 2, further comprising a wireless charging coil configured for inductive charging through a hat brim or cap structure.

### Item 4.

The apparatus of any of items 1-3, wherein the camera is mounted at a frontal, lateral, or rear-facing position on the headwear to provide an expanded field of view surrounding the wearer.

### Item 5.

The apparatus of any of items 1-4, wherein the motion sensor comprises both a gyroscope and an accelerometer, and the processor is configured to combine their outputs for enhanced motion compensation.

### Item 6.

The apparatus of any of items 1-5, wherein the processor applies temporal filtering or frame differencing to suppress redundant image data associated with wearer motion.

### Item 7.

The apparatus of any of items 1-6, wherein the wireless transmission module transmits the data-reduced visual stream via a protocol selected from Bluetooth, Wi-Fi, or 5G.

### Item 8.

The apparatus of any of items 1-7, further comprising a memory buffer configured to temporarily store motion-compensated image or event data prior to transmission.

### Item 9.

The apparatus of any of items 1-8, wherein the external device comprises a smartphone or wearable display configured to receive and process the transmitted stream for display or object tracking.

### Item 10.

The apparatus of any of items 1-9, wherein the processor is configured to automatically adjust camera parameters, including exposure or gain, based on motion data to maintain visual clarity during movement.

### Item 11.

A head-mounted wearable apparatus comprising:
(a) at least one event-based vision sensor configured to output asynchronous pixel-change data representing changes in the wearer's surrounding scene;
(b) a processor and wireless transmission module configured to transmit said pixel-change data or a derived representation thereof to an external processing unit;
   wherein the apparatus and the external processing unit are collectively configured to track personal items located within the wearer's near surroundings based on said event data.

### Item 12.

The apparatus of item 11, wherein the processor is configured to identify and track a plurality of personal items based on distinct motion signatures or event clusters.

### Item 13.

The apparatus of item 11 or 12, wherein the processor is further configured to reduce power consumption by limiting processing or transmission of event data associated with objects beyond a predetermined distance from the wearer.

### Item 14.

The apparatus of any of items 11-13, wherein the predetermined distance is dynamically adjusted based on detected user activity, such as walking or cycling.

### Item 15.

The apparatus of any of items 11-14, further comprising a depth-sensing module configured to estimate object distance from event data or parallax information.

### Item 16.

The apparatus of any of items 11-15, wherein the external processing unit executes a neural network model trained to classify personal objects based on received event data patterns.

### Item 17.

The apparatus of any of items 11-16, wherein the external processing unit provides a user alert when a tracked personal item exits a defined proximity range.

### Item 18.

The apparatus of any of items 11-17, wherein the processor and external processing unit are configured to synchronize timestamps to maintain temporal accuracy of event tracking.

### Item 19.

The apparatus of any of items 11-18, wherein the event-based vision sensor operates with a pixel resolution between 100×100 and 1280×720 and an event latency below 1 millisecond.

### Item 20.

The apparatus of any of items 11-19, wherein the system further comprises a low-power standby mode activated when no motion or event activity is detected for a threshold period.

### Embodiment AQ: Autonomous Beehive Defense Apparatus Using Sensor-Based Activation

A beehive protection device is disclosed for deterring or neutralizing hornets near a hive entrance. The device comprises at least one sensor, such as a camera, microphone, or a combination thereof, arranged to monitor activity proximate to the hive entrance, and at least one movable interception element, such as a strike arm or flap, configured to move across the entrance region. Signals from the sensor are analyzed-either locally or remotely-to detect the presence or characteristic behavior of a hornet, whereupon the interception element is actuated to intercept, repel, or eliminate the insect.

In preferred embodiments, the interception element is driven by energy released from a potential-energy storage mechanism, such as an elastic or spring element, that is charged during an arming phase and rapidly discharged upon trigger.

A latching system, for example magnetic or mechanical, may maintain the armed state until release. Power may be supplied from a solar panel and battery or from an external grid connection. The system enables low-power, autonomous, and non-chemical protection of beehives against hornet predation.

### Background of the Invention

Hornet predation represents a serious and increasing threat to honeybee colonies throughout Europe and other regions.

In particular, invasive species such as Vespa velutina (the Asian hornet) frequently attack at hive entrances, capturing worker bees as they return and causing severe stress to the colony. Sustained hornet presence can lead to reduced foraging activity, colony weakening, and eventual collapse.

Conventional protective measures are largely passive or chemical in nature.

Mechanical grids or entrance reducers provide limited deterrence but can also obstruct bee traffic and are ineffective against persistent hornet hovering.

Chemical repellents and bait traps, while somewhat effective, introduce toxicity risks, require maintenance, and can harm non-target species.

Active devices using electrical fields or sound emitters have been proposed, but these tend to consume excessive power, operate unreliably in outdoor conditions, or fail to discriminate between hornets and bees.

There remains a need for a low-power, autonomous, and selective system capable of protecting hive entrances without chemicals or human intervention.

Such a system should identify hornets accurately, operate safely near bees and humans, and respond rapidly enough to intercept the hornet before it attacks.

The present invention addresses these needs by providing a responsive, energy-efficient mechanism that detects hornet presence and performs a targeted mechanical interception.

### Example Embodiment

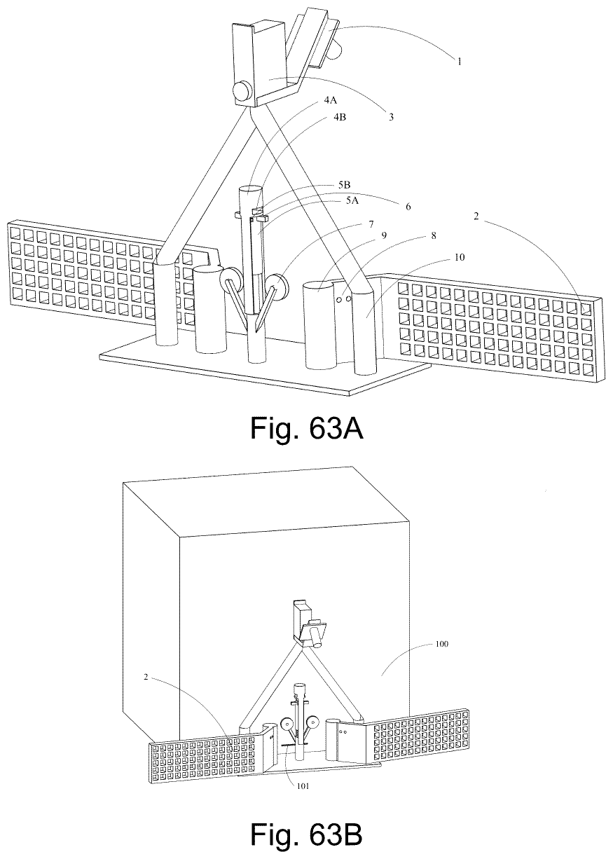

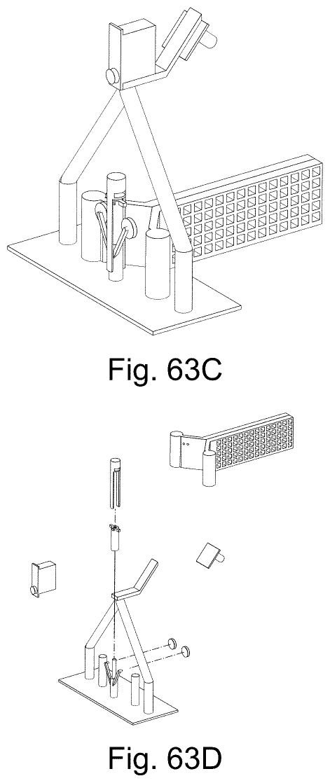

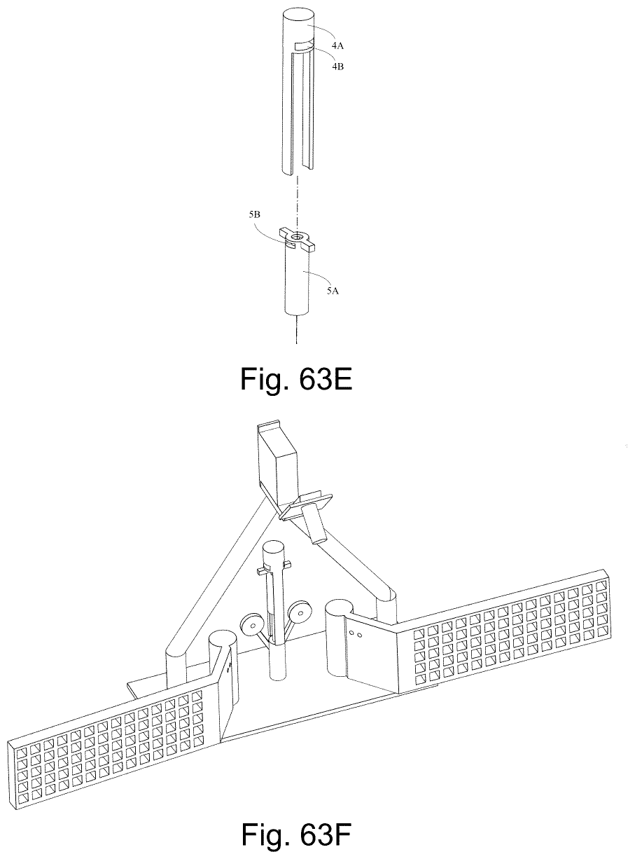

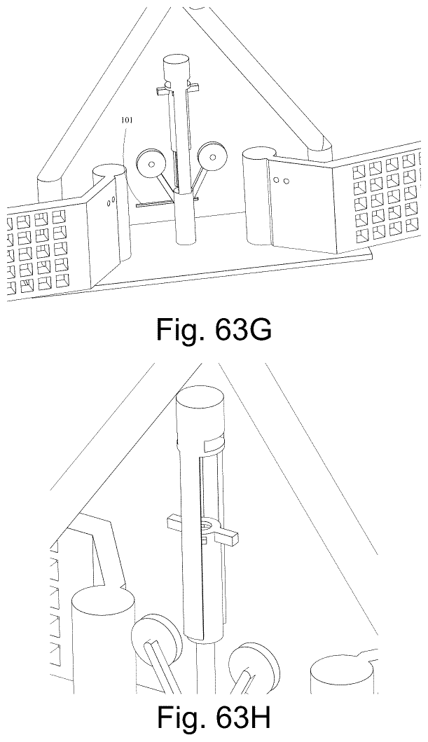

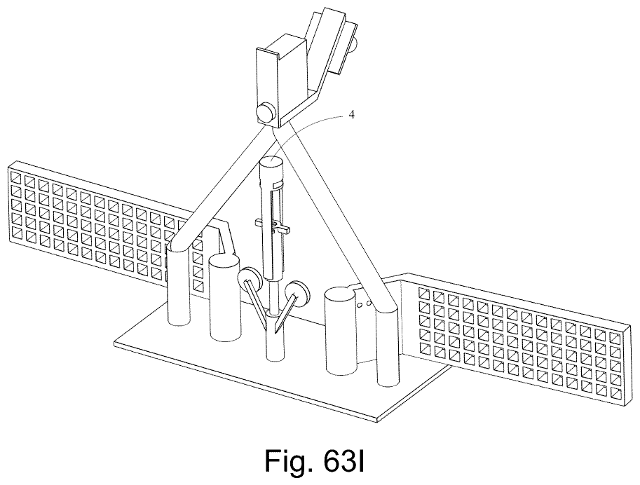

One example embodiment, shown in FIGS. 63A to 63I, will now be described:

The system may comprise two Strike Arms (2) positioned on opposite sides of an Entrance Zone (101) of a Hive Housing (100).

Each strike arm (2) is biased toward a closed position by an Elastic Return Element, such as a rubber band, of which one end is attached to a Cable Attachment Aperture (8) on the strike arm and the other end is fixed to a Rubber Anchor Point (10) on the housing.

The arms (2) are held in an open position by a Cable System routed over a Cable Guide Pulley (7). Each cable has one end connected to a Cable Attachment Aperture (8) on a corresponding strike arm and its opposite end fixed to a Cable Anchor (6) on a Secondary Magnet Carriage (5A). When the magnet carriages are coupled, tension in the cable system counteracts the force of the elastic return elements, maintaining the strike arms (2) in the open or “armed” position.

The Secondary Magnet Carriage (5A) includes a Magnet Seat (5B), and a Primary Magnet Carriage (4A) includes a corresponding Magnet Seat (4B).

The two magnet carriages (4A, 5A) are arranged to slide coaxially within a set of Linear Guides, such as tubular sections configured to slide telescopically one within the other.

The carriages form a Magnetic Latch Assembly, wherein magnets located in the respective seats (4B, 5B) can magnetically couple or decouple depending on their relative position.

The Primary Magnet Carriage (4A) is actuated by an Actuator Module (3), for example Actuator Module (3) may be a servo with pulley, that pulls on a cable connected to 4A.

When the strike arms (2) are in the closed position and the secondary magnet carriage (5A) is in its lower position, the actuator (3) lowers the primary magnet carriage (4A) until the magnets couple. Subsequently, the actuator raises the coupled pair (4A+5A), thereby pulling on the cable system and opening the strike arms (2).

As the actuator continues to lift the carriages, the opposing tension exerted by the elastic return elements increases.

At a predetermined upper limit, the elastic return force exceeds the magnetic coupling force, causing automatic magnetic decoupling of the two carriages.

Upon decoupling, the cable tension is released, and the elastic return elements drive the strike arms (2) inward toward one another, performing a rapid closing motion to intercept the hornet.

The coupling state between the primary and secondary carriages may be detected electronically, for example by measuring electrical resistance or continuity between conductive sections located on the carriages (4A, 5A), or by other sensing means.

When a continuous-rotation servo is employed as the actuator (3), the system may determine, through a learning process, the duration and rotation speed required for the actuator to move from the point of magnetic coupling to the point of magnetic decoupling.

This learned timing allows a processing unit to command the actuator to stop rotation just before decoupling occurs, thereby maintaining the strike arms (2) in a stable armed state under tension, ready for activation.

The timing parameters can be updated adaptively based on operating conditions, servo wear, or temperature variations.

Note: FIG. 63A shows the system in armed state. 63C shows the system in disarmed state, with element 4 magnetically coupled to element 5. FIG. 63H show the system moments after the element 4 and 5 have decoupled . . . the arms have not yet closed.

### Remark 1—Low-Cost Actuation:

The magnetic latching mechanism allows the use of a slow or highly geared servo, since high-speed response is not required for re-arming.

The rapid strike motion is produced entirely by the release of elastic energy stored in the return elements.

This enables the use of low-cost servos or gear motors with modest torque and speed ratings, improving system affordability and robustness.

### Remark 2—Fixed Mechanical Decoupling Point:

The decoupling point can alternatively be made mechanically fixed by introducing a physical stop that limits the upward travel of the secondary magnet carriage (5A).

Such a stop may be implemented by (i) a structural limit on the strike arms (2), (ii) a protrusion or shoulder on the primary magnet carriage (4A), or (iii) a restraining cable connecting the primary magnet carriage (4A) to a mounting base, the cable reaching its maximum length in a fully stretched position.

This configuration defines a repeatable release point independent of servo timing, providing a purely mechanical calibration.

### Control Mechanism and Supporting Electronics:

The system may be powered either by a stand-alone power source or through a wired connection to the electrical grid.

In one embodiment, the unit includes an integrated solar panel for energy harvesting and a rechargeable battery that provides autonomous operation for extended periods.

Alternatively, power may be supplied through a low-voltage DC adapter or from a centralized hive-management power system.

A power management circuit regulates charging and discharging of the battery and distributes power to the detector, actuator, and control subsystems.

The Hornet Detector (1) may comprise one or more sensing modalities:
a camera configured to monitor visual activity near the Entrance Zone (101) of the Hive Housing (100),
a microphone configured to capture the acoustic signature of insects, or
a combination of both modalities for multimodal detection.

The system can operate in either a locally processed mode or a remotely processed mode:

### 1. Local Processing Mode

In this configuration, a local controller or microprocessor—for example, a low-power microcontroller or single-board computer—is mounted within the device housing. The local processor executes algorithms to analyze camera or microphone data, identify hornet presence, and generate control signals for the Actuator Module (3). The controller may implement frequency-domain analysis for acoustic detection, or motion-based and shape-based recognition for visual detection. This mode provides autonomous operation without network dependency.

### 2. Remote Processing Mode

In another embodiment, the raw or pre-filtered sensor data is transmitted to a remote processor or cloud-based AI system for analysis.

Transmission may occur via Wi-Fi, LoRa, cellular, or other wireless communication interfaces.

The remote processor performs detection and classification using advanced or shared computing resources and transmits actuator commands back to the local node.

This configuration allows removal of costly local AI hardware, thereby reducing the price of each field unit while leveraging centralized computation.

In hybrid implementations, low-level filtering and event detection occur locally, while complex recognition or adaptive learning tasks are handled remotely.

The communication subsystem may further allow firmware updates, status reporting, and coordination between multiple hive-protection units within a single apiary network.

A control unit interprets detection signals and issues activation commands to the actuator (3). Upon confirmation of a hornet detection event, the control unit energizes the actuator to perform the strike cycle as previously described.

After the strike, the control logic optionally initiates a re-arming sequence, records event data, and reports the activation to the remote monitoring interface.

Safety interlocks may inhibit activation when non-target objects (e.g., bees or human interference) are detected within the field of view.

### Variations

In alternative embodiments, the latching and energy-storage subsystems may adopt a variety of equivalent configurations that achieve the same functional outcome of holding the Strike Arms (2) in an armed state and releasing them rapidly upon command or threshold tension.

The latching mechanism may be magnetic, mechanical, or electromechanical in nature. Examples include a magnetic latch using permanent or electromagnets; a mechanical pawl-and-notch or pin-and-recess latch released by a solenoid or servo; a ball-detent arrangement configured to disengage when a defined tensile load is exceeded; a cam-lock or ratchet-release system; or an electromagnetic clutch that selectively couples or decouples the drive shaft of the actuator. In further embodiments, the latch may employ shape-memory, thermal, or centrifugal release elements, or a friction-based coupling tuned to slip at a predetermined load. Each configuration may optionally include an adjustable preload element to calibrate the release force.

The energy-storage component may comprise an elastic band, tension spring, torsion spring, compression spring, or pneumatic or magnetic spring, any of which may be arranged to store potential energy during re-arming and to release that energy during the strike event. Combinations of different elastic or spring types may be employed to tailor response speed and impact force.

The orientation and motion of the Strike Arms (2) are not limited to a lateral configuration. In some embodiments, the arms may close left-to-right across the hive entrance, while in others they may close in a top-to-bottom or scissor-like motion.

Alternatively, the arms may travel in a parallel sliding or guillotine-style path, maintaining a substantially constant inter-arm distance during motion.

Each motion geometry can be driven by the same cable-and-latch principle, adapted through pulleys or linkages to suit the desired closing direction.

Accordingly, the inventive concept encompasses any arrangement of arms, latching, and energy-storage means that together provide a low-power, re-armable striking mechanism for intercepting hornets or similar insects at a hive entrance.

Various refinements, alternatives, and applications of the foregoing embodiment may be described by the following itemized list, each of which is considered to fall within the general inventive concept and may be combined where technically feasible: Various refinements, alternatives, and applications of the foregoing embodiment may be described by the following itemized list, each of which is considered to fall within the general inventive concept and may be combined where technically feasible:

### Item 1.

A beehive protection device configured to protect a hive entrance from hornets, comprising:
at least one sensor selected from the group consisting of a camera, a microphone, or a combination thereof, configured to monitor activity proximate to a hive entrance; and
at least one movable interception element selected from the group consisting of a strike arm, flap, barrier, or equivalent member arranged to move across said hive entrance;
wherein signals from said sensor are utilized to determine the presence of a hornet, and upon such determination the interception element is caused to move so as to intercept, repel, or neutralize the hornet.

### Item 2.

The device of item 1, further comprising either
(a) a control unit configured to receive and process the sensor signals locally to detect the presence of a hornet and to issue actuator commands, or
(b) a transmission unit configured to transmit the sensor signals to a remote processor that performs the hornet-detection analysis and returns control commands to the device.

### Item 3.

The device of any preceding item, further comprising a potential-energy storage mechanism configured to store mechanical energy during an arming phase and to release said stored energy to drive movement of the interception element upon detection of a hornet,
wherein the stored potential energy provides at least a portion of the kinetic energy used to move the interception element.

### Item 4.

The device of item 3, wherein the potential-energy storage mechanism comprises an elastic element, spring, or tensioned member configured to bias the interception element toward a closed position.

### Item 5.

The device of item 3 or 4, further comprising a latching mechanism configured to maintain the interception element in an armed position against the bias of the potential-energy storage mechanism until release.

### Item 6.

The device of item 5, wherein the latching mechanism is magnetic, comprising at least one pair of magnets arranged to magnetically couple when in proximity and to decouple when the force applied by the potential-energy storage mechanism exceeds the magnetic coupling force.

### Item 7.

The device of item 5 or 6, wherein the latching mechanism is mechanical and comprises a pawl, pin, cam, or ball-detent arrangement configured to release the interception element upon reaching a predefined tension threshold.

### Item 8.

The device of any of items 3-7, wherein an actuator is configured to charge the potential-energy storage mechanism during the arming phase by moving the interception element into the armed position.

### Item 9.

The device of item 8, wherein the actuator is a servo motor, stepper motor, or solenoid.

### Item 10.

The device of item 8 or 9, wherein the actuator is driven by a low-speed or highly-geared motor such that the rapid closing motion of the interception element is achieved solely by release of the stored potential energy.

### Item 11.

The device of any of items 5-10, wherein the actuator controls a primary latch element movable relative to a secondary latch element, and the two latch elements are magnetically or mechanically coupled when in the armed state.

### Item 12.

The device of item 11, wherein the actuator performs a learned re-arming cycle, the duration and rotation speed of which are determined by a processing unit based on the time required for magnetic or mechanical decoupling, thereby allowing the actuator to stop rotation just before decoupling and maintain the interception element in an armed state.

### Item 13.

The device of any of items 5-12, further comprising a physical stop configured to limit travel of a latch or carriage element such that decoupling occurs at a fixed mechanical position.

### Item 14.

The device of any preceding item, wherein the interception element moves laterally, vertically, or in a scissor-like or parallel-sliding configuration relative to the hive entrance.

### Item 15.

The device of any preceding item, wherein the sensor comprises both a camera and a microphone, and signals from both sensors are analyzed jointly or sequentially to confirm hornet presence.

### Item 16.

The device of any preceding item, wherein the analysis of sensor signals is performed by a remote processor and transmitted control commands are received wirelessly by the device via Wi-Fi, LoRa, or cellular communication.

### Item 17.

The device of any preceding item, wherein power is supplied by a solar panel coupled to a rechargeable battery or by a wired power source.

### Item 18.

The device of any preceding item, further comprising a safety or presence-detection subsystem configured to inhibit activation of the interception element when non-target objects or humans are detected within a predefined safety zone.

### Item 19.

The device of any preceding item, wherein multiple such devices are networked and configured to communicate detection or activation events to a central hive-management system.

### Item 20.

The device of any preceding item, wherein the interception element, potential-energy storage mechanism, actuator, and sensor assembly are enclosed in a weather-resistant housing adapted for outdoor operation near a beehive.
University research: The Photonic insecticides research can be found under Cordis, and a EIC transition project funding request has been filed

The photonic insecticides project received EU funding and was researched by VUB. Details can be found in slides resulting from project 10.3030/101016665, subproject ID: P2024-47, funded under the parent project PhotonHub Europe, Department of Applied Physics and Photonics, Vrije Universiteit Brussel, Professor Wendy Meulebroeck (wendy.meulebroeck@vub.be). The results will be uploaded to Cordis or a similar platform.

The technology herein referred to as photonic insecticides is also described in international application PCT/BG2025/050006. The content of these slides is included to provide context, experimental observations, and economic considerations relevant to the invention, and is not intended to limit the scope of the claims.

Also, after showing preliminary result, on 17 September, an EIC Transition application was submitted, with a consortium that includes a world-leading optical company, further strengthening the technical and commercial feasibility of the photonic insecticides technology.
Proposal acronym: Photonicinsecticides
Proposal ID: 101286975 (internal reference number: SEP-211236763)
Call: HORIZON-EIC-2025-TRANSITIONOPEN
Type of action: HORIZON-EIC
Topic: IOR IZON-1C-2025-IRANSITIONOPEN
Call closure: 2025-09-17 17:00:00
Date of submission: 2025-09-17 16:55:55

1. A targeting system comprising physical and operational features suitable for integration with a mobile platform, the targeting system comprising:
a. a camera configured to capture image data of a surrounding environment;
b. a laser unit configured to emit a laser beam; and
c. a control unit operatively coupled to the camera and the laser unit, wherein the control unit is configured to:
i. analyze the image data to locate one or more target insects, and
ii. activate the laser unit to fire the laser beam when the beam is expected to intersect with an intended target insect;
and wherein the laser beam is a converging beam directed toward a focal point located at a predetermined distance from the system.

2. The targeting system of claim 1, wherein the laser unit comprises a diode laser.

3. The targeting system of claim 1, wherein the laser unit is configured to emit a laser beam having a wavelength selected to prevent penetration to the human retina.

4. The targeting system of claim 1, wherein the control unit is further configured to either detect the presence of a human within a predefined distance threshold, or receive a signal indicating such detection, and to inhibit activation of the laser unit upon such detection.

5. The targeting system of claim 1, wherein the laser beam is optically aligned with a central axis of the camera, such that the laser beam is emitted along the camera's line of sight.

6. The targeting system of claim 1, further comprising a second camera that is not optically aligned with the central axis of the first camera, and that is configured with a wider field of view than the first camera.

7. The targeting system of claim 1, further comprising a movable mirror operatively coupled to the laser unit and configured to steer the laser beam toward a target.

8. The targeting system of claim 4, wherein the movable mirror comprises a microelectromechanical system (MEMS) device.

9. A system mounted on a mobile platform, the system comprising:
a. a mobility system comprising at least one propulsion mechanism selected from the group consisting of a wheel, a motorized leg, a water propeller, an air propeller, and an ion thruster; and
b. a targeting system according to claim 1.

10. A system mounted on a mobile platform, the system comprising:
a. a mobility system comprising at least one propulsion mechanism selected from the group consisting of a wheel, a motorized leg, a water propeller, an air propeller, and an ion thruster;
b. a camera configured to capture visual data representing the environment in proximity to the mobile platform;
c. a laser unit configured to emit a laser beam for use in neutralizing insects; and
d. a control unit operatively coupled to the camera and the laser unit, wherein the control unit is configured to:
i. analyze image data from the camera to detect the presence of a human within a predefined distance threshold; and
ii. inhibit activation of the laser unit upon detecting a human within said threshold.

11. A method for autonomous insect neutralization using a laser system mounted on a mobile platform, the method comprising:
a. locating an insect in the surrounding environment based on image data captured by at least one camera;
b. positioning a movable mirror to steer a laser beam toward the located insect;
c. verifying that one or more safety conditions are met, including confirming that no human is present within a nominal safety zone defined relative to the current optical path of the laser as reflected by the mirror;
d. activating a laser unit to emit a laser beam toward the insect and maintaining aim on the insect during emission; and
e. continuing movement of the mobile platform along a predetermined or dynamically generated path.

12. The method of claim 1, wherein the approximate location of the insect is determined in advance by a flying vehicle configured to scan an area using a camera system incorporating a field-of-view extending device, and wherein the resulting insect location data is used to guide or prioritize targeting actions performed by the mobile platform.

13. The system of claim 12, wherein the field-of-view extending device comprises one or more reflective optical elements arranged to redirect lateral light rays from regions outside the camera's native forward-facing field into unused pixel regions of the image sensor.

14. The system of claim 9, further comprising:
a. a flying vehicle configured to scan a target area using a camera system; and
b. a processing unit configured to detect and geolocate insects based on image data from the camera system,
wherein the control unit of the mobile neutralization platform is further configured to receive insect location data, either directly from the flying vehicle or indirectly via an intermediate communication node, and to navigate toward the identified insect locations while verifying one or more safety conditions prior to laser activation.

15. (canceled)

16. The system of claim 14, wherein the camera system comprises an event-based camera configured to output asynchronous image data representing changes in pixel intensity.

17. The system of claim 16, further comprising a field-of-view extending device operatively coupled to the camera system, the field-of-view extending device configured to redirect light from lateral or oblique angles into active sensing regions of the camera.

18. The system of claim 14, wherein the mobile platform is an aerial vehicle, comprising:
a. at least one propeller configured to provide aerial propulsion;
b. a battery unit configured to power the system; and
c. a battery housing assembly configured to contain the battery unit, wherein the battery housing assembly comprises one or more features that enable removal and replacement by an autonomous battery-swapping device.

19. The system of claim 18, wherein the battery-swapping device comprises:
a. a robotic platform configured to navigate to the flying system;
b. a robotic arm configured to reach the battery housing assembly from above, including via a vertically movable or articulated structure; and
c. a battery detachment mechanism comprising an end-effector configured to engage the battery housing assembly using either a mechanical clamp or an electromagnetic element.

20. The system of claim 14, wherein the mobile platform is an aerial vehicle, comprising:
a. at least one propeller configured to provide aerial propulsion;
b. a battery unit configured to power the system; and
c. a battery housing assembly configured to contain the battery unit, wherein the battery housing assembly comprises one or more features that enable removal and replacement by an autonomous battery-swapping device.
